(19) United States
(12) Patent Application Publication
(10) Pub. No.: US 2026/0215157 A1
(43) Pub. Date: Jul. 23, 2026

(54) LIGHT EMITTING ELEMENT, FUSED POLYCYCLIC COMPOUND FOR THE SAME, AND ELECTRONIC APPARATUS INCLUDING THE SAME

(71) Applicant: Samsung Display Co., Ltd., Yongin-si (KR)

(72) Inventors: Hirokazu KUWABARA, Yokohama-shi (JP); Keigo HOSHI, Yokohama-shi (JP)

(21) Appl. No.: 19/454,046

(22) Filed: Jan. 20, 2026

(30) Foreign Application Priority Data
Jan. 20, 2025 (JP) 2025-007562

(51) Int. Cl. H10K 85/60; C07F 5/02; C09K 11/06; H10K 50/11

(52) U.S. Cl. CPC H10K 85/658; C07F 5/02; C09K 11/06; H10K 85/6572; H10K 85/6574; H10K 85/6576; C09K 2211/1007; C09K 2211/1018; H10K 50/11

(57) ABSTRACT

A light emitting element includes a first electrode, a second electrode on the first electrode, and at least one functional layer between the first electrode and the second electrode and including a first compound represented by Formula 1.

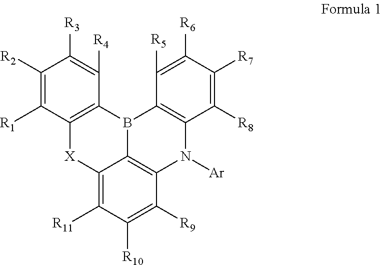

### CROSS-REFERENCE TO RELATED APPLICATION

The present application claims priority to and the benefit of Japanese Patent Application No. 2025-007562, filed on Jan. 20, 2025, in the Japan Patent Office, the entire content of which is incorporated herein by reference.

### BACKGROUND

### 1. Field

One or more embodiments of the present disclosure relate to a light emitting element, a fused polycyclic compound used for the light emitting element, and an electronic apparatus including the light emitting element.

### 2. Description of the Related Art

Recently, as image display devices, organic electroluminescence display devices have seen active development. The organic electroluminescence display devices are different from liquid crystal display devices and/or the like, and they are self-luminescent display devices in which display is implemented by recombining holes and electrons, separately injected from a first electrode and a second electrode, within an emission layer, to cause a light-emitting material containing an organic compound to emit light.

When applying organic electroluminescence elements to display devices, low driving voltage, high luminescence efficiency, and long lifespan are desired or required for the organic electroluminescence elements, and thus there is continuing demand or desire for the development of materials for the organic electroluminescence elements that may stably achieve such characteristics.

For example, to implement organic electroluminescence elements with high efficiency, technologies related to phosphorescence emission that utilizes triplet state energy, and/or technologies related to fluorescence emission that utilizes triplet-triplet annihilation (TTA), a phenomenon in which a singlet exciton is created by collision of triplet excitons, have been explored and developed. For instance, development of thermally activated delayed fluorescence (TADF) materials, which use a delayed fluorescence phenomenon, has been actively pursued.

### SUMMARY

One or more aspects of embodiments of the present disclosure are directed toward a light emitting element with improved element lifespan.

One or more aspects of embodiments of the present disclosure are related toward a fused polycyclic compound capable of improving the element lifespan of a light emitting element.

One or more aspects of embodiments of the present disclosure are directed toward an electronic apparatus that has excellent or suitable display quality by including the light emitting element with improved lifespan.

Additional aspects will be set forth in part in the description which follows and, in part, will be apparent from the description, or may be learned by practice of the presented embodiments.

According to one or more embodiments of the present disclosure, a light emitting element includes a first electrode, a second electrode on (e.g., arranged on) the first electrode, and at least one functional layer between (e.g., arranged between) the first electrode and the second electrode and containing a first compound represented by Formula 1,

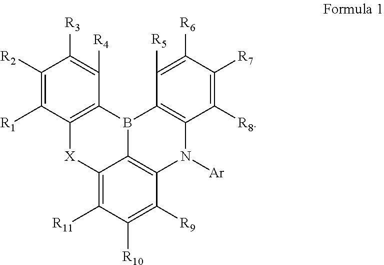

In Formula 1, X may be O, S, or NR₁₂, R₁ to R₁₁ may each independently be hydrogen, deuterium, a halogen, a cyano group, a hydroxyl group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, R₁₂ may be a substituted or unsubstituted aryl group having 6 to 30 ring-forming carbon atoms or a substituted or unsubstituted heteroaryl group having 2 to 30 ring-forming carbon atoms, and in the case where (e.g., when) R₁₂ is a substituted or unsubstituted heteroaryl group having 2 to 30 ring-forming carbon atoms, R₁₂ may include less than 2 (e.g., one) of any one selected from among a dibenzofuran moiety, a dibenzothiophene moiety, and a carbazole moiety, for example, R₁₂ may not include two or more of any one selected from among a dibenzofuran moiety, a dibenzothiophene moiety, and a carbazole moiety, and Ar is a substituent represented by Formula 2.

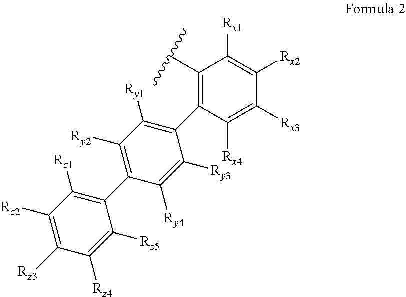

In Formula 2, Rₓ₁ to Rₓ₄ may each independently be hydrogen, deuterium, a halogen, a cyano group, a hydroxyl group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, at least one selected from among Rₓ₁ to Rₓ₃ may be a substituted or unsubstituted aryl group having 6 to 30 ring-forming carbon atoms or a substituted or unsubstituted heteroaryl group having 2 to 30 ring-forming carbon atoms, R_{y1} to R_{y4} and R_{z1} to R_{z5} may each independently be hydrogen, deuterium, a halogen, a cyano group, a hydroxyl group, a substituted or unsubstituted oxy group, a substituted or unsubstituted thio group, a substituted or unsubstituted boron group, a substituted or unsubstituted silyl group, a substituted or unsubstituted amine group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, a substituted or unsubstituted heteroaryl group having 2 to 30 ring-forming carbon atoms, and/or bonded to an adjacent group to form a ring, and

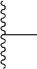

is a position to be connected to Formula 1.

In one or more embodiments, the at least one functional group may include an emission layer, a hole transport region between (e.g., arranged between) the first electrode and the emission layer, and an electron transport region between (e.g., arranged between) the emission layer and the second electrode, and the emission layer may include the first compound.

In one or more embodiments, the emission layer may be to emit delayed fluorescence with a central emission wavelength (e.g., emission peak wavelength) of about 430 nanometers (nm) to about 490 nm.

In one or more embodiments, Rₓ₁ to Rₓ₄ may each independently be hydrogen, deuterium, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and at least one selected from among Rₓ₁ to Rₓ₃ may be a substituent represented by any one selected from among Formula 3-1 to Formula 3-4.

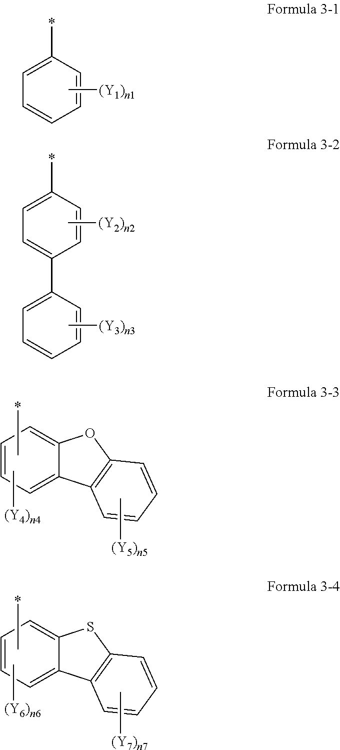

In Formula 3-1 to Formula 3-4, Y₁ to Y₇ may each independently be hydrogen, deuterium, a halogen, a cyano group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, n1 and n3 may each independently be an integer of 0 or greater and 5 or less, n2, n5, and n7 may each independently be an integer of 0 or greater and 4 or less, n4 and n6 may each independently be an integer of 0 or greater and 3 or less, and *— is a position to be connected to Formula 2.

In one or more embodiments, any one selected from among Rₓ₁ to Rₓ₃ may be a substituent represented by any one selected from among Formula 3-1 to Formula 3-4, and the rest of Rₓ₁ to Rₓ₃ may be hydrogen, deuterium, or an unsubstituted t-butyl group.

In one or more embodiments, the substituent represented by Formula 2 may be represented by any one selected from among Formula 2-1 to Formula 2-3.

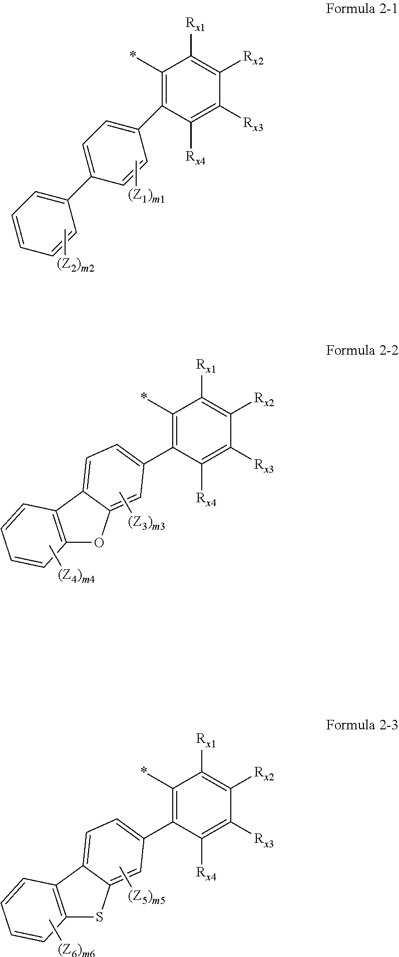

1 In Formula 2-1 to Formula 2-3, Z₁ to Z₆ may each independently be hydrogen, deuterium, a halogen, a cyano group, or a substituted or unsubstituted alkyl group having 1 to 10 carbon atoms, m1, m4, and m6 may each independently be an integer of 0 or greater and 4 or less, m2 may be an integer of 0 or greater and 5 or less, m3 and m5 may each independently be an integer of 0 or greater and 3 or less, and Rₓ₁ to Rₓ₄ may be each the same as defined in Formula 2.

In one or more embodiments, the first compound represented by Formula 1 may include at least one selected from among compounds of Compound Group 1 provided elsewhere herein.

According to one or more embodiments of the present disclosure, a fused polycyclic compound is represented by Formula 1.

According to one or more embodiments of the present disclosure, a display device includes a base layer, a circuit layer on (e.g., arranged on) the base layer, and a display element layer on (e.g., arranged on) the circuit layer and containing a light emitting element, and the light emitting element includes a first electrode, a second electrode on (e.g., arranged on) the first electrode, and an emission layer between (e.g., arranged between) the first electrode and the second electrode, and containing a first compound represented by Formula 1.

For example, in one or more embodiments, a light emitting element includes a first electrode, a second electrode arranged on the first electrode, and at least one functional layer arranged between them, where an emission layer includes a fused polycyclic first compound represented by Formula 1. In Formula 1, X is O, S, or NR₁₂; R₁-R₁₂ are each independently selected as defined herein (e.g., aryl groups having 6 to 30 ring-forming carbon atoms or heteroaryl groups having 2 to 30 ring-forming carbon atoms); and Ar is a substituent represented by Formula 2. At least one of Rₓ₁-Rₓ₃ may be an aryl or heteroaryl substituent (e.g., as in Formula 3-1 to 3-4), and any hydrogen is optionally substituted with deuterium, as described. The emission layer may emit delayed fluorescence (e.g., TADF) with a central emission wavelength of about 430 to about 490 nm and a full width at half maximum of about 10 nm to about 50 nm (e.g., about 20 nm to about 40 nm), thereby contributing to improved luminous efficiency and element lifespan. The first compound may be utilized alone or in combination with host and sensitizer systems, including hole-transporting hosts (e.g., Formula HT-1), electron-transporting hosts (e.g., Formula ET-1), and optional sensitizers (e.g., Formula D-1), and may include particular species disclosed in Compound Group 1. In one or more embodiments, a display device includes a base layer, a circuit layer on the base layer, and a display element layer containing the light emitting element, and an electronic apparatus includes at least one such display device, for example, televisions, monitors, outdoor billboards, personal computers, laptop computers, portable electronic devices, vehicular displays (including clusters, head-up displays, center information displays, and side-view displays), game consoles, and cameras, each benefiting from the improved stability, color purity, and lifetime characteristics provided by the fused polycyclic compounds described herein.

### BRIEF DESCRIPTION OF THE DRAWINGS

The accompanying drawings are included to provide a further understanding of the disclosure, and are incorporated in and constitute a part of this disclosure. The drawings illustrate embodiments of the present disclosure and, together with the description, serve to explain principles of the disclosure. Above and/or other aspects of the disclosure should become apparent and appreciated from the following description of embodiments taken in conjunction with the accompanying drawings. In the drawings:

FIG. 1 is a plan view of a display device according to one or more embodiments of the present disclosure;

FIG. 2 is a cross-sectional view of a display device according to one or more embodiments of the present disclosure;

FIG. 3 is a cross-sectional view schematically illustrating a light emitting element according to one or more embodiments of the present disclosure;

FIG. 4 is a cross-sectional view schematically illustrating a light emitting element according to one or more embodiments of the present disclosure;

FIG. 5 is a cross-sectional view schematically illustrating a light emitting element according to one or more embodiments of the present disclosure;

FIG. 6 is a cross-sectional view schematically illustrating a light emitting element according to one or more embodiments of the present disclosure;

FIGS. 7 and 8 are cross-sectional views each illustrating a display device according to one or more embodiments of the present disclosure;

FIG. 9 is a cross-sectional view of a display device according to one or more embodiments of the present disclosure;

FIG. 10 is a cross-sectional view of a display device according to one or more embodiments of the present disclosure;

FIG. 11 is a drawing illustrating a vehicle in which a display device according to one or more embodiments of the present disclosure is arranged; and

FIG. 12 is a graph showing the lowest singlet exciton energy level and the lowest triplet exciton energy level of each of light emitting elements respectively including example compounds and comparative example compounds as a dopant material according to one or more embodiments of the present disclosure. The vertical axis represents energy level in eV, and the horizontal axis represents the type of substituent.

### DETAILED DESCRIPTION

The disclosure may be modified in one or more suitable manners and have many forms, and thus specific/example embodiments will be exemplified in the drawings and described in more detail in the detailed description of the disclosure. It should be understood, however, that it is not intended to limit the disclosure to the particular forms disclosed, but rather, is intended to cover all modifications, equivalents, and alternatives falling within the spirit and scope of the disclosure.

When explaining each of drawings, like reference numbers are used for referring to like elements. In the accompanying drawings, the dimensions of each structure may be exaggeratingly illustrated for clarity of the present disclosure. It will be understood that, although the terms “first,” “second,” and/or the like, may be used herein to describe one or more suitable components, these components should not be limited by these terms. These terms are only used to distinguish one component from another. For example, a first component could be termed a second component, and, similarly, a second component could be termed a first component, without departing from the scope of example embodiments of the disclosure. As used herein, the singular forms, “a,” “an,” “one,” and “the” are intended to include the plural forms as well, unless the context clearly indicates otherwise. Further, the utilization of “may” when describing embodiments of the present disclosure refers to “one or more embodiments of the present disclosure”.

In the present disclosure, it will be understood that the terms “comprise(s)/comprising,” “include(s)/including,” “has (have)/having” and/or the like specify the presence of features, numbers, steps, operations, component, parts, or combinations thereof disclosed in the disclosure, but do not exclude the possibility of presence or addition of one or more other features, numbers, steps, operations, component, parts, or combinations thereof. Additionally, the terms “comprise(s)/comprising,” “include(s)/including,” “has (have)/having,” or other similar terms include or support the terms “consisting of” and “consisting essentially of,” indicating the presence of stated features, numbers, steps, operations, elements, and/or components, without or essentially without the presence of other features, numbers, steps, operations, elements, components, and/or groups thereof. As used herein, the terms “and,” “or,” and “and/or” may include any and all combinations of one or more of the associated listed items. Expressions such as “at least one of,” “one of,” and “selected from,” when preceding a list of elements, modify the entire list of elements and do not modify the individual elements of the list. For example, “at least one of a, b, or c,” “at least one selected from a, b, and c,” “at least one selected from among a to c,” and/or the like, may indicate only a, only b, only c, both (e.g., simultaneously) a and b, both (e.g., simultaneously) a and c, both (e.g., simultaneously) b and c, all of a, b, and c, or variations thereof. The “/” utilized herein may be interpreted as “and” or as “or” depending on the situation.

In the present disclosure, if (e.g., when) a layer, a film, a region, or a plate is referred to as being “on” or “in an upper portion of” another layer, film, region, or plate, it may be not only “directly on” the layer, film, region, or plate, but one or more intervening layers, films, regions, or plates may also be present therebetween. Opposite this, if (e.g., when) a layer, a film, a region, or a plate is referred to as being “below”, “in a lower portion of” another layer, film, region, or plate, it can be not only directly under the layer, film, region, or plate, but one or more intervening layers, films, regions, or plates may also be present therebetween. In addition, it will be understood that if (e.g., when) a part is referred to as being “on” another part, it may be arranged above the other part, or arranged under the other part as well. In contrast, “directly on” may refer to that there are no additional layers, films, regions, plates, etc., between a layer, a film, a region, a plate, etc. and the other part. For example, “directly on” may refer to two layers or two members are disposed without utilizing an additional member such as an adhesive member therebetween.

In the present disclosure, the term “substituted or unsubstituted” may refer to substituted or unsubstituted with at least one substituent selected from the group consisting of deuterium, a halogen, a cyano group, a nitro group, an amino group, a silyl group, an oxy group, a thio group, a sulfinyl group, a sulfonyl group, a carbonyl group, a boron group, a phosphine oxide group, a phosphine sulfide group, an alkyl group, an alkenyl group, an alkynyl group, a hydrocarbon ring group, an aryl group, and a heterocyclic group. In addition, each of the substituents exemplified above may be substituted or unsubstituted. For example, a biphenyl group may be interpreted as an aryl group or a phenyl group substituted with a phenyl group.

In the present disclosure, the phrase “bonded to an adjacent group to form a ring” may refer to that a group is bonded to an adjacent group to form a substituted or unsubstituted hydrocarbon ring or a substituted or unsubstituted heterocycle. The hydrocarbon ring includes an aliphatic hydrocarbon ring and/or an aromatic hydrocarbon ring. The heterocycle includes an aliphatic heterocycle and/or an aromatic heterocycle. The hydrocarbon ring and the heterocycle may each be monocyclic or polycyclic. In addition, the rings formed by adjacent groups being bonded to each other may be connected to another ring to form a spiro structure.

In the present disclosure, the term “adjacent group” may refer to a substituent substituted for an atom which is directly linked to an atom substituted with a corresponding substituent, another substituent substituted for an atom which is substituted with a corresponding substituent, or a substituent sterically positioned at the nearest position to a corresponding substituent. For example, two methyl groups in 1,2-dimethylbenzene may be interpreted as “adjacent groups” to each other, and two ethyl groups in 1,1-diethylcyclopentane may be interpreted as “adjacent groups” to each other. In addition, two methyl groups in 4,5-dimethylphenanthrene may be interpreted as “adjacent groups” to each other.

In the present disclosure, examples of a halogen may include fluorine, chlorine, bromine, or iodine.

In the present disclosure, an alkyl group may be linear or branched. The number of carbons in the alkyl group may be 1 to 50, 1 to 30, 1 to 20, 1 to 10, or 1 to 6. Examples of the alkyl group may include a methyl group, an ethyl group, an n-propyl group, an isopropyl group, an n-butyl group, an s-butyl group, a t-butyl group, an i-butyl group, a 2-ethylbutyl group, a 3,3-dimethylbutyl group, an n-pentyl group, an i-pentyl group, a neopentyl group, a t-pentyl group, a 1-methylpentyl group, a 3-methylpentyl group, a 2-ethylpentyl group, a 4-methyl-2-pentyl group, an n-hexyl group, a 1-methylhexyl group, a 2-ethylhexyl group, a 2-butylhexyl group, an n-heptyl group, a 1-methylheptyl group, a 2,2-dimethylheptyl group, a 2-ethylheptyl group, a 2-butylheptyl group, an n-octyl group, a t-octyl group, a 2-ethyloctyl group, a 2-butyloctyl group, a 2-hexyloctyl group, a 3,7-dimethyloctyl group, an n-nonyl group, an n-decyl group, a 2-ethyldecyl group, a 2-butyldecyl group, a 2-hexyldecyl group, a 2-octyldecyl group, an n-undecyl group, an n-dodecyl group, a 2-ethyldodecyl group, a 2-butyldodecyl group, a 2-hexyldocecyl group, a 2-octyldodecyl group, an n-tridecyl group, an n-tetradecyl group, an n-pentadecyl group, an n-hexadecyl group, a 2-ethylhexadecyl group, a 2-butylhexadecyl group, a 2-hexylhexadecyl group, a 2-octylhexadecyl group, an n-heptadecyl group, an n-octadecyl group, an n-nonadecyl group, an n-eicosyl group, a 2-ethyleicosyl group, a 2-butyleicosyl group, a 2-hexyleicosyl group, a 2-octyleicosyl group, an n-henicosyl group, an n-docosyl group, an n-tricosyl group, an n-tetracosyl group, an n-pentacosyl group, an n-hexacosyl group, an n-heptacosyl group, an n-octacosyl group, an n-nonacosyl group, an n-triacontyl group, and/or the like, but embodiments of the present disclosure are not limited thereto.

In the present disclosure, a cycloalkyl group may refer to a cyclic alkyl group. The number of carbons in the cycloalkyl group may be 3 to 50, 3 to 30, 3 to 20, or 3 to 10. Examples of the cycloalkyl group may include a cyclopropyl group, a cyclobutyl group, a cyclopentyl group, a cyclohexyl group, a 4-methylcyclohexyl group, a 4-t-butylcyclohexyl group, a cycloheptyl group, a cyclooctyl group, a cyclononyl group, a cyclodecyl group, a norbornyl group, a 1-adamantyl group, a 2-adamantyl group, an isobornyl group, a bicycloheptyl group, and/or the like, but embodiments of the present disclosure are not limited thereto.

In the present disclosure, an alkenyl group refers to a hydrocarbon group including at least one carbon-carbon double bond in the middle or terminal of an alkyl group having 2 or more carbon atoms. The alkenyl group may be linear or branched. The number of carbon atoms in the alkenyl group is not specifically limited, for example, may be 2 to 30, 2 to 20, or 2 to 10. Examples of the alkenyl group include a vinyl group, a 1-butenyl group, a 1-pentenyl group, a 1,3-butadienyl aryl group, a styrenyl group, a styryl vinyl group, and/or the like, but embodiments of the present disclosure are not limited thereto.

In the present disclosure, an alkynyl group refers to a hydrocarbon group including at least one carbon-carbon triple bond in the middle or terminal of an alkyl group having 2 or more carbon atoms. The alkynyl group may be linear or branched. Although the number of carbon atoms is not specifically limited, it may be 2 to 30, 2 to 20, or 2 to 10. Examples of the alkynyl group may include an ethynyl group, a propynyl group, and/or the like, but embodiments of the present disclosure are not limited thereto.

In the present disclosure, a hydrocarbon ring group refers to any functional group or substituent derived from an aliphatic hydrocarbon ring. The hydrocarbon ring group may be a saturated hydrocarbon ring group having 5 to 20 ring-forming carbon atoms.

In the present disclosure, an aryl group refers to any functional group or substituent derived from an aromatic hydrocarbon ring. The aryl group may be a monocyclic aryl group or a polycyclic aryl group. The number of ring-forming carbon atoms in the aryl group may be 6 to 30, 6 to 20, or 6 to 15. Examples of the aryl group may include a phenyl group, a naphthyl group, a fluorenyl group, an anthracenyl group, a phenanthryl group, a biphenylyl group, a terphenylyl group, a quaterphenyl group, a quinquephenyl group, a sexiphenyl group, a triphenylenyl group, a pyrenyl group, a benzofluoranthenyl group, a chrysenyl group, and/or the like, but embodiments of the present disclosure are not limited thereto.

In the present disclosure, a fluorenyl group may be substituted, and two substituents may be bonded to each other to form a spiro structure. Examples of the substituted fluorenyl group are as follows. However, embodiments of the present disclosure are not limited thereto.

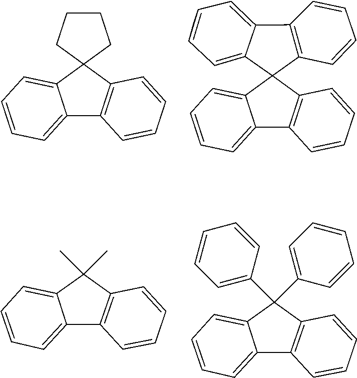

A heterocyclic group herein refers to any functional group or substituent derived from a ring containing at least one of B, O, N, P, Si, or Se as a heteroatom. The heterocyclic group may include an aliphatic heterocyclic group and/or an aromatic heterocyclic group. The aromatic heterocyclic group may be a heteroaryl group. The aliphatic heterocycle and the aromatic heterocycle may each be monocyclic or polycyclic.

In the present disclosure, the heterocyclic group may contain at least one of B, O, N, P, Si, or S as a heteroatom. If (e.g., when) the heterocyclic group contains two or more heteroatoms, the two or more heteroatoms may be the same as or different from each other. The heterocyclic group may be a monocyclic heterocyclic group or a polycyclic heterocyclic group, and includes a heteroaryl group. The number of ring-forming carbon atoms in the heterocyclic group may be 2 to 30, 2 to 20, or 2 to 10.

In the present disclosure, an aliphatic heterocyclic group may include at least one of B, O, N, P, Si, or S as a heteroatom. The number of ring-forming carbon atoms in the aliphatic heterocyclic group may be 2 to 30, 2 to 20, or 2 to 10. Examples of the aliphatic heterocyclic group may include an oxirane group, a thiirane group, a pyrrolidine group, a piperidine group, a tetrahydrofuran group, a tetrahydrothiophene group, a thiane group, a tetrahydropyran group, a 1,4-dioxane group, and/or the like, but embodiments of the present disclosure are not limited thereto.

In the present disclosure, a heteroaryl group may contain at least one of B, O, N, P, Si, or S as a heteroatom. If (e.g., when) the heteroaryl group contains two or more heteroatoms, the two or more heteroatoms may be the same as or different from each other. The heteroaryl group may be a monocyclic heterocyclic group or a polycyclic heterocyclic group. The number of ring-forming carbon atoms in the heteroaryl group may be 2 to 30, 2 to 20, or 2 to 10. Examples of the heteroaryl group may include a thiophene group, a furan group, a pyrrole group, an imidazole group, a pyridine group, a bipyridine group, a pyrimidine group, a triazine group, a triazole group, an acridyl group, a pyridazine group, a pyrazinyl group, a quinoline group, a quinazoline group, a quinoxaline group, a phenoxazine group, a phthalazine group, a pyrido pyrimidine group, a pyrido pyrazine group, a pyrazino pyrazine group, an isoquinoline group, an indole group, a carbazole group, an N-arylcarbazole group, an N-heteroarylcarbazole group, an N-alkylcarbazole group, a benzoxazole group, a benzimidazole group, a benzothiazole group, a benzocarbazole group, a benzothiophene group, a dibenzothiophene group, a thienothiophene group, a benzofuran group, a phenanthroline group, a thiazole group, an isoxazole group, an oxazole group, an oxadiazole group, a thiadiazole group, a phenothiazine group, a dibenzosilole group, a dibenzofuran group, and/or the like, but embodiments of the present disclosure are not limited thereto.

In the present disclosure, the above description of the aryl group may be applied to an arylene group except that the arylene group is a divalent group. The above description of the heteroaryl group may be applied to a heteroarylene group except that the heteroarylene group is a divalent group.

In the present disclosure, a silyl group may include an alkylsilyl group and/or an arylsilyl group. Examples of the silyl group may include a trimethylsilyl group, a triethylsilyl group, a t-butyldimethylsilyl group, a vinyldimethylsilyl group, a propyldimethylsilyl group, a triphenylsilyl group, a diphenylsilyl group, a phenylsilyl group, and/or the like, but embodiments of the present disclosure are not limited thereto.

In the present disclosure, the number of carbon atoms in a carbonyl group is not specifically limited, but may be 1 to 40, 1 to 30, or 1 to 20. For example, the carbonyl group may have the following structures, but embodiments of the present disclosure are not limited thereto.

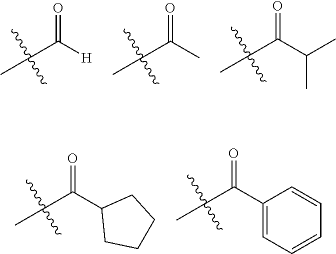

In the present disclosure, the number of carbon atoms in a sulfinyl group or a sulfonyl group is not particularly limited, for example, may be 1 to 30. The sulfinyl group may include an alkyl sulfinyl group and/or an aryl sulfinyl group. The sulfonyl group may include an alkyl sulfonyl group and/or an aryl sulfonyl group.

In the present disclosure, a thio group may include an alkylthio group and/or an arylthio group. The thio group may refer to that a sulfur atom is bonded to the alkyl group or the aryl group defined above. Examples of the thio group may include a methylthio group, an ethylthio group, a propylthio group, a pentylthio group, a hexylthio group, an octylthio group, a dodecylthio group, a cyclopentylthio group, a cyclohexylthio group, a phenylthio group, a naphthylthio group, but embodiments of the present disclosure are not limited thereto.

In the present disclosure, an oxy group may refer to that an oxygen atom is bonded to the alkyl group or the aryl group defined above. The oxy group may include an alkoxy group and/or an aryl oxy group. The alkoxy group may be a linear chain, a branched chain, or a ring chain. The number of carbon atoms in the alkoxy group is not specifically limited, but may be, for example, 1 to 20 or 1 to 10. Examples of the oxy group may include methoxy, ethoxy, n-propoxy, isopropoxy, butoxy, pentyloxy, hexyloxy, octyloxy, nonyloxy, decyloxy, benzyloxy, and/or the like, but embodiments of the present disclosure are not limited thereto.

A boron group as used herein may refer to that a boron atom is bonded to the alkyl group or the aryl group defined above. The boron group may include an alkyl boron group and/or an aryl boron group. Examples of the boron group may include a dimethylboron group, a diethylboron group, a t-butylmethylboron group, a diphenylboron group, a phenylboron group, and/or the like, but embodiments of the present disclosure are not limited thereto.

In the present disclosure, the number of carbon atoms in an amine group is not specifically limited, for example, may be 1 to 30. The amine group may include an alkyl amine group and/or an aryl amine group. Examples of the amine group may include a methylamine group, a dimethylamine group, a phenylamine group, a diphenylamine group, a naphthylamine group, a 9-methyl-anthracenylamine group, and/or the like, but embodiments of the present disclosure are not limited thereto. In the present disclosure, the term “amine group” is used interchangeably with the term “amino group.”

In the present disclosure, the alkyl group among an alkylthio group, an alkylsulfoxy group, an alkylaryl group, an alkylamino group, an alkyl boron group, an alkyl silyl group, and an alkyl amine group may be the same as the examples of the alkyl group described above.

In the present disclosure, the aryl group among an aryloxy group, an arylthio group, an arylsulfoxy group, an arylamino group, an arylboron group, an arylsilyl group, an arylamine group may be the same as the examples of the aryl group described above.

In the present disclosure, a direct linkage may refer to a single bond.

In the disclosure,

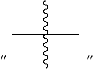

and “ [symbol] ” each refer to a position to be connected.

Hereinafter, example embodiments of the present disclosure will be described with reference to the accompanying drawings. In the present disclosure, the term “display device” may be used interchangeably with “display apparatus,” and the term “light emitting element” may be utilized interchangeably with the term “light emitting device.”

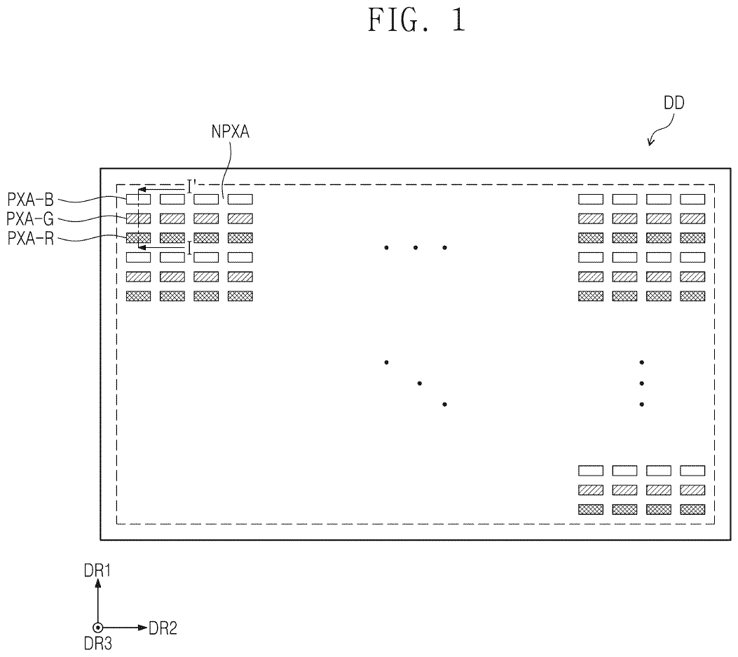

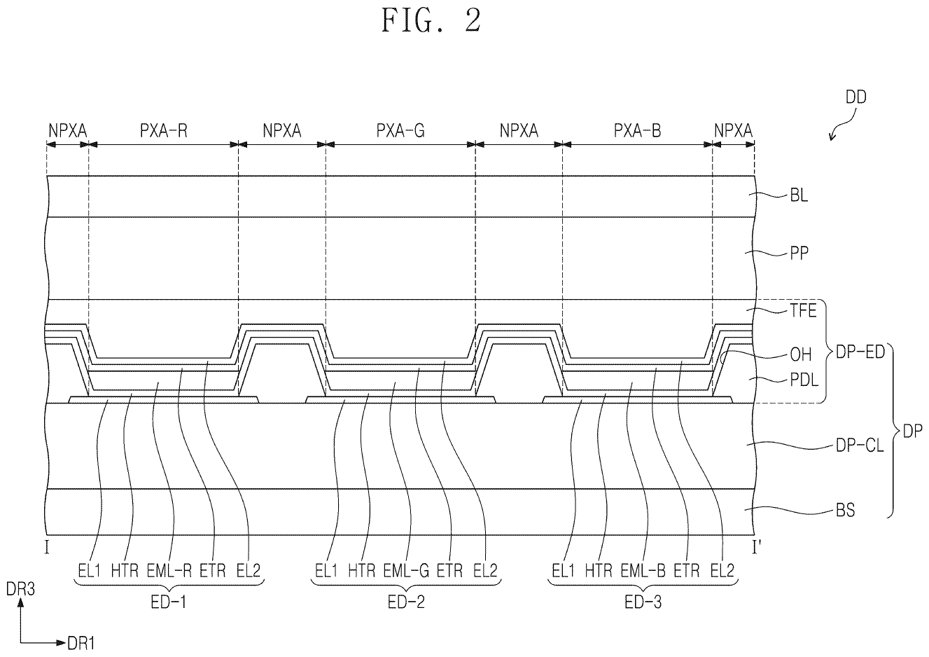

FIG. 1 is a plan view illustrating an embodiment of a display device DD according to one or more embodiments of the present disclosure. FIG. 2 is a cross-sectional view of the display device DD according to one or more embodiments. FIG. 2 is a cross-sectional view illustrating a part taken along the line I-I′ of the display device DD of FIG. 1.

The display device DD may include a display panel DP and an optical layer PP arranged on the display panel DP. The display panel DP may include light emitting elements ED-1, ED-2, and ED-3. The display device DD may include a plurality of light emitting elements ED-1, ED-2, and ED-3. The optical layer PP may be arranged on the display panel DP to control reflected light in the display panel DP due to external light. The optical layer PP may include, for example, a polarization layer and/or a color filter layer. In one or more embodiments, the optical layer PP may not be provided in the display device DD.

A base substrate BL may be arranged on the optical layer PP. The base substrate BL may be a member which provides a base surface on which the optical layer PP arranged. The base substrate BL may be a glass substrate, a metal substrate, a plastic substrate, and/or the like. However, embodiments of the present disclosure are not limited thereto, and the base substrate BL may be an inorganic layer, an organic layer, or a composite material layer. In one or more embodiments, the base substrate BL may not be provided.

The display device DD according to one or more embodiments may further include a filling layer. The filling layer may be arranged between a display element layer DP-ED and the base substrate BL. The filling layer may be an organic material layer. The filling layer may include at least one of an acrylic-based resin, a silicone-based resin, or an epoxy-based resin.

The display panel DP may include a base layer BS, a circuit layer DP-CL provided on the base layer BS, and the display element layer (also referred as display device layer) DP-ED. The display element layer DP-ED may include a pixel defining film PDL, the light emitting elements ED-1, ED-2, and ED-3 arranged between respective portions of the pixel defining film PDL, and an encapsulation layer TFE arranged on the light emitting elements ED-1, ED-2, and ED-3.

The base layer BS may be a member which provides a base surface on which the display element layer DP-ED is arranged. The base layer BS may be a glass substrate, a metal substrate, a plastic substrate, and/or the like. However, embodiments of the present disclosure are not limited thereto, and the base layer BS may be an inorganic layer, an organic layer, or a composite material layer.

In one or more embodiments, the circuit layer DP-CL is arranged on the base layer BS, and the circuit layer DP-CL may include a plurality of transistors. Each of the transistors may include a control electrode, an input electrode, and an output electrode. For example, in one or more embodiments, the circuit layer DP-CL may include switching transistor(s) and driving transistor(s) for driving the light emitting elements ED-1, ED-2, and ED-3 of the display element layer DP-ED.

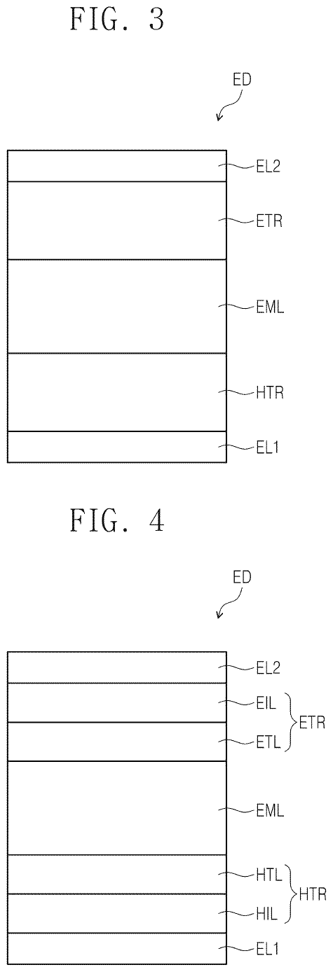

Each of the light emitting elements ED-1, ED-2, and ED-3 may have a structure of one of light emitting elements ED of embodiments according to FIG. 3 to 6, which will be described later. Each of the light emitting elements ED-1, ED-2, and ED-3 may include a first electrode EL1, a hole transport region HTR, respective emission layer EML-R, EML-G, or EML-B, an electron transport region ETR, and a second electrode EL2.

FIG. 2 illustrates an embodiment in which the respective emission layers EML-R, EML-G, and EML-B of the light emitting elements ED-1, ED-2, and ED-3 are arranged in openings OH defined in the pixel defining film PDL, and the hole transport region HTR, the electron transport region ETR, and the second electrode EL2 are each provided as a common layer in the entire light emitting elements ED-1, ED-2, and ED-3. However, embodiments of the present disclosure are not limited thereto, for example, in one or more embodiments, the hole transport region HTR and the electron transport region ETR may each be provided by being patterned inside the openings OH defined in the pixel defining film PDL. For example, in one or more embodiments, the hole transport region HTR, the respective emission layers EML-R, EML-G, and EML-B, and the electron transport region ETR of the light emitting elements ED-1, ED-2, and ED-3 may be provided by being patterned in an inkjet printing method.

The encapsulation layer TFE may cover the light emitting elements ED-1, ED-2, and ED-3. The encapsulation layer TFE may seal the display element layer DP-ED. The encapsulation layer TFE may be a thin film encapsulation layer. The encapsulation layer TFE may be formed by laminating one layer or a plurality of layers. The encapsulation layer TFE may include at least one insulation layer. The encapsulation layer TFE according to one or more embodiments may include at least one inorganic film (hereinafter, an encapsulation-inorganic film). The encapsulation layer TFE according to one or more embodiments may include at least one organic film (hereinafter, an encapsulation-organic film) and at least one encapsulation-inorganic film.

The encapsulation-inorganic film protects the display element layer DP-ED from moisture/oxygen, and the encapsulation-organic film protects the display element layer DP-ED from foreign substances such as dust particles. The encapsulation-inorganic film may include silicon nitride, silicon oxynitride, silicon oxide, titanium oxide, aluminum oxide, and/or the like, but embodiments of the present disclosure are not particularly limited thereto. The encapsulation-organic film may include an acrylic-based compound, an epoxy-based compound, and/or the like. In one or more embodiments, the encapsulation-organic film may include a photopolymerizable organic material, but embodiments of the present disclosure are not particularly limited thereto.

The encapsulation layer TFE may be arranged on the second electrode EL2 and may be arranged filling the opening OH.

Referring to FIG. 1 and FIG. 2, the display device DD may include a non-light emitting region NPXA and light emitting regions PXA-R, PXA-G, and PXA-B. The light emitting regions PXA-R, PXA-G, and PXA-B may be regions in which light generated by the respective light emitting elements ED-1, ED-2, and ED-3 is emitted. The light emitting regions PXA-R, PXA-G, and PXA-B may be spaced and/or apart (e.g., spaced apart or separated) from one another on a plane (e.g., in plan view).

Each of the light emitting regions PXA-R, PXA-G, and PXA-B may be a region divided by the pixel defining film PDL. The non-light emitting region NPXA may be areas between the adjacent light emitting regions PXA-R, PXA-G, and PXA-B, which correspond to the pixel defining film PDL. In one or more embodiments, the light emitting regions PXA-R, PXA-G, and PXA-B may respectively correspond to pixels. The pixel defining film PDL may divide the light emitting elements ED-1, ED-2, and ED-3. The respective emission layers EML-R, EML-G, and EML-B of the light emitting elements ED-1, ED-2, and ED-3 may be arranged in the openings OH defined in the pixel defining film PDL and separated from one another.

The light emitting regions PXA-R, PXA-G, and PXA-B may be divided into a plurality of groups according to the color of light generated from the light emitting elements ED-1, ED-2, and ED-3. In the display device DD of one or more embodiments illustrated in FIG. 1 and FIG. 2, three light emitting regions PXA-R, PXA-G, and PXA-B, which emit red color light, green color light, and blue color light, respectively, are illustrated as an example. For example, the display device DD of one or more embodiments may include a red light emitting region PXA-R, a green light emitting region PXA-G, and a blue light emitting region PXA-B that are separated from one another.

In the display device DD according to one or more embodiments, the plurality of light emitting elements ED-1, ED-2, and ED-3 may be to emit light beams having wavelengths different from one another. For example, in one or more embodiments, the display device DD may include a first light emitting element ED-1 that emits red color light, a second light emitting element ED-2 that emits green color light, and a third light emitting element ED-3 that emits blue color light. For example, the red light emitting region PXA-R, the green light emitting region PXA-G, and the blue light emitting region PXA-B of the display device DD may correspond to the first light emitting element ED-1, the second light emitting element ED-2, and the third light emitting element ED-3, respectively.

However, embodiments of the present disclosure are not limited thereto, and the first to third light emitting elements ED-1, ED-2, and ED-3 may be to emit light beams in substantially the same wavelength range or at least one light emitting element may be to emit a light beam in a wavelength range different from the others. For example, in one or more embodiments, the first to third light emitting elements ED-1, ED-2, and ED-3 may all emit blue color light.

The light emitting regions PXA-R, PXA-G, and PXA-B in the display device DD according to one or more embodiments may be arranged in a stripe form. Referring to FIG. 1, a plurality of red light emitting regions PXA-R may be arranged with each other along a second direction axis DR2, a plurality of green light emitting regions PXA-G may be arranged with each other along the second direction axis DR2, and the plurality of blue light emitting regions PXA-B may be arranged with each other along the second direction axis DR2. In addition, the red light emitting region PXA-R, the green light emitting region PXA-G, and the blue light emitting region PXA-B may be alternately arranged in this order along a first direction axis DR1.

FIG. 1 and FIG. 2 illustrate that all the light emitting regions PXA-R, PXA-G, and PXA-B have similar area, but embodiments of the present disclosure are not limited thereto. Thus, the light emitting regions PXA-R, PXA-G, and PXA-B may have different areas from each other according to the wavelength range of the emitted light. In this regard, the areas of the light emitting regions PXA-R, PXA-G, and PXA-B may refer to areas if (e.g., when) viewed on a plane defined by the first direction axis DR1 and the second direction axis DR2 (e.g., the areas in plan view).

An arrangement form of the light emitting regions PXA-R, PXA-G, and PXA-B is not limited to the configuration illustrated in FIG. 1, and the order in which the red light emitting region PXA-R, the green light emitting region PXA-G, and the blue light emitting region PXA-B are arranged may be provided in one or more suitable combinations according to the characteristics of display quality desired or required in the display device DD. For example, in one or more embodiments, the arrangement form of the light emitting regions PXA-R, PXA-G, and PXA-B may be a pentile (PENTILE®) arrangement form (for example, an RGBG matrix, an RGBG structure, or an RGBG matrix structure) or a diamond (Diamond Pixel™) arrangement form. (e.g., a display (e.g., an OLED display) containing red, blue, and green (RGB) light-emitting regions arranged in the shape of diamonds). PENTILE® is a duly registered trademark of Samsung Display Co., Ltd. Diamond Pixel™ is a trademark of Samsung Display Co., Ltd.

In one or more embodiments, the areas of the light emitting regions PXA-R, PXA-G, and PXA-B may be different from each other. For example, in one or more embodiments, the area of the green light emitting region PXA-G may be smaller than that of the blue light emitting region PXA-B, but embodiments of the present disclosure are not limited thereto.

Hereinafter, FIG. 3 to FIG. 6 are cross-sectional views each schematically showing a light emitting element according to one or more embodiments of the present disclosure. A light emitting element ED of one or more embodiments may include a first electrode EL1, a hole transport region HTR, an emission layer EML, an electron transport region ETR, and a second electrode EL2 stacked in order.

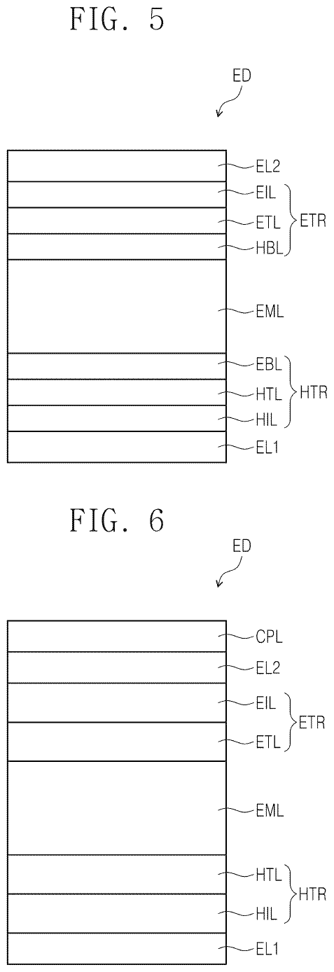

Compared with FIG. 3, FIG. 4 illustrates a cross-sectional view of a light emitting element ED of one or more embodiments, in which a hole transport region HTR includes a hole injection layer HIL and a hole transport layer HTL, and an electron transport region ETR includes an electron injection layer EIL and an electron transport layer ETL. In addition, compared with FIG. 3, FIG. 5 illustrates a cross-sectional view of a light emitting element ED of one or more embodiments, in which a hole transport region HTR includes a hole injection layer HIL, a hole transport layer HTL, and an electron blocking layer EBL, and an electron transport region ETR includes an electron injection layer EIL, an electron transport layer ETL, and a hole blocking layer HBL. Compared with FIG. 4, FIG. 6 illustrates a cross-sectional view of a light emitting element ED of one or more embodiments including a capping layer CPL arranged on a second electrode EL2.

The light emitting element ED according to one or more embodiments may include a fused polycyclic compound according to one or more embodiments of the present disclosure, which will be described in more detail later, in at least one functional layer included in the light emitting element ED. In the light emitting element ED according to one or more embodiments, the fused polycyclic compound according to one or more embodiments may be included in at least one of the hole transport region HTR, the emission layer EML, or the electron transport region ETR. For example, in the light emitting element ED according to one or more embodiments, the emission layer EML may include the fused polycyclic compound according to one or more embodiments.

The first electrode EL1 has conductivity (e.g., is a conductor). The first electrode EL1 may be formed of a metal material, a metal alloy, and/or a conductive compound. The first electrode EL1 may be an anode or a cathode. However, embodiments of the present disclosure are not limited thereto. In one or more embodiments, the first electrode EL1 may be a pixel electrode. The first electrode EL1 may be a transmissive electrode, a transflective electrode, or a reflective electrode. The first electrode EL1 may include at least one selected from among silver (Ag), magnesium (Mg), copper (Cu), aluminum (Al), platinum (Pt), palladium (Pd), gold (Au), nickel (Ni), neodymium (Nd), iridium (Ir), chromium (Cr), lithium (Li), calcium (Ca), lithium fluoride (LiF), molybdenum (Mo), titanium (Ti), tungsten (W) indium (In), tin (Sn), and zinc (Zn), a compound of two or more selected therefrom, a mixture of two or more selected therefrom, or an oxide thereof.

If (e.g., when) the first electrode EL1 is a transmissive electrode, the first electrode EL1 may include a transparent metal oxide such as indium tin oxide (ITO), indium zinc oxide (IZO), zinc oxide (ZnO), and/or indium tin zinc oxide (ITZO). If (e.g., when) the first electrode EL1 is a transflective electrode or a reflective electrode, the first electrode EL1 may include Ag, Mg, Cu, Al, Pt, Pd, Au, Ni, Nd, Ir, Cr, Li, Ca, LiF/Ca (a stacked structure of LiF and Ca), LiF/Al (a stacked structure of LiF and Al), Mo, Ti, W, a compound thereof, or a mixture thereof (e.g., a mixture of Ag and Mg). In one or more embodiments, the first electrode EL1 may have a multilayer structure including a reflective film or a transflective film formed of one or more of the above-described materials, and a transparent conductive film formed of ITO, IZO, ZnO, ITZO, and/or the like. For example, in one or more embodiments, the first electrode EL1 may have a three-layer structure of ITO/Ag/ITO, but embodiments of the present disclosure are not limited thereto. In one or more embodiments, the first electrode EL1 may include one of the above-described metal materials, a combination of at least two metal materials of the above-described metal materials, an oxide of the above-described metal materials, and/or the like. A thickness of the first electrode EL1 may be from about 700 ångström (Å) to about 10,000 Å. For example, in one or more embodiments, the thickness of the first electrode EL1 may be from about 1,000 Å to about 3,000 Å.

The hole transport region HTR is provided on the first electrode EL1. The hole transport region HTR may include at least one of a hole injection layer HIL, a hole transport layer HTL, a buffer layer or an emission-auxiliary layer, or an electron blocking layer EBL. A thickness of the hole transport region HTR may be, for example, from about 50 Å to about 15,000 Å.

The hole transport region HTR may have a single layer formed of a single material, a single layer formed of a plurality of different materials, or a multilayer structure including a plurality of layers formed of a plurality of different materials.

For example, in one or more embodiments, the hole transport region HTR may have a single layer structure of a hole injection layer HIL or a hole transport layer HTL, or may have a single layer structure formed of a hole injection material and/or a hole transport material. In one or more, the hole transport region HTR may have a single layer structure formed of a plurality of different materials, or a structure in which a hole injection layer HIL/hole transport layer HTL, a hole injection layer HIL/hole transport layer HTL/buffer layer, a hole injection layer HIL/buffer layer, a hole transport layer HTL/buffer layer, or a hole injection layer HIL/hole transport layer HTL/electron blocking layer EBL are stacked in order (e.g., in the stated order) from the first electrode EL1, but embodiments of the present disclosure are not limited thereto.

The hole transport region HTR may be formed using one or more suitable methods such as a vacuum deposition method, a spin coating method, a casting method, a Langmuir-Blodgett (LB) method, an inkjet printing method, a laser printing method, and/or a laser induced thermal imaging (LITI) method.

In one or more embodiments, the hole transport region HTR may include a compound represented by Formula H-1:

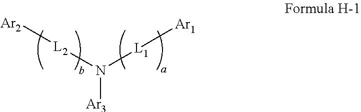

In Formula H-1, L₁ and L₂ may each independently be a direct linkage, a substituted or unsubstituted arylene group having 6 to 30 ring-forming carbon atoms, or a substituted or unsubstituted heteroarylene group having 2 to 30 ring-forming carbon atoms. a and b may each independently be an integer of 0 to 10. If (e.g., when) a and/or b are each an integer of 2 or greater, a plurality of L₁'s and/or a plurality of L₂'s may each independently be a substituted or unsubstituted arylene group having 6 to 30 ring-forming carbon atoms or a substituted or unsubstituted heteroarylene group having 2 to 30 ring-forming carbon atoms.

In Formula H-1, Ar₁ and Ar₂ may each independently be a substituted or unsubstituted aryl group having 6 to 30 ring-forming carbon atoms or a substituted or unsubstituted heteroaryl group having 2 to 30 ring-forming carbon atoms. In addition, in Formula H-1, Ar₃ may be a substituted or unsubstituted aryl group having 6 to 30 ring-forming carbon atoms or a substituted or unsubstituted heteroaryl group having 2 to 30 ring-forming carbon atoms.

In one or more embodiments, the compound represented by Formula H-1 may be a monoamine compound. In one or more embodiments, the compound represented by Formula H-2 may be a diamine compound in which at least one selected from among Ar₁ to Ar₃ includes an amine group as a substituent. In one or more embodiments, the compound represented by Formula H-1 may be a carbazole-based compound including a substituted or unsubstituted carbazole group in at least one of Ar₁ or Ar₂, or a fluorene-based compound including a substituted or unsubstituted fluorene group in at least one of Ar₁ or Ar₂.

The compound represented by Formula H-1 may be any one selected from among compounds in Compound Group H. However, the compounds listed in Compound Group H are mere examples, and the compounds represented by Formula H-1 are not limited to those represented by Compound Group H:

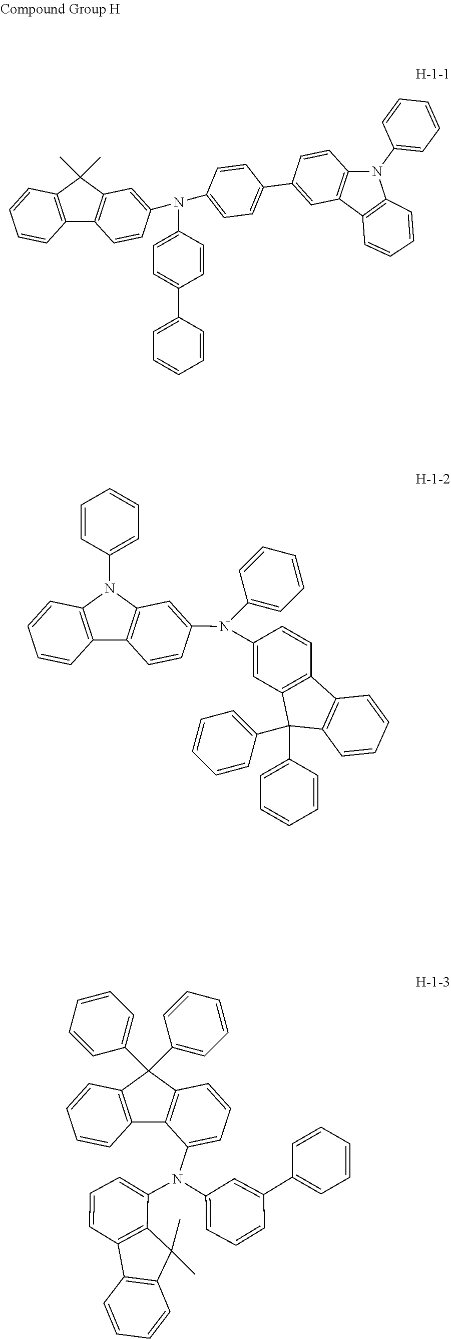 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(N(c2ccc3c(c2)C(c2ccccc2)(c2ccccc2)c2ccccc2-3)c2ccc3c4ccccc4n(-c4ccccc4)c3c2)cc1 ; CC1(C)c2ccccc2-c2cccc(N(c3cccc(-c4ccccc4)c3)c3cccc4c3-c3ccccc3C4(c3ccccc3)c3ccccc3)c21]

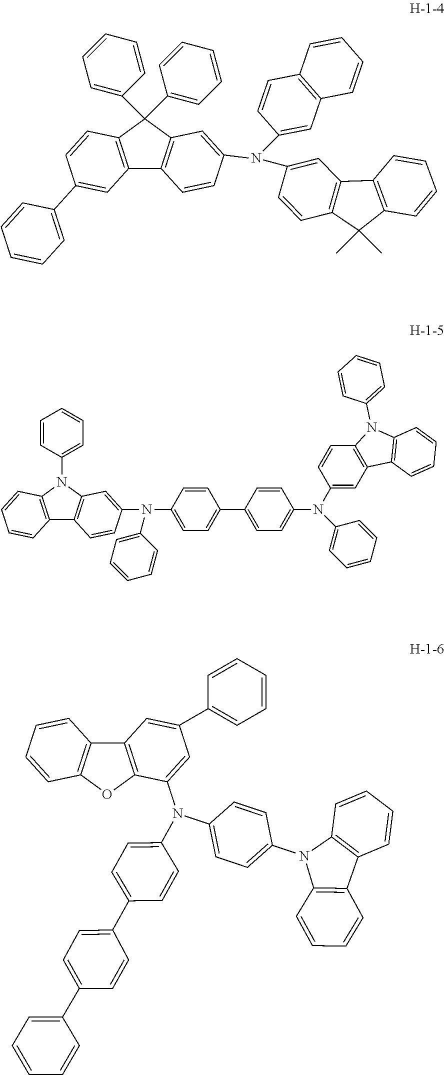 [SMILES: CC1(C)c2ccccc2-c2cc(N(c3ccc4c(c3)C(c3ccccc3)(c3ccccc3)c3ccc(-c5ccccc5)cc3-4)c3ccc4ccccc4c3)ccc21 ; c1ccc(N(c2ccc(-c3ccc(N(c4ccccc4)c4ccc5c6ccccc6n(-c6ccccc6)c5c4)cc3)cc2)c2ccc3c(c2)c2ccccc2n3-c2ccccc2)cc1 ; c1ccc(-c2ccc(-c3ccc(N(c4ccc(-n5c6ccccc6c6ccccc65)cc4)c4cc(-c5ccccc5)cc5c4oc4ccccc45)cc3)cc2)cc1]

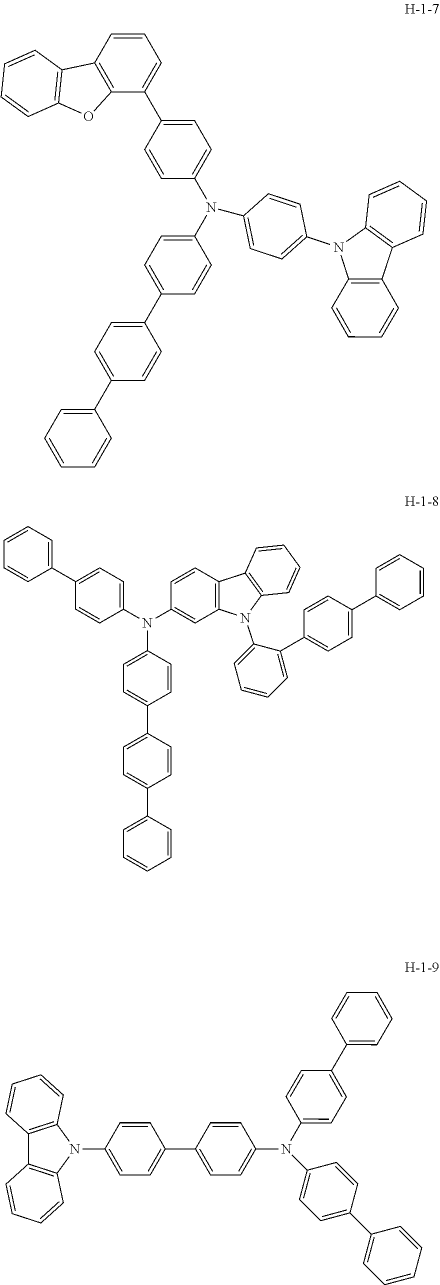 [SMILES: c1ccc(-c2ccc(-c3ccc(N(c4ccc(-c5cccc6c5oc5ccccc56)cc4)c4ccc(-n5c6ccccc6c6ccccc65)cc4)cc3)cc2)cc1 ; c1ccc(-c2ccc(-c3ccc(N(c4ccc(-c5ccccc5)cc4)c4ccc5c6ccccc6n(-c6ccccc6-c6ccc(-c7ccccc7)cc6)c5c4)cc3)cc2)cc1 ; c1ccc(-c2ccc(N(c3ccc(-c4ccccc4)cc3)c3ccc(-c4ccc(-n5c6ccccc6c6ccccc65)cc4)cc3)cc2)cc1]

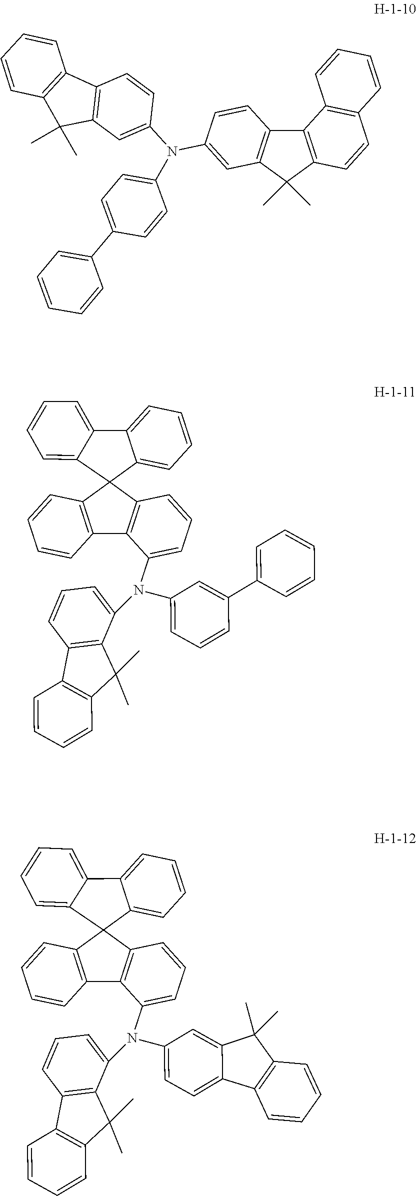 [SMILES: CC1(C)c2ccccc2-c2ccc(N(c3ccc(-c4ccccc4)cc3)c3ccc4c(c3)C(C)(C)c3ccc5ccccc5c3-4)cc21 ; CC1(C)c2ccccc2-c2cccc(N(c3cccc(-c4ccccc4)c3)c3cccc4c3-c3ccccc3C43c4ccccc4-c4ccccc43)c21 ; CC1(C)c2ccccc2-c2ccc(N(c3cccc4c3-c3ccccc3C43c4ccccc4-c4ccccc43)c3cccc4c3C(C)(C)c3ccccc3-4)cc21]

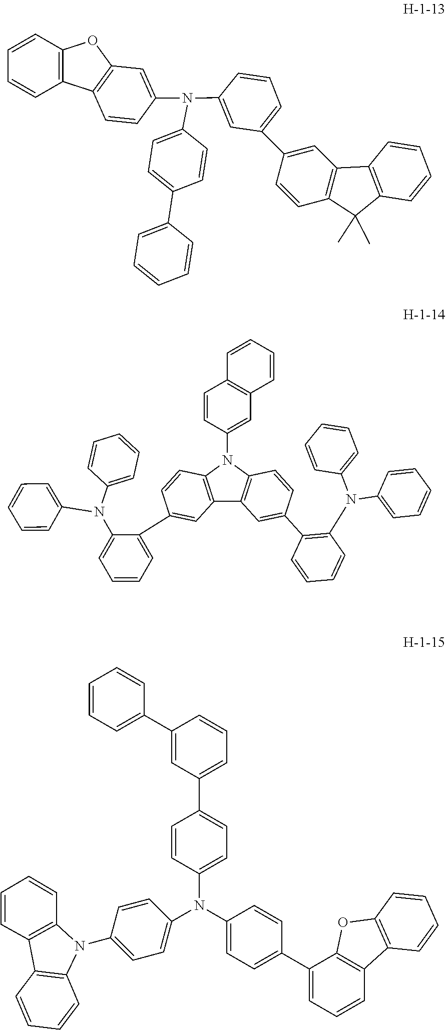 [SMILES: CC1(C)c2ccccc2-c2cc(-c3cccc(N(c4ccc(-c5ccccc5)cc4)c4ccc5c(c4)oc4ccccc45)c3)ccc21 ; c1ccc(N(c2ccccc2)c2ccccc2-c2ccc3c(c2)c2cc(-c4ccccc4N(c4ccccc4)c4ccccc4)ccc2n3-c2ccc3ccccc3c2)cc1 ; c1ccc(-c2cccc(-c3ccc(N(c4ccc(-c5cccc6c5oc5ccccc56)cc4)c4ccc(-n5c6ccccc6c6ccccc65)cc4)cc3)c2)cc1]

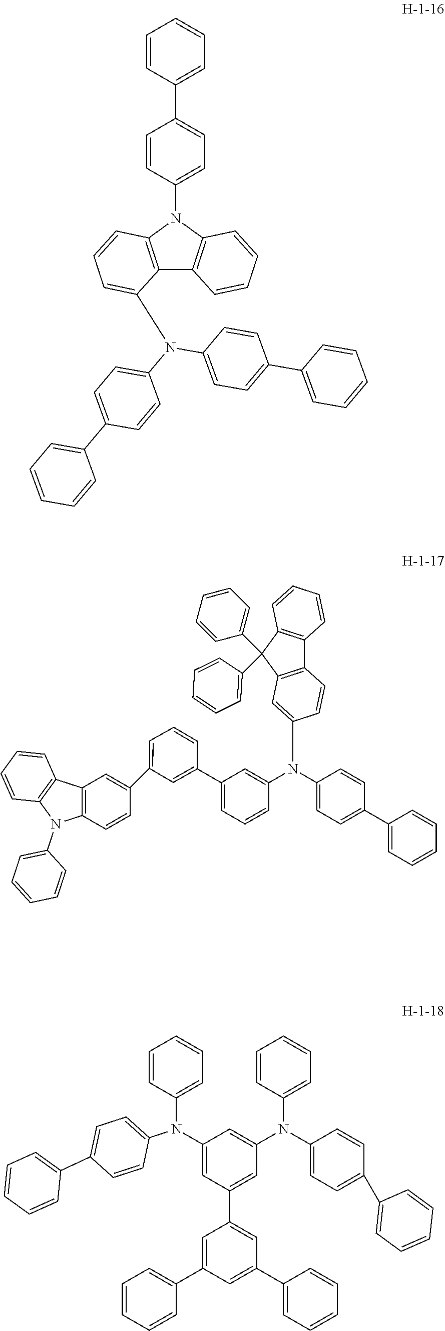 [SMILES: c1ccc(-c2ccc(N(c3ccc(-c4ccccc4)cc3)c3cccc4c3c3ccccc3n4-c3ccc(-c4ccccc4)cc3)cc2)cc1 ; c1ccc(-c2ccc(N(c3cccc(-c4cccc(-c5ccc6c(c5)c5ccccc5n6-c5ccccc5)c4)c3)c3ccc4c(c3)C(c3ccccc3)(c3ccccc3)c3ccccc3-4)cc2)cc1 ; c1ccc(-c2ccc(N(c3ccccc3)c3cc(-c4cc(-c5ccccc5)cc(-c5ccccc5)c4)cc(N(c4ccccc4)c4ccc(-c5ccccc5)cc4)c3)cc2)cc1]

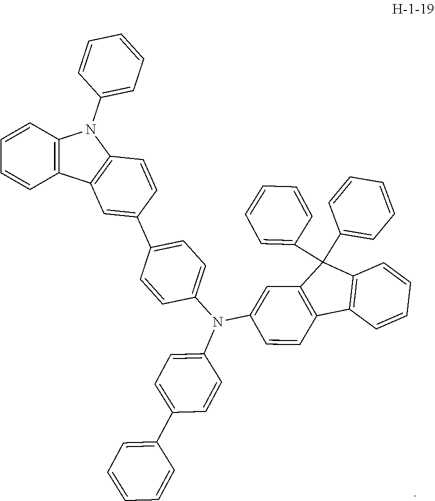 [SMILES: c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

In one or more embodiments, the hole transport region HTR may include one or more selected from among a phthalocyanine compound such as copper phthalocyanine; N¹,N¹′-([1,1′-biphenyl]-4,4′-diyl)bis(N¹-phenyl-N⁴,N⁴-di-m-tolylbenzene-1,4-diamine) (DNTPD), 4,4′,4″-[tris(3-methylphenyl)phenylamino]triphenylamine (m-MTDATA), 4,4′,4″-tris(N,N-diphenylamino)triphenylamine (TDATA), 4,4′,4″-tris[N (2-naphthyl)-N-phenylamino]-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonic acid (PANI/CSA), polyaniline/poly(4-styrenesulfonate) (PANI/PSS), N,N′-di(naphthalen-1-yl)-N,N′-diphenyl-benzidine (NPB), triphenylamine-containing polyetherketone (TPAPEK), 4-isopropyl-4′-methyldiphenyliodonium [tetrakis(pentafluorophenyl) borate], dipyrazino[2,3-f:2′,3′-h]quinoxaline-2,3,6,7,10,11-hexacarbonitrile (HATCN), and/or the like.

In one or more embodiments, the hole transport region HTR may include one or more selected from among a carbazole-based derivative such as N-phenyl carbazole and/or polyvinyl carbazole, a fluorene-based derivative, a triphenylamine-based derivative such as N,N′-bis(3-methylphenyl)-N,N′-diphenyl-[1,1-biphenyl]-4,4′-diamine (TPD) and/or 4,4′,4″-tris(N-carbazolyl)triphenylamine (TCTA), N,N′-di(naphthalen-1-yl)-N,N′-diphenyl-benzidine (NPB), 4,4′-cyclohexylidene bis[N,N-bis(4-methylphenyl]benzenamine] (TAPC), 4,4′-bis[N,N′-(3-tolyl)amino]-3,3′-dimethylbiphenyl (HMTPD), 1,3-bis(N-carbazolyl)benzene (mCP), and/or the like.

In one or more embodiments, the hole transport region HTR may include one or more selected from among 9-(4-tert-butylphenyl)-3,6-bis(triphenylsilyl)-9H-carbazole (CzSi), 9-phenyl-9H-3,9′-bicarbazole (CCP), 1,3-bis(1,8-dimethyl-9H-carbazol-9-yl)benzene (mDCP), and/or the like.

The hole transport region HTR may include one or more of the above-described compounds of the hole transport region in at least one of a hole injection layer HIL, a hole transport layer HTL, or an electron blocking layer EBL.

A thickness of the hole transport region HTR may be from about 100 Å to about 10,000 Å, for example, from about 100 Å to about 5,000 Å. If (e.g., when) the hole transport region HTR includes a hole injection layer HIL, the hole injection layer HIL may have, for example, a thickness of about 30 Å to about 1,000 Å. If (e.g., when) the hole transport region HTR includes a hole transport layer HTL, the hole transport layer HTL may have a thickness of about 250 Å to about 1,000 Å. For example, if (e.g., when) the hole transport region HTR includes an electron blocking layer EBL, the electron blocking layer EBL may have a thickness of about 10 Å to about 1,000 Å. If (e.g., when) the thicknesses of the hole transport region HTR, the hole injection layer HIL, the hole transport layer HTL and the electron blocking layer EBL satisfy the above-described respective ranges, satisfactory hole transport properties may be achieved without a substantial increase in driving voltage.

In one or more embodiments, the hole transport region HTR may further include a charge generating material to increase conductivity (e.g., electric conductivity) in addition to the above-described materials. The charge generating material may be dispersed uniformly (e.g., substantially uniformly) or non-uniformly in the hole transport region HTR. The charge generating material may be, for example, a p-dopant. The p-dopant may include at least one of a halogenated metal compound (e.g., metal halide), a quinone derivative, a metal oxide, or a cyano group-containing compound, but embodiments of the present disclosure are not limited thereto. For example, in one or more embodiments, the p-dopant may include a metal halide compound such as CuI and/or RbI, a quinone derivative such as tetracyanoquinodimethane (TCNQ) and/or 2,3,5,6-tetrafluoro-7,7,8,8-tetracyanoquinodimethane (F4-TCNQ), a metal oxide such as tungsten oxide and/or molybdenum oxide, a cyano group-containing compound such as dipyrazino[2,3-f:2′,3′-h]quinoxaline-2,3,6,7,10,11-hexacarbonitrile (HATCN) and/or 4-[[2,3-bis[cyano-(4-cyano-2,3,5,6-tetrafluorophenyl)methylidene]cyclopropylidene]-cyanomethyl]-2,3,5,6-tetrafluorobenzonitrile (NDP9), and/or the like, but embodiments of the present disclosure are not limited thereto.

As described above, the hole transport region HTR may further include at least one of the buffer layer or the electron blocking layer EBL in addition to the hole injection layer HIL and the hole transport layer HTL. The buffer layer may compensate for a resonance distance according to the wavelength of light emitted from the emission layer EML and may thus increase light emission efficiency. A material that may be included in the hole transport region HTR may be used as a material to be included in the buffer layer. The electron blocking layer EBL is a layer that serves to prevent or reduce the electron injection from the electron transport region ETR to the hole transport region HTR.

The emission layer EML is provided onto the hole transport region HTR. The emission layer EML may have a thickness of, for example, about 100 Å to about 1000 Å, or about 100 Å to about 300 Å. The emission layer EML may have a single layer made of a single material, a single layer made of a plurality of different materials, or a multi-layer structure including a plurality of layers made of a plurality of different materials.

The light emitting element ED according to one or more embodiments may include a fused polycyclic compound represented by Formula 1 in at least one functional layer arranged between the first electrode EL1 and the second electrode EL2. In the light emitting element ED according to one or more embodiments, the emission layer EML may include the fused polycyclic compound according to one or more embodiments. In one or more embodiments, the emission layer EML may include the fused polycyclic compound as a dopant. The fused polycyclic compound according to one or more embodiments may be a dopant material of the emission layer EML. In this disclosure, the fused polycyclic compound according to one or more embodiments may be referred to as a first compound.

The fused polycyclic compound according to one or more embodiments includes a fused cyclic core with five rings being fused and containing one boron atom, one nitrogen atom, and one other hetero atom, and a first substituent connected to the fused cyclic core. In one or more embodiments, the fused cyclic core included in the fused polycyclic compound may have five rings formed by three substituted or unsubstituted benzene rings being connected through a first boron atom, a first nitrogen atom, and a first hetero atom. For example, the three benzene rings, included in the fused cyclic core, may be connected with respect to the first boron atom, a first benzene ring and a second benzene ring among the three benzene rings may be connected through the first hetero atom, and a remaining third benzene ring may be connected to the first benzene ring through the first nitrogen atom. The first boron atom, the first nitrogen atom, and the first hetero atom may be all connected to the first benzene ring. In one or more embodiments, the first hetero atom may be an oxygen (O) atom, a sulfur(S) atom, or a nitrogen (N) atom.

The fused polycyclic compound according to one or more embodiments may include a first substituent connected to the fused cyclic core. The first substituent may be connected to the first nitrogen atom. The first substituent may have a structure in which a first benzene moiety connected to the first nitrogen atom is included, and a first sub substituent and a second sub substituent are each connected to the first benzene moiety. The first sub substituent may include a second benzene moiety connected at an ortho position carbon with respect to a carbon atom connected to the first nitrogen atom among carbon atoms constituting the first benzene moiety, and a third benzene moiety connected at a para position carbon with respect to a carbon atom connected to the first benzene moiety among carbon atoms constituting the second benzene moiety. The first sub substituent may include a biphenyl moiety. In one or more embodiments, in the first sub substituent, the second benzene moiety and the third benzene moiety may form an addition ring by a second hetero atom. The second hetero atom may be an oxygen (O) atom or a sulfur(S) atom. The first sub substituent may include a dibenzofuran moiety or a dibenzothiophene moiety. The second sub substituent may be a substituted or unsubstituted aryl group having 6 to 30 ring-forming carbon atoms or a substituted or substituted heteroaryl group having 2 to 30 ring-forming carbon atoms. In one or more embodiments, the second sub substituent may be a substituted or unsubstituted phenyl group, a substituted or unsubstituted biphenyl group, a substituted or unsubstituted dibenzofuran group, or a substituted or unsubstituted dibenzothiophene group.

In embodiments in which the first hetero atom is a nitrogen atom in the fused cyclic core of the fused polycyclic compound according to one or more embodiments, the fused polycyclic compound according to one or more embodiments may include a second substituent connected to the first hetero atom. The second substituent may be a substituted or unsubstituted aryl group having 6 to 30 ring-forming carbon atoms or a substituted or substituted heteroaryl group having 2 to 30 ring-forming carbon atoms. In these embodiments, the second substituent may include no more than two of any one selected from among a dibenzofuran moiety, a dibenzothiophene moiety, and a carbazole moiety. For example, the second substituent may not include (e.g., may exclude) a 2-[3-(dibenzofuranphenyl-2-yl)phenyl]dibenzofuran group, or a 2-[3-dibenzothiophenyl-2-yl)phenyl]dibenzothiophene group.

The fused polycyclic compound according to one or more embodiments may be represented by Formula 1.

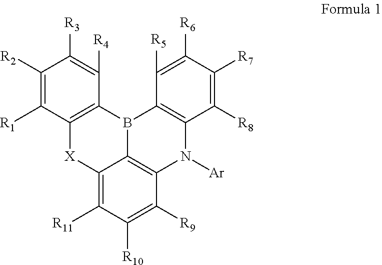

The fused polycyclic compound represented by Formula 1, according to one or more embodiments, may include a fused cyclic core which is formed by five rings fused with respect to a first boron atom, a first nitrogen atom, and a first hetero atom (denoted as X in Formula 1), and a first substituent (denoted as Ar in Formula 1) connected to the fused cyclic core.

In Formula 1, R₁ to R₁₁ may each independently be hydrogen, deuterium, a halogen, a cyano group, a hydroxyl group, a substituted or unsubstituted amine group, a substituted or unsubstituted alkyl group having 1 to 20 carbon atoms, a substituted or unsubstituted aryl group having 6 to 40 ring-forming carbon atoms, or a substituted or unsubstituted heteroaryl group having 2 to 40 ring-forming carbon atoms. For example, in one or more embodiments, R₁, R₄, R₅, R₈, R₉, and R₁₁ may each independently be hydrogen or deuterium, R₂, R₃, R₆, and R₇ may each independently be a substituted or unsubstituted t-butyl group, a substituted or unsubstituted phenyl group, or a substituted or unsubstituted carbazole group, and R₁₀ may be a substituted or unsubstituted t-butyl group or a substituted or unsubstituted phenyl group.

In Formula 1, X may be O, S, or NR₁₂.

In Formula 1, R₁₂ may be a substituted or unsubstituted aryl group having 6 to 30 ring-forming carbon atoms or a substituted or substituted heteroaryl group having 2 to 30 ring-forming carbon atoms. For example, in one or more embodiments, R₁₂ may be a substituted or unsubstituted m-terphenyl group. If (e.g., when) R₁₂ is a substituted or unsubstituted heteroaryl group having 2 to 30 ring-forming carbon atoms, R₁₂ may include less than 2 (e.g., one) of any one selected from among a dibenzofuran moiety, a dibenzothiophene moiety, and a carbazole moiety, for example, R₁₂ may not include two or more of any one selected from among a dibenzofuran moiety, a dibenzothiophene moiety, and a carbazole moiety. For example, in one or more embodiments, R₁₂ may include one of the dibenzofuran moiety, the dibenzothiophene moiety, and the carbazole moiety, but may include less than 2 (e.g., one) of any one selected from among the dibenzofuran moiety, the dibenzothiophene moiety, and the carbazole moiety. For example, R₁₂ may include less than 2 (e.g., one) of the dibenzofuran moiety, less than 2 (e.g., one) of the dibenzothiophene moiety, and/or less than 2 (e.g., one) of the carbazole moiety. In addition, R₁₂ may not correspond to a structure that includes the dibenzofuran moiety and the dibenzothiophene moiety together, may not correspond to a structure that includes the dibenzofuran moiety and the carbazole moiety together, and may not correspond to a structure that includes the dibenzothiophene moiety and the carbazole moiety together. For example, in one or more embodiments, R₁₂ may not include (e.g., may exclude) a 2-[3-(dibenzofuranphenyl-2-yl)phenyl]dibenzofuran group, or a 2-[3-dibenzothiophenyl-2-yl)phenyl]dibenzothiophene group.

In Formula 1, Ar is a substituent represented by Formula 2. In one or more embodiments, Ar may have the same structure as that of the substituent represented by R₁₂ previously described, or may have a different structure.

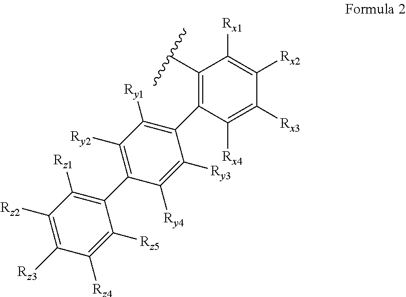

In Formula 2, Rₓ₁ to Rₓ₄ may each independently be hydrogen, deuterium, a halogen, a cyano group, a hydroxyl group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, in one or more embodiments, Rₓ₁ to Rₓ₄ may each independently be hydrogen, deuterium, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In Formula 2, at least one selected from among Rₓ₁ to Rₓ₃ is a substituted or unsubstituted aryl group having 6 to 30 ring-forming carbon atoms or a substituted or unsubstituted heteroaryl group having 2 to 30 ring-forming carbon atoms. For example, in one or more embodiments, one selected from among Rₓ₁ to Rₓ₃ may be a substituted or unsubstituted phenyl group, a substituted or unsubstituted biphenyl group, a substituted or unsubstituted dibenzofuran group, or a substituted or unsubstituted dibenzothiophene group, and the rest of Rₓ₁ to Rₓ₃ may be hydrogen, deuterium, or an unsubstituted t-butyl group.

In Formula 2, R_{y1} to R_{y4} and R_{z1} to R_{z5} may each independently be hydrogen, deuterium, a halogen, a cyano group, a hydroxyl group, a substituted or unsubstituted oxy group, a substituted or unsubstituted thio group, a substituted or unsubstituted boron group, a substituted or unsubstituted silyl group, a substituted or unsubstituted amine group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms. In one or more embodiments, R_{y1} to R_{y4} and R_{z1} to R_{z5} may each independently be hydrogen, deuterium, a substituted or unsubstituted oxy group, or a substituted or unsubstituted thio group. In one or more embodiments, one or more selected from among Ry to R_{y4} and R_{z1} to R_{z5} may each independently bonded to an adjacent group to form a ring. For example, in one or more embodiments, R_{y4} or R_{z5} may correspond to a substituted or unsubstituted oxy group or a substituted or unsubstituted thio group, and R_{y4} and R_{z5} may be bonded to each other to form a hetero ring containing an oxygen atom or a sulfur atom. In one or more embodiments, R_{y2} or R_{z1} may correspond to a substituted or unsubstituted oxy group or a substituted or unsubstituted thio group, and R_{y2} and Rz may be bonded to each other to form a hetero ring containing an oxygen atom or a sulfur atom. Because R_{y4} and R_{z5} are bonded to each other to form a ring, or R_{y1} and R_{z1} are bonded to each other to form a ring, a dibenzofuran moiety or a dibenzothiophene moiety may be provided by Formula 2 according to one or more embodiments.

In Formula 2,

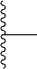

is a position to be connected to Formula 1.

In this disclosure, in Formula 1, a benzene ring substituted with the substituents represented by R₁ to R₄ of Formula 1 may correspond to the second benzene ring previously described, a benzene ring substituted with the substituents represented by R₅ to R₈ may correspond to the third benzene ring previously described, and a benzene ring substituted with the substituents represented by R₉ to R₁₁ may correspond to the first benzene ring previously described. In Formula 1, the substituent represented by Ar may correspond to the first substituent previously described.

In addition, in Formula 2, a benzene ring substituted with the substituents represented by Rₓ₁ to Rₓ₄ may correspond to the first benzene moiety previously described, and a biphenyl moiety substituted with the substituents represented by R_{y1} to R_{y4} and R_{z1} to R_{z5} may correspond to the first sub substituent previously described. In particular, the benzene ring substituted with the substituents represented by R_{y1} to R_{y4} may correspond to the second benzene moiety previously described, and the benzene ring substituted with the substituents represented by R_{z1} to R_{z5} may correspond to the third benzene moiety previously described. Any substituent corresponding to a substituted or unsubstituted aryl group having 6 to 30 ring-forming carbon atoms or a substituted or unsubstituted heteroaryl group having 2 to 30 ring-forming carbon atoms, among the substituents represented by Rₓ₁ to Rₓ₄, may correspond to the second sub substituent previously described.

In one or more embodiments, at least one selected from among Rₓ₁ to Rₓ₃ may be a substituent represented by any one selected from among Formula 3-1 to Formula 3-4. For example, in one or more embodiments, any one selected from among Rₓ₁ to Rₓ₃ may be a substituent represented by any one selected from among Formula 3-1 to Formula 3-4, and the rest of Rₓ₁ to Rₓ₃ may be hydrogen, deuterium, or an unsubstituted t-butyl group.

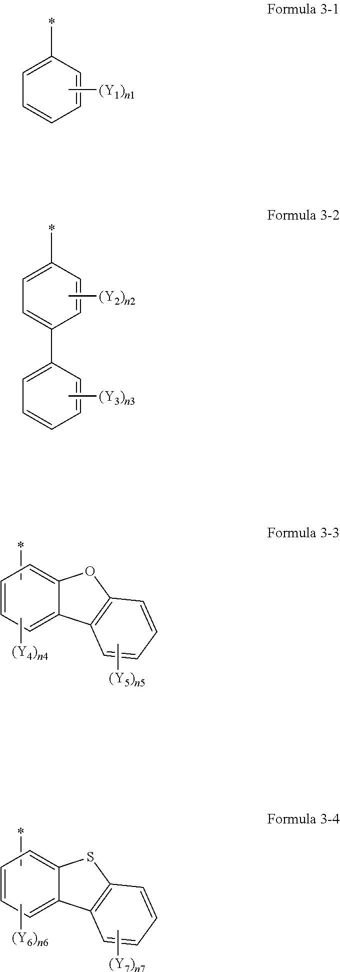

In Formula 3-1 to Formula 3-4, Y₁ to Y may each independently be hydrogen, deuterium, a halogen, a cyano group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, in one or more embodiments, Y₁ to Y₇ may each independently be hydrogen or deuterium.

In Formula 3-1, n1 may be an integer of 0 or greater and 5 or less. If (e.g., when) n1 is 0, it may refer to that the fused polycyclic compound according to one or more embodiments is not substituted with Y₁. If (e.g., when n1 is 5 and each Y₁ is hydrogen, the embodiment may be the same as the embodiment in which n1 is 0. If (e.g., when) n1 is an integer of 2 or greater, Y₁ provided in plurality may be the same, or at least one selected from among the plurality of Y₁'s may be different. In Formula 3-2, n2 may be an integer of 0 or greater and 4 or less. If (e.g., when) n2 is 0, it may refer to that the fused polycyclic compound according to one or more embodiments is not substituted with Y₂. If (e.g., when) n2 is 4 and each Y₂ is hydrogen, the embodiment may be the same as the embodiment in which n2 is 0. If (e.g., when) n2 is an integer of 2 or greater, Y₂ provided in plurality may be the same, or at least one selected from among the plurality of Y₂'s may be different.

In Formula 3-2, n3 may be an integer of 0 or greater and 5 or less. If (e.g., when) n3 is 0, it may refer to that the fused polycyclic compound according to one or more embodiments is not substituted with Y₃. If (e.g., when) n3 is 5 and each Y₃ is hydrogen, the embodiment may be the same as the embodiment in which n3 is 0. If (e.g., when) n3 is an integer of 2 or greater, Y₂ provided in plurality may be the same, or at least one selected from among the plurality of Y₃'s may be different.

In Formula 3-3, n4 may be an integer of 0 or greater and 3 or less. If (e.g., when) n4 is 0, it may refer to that the fused polycyclic compound according to one or more embodiments is not substituted with Y₄. If (e.g., when) n4 is 3 and each Y₄ is hydrogen, the embodiment may be the same as the embodiment in which n4 is 0. If (e.g., when) n4 is an integer of 2 or greater, Y₄ provided in plurality may be the same, or at least one selected from among the plurality of Y₄'s may be different.

In Formula 3-3, n5 may be an integer of 0 or greater and 4 or less. If (e.g., when) n5 is 0, it may refer to that the fused polycyclic compound according to one or more embodiments is not substituted with Y₅. If (e.g., when) n5 is 4 and each Y₅ is hydrogen, the embodiment may be the same as the embodiment in which n5 is 0. If (e.g., when) n5 is an integer of 2 or greater, Y₅ provided in plurality may be the same, or at least one selected from among the plurality of Y₆'s may be different.

In Formula 3-4, n6 may be an integer of 0 or greater and 3 or less. If (e.g., when) n6 is 0, it may refer to that the fused polycyclic compound according to one or more embodiments is not substituted with Y₆. If (e.g., when) n6 is 3 and each Y₆ is hydrogen, the embodiment may be the same as the embodiment in which n6 is 0. If (e.g., when) n6 is an integer of 2 or greater, Y₆ provided in plurality may be the same, or at least one selected from among the plurality of Y₆'s may be different.

In Formula 3-4, n7 may be an integer of 0 or greater and 4 or less. If (e.g., when) n7 is 0, it may refer to that the fused polycyclic compound according to one or more embodiments is not substituted with Y₇. If (e.g., when) n7 is 4 and each Y₇ is hydrogen, the embodiment may be the same as the embodiment in which n7 is 0. If (e.g., when n7) is an integer of 2 or greater, Y₇ provided in plurality may be the same, or at least one selected from among the plurality of Y₇'s may be different.

In Formula 3-1 to Formula 3-4, [symbol] may be a position to be connected to Formula 2.

In one or more embodiments, the substituent represented by Formula 2 may be represented by any one selected from among Formula 2-1 to Formula 2-3.

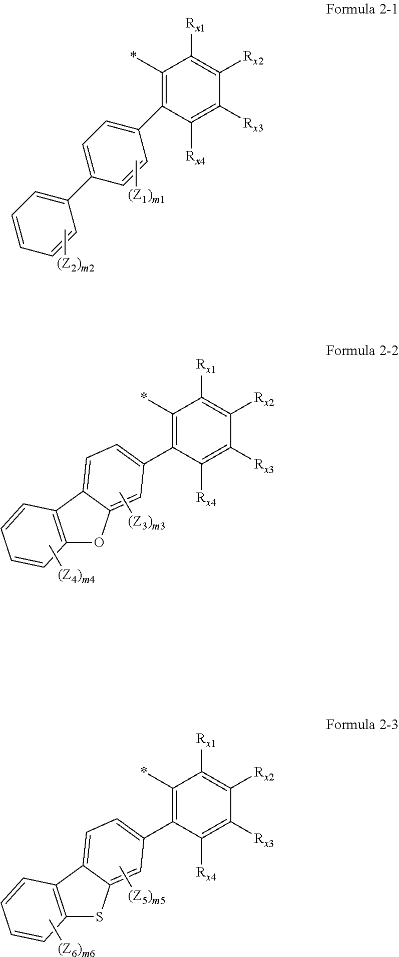

In Formula 2-1 to Formula 2-3, Z₁ to Z₆ may each independently be hydrogen, deuterium, a halogen, a cyano group, or a substituted or unsubstituted alkyl group having 1 to 10 carbon atoms. For example, in one or more embodiments, Z₁ to Z₆ may each independently be hydrogen or deuterium.

In Formula 2-1, m1 may be an integer of 0 or greater and 4 or less. If (e.g., when) m1 is 0, it may refer to that the fused polycyclic compound according to one or more embodiments is not substituted with Z₁. If (e.g., when) m1 is 4 and each Z₁ is hydrogen, the embodiment may be the same as the embodiment in which m1 is 0. If (e.g., when) m1 is an integer of 2 or greater, Z₁ provided in plurality may be the same, or at least one selected from among the plurality of Z₁'s may be different.

In Formula 2-1, m2 may be an integer of 0 or greater and 5 or less. If (e.g., when) m2 is 0, it may refer to that the fused polycyclic compound according to one or more embodiments is not substituted with Z₂. If (e.g., when) m2 is 5 and each Z₂ is hydrogen, the embodiment may be the same as the embodiment in which m2 is 0. If (e.g., when) m2 is an integer of 2 or greater, Z₂ provided in plurality may be the same, or at least one selected from among the plurality of Z₂'s may be different.

In Formula 2-2, m3 may be an integer of 0 or greater and 3 or less. If (e.g., when) m3 is 0, it may refer to that the fused polycyclic compound according to one or more embodiments is not substituted with Z₃. If (e.g., when) m3 is 3 and each Z₃ is hydrogen, the embodiment may be the same as the embodiment in which m3 is 0. If (e.g., when) m3 is an integer of 2 or greater, Z₃ provided in plurality may be all the same, or at least one selected from among the plurality of Z₃'s may be different.

In Formula 2-2, m4 may be an integer of 0 or greater and 4 or less. If (e.g., when) m4 is 0, it may refer to that the fused polycyclic compound according to one or more embodiments is not substituted with Z₄. If (e.g., when) m4 is 4 and each Z₄ is hydrogen, the embodiment may be the same as the embodiment in which m4 is 0. If (e.g., when) m4 is an integer of 2 or greater, Z₄ provided in plurality may be the same, or at least one selected from among the plurality of Z₄'s may be different.

In Formula 2-3, m5 may be an integer of 0 or greater and 3 or less. If (e.g., when) m5 is 0, it may refer to that the fused polycyclic compound according to one or more embodiments is not substituted with Z₅. If (e.g., when) m5 is 3 and each Z₅ is hydrogen, the embodiment may be the same as the embodiment in which m5 is 0. If (e.g., when) m5 is an integer of 2 or greater, Z₅ provided in plurality may be the same, or at least one selected from among the plurality of Z₅'s may be different.

In Formula 2-3, m6 may be an integer of 0 or greater and 4 or less. If (e.g., when) m6 is 0, it may refer to that the fused polycyclic compound according to one or more embodiments is not substituted with Z₆. If (e.g., when) m6 is 4 and each Z₆ is hydrogen, the embodiment may be the same as the embodiment in which m6 is 0. If (e.g., when) m6 is an integer of 2 or greater, Ze provided in plurality may be the same, or at least one selected from among the plurality of Z₆'s may be different.

In Formula 2-1 to Formula 2-3, [symbol] is a position to be connected to Formula 1.

In Formula 2-1 to Formula 2-3, Rₓ₁ to Rₓ₄ may be applied with the same content as those described in Formula 2.

In one or more embodiments, the substituent represented by Formula 2 may be represented by any one selected from among Formula 2-4 to Formula 2-17.

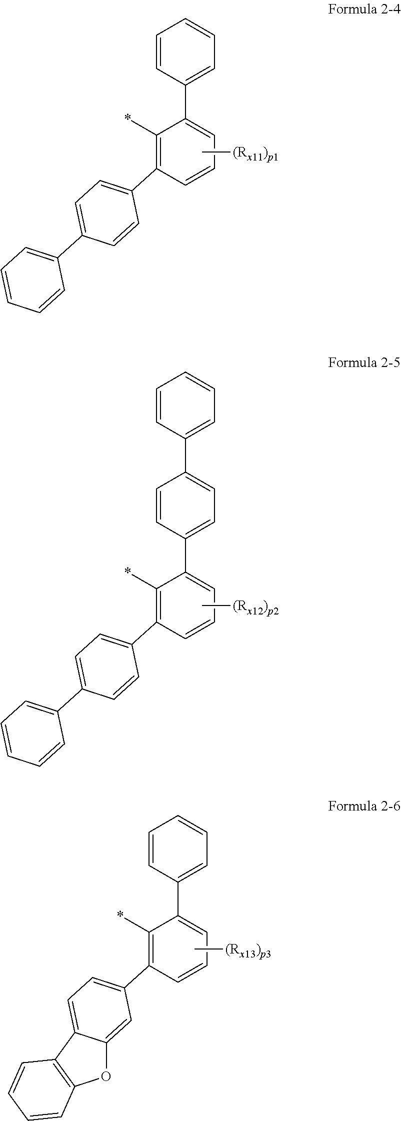

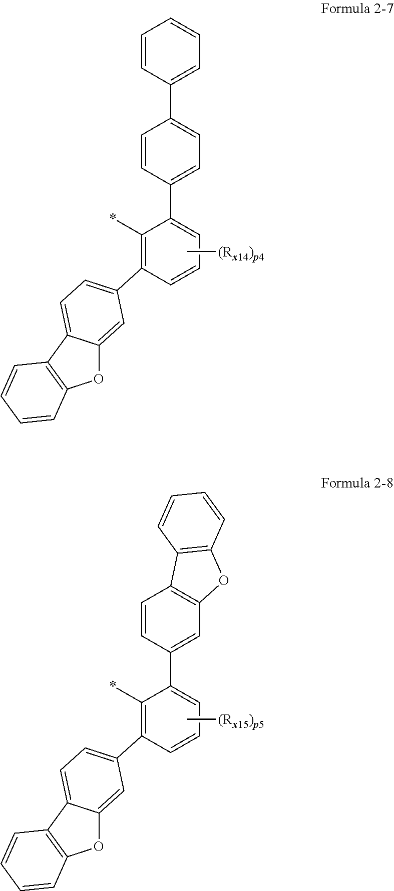

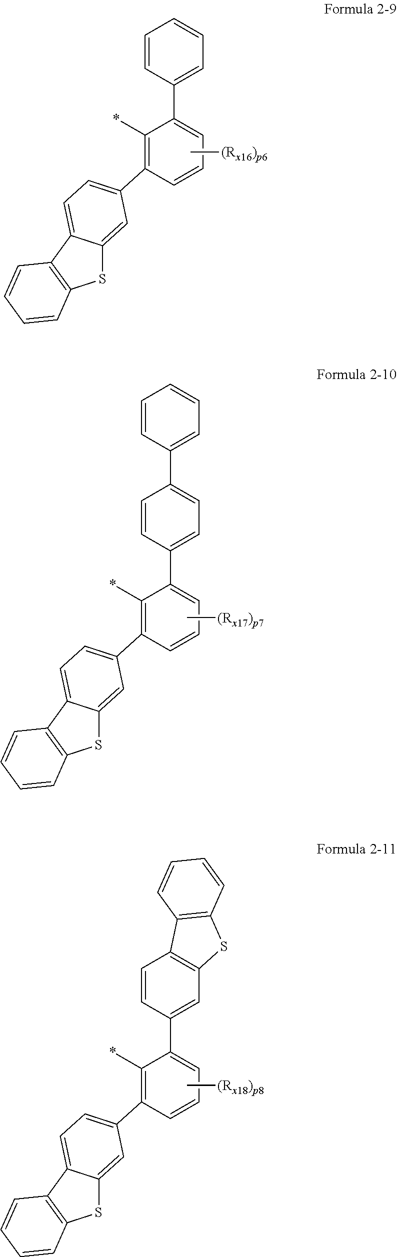

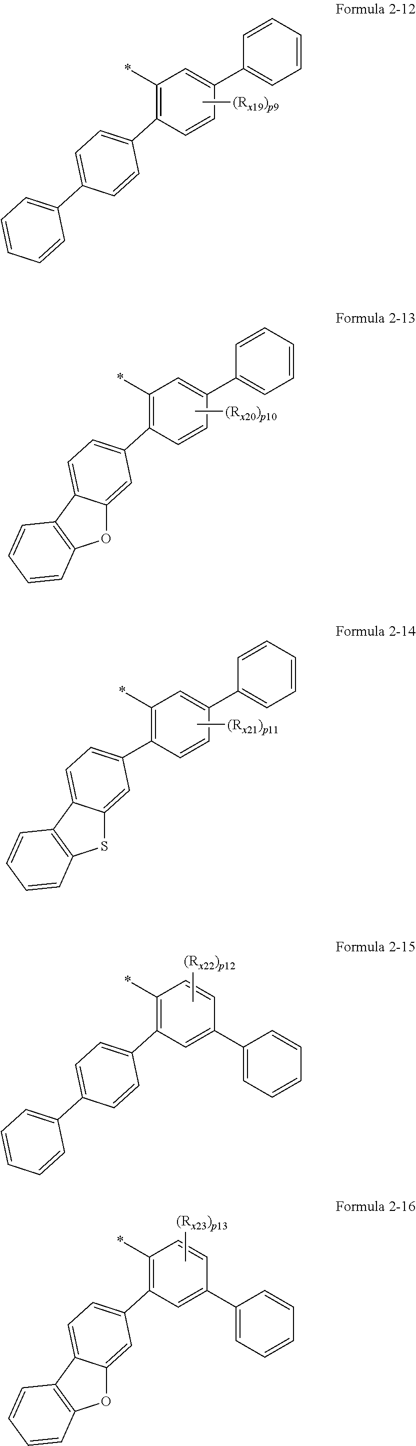

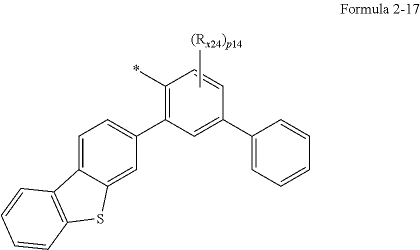

In Formula 2-4 to Formula 2-17, Rₓ₁₁ to Rₓ₂₄ may each independently be hydrogen, deuterium, an unsubstituted t-butyl group, or an unsubstituted phenyl group. For example, in one or more embodiments, Rₓ₁₁ to Rₓ₂₄ may each independently be hydrogen, deuterium, or an unsubstituted t-butyl group.

In Formula 2-4 to Formula 2-17, p1 to p14 may each independently be an integer of 0 or greater and 3 or less. If (e.g., when) each of p1 to p14 is 0, it may refer to that the fused polycyclic compound according to one or more embodiments is not substituted with each of Rₓ₁₁ to Rₓ₂₄. If (e.g., when) each of p1 to p14 is 3, and each of Rₓ₁₁'s to Rₓ₂₄'s is hydrogen, the embodiments may be the same as the embodiments in which each of p1 to p14 is 0. If (e.g., when) each of p1 to p14 is an integer of 2 or greater, each of Rₓ₁₁ to Rₓ₂₄, provided in plurality, may be the same, or at least one selected from among Rₓ₁₁ to Rₓ₂₄ each in plurality may be different. In Formula 2-4 to Formula 2-17, [symbol] is a position to be connected to Formula 1.

In Formula 2-4 to Formula 2-17, any hydrogen may be optionally substituted with deuterium. Each of Formula 2-4 to Formula 2-17 may have a structure in which any hydrogen is optionally substituted with deuterium.

In one or more embodiments, the fused polycyclic compound represented by Formula 1 may be represented by any one selected from among Formula 1-1 to Formula 1-6.

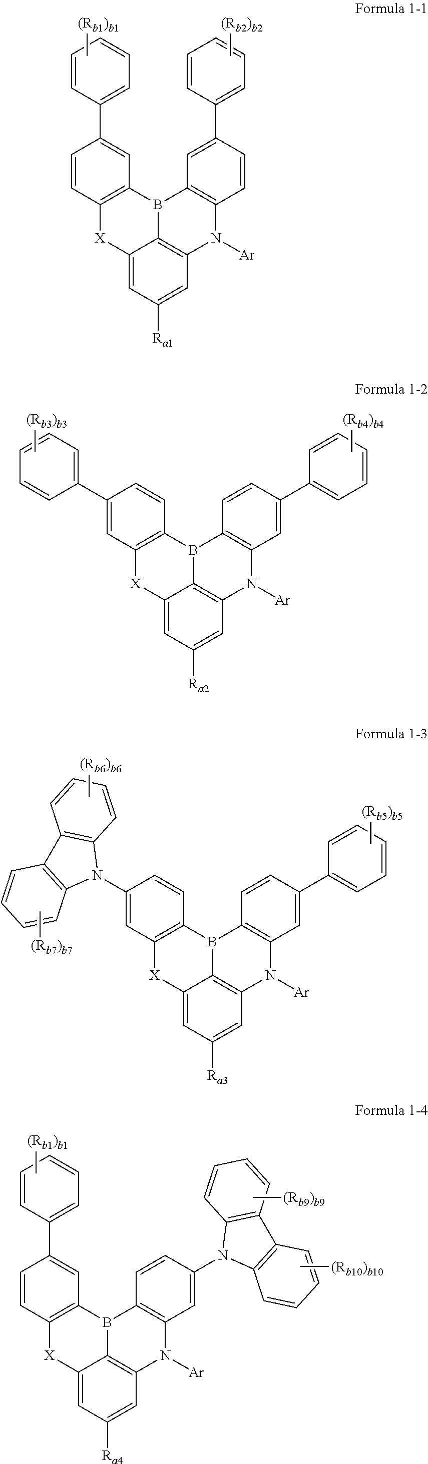

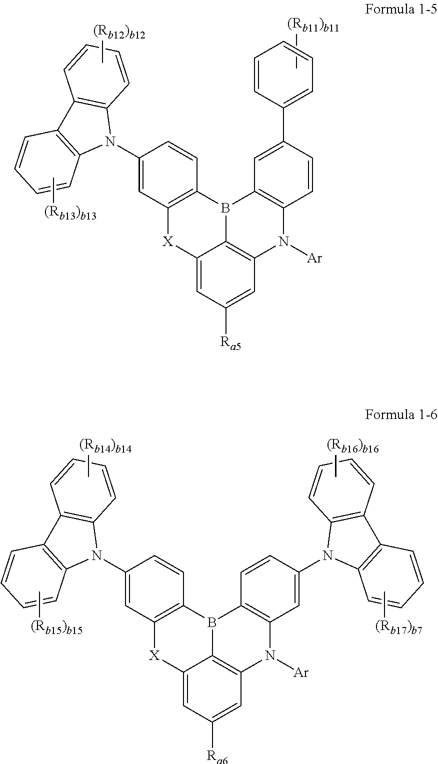

In Formula 1-1 to Formula 1-6, Rₐ₁ to Rₐ₆ may each independently be hydrogen, deuterium, a substituted or unsubstituted t-butyl group, or a substituted or unsubstituted aryl group having 6 to 30 ring-forming carbon atoms. For example, in one or more embodiments, Rₐ₁ to Rₐ₆ may each independently be hydrogen, an unsubstituted t-butyl group, or a phenyl group substituted with a t-butyl group.

In Formula 1-1 to Formula 1-6, R_{b1} to R_{b17} may each independently be hydrogen, deuterium, a cyano group, a substituted or unsubstituted t-butyl group, a substituted or unsubstituted aryl group having 6 to 30 ring-forming carbon atoms, or an unsubstituted heteroaryl group having 2 to 30 ring-forming carbon atoms. For example, in one or more embodiments, R_{b1} to R_{b17} may each independently be hydrogen, deuterium, a cyano group, a substituted or unsubstituted t-butyl group, a substituted or unsubstituted phenyl group, or a substituted or unsubstituted pyridine group.

In Formula 1-1, b1 and b2 may each independently be an integer of 0 or greater and 5 or less. If (e.g., when) each of b1 and b2 is 0, it may refer to that the fused polycyclic compound according to one or more embodiments is not substituted with each of R_{b1} and R_{b2}. If (e.g., when) each of b1 and b2 is 5, and each of R_{b1}'s and R_{b2}'s is hydrogen, the embodiments may be the same as the embodiments in which each of b1 to b2 is 0. If (e.g., when) each of b1 and b2 is an integer of 2 or greater, each of R_{b1} to R_{b2}, provided in plurality, may be the same, or at least one selected from among R_{b1} and/or R_{b2} each in plurality may be different.

In Formula 1-2, b3 and b4 may each independently be an integer of 0 or greater and 5 or less. If (e.g., when) each of b3 and b4 is 0, it may refer to that the fused polycyclic compound according to one or more embodiments is not substituted with each of R_{b3} and R_{b4}. If (e.g., when) each of b3 and b4 is 5, and each of R_{b3}'s and R_{b4}'s is hydrogen, the embodiments may be the same as the embodiments in which each of b3 and b4 is 0. If (e.g., when) each of b3 and b4 is an integer of 2 or greater, each of R_{b3} and R_{b4}, provided in plurality, may be the same, or at least one selected from among R_{b3} and/or R_{b4} each in plurality may be different.

In Formula 1-3, b5 may be an integer of 0 or greater and 5 or less. If (e.g., when) b5 is 0, it may refer to that the fused polycyclic compound according to one or more embodiments is not substituted with R_{b5}. If (e.g., when) b5 is 5 and each R_{b5} is hydrogen, the embodiment may be the same as the embodiment in which b5 is 0. If (e.g., when) b5 is an integer of 2 or greater, R_{b5} provided in plurality may be the same, or at least one selected from among the plurality of R_{b5}'s may be different.

In Formula 1-3, b6 and b7 may each independently be an integer of 0 or greater and 4 or less. If (e.g., when) each of b6 and b7 is 0, it may refer to that the fused polycyclic compound according to one or more embodiments is not substituted with each of R_{b6} and R_{b7}. If (e.g., when) each of b6 and b7 is 4, and each of R_{b6}'s and R_{b7}'s is hydrogen, the embodiments may be the same as the embodiments in which each of b6 and b7 is 0. If (e.g., when) each of b6 and b7 is an integer of 2 or greater, each of R_{b6} and R_{b7}, provided in plurality, may be the same, or at least one selected from among R_{b6} and/or R_{b7} each in plurality may be different. In Formula 1-4, b8 may be an integer of 0 or greater and 5 or less. When

b8 is 0, it may refer to that the fused polycyclic compound according to one or more embodiments is not substituted with R_{b8}. If (e.g., when) b8 is 5 and each R_{b8} is hydrogen, the embodiment may be the same as the embodiment in which b8 is 0. If (e.g., when) b8 is an integer of 2 or greater, R_{b8} provided in plurality may be the same, or at least one selected from among the plurality of R_{b8}'s may be different.

In Formula 1-4, b9 and b10 may each independently be an integer of 0 or greater and 4 or less. If (e.g., when) each of b9 and b10 is 0, it may refer to that the fused polycyclic compound according to one or more embodiments is not substituted with each of R_{b9} and R_{b10}. If (e.g., when) each of b9 and b10 is 4, and each of R_{b9}'s and R_{b10}'s is hydrogen, the embodiments may be the same as the embodiments in which each of b9 and b10 is 0. If (e.g., when) each of b9 and b10 is an integer of 2 or greater, each of R_{b9} and R_{b10}, provided in plurality, may be the same, or at least one selected from among R_{b9} and/or R_{b10} each in plurality may be different.

In Formula 1-5, b11 may be an integer of 0 or greater and 5 or less. If (e.g., when) b11 is 0, it may refer to that the fused polycyclic compound according to one or more embodiments is not substituted with R_{b11}. If (e.g., when) b11 is 5 and each R_{b11} is hydrogen, the embodiment may be the same as the embodiment in which b11 is 0. If (e.g., when) b11 is an integer of 2 or greater, R_{b11} provided in plurality may be the same, or at least one selected from among the plurality of R_{b11}'s may be different.

In Formula 1-5, b12 and b13 may each independently be an integer of 0 or greater and 4 or less. If (e.g., when) each of b12 and b13 is 0, it may refer to that the fused polycyclic compound according to one or more embodiments is not substituted with each of R_{b12} and R_{b13}. If (e.g., when) each of b12 and b13 is 4, and each of R_{b12}'s and R_{b13}'s is hydrogen, the embodiments may be the same as the embodiments in which each of b12 and b13 is 0. If (e.g., when) each of b12 and b13 is an integer of 2 or greater, each of R_{b12} and R_{b13}, provided in plurality, may be the same, or at least one selected from among R_{b12} and/or R_{b13} each in plurality may be different.

In Formula 1-6, b14 to b17 may each independently be an integer of 0 or greater and 4 or less. If (e.g., when) each of b14 to b17 is 0, it may refer to that the fused polycyclic compound according to one or more embodiments is not substituted with each of R_{b14} to R_{b17}. If (e.g., when) each of b14 to b17 is 4, and each of R_{b14}'s to R_{b17}'s is hydrogen, the embodiments may be the same as the embodiments in which each of b14 to b17 is 0. If (e.g., when) each of b14 to b17 is an integer of 2 or greater, each of R_{b14} to R_{b17}, provided in plurality, may be the same, or at least one selected from among R_{b14} to R_{b17} each in plurality may be different.

In Formula 1-1 to Formula 1-6, X and Ar may be applied with the same content as described in Formula 1.

In Formula 1-1 to Formula 1-6, any hydrogen may be optionally substituted with deuterium. Each of Formula 1-1 to Formula 1-6 may have a structure in which any hydrogen is optionally substituted with deuterium.

In one or more embodiments, the fused polycyclic compound represented by Formula 1 may be represented by Formula 1-7.

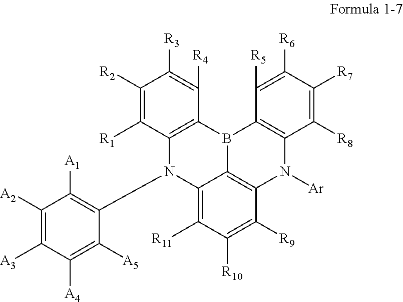

In Formula 1-7, A₁ to A₅ may each independently be hydrogen, deuterium, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. However, the case where two or more selected from among A₁ to A₅ may each independently be a substituted or unsubstituted dibenzofuran group, a substituted or unsubstituted dibenzothiophene group, or a substituted or unsubstituted carbazole group may not be included. For example, in one or more embodiments, A₁ to A₄ may each independently be hydrogen, deuterium, a substituted or unsubstituted alkyl group having 1 to 20 carbon atoms, or a substituted or unsubstituted aryl group having 6 to 30 ring-forming carbon atoms, A₅ may be hydrogen, deuterium, a substituted or unsubstituted aryl group having 6 to 30 ring-forming carbon atoms, or a substituted or unsubstituted heteroaryl group having 2 to 30 ring-forming carbon atoms.

In Formula 1-7, Ar and R₁ to R₁₁ may be applied with the same content as described in Formula 1.

In one or more embodiments, the fused polycyclic compound represented by Formula 1 may be represented by any one among Formula 1-8 to Formula 1-16.

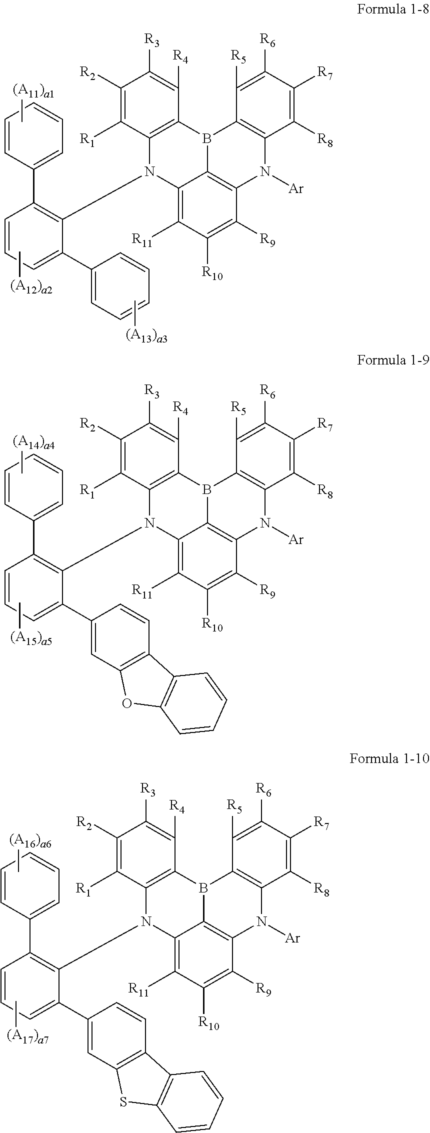

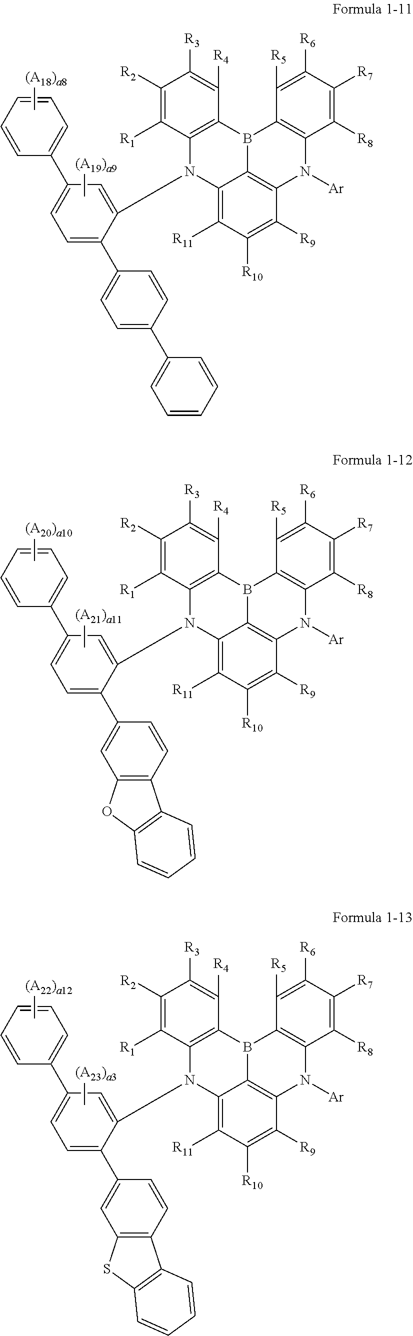

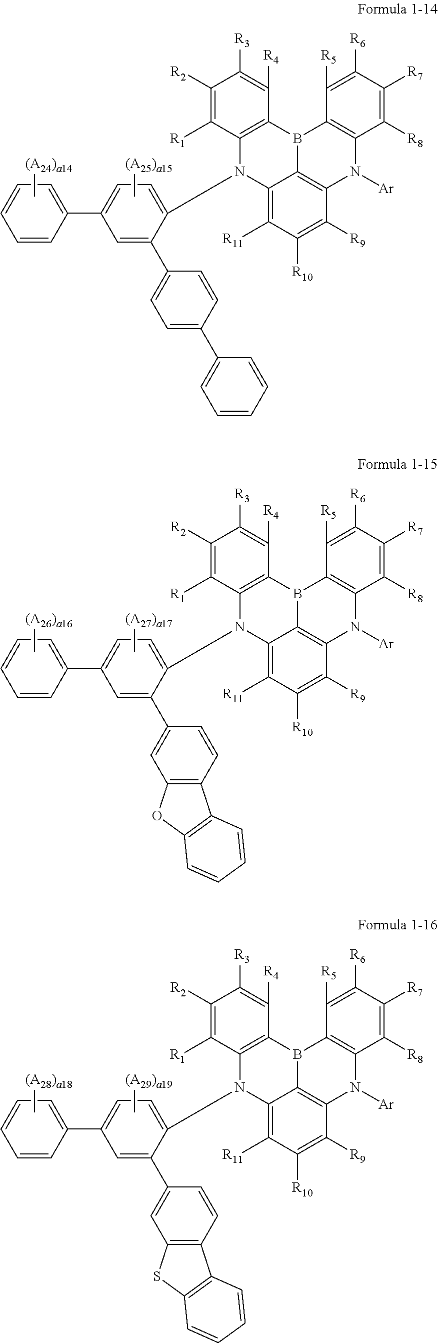

In Formula 1-8 to Formula 1-16, A₁₁, A₁₃, A₁₄, A₁₆, A₁₈, A₂₀, A₂₂, A₂₄, A₂₆, and A₂₈ may each independently be hydrogen, deuterium or a substituted or unsubstituted aryl group having 6 to 30 ring-forming carbon atoms. For example, in one or more embodiments, A₁₁, A₁₃, A₁₄, A₁₆, A₁₈, A₂₀, A₂₂, A₂₄, A₂₆, and A₂₈ may each independently be hydrogen or a substituted or unsubstituted phenyl group.

In Formula 1-8 to Formula 1-16, A₁₂, A₁₅, A₁₇, A₁₉, A₂₁, A₂₃, A₂₅, A₂₇, and A₂₉ may each independently be hydrogen, deuterium, a substituted or unsubstituted alkyl group having 1 to 20 carbon atoms, or a substituted or unsubstituted aryl group having 6 to 30 ring-forming carbon atoms. For example, in one or more embodiments, A₁₂, A₁₅, A₁₇, A₁₉, A₂₁, A₂₃, A₂₅, A₂₇, and A₂₉ may each independently be hydrogen, deuterium, or a substituted or unsubstituted t-butyl group.

In Formula 1-8 to Formula 1-16, a1, a3, a4, a6, a8, a10, a12, a14, a16, and a18 may each independently be an integer of 0 or greater and 5 or less. If (e.g., when) a1, a3, a4, a6, a8, a10, a12, a14, a16, and a18 are each 0, it may refer to that the fused polycyclic compound according to one or more embodiments is not substituted with each of A₁₁, A₁₃, A₁₄, A₁₆, A₁₈, A₂₀, A₂₂, A₂₄, A₂₆, and A₂₈. If (e.g., when) each of a1, a3, a4, a6, a8, a10, a12, a14, a16, and a18 is 5, and A₁₁, A₁₃, A₁₄, A₁₆, A₁₈, A₂₀, A₂₂, A₂₄, A₂₆, and A₂₈ are all hydrogens, the embodiments may be the same as the embodiments in which each of a1, a3, a4, a6, a8, a10, a12, a14, a16, and a18 is 0. If (e.g., when) each of a1, a3, a4, a6, a8, a10, a12, a14, a16, and a18 is an integer of 2 or greater, A₁₁, A₁₃, A₁₄, A₁₆, A₁₈, A₂₀, A₂₂, A₂₄, A₂₆, and A₂₈ each provided in plurality are the same, or at least one selected from among A₁₁, A₁₃, A₁₄, A₁₆, A₁₈, A₂₀, A₂₂, A₂₄, A₂₆, and A₂₈ each provided in plurality may be different.

In Formula 1-8 to Formula 1-16, a2, a5, a7, a9, a11, a13, a15, a17, and a19 may each independently be an integer of 0 or greater and 3 or less. If (e.g., when) each of a2, a5, a7, a9. a11, a13, a15, a17, and a19 is 0, it may refer to that the fused polycyclic compound according to one or more embodiments is not substituted with each of A₁₂, A₁₅, A₁₇, A₁₉, A₂₁, A₂₃, A₂₅, A₂₇, and A₂₉. If (e.g., when) each of a2, a5, a7, a9, a11, a13, a15, a17, and a19 is 5, and each of A₁₂'s, A₁₅'s, A₁₇'s, A₁₉'s, A₂₁'s, A₂₃'s, A₂₅'s, A₂₇'s, and A₂₉'s is hydrogen, the embodiments may be the same as the embodiments in which each of a2, a5, a7, a9, a11, a13, a15, a17, and a19 is 0. If (e.g., when) each of a2, a5, a7, a9, a11, a13, a15, a17, and a19 is an integer of 2 or greater, A₁₂, A₁₅, A₁₇, A₁₉, A₂₁, A₂₃, A₂₅, A₂₇, and A₂₉ each provided in plurality may each independently be the same, or at least one selected from among A₁₂, A₁₅, A₁₇, A₁₉, A₂₁, A₂₃, A₂₅, A₂₇, and A₂₉ each provided in plurality may be different.

In Formula 1-8 to Formula 1-16, Ar and R₁ to R₁₁ may be applied with the same content as described in Formula 1.

In Formula 1-8 to Formula 1-16, any hydrogen may be optionally substituted with deuterium. Each of Formula 1-8 to Formula 1-16 may have a structure in which any hydrogen is optionally substituted with deuterium.

The fused polycyclic compound according to one or more embodiments may be any one selected from among compounds listed in Compound Group 1. At least one functional layer included in the light emitting element ED according to one or more embodiments may include at least one fused polycyclic compound selected from among the compounds listed in Compound Group 1. The light emitting element ED according to one or more embodiments may include at least one fused polycyclic compound selected from among the compounds listed in Compound Group 1 in the emission layer EML.

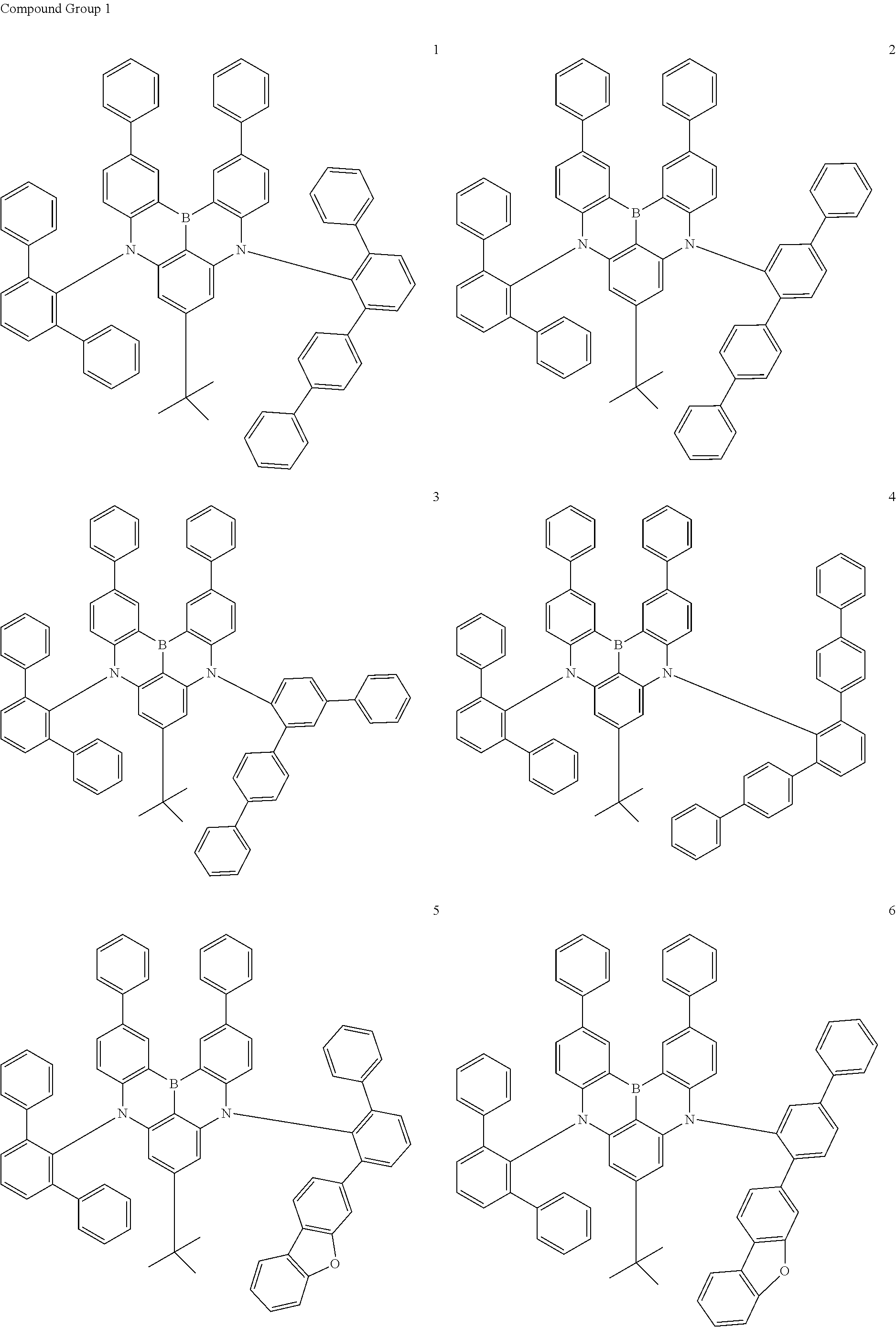

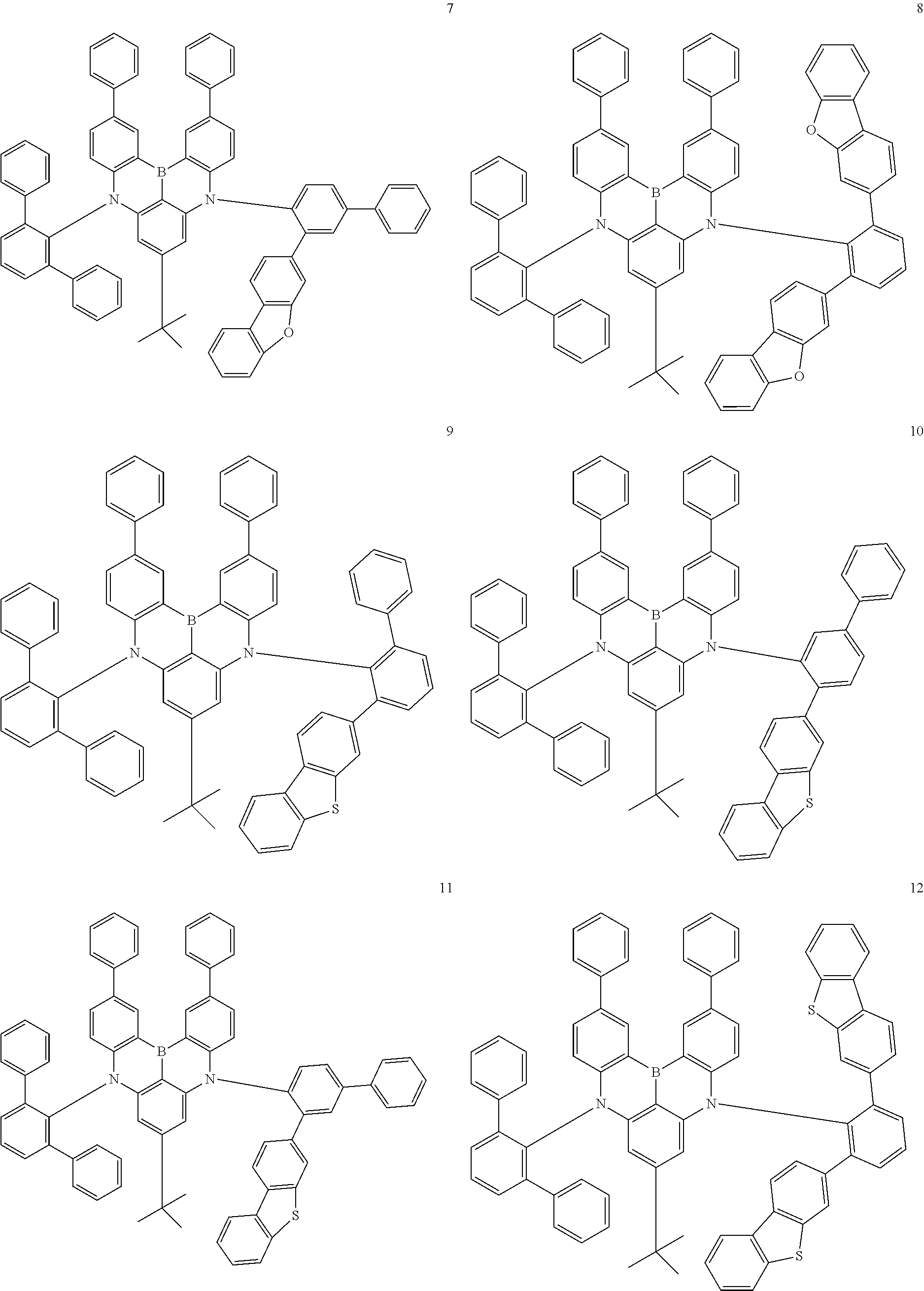

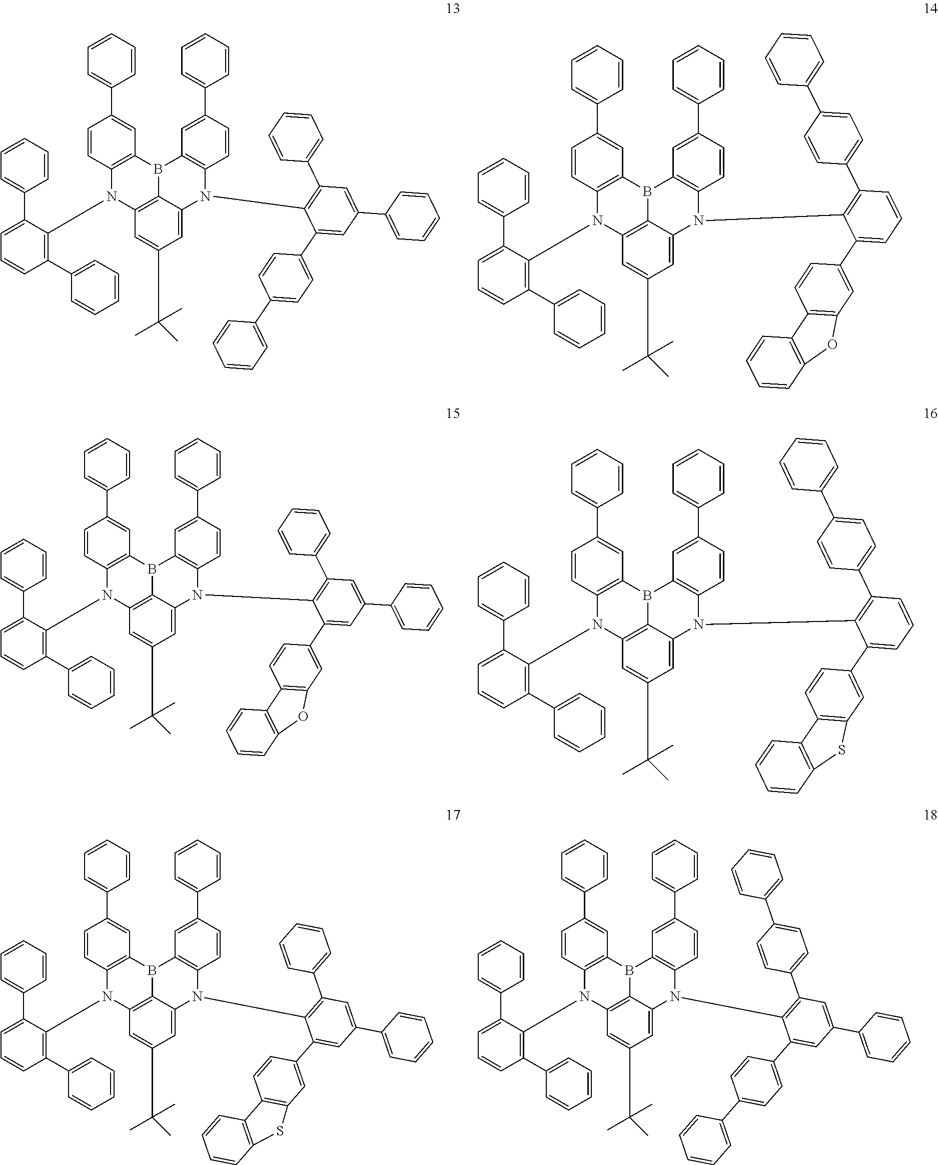

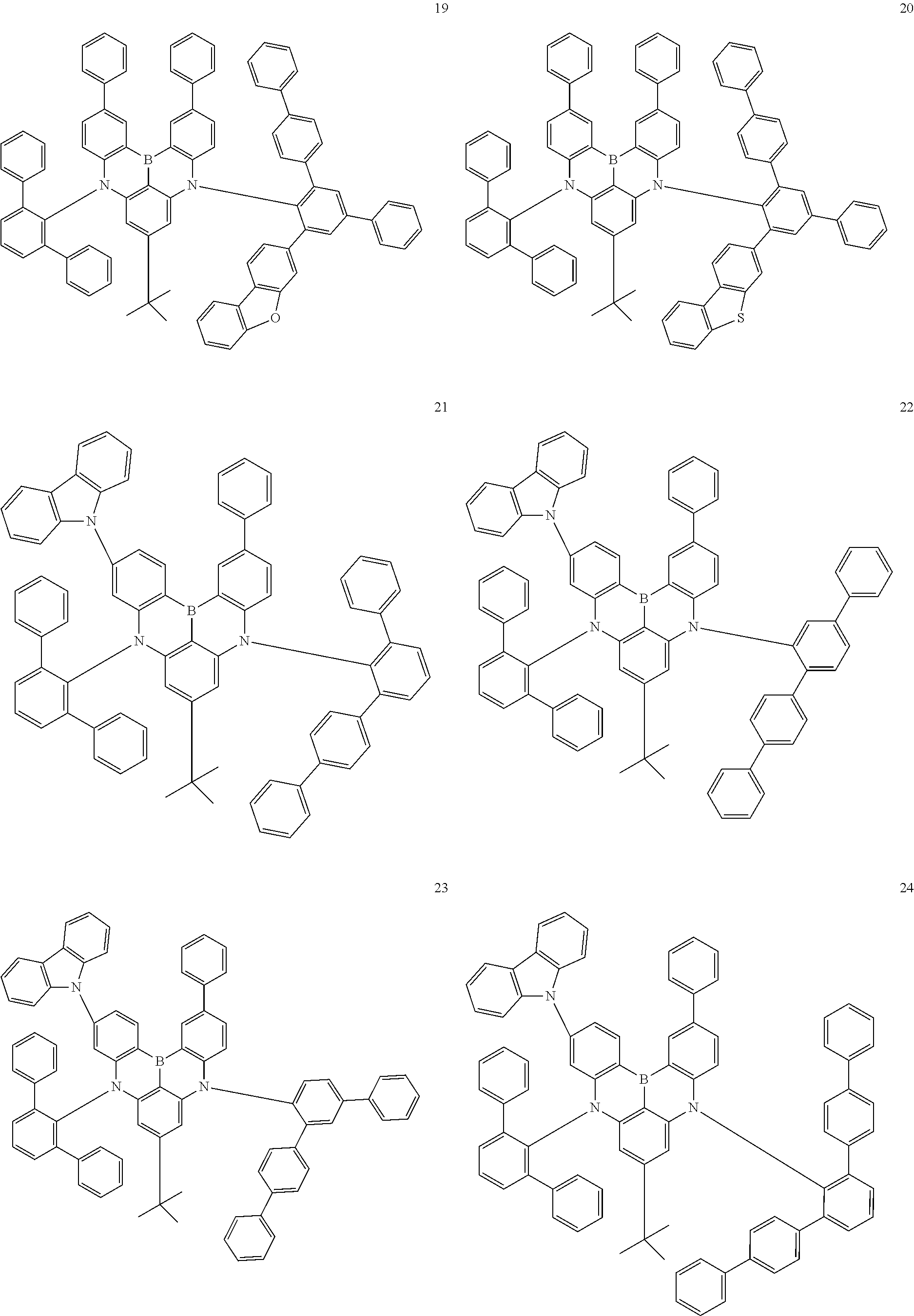

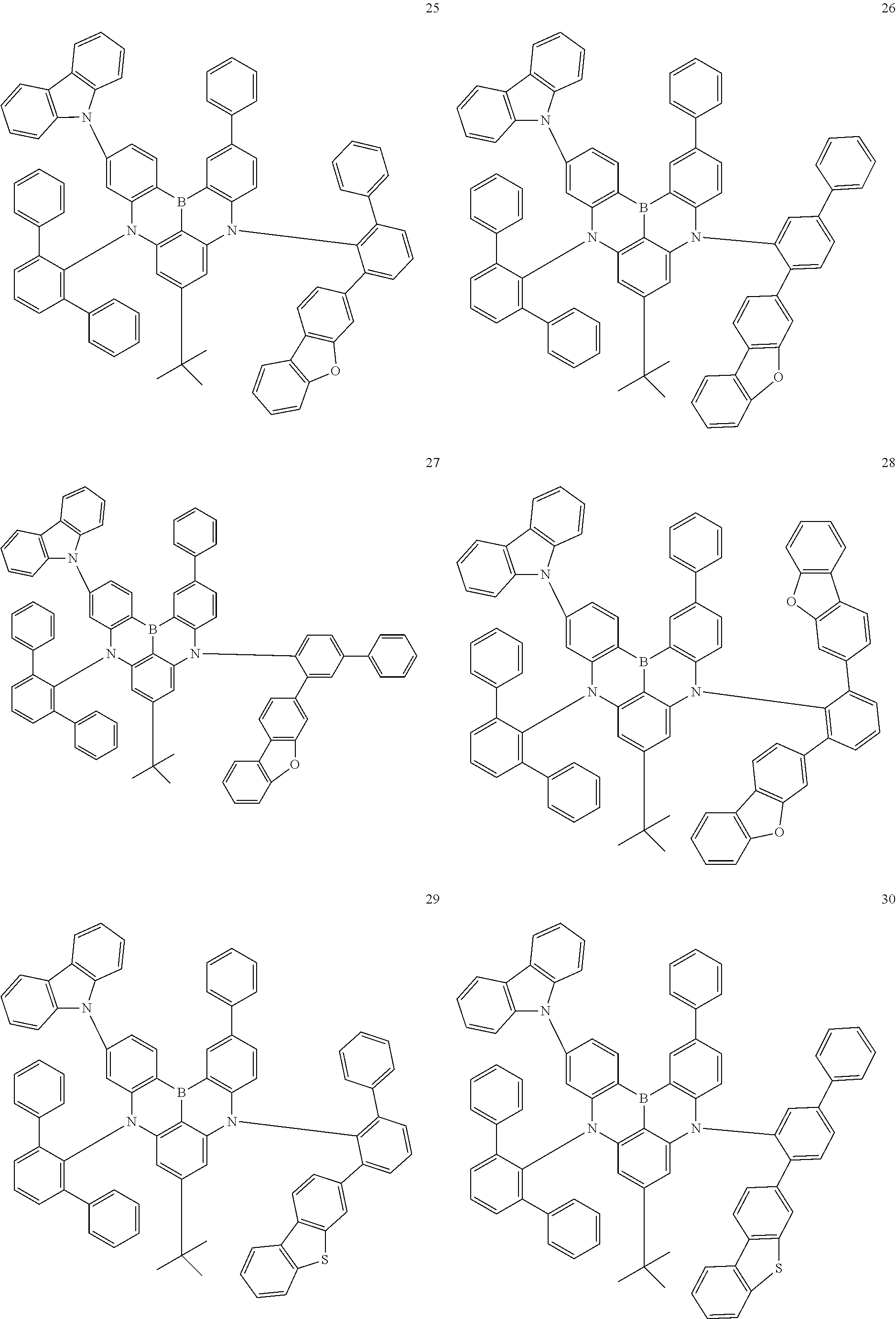

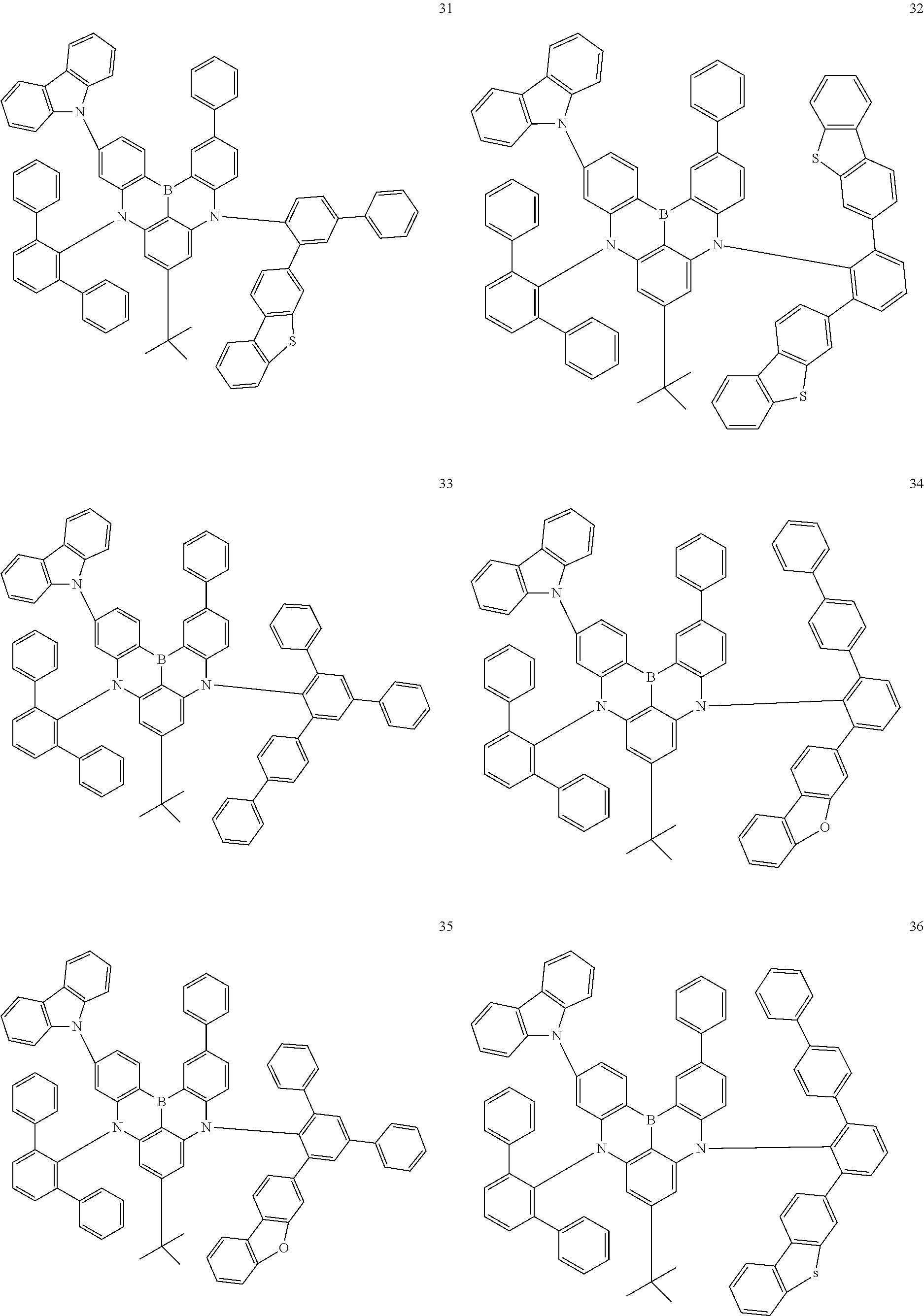

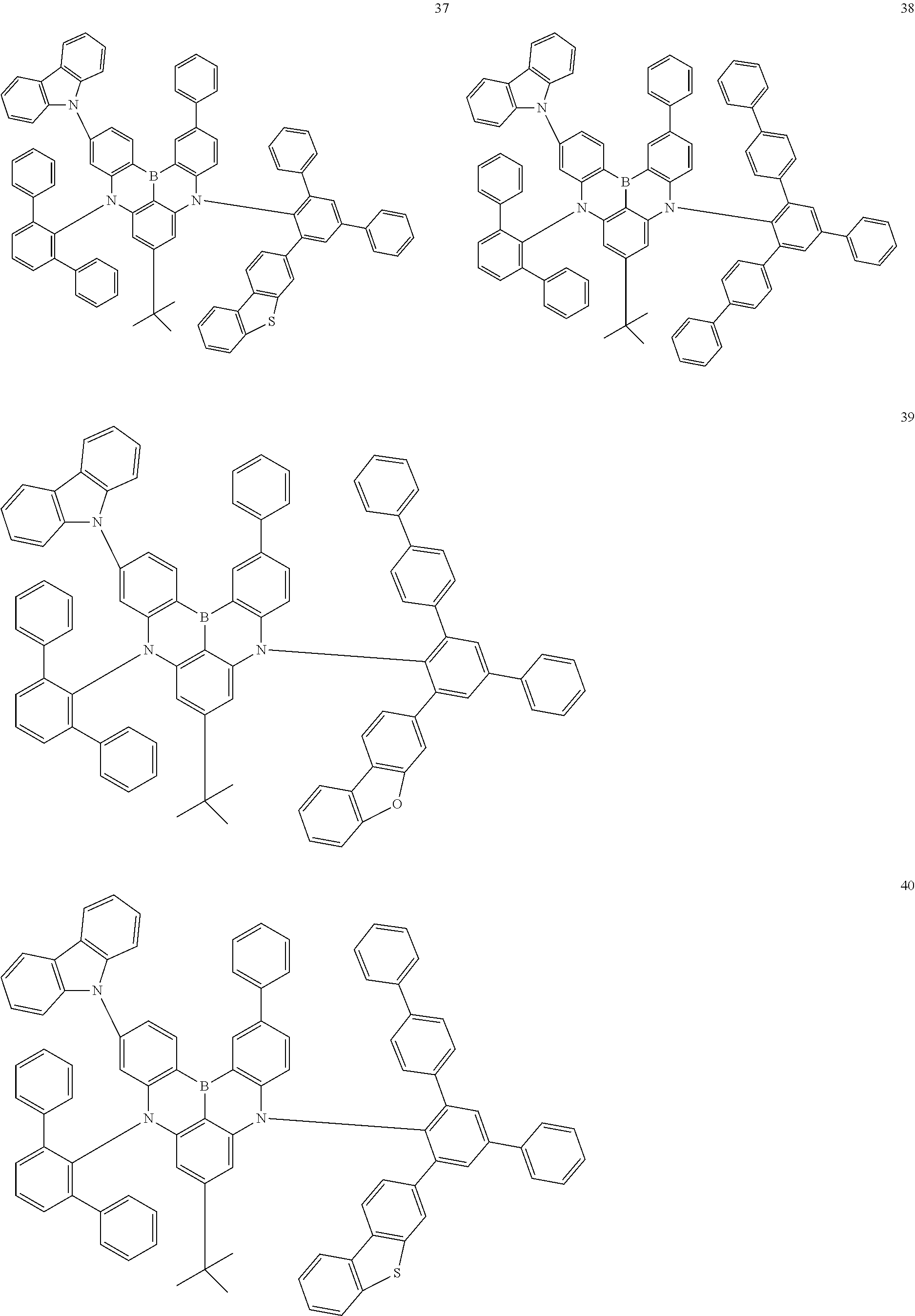

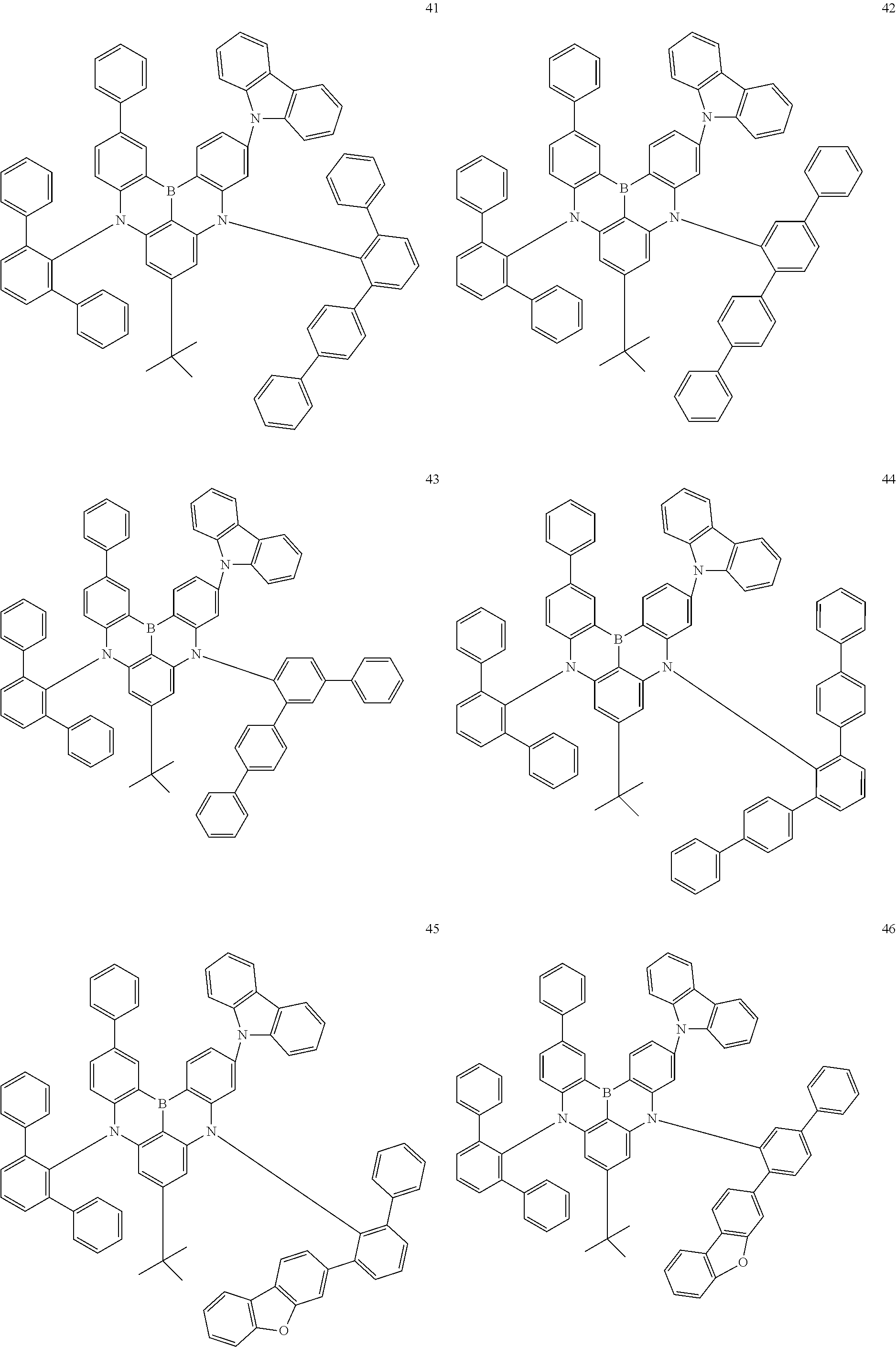

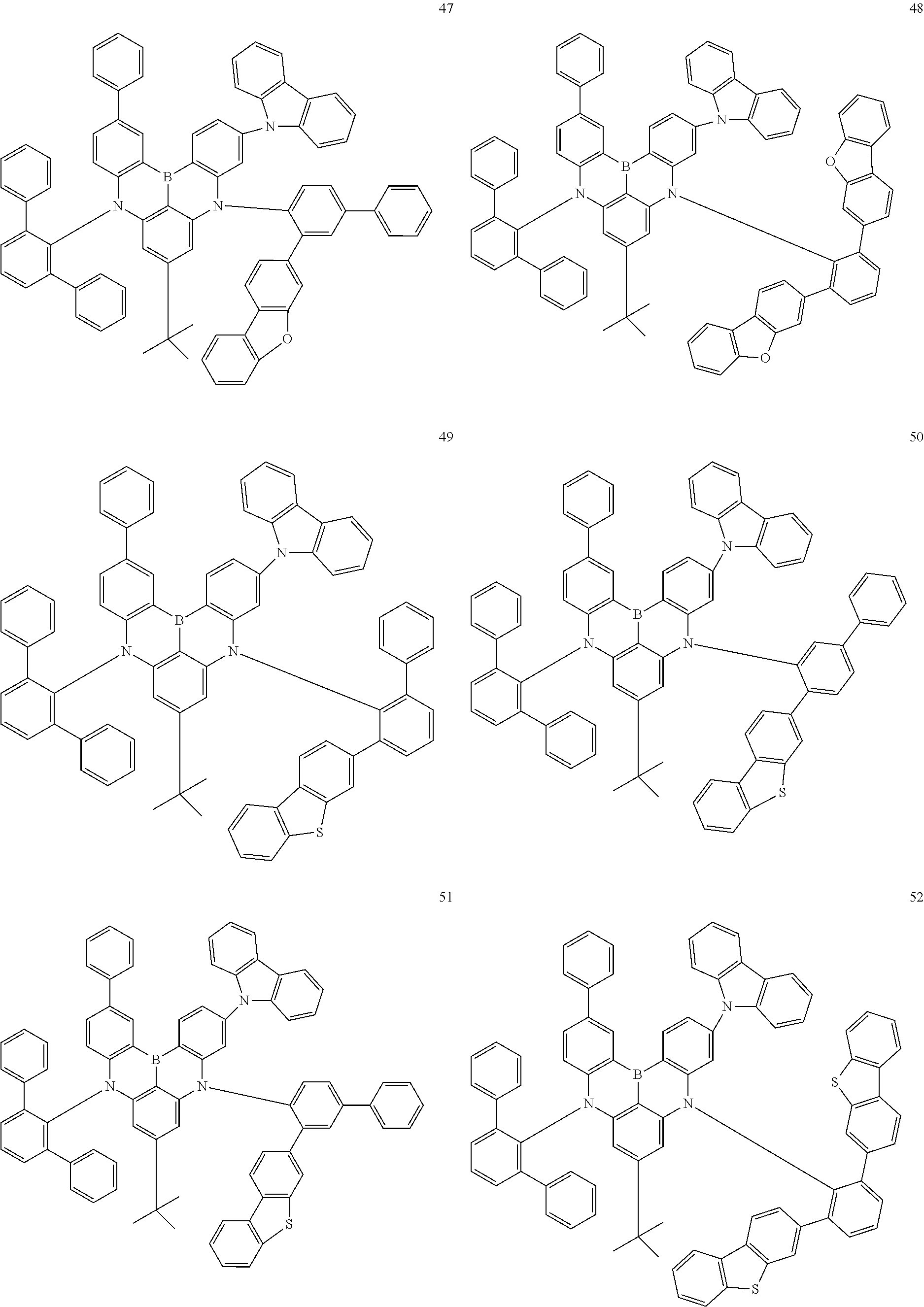

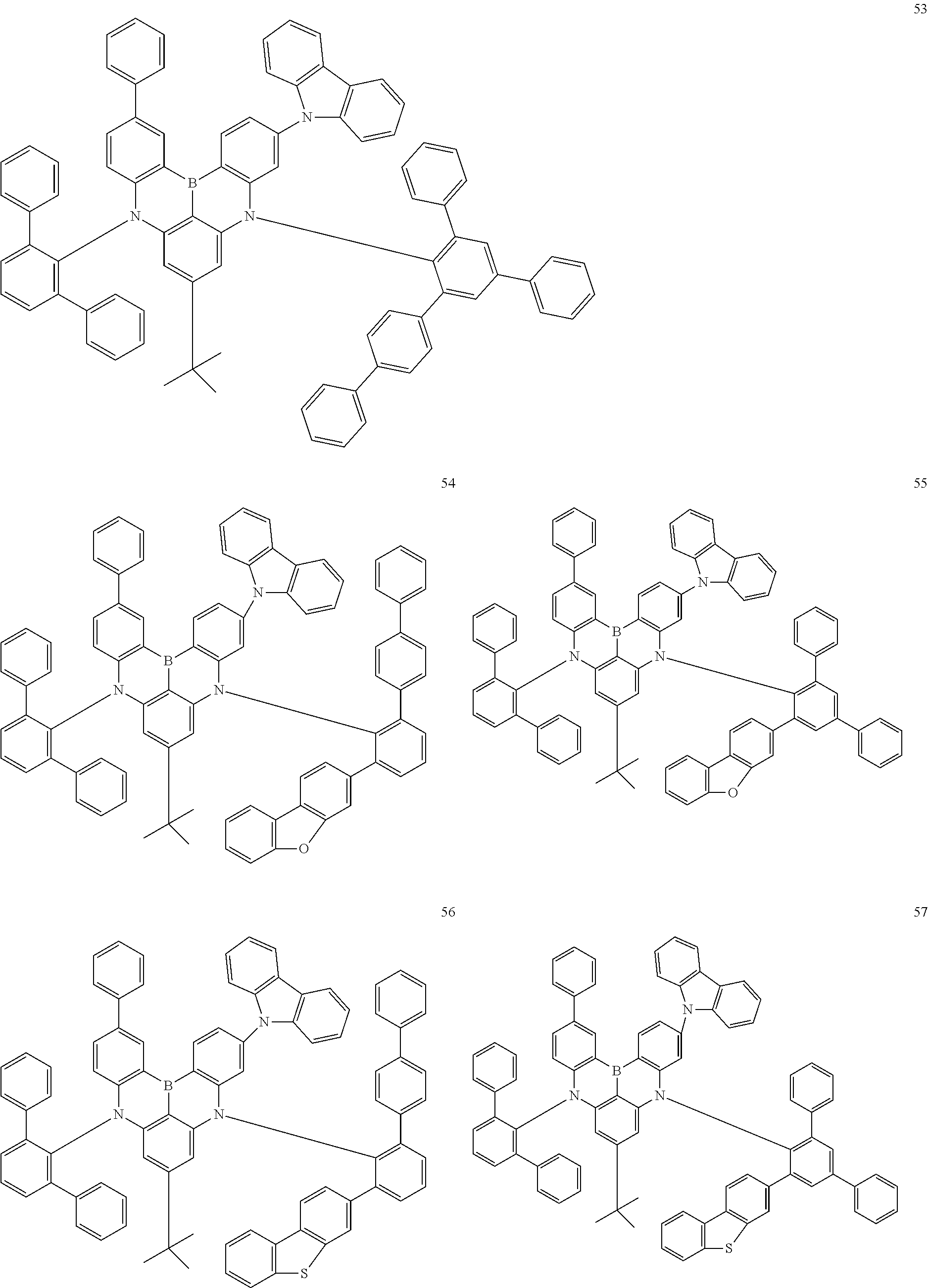

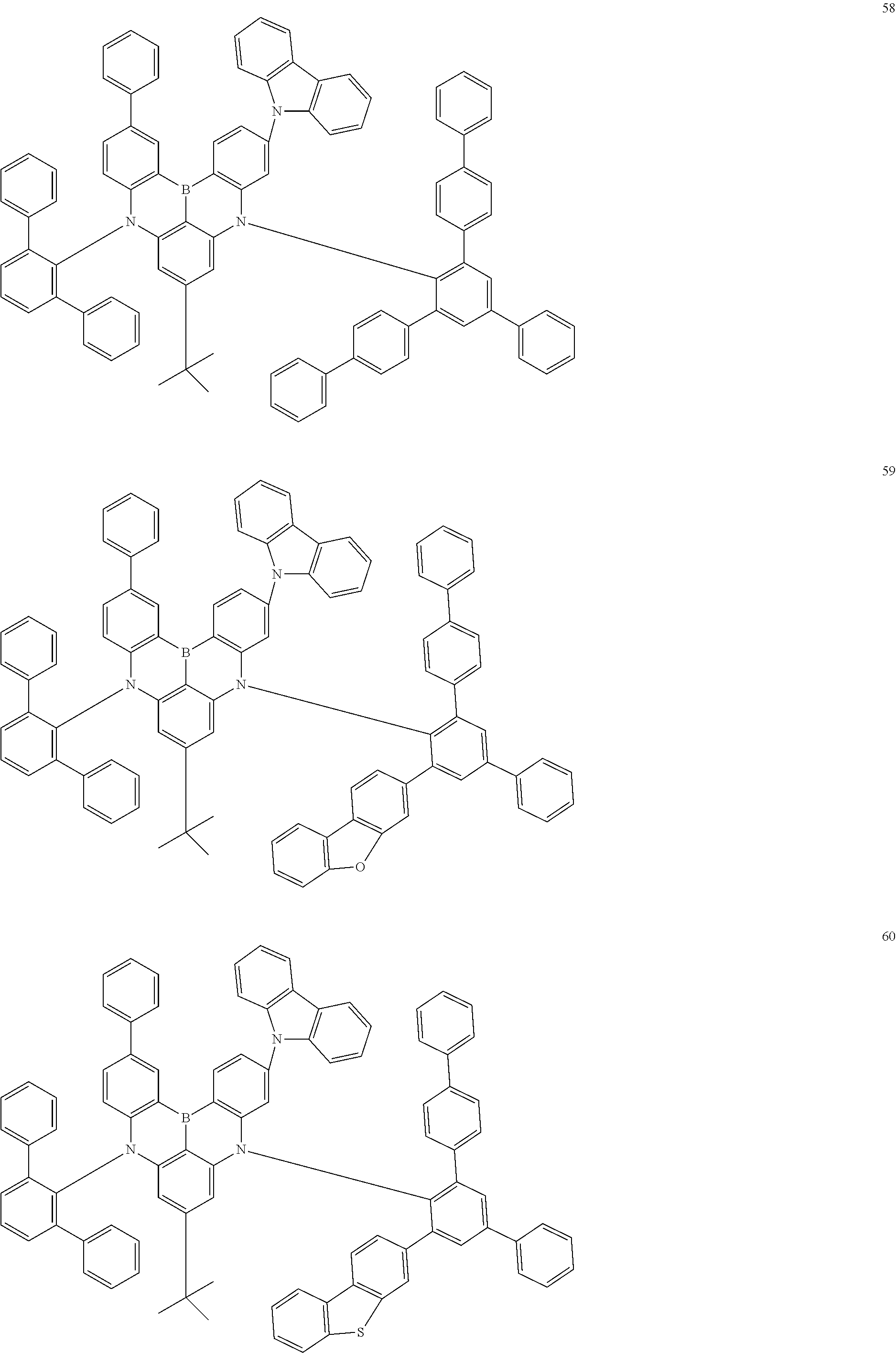

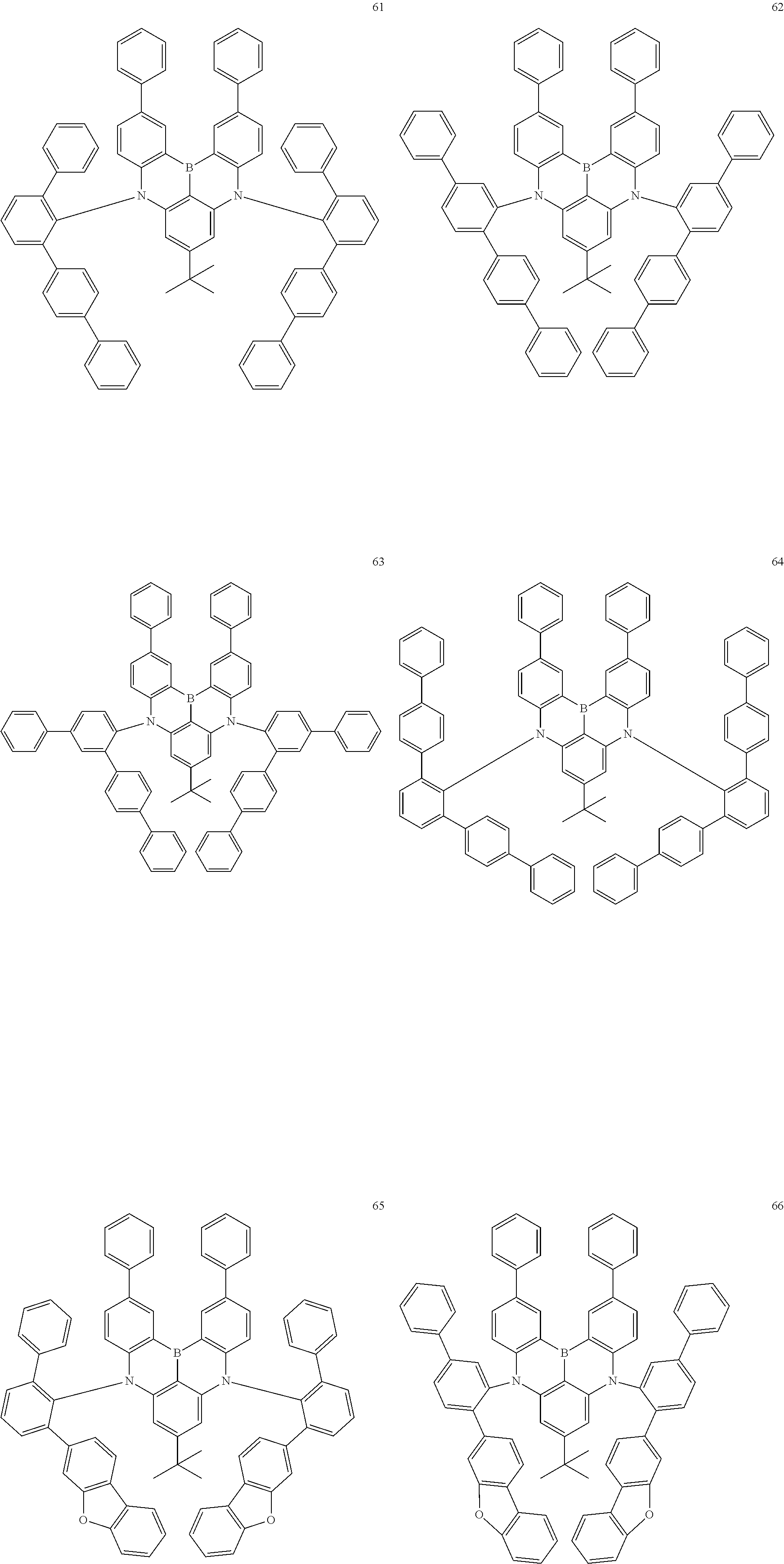

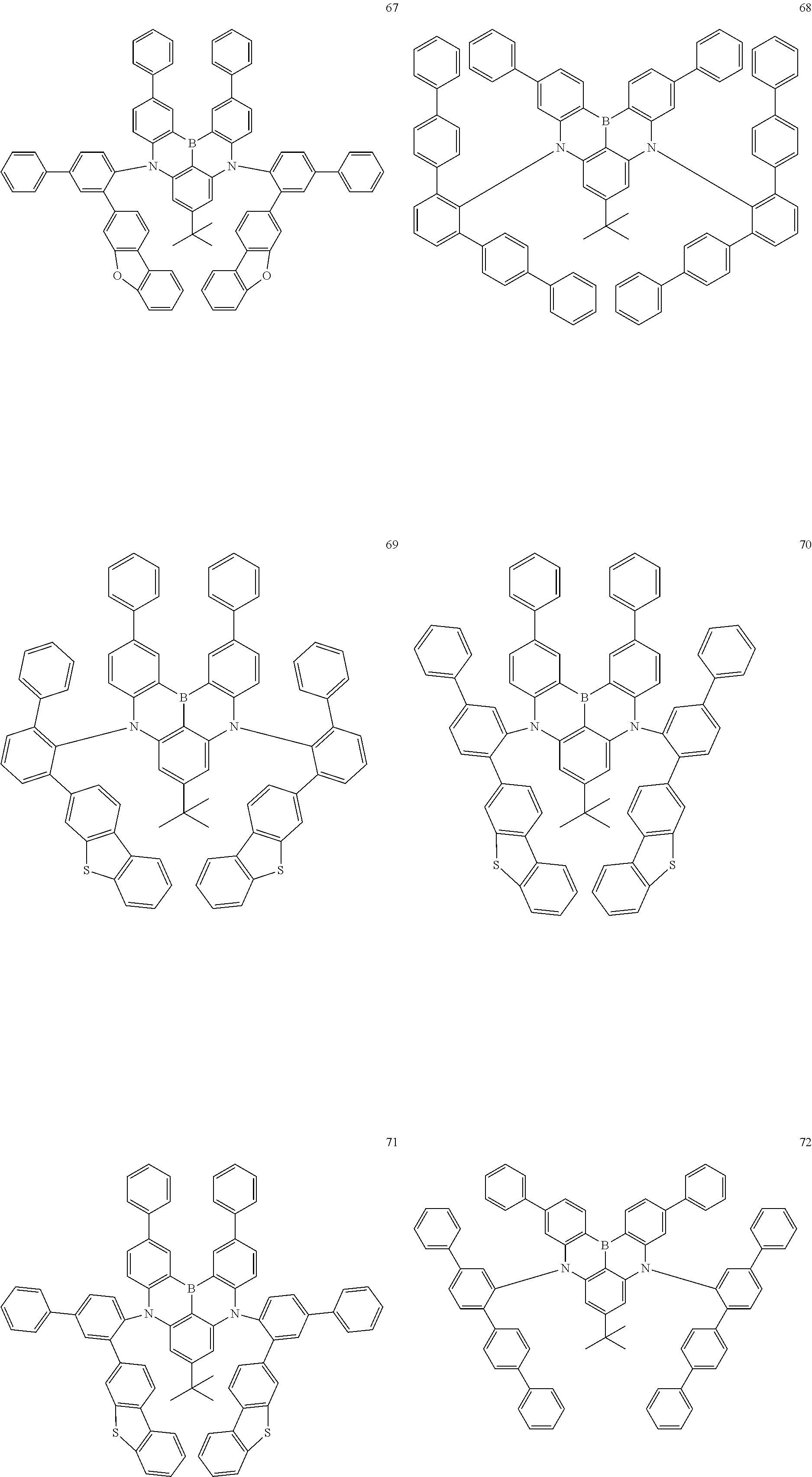

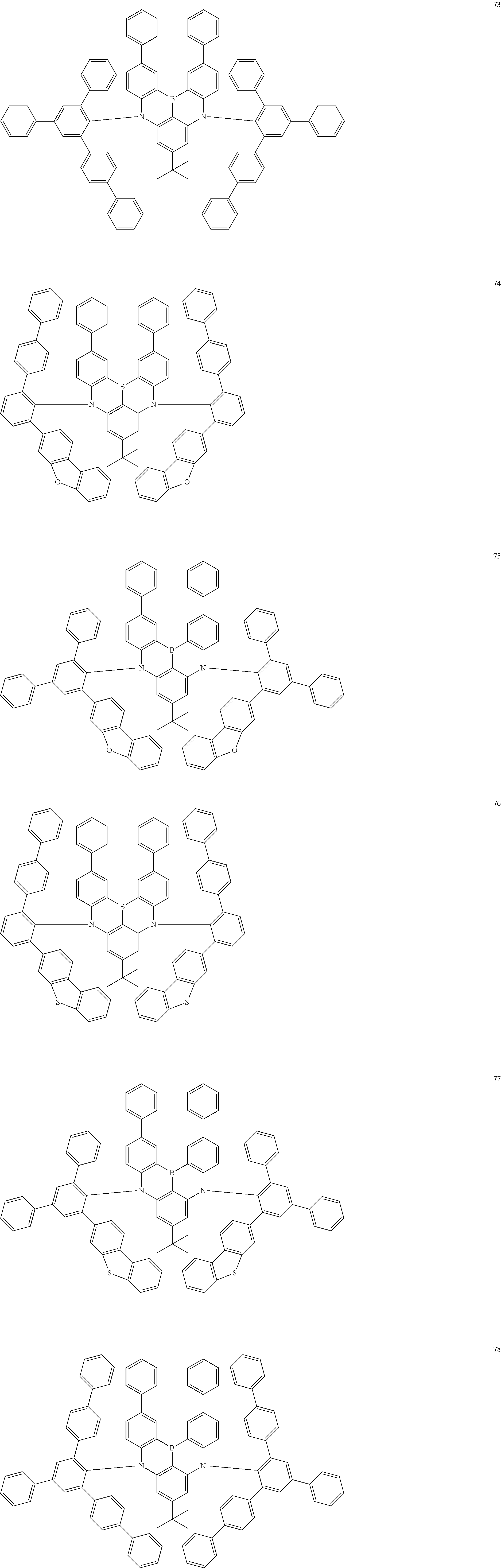

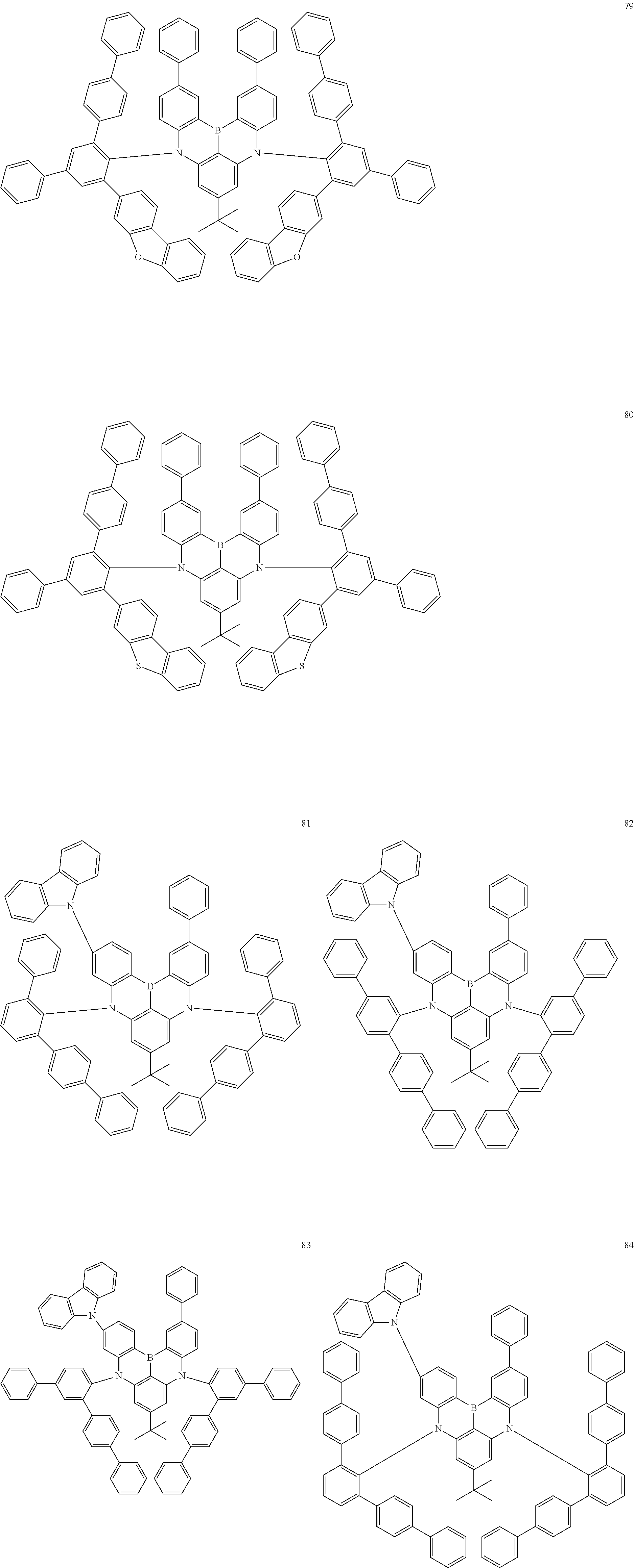

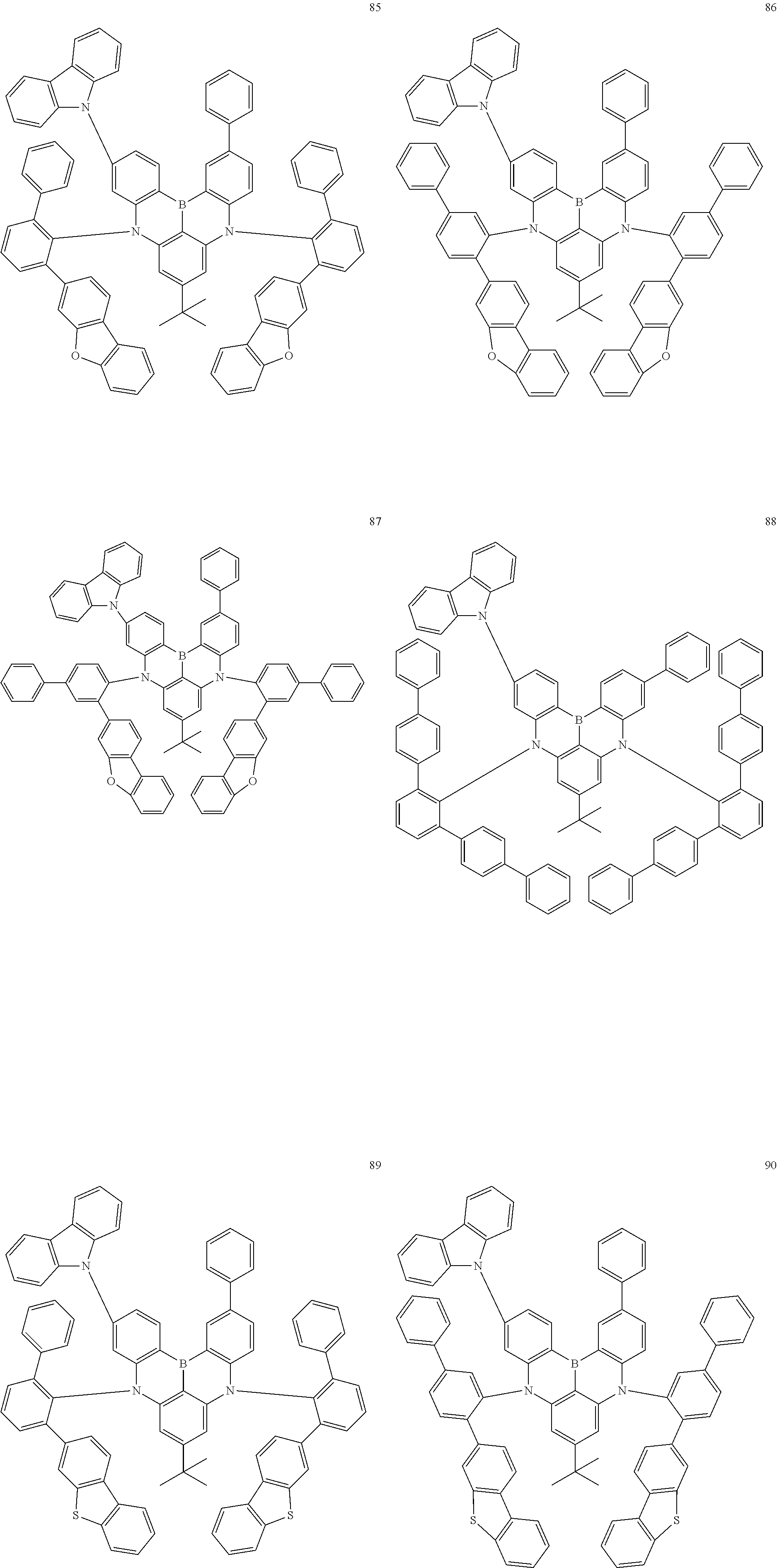

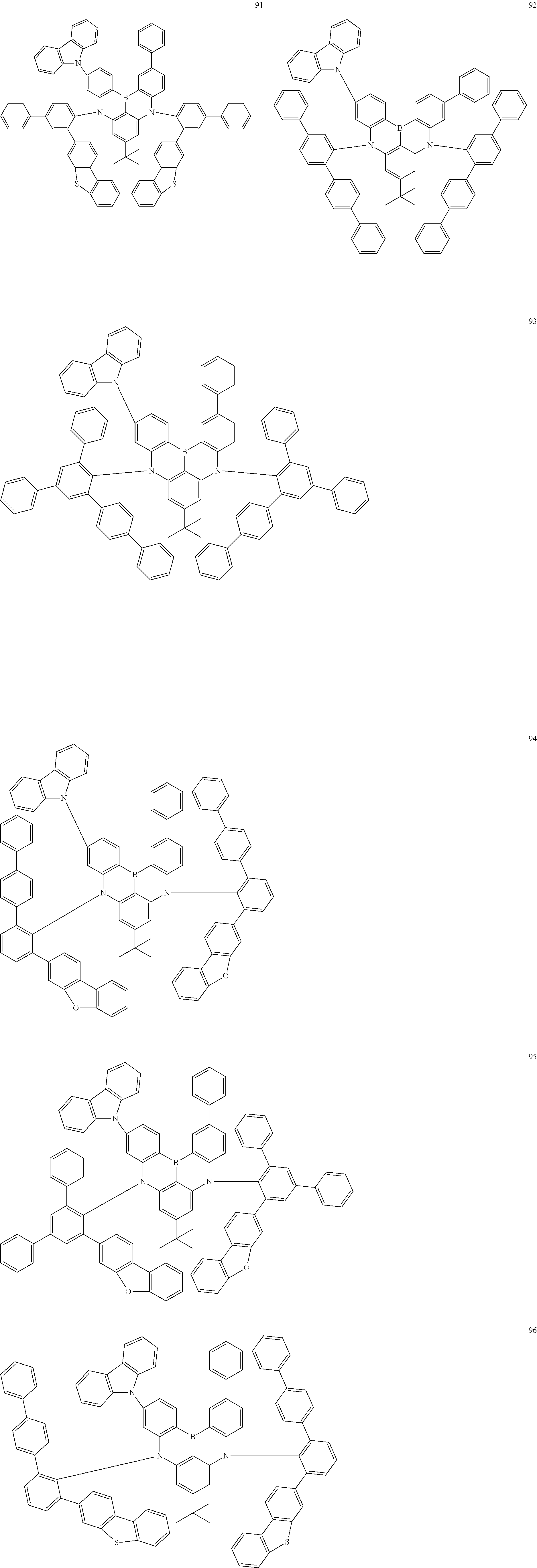

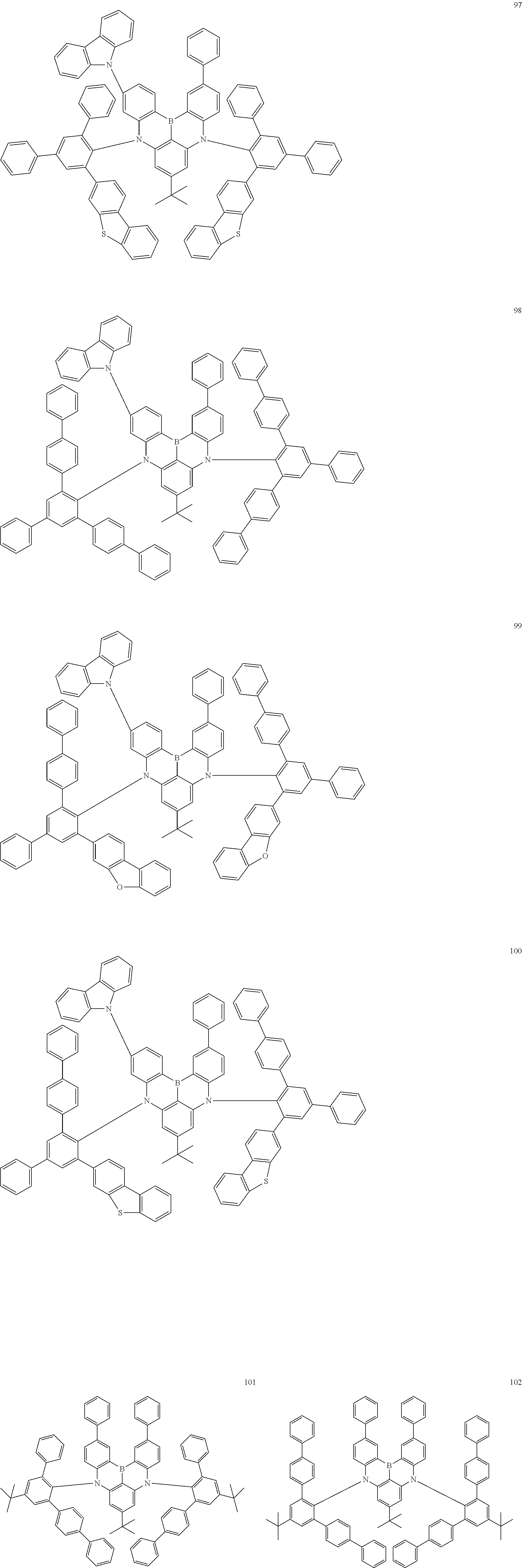

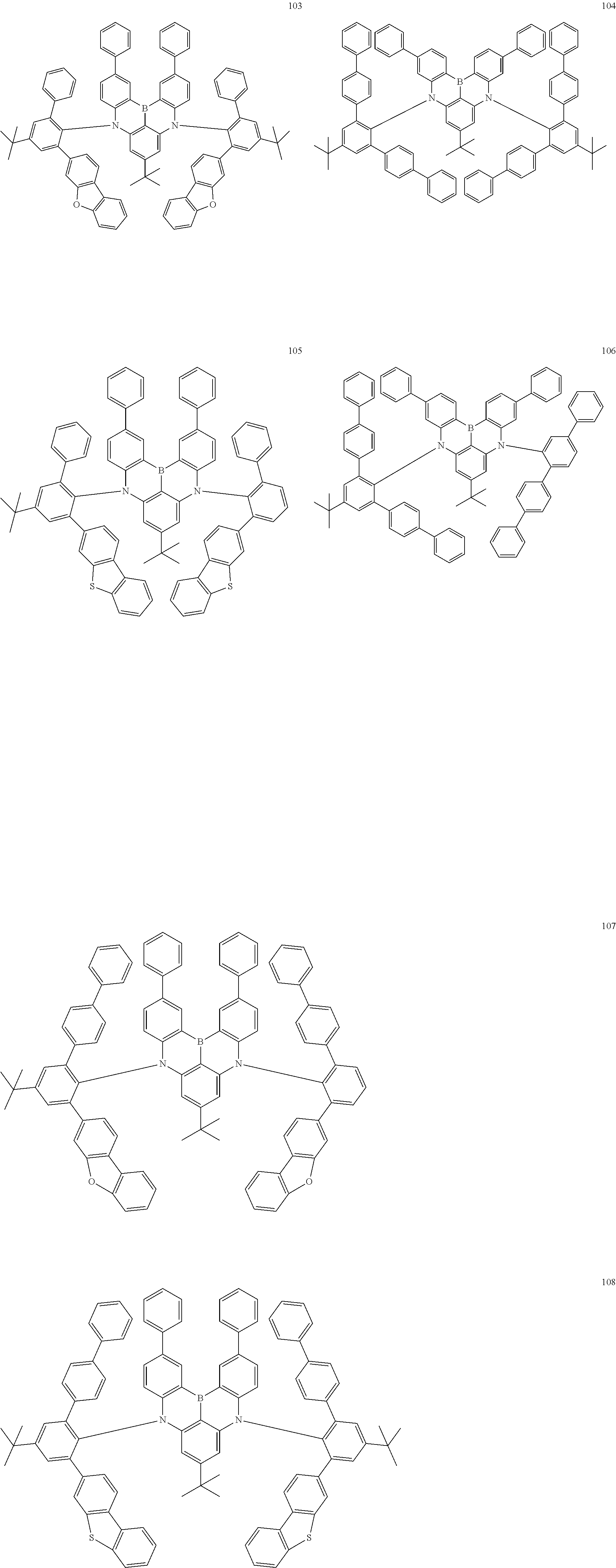

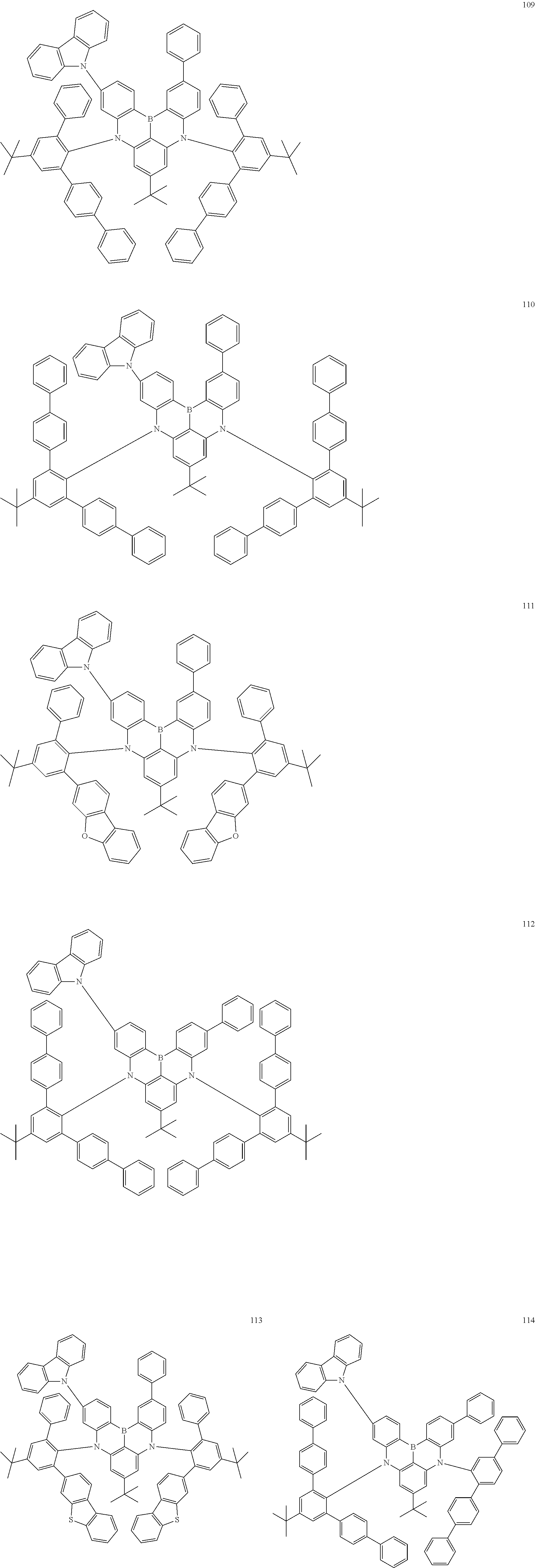

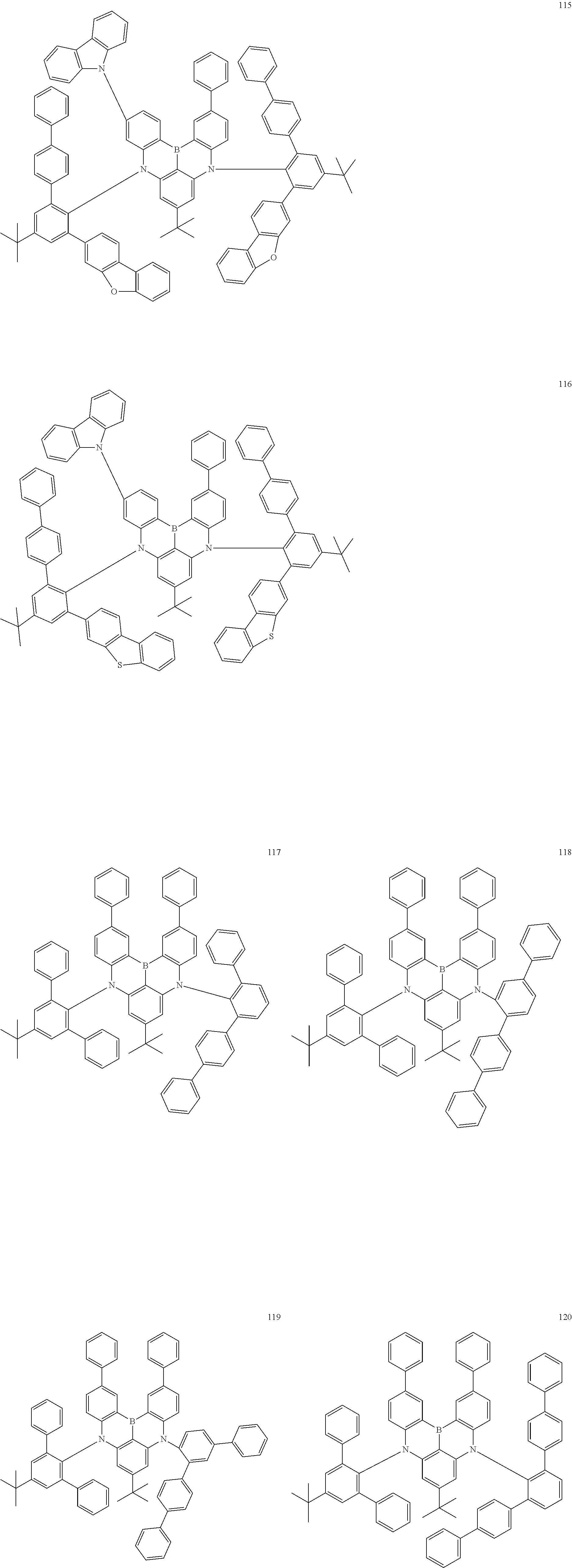

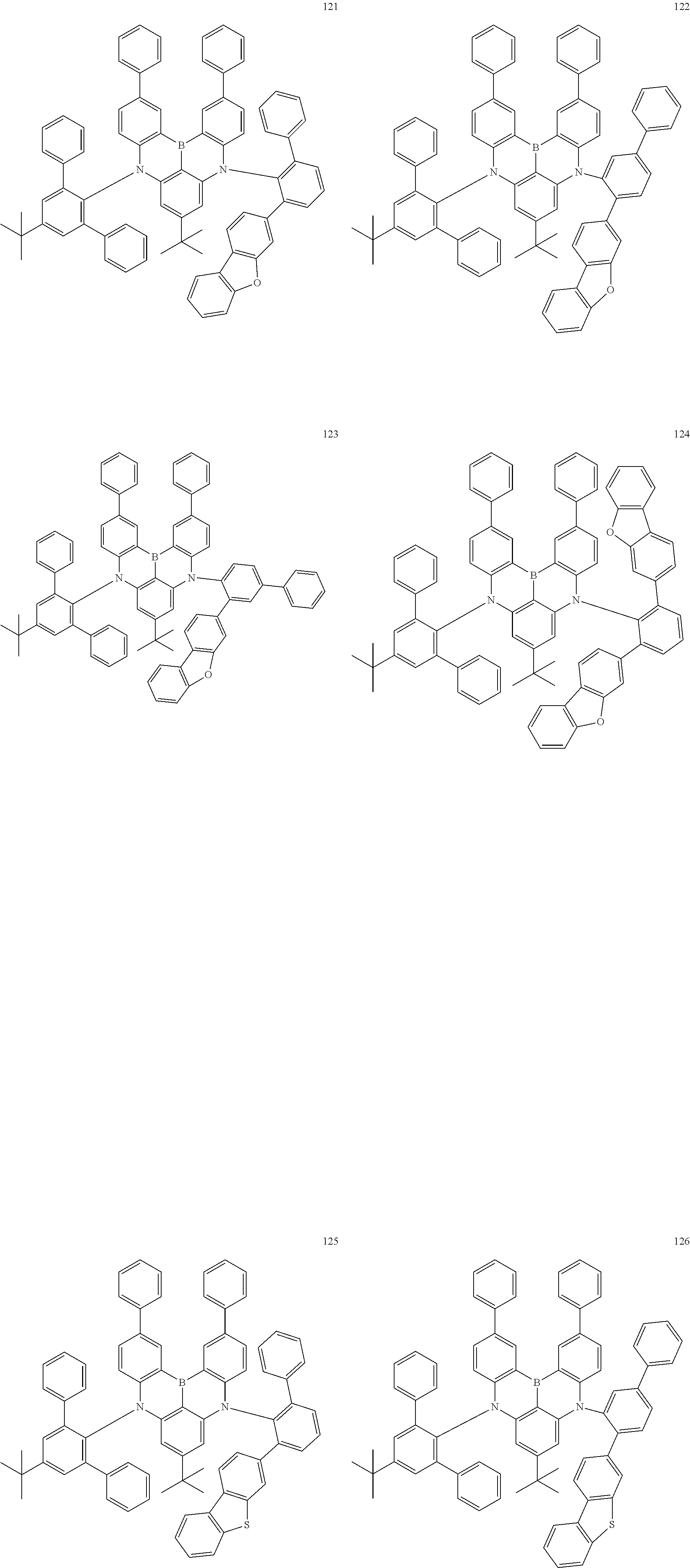

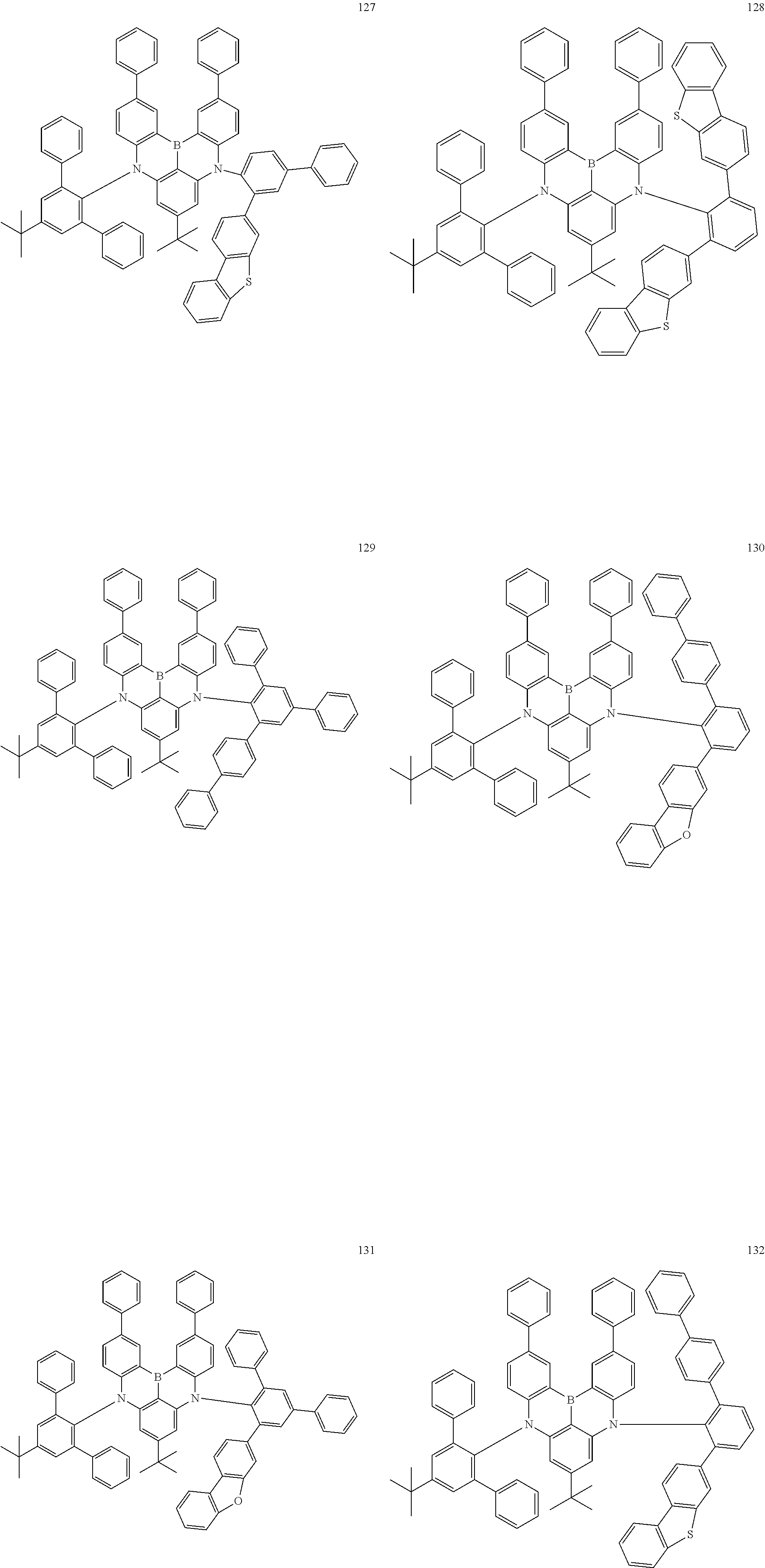

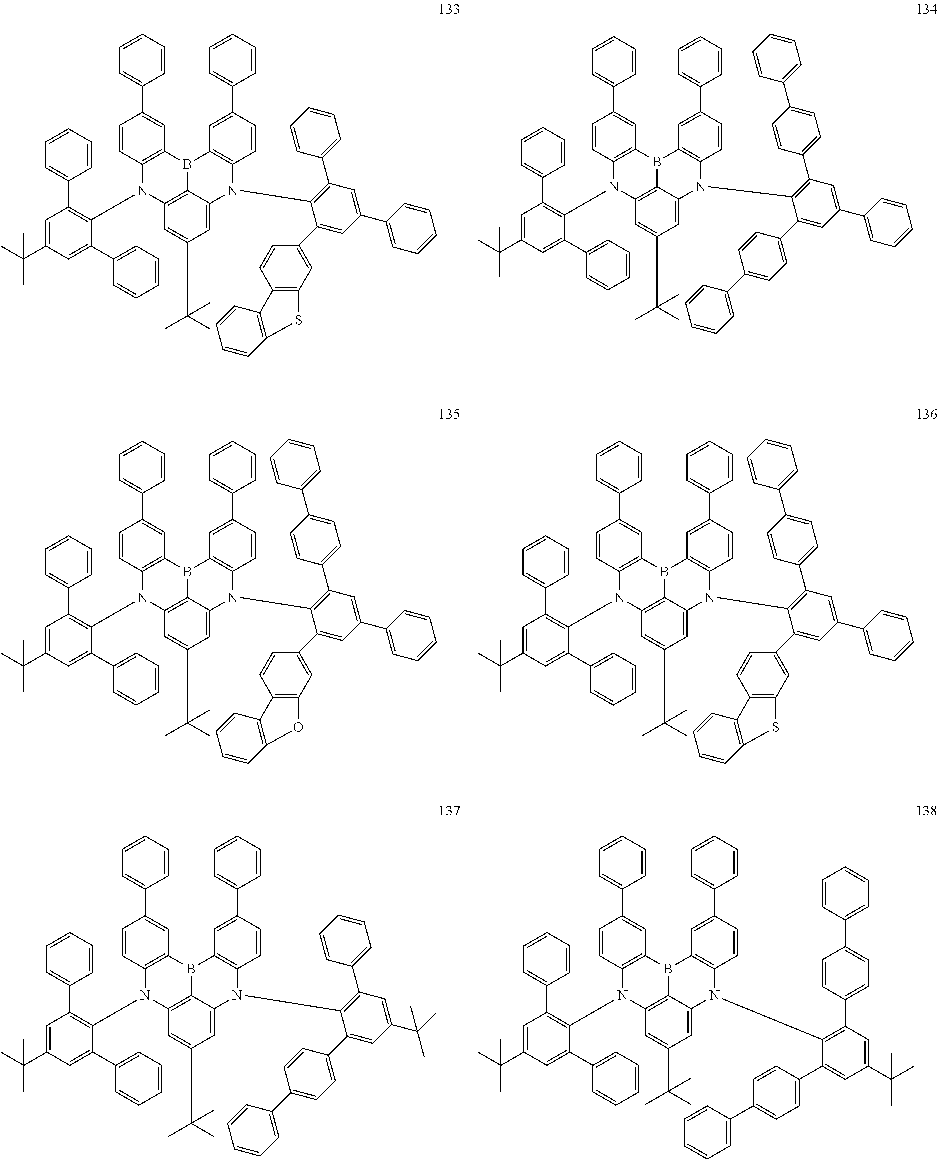

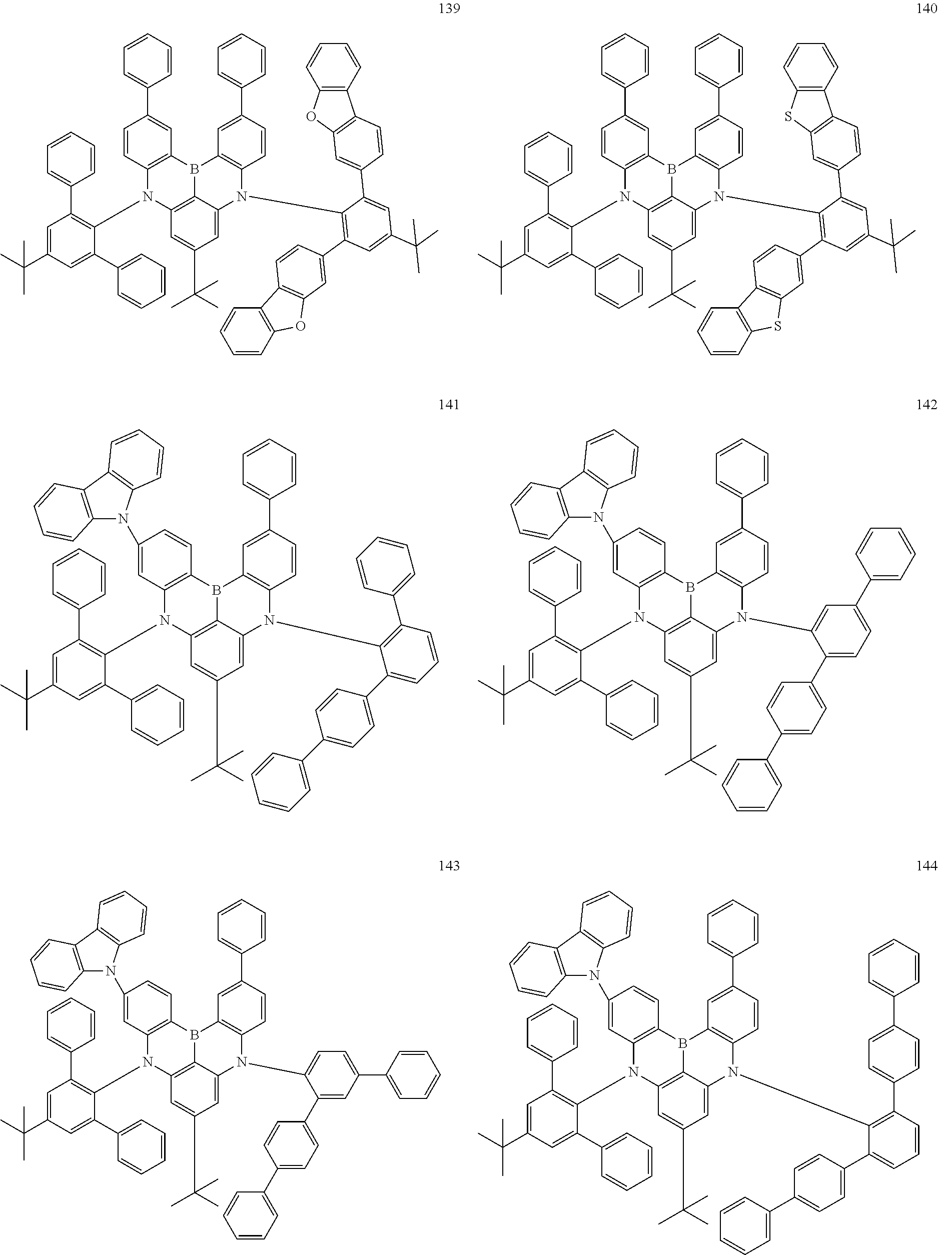

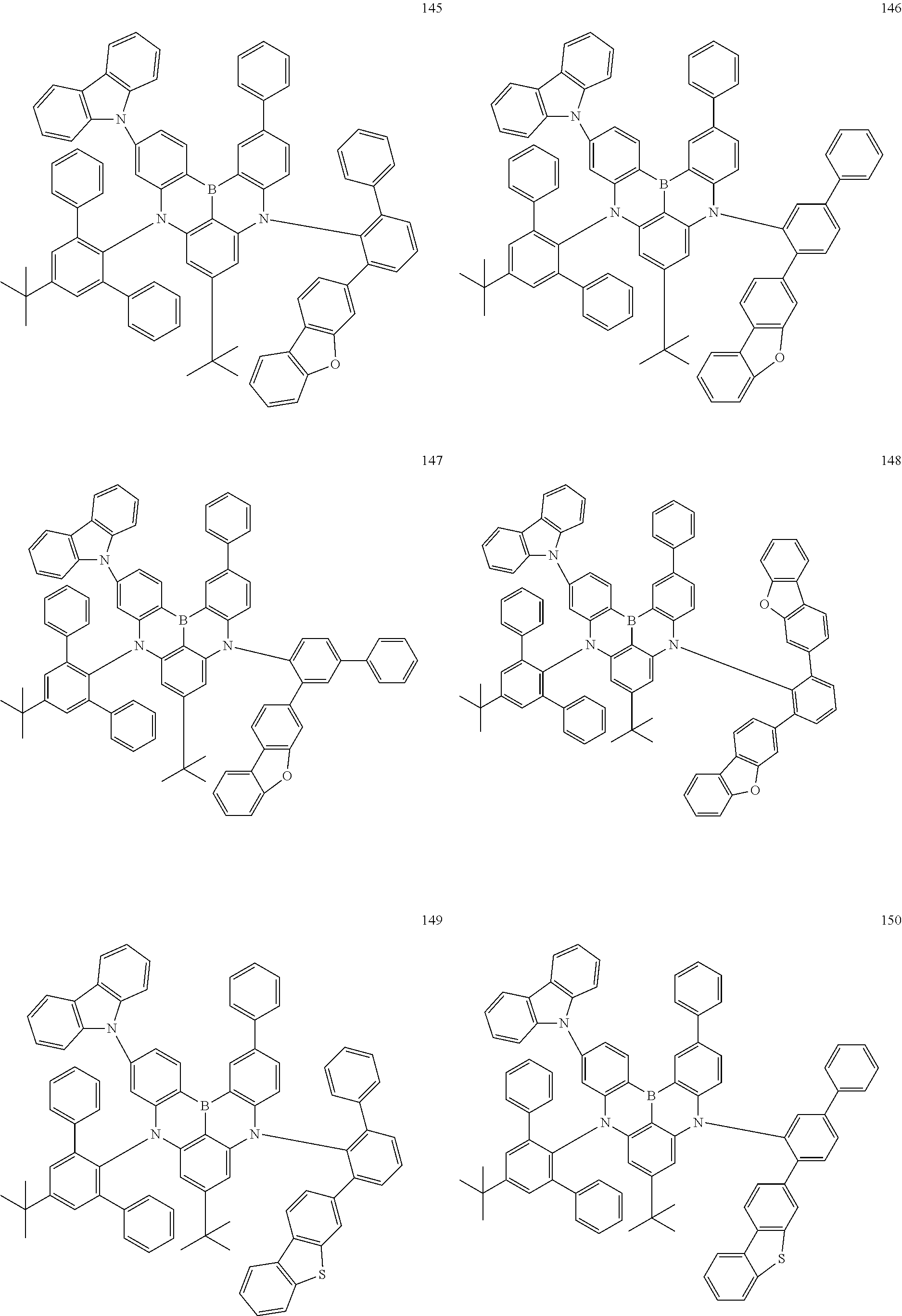

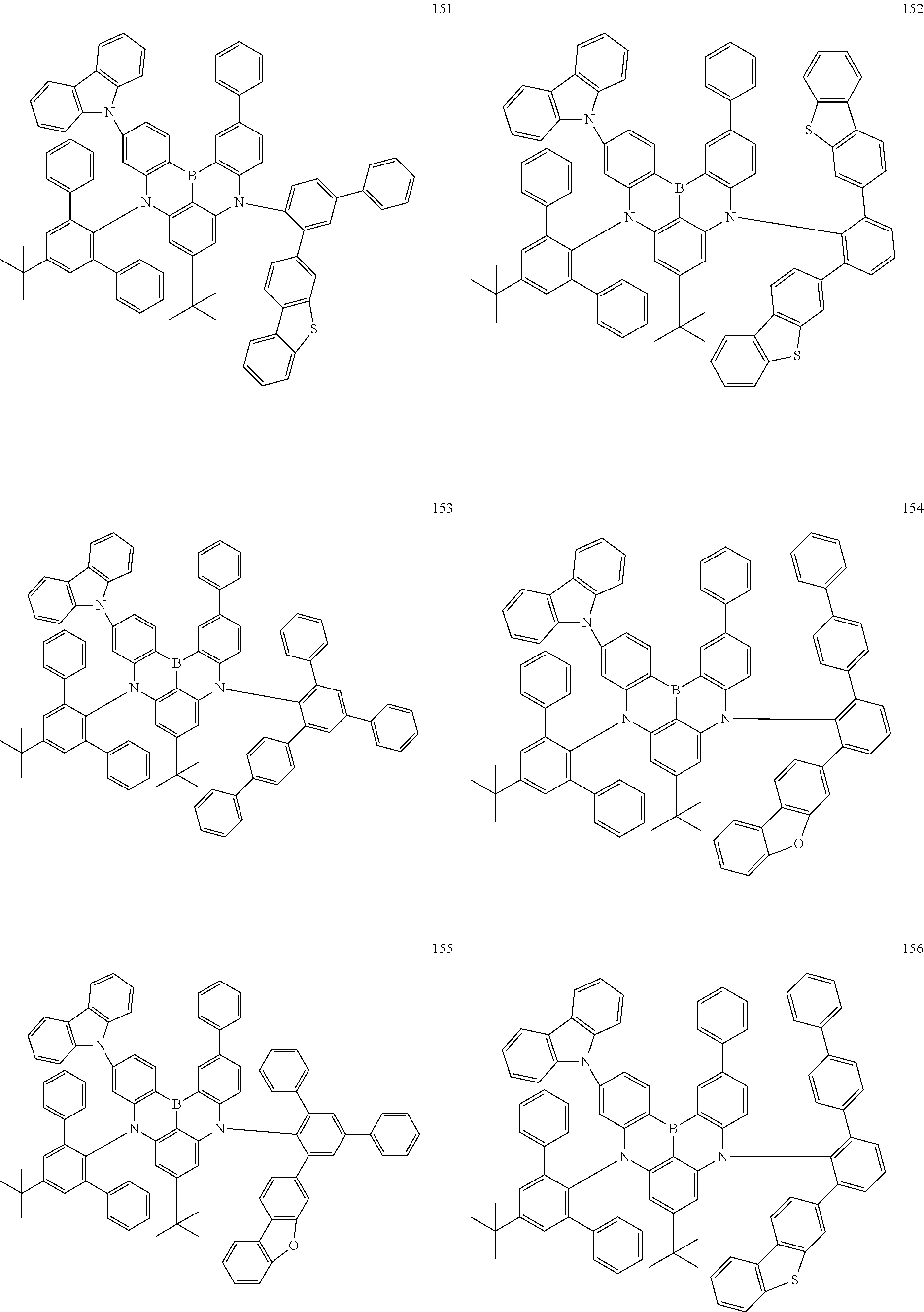

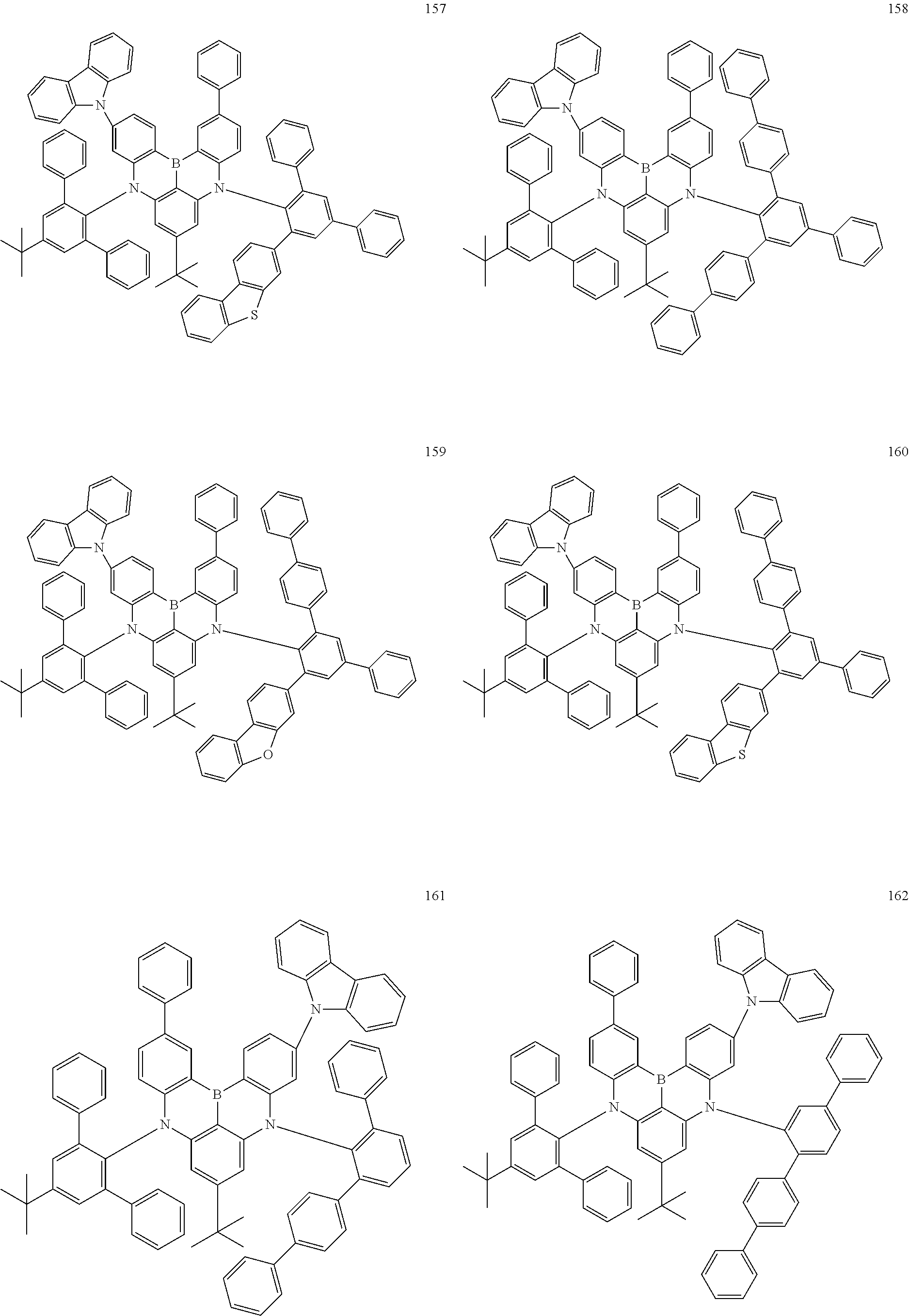

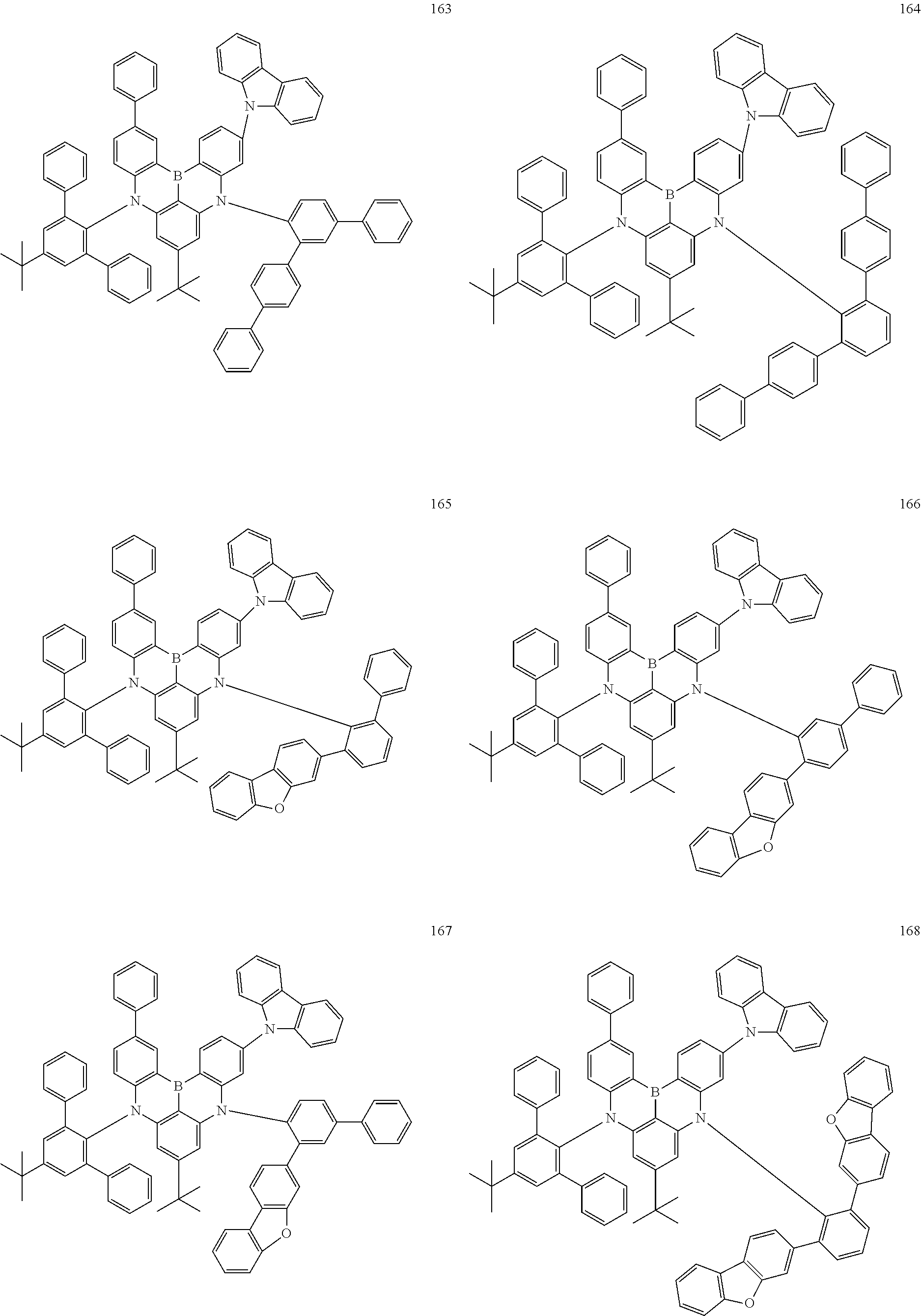

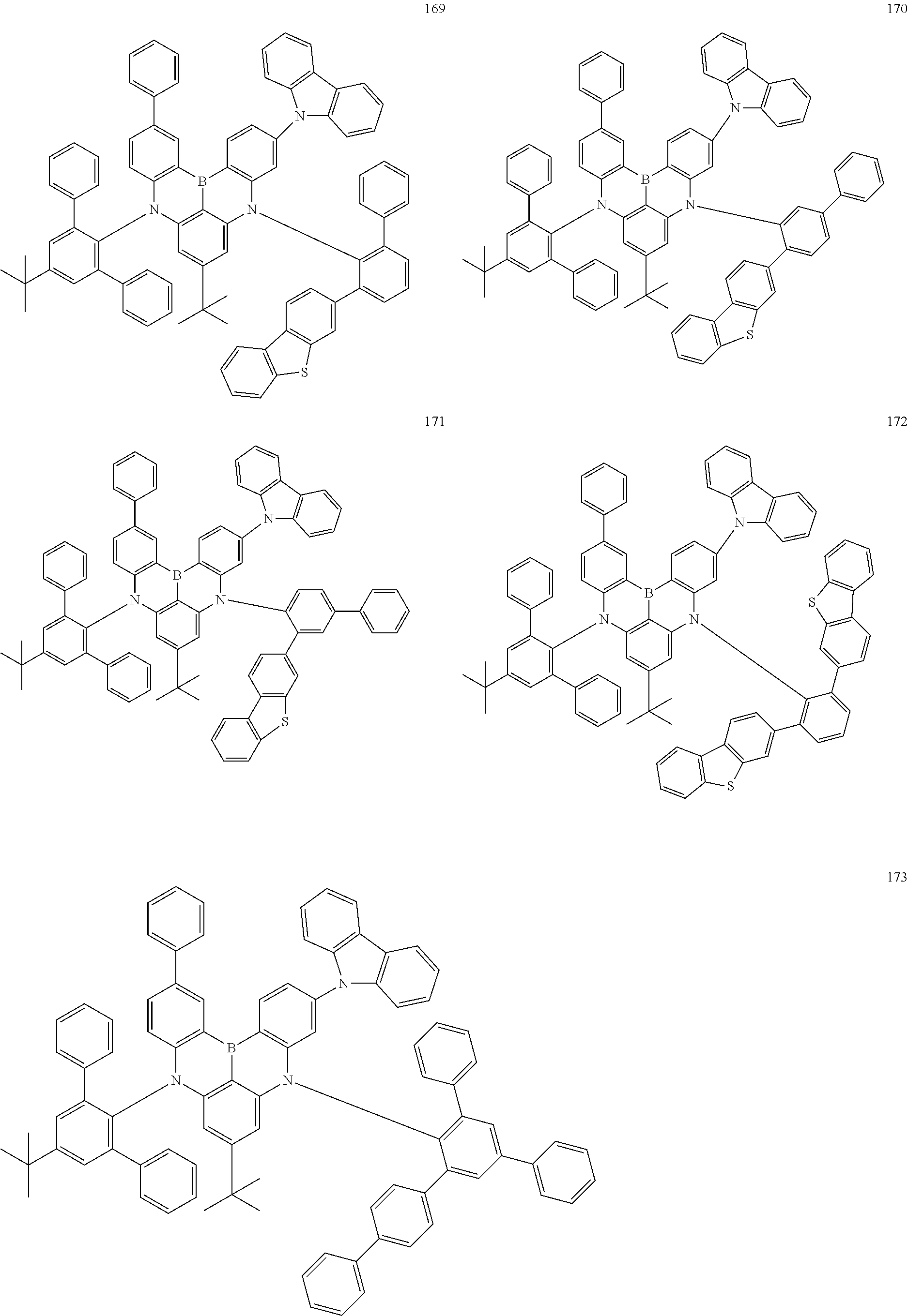

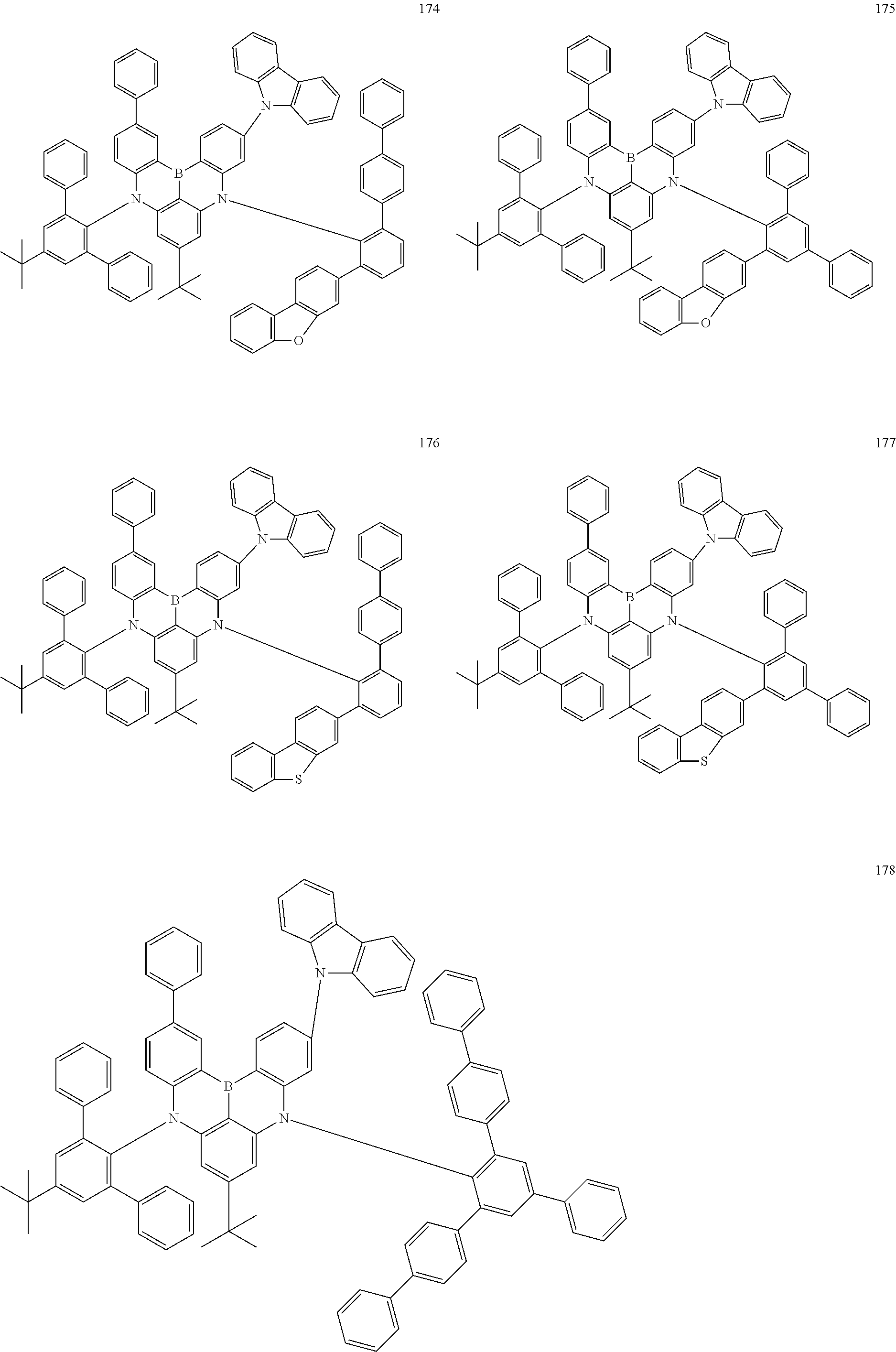

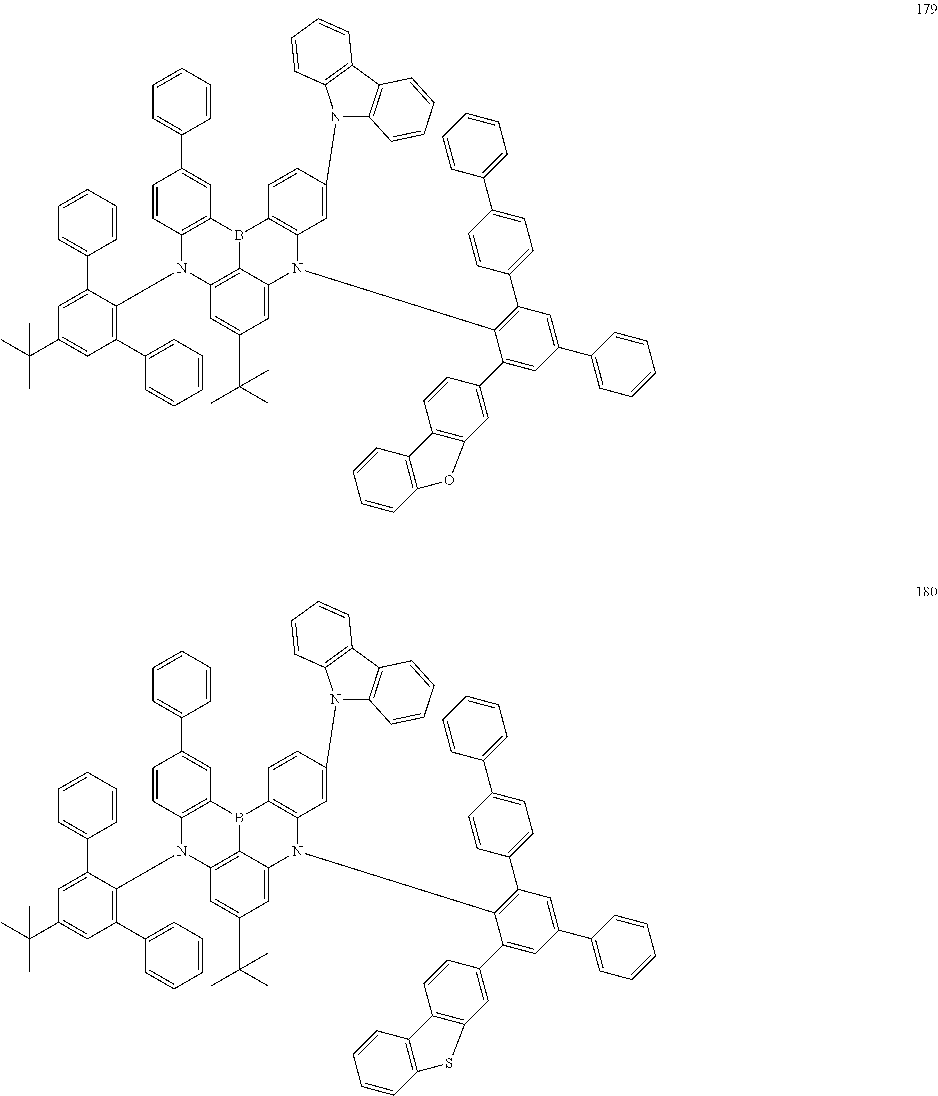 [SMILES: CC(C)(C)c1cc(-c2ccccc2)c(N2c3ccc(-c4ccccc4)cc3B3c4ccc(-n5c6ccccc6c6ccccc65)cc4N(c4c(-c5ccc(-c6ccccc6)cc5)cc(-c5ccccc5)cc4-c4ccc5c(c4)oc4ccccc45)c4cc(C(C)(C)C)cc2c43)c(-c2ccccc2)c1 ; CC(C)(C)c1cc(-c2ccccc2)c(N2c3ccc(-c4ccccc4)cc3B3c4ccc(-n5c6ccccc6c6ccccc65)cc4N(c4c(-c5ccc(-c6ccccc6)cc5)cc(-c5ccccc5)cc4-c4ccc5c(c4)sc4ccccc45)c4cc(C(C)(C)C)cc2c43)c(-c2ccccc2)c1]

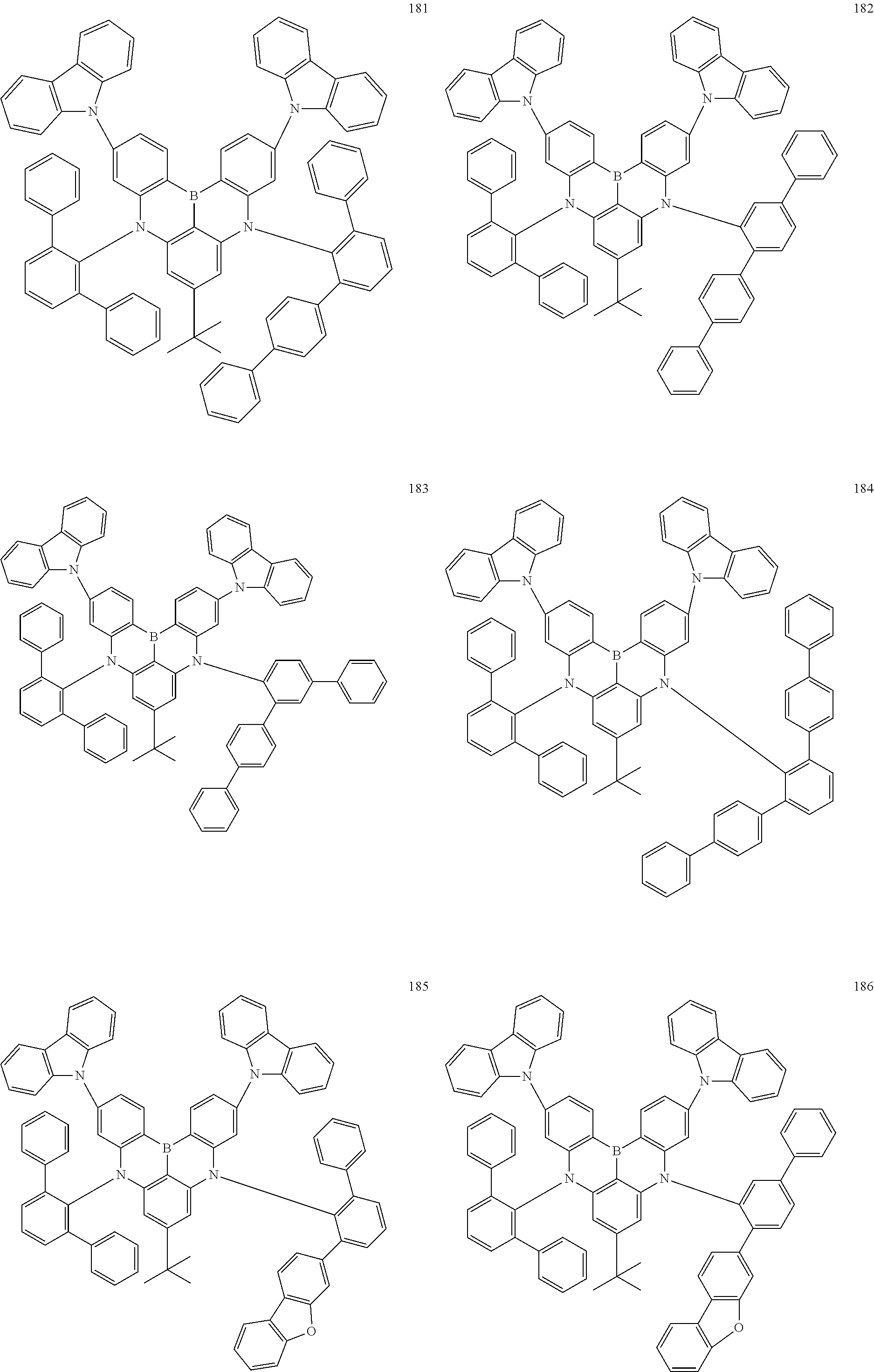

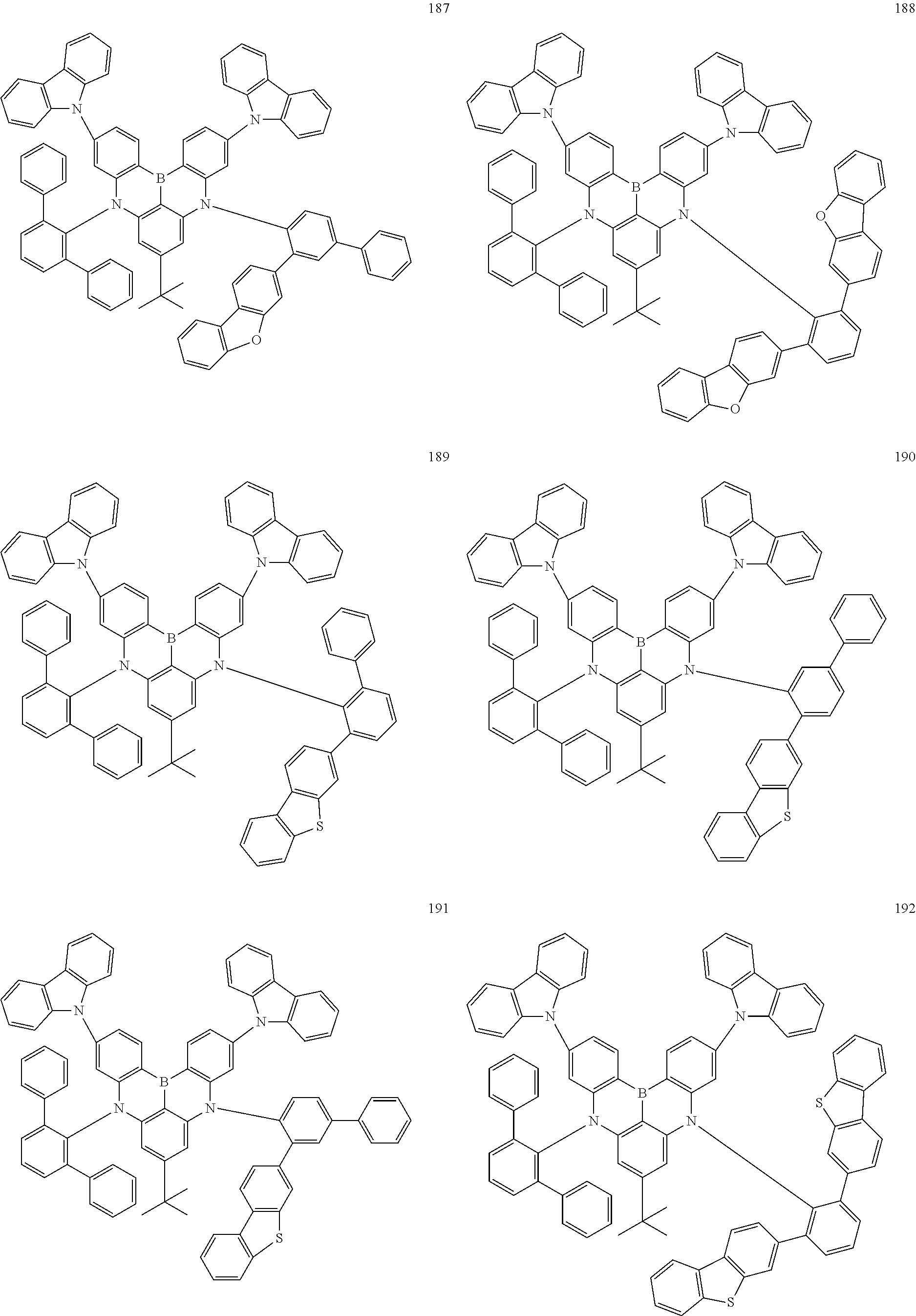

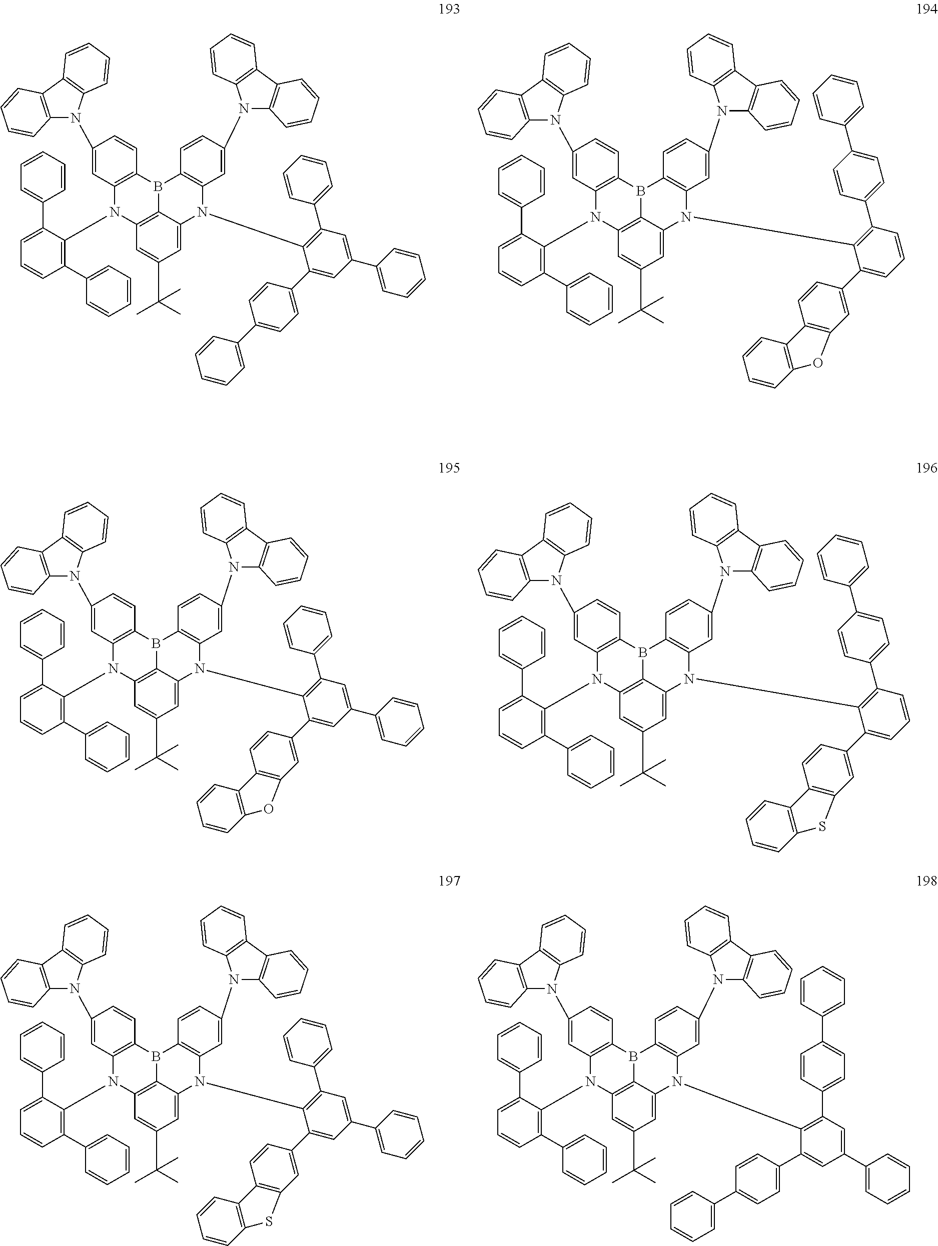

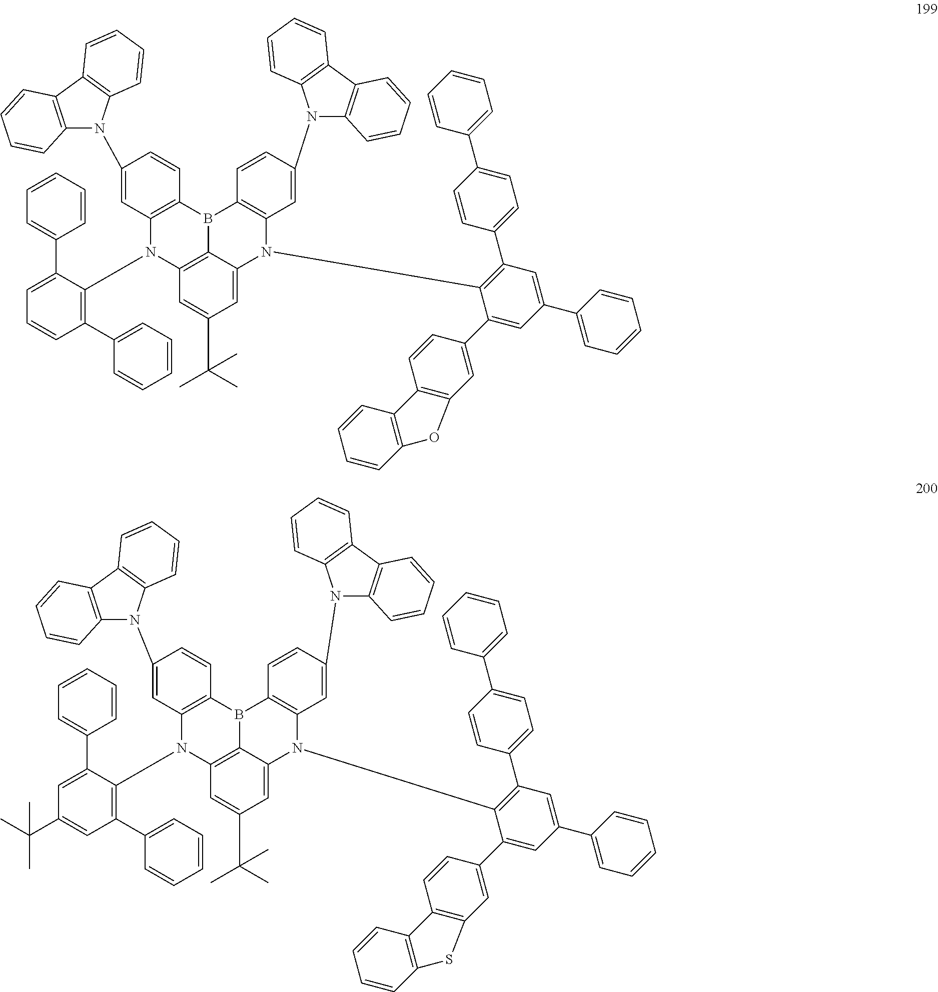

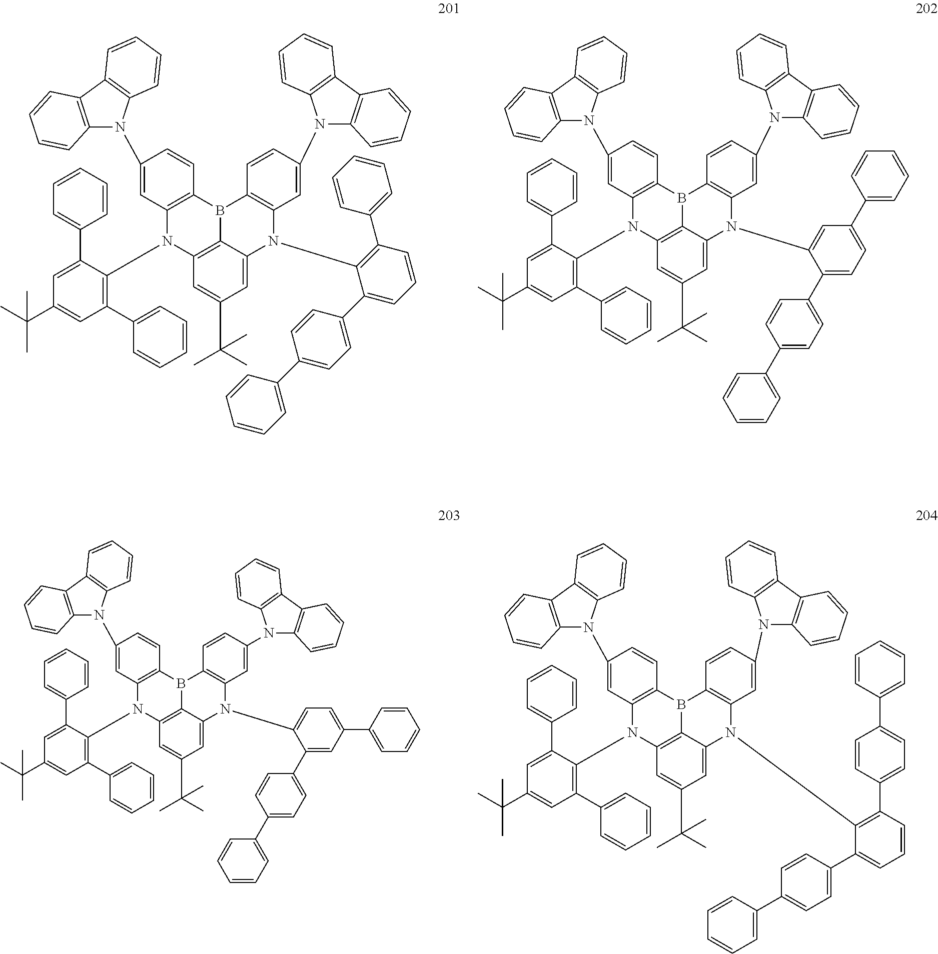

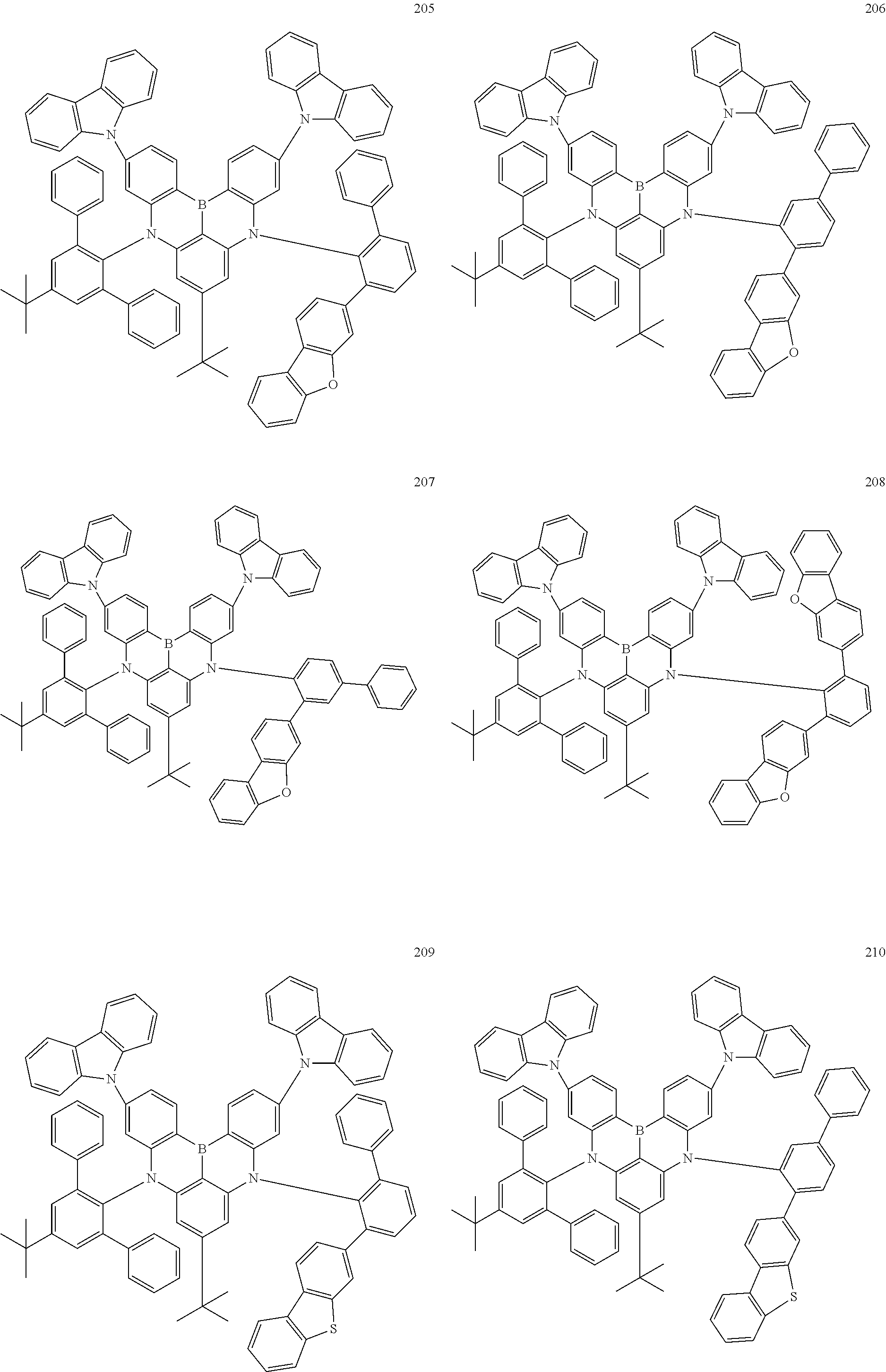

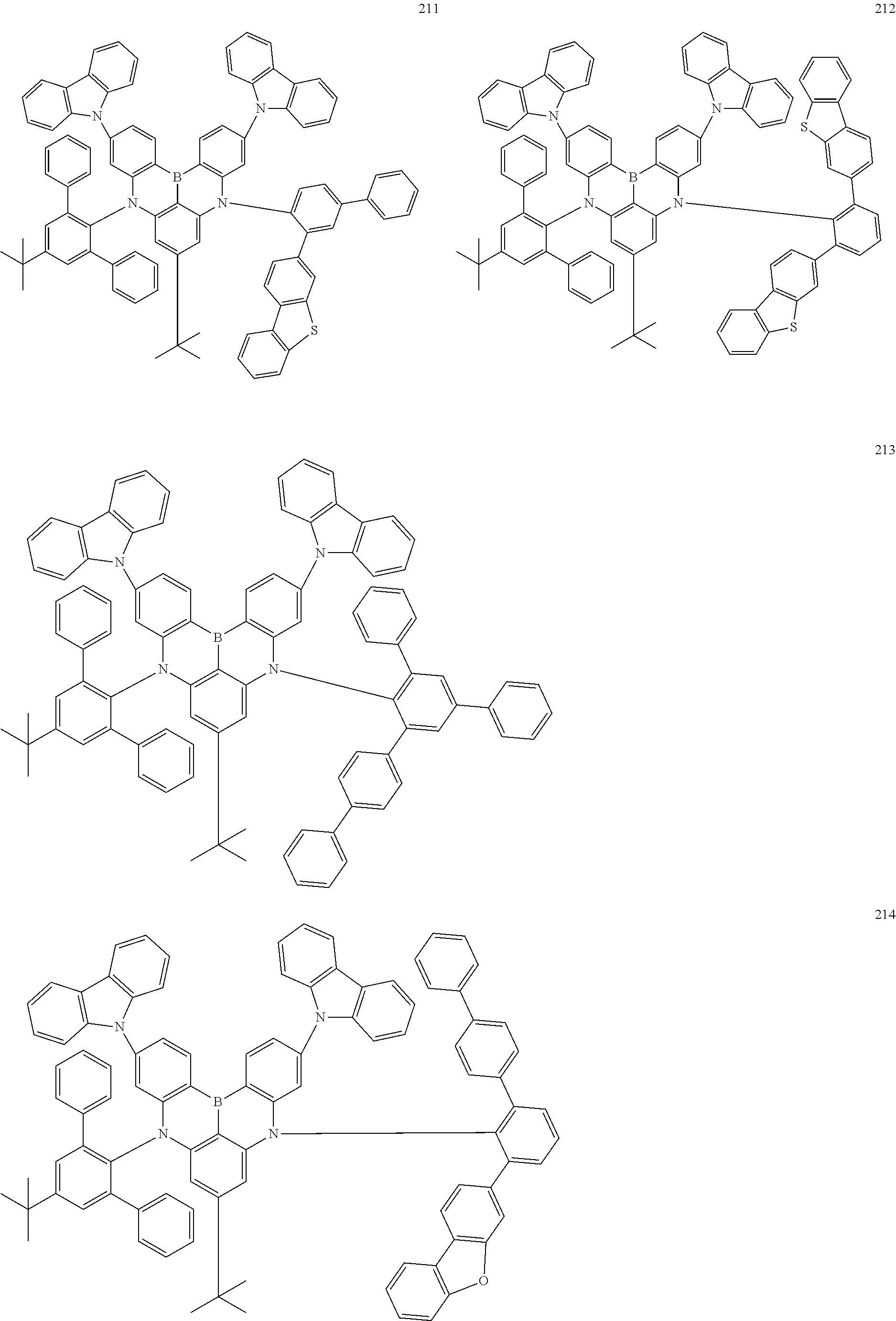

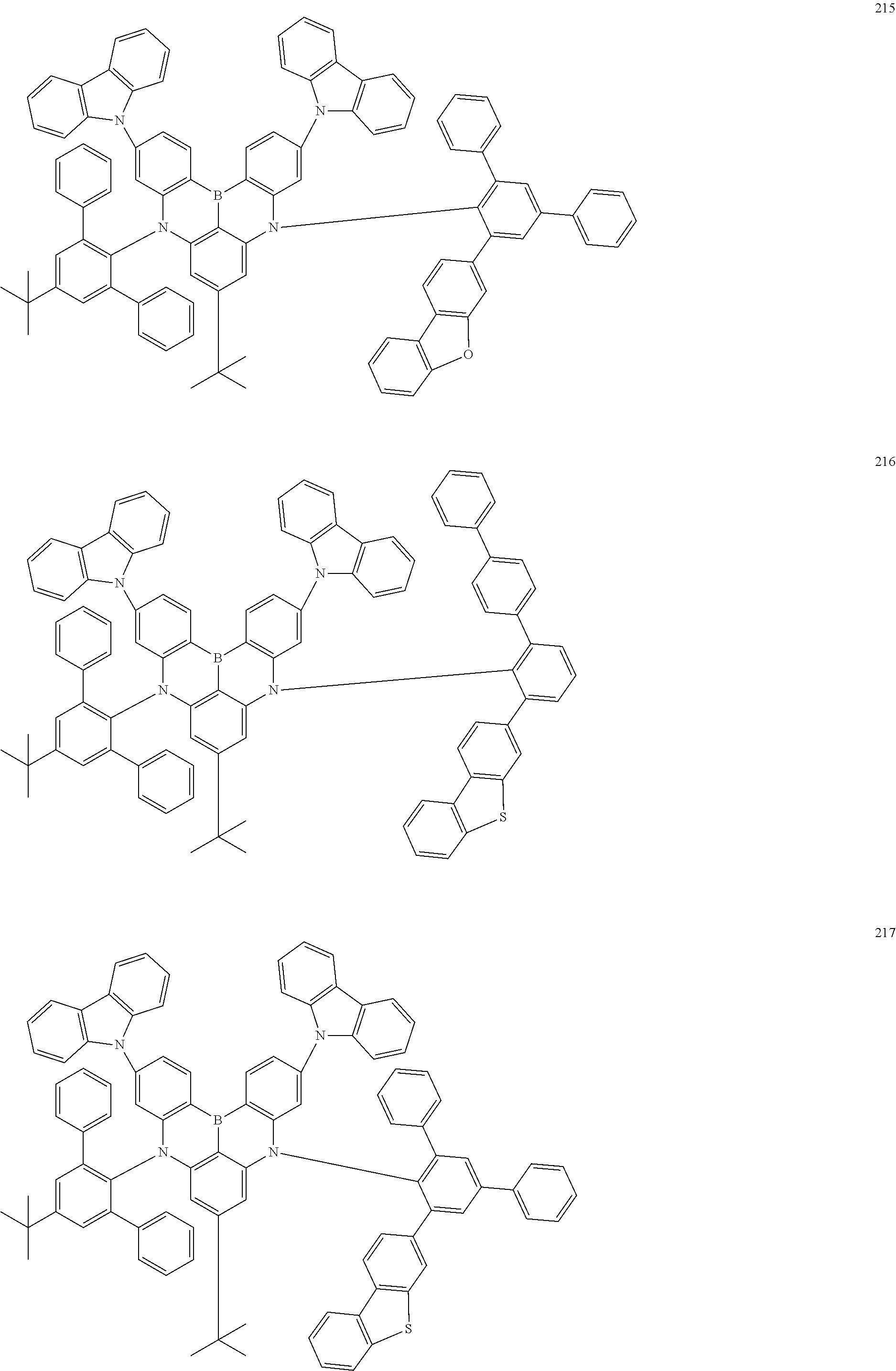

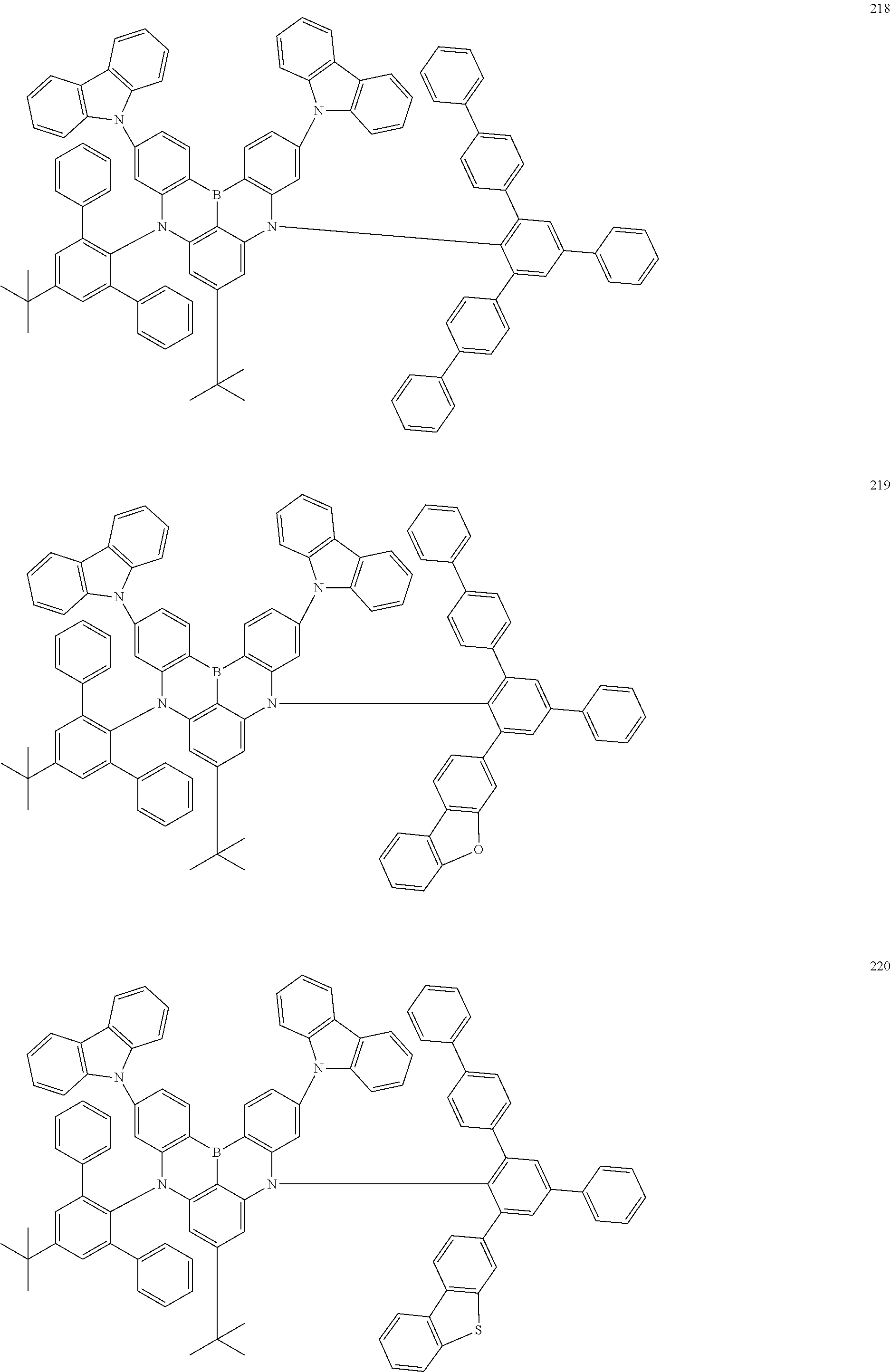

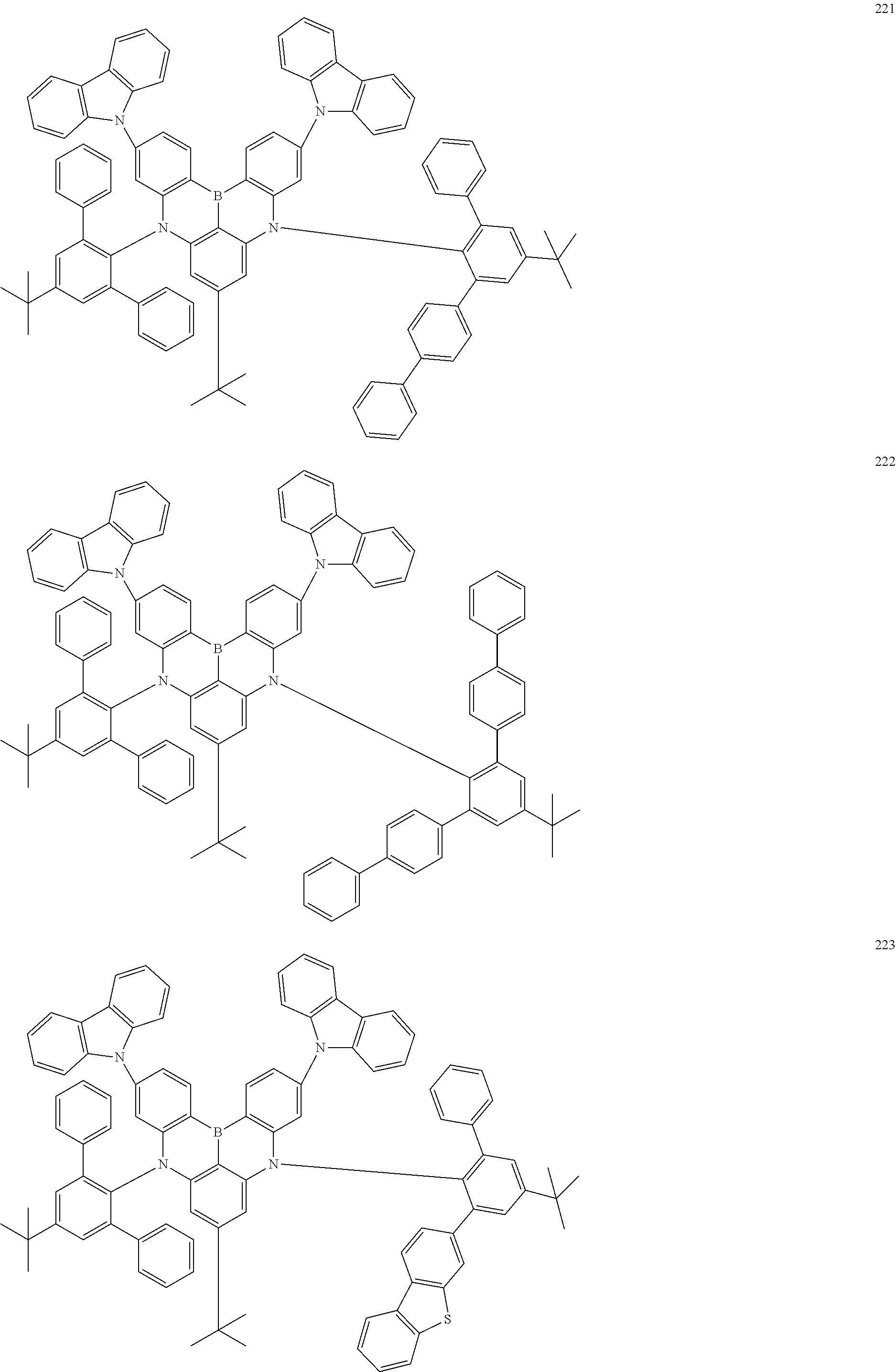

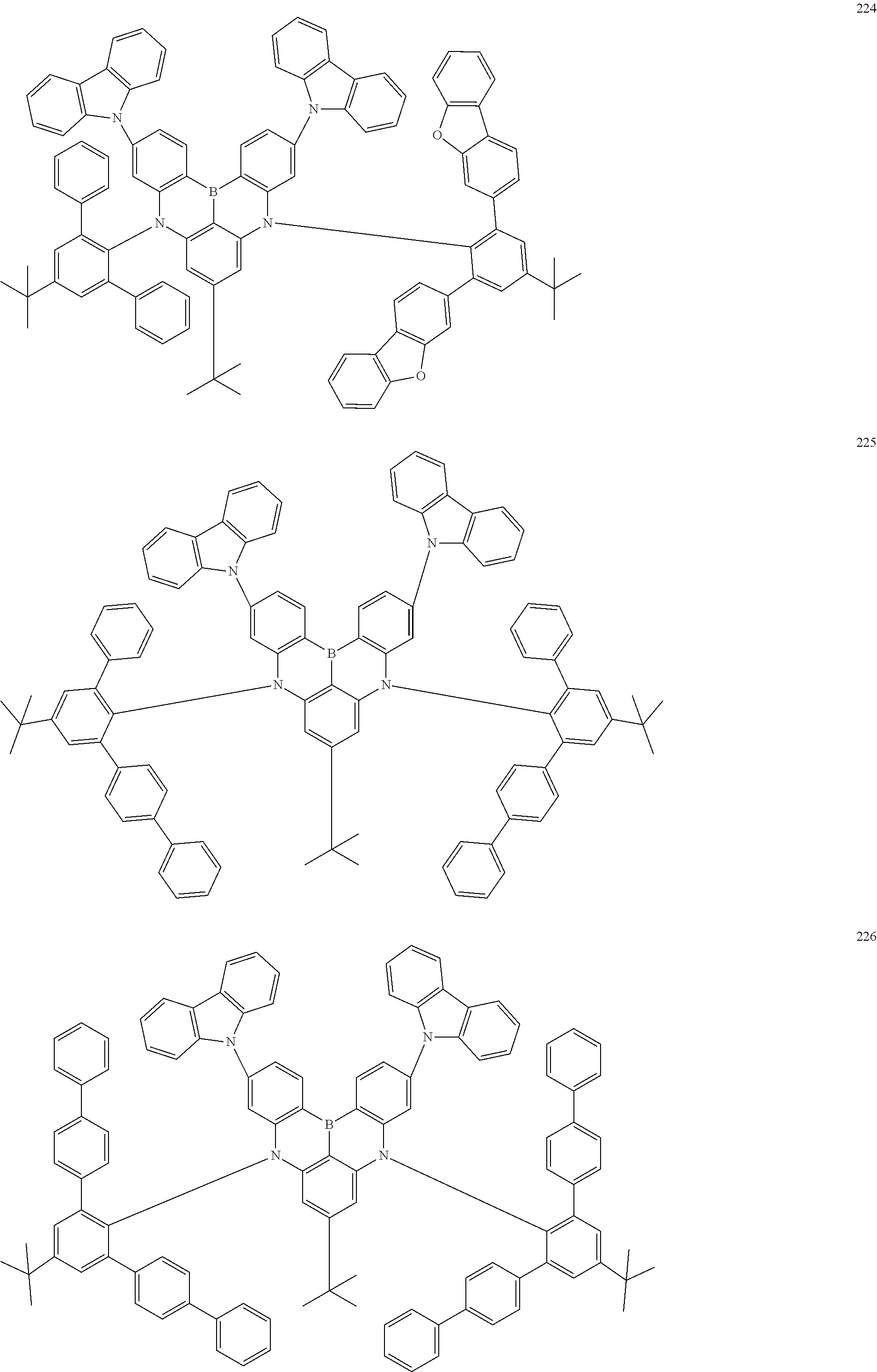

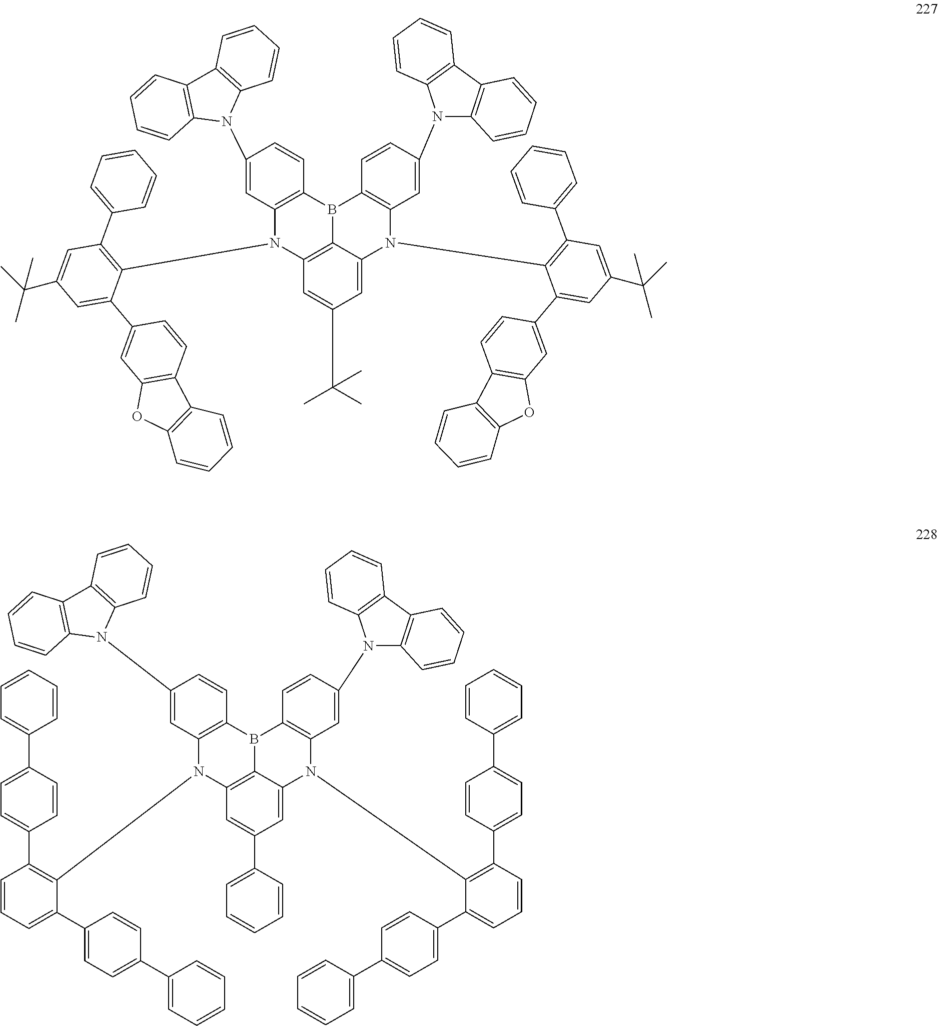 [SMILES: CC(C)(C)c1cc(-c2ccccc2)c(N2c3cc(-n4c5ccccc5c5ccccc54)ccc3B3c4ccc(-n5c6ccccc6c6ccccc65)cc4N(c4c(-c5ccccc5)cc(C(C)(C)C)cc4-c4ccc5c(c4)oc4ccccc45)c4cc(C(C)(C)C)cc2c43)c(-c2ccc3c(c2)oc2ccccc23)c1 ; c1ccc(-c2ccc(-c3cccc(-c4ccc(-c5ccccc5)cc4)c3N3c4cc(-n5c6ccccc6c6ccccc65)ccc4B4c5ccc(-n6c7ccccc7c7ccccc76)cc5N(c5c(-c6ccc(-c7ccccc7)cc6)cccc5-c5ccc(-c6ccccc6)cc5)c5cc(-c6ccccc6)cc3c54)cc2)cc1]

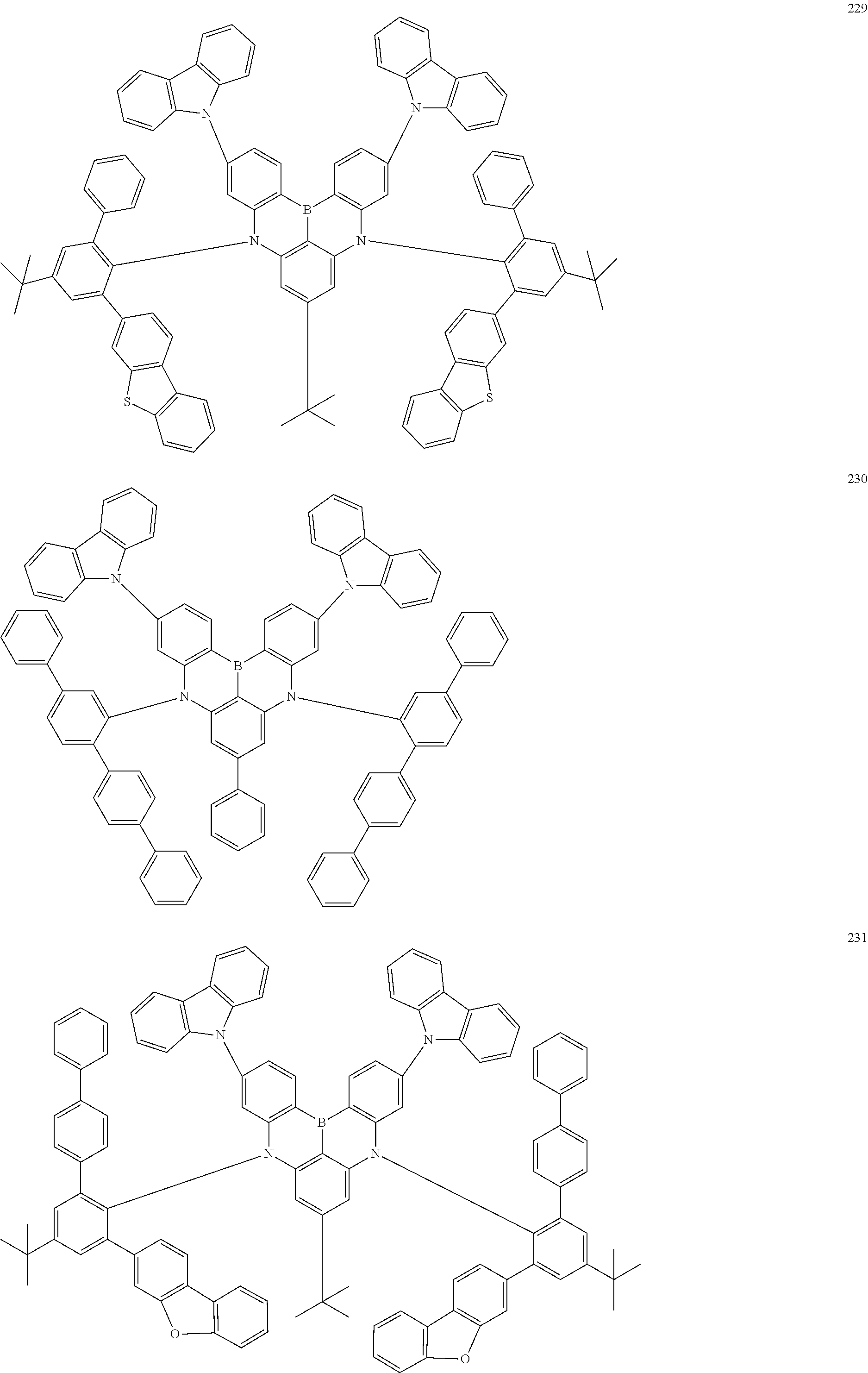

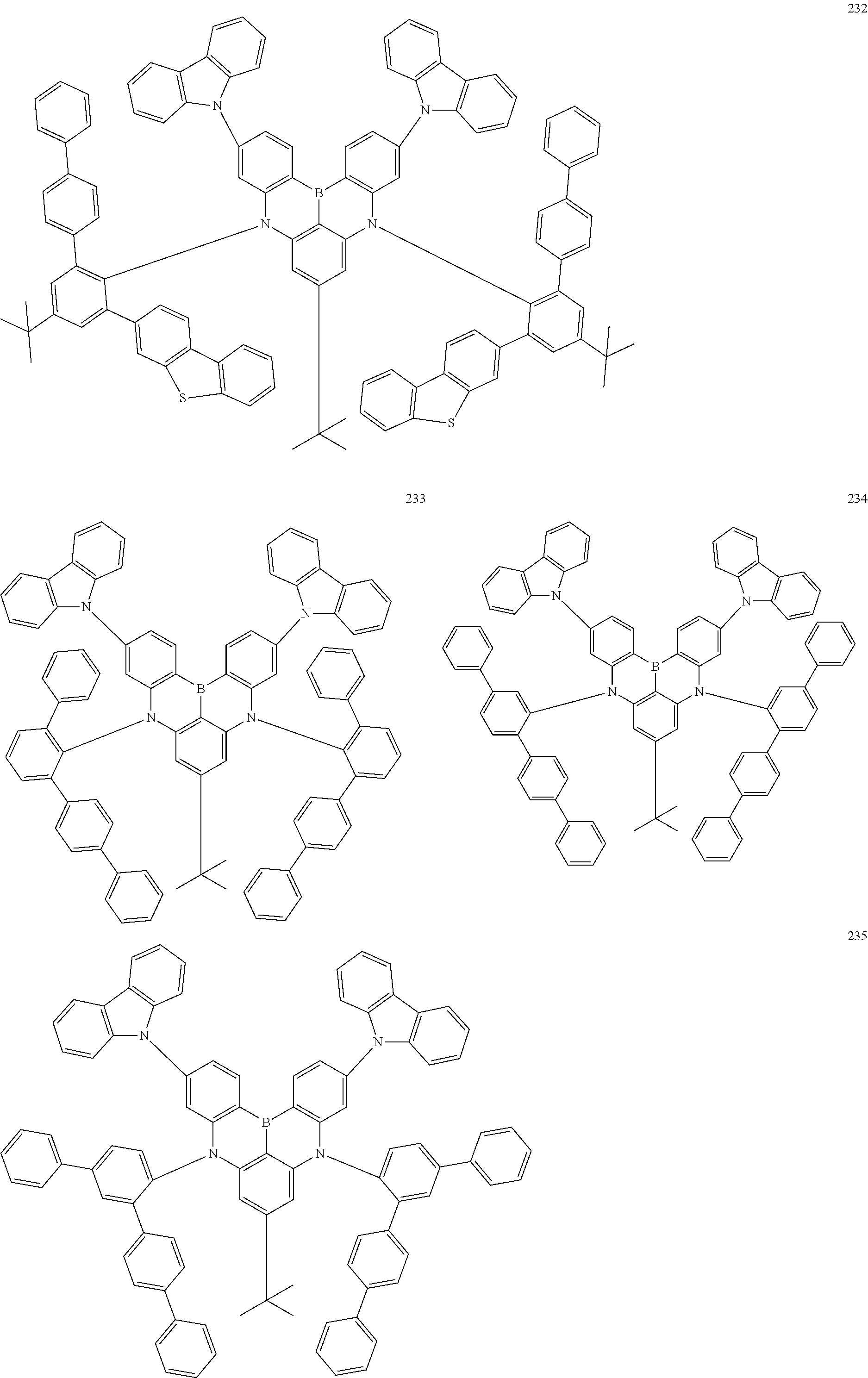

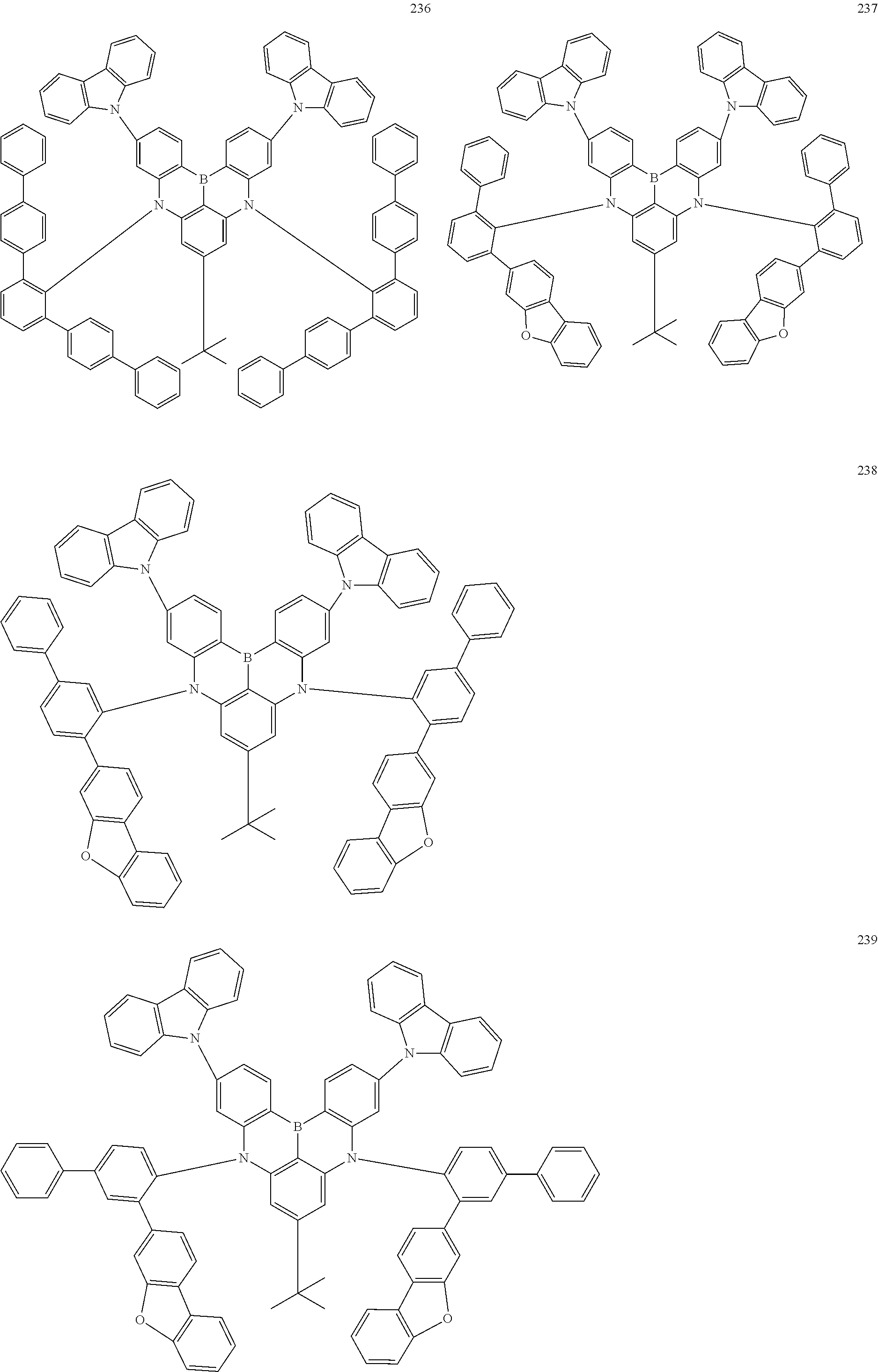

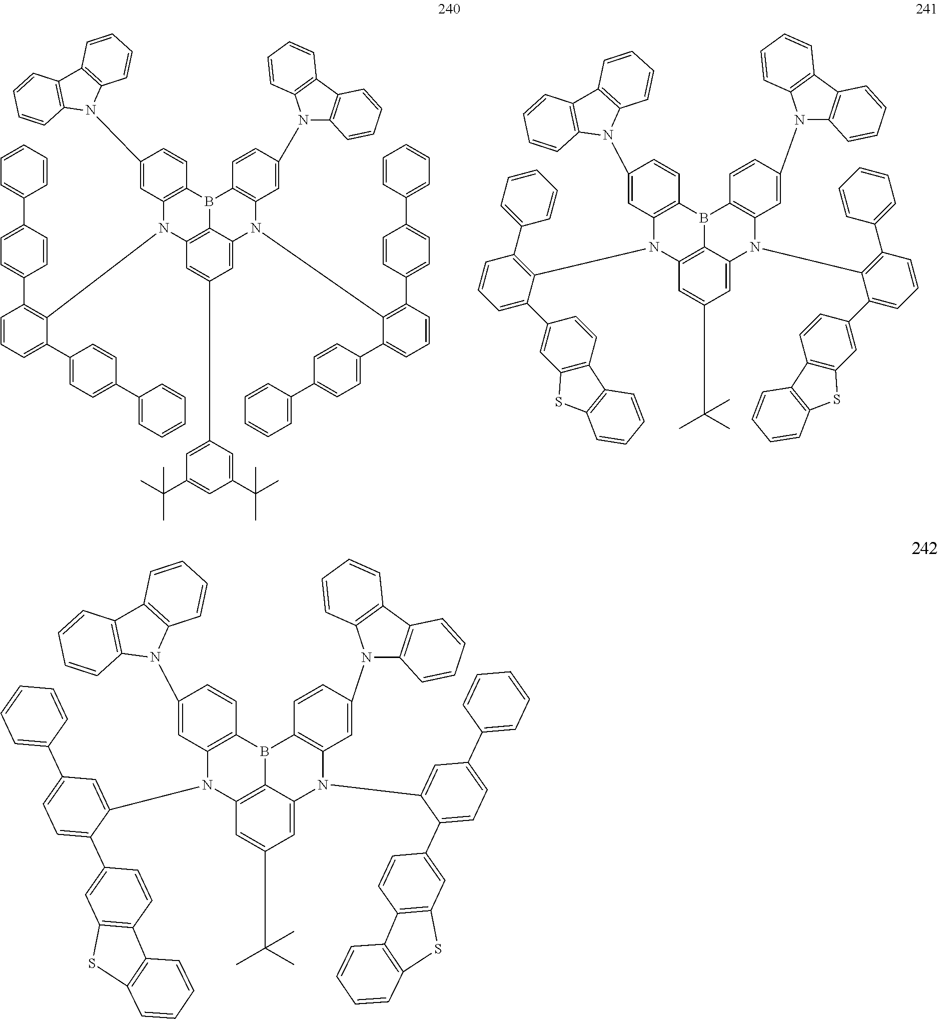

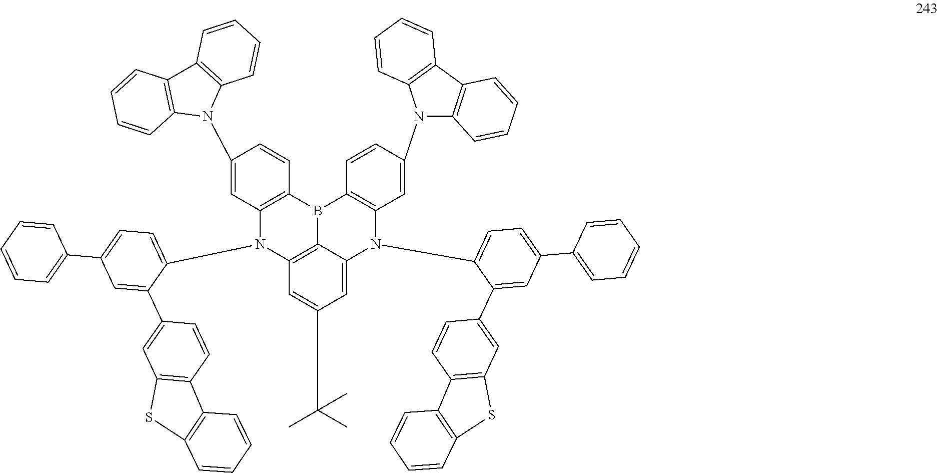 [SMILES: CC(C)(C)c1cc2c3c(c1)N(c1ccc(-c4ccccc4)cc1-c1ccc4c(c1)sc1ccccc14)c1cc(-n4c5ccccc5c5ccccc54)ccc1B3c1ccc(-n3c4ccccc4c4ccccc43)cc1N2c1ccc(-c2ccccc2)cc1-c1ccc2c(c1)sc1ccccc12]

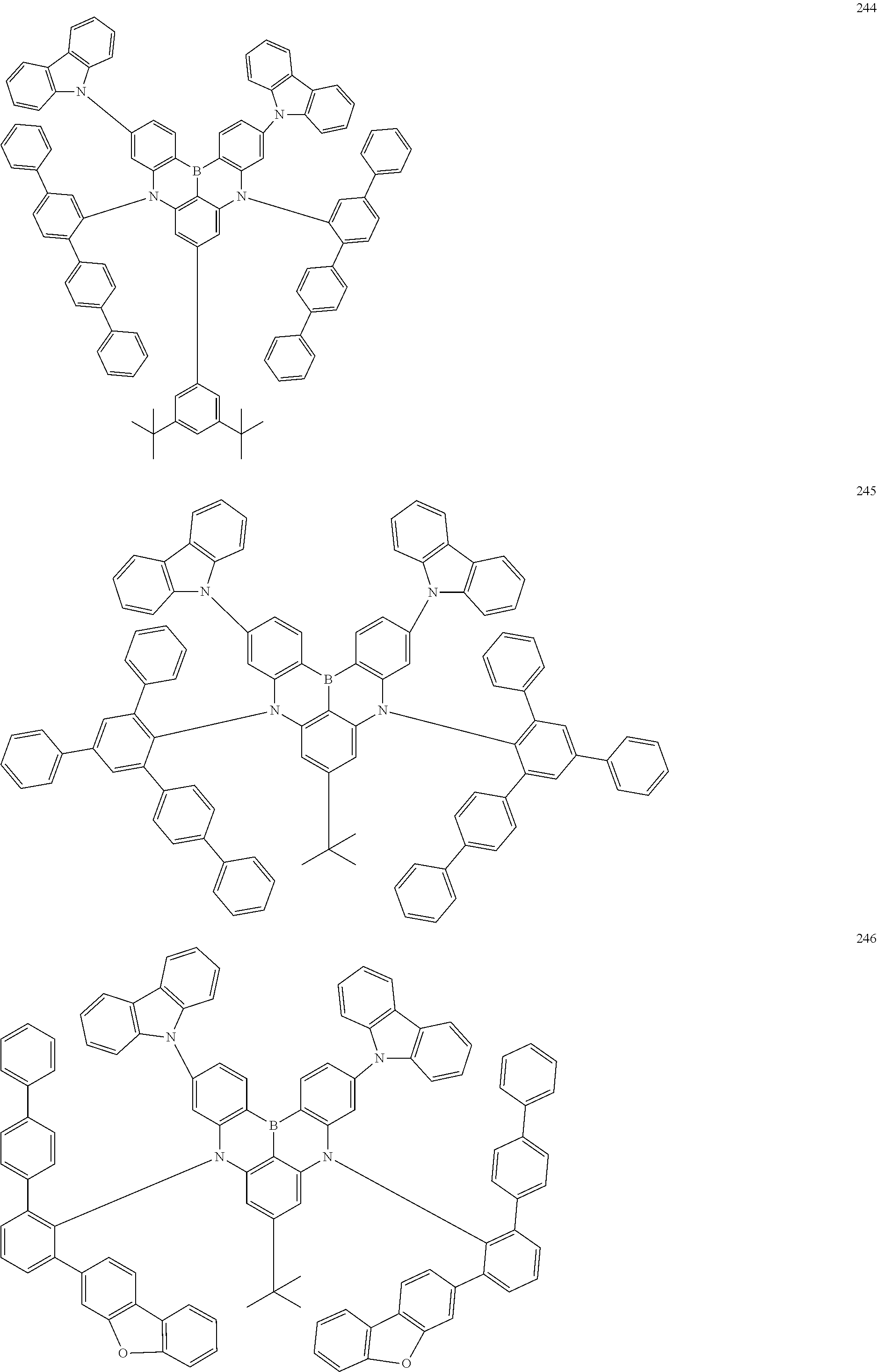

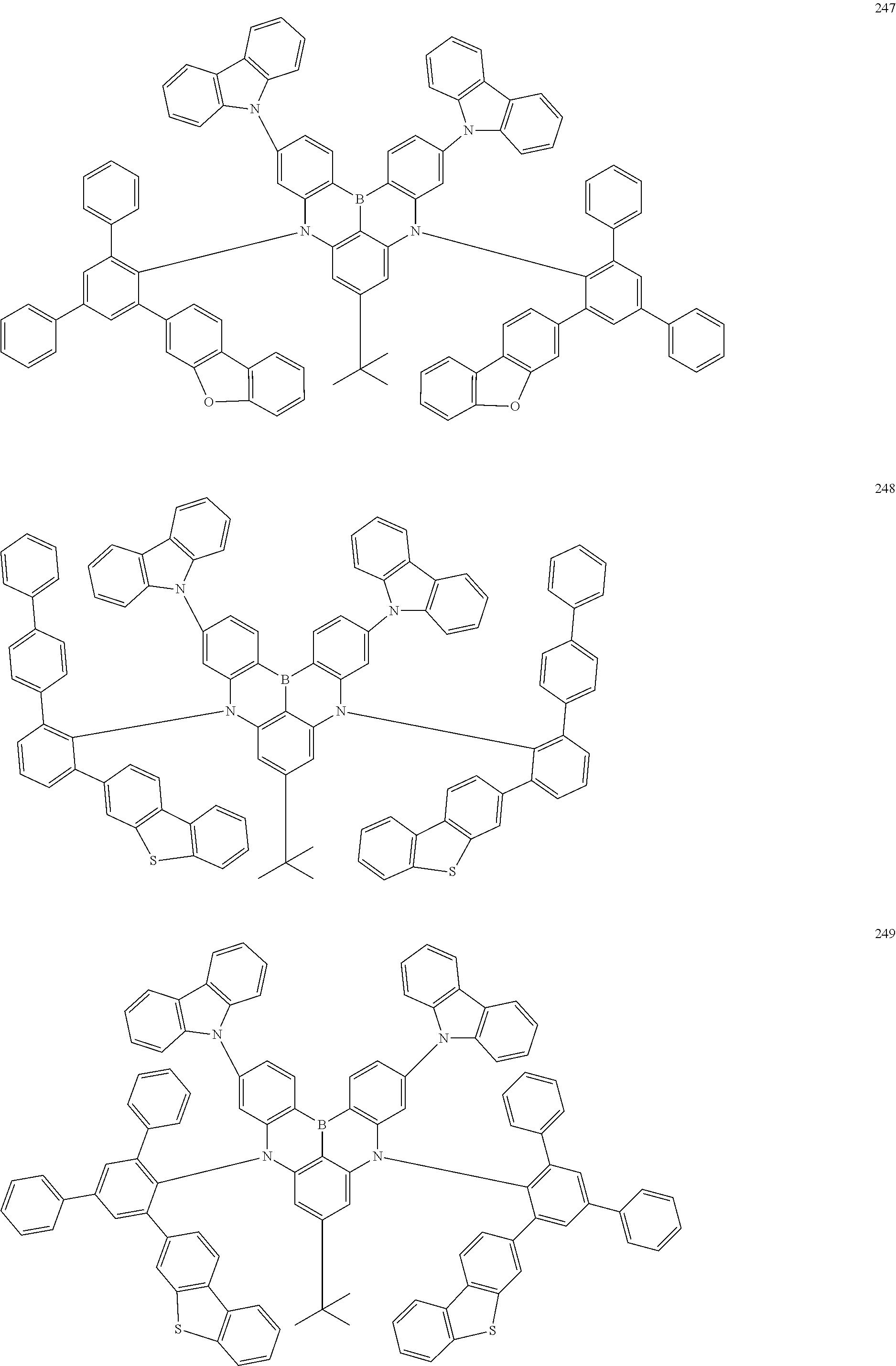

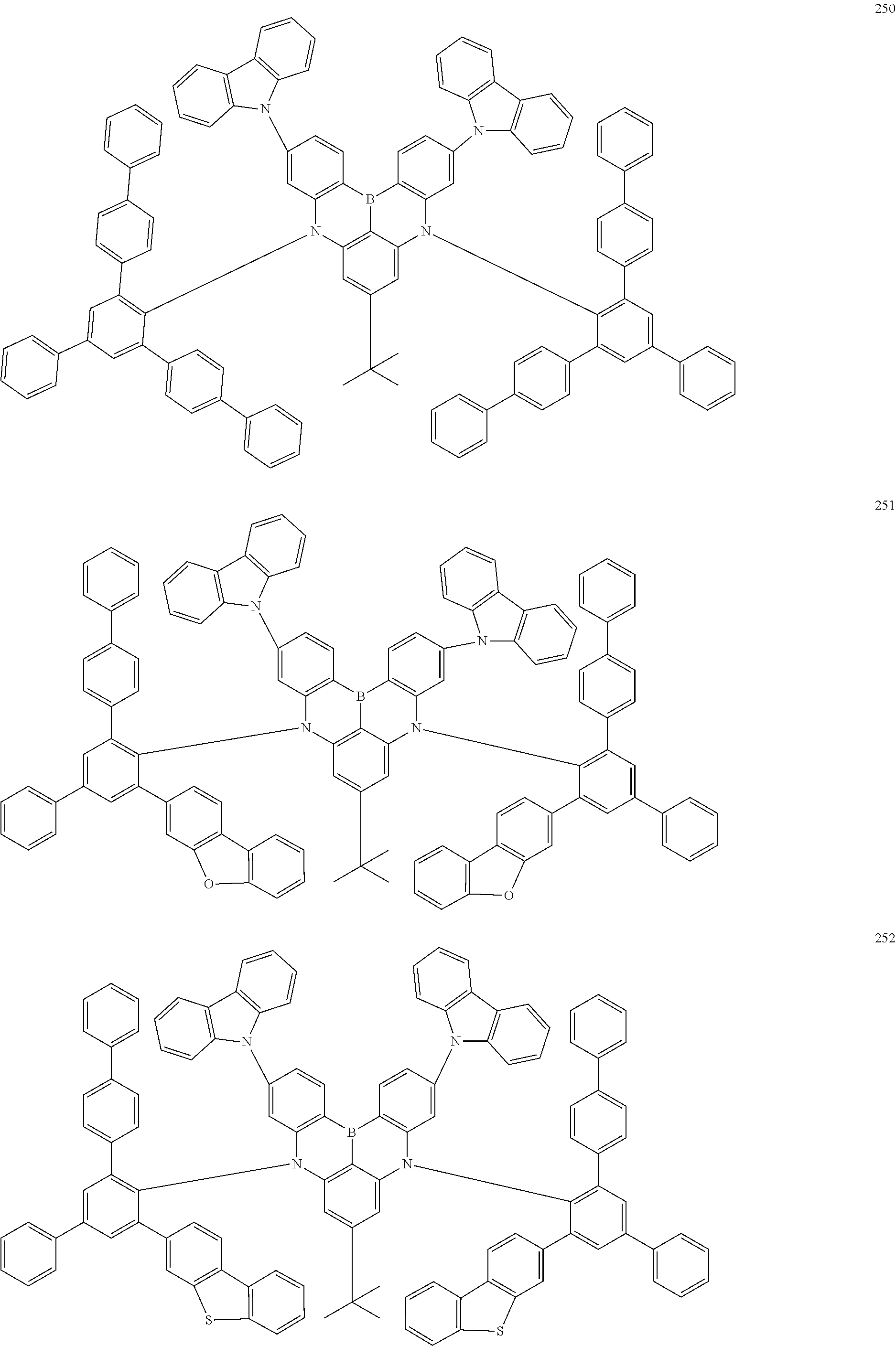

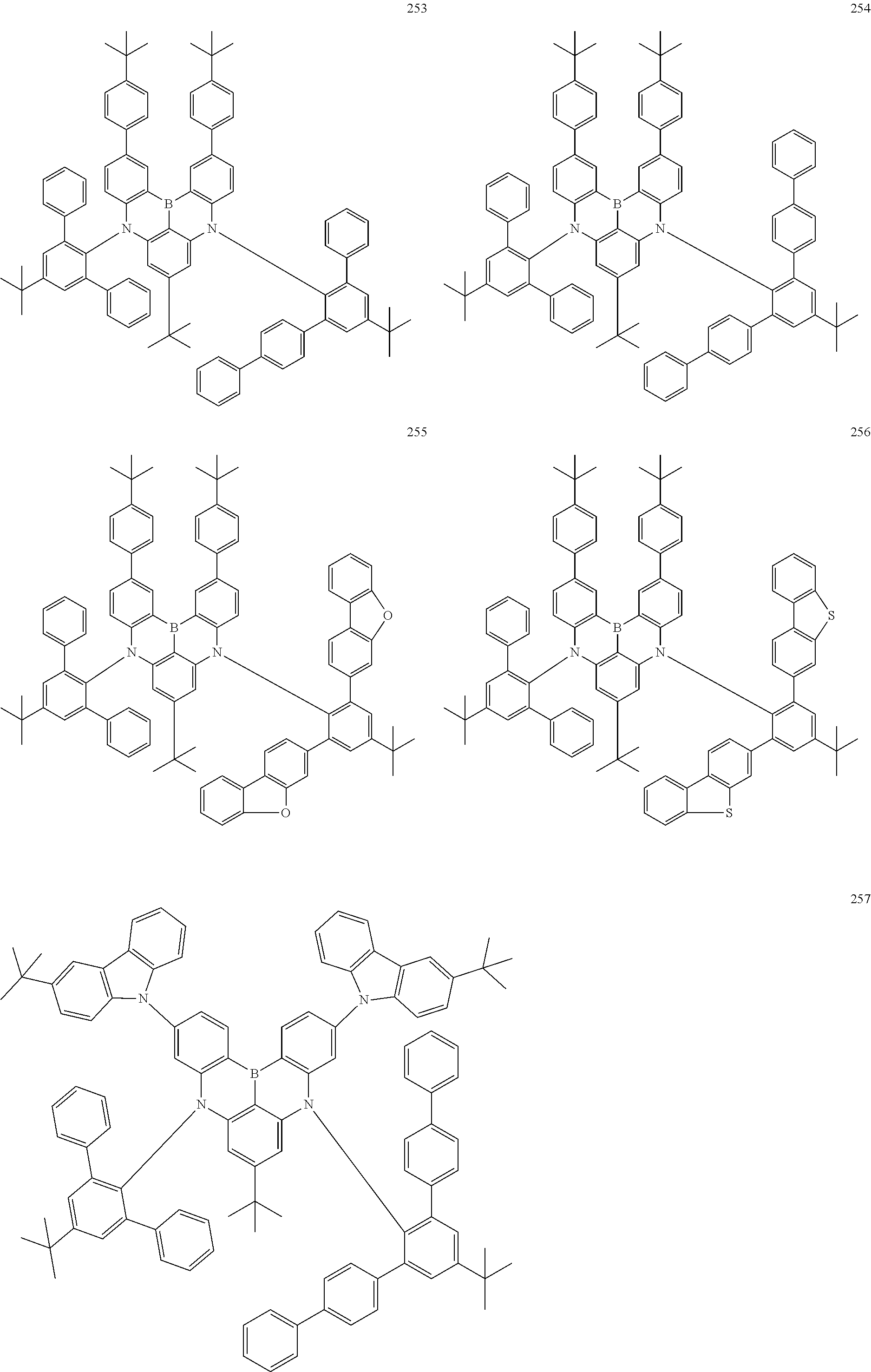

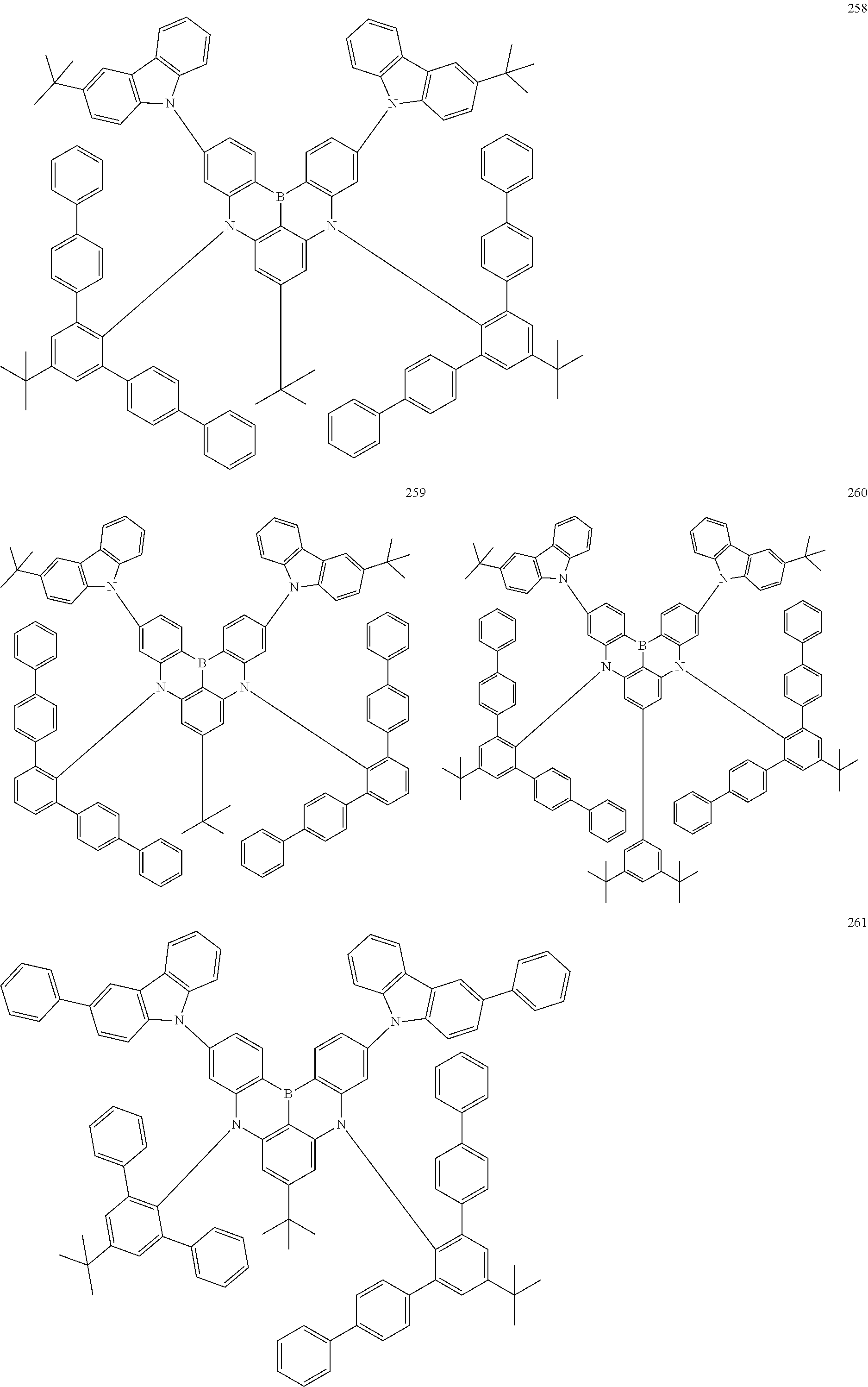

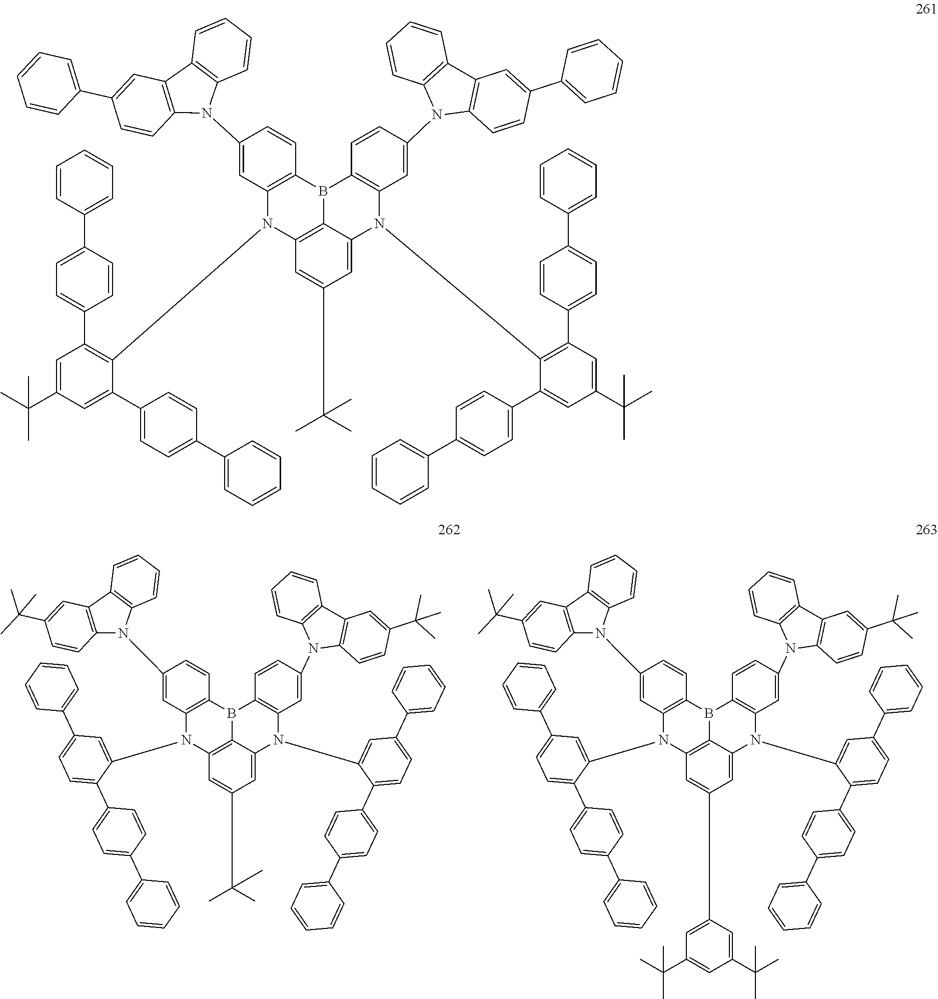

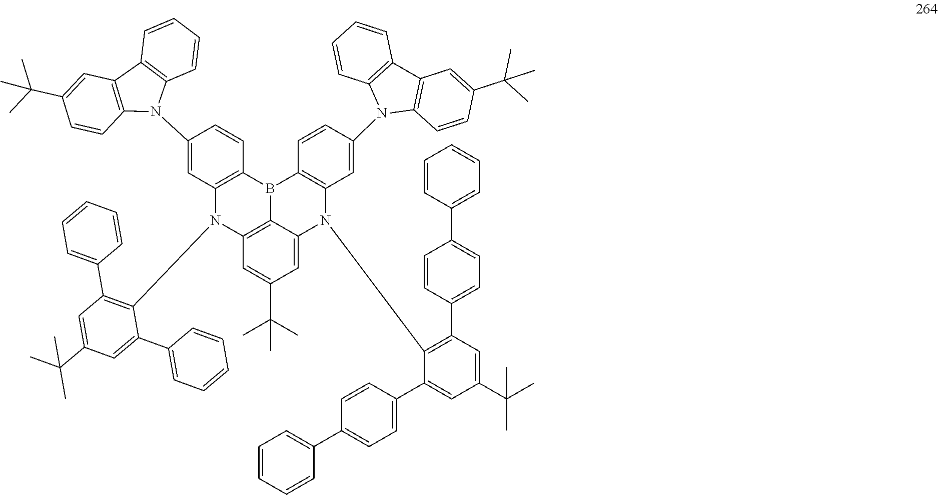 [SMILES: CC(C)(C)c1cc(-c2ccccc2)c(N2c3cc(-n4c5ccccc5c5cc(C(C)(C)C)ccc54)ccc3B3c4ccc(-n5c6ccccc6c6cc(C(C)(C)C)ccc65)cc4N(c4c(-c5ccc(-c6ccccc6)cc5)cc(C(C)(C)C)cc4-c4ccc(-c5ccccc5)cc4)c4cc(C(C)(C)C)cc2c43)c(-c2ccccc2)c1]

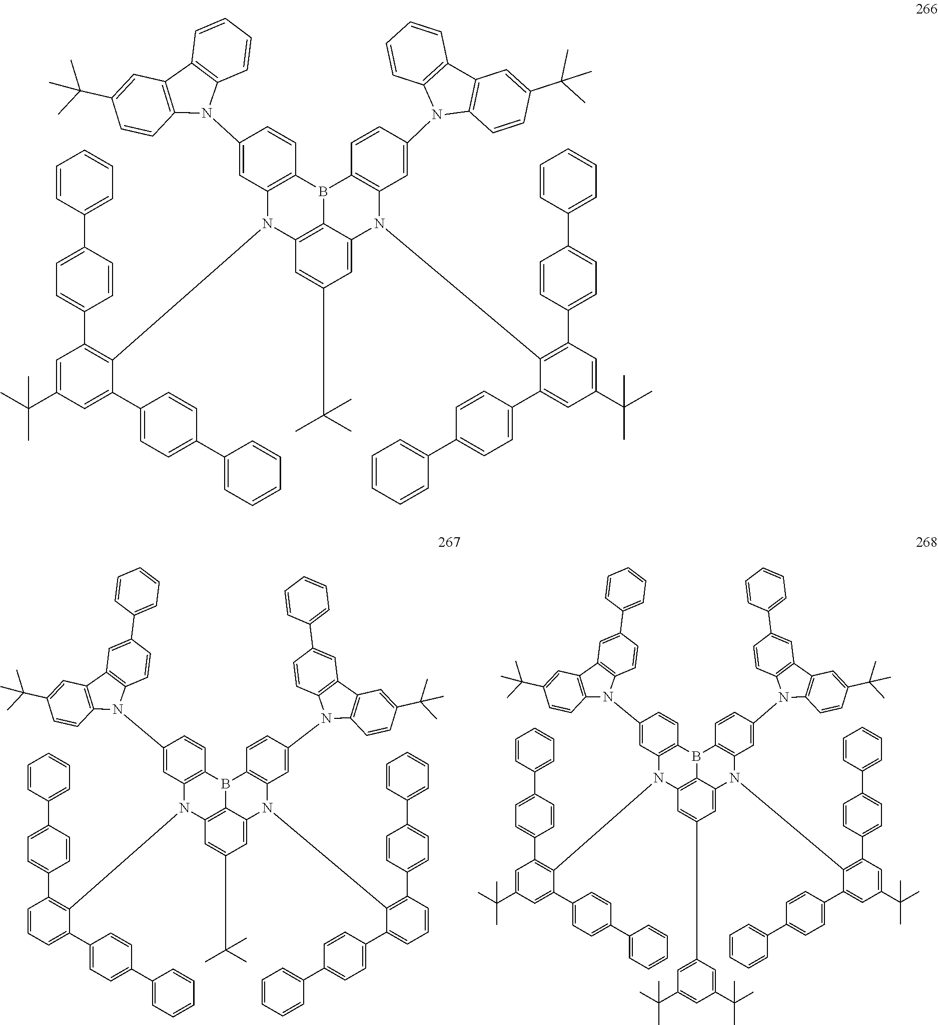

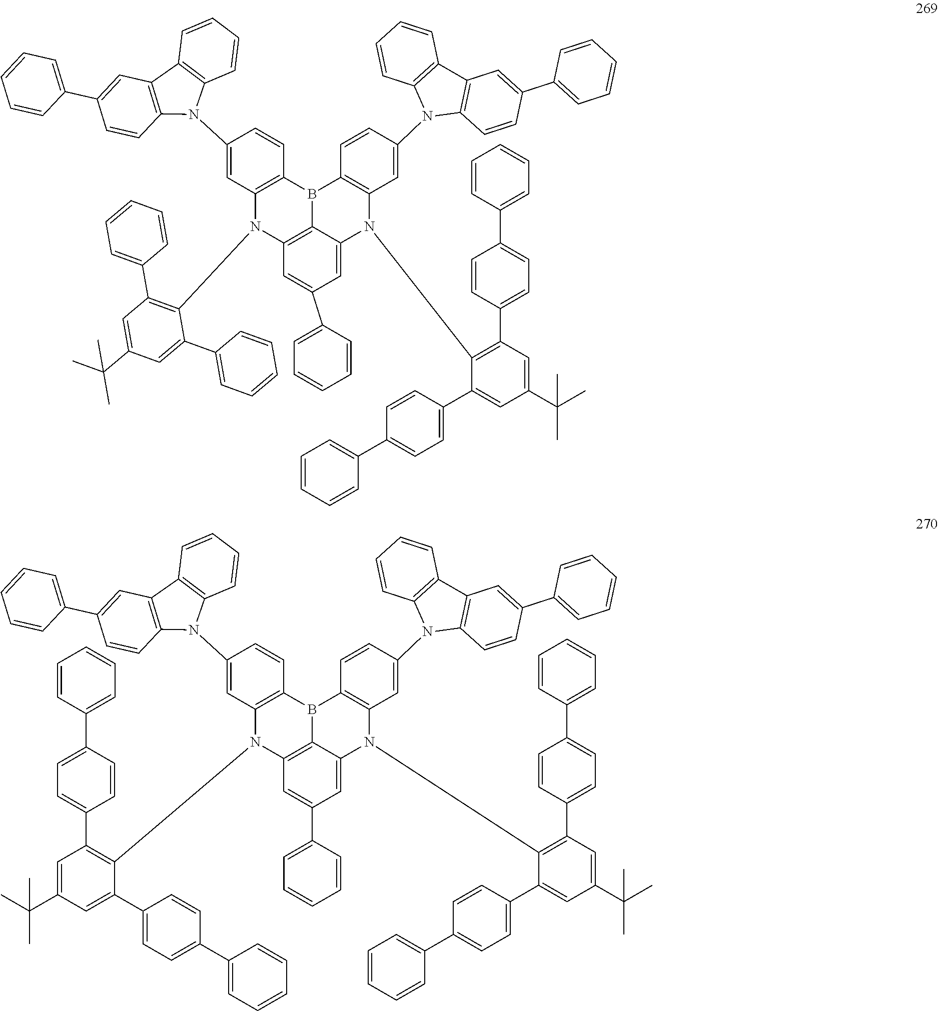 [SMILES: CC(C)(C)c1cc(-c2ccccc2)c(N2c3cc(-n4c5ccccc5c5cc(-c6ccccc6)ccc54)ccc3B3c4ccc(-n5c6ccccc6c6cc(-c7ccccc7)ccc65)cc4N(c4c(-c5ccc(-c6ccccc6)cc5)cc(C(C)(C)C)cc4-c4ccc(-c5ccccc5)cc4)c4cc(-c5ccccc5)cc2c43)c(-c2ccccc2)c1 ; CC(C)(C)c1cc(-c2ccc(-c3ccccc3)cc2)c(N2c3cc(-n4c5ccccc5c5cc(-c6ccccc6)ccc54)ccc3B3c4ccc(-n5c6ccccc6c6cc(-c7ccccc7)ccc65)cc4N(c4c(-c5ccc(-c6ccccc6)cc5)cc(C(C)(C)C)cc4-c4ccc(-c5ccccc5)cc4)c4cc(-c5ccccc5)cc2c43)c(-c2ccc(-c3ccccc3)cc2)c1]

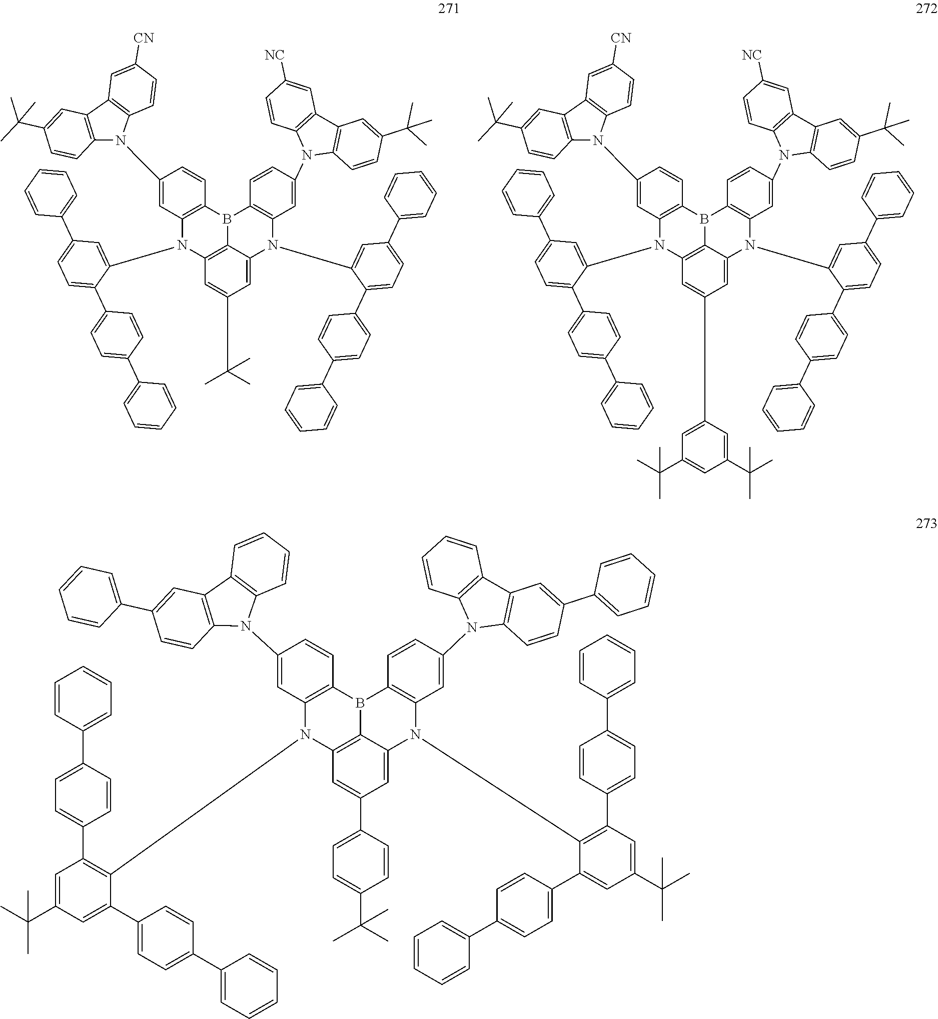

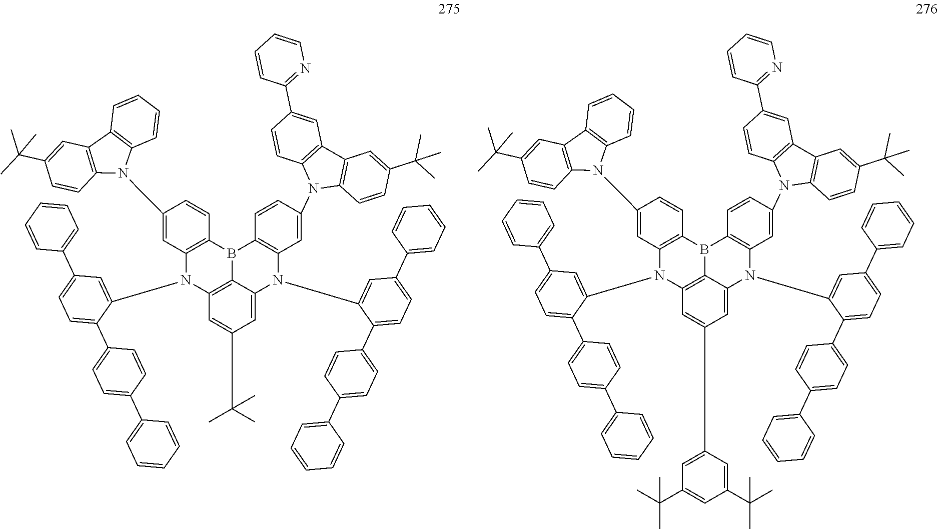 [SMILES: CC(C)(C)c1cc2c3c(c1)N(c1cc(-c4ccccc4)ccc1-c1ccc(-c4ccccc4)cc1)c1cc(-n4c5ccc(-c6ccccn6)cc5c5cc(C(C)(C)C)ccc54)ccc1B3c1ccc(-n3c4ccccc4c4cc(C(C)(C)C)ccc43)cc1N2c1cc(-c2ccccc2)ccc1-c1ccc(-c2ccccc2)cc1 ; CC(C)(C)c1cc(-c2cc3c4c(c2)N(c2cc(-c5ccccc5)ccc2-c2ccc(-c5ccccc5)cc2)c2cc(-n5c6ccc(-c7ccccn7)cc6c6cc(C(C)(C)C)ccc65)ccc2B4c2ccc(-n4c5ccccc5c5cc(C(C)(C)C)ccc54)cc2N3c2cc(-c3ccccc3)ccc2-c2ccc(-c3ccccc3)cc2)cc(C(C)(C)C)c1]

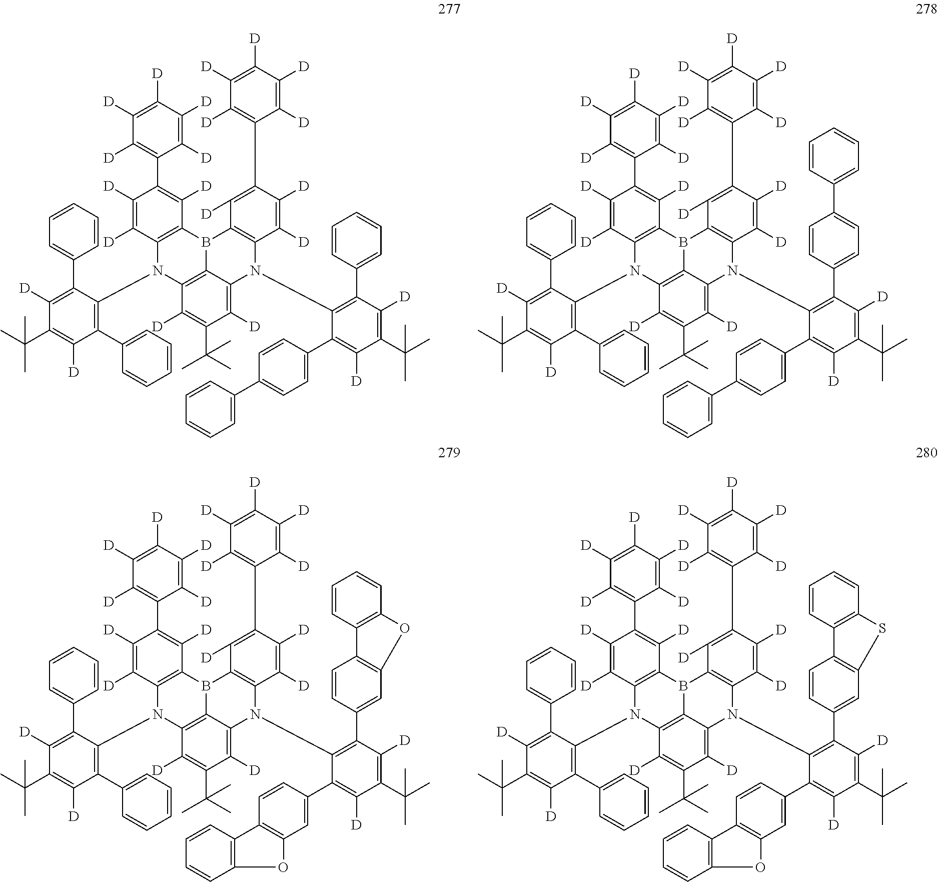

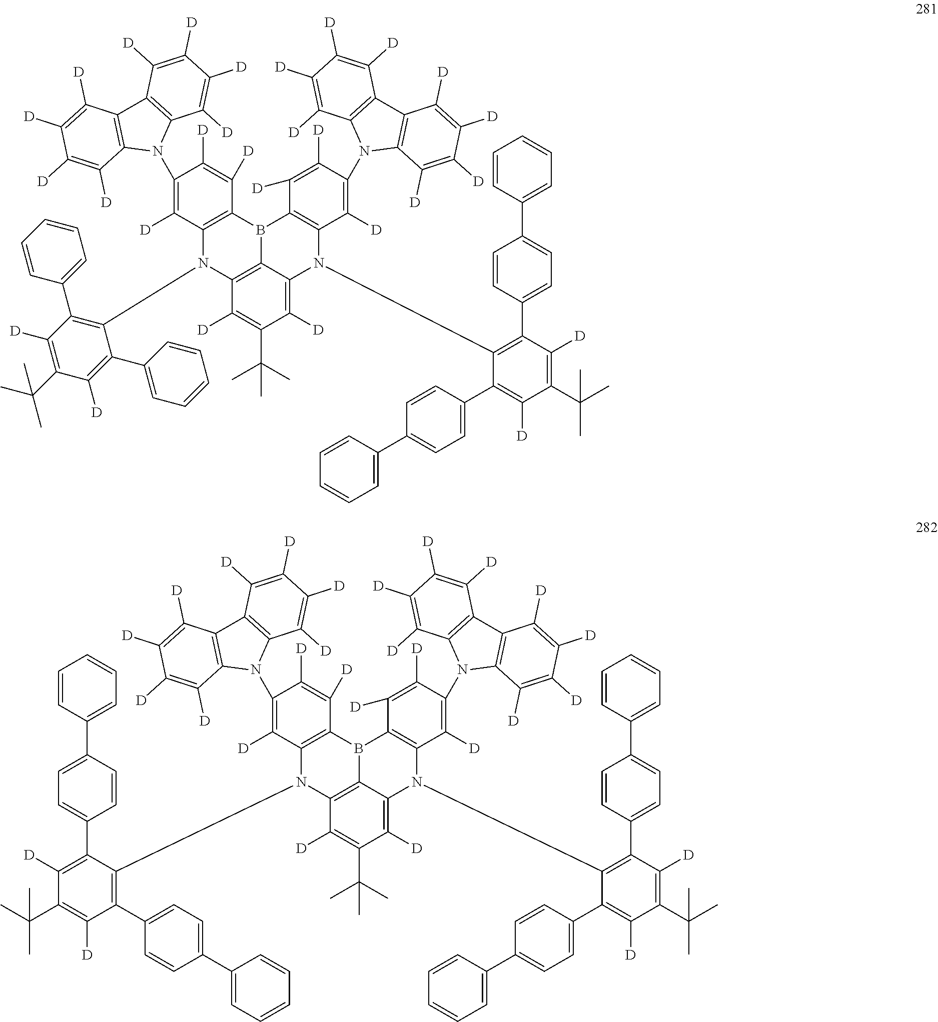

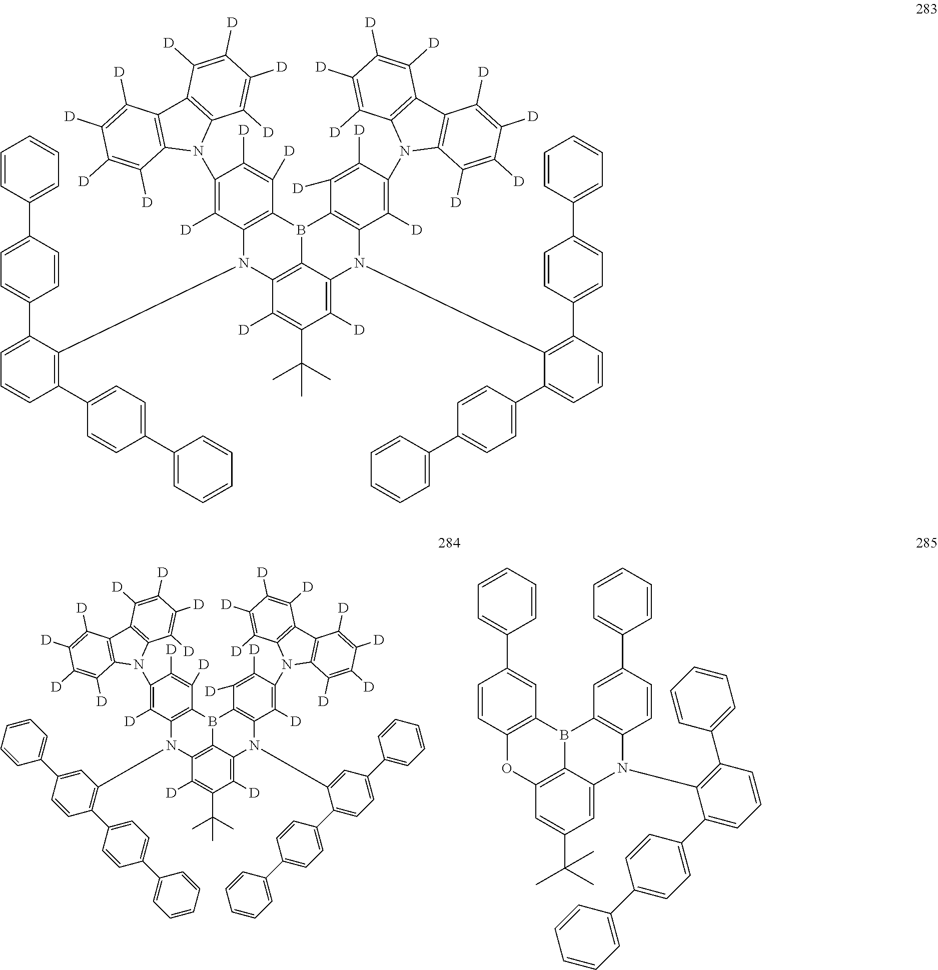

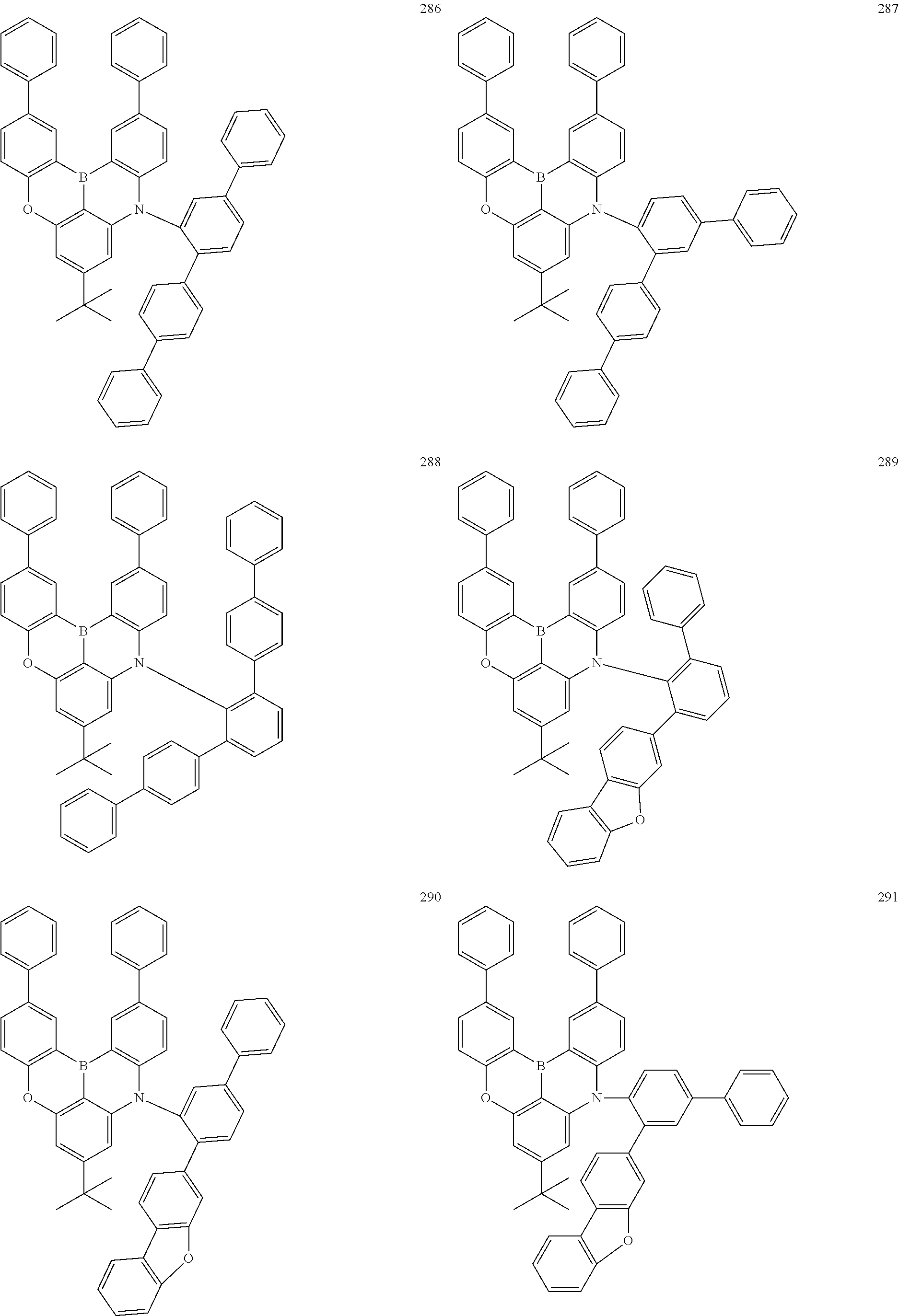

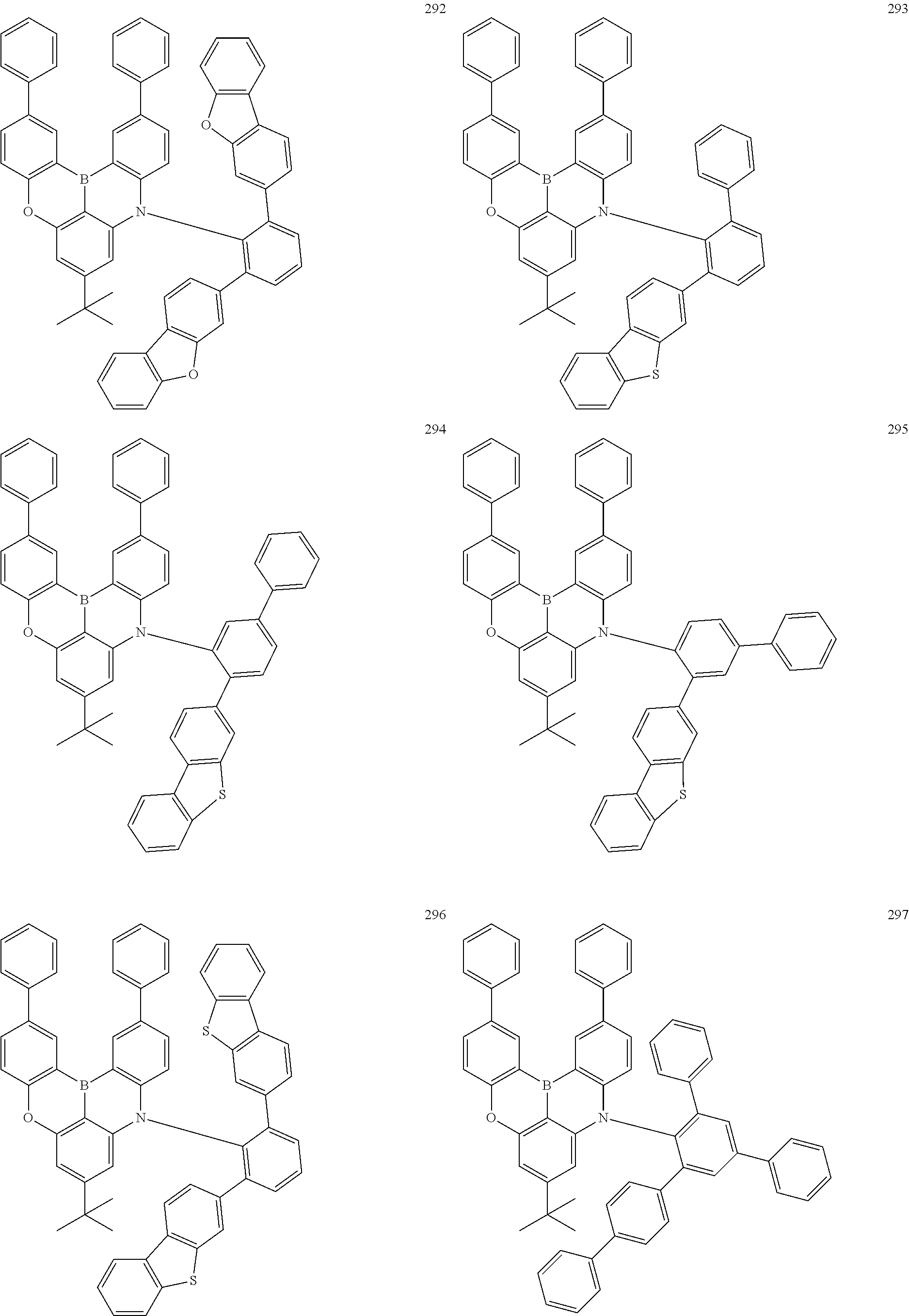

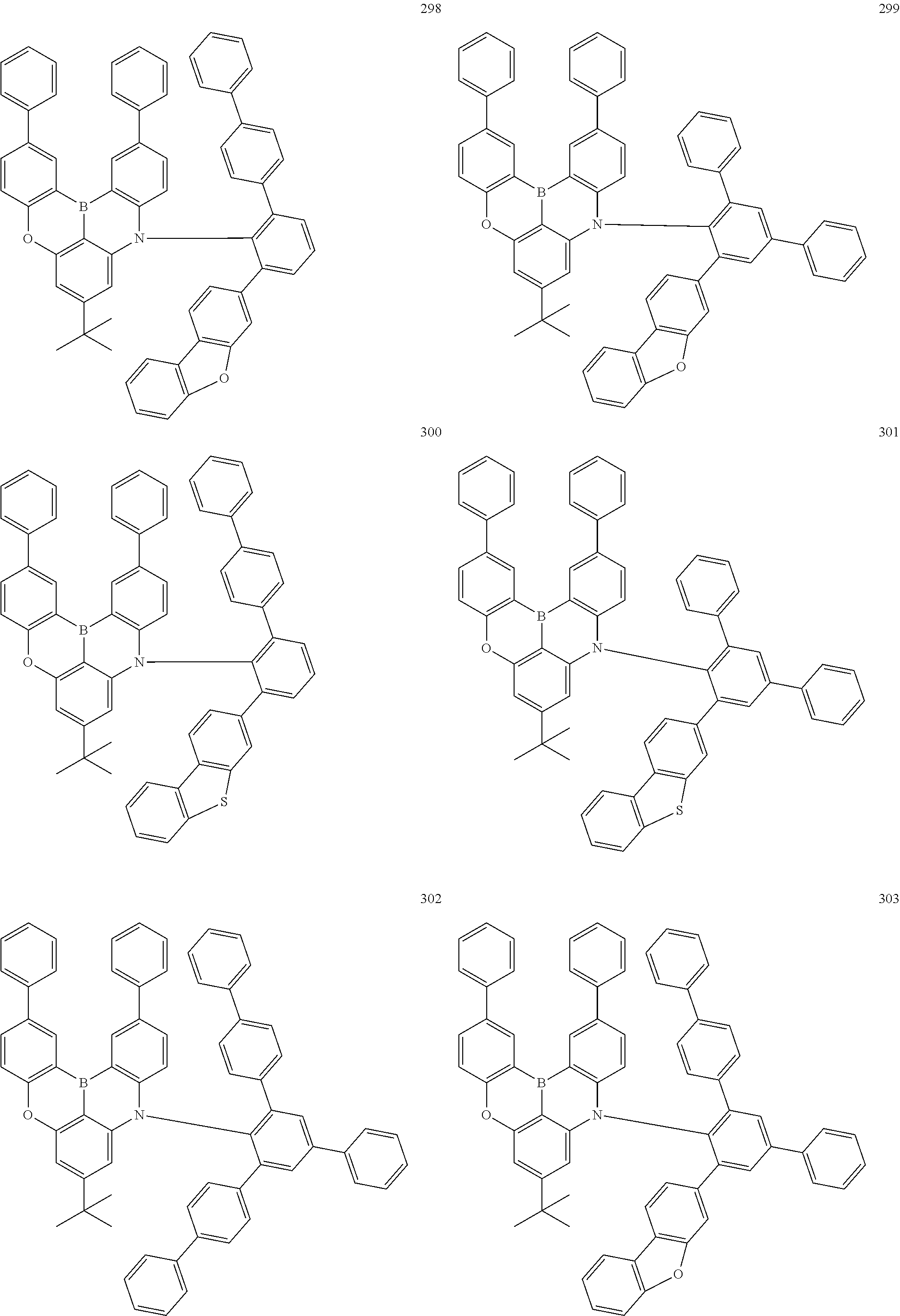

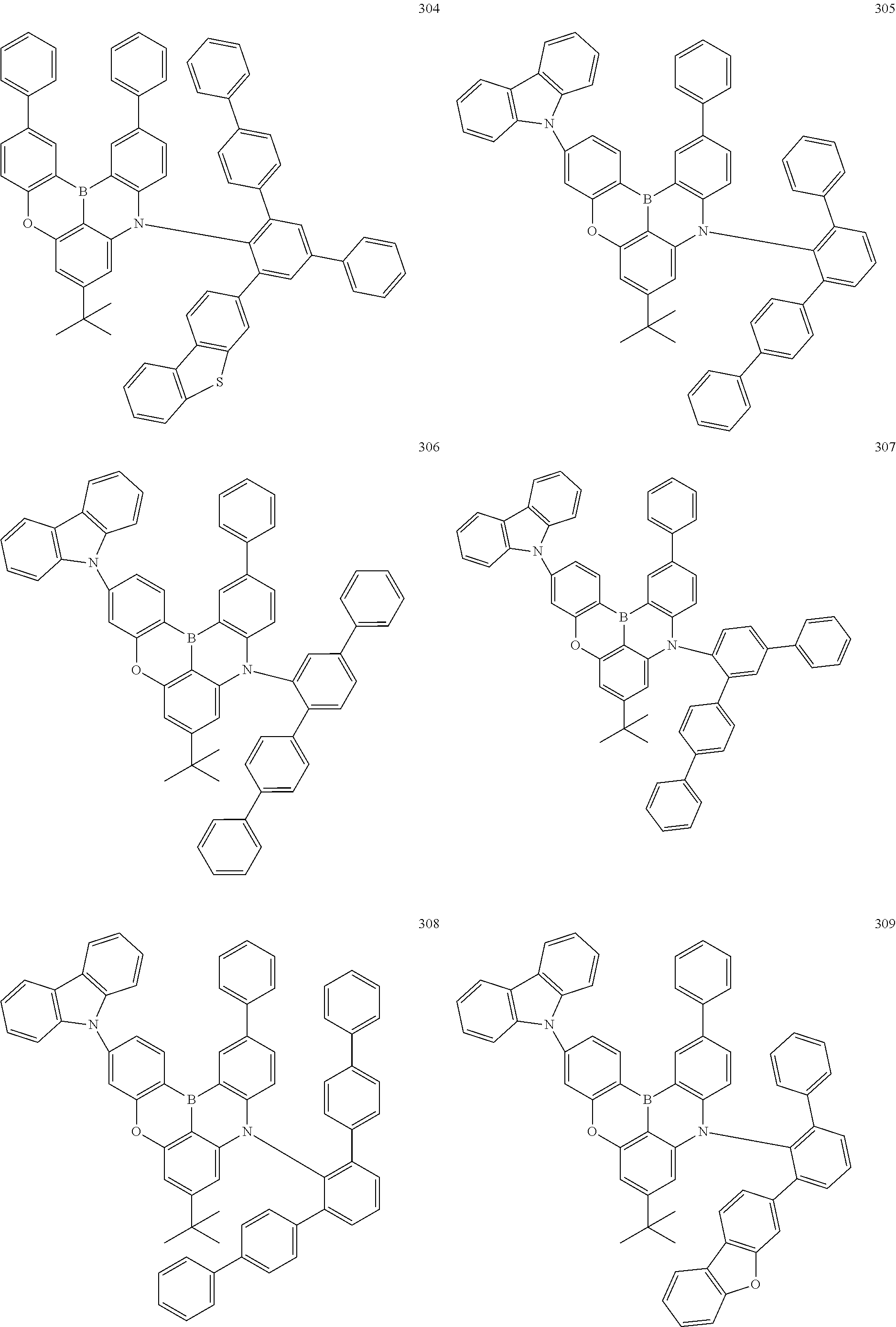

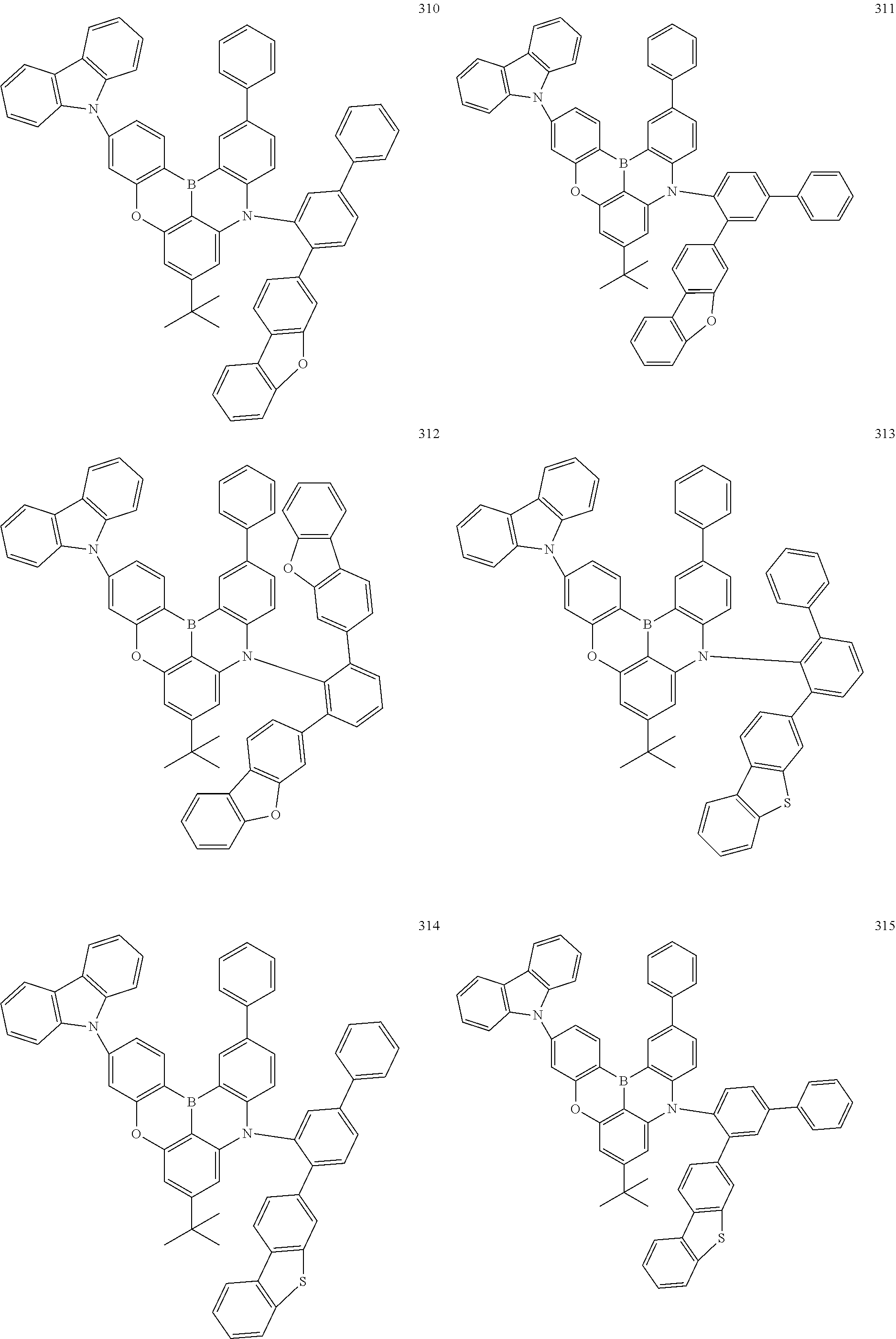

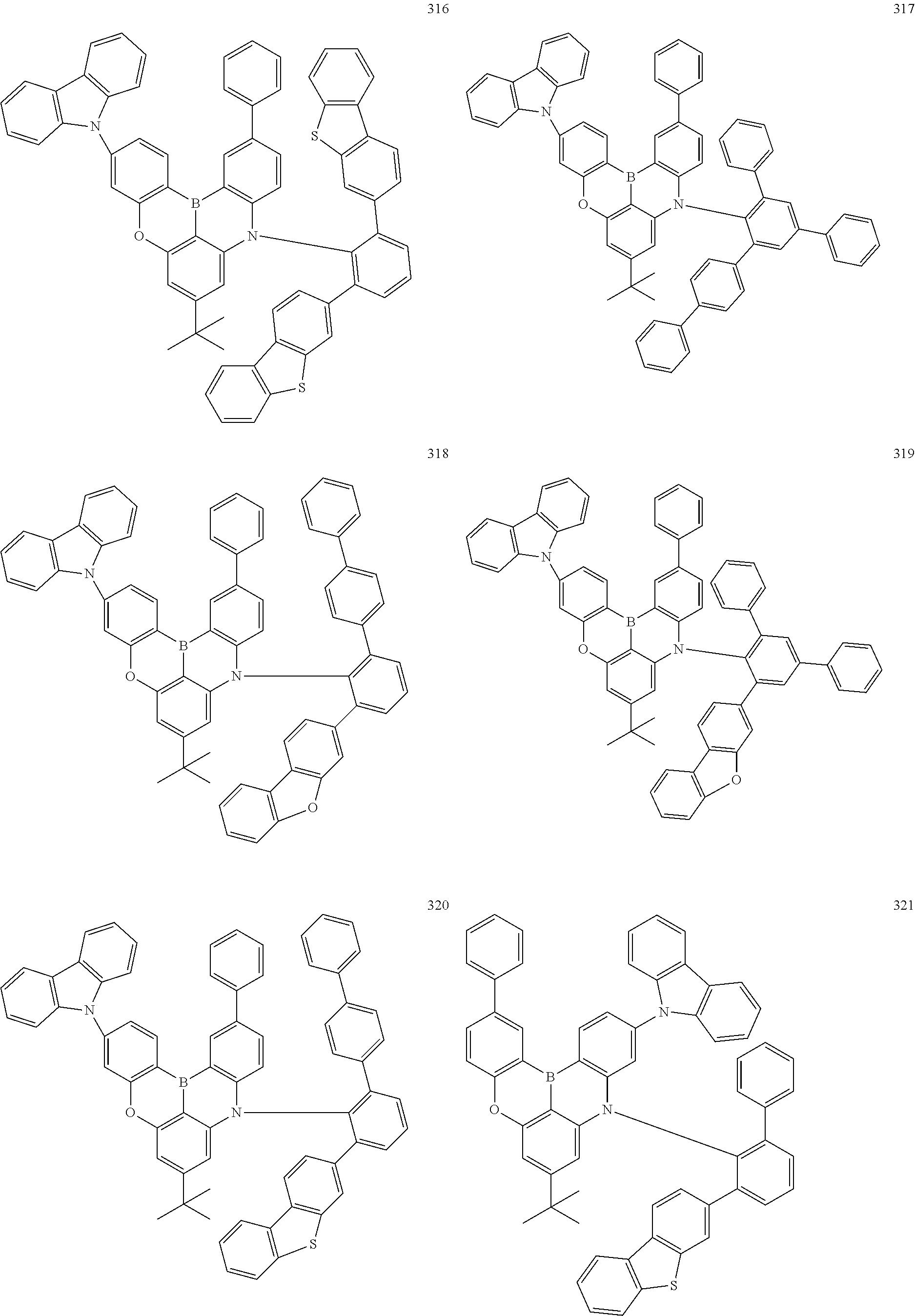

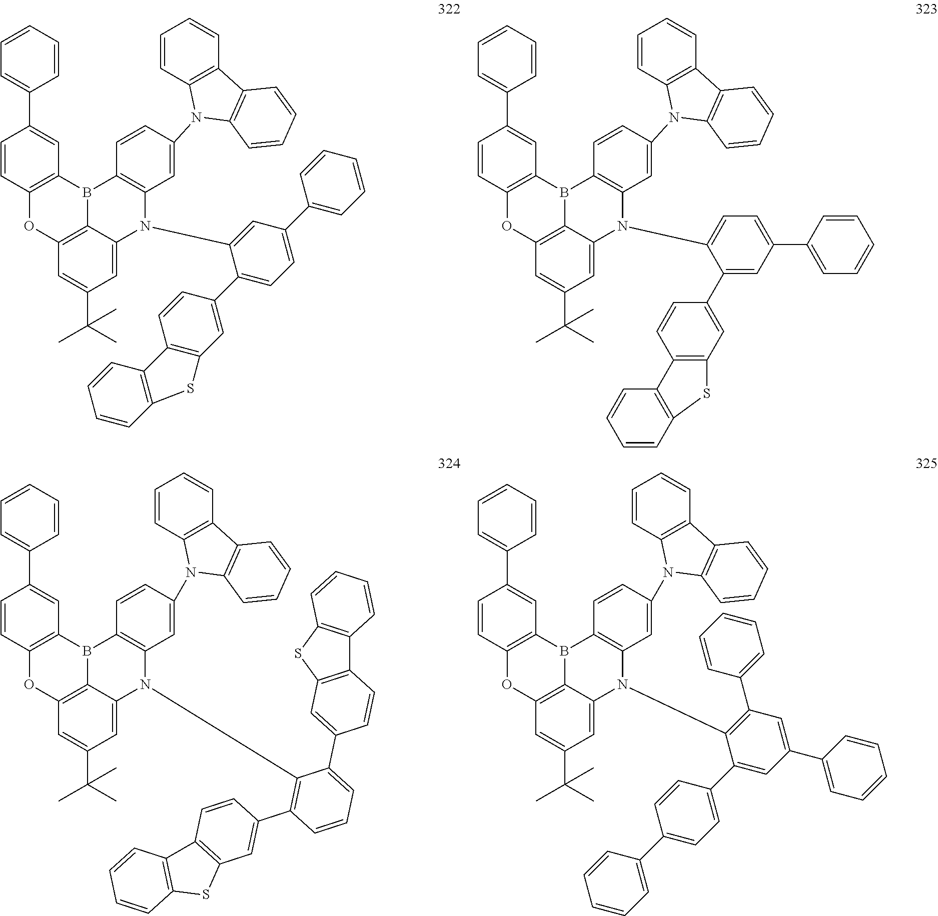

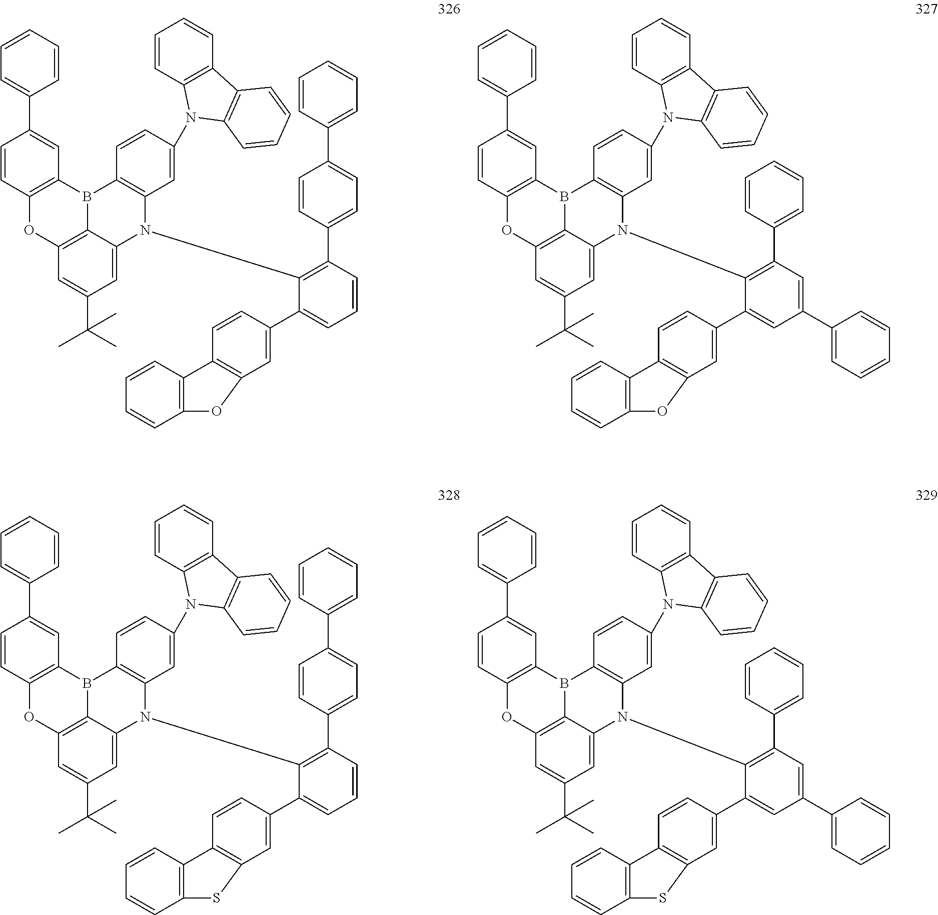

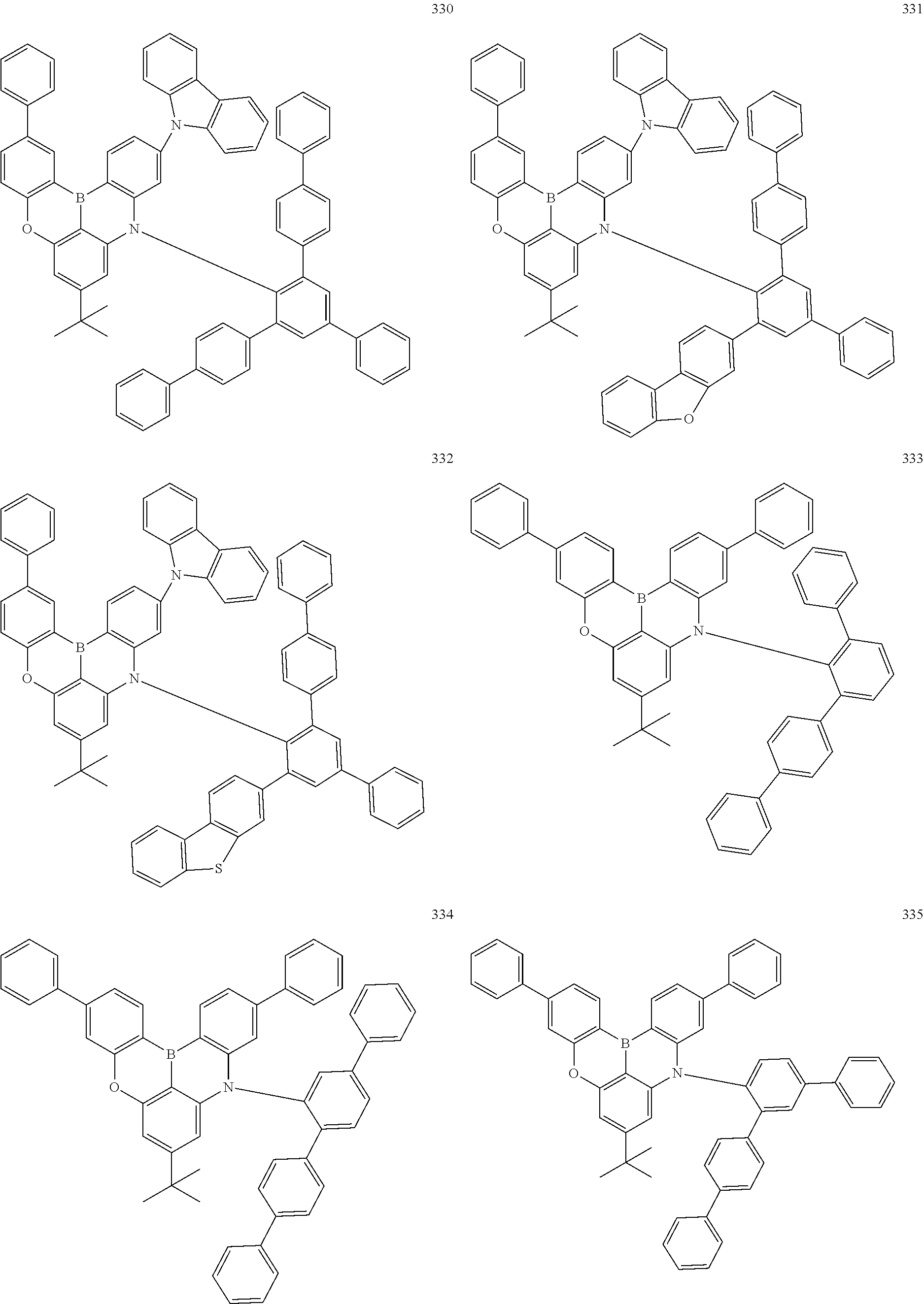

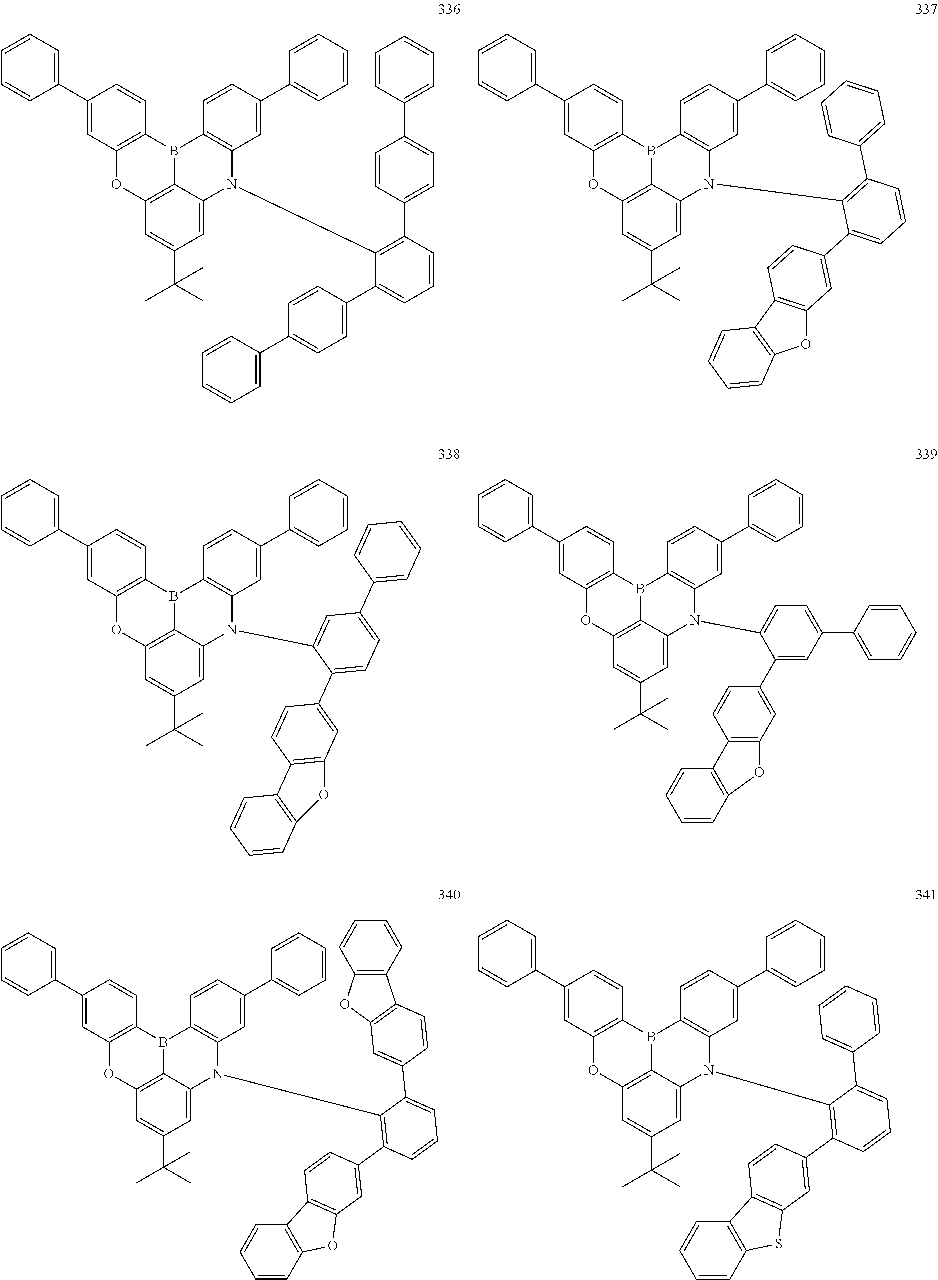

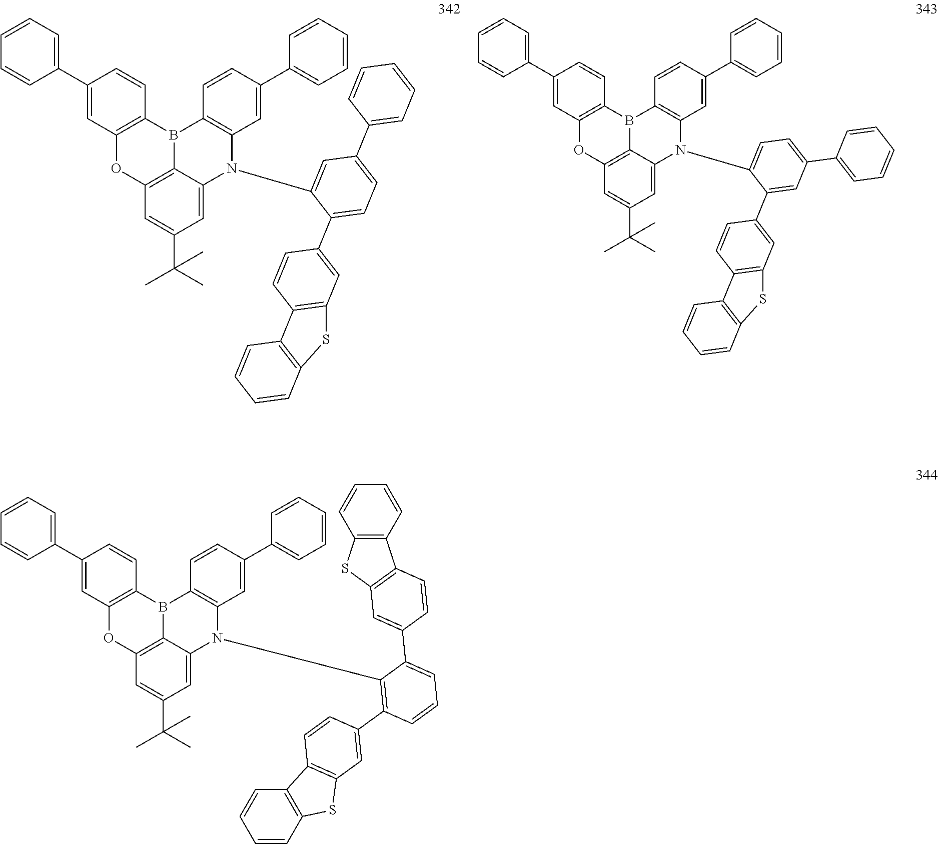 [SMILES: CC(C)(C)c1cc2c3c(c1)N(c1cc(-c4ccccc4)ccc1-c1ccc4c(c1)sc1ccccc14)c1cc(-c4ccccc4)ccc1B3c1ccc(-c3ccccc3)cc1O2 ; CC(C)(C)c1cc2c3c(c1)N(c1ccc(-c4ccccc4)cc1-c1ccc4c(c1)sc1ccccc14)c1cc(-c4ccccc4)ccc1B3c1ccc(-c3ccccc3)cc1O2 ; CC(C)(C)c1cc2c3c(c1)N(c1c(-c4ccc5c(c4)sc4ccccc45)cccc1-c1ccc4c(c1)sc1ccccc14)c1cc(-c4ccccc4)ccc1B3c1ccc(-c3ccccc3)cc1O2]

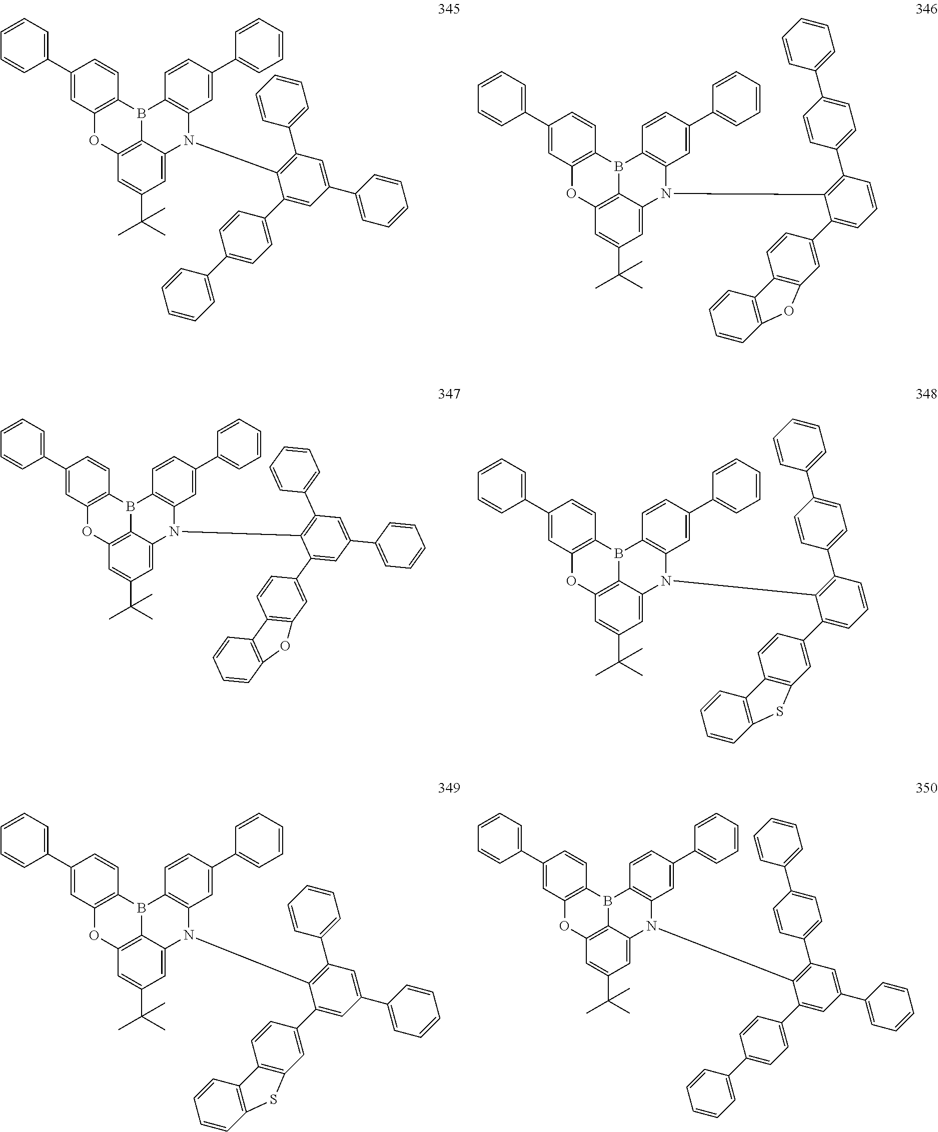

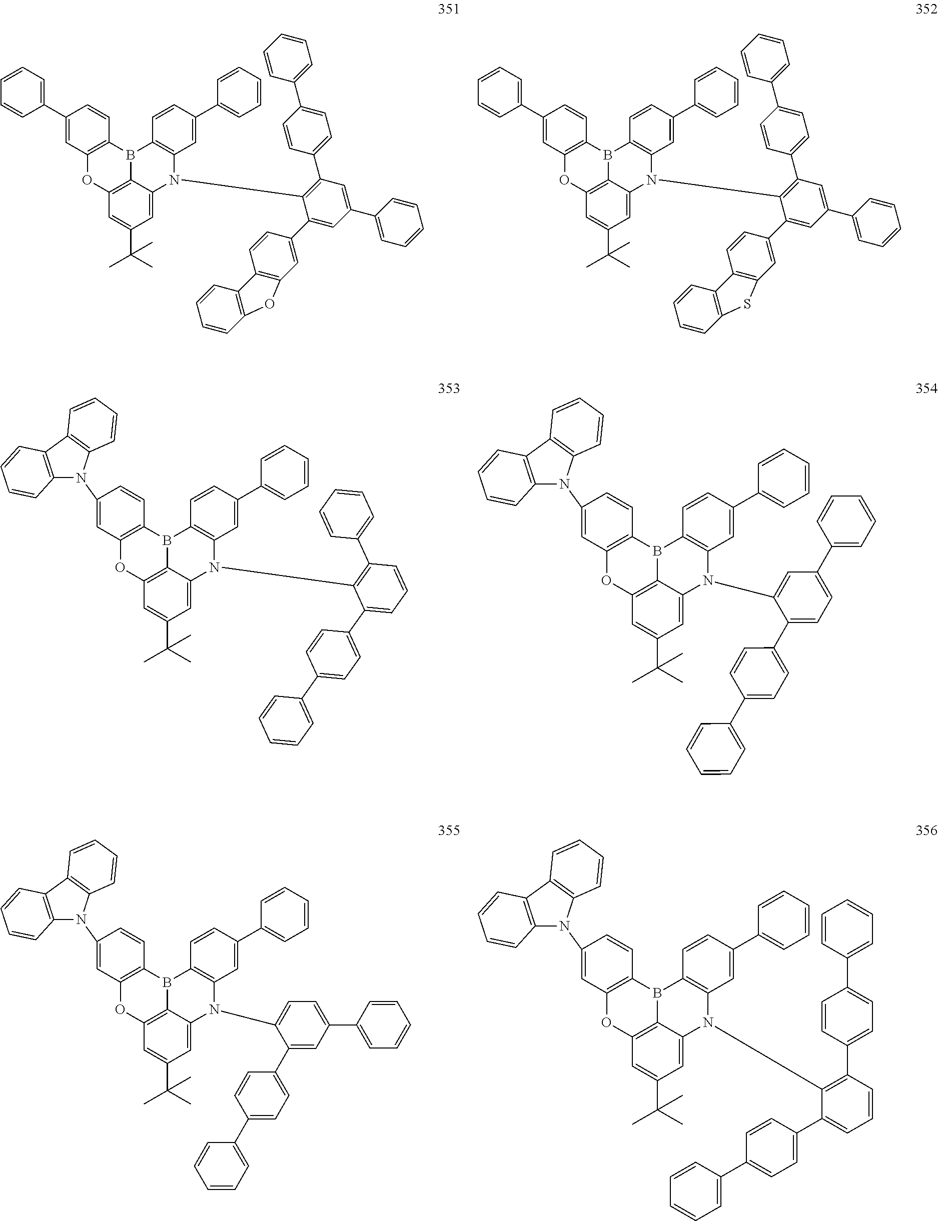

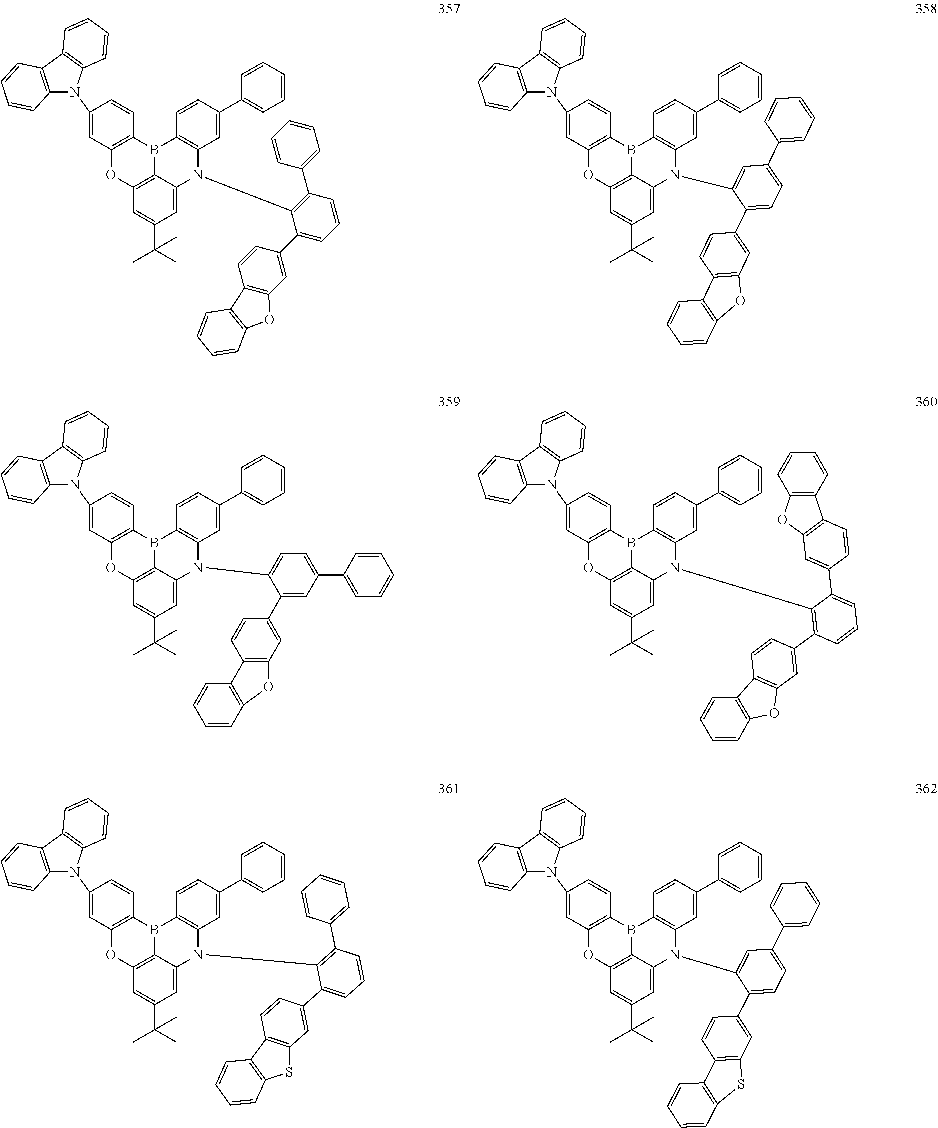

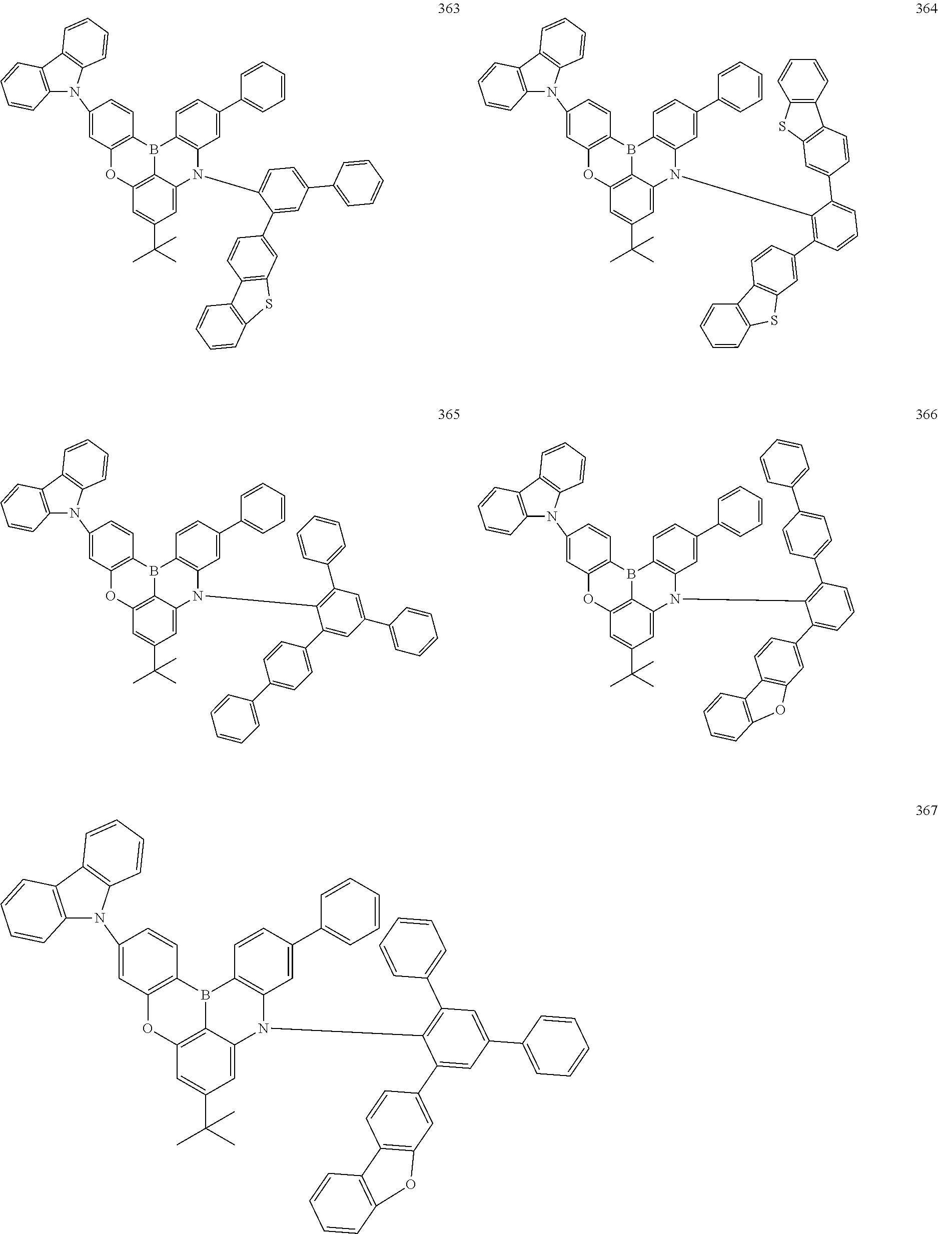

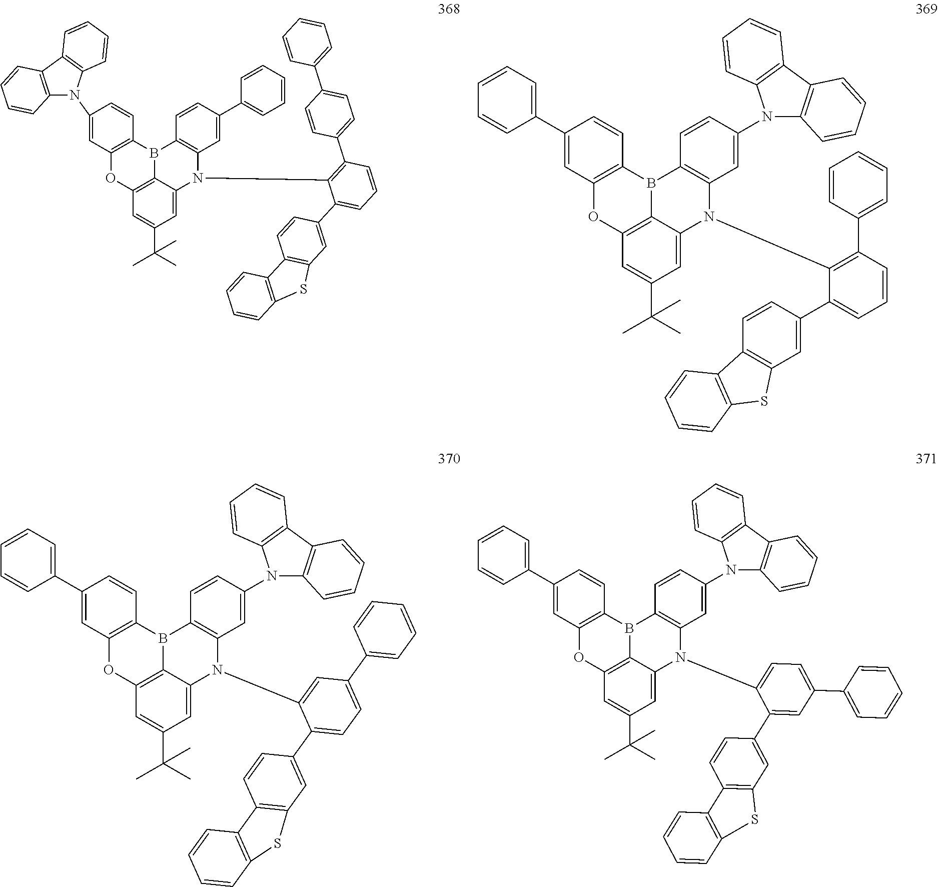 [SMILES: CC(C)(C)c1cc2c3c(c1)N(c1c(-c4ccc(-c5ccccc5)cc4)cccc1-c1ccc4c(c1)sc1ccccc14)c1cc(-c4ccccc4)ccc1B3c1ccc(-n3c4ccccc4c4ccccc43)cc1O2 ; CC(C)(C)c1cc2c3c(c1)N(c1c(-c4ccccc4)cccc1-c1ccc4c(c1)sc1ccccc14)c1cc(-n4c5ccccc5c5ccccc54)ccc1B3c1ccc(-c3ccccc3)cc1O2 ; CC(C)(C)c1cc2c3c(c1)N(c1cc(-c4ccccc4)ccc1-c1ccc4c(c1)sc1ccccc14)c1cc(-n4c5ccccc5c5ccccc54)ccc1B3c1ccc(-c3ccccc3)cc1O2 ; CC(C)(C)c1cc2c3c(c1)N(c1ccc(-c4ccccc4)cc1-c1ccc4c(c1)sc1ccccc14)c1cc(-n4c5ccccc5c5ccccc54)ccc1B3c1ccc(-c3ccccc3)cc1O2]

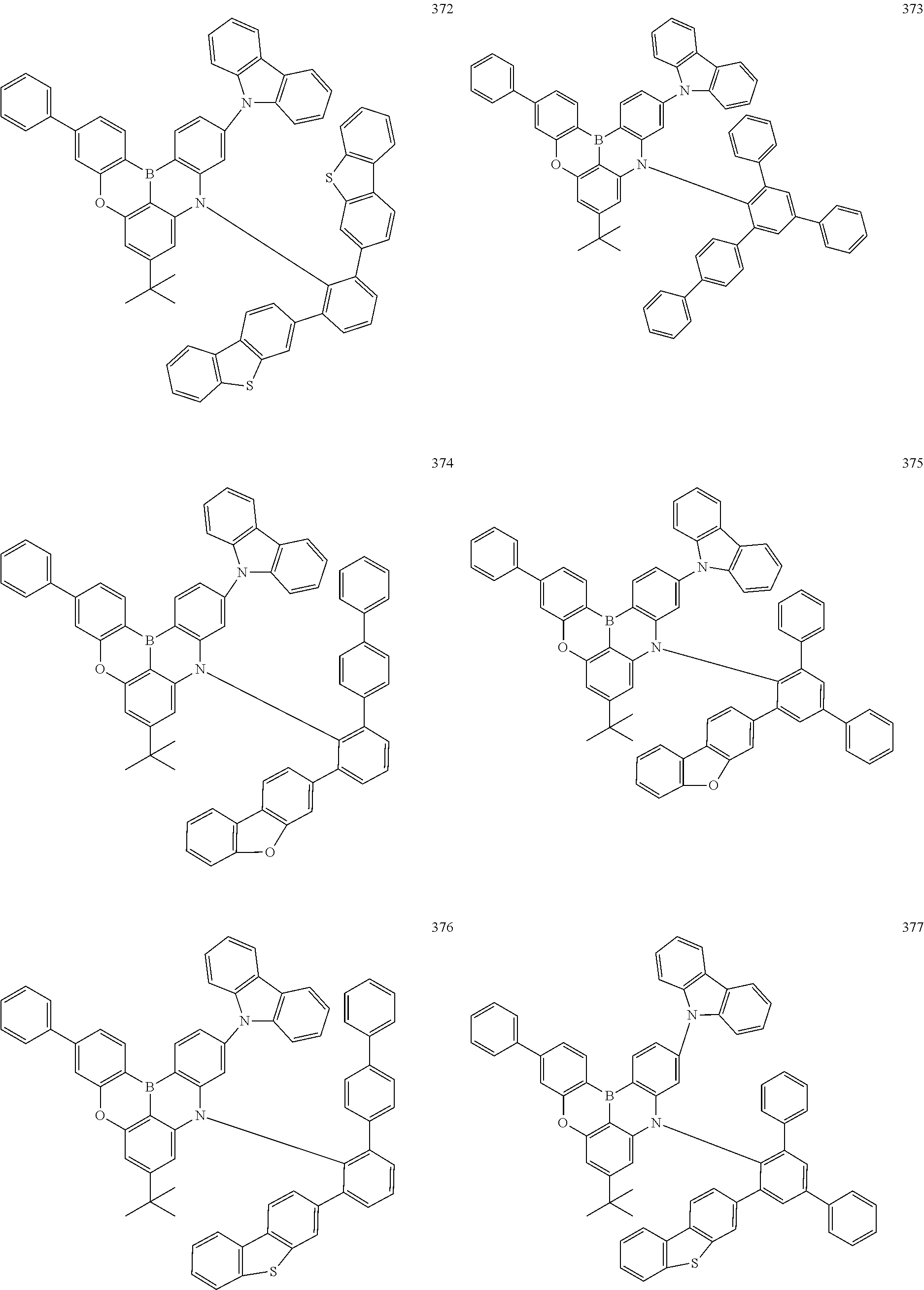

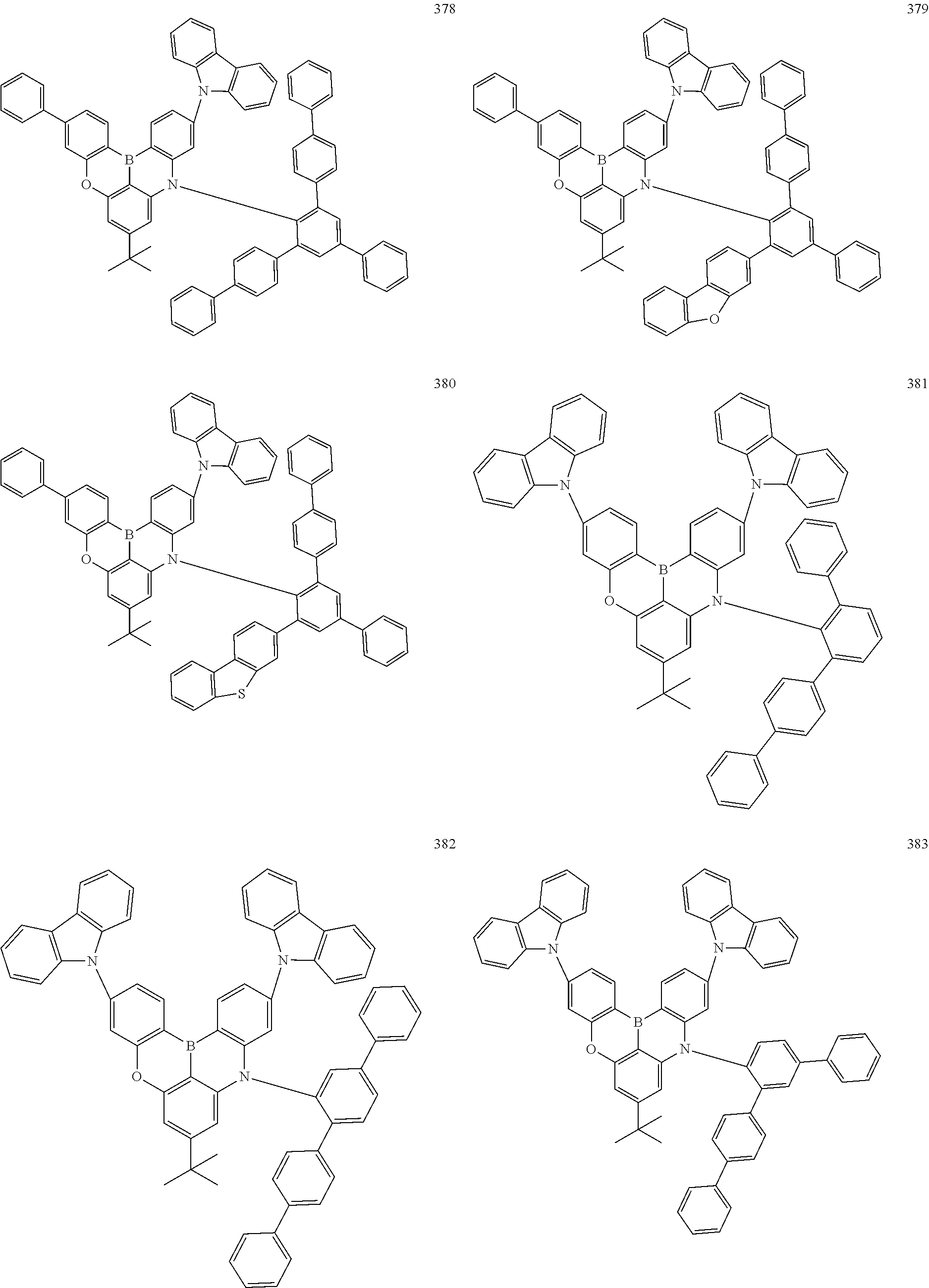

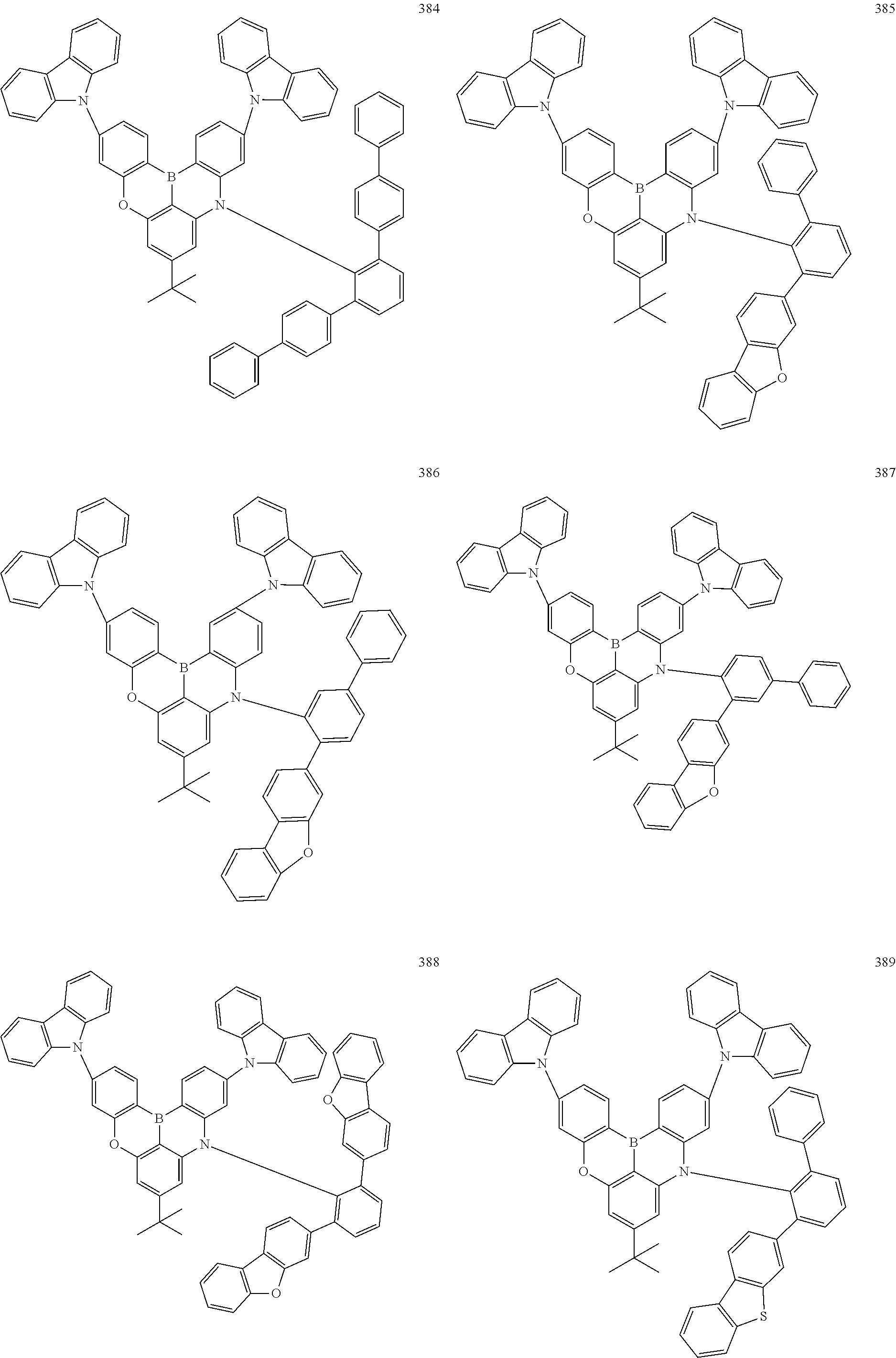

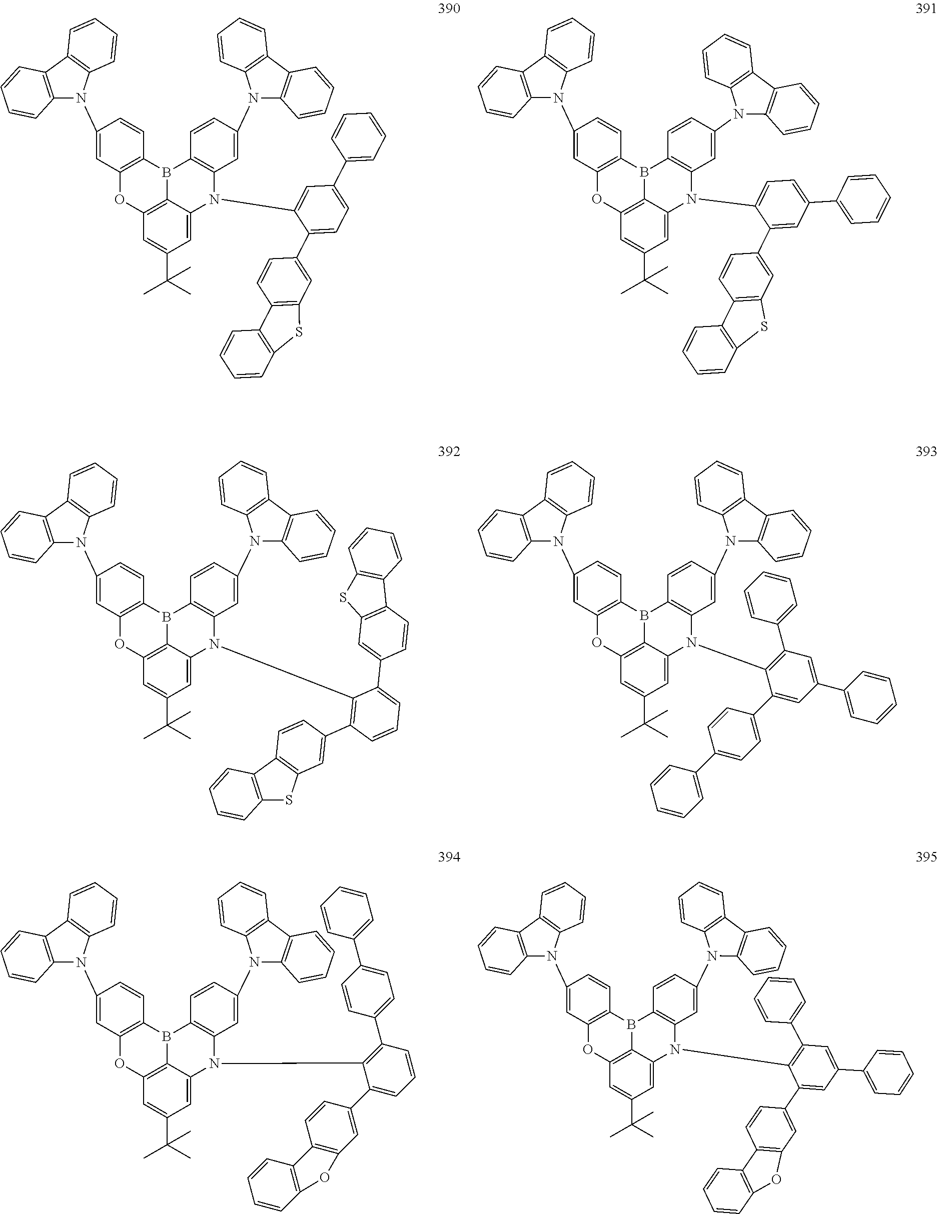

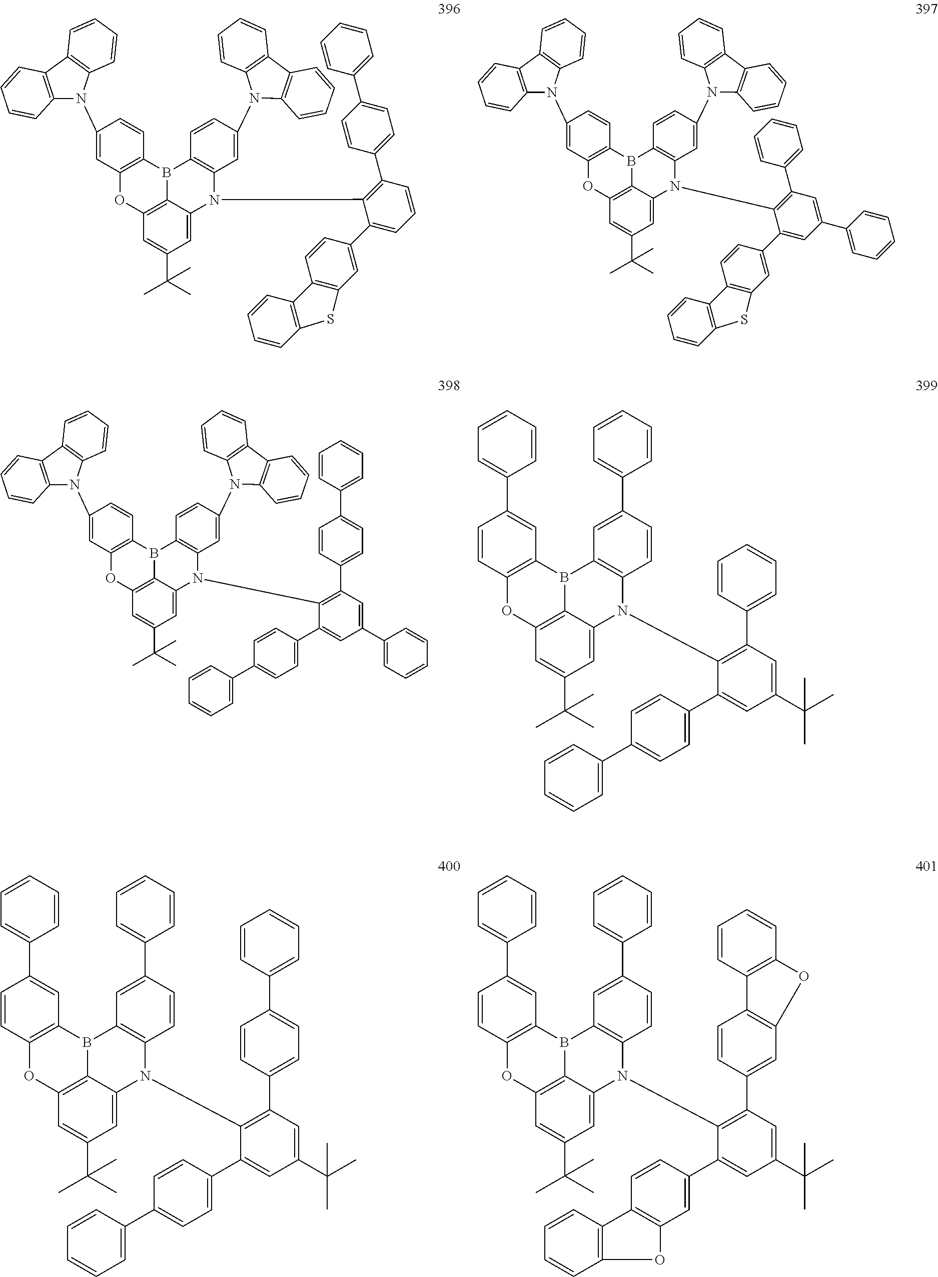

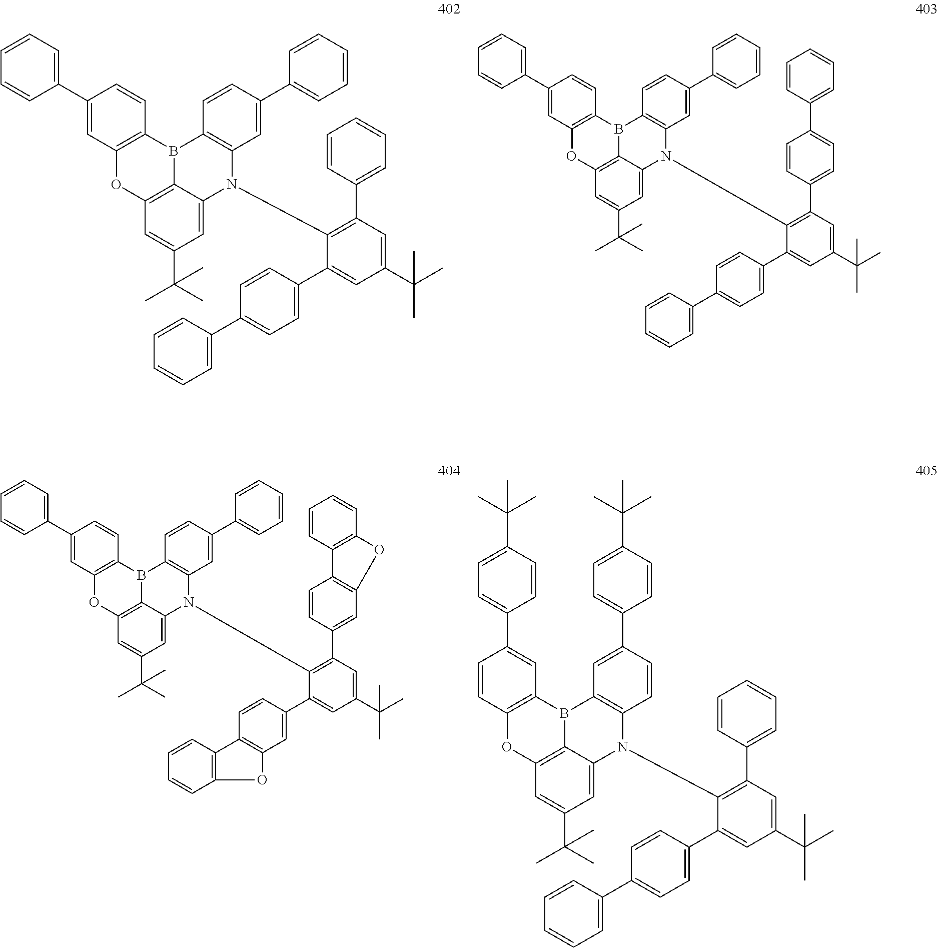

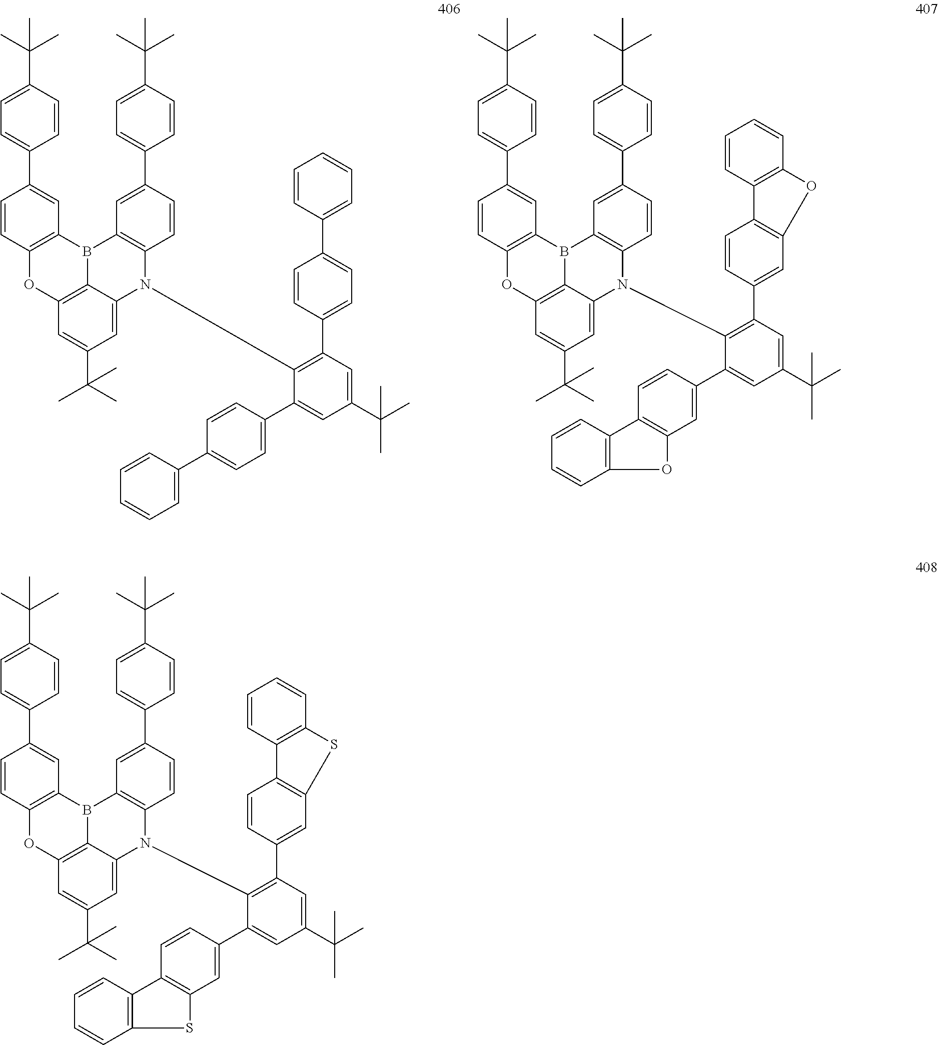 [SMILES: CC(C)(C)c1ccc(-c2ccc3c(c2)B2c4cc(-c5ccc(C(C)(C)C)cc5)ccc4N(c4c(-c5ccc(-c6ccccc6)cc5)cc(C(C)(C)C)cc4-c4ccc(-c5ccccc5)cc4)c4cc(C(C)(C)C)cc(c42)O3)cc1 ; CC(C)(C)c1ccc(-c2ccc3c(c2)B2c4cc(-c5ccc(C(C)(C)C)cc5)ccc4N(c4c(-c5ccc6c(c5)oc5ccccc56)cc(C(C)(C)C)cc4-c4ccc5c(c4)oc4ccccc45)c4cc(C(C)(C)C)cc(c42)O3)cc1 ; CC(C)(C)c1ccc(-c2ccc3c(c2)B2c4cc(-c5ccc(C(C)(C)C)cc5)ccc4N(c4c(-c5ccc6c(c5)sc5ccccc56)cc(C(C)(C)C)cc4-c4ccc5c(c4)sc4ccccc45)c4cc(C(C)(C)C)cc(c42)O3)cc1]

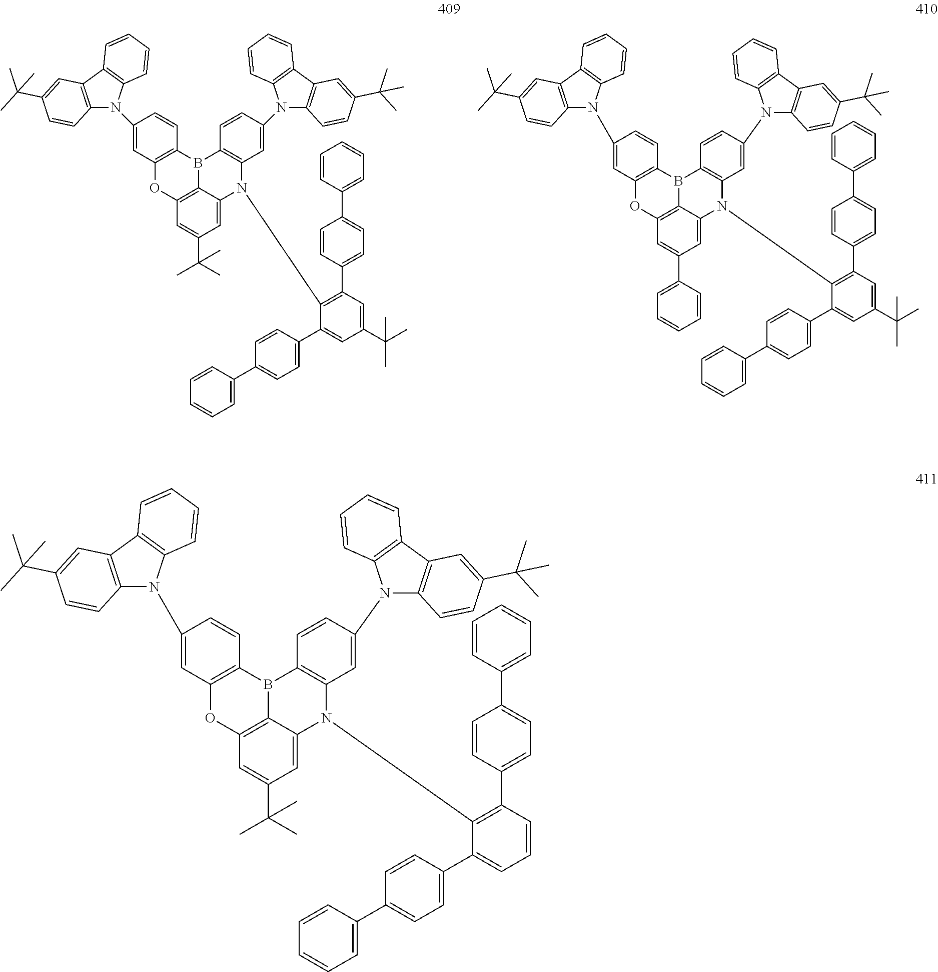 [SMILES: CC(C)(C)c1cc(-c2ccc(-c3ccccc3)cc2)c(N2c3cc(-n4c5ccccc5c5cc(C(C)(C)C)ccc54)ccc3B3c4ccc(-n5c6ccccc6c6cc(C(C)(C)C)ccc65)cc4Oc4cc(C(C)(C)C)cc2c43)c(-c2ccc(-c3ccccc3)cc2)c1 ; CC(C)(C)c1cc(-c2ccc(-c3ccccc3)cc2)c(N2c3cc(-n4c5ccccc5c5cc(C(C)(C)C)ccc54)ccc3B3c4ccc(-n5c6ccccc6c6cc(C(C)(C)C)ccc65)cc4Oc4cc(-c5ccccc5)cc2c43)c(-c2ccc(-c3ccccc3)cc2)c1 ; CC(C)(C)c1cc2c3c(c1)N(c1c(-c4ccc(-c5ccccc5)cc4)cccc1-c1ccc(-c4ccccc4)cc1)c1cc(-n4c5ccccc5c5cc(C(C)(C)C)ccc54)ccc1B3c1ccc(-n3c4ccccc4c4cc(C(C)(C)C)ccc43)cc1O2]

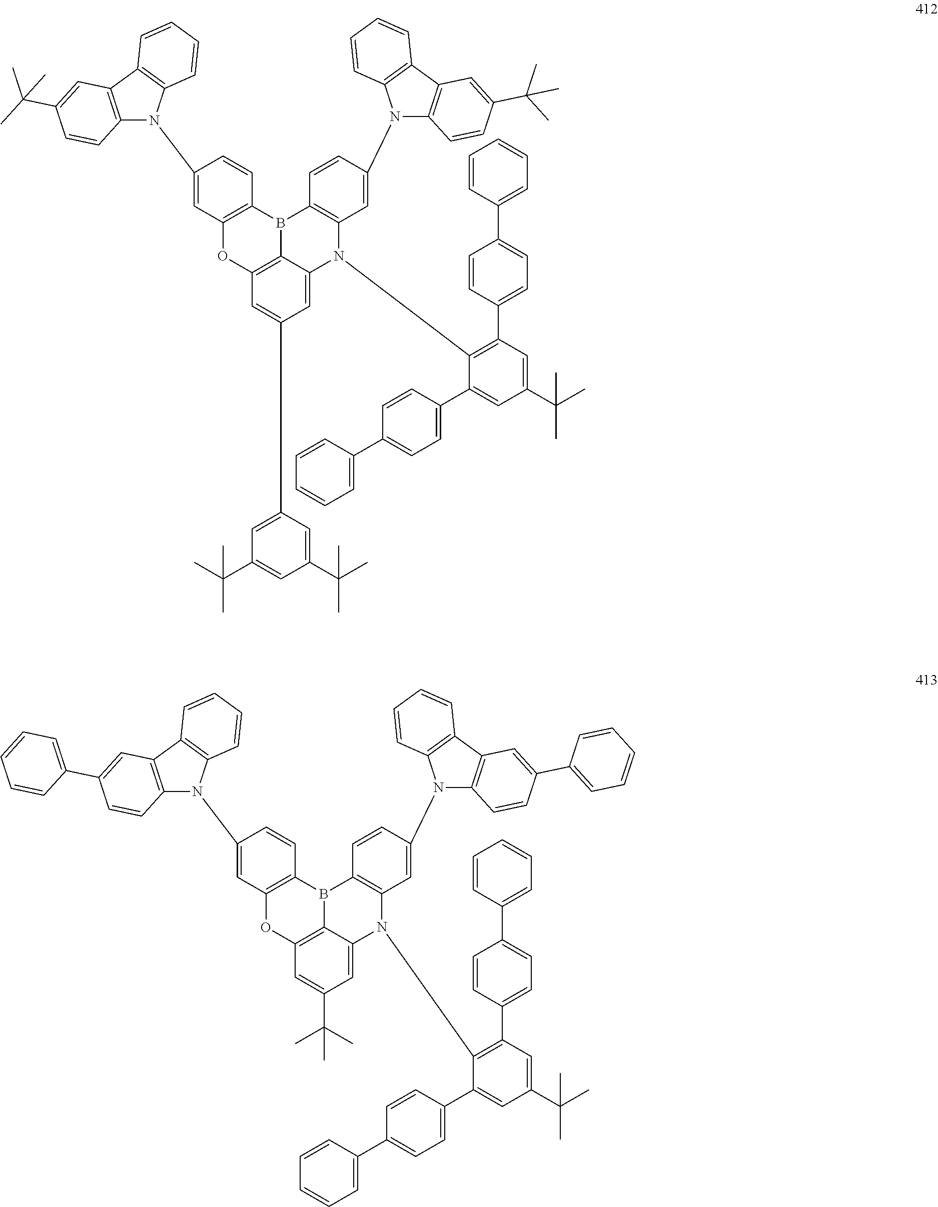 [SMILES: CC(C)(C)c1cc(-c2cc3c4c(c2)N(c2c(-c5ccc(-c6ccccc6)cc5)cc(C(C)(C)C)cc2-c2ccc(-c5ccccc5)cc2)c2cc(-n5c6ccccc6c6cc(C(C)(C)C)ccc65)ccc2B4c2ccc(-n4c5ccccc5c5cc(C(C)(C)C)ccc54)cc2O3)cc(C(C)(C)C)c1 ; CC(C)(C)c1cc(-c2ccc(-c3ccccc3)cc2)c(N2c3cc(-n4c5ccccc5c5cc(-c6ccccc6)ccc54)ccc3B3c4ccc(-n5c6ccccc6c6cc(-c7ccccc7)ccc65)cc4Oc4cc(C(C)(C)C)cc2c43)c(-c2ccc(-c3ccccc3)cc2)c1]

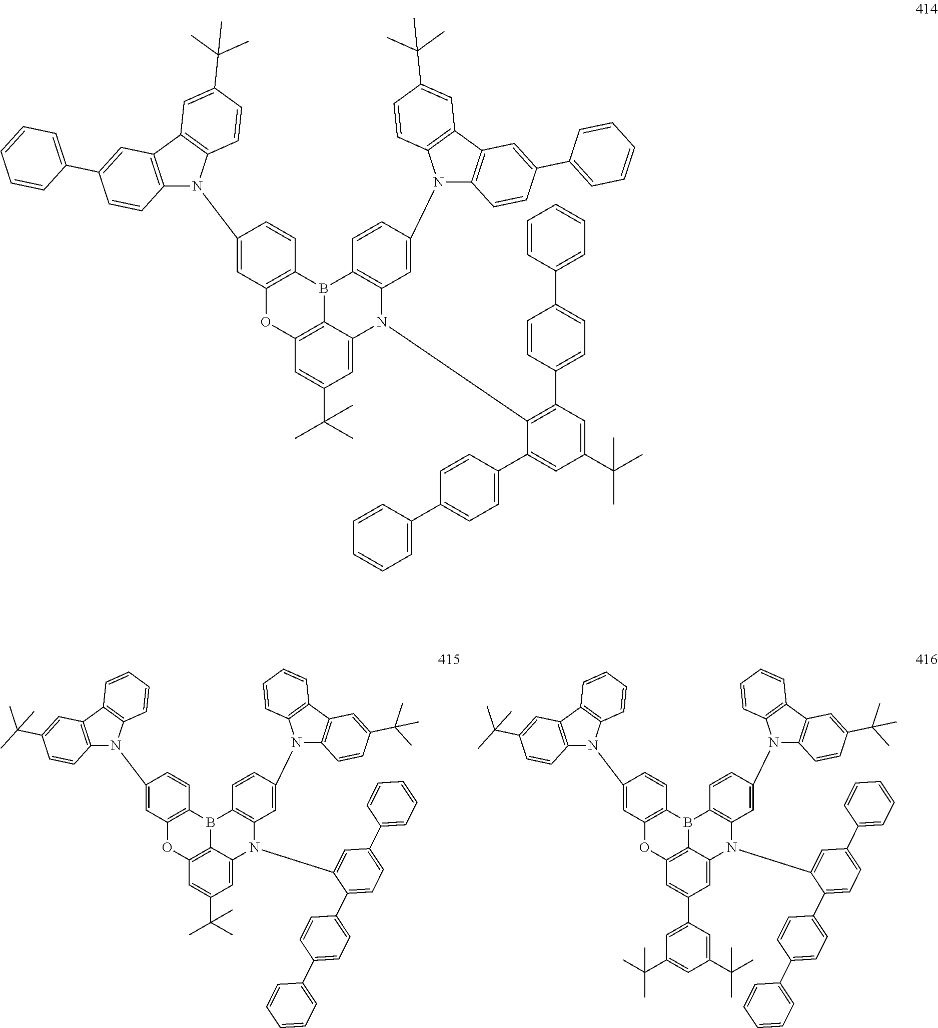

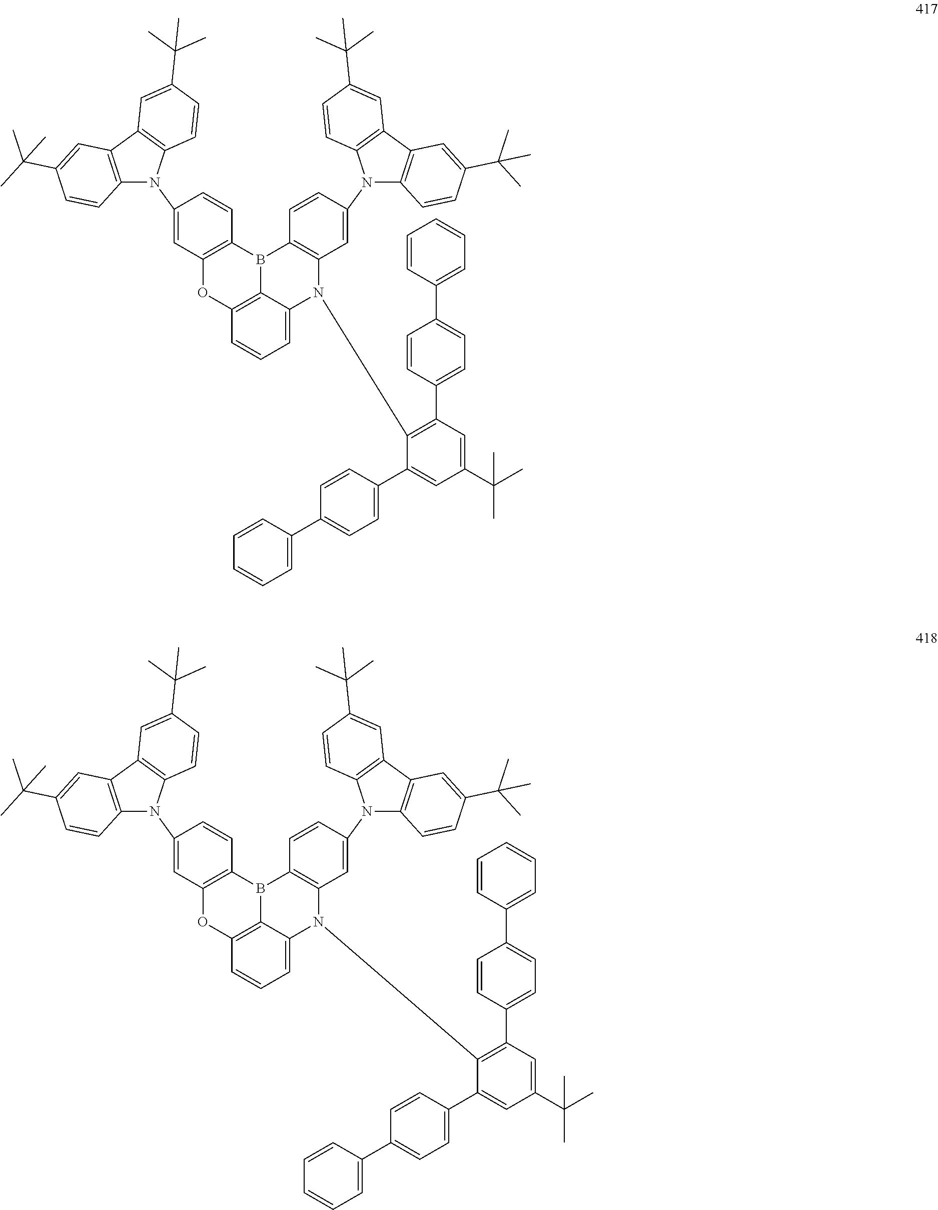

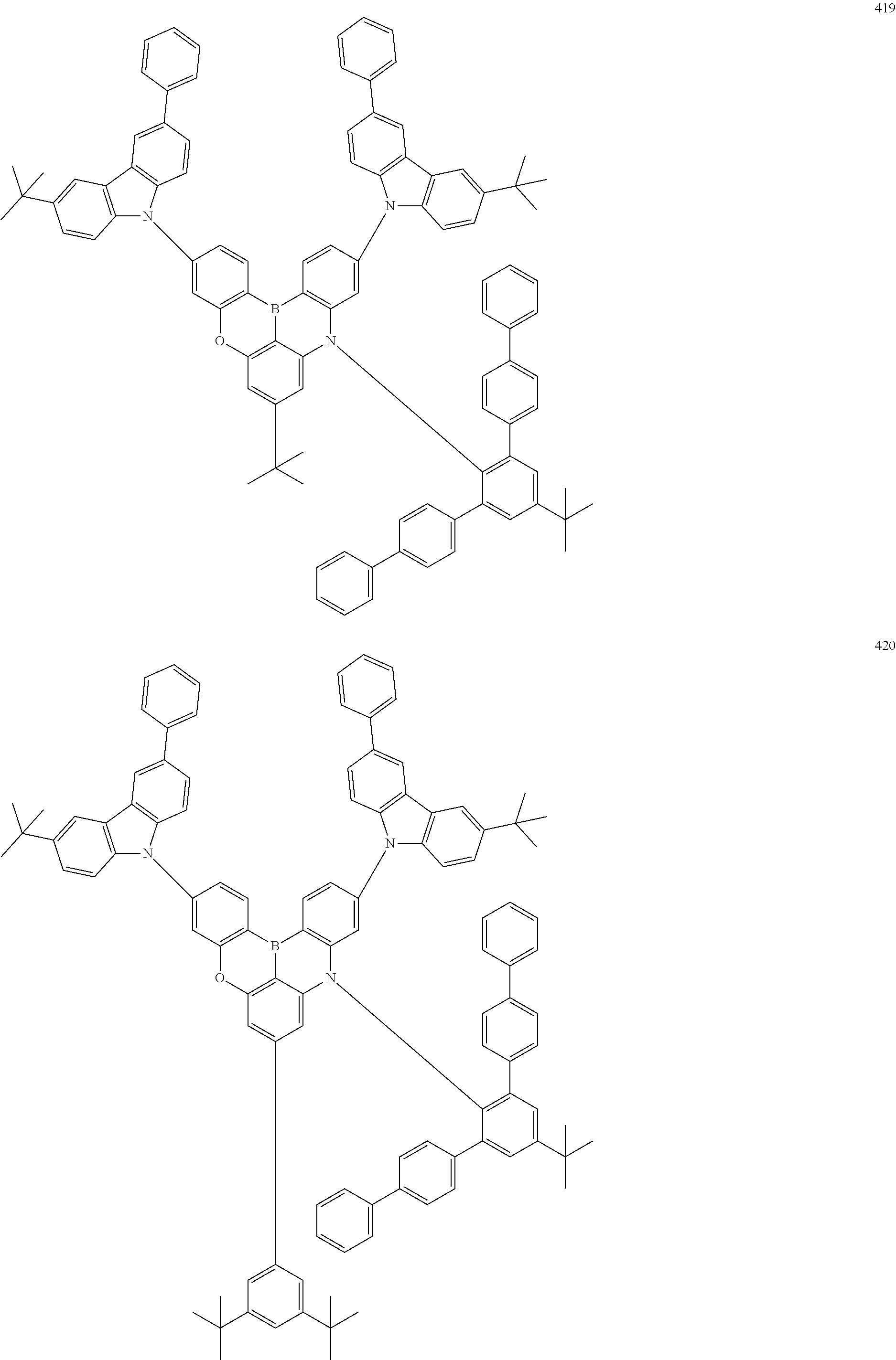

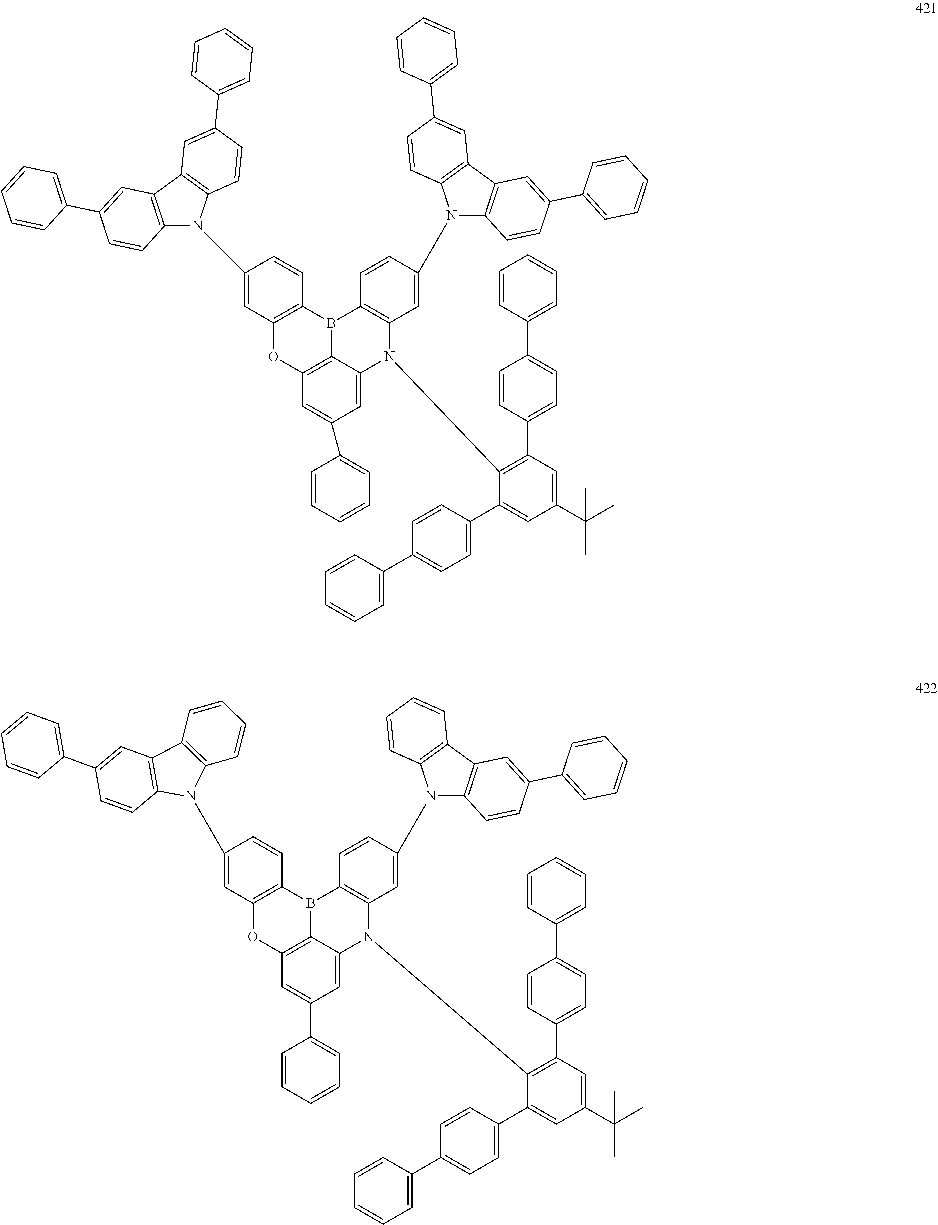 [SMILES: CC(C)(C)c1cc(-c2ccc(-c3ccccc3)cc2)c(N2c3cc(Cn4c5ccc(-c6ccccc6)cc5c5cc(-c6ccccc6)ccc54)ccc3B3c4ccc(Cn5c6ccc(-c7ccccc7)cc6c6cc(-c7ccccc7)ccc65)cc4Oc4cc(-c5ccccc5)cc2c43)c(-c2ccc(-c3ccccc3)cc2)c1 ; CC(C)(C)c1cc(-c2ccc(-c3ccccc3)cc2)c(N2c3cc(Cn4c5ccccc5c5cc(-c6ccccc6)ccc54)ccc3B3c4ccc(Cn5c6ccccc6c6cc(-c7ccccc7)ccc65)cc4Oc4cc(-c5ccccc5)cc2c43)c(-c2ccc(-c3ccccc3)cc2)c1]

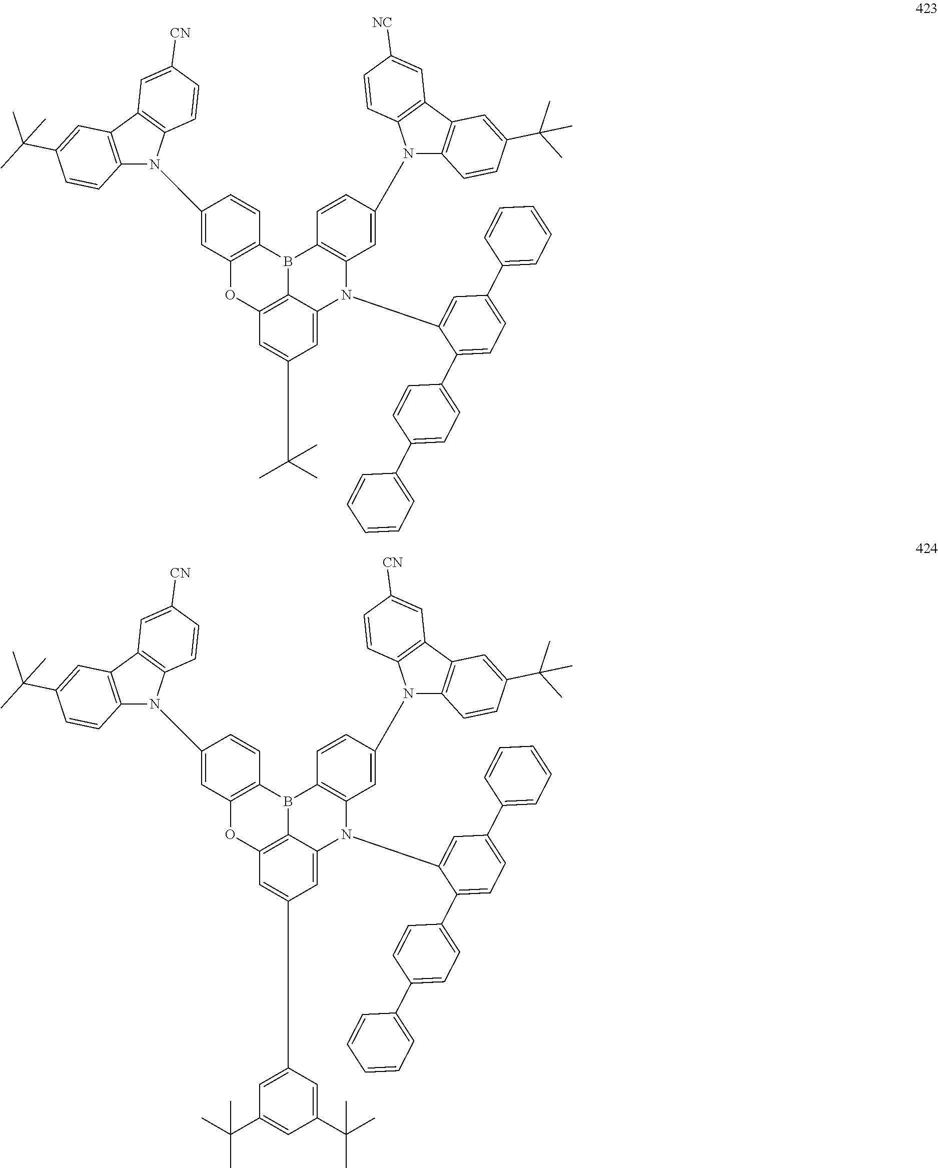

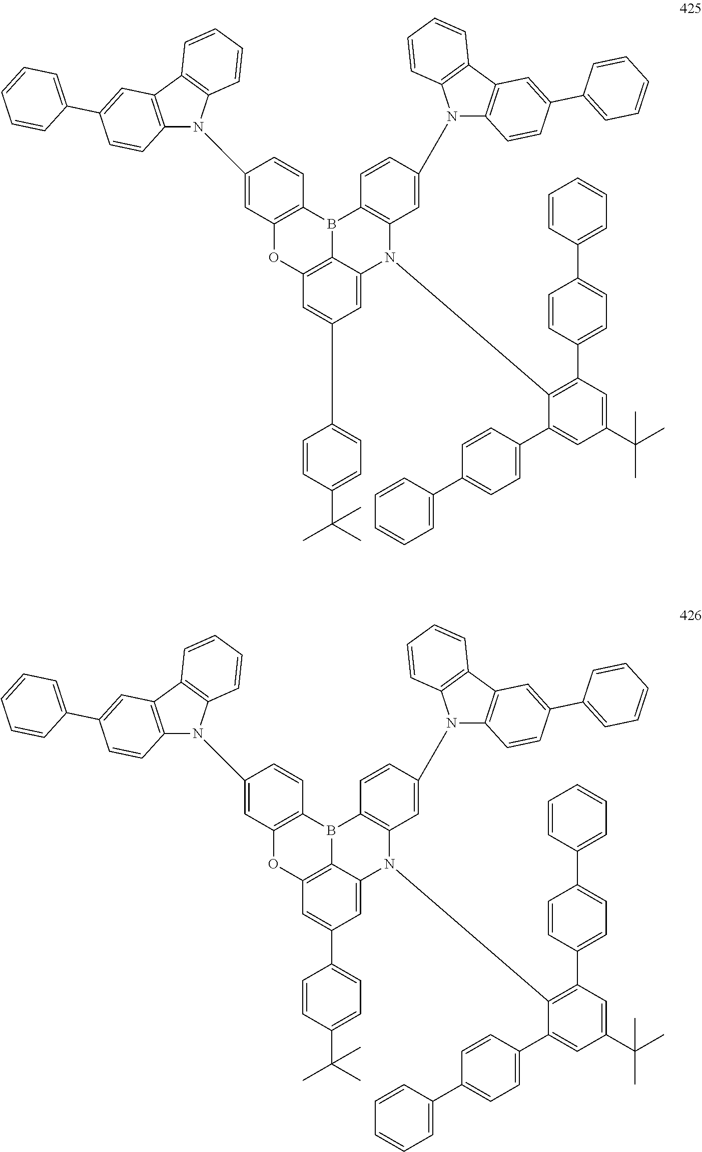 [SMILES: CC(C)(C)c1ccc(CCc2cc3c4c(c2)N(c2c(-c5ccc(-c6ccccc6)cc5)cc(C(C)(C)C)cc2-c2ccc(-c5ccccc5)cc2)c2cc(Cn5c6ccccc6c6cc(-c7ccccc7)ccc65)ccc2B4c2ccc(Cn4c5ccccc5c5cc(-c6ccccc6)ccc54)cc2O3)cc1 ; CC(C)(C)c1ccc(-c2cc3c4c(c2)N(c2c(-c5ccc(-c6ccccc6)cc5)cc(C(C)(C)C)cc2-c2ccc(-c5ccccc5)cc2)c2cc(Cn5c6ccccc6c6cc(-c7ccccc7)ccc65)ccc2B4c2ccc(Cn4c5ccccc5c5cc(-c6ccccc6)ccc54)cc2O3)cc1]

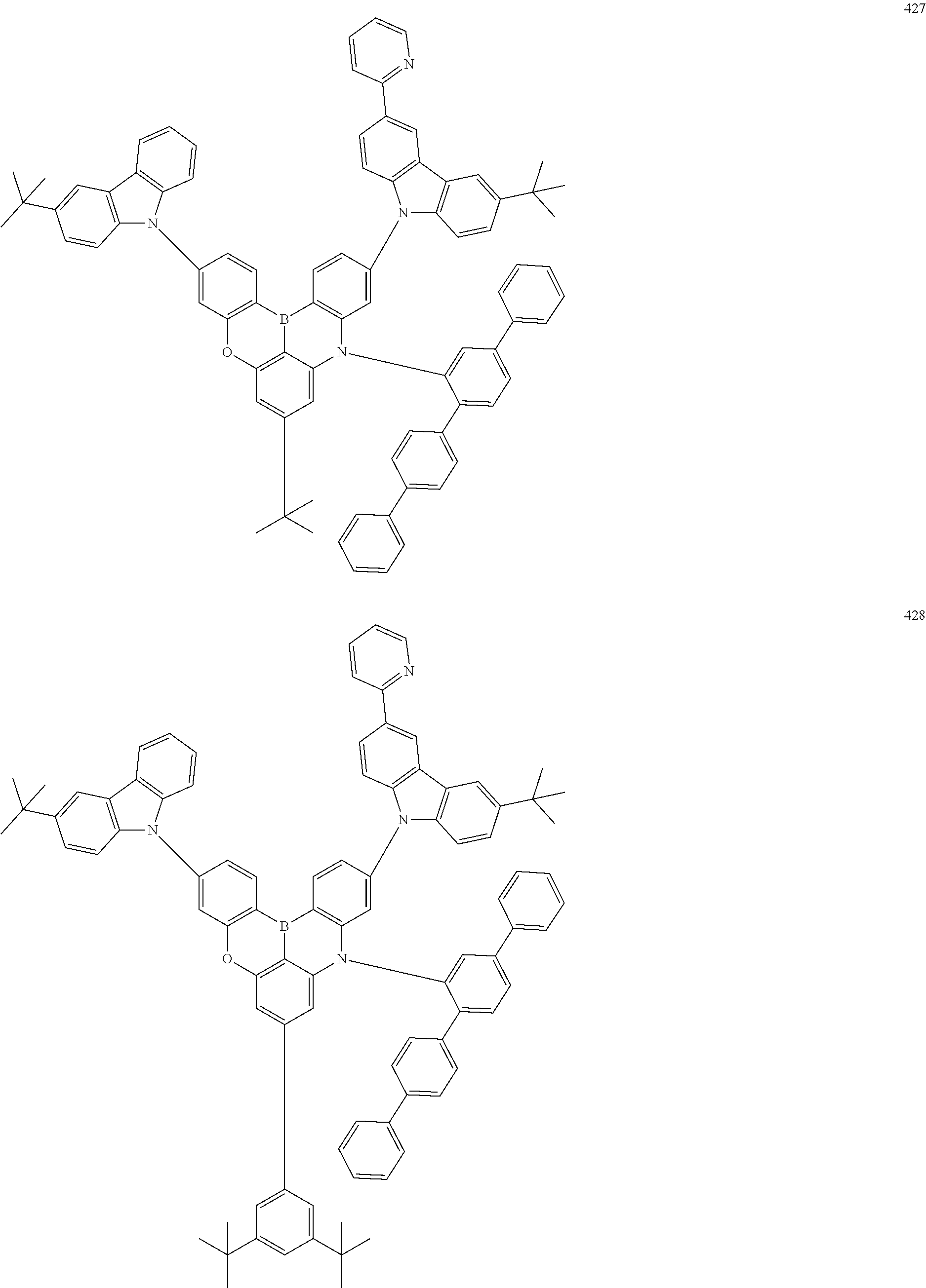

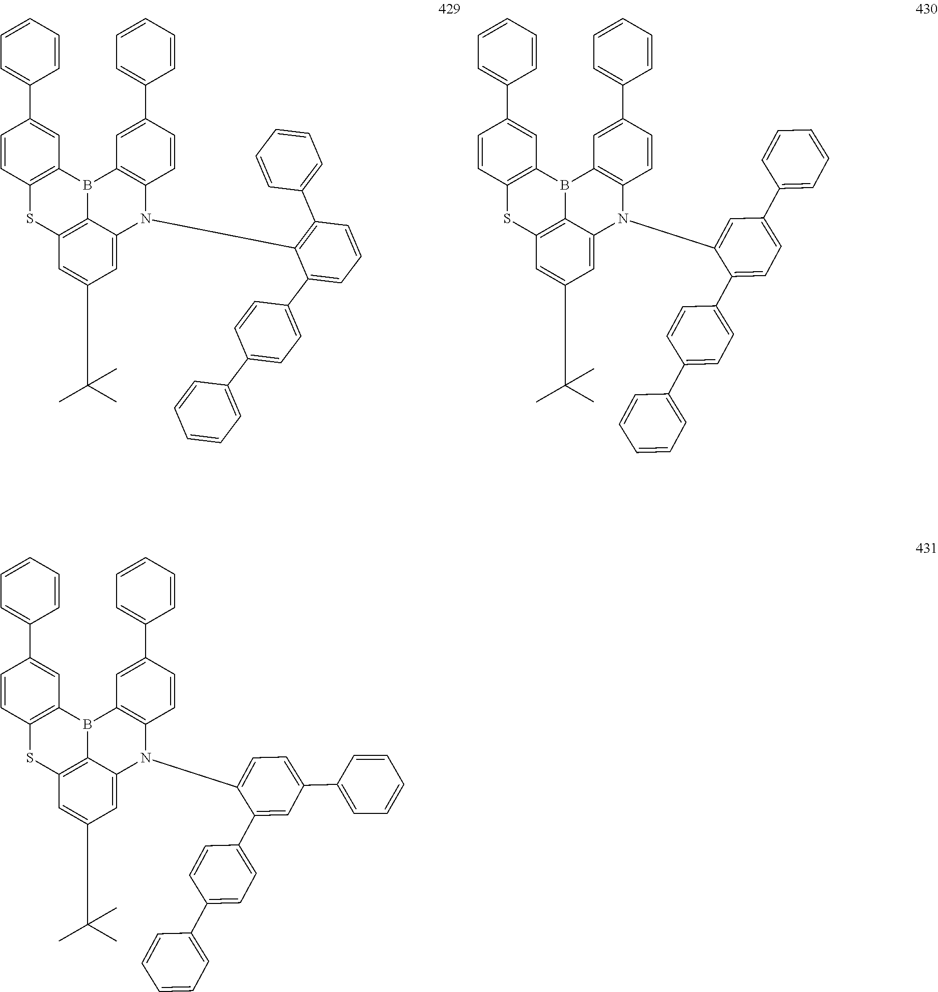 [SMILES: CC(C)(C)CCc1cc2c3c(c1)N(c1c(-c4ccccc4)cccc1-c1ccc(-c4ccccc4)cc1)c1ccc(-c4ccccc4)cc1B3c1cc(-c3ccccc3)ccc1S2 ; CC(C)(C)CCc1cc2c3c(c1)N(c1cc(-c4ccccc4)ccc1-c1ccc(-c4ccccc4)cc1)c1ccc(-c4ccccc4)cc1B3c1cc(-c3ccccc3)ccc1S2 ; CC(C)(C)CCc1cc2c3c(c1)N(c1ccc(-c4ccccc4)cc1-c1ccc(-c4ccccc4)cc1)c1ccc(-c4ccccc4)cc1B3c1cc(-c3ccccc3)ccc1S2]

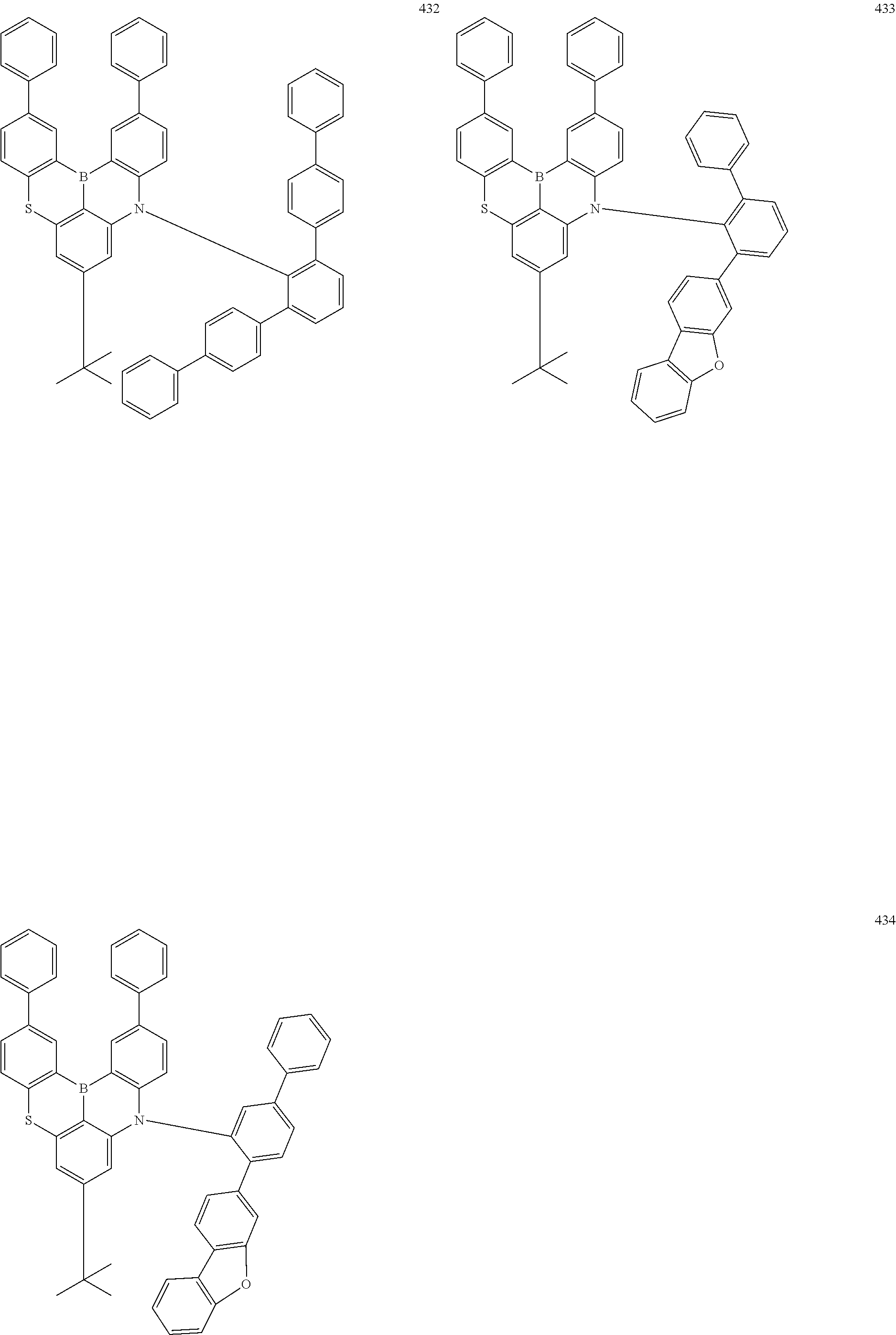 [SMILES: CC(C)(C)CCc1cc2c3c(c1)N(c1c(-c4ccc(-c5ccccc5)cc4)cccc1-c1ccc(-c4ccccc4)cc1)c1ccc(-c4ccccc4)cc1B3c1cc(-c3ccccc3)ccc1S2 ; CC(C)(C)CCc1cc2c3c(c1)N(c1c(-c4ccccc4)cccc1-c1ccc4c(c1)oc1ccccc14)c1ccc(-c4ccccc4)cc1B3c1cc(-c3ccccc3)ccc1S2 ; CC(C)(C)CCc1cc2c3c(c1)N(c1cc(-c4ccccc4)ccc1-c1ccc4c(c1)oc1ccccc14)c1ccc(-c4ccccc4)cc1B3c1cc(-c3ccccc3)ccc1S2]

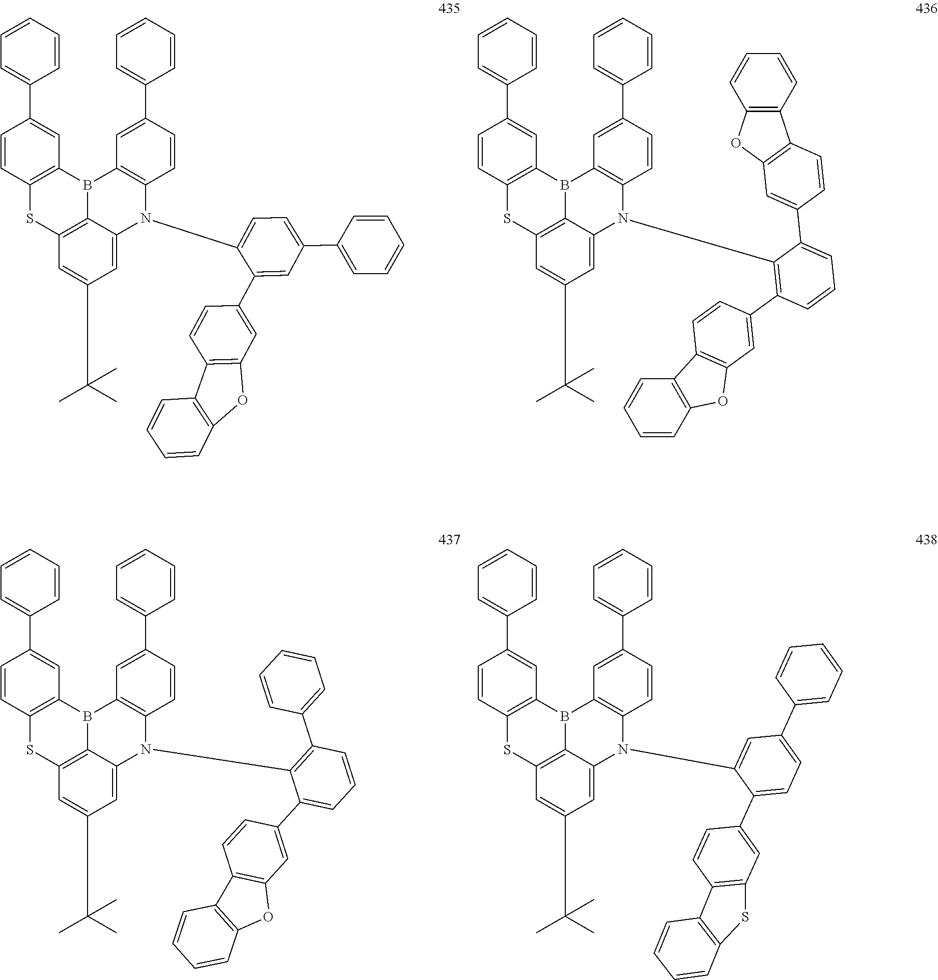 [SMILES: CC(C)(C)CCc1cc2c3c(c1)N(c1ccc(-c4ccccc4)cc1-c1ccc4c(c1)oc1ccccc14)c1ccc(-c4ccccc4)cc1B3c1cc(-c3ccccc3)ccc1S2 ; CC(C)(C)CCc1cc2c3c(c1)N(c1c(-c4ccc5c(c4)oc4ccccc45)cccc1-c1ccc4c(c1)oc1ccccc14)c1ccc(-c4ccccc4)cc1B3c1cc(-c3ccccc3)ccc1S2 ; CC(C)(C)CCc1cc2c3c(c1)N(c1c(-c4ccccc4)cccc1-c1ccc4c(c1)oc1ccccc14)c1ccc(-c4ccccc4)cc1B3c1cc(-c3ccccc3)ccc1S2 ; CC(C)(C)CCc1cc2c3c(c1)N(c1cc(-c4ccccc4)ccc1-c1ccc4c(c1)sc1ccccc14)c1ccc(-c4ccccc4)cc1B3c1cc(-c3ccccc3)ccc1S2]

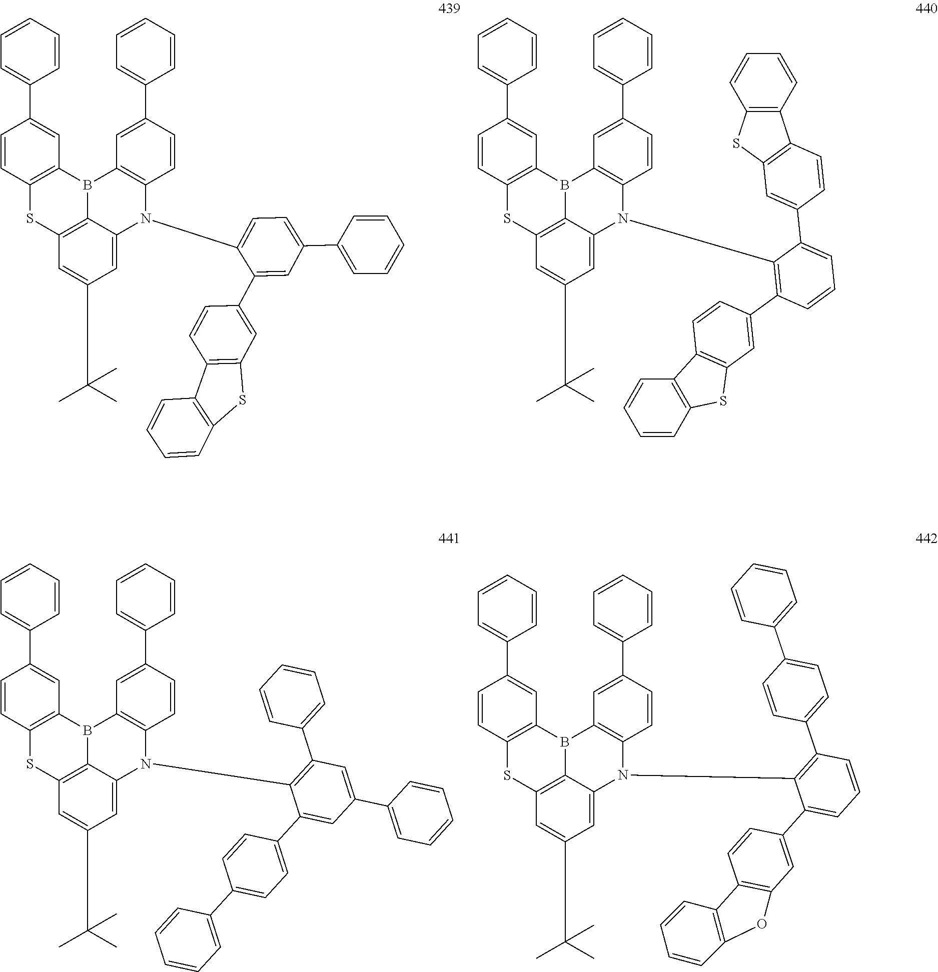 [SMILES: CC(C)(C)CCc1cc2c3c(c1)N(c1ccc(-c4ccccc4)cc1-c1ccc4c(c1)sc1ccccc14)c1ccc(-c4ccccc4)cc1B3c1cc(-c3ccccc3)ccc1S2 ; CC(C)(C)CCc1cc2c3c(c1)N(c1c(-c4ccc5c(c4)sc4ccccc45)cccc1-c1ccc4c(c1)sc1ccccc14)c1ccc(-c4ccccc4)cc1B3c1cc(-c3ccccc3)ccc1S2 ; CC(C)(C)CCc1cc2c3c(c1)N(c1c(-c4ccccc4)cc(-c4ccccc4)cc1-c1ccc(-c4ccccc4)cc1)c1ccc(-c4ccccc4)cc1B3c1cc(-c3ccccc3)ccc1S2 ; CC(C)(C)CCc1cc2c3c(c1)N(c1c(-c4ccc(-c5ccccc5)cc4)cccc1-c1ccc4c(c1)oc1ccccc14)c1ccc(-c4ccccc4)cc1B3c1cc(-c3ccccc3)ccc1S2]

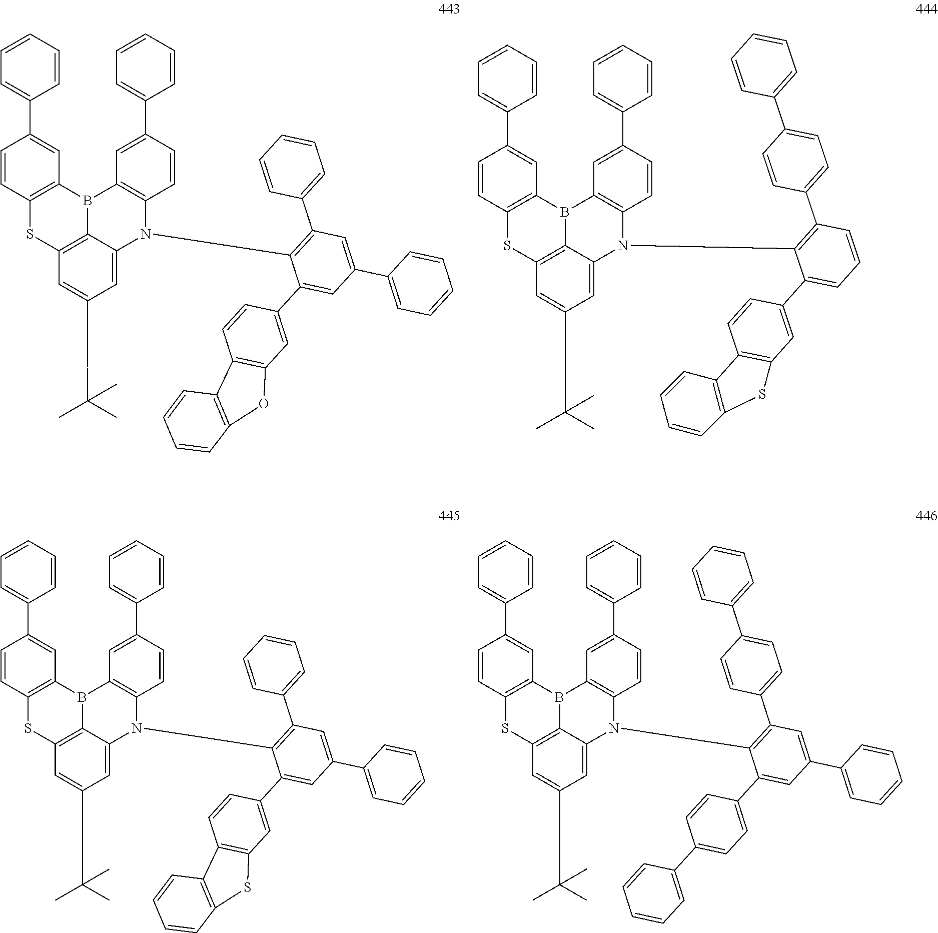 [SMILES: CC(C)(C)CCc1cc2c3c(c1)N(c1c(-c4ccccc4)cc(-c4ccccc4)cc1-c1ccc4c(c1)oc1ccccc14)c1ccc(-c4ccccc4)cc1B3c1cc(-c3ccccc3)ccc1S2 ; CC(C)(C)CCc1cc2c3c(c1)N(c1c(-c4ccc(-c5ccccc5)cc4)cccc1-c1ccc4c(c1)sc1ccccc14)c1ccc(-c4ccccc4)cc1B3c1cc(-c3ccccc3)ccc1S2 ; CC(C)(C)CCc1cc2c3c(c1)N(c1c(-c4ccccc4)cc(-c4ccccc4)cc1-c1ccc4c(c1)sc1ccccc14)c1ccc(-c4ccccc4)cc1B3c1cc(-c3ccccc3)ccc1S2 ; CC(C)(C)CCc1cc2c3c(c1)N(c1c(-c4ccc(-c5ccccc5)cc4)cc(-c4ccccc4)cc1-c1ccc(-c4ccccc4)cc1)c1ccc(-c4ccccc4)cc1B3c1cc(-c3ccccc3)ccc1S2]

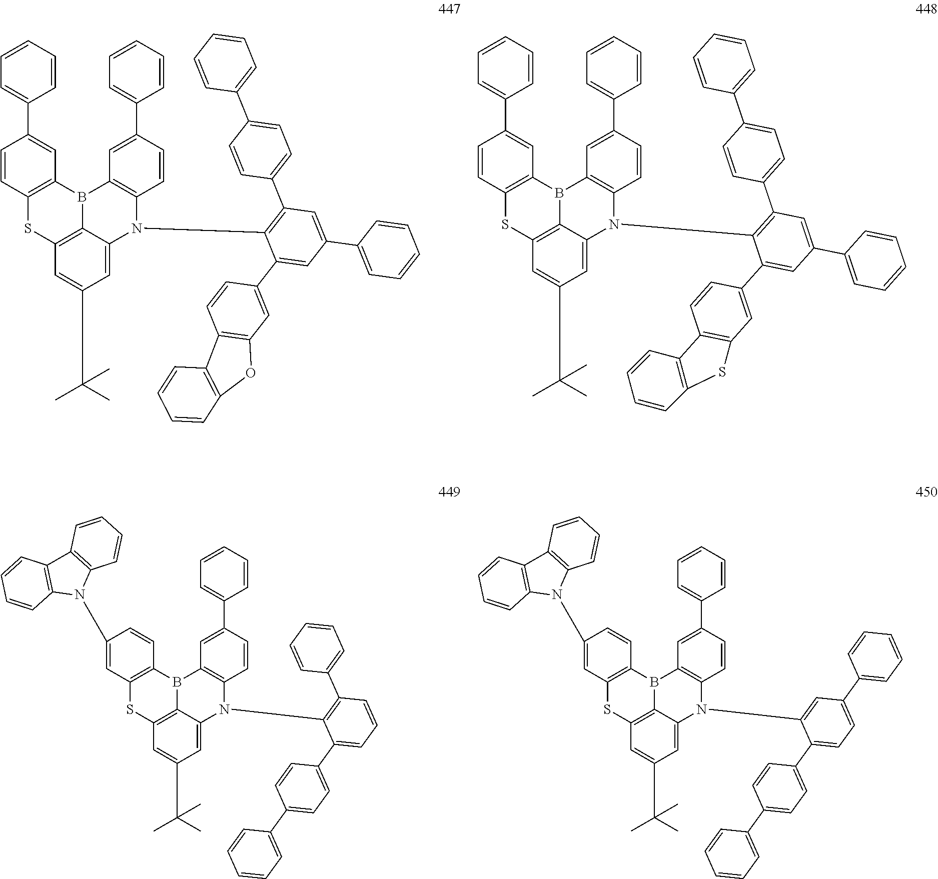

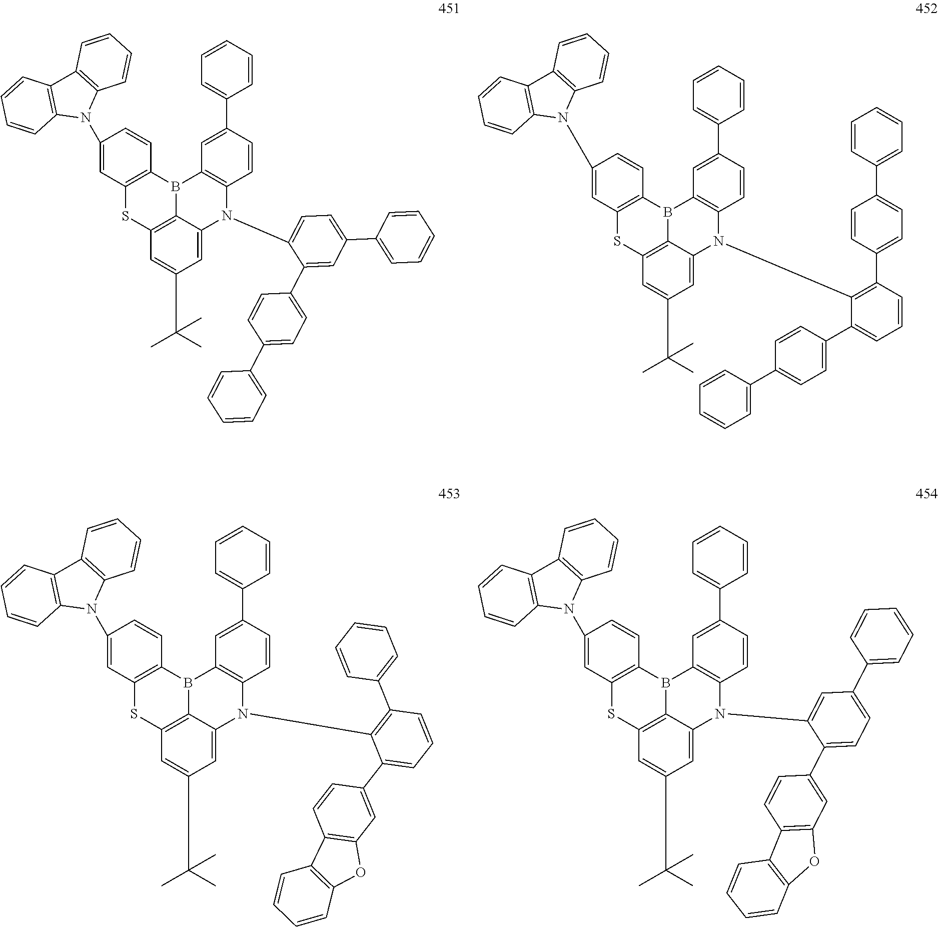 [SMILES: CC(C)(C)Cc1cc2c3c(c1)N(c1ccc(-c4ccccc4)cc1-c1ccc(-c4ccccc4)cc1)c1ccc(-c4ccccc4)cc1B3c1ccc(-n3c4ccccc4c4ccccc43)cc1S2 ; CC(C)(C)Cc1cc2c3c(c1)N(c1c(-c4ccc(-c5ccccc5)cc4)cccc1-c1ccc(-c4ccccc4)cc1)c1ccc(-c4ccccc4)cc1B3c1ccc(Cn3c4ccccc4c4ccccc43)cc1S2 ; CC(C)(C)CCc1cc2c3c(c1)N(c1c(-c4ccccc4)cccc1-c1ccc4c(c1)oc1ccccc14)c1ccc(-c4ccccc4)cc1B3c1ccc(-n3c4ccccc4c4ccccc43)cc1S2 ; CC(C)(C)CCc1cc2c3c(c1)N(c1cc(-c4ccccc4)ccc1-c1ccc4c(c1)oc1ccccc14)c1ccc(-c4ccccc4)cc1B3c1ccc(-n3c4ccccc4c4ccccc43)cc1S2]

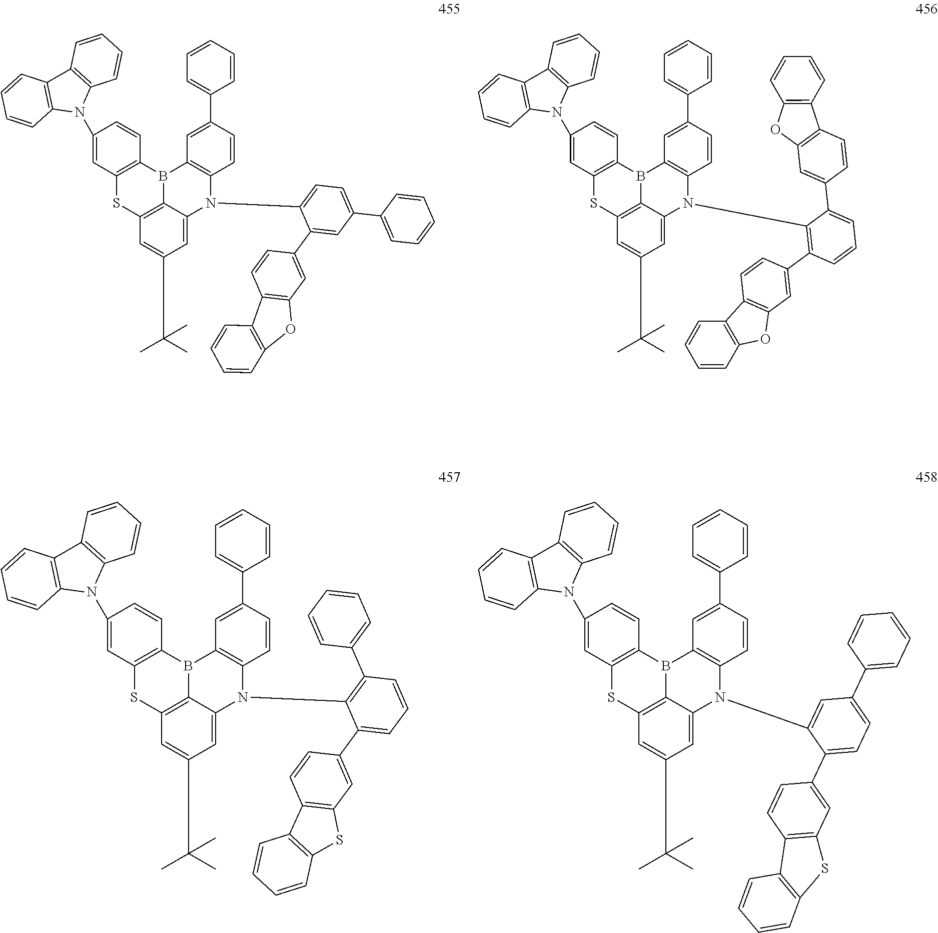 [SMILES: CC(C)(C)CCc1cc2c3c(c1)N(c1ccc(-c4ccccc4)cc1-c1ccc4c(c1)oc1ccccc14)c1ccc(-c4ccccc4)cc1B3c1ccc(-n3c4ccccc4c4ccccc43)cc1S2 ; CC(C)(C)CCc1cc2c3c(c1)N(c1c(-c4ccc5c(c4)oc4ccccc45)cccc1-c1ccc4c(c1)oc1ccccc14)c1ccc(-c4ccccc4)cc1B3c1ccc(-n3c4ccccc4c4ccccc43)cc1S2 ; CC(C)(C)CCc1cc2c3c(c1)N(c1c(-c4ccccc4)cccc1-c1ccc4c(c1)sc1ccccc14)c1ccc(-c4ccccc4)cc1B3c1ccc(-n3c4ccccc4c4ccccc43)cc1S2 ; CC(C)(C)CCc1cc2c3c(c1)N(c1cc(-c4ccccc4)ccc1-c1ccc4c(c1)sc1ccccc14)c1ccc(-c4ccccc4)cc1B3c1ccc(-n3c4ccccc4c4ccccc43)cc1S2]

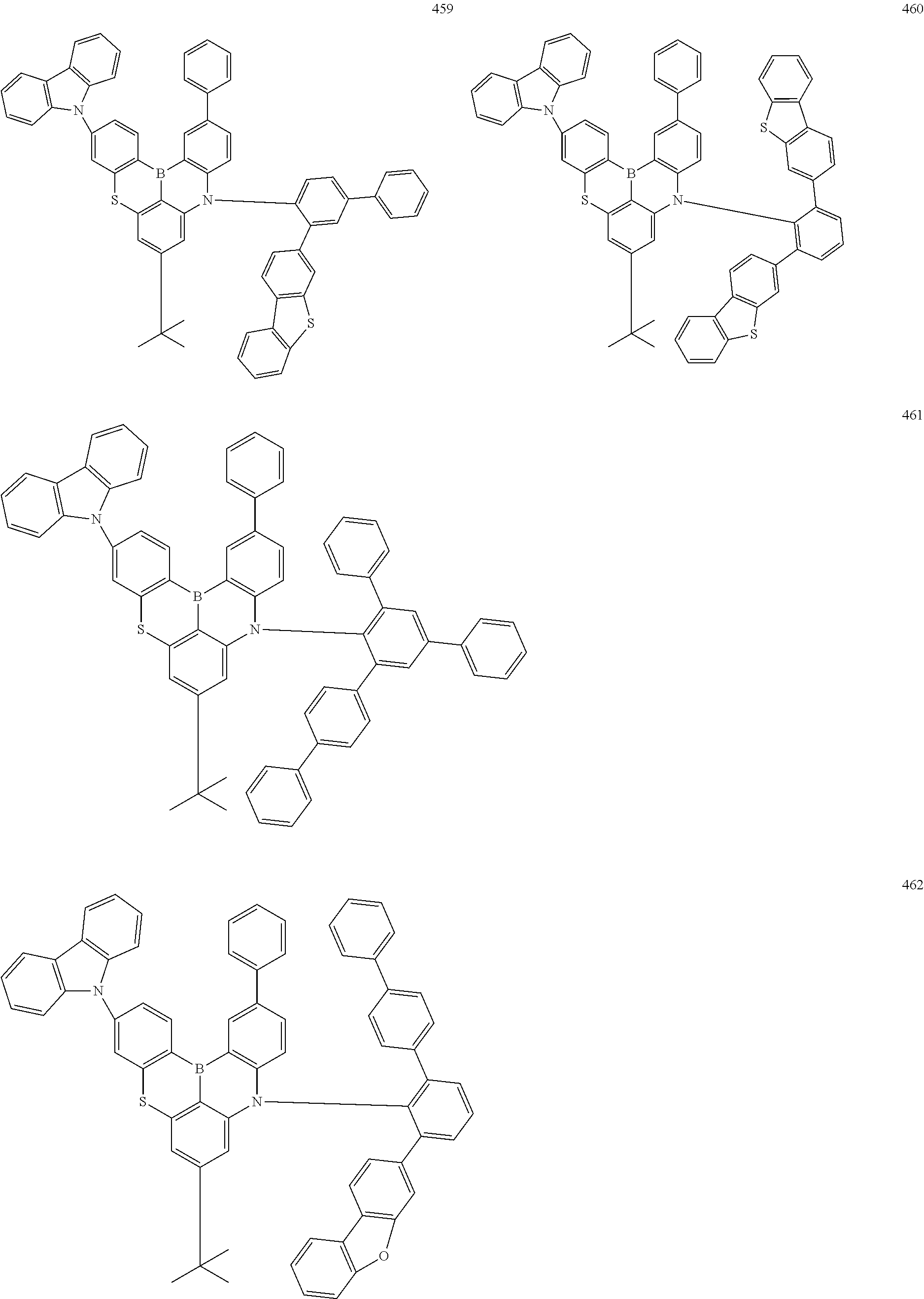

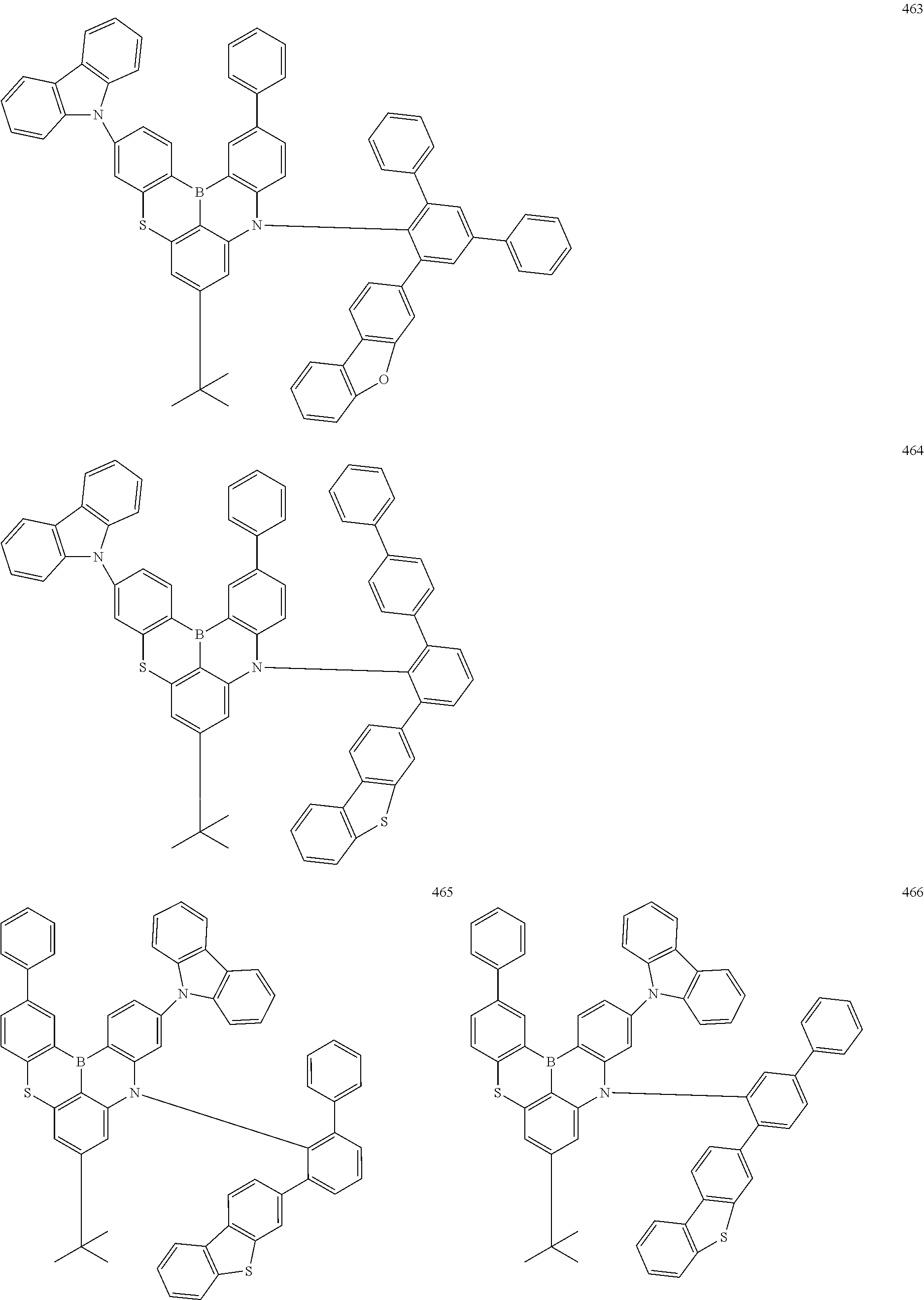

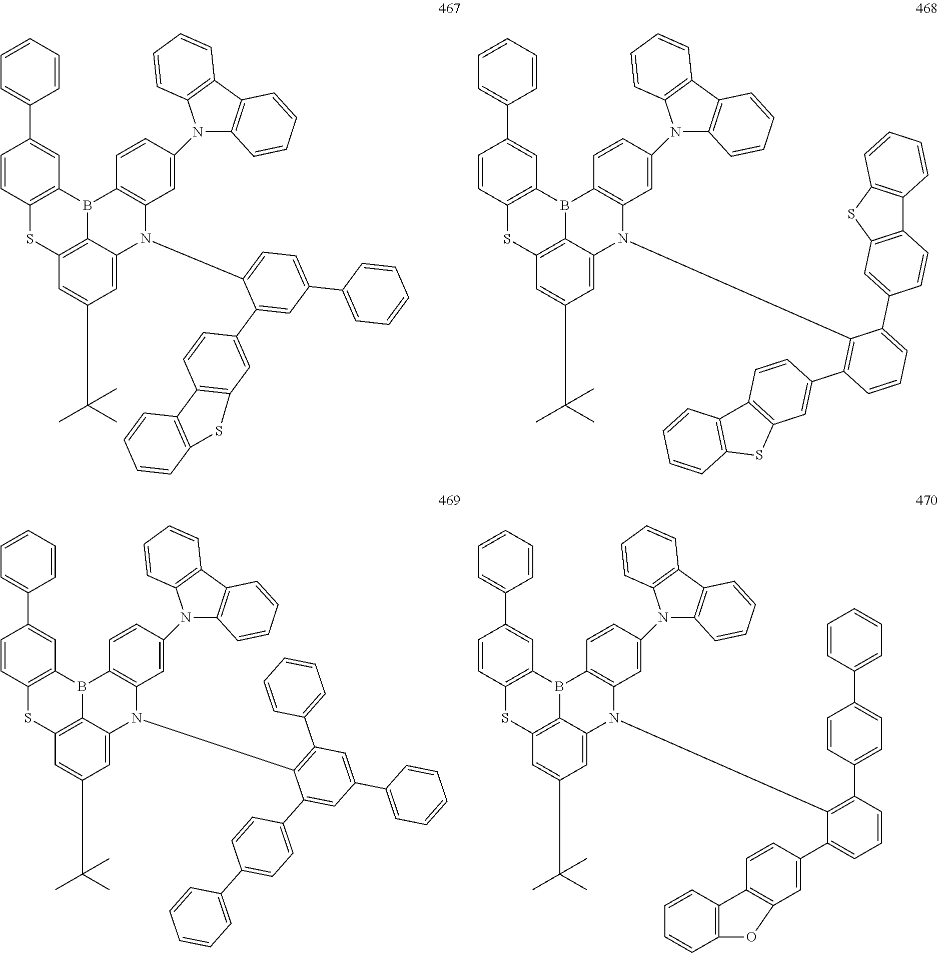

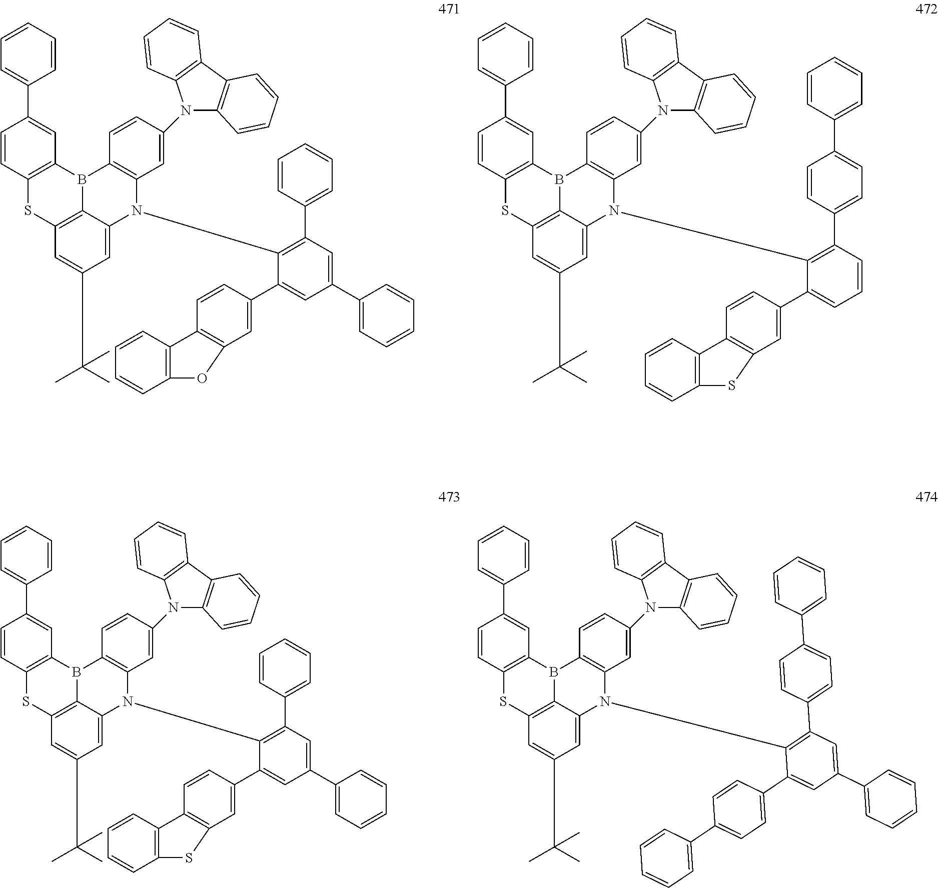

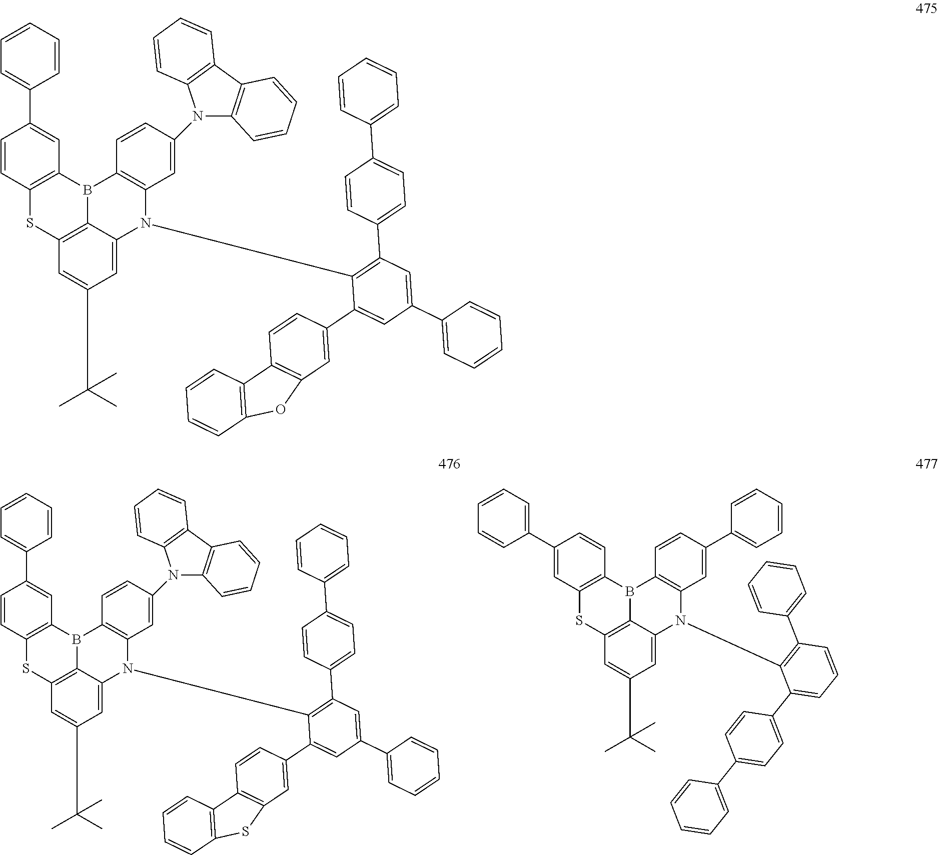 [SMILES: CC(C)(C)CCc1cc2c3c(c1)N(c1c(-c4ccc(-c5ccccc5)cc4)cc(-c4ccccc4)cc1-c1ccc4c(c1)oc1ccccc14)c1cc(-n4c5ccccc5c5ccccc54)ccc1B3c1cc(-c3ccccc3)ccc1S2 ; CC(C)(C)CCc1cc2c3c(c1)N(c1c(-c4ccc(-c5ccccc5)cc4)cc(-c4ccccc4)cc1-c1ccc4c(c1)sc1ccccc14)c1cc(-n4c5ccccc5c5ccccc54)ccc1B3c1cc(-c3ccccc3)ccc1S2 ; CC(C)(C)Cc1cc2c3c(c1)N(c1c(-c4ccccc4)cccc1-c1ccc(-c4ccccc4)cc1)c1cc(-c4ccccc4)ccc1B3c1ccc(-c3ccccc3)cc1S2]

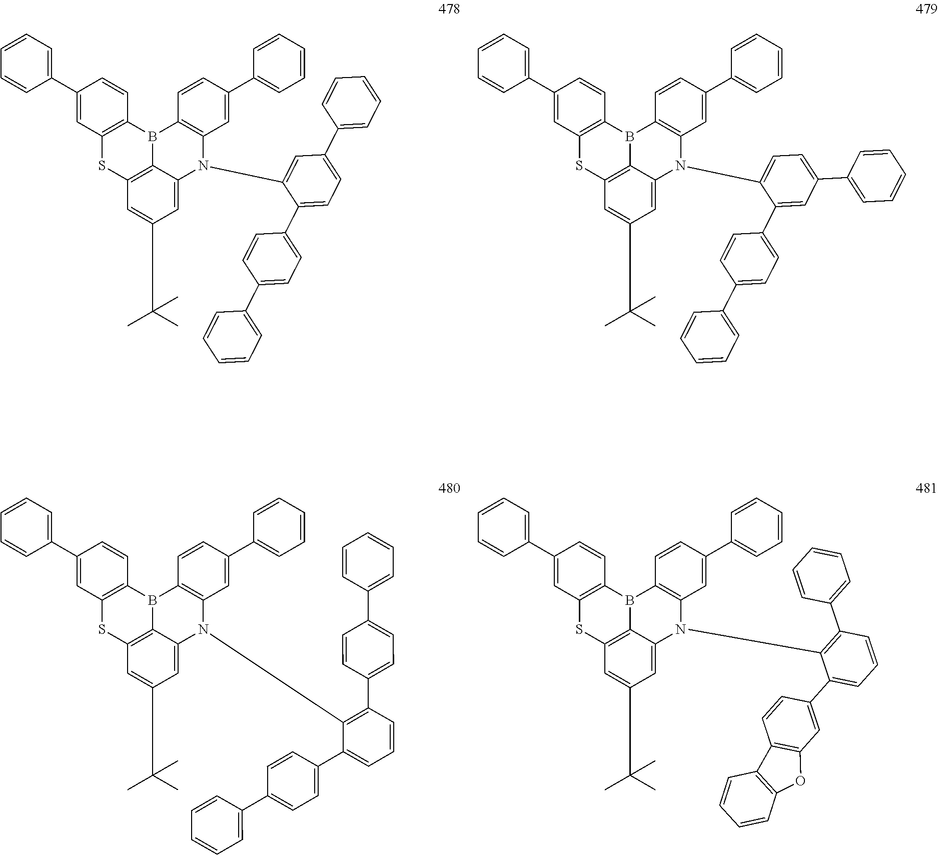 [SMILES: CC(C)(C)CCc1cc2c3c(c1)N(c1cc(-c4ccccc4)ccc1-c1ccc(-c4ccccc4)cc1)c1cc(-c4ccccc4)ccc1B3c1ccc(-c3ccccc3)cc1S2 ; CC(C)(C)CCc1cc2c3c(c1)N(c1ccc(-c4ccccc4)cc1-c1ccc(-c4ccccc4)cc1)c1cc(-c4ccccc4)ccc1B3c1ccc(-c3ccccc3)cc1S2 ; CC(C)(C)CCc1cc2c3c(c1)N(c1c(-c4ccc(-c5ccccc5)cc4)cccc1-c1ccc(-c4ccccc4)cc1)c1cc(-c4ccccc4)ccc1B3c1ccc(-c3ccccc3)cc1S2 ; CC(C)(C)CCc1cc2c3c(c1)N(c1c(-c4ccccc4)cccc1-c1ccc4c(c1)oc1ccccc14)c1cc(-c4ccccc4)ccc1B3c1ccc(-c3ccccc3)cc1S2]

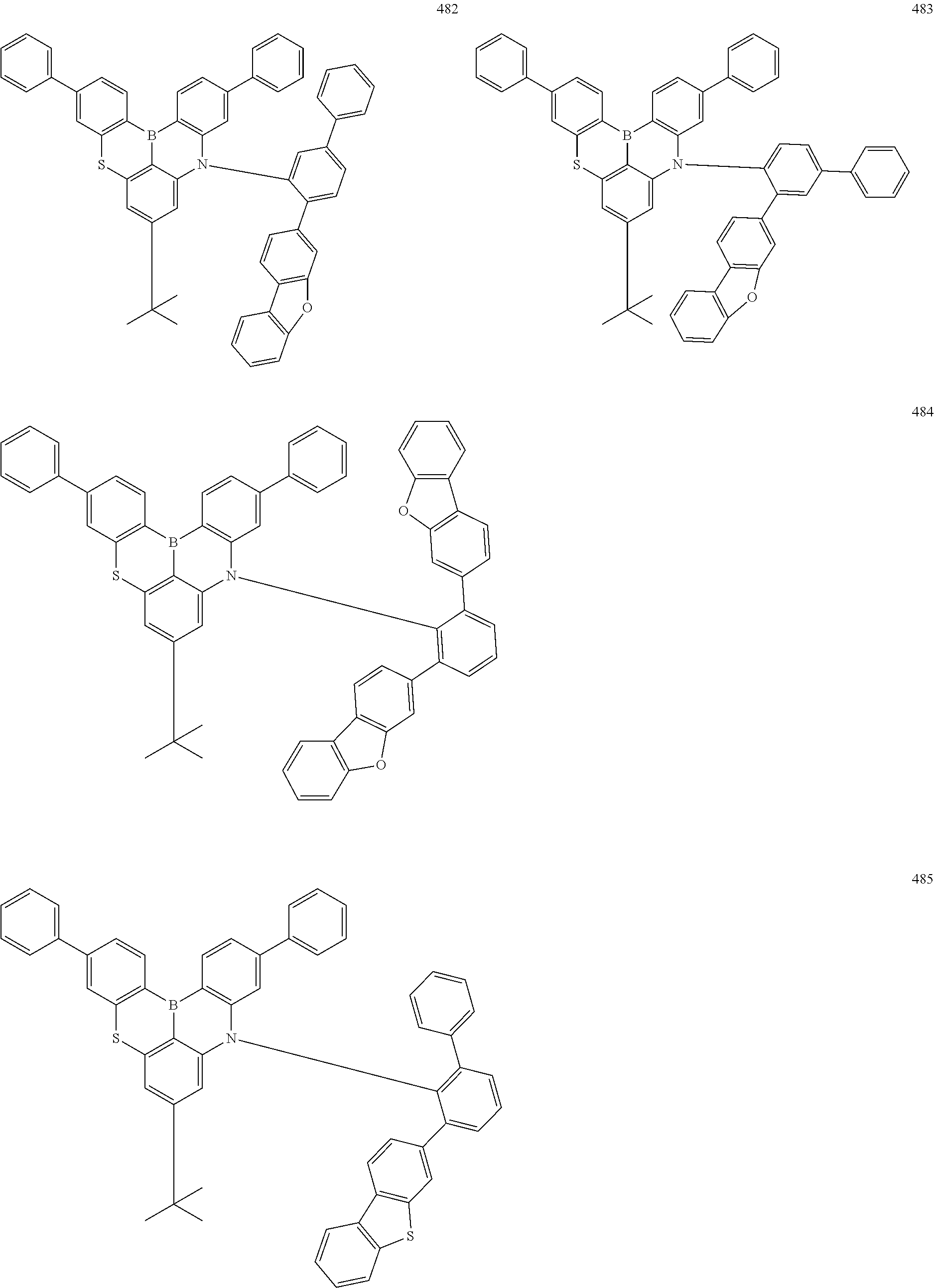 [SMILES: CC(C)(C)CCc1cc2c3c(c1)N(c1cc(-c4ccccc4)ccc1-c1ccc4c(c1)oc1ccccc14)c1cc(-c4ccccc4)ccc1B3c1ccc(-c3ccccc3)cc1S2 ; CC(C)(C)CCc1cc2c3c(c1)N(c1ccc(-c4ccccc4)cc1-c1ccc4c(c1)oc1ccccc14)c1cc(-c4ccccc4)ccc1B3c1ccc(-c3ccccc3)cc1S2 ; CC(C)(C)CCc1cc2c3c(c1)N(c1c(-c4ccc5c(c4)oc4ccccc45)cccc1-c1ccc4c(c1)oc1ccccc14)c1cc(-c4ccccc4)ccc1B3c1ccc(-c3ccccc3)cc1S2 ; CC(C)(C)CCc1cc2c3c(c1)N(c1c(-c4ccccc4)cccc1-c1ccc4c(c1)sc1ccccc14)c1cc(-c4ccccc4)ccc1B3c1ccc(-c3ccccc3)cc1S2]

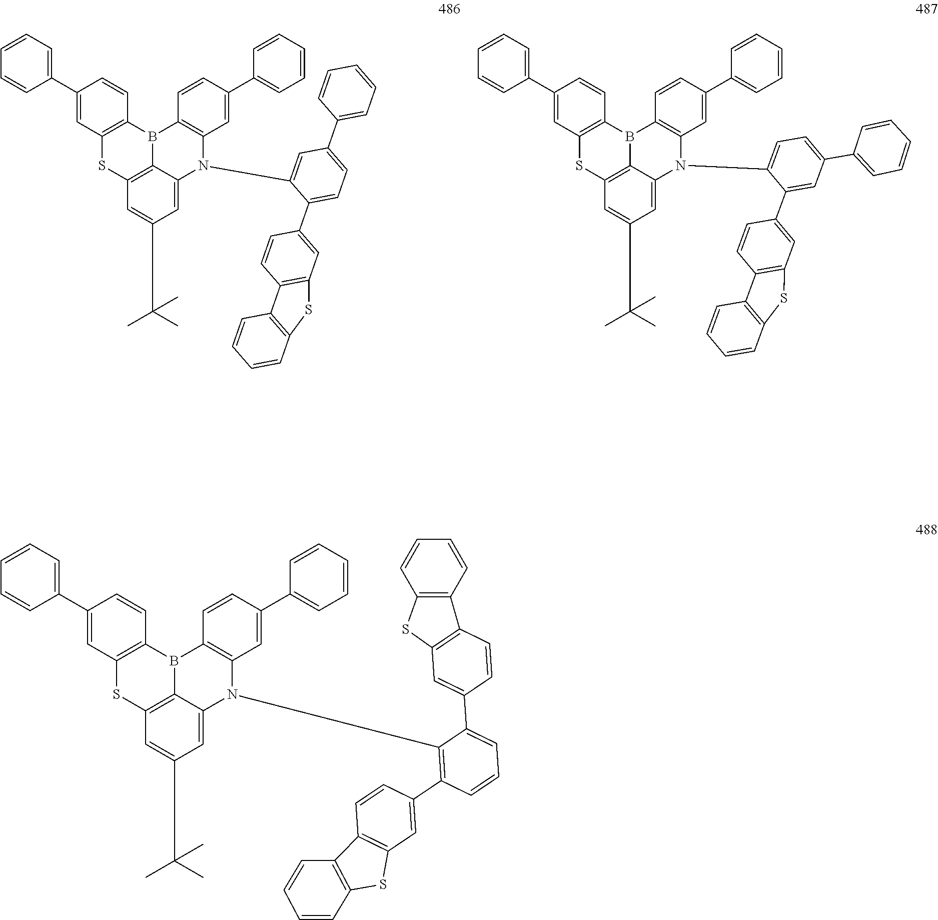 [SMILES: CC(C)(C)CCc1cc2c3c(c1)N(c1cc(-c4ccccc4)ccc1-c1ccc4c(c1)sc1ccccc14)c1cc(-c4ccccc4)ccc1B3c1ccc(-c3ccccc3)cc1S2 ; CC(C)(C)CCc1cc2c3c(c1)N(c1ccc(-c4ccccc4)cc1-c1ccc4c(c1)sc1ccccc14)c1cc(-c4ccccc4)ccc1B3c1ccc(-c3ccccc3)cc1S2 ; CC(C)(C)CCc1cc2c3c(c1)N(c1c(-c4ccc5c(c4)sc4ccccc45)cccc1-c1ccc4c(c1)sc1ccccc14)c1cc(-c4ccccc4)ccc1B3c1ccc(-c3ccccc3)cc1S2]

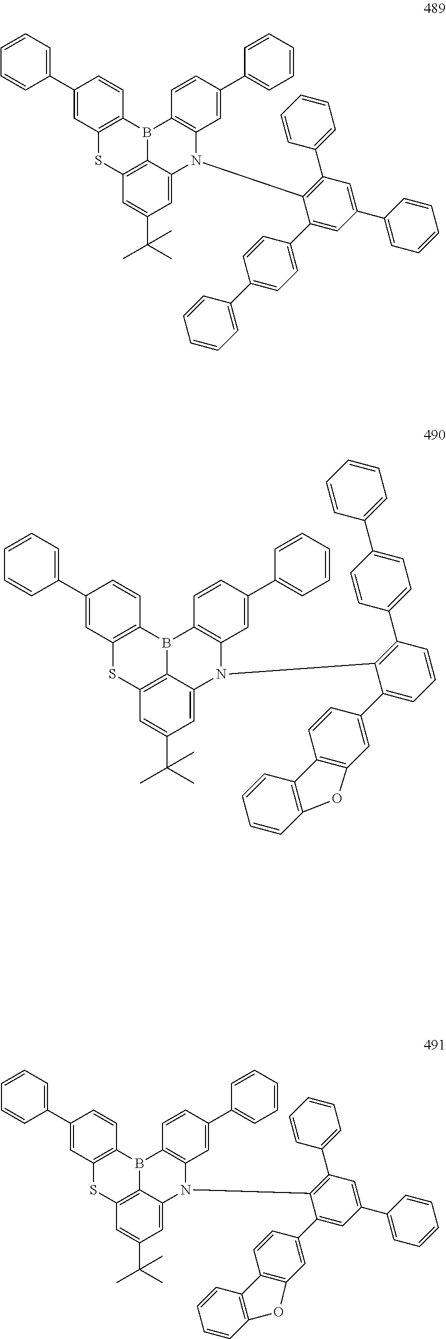 [SMILES: CC(C)(C)c1cc2c3c(c1)N(c1c(-c4ccccc4)cc(-c4ccccc4)cc1-c1ccc(-c4ccccc4)cc1)c1cc(-c4ccccc4)ccc1B3c1ccc(-c3ccccc3)cc1S2 ; CC(C)(C)c1cc2c3c(c1)N(c1c(-c4ccc(-c5ccccc5)cc4)cccc1-c1ccc4c(c1)oc1ccccc14)c1cc(-c4ccccc4)ccc1B3c1ccc(-c3ccccc3)cc1S2 ; CC(C)(C)c1cc2c3c(c1)N(c1c(-c4ccccc4)cc(-c4ccccc4)cc1-c1ccc4c(c1)oc1ccccc14)c1cc(-c4ccccc4)ccc1B3c1ccc(-c3ccccc3)cc1S2]

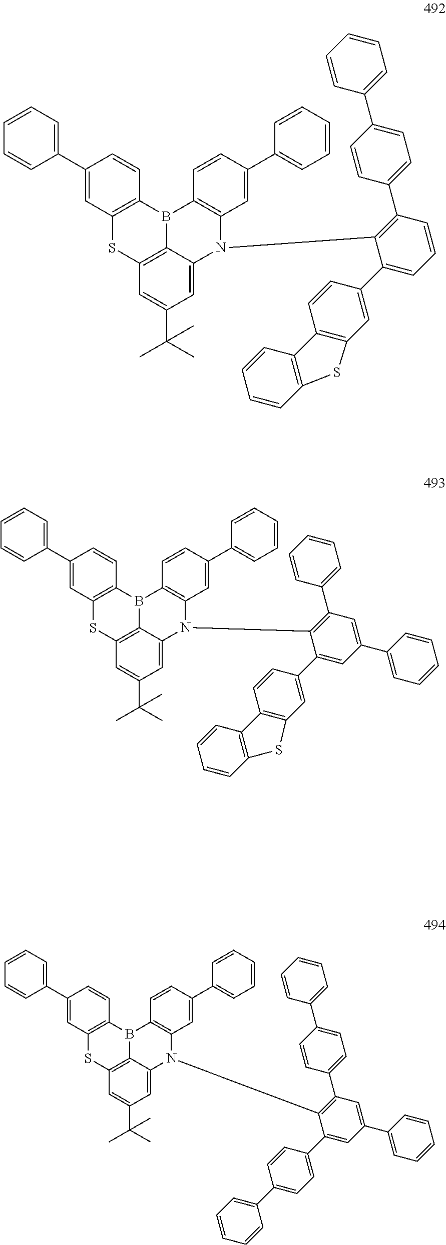 [SMILES: CC(C)(C)c1cc2c3c(c1)N(c1c(-c4ccc(-c5ccccc5)cc4)cccc1-c1ccc4c(c1)sc1ccccc14)c1cc(-c4ccccc4)ccc1B3c1ccc(-c3ccccc3)cc1S2 ; CC(C)(C)c1cc2c3c(c1)N(c1c(-c4ccccc4)cc(-c4ccccc4)cc1-c1ccc4c(c1)sc1ccccc14)c1cc(-c4ccccc4)ccc1B3c1ccc(-c3ccccc3)cc1S2 ; CC(C)(C)c1cc2c3c(c1)N(c1c(-c4ccc(-c5ccccc5)cc4)cc(-c4ccccc4)cc1-c1ccc(-c4ccccc4)cc1)c1cc(-c4ccccc4)ccc1B3c1ccc(-c3ccccc3)cc1S2]

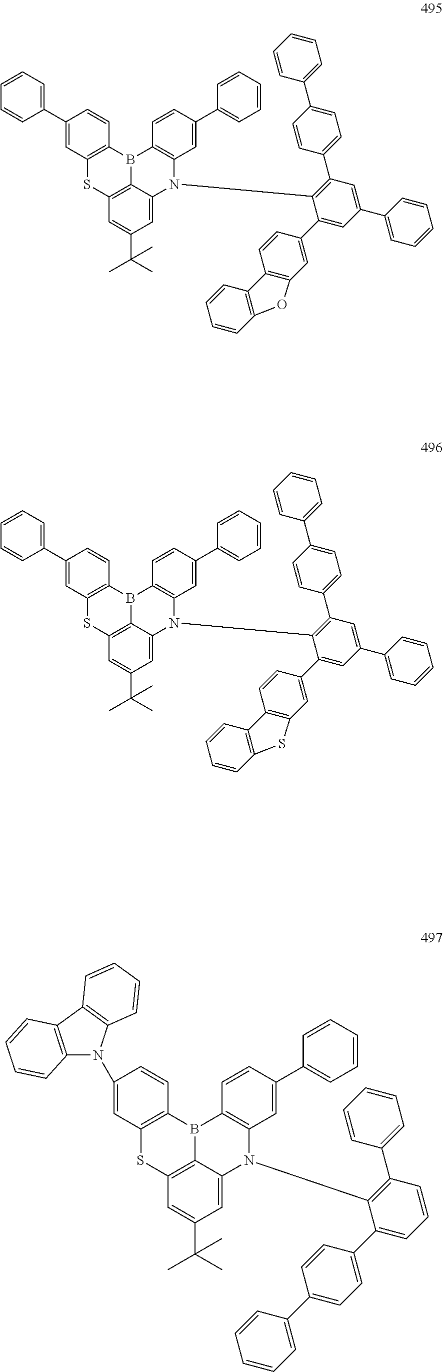 [SMILES: CC(C)(C)c1cc2c3c(c1)N(c1c(-c4ccc(-c5ccccc5)cc4)cc(-c4ccccc4)cc1-c1ccc4c(c1)oc1ccccc14)c1cc(-c4ccccc4)ccc1B3c1ccc(-c3ccccc3)cc1S2 ; CC(C)(C)c1cc2c3c(c1)N(c1c(-c4ccc(-c5ccccc5)cc4)cc(-c4ccccc4)cc1-c1ccc4c(c1)sc1ccccc14)c1cc(-c4ccccc4)ccc1B3c1ccc(-c3ccccc3)cc1S2 ; CC(C)(C)c1cc2c3c(c1)N(c1c(-c4ccccc4)cccc1-c1ccc(-c4ccccc4)cc1)c1cc(-c4ccccc4)ccc1B3c1ccc(-n3c4ccccc4c4ccccc43)cc1S2]

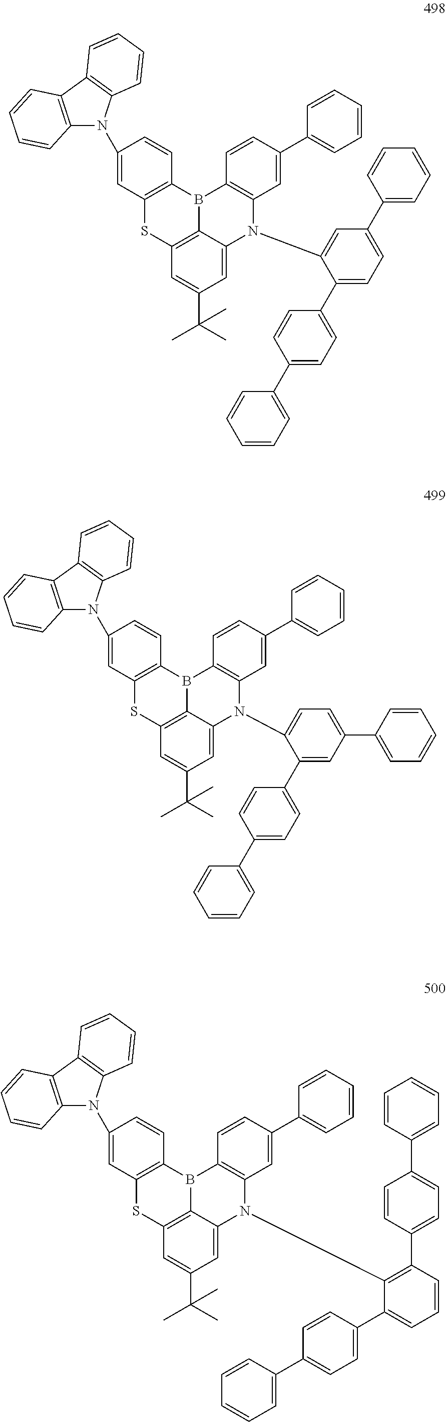 [SMILES: CC(C)(C)c1cc2c3c(c1)N(c1cc(-c4ccccc4)ccc1-c1ccc(-c4ccccc4)cc1)c1cc(-c4ccccc4)ccc1B3c1ccc(-n3c4ccccc4c4ccccc43)cc1S2 ; CC(C)(C)c1cc2c3c(c1)N(c1ccc(-c4ccccc4)cc1-c1ccc(-c4ccccc4)cc1)c1cc(-c4ccccc4)ccc1B3c1ccc(-n3c4ccccc4c4ccccc43)cc1S2 ; CC(C)(C)c1cc2c3c(c1)N(c1c(-c4ccc(-c5ccccc5)cc4)cccc1-c1ccc(-c4ccccc4)cc1)c1cc(-c4ccccc4)ccc1B3c1ccc(-n3c4ccccc4c4ccccc43)cc1S2]

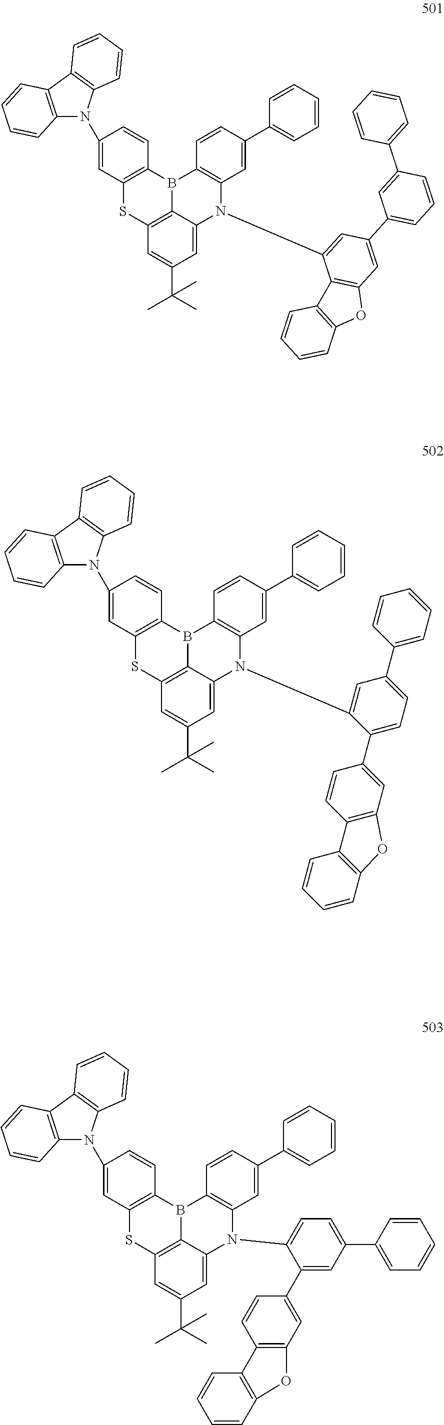 [SMILES: CC(C)(C)c1cc2c3c(c1)N(c1cc(-c4cccc(-c5ccccc5)c4)cc4oc5ccccc5c14)c1cc(-c4ccccc4)ccc1B3c1ccc(-n3c4ccccc4c4ccccc43)cc1S2 ; CC(C)(C)c1cc2c3c(c1)N(c1cc(-c4ccccc4)ccc1-c1ccc4c(c1)oc1ccccc14)c1cc(-c4ccccc4)ccc1B3c1ccc(-n3c4ccccc4c4ccccc43)cc1S2 ; CC(C)(C)c1cc2c3c(c1)N(c1ccc(-c4ccccc4)cc1-c1ccc4c(c1)oc1ccccc14)c1cc(-c4ccccc4)ccc1B3c1ccc(-n3c4ccccc4c4ccccc43)cc1S2]

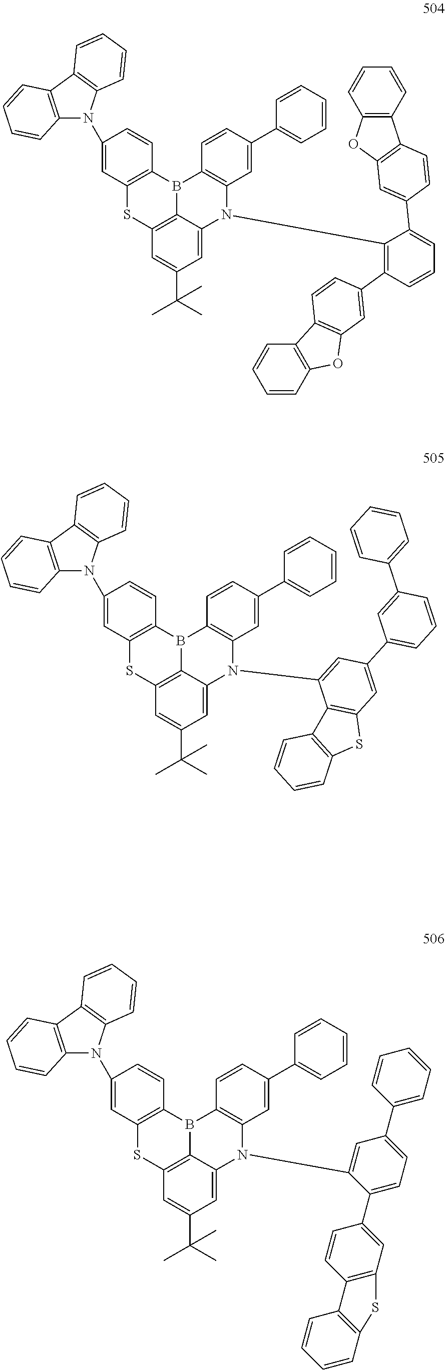 [SMILES: CC(C)(C)c1cc2c3c(c1)N(c1c(-c4ccc5c(c4)oc4ccccc45)cccc1-c1ccc4c(c1)oc1ccccc14)c1cc(-c4ccccc4)ccc1B3c1ccc(-n3c4ccccc4c4ccccc43)cc1S2 ; CC(C)(C)c1cc2c3c(c1)N(c1cc(-c4cccc(-c5ccccc5)c4)cc4sc5ccccc5c14)c1cc(-c4ccccc4)ccc1B3c1ccc(-n3c4ccccc4c4ccccc43)cc1S2 ; CC(C)(C)c1cc2c3c(c1)N(c1cc(-c4ccccc4)ccc1-c1ccc4c(c1)sc1ccccc14)c1cc(-c4ccccc4)ccc1B3c1ccc(-n3c4ccccc4c4ccccc43)cc1S2]

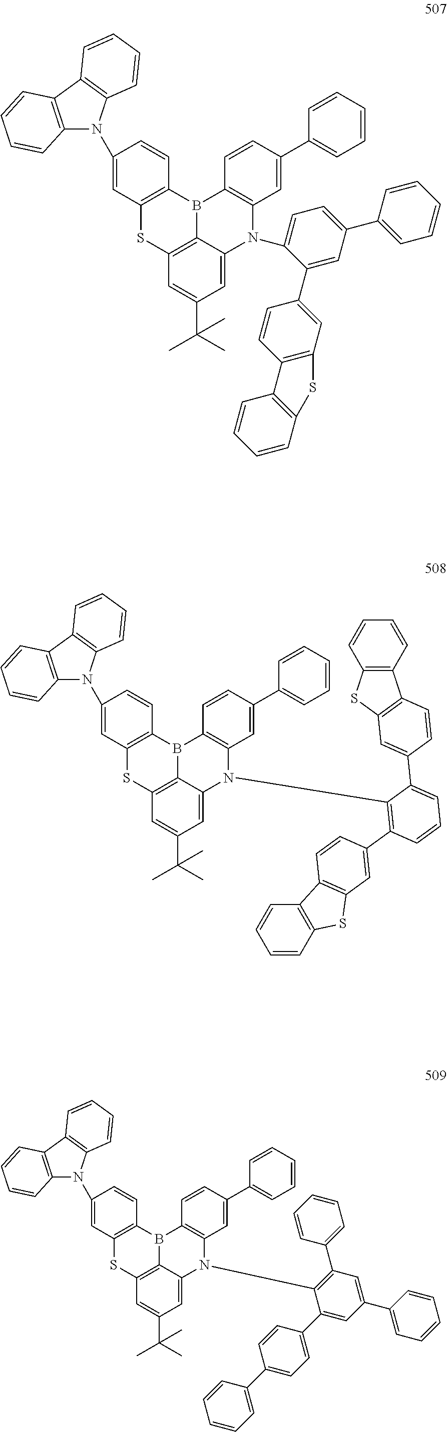 [SMILES: CC(C)(C)c1cc2c3c(c1)N(c1ccc(-c4ccccc4)cc1-c1ccc4c(c1)sc1ccccc14)c1cc(-c4ccccc4)ccc1B3c1ccc(-n3c4ccccc4c4ccccc43)cc1S2 ; CC(C)(C)c1cc2c3c(c1)N(c1c(-c4ccc5c(c4)sc4ccccc45)cccc1-c1ccc4c(c1)sc1ccccc14)c1cc(-c4ccccc4)ccc1B3c1ccc(-n3c4ccccc4c4ccccc43)cc1S2 ; CC(C)(C)c1cc2c3c(c1)N(c1c(-c4ccccc4)cc(-c4ccccc4)cc1-c1ccc(-c4ccccc4)cc1)c1cc(-c4ccccc4)ccc1B3c1ccc(-n3c4ccccc4c4ccccc43)cc1S2]

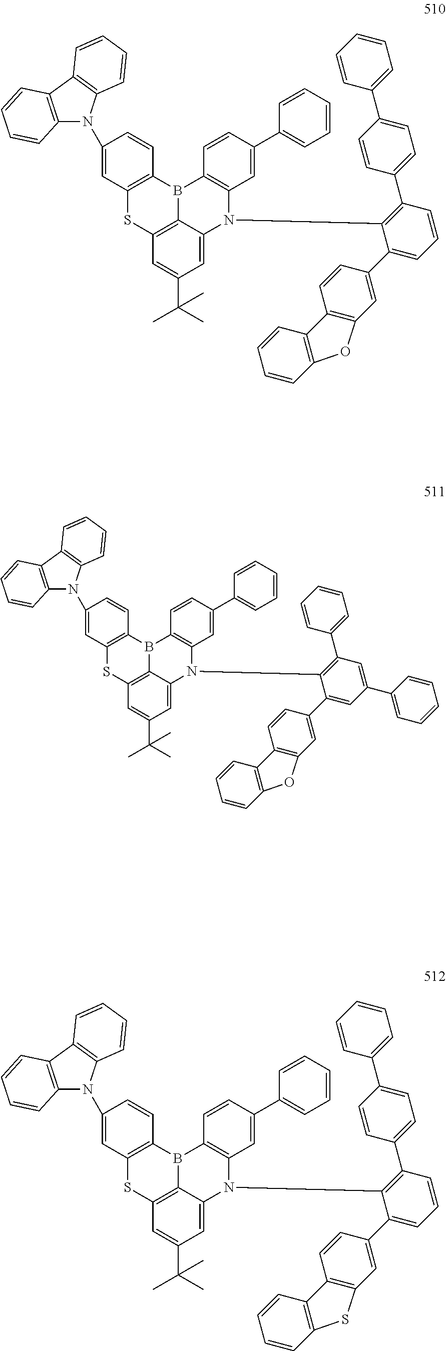 [SMILES: CC(C)(C)c1cc2c3c(c1)N(c1c(-c4ccc(-c5ccccc5)cc4)cccc1-c1ccc4c(c1)oc1ccccc14)c1cc(-c4ccccc4)ccc1B3c1ccc(-n3c4ccccc4c4ccccc43)cc1S2 ; CC(C)(C)c1cc2c3c(c1)N(c1c(-c4ccccc4)cc(-c4ccccc4)cc1-c1ccc4c(c1)oc1ccccc14)c1cc(-c4ccccc4)ccc1B3c1ccc(-n3c4ccccc4c4ccccc43)cc1S2 ; CC(C)(C)c1cc2c3c(c1)N(c1c(-c4ccc(-c5ccccc5)cc4)cccc1-c1ccc4c(c1)sc1ccccc14)c1cc(-c4ccccc4)ccc1B3c1ccc(-n3c4ccccc4c4ccccc43)cc1S2]

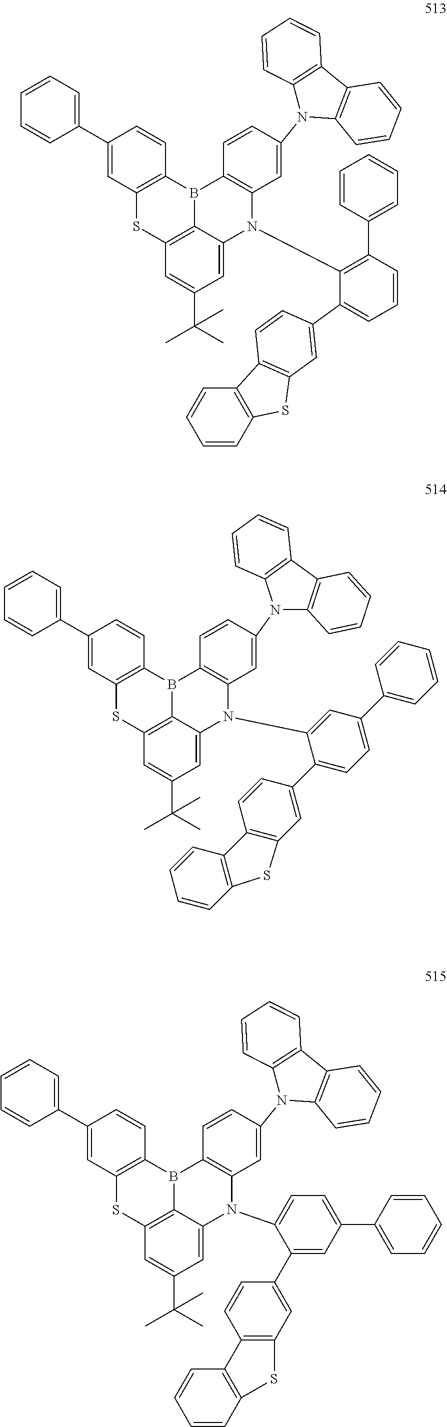 [SMILES: CC(C)(C)c1cc2c3c(c1)N(c1c(-c4ccccc4)cccc1-c1ccc4c(c1)sc1ccccc14)c1cc(-n4c5ccccc5c5ccccc54)ccc1B3c1ccc(-c3ccccc3)cc1S2 ; CC(C)(C)c1cc2c3c(c1)N(c1cc(-c4ccccc4)ccc1-c1ccc4c(c1)sc1ccccc14)c1cc(-n4c5ccccc5c5ccccc54)ccc1B3c1ccc(-c3ccccc3)cc1S2 ; CC(C)(C)c1cc2c3c(c1)N(c1ccc(-c4ccccc4)cc1-c1ccc4c(c1)sc1ccccc14)c1cc(-n4c5ccccc5c5ccccc54)ccc1B3c1ccc(-c3ccccc3)cc1S2]

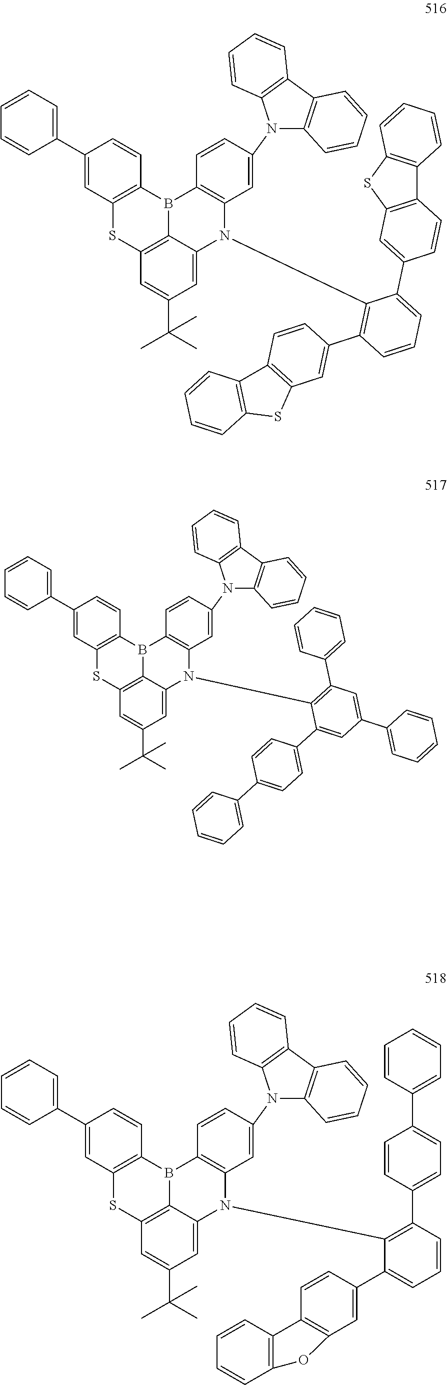 [SMILES: CC(C)(C)c1cc2c3c(c1)N(c1c(-c4ccc5c(c4)sc4ccccc45)cccc1-c1ccc4c(c1)sc1ccccc14)c1cc(-n4c5ccccc5c5ccccc54)ccc1B3c1ccc(-c3ccccc3)cc1S2 ; CC(C)(C)c1cc2c3c(c1)N(c1c(-c4ccccc4)cc(-c4ccccc4)cc1-c1ccc(-c4ccccc4)cc1)c1cc(-n4c5ccccc5c5ccccc54)ccc1B3c1ccc(-c3ccccc3)cc1S2 ; CC(C)(C)c1cc2c3c(c1)N(c1c(-c4ccc(-c5ccccc5)cc4)cccc1-c1ccc4c(c1)oc1ccccc14)c1cc(-n4c5ccccc5c5ccccc54)ccc1B3c1ccc(-c3ccccc3)cc1S2]

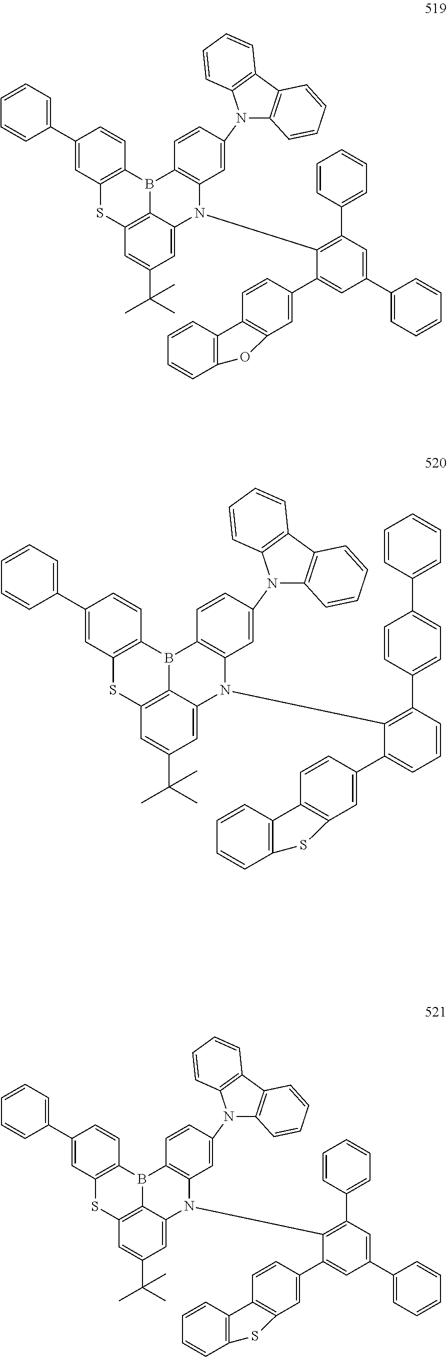 [SMILES: CC(C)(C)c1cc2c3c(c1)N(c1c(-c4ccccc4)cc(-c4ccccc4)cc1-c1ccc4c(c1)oc1ccccc14)c1cc(-n4c5ccccc5c5ccccc54)ccc1B3c1ccc(-c3ccccc3)cc1S2 ; CC(C)(C)c1cc2c3c(c1)N(c1c(-c4ccc(-c5ccccc5)cc4)cccc1-c1ccc4c(c1)sc1ccccc14)c1cc(-n4c5ccccc5c5ccccc54)ccc1B3c1ccc(-c3ccccc3)cc1S2 ; CC(C)(C)c1cc2c3c(c1)N(c1c(-c4ccccc4)cc(-c4ccccc4)cc1-c1ccc4c(c1)sc1ccccc14)c1cc(-n4c5ccccc5c5ccccc54)ccc1B3c1ccc(-c3ccccc3)cc1S2]

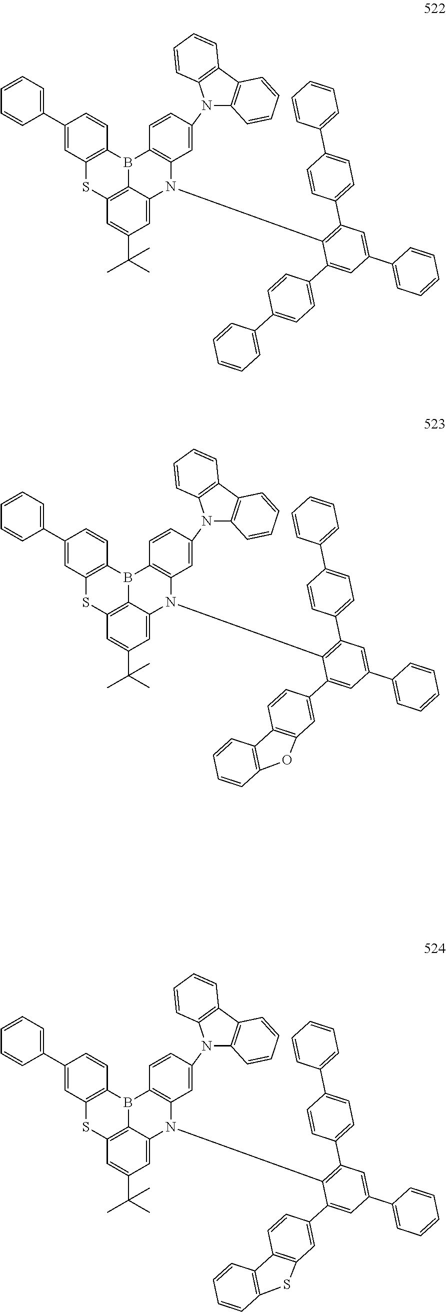 [SMILES: CC(C)(C)c1cc2c3c(c1)N(c1c(-c4ccc(-c5ccccc5)cc4)cc(-c4ccccc4)cc1-c1ccc(-c4ccccc4)cc1)c1cc(-n4c5ccccc5c5ccccc54)ccc1B3c1ccc(-c3ccccc3)cc1S2 ; CC(C)(C)c1cc2c3c(c1)N(c1c(-c4ccc(-c5ccccc5)cc4)cc(-c4ccccc4)cc1-c1ccc4c(c1)oc1ccccc14)c1cc(-n4c5ccccc5c5ccccc54)ccc1B3c1ccc(-c3ccccc3)cc1S2 ; CC(C)(C)c1cc2c3c(c1)N(c1c(-c4ccc(-c5ccccc5)cc4)cc(-c4ccccc4)cc1-c1ccc4c(c1)sc1ccccc14)c1cc(-n4c5ccccc5c5ccccc54)ccc1B3c1ccc(-c3ccccc3)cc1S2]

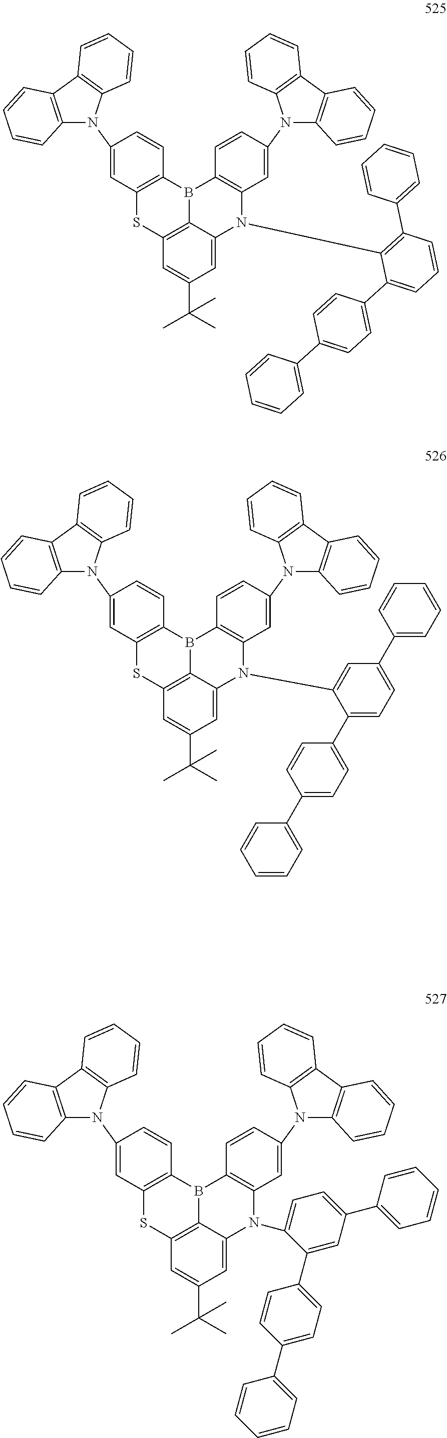 [SMILES: CC(C)(C)c1cc2c3c(c1)N(c1c(-c4ccccc4)cccc1-c1ccc(-c4ccccc4)cc1)c1cc(-n4c5ccccc5c5ccccc54)ccc1B3c1ccc(-n3c4ccccc4c4ccccc43)cc1S2 ; CC(C)(C)c1cc2c3c(c1)N(c1cc(-c4ccccc4)ccc1-c1ccc(-c4ccccc4)cc1)c1cc(-n4c5ccccc5c5ccccc54)ccc1B3c1ccc(-n3c4ccccc4c4ccccc43)cc1S2 ; CC(C)(C)c1cc2c3c(c1)N(c1ccc(-c4ccccc4)cc1-c1ccc(-c4ccccc4)cc1)c1cc(-n4c5ccccc5c5ccccc54)ccc1B3c1ccc(-n3c4ccccc4c4ccccc43)cc1S2]

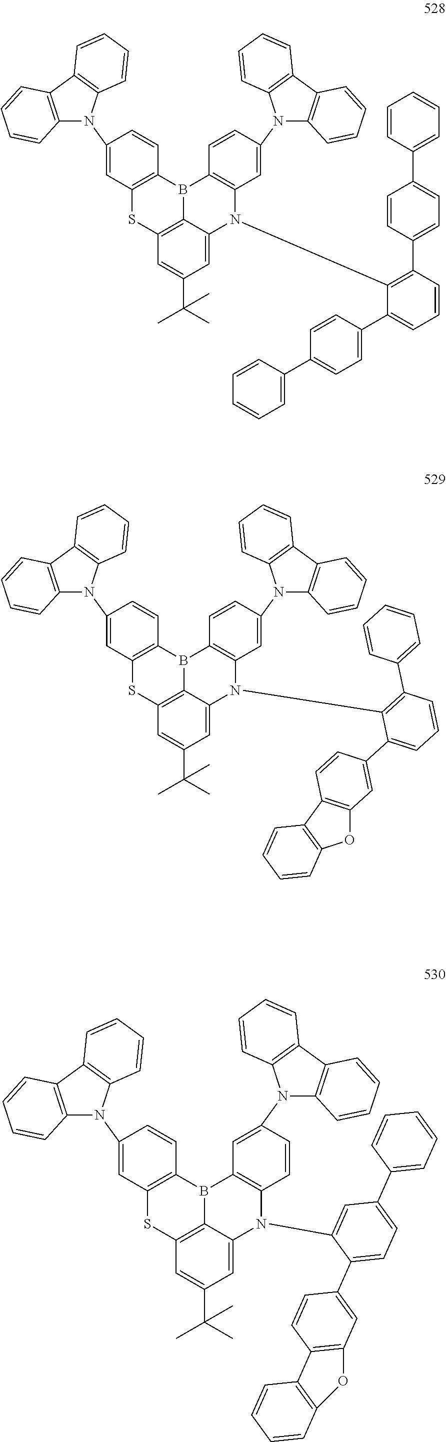 [SMILES: CC(C)(C)c1cc2c3c(c1)N(c1c(-c4ccc(-c5ccccc5)cc4)cccc1-c1ccc(-c4ccccc4)cc1)c1cc(-n4c5ccccc5c5ccccc54)ccc1B3c1ccc(-n3c4ccccc4c4ccccc43)cc1S2 ; CC(C)(C)c1cc2c3c(c1)N(c1c(-c4ccccc4)cccc1-c1ccc4c(c1)oc1ccccc14)c1cc(-n4c5ccccc5c5ccccc54)ccc1B3c1ccc(-n3c4ccccc4c4ccccc43)cc1S2 ; CC(C)(C)c1cc2c3c(c1)N(c1cc(-c4ccccc4)ccc1-c1ccc4c(c1)oc1ccccc14)c1ccc(-n4c5ccccc5c5ccccc54)cc1B3c1ccc(-n3c4ccccc4c4ccccc43)cc1S2]

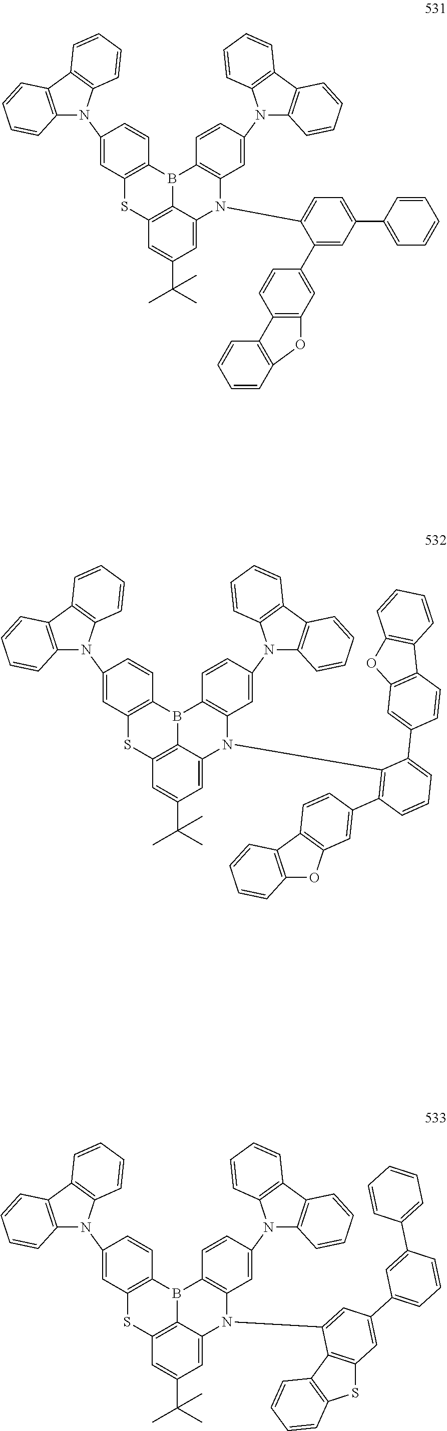 [SMILES: CC(C)(C)c1cc2c3c(c1)N(c1ccc(-c4ccccc4)cc1-c1ccc4c(c1)oc1ccccc14)c1cc(-n4c5ccccc5c5ccccc54)ccc1B3c1ccc(-n3c4ccccc4c4ccccc43)cc1S2 ; CC(C)(C)c1cc2c3c(c1)N(c1c(-c4ccc5c(c4)oc4ccccc45)cccc1-c1ccc4c(c1)oc1ccccc14)c1cc(-n4c5ccccc5c5ccccc54)ccc1B3c1ccc(-n3c4ccccc4c4ccccc43)cc1S2 ; CC(C)(C)c1cc2c3c(c1)N(c1cc(-c4cccc(-c5ccccc5)c4)cc4sc5ccccc5c14)c1cc(-n4c5ccccc5c5ccccc54)ccc1B3c1ccc(-n3c4ccccc4c4ccccc43)cc1S2]

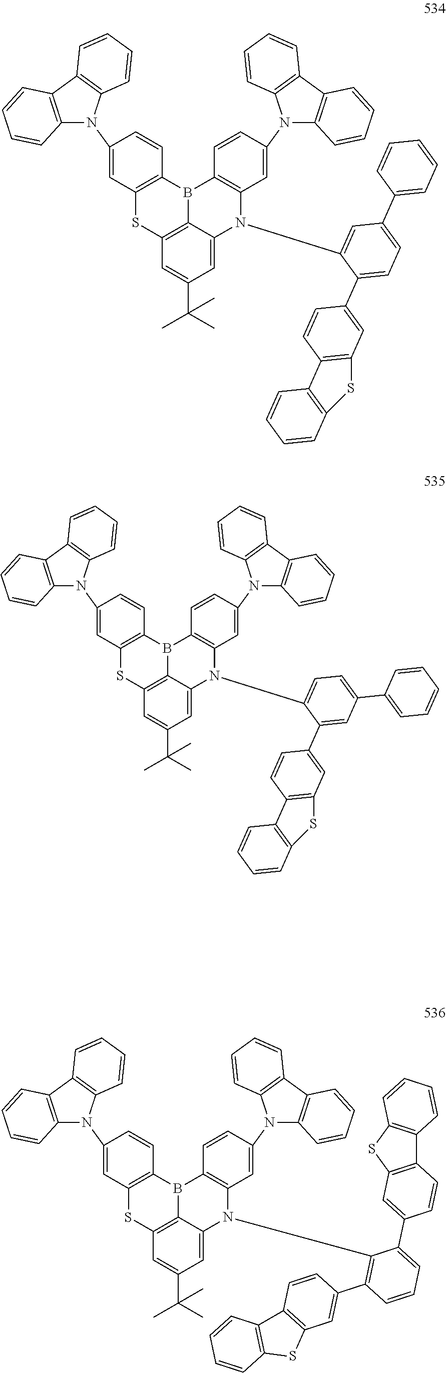 [SMILES: CC(C)(C)c1cc2c3c(c1)N(c1cc(-c4ccccc4)ccc1-c1ccc4c(c1)sc1ccccc14)c1cc(-n4c5ccccc5c5ccccc54)ccc1B3c1ccc(-n3c4ccccc4c4ccccc43)cc1S2 ; CC(C)(C)c1cc2c3c(c1)N(c1ccc(-c4ccccc4)cc1-c1ccc4c(c1)sc1ccccc14)c1cc(-n4c5ccccc5c5ccccc54)ccc1B3c1ccc(-n3c4ccccc4c4ccccc43)cc1S2 ; CC(C)(C)c1cc2c3c(c1)N(c1c(-c4ccc5c(c4)sc4ccccc45)cccc1-c1ccc4c(c1)sc1ccccc14)c1cc(-n4c5ccccc5c5ccccc54)ccc1B3c1ccc(-n3c4ccccc4c4ccccc43)cc1S2]

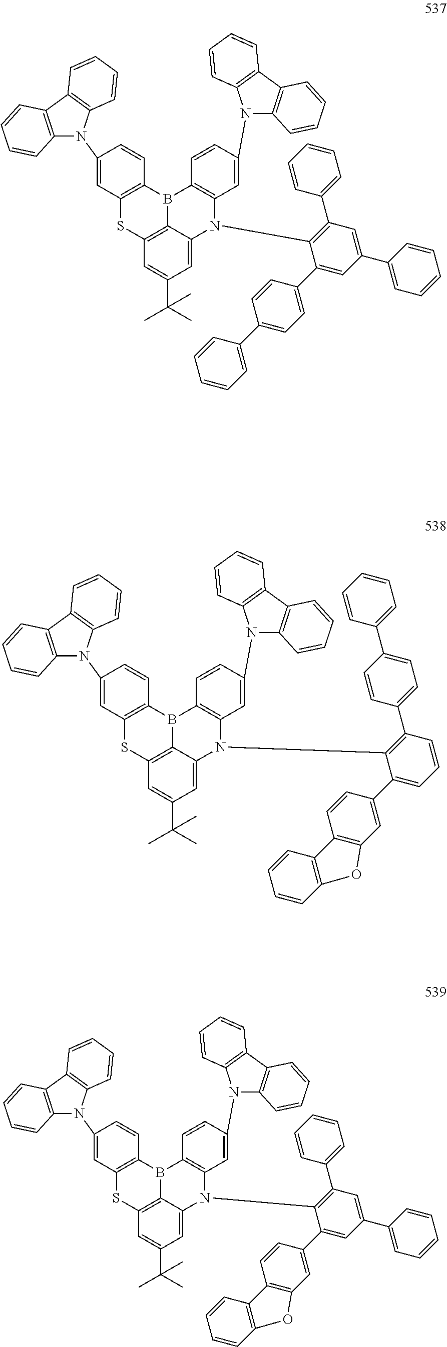 [SMILES: CC(C)(C)c1cc2c3c(c1)N(c1c(-c4ccccc4)cc(-c4ccccc4)cc1-c1ccc(-c4ccccc4)cc1)c1cc(-n4c5ccccc5c5ccccc54)ccc1B3c1ccc(-n3c4ccccc4c4ccccc43)cc1S2 ; CC(C)(C)c1cc2c3c(c1)N(c1c(-c4ccc(-c5ccccc5)cc4)cccc1-c1ccc4c(c1)oc1ccccc14)c1cc(-n4c5ccccc5c5ccccc54)ccc1B3c1ccc(-n3c4ccccc4c4ccccc43)cc1S2 ; CC(C)(C)c1cc2c3c(c1)N(c1c(-c4ccccc4)cc(-c4ccccc4)cc1-c1ccc4c(c1)oc1ccccc14)c1cc(-n4c5ccccc5c5ccccc54)ccc1B3c1ccc(-n3c4ccccc4c4ccccc43)cc1S2]

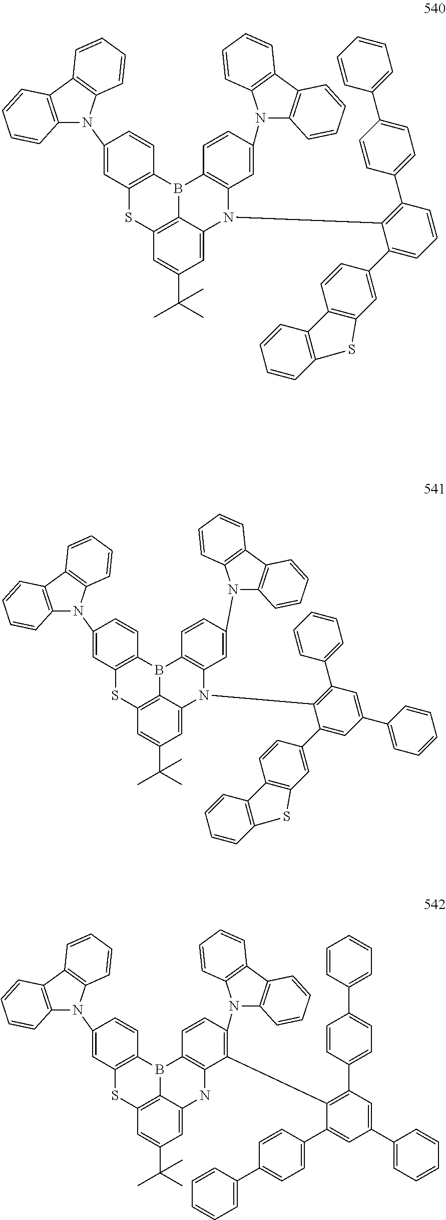 [SMILES: CC(C)(C)c1cc2c3c(c1)N(c1c(-c4ccc(-c5ccccc5)cc4)cccc1-c1ccc4c(c1)sc1ccccc14)c1cc(-n4c5ccccc5c5ccccc54)ccc1B3c1ccc(-n3c4ccccc4c4ccccc43)cc1S2 ; CC(C)(C)c1cc2c3c(c1)N(c1c(-c4ccccc4)cc(-c4ccccc4)cc1-c1ccc4c(c1)sc1ccccc14)c1cc(-n4c5ccccc5c5ccccc54)ccc1B3c1ccc(-n3c4ccccc4c4ccccc43)cc1S2 ; CC(C)(C)c1cc2c3c(c1)Sc1cc(-n4c5ccccc5c5ccccc54)ccc1B3c1ccc(-n3c4ccccc4c4ccccc43)c(-c3c(-c4ccc(-c5ccccc5)cc4)cc(-c4ccccc4)cc3-c3ccc(-c4ccccc4)cc3)c1N2]

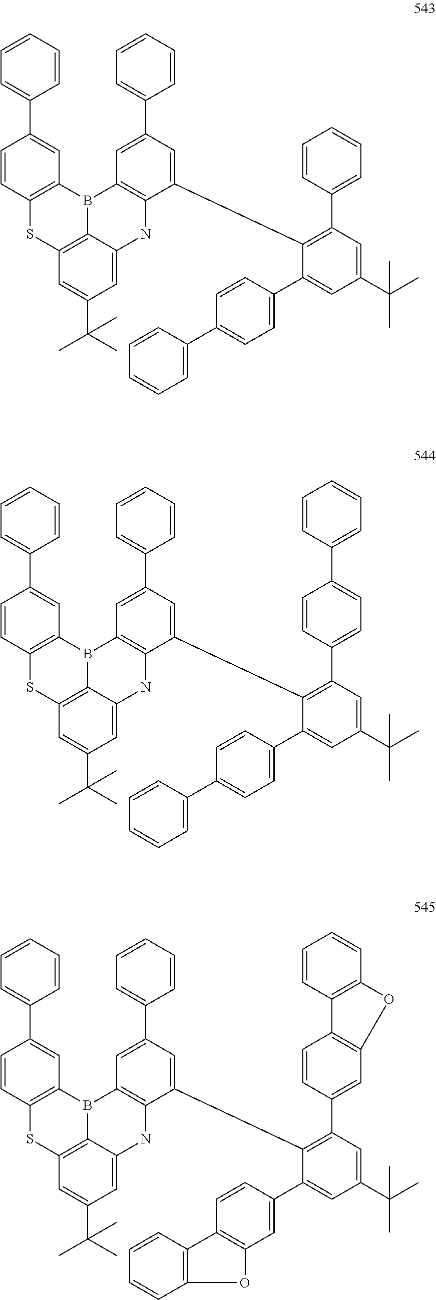 [SMILES: CC(C)(C)c1cc2c3c(c1)Sc1ccc(-c4ccccc4)cc1B3c1cc(-c3ccccc3)cc(-c3c(-c4ccccc4)cc(C(C)(C)C)cc3-c3ccc(-c4ccccc4)cc3)c1N2 ; CC(C)(C)c1cc2c3c(c1)Sc1ccc(-c4ccccc4)cc1B3c1cc(-c3ccccc3)cc(-c3c(-c4ccc(-c5ccccc5)cc4)cc(C(C)(C)C)cc3-c3ccc(-c4ccccc4)cc3)c1N2 ; CC(C)(C)c1cc2c3c(c1)Sc1ccc(-c4ccccc4)cc1B3c1cc(-c3ccccc3)cc(-c3c(-c4ccc5c(c4)oc4ccccc45)cc(C(C)(C)C)cc3-c3ccc4c(c3)oc3ccccc34)c1N2]

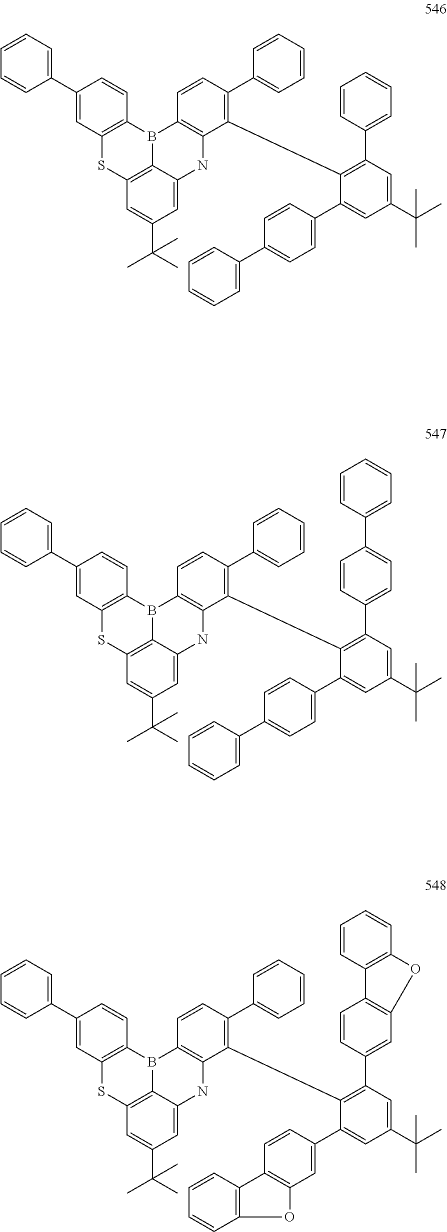 [SMILES: CC(C)(C)c1cc2c3c(c1)Sc1cc(-c4ccccc4)ccc1B3c1ccc(-c3ccccc3)c(-c3c(-c4ccccc4)cc(C(C)(C)C)cc3-c3ccc(-c4ccccc4)cc3)c1N2 ; CC(C)(C)c1cc2c3c(c1)Sc1cc(-c4ccccc4)ccc1B3c1ccc(-c3ccccc3)c(-c3c(-c4ccc(-c5ccccc5)cc4)cc(C(C)(C)C)cc3-c3ccc(-c4ccccc4)cc3)c1N2 ; CC(C)(C)c1cc2c3c(c1)Sc1cc(-c4ccccc4)ccc1B3c1ccc(-c3ccccc3)c(-c3c(-c4ccc5c(c4)oc4ccccc45)cc(C(C)(C)C)cc3-c3ccc4c(c3)oc3ccccc34)c1N2]

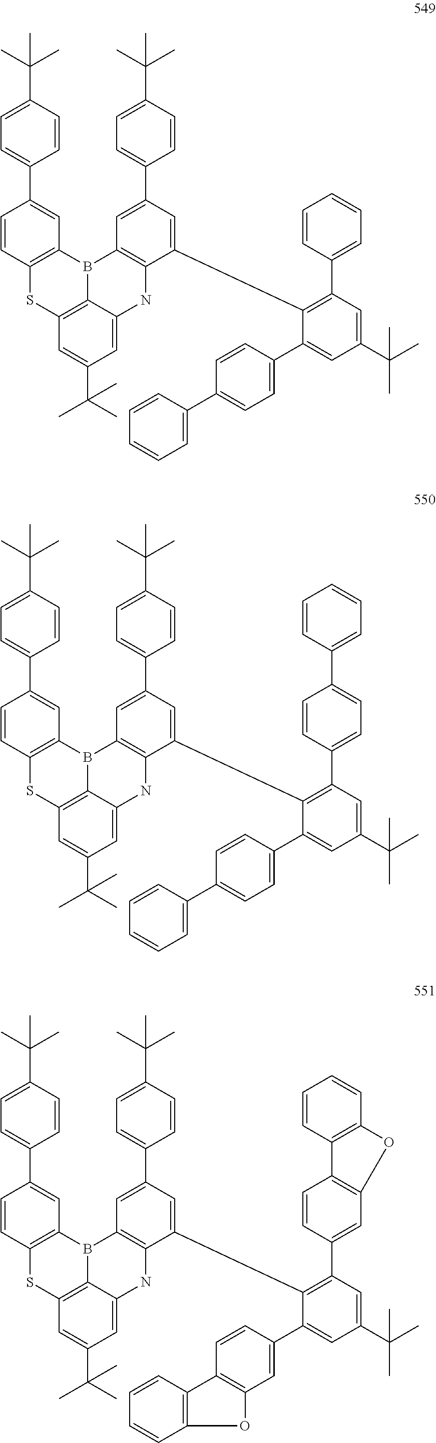 [SMILES: CC(C)(C)c1ccc(-c2ccc3c(c2)B2c4cc(-c5ccc(C(C)(C)C)cc5)cc(-c5c(-c6ccccc6)cc(C(C)(C)C)cc5-c5ccc(-c6ccccc6)cc5)c4Nc4cc(C(C)(C)C)cc(c42)S3)cc1 ; CC(C)(C)c1ccc(-c2ccc3c(c2)B2c4cc(-c5ccc(C(C)(C)C)cc5)cc(-c5c(-c6ccc(-c7ccccc7)cc6)cc(C(C)(C)C)cc5-c5ccc(-c6ccccc6)cc5)c4Nc4cc(C(C)(C)C)cc(c42)S3)cc1 ; CC(C)(C)c1ccc(-c2ccc3c(c2)B2c4cc(-c5ccc(C(C)(C)C)cc5)cc(-c5c(-c6ccc7c(c6)oc6ccccc67)cc(C(C)(C)C)cc5-c5ccc6c(c5)oc5ccccc56)c4Nc4cc(C(C)(C)C)cc(c42)S3)cc1]

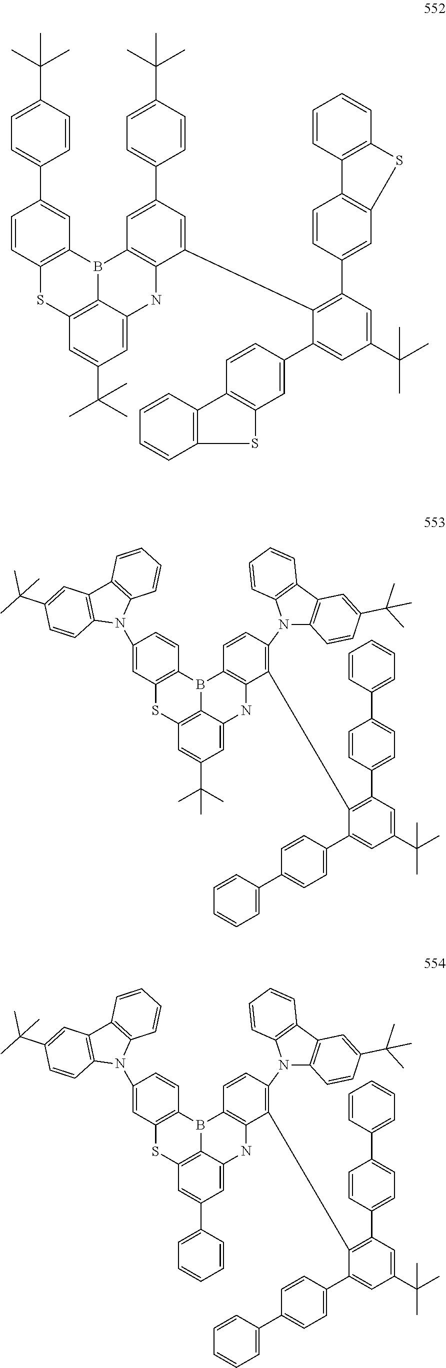

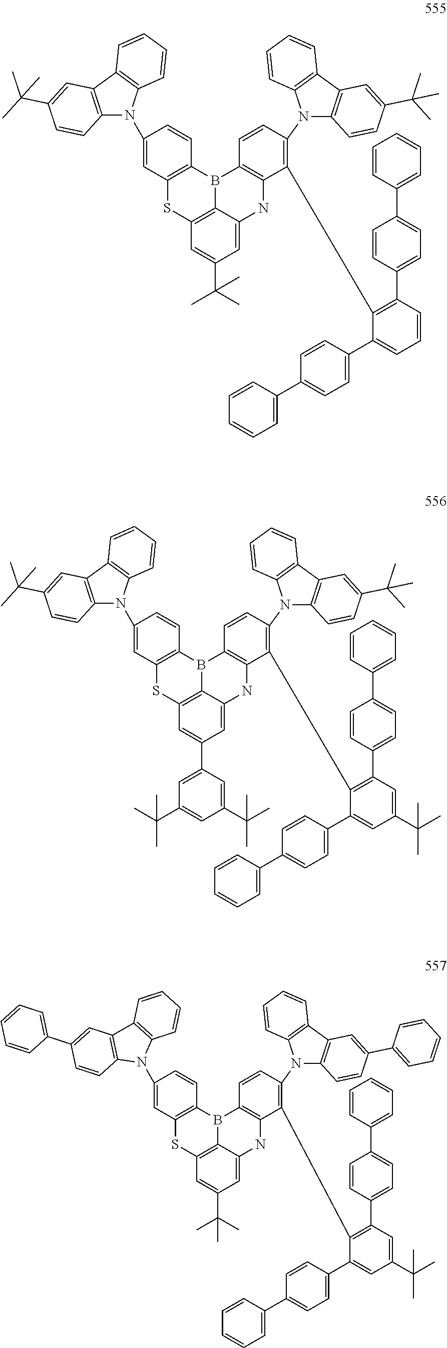

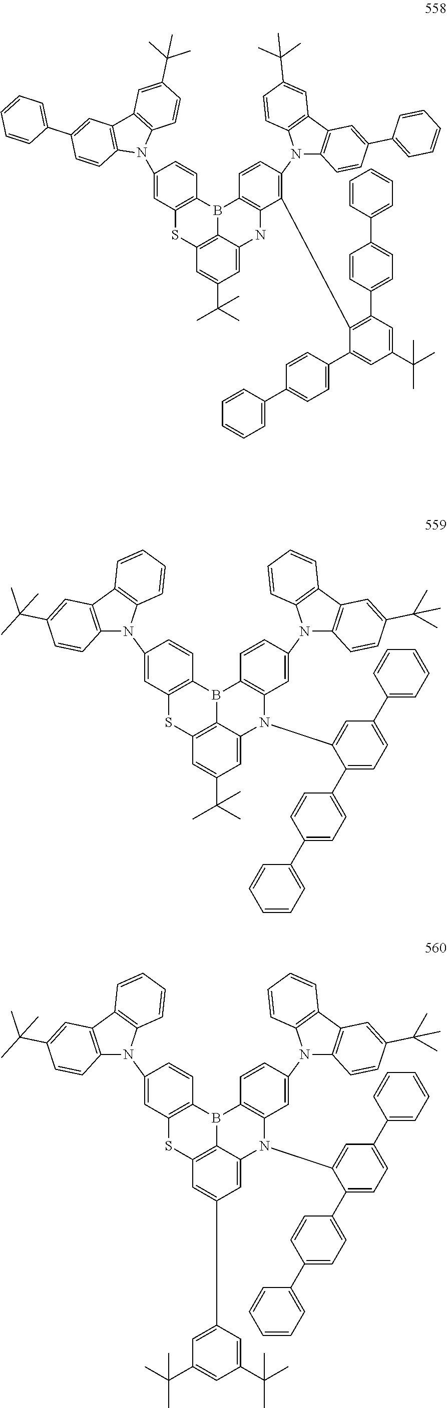

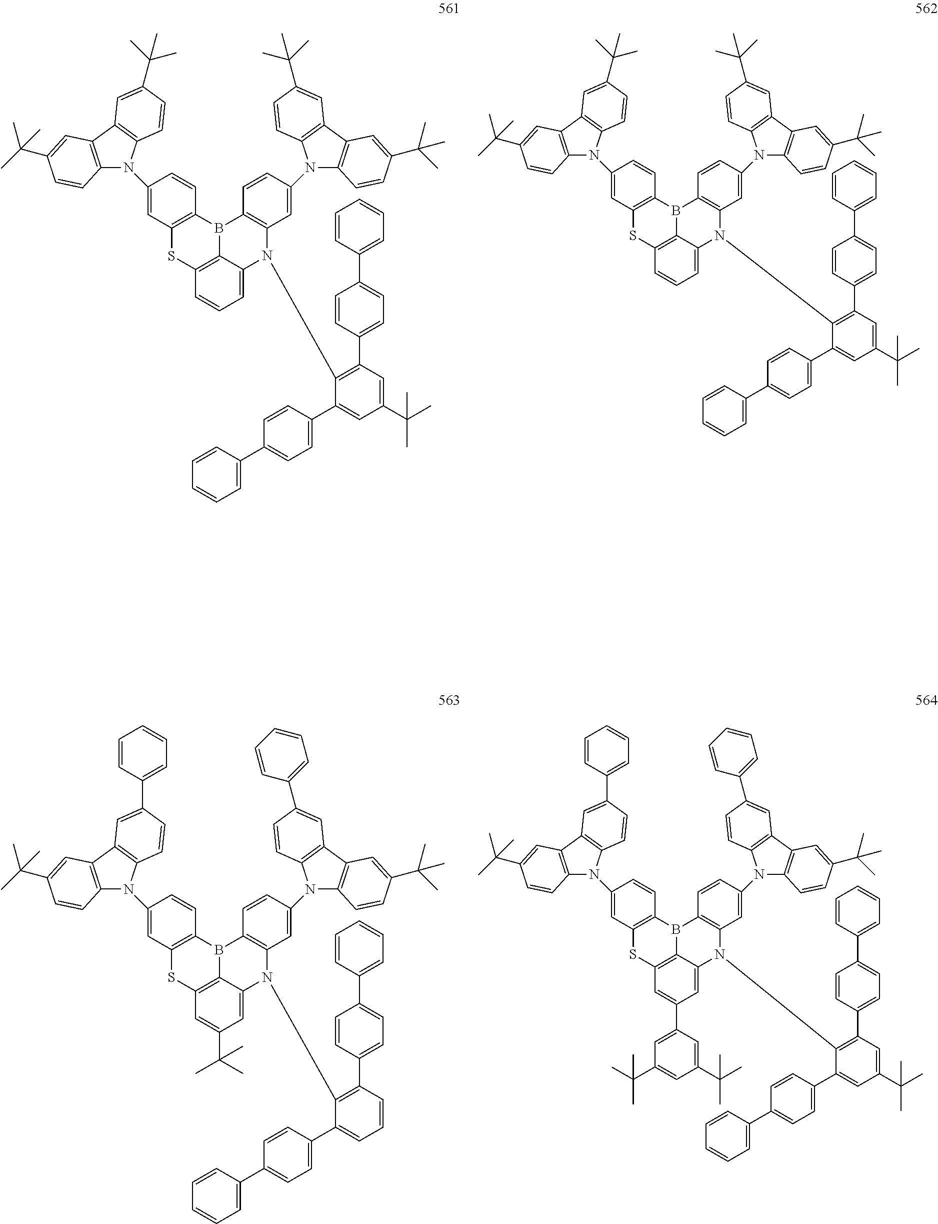

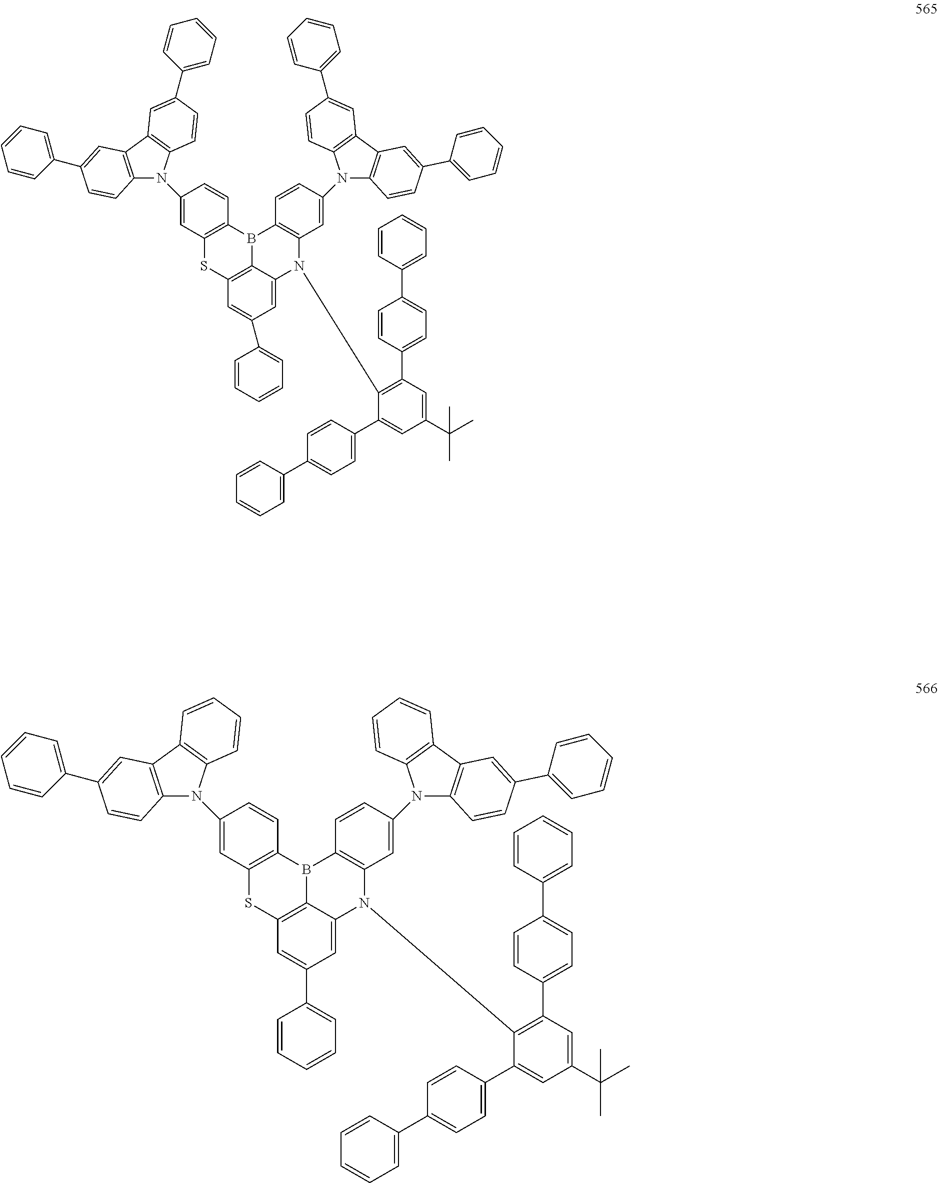 [SMILES: CC(C)(C)c1cc(-c2ccc(-c3ccccc3)cc2)c(N2c3cc(-n4c5ccc(-c6ccccc6)cc5c5cc(-c6ccccc6)ccc54)ccc3B3c4ccc(-n5c6ccc(-c7ccccc7)cc6c6cc(-c7ccccc7)ccc65)cc4Sc4cc(-c5ccccc5)cc2c43)c(-c2ccc(-c3ccccc3)cc2)c1 ; CC(C)(C)c1cc(-c2ccc(-c3ccccc3)cc2)c(N2c3cc(-n4c5ccccc5c5cc(-c6ccccc6)ccc54)ccc3B3c4ccc(-n5c6ccccc6c6cc(-c7ccccc7)ccc65)cc4Sc4cc(-c5ccccc5)cc2c43)c(-c2ccc(-c3ccccc3)cc2)c1]

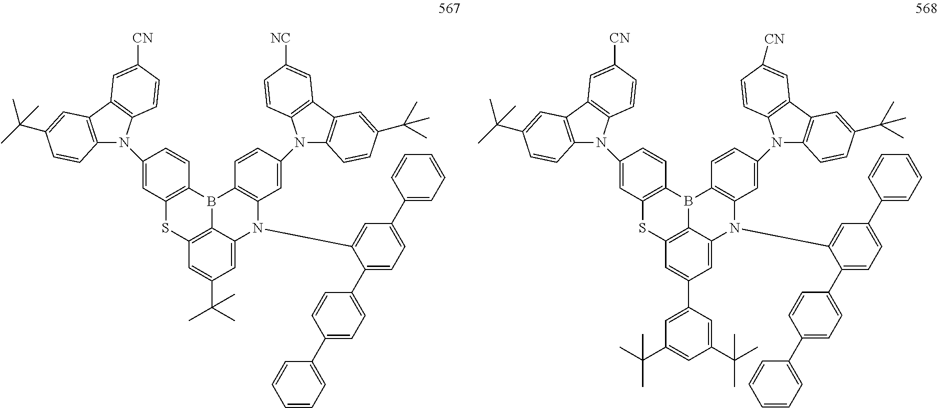 [SMILES: CC(C)(C)c1cc2c3c(c1)N(c1cc(-c4ccccc4)ccc1-c1ccc(-c4ccccc4)cc1)c1cc(-n4c5ccc(C#N)cc5c5cc(C(C)(C)C)ccc54)ccc1B3c1ccc(-n3c4ccc(C#N)cc4c4cc(C(C)(C)C)ccc43)cc1S2 ; CC(C)(C)c1cc(-c2cc3c4c(c2)N(c2cc(-c5ccccc5)ccc2-c2ccc(-c5ccccc5)cc2)c2cc(-n5c6ccc(C#N)cc6c6cc(C(C)(C)C)ccc65)ccc2B4c2ccc(-n4c5ccc(C#N)cc5c5cc(C(C)(C)C)ccc54)cc2S3)cc(C(C)(C)C)c1]

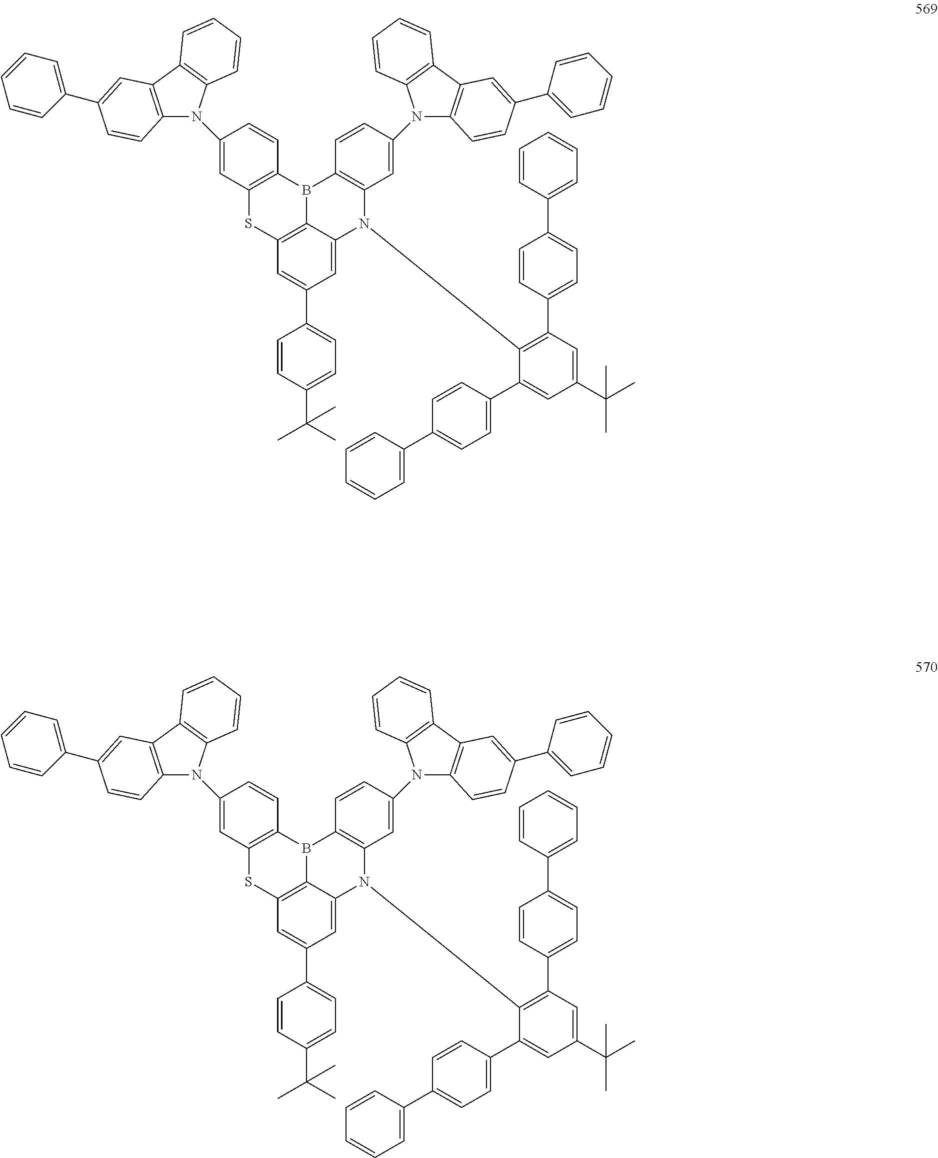 [SMILES: CC(C)(C)c1ccc(-c2cc3c4c(c2)N(c2c(-c5ccc(-c6ccccc6)cc5)cc(C(C)(C)C)cc2-c2ccc(-c5ccccc5)cc2)c2cc(-n5c6ccccc6c6cc(-c7ccccc7)ccc65)ccc2B4c2ccc(-n4c5ccccc5c5cc(-c6ccccc6)ccc54)cc2S3)cc1 ; CC(C)(C)c1ccc(-c2cc3c4c(c2)N(c2c(-c5ccc(-c6ccccc6)cc5)cc(C(C)(C)C)cc2-c2ccc(-c5ccccc5)cc2)c2cc(-n5c6ccccc6c6cc(-c7ccccc7)ccc65)ccc2B4c2ccc(-n4c5ccccc5c5cc(-c6ccccc6)ccc54)cc2S3)cc1]

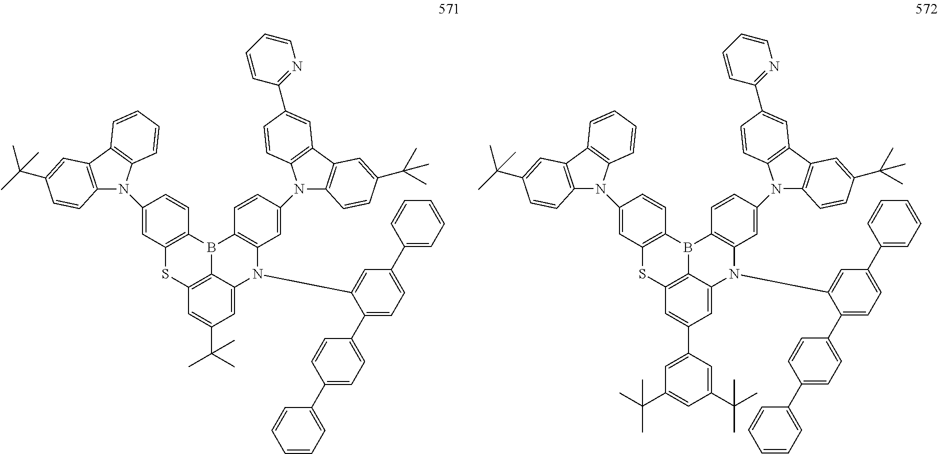 [SMILES: CC(C)(C)c1cc2c3c(c1)N(c1cc(-c4ccccc4)ccc1-c1ccc(-c4ccccc4)cc1)c1cc(-n4c5ccc(-c6ccccn6)cc5c5cc(C(C)(C)C)ccc54)ccc1B3c1ccc(-n3c4ccccc4c4cc(C(C)(C)C)ccc43)cc1S2 ; CC(C)(C)c1cc(-c2cc3c4c(c2)N(c2cc(-c5ccccc5)ccc2-c2ccc(-c5ccccc5)cc2)c2cc(-n5c6ccc(-c7ccccn7)cc6c6cc(C(C)(C)C)ccc65)ccc2B4c2ccc(-n4c5ccccc5c5cc(C(C)(C)C)ccc54)cc2S3)cc(C(C)(C)C)c1]

In the particular example compounds presented in Compound Group 1, “D” refers to deuterium.

Because the fused polycyclic compound according to one or more embodiments has a structure where a first substituent is connected to the fused polycyclic hetero ring, long lifespan may be achieved.

The fused polycyclic compound according to one or more embodiments includes a fused cyclic core with five rings fused and including a first boron atom, a first nitrogen atom, and a first hetero atom, and a first substituent connected to the first nitrogen atom in the fused cyclic core. In one or more embodiments, the fused cyclic core, included in the fused polycyclic compound, may include first to third benzene rings that are connected through the first boron atom, the first nitrogen atom, and the first hetero atom to thereby form the five rings. The first substituent may have a structure in which a first benzene moiety connected to the first nitrogen atom is included, and a first sub substituent and a second sub substituent are each connected to the first benzene moiety. The first substituent may have a structure in which the first benzene moiety connected to the first nitrogen atom is included, and the first sub substituent is connected at an ortho position carbon with respect to a carbon atom connected to the first nitrogen atom, among the carbon atoms constituting the first benzene moiety. The first sub substituent may include a second benzene moiety connected at the ortho position carbon with respect to the carbon atom connected to the first nitrogen atom among the carbon atoms constituting the first benzene moiety, and a third benzene moiety connected at a para position carbon with respect to a carbon atom connected to the first benzene moiety among the carbon atoms constituting the second benzene moiety. The second sub substituent may be a substituted or unsubstituted aryl group having 6 to 30 ring-forming carbon atoms or a substituted or substituted heteroaryl group having 2 to 30 ring-forming carbon atoms.

The fused polycyclic compound according to one or more embodiments of the present disclosure may exhibit excellent or suitable molecular stability due to the particular structure of the first substituent, thereby contributing to long lifespan of the light emitting element ED. The fused polycyclic compound according to one or more embodiments may effectively maintain a trigonal planar structure of the boron atom through effect of steric hindrance caused by the first substituent. The boron atom may have electron-deficiency characteristics due to its empty p-orbital, and may thus form bonding with another nucleophile to change into a tetrahedral structure, which may result in deterioration of an element. According to the present disclosure, because the fused polycyclic compound represented by Formula 1 includes the first substituent having a steric hindrance structure, the empty p-orbital of the boron atom may be effectively protected, thereby preventing or reducing a deterioration phenomenon caused by the structural deformation.

In addition, because the first substituent is included in the fused polycyclic compound according to one or more embodiments, molecular interaction may be suppressed or reduced, and formation of excimer or exciplex may thus be controlled or selected, thereby increasing luminescence efficiency. In addition, because the fused polycyclic compound according to one or more embodiments, represented by Formula 1, includes the first substituent, a dihedral angle between a plane including the fused cyclic core structure centered on the boron atom and a plane including the first substituent may become larger, and accordingly, the distance between the molecules may increase, there are effects of reducing Dexter energy transfer. The Dexter energy transfer is a phenomenon that triplet exciton moves between molecules, and increases when the distance between the molecules is short, and may result in increasing a quenching phenomenon due to the increase in triplet concentration. According to the present disclosure, in the fused polycyclic compound according to one or more embodiments, due to its structure having great steric hindrance, the distance between the adjacent molecules may increase, so that the Dexter energy transfer may be suppressed or reduced, thereby suppressing or reducing lifespan deterioration occurring due to the increase in triplet concentration. Therefore, when applying the fused polycyclic compound according to one or more embodiments to the emission layer EML of the light emitting element ED, luminescence efficiency may be improved, and also, the element lifespan may be improved.

An emission spectrum of the fused polycyclic compound according to one or more embodiments, represented by Formula 1, has a full width at half maximum of about 10 nm to about 50 nm, or a full width at half maximum of about 20 nm to about 40 nm. Because the emission spectrum of the first dopant (i.e., first compound) according to one or more embodiments, represented by Formula 1, has a full width at half maximum within the above ranges, the luminescence efficiency may be improved upon application to the element. In addition, when the fused polycyclic compound is used as a material for a blue light emitting element, the element lifespan may be improved.

In one or more embodiments, the fused polycyclic compound according to one or more embodiments, represented by Formula 1, may be a thermally activated delayed fluorescence light-emitting material. In one or more embodiments, the fused polycyclic compound according to one or more embodiments, represented by Formula 1, may be a thermally activated delayed fluorescence dopant having a difference (ΔE_{ST}) of about 0.6 eV or less between the lowest triplet exciton energy level (T1) and the lowest singlet exciton energy level (S1). In other words, the difference in energy between the lowest singlet (S1) state and the lowest triplet (T1) state of the fused polycyclic compound may be about 0.6 eV or less. The fused polycyclic compound according to one or more embodiments, represented by Formula 1, may be a thermally activated delayed fluorescence dopant having a difference (ΔE_{ST}) of about 0.2 eV or less between the lowest triplet exciton energy level (T1) and the lowest singlet exciton energy level (S1). However, embodiments of the present disclosure are not limited thereto.

In one or more embodiments, the fused polycyclic compound according to one or more embodiments, represented by Formula 1, may include a first substituent and a second substituent in the compound. By adjusting the number of substitutions, substituting positions, and/or the like of the first substituent and the second substituent, the singlet exciton energy level and the triplet exciton energy level of overall compound may be appropriately or suitably controlled or selected. Through this, the fused polycyclic compound according to one or more embodiments of the present disclosure may have improved thermally activated delayed fluorescence characteristics.

The fused polycyclic compound according to one or more embodiments, represented by Formula 1, may be a light-emitting material having a central emission wavelength (emission peak wavelength) in a wavelength range of about 430 nm to about 490 nm. For example, the fused polycyclic compound according to one or more embodiments, represented by Formula 1, may be a blue-color thermally activated delayed fluorescence (TADF) dopant. However, embodiments of the present disclosure are not limited thereto, for example, in one or more embodiments in which the fused polycyclic compound according to one or more embodiments is used as a light-emitting material, the first dopant may be used as a dopant material emitting light in one or more suitable wavelength ranges such as a red light-emitting dopant and/or a green light-emitting dopant.

In the light emitting element ED according to one or more embodiments, the emission layer EML may be to emit delayed fluorescence. For example, in one or more embodiments, the emission layer EML may be to emit thermally activated delayed fluorescence (TADF).

In one or more embodiments, the emission layer EML of the light emitting element ED may be to emit blue color light. For example, the emission layer EML of the organic electroluminescent light emitting element ED according to one or more embodiments may be to emit blue color light in a wavelength range of about 490 nm or less. However, embodiments of the present disclosure are not limited thereto, and the emission layer EML may also emit green color light or red color light.

The fused polycyclic compound according to one or more embodiments may be included in the emission layer EML. The fused polycyclic compound according to one or more embodiments may be included in the emission layer EML as a dopant material. The fused polycyclic compound according to one or more embodiments may be a thermally activated delayed fluorescence material. The fused polycyclic compound according to one or more embodiments may be used as a thermally activated delayed fluorescence dopant. For example, in the light emitting element ED according to one or more embodiments, the emission layer EML may include at least one selected from among the fused polycyclic compounds listed in Compound Group 1, described above, as the thermally activated delayed fluorescence dopant. However, the use of the fused polycyclic compound according to one or more embodiments is not limited thereto.

In one or more embodiments, the emission layer EML may include a plurality of compounds. The emission layer EML of one or more embodiments may include the fused polycyclic compound represented by Formula 1, i.e., the first compound, and at least one of a second compound represented by Formula HT-1, a third compound represented by Formula ET-1, or a fourth compound represented by Formula D-1.

In one or more embodiments, the emission layer EML may include the first compound represented by Formula 1, and may further include at least one of the second compound represented by Formula HT-1, the third compound represented by Formula ET-1, or the fourth compound represented by Formula D-1.

In one or more embodiments, the second compound may be used as a hole transporting host material of the emission layer EML.

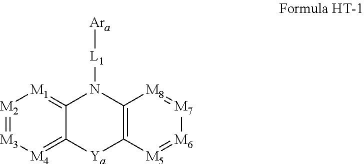

In Formula HT-1, M₁ to M₈ may each independently be N or CR₅₁. For example, in one or more embodiments, all of M₁ to M₈ may be CR₅₁. In one or more embodiments, any one selected from among M₁ to M₈ may be N, and the rest may

In Formula HT-1, L₁ may be a direct linkage, a substituted or unsubstituted arylene group having 6 to 30 ring-forming carbon atoms, or a substituted or unsubstituted heteroarylene group having 2 to 30 ring-forming carbon atoms. For example, in one or more embodiments, L₁ may be a direct linkage, a substituted or unsubstituted phenylene group, a substituted or unsubstituted divalent biphenyl group, a substituted or unsubstituted divalent carbazole group, and/or the like, but embodiments of the present disclosure are not limited thereto.

In Formula HT-1, Yₐ may be a direct linkage, CR₅₂R₅₃, or SiR₅₄R₅₅. For example, it may refer to that the two six-membered rings (e.g., two benzene rings) linked to the nitrogen atom in Formula HT-1 are linked via a direct linkage,

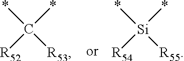

In Formula HT-1, if (e.g., when) Yₐ is a direct linkage, the second compound represented by Formula HT-1 may include a carbazole moiety.

In Formula HT-1, Ara may be a substituted or unsubstituted aryl group having 6 to 30 ring-forming carbon atoms or a substituted or unsubstituted heteroaryl group having 2 to 30 ring-forming carbon atoms. For example, in one or more embodiments, Ara may be a substituted or unsubstituted carbazole group, a substituted or unsubstituted dibenzofuran group, a substituted or unsubstituted dibenzothiophene group, a substituted or unsubstituted biphenyl group, and/or the like, but embodiments of the present disclosure are not limited thereto.

In Formula HT-1, R₅₁ to R₅₅ may each independently be hydrogen, deuterium, a halogen, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms. In one or more embodiments, one or more selected from among R₅₁ to R₅₅ may be each independently bonded to an adjacent group to form a ring. For example, in one or more embodiments, R₅₁ to R₅₅ may each independently be hydrogen or deuterium. In one or more embodiments, R₅₁ to R₅₅ may each independently be an unsubstituted methyl group or an unsubstituted phenyl group.

In one or more embodiments, the second compound represented by Formula HT-1 may be any one selected from among compounds represented by Compound Group 2. The emission layer EML may include at least one selected from among the compounds represented by Compound Group 2 as a hole transporting host material.

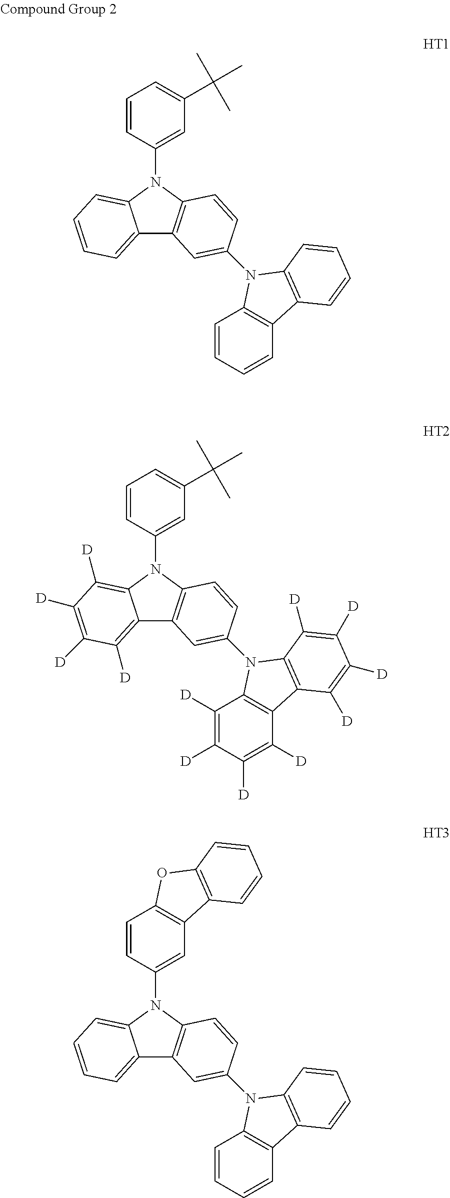 [SMILES: CC(C)(C)c1cccc(-n2c3ccccc3c3cc(-n4c5ccccc5c5ccccc54)ccc32)c1 ; [2H]c1c([2H])c([2H])c2c(c1[2H])c1cc(-n3c4c([2H])c([2H])c([2H])c([2H])c4c4c([2H])c([2H])c([2H])c([2H])c43)ccc1n2-c1cccc(C(C)(C)C)c1 ; c1ccc2c(c1)oc1ccc(-n3c4ccccc4c4cc(-n5c6ccccc6c6ccccc65)ccc43)cc12]

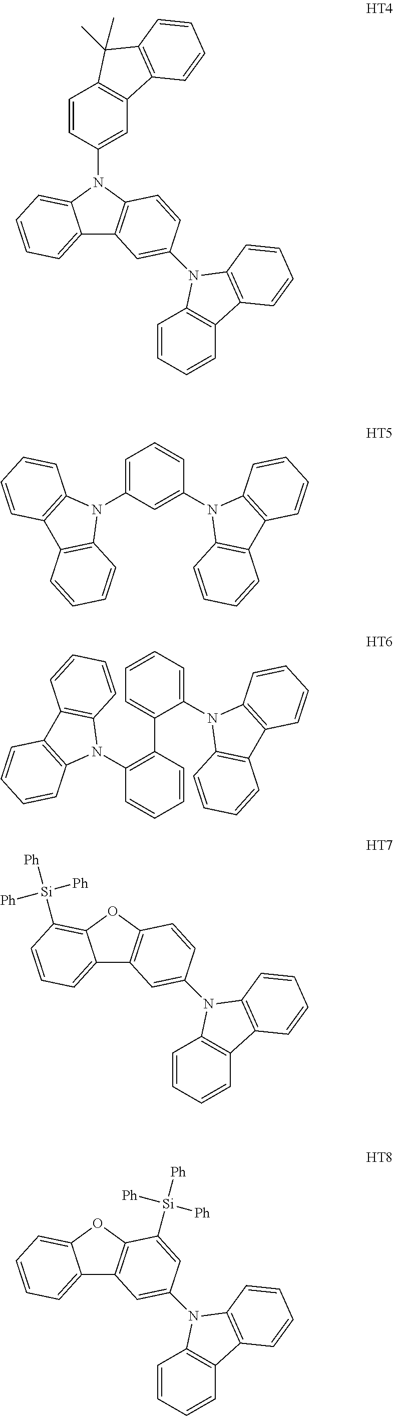 [SMILES: CC1(C)c2ccccc2-c2cc(-n3c4ccccc4c4cc(-n5c6ccccc6c6ccccc65)ccc43)ccc21 ; c1cc(-n2c3ccccc3c3ccccc32)cc(-n2c3ccccc3c3ccccc32)c1 ; c1ccc(-n2c3ccccc3c3ccccc32)c(-c2ccccc2-n2c3ccccc3c3ccccc32)c1 ; c1ccc([Si](c2ccccc2)(c2ccccc2)c2cccc3c2oc2ccc(-n4c5ccccc5c5ccccc54)cc23)cc1 ; c1ccc([Si](c2ccccc2)(c2ccccc2)c2cc(-n3c4ccccc4c4ccccc43)cc3c2oc2ccccc23)cc1]

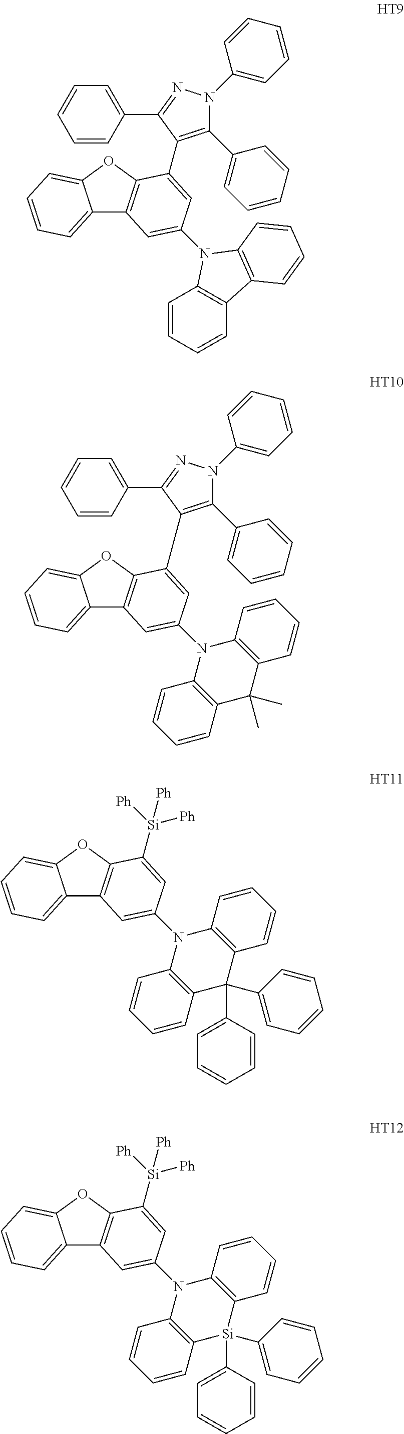 [SMILES: c1ccc(-c2nn(-c3ccccc3)c(-c3ccccc3)c2-c2cc(-n3c4ccccc4c4ccccc43)cc3c2oc2ccccc23)cc1 ; CC1(C)c2ccccc2N(c2cc(-c3c(-c4ccccc4)nn(-c4ccccc4)c3-c3ccccc3)c3oc4ccccc4c3c2)c2ccccc21 ; c1ccc(C2(c3ccccc3)c3ccccc3N(c3cc([Si](c4ccccc4)(c4ccccc4)c4ccccc4)c4oc5ccccc5c4c3)c3ccccc32)cc1 ; c1ccc([Si]2(c3ccccc3)c3ccccc3N(c3cc([Si](c4ccccc4)(c4ccccc4)c4ccccc4)c4oc5ccccc5c4c3)c3ccccc32)cc1]

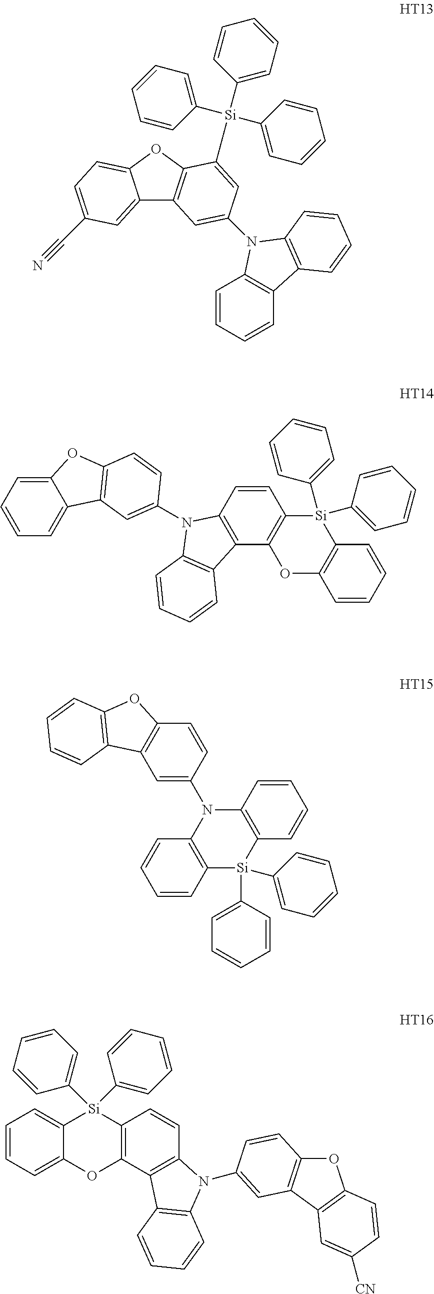 [SMILES: N#Cc1ccc2oc3c([Si](c4ccccc4)(c4ccccc4)c4ccccc4)cc(-n4c5ccccc5c5ccccc54)cc3c2c1 ; c1ccc([Si]2(c3ccccc3)c3ccccc3Oc3c2ccc2c3c3ccccc3n2-c2ccc3oc4ccccc4c3c2)cc1 ; c1ccc([Si]2(c3ccccc3)c3ccccc3N(c3ccc4oc5ccccc5c4c3)c3ccccc32)cc1 ; N#Cc1ccc2oc3ccc(-n4c5ccccc5c5c6c(ccc54)[Si](c4ccccc4)(c4ccccc4)c4ccccc4O6)cc3c2c1]

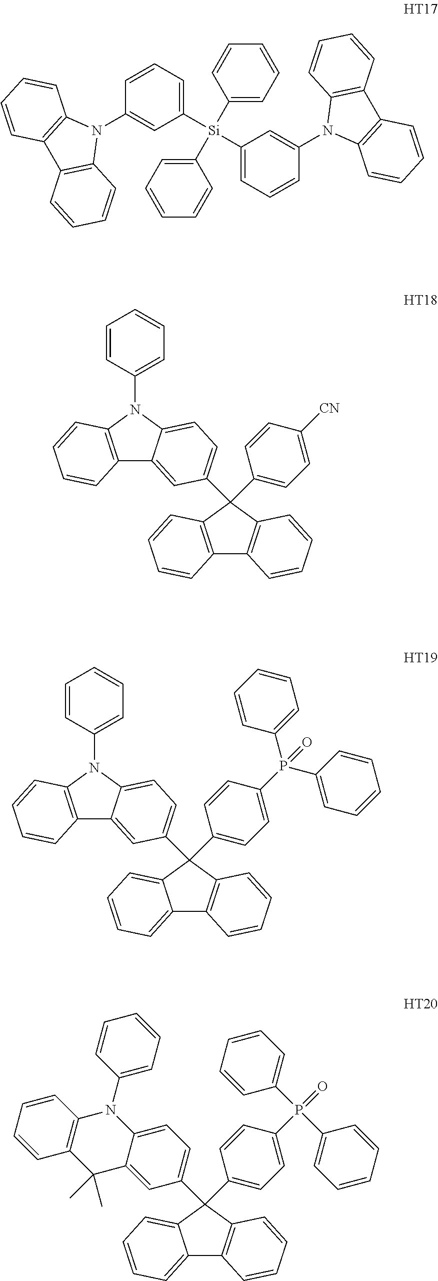 [SMILES: c1ccc([Si](c2ccccc2)(c2cccc(-n3c4ccccc4c4ccccc43)c2)c2cccc(-n3c4ccccc4c4ccccc43)c2)cc1 ; N#Cc1ccc(C2(c3ccc4c(c3)c3ccccc3n4-c3ccccc3)c3ccccc3-c3ccccc32)cc1 ; O=P(c1ccccc1)(c1ccccc1)c1ccc(C2(c3ccc4c(c3)c3ccccc3n4-c3ccccc3)c3ccccc3-c3ccccc32)cc1 ; CC1(C)c2ccccc2N(c2ccccc2)c2ccc(C3(c4ccc(P(=O)(c5ccccc5)c5ccccc5)cc4)c4ccccc4-c4ccccc43)cc21]

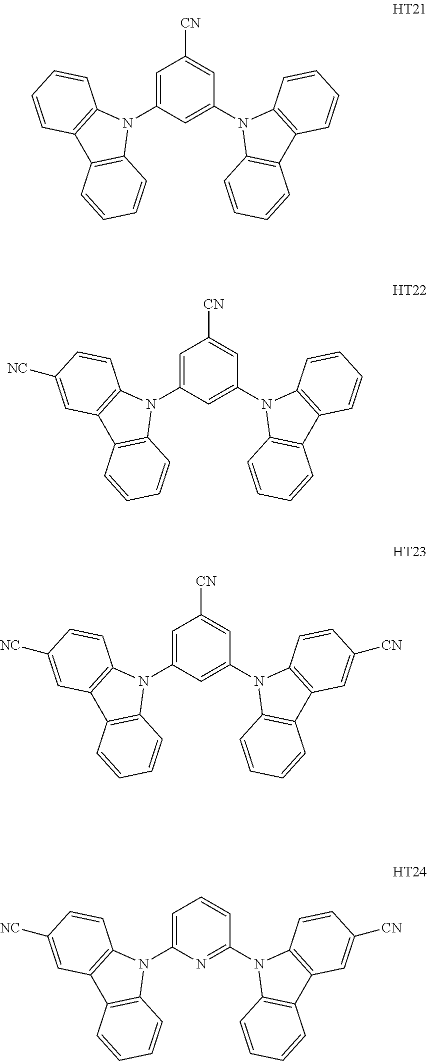 [SMILES: N#Cc1cc(-n2c3ccccc3c3ccccc32)cc(-n2c3ccccc3c3ccccc32)c1 ; N#Cc1cc(-n2c3ccccc3c3ccccc32)cc(-n2c3ccccc3c3cc(C#N)ccc32)c1 ; N#Cc1cc(-n2c3ccccc3c3cc(C#N)ccc32)cc(-n2c3ccccc3c3cc(C#N)ccc32)c1 ; N#Cc1ccc2c(c1)c1ccccc1n2-c1cccc(-n2c3ccccc3c3cc(C#N)ccc32)n1]

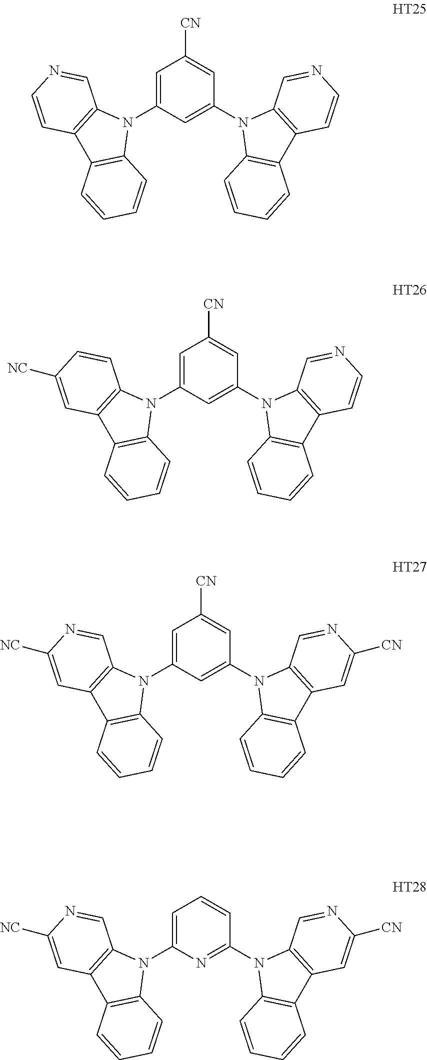 [SMILES: N#Cc1cc(-n2c3ccccc3c3ccncc32)cc(-n2c3ccccc3c3ccncc32)c1 ; N#Cc1cc(-n2c3ccccc3c3cc(C#N)ccc32)cc(-n2c3ccccc3c3ccncc32)c1 ; N#Cc1cc(-n2c3ccccc3c3cc(C#N)ncc32)cc(-n2c3ccccc3c3cc(C#N)ncc32)c1 ; N#Cc1cc2c3ccccc3n(-c3cccc(-n4c5ccccc5c5cc(C#N)ncc54)n3)c2cn1]

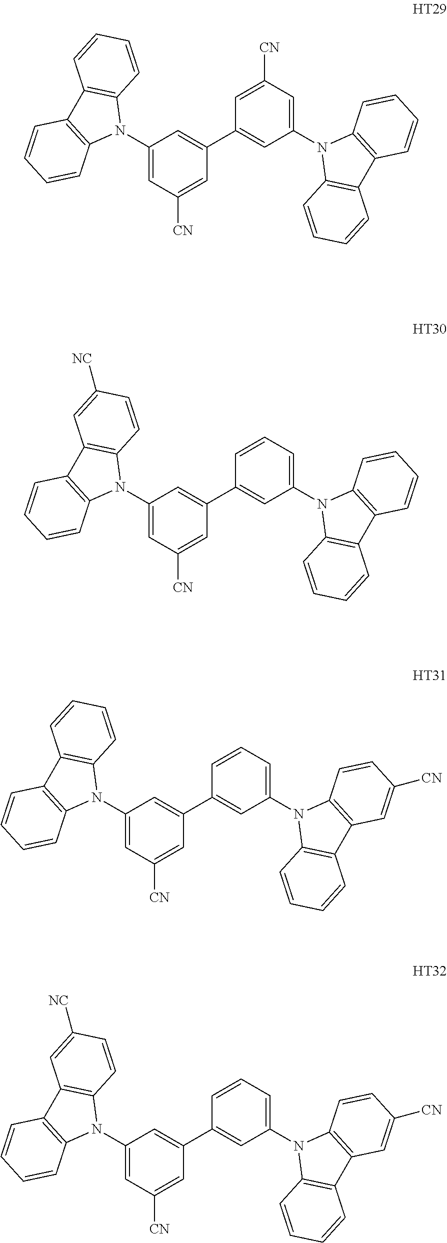 [SMILES: N#Cc1cc(-c2cc(C#N)cc(-n3c4ccccc4c4ccccc43)c2)cc(-n2c3ccccc3c3ccccc32)c1 ; N#Cc1cc(-c2cccc(-n3c4ccccc4c4ccccc43)c2)cc(-n2c3ccccc3c3cc(C#N)ccc32)c1 ; N#Cc1cc(-c2cccc(-n3c4ccccc4c4cc(C#N)ccc43)c2)cc(-n2c3ccccc3c3ccccc32)c1 ; N#Cc1cc(-c2cccc(-n3c4ccccc4c4cc(C#N)ccc43)c2)cc(-n2c3ccccc3c3cc(C#N)ccc32)c1]

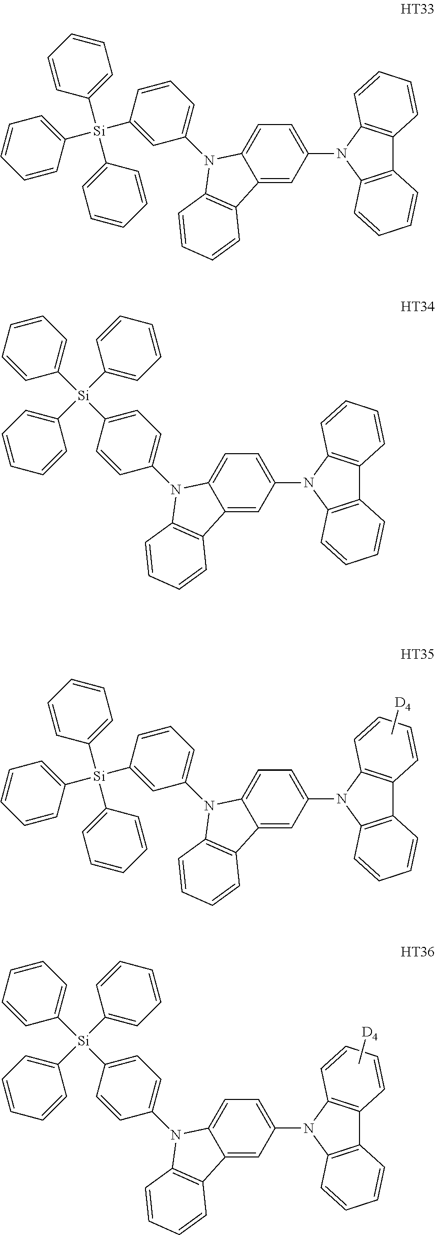

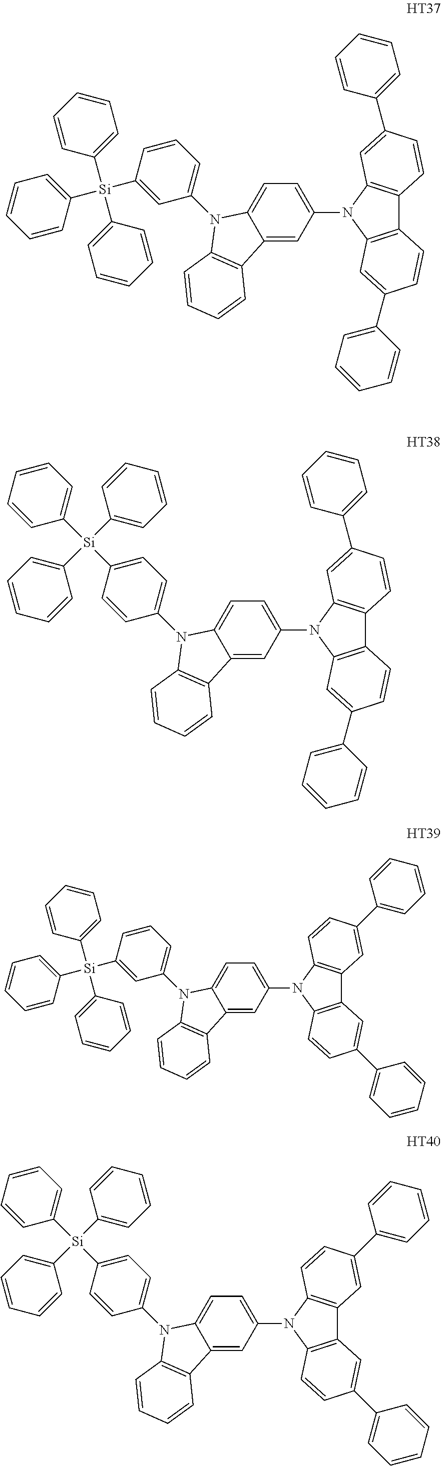 [SMILES: c1ccc(-c2ccc3c4ccc(-c5ccccc5)cc4n(-c4ccc5c(c4)c4ccccc4n5-c4cccc([Si](c5ccccc5)(c5ccccc5)c5ccccc5)c4)c3c2)cc1 ; c1ccc(-c2ccc3c4ccc(-c5ccccc5)cc4n(-c4ccc5c(c4)c4ccccc4n5-c4ccc([Si](c5ccccc5)(c5ccccc5)c5ccccc5)cc4)c3c2)cc1 ; c1ccc(-c2ccc3c(c2)c2cc(-c4ccccc4)ccc2n3-c2ccc3c(c2)c2ccccc2n3-c2cccc([Si](c3ccccc3)(c3ccccc3)c3ccccc3)c2)cc1 ; c1ccc(-c2ccc3c(c2)c2cc(-c4ccccc4)ccc2n3-c2ccc3c(c2)c2ccccc2n3-c2ccc([Si](c3ccccc3)(c3ccccc3)c3ccccc3)cc2)cc1]

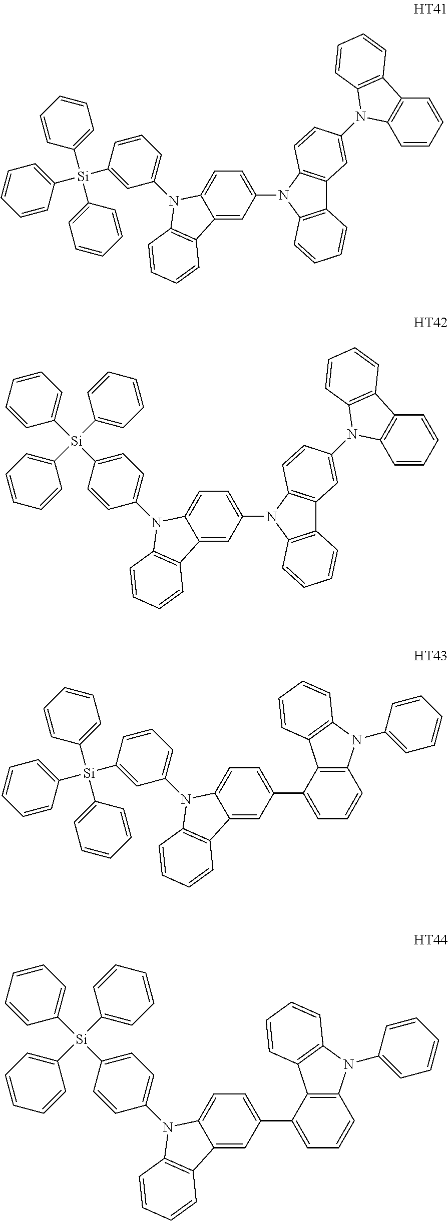 [SMILES: c1ccc([Si](c2ccccc2)(c2ccccc2)c2cccc(-n3c4ccccc4c4cc(-n5c6ccccc6c6cc(-n7c8ccccc8c8ccccc87)ccc65)ccc43)c2)cc1 ; c1ccc([Si](c2ccccc2)(c2ccccc2)c2ccc(-n3c4ccccc4c4cc(-n5c6ccccc6c6cc(-n7c8ccccc8c8ccccc87)ccc65)ccc43)cc2)cc1 ; c1ccc(-n2c3ccccc3c3c(-c4ccc5c(c4)c4ccccc4n5-c4cccc([Si](c5ccccc5)(c5ccccc5)c5ccccc5)c4)cccc32)cc1 ; c1ccc(-n2c3ccccc3c3c(-c4ccc5c(c4)c4ccccc4n5-c4ccc([Si](c5ccccc5)(c5ccccc5)c5ccccc5)cc4)cccc32)cc1]

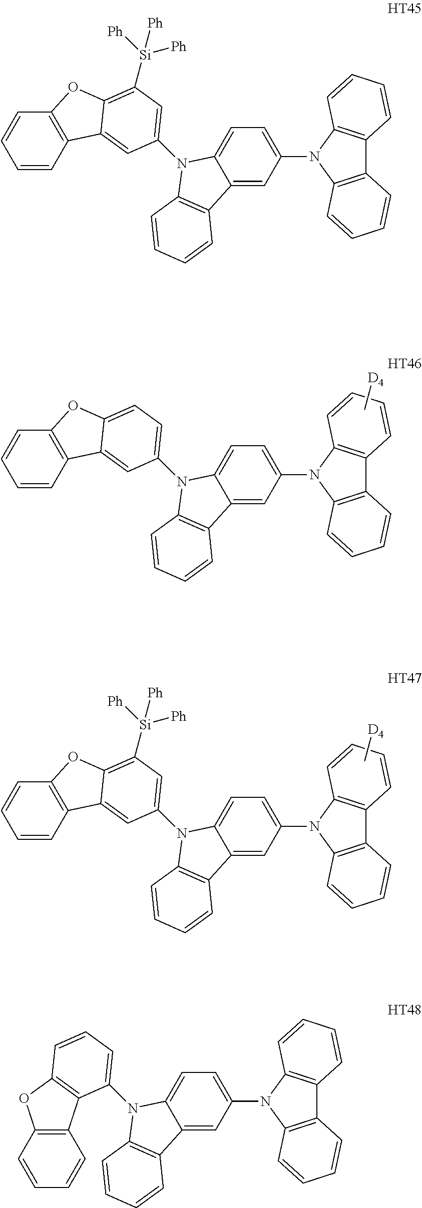

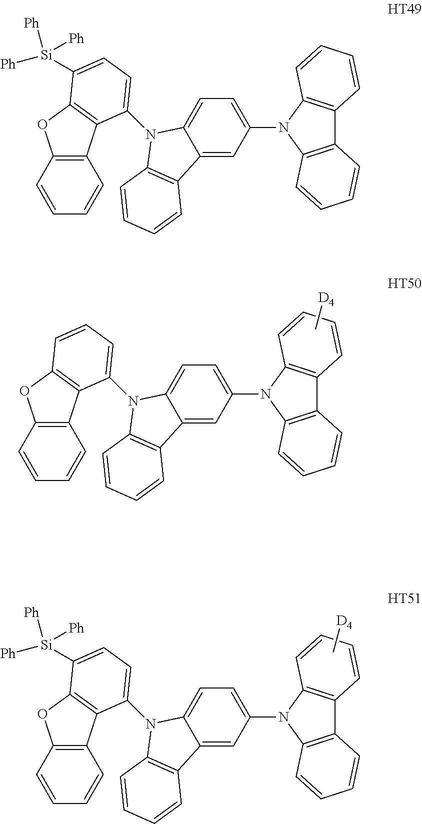

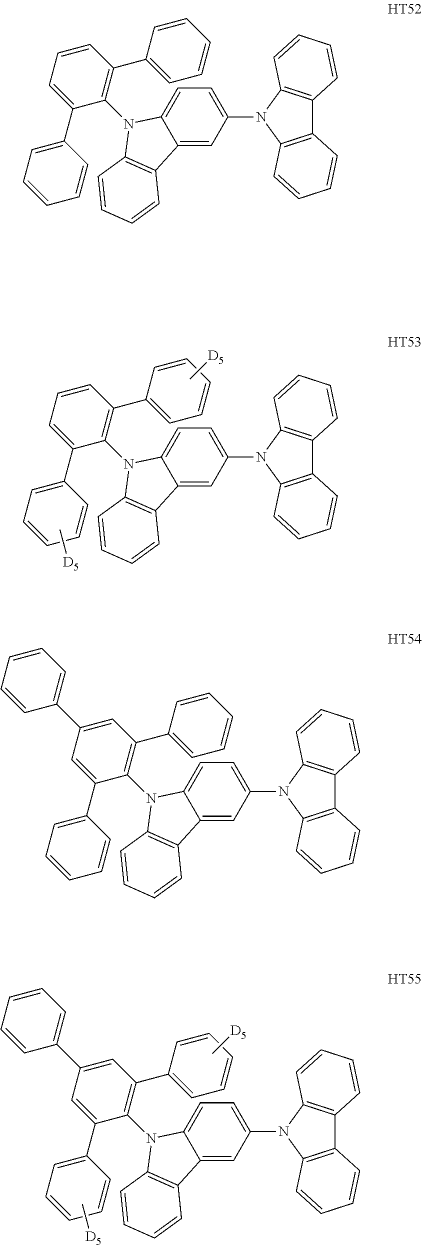

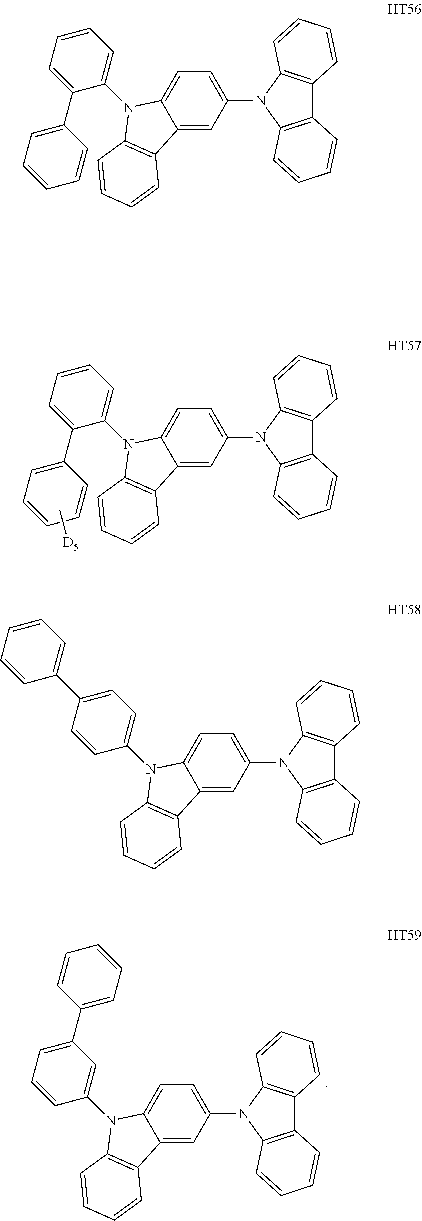

In embodiment compounds presented in Compound Group 2, “D” may refer to deuterium, and “Ph” may refer to a substituted or unsubstituted phenyl group. For example, in embodiment compounds presented in Compound Group 2, “Ph” may refer to an unsubstituted phenyl group.

In one or more embodiments, the emission layer EML may include the third compound represented by Formula ET-1. For example, the third compound may be used as an electron transporting host material for the emission layer EML.

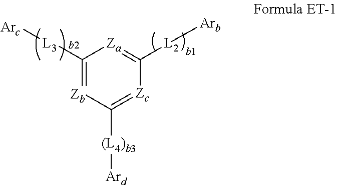

In Formula ET-1, at least one selected from among Zₐ to Z_{c} may be N, and the rest are CR₅₆. For example, in one or more embodiments, any one selected from among Zₐ to Z_{c} may be N, and the rest may each independently be CR₅₆. In these embodiments, the third compound represented by Formula ET-1 may include a pyridine moiety. In one or more embodiments, two selected from among Zₐ to Z_{c} may be N, and the rest may be CR₅₆. In these embodiments, the third compound represented by Formula ET-1 may include a pyrimidine moiety. In one or more embodiments, Zₐ to Z_{c} may all be N. In these embodiments, the third compound represented by Formula ET-1 may include a triazine moiety.

In Formula ET-1, R₅₆ may be hydrogen, deuterium, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms.

In Formula ET-1, b1 to b3 may each independently be an integer of 0 to 10.

In Formula ET-1, Arb to Ard may each independently be hydrogen, deuterium, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, in one or more embodiments, Arb to Ard may each independently be a substituted or unsubstituted phenyl group or a substituted or unsubstituted carbazole group.

In Formula ET-1, L₂ to L₄ may each independently be a direct linkage, a substituted or unsubstituted arylene group having 6 to 30 ring-forming carbon atoms, or a substituted or unsubstituted heteroarylene group having 2 to 30 ring-forming carbon atoms. In one or more embodiments, if (e.g., when) b1 to b3 are each an integer of 2 or greater, L₂ to L₄ each in plurality may each independently be a substituted or unsubstituted arylene group having 6 to 30 ring-forming carbon atoms or a substituted or unsubstituted heteroarylene group having 2 to 30 ring-forming carbon atoms.

In one or more embodiments, the third compound may be any one selected from among compounds in Compound Group 3. The light emitting element ED of one or more embodiments may include at least one selected from among the compounds in Compound Group 3.

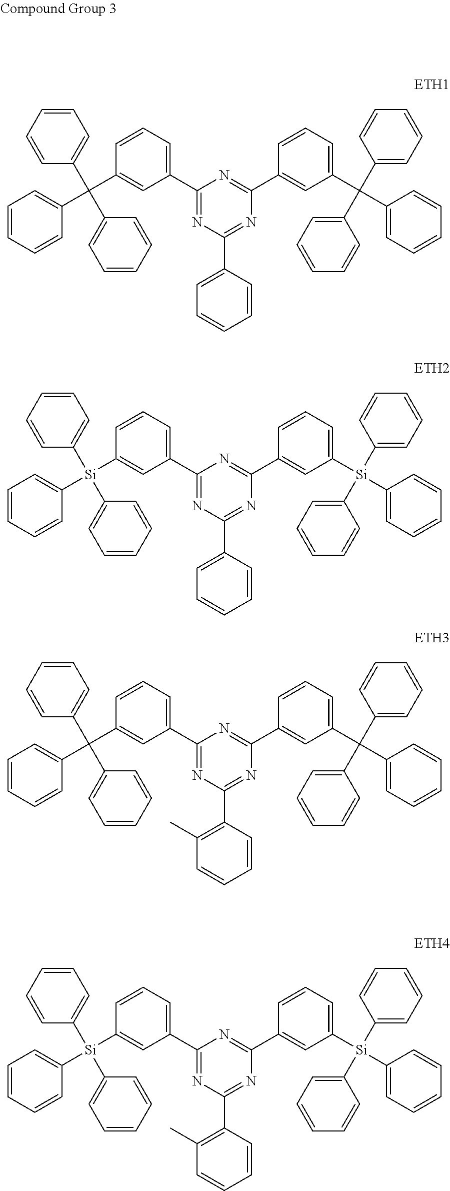 [SMILES: c1ccc(-c2nc(-c3cccc(C(c4ccccc4)(c4ccccc4)c4ccccc4)c3)nc(-c3cccc(C(c4ccccc4)(c4ccccc4)c4ccccc4)c3)n2)cc1 ; c1ccc(-c2nc(-c3cccc([Si](c4ccccc4)(c4ccccc4)c4ccccc4)c3)nc(-c3cccc([Si](c4ccccc4)(c4ccccc4)c4ccccc4)c3)n2)cc1 ; Cc1ccccc1-c1nc(-c2cccc(C(c3ccccc3)(c3ccccc3)c3ccccc3)c2)nc(-c2cccc(C(c3ccccc3)(c3ccccc3)c3ccccc3)c2)n1 ; Cc1ccccc1-c1nc(-c2cccc([Si](c3ccccc3)(c3ccccc3)c3ccccc3)c2)nc(-c2cccc([Si](c3ccccc3)(c3ccccc3)c3ccccc3)c2)n1]

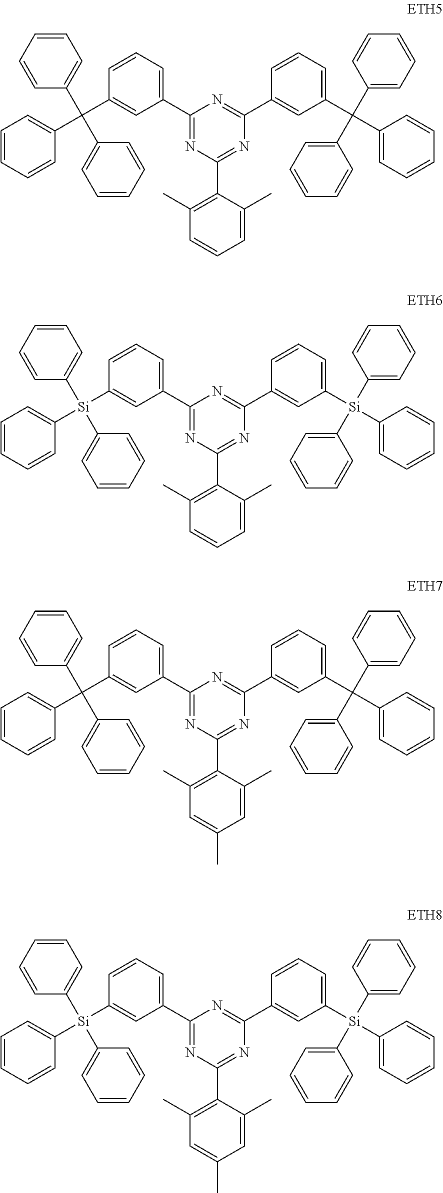 [SMILES: Cc1cccc(C)c1-c1nc(-c2cccc(C(c3ccccc3)(c3ccccc3)c3ccccc3)c2)nc(-c2cccc(C(c3ccccc3)(c3ccccc3)c3ccccc3)c2)n1 ; Cc1cccc(C)c1-c1nc(-c2cccc([Si](c3ccccc3)(c3ccccc3)c3ccccc3)c2)nc(-c2cccc([Si](c3ccccc3)(c3ccccc3)c3ccccc3)c2)n1 ; Cc1cc(C)c(-c2nc(-c3cccc(C(c4ccccc4)(c4ccccc4)c4ccccc4)c3)nc(-c3cccc(C(c4ccccc4)(c4ccccc4)c4ccccc4)c3)n2)c(C)c1 ; Cc1cc(C)c(-c2nc(-c3cccc([Si](c4ccccc4)(c4ccccc4)c4ccccc4)c3)nc(-c3cccc([Si](c4ccccc4)(c4ccccc4)c4ccccc4)c3)n2)c(C)c1]

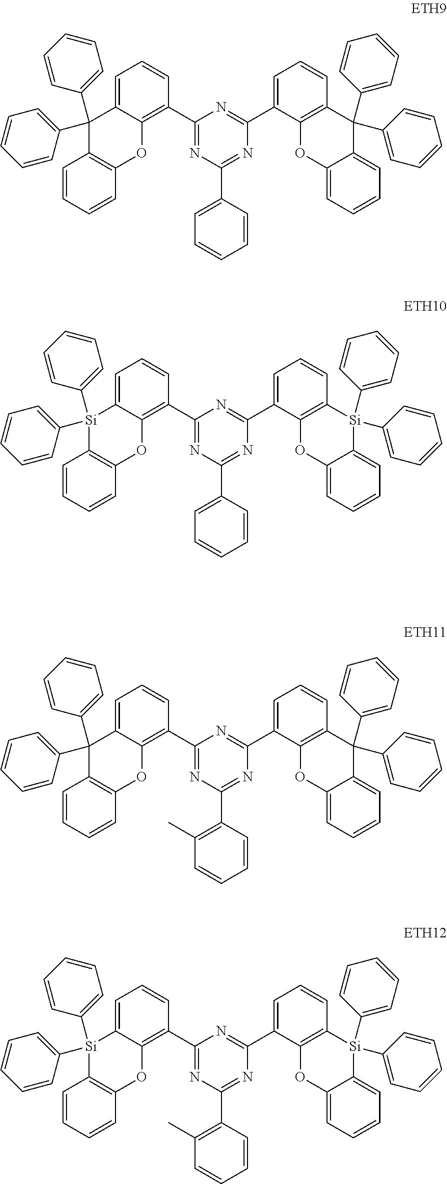 [SMILES: c1ccc(-c2nc(-c3cccc4c3Oc3ccccc3C4(c3ccccc3)c3ccccc3)nc(-c3cccc4c3Oc3ccccc3C4(c3ccccc3)c3ccccc3)n2)cc1 ; c1ccc(-c2nc(-c3cccc4c3Oc3ccccc3[Si]4(c3ccccc3)c3ccccc3)nc(-c3cccc4c3Oc3ccccc3[Si]4(c3ccccc3)c3ccccc3)n2)cc1 ; Cc1ccccc1-c1nc(-c2cccc3c2Oc2ccccc2C3(c2ccccc2)c2ccccc2)nc(-c2cccc3c2Oc2ccccc2C3(c2ccccc2)c2ccccc2)n1 ; Cc1ccccc1-c1nc(-c2cccc3c2Oc2ccccc2[Si]3(c2ccccc2)c2ccccc2)nc(-c2cccc3c2Oc2ccccc2[Si]3(c2ccccc2)c2ccccc2)n1]

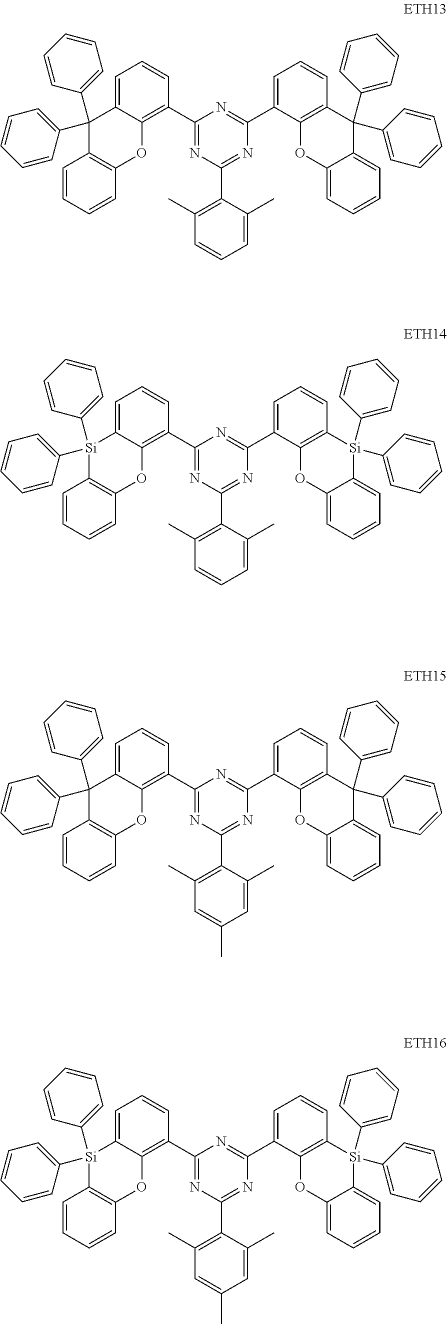 [SMILES: Cc1cccc(C)c1-c1nc(-c2cccc3c2Oc2ccccc2C3(c2ccccc2)c2ccccc2)nc(-c2cccc3c2Oc2ccccc2C3(c2ccccc2)c2ccccc2)n1 ; Cc1cccc(C)c1-c1nc(-c2cccc3c2Oc2ccccc2[Si]3(c2ccccc2)c2ccccc2)nc(-c2cccc3c2Oc2ccccc2[Si]3(c2ccccc2)c2ccccc2)n1 ; Cc1cc(C)c(-c2nc(-c3cccc4c3Oc3ccccc3C4(c3ccccc3)c3ccccc3)nc(-c3cccc4c3Oc3ccccc3C4(c3ccccc3)c3ccccc3)n2)c(C)c1 ; Cc1cc(C)c(-c2nc(-c3cccc4c3Oc3ccccc3[Si]4(c3ccccc3)c3ccccc3)nc(-c3cccc4c3Oc3ccccc3[Si]4(c3ccccc3)c3ccccc3)n2)c(C)c1]

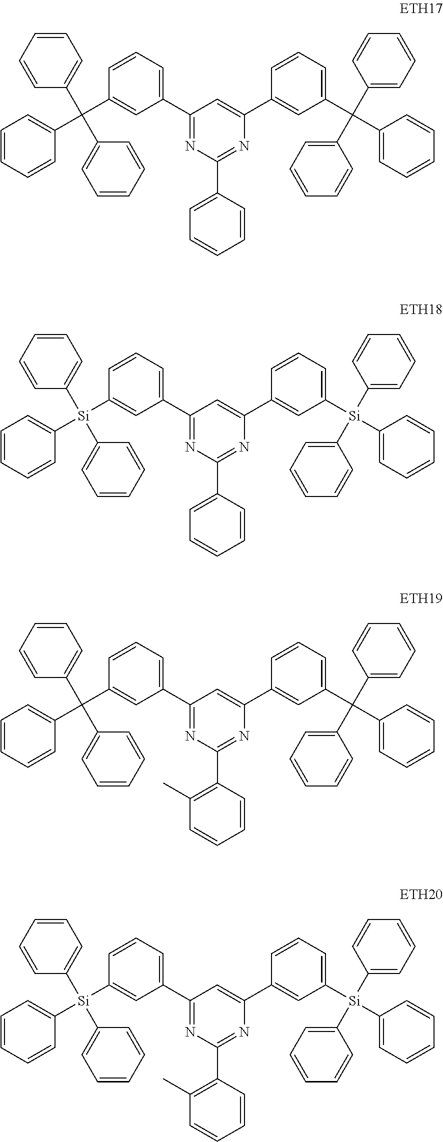 [SMILES: c1ccc(-c2nc(-c3cccc(C(c4ccccc4)(c4ccccc4)c4ccccc4)c3)cc(-c3cccc(C(c4ccccc4)(c4ccccc4)c4ccccc4)c3)n2)cc1 ; c1ccc(-c2nc(-c3cccc([Si](c4ccccc4)(c4ccccc4)c4ccccc4)c3)cc(-c3cccc([Si](c4ccccc4)(c4ccccc4)c4ccccc4)c3)n2)cc1 ; Cc1ccccc1-c1nc(-c2cccc(C(c3ccccc3)(c3ccccc3)c3ccccc3)c2)cc(-c2cccc(C(c3ccccc3)(c3ccccc3)c3ccccc3)c2)n1 ; Cc1ccccc1-c1nc(-c2cccc([Si](c3ccccc3)(c3ccccc3)c3ccccc3)c2)cc(-c2cccc([Si](c3ccccc3)(c3ccccc3)c3ccccc3)c2)n1]

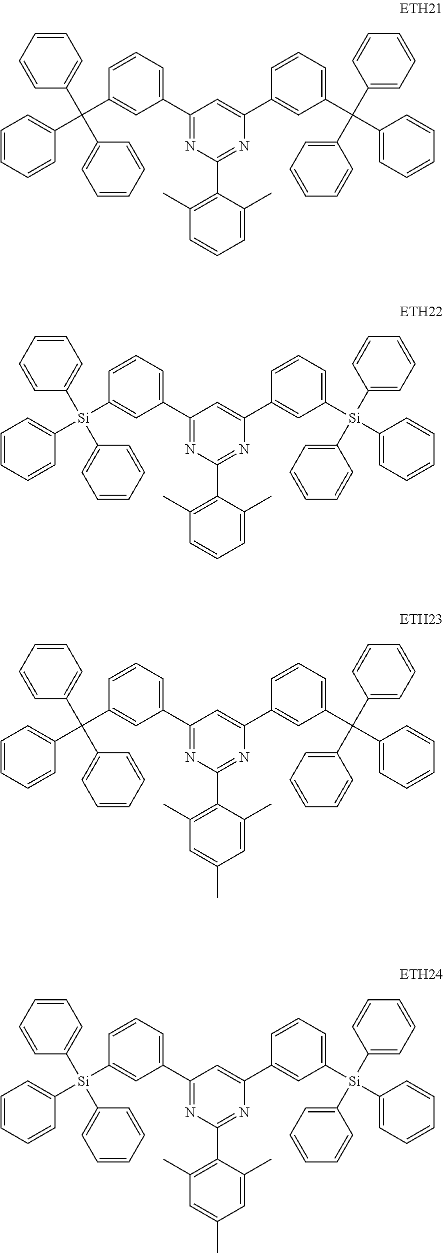 [SMILES: Cc1cccc(C)c1-c1nc(-c2cccc(C(c3ccccc3)(c3ccccc3)c3ccccc3)c2)cc(-c2cccc(C(c3ccccc3)(c3ccccc3)c3ccccc3)c2)n1 ; Cc1cccc(C)c1-c1nc(-c2cccc([Si](c3ccccc3)(c3ccccc3)c3ccccc3)c2)cc(-c2cccc([Si](c3ccccc3)(c3ccccc3)c3ccccc3)c2)n1 ; Cc1cc(C)c(-c2nc(-c3cccc(C(c4ccccc4)(c4ccccc4)c4ccccc4)c3)cc(-c3cccc(C(c4ccccc4)(c4ccccc4)c4ccccc4)c3)n2)c(C)c1 ; Cc1cc(C)c(-c2nc(-c3cccc([Si](c4ccccc4)(c4ccccc4)c4ccccc4)c3)cc(-c3cccc([Si](c4ccccc4)(c4ccccc4)c4ccccc4)c3)n2)c(C)c1]

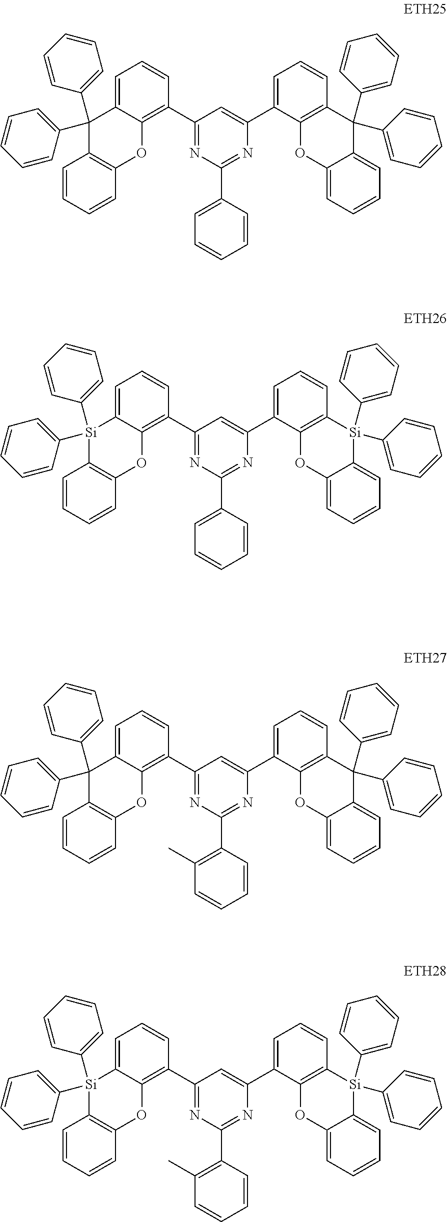 [SMILES: c1ccc(-c2nc(-c3cccc4c3Oc3ccccc3C4(c3ccccc3)c3ccccc3)cc(-c3cccc4c3Oc3ccccc3C4(c3ccccc3)c3ccccc3)n2)cc1 ; c1ccc(-c2nc(-c3cccc4c3Oc3ccccc3[Si]4(c3ccccc3)c3ccccc3)cc(-c3cccc4c3Oc3ccccc3[Si]4(c3ccccc3)c3ccccc3)n2)cc1 ; Cc1ccccc1-c1nc(-c2cccc3c2Oc2ccccc2C3(c2ccccc2)c2ccccc2)cc(-c2cccc3c2Oc2ccccc2C3(c2ccccc2)c2ccccc2)n1 ; Cc1ccccc1-c1nc(-c2cccc3c2Oc2ccccc2[Si]3(c2ccccc2)c2ccccc2)cc(-c2cccc3c2Oc2ccccc2[Si]3(c2ccccc2)c2ccccc2)n1]

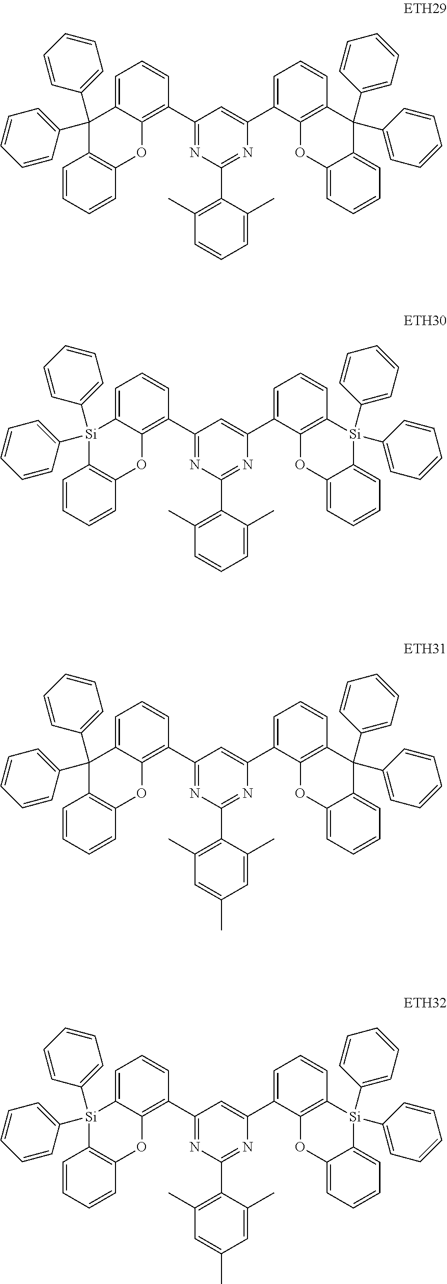 [SMILES: Cc1cccc(C)c1-c1nc(-c2cccc3c2Oc2ccccc2C3(c2ccccc2)c2ccccc2)cc(-c2cccc3c2Oc2ccccc2C3(c2ccccc2)c2ccccc2)n1 ; Cc1cccc(C)c1-c1nc(-c2cccc3c2Oc2ccccc2[Si]3(c2ccccc2)c2ccccc2)cc(-c2cccc3c2Oc2ccccc2[Si]3(c2ccccc2)c2ccccc2)n1 ; Cc1cc(C)c(-c2nc(-c3cccc4c3Oc3ccccc3C4(c3ccccc3)c3ccccc3)cc(-c3cccc4c3Oc3ccccc3C4(c3ccccc3)c3ccccc3)n2)c(C)c1 ; Cc1cc(C)c(-c2nc(-c3cccc4c3Oc3ccccc3[Si]4(c3ccccc3)c3ccccc3)cc(-c3cccc4c3Oc3ccccc3[Si]4(c3ccccc3)c3ccccc3)n2)c(C)c1]

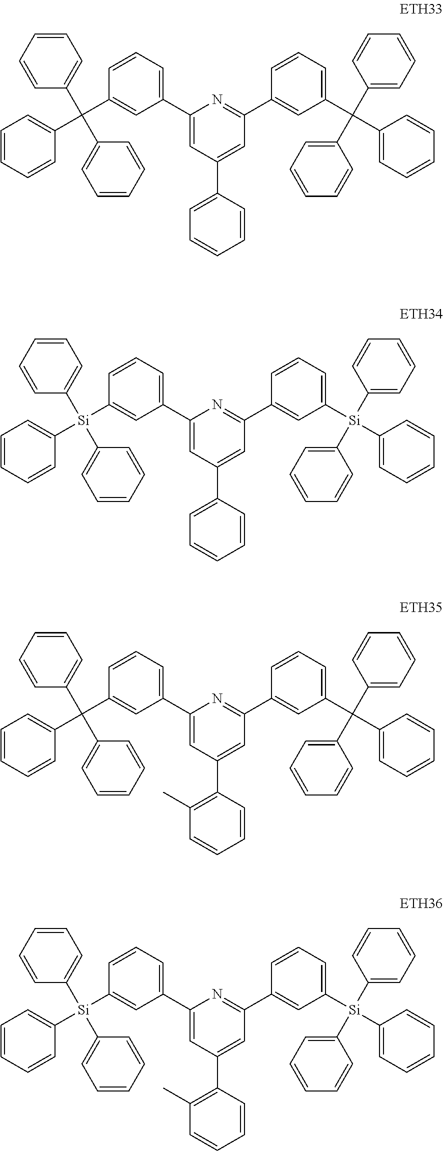 [SMILES: c1ccc(-c2cc(-c3cccc(C(c4ccccc4)(c4ccccc4)c4ccccc4)c3)nc(-c3cccc(C(c4ccccc4)(c4ccccc4)c4ccccc4)c3)c2)cc1 ; c1ccc(-c2cc(-c3cccc([Si](c4ccccc4)(c4ccccc4)c4ccccc4)c3)nc(-c3cccc([Si](c4ccccc4)(c4ccccc4)c4ccccc4)c3)c2)cc1 ; Cc1ccccc1-c1cc(-c2cccc(C(c3ccccc3)(c3ccccc3)c3ccccc3)c2)nc(-c2cccc(C(c3ccccc3)(c3ccccc3)c3ccccc3)c2)c1 ; Cc1ccccc1-c1cc(-c2cccc([Si](c3ccccc3)(c3ccccc3)c3ccccc3)c2)nc(-c2cccc([Si](c3ccccc3)(c3ccccc3)c3ccccc3)c2)c1]

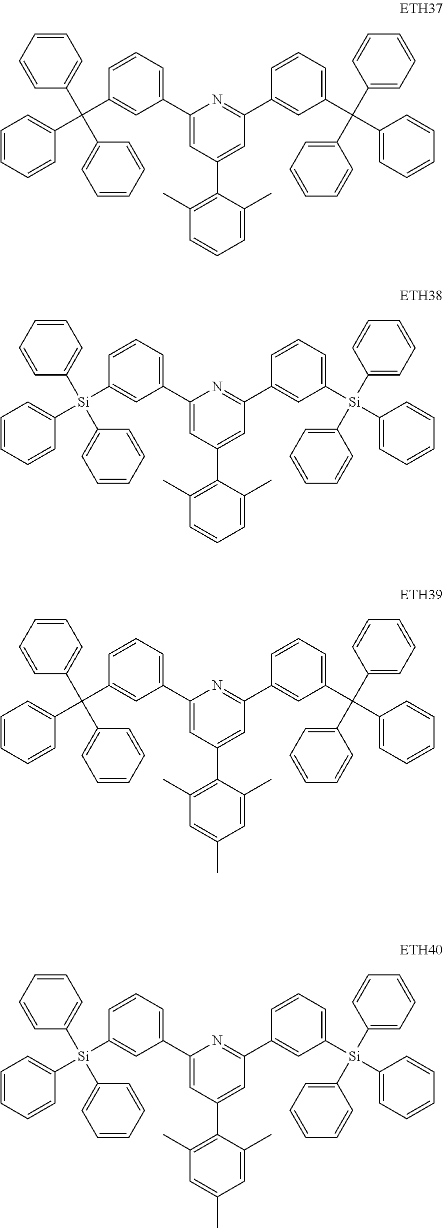 [SMILES: Cc1cccc(C)c1-c1cc(-c2cccc(C(c3ccccc3)(c3ccccc3)c3ccccc3)c2)nc(-c2cccc(C(c3ccccc3)(c3ccccc3)c3ccccc3)c2)c1 ; Cc1cccc(C)c1-c1cc(-c2cccc([Si](c3ccccc3)(c3ccccc3)c3ccccc3)c2)nc(-c2cccc([Si](c3ccccc3)(c3ccccc3)c3ccccc3)c2)c1 ; Cc1cc(C)c(-c2cc(-c3cccc(C(c4ccccc4)(c4ccccc4)c4ccccc4)c3)nc(-c3cccc(C(c4ccccc4)(c4ccccc4)c4ccccc4)c3)c2)c(C)c1 ; Cc1cc(C)c(-c2cc(-c3cccc([Si](c4ccccc4)(c4ccccc4)c4ccccc4)c3)nc(-c3cccc([Si](c4ccccc4)(c4ccccc4)c4ccccc4)c3)c2)c(C)c1]

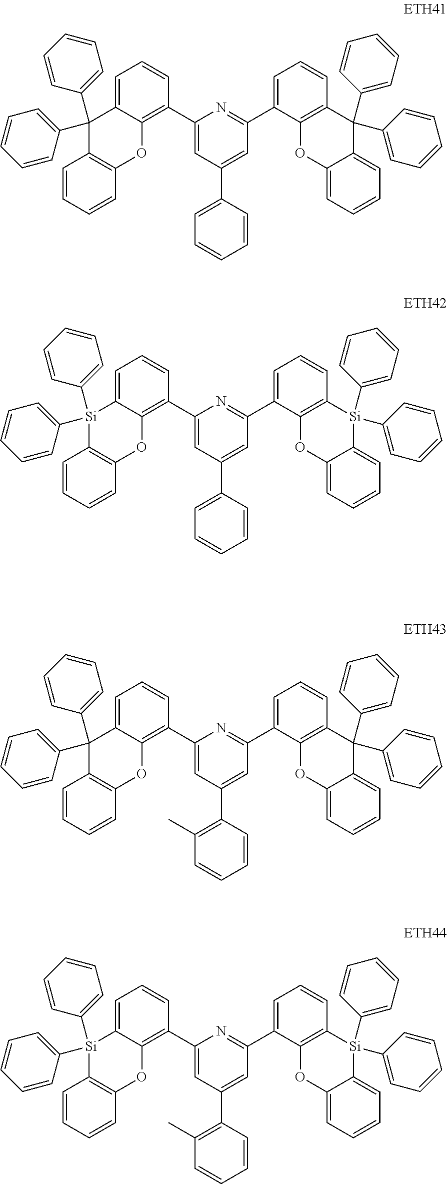 [SMILES: c1ccc(-c2cc(-c3cccc4c3Oc3ccccc3C4(c3ccccc3)c3ccccc3)nc(-c3cccc4c3Oc3ccccc3C4(c3ccccc3)c3ccccc3)c2)cc1 ; c1ccc(-c2cc(-c3cccc4c3Oc3ccccc3[Si]4(c3ccccc3)c3ccccc3)nc(-c3cccc4c3Oc3ccccc3[Si]4(c3ccccc3)c3ccccc3)c2)cc1 ; Cc1ccccc1-c1cc(-c2cccc3c2Oc2ccccc2C3(c2ccccc2)c2ccccc2)nc(-c2cccc3c2Oc2ccccc2C3(c2ccccc2)c2ccccc2)c1 ; Cc1ccccc1-c1cc(-c2cccc3c2Oc2ccccc2[Si]3(c2ccccc2)c2ccccc2)nc(-c2cccc3c2Oc2ccccc2[Si]3(c2ccccc2)c2ccccc2)c1]

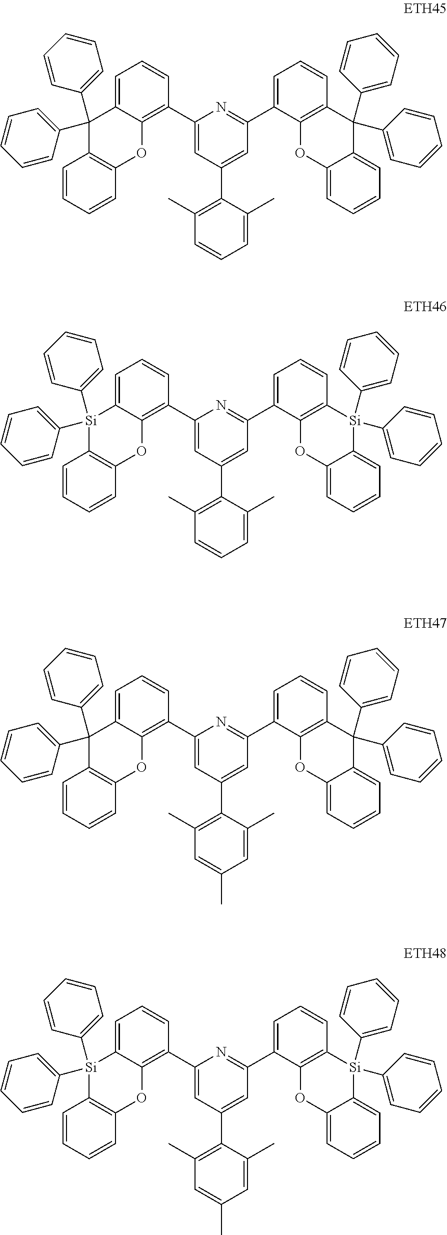 [SMILES: Cc1cccc(C)c1-c1cc(-c2cccc3c2Oc2ccccc2C3(c2ccccc2)c2ccccc2)nc(-c2cccc3c2Oc2ccccc2C3(c2ccccc2)c2ccccc2)c1 ; Cc1cccc(C)c1-c1cc(-c2cccc3c2Oc2ccccc2[Si]3(c2ccccc2)c2ccccc2)nc(-c2cccc3c2Oc2ccccc2[Si]3(c2ccccc2)c2ccccc2)c1 ; Cc1cc(C)c(-c2cc(-c3cccc4c3Oc3ccccc3C4(c3ccccc3)c3ccccc3)nc(-c3cccc4c3Oc3ccccc3C4(c3ccccc3)c3ccccc3)c2)c(C)c1 ; Cc1cc(C)c(-c2cc(-c3cccc4c3Oc3ccccc3[Si]4(c3ccccc3)c3ccccc3)nc(-c3cccc4c3Oc3ccccc3[Si]4(c3ccccc3)c3ccccc3)c2)c(C)c1]

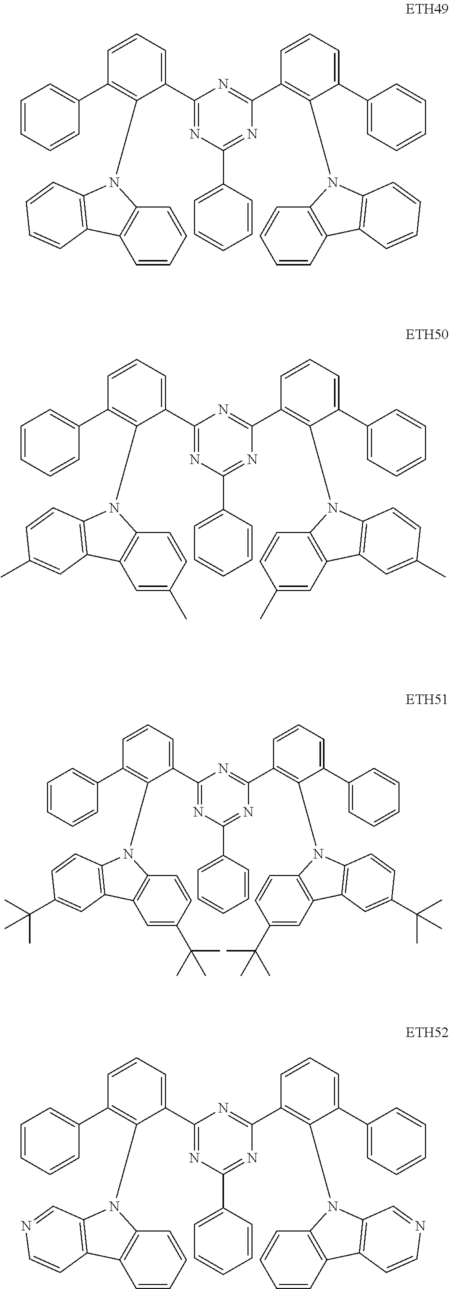

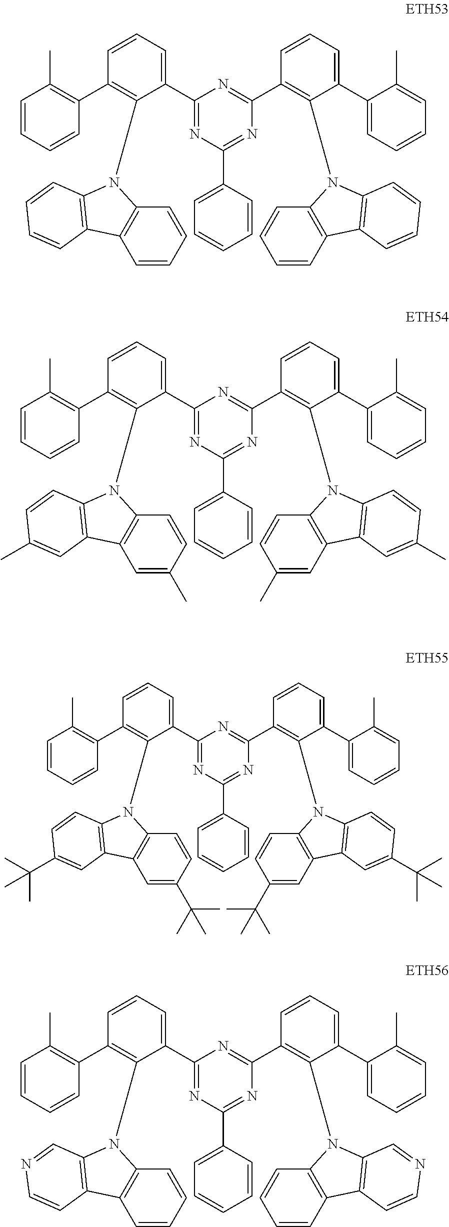

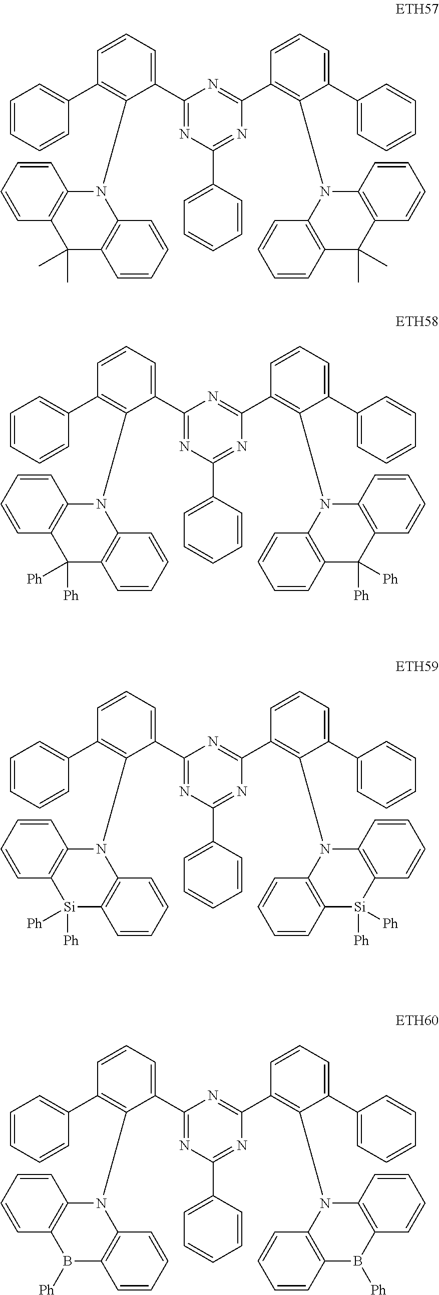

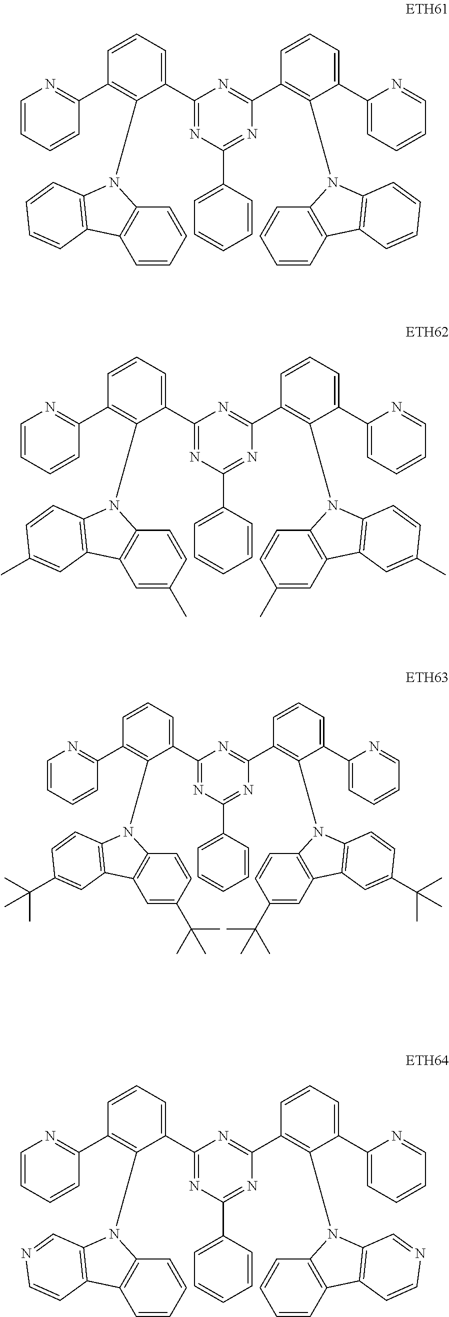

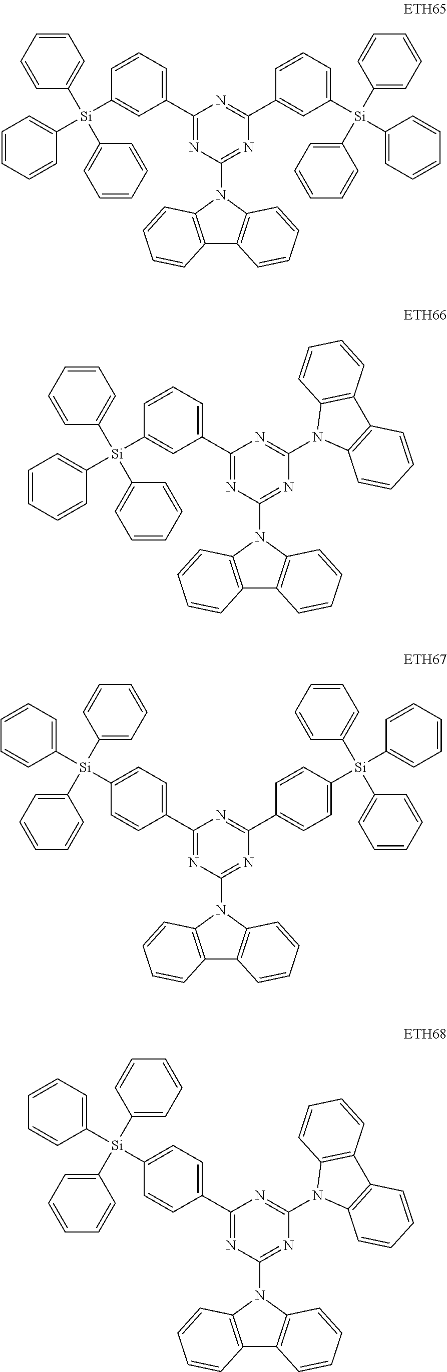 [SMILES: c1ccc([Si](c2ccccc2)(c2ccccc2)c2cccc(-c3nc(-c4cccc([Si](c5ccccc5)(c5ccccc5)c5ccccc5)c4)nc(-n4c5ccccc5c5ccccc54)n3)c2)cc1 ; c1ccc([Si](c2ccccc2)(c2ccccc2)c2cccc(-c3nc(-n4c5ccccc5c5ccccc54)nc(-n4c5ccccc5c5ccccc54)n3)c2)cc1 ; c1ccc([Si](c2ccccc2)(c2ccccc2)c2ccc(-c3nc(-c4ccc([Si](c5ccccc5)(c5ccccc5)c5ccccc5)cc4)nc(-n4c5ccccc5c5ccccc54)n3)cc2)cc1 ; c1ccc([Si](c2ccccc2)(c2ccccc2)c2ccc(-c3nc(-n4c5ccccc5c5ccccc54)nc(-n4c5ccccc5c5ccccc54)n3)cc2)cc1]

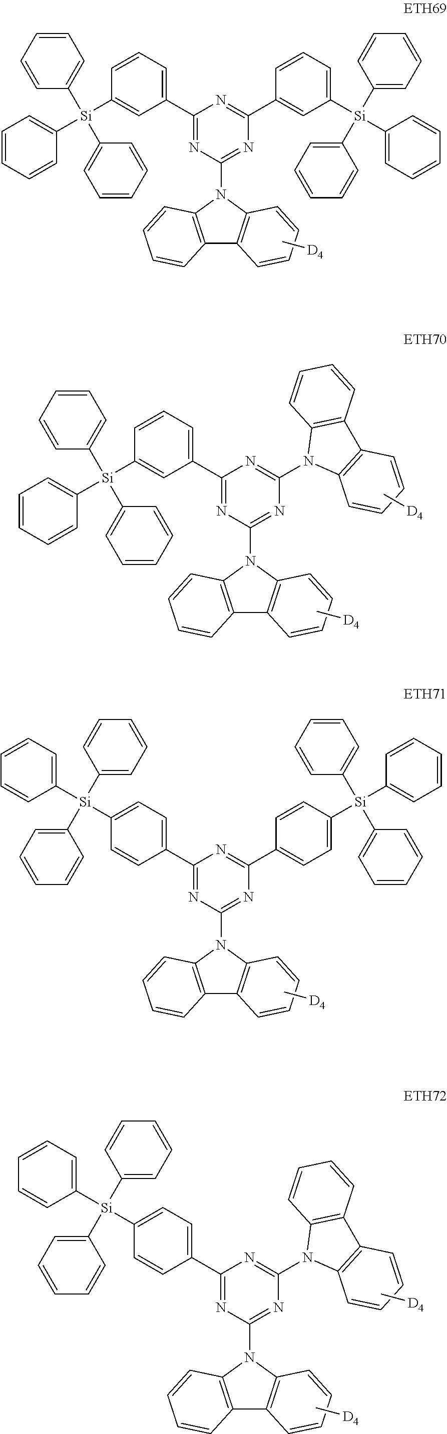

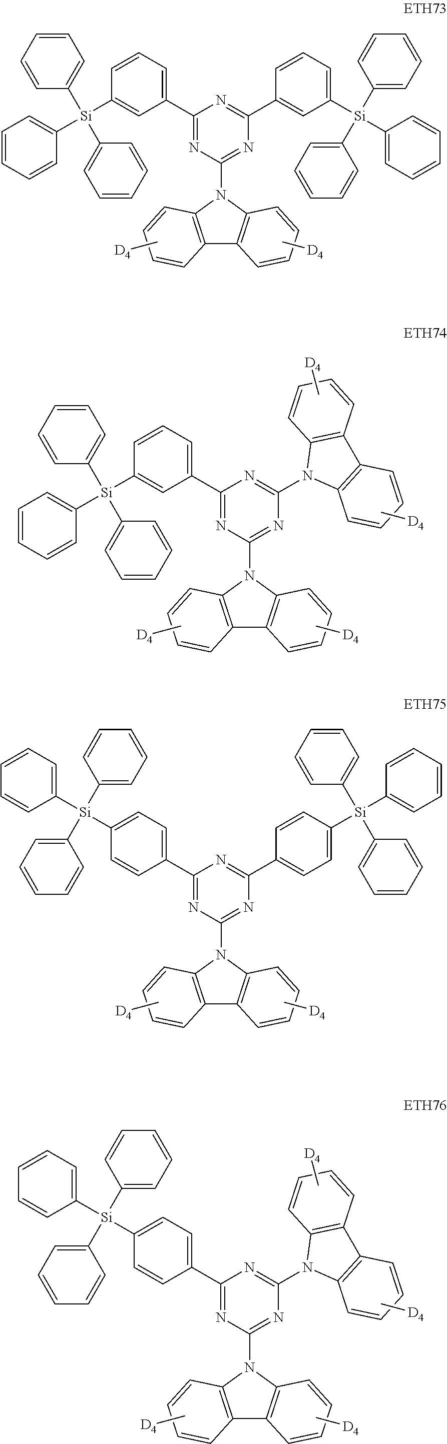

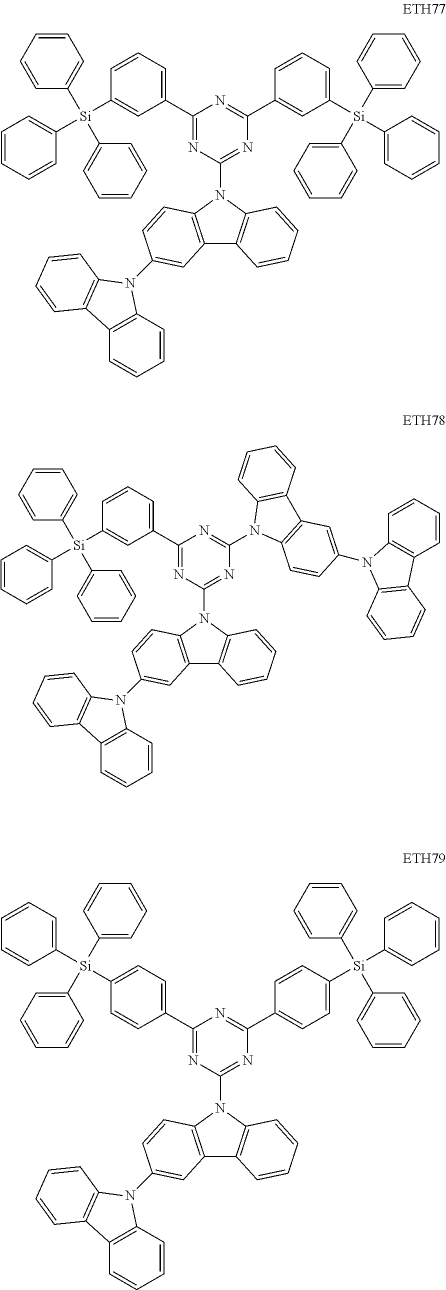 [SMILES: c1ccc([Si](c2ccccc2)(c2ccccc2)c2cccc(-c3nc(-c4cccc([Si](c5ccccc5)(c5ccccc5)c5ccccc5)c4)nc(-n4c5ccccc5c5cc(-n6c7ccccc7c7ccccc76)ccc54)n3)c2)cc1 ; c1ccc([Si](c2ccccc2)(c2ccccc2)c2cccc(-c3nc(-n4c5ccccc5c5cc(-n6c7ccccc7c7ccccc76)ccc54)nc(-n4c5ccccc5c5cc(-n6c7ccccc7c7ccccc76)ccc54)n3)c2)cc1 ; c1ccc([Si](c2ccccc2)(c2ccccc2)c2ccc(-c3nc(-c4ccc([Si](c5ccccc5)(c5ccccc5)c5ccccc5)cc4)nc(-n4c5ccccc5c5cc(-n6c7ccccc7c7ccccc76)ccc54)n3)cc2)cc1]

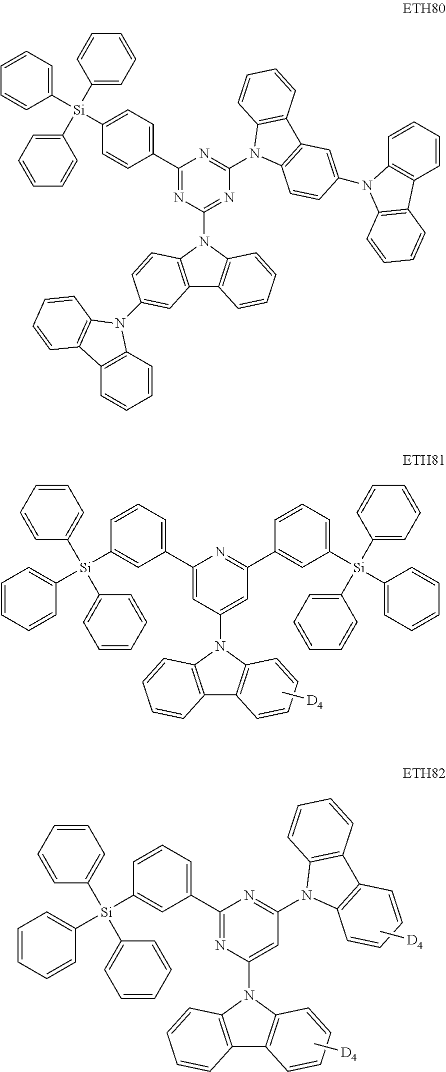

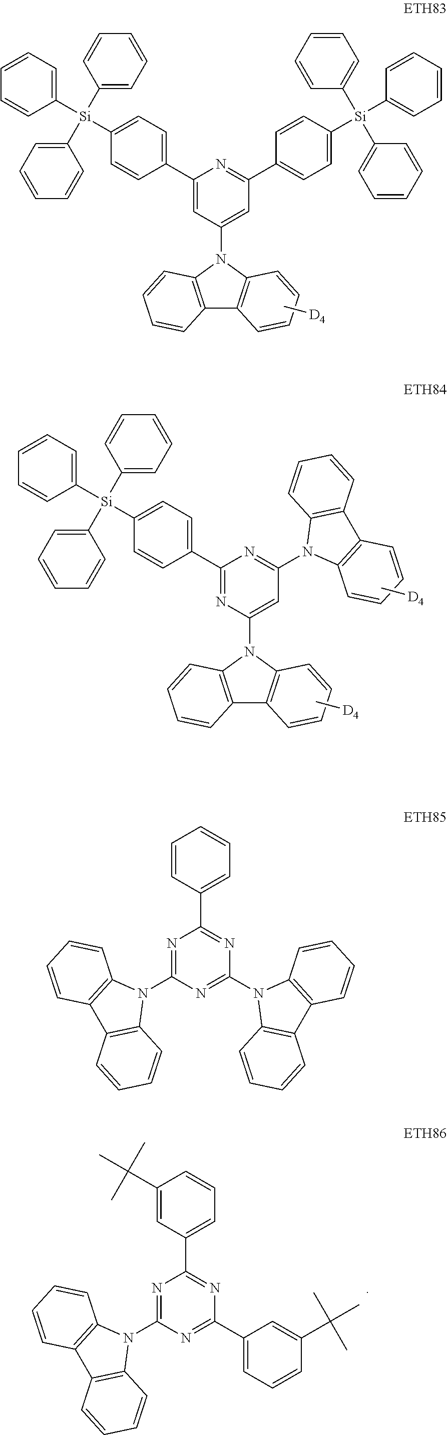

In the embodiment compounds presented in Compound Group 3, “D” refers to deuterium, and “Ph” refers to an unsubstituted phenyl group.

In one or more embodiments, the emission layer EML may include the second compound and the third compound, and the second compound and the third compound may form an exciplex. In the emission layer EML, an exciplex may be formed by the hole transporting host and the electron transporting host. In this regard, a triplet energy of the exciplex formed by the hole transporting host and the electron transporting host may correspond to a difference between a lowest unoccupied molecular orbital (LUMO) energy level of the electron transporting host and a highest occupied molecular orbital (HOMO) energy level of the hole transporting host.

For example, in one or more embodiments, an absolute value of the triplet energy (T1) of the exciplex formed by the hole transporting host and the electron transporting host may be about 2.4 eV to about 3.0 eV. In addition, the triplet energy of the exciplex may be a value smaller than an energy gap of each host material. The exciplex may have a triplet energy of about 3.0 eV or less that is an energy gap between the hole transporting host and the electron transporting host.

In one or more embodiments, the emission layer EML may include a fourth compound in addition to the first compound to the third compound as described above. The fourth compound may be used as a phosphorescent sensitizer of the emission layer EML. The energy may be transferred from the fourth compound to the first compound, thereby emitting light.

For example, in one or more embodiments, the emission layer EML may include, as the fourth compound, an organometallic complex containing platinum (Pt) as a central metal atom and ligands linked to the central metal atom. The emission layer EML in the light emitting element ED of one or more embodiments may include, as the fourth compound, a compound represented by Formula D-1:

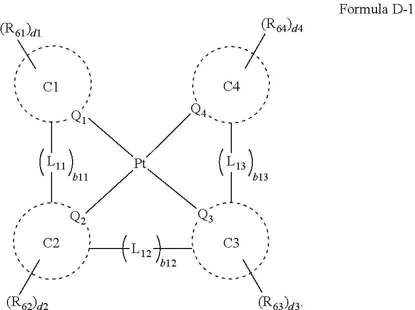

In Formula D-1, Q₁ to Q₄ may each independently be C or N.

In Formula D-1, C1 to C4 may each independently be a substituted or unsubstituted hydrocarbon ring having 5 to 30 ring-forming carbon atoms or a substituted or unsubstituted heterocycle having 2 to 30 ring-forming carbon atoms.

In Formula D-1, L₁₁ to L₁₃ may each independently be a direct linkage,

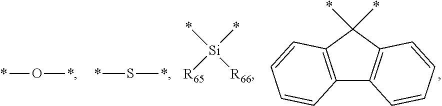

a substituted or unsubstituted alkylene group having 1 to 20 carbon atoms, a substituted or unsubstituted arylene group having 6 to 30 ring-forming carbon atoms, or a substituted or unsubstituted heteroarylene group having 2 to 30 ring-forming carbon atoms. In L₁₁ to L₁₃, [symbol] refers to a part linked to C1 to C4.

In Formula D-1, b11 to b13 may each independently be 0 or 1. If (e.g., when) b11 is 0, C1 and C2 may not be linked to each other. If (e.g., when) b12 is 0, C2 and C3 may not be linked to each other. If (e.g., when) b13 is 0, C3 and C4 may not be linked to each other.

In Formula D-1, R₆₁ to R₆₆ may each independently be hydrogen, deuterium, a halogen, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms. In one or more embodiments, one or more selected from among R₆₁ to R₆₆ may be independently bonded to an adjacent group to form a ring. In one or more embodiments, R₆₁ to R₆₆ may each independently be a substituted or unsubstituted methyl group or a substituted or unsubstituted t-butyl group.

In Formula D-1, d1 to d4 may each independently be an integer of 0 to 4. In Formula D-1, if (e.g., when) each of d1 to d4 is 0, the fourth compound may not be substituted with each of R₆₁ to R₆₄. The embodiment in which each of d1 to d4 is 4 and R₆₁'s to R₆₄′ are each hydrogen may be the same as the embodiment in which each of d1 to d4 is 0. If (e.g., when) each of d1 to d4 is an integer of 2 or greater, a plurality of R₆₁'s to R₆₄'s may each be the same or at least one selected from among the plurality of R₆₁'s to R₆₄'s may be different from the others.

In Formula D-1, C1 to C4 may each independently be a substituted or unsubstituted hydrocarbon ring or a substituted or unsubstituted heterocycle represented by any one selected from among C-1 to C-4:

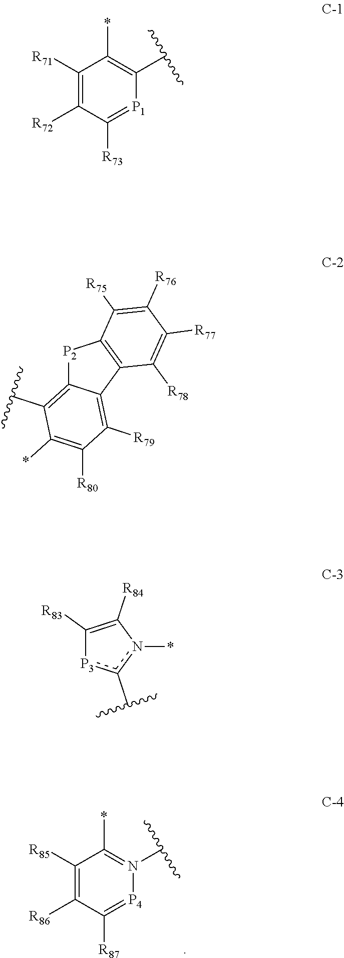

In C-1 to C-4, P₁ may be C—* or CR₇₄, P₂ may be N—* or NR₈₁, P₃ may be N—* or NR₈₂, and P₄ may be C—* or CR₈₈. R₇₁ to R₈₈ may each independently be a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and/or may be bonded to an adjacent group to form a ring.

In addition, in C-1 to C-4,

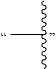

corresponds to a part linked to Pt that is a central metal atom, and “ [symbol] ” corresponds to a part linked to a neighboring cyclic group (C1 to C4) or an adjacent linker (L₁₁ to L₁₃).

The emission layer EML of one or more embodiments may include the first compound, which is a fused polycyclic compound represented by Formula 1, and at least one selected from among the second to fourth compounds. For example, in one or more embodiments, the emission layer EML may include the first compound, the second compound, and the third compound. In the emission layer EML, the second compound and the third compound may form an exciplex, and the energy may be transferred from the exciplex to the first compound, thereby emitting light.

In one or more embodiments, the emission layer EML may include the first compound, the second compound, the third compound, and the fourth compound. In the emission layer EML, the second compound and the third compound may form an exciplex, and the energy may be transferred from the exciplex to the fourth compound and the first compound, thereby emitting light. In one or more embodiments, the fourth compound may be a sensitizer. The fourth compound included in the emission layer EML in the light emitting element ED of one or more embodiments may serve as a sensitizer to deliver energy from the host to the first compound that is a light emitting dopant. For example, in one or more embodiments, the fourth compound serving as an auxiliary dopant accelerates energy delivery to the first compound that is a light emitting dopant, thereby increasing the emission ratio of the first compound. Therefore, the emission layer EML of one or more embodiments may improve luminous efficiency. In addition, if (e.g., when) the energy delivery to the first compound is increased, an exciton formed in the emission layer EML is not accumulated inside the emission layer EML and instead emits light rapidly, and thus deterioration of the element may be reduced. Therefore, the service life of the light emitting element ED of one or more embodiments may increase.

The light emitting element ED of one or more embodiments may include all of the first compound, the second compound, the third compound, and the fourth compound, and the emission layer EML may include the combination of two host materials and two dopant materials. In the light emitting element ED of one or more embodiments, the emission layer EML may concurrently (e.g., simultaneously) include the second compound and the third compound, which are two different hosts, the first compound that emits a delayed fluorescence, and the fourth compound including an organometallic complex, thereby exhibiting excellent or suitable luminous efficiency characteristics.

In one or more embodiments, the fourth compound represented by Formula D-1 may be any one selected from among compounds represented by Compound Group 4. The emission layer EML may include at least one selected from among the compounds represented by Compound Group 4 as a sensitizer material.

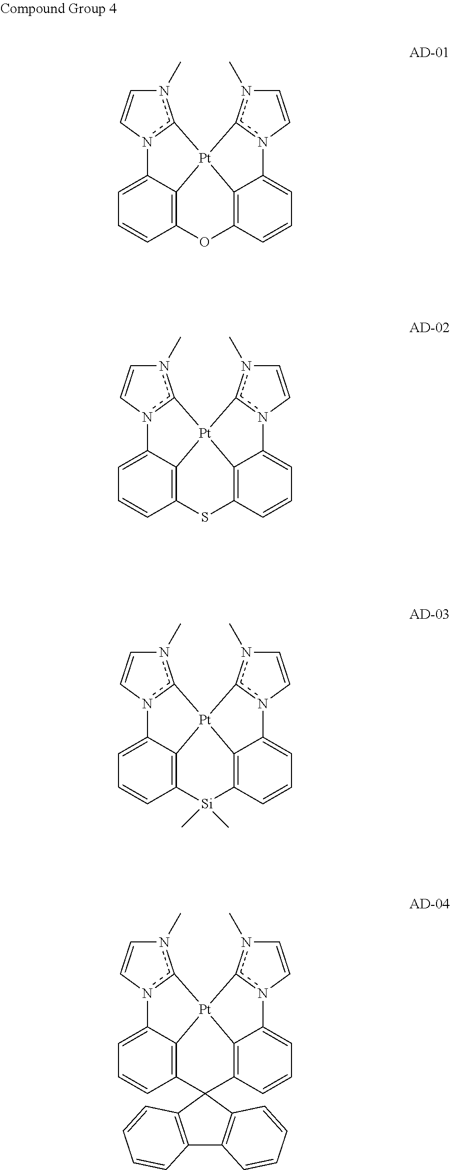

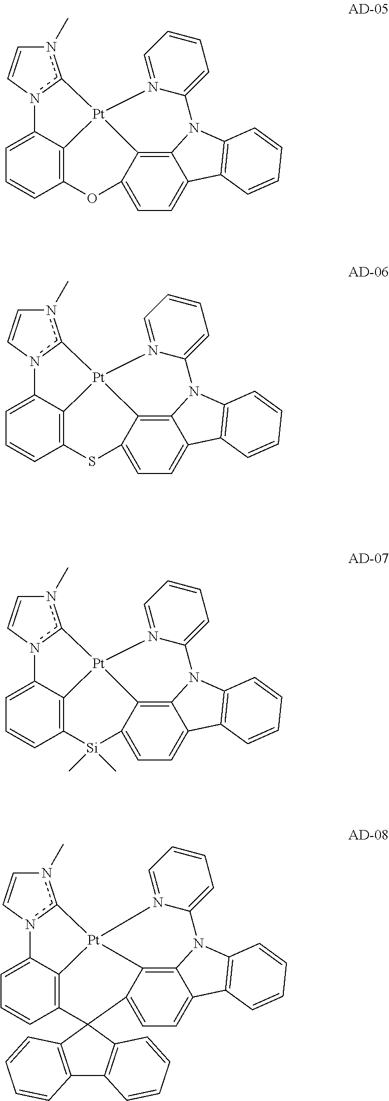

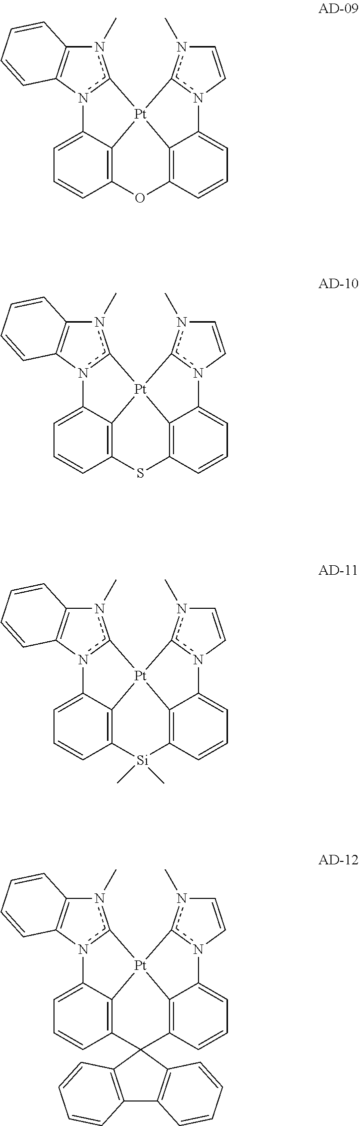

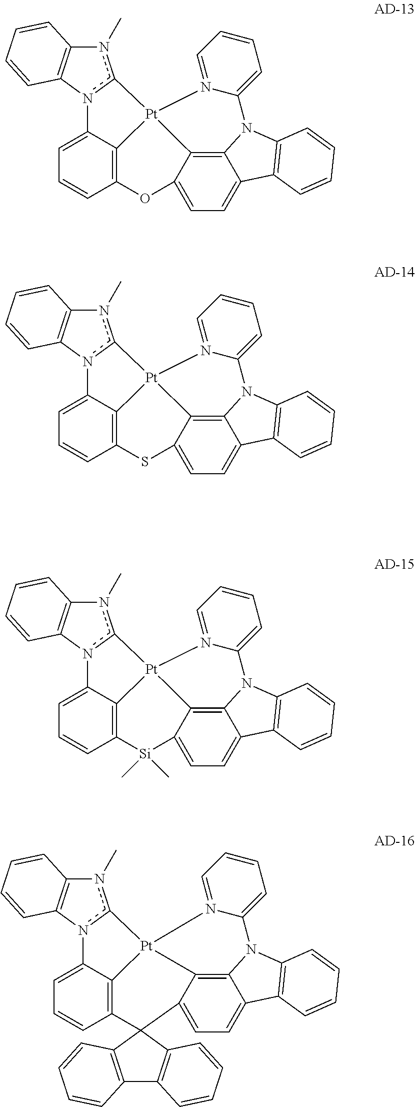

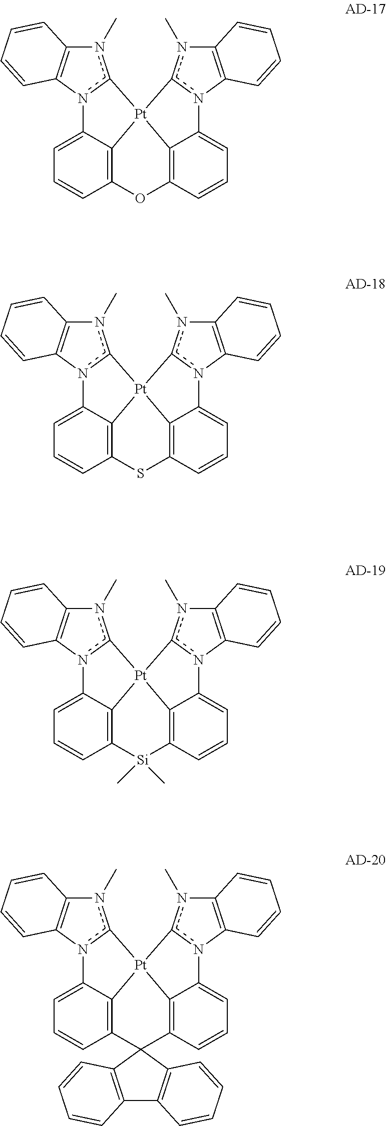

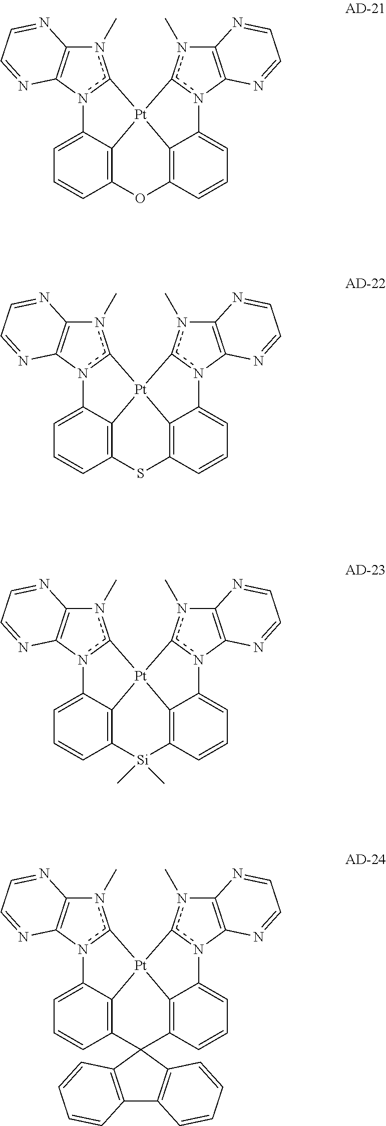

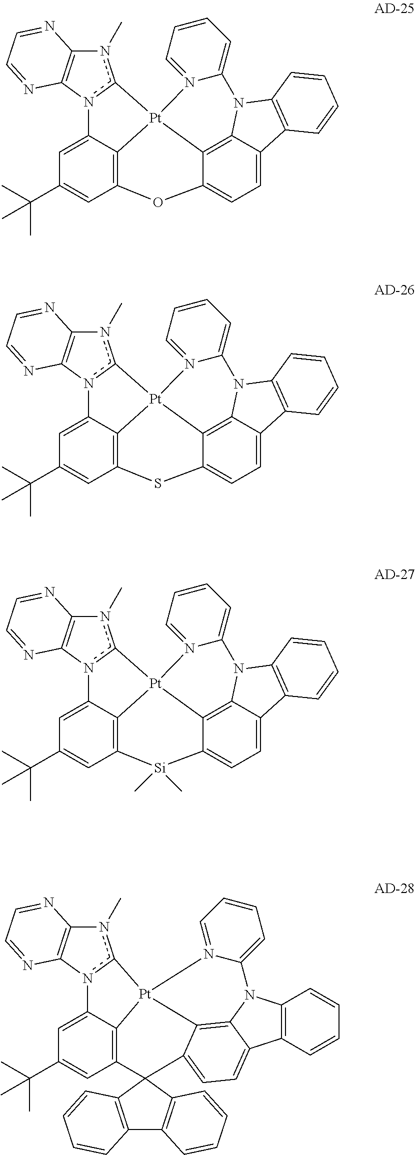

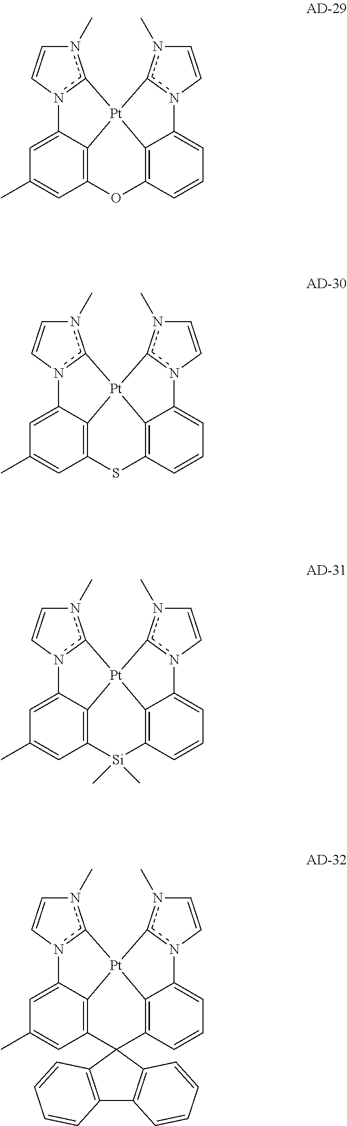

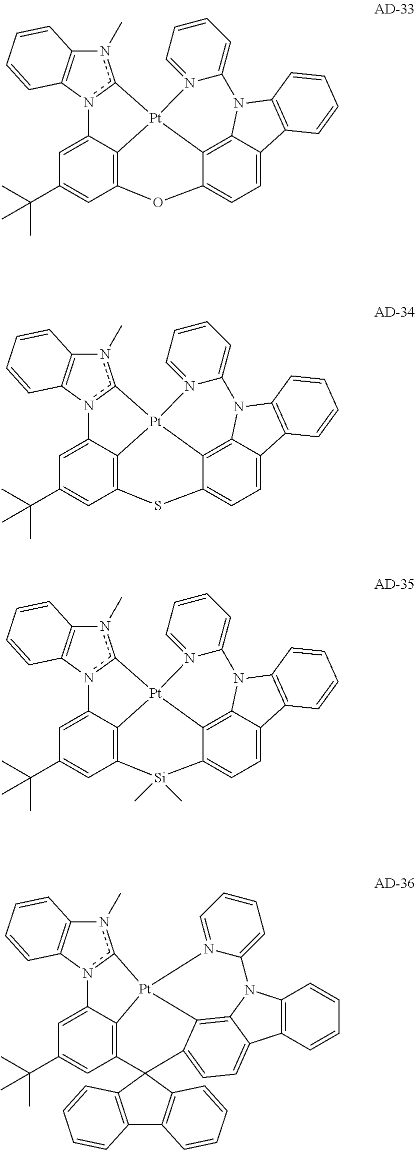

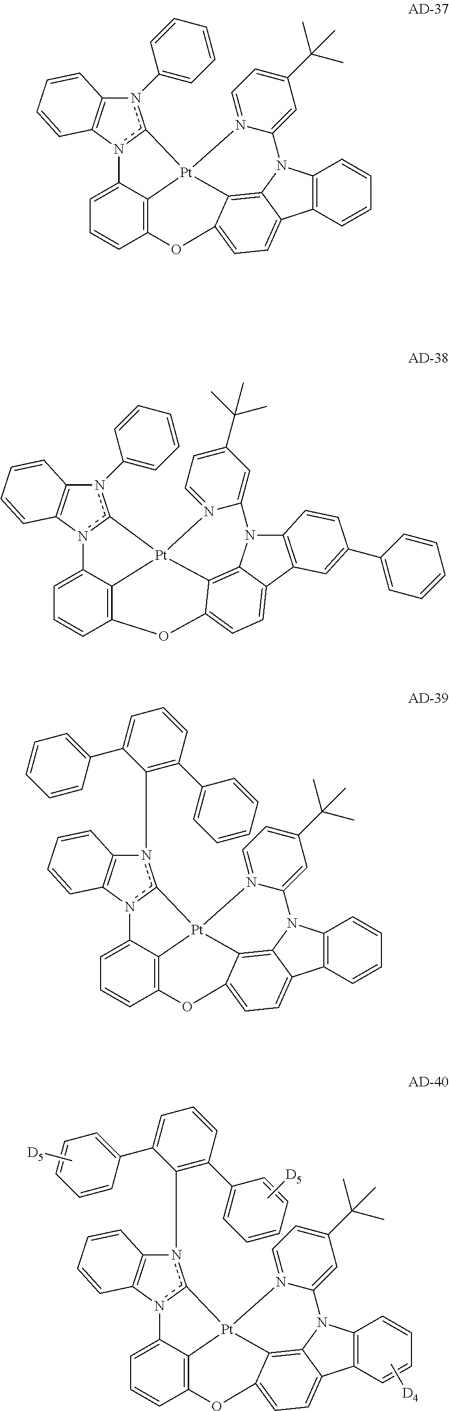

In the embodiment compounds presented in Compound Group 4, “D” refers to deuterium.

The light emitting element ED of one or more embodiments may include a plurality of emission layers. The plurality of emission layers may be sequentially stacked and provided, and for example, in one or more embodiments, the light emitting element ED including the plurality of emission layers may be to emit white color light. The light emitting element including the plurality of emission layers may be a light emitting element having a tandem structure. When the light emitting element ED includes a plurality of emission layers, at least one emission layer EML may include the first compound represented by Formula 1 of one or more embodiments. In one or more embodiments, if (e.g., when) the light emitting element ED includes the plurality of emission layers, at least one emission layer EML may include all of the first compound, the second compound, the third compound, and the fourth compound as described above.

When the emission layer EML in the light emitting element ED of one or more embodiments includes all of the first compound, the second compound, and the third compound, with respect to a total weight of the first compound, the second compound, and the third compound, the content (e.g., amount) of the first compound may be about 0.1 wt % to about 5 wt %. However, embodiments of the present disclosure are not limited thereto. When the content (e.g., amount) of the first compound satisfy the above-described proportion, the energy transfer from the second compound and the third compound to the first compound may increase, and thus the luminous efficiency and element service life may increase.

The contents (e.g., amounts) of the second compound and the third compound in the emission layer EML may be the rest excluding the weight of the first compound. For example, in one or more embodiments, the contents (e.g., amounts) of the second compound and the third compound in the emission layer EML may be about 65 wt % to about 95 wt % with respect to the total weight of the first compound, the second compound, and the third compound.

In the total weight of the second compound and the third compound, a weight ratio of the second compound to the third compound may be about 3:7 to about 7:3.

When the contents (e.g., amounts) of the second compound and the third compound satisfy the above-described ratio, a charge balance characteristic in the emission layer EML are improved, and thus the luminous efficiency and element service life may increase. When the contents (e.g., amounts) of the second compound and the third compound deviate from the above-described ratio range, a charge balance in the emission layer EML is broken, and thus the luminous efficiency may be reduced, and the element may be easily deteriorated.

In one or more embodiments, when the emission layer EML includes the fourth compound, the content (e.g., amount) of the fourth compound in the emission layer EML may be about 10 wt % to about 30 wt % with respect to a total weight of the first compound, the second compound, the third compound, and the fourth compound. However, embodiments of the present disclosure are not limited thereto. When the content (e.g., amount) of the fourth compound satisfies the above-described content (e.g., amount), the energy delivery from the host to the first compound which is a light emitting dopant may be increased, thereby a luminous ratio may be improved, and thus the luminous efficiency of the emission layer EML may be improved. When the first compound, the second compound, the third compound, and the fourth compound included in the emission layer EML satisfy the above-described content (e.g., amount) ratio range, excellent or suitable luminous efficiency and long service life of the light emitting element may be achieved. In the light emitting element ED of one or more embodiments, the emission layer EML may include at least one of an anthracene derivative, a pyrene derivative, a fluoranthene derivative, a chrysene derivative, a dihydrobenzanthracene derivative, or a triphenylene derivative. For example, in one or more embodiments, the emission layer EML may include the anthracene derivative and/or the pyrene derivative.

In each light emitting element ED of embodiments illustrated in FIG. 3 to 6, the emission layer EML may further include a suitable host and/or dopant besides the above-described host and dopant, and for example, in one or more embodiments, the emission layer EML may include a compound represented by Formula E-1. The compound represented by Formula E-1 may be used as a fluorescent host material.

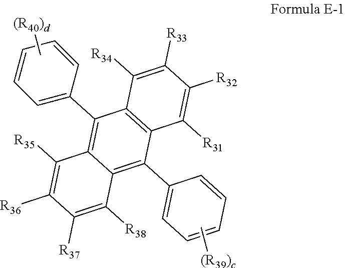

In Formula E-1, R₃₁ to R₄₀ may each independently be hydrogen, deuterium, a halogen, a substituted or unsubstituted silyl group, a substituted or unsubstituted thio group, a substituted or unsubstituted oxy group, a substituted or unsubstituted alkyl group having 1 to 10 carbon atoms, a substituted or unsubstituted alkenyl group having 2 to 10 carbon atoms, a substituted or unsubstituted aryl group having 6 to 30 ring-forming carbon atoms, or a substituted or unsubstituted heteroaryl group having 2 to 30 ring-forming carbon atoms, and/or may be bonded to an adjacent group to form a ring. In one or more embodiments, one or more selected from among R₃₁ to R₄₀ may be each independently bonded to an adjacent group to form a saturated hydrocarbon ring, an unsaturated hydrocarbon ring, a saturated heterocycle, or an unsaturated heterocycle.

In Formula E-1, c and d may each independently be an integer of 0 to 5.

The compound represented by Formula E-1 may be any one selected from among Compound E1 to Compound E19:

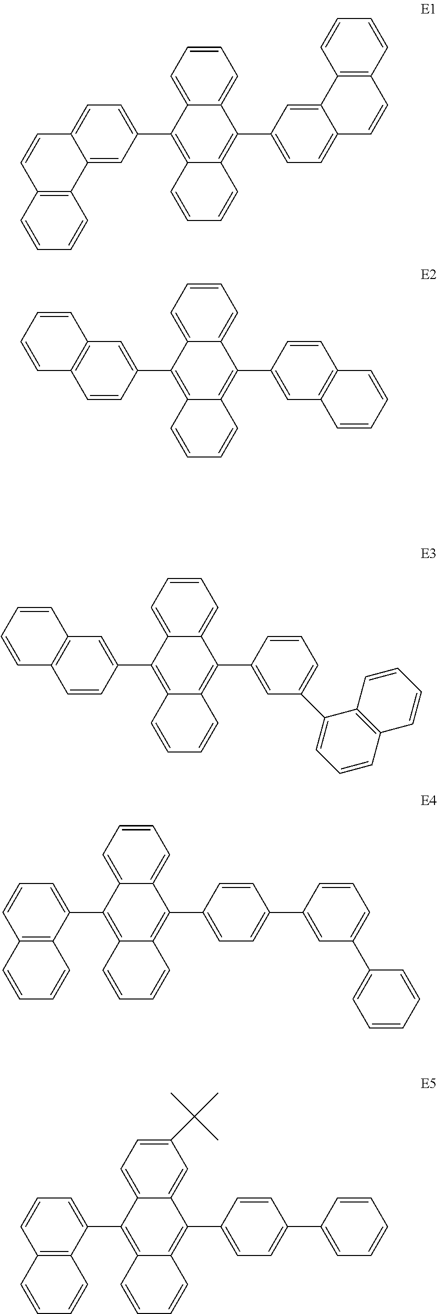

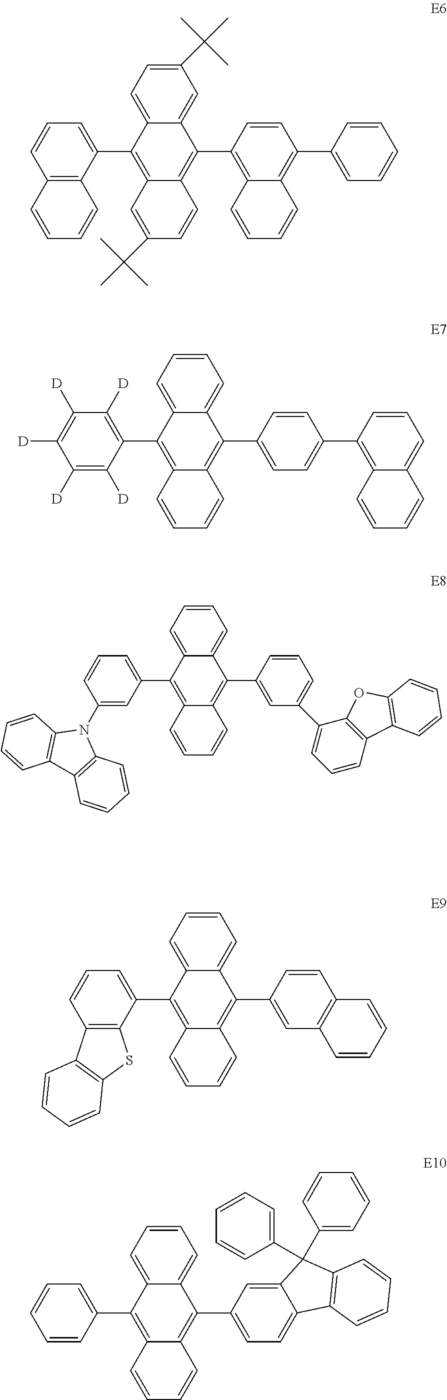

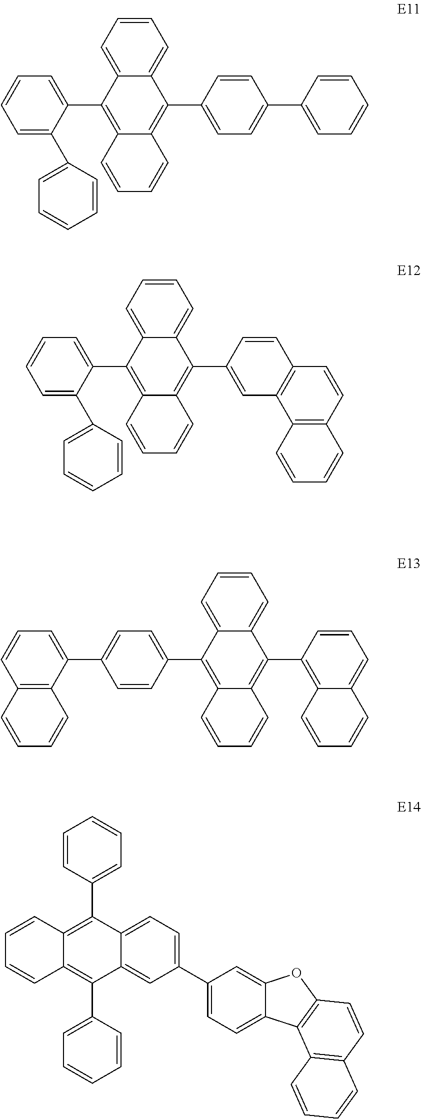

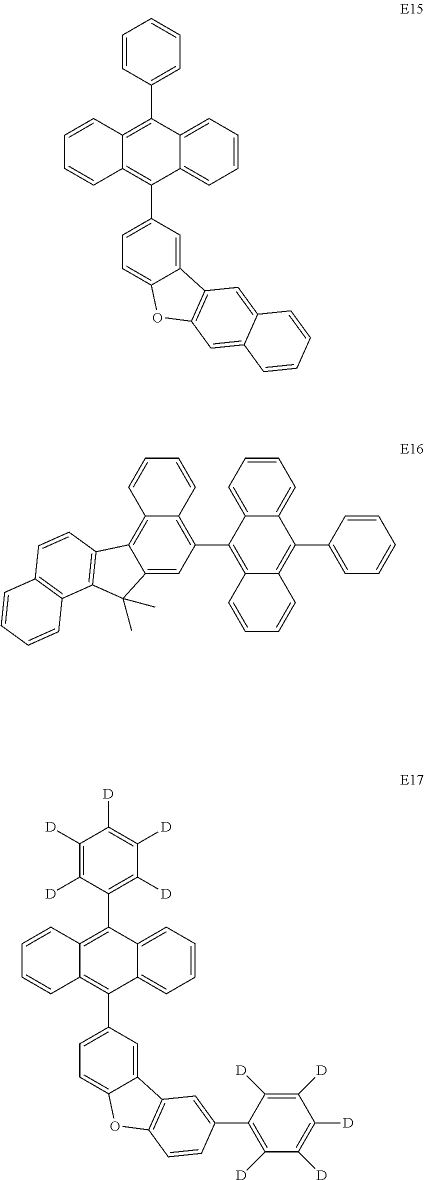

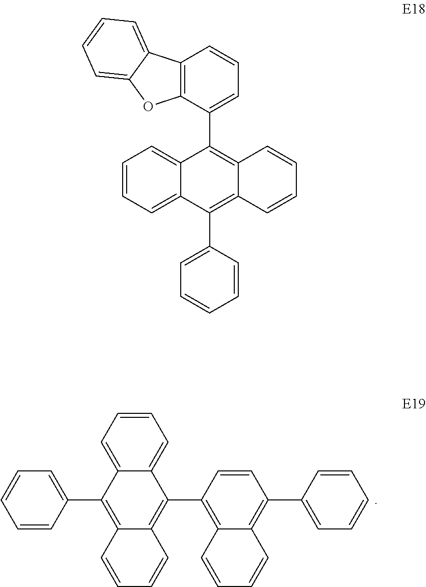

In one or more embodiments, the emission layer EML may include a compound represented by Formula E-2a or Formula E-2b. The compound represented by Formula E-2a or Formula E-2b may be used as a phosphorescent host material.

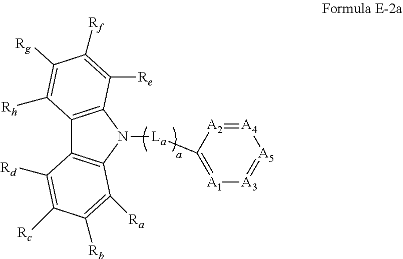

In Formula E-2a, a may be an integer of 0 to 10, and Lₐ may be a direct linkage, a substituted or unsubstituted arylene group having 6 to 30 ring-forming carbon atoms, or a substituted or unsubstituted heteroarylene group having 2 to 30 ring-forming carbon atoms. In one or more embodiments, if (e.g., when) a is an integer of 2 or greater, a plurality of Lₐ's may each independently be a substituted or unsubstituted arylene group having 6 to 30 ring-forming carbon atoms or a substituted or unsubstituted heteroarylene group having 2 to 30 ring-forming carbon atoms.

In addition, in Formula E-2a, A₁ to A₅ may each independently be N or CRᵢ. Rₐ to Rᵢ may each independently be hydrogen, deuterium, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or may be bonded to an adjacent group to form a ring. In one or more embodiments, one or more selected from among Rₐ to Rᵢ may be each independently bonded to an adjacent group to form a hydrocarbon ring or a heterocycle containing N, O, S, and/or the like, as a ring-forming atom.

In one or more embodiments, in Formula E-2a, two or three selected from among A₁ to A₅ may be N, and the rest may be CRᵢ.

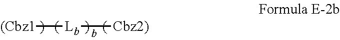

In Formula E-2b, Cbz1 and Cbz2 may each independently be an unsubstituted carbazole group or a carbazole group substituted with an aryl group having 6 to 30 ring-forming carbon atoms. L_{b} may be a direct linkage, a substituted or unsubstituted arylene group having 6 to 30 ring-forming carbon atoms, or a substituted or unsubstituted heteroarylene group having 2 to 30 ring-forming carbon atoms. b is an integer of 0 to 10, and if (e.g., when) b is an integer of 2 or greater, a plurality of L_{b}'s may each independently be a substituted or unsubstituted arylene group having 6 to 30 ring-forming carbon atoms or a substituted or unsubstituted heteroarylene group having 2 to 30 ring-forming carbon atoms.

The compound represented by Formula E-2a or Formula E-2b may be any one selected from among compounds of Compound Group E-2. However, the compounds listed in Compound Group E-2 are mere examples, and the compound represented by Formula E-2a or Formula E-2b is not limited to those represented in Compound Group E-2.

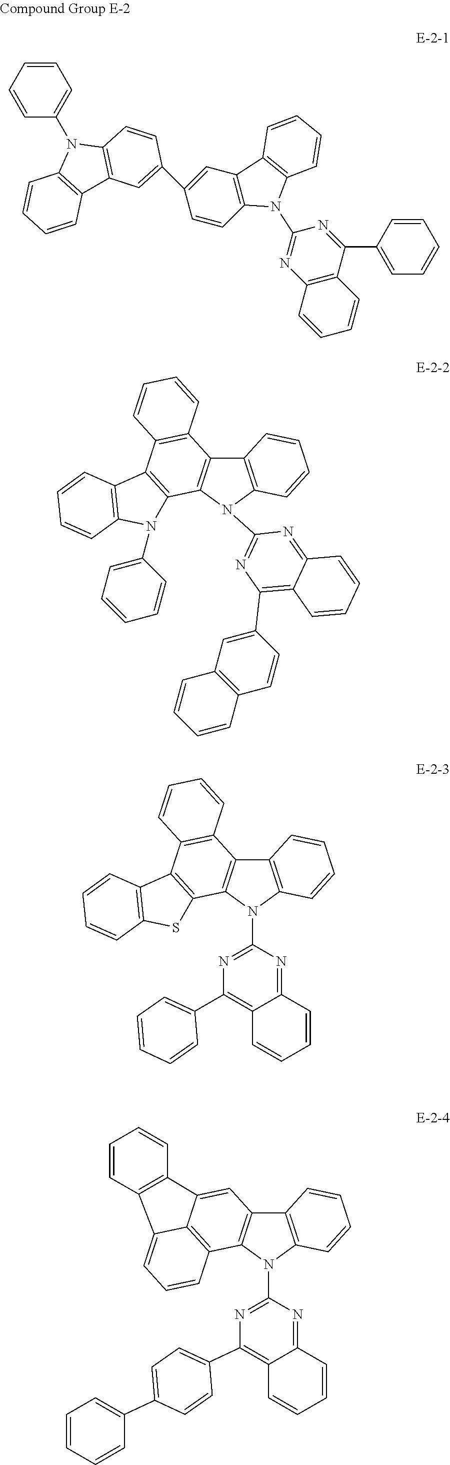

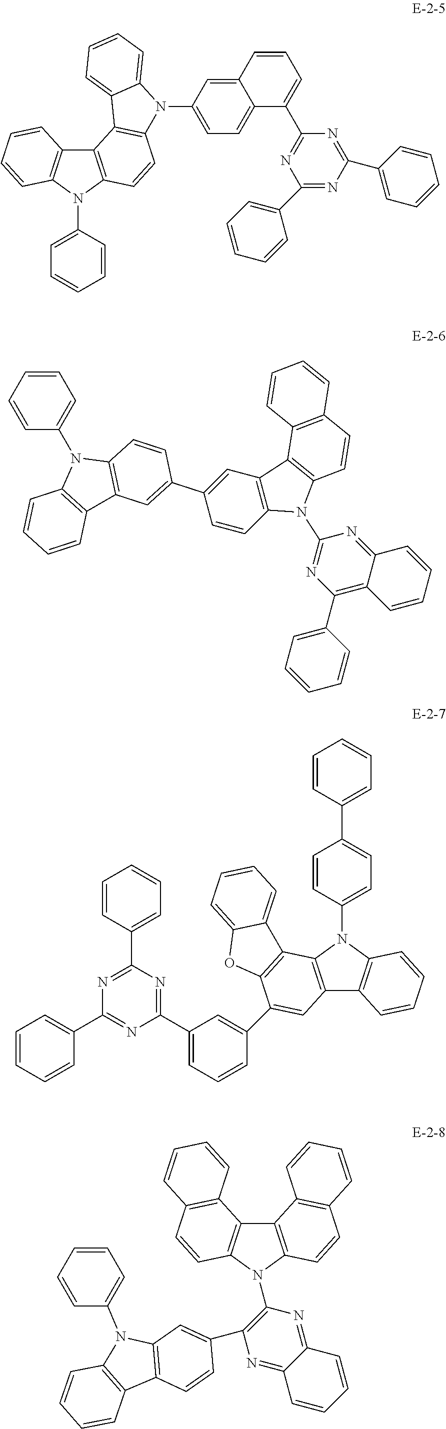 [SMILES: c1ccc(-c2nc(-c3ccccc3)nc(-c3cccc4cc(-n5c6ccccc6c6c7c8ccccc8n(-c8ccccc8)c7ccc65)ccc34)n2)cc1 ; c1ccc(-c2nc(-n3c4ccc(-c5ccc6c(c5)c5ccccc5n6-c5ccccc5)cc4c4c5ccccc5ccc43)nc3ccccc23)cc1 ; c1ccc(-c2ccc(-n3c4ccccc4c4cc(-c5cccc(-c6nc(-c7ccccc7)nc(-c7ccccc7)n6)c5)c5oc6ccccc6c5c43)cc2)cc1 ; c1ccc(-n2c3ccccc3c3ccc(-c4nc5ccccc5nc4-n4c5ccc6ccccc6c5c5c6ccccc6ccc54)cc32)cc1]

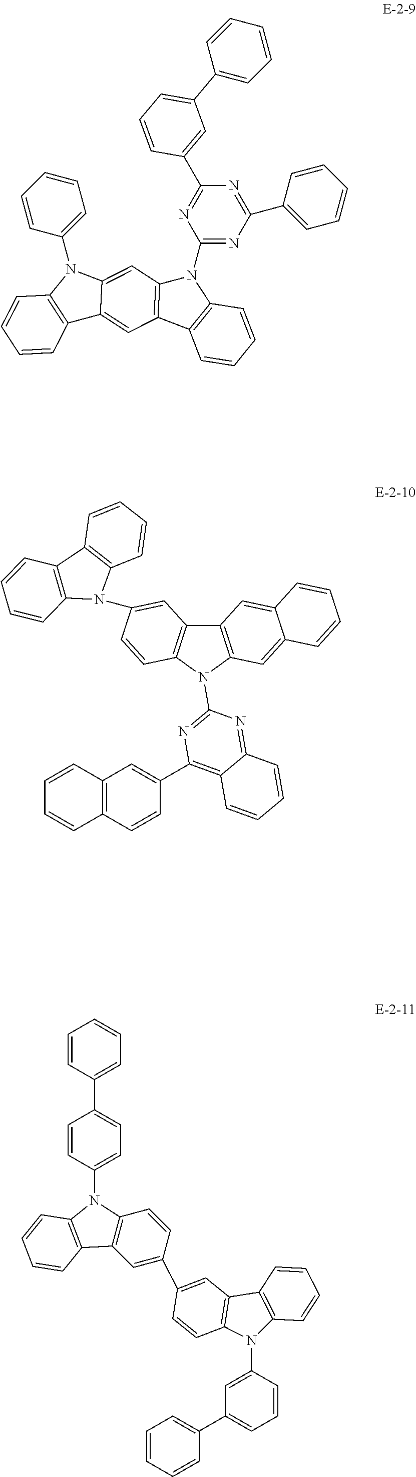 [SMILES: c1ccc(-c2cccc(-c3nc(-c4ccccc4)nc(-n4c5ccccc5c5cc6c7ccccc7n(-c7ccccc7)c6cc54)n3)c2)cc1 ; c1ccc2cc(-c3nc(-n4c5ccc(-n6c7ccccc7c7ccccc76)cc5c5cc6ccccc6cc54)nc4ccccc34)ccc2c1 ; c1ccc(-c2ccc(-n3c4ccccc4c4cc(-c5ccc6c(c5)c5ccccc5n6-c5cccc(-c6ccccc6)c5)ccc43)cc2)cc1]

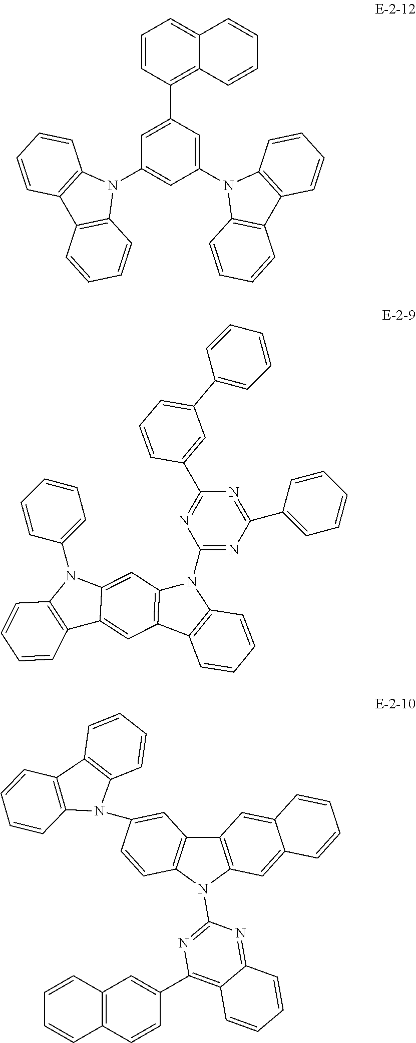 [SMILES: c1ccc2c(-c3cc(-n4c5ccccc5c5ccccc54)cc(-n4c5ccccc5c5ccccc54)c3)cccc2c1 ; c1ccc(-c2cccc(-c3nc(-c4ccccc4)nc(-n4c5ccccc5c5cc6c7ccccc7n(-c7ccccc7)c6cc54)n3)c2)cc1 ; c1ccc2cc(-c3nc(-n4c5ccc(-n6c7ccccc7c7ccccc76)cc5c5cc6ccccc6cc54)nc4ccccc34)ccc2c1]

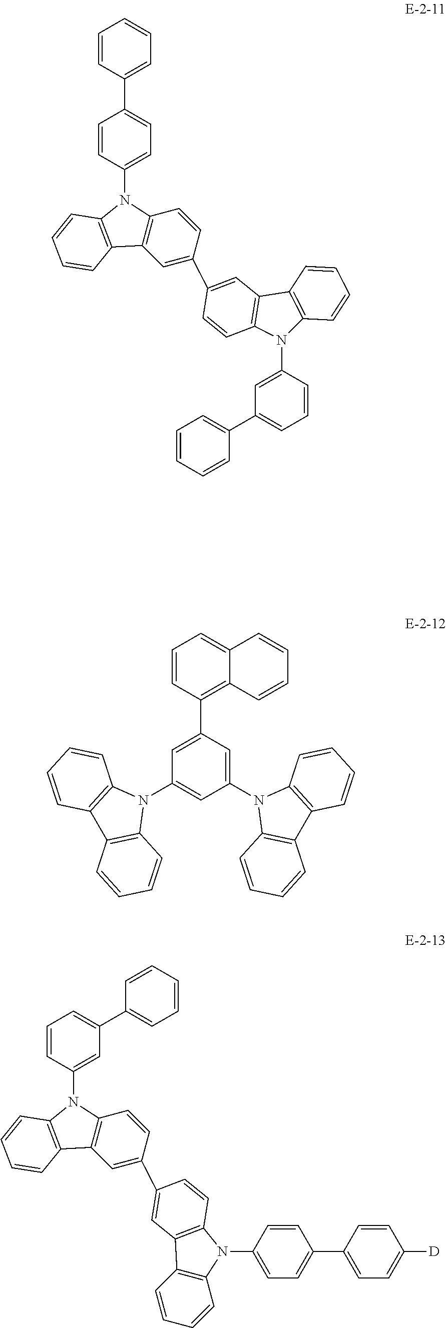 [SMILES: c1ccc(-c2ccc(-n3c4ccccc4c4cc(-c5ccc6c(c5)c5ccccc5n6-c5cccc(-c6ccccc6)c5)ccc43)cc2)cc1 ; c1ccc2c(-c3cc(-n4c5ccccc5c5ccccc54)cc(-n4c5ccccc5c5ccccc54)c3)cccc2c1 ; [2H]c1ccc(-c2ccc(-n3c4ccccc4c4cc(-c5ccc6c(c5)c5ccccc5n6-c5cccc(-c6ccccc6)c5)ccc43)cc2)cc1]

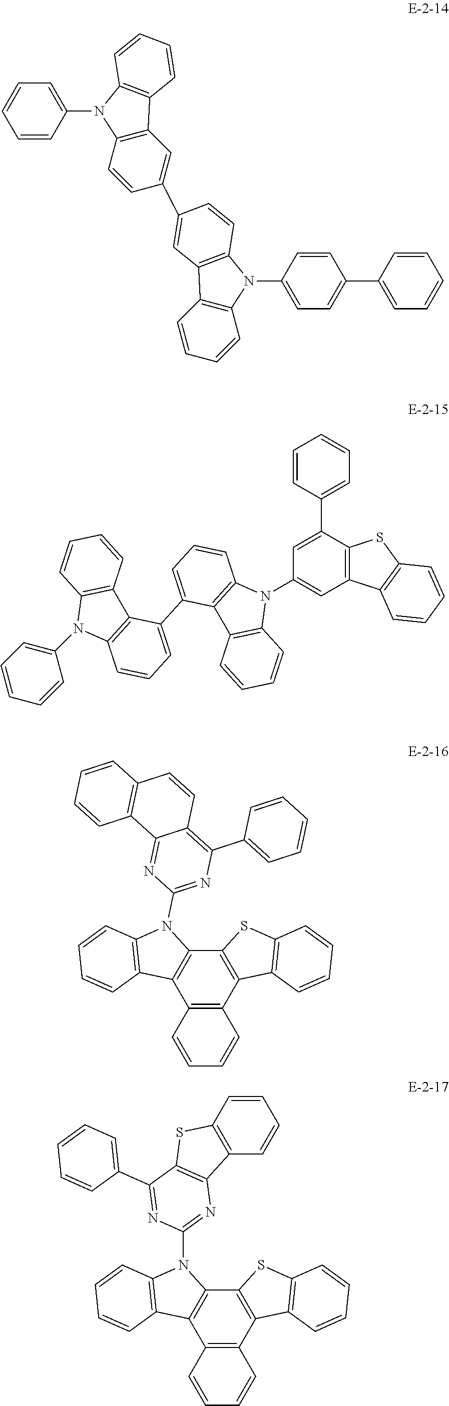

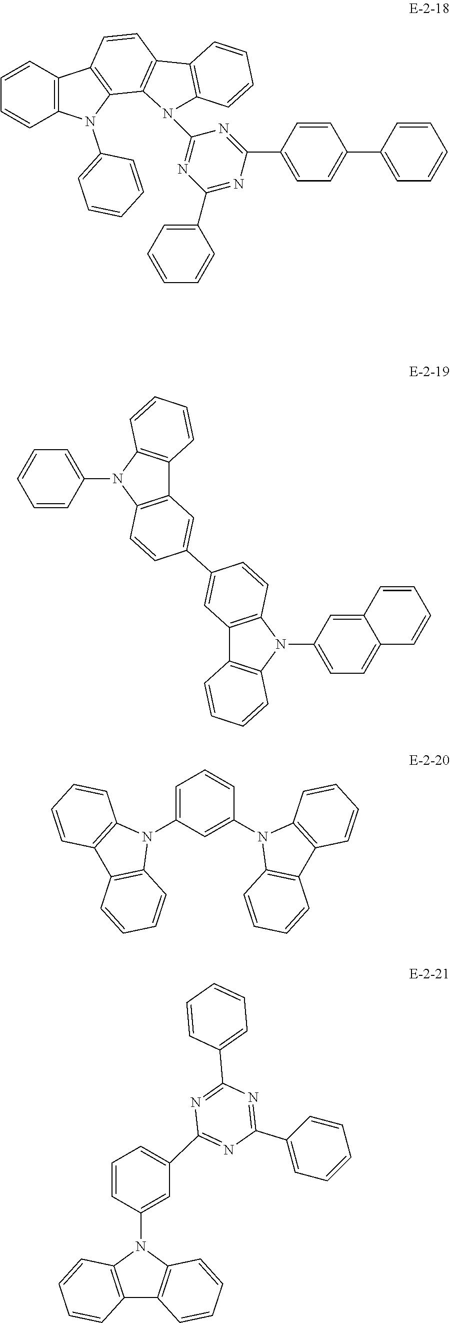 [SMILES: c1ccc(-c2ccc(-c3nc(-c4ccccc4)nc(-n4c5ccccc5c5ccc6c7ccccc7n(-c7ccccc7)c6c54)n3)cc2)cc1 ; c1ccc(-n2c3ccccc3c3cc(-c4ccc5c(c4)c4ccccc4n5-c4ccc5ccccc5c4)ccc32)cc1 ; c1cc(-n2c3ccccc3c3ccccc32)cc(-n2c3ccccc3c3ccccc32)c1 ; c1ccc(-c2nc(-c3ccccc3)nc(-c3cccc(-n4c5ccccc5c5ccccc54)c3)n2)cc1]

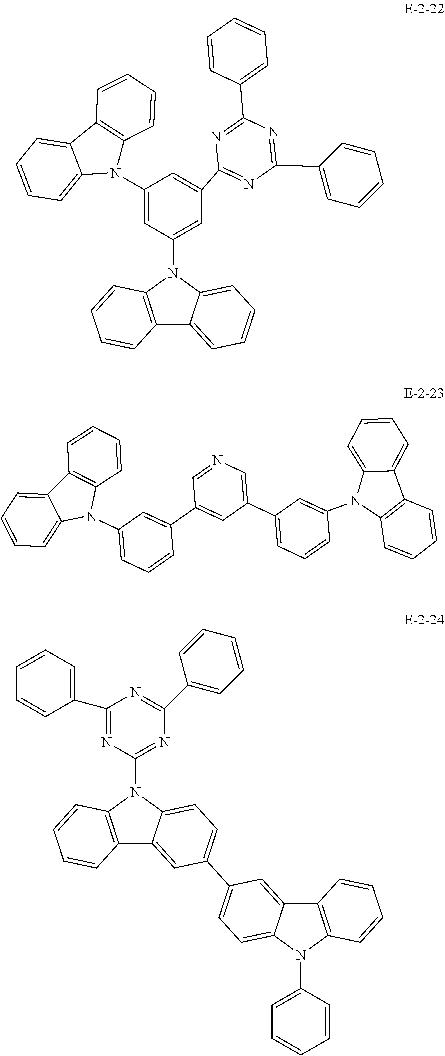 [SMILES: c1ccc(-c2nc(-c3ccccc3)nc(-c3cc(-n4c5ccccc5c5ccccc54)cc(-n4c5ccccc5c5ccccc54)c3)n2)cc1 ; c1cc(-c2cncc(-c3cccc(-n4c5ccccc5c5ccccc54)c3)c2)cc(-n2c3ccccc3c3ccccc32)c1 ; c1ccc(-c2nc(-c3ccccc3)nc(-n3c4ccccc4c4cc(-c5ccc6c(c5)c5ccccc5n6-c5ccccc5)ccc43)n2)cc1]

In one or more embodiments, the emission layer EML may further include a general material suitable in the art as a host material. For example, the emission layer EML may include, as a host material, at least one of bis(4-(9H-carbazol-9-yl)phenyl)diphenylsilane (BCPDS), (4-(1-(4-(diphenylamino)phenyl)cyclohexyl)phenyl)diphenyl-phosphine oxide (POPCPA), bis[2-(diphenylphosphino)phenyl]ether oxide (DPEPO), 4,4′-bis(N-carbazolyl)-1,1′-biphenyl (CBP), 1,3-bis(carbazol-9-yl)benzene (mCP), 2,8-bis(diphenylphosphoryl)dibenzo[b,d]furan (PPF), 4,4′,4″-tris(carbazol-9-yl)-triphenylamine (TCTA), or 1,3,5-tris(1-phenyl-1H-benzo[d]imidazol-2-yl)benzene (TPBi). However, embodiments of the present disclosure are not limited thereto, for example, tris(8-hydroxyquinolinato)aluminum (Alq₃), 9,10-di(naphthalen-2-yl) anthracene (ADN), 2-tert-butyl-9,10-di(naphth-2-yl) anthracene (TBADN), distyrylarylene (DSA), 4,4′-bis(9-carbazolyl)-2,2′-dimethyl-biphenyl (CDBP), 2-methyl-9,10-bis(naphthalen-2-yl) anthracene (MADN), hexaphenyl cyclotriphosphazene (CP1), 1,4-bis(triphenylsilyl)benzene (UGH2), hexaphenylcyclotrisiloxane (DPSiO₃), octaphenylcyclotetrasiloxane (DPSiO₄), and/or the like may be used as a host material.

In one or more embodiments, the emission layer EML may include a compound represented by Formula M-a. The compound represented by Formula M-a may be used as a phosphorescent dopant material.

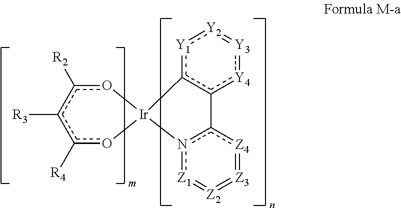

In Formula M-a, Y₁ to Y₄ and Z₁ to Z₄ may be each CR₁ or N, R₁ to R₄ may each independently be hydrogen, deuterium, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or may be bonded to an adjacent group to form a ring. In Formula M-a, m is 0 or 1, and n is 2 or 3. In Formula M-a, if (e.g., when) m is 0, n is 3, and if (e.g., when) m is 1, n is 2.

The compound represented by Formula M-a may be used as a phosphorescent dopant.

The compound represented by Formula M-a may be any one selected from among Compound M-a1 to Compound M-a25. However, Compounds M-a1 to M-a25 are mere examples, and the compound represented by Formula M-a is not limited to those represented by Compounds M-a1 to M-a25.

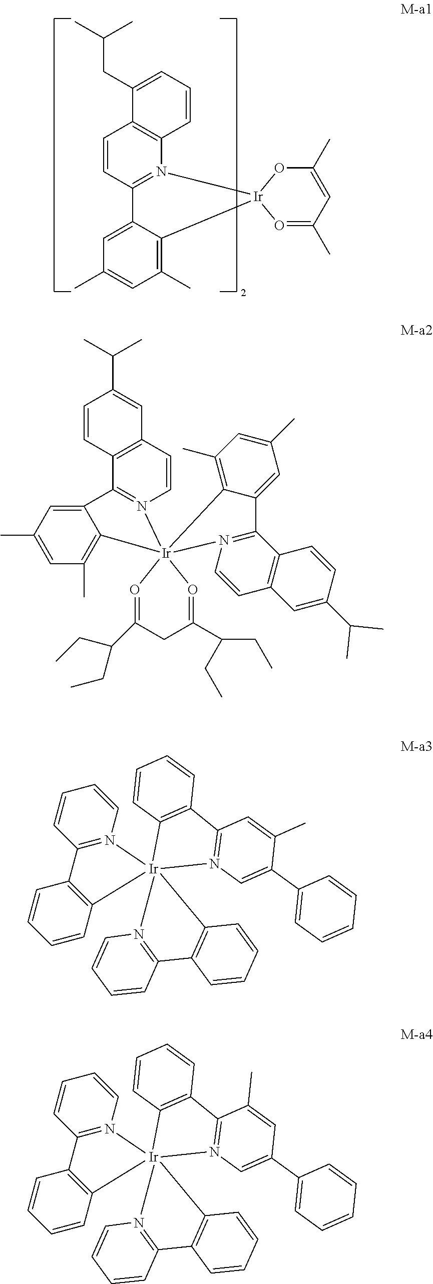

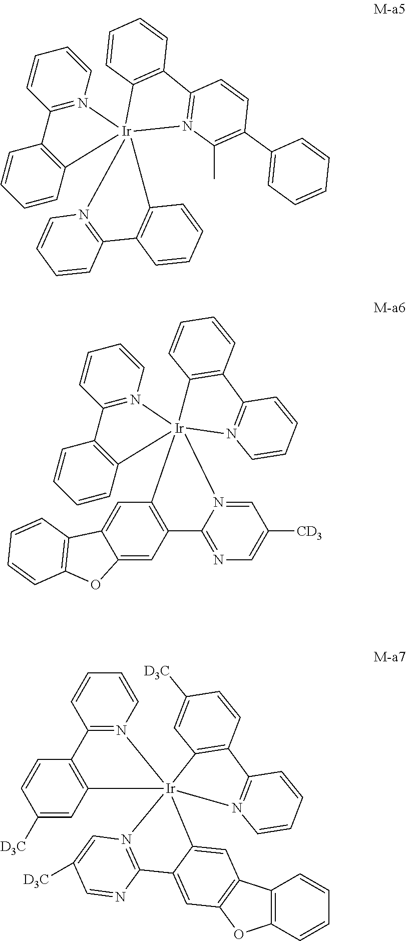

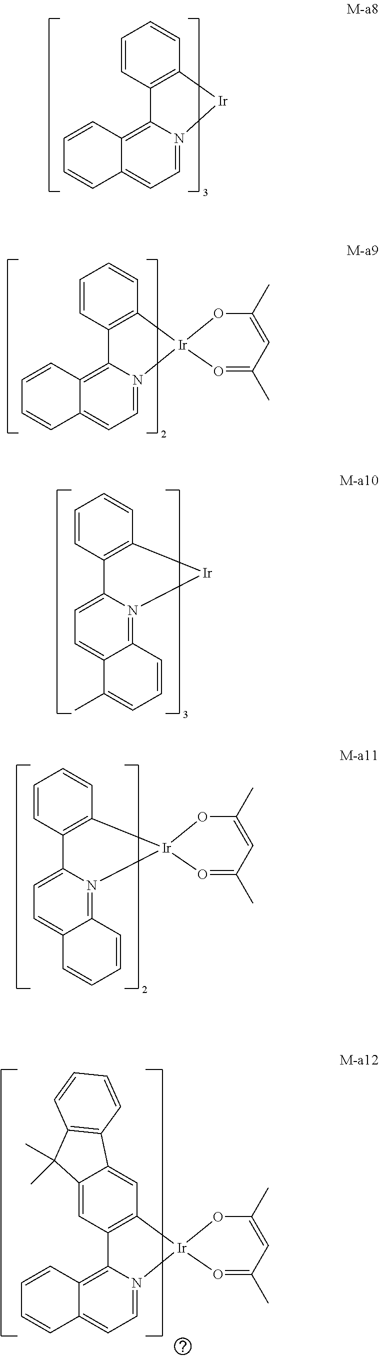

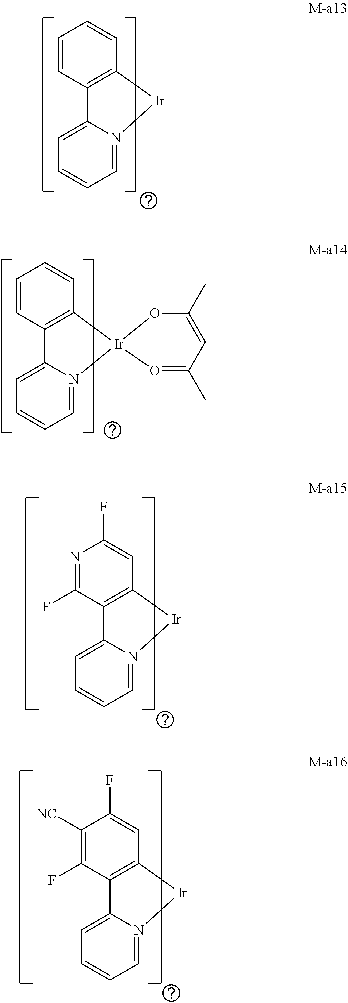

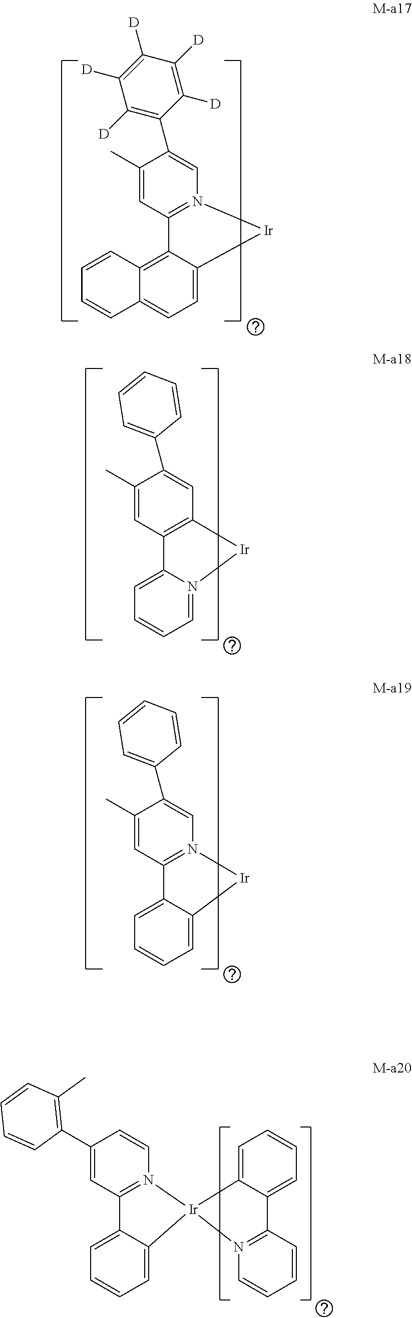

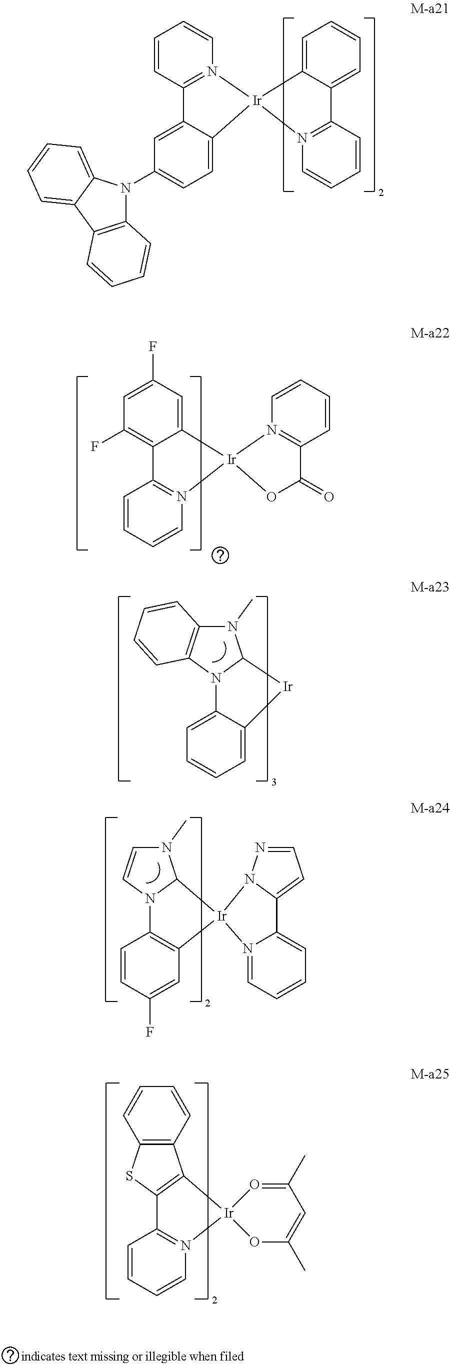

In one or more embodiments, the emission layer EML may include a compound represented by any one selected from among Formula F-a to Formula F-c. The compound represented by Formula F-a to Formula F-c may be used as a fluorescence dopant material.

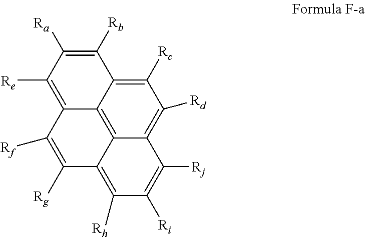

In Formula F-a, two selected from among Rₐ to Rⱼ may each independently be substituted with *—NAr₁Ar₂. The others, which are not substituted with *—NAM₁Ar₂, among Rₐ to Rⱼ may each independently be hydrogen, deuterium, a halogen, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In *—NA₁Ar₂, Ar₁ and Ar₂ may each independently be a substituted or unsubstituted aryl group having 6 to 30 ring-forming carbon atoms or a substituted or unsubstituted heteroaryl group having 2 to 30 ring-forming carbon atoms. For example, in one or more embodiments, at least one of Ar₁ or Ar₂ may be a heteroaryl group containing O or S as a ring-forming atom.

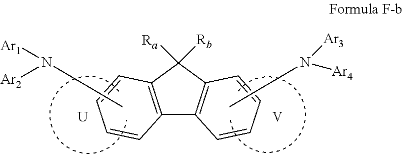

In Formula F-b, Rₐ and R_{b} may each independently be hydrogen, deuterium, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or may be bonded to an adjacent group to form a ring. Ar₁ to Ar₄ may each independently be a substituted or unsubstituted aryl group having 6 to 30 ring-forming carbon atoms or a substituted or unsubstituted heteroaryl group having 2 to 30 ring-forming carbon atoms.

In Formula F-b, U and V may each independently be a substituted or unsubstituted hydrocarbon ring having 5 to 30 ring-forming carbon atoms or a substituted or unsubstituted heterocycle having 2 to 30 ring-forming carbon atoms. In one or more embodiments, at least one selected from among Ar₁ to Ar₄ may be a heteroaryl group containing O or S as a ring-forming atom.

In Formula F-b, the number of rings represented by U and V may each independently be 0 or 1. For example, in Formula F-b, it refers to that if (e.g., when) the number of U or V is 1, one ring constitutes a part of a fused ring at a portion indicated by U or V, and if (e.g., when) the number of U or V is 0, a ring indicated by U or V does not exist. For example, if (e.g., when) the number of U is 0 and the number of V is 1, or if (e.g., when) the number of U is 1 and the number of V is 0, the fused ring having a fluorene core in Formula F-b may be a cyclic compound having four rings. In one or more embodiments, if (e.g., when) each number of U and V is 0, the fused ring in Formula F-b may be a cyclic compound having three rings. In one or more embodiments, if (e.g., when) each number of U and V is 1, the fused ring having a fluorene core in Formula F-b may be a cyclic compound having five rings.

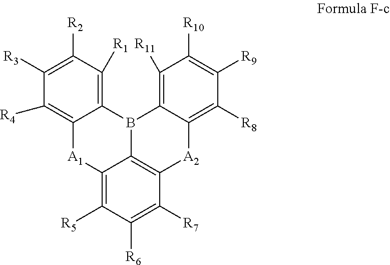

In Formula F-c, A₁ and A₂ may each independently be O, S, Se, or NRₘ, and Rₘ may be hydrogen, deuterium, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. R₁ to R₁₁ may each independently be hydrogen, deuterium, a halogen, a cyano group, a substituted or unsubstituted amine group, a substituted or unsubstituted boryl group, a substituted or unsubstituted oxy group, a substituted or unsubstituted thio group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and/or may be bonded to an adjacent group to form a ring.

In one or more embodiments, in Formula F-c, A₁ and A₂ may each independently be bonded to substituents of an adjacent ring to form a fused ring. For example, if (e.g., when) A₁ and A₂ may each independently be NRₘ, in one or more embodiments, A₁ may be bonded to R₄ or R₅ to form a ring. In one or more embodiments, A₂ may be bonded to R₇ or R₈ to form a ring.

In one or more embodiments, the emission layer EML may further include, as a suitable dopant material, one or more selected from among styryl derivatives (e.g., 1,4-bis[2-(3-N-ethylcarbazolyl) vinyl]benzene (BCzVB), 4-(di-p-tolylamino)-4′-[(di-p-tolylamino) styryl]stilbene (DPAVB), and N-(4-((E)-2-(6-((E)-4-(diphenylamino) styryl) naphthalen-2-yl) vinyl)phenyl)-N-phenylbenzenamine (N-BDAVBi), 4,4′-bis[2-(4-(N, N-diphenylamino)phenyl) vinyl]biphenyl (DPAVBi)), perylene and derivatives thereof (e.g., 2,5,8,11-tetra-t-butylperylene (TBP)), pyrene and derivatives thereof (e.g., 1,1-dipyrene, 1,4-dipyrenylbenzene, 1,4-bis(N,N-diphenylamino)pyrene), and/or the like.

In one or more embodiments, the emission layer EML may further include a suitable phosphorescence dopant material. For example, a metal complex containing iridium (Ir), platinum (Pt), osmium (Os), aurum (Au), titanium (Ti), zirconium (Zr), hafnium (Hf), europium (Eu), terbium (Tb), or thulium (Tm) may be used as a phosphorescent dopant. For example, iridium (III) bis(4,6-difluorophenylpyridinato-N, C2) (FIrpic), bis(2,4-difluorophenylpyridinato)-tetrakis(1-pyrazolyl) borate iridium (III) (Fir6), or platinum octaethyl porphyrin (PtOEP) may be used as a phosphorescent dopant. However, embodiments of the present disclosure are not limited thereto.

In one or more embodiments, the emission layer EML may include a quantum dot material. In one or more embodiments, the quantum dot may have a core/shell structure. The core of the quantum dot may be selected from among a Group II-VI compound, a Group III-VI compound, a Group I-III-IV compound, a Group III-V compound, a Group III-II-V compound, a Group IV-VI compound, a Group IV element, a Group IV compound, and/or a combination thereof.

The Group II-VI compound may be selected from the group consisting of a binary compound selected from the group consisting of CdSe, CdTe, CdS, ZnS, ZnSe, ZnTe, ZnO, HgS, HgSe, HgTe, MgSe, MgS, and a mixture thereof, a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a mixture thereof, a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, HgZnSTe, and a mixture thereof, and a mixture thereof.

The Group III-VI compound may include a binary compound such as In₂S₃ and/or In₂Se₃, a ternary compound such as InGaS₃ and/or InGaSe₃, or any combination thereof.

The Group I-III-VI compound may be selected from among a ternary compound selected from the group consisting of AgInS, AgInS₂, CuInS, CuInS₂, AgGaS₂, CuGaS₂ CuGaO₂, AgGaO₂, AgAlO₂, and a mixture thereof, and/or a quaternary compound such as AgInGaS₂ and/or CuInGaS₂.

The Group III-V compound may be selected from the group consisting of a binary compound selected from the group consisting of GaN, GaP, GaAs, GaSb, AlN, AlP, AlAs, AlSb, InN, InP, InAs, InSb, and a mixture thereof, a ternary compound selected from the group consisting of GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, and a mixture thereof, a quaternary compound selected from the group consisting of GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and a mixture thereof, and a mixture thereof. In one or more embodiments, the Group III-V compound may further include a Group II metal. For example, InZnP, and/or the like, may be selected as a Group III-II-V compound.

The Group IV-VI compound may be selected from the group consisting of a binary compound selected from the group consisting of SnS, SnSe, SnTe, PbS, PbSe, PbTe, and a mixture thereof, a ternary compound selected from the group consisting of SnSeS, SnSeTe, SnSTe, PbSeS, PbSeTe, PbSTe, SnPbS, SnPbSe, SnPbTe, and a mixture thereof, a quaternary compound selected from the group consisting of SnPbSSe, SnPbSeTe, SnPbSTe, and a mixture thereof, and a mixture thereof. The Group IV element may be selected from the group consisting of Si, Ge, and a mixture thereof. The Group IV compound may be a binary compound selected from the group consisting of SiC, SiGe, and a mixture thereof.

Each element included in a polynary compound such as the binary compound, the ternary compound, or the quaternary compound may be present in a particle with a substantially uniform or non-uniform concentration distribution. For example, the above formulae refer to the types (kinds) of elements included in the compounds, and the elemental ratio in the compound may be different. For example, AgInGaS₂ may refer to AgInₓGa₁₋ₓS₂ (where x is a real number of 0 to 1).

The quantum dot may have a single structure in which the concentration of each element included in the quantum dot is substantially uniform or a double structure of core-shell. For example, the material included in the core may be different from the material included in the shell.

The shell of the quantum dot may serve as a protection layer to prevent or reduce the chemical deformation of the core to maintain semiconductor properties, and/or a charging layer to impart electrophoresis properties to the quantum dot. The shell may be a single layer or multiple layers. An interface between the core and the shell may have a concentration gradient in which the concentration of an element present in the shell becomes lower towards the center.

In one or more embodiments, the quantum dot may have the above-described core/shell structure including a core containing nanocrystals and a shell around (e.g., surrounding) the core. An example of the shell of the quantum dot may include a metal or non-metal oxide, a semiconductor compound, or a combination thereof.

For example, the metal or non-metal oxide for the shell may be a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, and/or NiO, or a ternary compound such as MgAl₂O₄, CoFe₂O₄, NiFe₂O₄, and/or CoMn₂O₄, but embodiments of the present disclosure are not limited thereto.

Also, examples of the semiconductor compound suitable as a shell may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AIP, AlSb, and/or the like, but embodiments of the present disclosure are not limited thereto.

Each element included in a polynary compound such as the binary compound, or the ternary compound may be present in a particle with a substantially uniform or non-uniform concentration distribution. For example, the formulae may refer to the types (kinds) of elements included in the compounds, and the elemental ratio in the compound may be different.

The quantum dot may have a full width at half maximum (FWHM) of an emission spectrum of about 45 nm or less, about 40 nm or less, or about 30 nm or less, and color purity or color reproducibility of the quantum dot may be improved in the above range. In addition, light emitted through such quantum dots is emitted in all directions so that a wide viewing angle may be improved.

In addition, although the form of the quantum dot is not particularly limited as long as it is a form commonly used in the art, for example, the quantum dot in the form of spherical nanoparticles, pyramidal nanoparticles, multi-arm nanoparticles, cubic nanoparticles, nanotubes, nanowires, nanofibers, nanoplate particles, and/or the like may be used.

As the size of the quantum dot is adjusted or the elemental ratio in the quantum dot compound is adjusted, it may control the energy band gap of the quantum dot, and thus light in one or more suitable wavelength ranges may be obtained in a quantum dot emission layer. Therefore, when the quantum dot as above (e.g., using different sizes of quantum dots or different elemental ratios in the quantum dot compound) is used, the light emitting element, which emits light in one or more suitable wavelengths, may be implemented. For example, the adjustment of the size of the quantum dot or the elemental ratio in the quantum dot compound may be selected to enable the quantum dots to emit red, green, and/or blue light. In one or more embodiments, the quantum dots may be configured to emit white color light by combining one or more suitable colors of light.

In each of the light emitting elements ED of embodiments illustrated in FIGS. 3 to 6, the electron transport region ETR may be provided on the emission layer EML. The electron transport region ETR may include at least one of a hole blocking layer HBL, an electron transport layer ETL, or an electron injection layer EIL, but embodiments of the present disclosure are not limited thereto.

The electron transport region ETR may have a single layer formed of a single material, a single layer formed of a plurality of different materials, or a multilayer structure including a plurality of layers formed of a plurality of different materials.

For example, in one or more embodiments, the electron transport region ETR may have a single layer structure of an electron injection layer EIL or an electron transport layer ETL, or may have a single layer structure formed of an electron injection material and/or an electron transport material. In one or more embodiments, the electron transport region ETR may have a single layer structure formed of a plurality of different materials, or may have a structure in which an electron transport layer ETL/electron injection layer EIL, or a hole blocking layer HBL/electron transport layer ETL/electron injection layer EIL are stacked in order (e.g., in the stated order) from the emission layer EML, but embodiments of the present disclosure are not limited thereto. The electron transport region ETR may have a thickness, for example, from about 1,000 Å to about 1,500 Å.

The electron transport region ETR may be formed using one or more suitable methods such as a vacuum deposition method, a spin coating method, a casting method, a Langmuir-Blodgett (LB) method, an inkjet printing method, a laser printing method, and/or a laser induced thermal imaging (LITI) method.

In one or more embodiments, the electron transport region ETR may include a compound represented by Formula ET-2:

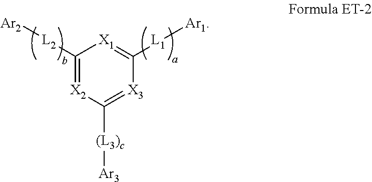

In Formula ET-2, at least one selected from among X₁ to X₃ may be N, and the rest are CRₐ. Rₐ may be hydrogen, deuterium, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. Ar₁ to Ar₃ may each independently be hydrogen, deuterium, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In Formula ET-2, a to c may each independently be an integer of 0 to 10. In Formula ET-2, L₁ to L₃ may each independently be a direct linkage, a substituted or unsubstituted arylene group having 6 to 30 ring-forming carbon atoms, or a substituted or unsubstituted heteroarylene group having 2 to 30 ring-forming carbon atoms. In one or more embodiments, if (e.g., when) a to c may each independently be an integer of 2 or greater, L₁'s to L₃'s may each independently be a substituted or unsubstituted arylene group having 6 to 30 ring-forming carbon atoms or a substituted or unsubstituted heteroarylene group having 2 to 30 ring-forming carbon atoms.

In one or more embodiments, the electron transport region ETR may include an anthracene-based compound. However, embodiments of the present disclosure are not limited thereto, and the electron transport region ETR may include, for example, tris(8-hydroxyquinolinato)aluminum (Alq₃), 1,3,5-tri[(3-pyridyl)-phen-3-yl]benzene, 2,4,6-tris(3′-(pyridin-3-yl) biphenyl-3-yl)-1,3,5-triazine, 2-(4-(N-phenylbenzimidazol-1-yl)phenyl)-9,10-dinaphthylanthracene, 1,3,5-tri (1-phenyl-1H-benzo[d]imidazol-2-yl)benzene (TPBi), 2,9-dimethyl-4,7-diphenyl-1,10-phenanthroline (BCP), 4,7-diphenyl-1,10-phenanthroline (Bphen), 3-(biphenyl-4-yl)-4-phenyl-5-tert-butylphenyl-1,2,4-triazole (TAZ), 4-(naphthalen-1-yl)-3,5-diphenyl-4H-1,2,4-triazole (NTAZ), 2-(biphenyl-4-yl)-5-(4-tert-butylphenyl)-1,3,4-oxadiazole (tBu-PBD), bis(2-methyl-8-quinolinolato-N1,O8)-(1,1′-biphenyl-4-olato)aluminum (BAlq), beryllium bis(benzoquinolin-10-olate) (Bebq₂), 9,10-di(naphthalen-2-yl) anthracene (ADN), 1,3-bis[3,5-di(pyridin-3-yl)phenyl]benzene (BmPyPhB), and/or a mixture thereof.

In one or more embodiments, the electron transport region ETR may include at least one selected from among Compound ET1 to Compound ET36:

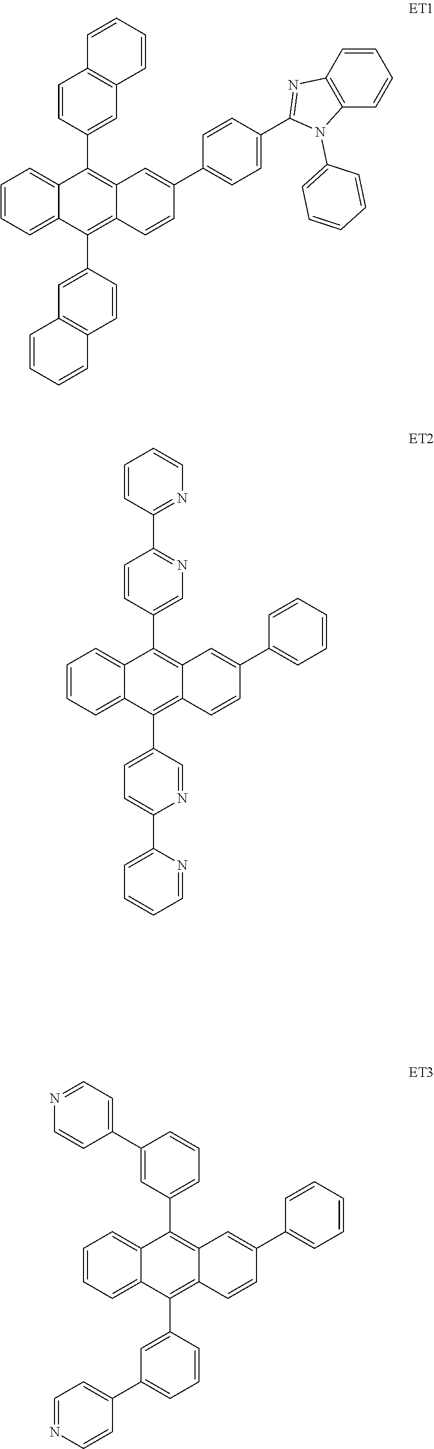 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)nc4)c3c2)cc1 ; c1ccc(-c2ccc3c(-c4cccc(-c5ccncc5)c4)c4ccccc4c(-c4cccc(-c5ccncc5)c4)c3c2)cc1]

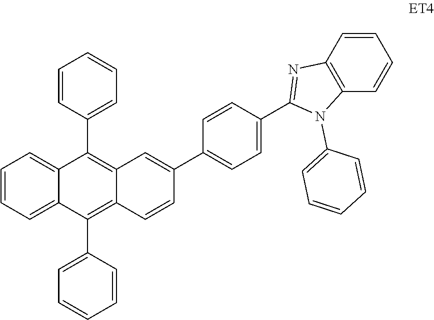 [SMILES: c1ccc(-c2c3ccccc3c(-c3ccccc3)c3cc(-c4ccc(-c5nc6ccccc6n5-c5ccccc5)cc4)ccc23)cc1]

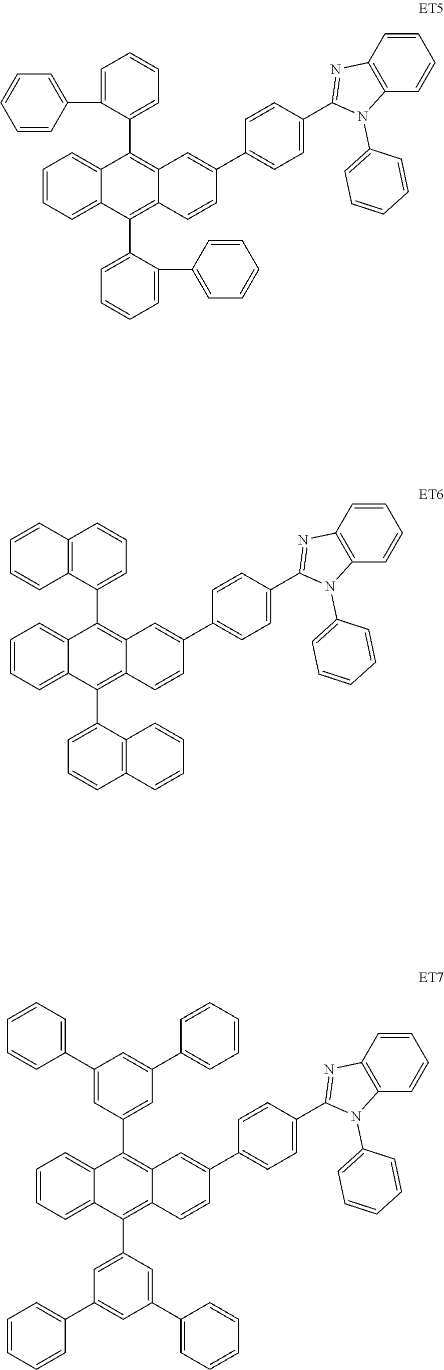 [SMILES: c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1 ; c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1]

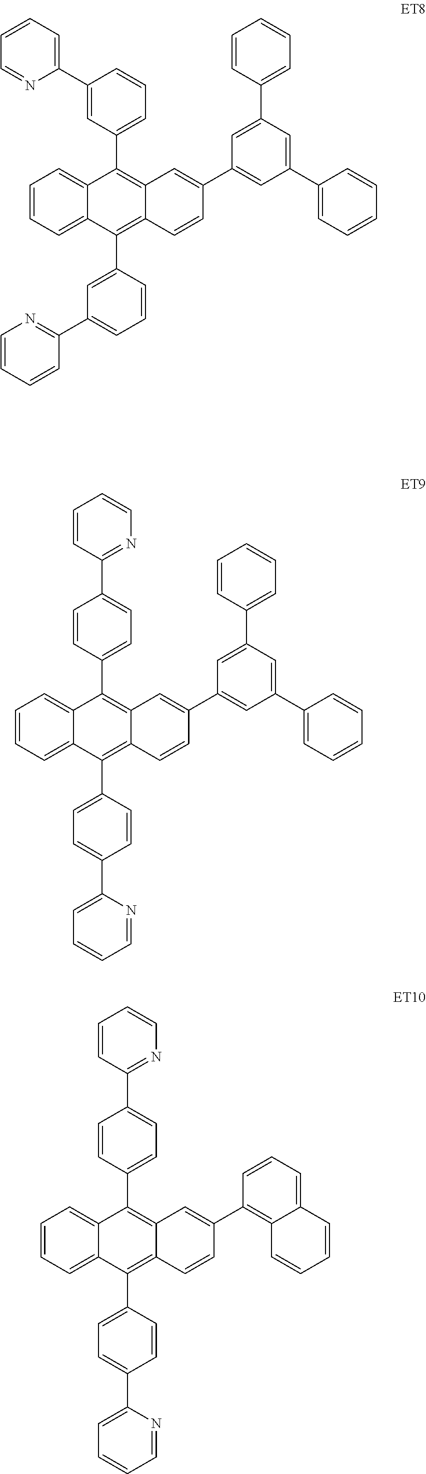 [SMILES: c1ccc(-c2cc(-c3ccccc3)cc(-c3ccc4c(-c5cccc(-c6ccccn6)c5)c5ccccc5c(-c5cccc(-c6ccccn6)c5)c4c3)c2)cc1 ; c1ccc(-c2cc(-c3ccccc3)cc(-c3ccc4c(-c5ccc(-c6ccccn6)cc5)c5ccccc5c(-c5ccc(-c6ccccn6)cc5)c4c3)c2)cc1 ; c1ccc(-c2ccc(-c3c4ccccc4c(-c4ccc(-c5ccccn5)cc4)c4cc(-c5cccc6ccccc56)ccc34)cc2)nc1]

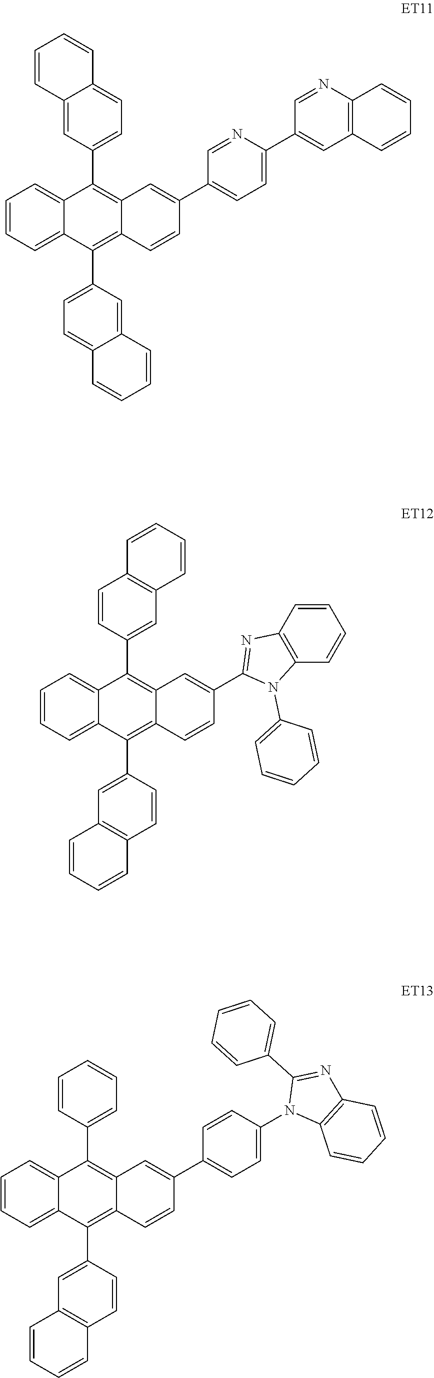 [SMILES: c1ccc2cc(-c3c4ccccc4c(-c4ccc5ccccc5c4)c4cc(-c5ccc(-c6cnc7ccccc7c6)nc5)ccc34)ccc2c1 ; c1ccc(-n2c(-c3ccc4c(-c5ccc6ccccc6c5)c5ccccc5c(-c5ccc6ccccc6c5)c4c3)nc3ccccc32)cc1 ; c1ccc(-c2c3ccccc3c(-c3ccc4ccccc4c3)c3ccc(-c4ccc(-n5c(-c6ccccc6)nc6ccccc65)cc4)cc23)cc1]

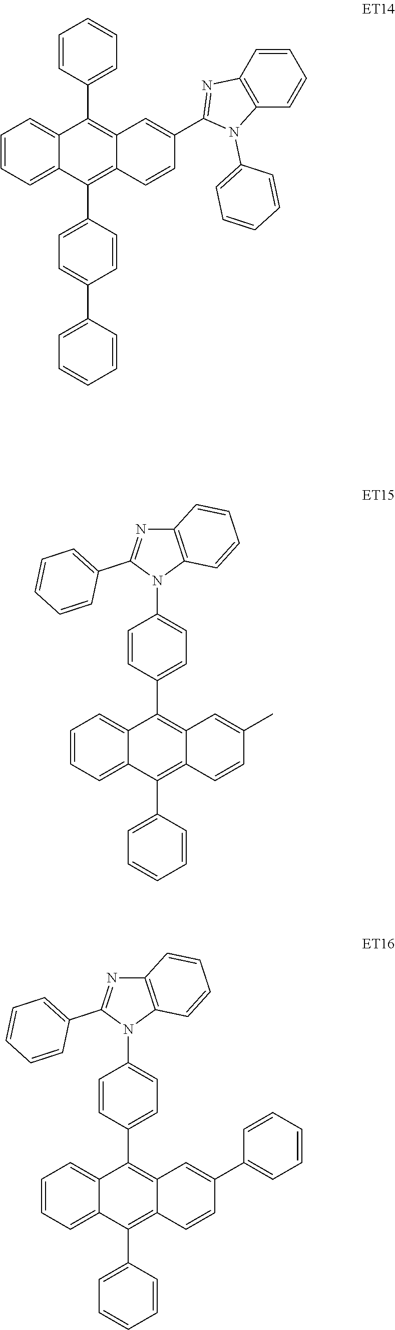 [SMILES: c1ccc(-c2ccc(-c3c4ccccc4c(-c4ccccc4)c4cc(-c5nc6ccccc6n5-c5ccccc5)ccc34)cc2)cc1 ; Cc1ccc2c(-c3ccccc3)c3ccccc3c(-c3ccc(-n4c(-c5ccccc5)nc5ccccc54)cc3)c2c1 ; c1ccc(-c2ccc3c(-c4ccccc4)c4ccccc4c(-c4ccc(-n5c(-c6ccccc6)nc6ccccc65)cc4)c3c2)cc1]

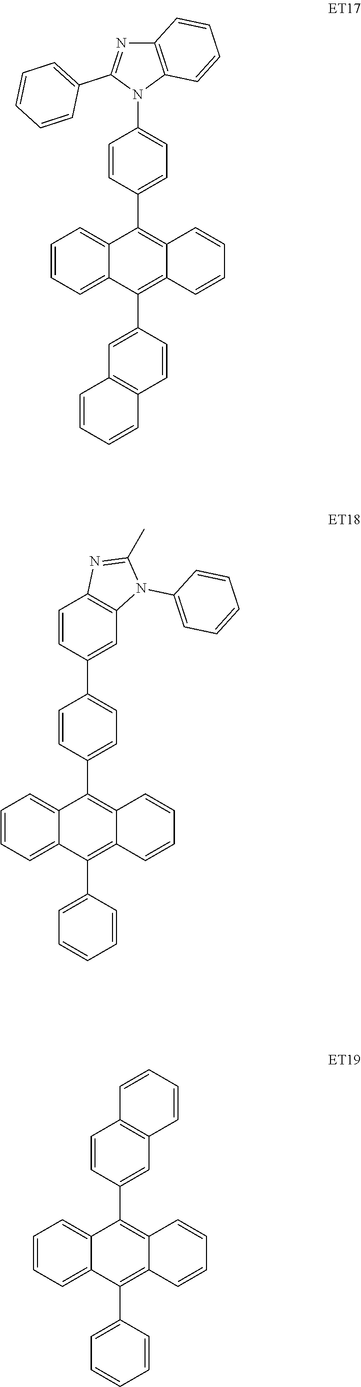

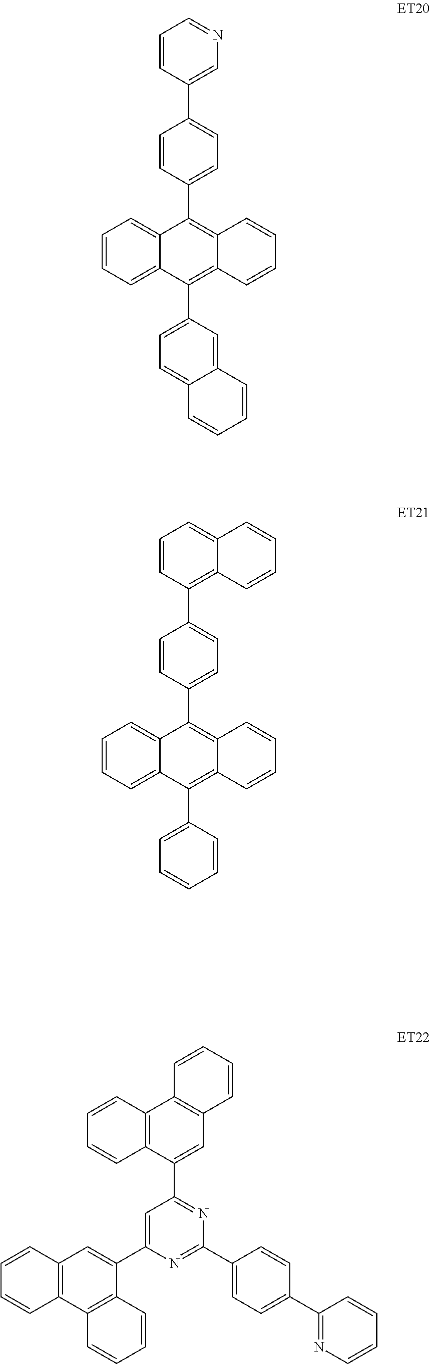

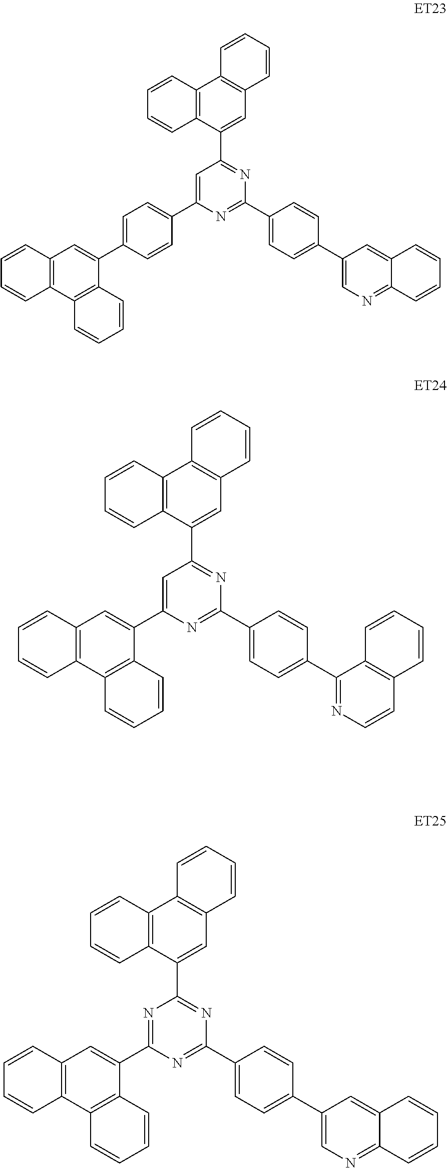 [SMILES: c1ccc2ncc(-c3ccc(-c4nc(-c5ccc(-c6cc7ccccc7c7ccccc67)cc5)cc(-c5cc6ccccc6c6ccccc56)n4)cc3)cc2c1 ; c1ccc2c(-c3ccc(-c4nc(-c5cc6ccccc6c6ccccc56)cc(-c5cc6ccccc6c6ccccc56)n4)cc3)nccc2c1 ; c1ccc2ncc(-c3ccc(-c4nc(-c5cc6ccccc6c6ccccc56)nc(-c5cc6ccccc6c6ccccc56)n4)cc3)cc2c1]

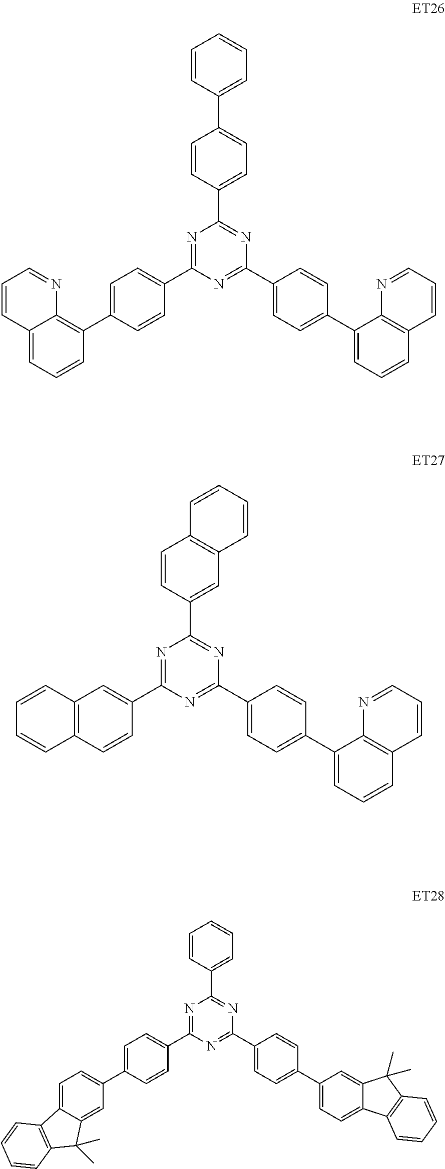 [SMILES: c1ccc(-c2ccc(-c3nc(-c4ccc(-c5cccc6cccnc56)cc4)nc(-c4ccc(-c5cccc6cccnc56)cc4)n3)cc2)cc1 ; c1ccc2cc(-c3nc(-c4ccc(-c5cccc6cccnc56)cc4)nc(-c4ccc5ccccc5c4)n3)ccc2c1 ; CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21]

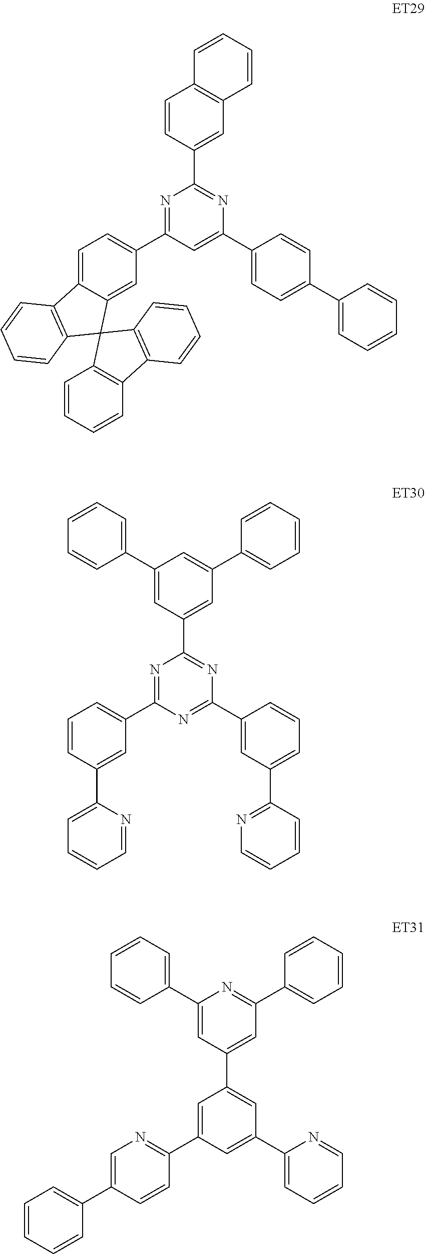 [SMILES: c1ccc(-c2ccc(-c3cc(-c4ccc5c(c4)C4(c6ccccc6-c6ccccc64)c4ccccc4-5)nc(-c4ccc5ccccc5c4)n3)cc2)cc1 ; c1ccc(-c2cc(-c3ccccc3)cc(-c3nc(-c4cccc(-c5ccccn5)c4)nc(-c4cccc(-c5ccccn5)c4)n3)c2)cc1 ; c1ccc(-c2ccc(-c3cc(-c4cc(-c5ccccc5)nc(-c5ccccc5)c4)cc(-c4ccccn4)c3)nc2)cc1]

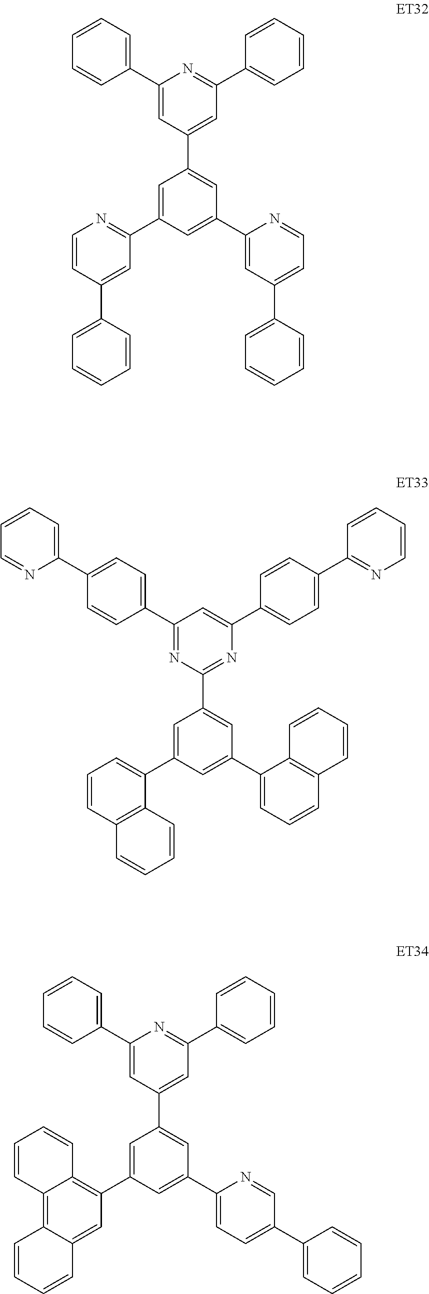 [SMILES: c1ccc(-c2ccnc(-c3cc(-c4cc(-c5ccccc5)nc(-c5ccccc5)c4)cc(-c4cc(-c5ccccc5)ccn4)c3)c2)cc1 ; c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1 ; c1ccc(-c2ccc(-c3cc(-c4cc(-c5ccccc5)nc(-c5ccccc5)c4)cc(-c4cc5ccccc5c5ccccc45)c3)nc2)cc1]

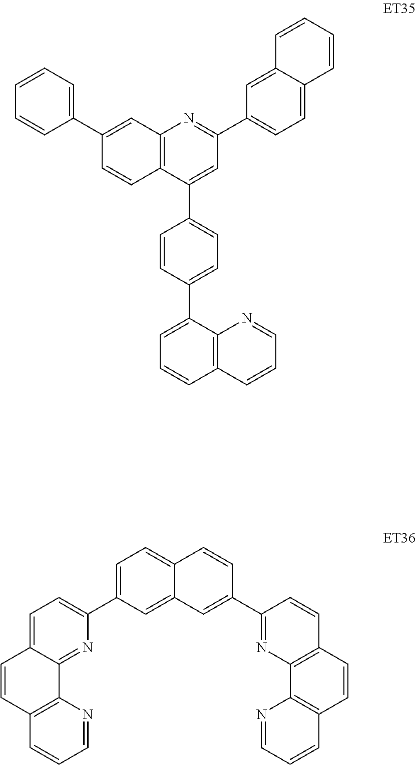 [SMILES: c1ccc(-c2ccc3c(-c4ccc(-c5cccc6cccnc56)cc4)cc(-c4ccc5ccccc5c4)nc3c2)cc1 ; c1cnc2c(c1)ccc1ccc(-c3ccc4ccc(-c5ccc6ccc7cccnc7c6n5)cc4c3)nc12]

In one or more embodiments, the electron transport region ETR may include a metal halide such as LiF, NaCl, CsF, RbCl, RbI, CuI, and/or Kl, a lanthanide metal such as Yb, or a co-deposited material of the metal halide and the lanthanide metal. For example, in one or more embodiments, the electron transport region ETR may include Kl:Yb, RbI:Yb, LiF:Yb, and/or the like, as a co-deposited material. In one or more embodiments, the electron transport region ETR may be formed using a metal oxide such as Li₂O and/or BaO, or lithium-8-hydroxyquinolinolate (Liq), and/or the like, but embodiments of the present disclosure are not limited thereto. In one or more embodiments, the electron transport region ETR may also be formed of a mixture material of an electron transport material and an insulating organometallic salt. The organometallic salt may be a material having an energy band gap of about 4 eV or more. For example, the organometallic salt may include, for example, a metal acetate, a metal benzoate, a metal acetoacetate, a metal acetylacetonate, and/or a metal stearate.

In one or more embodiments, the electron transport region ETR may further include at least one of 2,9-dimethyl-4,7-diphenyl-1,10-phenanthroline (BCP), diphenyl(4-(triphenylsilyl)phenyl)phosphine oxide (TSPO1), or 4,7-diphenyl-1,10-phenanthroline (Bphen) in addition to one or more of the above-described materials, but embodiments of the present disclosure are not limited thereto.

The electron transport region ETR may include one or more of the above-described compounds of the hole transport region in at least one of the electron injection layer EIL, the electron transport layer ETL, or the hole blocking layer HBL.

If (e.g., when) the electron transport region ETR includes the electron transport layer ETL, the electron transport layer ETL may have a thickness of about 100 Å to about 1,000 Å, for example, about 150 Å to about 500 Å. If (e.g., when) the thickness of the electron transport layer ETL satisfies the aforementioned range, satisfactory electron transport characteristics may be obtained without a substantial increase in driving voltage. If (e.g., when) the electron transport region ETR includes the electron injection layer EIL, the electron injection layer EIL may have a thickness of about 1 Å to about 100 Å, for example, about 3 Å to about 90 Å. If (e.g., when) the thickness of the electron injection layer EIL satisfies the above-described range, satisfactory electron injection characteristics may be obtained without a substantial increase in driving voltage.

The second electrode EL2 is provided on the electron transport region ETR. The second electrode EL2 may be a common electrode. The second electrode EL2 may be a cathode or an anode, but embodiments of the present disclosure are not limited thereto. For example, if (e.g., when) the first electrode EL1 is an anode, the second electrode EL2 may be a cathode, and if (e.g., when) the first electrode EL1 is a cathode, the second electrode EL2 may be an anode.

The second electrode EL2 may be a transmissive electrode, a transflective electrode, or a reflective electrode. If (e.g., when) the second electrode EL2 is a transmissive electrode, the second electrode EL2 may be formed of a transparent metal oxide, for example, indium tin oxide (ITO), indium zinc oxide (IZO), zinc oxide (ZnO), indium tin zinc oxide (ITZO), and/or the like.

If (e.g., when) the second electrode EL2 is a transflective electrode or a reflective electrode, the second electrode EL2 may include Ag, Mg, Cu, Al, Pt, Pd, Au, Ni, Nd, Ir, Cr, Li, Ca, LiF/Ca, LiF/Al, Mo, Ti, Yb, W, a compound thereof, or a mixture thereof (e.g., AgMg, AgYb, or MgYb). In one or more embodiments, the second electrode EL2 may have a multilayer structure including a reflective film or a transflective film formed of one of the above-described materials, and a transparent conductive film formed of ITO, IZO, ZnO, ITZO, and/or the like. For example, in one or more embodiments, the second electrode EL2 may include one the above-described metal materials, a combination of at least two metal materials of the above-described metal materials, an oxide of the above-described metal materials, and/or the like.

In one or more embodiments, the second electrode EL2 may be connected with an auxiliary electrode. If (e.g., when) the second electrode EL2 is connected with the auxiliary electrode, the resistance of the second electrode EL2 may be decreased.

In one or more embodiments, the capping layer CPL may further be arranged on the second electrode EL2 of the light emitting element ED of one or more embodiments. The capping layer CPL may include a multilayer or a single layer.

In one or more embodiments, the capping layer CPL may be an organic layer or an inorganic layer. For example, if (e.g., when) the capping layer CPL contains an inorganic material, the inorganic material may include an alkali metal compound (e.g., LiF), an alkaline earth metal compound (e.g., MgF₂), SiON, SiNₓ, SiO_{y}, and/or the like.

In one or more embodiments, if (e.g., when) the capping layer CPL includes an organic material, the organic material may include α-NPD, NPB, TPD, m-MTDATA, Alq₃, CuPc, N⁴,N⁴, N⁴′, N⁴′-tetra(biphenyl-4-yl) biphenyl-4,4′-diamine (TPD15), 4,4′,4″-tris(carbazol-9-yl)triphenylamine (TCTA), and/or the like, or may include an epoxy resin and/or an acrylate such as methacrylate. However, embodiments of the present disclosure are not limited thereto, for example, in one or more embodiments, the capping layer CPL may include at least one selected from among Compounds P1 to P5:

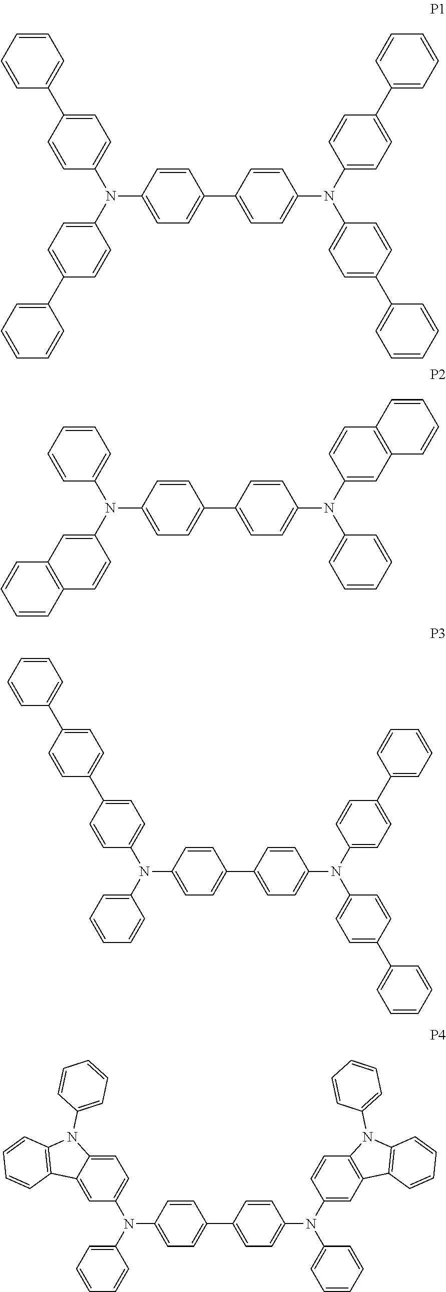 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1 ; c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1]

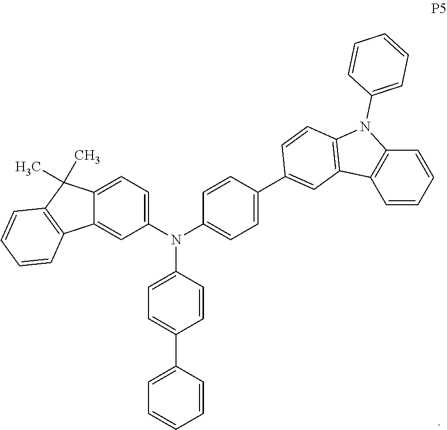 [SMILES: CC1(C)c2ccccc2-c2cc(N(c3ccc(-c4ccccc4)cc3)c3ccc(-c4ccc5c(c4)c4ccccc4n5-c4ccccc4)cc3)ccc21]

The refractive index of the capping layer CPL may be about 1.6 or more. For example, in one or more embodiments, the refractive index of the capping layer CPL may be about 1.6 or more with respect to light in a wavelength range of about 550 nm to about 660 nm.

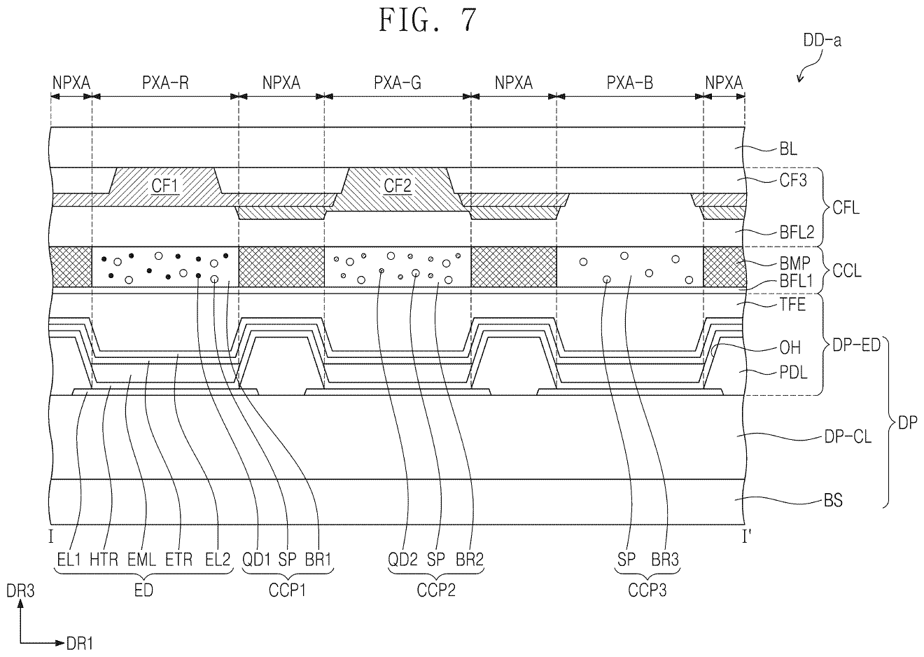

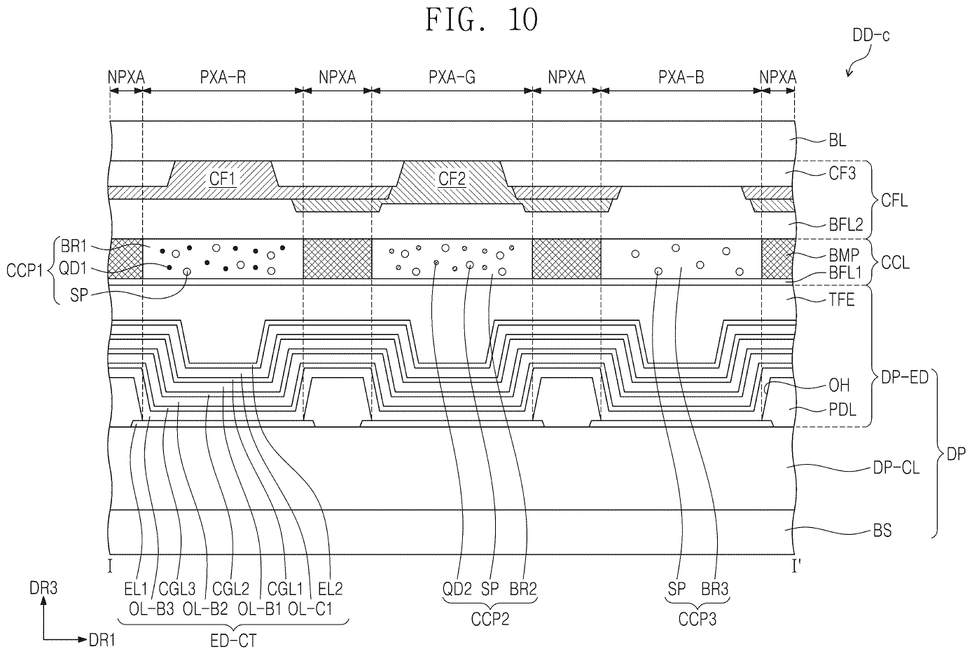

Each of FIGS. 7 to 10 is a cross-sectional view of a display device according to one or more embodiments of the disclosure. Hereinafter, in describing the display devices of embodiments with reference to FIGS. 7 to 10, the duplicated features which have been described in FIGS. 1 to 6 are not described again, but their differences will be mainly described.

Referring to FIG. 7, the display device DD-a according to one or more embodiments may include a display panel DP including a display element layer DP-ED, a light control layer CCL arranged on the display panel DP, and a color filter layer CFL. In one or more embodiments illustrated in FIG. 7, the display panel DP may include a base layer BS, a circuit layer DP-CL provided on the base layer BS, and the display element layer DP-ED, and the display element layer DP-ED may include a light emitting element ED.

The light emitting element ED may include a first electrode EL1, a hole transport region HTR arranged on the first electrode EL1, an emission layer EML arranged on the hole transport region HTR, an electron transport region ETR arranged on the emission layer EML, and a second electrode EL2 arranged on the electron transport region ETR. The structures of the light emitting elements of FIGS. 3 to 6 as described above may be equally applied to the structure of the light emitting element ED illustrated in FIG. 7.

The emission layer EML of the light emitting element ED included in the display device DD-a according to one or more embodiments may include the fused polycyclic compound according to one or more embodiments described above.

Referring to FIG. 7, the emission layer EML may be arranged in an opening OH defined in a pixel defining film PDL. For example, the emission layer EML which is divided by the pixel defining film PDL and provided corresponding to each light emitting regions PXA-R, PXA-G, and PXA-B may be to emit light in substantially the same wavelength range. In the display device DD-a of one or more embodiments, the emission layer EML may be to emit blue color light. In one or more embodiments, the emission layer EML may be provided as a common layer across the entire light emitting regions PXA-R, PXA-G, and PXA-B.

The light control layer CCL may be arranged on the display panel DP. The light control layer CCL may include a light conversion body. The light conversion body may be a quantum dot, a phosphor, and/or the like. The light conversion body may be to emit provided light by converting the wavelength thereof. For example, in one or more embodiments, the light control layer CCL may a layer containing a quantum dot or a layer containing a phosphor.

The light control layer CCL may include a plurality of light control parts CCP1, CCP2, and CCP3. The light control parts CCP1, CCP2, and CCP3 may be spaced and/or apart (e.g., spaced apart or separated) from one another.

Referring to FIG. 7, divided patterns BMP may be arranged between the light control parts CCP1, CCP2, and CCP3 which are spaced and/or apart (e.g., spaced apart or separated) from one another, but embodiments of the present disclosure are not limited thereto. FIG. 7 illustrates that the divided patterns BMP do not overlap the light control parts CCP1, CCP2, and CCP3, but, in one or more embodiments, at least a portion of the edges of each of the light control parts CCP1, CCP2, and CCP3 may overlap the divided patterns BMP.

In one or more embodiments, the light control layer CCL may include a first light control part CCP1 containing a first quantum dot QD1 which converts first color light provided from the light emitting element ED into second color light, a second light control part CCP2 containing a second quantum dot QD2 which converts the first color light into third color light, and a third light control part CCP3 which transmits the first color light.

In one or more embodiments, the first light control part CCP1 may provide red color light that is the second color light, and the second light control part CCP2 may provide green color light that is the third color light. The third light control part CCP3 may provide blue color light by transmitting the blue color light that is the first color light provided from the light emitting element ED. For example, the first quantum dot QD1 may be a red quantum dot to emit red color light, and the second quantum dot QD2 may be a green quantum dot to emit green color light. The same content on quantum dots described above may be applied with respect to the quantum dots QD1 and QD2.

In one or more embodiments, the light control layer CCL may further include a scatterer SP. The first light control part CCP1 may include the first quantum dot QD1 and the scatterer SP, the second light control part CCP2 may include the second quantum dot QD2 and the scatterer SP, and the third light control part CCP3 may not include (e.g., may exclude) any quantum dot but include the scatterer SP.

The scatterer SP may be inorganic particles. For example, the scatterer SP may include at least one of TiO₂, ZnO, Al₂O₃, SiO₂, or hollow sphere silica. The scatterer SP may include any one selected from among TiO₂, ZnO, Al₂O₃, SiO₂, and hollow sphere silica, or may be a mixture of at least two materials selected from among TiO₂, ZnO, Al₂O₃, SiO₂, and hollow sphere silica.

The first light control part CCP1, the second light control part CCP2, and the third light control part CCP3 may respectively include base resins BR1, BR2, and BR3 in which the quantum dots QD1 and QD2 and the scatterer SP are dispersed, accordingly. In one or more embodiments, the first light control part CCP1 may include the first quantum dot QD1 and the scatterer SP dispersed in a first base resin BR1, the second light control part CCP2 may include the second quantum dot QD2 and the scatterer SP dispersed in a second base resin BR2, and the third light control part CCP3 may include the scatterer SP dispersed in a third base resin BR3.

The base resins BR1, BR2, and BR3 are media in which the quantum dots QD1 and QD2 and the scatterer SP are dispersed accordingly, and may be formed of one or more suitable resin compositions, which may be generally referred to as a binder. For example, the base resins BR1, BR2, and BR3 may be each independently selected from among acrylic-based resins, urethane-based resins, silicone-based resins, epoxy-based resins, and/or the like. The base resins BR1, BR2, and BR3 may each be a transparent resin. In one or more embodiments, the first base resin BR1, the second base resin BR2, and the third base resin BR3 may be the same as or different from one another.

The light control layer CCL may include a barrier layer BFL1. The barrier layer BFL1 may serve to prevent or reduce the penetration of moisture and/or oxygen (hereinafter, referred to as ‘moisture/oxygen’). The barrier layer BFL1 may block the light control parts CCP1, CCP2, and CCP3 from being exposed to moisture/oxygen. The barrier layer BFL1 may cover the light control parts CCP1, CCP2, and CCP3. In one or more embodiments, a barrier layer BFL2 may be provided between the light control parts CCP1, CCP2, and CCP3 and the color filter layer CFL.

The barrier layers BFL1 and BFL2 may each include at least one inorganic layer. For example, in one or more embodiments, the barrier layers BFL1 and BFL2 may each include an inorganic material. For example, the barrier layers BFL1 and BFL2 may each independently include a silicon nitride, an aluminum nitride, a zirconium nitride, a titanium nitride, a hafnium nitride, a tantalum nitride, a silicon oxide, an aluminum oxide, a titanium oxide, a tin oxide, a cerium oxide, a silicon oxynitride, a metal thin film which secures a transmittance, and/or the like. In one or more embodiments, the barrier layers BFL1 and BFL2 may each independently further include an organic film. The barrier layers BFL1 and BFL2 may be each formed of a single layer or a plurality of layers.

In the display device DD-a of one or more embodiments, the color filter layer CFL may be arranged on the light control layer CCL. For example, in one or more embodiments, the color filter layer CFL may be directly arranged on the light control layer CCL. In these embodiments, the barrier layer BFL2 may not be provided.

The color filter layer CFL may include color filters CF1, CF2, and CF₃. The color filter layer CFL may include a first filter CF1 configured to transmit the second color light, a second filter CF2 configured to transmit the third color light, and a third filter CF3 configured to transmit the first color light. For example, in one or more embodiments, the first filter CF1 may be a red filter, the second filter CF2 may be a green filter, and the third filter CF3 may be a blue filter. The filters CF1, CF2, and CF3 each may include a polymeric photosensitive resin and a pigment and/or a dye. For example, in one or more embodiments, the first filter CF1 may include a red pigment and/or a red dye, the second filter CF2 may include a green pigment and/or a green dye, and the third filter CF3 may include a blue pigment and/or a blue dye.

However, embodiments of the present disclosure are not limited thereto, for example, in one or more embodiments, the third filter CF3 may not include (e.g., may exclude) a pigment or a dye. The third filter CF3 may include a polymeric photosensitive resin and may not include (e.g., may exclude) a pigment or a dye. The third filter CF3 may be transparent. In one or more embodiments, the third filter CF3 may be formed of a transparent photosensitive resin.

Furthermore, in one or more embodiments, the first filter CF1 and the second filter CF2 may be a yellow filter. The first filter CF1 and the second filter CF2 may not be separated but be provided as one filter.

In one or more embodiments, the color filter layer CFL may further include a light shielding part. The light shielding part may be a black matrix. The light shielding part may include an organic light shielding material and/or an inorganic light shielding material each containing a black pigment and/or a black dye. The light shielding part may prevent or reduce light leakage, and may separate boundaries between the adjacent filters CF1, CF2, and CF3.

The first to third filters CF1, CF2, and CF3 may be arranged corresponding to the red light emitting region PXA-R, the green light emitting region PXA-G, and the blue light emitting region PXA-B, respectively.

A base substrate BL may be arranged on the color filter layer CFL. The base substrate BL may be a member which provides a base surface on which the color filter layer CFL, the light control layer CCL, and/or the like are arranged. The base substrate BL may be a glass substrate, a metal substrate, a plastic substrate, and/or the like. However, embodiments of the present disclosure are not limited thereto, and the base substrate BL may be an inorganic layer, an organic layer, or a composite material layer. In one or more embodiments, the base substrate BL may not be provided.

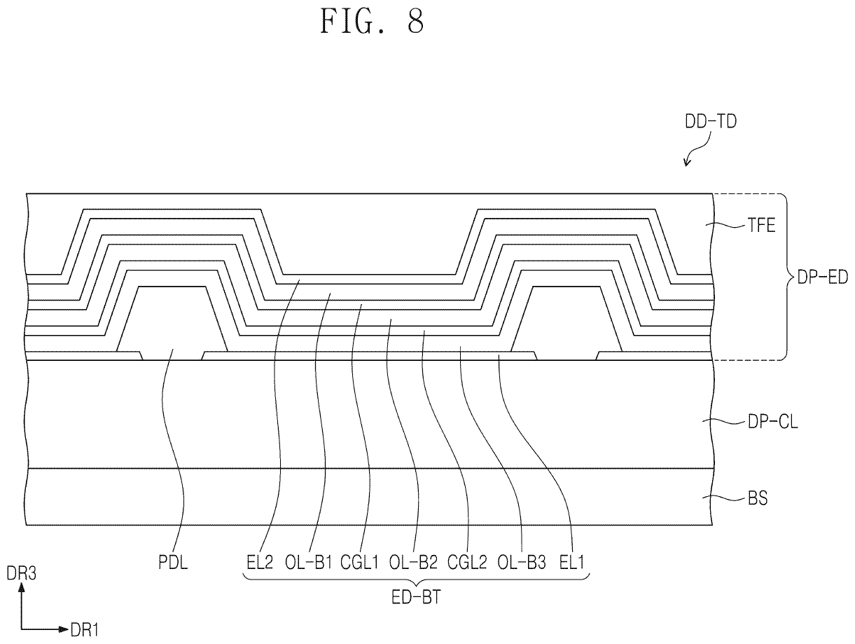

FIG. 8 is a cross-sectional view illustrating a portion of a display device according to one or more embodiments of the present disclosure. In a display device DD-TD of one or more embodiments, a light emitting element ED-BT may include a plurality of light emitting structures OL-B1, OL-B2, and OL-B3. The light emitting element ED-BT may include a first electrode EL1 and a second electrode EL2 which face each other, and the plurality of light emitting structures OL-B1, OL-B2, and OL-B3 sequentially stacked in a thickness direction (i.e., DR3) between the first electrode EL1 and the second electrode EL2. The light emitting structures OL-B1, OL-B2, and OL-B3 each may include an emission layer EML (FIG. 7) and a hole transport region HTR and an electron transport region ETR arranged with the emission layer EML (FIG. 7) located therebetween.

For example, the light emitting element ED-BT included in the display device DD-TD of one or more embodiments may be a light emitting element having a tandem structure and including a plurality of emission layers.

In one or more embodiments illustrated in FIG. 8, all light beams respectively emitted from the light emitting structures OL-B1, OL-B2, and OL-B3 may be blue color light. However, embodiments of the present disclosure are not limited thereto, for example, in one or more embodiments, the light beams respectively emitted from the light emitting structures OL-B1, OL-B2, and OL-B3 may have wavelength ranges different from one another. For example, in one or more embodiments, the light emitting element ED-BT including the plurality of light emitting structures OL-B1, OL-B2, and OL-B3 which emit light beams having wavelength ranges different from one another may be to emit white color light.

Charge generation layers CGL1 and CGL2 may be respectively arranged between neighboring light emitting structures OL-B1, OL-B2, and OL-B3. The charge generation layers CGL1 and CGL2 may each include a p-type (kind) charge generation layer and/or an n-type (kind) charge generation layer.

The fused polycyclic compound according to one or more embodiments described above may be included in at least one selected from among the emission structures OL-B1, OL-B2, and OL-B3 included in the display device DD-TD according to one or more embodiments. For example, at least one selected from among a plurality of emission layers included in the light emitting element ED-BT may include the fused polycyclic compound according to one or more embodiments.

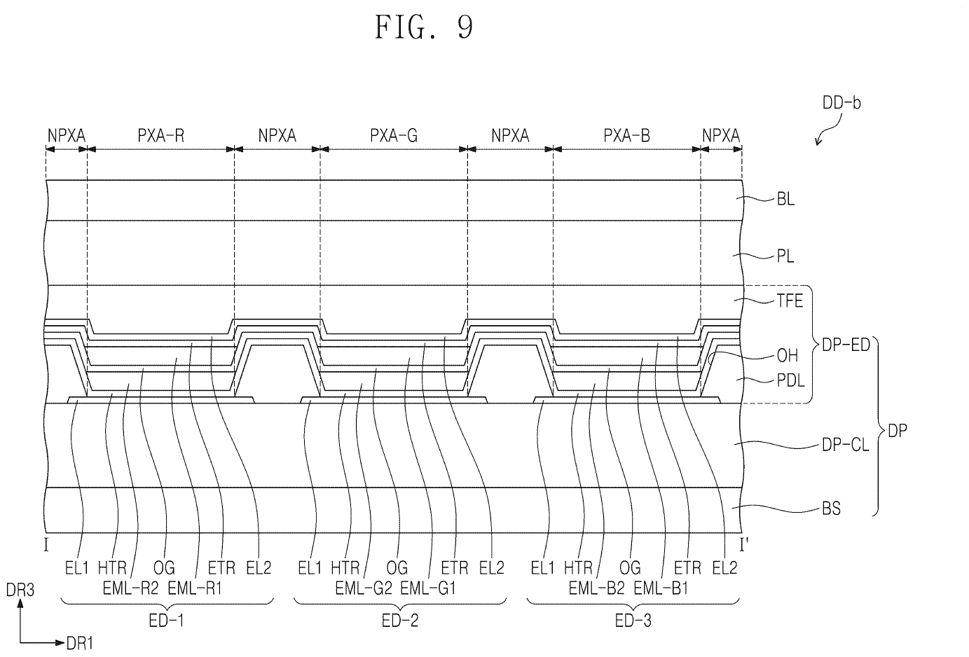

Referring to FIG. 9, a display device DD-b according to one or more embodiments may include light emitting elements ED-1, ED-2, and ED-3 in each of which two emission layers are stacked. Compared with the display device DD of one or more embodiments illustrated in FIG. 2, embodiments illustrated in FIG. 9 have a difference in that the first to third light emitting elements ED-1, ED-2, and ED-3 each include two emission layers stacked in a thickness direction. In each of the first to third light emitting elements ED-1, ED-2, and ED-3, the two emission layers may be to emit light in substantially the same wavelength region.

According to one or more embodiments, the first light emitting element ED-1 may include a first red emission layer EML-R1 and a second red emission layer EML-R2. The second light emitting element ED-2 may include a first green emission layer EML-G1 and a second green emission layer EML-G2. In addition, the third light emitting element ED-3 may include a first blue emission layer EML-B1 and a second blue emission layer EML-B2. An emission auxiliary part OG may be arranged between the first red emission layer EML-R1 and the second red emission layer EML-R2, between the first green emission layer EML-G1 and the second green emission layer EML-G2, and between the first blue emission layer EML-B1 and the second blue emission layer EML-B2. In this regard, at least one of the first blue-color emission layer EML-B1 or the second blue-color emission layer EML-B2 may include the fused polycyclic compound of embodiments.

The emission auxiliary part OG may include a single layer or a multilayer. The emission auxiliary part OG may include a charge generation layer. For example, the emission auxiliary part OG may include an electron transport region, a charge generation layer, and a hole transport region that are sequentially stacked. The emission auxiliary part OG may be provided as a common layer across the whole of the first to third light emitting elements ED-1, ED-2, and ED-3. However, embodiments of the present disclosure are not limited thereto, for example, in one or more embodiments, the emission auxiliary part OG may be provided by being patterned within openings OH defined in a pixel defining film PDL.

The first red emission layer EML-R₁, the first green emission layer EML-G1, and the first blue emission layer EML-B1 may each be arranged between the emission auxiliary part OG and an electron transport region ETR. The second red emission layer EML-R₂, the second green emission layer EML-G2, and the second blue emission layer EML-B2 may each be arranged between a hole transport region HTR and the emission auxiliary part OG.

For example, in one or more embodiments, the first light emitting element ED-1 may include a first electrode EL1, the hole transport region HTR, the second red emission layer EML-R₂, the emission auxiliary part OG, the first red emission layer EML-R₁, the electron transport region ETR, and a second electrode EL2 that are sequentially stacked. The second light emitting element ED-2 may include a first electrode EL1, the hole transport region HTR, the second green emission layer EML-G2, the emission auxiliary part OG, the first green emission layer EML-G1, the electron transport region ETR, and the second electrode EL2 that are sequentially stacked. The third light emitting element ED-3 may include a first electrode EL1, the hole transport region HTR, the second blue emission layer EML-B2, the emission auxiliary part OG, the first blue emission layer EML-B1, the electron transport region ETR, and the second electrode EL2 that are sequentially stacked.

An optical auxiliary layer PL may be arranged on the display element layer DP-ED. The optical auxiliary layer PL may include a polarizing layer. The optical auxiliary layer PL may be arranged on the display panel DP and control reflected light in the display panel DP due to external light. In one or more embodiments, the optical auxiliary layer PL may not be provided in the display device DD-b.

At least one emission layer included in the display device DD-b according to one or more embodiments illustrated in FIG. 9 may include the fused polycyclic compound according to one or more embodiments described above. For example, in one or more embodiments, at least one of a first blue-color emission layer EML-B1 or a second blue-color emission layer EML-B2 may include the fused polycyclic compound according to one or more embodiments.

Unlike FIGS. 8 and 9, FIG. 10 illustrates that a display device DD-c includes four light emitting structures OL-B1, OL-B2, OL-B3, and OL-C1. A light emitting element ED-CT may include a first electrode EL1 and a second electrode EL2 which face each other, and first to fourth light emitting structures OL-B1, OL-B2, OL-B3, and OL-C1 that are stacked in a thickness direction between the first electrode EL1 and the second electrode EL2. Charge generation layers CGL1, CGL2, and CGL3 may be respectively arranged between neighboring first to fourth light emitting structures OL-B1, OL-B2, OL-B3, and OL-C1. Among the four light emitting structures, the first to third light emitting structures OL-B1, OL-B2, and OL-B3 may each be to emit blue color light, and the fourth light emitting structure OL-C1 may be to emit green color light. However, embodiments of the present disclosure are not limited thereto, for example, in one or more embodiments, the first to fourth light emitting structures OL-B1, OL-B2, OL-B3, and OL-C1 may be to emit light beams in different wavelength regions.

The charge generation layers CGL1, CGL2, and CGL3 respectively arranged between adjacent light emitting structures OL-B1, OL-B2, OL-B3, and OL-C1 may each include a p-type (kind) charge generation layer and/or an n-type (kind) charge generation layer.

The fused polycyclic compound according to one or more embodiments described above may be included in at least one selected from among the emission structures OL-B1, OL-B2, OL-B3, and OL-C1 included in the display device DD-c according to one or more embodiments. For example, in one or more embodiments, at least one selected from among the first to third emission structures OL-B1, OL-B2, and OL-B3 may include the fused polycyclic compound according to one or more embodiments described above.

The light emitting element ED according to one or more embodiments of the disclosure may include the polycyclic compound according to one or more embodiments, represented by Formula 1 described above, in at least one functional layer arranged between the first electrode EL1 and the second electrode EL2, thereby exhibiting excellent or suitable luminescence efficiency and improved lifespan characteristics. For example, the polycyclic compound according to one or more embodiments may be included in the emission layer EML of the light emitting element ED according to one or more embodiments, and the light emitting element according to one or more embodiments may have long lifespan characteristics.

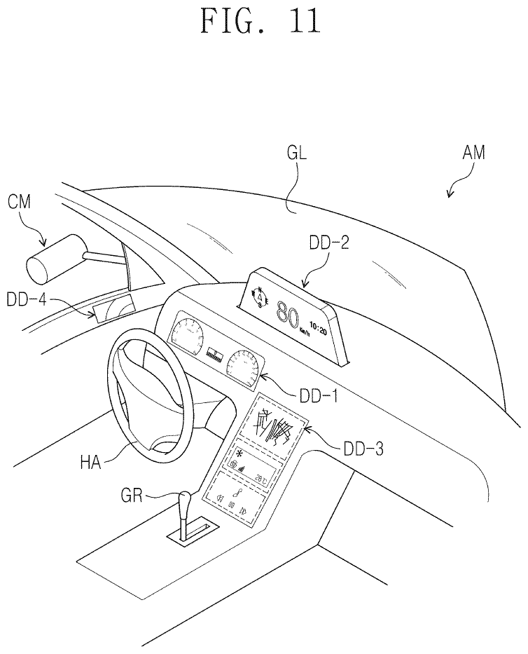

FIG. 11 is a view illustrating a vehicle AM in which first to fourth display devices DD-1, DD-2, DD-3, and DD-4 are arranged. At least one selected from among the first to fourth display devices DD-1, DD-2, DD-3, and DD-4 may include a same configuration as one of the display devices DD, DD-TD, DD-a, DD-b, and DD-c described with reference to FIGS. 1, and 2, and 7 to 10.

FIG. 11 illustrates a vehicle AM, but this is a mere example, and the first to fourth display devices DD-1, DD-2, DD-3, and DD-4 may be arranged in other transportation apparatuses such as bicycles, motorcycles, trains, ships, and/or airplanes. In one or more embodiments, at least one selected from among the first to fourth display devices DD-1, DD-2, DD-3, and DD-4 including the same configuration as one of the display devices DD, DD-TD, DD-a, DD-b, and DD-c of one or more embodiments may be employed in a personal computer, a laptop computer, a personal digital terminal, a game console, a portable electronic device, a television, a monitor, an outdoor billboard, and/or the like. These are merely provided as example embodiments, and thus the display device may be employed in other electronic apparatuses unless departing from the disclosure. For example, in one or more embodiments, the electronic apparatus may be at least one selected from among a large-size display device including a television, a monitor, and an outdoor billboard, and a small- and medium-size display device including a personal computer, a laptop computer, a personal digital assistant, a vehicular display device, a game console, a portable electronic device, and a camera.

At least one selected from among the first to fourth display devices DD-1, DD-2, DD-3, and DD-4 may include the light emitting element ED of one or more embodiments described with reference to FIGS. 3 to 6.

At least one selected from among first to fourth display devices DD-1, DD-2, DD-3, and DD-4 may include any one of the light emitting elements ED according to embodiments described with reference to FIGS. 3 to 6. The light emitting element ED according to one or more embodiments may include the fused polycyclic compound according to one or more embodiments. At least one selected from among the first to fourth display devices DD-1, DD-2, DD-3, and DD-4 may include the light emitting element ED containing the fused polycyclic compound according to one or more embodiments, and may thus have improved display lifespan.

Referring to FIG. 11, the vehicle AM may include a steering wheel HA and a gear GR for driving the vehicle AM. In addition, the vehicle AM may include a front window GL arranged so as to face a driver.

The first display device DD-1 may be arranged in a first region overlapping the steering wheel HA. For example, the first display device DD-1 may be a digital cluster which displays first information of the vehicle AM. The first information may include a first scale which indicates a driving speed of the vehicle AM, a second scale which indicates an engine speed (that is, revolutions per minute (RPM)), an image which indicates a fuel state, and/or the like. The first scale and the second scale may be indicated as a digital image.

The second display device DD-2 may be arranged in a second region opposite to (e.g., facing) a driver seat and overlapping the front window GL. The driver seat may be a seat which the steering wheel HA faces. For example, the second display device DD-2 may be a head up display (HUD) which displays second information of the vehicle AM. In one or more embodiments, the second display device DD-2 may be optically transparent. The second information may include digital numbers which indicate a driving speed, and may further include information such as the current time. In one or more embodiments, the second information of the second display device DD-2 may be projected to the front window GL to be displayed.

The third display device DD-3 may be arranged in a third region adjacent to the gear GR. For example, the third display device DD-3 may be arranged between the driver seat and a passenger seat and may be a center information display (CID) for a vehicle for displaying third information. The passenger seat may be a seat spaced and/or apart (e.g., spaced apart or separated) from the driver seat with the gear GR arranged therebetween. The third information may include information about traffic (e.g., navigation information), playing music or radio or a video (or an image), temperatures inside the vehicle AM, and/or the like.

The fourth display device DD-4 may be spaced and/or apart (e.g., spaced apart or separated) from the steering wheel HA and the gear GR, and may be arranged in a fourth region adjacent to a side of the vehicle AM. For example, the fourth display device DD-4 may be a digital side-view mirror which displays fourth information. The fourth display device DD-4 may display an image outside the vehicle AM taken by a camera module CM arranged outside the vehicle AM. The fourth information may include an image outside the vehicle AM.

The above-described first to fourth information may be examples, and the first to fourth display devices DD-1, DD-2, DD-3, and DD-4 may further display information about the inside and outside of the vehicle AM. The first to fourth information may include different information. However, embodiments of the present disclosure are not limited thereto, and a part of the first to fourth information may include the same information as one another.

Hereinafter, with reference to Examples and Comparative Examples, the fused polycyclic compound according to one or more embodiments of the disclosure and the light emitting element according to one or more embodiments will be described in more detail. In addition, the following examples are intended to help understanding of the disclosure, and the scope of the disclosure is not limited thereto.

### EXAMPLE

### 1. Synthesis of Fused Polycyclic Compound

First, a method for synthesizing the fused polycyclic compound according to one or more embodiments will be described in more detail by exemplifying the synthesis method of Compound 51, 137, 138, 139, 140, 182, 183, 222, 226, 228, 240, 263, 264, 401, and 543. In addition, the methods for synthesizing the fused polycyclic compounds to be described hereinafter are mere examples, and the method for synthesizing the fused polycyclic compound according to one or more embodiments of the disclosure is not limited to the following examples.

### (1) Synthesis of Compound 51

### Synthesis of Intermediate 51-(1)

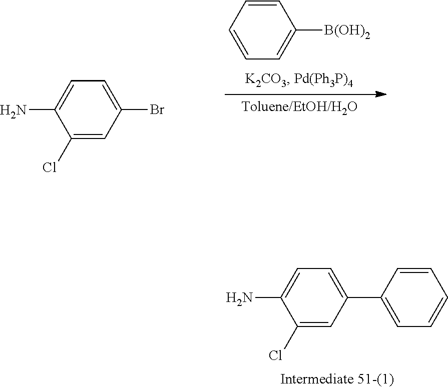 [SMILES: OB(O)c1ccccc1 ; Nc1ccc(Br)cc1Cl ; Nc1ccc(-c2ccccc2)cc1Cl]

Under an argon (Ar) atmosphere, 120.24 mL of toluene and 60.12 mL of a mixture of EtOH and water in 1:1 were added to 4-bromo-2-chloroaniline (15.03 g, 72.74 mmol) and phenylboronic acid (31.04 g, 254.57 mmol), K₂CO₃ (60.32 g, 436.41 mmol), and Pd(Ph₃P)₄ (13.03 g, 11.27 mmol) in a reaction vessel, and then heated for about 24 hours while the outside temperature of the reaction vessel was maintained at about 80° C. After cooling, the mixture was filtered through celite and separated to concentrate an organic layer. The organic layer was purified with silica gel column chromatography to obtain Intermediate 51-(1) (about 12.59 g, about 85% yield). The molecular weight of Intermediate 51-(1) was about 204 from fast atom bombardment mass spectrometry (FAB MS) measurement.

### Synthesis of Intermediate 51-(2)

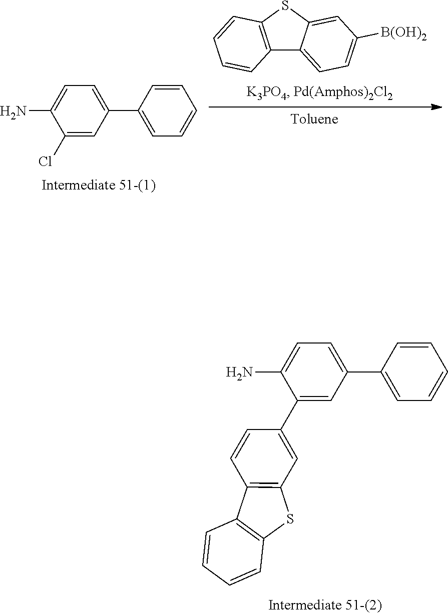 [SMILES: OB(O)c1ccc2c(c1)sc1ccccc12 ; Nc1ccc(-c2ccccc2)cc1Cl ; Nc1ccc(-c2ccccc2)cc1-c1ccc2c(c1)sc1ccccc12]

Under an Ar atmosphere, 96.32 mL of toluene and 48.16 mL of a mixture of EtOH and water in 1:1 were added to Intermediate 51-(1) (12.04 g, 59.12 mmol) and dibenzo[b,d]thiophen-3-ylboronic acid (17.53 g, 76.85 mmol), K₃PO₄ (25.1 g, 118.23 mmol), bis(di-tert-butyl(4-dimethylaminophenyl)phosphine) dichloropalladium (II) (Pd(Amphos)₂Cl₂) (4.19 g, 5.91 mmol) in a reaction vessel, and then heated for about 24 hours while the outside temperature of the reaction vessel was maintained at about 40° C. After cooling, the mixture was filtered through celite and separated to concentrate an organic layer. The organic layer was purified with silica gel column chromatography to obtain Intermediate 51-(2) (about 16.83 g, about 81% yield). The molecular weight of Intermediate 51-(2) was about 351 from FAB MS measurement.

### Synthesis of Intermediate 51-(3)

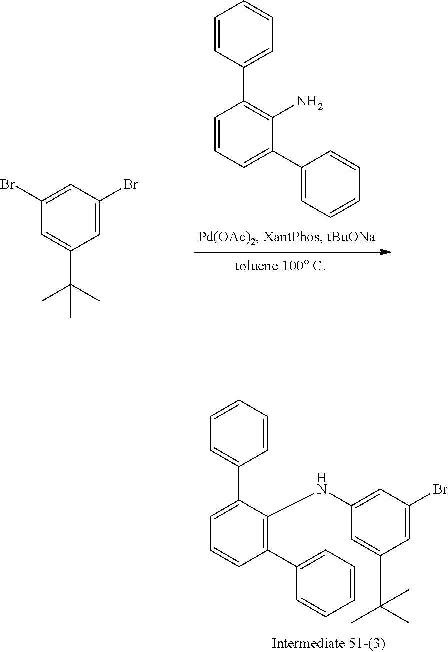 [SMILES: CC(C)(C)c1cc(Br)cc(Br)c1 ; Nc1c(-c2ccccc2)cccc1-c1ccccc1 ; CC(C)(C)c1cc(Br)cc(Nc2c(-c3ccccc3)cccc2-c2ccccc2)c1]

Under an Ar atmosphere, 1,3-dibromo-5-(tert-butyl)benzene (15.22 g, 52.12 mmol) and [1,1′:3′,1″-terphenyl]-2′-amine (14.07 g, 57.33 mmol), palladium (II) acetate (Pd(OAc) 2) (0.35 g, 1.56 mmol), (9,9-dimethyl-9H-xanthene-4,5-diyl)bis(diphenylphosphane) (XantPhos) (1.81 g, 3.13 mmol), sodium tert-butoxide (tBuONa) (6.01 g, and 62.55 mmol) were added to 260 mL of toluene, and heated and agitated for about 8 hours at about 100° C. After cooling, water was added, and the mixture was filtered through celite and separated to concentrate an organic layer. The organic layer was purified with silica gel column chromatography to obtain Intermediate 51-(3) (about 17.73 g, about 72% yield). The molecular weight of Intermediate 51-(3) was about 472 from FAB MS measurement.

### Synthesis of Intermediate 51-(4)

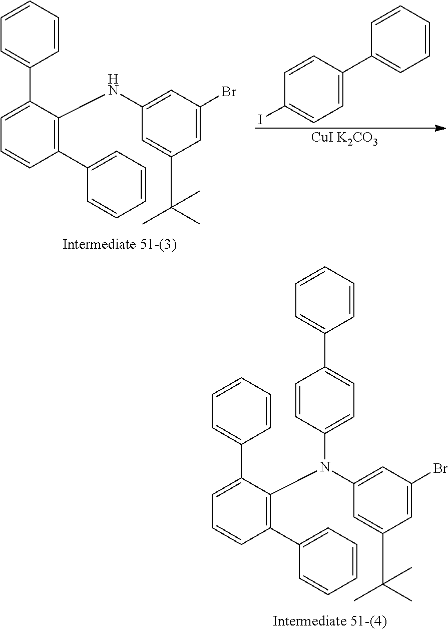

A small amount of toluene in about 10 mL was added to Intermediate 51-(3) (15.04 g, 31.83 mmol) and 4-iodo-1,1′-biphenyl (89.17 g, 318.33 mmol), CuI (15.16 g, 79.58 mmol), and K₂CO₃ (65.99 g, 477.49 mmol) in a reaction vessel, and heated for about 24 hours while the outside temperature of the reaction vessel was maintained at about 215° C. After cooling, the mixture was diluted with CH₂Cl₂ and water was added thereto, and the reaction solution was filtered through celite and separated to concentrate an organic layer. The organic layer was purified with silica gel column chromatography to obtain Intermediate 51-(4) (about 16.11 g, about 81% yield). The molecular weight of Intermediate 51-(4) was about 625 from FAB MS measurement.

### Synthesis of Intermediate 51-(5)

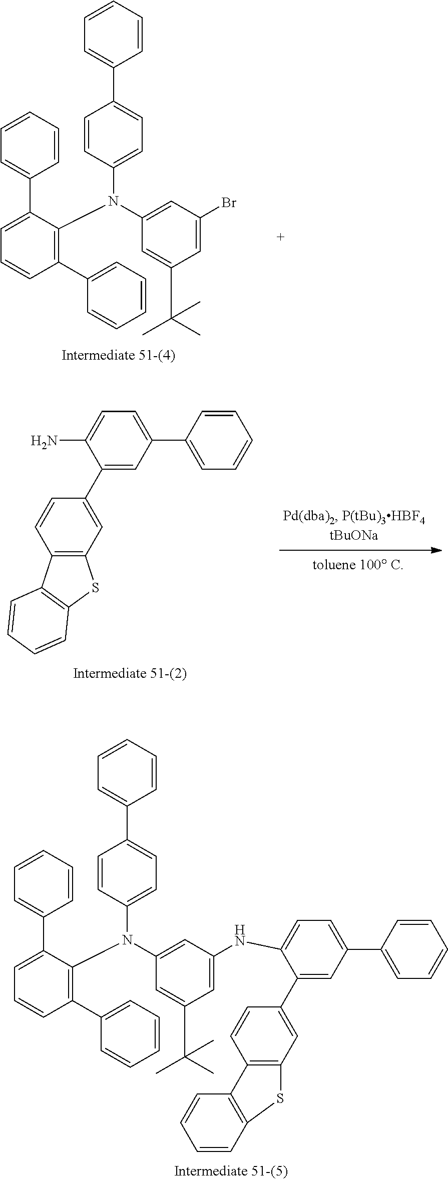 [SMILES: CC(C)(C)c1cc(Br)cc(N(c2ccc(-c3ccccc3)cc2)c2c(-c3ccccc3)cccc2-c2ccccc2)c1 ; Nc1ccc(-c2ccccc2)cc1-c1ccc2c(c1)sc1ccccc12 ; CC(C)(C)c1cc(Nc2ccc(-c3ccccc3)cc2-c2ccc3c(c2)sc2ccccc23)cc(N(c2ccc(-c3ccccc3)cc2)c2c(-c3ccccc3)cccc2-c2ccccc2)c1]

Under an Ar atmosphere, Intermediate 51-(4) (7.05 g, 11.29 mmol) and Intermediate 51-(2) (4.17 g, 11.85 mmol), bis(dibenzylideneacetone) palladium (0) (Pd(dba) 2) (0.65 g, 1.13 mmol), P(tBu)₃·HBF₄ (0.65 g, 2.26 mmol), and tBuONa (2.49 g, 25.96 mmol) were added to 56 mL of toluene, and heated and agitated for about 8 hours at about 100° C. After cooling, water was added, and the mixture was filtered through celite and separated to concentrate an organic layer. The organic layer was purified with silica gel column chromatography to obtain Intermediate 51-(5) (about 8.49 g, about 84% yield). The molecular weight of Intermediate 51-(5) was about 895 from FAB MS measurement.

### Synthesis of Intermediate 51-(6)

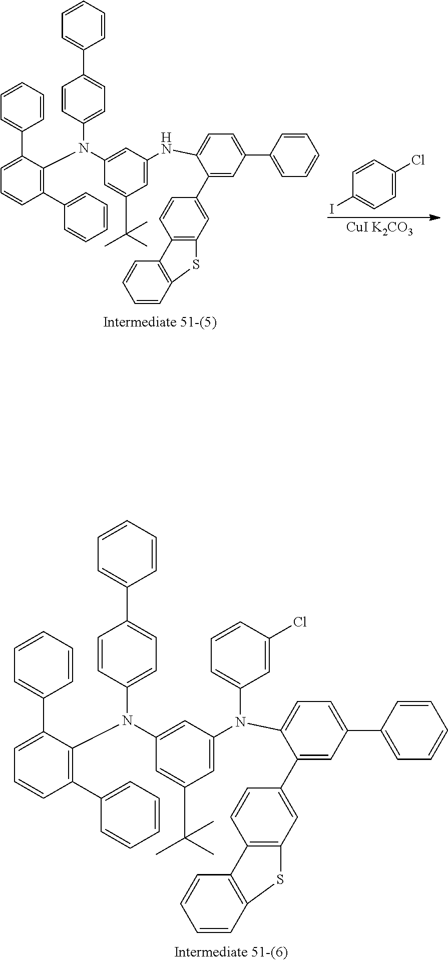

A small amount of toluene in about 10 mL was added to Intermediate 51-(5) (8.11 g, 9.06 mmol) and 1-chloro-3-iodobenzene (21.6 g, 90.59 mmol), CuI (4.31 g, 22.65 mmol), and K₂CO₃ (18.78 g, 135.89 mmol) in a reaction vessel, and heated for about 24 hours while the outside temperature of the reaction vessel was maintained at about 215° C. After cooling, the mixture was diluted with CH₂Cl₂ and water was added thereto, and the reaction solution was filtered through celite and separated to concentrate an organic layer. The organic layer was purified with silica gel column chromatography to obtain Intermediate 51-(6) (about 7.11 g, about 78% yield). The molecular weight of Intermediate 51-(6) was about 1006 from FAB MS measurement.

### Synthesis of Intermediate 51-(7)

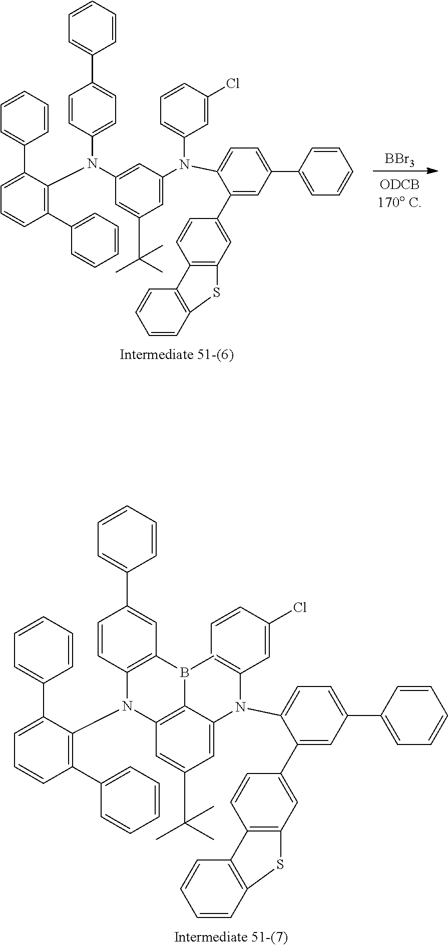

Under an Ar atmosphere, Intermediate 51-(6) (6.55 g, 6.51 mmol) was dissolved in ortho dichlorobenzene (ODCB) (65 mL), BBr₃ (3.26 g, 13.02 mmol) was added thereto, and heated and agitated for about 10 hours at about 170° C. The reaction solution was then cooled to room temperature, N, N-diisopropylethylamine (DIPEA) (10.08 g, 78.15 mmol) was added, and water was added thereto, and the reaction solution was filtered through celite and separated to concentrate an organic layer. The organic layer was purified with silica gel column chromatography to obtain Intermediate 51-(7) (about 2.51 g, about 38% yield). The molecular weight of Intermediate 51-(7) was about 1014 from FAB MS measurement.

### Synthesis of Compound 51

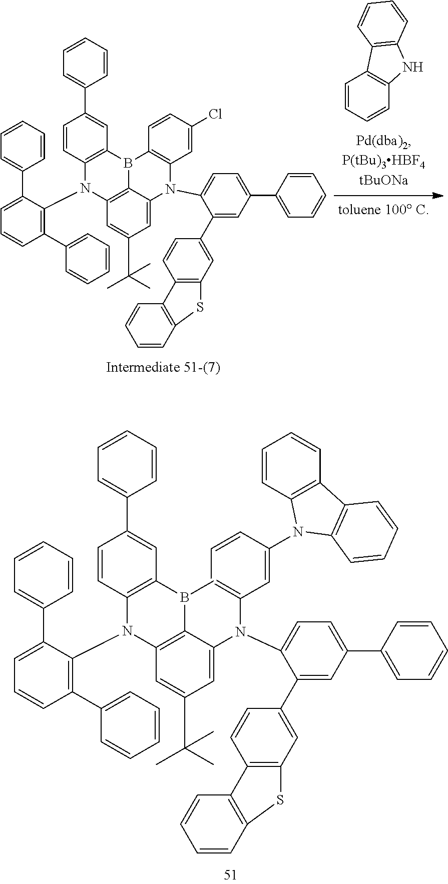

Under an Ar atmosphere, Intermediate 51-(7) (2.33 g, 2.3 mmol) and 9H-carbazole (0.58 g, 3.45 mmol), Pd(dba) 2 (0.13 g, 0.23 mmol), P(tBu)₃·HBF₄ (0.13 g, 0.46 mmol), and tBuONa (0.51 g, 5.29 mmol) were added to 11 mL of toluene, and heated and agitated for about 8 hours at about 100° C. After cooling, water was added, and the mixture was filtered through celite and separated to concentrate an organic layer. The organic layer was purified with silica gel column chromatography to obtain Compound 51 (about 2.37 g, about 90% yield). The molecular weight of Compound 51 was about 1144 from FAB MS measurement. Sublimation purification (about 320° C., 3.3×10⁻³ Pa) was further performed for device evaluation.

### (1) Synthesis of Compound 137

### Synthesis of Intermediate 137-(1)

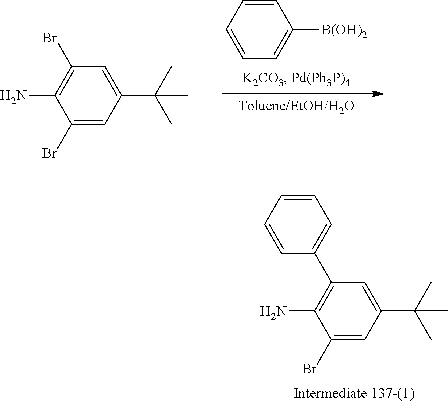 [SMILES: CC(C)(C)c1cc(Br)c(N)c(Br)c1 ; OB(O)c1ccccc1 ; CC(C)(C)c1cc(Br)c(N)c(-c2ccccc2)c1]

Under an Ar atmosphere, 200 mL of toluene and 100 mL of a mixture of EtOH and water in 1:1 were added to 2,6-dibromo-4-(tert-butyl) aniline (25 g, 81.43 mmol) and phenylboronic acid (9.93 g, 81.43 mmol), K₂CO₃ (67.52 g, 488.55 mmol), and Pd(Ph₃P) 4 (14.58 g, 12.62 mmol) in a reaction vessel, and then heated for about 24 hours while the outside temperature of the reaction vessel was maintained at about 80° C. After cooling, the mixture was filtered through celite and separated to concentrate an organic layer. The organic layer was purified with silica gel column chromatography to obtain Intermediate 137-(1) (about 18.58 g, about 75% yield). The molecular weight of Intermediate 137-(1) was about 304 from FAB MS measurement.

### Synthesis of Intermediate 137-(2)

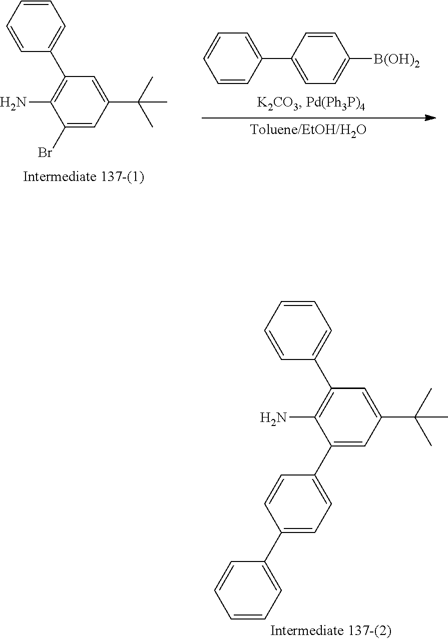 [SMILES: CC(C)(C)c1cc(Br)c(N)c(-c2ccccc2)c1 ; OB(O)c1ccc(-c2ccccc2)cc1 ; CC(C)(C)c1cc(-c2ccccc2)c(N)c(-c2ccc(-c3ccccc3)cc2)c1]

Under an Ar atmosphere, 100.4 mL of toluene and 50.2 mL of a mixture of EtOH and water in 1:1 were added to Intermediate 137-(1) (12.55 g, 41.25 mmol) and [1,1′-biphenyl]-4-ylboronic acid (12.25 g, 61.88 mmol), K₂CO₃ (34.21 g, 247.51 mmol), and Pd(Ph₃P) 4 (7.39 g, 6.39 mmol) in a reaction vessel, and then heated for about 24 hours while the outside temperature of the reaction vessel was maintained at about 80° C. After cooling, the mixture was filtered through celite and separated to concentrate an organic layer. The organic layer was purified with silica gel column chromatography to obtain Intermediate 137-(2) (about 13.7 g, about 88% yield). The molecular weight of Intermediate 137-(2) was about 378 from FAB MS measurement.

### Synthesis of Intermediate 137-(3)

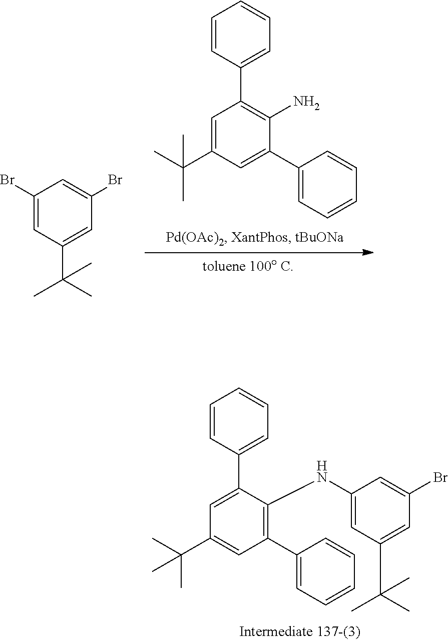

Under an Ar atmosphere, 1,3-dibromo-5-(tert-butyl)benzene (15.11 g, 51.74 mmol) and 5′-(tert-butyl)-[1,1′: 3′,1″-terphenyl]-2′-amine (17.16 g, 56.92 mmol), Pd(OAc)₂ (0.35 g, 1.55 mmol), XantPhos (1.8 g, 3.1 mmol), tBuONa (5.97 g, 62.09 mmol) were added to 258 mL of toluene, and heated and agitated for about 8 hours at about 100° C. After cooling, water was added, and the mixture was filtered through celite and separated to concentrate an organic layer. The organic layer was purified with silica gel column chromatography to obtain Intermediate 137-(3) (about 21.22 g, about 80% yield). The molecular weight of Intermediate 137-(3) was about 513 from FAB MS measurement.

### Synthesis of Intermediate 137-(4)

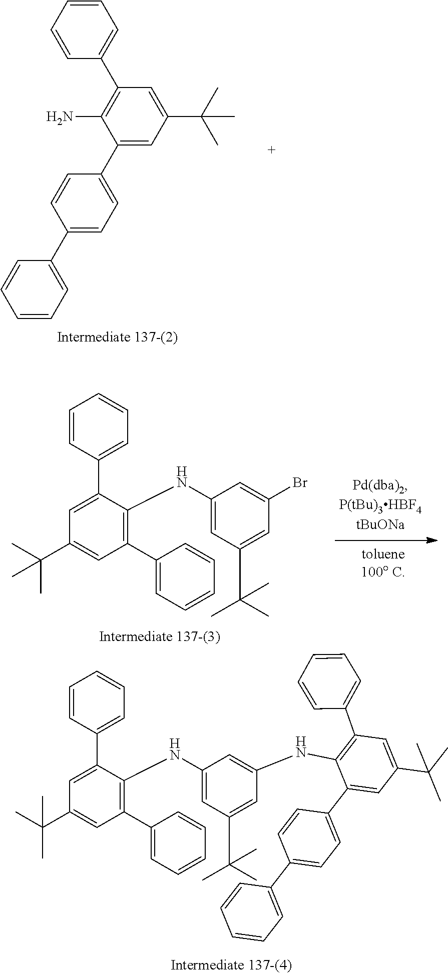 [SMILES: CC(C)(C)c1cc(-c2ccccc2)c(N)c(-c2ccc(-c3ccccc3)cc2)c1 ; CC(C)(C)c1cc(Br)cc(Nc2c(-c3ccccc3)cc(C(C)(C)C)cc2-c2ccccc2)c1 ; CC(C)(C)c1cc(Nc2c(-c3ccccc3)cc(C(C)(C)C)cc2-c2ccccc2)cc(Nc2c(-c3ccccc3)cc(C(C)(C)C)cc2-c2ccc(-c3ccccc3)cc2)c1]

Under an Ar atmosphere, Intermediate 137-(3) (10.02 g, 19.55 mmol) and Intermediate 137-(2) (11.07 g, 29.32 mmol), Pd(dba) 2 (1.12 g, 1.95 mmol), P(tBu)₃·HBF₄ (1.13 g, 3.91 mmol), and tBuONa (4.32 g, 44.96 mmol) were added to 97 mL of toluene, and heated and agitated for about 8 hours at about 100° C. After cooling, water was added, and the mixture was filtered through celite and separated to concentrate an organic layer. The organic layer was purified with silica gel column chromatography to obtain Intermediate 137-(4) (about 13.13 g, about 83% yield). The molecular weight of Intermediate 137-(4) was about 809 from FAB MS measurement.

### Synthesis of Intermediate 137-(5)

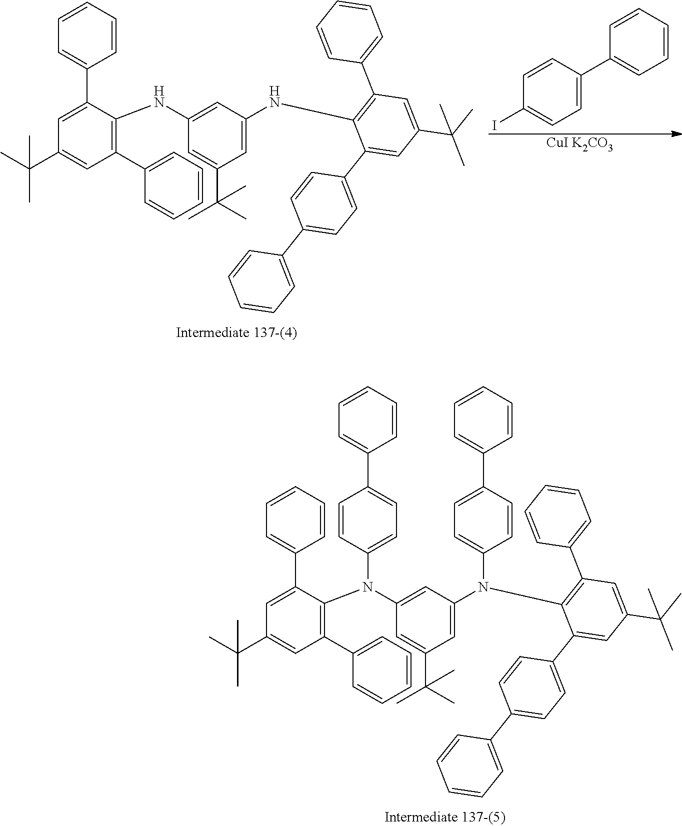

A small amount of toluene in about 10 mL was added to Intermediate 137-(4) (6.02 g, 7.44 mmol) and 4-iodo-1,1′-biphenyl (20.84 g, 74.4 mmol), CuI (3.54 g, 18.6 mmol), and K₂CO₃ (15.42 g, 111.6 mmol) in a reaction vessel, and heated for about 24 hours while the outside temperature of the reaction vessel was maintained at about 215° C. After cooling, the mixture was diluted with CH₂Cl₂ and water was added thereto, and the reaction solution was filtered through celite and separated to concentrate an organic layer. The organic layer was purified with silica gel column chromatography to obtain Intermediate 137-(5) (about 7.12 g, about 86% yield). The molecular weight of Intermediate 137-(5) was about 1114 from FAB MS measurement.

### Synthesis of Compound 137

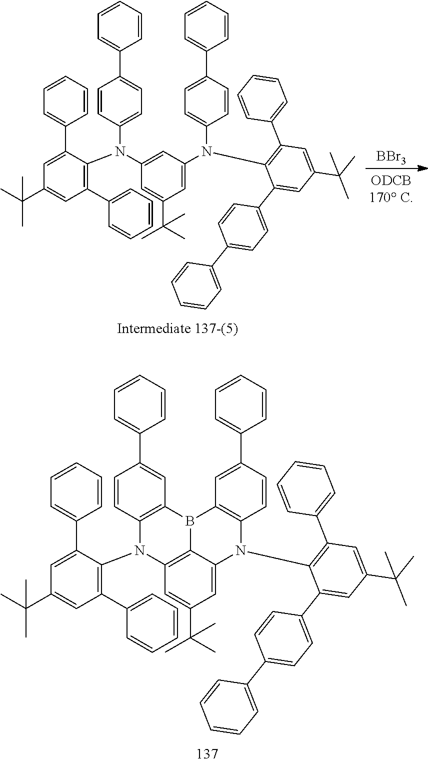

Under an Ar atmosphere, Intermediate 137-(5) (6.55 g, 5.88 mmol) was dissolved in ODCB (59 mL), BBr₃ (2.95 g, 11.76 mmol) was added thereto, and heated and agitated for about 10 hours at about 170° C. The reaction solution was then cooled to room temperature, DIPEA (9.11 g, 70.59 mmol) was added, and water was added thereto, and the reaction solution was filtered through celite and separated to concentrate an organic layer. The organic layer was purified with silica gel column chromatography to obtain Compound 137 (about 2.97 g, about 45% yield). The molecular weight of Compound 137 was about 1121 from FAB MS measurement. Sublimation purification (about 300° C., 2.8×10⁻³ Pa) was further performed for device evaluation.

### (2) Synthesis of Compound 138

### Synthesis of Intermediate 138-(1)

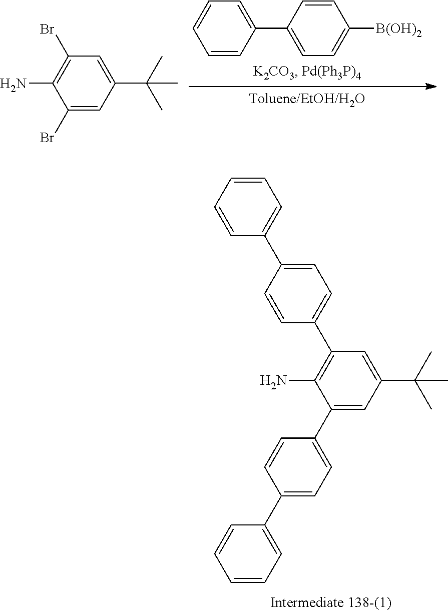

Under an Ar atmosphere, 88.48 mL of toluene and 44.24 mL of a mixture of EtOH and water in 1:1 were added to 2,6-dibromo-4-(tert-butyl) aniline (11.06 g, 36.02 mmol) and [1,1′-biphenyl]-4-ylboronic acid (21.4 g, 108.07 mmol), K₂CO₃ (29.87 g, 216.14 mmol), and Pd(Ph₃P) 4 (6.45 g, 5.58 mmol) in a reaction vessel, and then heated for about 24 hours while the outside temperature of the reaction vessel was maintained at about 80° C. After cooling, the mixture was filtered through celite and separated to concentrate an organic layer. The organic layer was purified with silica gel column chromatography to obtain Intermediate 138-(1) (about 14.38 g, about 88% yield). The molecular weight of Intermediate 138-(1) was about 454 from FAB MS measurement.

### Synthesis of Intermediate 138-(2)

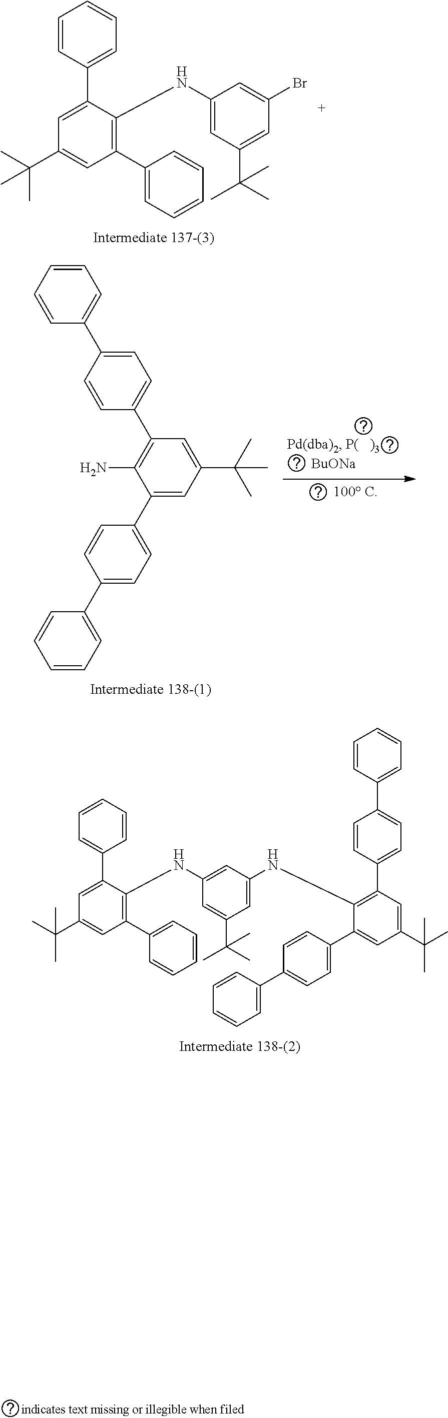

Under an Ar atmosphere, Intermediate 137-(3) (7.04 g, 13.74 mmol) and Intermediate 138-(1) (7.48 g, 16.48 mmol), Pd(dba) 2 (0.79 g, 1.37 mmol), P(tBu)₃·HBF₄ (0.8 g, 2.75 mmol), and tBuONa (3.04 g, 31.59 mmol) were added to 68 mL of toluene, and heated and agitated for about 8 hours at about 100° C. After cooling, water was added, and the mixture was filtered through celite and separated to concentrate an organic layer. The organic layer was purified with silica gel column chromatography to obtain Intermediate 138-(2) (about 9.48 g, about 78% yield). The molecular weight of Intermediate 138-(2) was about 885 from FAB MS measurement.

### Synthesis of Intermediate 138-(3)

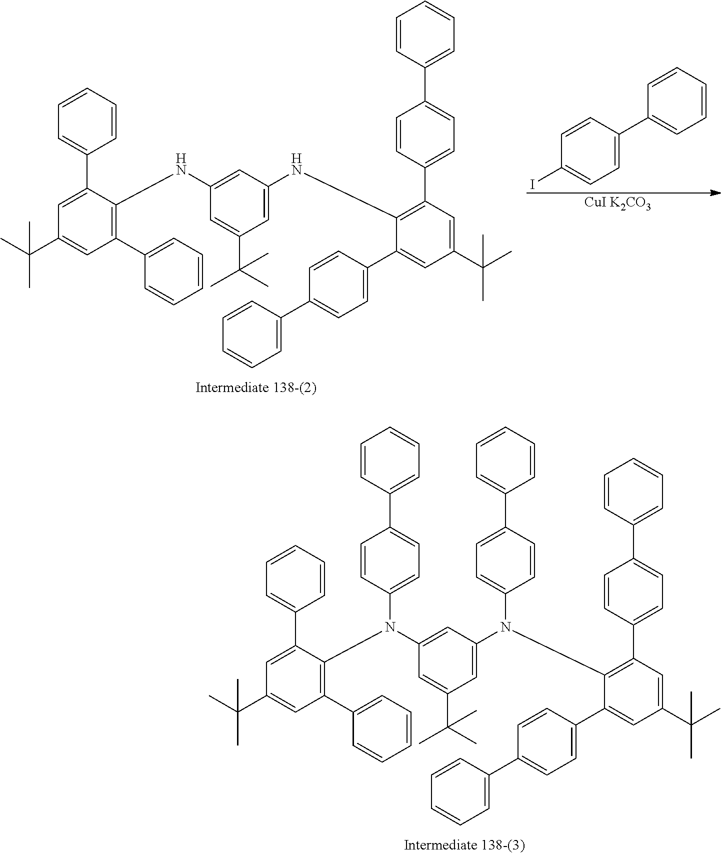

A small amount of toluene in about 10 mL was added to Intermediate 138-(2) (9.02 g, 10.19 mmol) and 4-iodo-1,1′-biphenyl (28.54 g, 101.89 mmol), CuI (4.85 g, 25.47 mmol), and K₂CO₃ (21.12 g, 152.84 mmol) in a reaction vessel, and heated for about 24 hours while the outside temperature of the reaction vessel was maintained at about 215° C. After cooling, the mixture was diluted with CH₂Cl₂ and water was added thereto, and the reaction solution was filtered through celite and separated to concentrate an organic layer. The organic layer was purified with silica gel column chromatography to obtain Intermediate 138-(3) (about 10.55 g, about 87% yield). The molecular weight of Intermediate 138-(3) was about 1190 from FAB MS measurement.

### Synthesis of Compound 138

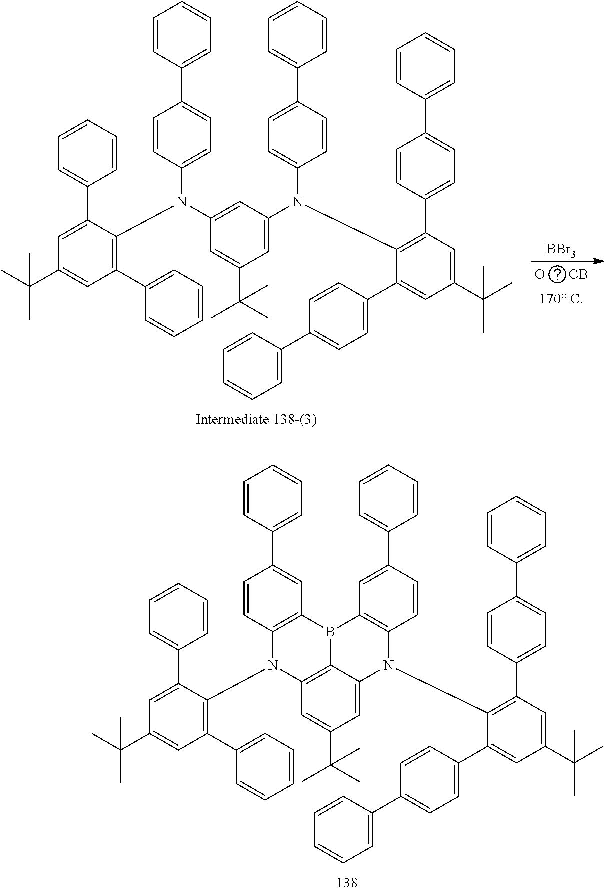

Under an Ar atmosphere, Intermediate 138-(3) (5.01 g, 4.21 mmol) was dissolved in ODCB (42 mL), BBr₃ (2.11 g, 8.42 mmol) was added thereto, and heated and agitated for about 10 hours at about 170° C. The reaction solution was then cooled to room temperature, DIPEA (6.52 g, 50.54 mmol) was added, and water was added thereto, and the reaction solution was filtered through celite and separated to concentrate an organic layer. The organic layer was purified with silica gel column chromatography to obtain Compound 138 (about 2.07 g, about 41% yield). The molecular weight of Compound 138 was about 1197 from FAB MS measurement. Sublimation purification (about 320° C., 2.5×10⁻³ Pa) was further performed for device evaluation.

### (3) Synthesis of Compound 139

### Synthesis of Intermediate 139-(1)

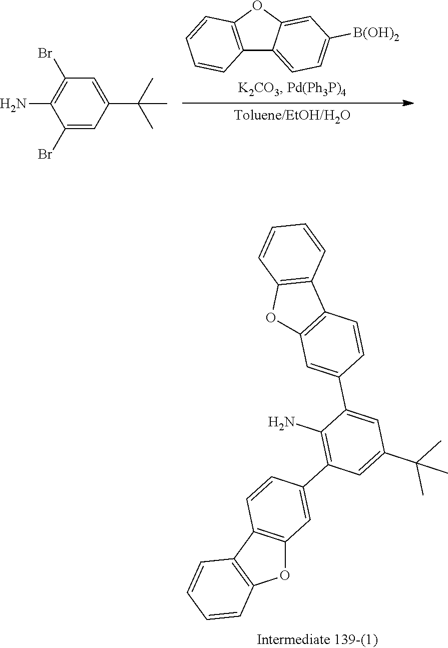

Under an Ar atmosphere, 64.16 mL of toluene and 32.08 mL of a mixture of EtOH and water in 1:1 were added to 2,6-dibromo-4-(tert-butyl) aniline (8.02 g, 26.12 mmol) and dibenzo[b,d]furan-3-ylboronic acid (15.52 g, 78.36 mmol), K₂CO₃ (21.66 g, 156.73 mmol), and Pd(Ph₃P) 4 (4.68 g, 4.05 mmol) in a reaction vessel, and then heated for about 24 hours while the outside temperature of the reaction vessel was maintained at about 80° C. After cooling, the mixture was filtered through celite and separated to concentrate an organic layer. The organic layer was purified with silica gel column chromatography to obtain Intermediate 139-(1) (about 9.72 g, about 82% yield). The molecular weight of Intermediate 139-(1) was about 454 from FAB MS measurement.

### Synthesis of Intermediate 139-(2)

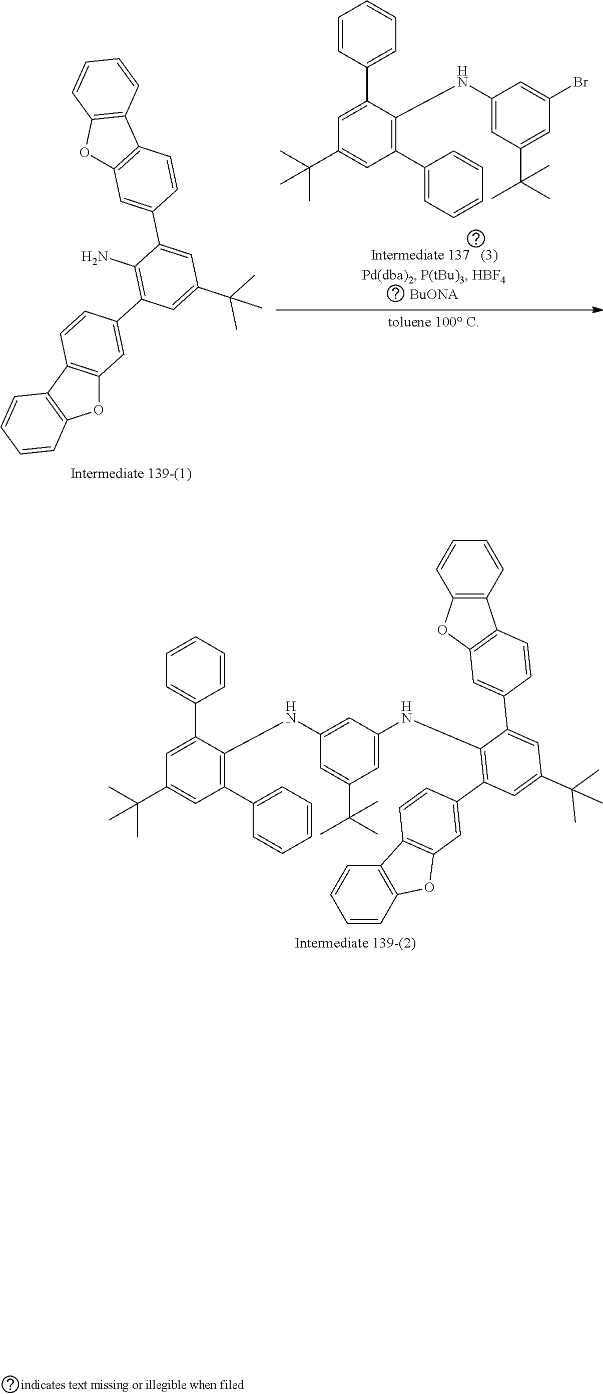 [SMILES: CC(C)(C)c1cc(-c2ccc3c(c2)oc2ccccc23)c(N)c(-c2ccc3c(c2)oc2ccccc23)c1 ; CC(C)(C)c1cc(Br)cc(Nc2c(-c3ccccc3)cc(C(C)(C)C)cc2-c2ccccc2)c1 ; CC(C)(C)c1cc(Nc2c(-c3ccccc3)cc(C(C)(C)C)cc2-c2ccccc2)cc(Nc2c(-c3ccc4c(c3)oc3ccccc34)cc(C(C)(C)C)cc2-c2ccc3c(c2)oc2ccccc23)c1]

Under an Ar atmosphere, Intermediate 137-(3) (9.52 g, 18.57 mmol) and Intermediate 139-(1) (10.73 g, 22.29 mmol), Pd(dba) 2 (1.07 g, 1.86 mmol), P(tBu)₃·HBF₄ (1.08 g, 3.71 mmol), and tBuONa (4.11 g, 42.72 mmol) were added to 92 mL of toluene, and heated and agitated for about 8 hours at about 100° C. After cooling, water was added, and the mixture was filtered through celite and separated to concentrate an organic layer. The organic layer was purified with silica gel column chromatography to obtain Intermediate 139-(2) (about 12.89 g, about 76% yield). The molecular weight of Intermediate 139-(2) was about 913 from FAB MS measurement.

### Synthesis of Intermediate 139-(3)

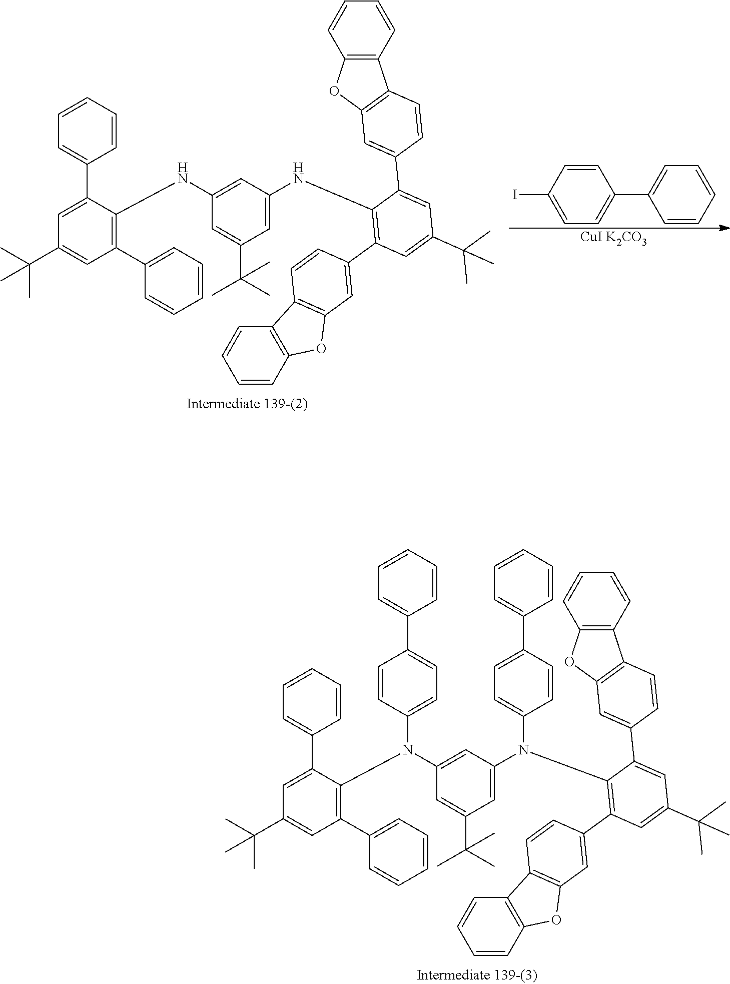

A small amount of toluene in about 10 mL was added to Intermediate 139-(2) (9.53 g, 10.44 mmol) and 4-iodo-1,1′-biphenyl (29.23 g, 104.36 mmol), CuI (4.97 g, 26.09 mmol), and K₂CO₃ (21.63 g, 156.53 mmol) in a reaction vessel, and heated for about 24 hours while the outside temperature of the reaction vessel was maintained at about 215° C. After cooling, the mixture was diluted with CH₂Cl₂ and water was added thereto, and the reaction solution was filtered through celite and separated to concentrate an organic layer. The organic layer was purified with silica gel column chromatography to obtain Intermediate 139-(3) (about 10.42 g, about 82% yield). The molecular weight of Intermediate 139-(3) was about 1218 from FAB MS measurement.

### Synthesis of Compound 139

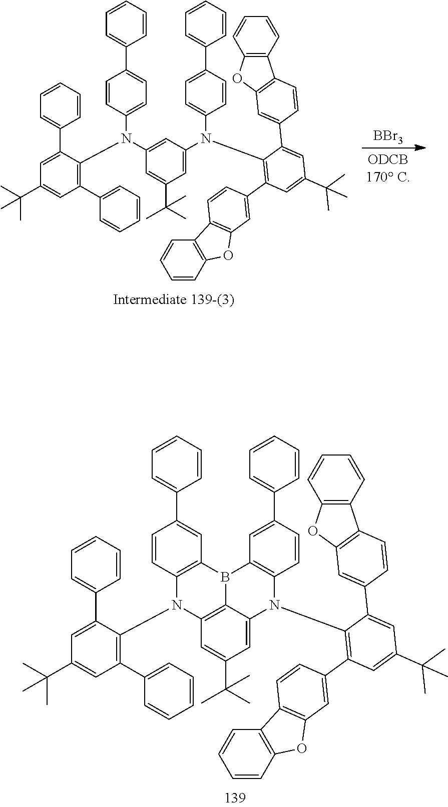

Under an Ar atmosphere, Intermediate 139-(3) (5.21 g, 4.38 mmol) was dissolved in ODCB (44 mL), BBr₃ (2.19 g, 8.76 mmol) was added thereto, and heated and agitated for about 10 hours at about 170° C. The reaction solution was then cooled to room temperature, DIPEA (6.78 g, 52.55 mmol) was added, and water was added thereto, and the reaction solution was filtered through celite and separated to concentrate an organic layer. The organic layer was purified with silica gel column chromatography to obtain Compound 139 (about 2.52 g, about 47% yield). The molecular weight of Compound 139 was about 1225 from FAB MS measurement. Sublimation purification (about 310° C., 2.5×10⁻³ Pa) was further performed for device evaluation.

### (4) Synthesis of Compound 140

### Synthesis of Intermediate 140-(1)

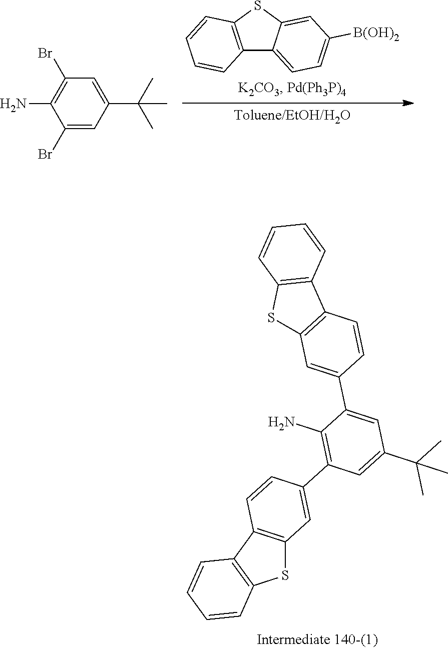

Under an Ar atmosphere, 60.4 mL of toluene and 30.2 mL of a mixture of EtOH and water in 1:1 were added to 2,6-dibromo-4-(tert-butyl) aniline (7.55 g, 24.59 mmol) and dibenzo[b, d]thiophen-3-ylboronic acid (16.83 g, 73.77 mmol), K₂CO₃ (20.39 g, 147.54 mmol), and Pd(Ph₃P) 4 (4.40 g, 3.81 mmol) in a reaction vessel, and then heated for about 24 hours while the outside temperature of the reaction vessel was maintained at about 80° C. After cooling, the mixture was filtered through celite and separated to concentrate an organic layer. The organic layer was purified with silica gel column chromatography to obtain Intermediate 140-(1) (about 10.99 g, about 87% yield). The molecular weight of Intermediate 140-(1) was about 514 from FAB MS measurement.

### Synthesis of Intermediate 140-(2)

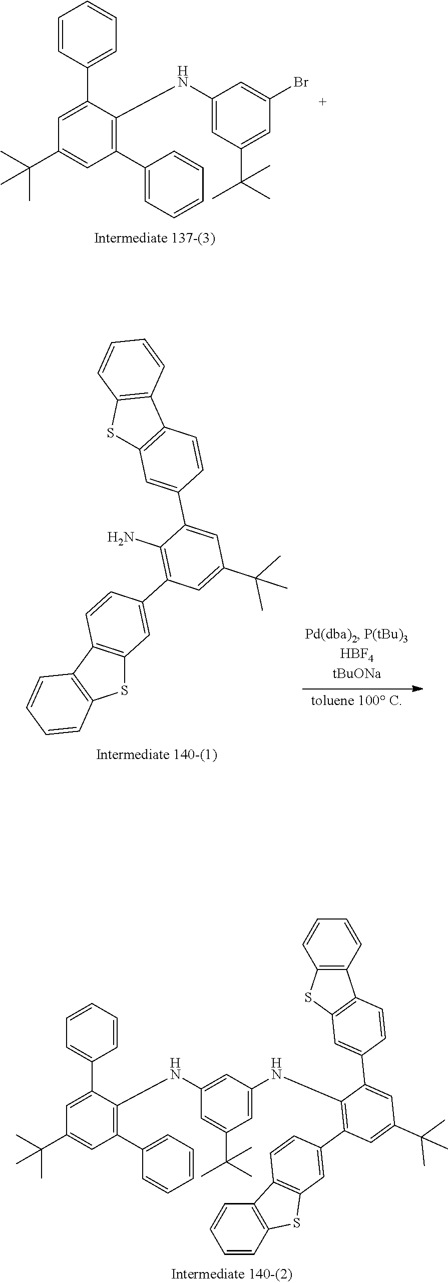 [SMILES: CC(C)(C)c1cc(Br)cc(Nc2c(-c3ccccc3)cc(C(C)(C)C)cc2-c2ccccc2)c1 ; CC(C)(C)c1cc(-c2ccc3c(c2)sc2ccccc23)c(N)c(-c2ccc3c(c2)sc2ccccc23)c1 ; CC(C)(C)c1cc(Nc2c(-c3ccccc3)cc(C(C)(C)C)cc2-c2ccccc2)cc(Nc2c(-c3ccc4c(c3)sc3ccccc34)cc(C(C)(C)C)cc2-c2ccc3c(c2)sc2ccccc23)c1]

Under an Ar atmosphere, Intermediate 137-(3) (7.05 g, 13.76 mmol) and Intermediate 140-(1) (8.48 g, 16.51 mmol), Pd(dba) 2 (0.79 g, 1.38 mmol), P(tBu)₃·HBF₄ (0.80 g, 2.75 mmol), and tBuONa (3.04 g, 31.64 mmol) were added to 68 mL of toluene, and heated and agitated for about 8 hours at about 100° C. After cooling, water was added, and the mixture was filtered through celite and separated to concentrate an organic layer. The organic layer was purified with silica gel column chromatography to obtain Intermediate 140-(2) (about 11.05 g, about 85% yield). The molecular weight of Intermediate 140-(2) was about 945 from FAB MS measurement.

### Synthesis of Intermediate 140-(3)

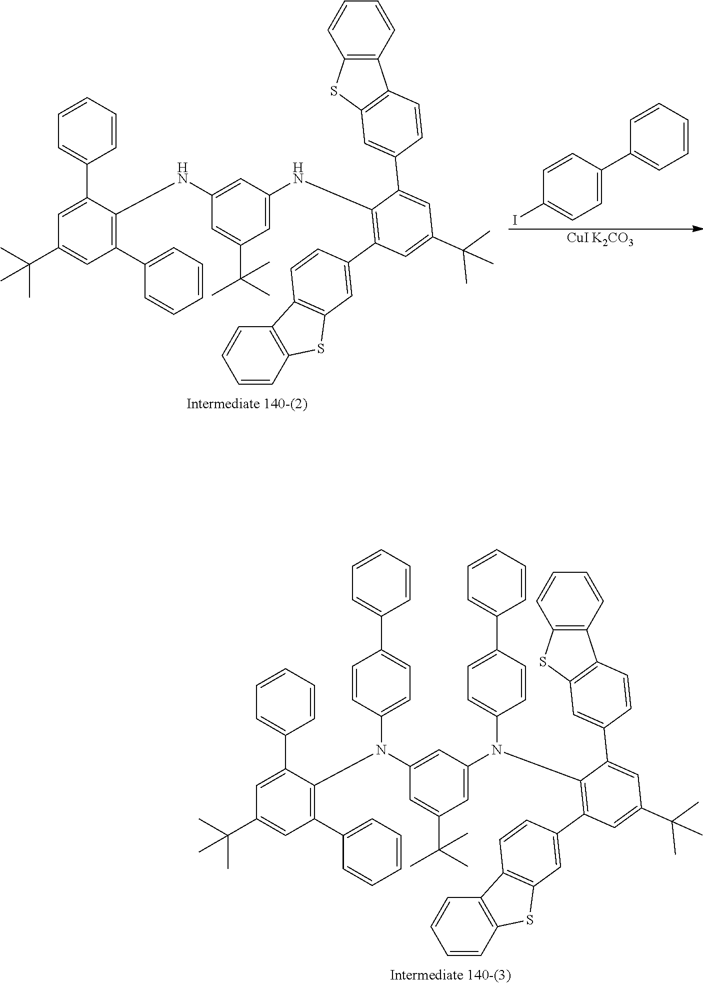

A small amount of toluene in about 10 mL was added to Intermediate 140-(2) (10.02 g, 10.6 mmol) and 4-iodo-1,1′-biphenyl (29.69 g, 105.99 mmol), CuI (5.05 g, 26.5 mmol), and K₂CO₃ (21.97 g, 158.99 mmol) in a reaction vessel, and heated for about 24 hours while the outside temperature of the reaction vessel was maintained at about 215° C. After cooling, the mixture was diluted with CH₂Cl₂ and water was added thereto, and the reaction solution was filtered through celite and separated to concentrate an organic layer. The organic layer was purified with silica gel column chromatography to obtain Intermediate 140-(3) (about 11.13 g, about 84% yield). The molecular weight of Intermediate 140-(3) was about 1250 from FAB MS measurement.

### Synthesis of Compound 140

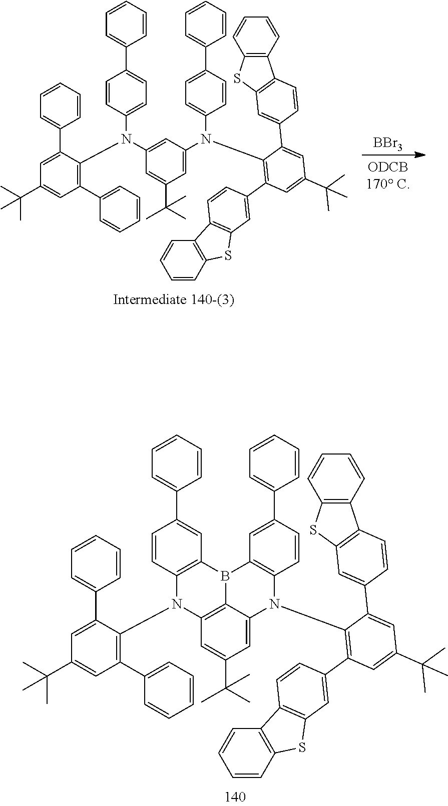

Under an Ar atmosphere, Intermediate 140-(3) (6.01 g, 4.81 mmol) was dissolved in ODCB (48 mL), BBr₃ (2.41 g, 9.62 mmol) was added thereto, and heated and agitated for about 10 hours at about 170° C. The reaction solution was then cooled to room temperature, DIPEA (7.44 g, 57.71 mmol) was added, and water was added thereto, and the reaction solution was filtered through celite and separated to concentrate an organic layer. The organic layer was purified with silica gel column chromatography to obtain Compound 140 (about 1.94 g, about 32% yield). The molecular weight of Compound 140 was about 1258 from FAB MS measurement. Sublimation purification (about 320° C., 3.1×10⁻³ Pa) was further performed for device evaluation.

### (5) Synthesis of Compound 182

### Synthesis of Intermediate 182-(1)

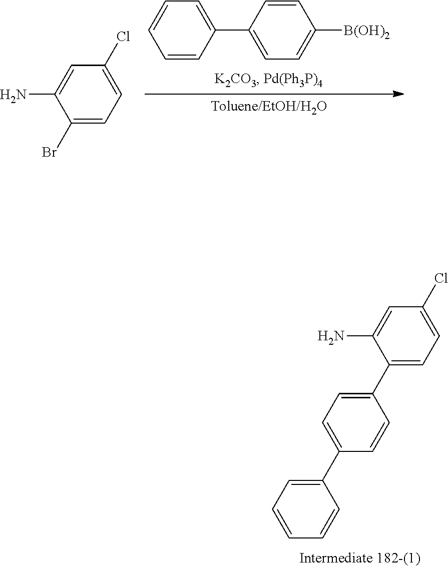

Under an Ar atmosphere, 59.84 mL of toluene and 29.92 mL of a mixture of EtOH and water in 1:1 were added to 2-bromo-5-chloroaniline (7.48 g, 36.23 mmol) and [1,1′-biphenyl]-4-ylboronic acid (7.89 g, 39.85 mmol), K₂CO₃ (30.04 g, 217.37 mmol), and Pd(Ph₃P) 4 (6.49 g, 5.62 mmol) in a reaction vessel, and then heated for about 24 hours while the outside temperature of the reaction vessel was maintained at about 80° C. After cooling, the mixture was filtered through celite and separated to concentrate an organic layer. The organic layer was purified with silica gel column chromatography to obtain Intermediate 182-(1) (about 8.31 g, about 82% yield). The molecular weight of Intermediate 182-(1) was about 280 from FAB MS measurement.

### Synthesis of Intermediate 182-(2)

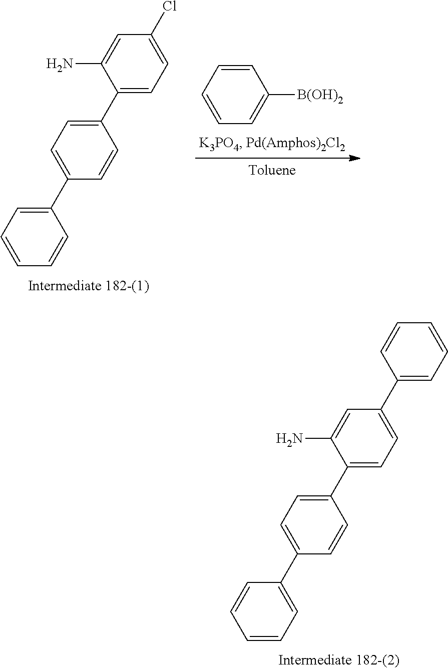

Under an Ar atmosphere, 64.88 mL of toluene and 32.44 mL of a mixture of EtOH and water in 1:1 were added to Intermediate 182-(1) (8.11 g, 28.99 mmol) and phenylboronic acid (10.6 g, 86.96 mmol), K₃PO₄ (12.31 g, 57.98 mmol), and Pd(Amphos) 2Cl₂ (2.05 g, 2.9 mmol) in a reaction vessel, and then heated for about 24 hours while the outside temperature of the reaction vessel was maintained at about 40° C. After cooling, the mixture was filtered through celite and separated to concentrate an organic layer. The organic layer was purified with silica gel column chromatography to obtain Intermediate 182-(2) (about 8.39 g, about 90% yield). The molecular weight of Intermediate 182-(2) was about 321 from FAB MS measurement.

### Synthesis of Intermediate 182-(3)

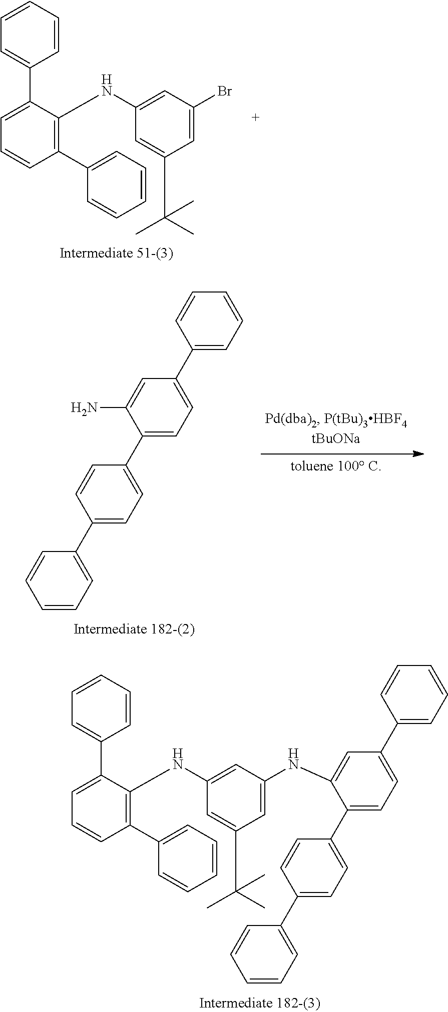 [SMILES: CC(C)(C)c1cc(Br)cc(Nc2c(-c3ccccc3)cccc2-c2ccccc2)c1 ; Nc1cc(-c2ccccc2)ccc1-c1ccc(-c2ccccc2)cc1 ; CC(C)(C)c1cc(Nc2cc(-c3ccccc3)ccc2-c2ccc(-c3ccccc3)cc2)cc(Nc2c(-c3ccccc3)cccc2-c2ccccc2)c1]

Under an Ar atmosphere, Intermediate 51-(3) (8.02 g, 17.57 mmol) and Intermediate 182-(2) (6.78 g, 21.09 mmol), Pd(dba) 2 (1.01 g, 1.76 mmol), P(tBu)₃·HBF₄ (1.02 g, 3.51 mmol), and tBuONa (3.88 g, 40.41 mmol) were added to 87 mL of toluene, and heated and agitated for about 8 hours at about 100° C. After cooling, water was added, and the mixture was filtered through celite and separated to concentrate an organic layer. The organic layer was purified with silica gel column chromatography to obtain Intermediate 182-(3) (about 11.14 g, about 91% yield). The molecular weight of Intermediate 182-(3) was about 697 from FAB MS measurement.

### Synthesis of Intermediate 182-(4)

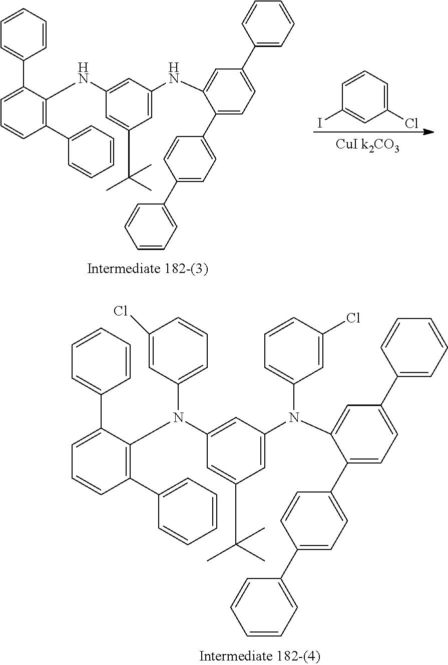 [SMILES: CC(C)(C)c1cc(Nc2cc(-c3ccccc3)ccc2-c2ccc(-c3ccccc3)cc2)cc(Nc2c(-c3ccccc3)cccc2-c2ccccc2)c1 ; Clc1cccc(I)c1 ; CC(C)(C)c1cc(N(c2cccc(Cl)c2)c2cc(-c3ccccc3)ccc2-c2ccc(-c3ccccc3)cc2)cc(N(c2cccc(Cl)c2)c2c(-c3ccccc3)cccc2-c2ccccc2)c1]

A small amount of toluene in about 10 mL was added to Intermediate 182-(3) (8.16 g, 11.71 mmol) and 1-chloro-3-iodobenzene (27.92 g, 117.08 mmol), CuI (5.57 g, 29.27 mmol), and K₂CO₃ (24.27 g, 175.62 mmol) in a reaction vessel, and heated for about 24 hours while the outside temperature of the reaction vessel was maintained at about 215° C. After cooling, the mixture was diluted with CH₂Cl₂ and water was added thereto, and the reaction solution was filtered through celite and separated to concentrate an organic layer. The organic layer was purified with silica gel column chromatography to obtain Intermediate 182-(4) (about 7.31 g, about 68% yield). The molecular weight of Intermediate 182-(4) was about 918 from FAB MS measurement.

### Synthesis of Intermediate 182-(5)

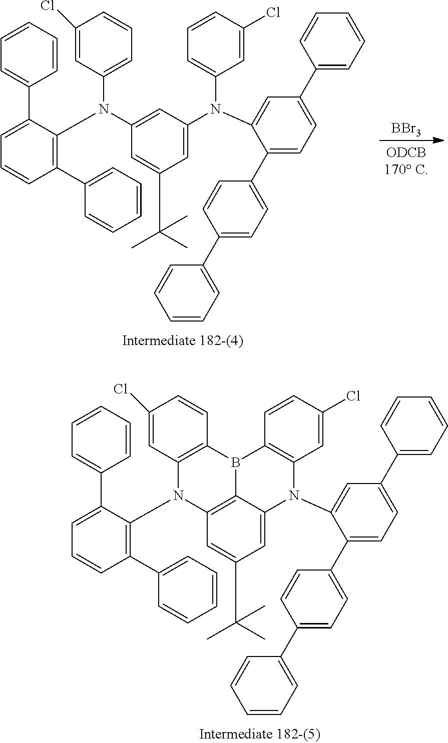

Under an Ar atmosphere, Intermediate 182-(4) (7.03 g, 7.66 mmol) was dissolved in ODCB (77 mL), BBr₃ (3.84 g, 15.32 mmol) was added thereto, and heated and agitated for about 10 hours at about 170° C. The reaction solution was then cooled to room temperature, DIPEA (11.85 g, 91.89 mmol) was added, and water was added thereto, and the reaction solution was filtered through celite and separated to concentrate an organic layer. The organic layer was purified with silica gel column chromatography to obtain Intermediate 182-(5) (about 2.55 g, about 36% yield). The molecular weight of Intermediate 182-(5) was about 926 from FAB MS measurement.

### Synthesis of Compound 182

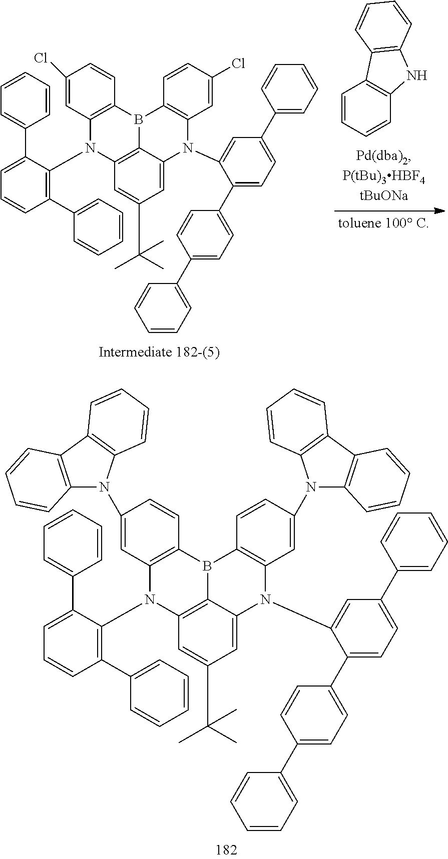

Under an Ar atmosphere, Intermediate 182-(5) (1.51 g, 1.63 mmol) and 9H-carbazole (0.68 g, 4.08 mmol), Pd(dba) 2 (0.09 g, 0.16 mmol), P(tBu)₃·HBF₄ (0.09 g, 0.33 mmol), and tBuONa (0.63 g, 6.52 mmol) were added to 8 mL of toluene, and heated and agitated for about 8 hours at about 100° C. After cooling, water was added, and the mixture was filtered through celite and separated to concentrate an organic layer. The organic layer was purified with silica gel column chromatography to obtain Compound 182 (about 1.57 g, about 81% yield). The molecular weight of Compound 182 was about 1187 from FAB MS measurement. Sublimation purification (about 340° C., 2.5×10⁻³ Pa) was further performed for device evaluation.

### (6) Synthesis of Compound 183

### Synthesis of Intermediate 183-(1)

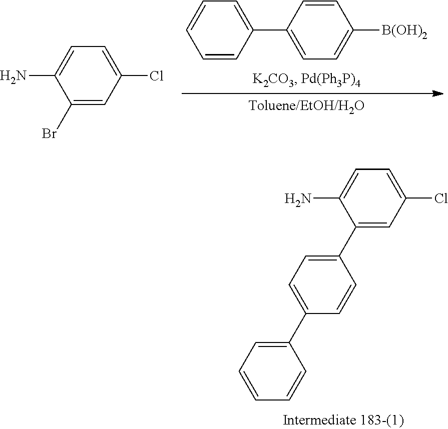 [SMILES: Nc1ccc(Cl)cc1Br ; OB(O)c1ccc(-c2ccccc2)cc1 ; Nc1ccc(Cl)cc1-c1ccc(-c2ccccc2)cc1]

Under an Ar atmosphere, 64.4 mL of toluene and 32.2 mL of a mixture of EtOH and water in 1:1 were added to 2-bromo-4-chloroaniline (8.05 g, 38.99 mmol) and [1,1′-biphenyl]-4-ylboronic acid (8.49 g, 42.89 mmol), K₂CO₃ (32.33 g, 233.93 mmol), and Pd(Ph₃P)₄ (6.98 g, 6.04 mmol) in a reaction vessel, and then heated for about 24 hours while the outside temperature of the reaction vessel was maintained at about 80° C. After cooling, the mixture was filtered through celite and separated to concentrate an organic layer. The organic layer was purified with silica gel column chromatography to obtain Intermediate 183-(1) (about 9.60 g, about 88% yield). The molecular weight of Intermediate 183-(1) was about 280 from FAB MS measurement.

### Synthesis of Intermediate 183-(2)

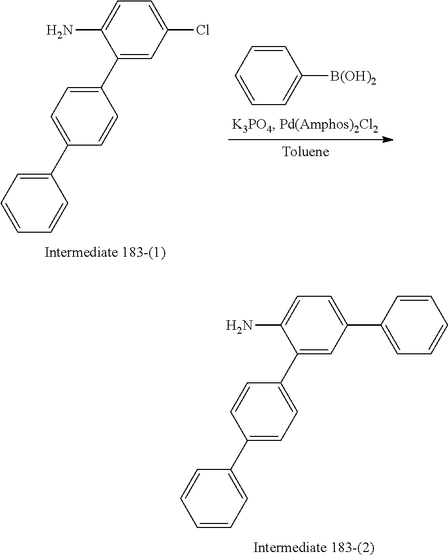 [SMILES: Nc1ccc(Cl)cc1-c1ccc(-c2ccccc2)cc1 ; OB(O)c1ccccc1 ; Nc1ccc(-c2ccccc2)cc1-c1ccc(-c2ccccc2)cc1]

Under an Ar atmosphere, 75.36 mL of toluene and 37.68 mL of a mixture of EtOH and water in 1:1 were added to Intermediate 183-(1) (9.42 g, 33.67 mmol) and phenylboronic acid (12.32 g, 101.01 mmol), K₃PO₄ (14.29 g, 67.34 mmol), and Pd(Amphos) 2Cl₂ (2.38 g, 3.37 mmol) in a reaction vessel, and then heated for about 24 hours while the outside temperature of the reaction vessel was maintained at about 90° C. After cooling, the mixture was filtered through celite and separated to concentrate an organic layer. The organic layer was purified with silica gel column chromatography to obtain Intermediate 183-(2) (about 9.42 g, about 87% yield). The molecular weight of Intermediate 183-(2) was about 321 from FAB MS measurement.

### Synthesis of Intermediate 183-(3)

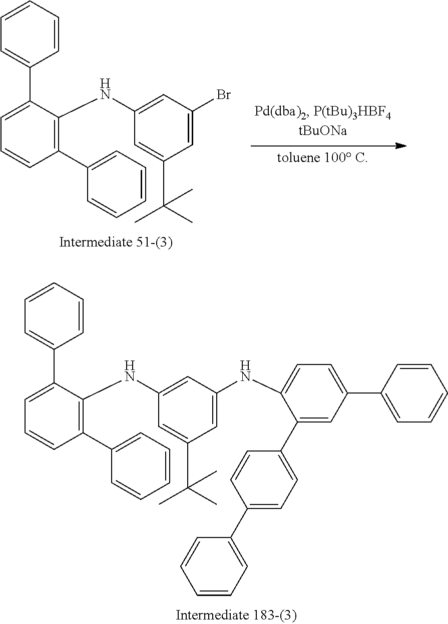 [SMILES: CC(C)(C)c1cc(Br)cc(Nc2c(-c3ccccc3)cccc2-c2ccccc2)c1 ; CC(C)(C)c1cc(Nc2ccc(-c3ccccc3)cc2-c2ccc(-c3ccccc3)cc2)cc(Nc2c(-c3ccccc3)cccc2-c2ccccc2)c1]

Under an Ar atmosphere, Intermediate 51-(3) (9.31 g, 20.4 mmol) and Intermediate 183-(2) (7.87 g, 24.48 mmol), Pd(dba) 2 (1.17 g, 2.04 mmol), P(tBu)₃·HBF₄ (1.18 g, 4.08 mmol), and tBuONa (4.51 g, 46.91 mmol) were added to 101 mL of toluene, and heated and agitated for about 8 hours at about 100° C. After cooling, water was added, and the mixture was filtered through celite and separated to concentrate an organic layer. The organic layer was purified with silica gel column chromatography to obtain Intermediate 183-(3) (about 12.08 g, about 85% yield). The molecular weight of Intermediate 183-(3) was about 697 from FAB MS measurement.

### Synthesis of Intermediate 183-(4)

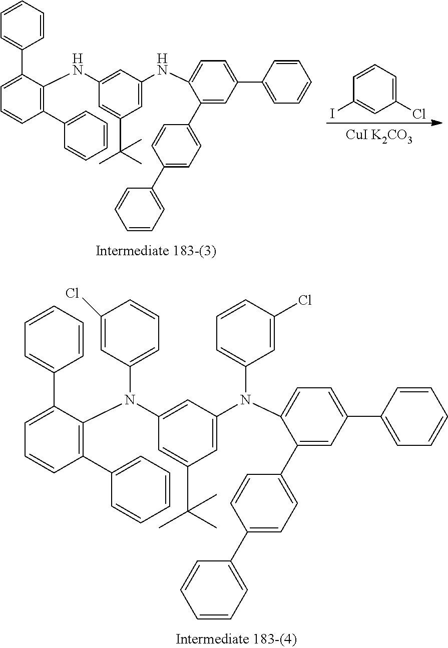

A small amount of toluene in about 10 mL was added to Intermediate 183-(3) (6.21 g, 8.91 mmol) and 1-chloro-3-iodobenzene (21.25 g, 89.1 mmol), CuI (4.24 g, 22.28 mmol), and K₂CO₃ (18.47 g, 133.66 mmol) in a reaction vessel, and heated for about 24 hours while the outside temperature of the reaction vessel was maintained at about 215° C. After cooling, the mixture was diluted with CH₂Cl₂ and water was added thereto, and the reaction solution was filtered through celite and separated to concentrate an organic layer. The organic layer was purified with silica gel column chromatography to obtain Intermediate 183-(4) (about 5.89 g, about 72% yield). The molecular weight of Intermediate 183-(4) was about 918 from FAB MS measurement.

### Synthesis of Intermediate 183-(5)

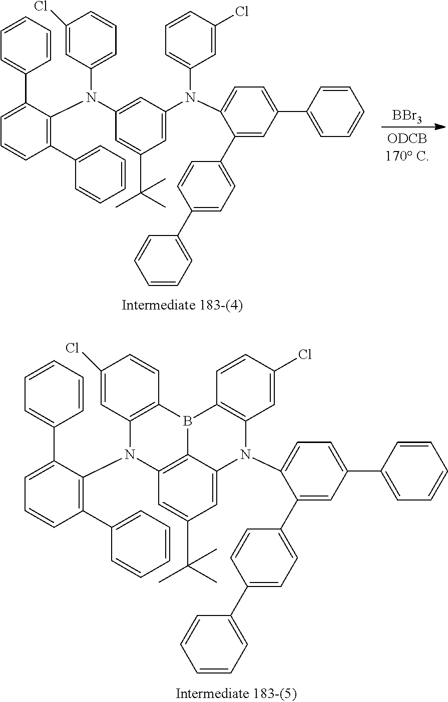

Under an Ar atmosphere, Intermediate 183-(4) (5.54 g, 6.03 mmol) was dissolved in ODCB (60 mL), BBr₃ (3.02 g, 12.07 mmol) was added thereto, and heated and agitated for about 10 hours at about 170° C. The reaction solution was then cooled to room temperature, DIPEA (9.34 g, 72.42 mmol) was added, and water was added thereto, and the reaction solution was filtered through celite and separated to concentrate an organic layer. The organic layer was purified with silica gel column chromatography to obtain Intermediate 183-(5) (about 3.97 g, about 71% yield). The molecular weight of Intermediate 183-(5) was about 926 from FAB MS measurement.

### Synthesis of Compound 183

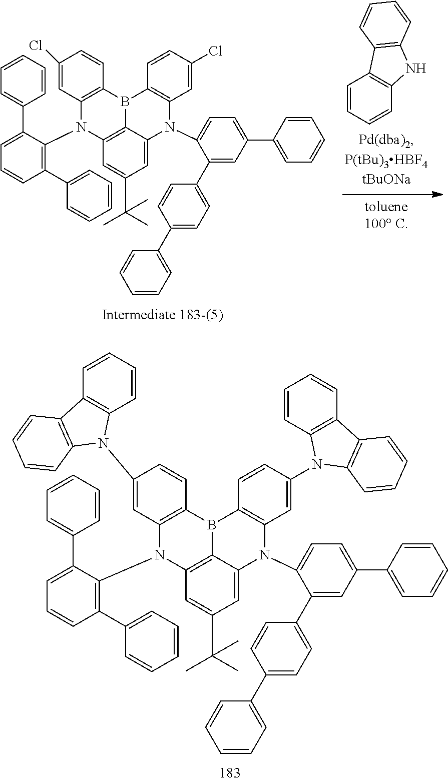

Under an Ar atmosphere, Intermediate 183-(5) (1.51 g, 1.63 mmol) and 9H-carbazole (0.68 g, 4.08 mmol), Pd(dba) 2 (0.09 g, 0.16 mmol), P(tBu)₃·HBF₄ (0.09 g, 0.33 mmol), and tBuONa (0.63 g, 6.52 mmol) were added to 8 mL of toluene, and heated and agitated for about 8 hours at about 100° C. After cooling, water was added, and the mixture was filtered through celite and separated to concentrate an organic layer. The organic layer was purified with silica gel column chromatography to obtain Compound 183 (about 1.47 g, about 76% yield). The molecular weight of Compound 183 was about 1187 from FAB MS measurement. Sublimation purification (about 320° C., 2.6×10⁻³ Pa) was further performed for device evaluation.

### (7) Synthesis of Compound 222

### Synthesis of Intermediate 222-(1)

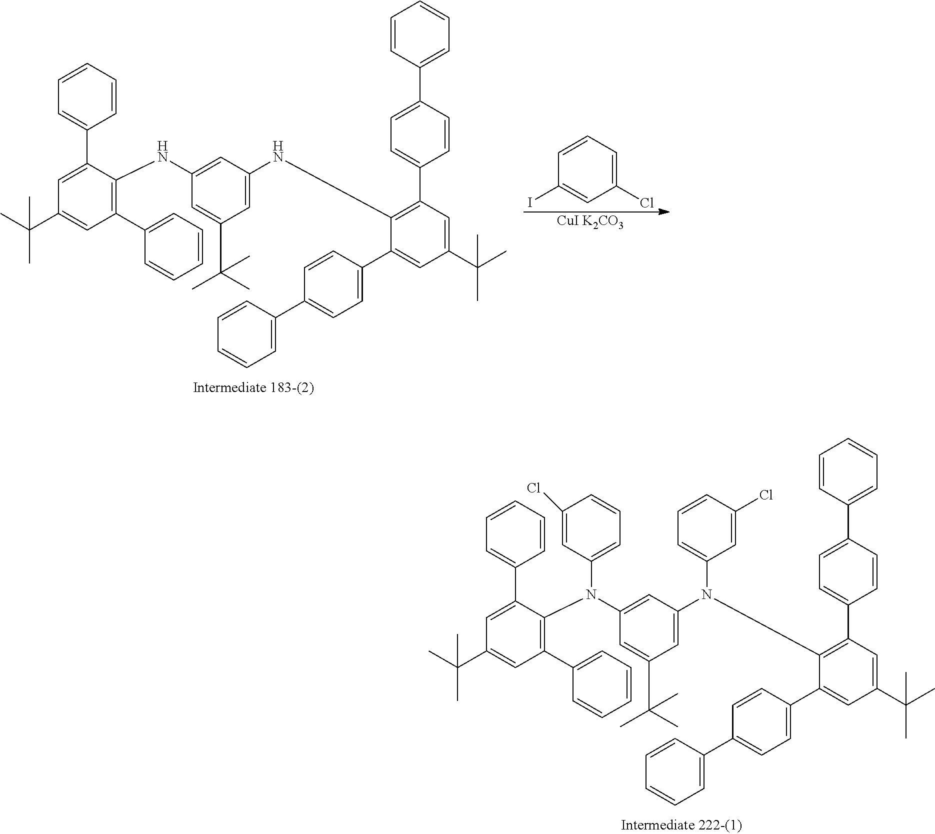

A small amount of toluene in about 10 mL was added to Intermediate 138-(2) (4.11 g, 5.9 mmol) and 1-chloro-3-iodobenzene (14.06 g, 58.97 mmol), CuI (2.81 g, 14.74 mmol), and K₂CO₃ (12.23 g, 88.46 mmol) in a reaction vessel, and heated for about 24 hours while the outside temperature of the reaction vessel was maintained at about 215° C. After cooling, the mixture was diluted with CH₂Cl₂ and water was added thereto, and the reaction solution was filtered through celite and separated to concentrate an organic layer. The organic layer was purified with silica gel column chromatography to obtain Intermediate 222-(1) (about 5.69 g, about 87% yield). The molecular weight of Intermediate 222-(1) was about 1108 from FAB MS measurement.

### Synthesis of Intermediate 222-(2)

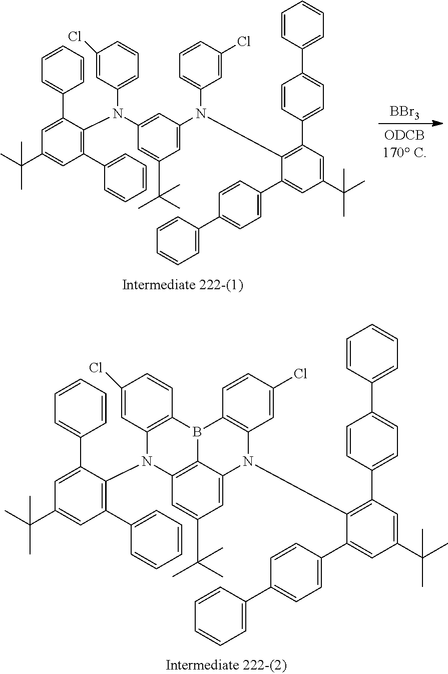

Under an Ar atmosphere, Intermediate 222-(1) (5.44 g, 4.91 mmol) was dissolved in ODCB (49 mL), BBr₃ (2.46 g, 9.82 mmol) was added thereto, and heated and agitated for about 10 hours at about 170° C. The reaction solution was then cooled to room temperature, DIPEA (7.6 g, 58.9 mmol) was added, and water was added thereto, and the reaction solution was filtered through celite and separated to concentrate an organic layer. The organic layer was purified with silica gel column chromatography to obtain Intermediate 222-(2) (about 3.61 g, about 65% yield). The molecular weight of Intermediate 222-(2) was about 1130 from FAB MS measurement.

### Synthesis of Compound 222

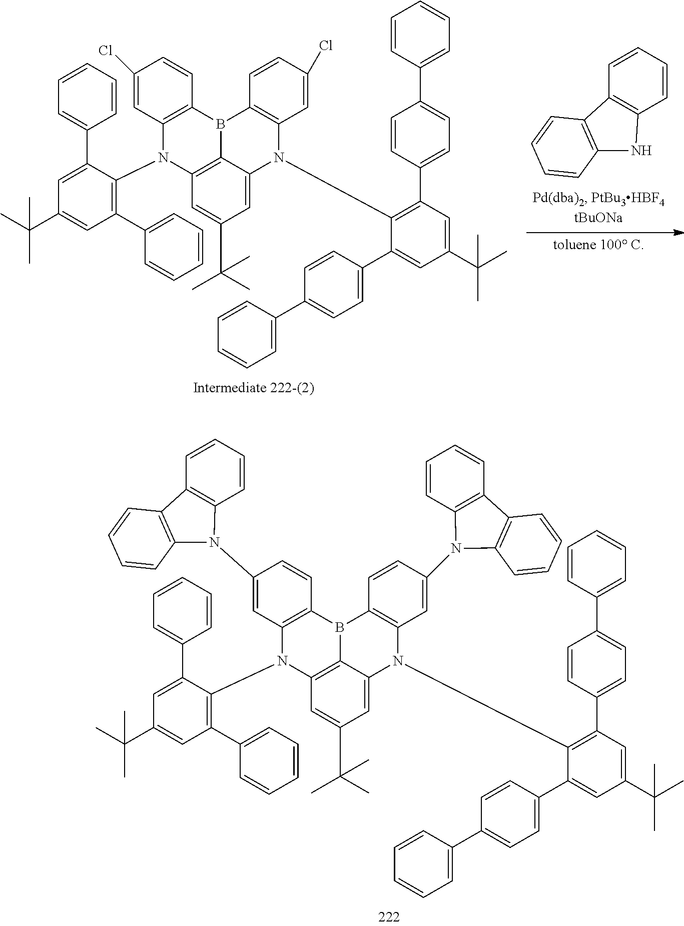

Under an Ar atmosphere, Intermediate 222-(2) (3.22 g, 2.85 mmol) and 9H-carbazole (1.19 g, 7.12 mmol), Pd(dba) 2 (0.16 g, 0.28 mmol), P(tBu)₃·HBF₄ (0.17 g, 0.57 mmol), and tBuONa (1.1 g, 11.4 mmol) were added to 14 mL of toluene, and heated and agitated for about 8 hours at about 100° C. After cooling, water was added, and the mixture was filtered through celite and separated to concentrate an organic layer. The organic layer was purified with silica gel column chromatography to obtain Compound 222 (about 3.33 g, about 84% yield). The molecular weight of Compound 222 was about 1392 from FAB MS measurement. Sublimation purification (about 330° C., 2.9×10⁻³ Pa) was further performed for device evaluation.

### (8) Synthesis of Compound 226

### Synthesis of Intermediate 226-(1)

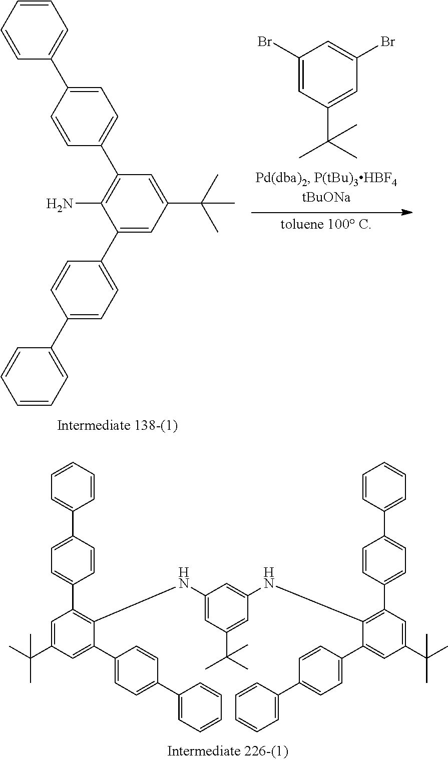 [SMILES: CC(C)(C)c1cc(-c2ccc(-c3ccccc3)cc2)c(N)c(-c2ccc(-c3ccccc3)cc2)c1 ; CC(C)(C)c1cc(Br)cc(Br)c1 ; CC(C)(C)c1cc(Nc2c(-c3ccc(-c4ccccc4)cc3)cc(C(C)(C)C)cc2-c2ccc(-c3ccccc3)cc2)cc(Nc2c(-c3ccc(-c4ccccc4)cc3)cc(C(C)(C)C)cc2-c2ccc(-c3ccccc3)cc2)c1]

Under an Ar atmosphere, 1,3-dibromo-5-(tert-butyl)benzene (4.18 g, 14.31 mmol) and Intermediate 138-(1) (16.23 g, 35.79 mmol), Pd(dba) 2 (0.82 g, 1.43 mmol), P(tBu)₃·HBF₄ (0.83 g, 2.86 mmol), and tBuONa (5.5 g, 57.26 mmol) were added to 71 mL of toluene, and heated and agitated for about 8 hours at about 100° C. After cooling, water was added, and the mixture was filtered through celite and separated to concentrate an organic layer. The organic layer was purified with silica gel column chromatography to obtain Intermediate 226-(1) (about 12.03 g, about 81% yield). The molecular weight of Intermediate 226-(1) was about 1037 from FAB MS measurement.

### Synthesis of Intermediate 226-(2)

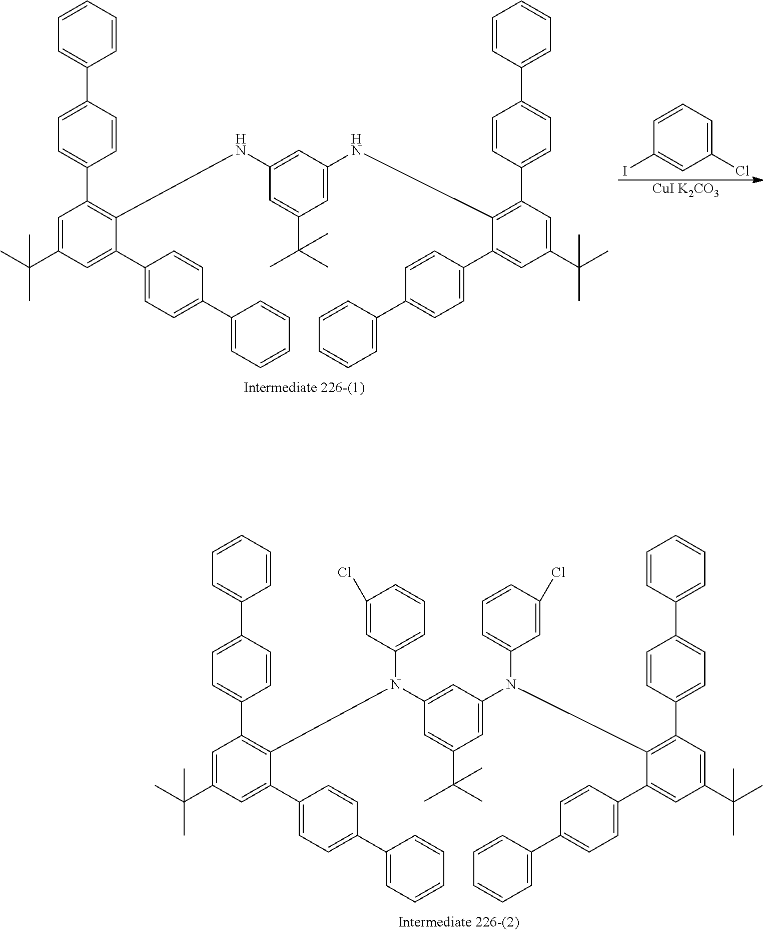

A small amount of toluene in about 10 mL was added to Intermediate 226-(1) (12.08 g, 11.64 mmol) and 1-chloro-3-iodobenzene (27.76 g, 116.44 mmol), CuI (5.54 g, 29.11 mmol), and K₂CO₃ (24.14 g, 174.66 mmol) in a reaction vessel, and heated for about 24 hours while the outside temperature of the reaction vessel was maintained at about 215° C. After cooling, the mixture was diluted with CH₂Cl₂ and water was added thereto, and the reaction solution was filtered through celite and separated to concentrate an organic layer. The organic layer was purified with silica gel column chromatography to obtain Intermediate 226-(2) (about 10.84 g, about 74% yield). The molecular weight of Intermediate 226-(2) was about 1259 from FAB MS measurement.

### Synthesis of Intermediate 226-(3)

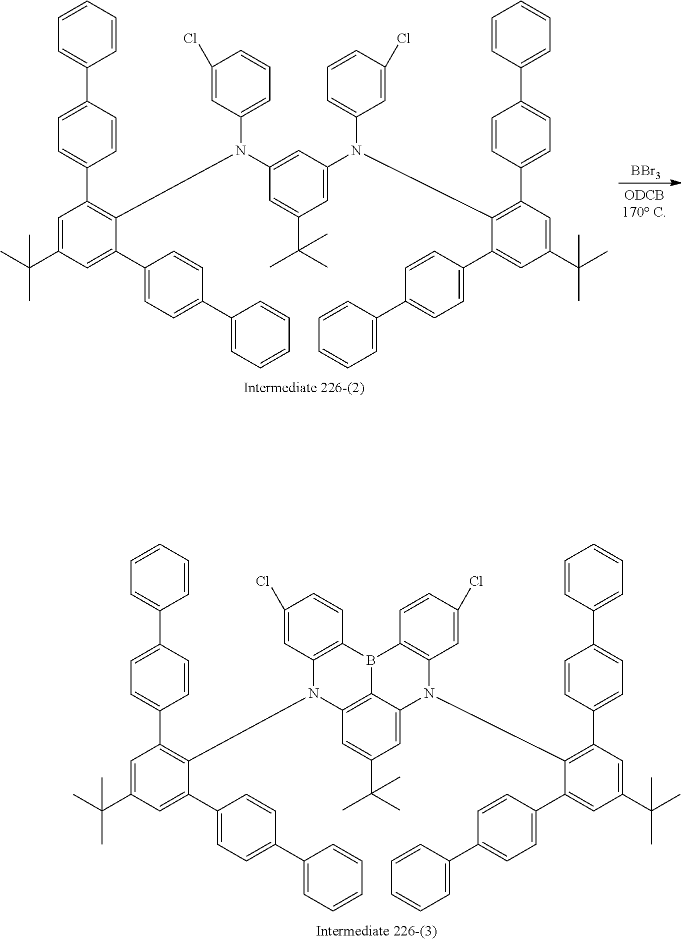

Under an Ar atmosphere, Intermediate 226-(2) (5.17 g, 4.11 mmol) was dissolved in ODCB (41 mL), BBr₃ (2.06 g, 8.22 mmol) was added thereto, and heated and agitated for about 10 hours at about 170° C. The reaction solution was then cooled to room temperature, DIPEA (6.36 g, 49.3 mmol) was added, and water was added thereto, and the reaction solution was filtered through celite and separated to concentrate an organic layer. The organic layer was purified with silica gel column chromatography to obtain Intermediate 226-(3) (about 4.06 g, about 78% yield). The molecular weight of Intermediate 226-(3) was about 1266 from FAB MS measurement.

### Synthesis of Compound 226

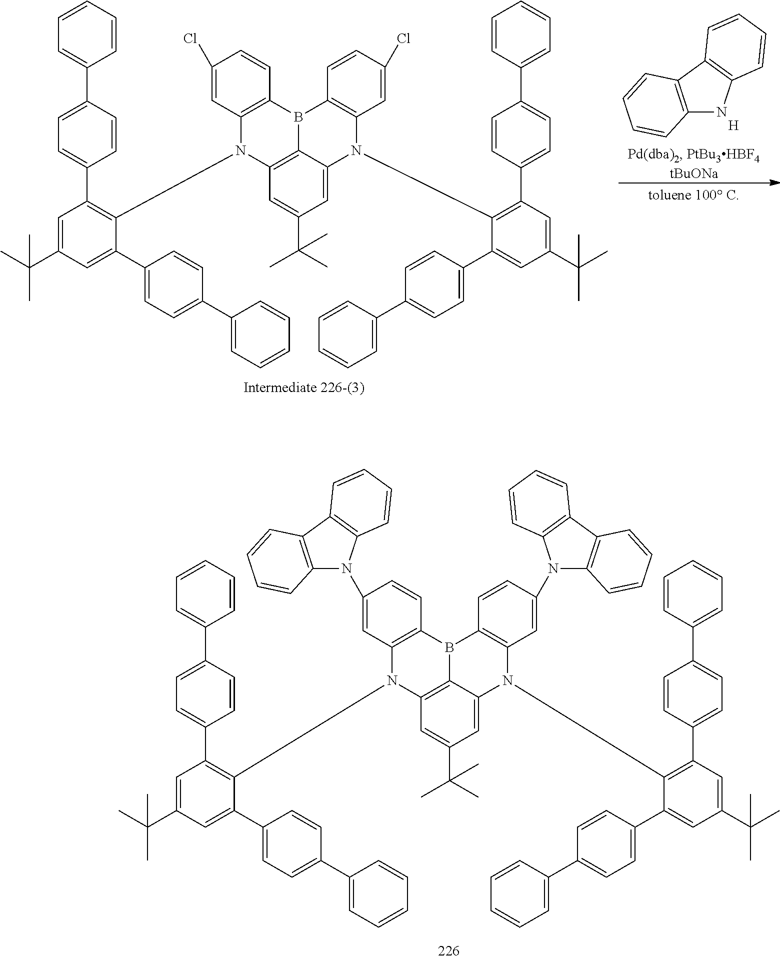

Under an Ar atmosphere, Intermediate 226-(3) (3.88 g, 3.06 mmol) and 9H-carbazole (1.28 g, 7.66 mmol), Pd(dba) 2 (0.18 g, 0.31 mmol), P(tBu)₃·HBF₄ (0.18 g, 0.61 mmol), and tBuONa (1.18 g, 12.26 mmol) were added to 15 mL of toluene, and heated and agitated for about 8 hours at about 100° C. After cooling, water was added, and the mixture was filtered through celite and separated to concentrate an organic layer. The organic layer was purified with silica gel column chromatography to obtain Compound 226 (about 2.85 g, about 4% yield). The molecular weight of Compound 226 was about 1259 from FAB MS measurement. Sublimation purification (about 340° C., 3.1×10⁻³ Pa) was further performed for device evaluation.

### (10) Synthesis of Compound 228

### Synthesis of Intermediate 228-(1)

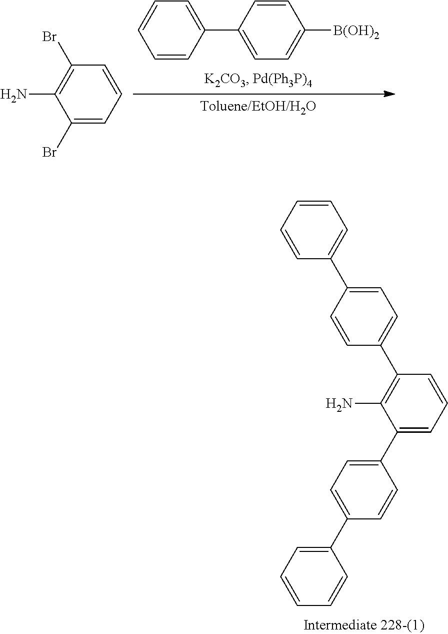 [SMILES: Nc1c(Br)cccc1Br ; OB(O)c1ccc(-c2ccccc2)cc1 ; Nc1c(-c2ccc(-c3ccccc3)cc2)cccc1-c1ccc(-c2ccccc2)cc1]

Under an Ar atmosphere, 56.32 mL of toluene and 28.16 mL of a mixture of EtOH and water in 1:1 were added to 2,6-dibromoaniline (7.04 g, 28.06 mmol) and [1,1′-biphenyl]-4-ylboronic acid (13.33 g, 67.34 mmol), K₂CO₃ (23.27 g, 168.34 mmol), and Pd(Ph₃P) 4 (5.03 g, 4.35 mmol) in a reaction vessel, and then heated for about 24 hours while the outside temperature of the reaction vessel was maintained at about 80° C. After cooling, the mixture was filtered through celite and separated to concentrate an organic layer. The organic layer was purified with silica gel column chromatography to obtain Intermediate 228-(1) (about 9.03 g, about 81% yield). The molecular weight of Intermediate 228-(1) was about 398 from FAB MS measurement.

### Synthesis of Intermediate 228-(2)

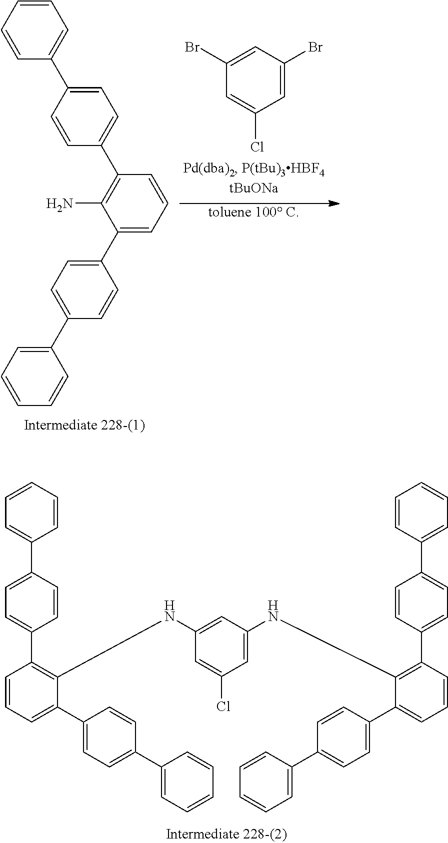 [SMILES: Nc1c(-c2ccc(-c3ccccc3)cc2)cccc1-c1ccc(-c2ccccc2)cc1 ; Clc1cc(Br)cc(Br)c1 ; "toluene 100° C." ; Clc1cc(Nc2c(-c3ccc(-c4ccccc4)cc3)cccc2-c2ccc(-c3ccccc3)cc2)cc(Nc2c(-c3ccc(-c4ccccc4)cc3)cccc2-c2ccc(-c3ccccc3)cc2)c1]

Under an Ar atmosphere, 1,3-dibromo-5-chlorobenzene (4.63 g, 17.13 mmol) and Intermediate 228-(1) (8.17 g, 20.55 mmol), Pd(dba) 2 (0.98 g, 1.71 mmol), P(tBu)₃. HBF₄ (0.99 g, 3.43 mmol), and tBuONa (3.79 g, 39.39 mmol) were added to 85 mL of toluene, and heated and agitated for about 8 hours at about 100° C. After cooling, water was added, and the mixture was filtered through celite and separated to concentrate an organic layer. The organic layer was purified with silica gel column chromatography to obtain Intermediate 228-(2) (about 11.92 g, about 77% yield). The molecular weight of Intermediate 228-(2) was about 904 from FAB MS measurement.

### Synthesis of Intermediate 228-(3)

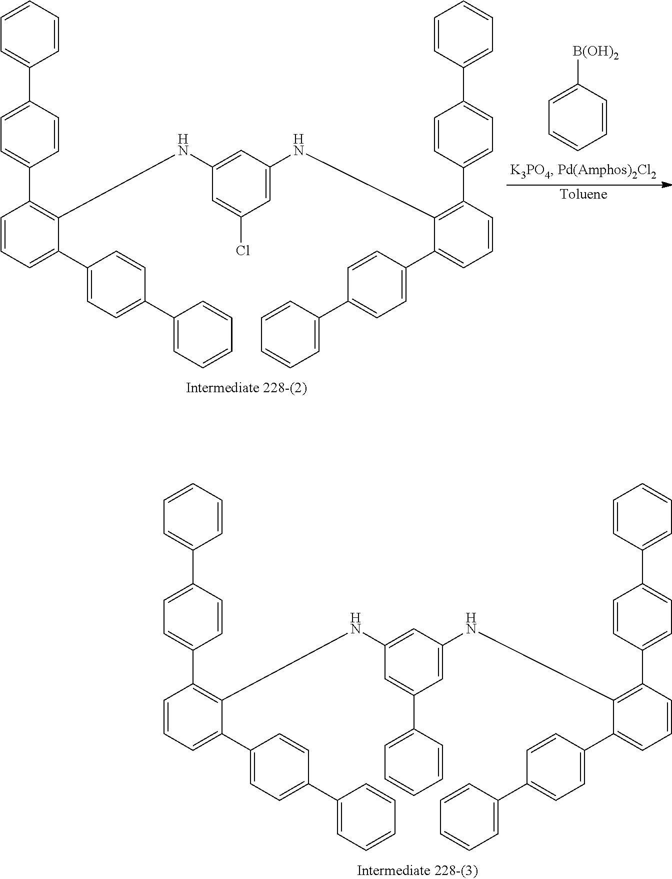

Under an Ar atmosphere, 92.4 mL of toluene and 46.2 mL of a mixture of EtOH and water in 1:1 were added to Intermediate 228-(2) (11.55 g, 12.78 mmol) and phenylboronic acid (4.68 g, 38.35 mmol), K₃PO₄ (5.43 g, 25.57 mmol), and Pd(Amphos) 2Cl₂ (0.91 g, 1.28 mmol) in a reaction vessel, and then heated for about 24 hours while the outside temperature of the reaction vessel was maintained at about 90° C. After cooling, the mixture was filtered through celite and separated to concentrate an organic layer. The organic layer was purified with silica gel column chromatography to obtain Intermediate 228-(3) (about 9.06 g, about 75% yield). The molecular weight of Intermediate 228-(3) was about 945 from FAB MS measurement.

### Synthesis of Intermediate 228-(4)

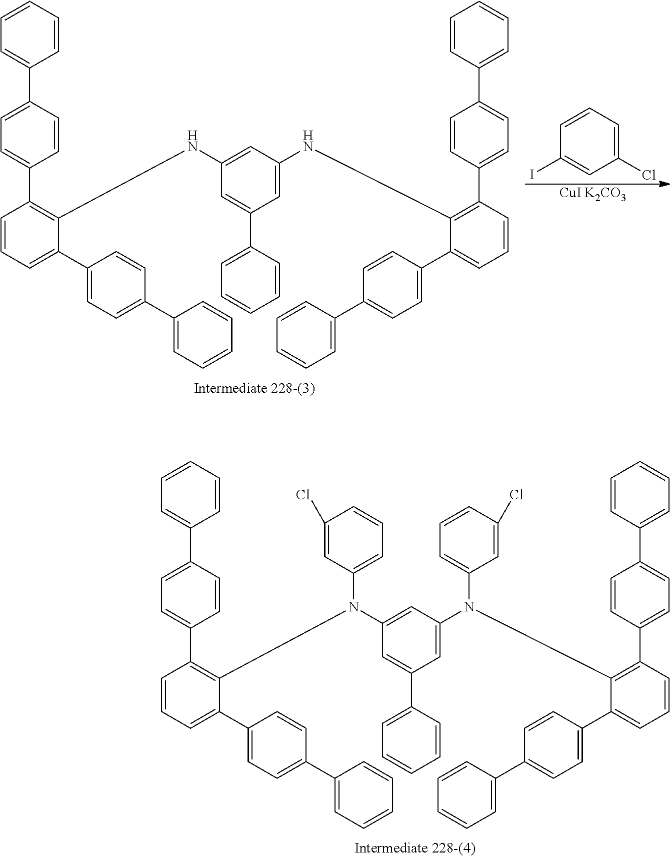

A small amount of toluene in about 10 mL was added to Intermediate 228-(3) (8.54 g, 9.03 mmol) and 1-chloro-3-iodobenzene (21.54 g, 90.35 mmol), CuI (4.3 g, 22.59 mmol), and K₂CO₃ (18.73 g, 135.52 mmol) in a reaction vessel, and heated for about 24 hours while the outside temperature of the reaction vessel was maintained at about 215° C. After cooling, the mixture was diluted with CH₂Cl₂ and water was added thereto, and the reaction solution was filtered through celite and separated to concentrate an organic layer. The organic layer was purified with silica gel column chromatography to obtain Intermediate 228-(4) (about 7.38 g, about 70% yield). The molecular weight of Intermediate 228-(4) was about 1166 from FAB MS measurement.

### Synthesis of Intermediate 228-(5)

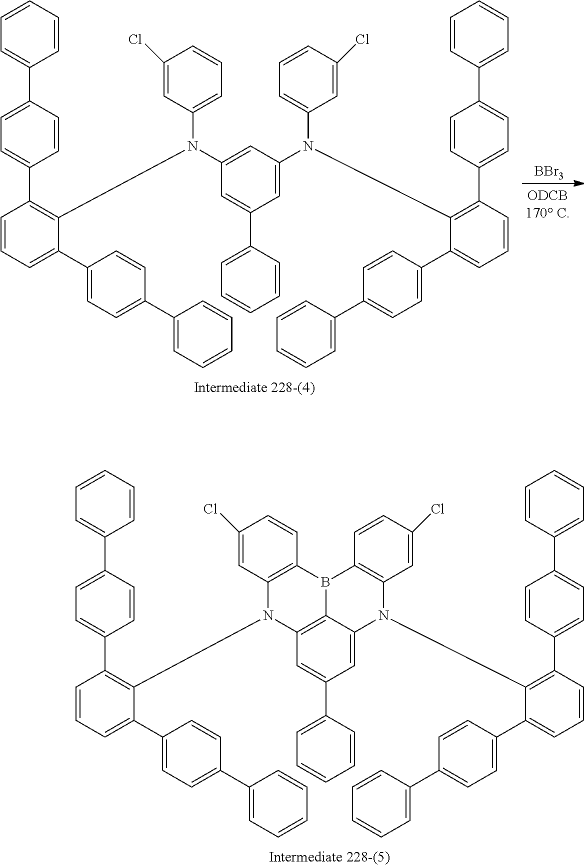

Under an Ar atmosphere, Intermediate 228-(4) (6.88 g, 5.9 mmol) was dissolved in ODCB (59 mL), BBr₃ (2.96 g, 11.8 mmol) was added thereto, and heated and agitated for about 10 hours at about 170° C. The reaction solution was then cooled to room temperature, DIPEA (9.13 g, 70.79 mmol) was added, and water was added thereto, and the reaction solution was filtered through celite and separated to concentrate an organic layer. The organic layer was purified with silica gel column chromatography to obtain Intermediate 228-(5) (about 2.49 g, about 36% yield). The molecular weight of Intermediate 228-(5) was about 1174 from FAB MS measurement.

### Synthesis of Compound 228

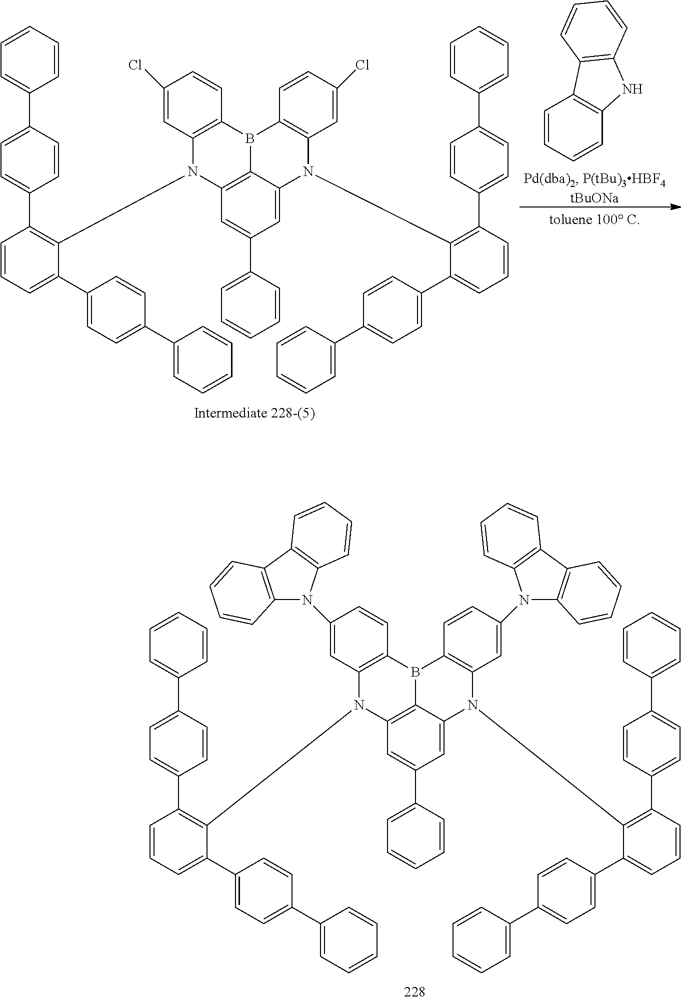

Under an Ar atmosphere, Intermediate 228-(5) (2.11 g, 1.8 mmol) and 9H-carbazole (0.75 g, 4.49 mmol), Pd(dba) 2 (0.1 g, 0.18 mmol), P(tBu)₃·HBF₄ (0.1 g, 0.36 mmol), and tBuONa (0.69 g, 7.19 mmol) were added to 8 mL of toluene, and heated and agitated for about 8 hours at about 100° C. After cooling, water was added, and the mixture was filtered through celite and separated to concentrate an organic layer. The organic layer was purified with silica gel column chromatography to obtain Compound 228 (about 2.22 g, about 86% yield). The molecular weight of Compound 228 was about 1436 from FAB MS measurement. Sublimation purification (about 340° C., 2.6×10⁻³ Pa) was further performed for device evaluation.

### (11) Synthesis of Compound 240

### Synthesis of Intermediate 240-(1)

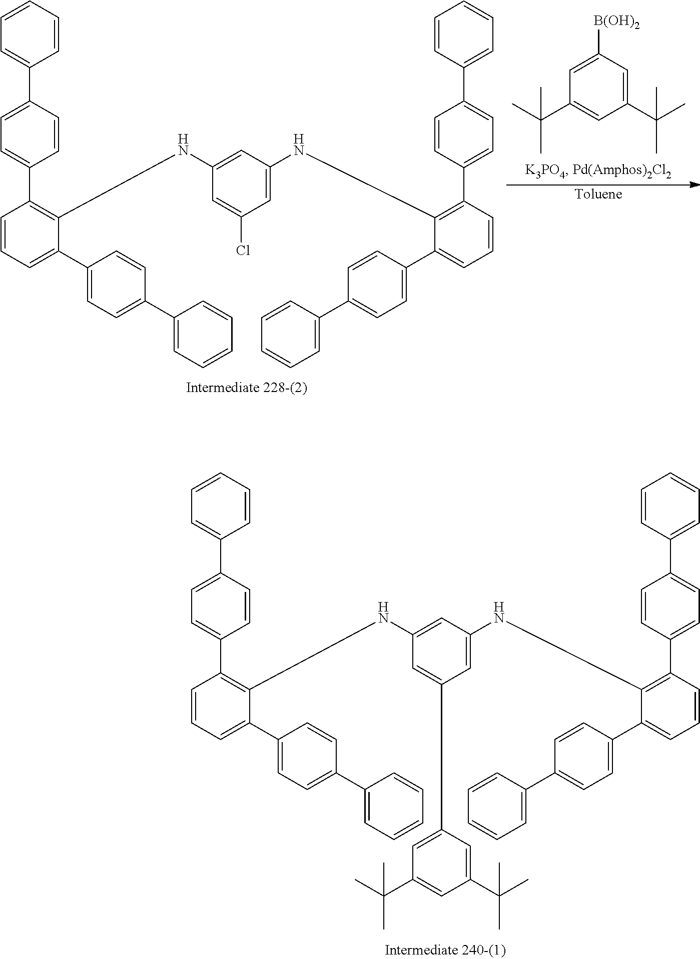

Under an Ar atmosphere, 89.84 mL of toluene and 44.92 mL of a mixture of EtOH and water in 1:1 were added to Intermediate 228-(2) (11.23 g, 12.43 mmol) and (3,5-di-tert-butylphenyl) boronic acid (8.73 g, 37.29 mmol), K₃PO₄ (5.28 g, 24.86 mmol), and Pd(Amphos) 2Cl₂ (0.88 g, 1.24 mmol) in a reaction vessel, and then heated for about 24 hours while the outside temperature of the reaction vessel was maintained at about 90° C. After cooling, the mixture was filtered through celite and separated to concentrate an organic layer. The organic layer was purified with silica gel column chromatography to obtain Intermediate 240-(1) (about 9.73 g, about 74% yield). The molecular weight of Intermediate 240-(1) was about 1057 from FAB MS measurement.

### Synthesis of Intermediate 240-(2)

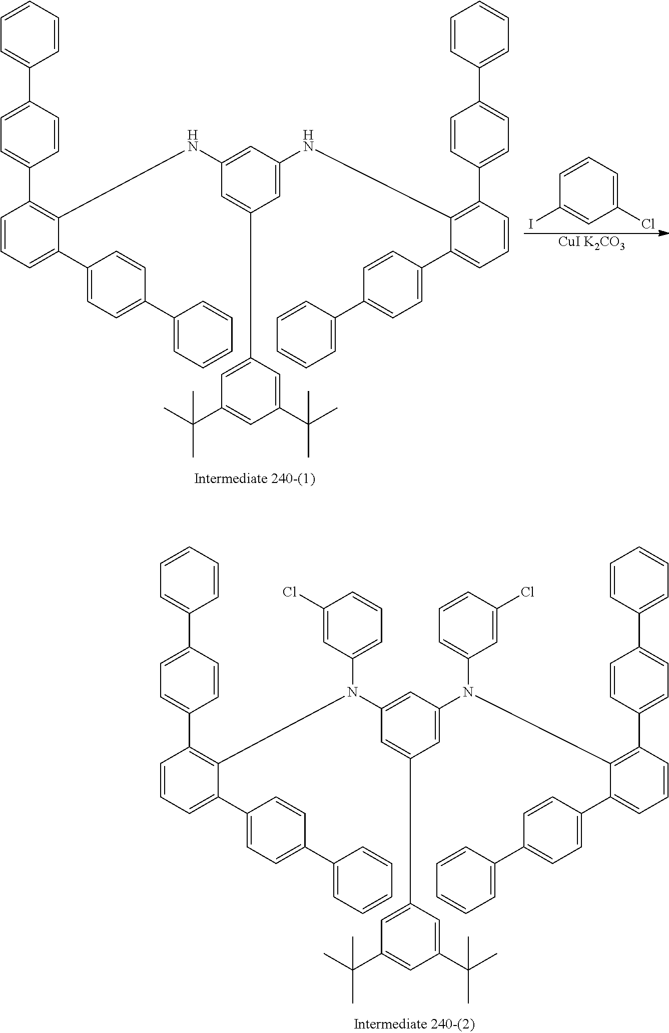

A small amount of toluene in about 10 mL was added to Intermediate 240-(1) (8.54 g, 9.52 mmol) and 1-chloro-3-iodobenzene (22.7 g, 95.2 mmol), CuI (4.53 g, 23.8 mmol), and K₂CO₃ (19.74 g, 142.8 mmol) in a reaction vessel, and heated for about 24 hours while the outside temperature of the reaction vessel was maintained at about 215° C. After cooling, the mixture was diluted with CH₂Cl₂ and water was added thereto, and the reaction solution was filtered through celite and separated to concentrate an organic layer. The organic layer was purified with silica gel column chromatography to obtain Intermediate 240-(2) (about 10.22 g, about 84% yield). The molecular weight of Intermediate 240-(2) was about 1279 from FAB MS measurement.

### Synthesis of Intermediate 240-(3)

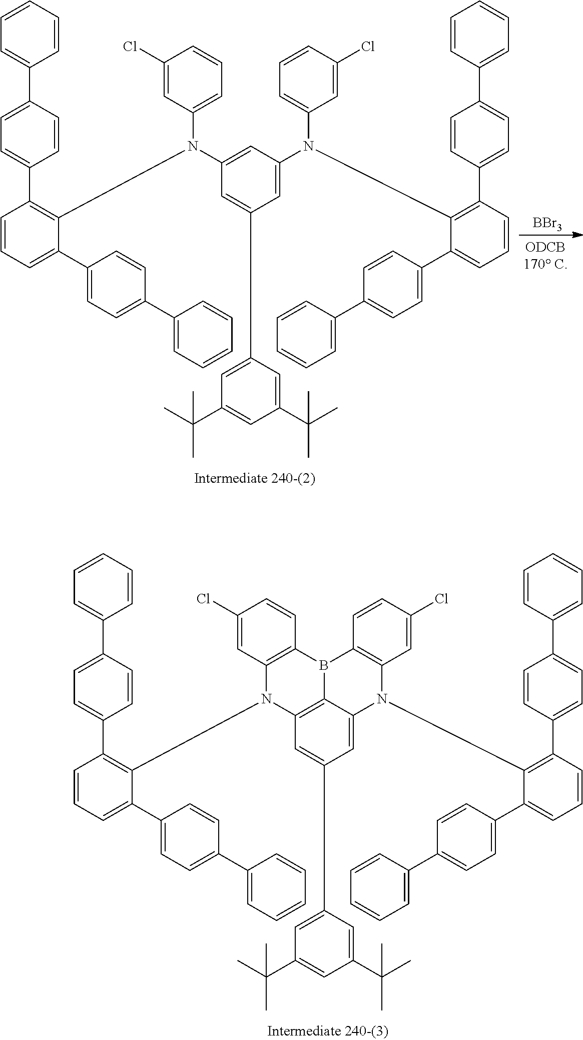

Under an Ar atmosphere, Intermediate 240-(2) (9.88 g, 7.73 mmol) was dissolved in ODCB (77 mL), BBr₃ (3.87 g, 15.46 mmol) was added thereto, and heated and agitated for about 10 hours at about 170° C. The reaction solution was then cooled to room temperature, DIPEA (11.96 g, 92.73 mmol) was added, and water was added thereto, and the reaction solution was filtered through celite and separated to concentrate an organic layer. The organic layer was purified with silica gel column chromatography to obtain Intermediate 240-(3) (about 3.08 g, about 31% yield). The molecular weight of Intermediate 240-(3) was about 1286 from FAB MS measurement.

### Synthesis of Compound 240

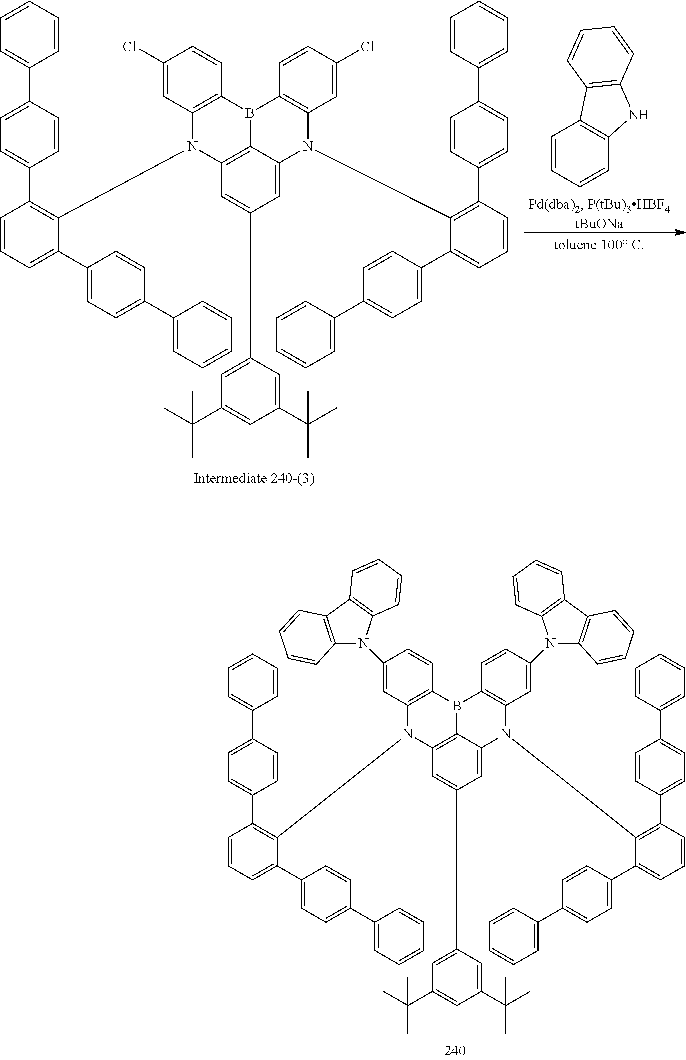

Under an Ar atmosphere, Intermediate 240-(3) (2.55 g, 1.98 mmol) and 9H-carbazole (0.83 g, 4.96 mmol), Pd(dba) 2 (0.11 g, 0.2 mmol), P(tBu)₃·HBF₄ (0.12 g, 0.4 mmol), and tBuONa (0.76 g, 7.93 mmol) were added to 9 mL of toluene, and heated and agitated for about 8 hours at about 100° C. After cooling, water was added, and the mixture was filtered through celite and separated to concentrate an organic layer. The organic layer was purified with silica gel column chromatography to obtain Compound 240 (about 2.45 g, about 80% yield). The molecular weight of Compound 240 was about 1548 from FAB MS measurement. Sublimation purification (about 350° C., 2.1×10⁻³ Pa) was further performed for device evaluation.

### (12) Synthesis of Compound 263

### Synthesis of Intermediate 263-(1)

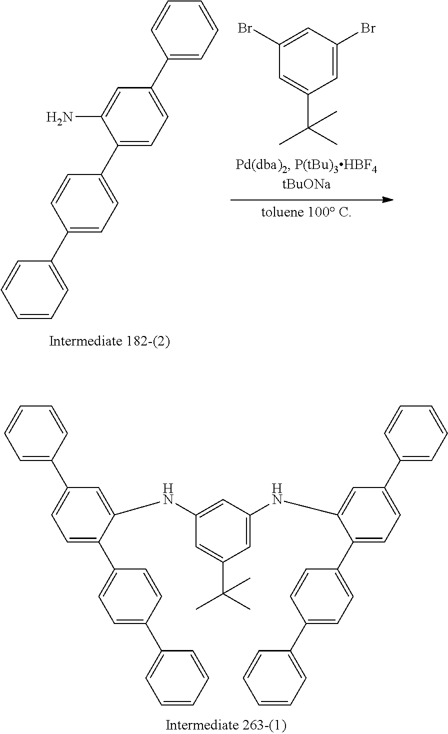

Under an Ar atmosphere, 1,3-dibromo-5-(tert-butyl)benzene (5.01 g, 17.16 mmol) and Intermediate 182-(2) (13.79 g, 42.89 mmol), Pd(dba) 2 (0.99 g, 1.72 mmol), P(tBu)₃·HBF₄ (1 g, 3.43 mmol), and tBuONa (6.6 g, 68.63 mmol) were added to 85 mL of toluene, and heated and agitated for about 8 hours at about 100° C. After cooling, water was added, and the mixture was filtered through celite and separated to concentrate an organic layer. The organic layer was purified with silica gel column chromatography to obtain Intermediate 263-(1) (about 12.07 g, about 91% yield). The molecular weight of Intermediate 263-(1) was about 773 from FAB MS measurement.

### Synthesis of Intermediate 263-(2)

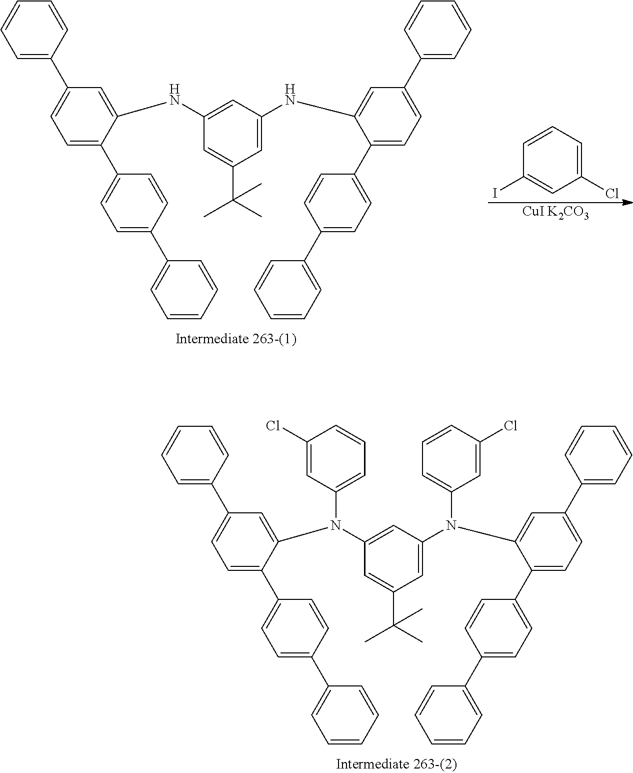

A small amount of toluene in about 10 mL was added to Intermediate 263-(1) (11.55 g, 9.52 mmol) and 1-chloro-3-iodobenzene (22.7 g, 95.2 mmol), CuI (4.53 g, 23.8 mmol), and K₂CO₃ (19.74 g, 142.8 mmol) in a reaction vessel, and heated for about 24 hours while the outside temperature of the reaction vessel was maintained at about 215° C. After cooling, the mixture was diluted with CH₂Cl₂ and water was added thereto, and the reaction solution was filtered through celite and separated to concentrate an organic layer. The organic layer was purified with silica gel column chromatography to obtain Intermediate 263-(2) (about 7.29 g, about 77% yield). The molecular weight of Intermediate 263-(2) was about 994 from FAB MS measurement.

### Synthesis of Intermediate 263-(3)

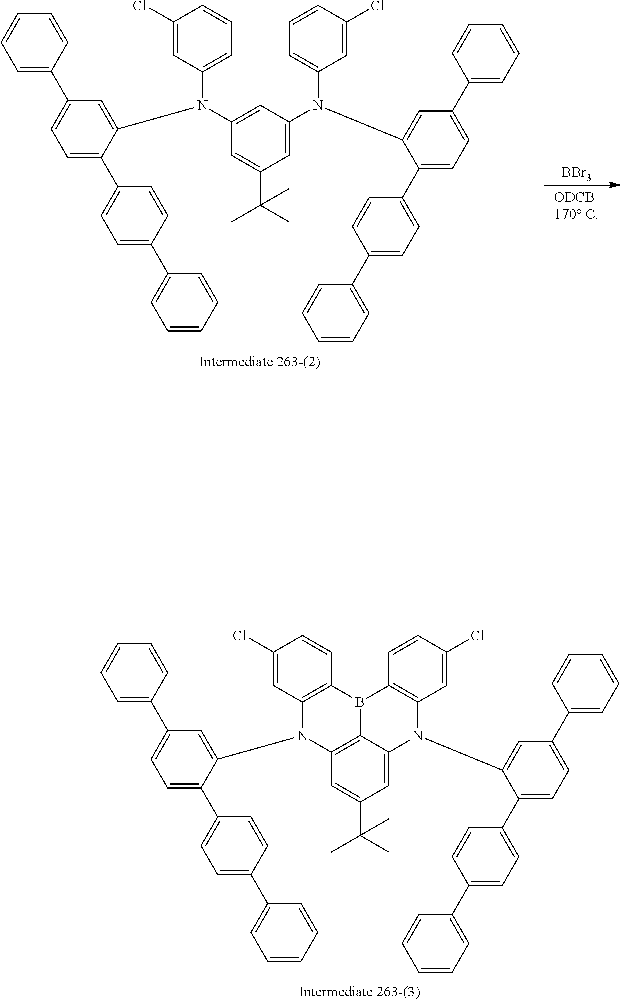 [SMILES: CC(C)(C)c1cc(N(c2cccc(Cl)c2)c2cc(-c3ccccc3)ccc2-c2ccc(-c3ccccc3)cc2)cc(N(c2cccc(Cl)c2)c2cc(-c3ccccc3)ccc2-c2ccc(-c3ccccc3)cc2)c1 ; "BBr3" ; CC(C)(C)c1cc2c3c(c1)N(c1cc(-c4ccccc4)ccc1-c1ccc(-c4ccccc4)cc1)c1cc(Cl)ccc1B3c1ccc(Cl)cc1N2c1cc(-c2ccccc2)ccc1-c1ccc(-c2ccccc2)cc1]

Under an Ar atmosphere, Intermediate 263-(2) (7.01 g, 7.05 mmol) was dissolved in ODCB (71 mL), BBr₃ (3.53 g, 14.1 mmol) was added thereto, and heated and agitated for about 10 hours at about 170° C. The reaction solution was then cooled to room temperature, DIPEA (10.92 g, 84.62 mmol) was added, and water was added thereto, and the reaction solution was filtered through celite and separated to concentrate an organic layer. The organic layer was purified with silica gel column chromatography to obtain Intermediate 263-(3) (about 1.98 g, about 28% yield). The molecular weight of Intermediate 263-(3) was about 1002 from FAB MS measurement.

### Synthesis of Compound 263

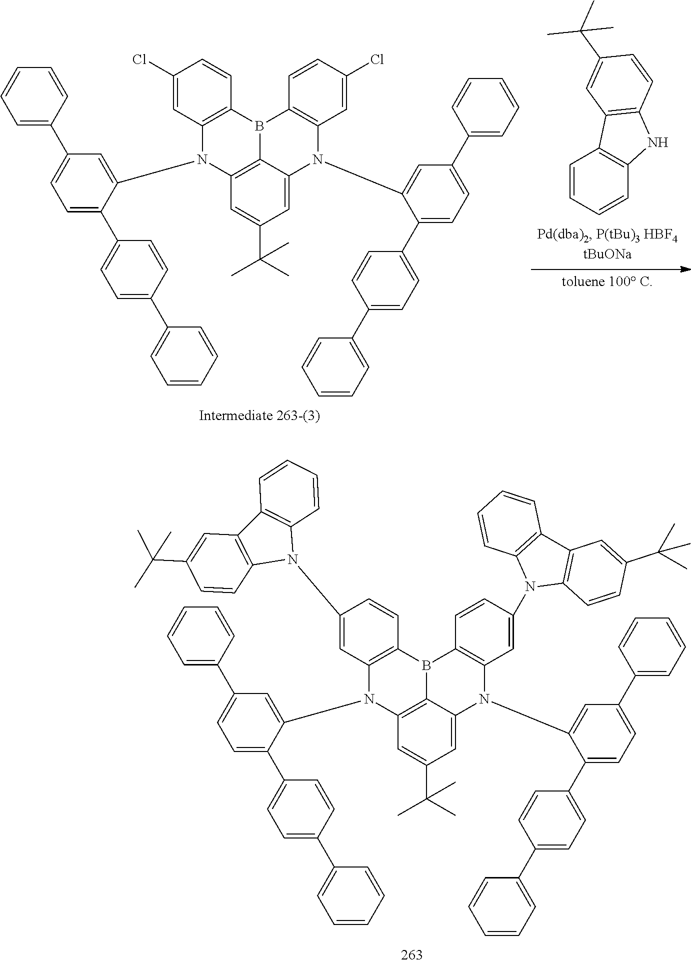 [SMILES: CC(C)(C)c1cc2c3c(c1)N(c1cc(-c4ccccc4)ccc1-c1ccc(-c4ccccc4)cc1)c1cc(Cl)ccc1B3c1ccc(Cl)cc1N2c1cc(-c2ccccc2)ccc1-c1ccc(-c2ccccc2)cc1 ; CC(C)(C)c1ccc2[nH]c3ccccc3c2c1 ; CC(C)(C)c1cc2c3c(c1)N(c1cc(-c4ccccc4)ccc1-c1ccc(-c4ccccc4)cc1)c1cc(-n4c5ccccc5c5cc(C(C)(C)C)ccc54)ccc1B3c1ccc(-n3c4ccccc4c4cc(C(C)(C)C)ccc43)cc1N2c1cc(-c2ccccc2)ccc1-c1ccc(-c2ccccc2)cc1]

Under an Ar atmosphere, Intermediate 263-(3) (1.85 g, 6.34 mmol) and 3-(tert-butyl)-9H-carbazole (5.09 g, 15.84 mmol), Pd(dba) 2 (0.36 g, 0.63 mmol), P(tBu)₃·HBF₄ (0.37 g, 1.27 mmol), and tBuONa (2.44 g, 25.34 mmol) were added to 31 mL of toluene, and heated and agitated for about 8 hours at about 100° C. After cooling, water was added, and the mixture was filtered through celite and separated to concentrate an organic layer. The organic layer was purified with silica gel column chromatography to obtain Compound 263 (about 3.62 g, about 74% yield). The molecular weight of Compound 263 was about 773 from FAB MS measurement. Sublimation purification (about 320° C., 2.7×10⁻³ Pa) was further performed for device evaluation.

### (13) Synthesis of Compound 264

### Synthesis of Intermediate 264-(1)

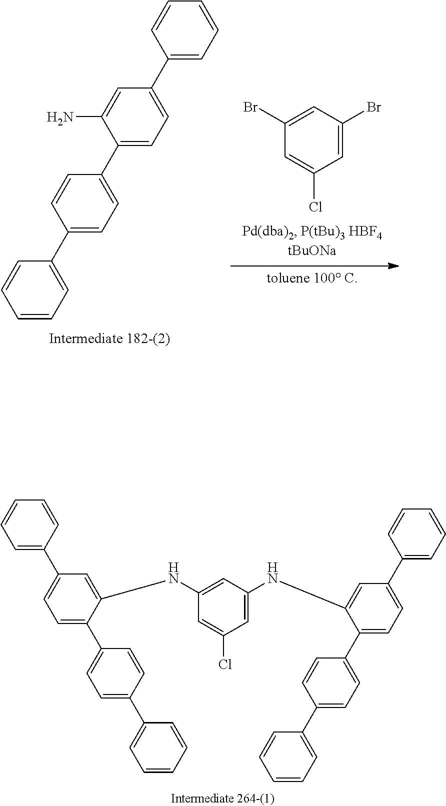 [SMILES: Nc1cc(-c2ccccc2)ccc1-c1ccc(-c2ccccc2)cc1 ; Clc1cc(Br)cc(Br)c1 ; Clc1cc(Nc2cc(-c3ccccc3)ccc2-c2ccc(-c3ccccc3)cc2)cc(Nc2cc(-c3ccccc3)ccc2-c2ccc(-c3ccccc3)cc2)c1]

Under an Ar atmosphere, 1,3-dibromo-5-chlorobenzene (5.22 g, 19.31 mmol) and Intermediate 182-(2) (15.52 g, 48.27 mmol), Pd(dba) 2 (1.11 g, 1.93 mmol), P(tBu)₃·HBF₄ (1.12 g, 3.86 mmol), and tBuONa (7.42 g, 77.23 mmol) were added to 96 mL of toluene, and heated and agitated for about 8 hours at about 100° C. After cooling, water was added, and the mixture was filtered through celite and separated to concentrate an organic layer. The organic layer was purified with silica gel column chromatography to obtain Intermediate 264-(1) (about 12.77 g, about 88% yield). The molecular weight of Intermediate 264-(1) was about 751 from FAB MS measurement.

### Synthesis of Intermediate 264-(2)

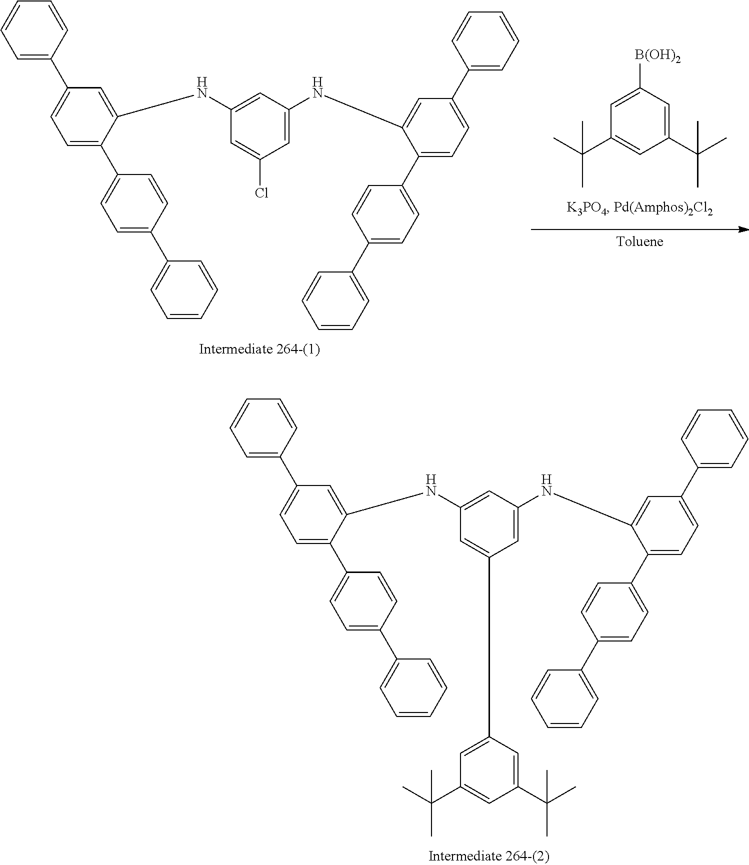 [SMILES: Clc1cc(Nc2cc(-c3ccccc3)ccc2-c2ccc(-c3ccccc3)cc2)cc(Nc2cc(-c3ccccc3)ccc2-c2ccc(-c3ccccc3)cc2)c1 ; CC(C)(C)c1cc(B(O)O)cc(C(C)(C)C)c1 ; CC(C)(C)c1cc(-c2cc(Nc3cc(-c4ccccc4)ccc3-c3ccc(-c4ccccc4)cc3)cc(Nc3cc(-c4ccccc4)ccc3-c3ccc(-c4ccccc4)cc3)c2)cc(C(C)(C)C)c1]

Under an Ar atmosphere, 89.84 mL of toluene and 44.92 mL of a mixture of EtOH and water in 1:1 were added to Intermediate 264-(1) (11.23 g, 12.43 mmol) and (3,5-di-tert-butylphenyl) boronic acid (8.73 g, 37.29 mmol), K₃PO₄ (5.28 g, 24.86 mmol), and Pd(Amphos) 2Cl₂ (0.88 g, 1.24 mmol) in a reaction vessel, and then heated for about 24 hours while the outside temperature of the reaction vessel was maintained at about 90° C. After cooling, water was added, and the mixture was filtered through celite and separated to concentrate an organic layer. The organic layer was purified with silica gel column chromatography to obtain Intermediate 264-(2) (about 12.77 g, about 88% yield). The molecular weight of Intermediate 264-(2) was about 751 from FAB MS measurement.

### Synthesis of Intermediate 264-(3)

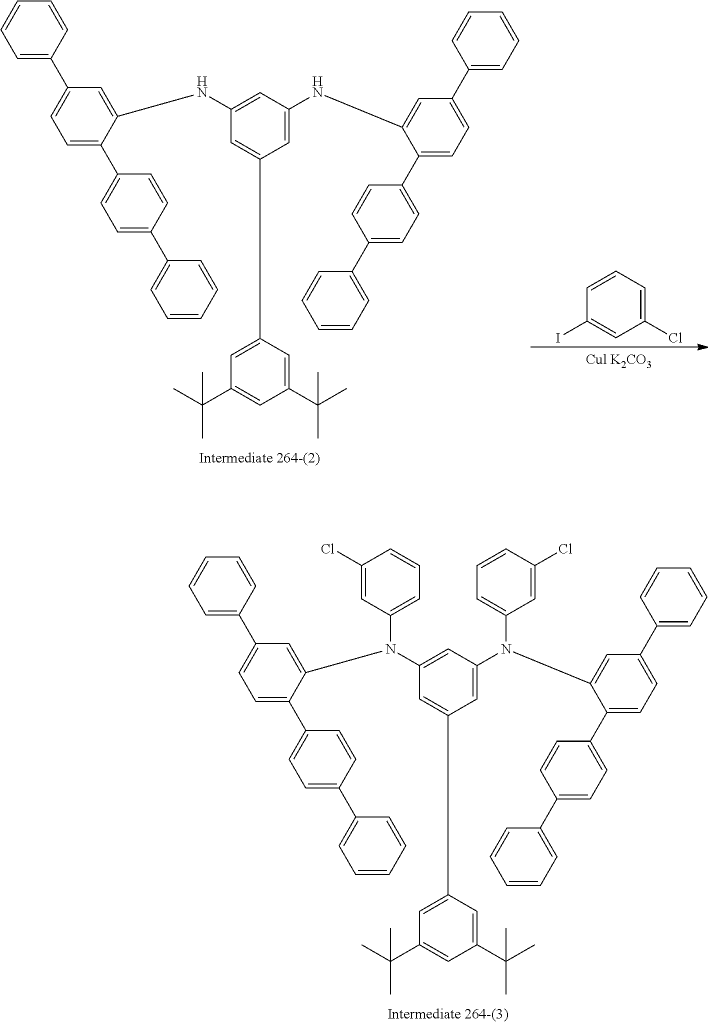 [SMILES: CC(C)(C)c1cc(-c2cc(Nc3cc(-c4ccccc4)ccc3-c3ccc(-c4ccccc4)cc3)cc(Nc3cc(-c4ccccc4)ccc3-c3ccc(-c4ccccc4)cc3)c2)cc(C(C)(C)C)c1 ; Clc1cccc(I)c1 ; CC(C)(C)c1cc(-c2cc(N(c3cccc(Cl)c3)c3cc(-c4ccccc4)ccc3-c3ccc(-c4ccccc4)cc3)cc(N(c3cccc(Cl)c3)c3cc(-c4ccccc4)ccc3-c3ccc(-c4ccccc4)cc3)c2)cc(C(C)(C)C)c1]

A small amount of toluene in about 10 mL was added to Intermediate 264-(2) (12.44 g, 9.52 mmol) and 1-chloro-3-iodobenzene (22.7 g, 95.2 mmol), CuI (4.53 g, 23.8 mmol), and K₂CO₃ (19.74 g, 142.8 mmol) in a reaction vessel, and heated for about 24 hours while the outside temperature of the reaction vessel was maintained at about 215° C. After cooling, the mixture was diluted with CH₂Cl₂ and water was added thereto, and the reaction solution was filtered through celite and separated to concentrate an organic layer. The organic layer was purified with silica gel column chromatography to obtain Intermediate 264-(3) (about 8.90 g, about 83% yield). The molecular weight of Intermediate 264-(3) was about 1126 from FAB MS measurement.

### Synthesis of Intermediate 264-(4)

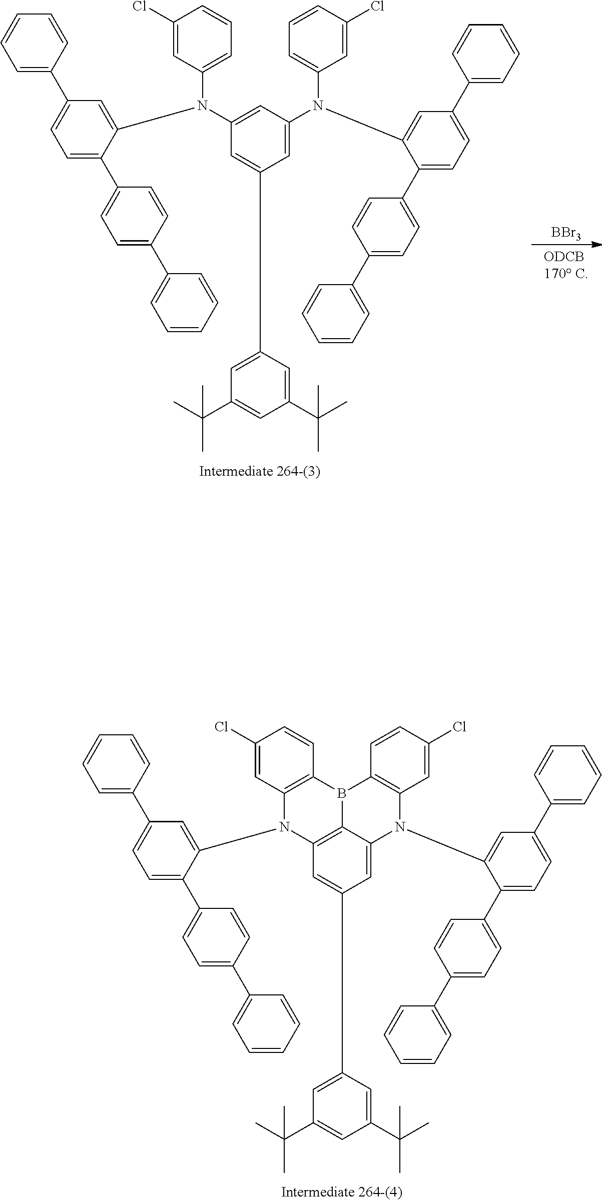 [SMILES: CC(C)(C)c1cc(-c2cc(N(c3cccc(Cl)c3)c3cc(-c4ccccc4)ccc3-c3ccc(-c4ccccc4)cc3)cc(N(c3cccc(Cl)c3)c3cc(-c4ccccc4)ccc3-c3ccc(-c4ccccc4)cc3)c2)cc(C(C)(C)C)c1 ; "BBr3" ; CC(C)(C)c1cc(-c2cc3c4c(c2)N(c2cc(-c5ccccc5)ccc2-c2ccc(-c5ccccc5)cc2)c2cc(Cl)ccc2B4c2ccc(Cl)cc2N3c2cc(-c3ccccc3)ccc2-c2ccc(-c3ccccc3)cc2)cc(C(C)(C)C)c1]

Under an Ar atmosphere, Intermediate 264-(3) (8.71 g, 7.73 mmol) was dissolved in ODCB (77 mL), BBr₃ (3.87 g, 15.47 mmol) was added thereto, and heated and agitated for about 10 hours at about 170° C. The reaction solution was then cooled to room temperature, DIPEA (11.97 g, 92.8 mmol) was added, and water was added thereto, and the reaction solution was filtered through celite and separated to concentrate an organic layer. The organic layer was purified with silica gel column chromatography to obtain Intermediate 264-(4) (about 3.24 g, about 37% yield). The molecular weight of Intermediate 264-(4) was about 1134 from FAB MS measurement.

### Synthesis of Compound 264

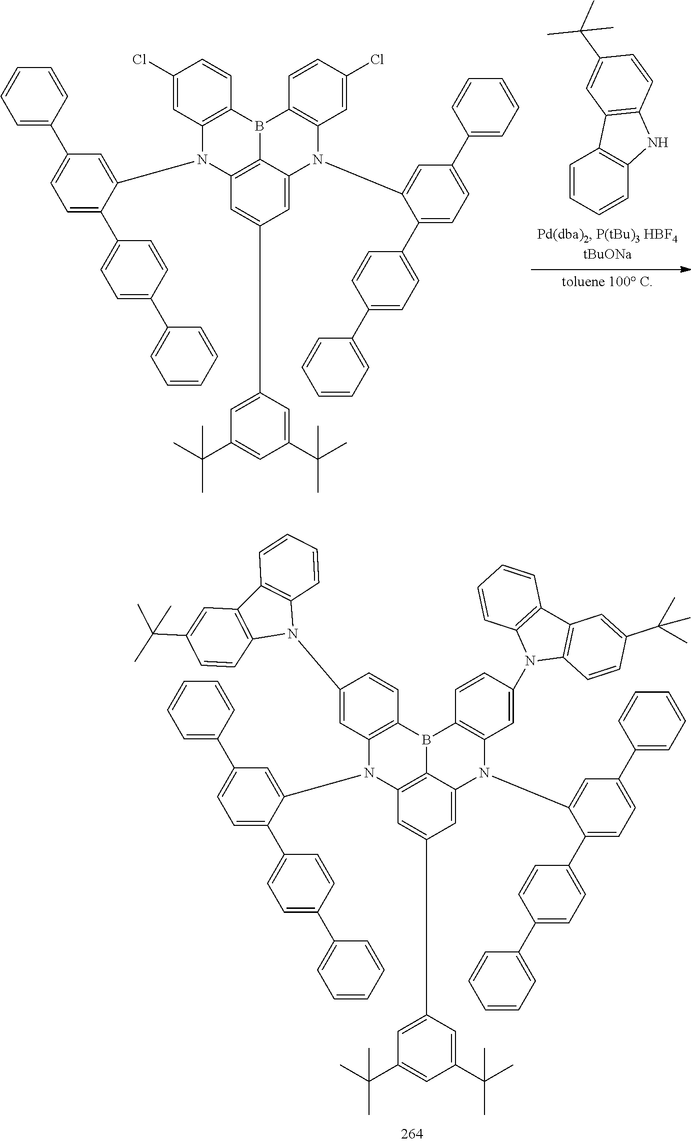 [SMILES: CC(C)(C)c1cc(-c2cc3c4c(c2)N(c2cc(-c5ccccc5)ccc2-c2ccc(-c5ccccc5)cc2)c2cc(Cl)ccc2B4c2ccc(Cl)cc2N3c2cc(-c3ccccc3)ccc2-c2ccc(-c3ccccc3)cc2)cc(C(C)(C)C)c1 ; CC(C)(C)c1ccc2[nH]c3ccccc3c2c1 ; CC(C)(C)c1cc(-c2cc3c4c(c2)N(c2cc(-c5ccccc5)ccc2-c2ccc(-c5ccccc5)cc2)c2cc(-n5c6ccccc6c6cc(C(C)(C)C)ccc65)ccc2B4c2ccc(-n4c5ccccc5c5cc(C(C)(C)C)ccc54)cc2N3c2cc(-c3ccccc3)ccc2-c2ccc(-c3ccccc3)cc2)cc(C(C)(C)C)c1]

Under an Ar atmosphere, Intermediate 264-(4) (3.01 g, 2.65 mmol) and 3-(tert-butyl)-9H-carbazole (1.48 g, 6.64 mmol), Pd(dba) 2 (0.15 g, 0.27 mmol), P(tBu)₃·HBF₄ (0.15 g, 0.53 mmol), and tBuONa (1.02 g, 10.62 mmol) were added to 13 mL of toluene, and heated and agitated for about 8 hours at about 100° C. After cooling, water was added, and the mixture was filtered through celite and separated to concentrate an organic layer. The organic layer was purified with silica gel column chromatography to obtain Compound 264 (about 3.08 g, about 77% yield). The molecular weight of Compound 264 was about 1508 from FAB MS measurement. Sublimation purification (about 350° C., 3.3×10⁻³ Pa) was further performed for device evaluation.

### (14) Synthesis of Compound 401

### Synthesis of Intermediate 401-(1)

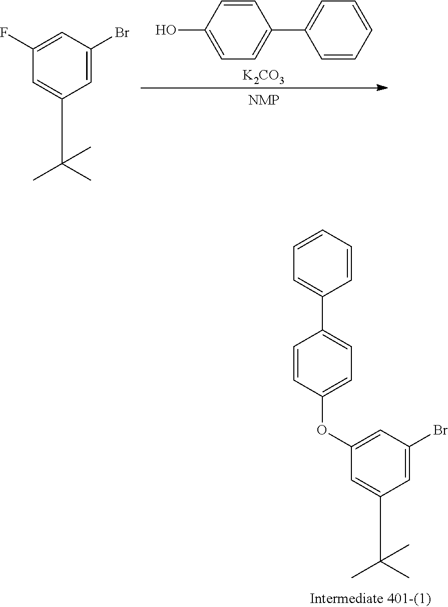

Under an Ar atmosphere, 102 mL of N-methyl-2-pyrrolidone (NMP) was added to 1-bromo-3-(tert-butyl)-5-fluorobenzene (10.22 g, 44.22 mmol) and [1,1′-biphenyl]-4-ol (9.03 g, 53.07 mmol), and K₂CO₃ (27.5 g, 199 mmol) in a reaction vessel, and heated for about 24 hours while the outside temperature of the reaction vessel was maintained at about 140° C. After cooling, the mixture was diluted with CH₂Cl₂ and water was added thereto, and the reaction solution was filtered through celite and separated to concentrate an organic layer. The organic layer was purified with silica gel column chromatography to obtain Intermediate 401-(1) (about 14.16 g, about 84% yield). The molecular weight of Intermediate 401-(1) was about 381 from FAB MS measurement.

### Synthesis of Intermediate 401-(2)

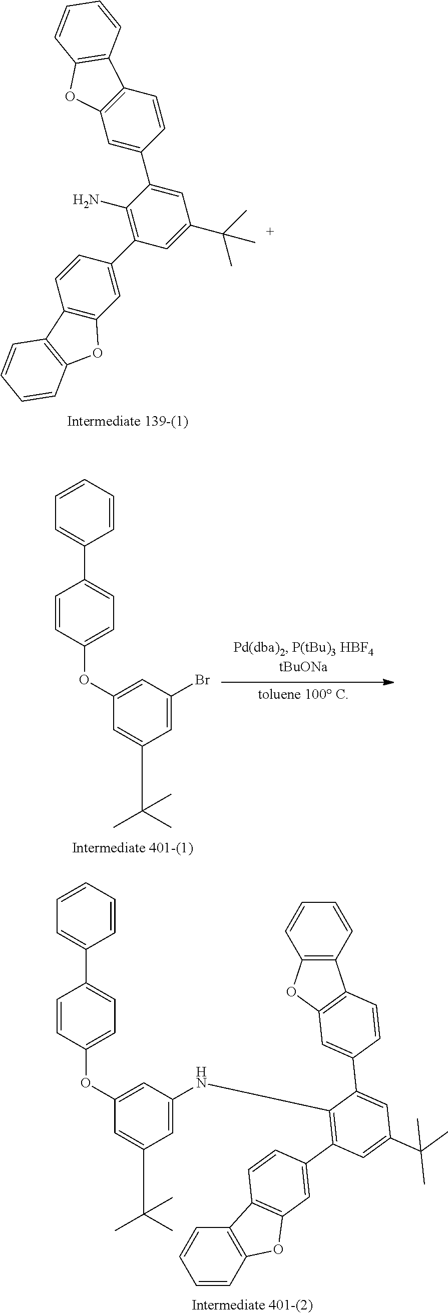 [SMILES: CC(C)(C)c1cc(-c2ccc3c(c2)oc2ccccc23)c(N)c(-c2ccc3c(c2)oc2ccccc23)c1 ; CC(C)(C)c1cc(Br)cc(Oc2ccc(-c3ccccc3)cc2)c1 ; CC(C)(C)c1cc(Nc2c(-c3ccc4c(c3)oc3ccccc34)cc(C(C)(C)C)cc2-c2ccc3c(c2)oc2ccccc23)cc(Oc2ccc(-c3ccccc3)cc2)c1]

Under an Ar atmosphere, Intermediate 401-(1) (13.22 g, 34.67 mmol) and Intermediate 139-(1) (20.04 g, 41.6 mmol), Pd(dba) 2 (1.99 g, 3.47 mmol), P(tBu)₃·HBF₄ (2.01 g, 6.93 mmol), and tBuONa (7.66 g, 79.74 mmol) were added to 173 mL of toluene, and heated and agitated for about 8 hours at about 100° C. After cooling, water was added, and the mixture was filtered through celite and separated to concentrate an organic layer. The organic layer was purified with silica gel column chromatography to obtain Intermediate 401-(2) (about 21.96 g, about 81% yield). The molecular weight of Intermediate 401-(2) was about 782 from FAB MS measurement.

### Synthesis of Intermediate 401-(3)

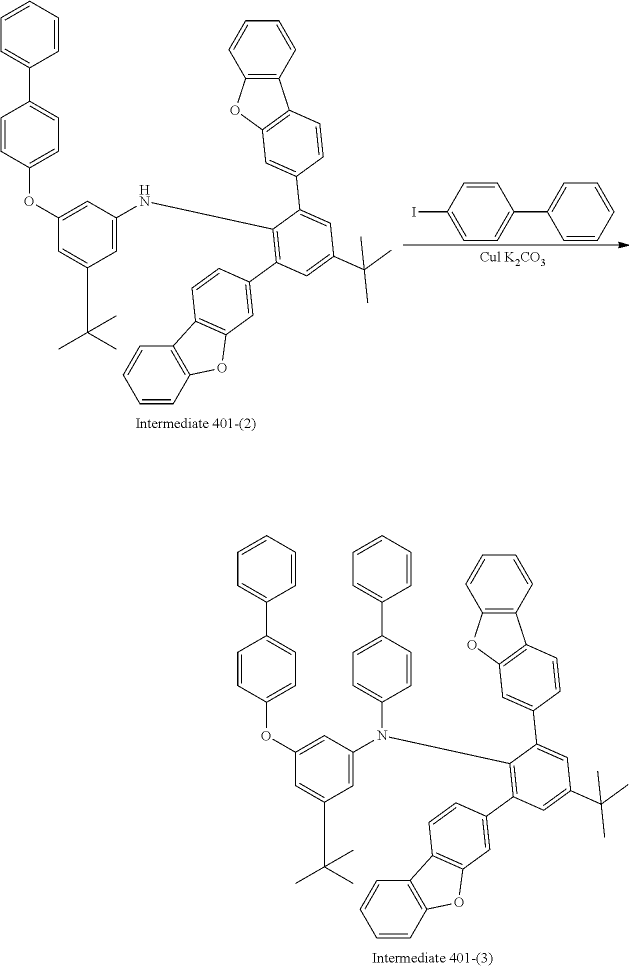

A small amount of toluene in about 10 mL was added to Intermediate 401-(2) (10.05 g, 9.52 mmol) and 4-iodo-1,1′-biphenyl (26.67 g, 95.2 mmol), CuI (4.53 g, 23.8 mmol), and K₂CO₃ (19.74 g, 142.8 mmol) in a reaction vessel, and heated for about 24 hours while the outside temperature of the reaction vessel was maintained at about 215° C. After cooling, the mixture was diluted with CH₂Cl₂ and water was added thereto, and the reaction solution was filtered through celite and separated to concentrate an organic layer. The organic layer was purified with silica gel column chromatography to obtain Intermediate 401-(3) (about 7.74 g, about 87% yield). The molecular weight of Intermediate 401-(3) was about 934 from FAB MS measurement.

### Synthesis of Compound 401

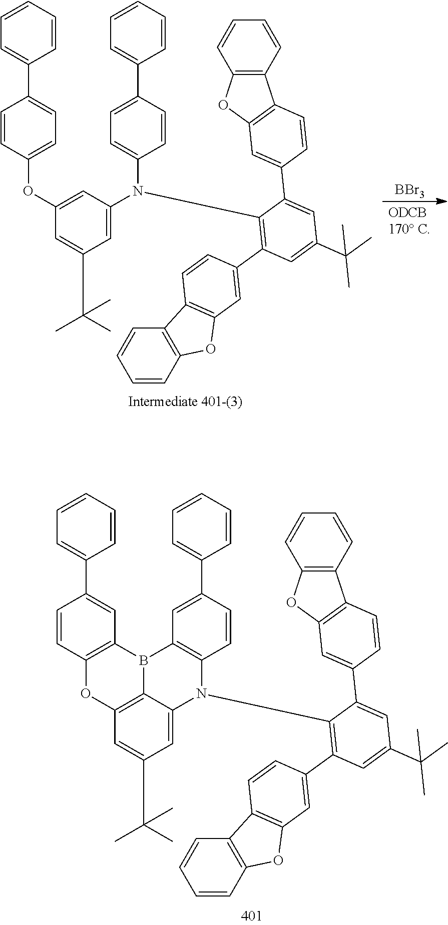 [SMILES: CC(C)(C)c1cc(Oc2ccc(-c3ccccc3)cc2)cc(N(c2ccc(-c3ccccc3)cc2)c2c(-c3ccc4c(c3)oc3ccccc34)cc(C(C)(C)C)cc2-c2ccc3c(c2)oc2ccccc23)c1 ; "BBr3" ; CC(C)(C)c1cc(-c2ccc3c(c2)oc2ccccc23)c(N2c3ccc(-c4ccccc4)cc3B3c4cc(-c5ccccc5)ccc4Oc4cc(C(C)(C)C)cc2c43)c(-c2ccc3c(c2)oc2ccccc23)c1]

Under an Ar atmosphere, Intermediate 401-(3) (7.51 g, 8.04 mmol) was dissolved in ODCB (80 mL), BBr₃ (4.03 g, 16.08 mmol) was added thereto, and heated and agitated for about 10 hours at about 170° C. The reaction solution was then cooled to room temperature, DIPEA (12.44 g, 96.47 mmol) was added, and water was added thereto, and the reaction solution was filtered through celite and separated to concentrate an organic layer. The organic layer was purified with silica gel column chromatography to obtain Compound 401 (about 1.82 g, about 24% yield). The molecular weight of Compound 401 was about 942 from FAB MS measurement. Sublimation purification (about 280° C., 2.3×10⁻³ Pa) was further performed for device evaluation.

### (15) Synthesis of Compound 543

### Synthesis of Intermediate 543-(1)

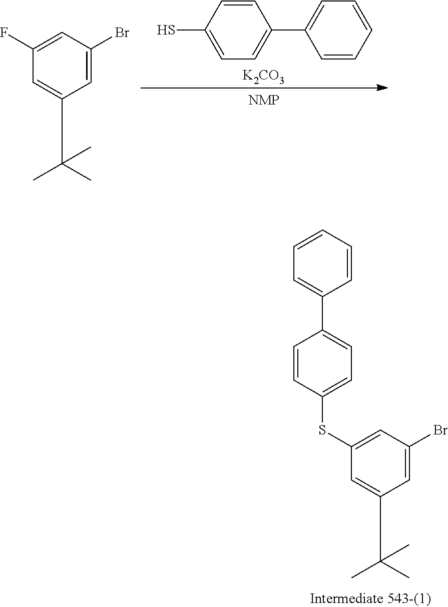

Under an Ar atmosphere, 86 mL of NMP was added to 1-bromo-3-(tert-butyl)-5-fluorobenzene (8.66 g, 37.47 mmol) and [1,1′-biphenyl]-4-thiol (7.65 g, 44.97 mmol), K₂CO₃ (23.31 g, 168.62 mmol) in a reaction vessel, and heated for about 24 hours while the outside temperature of the reaction vessel was maintained at about 140° C. After cooling, the mixture was diluted with CH₂Cl₂ and water was added thereto, and the reaction solution was filtered through celite and separated to concentrate an organic layer. The organic layer was purified with silica gel column chromatography to obtain Intermediate 543-(1) (about 8.34 g, about 56% yield). The molecular weight of Intermediate 543-(1) was about 397 from FAB MS measurement.

### Synthesis of Intermediate 543-(2)

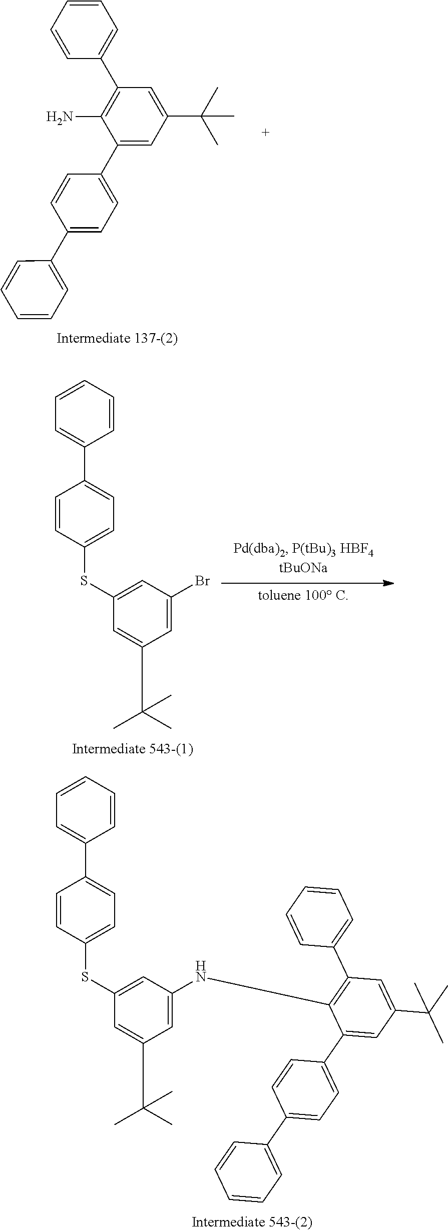 [SMILES: CC(C)(C)c1cc(-c2ccccc2)c(N)c(-c2ccc(-c3ccccc3)cc2)c1 ; CC(C)(C)c1cc(Br)cc(Sc2ccc(-c3ccccc3)cc2)c1 ; CC(C)(C)c1cc(Nc2c(-c3ccccc3)cc(C(C)(C)C)cc2-c2ccc(-c3ccccc3)cc2)cc(Sc2ccc(-c3ccccc3)cc2)c1]

Under an Ar atmosphere, Intermediate 543-(1) (7.75 g, 19.5 mmol) and Intermediate 137-(2) (8.84 g, 23.4 mmol), Pd(dba) 2 (1.12 g, 1.95 mmol), P(tBu)₃·HBF₄ (1.13 g, 3.9 mmol), and tBuONa (4.31 g, 44.86 mmol) were added to 97 mL of toluene, and heated and agitated for about 8 hours at about 100° C. After cooling, water was added, and the mixture was filtered through celite and separated to concentrate an organic layer. The organic layer was purified with silica gel column chromatography to obtain Intermediate 543-(2) (about 11.37 g, about 84% yield). The molecular weight of Intermediate 543-(2) was about 694 from FAB MS measurement.

### Synthesis of Intermediate 543-(3)

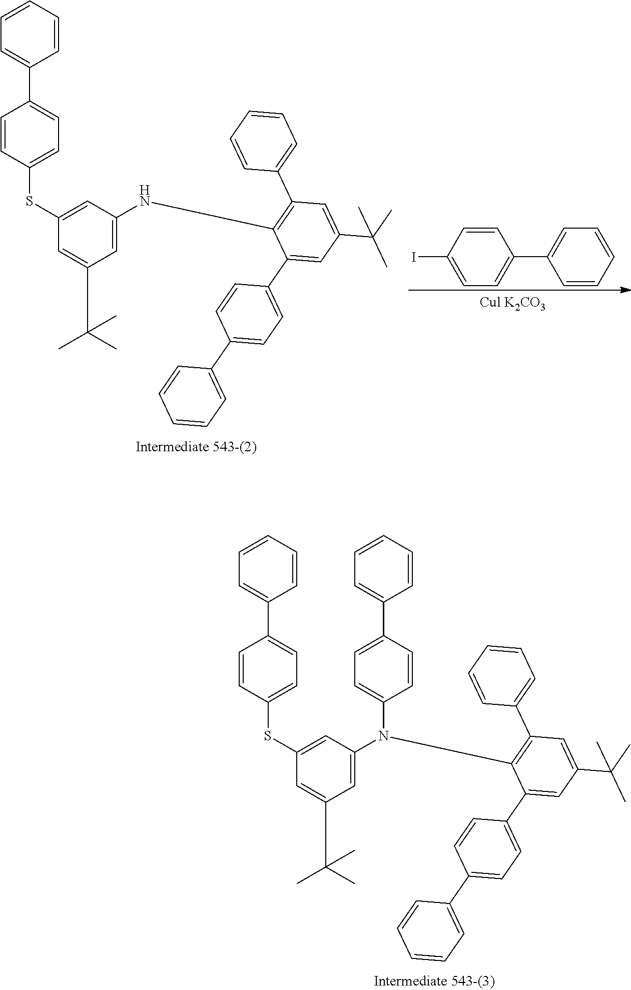

A small amount of toluene in about 10 mL was added to Intermediate 543-(2) (11.02 g, 9.52 mmol) and 4-iodo-1,1′-biphenyl (26.67 g, 95.2 mmol), CuI (4.53 g, 23.8 mmol), and K₂CO₃ (19.74 g, 142.8 mmol) in a reaction vessel, and heated for about 24 hours while the outside temperature of the reaction vessel was maintained at about 215° C. After cooling, the mixture was diluted with CH₂Cl₂ and water was added thereto, and the reaction solution was filtered through celite and separated to concentrate an organic layer. The organic layer was purified with silica gel column chromatography to obtain Intermediate 543-(3) (about 5.72 g, about 71% yield). The molecular weight of Intermediate 543-(3) was about 846 from FAB MS measurement.

### Synthesis of Compound 543

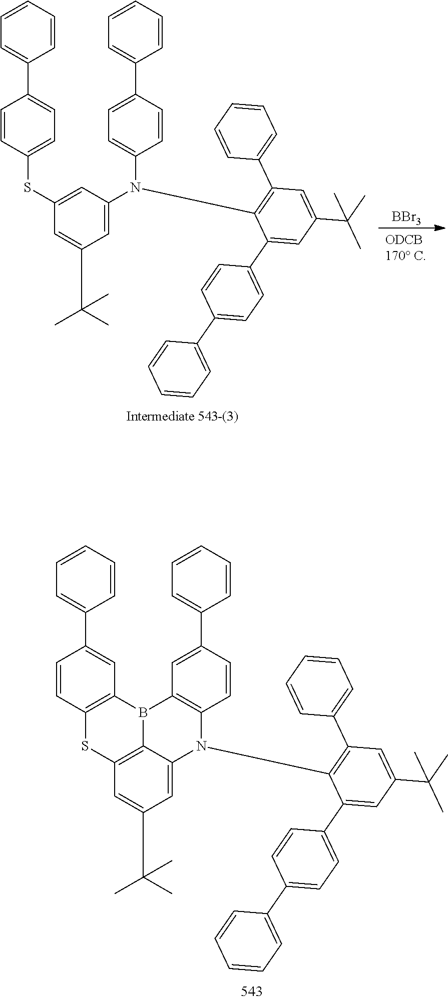

Under an Ar atmosphere, Intermediate 543-(3) (5.54 g, 6.55 mmol) was dissolved in ODCB (65 mL), BBr₃ (3.28 g, 13.09 mmol) was added thereto, and heated and agitated for about 10 hours at about 170° C. The reaction solution was then cooled to room temperature, DIPEA (10.13 g, 78.56 mmol) was added, and water was added thereto, and the reaction solution was filtered through celite and separated to concentrate an organic layer. The organic layer was purified with silica gel column chromatography to obtain Compound 543 (about 1.45 g, about 26% yield). The molecular weight of Compound 543 was about 854 from FAB MS measurement. Sublimation purification (about 320° C., 2.5×10⁻³ Pa) was further performed for device evaluation.

### 2. Manufacturing and Evaluating Light Emitting Elements

A light emitting element according to an embodiment, which includes the fused polycyclic compound according to an embodiment in an emission layer thereof, was manufactured in the following method. Using the fused polycyclic compounds of Compounds 51, 137, 138, 139, 140, 182, 183, 222, 226, 228, 240, 263, 264, 401, and 543, which are the example compounds described above, as a dopant material for the emission layer, respectively, the light emitting elements according to Examples 1 to 15 were manufactured. Comparative Examples 1 to 9 correspond to the light emitting elements manufactured respectively using Comparative Example Compounds X1 to X9 as a dopant material for the emission layer.

### Example Compound

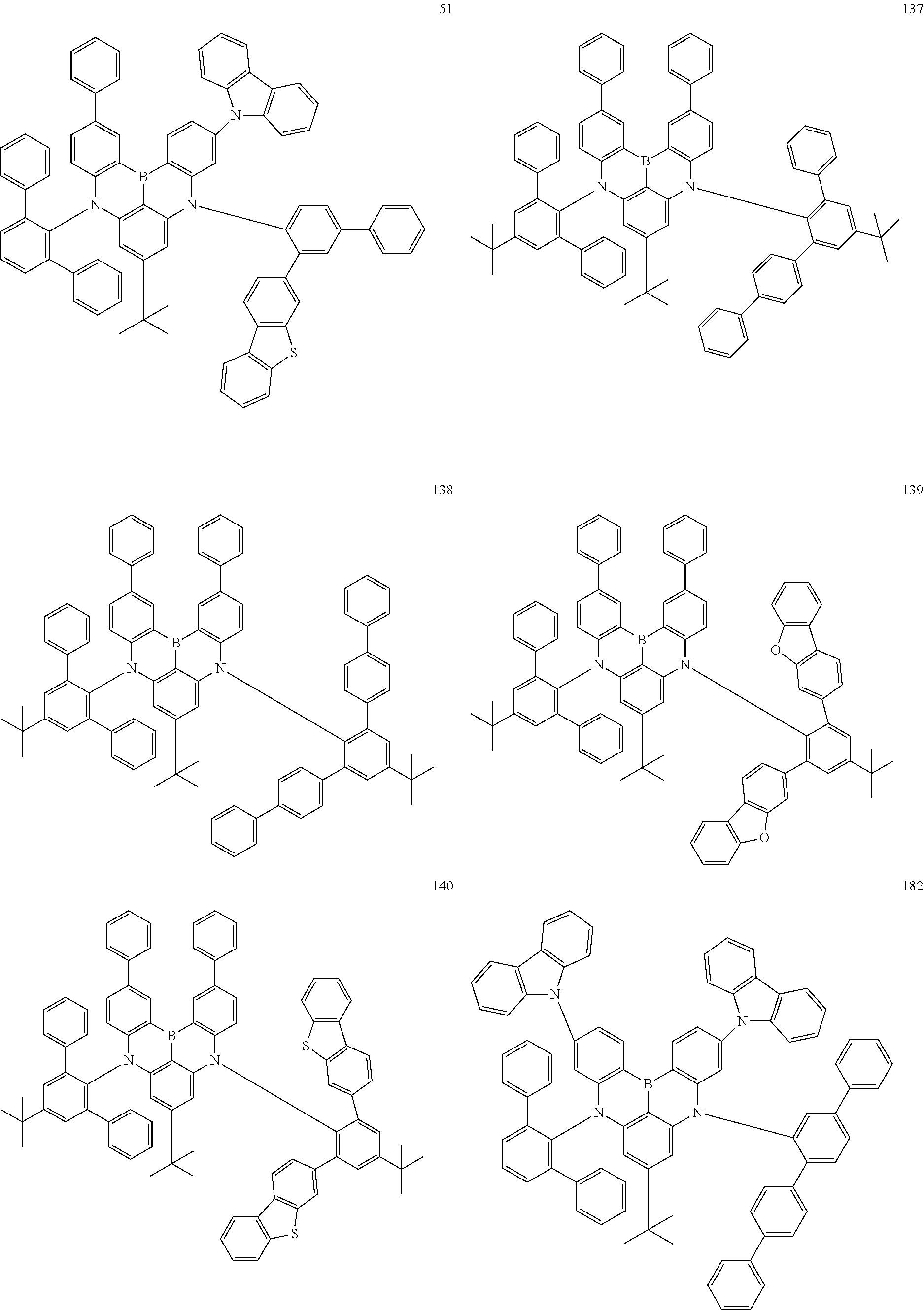

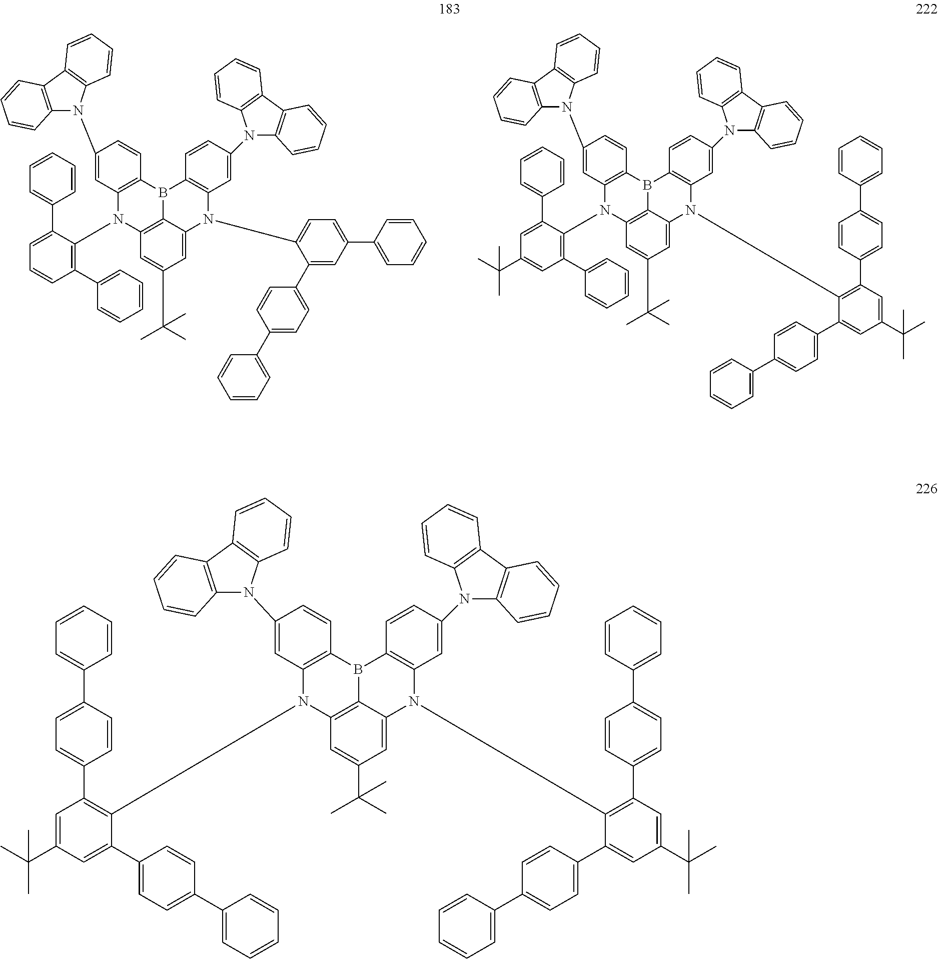

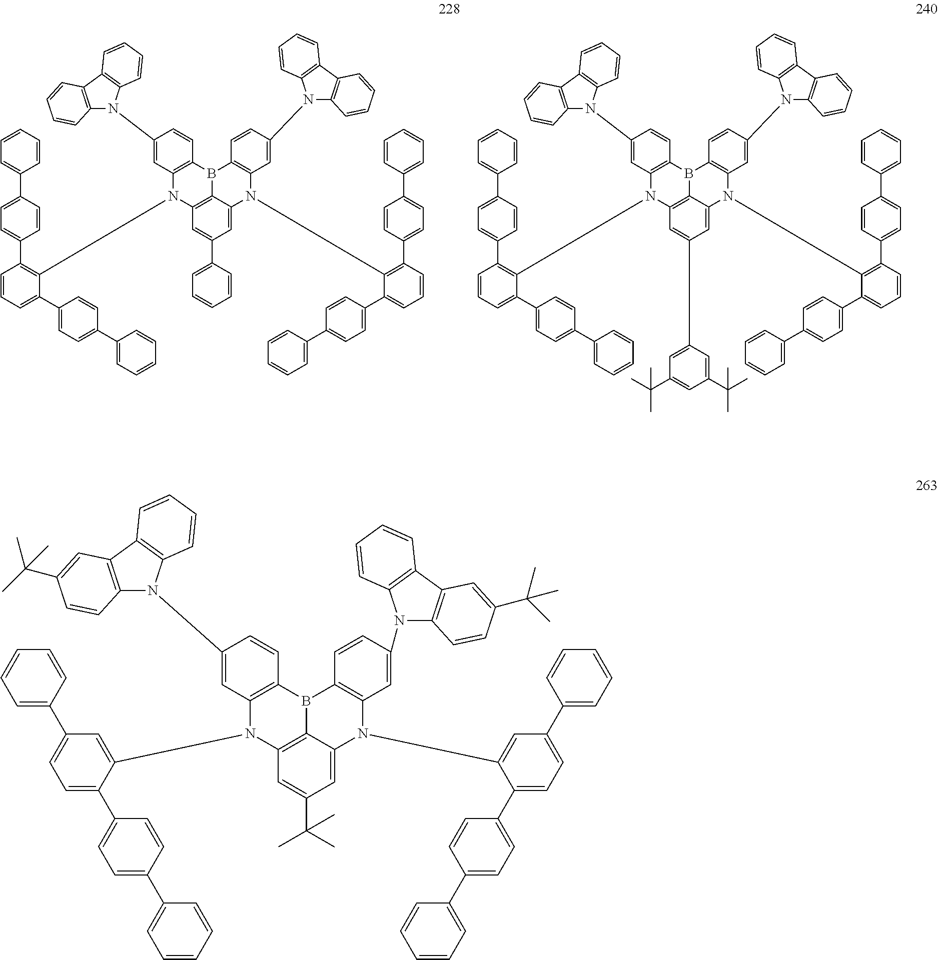

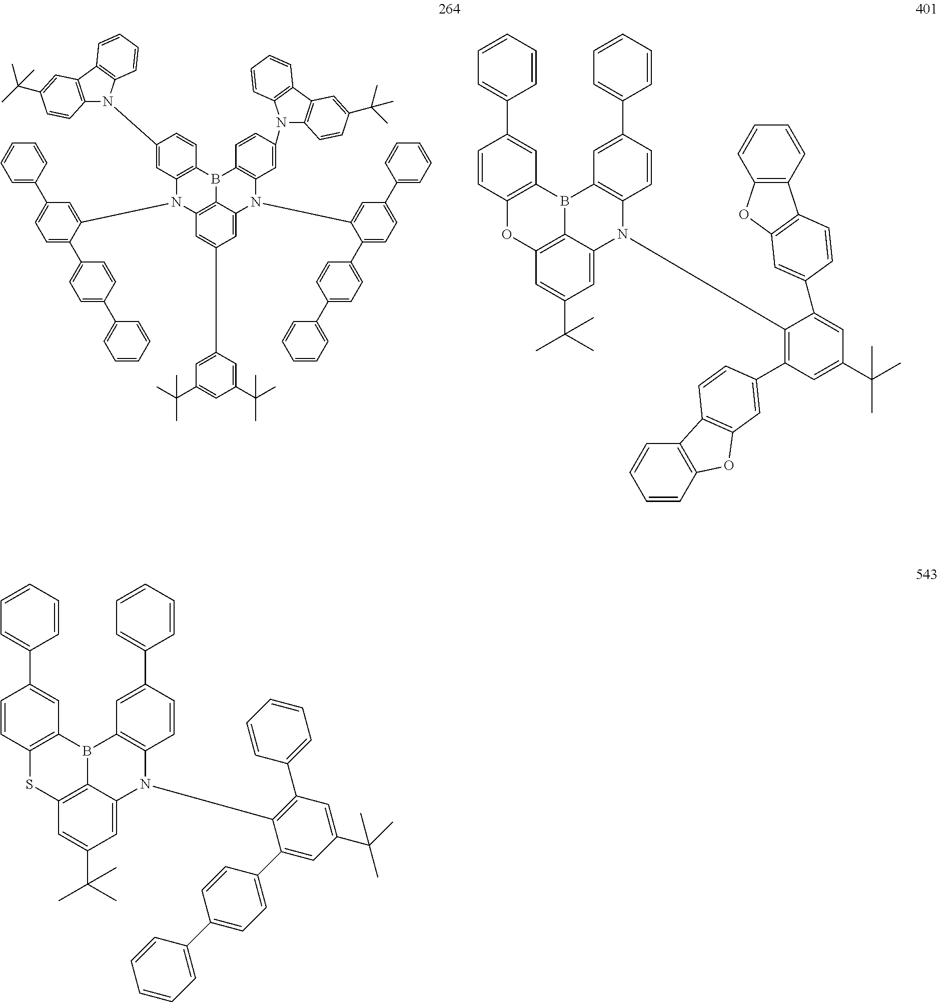 [SMILES: CC(C)(C)c1cc(-c2cc3c4c(c2)N(c2cc(-c5ccccc5)ccc2-c2ccc(-c5ccccc5)cc2)c2cc(-n5c6ccccc6c6cc(C(C)(C)C)ccc65)ccc2B4c2ccc(-n4c5ccccc5c5cc(C(C)(C)C)ccc54)cc2N3c2cc(-c3ccccc3)ccc2-c2ccc(-c3ccccc3)cc2)cc(C(C)(C)C)c1 ; CC(C)(C)c1cc(-c2ccc3c(c2)oc2ccccc23)c(N2c3ccc(-c4ccccc4)cc3B3c4cc(-c5ccccc5)ccc4Oc4cc(C(C)(C)C)cc2c43)c(-c2ccc3c(c2)oc2ccccc23)c1 ; CC(C)(C)c1cc(-c2ccccc2)c(N2c3ccc(-c4ccccc4)cc3B3c4cc(-c5ccccc5)ccc4Sc4cc(C(C)(C)C)cc2c43)c(-c2ccc(-c3ccccc3)cc2)c1]

### Comparative Example Compound

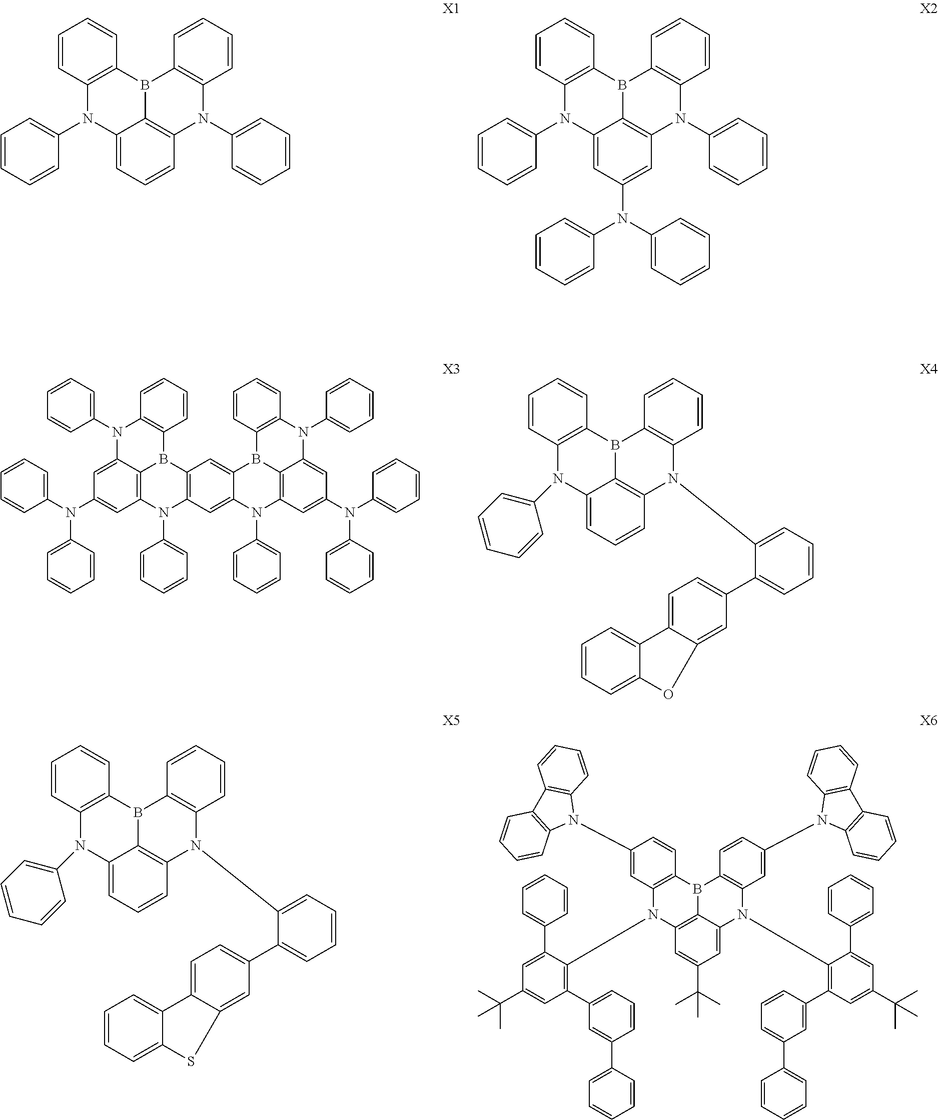

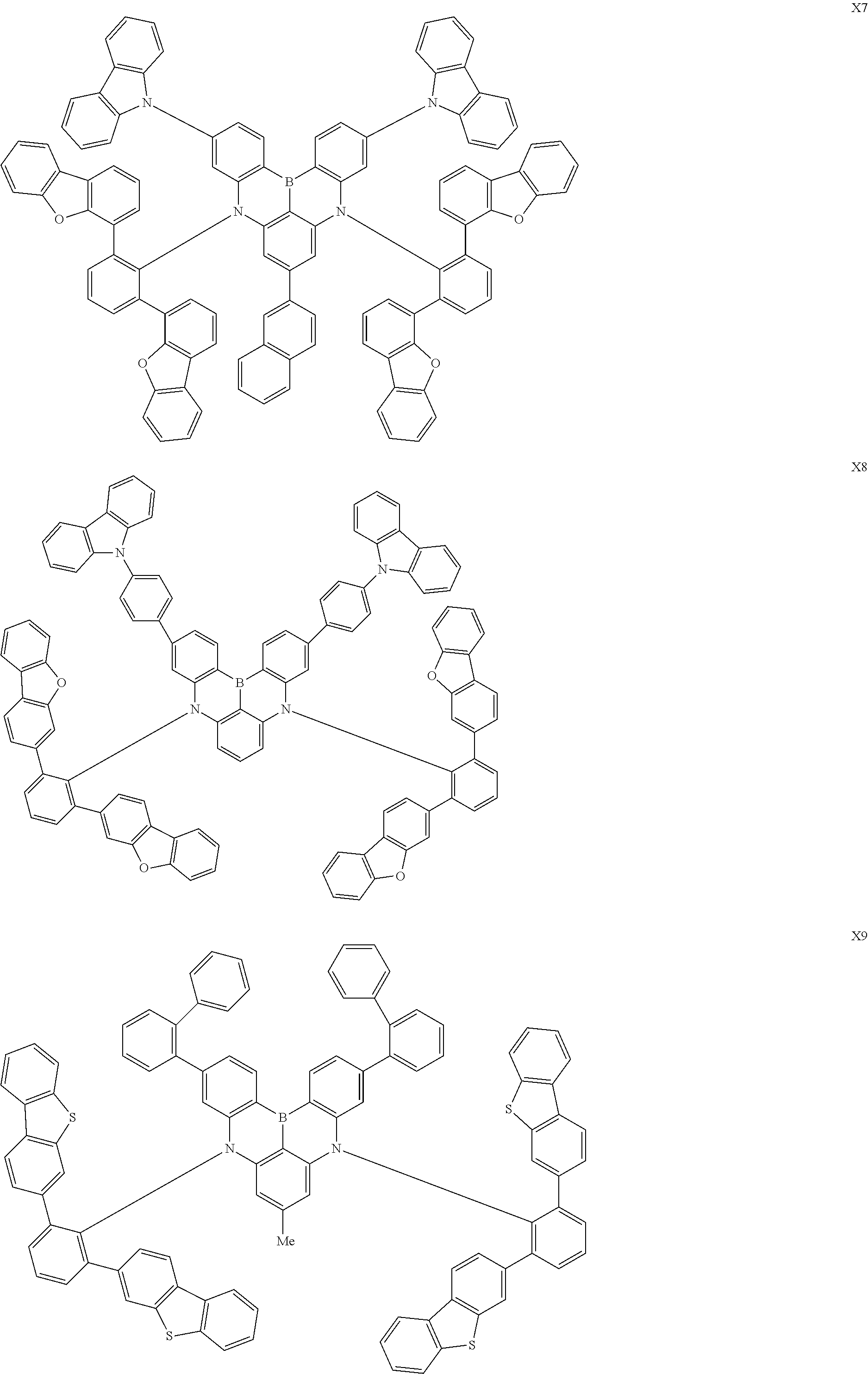

### Manufacturing Light Emitting Element

A first electrode was formed including ITO with a thickness of about 150 nm, and a hole injection layer was formed on the first electrode by including dipyrazino[2,3-f:2′,3′-h]quinoxaline-2,3,6,7,10,11-hexacarbonitrile (HATCN) with a thickness of about 10 nm, a hole transport layer was formed on the hole injection layer by including N,N′-di(1-naphthyl)-N,N′-diphenyl-(1,1′-biphenyl)-4,4′-diamine (NPD) with a thickness of about 80 nm, an auxiliary emission layer was formed on the hole transport layer by including 1,3-bis(N-carbazolyl)benzene (mCP) with a thickness of about 5 nm, an emission layer including 3,3′-di(9H-carbazol-9-yl)-1,1′-biphenyl (mCBP) doped with an example compound or a comparative example compound in about 1 wt % was formed with a thickness of about 20 nm on the auxiliary emission layer, an electron transport layer was formed on the emission layer by including 2,2′,2″-(1,3,5-benzinetriyl)-tris(1-phenyl-1-H-benzimidazole) (TPBi) with a thickness of about 30 nm, an electron injection layer was formed on the electron transport layer by including LiF with a thickness of about 0.5 nm, and a second electrode was formed on the electron injection layer by including Al with a thickness of about 100 nm. Each layer was formed by a deposition method under a vacuum atmosphere.

The compounds used for the manufacturing of the light emitting elements according to the examples and comparative examples were listed below. The following materials were suitable materials, and a commercialized product was sublimated and purified to be used in the manufacturing of the elements.

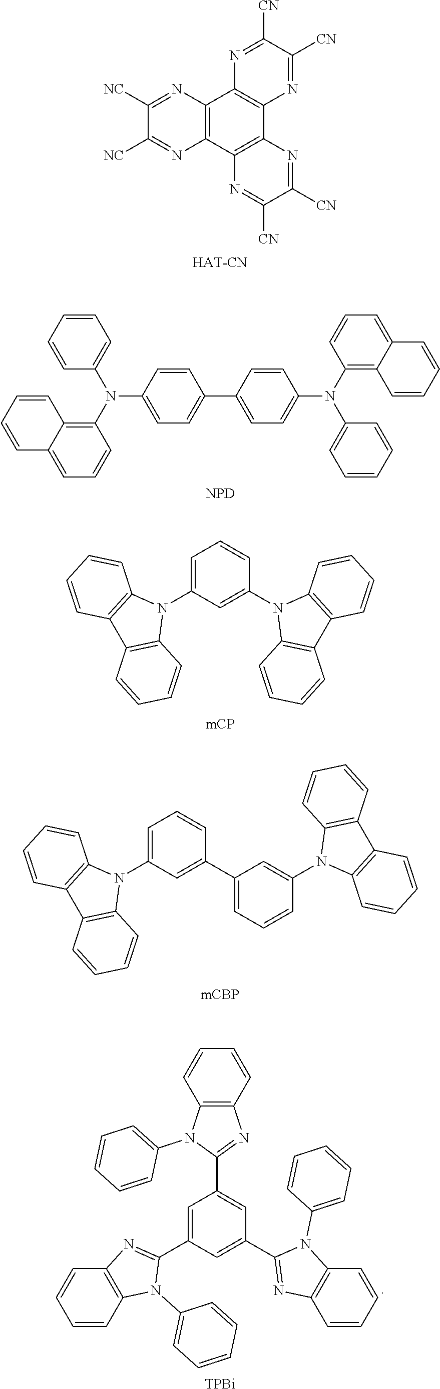

### Evaluation on Characteristics of Light Emitting Element

Evaluation results on each of the light emitting elements according to Examples 1 to 15 and Comparative Examples 1 to 9 are listed on Table 1. Values of the maximum emission wavelength (λₘₐₓ) and relative lifespan (LT50) for each of the manufactured light emitting elements were compared, and the results are listed on Table 1.

In the evaluation results on the characteristics for the examples and comparative examples listed on Table 1, the maximum emission wavelength (λₘₐₓ) indicates the maximum emission wavelength (e.g., emission peak wavelength) value in an emission spectrum of the light emitting element, and the relative lifespan indicates the time taken for the luminance to decrease by half from the initial luminance 100 cd/m². The relative lifespan is expressed relatively based on the results of Comparative Example 3.

TABLE 1

| Element | | | LT50 |
|---|---|---|---|
| manufacturing | | λmax | Relative |
| example | Dopant | (nm) | lifespan |
| Example 1 | Compound 51 | 462 | 4.1 |
| Example 2 | Compound 137 | 463 | 5.2 |
| Example 3 | Compound 138 | 463 | 6.2 |
| Example 4 | Compound 139 | 462 | 3.8 |
| Example 5 | Compound 140 | 460 | 3.0 |
| Example 6 | Compound 182 | 463 | 6.0 |
| Example 7 | Compound 183 | 463 | 6.2 |
| Example 8 | Compound 222 | 461 | 7.5 |
| Example 9 | Compound 226 | 461 | 7.3 |
| Example 10 | Compound 228 | 460 | 6.8 |
| Example 11 | Compound 240 | 463 | 7.1 |
| Example 12 | Compound 263 | 463 | 7.0 |
| Example 13 | Compound 264 | 464 | 6.5 |
| Example 14 | Compound 401 | 455 | 2.8 |
| Example 15 | Compound 543 | 460 | 3.3 |
| Comparative | Comparative Example | 457 | 0.3 |
| Example 1 | Compound X1 | | |
| Comparative | Comparative Example | 446 | 0.2 |
| Example 2 | Compound X2 | | |
| Comparative | Comparative Example | 467 | 1.0 |
| Example 3 | Compound X3 | | |
| Comparative | Comparative Example | 456 | 0.1 |
| Example 4 | Compound X4 | | |
| Comparative | Comparative Example | 457 | 0.2 |
| Example 5 | Compound X5 | | |
| Comparative | Comparative Example | 461 | 2.3 |
| Example 6 | Compound X6 | | |
| Comparative | Comparative Example | 463 | 2.0 |
| Example 7 | Compound X7 | | |
| Comparative | Comparative Example | 463 | 1.6 |
| Example 8 | Compound X8 | | |
| Comparative | Comparative Example | 465 | 1.3 |
| Example 9 | Compound X9 | | |

Referring to the results on Table 1, in each of the light emitting elements according to the Examples where the fused polycyclic compound according to an embodiment of the disclosure was used as a light-emitting material, it can be seen that the lifespan characteristics are improved, compared to those of the Comparative Examples. Because the Example compounds each include a fused cyclic core with five rings fused around a first boron atom, a first nitrogen atom, and a first hetero atom, and a first substituent connected to the first nitrogen atom of the fused cyclic core, long lifespan may be achieved. The Example compounds may exhibit excellent or suitable molecular stability due to a particular structure of the first substituent, thereby contributing to long lifespan of the light emitting element ED.

In addition, for all Examples 1 to 15, color purity close to pure blue was observed at around 460 nm in the emission wavelengths, accompanied by long lifespan compared to LT50 of Comparative Examples 1 to 9.

Referring to Table 1 for Comparative Examples 1 to 3, Comparative Example Compounds X₁ to X₃ each had a plate-like structure centered on one boron atom and two nitrogen atoms, because the first substituent, proposed by the present disclosure, was not included in their plate-like structures, it can be seen that the element lifespan values according to Comparative Examples 1 to 3, respectively including Comparative Example Compounds X₁ to X₃ as a dopant material, decreased.

Referring to Table 1 for Comparative Examples 4 and 5, Comparative Example Compounds X₄ and X₅ each had the plate-like structure centered on one boron atom and two nitrogen atoms, because the first substituent, proposed by the present disclosure, was not included their plate-like structures, it can be seen that the element lifespan values significantly decreased. For example, Comparative Example Compounds X₄ and X₅ each included a first benzene moiety and a first sub substituent of the first substituent proposed by the present disclosure, but it can be seen that a second sub substituent was not included; as a result, interaction between molecules increased due to the substituent with a small volume, thereby reducing the stability of the compound. Accordingly, it can be seen that effect of long lifespan was reduced in Comparative Examples 4 and 5 in which Comparative Example Compounds X₄ and X₅ were respectively included as a dopant material. In contrast, it can be seen that because the example compounds included the first substituent proposed by the present disclosure, effects of protecting the fused cyclic core increased, thereby reducing deterioration of the compound. Accordingly, it can be seen that the light emitting element according to one or more embodiments of the disclosure, which included an Example compound as a dopant material, achieved long lifespan.

Referring to Table 1 for Comparative Examples 6 and 7, Comparative Example Compounds X₆ and X₇ each had the plate-like structure centered on one boron atom and two nitrogen atoms, because the first substituent, proposed by the present disclosure, was not included in their plate-like structures, it can be seen that the element lifespan values significantly decreased. For example, because Comparative Example Compounds X₆ and X₇ did not include a third benzene moiety bonded to the first benzene moiety in a carbon atom at a para position among carbon atoms constituting the second benzene moiety of the first substituent proposed by the disclosure, it can be seen that material stability decreased electronically, physically, and structurally, thereby increasing deterioration of the material. Accordingly, it can be seen that effect of long lifespan was reduced in Comparative Examples 6 and 7 in which Comparative Example Compounds X₆ and X₇ were respectively included as a dopant material.

Referring to Table 1 for Comparative Examples 8 and 9, Comparative Example Compounds X₈ and X₉ each had a plate-like structure centered on one boron atom and two nitrogen atoms, but the first substituent, proposed by the present disclosure, was not included in their plate-like structures, and the second substituent proposed by the present disclosure was not included in the plate-like structure either, and as a result, it can be seen that element lifespan was reduced. For example, it can be seen that because Comparative Example Compounds X₈ and X₉ did not include the second substituent proposed by the present disclosure, but included 4 or more of heterocycle moiety such as dibenzofuran on a substituent connected to the fused cyclic core, which increases stacking between molecules and reduces the material stability. Accordingly, it can be seen that effect of long lifespan was reduced in Comparative Examples 8 and 9 in which Comparative Example Compounds X₈ and X₉ were respectively included as a dopant material.

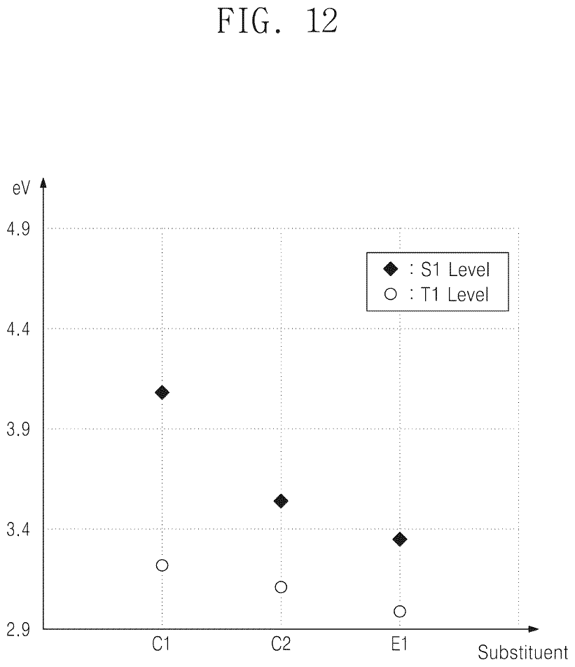

Hereinafter, referring to FIG. 12 and Table 1, the fused polycyclic compound according to one or more embodiments of the disclosure and the light emitting element according to one or more embodiments of the disclosure will be further described.

FIG. 12 is a graph showing the lowest singlet exciton energy level (S1 level) and the lowest triplet exciton energy level (T1 level) of each of the light emitting elements each including an example compound or a comparative example compound as a dopant material. FIG. 12 is a graph showing the lowest singlet exciton energy level (S₁ level) and the lowest triplet exciton energy level (T1 level) for the light emitting elements respectively including Comparative Example Compound Q1 in which Substituent C1 is connected to the first nitrogen atom of the fused cyclic core, Comparative Example Compound Q2 in which Substituent C2 is connected to the first nitrogen atom of the fused cyclic core, and Example Compound 222 in which Substituent E1 is connected to the first nitrogen atom of the fused cyclic core as a dopant material. The lowest singlet exciton energy level (S₁ level) and the lowest triplet exciton energy level (T1 level) were calculated through the DFT theory of molecular orbit, and the calculation was performed through B3LYP/6-31G (d) (TD-DFT) using a Gaussian 09 program.

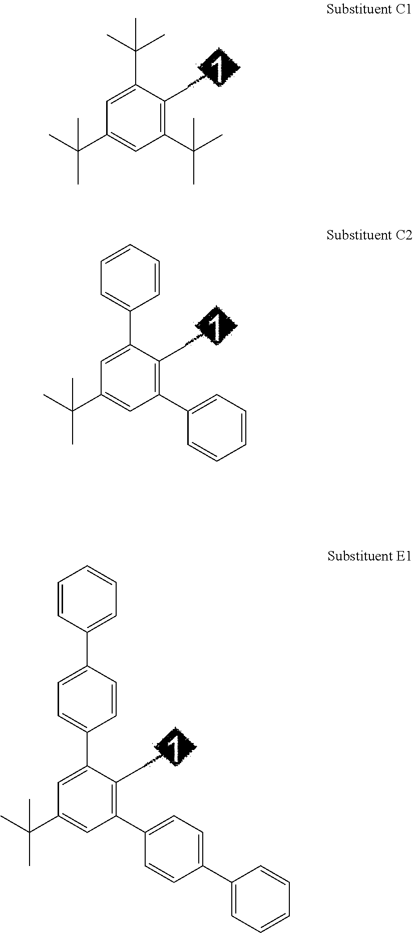

In Substituent C1, Substituent C2, and Substituent E1, [symbol] indicates a position to be connected to the first nitrogen atom of the fused cyclic core.

Referring to FIG. 12, compared to Comparative Example Compounds Q1 and Q2, Example Compound 222 had relatively satisfactory values of the lowest singlet exciton energy level and lowest triplet exciton energy level, so that material deterioration may be prevented or reduced. Compared to Substituents C1 and C2, Substituent E1 had a relatively extended conjugation structure, and therefore, it can be understood that as the conjugation structure of the substituent extends, the overall molecule containing the substituent structure stabilizes, so that the values of the lowest singlet exciton energy level and the lowest triplet exciton energy level stabilize. Accordingly, it can be understood that long lifespan may be achieved in the light emitting element including the example compound containing Substituent E1.

Referring to FIG. 12 and Table 1, in Example 8 including Example Compound 222, effect of long lifespan was evidentially exhibited, compared to Comparative Example 6 including Comparative Example Compound X₆. Comparative Example Compound 6 did not include a p-terphenyl moiety, unlike the first substituent, and thus the conjugation structure extended in a level similar to Substituent C2 not Substituent E1, and accordingly, it can be seen that the values of the lowest singlet exciton energy level and the lowest triplet exciton energy level were less favorable, thereby decreasing the effect of long lifespan. The substituent of Comparative Example Compound 6 was different from Substituent C2 in that a phenyl group was further included in the m-terphenyl moiety, but it was not involved in resonance stabilization, and it was not able to achieve effect of protecting the fused cyclic core, and therefore, it can be understood that Comparative Example Compounds Q₂ and 6 containing Substituent C2 had substantially similar effects.

In Table 2, in order to describe the effects of one or more embodiments of the present disclosure in more detail, the number of benzene rings involved in protection of the fused cyclic core and the number of benzene rings not involved in protection of the fused cyclic core are compared among the benzene rings in a first partial structure of each of Example Compound 222 and Comparative Example Compound X₆. In Table 2, the “first partial structure” may refer to all substituent structures around (e.g., surrounding) the fused cyclic core. For example, the “first partial structure” may refer to a region including the first substituent connected to a first nitrogen atom of the fused cyclic core and the second substituent bonded to a first hetero atom of the fused cyclic core when the first hetero atom corresponds to a nitrogen atom.

TABLE 2

| | Benzene ring in first partial structure | |
|---|---|---|
| | Number of | Number of |
| | benzene rings | benzene rings |
| | involved in | not involved |
| | protection of fused | in protection of |
| Compound | cyclic core | fused cyclic core |
| Example | 8 | 0 |
| Compound 222 | | |
| Comparative | 6 | 2 |
| Example | | |
| Compound X6 | | |

Referring to Table 1 and Table 2, it can be seen that Example Compound 222 had a relatively large number of benzene rings involved in the protection of the fused cyclic core, compared to Comparative Example Compound X₆, even though both of Example Compound 222 and Comparative Example Compound X₆ had 8 benzene rings in the first partial structure. It can be seen that, because Comparative Example Compound X₆ includes a phenyl group further connected to an m-terphenyl moiety, but the phenyl group further connected does not have a linearly arranged form, effect of protecting the fused cyclic core is relatively reduced. In contrast, it can be seen that because Example Compound 222 has the first substituent arranged in a form around (e.g., surrounding) the fused cyclic core, the effect of protecting the fused cyclic core is improved and material deterioration is reduced. Accordingly, it can be seen that long lifespan was achieved in the light emitting element according to one or more embodiments of the disclosure, including Example Compound 222 as a dopant material.

Use of the fused polycyclic compound according to one or more embodiments of the disclosure in the emission layer contributes to long lifespan of the light emitting element. By including the fused cyclic core centered on a boron atom, a first nitrogen atom, and a first hetero atom, and including a structure where the first substituent is substituted for the first nitrogen atom of the fused cyclic core, the fused polycyclic compound according to one or more embodiments of the disclosure may have high material stability. Therefore, when introducing the fused polycyclic compound according to one or more embodiments in the emission layer of the light emitting element, long lifespan may be achieved.

The light emitting element according to one or more embodiments may exhibit element characteristics of improved long lifespan by including the fused polycyclic compound of one or more embodiments.

The fused polycyclic compound according to one or more embodiments may be included in an emission layer of the light emitting element, thereby contributing to long lifespan of the light emitting element.

The electronic apparatus according to one or more embodiments may have excellent or suitable display quality by including the light emitting element of one or more embodiments.

In one or more embodiments, the emission layer is arranged between the first and second electrodes and includes the fused polycyclic first compound represented by Formula 1 together with one or more host and optional sensitizer systems defined herein (e.g., hole-transporting hosts such as Formula HT-1, electron-transporting hosts such as Formula ET-1, and sensitizers such as Formula D-1). At least one of Rₓ₁-Rₓ₃ in the Ar substituent (Formula 2) may be an aryl or heteroaryl substituent (e.g., Formula 3-1 to 3-4), and any hydrogen is optionally substituted with deuterium, as described, thereby providing steric protection of the BN-containing core and enhancing material stability. In device embodiments, the emission layer may include the first compound at about 0.1 wt % to about 5 wt % (e.g., about 1 wt % in the Examples) and emit delayed fluorescence (TADF) with a central emission wavelength of about 430 nm to about 490 nm and a full width at half maximum of about 10 nm to about 50 nm (e.g., about 20 nm to about 40 nm), yielding improved luminous efficiency and element lifespan relative to comparative dopants (see Examples and Table 1).

As utilized herein, the terms “substantially,” “about,” or similar terms are used as terms of approximation and not as terms of degree, and are intended to account for the inherent deviations in measured or calculated values that would be recognized by those of ordinary skill in the art. “About” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, +20%, +10%, or +5% of the stated value. Also, it should be understood that, even if the terms “about,” “approximately,” or “substantially” are not expressly recited in a given element (e.g., a claim element), the scope of such element is intended to include variations that are insubstantial or within the understanding of one of ordinary skill in the art. For example, numerical values and ranges provided herein are intended to include tolerances and measurement uncertainties that would be recognized by those skilled in the art, and the elements (e.g., claim elements) should be construed accordingly to encompass such equivalents.

In the context of the present application and unless otherwise defined, the terms “use,” “using,” and “used” may be considered synonymous with the terms “utilize,” “utilizing,” and “utilized,” respectively.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this disclosure, including the claims, to expressly recite any sub-range subsumed within the ranges expressly recited herein.

The light emitting element, the display device, the electronic device, the electronic apparatus, a device for manufacturing the same, or any other relevant apparatuses/devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random-access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

In the present disclosure, each suitable feature of the various embodiments of the disclosure may be combined or combined with each other, partially or entirely, and may be technically interlocked and operated in various suitable ways, and each embodiment may be implemented independently of each other or in conjunction with each other in any suitable manner unless otherwise stated or implied.

In the above, description has been made with reference to one or more embodiments of the disclosure, but those skilled or of ordinary skill in the art may understand that one or more suitable modifications and changes may be made to the disclosure insofar as such modifications and changes do not depart from the spirit and technical scope of the disclosure set forth in the appended claims.

Therefore, the technical scope of the disclosure is not to be limited to the contents stated in the detailed description of the disclosure, but should be determined by the appended claims and equivalents thereof.

What is claimed is:

1. A light emitting element, comprising:
a first electrode;
a second electrode on the first electrode; and
at least one functional layer between the first electrode and the second electrode, the at least one functional layer comprising a first compound represented by Formula 1: 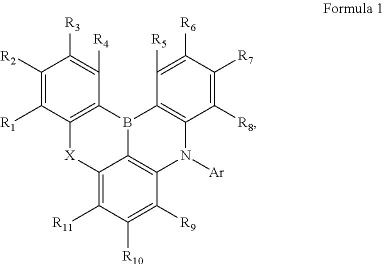
wherein, in Formula 1,
X is O, S, or NR₁₂,
R₁ to R₁₁ are each independently hydrogen, deuterium, a halogen, a cyano group, a hydroxyl group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
R₁₂ is a substituted or unsubstituted aryl group having 6 to 30 ring-forming carbon atoms or a substituted or unsubstituted heteroaryl group having 2 to 30 ring-forming carbon atoms, and when R₁₂ is a substituted or unsubstituted heteroaryl group having 2 to 30 ring-forming carbon atoms, then R₁₂ does not comprise two or more of any one selected from among a dibenzofuran moiety, a dibenzothiophene moiety, and a carbazole moiety, and
Ar is a substituent represented by Formula 2: 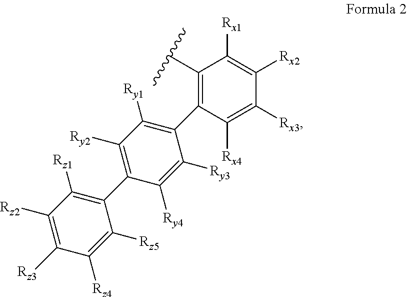
and
wherein, in Formula 2,
Rₓ₁ to Rₓ₄ are each independently hydrogen, deuterium, a halogen, a cyano group, a hydroxyl group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
at least one selected from among Rₓ₁ to Rₓ₃ is a substituted or unsubstituted aryl group having 6 to 30 ring-forming carbon atoms or a substituted or unsubstituted heteroaryl group having 2 to 30 ring-forming carbon atoms,
R_{y1} to R_{y4} and R_{z1} to R_{z5} are each independently hydrogen, deuterium, a halogen, a cyano group, a hydroxyl group, a substituted or unsubstituted oxy group, a substituted or unsubstituted thio group, a substituted or unsubstituted boron group, a substituted or unsubstituted silyl group, a substituted or unsubstituted amine group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or bonded to an adjacent group to form a ring, and 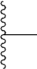
is a position to be connected to Formula 1.

2. The light emitting element of claim 1,
wherein the at least one functional layer comprises an emission layer, a hole transport region between the first electrode and the emission layer, and an electron transport region between the emission layer and the second electrode, and
the emission layer comprises the first compound.

3. The light emitting element of claim 1,
wherein Rₓ₁ to Rₓ₄ are each independently hydrogen, deuterium, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and
at least one selected from among Rₓ₁ to Rₓ₃ is a substituent represented by any one selected from among Formula 3-1 to Formula 3-4: 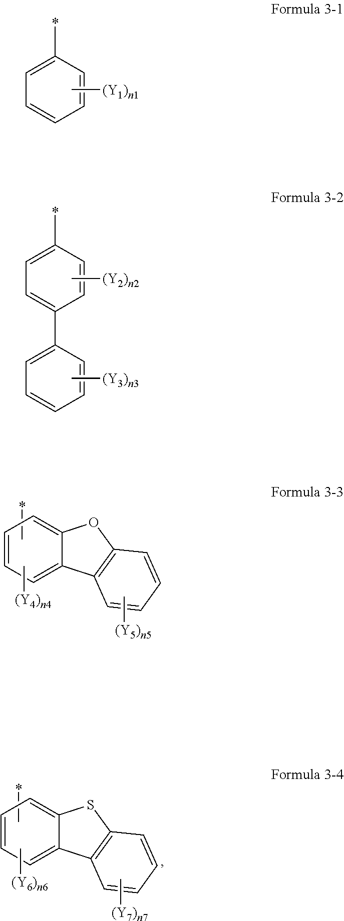
in Formula 3-1 to Formula 3-4,
Y₁ to Y₇ being each independently hydrogen, deuterium, a halogen, a cyano group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
n1 and n3 being each independently an integer of 0 or greater and 5 or less,
n2, n5, and n7 being each independently an integer of 0 or greater and 4 or less,
n4 and n6 being each independently an integer of 0 or greater and 3 or less, and [symbol]
being a position to be connected to Formula 2.

4. The light emitting element of claim 3,
wherein any one selected from among Rₓ₁ to Rₓ₃ is a substituent represented by any one selected from among Formula 3-1 to Formula 3-4, and
the rest of Rₓ₁ to Rₓ₃ are each hydrogen, deuterium, or an unsubstituted t-butyl group.

5. The light emitting element of claim 1, wherein the substituent represented by Formula 2 is represented by any one selected from among Formula 2-1 to Formula 2-3: 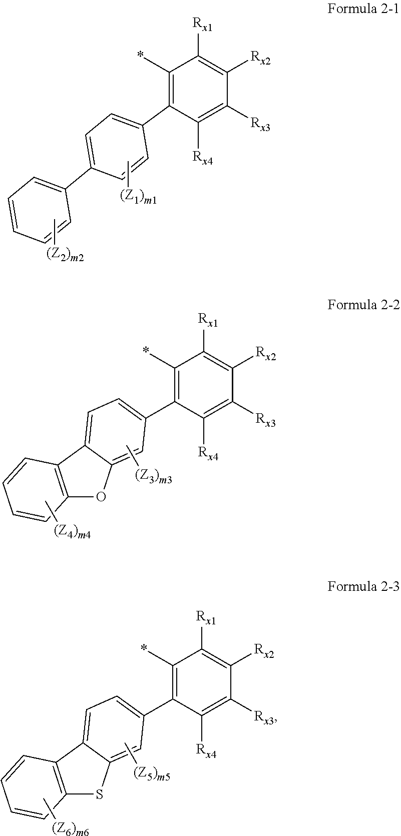
in Formula 2-1 to Formula 2-3, Z₁ to Z₆ being each independently hydrogen, deuterium, a halogen, a cyano group, or a substituted or unsubstituted alkyl group having 1 to 10 carbon atoms,
m1, m4, and m6 being each independently an integer of 0 or greater and 4 or less,
m2 being an integer of 0 or greater and 5 or less,
m3 and m5 being each independently an integer of 0 or greater and 3 or less, and
Rₓ₁ to Rₓ₄ being each the same as defined in Formula 2.

6. The light emitting element of claim 1, wherein the substituent represented by Formula 2 is represented by any one selected from among Formula 2-4 to Formula 2-17: 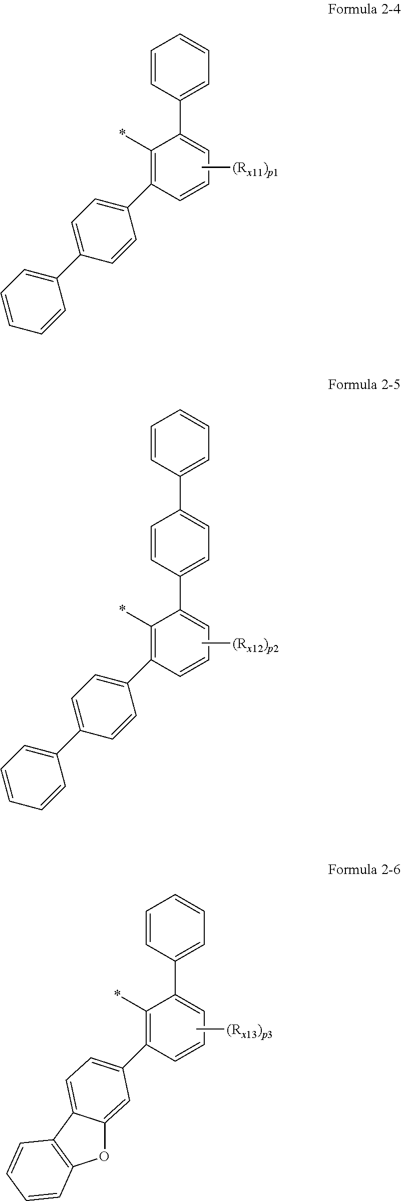 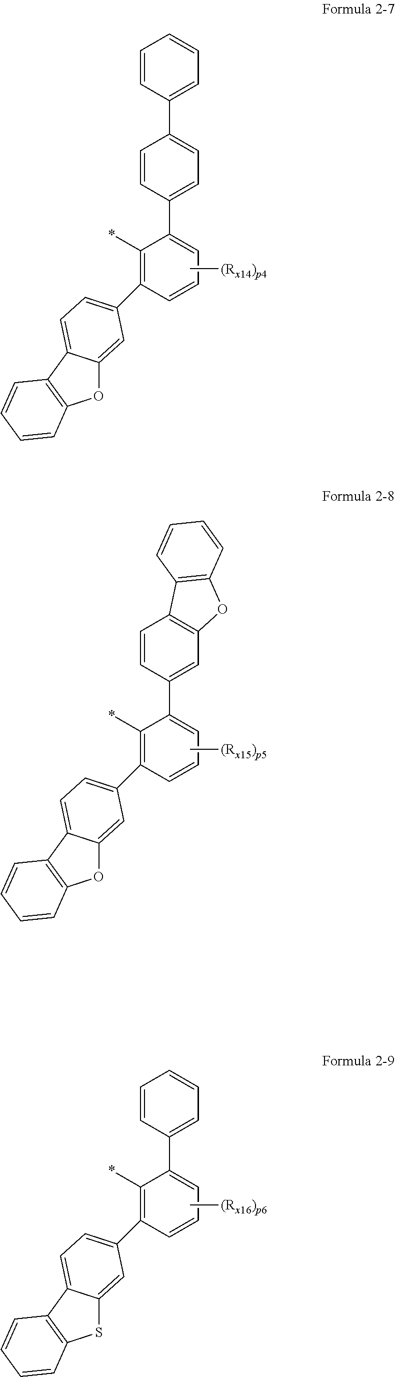 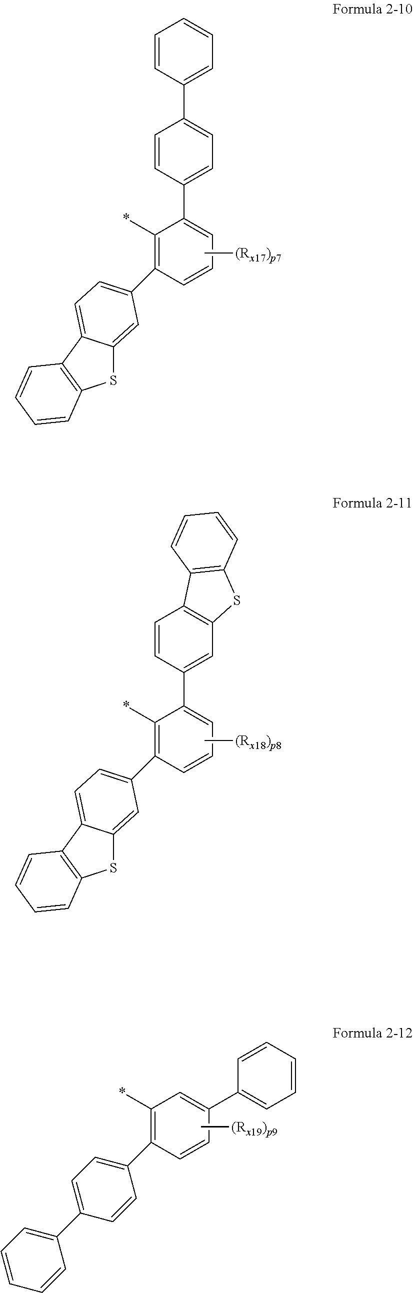 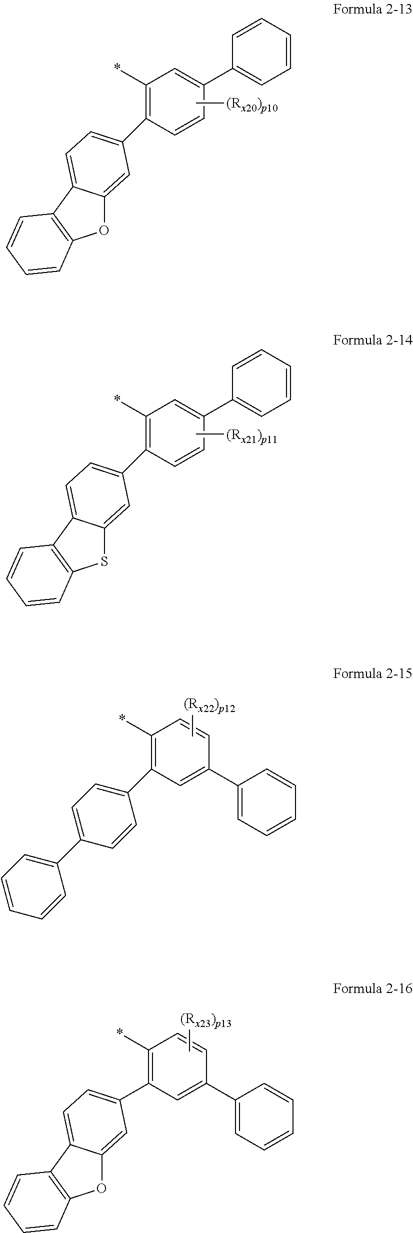 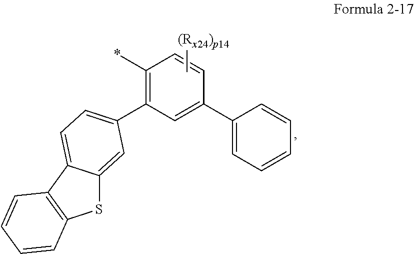
in Formula 2-4 to Formula 2-17,
Rₓ₁₁ to Rₓ₂₄ being each independently hydrogen, deuterium, an unsubstituted t-butyl group, or an unsubstituted phenyl group,
p1 to p14 being each independently an integer of 0 or greater and 3 or less, and [symbol]
being a position to be connected to Formula 1.

7. The light emitting element of claim 1, wherein the first compound represented by Formula 1 is represented by any one selected from among Formula 1-1 to Formula 1-6: 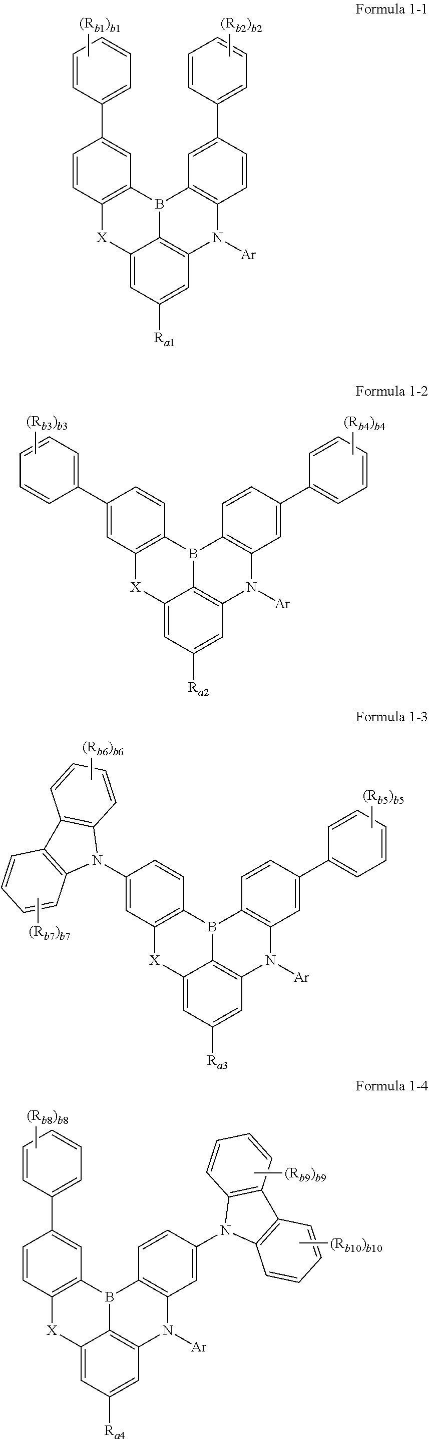 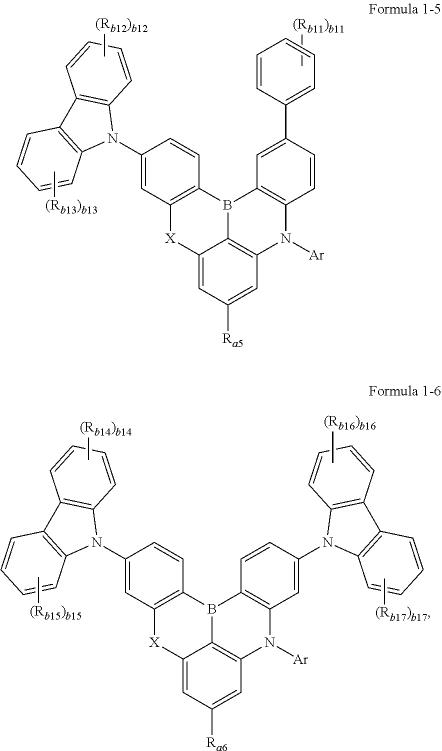
in Formula 1-1 to Formula 1-6,
Rₐ₁ to Rₐ₆ being each independently hydrogen, deuterium, a substituted or unsubstituted t-butyl group, or a substituted or unsubstituted aryl group having 6 to 30 ring-forming carbon atoms,
R_{b1} to R_{b17} being each independently hydrogen, deuterium, a cyano group, a substituted or unsubstituted t-butyl group, a substituted or unsubstituted aryl group having 6 to 30 ring-forming carbon atoms, or a substituted or unsubstituted heteroaryl group having 2 to 30 ring-forming carbon atoms,
b1 to b5, b8, and b11 being each independently an integer of 0 or greater and 5 or less,
b6, b7, b9, b10, and b12 to b17 being each independently an integer of 0 or greater and 4 or less,
X and Ar being each the same as defined in Formula 1, and
Formula 1-1 to Formula 1-6 comprising a structure in which any hydrogen being optionally substituted with deuterium.

8. The light emitting element of claim 1, wherein the first compound represented by Formula 1 is represented by Formula 1-7: 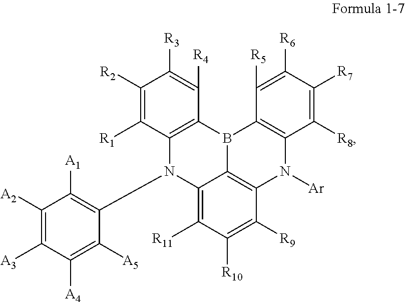
and
wherein, A₁ to A₅ are each independently hydrogen, deuterium, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
a case where two or more selected from among A₁ to A₅ are each independently a substituted or unsubstituted dibenzofuran group, a substituted or unsubstituted dibenzothiophene group, or a substituted or unsubstituted carbazole group is excluded, and
Ar and R₁ to R₁₁ are each the same as defined in Formula 1.

9. The light emitting element of claim 1, wherein the first compound represented by Formula 1 is represented by any one selected from among Formula 1-8 to Formula 1-16: 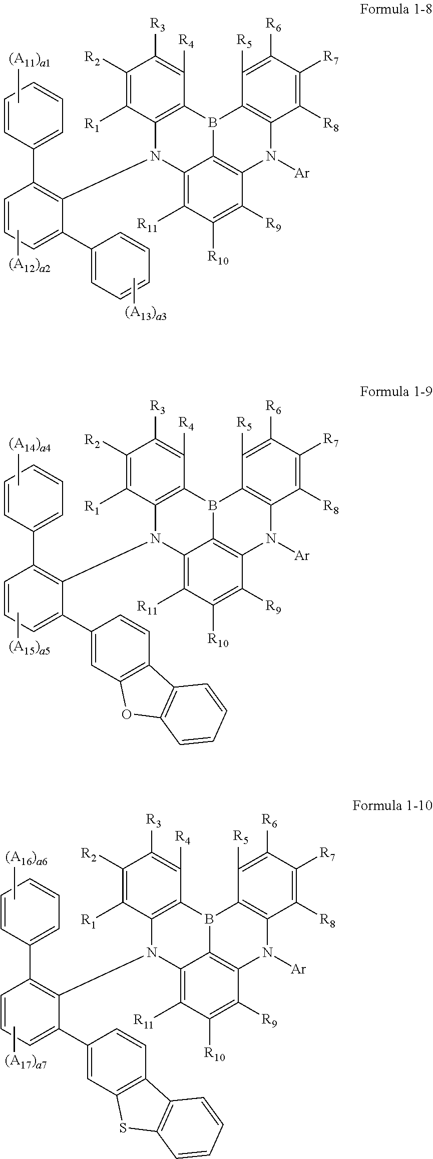 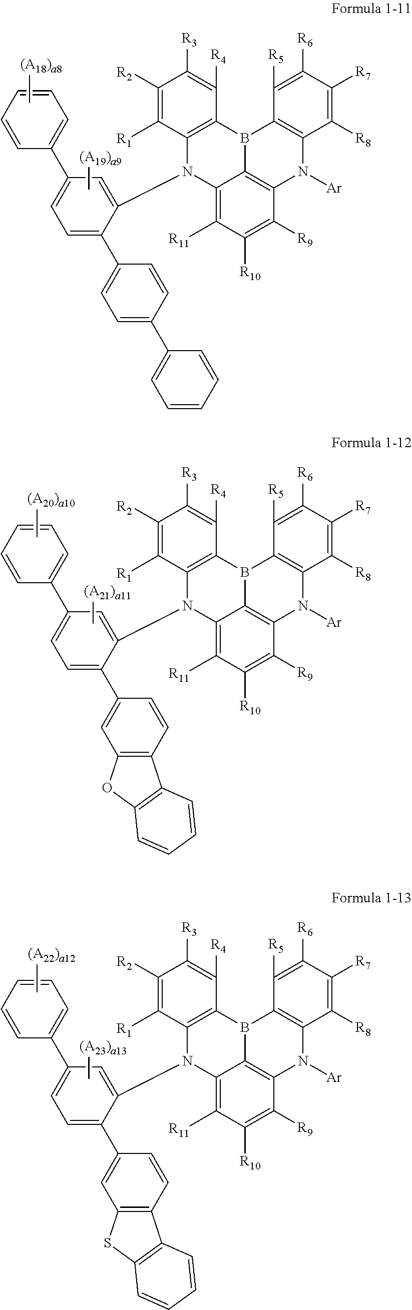 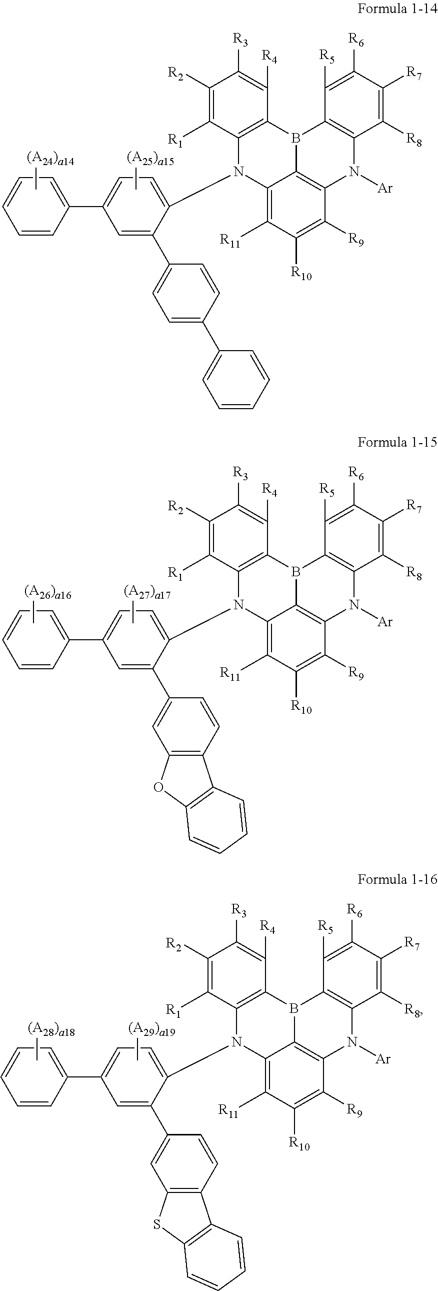
in Formula 1-8 to Formula 1-16,
A₁₁, A₁₃, A₁₄, A₁₆, A₁₈, A₂₀, A₂₂, A₂₄, A₂₆, and A₂₈ being each independently hydrogen, deuterium, or a substituted or unsubstituted aryl group having 6 to 30 ring-forming carbon atoms,
A₁₂, A₁₅, A₁₇, A₁₉, A₂₁, A₂₃, A₂₅, A₂₇, and A₂₉ being each independently hydrogen, deuterium, or a substituted or unsubstituted alkyl group having 1 to 20 carbon atoms, or a substituted or unsubstituted aryl group having 6 to 30 ring-forming carbon atoms,
a1, a3, a4, a6, a8, a10, a12, a14, a16, and a18 being each independently an integer of 0 or greater and 5 or less,
a2, a5, a7, a9, a11, a13, a15, a17, and a19 being each independently an integer of 0 or greater and 3 or less, and
Ar and R₁ to R₁₁ being each the same as defined in Formula 1.

10. The light emitting element of claim 1, wherein the first compound represented by Formula 1 comprises at least one selected from among compounds in Compound Group 1: 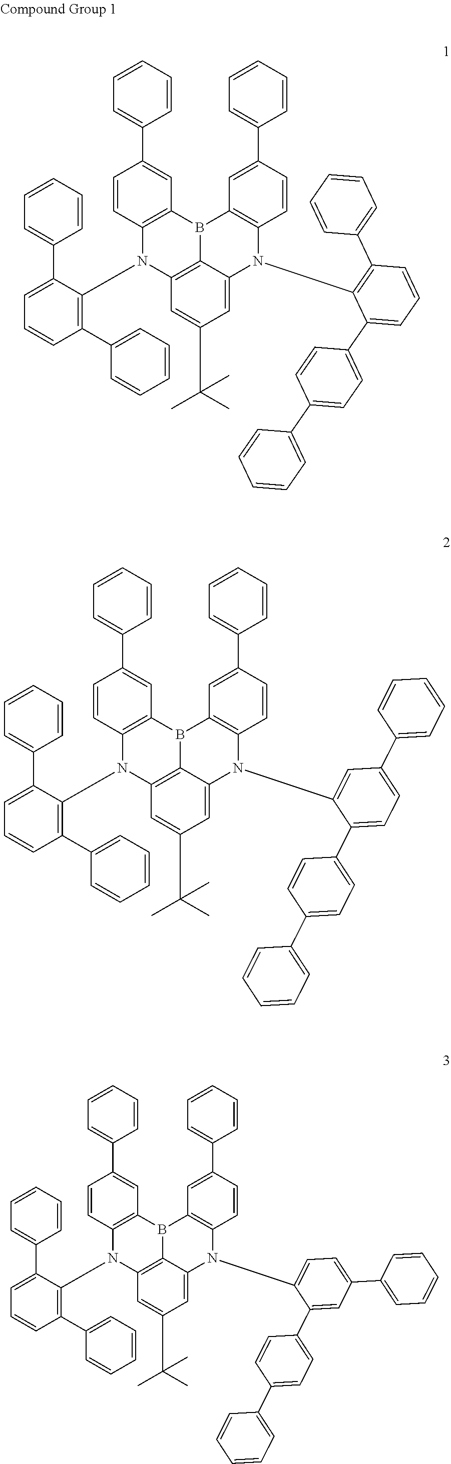 [SMILES: CC(C)(C)c1cc2c3c(c1)N(c1c(-c4ccccc4)cccc1-c1ccc(-c4ccccc4)cc1)c1ccc(-c4ccccc4)cc1B3c1cc(-c3ccccc3)ccc1N2c1c(-c2ccccc2)cccc1-c1ccccc1 ; CC(C)(C)c1cc2c3c(c1)N(c1c(-c4ccccc4)cccc1-c1ccccc1)c1ccc(-c4ccccc4)cc1B3c1cc(-c3ccccc3)ccc1N2c1cc(-c2ccccc2)ccc1-c1ccc(-c2ccccc2)cc1 ; CC(C)(C)c1cc2c3c(c1)N(c1c(-c4ccccc4)cccc1-c1ccccc1)c1ccc(-c4ccccc4)cc1B3c1cc(-c3ccccc3)ccc1N2c1ccc(-c2ccccc2)cc1-c1ccc(-c2ccccc2)cc1] 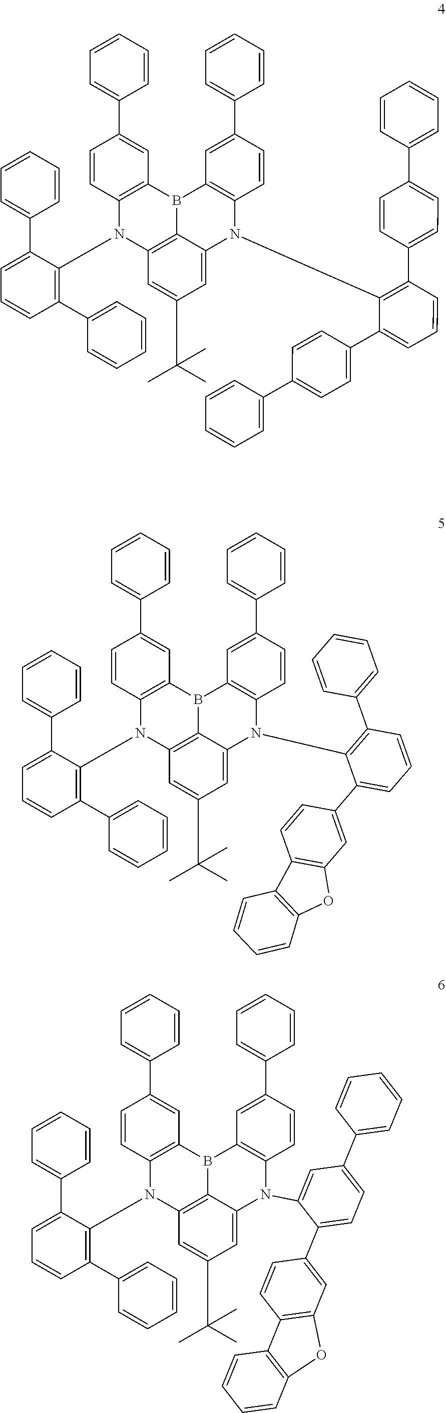 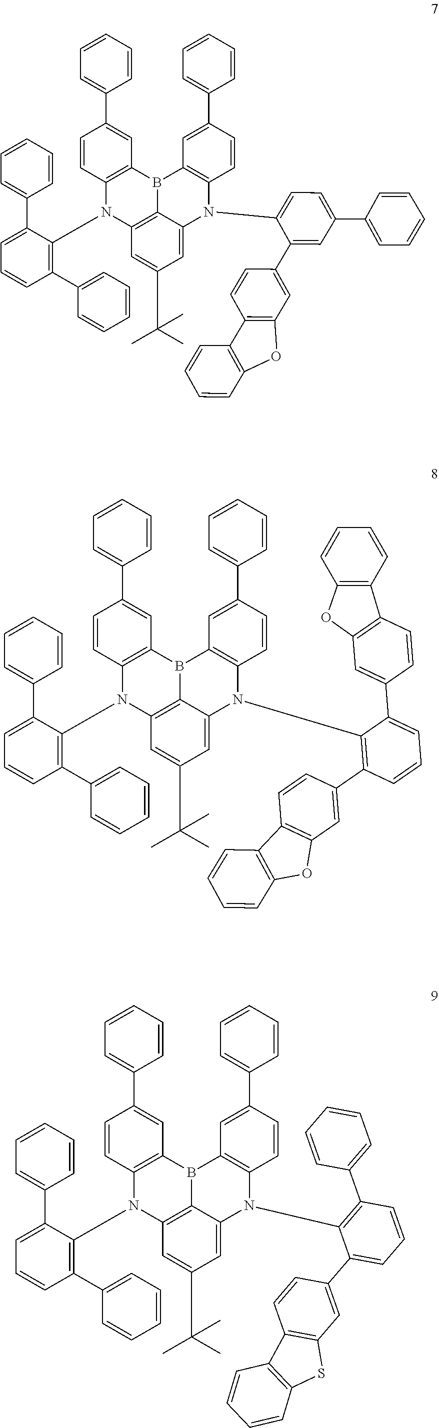 [SMILES: CC(C)(C)c1cc2c3c(c1)N(c1c(-c4ccccc4)cccc1-c1ccccc1)c1ccc(-c4ccccc4)cc1B3c1cc(-c3ccccc3)ccc1N2c1ccc(-c2ccccc2)cc1-c1ccc2c(c1)oc1ccccc12 ; CC(C)(C)c1cc2c3c(c1)N(c1c(-c4ccc5c(c4)oc4ccccc45)cccc1-c1ccc4c(c1)oc1ccccc14)c1ccc(-c4ccccc4)cc1B3c1cc(-c3ccccc3)ccc1N2c1c(-c2ccccc2)cccc1-c1ccccc1 ; CC(C)(C)c1cc2c3c(c1)N(c1c(-c4ccccc4)cccc1-c1ccc4c(c1)sc1ccccc14)c1ccc(-c4ccccc4)cc1B3c1cc(-c3ccccc3)ccc1N2c1c(-c2ccccc2)cccc1-c1ccccc1] 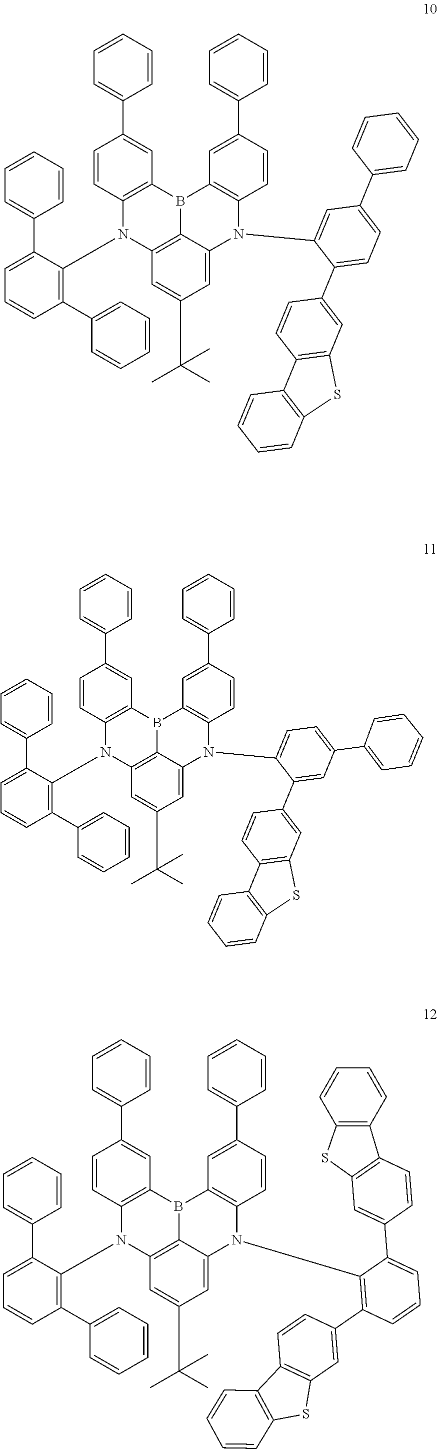 [SMILES: CC(C)(C)c1cc2c3c(c1)N(c1c(-c4ccccc4)cccc1-c1ccccc1)c1ccc(-c4ccccc4)cc1B3c1cc(-c3ccccc3)ccc1N2c1cc(-c2ccccc2)ccc1-c1ccc2c(c1)sc1ccccc12 ; CC(C)(C)c1cc2c3c(c1)N(c1c(-c4ccccc4)cccc1-c1ccccc1)c1ccc(-c4ccccc4)cc1B3c1cc(-c3ccccc3)ccc1N2c1ccc(-c2ccccc2)cc1-c1ccc2c(c1)sc1ccccc12 ; CC(C)(C)c1cc2c3c(c1)N(c1c(-c4ccc5c(c4)sc4ccccc45)cccc1-c1ccc4c(c1)sc1ccccc14)c1ccc(-c4ccccc4)cc1B3c1cc(-c3ccccc3)ccc1N2c1c(-c2ccccc2)cccc1-c1ccccc1] 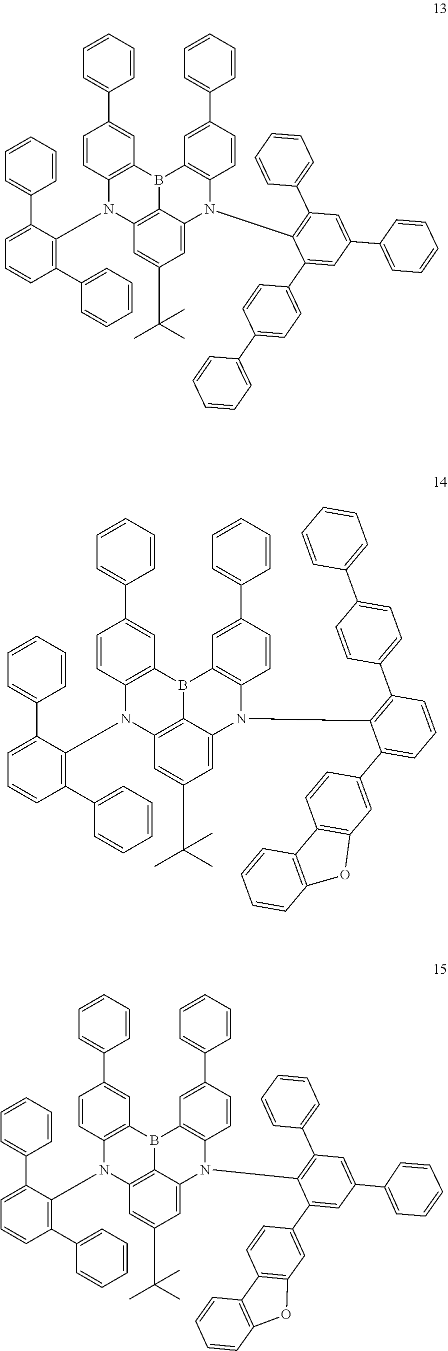 [SMILES: CC(C)(C)c1cc2c3c(c1)N(c1c(-c4ccccc4)cc(-c4ccccc4)cc1-c1ccc(-c4ccccc4)cc1)c1ccc(-c4ccccc4)cc1B3c1cc(-c3ccccc3)ccc1N2c1c(-c2ccccc2)cccc1-c1ccccc1 ; CC(C)(C)c1cc2c3c(c1)N(c1c(-c4ccc(-c5ccccc5)cc4)cccc1-c1ccc4c(c1)oc1ccccc14)c1ccc(-c4ccccc4)cc1B3c1cc(-c3ccccc3)ccc1N2c1c(-c2ccccc2)cccc1-c1ccccc1 ; CC(C)(C)c1cc2c3c(c1)N(c1c(-c4ccccc4)cc(-c4ccccc4)cc1-c1ccc4c(c1)oc1ccccc14)c1ccc(-c4ccccc4)cc1B3c1cc(-c3ccccc3)ccc1N2c1c(-c2ccccc2)cccc1-c1ccccc1] 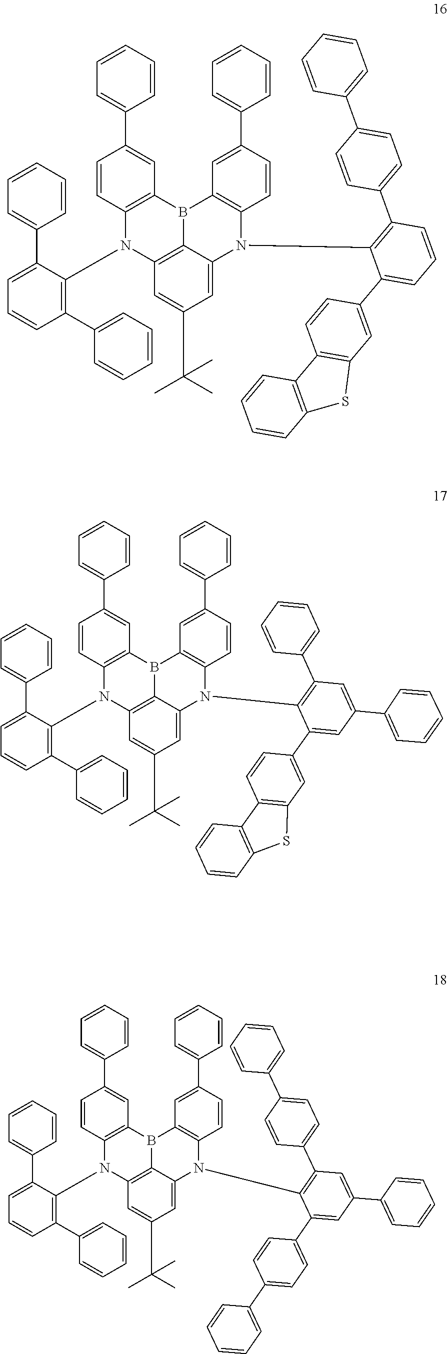 [SMILES: CC(C)(C)c1cc2c3c(c1)N(c1c(-c4ccc(-c5ccccc5)cc4)cccc1-c1ccc4c(c1)sc1ccccc14)c1ccc(-c4ccccc4)cc1B3c1cc(-c3ccccc3)ccc1N2c1c(-c2ccccc2)cccc1-c1ccccc1 ; CC(C)(C)c1cc2c3c(c1)N(c1c(-c4ccccc4)cc(-c4ccccc4)cc1-c1ccc4c(c1)sc1ccccc14)c1ccc(-c4ccccc4)cc1B3c1cc(-c3ccccc3)ccc1N2c1c(-c2ccccc2)cccc1-c1ccccc1 ; CC(C)(C)c1cc2c3c(c1)N(c1c(-c4ccc(-c5ccccc5)cc4)cc(-c4ccccc4)cc1-c1ccc(-c4ccccc4)cc1)c1ccc(-c4ccccc4)cc1B3c1cc(-c3ccccc3)ccc1N2c1c(-c2ccccc2)cccc1-c1ccccc1] 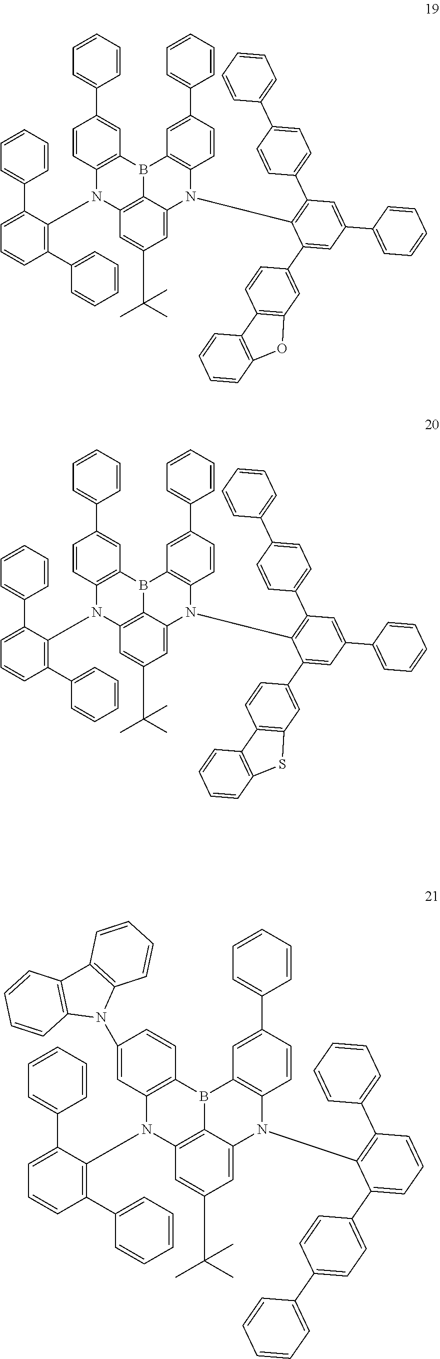 [SMILES: CC(C)(C)c1cc2c3c(c1)N(c1c(-c4ccc(-c5ccccc5)cc4)cc(-c4ccccc4)cc1-c1ccc4c(c1)oc1ccccc14)c1ccc(-c4ccccc4)cc1B3c1cc(-c3ccccc3)ccc1N2c1c(-c2ccccc2)cccc1-c1ccccc1 ; CC(C)(C)c1cc2c3c(c1)N(c1c(-c4ccc(-c5ccccc5)cc4)cc(-c4ccccc4)cc1-c1ccc4c(c1)sc1ccccc14)c1ccc(-c4ccccc4)cc1B3c1cc(-c3ccccc3)ccc1N2c1c(-c2ccccc2)cccc1-c1ccccc1 ; CC(C)(C)c1cc2c3c(c1)N(c1c(-c4ccccc4)cccc1-c1ccccc1)c1cc(-n4c5ccccc5c5ccccc54)ccc1B3c1cc(-c3ccccc3)ccc1N2c1c(-c2ccccc2)cccc1-c1ccc(-c2ccccc2)cc1] 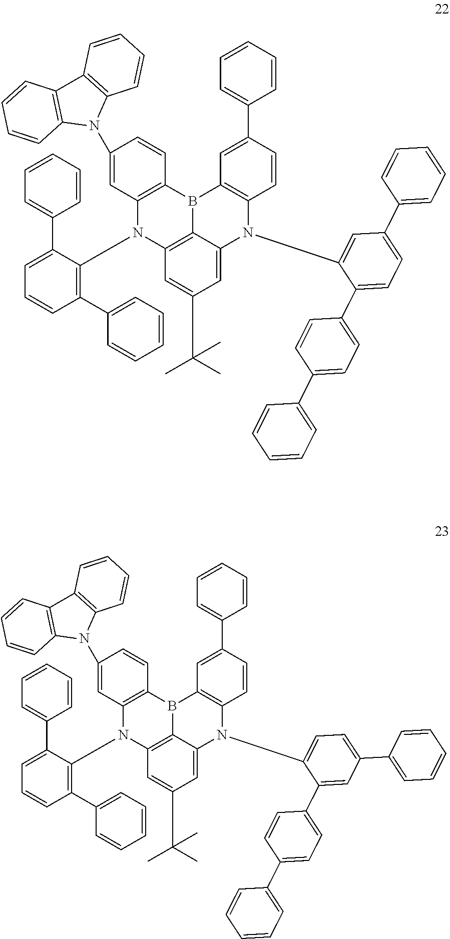 [SMILES: CC(C)(C)c1cc2c3c(c1)N(c1c(-c4ccccc4)cccc1-c1ccccc1)c1cc(-n4c5ccccc5c5ccccc54)ccc1B3c1cc(-c3ccccc3)ccc1N2c1cc(-c2ccccc2)ccc1-c1ccc(-c2ccccc2)cc1 ; CC(C)(C)c1cc2c3c(c1)N(c1c(-c4ccccc4)cccc1-c1ccccc1)c1cc(-n4c5ccccc5c5ccccc54)ccc1B3c1cc(-c3ccccc3)ccc1N2c1ccc(-c2ccccc2)cc1-c1ccc(-c2ccccc2)cc1] 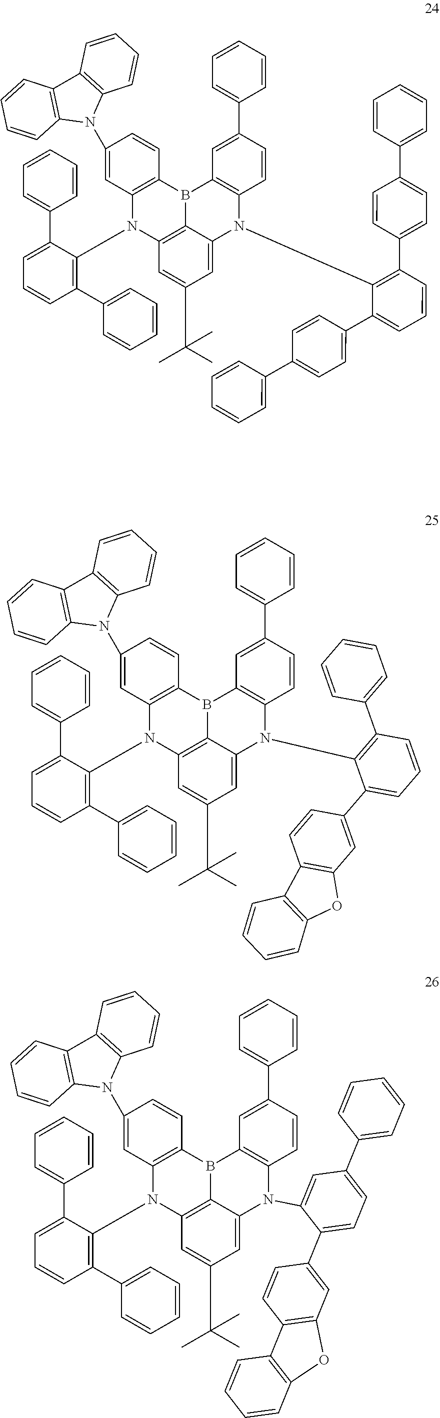 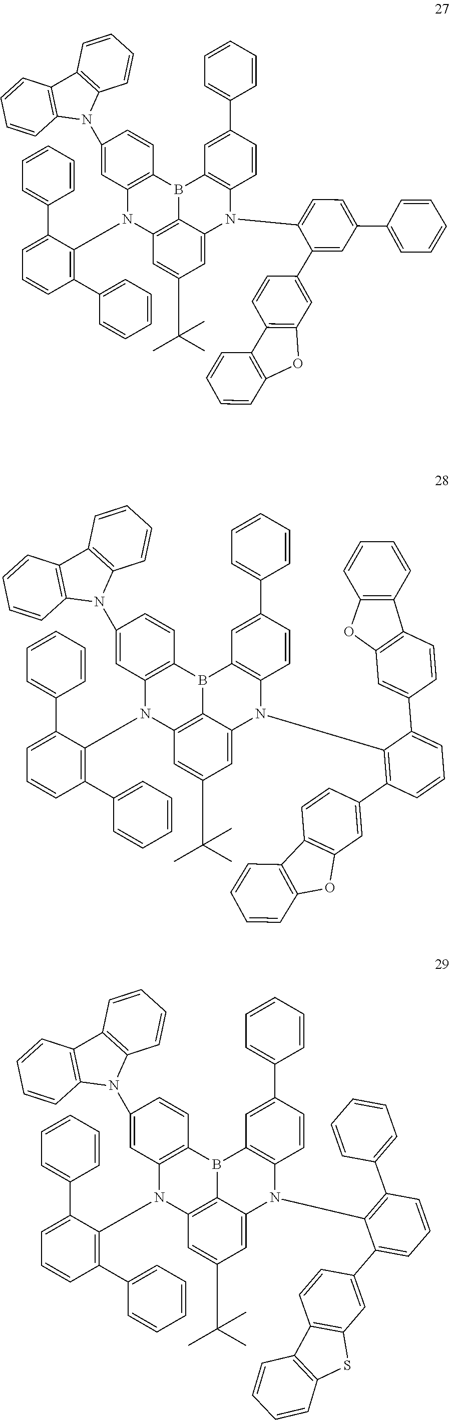 [SMILES: CC(C)(C)c1cc2c3c(c1)N(c1c(-c4ccccc4)cccc1-c1ccccc1)c1cc(-n4c5ccccc5c5ccccc54)ccc1B3c1cc(-c3ccccc3)ccc1N2c1ccc(-c2ccccc2)cc1-c1ccc2c(c1)oc1ccccc12 ; CC(C)(C)c1cc2c3c(c1)N(c1c(-c4ccccc4)cccc1-c1ccccc1)c1cc(-n4c5ccccc5c5ccccc54)ccc1B3c1cc(-c3ccccc3)ccc1N2c1c(-c2ccc3c(c2)oc2ccccc23)cccc1-c1ccc2c(c1)oc1ccccc12 ; CC(C)(C)c1cc2c3c(c1)N(c1c(-c4ccccc4)cccc1-c1ccccc1)c1cc(-n4c5ccccc5c5ccccc54)ccc1B3c1cc(-c3ccccc3)ccc1N2c1c(-c2ccccc2)cccc1-c1ccc2c(c1)sc1ccccc12] 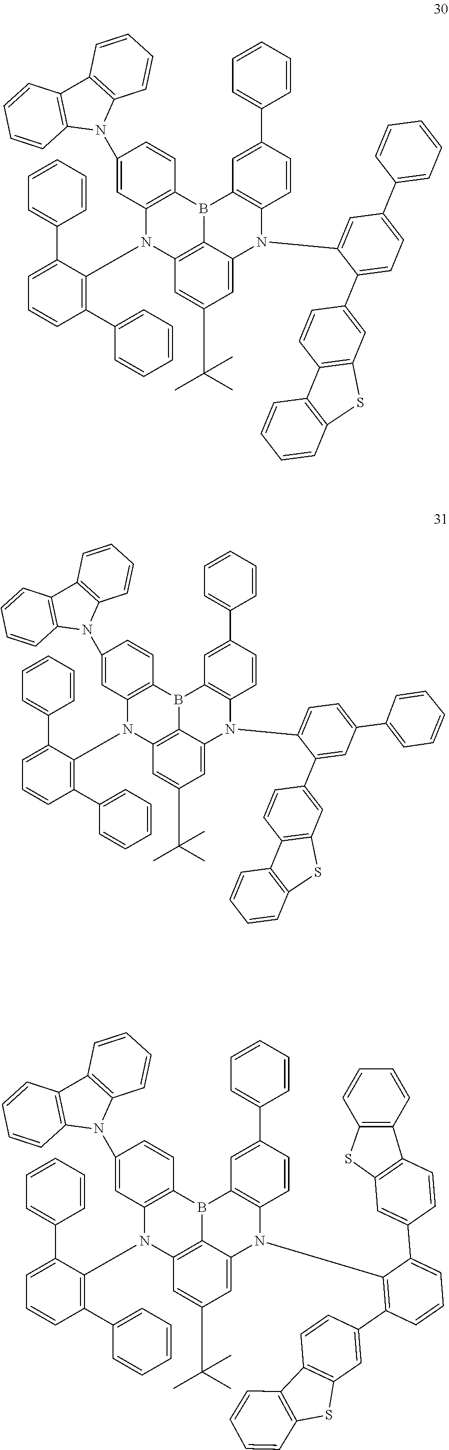 [SMILES: CC(C)(C)c1cc2c3c(c1)N(c1c(-c4ccccc4)cccc1-c1ccccc1)c1cc(-n4c5ccccc5c5ccccc54)ccc1B3c1cc(-c3ccccc3)ccc1N2c1cc(-c2ccccc2)ccc1-c1ccc2c(c1)sc1ccccc12 ; CC(C)(C)c1cc2c3c(c1)N(c1c(-c4ccccc4)cccc1-c1ccccc1)c1cc(-n4c5ccccc5c5ccccc54)ccc1B3c1cc(-c3ccccc3)ccc1N2c1ccc(-c2ccccc2)cc1-c1ccc2c(c1)sc1ccccc12 ; CC(C)(C)c1cc2c3c(c1)N(c1c(-c4ccccc4)cccc1-c1ccccc1)c1cc(-n4c5ccccc5c5ccccc54)ccc1B3c1cc(-c3ccccc3)ccc1N2c1c(-c2ccc3c(c2)sc2ccccc23)cccc1-c1ccc2c(c1)sc1ccccc12] 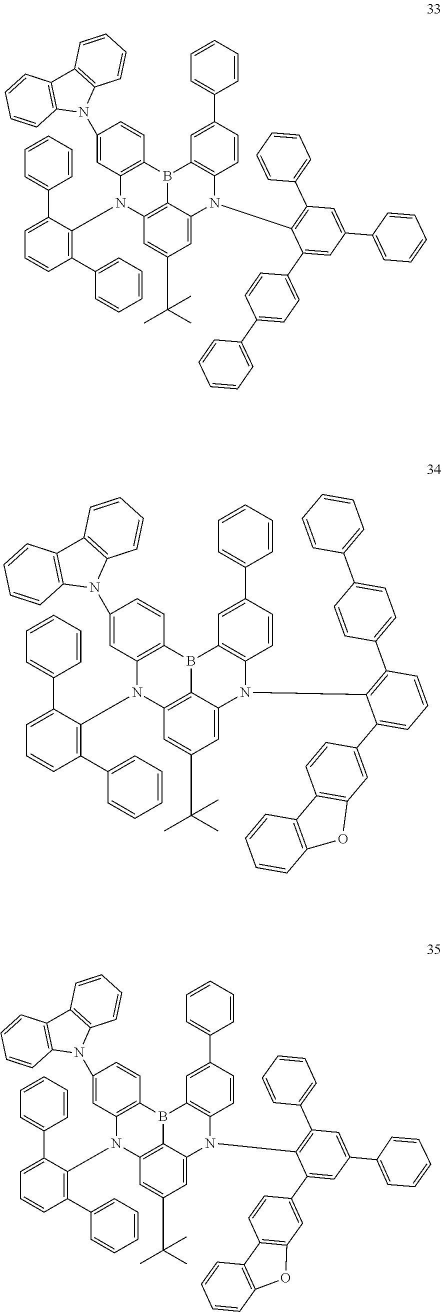 [SMILES: CC(C)(C)c1cc2c3c(c1)N(c1c(-c4ccccc4)cccc1-c1ccccc1)c1cc(-n4c5ccccc5c5ccccc54)ccc1B3c1cc(-c3ccccc3)ccc1N2c1c(-c2ccccc2)cc(-c2ccccc2)cc1-c1ccc(-c2ccccc2)cc1 ; CC(C)(C)c1cc2c3c(c1)N(c1c(-c4ccccc4)cccc1-c1ccccc1)c1cc(-n4c5ccccc5c5ccccc54)ccc1B3c1cc(-c3ccccc3)ccc1N2c1c(-c2ccc(-c3ccccc3)cc2)cccc1-c1ccc2c(c1)oc1ccccc12 ; CC(C)(C)c1cc2c3c(c1)N(c1c(-c4ccccc4)cccc1-c1ccccc1)c1cc(-n4c5ccccc5c5ccccc54)ccc1B3c1cc(-c3ccccc3)ccc1N2c1c(-c2ccccc2)cc(-c2ccccc2)cc1-c1ccc2c(c1)oc1ccccc12] 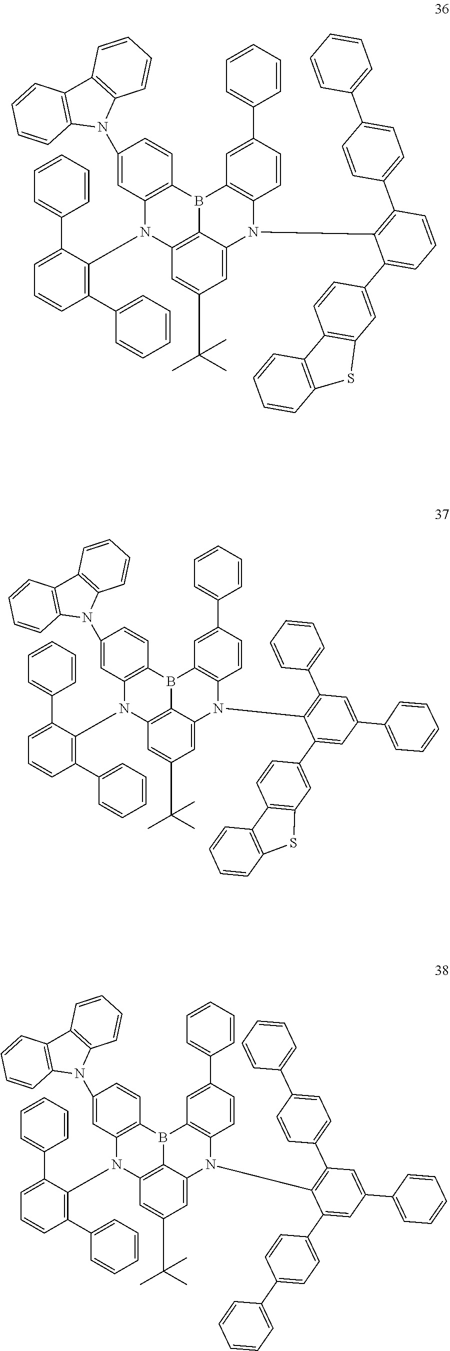 [SMILES: CC(C)(C)c1cc2c3c(c1)N(c1c(-c4ccccc4)cccc1-c1ccccc1)c1cc(-n4c5ccccc5c5ccccc54)ccc1B3c1cc(-c3ccccc3)ccc1N2c1c(-c2ccc(-c3ccccc3)cc2)cccc1-c1ccc2c(c1)sc1ccccc12 ; CC(C)(C)c1cc2c3c(c1)N(c1c(-c4ccccc4)cccc1-c1ccccc1)c1cc(-n4c5ccccc5c5ccccc54)ccc1B3c1cc(-c3ccccc3)ccc1N2c1c(-c2ccccc2)cc(-c2ccccc2)cc1-c1ccc2c(c1)sc1ccccc12 ; CC(C)(C)c1cc2c3c(c1)N(c1c(-c4ccccc4)cccc1-c1ccccc1)c1cc(-n4c5ccccc5c5ccccc54)ccc1B3c1cc(-c3ccccc3)ccc1N2c1c(-c2ccc(-c3ccccc3)cc2)cc(-c2ccccc2)cc1-c1ccc(-c2ccccc2)cc1] 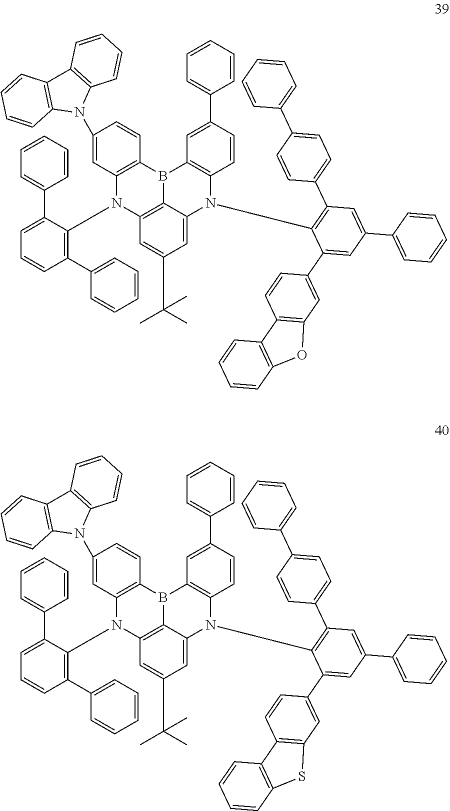 [SMILES: CC(C)(C)c1cc2c3c(c1)N(c1c(-c4ccccc4)cccc1-c1ccccc1)c1cc(-n4c5ccccc5c5ccccc54)ccc1B3c1cc(-c3ccccc3)ccc1N2c1c(-c2ccc(-c3ccccc3)cc2)cc(-c2ccccc2)cc1-c1ccc2c(c1)oc1ccccc12 ; CC(C)(C)c1cc2c3c(c1)N(c1c(-c4ccccc4)cccc1-c1ccccc1)c1cc(-n4c5ccccc5c5ccccc54)ccc1B3c1cc(-c3ccccc3)ccc1N2c1c(-c2ccc(-c3ccccc3)cc2)cc(-c2ccccc2)cc1-c1ccc2c(c1)sc1ccccc12] 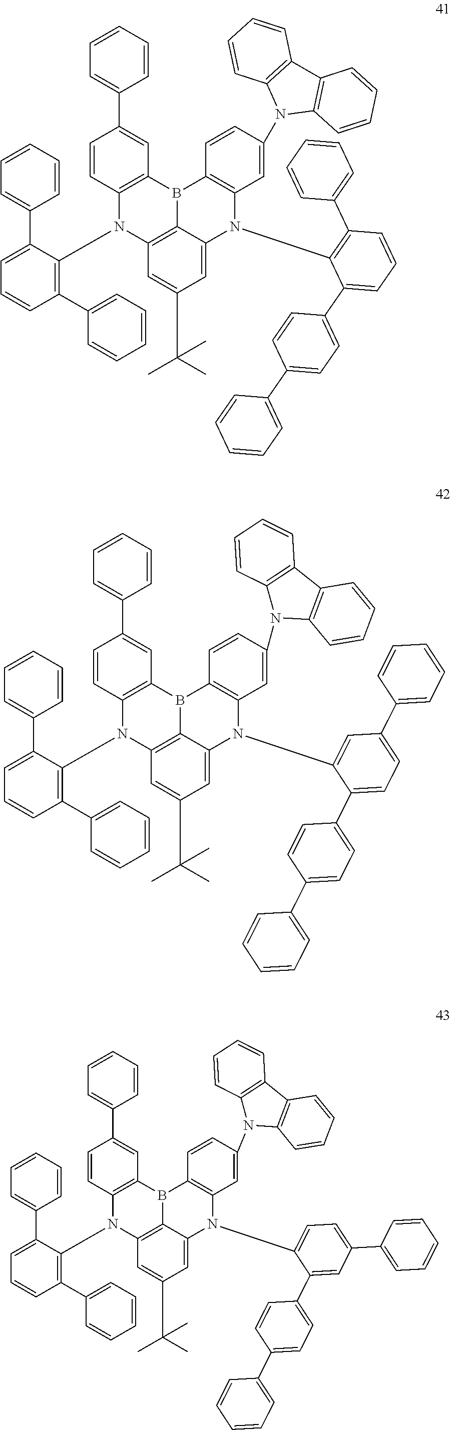 [SMILES: CC(C)(C)c1cc2c3c(c1)N(c1c(-c4ccccc4)cccc1-c1ccc(-c4ccccc4)cc1)c1cc(-n4c5ccccc5c5ccccc54)ccc1B3c1cc(-c3ccccc3)ccc1N2c1c(-c2ccccc2)cccc1-c1ccccc1 ; CC(C)(C)c1cc2c3c(c1)N(c1c(-c4ccccc4)cccc1-c1ccccc1)c1ccc(-c4ccccc4)cc1B3c1ccc(-n3c4ccccc4c4ccccc43)cc1N2c1cc(-c2ccccc2)ccc1-c1ccc(-c2ccccc2)cc1 ; CC(C)(C)c1cc2c3c(c1)N(c1c(-c4ccccc4)cccc1-c1ccccc1)c1ccc(-c4ccccc4)cc1B3c1ccc(-n3c4ccccc4c4ccccc43)cc1N2c1ccc(-c2ccccc2)cc1-c1ccc(-c2ccccc2)cc1] 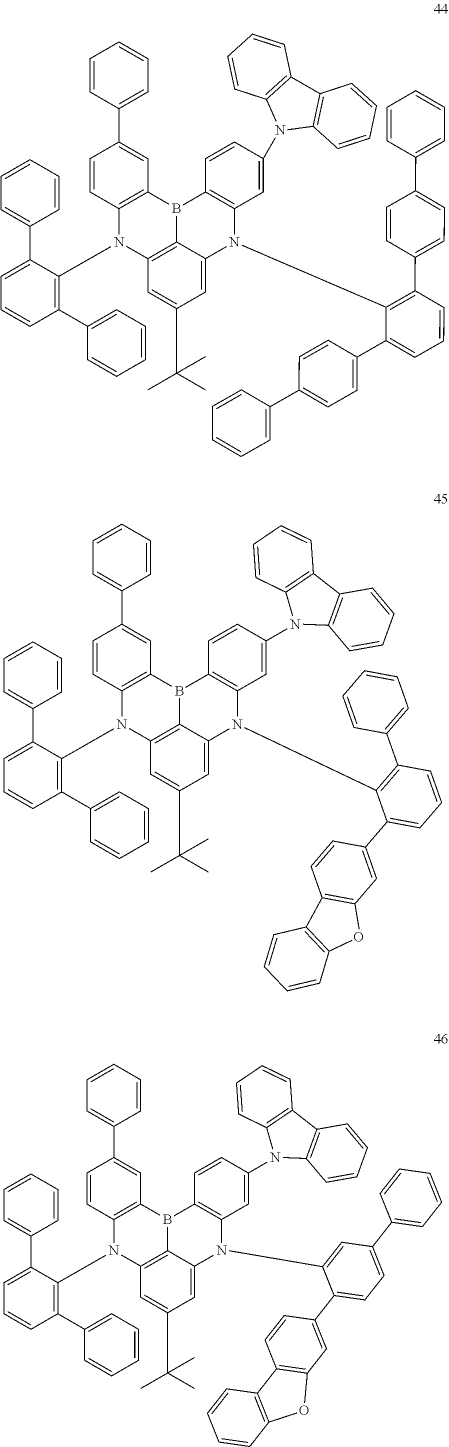 [SMILES: CC(C)(C)c1cc2c3c(c1)N(c1c(-c4ccc(-c5ccccc5)cc4)cccc1-c1ccc(-c4ccccc4)cc1)c1cc(-n4c5ccccc5c5ccccc54)ccc1B3c1cc(-c3ccccc3)ccc1N2c1c(-c2ccccc2)cccc1-c1ccccc1 ; CC(C)(C)c1cc2c3c(c1)N(c1c(-c4ccccc4)cccc1-c1ccc4c(c1)oc1ccccc14)c1cc(-n4c5ccccc5c5ccccc54)ccc1B3c1cc(-c3ccccc3)ccc1N2c1c(-c2ccccc2)cccc1-c1ccccc1 ; CC(C)(C)c1cc2c3c(c1)N(c1c(-c4ccccc4)cccc1-c1ccccc1)c1ccc(-c4ccccc4)cc1B3c1ccc(-n3c4ccccc4c4ccccc43)cc1N2c1cc(-c2ccccc2)ccc1-c1ccc2c(c1)oc1ccccc12] 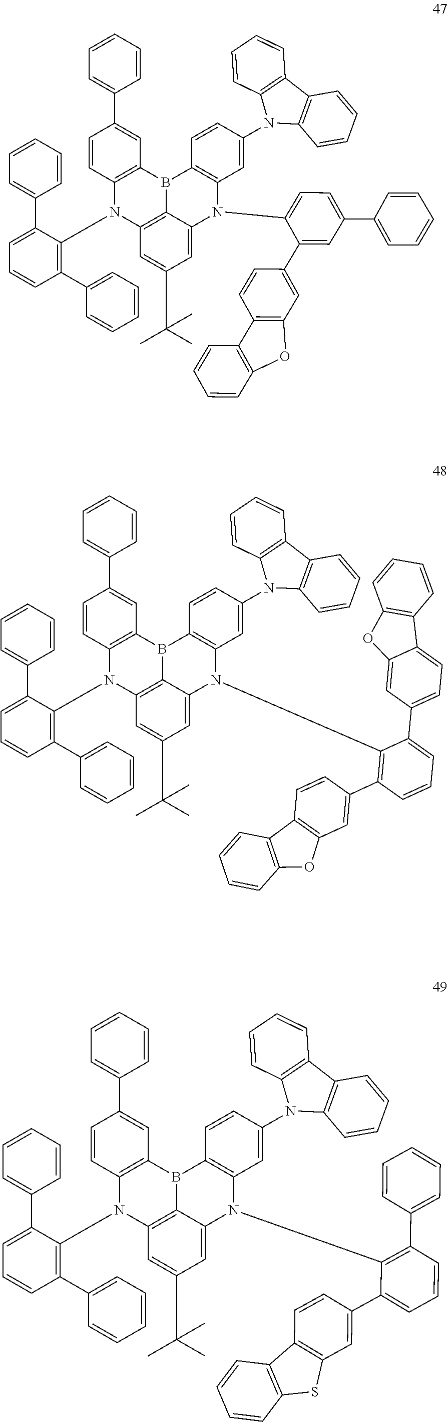 [SMILES: CC(C)(C)c1cc2c3c(c1)N(c1c(-c4ccccc4)cccc1-c1ccccc1)c1ccc(-c4ccccc4)cc1B3c1ccc(-n3c4ccccc4c4ccccc43)cc1N2c1ccc(-c2ccccc2)cc1-c1ccc2c(c1)oc1ccccc12 ; CC(C)(C)c1cc2c3c(c1)N(c1c(-c4ccc5c(c4)oc4ccccc45)cccc1-c1ccc4c(c1)oc1ccccc14)c1cc(-n4c5ccccc5c5ccccc54)ccc1B3c1cc(-c3ccccc3)ccc1N2c1c(-c2ccccc2)cccc1-c1ccccc1 ; CC(C)(C)c1cc2c3c(c1)N(c1c(-c4ccccc4)cccc1-c1ccc4c(c1)sc1ccccc14)c1cc(-n4c5ccccc5c5ccccc54)ccc1B3c1cc(-c3ccccc3)ccc1N2c1c(-c2ccccc2)cccc1-c1ccccc1] 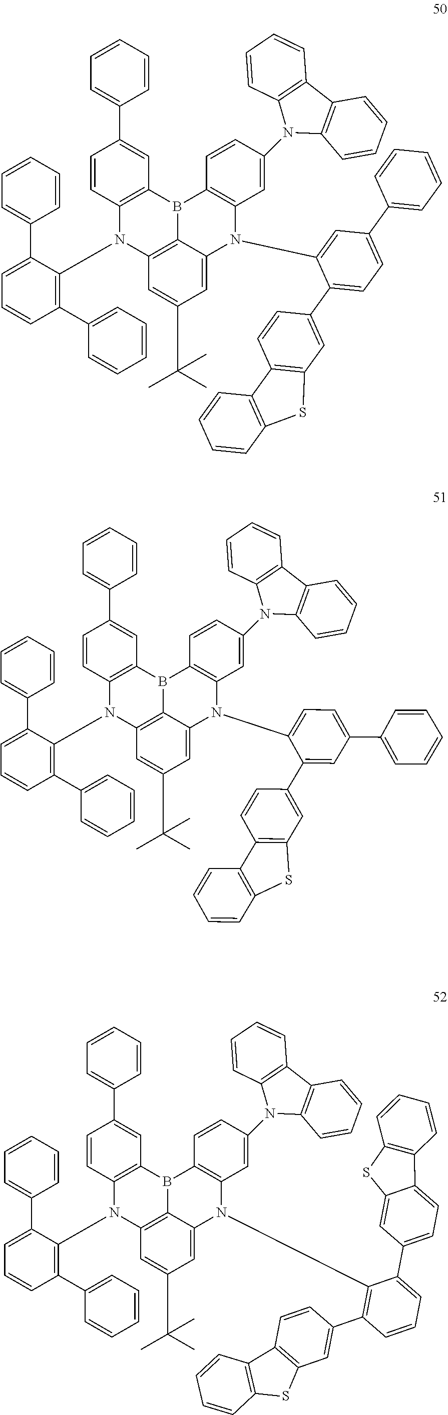 [SMILES: CC(C)(C)c1cc2c3c(c1)N(c1c(-c4ccccc4)cccc1-c1ccccc1)c1ccc(-c4ccccc4)cc1B3c1ccc(-n3c4ccccc4c4ccccc43)cc1N2c1cc(-c2ccccc2)ccc1-c1ccc2c(c1)sc1ccccc12 ; CC(C)(C)c1cc2c3c(c1)N(c1c(-c4ccccc4)cccc1-c1ccccc1)c1ccc(-c4ccccc4)cc1B3c1ccc(-n3c4ccccc4c4ccccc43)cc1N2c1ccc(-c2ccccc2)cc1-c1ccc2c(c1)sc1ccccc12 ; CC(C)(C)c1cc2c3c(c1)N(c1c(-c4ccc5c(c4)sc4ccccc45)cccc1-c1ccc4c(c1)sc1ccccc14)c1cc(-n4c5ccccc5c5ccccc54)ccc1B3c1cc(-c3ccccc3)ccc1N2c1c(-c2ccccc2)cccc1-c1ccccc1] 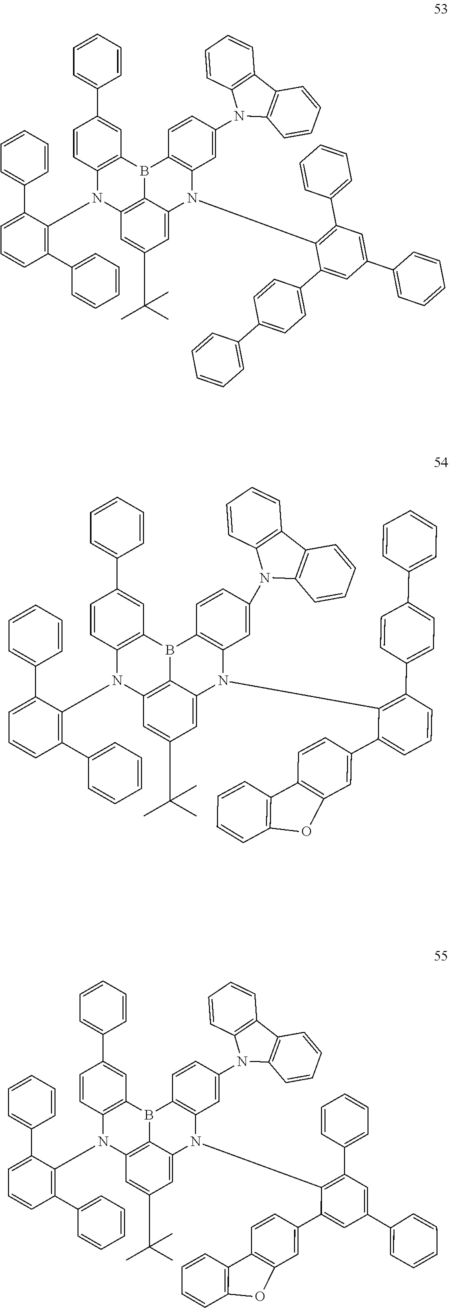 [SMILES: CC(C)(C)c1cc2c3c(c1)N(c1c(-c4ccccc4)cc(-c4ccccc4)cc1-c1ccc(-c4ccccc4)cc1)c1cc(-n4c5ccccc5c5ccccc54)ccc1B3c1cc(-c3ccccc3)ccc1N2c1c(-c2ccccc2)cccc1-c1ccccc1 ; CC(C)(C)c1cc2c3c(c1)N(c1c(-c4ccc(-c5ccccc5)cc4)cccc1-c1ccc4c(c1)oc1ccccc14)c1cc(-n4c5ccccc5c5ccccc54)ccc1B3c1cc(-c3ccccc3)ccc1N2c1c(-c2ccccc2)cccc1-c1ccccc1 ; CC(C)(C)c1cc2c3c(c1)N(c1c(-c4ccccc4)cc(-c4ccccc4)cc1-c1ccc4c(c1)oc1ccccc14)c1cc(-n4c5ccccc5c5ccccc54)ccc1B3c1cc(-c3ccccc3)ccc1N2c1c(-c2ccccc2)cccc1-c1ccccc1] 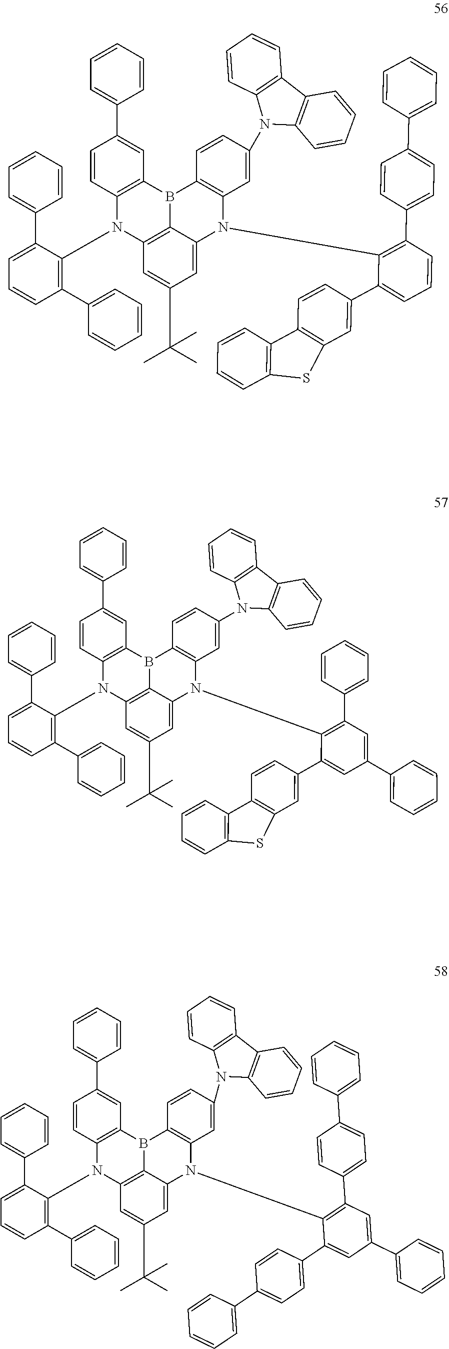 [SMILES: CC(C)(C)c1cc2c3c(c1)N(c1c(-c4ccc(-c5ccccc5)cc4)cccc1-c1ccc4c(c1)sc1ccccc14)c1cc(-n4c5ccccc5c5ccccc54)ccc1B3c1cc(-c3ccccc3)ccc1N2c1c(-c2ccccc2)cccc1-c1ccccc1 ; CC(C)(C)c1cc2c3c(c1)N(c1c(-c4ccccc4)cc(-c4ccccc4)cc1-c1ccc4c(c1)sc1ccccc14)c1cc(-n4c5ccccc5c5ccccc54)ccc1B3c1cc(-c3ccccc3)ccc1N2c1c(-c2ccccc2)cccc1-c1ccccc1 ; CC(C)(C)c1cc2c3c(c1)N(c1c(-c4ccc(-c5ccccc5)cc4)cc(-c4ccccc4)cc1-c1ccc(-c4ccccc4)cc1)c1cc(-n4c5ccccc5c5ccccc54)ccc1B3c1cc(-c3ccccc3)ccc1N2c1c(-c2ccccc2)cccc1-c1ccccc1] 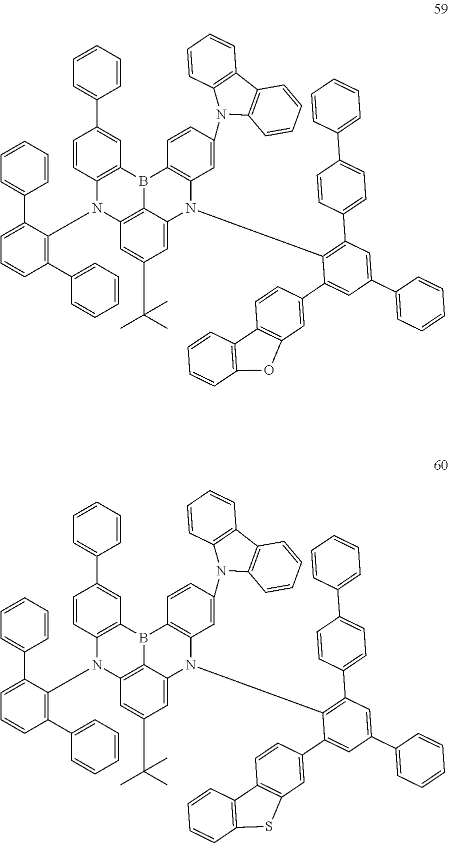 [SMILES: CC(C)(C)c1cc2c3c(c1)N(c1c(-c4ccc(-c5ccccc5)cc4)cc(-c4ccccc4)cc1-c1ccc4c(c1)oc1ccccc14)c1cc(-n4c5ccccc5c5ccccc54)ccc1B3c1cc(-c3ccccc3)ccc1N2c1c(-c2ccccc2)cccc1-c1ccccc1 ; CC(C)(C)c1cc2c3c(c1)N(c1c(-c4ccc(-c5ccccc5)cc4)cc(-c4ccccc4)cc1-c1ccc4c(c1)sc1ccccc14)c1cc(-n4c5ccccc5c5ccccc54)ccc1B3c1cc(-c3ccccc3)ccc1N2c1c(-c2ccccc2)cccc1-c1ccccc1] 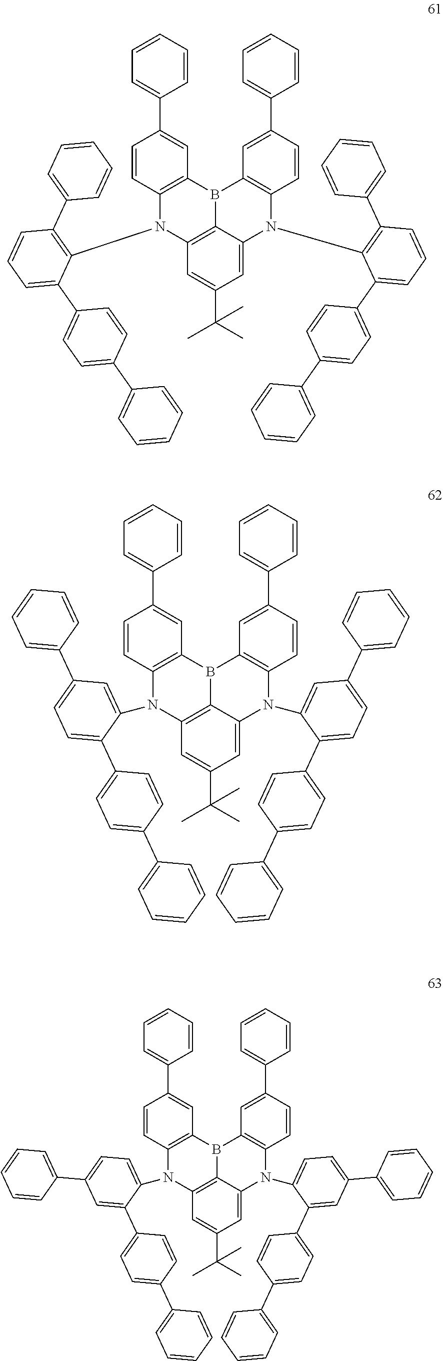 [SMILES: CC(C)(C)c1cc2c3c(c1)N(c1c(-c4ccccc4)cccc1-c1ccc(-c4ccccc4)cc1)c1ccc(-c4ccccc4)cc1B3c1cc(-c3ccccc3)ccc1N2c1c(-c2ccccc2)cccc1-c1ccc(-c2ccccc2)cc1 ; CC(C)(C)c1cc2c3c(c1)N(c1cc(-c4ccccc4)ccc1-c1ccc(-c4ccccc4)cc1)c1ccc(-c4ccccc4)cc1B3c1cc(-c3ccccc3)ccc1N2c1cc(-c2ccccc2)ccc1-c1ccc(-c2ccccc2)cc1 ; CC(C)(C)c1cc2c3c(c1)N(c1ccc(-c4ccccc4)cc1-c1ccc(-c4ccccc4)cc1)c1ccc(-c4ccccc4)cc1B3c1cc(-c3ccccc3)ccc1N2c1ccc(-c2ccccc2)cc1-c1ccc(-c2ccccc2)cc1] 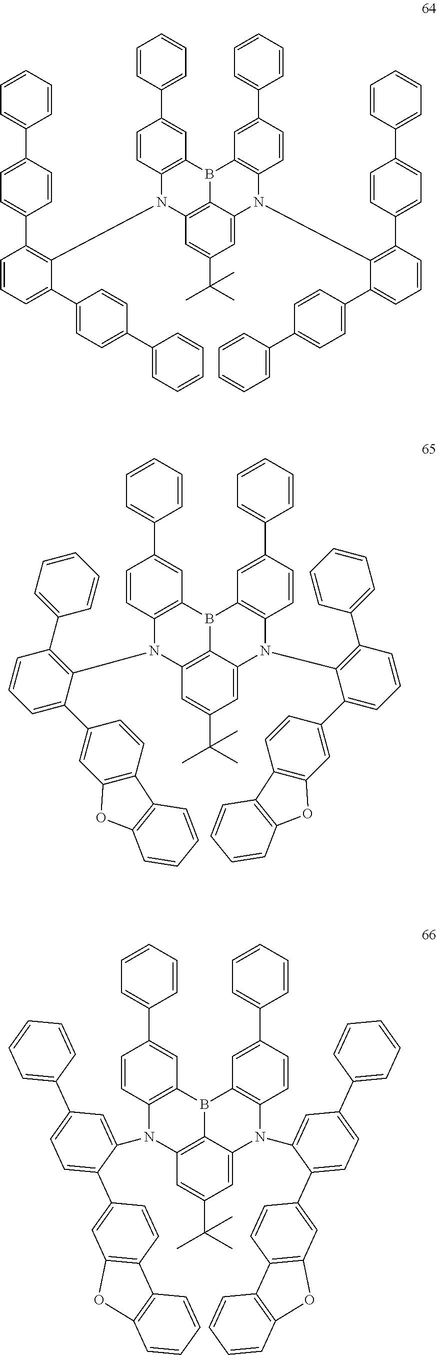 [SMILES: CC(C)(C)c1cc2c3c(c1)N(c1c(-c4ccc(-c5ccccc5)cc4)cccc1-c1ccc(-c4ccccc4)cc1)c1ccc(-c4ccccc4)cc1B3c1cc(-c3ccccc3)ccc1N2c1c(-c2ccc(-c3ccccc3)cc2)cccc1-c1ccc(-c2ccccc2)cc1 ; CC(C)(C)c1cc2c3c(c1)N(c1c(-c4ccccc4)cccc1-c1ccc4c(c1)oc1ccccc14)c1ccc(-c4ccccc4)cc1B3c1cc(-c3ccccc3)ccc1N2c1c(-c2ccccc2)cccc1-c1ccc2c(c1)oc1ccccc12 ; CC(C)(C)c1cc2c3c(c1)N(c1cc(-c4ccccc4)ccc1-c1ccc4c(c1)oc1ccccc14)c1ccc(-c4ccccc4)cc1B3c1cc(-c3ccccc3)ccc1N2c1cc(-c2ccccc2)ccc1-c1ccc2c(c1)oc1ccccc12] 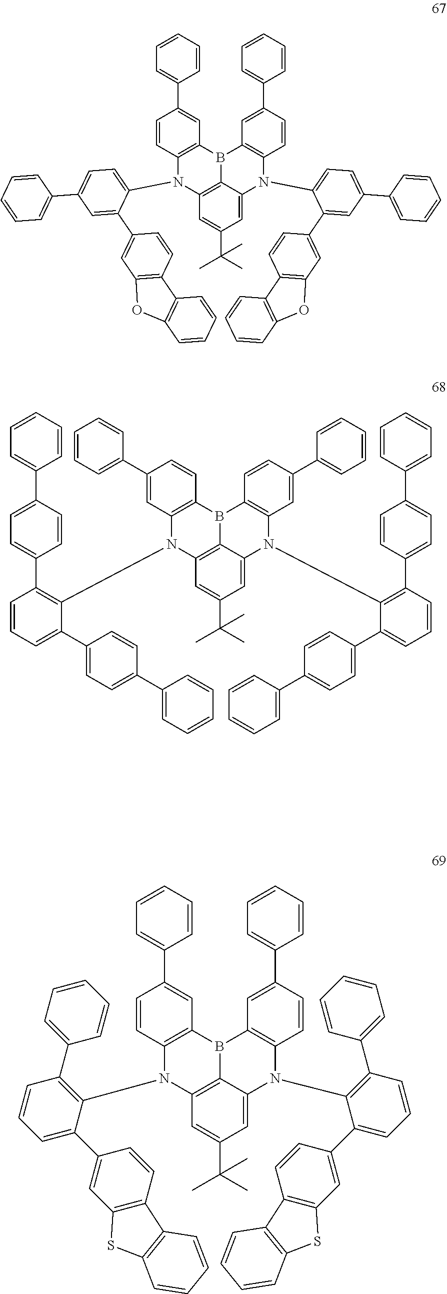 [SMILES: CC(C)(C)c1cc2c3c(c1)N(c1ccc(-c4ccccc4)cc1-c1ccc4c(c1)oc1ccccc14)c1ccc(-c4ccccc4)cc1B3c1cc(-c3ccccc3)ccc1N2c1ccc(-c2ccccc2)cc1-c1ccc2c(c1)oc1ccccc12 ; CC(C)(C)c1cc2c3c(c1)N(c1c(-c4ccc(-c5ccccc5)cc4)cccc1-c1ccc(-c4ccccc4)cc1)c1cc(-c4ccccc4)ccc1B3c1ccc(-c3ccccc3)cc1N2c1c(-c2ccc(-c3ccccc3)cc2)cccc1-c1ccc(-c2ccccc2)cc1 ; CC(C)(C)c1cc2c3c(c1)N(c1c(-c4ccccc4)cccc1-c1ccc4c(c1)sc1ccccc14)c1ccc(-c4ccccc4)cc1B3c1cc(-c3ccccc3)ccc1N2c1c(-c2ccccc2)cccc1-c1ccc2c(c1)sc1ccccc12] 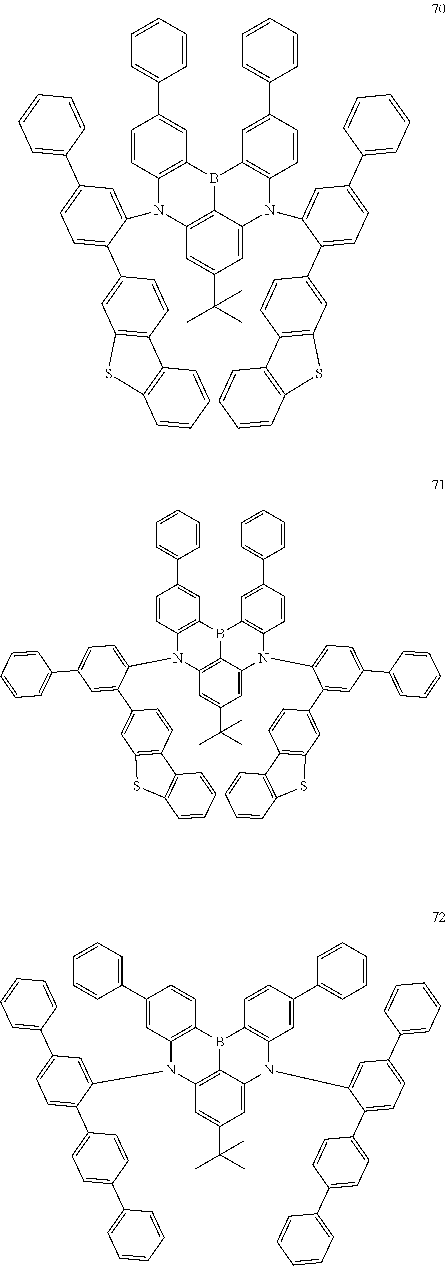 [SMILES: CC(C)(C)c1cc2c3c(c1)N(c1cc(-c4ccccc4)ccc1-c1ccc4c(c1)sc1ccccc14)c1ccc(-c4ccccc4)cc1B3c1cc(-c3ccccc3)ccc1N2c1cc(-c2ccccc2)ccc1-c1ccc2c(c1)sc1ccccc12 ; CC(C)(C)c1cc2c3c(c1)N(c1ccc(-c4ccccc4)cc1-c1ccc4c(c1)sc1ccccc14)c1ccc(-c4ccccc4)cc1B3c1cc(-c3ccccc3)ccc1N2c1ccc(-c2ccccc2)cc1-c1ccc2c(c1)sc1ccccc12 ; CC(C)(C)c1cc2c3c(c1)N(c1cc(-c4ccccc4)ccc1-c1ccc(-c4ccccc4)cc1)c1cc(-c4ccccc4)ccc1B3c1ccc(-c3ccccc3)cc1N2c1cc(-c2ccccc2)ccc1-c1ccc(-c2ccccc2)cc1] 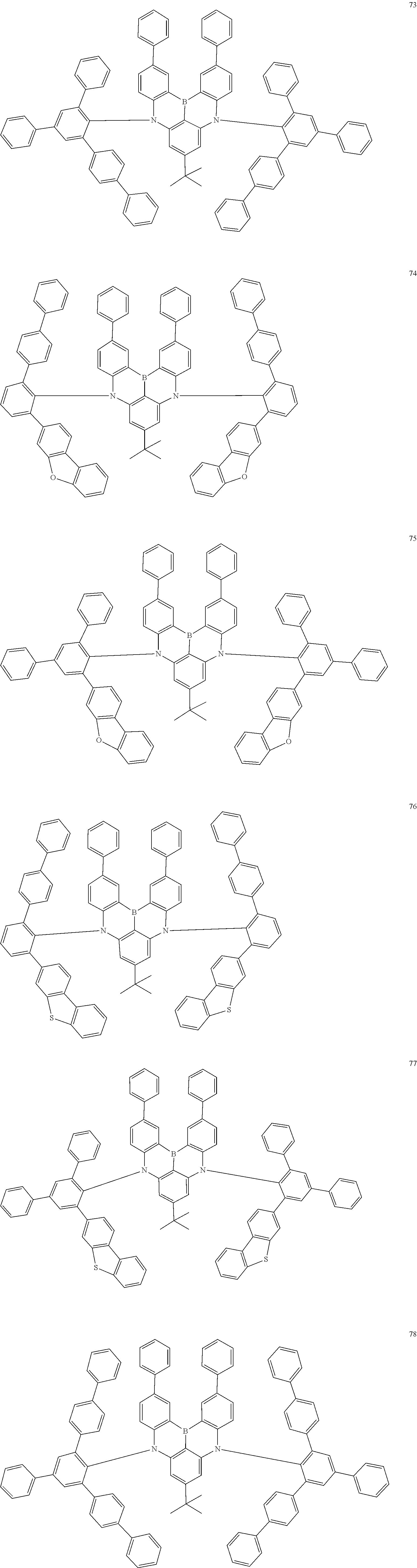 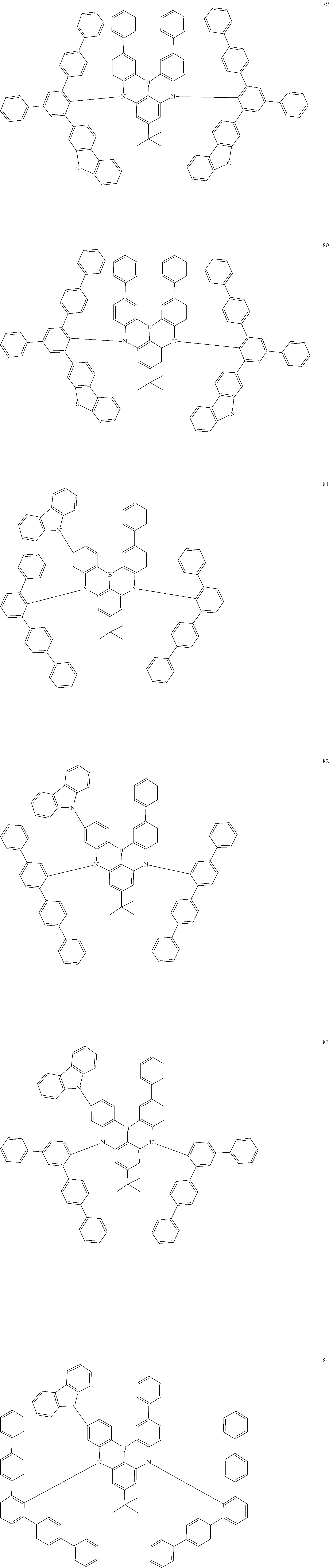 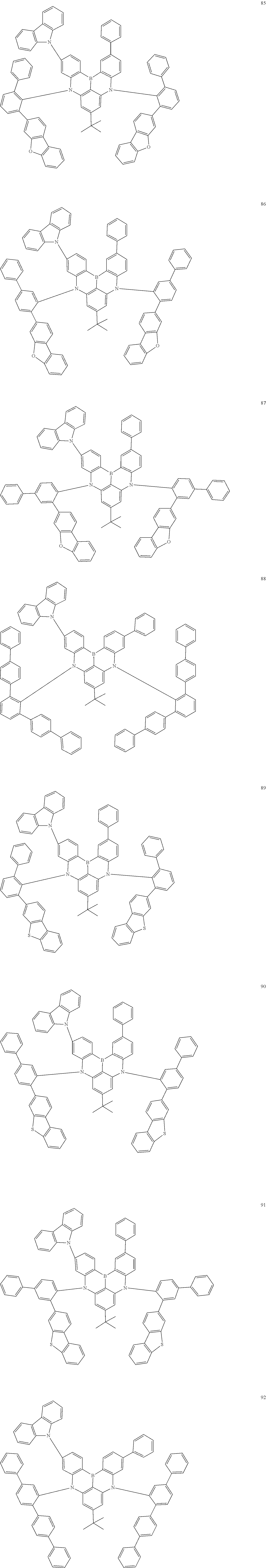 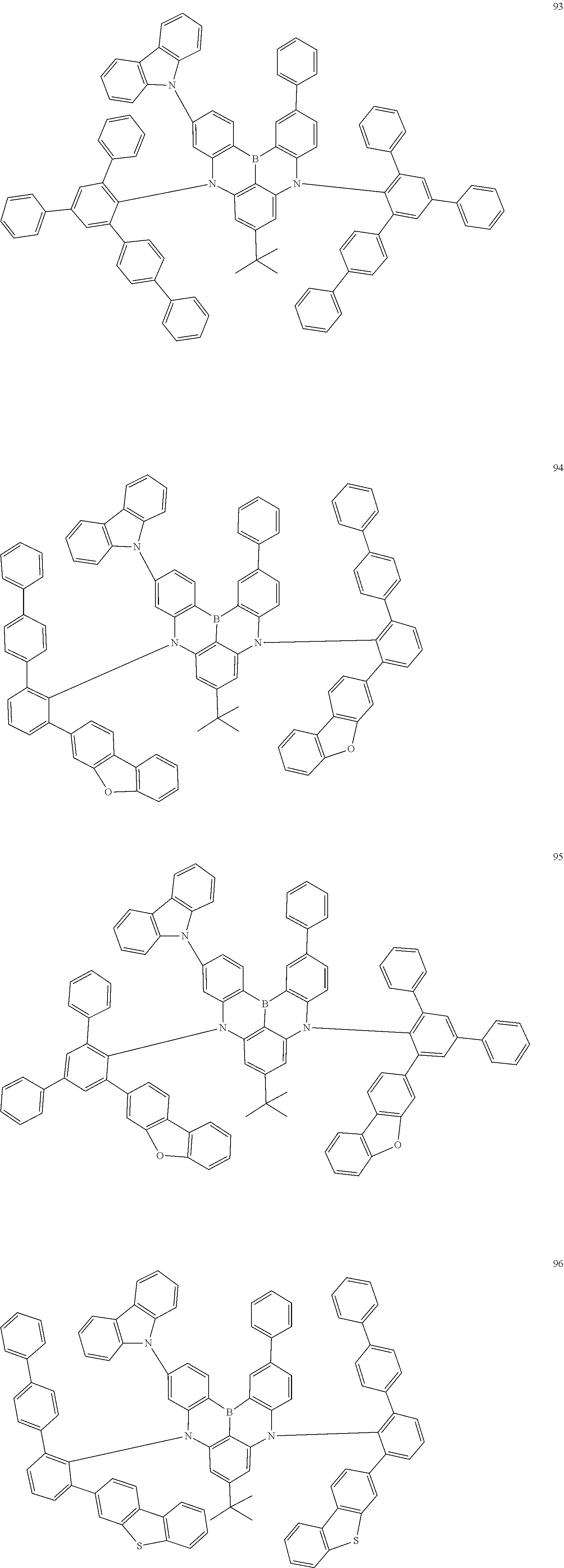 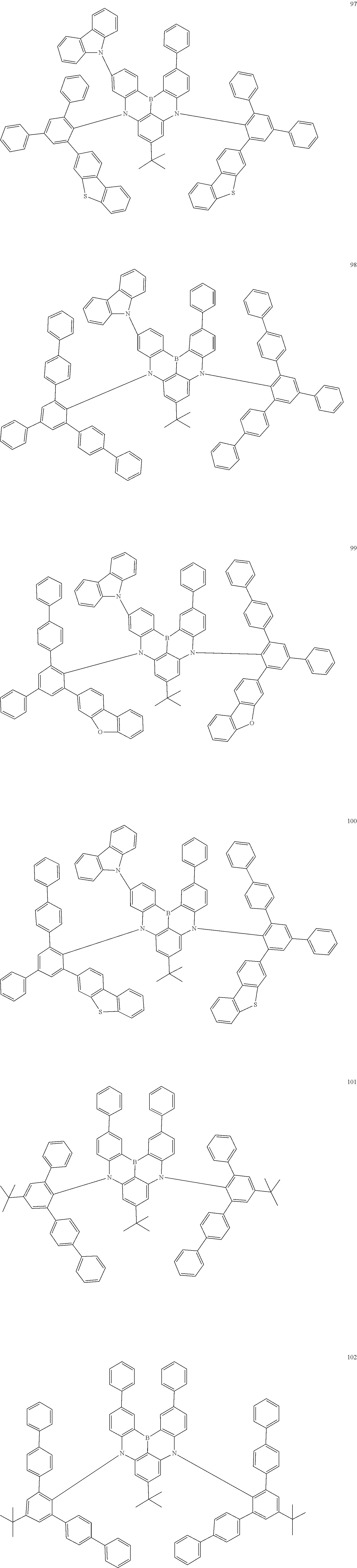 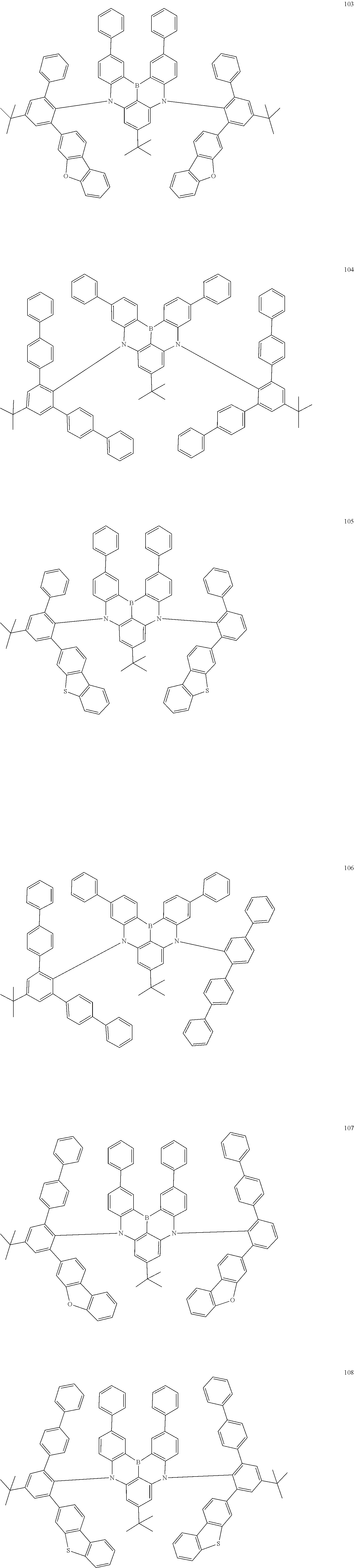 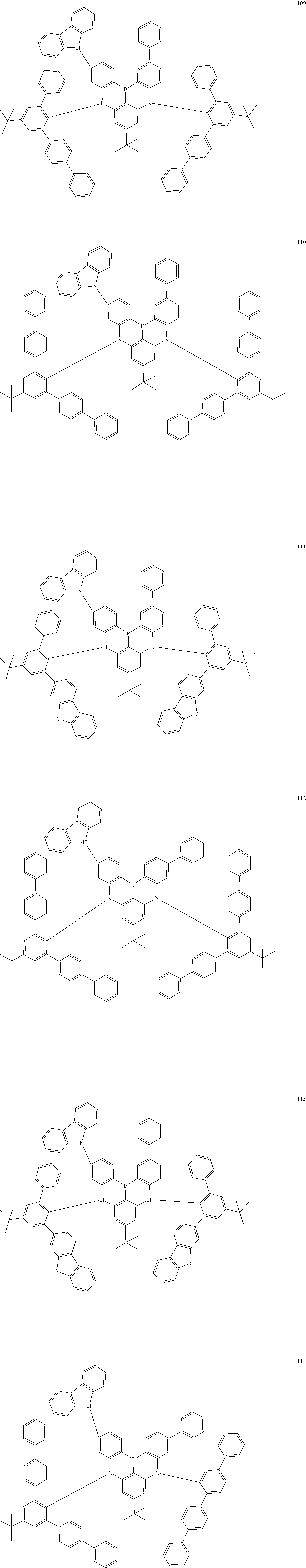 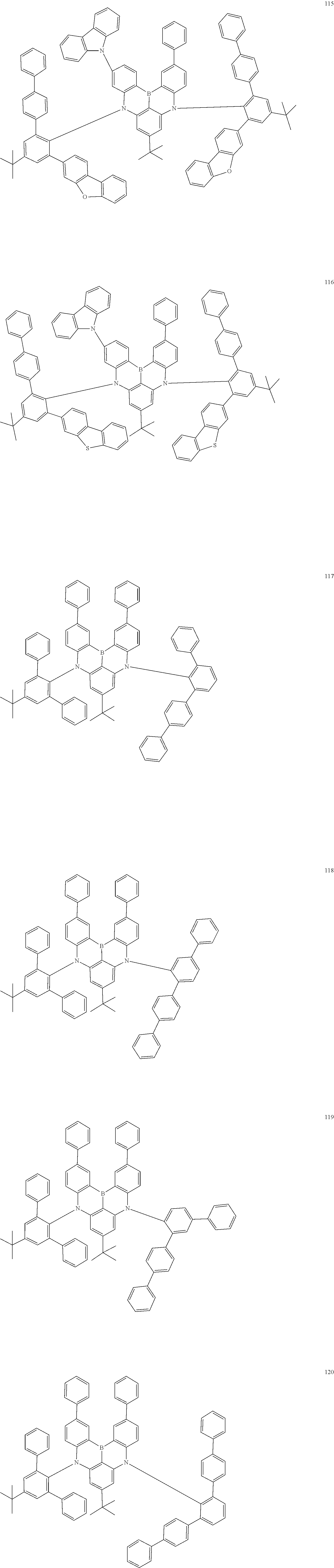 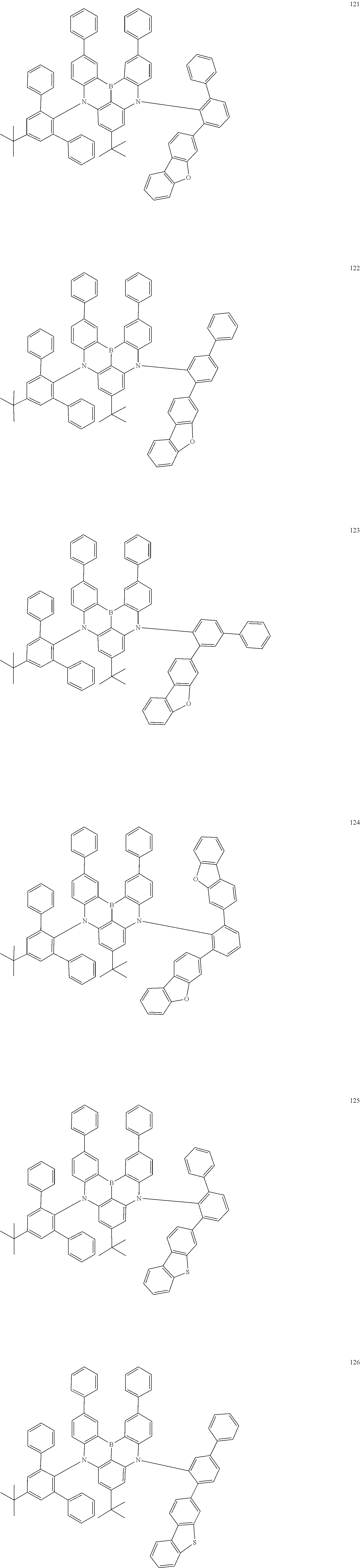 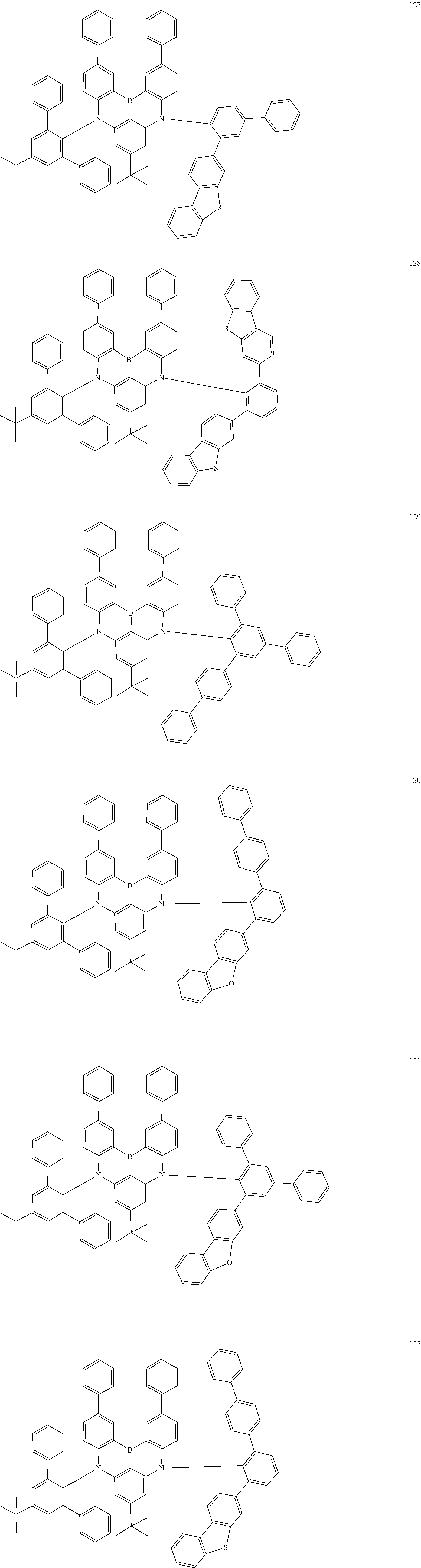 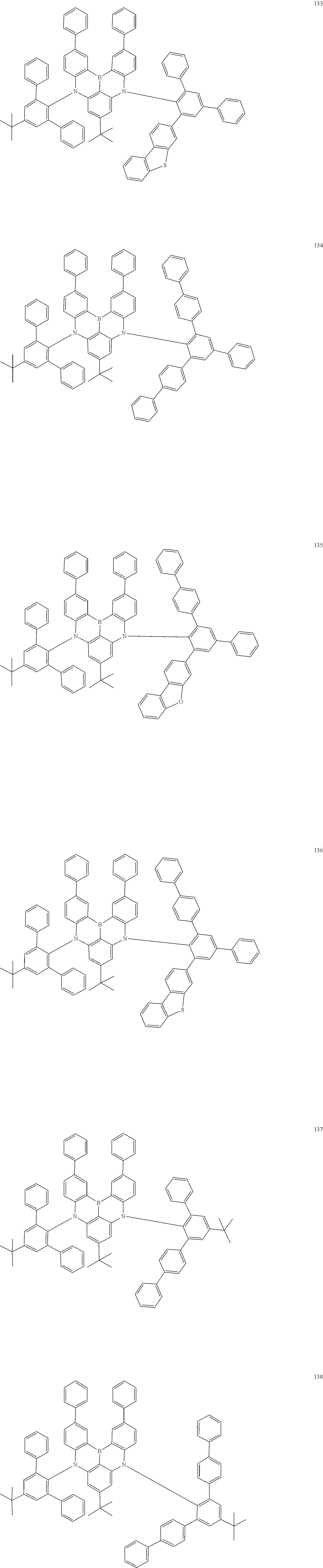 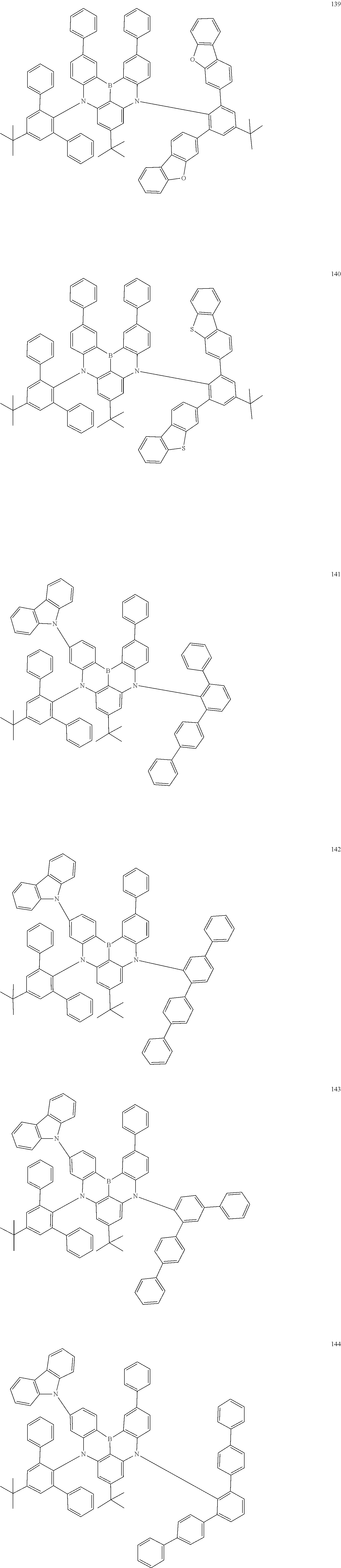 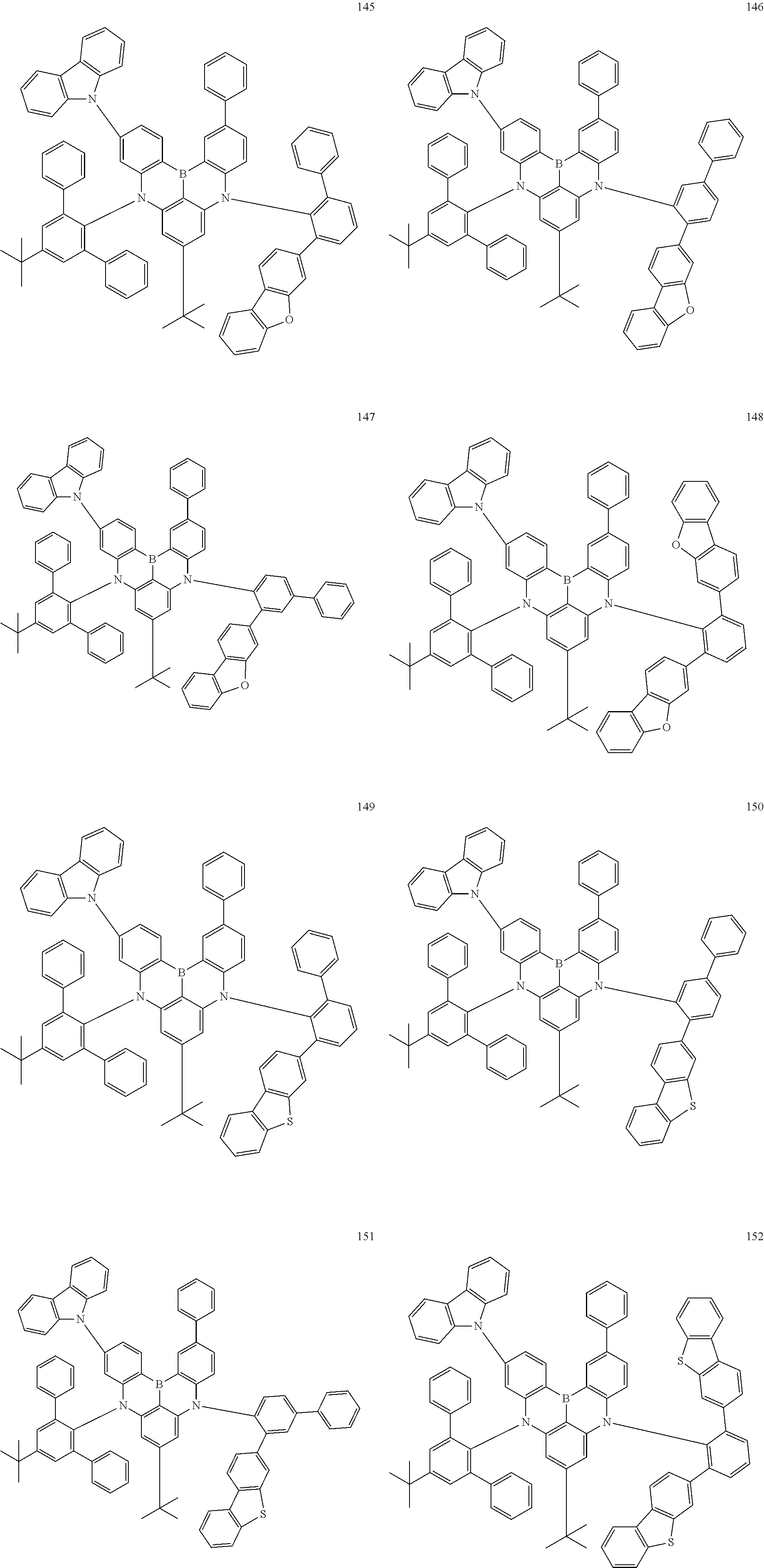 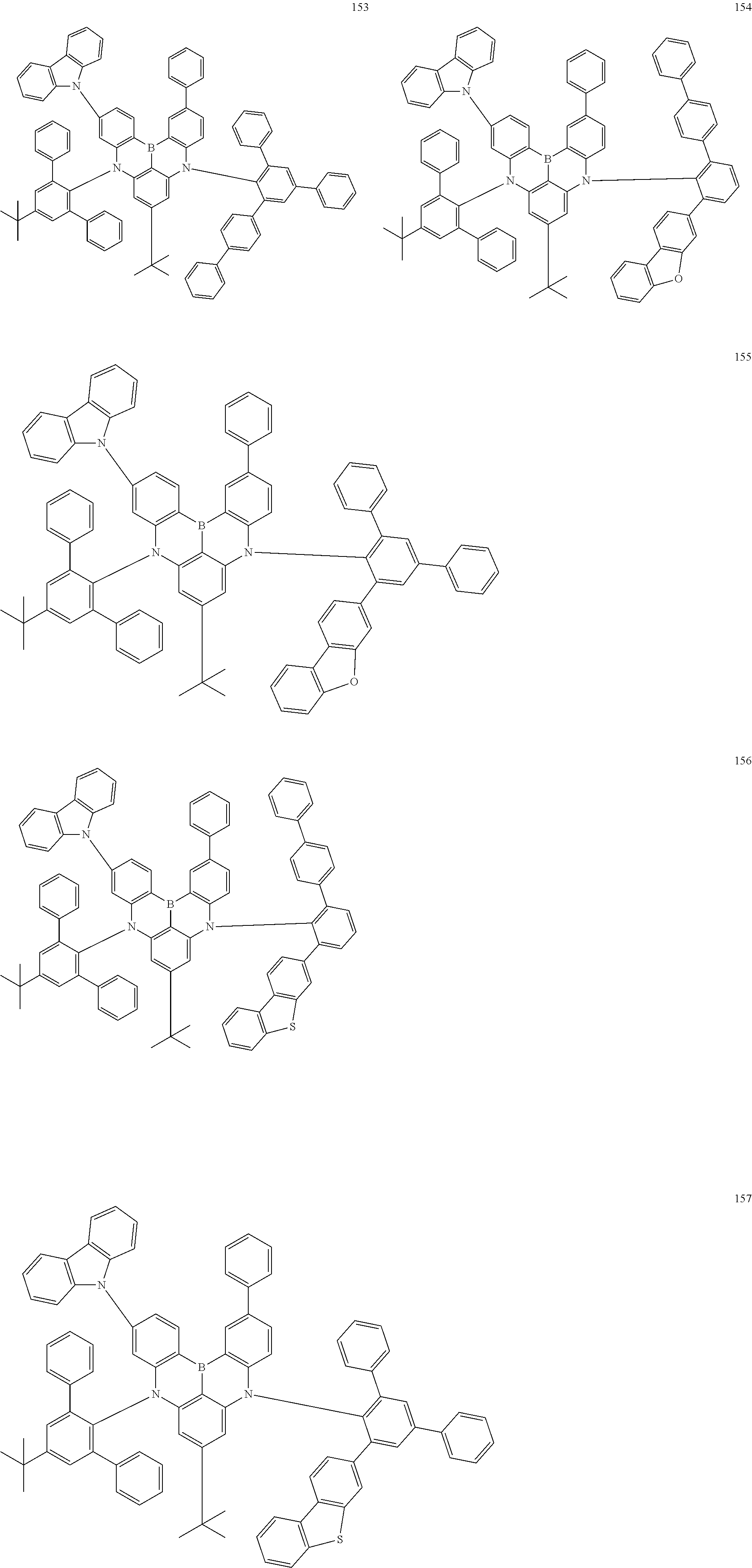 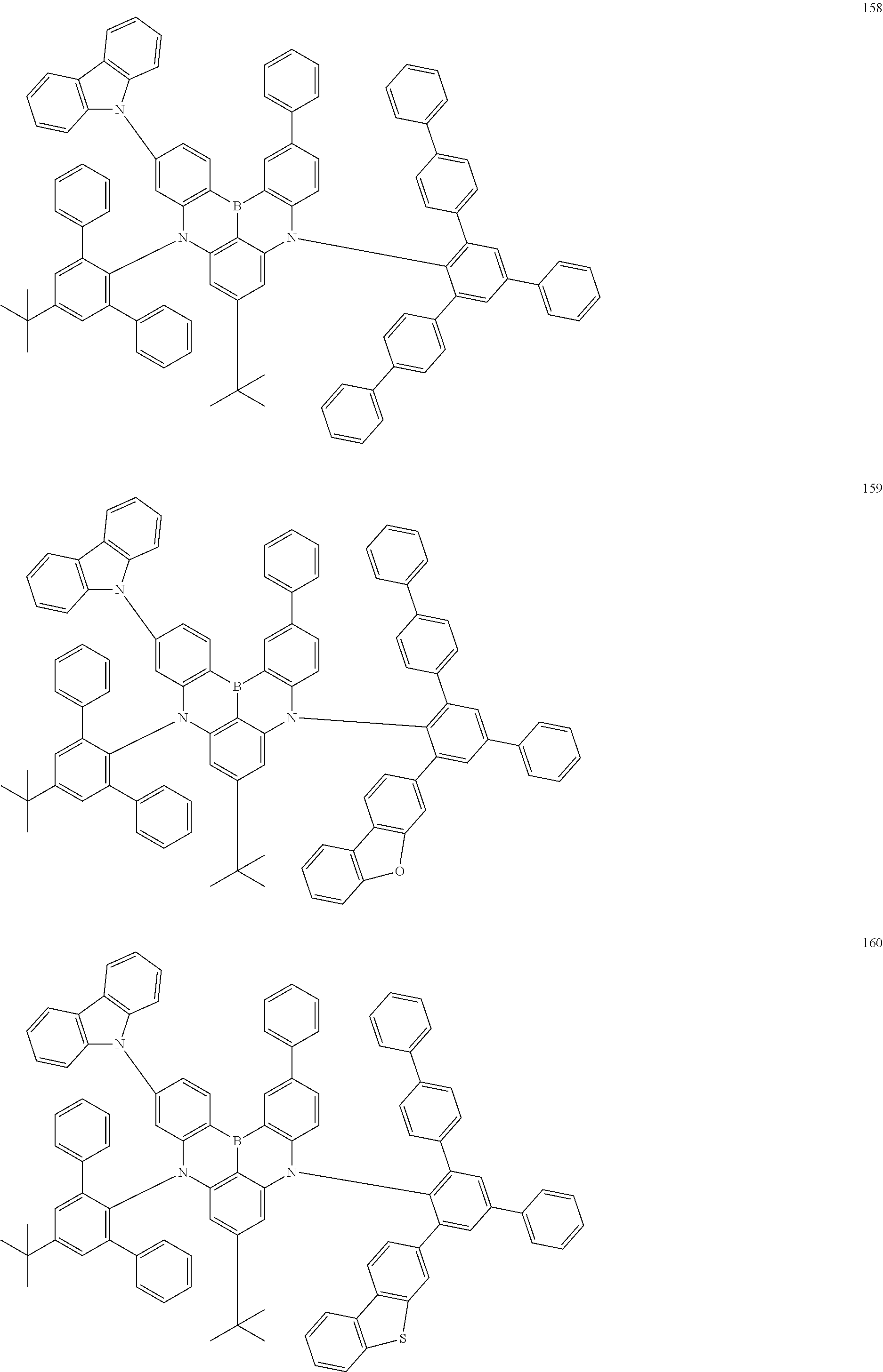 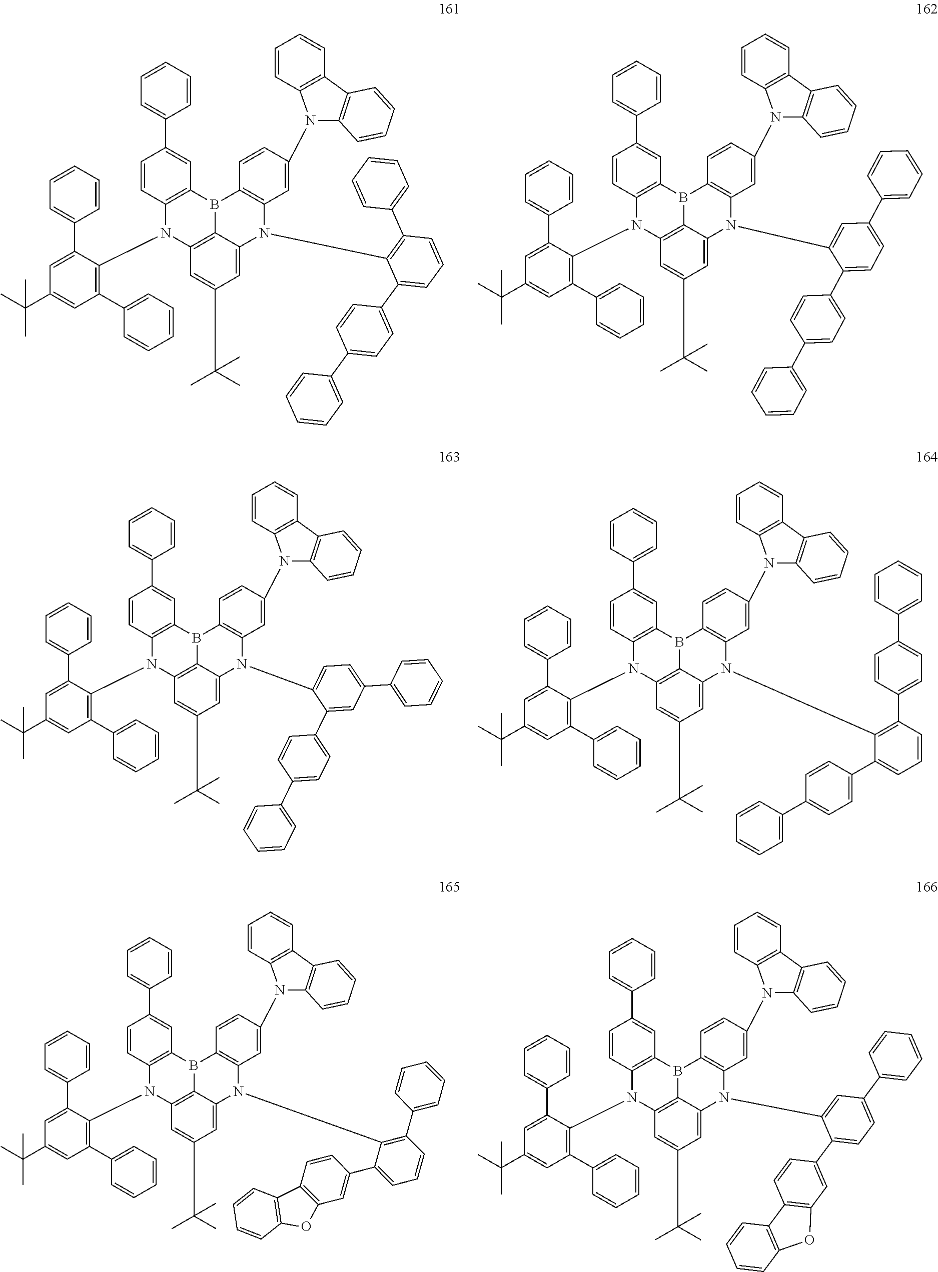 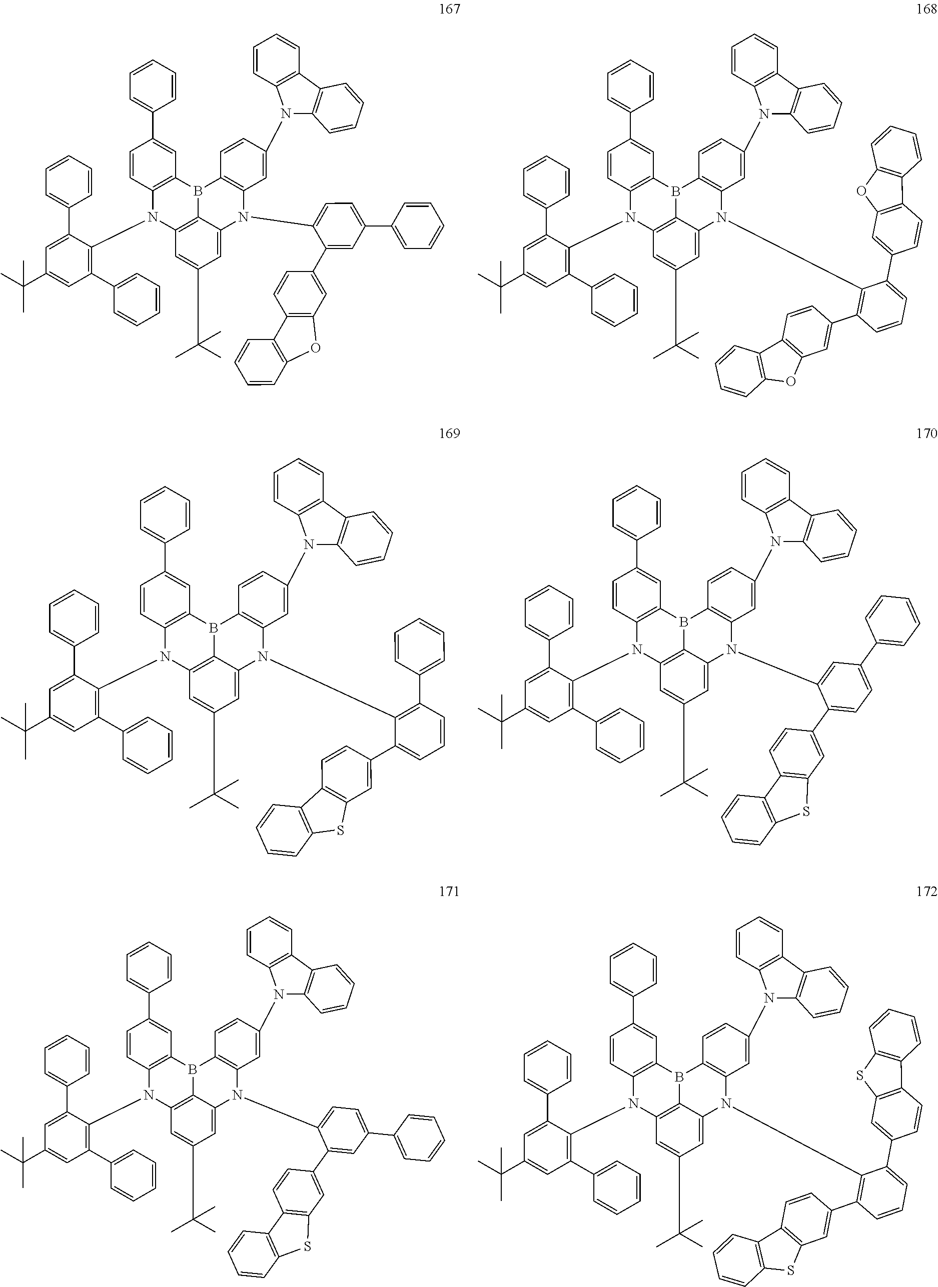 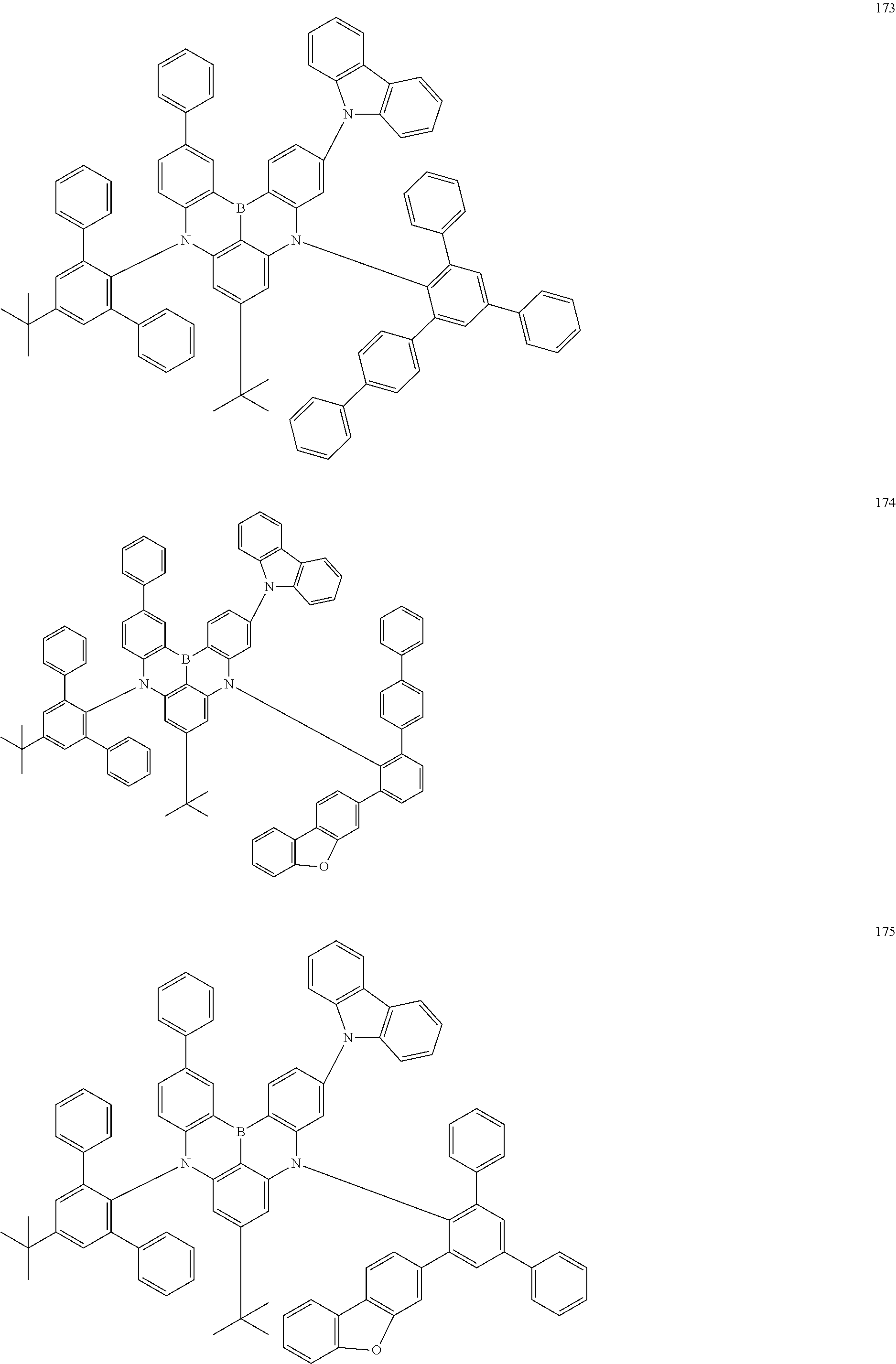 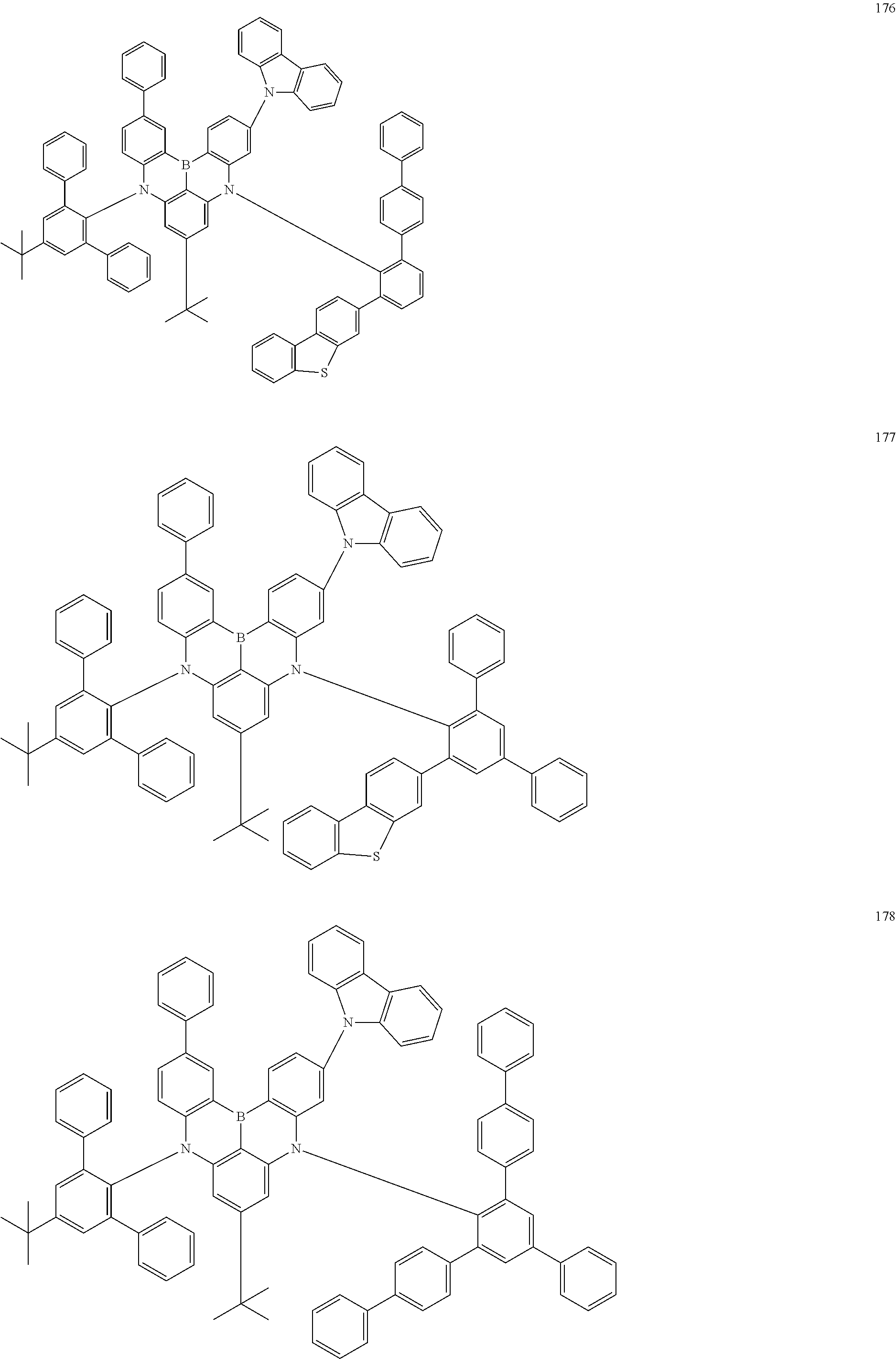 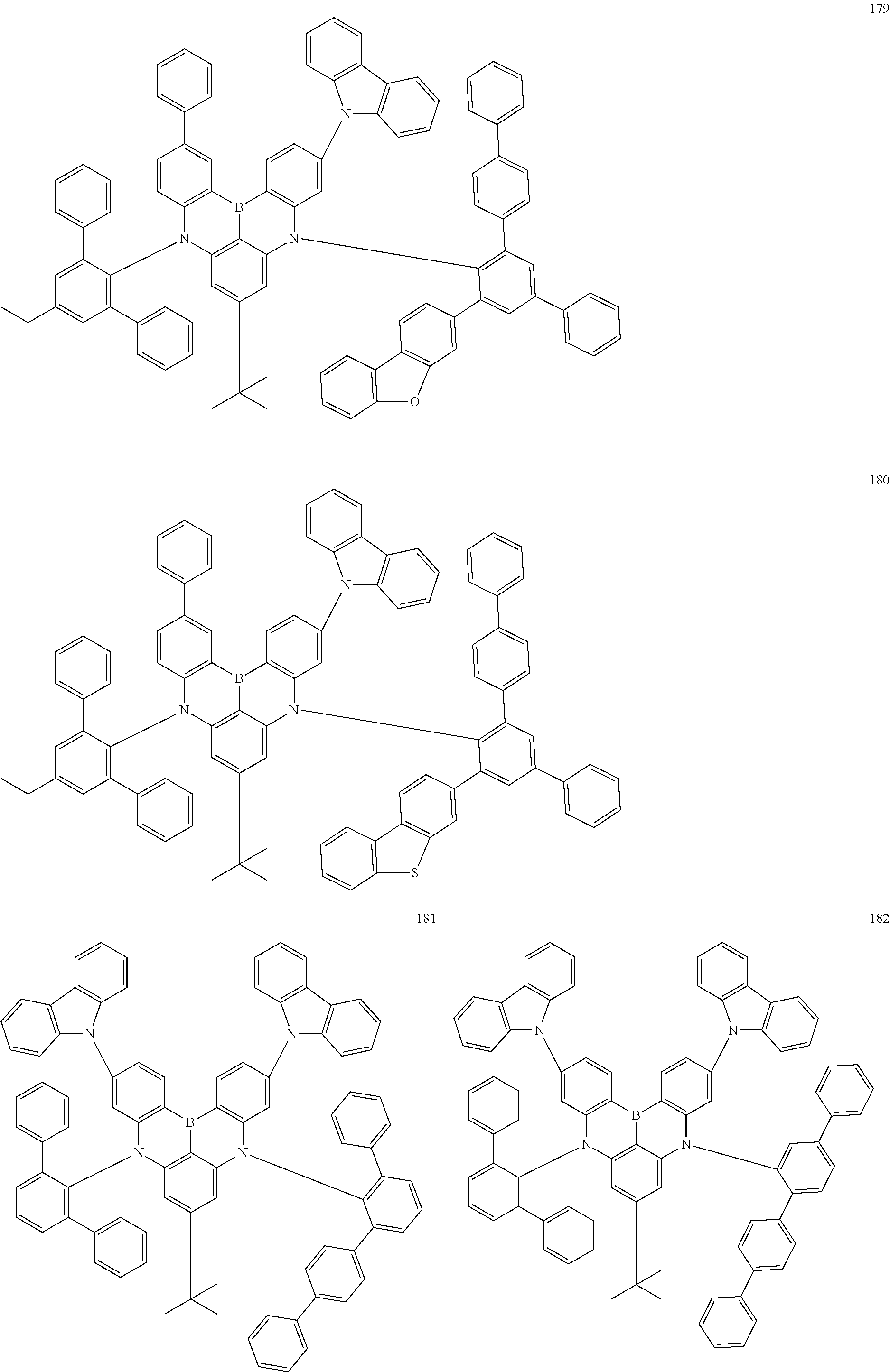 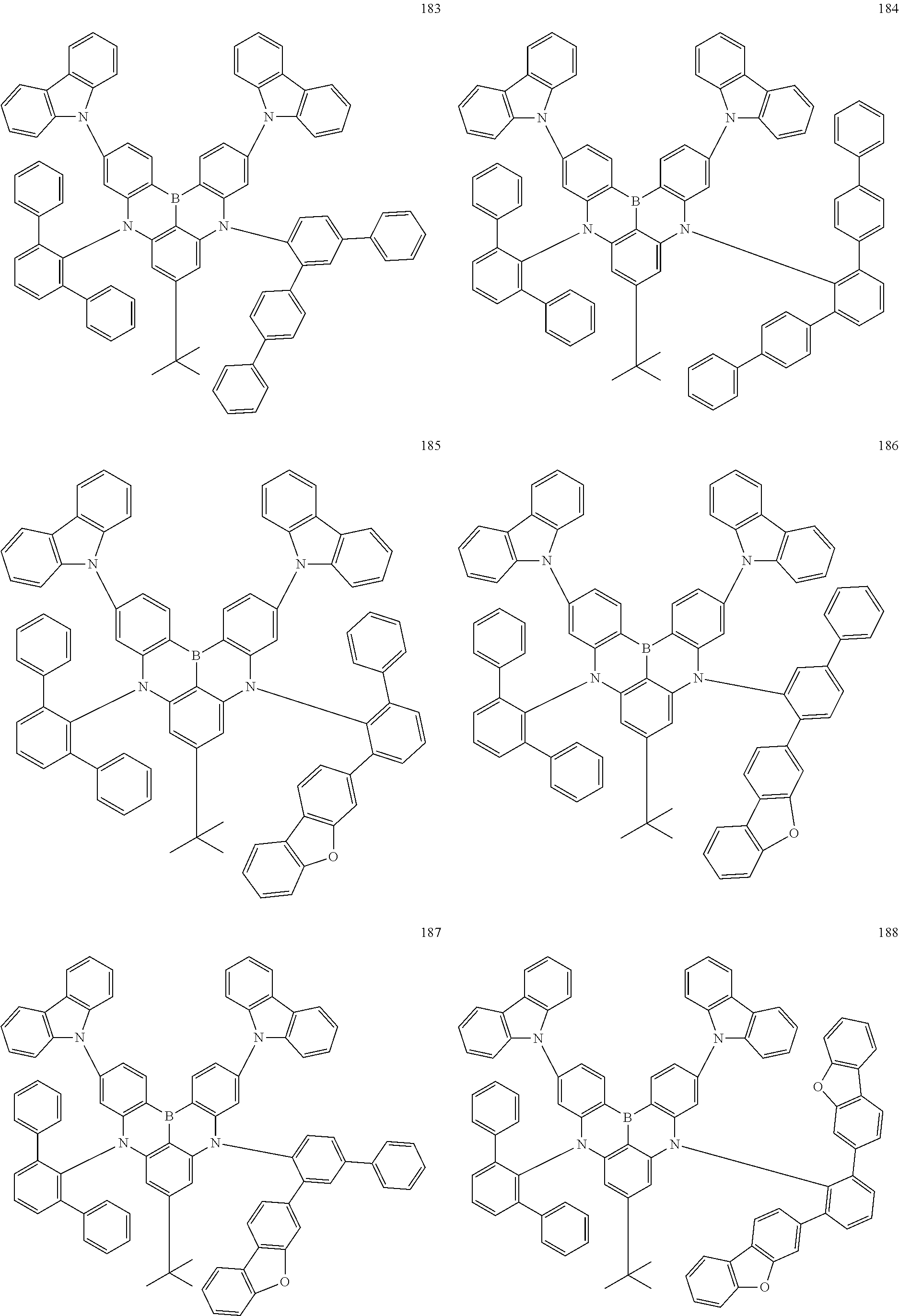 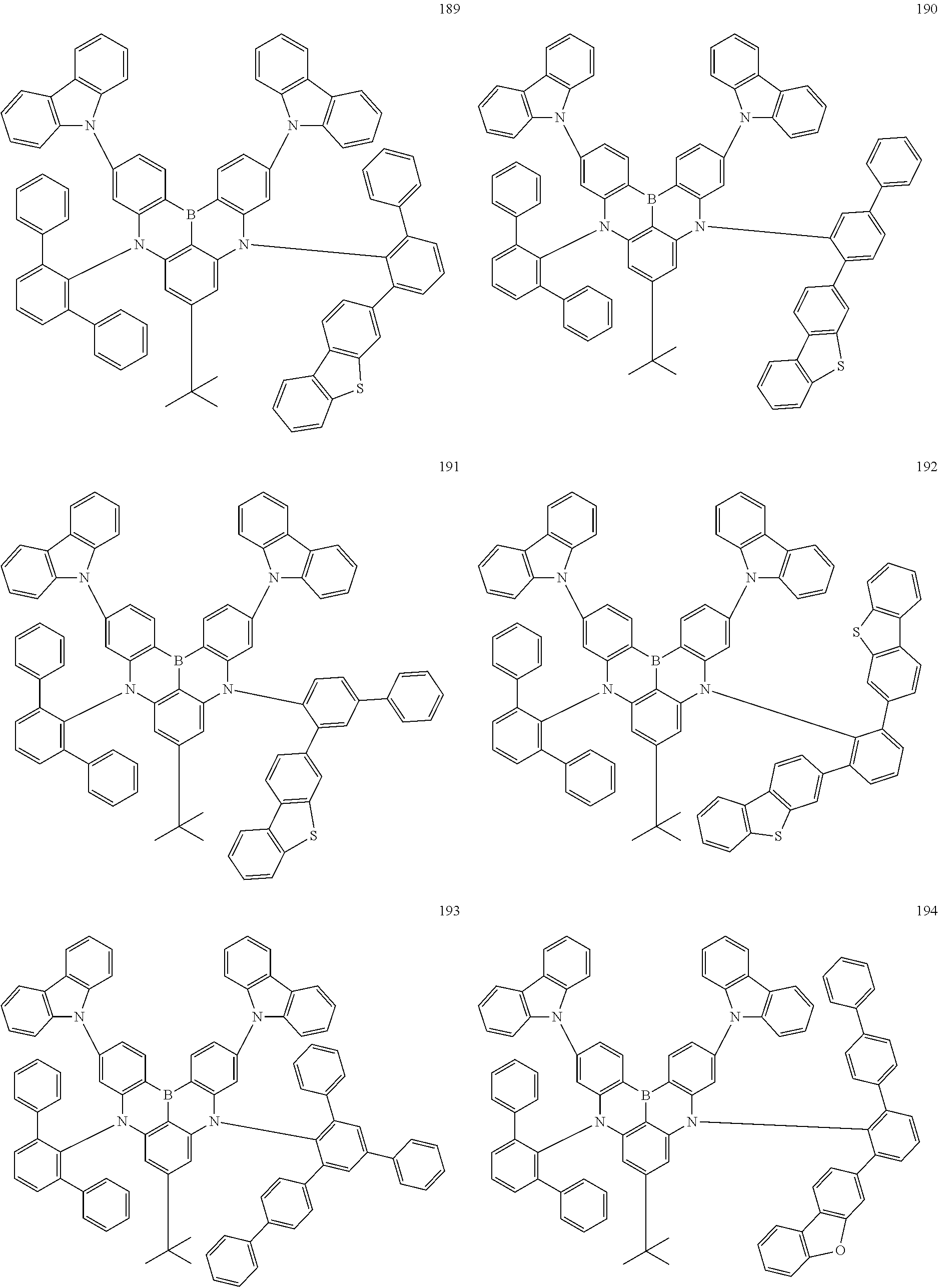 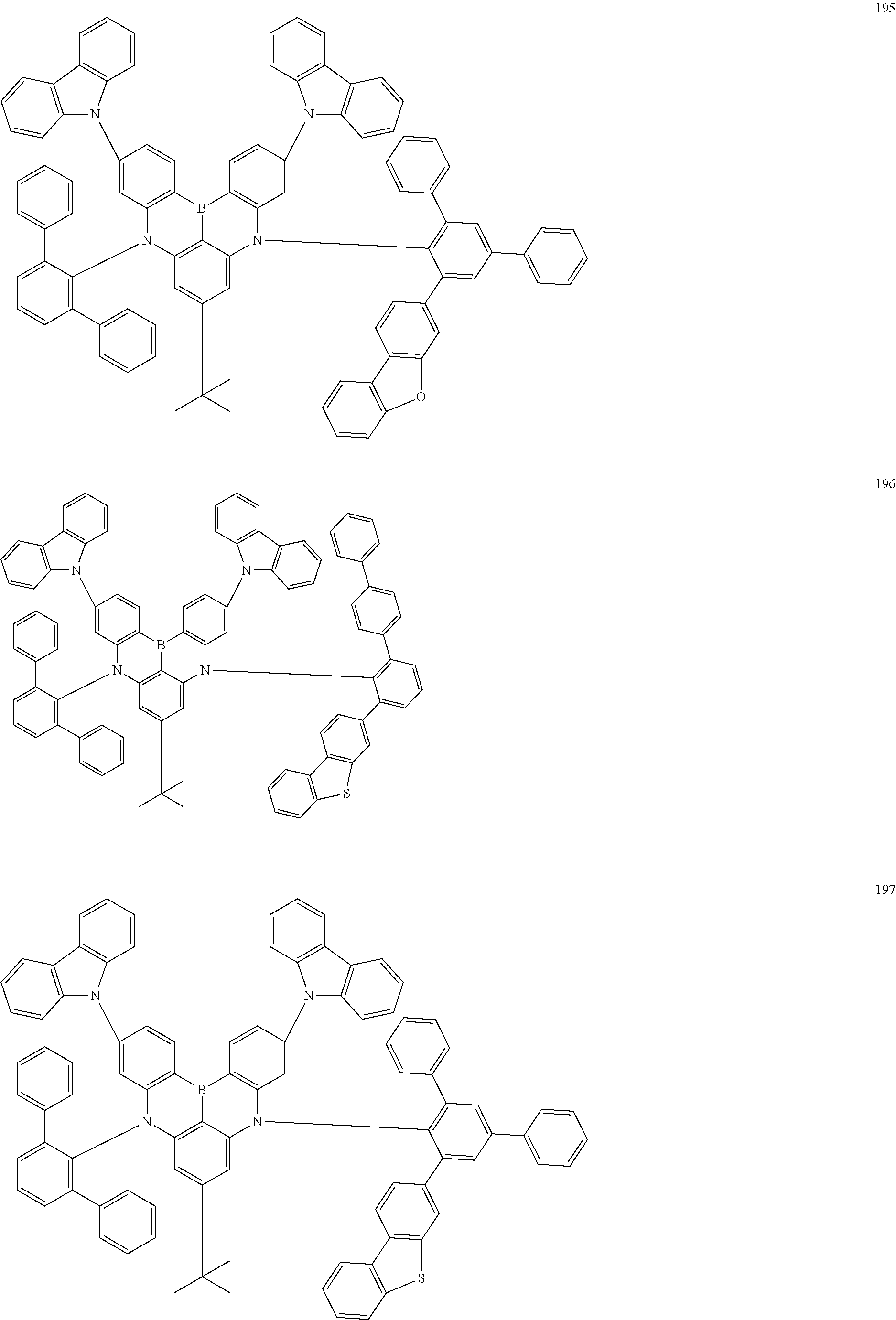 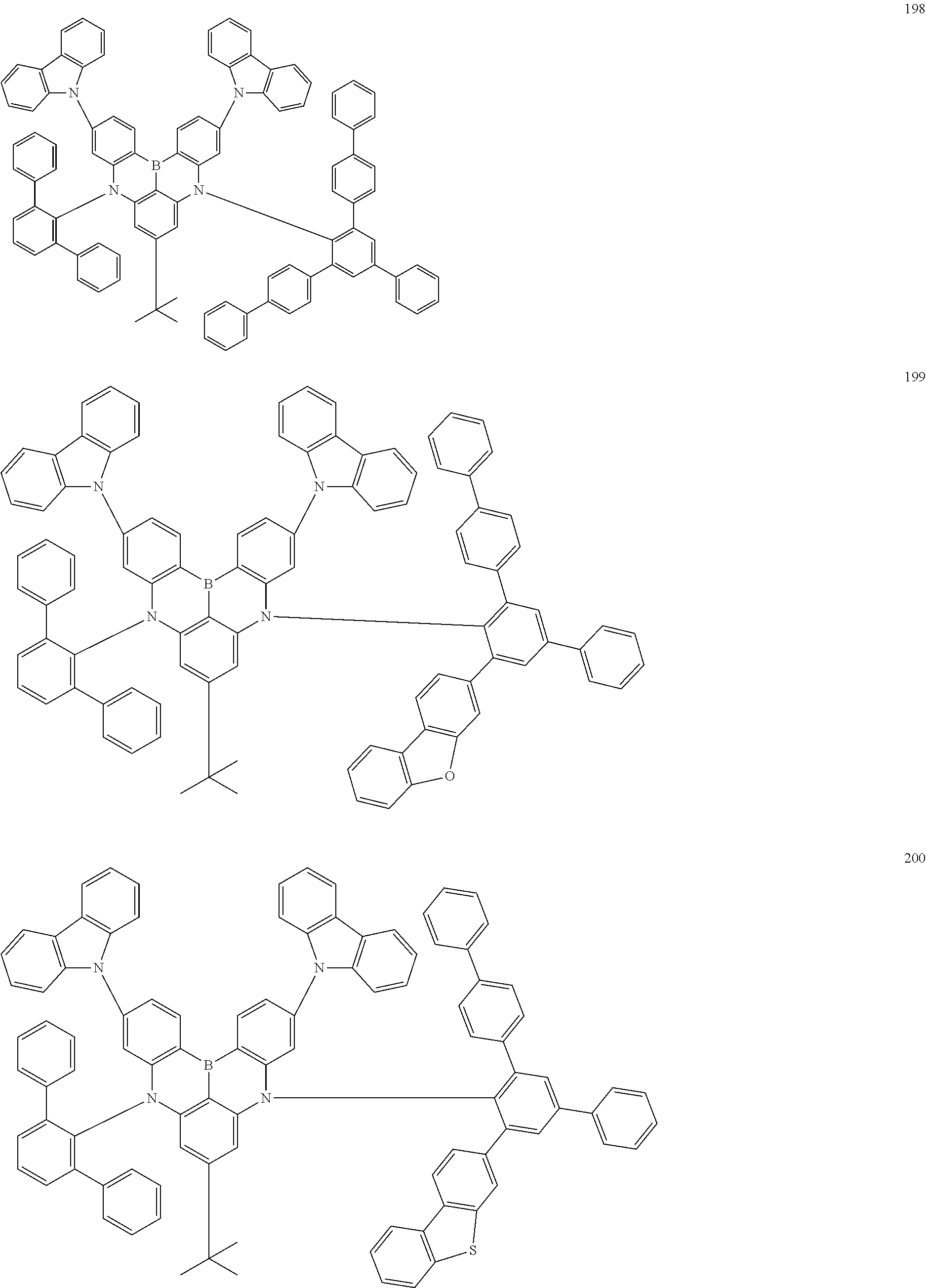 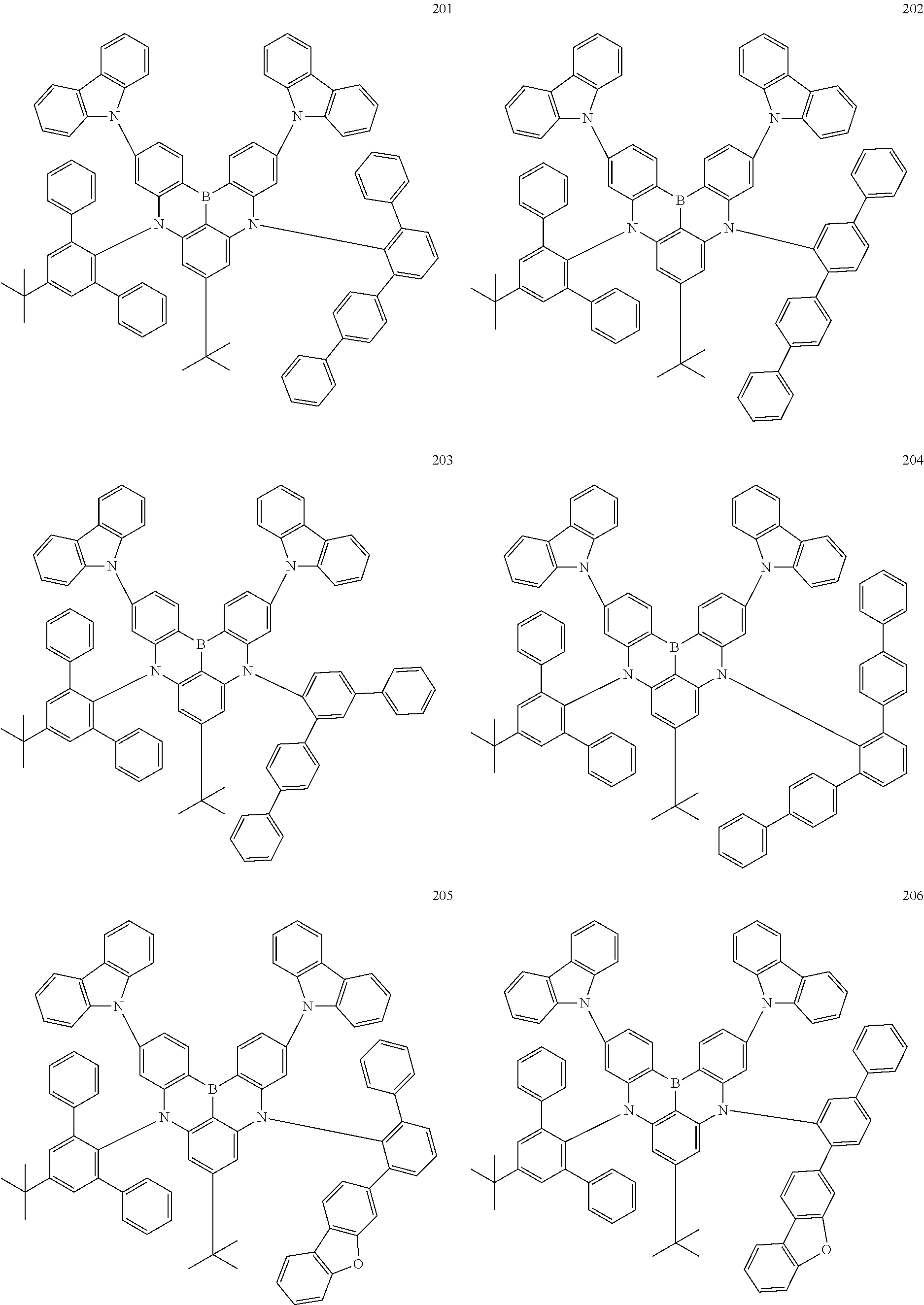 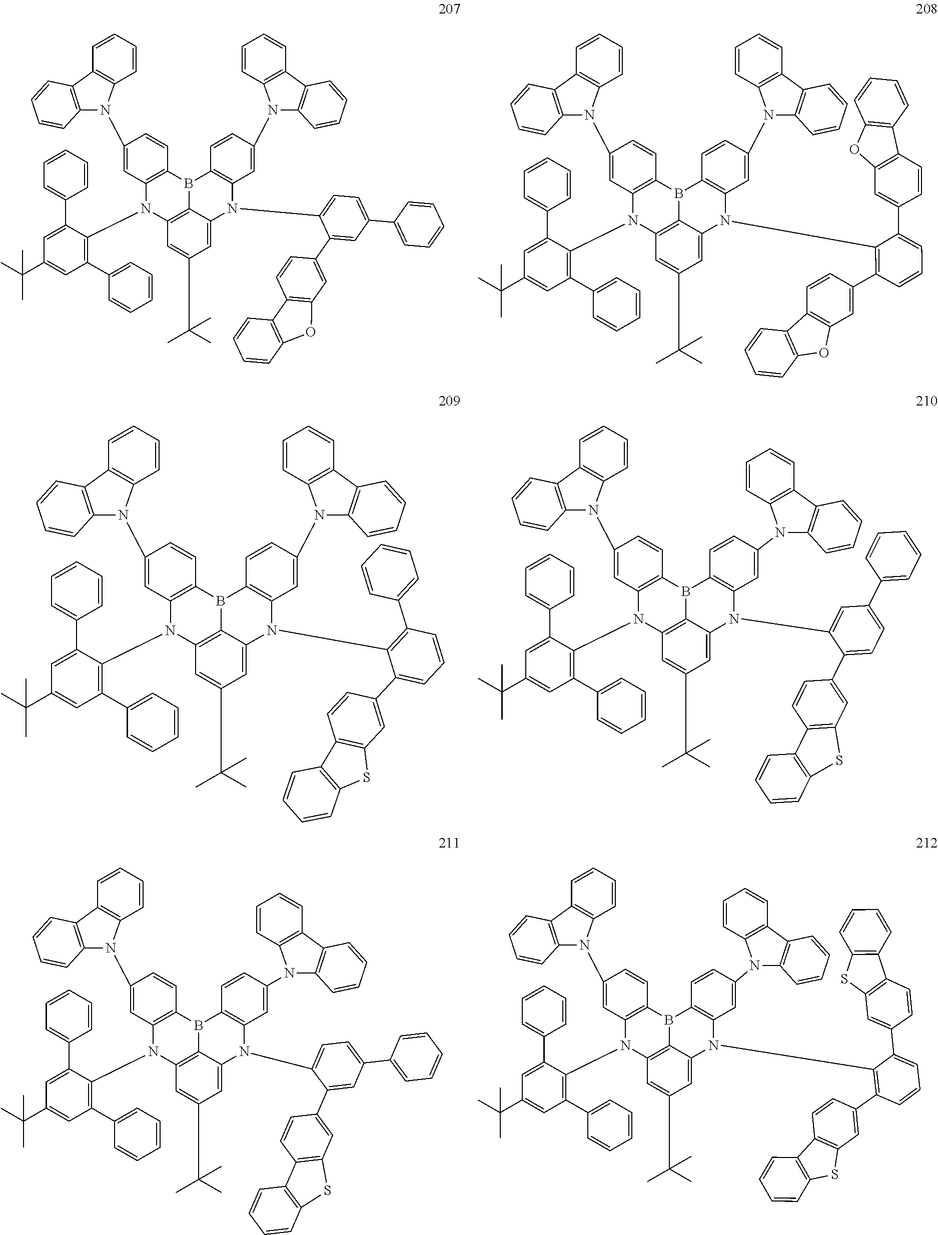 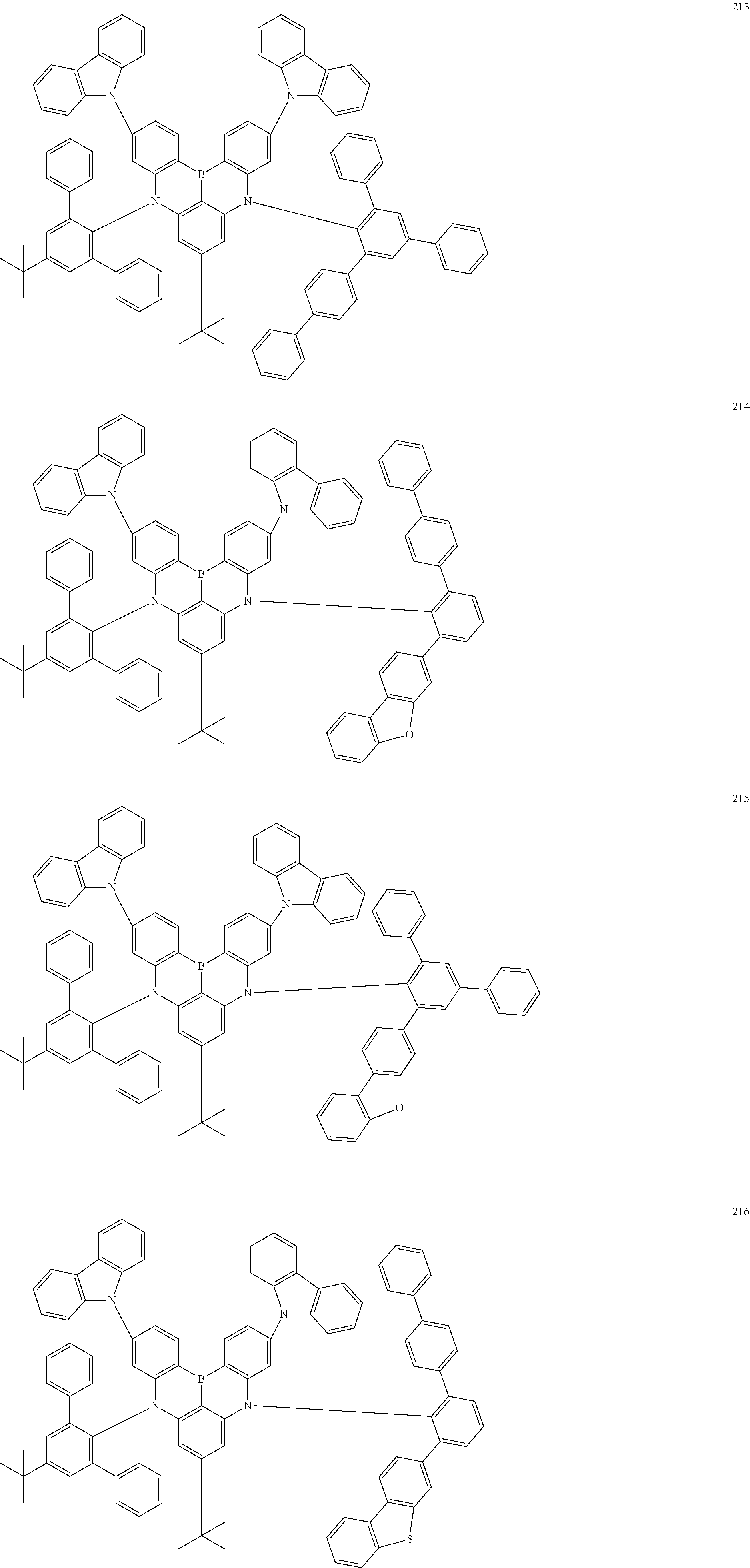 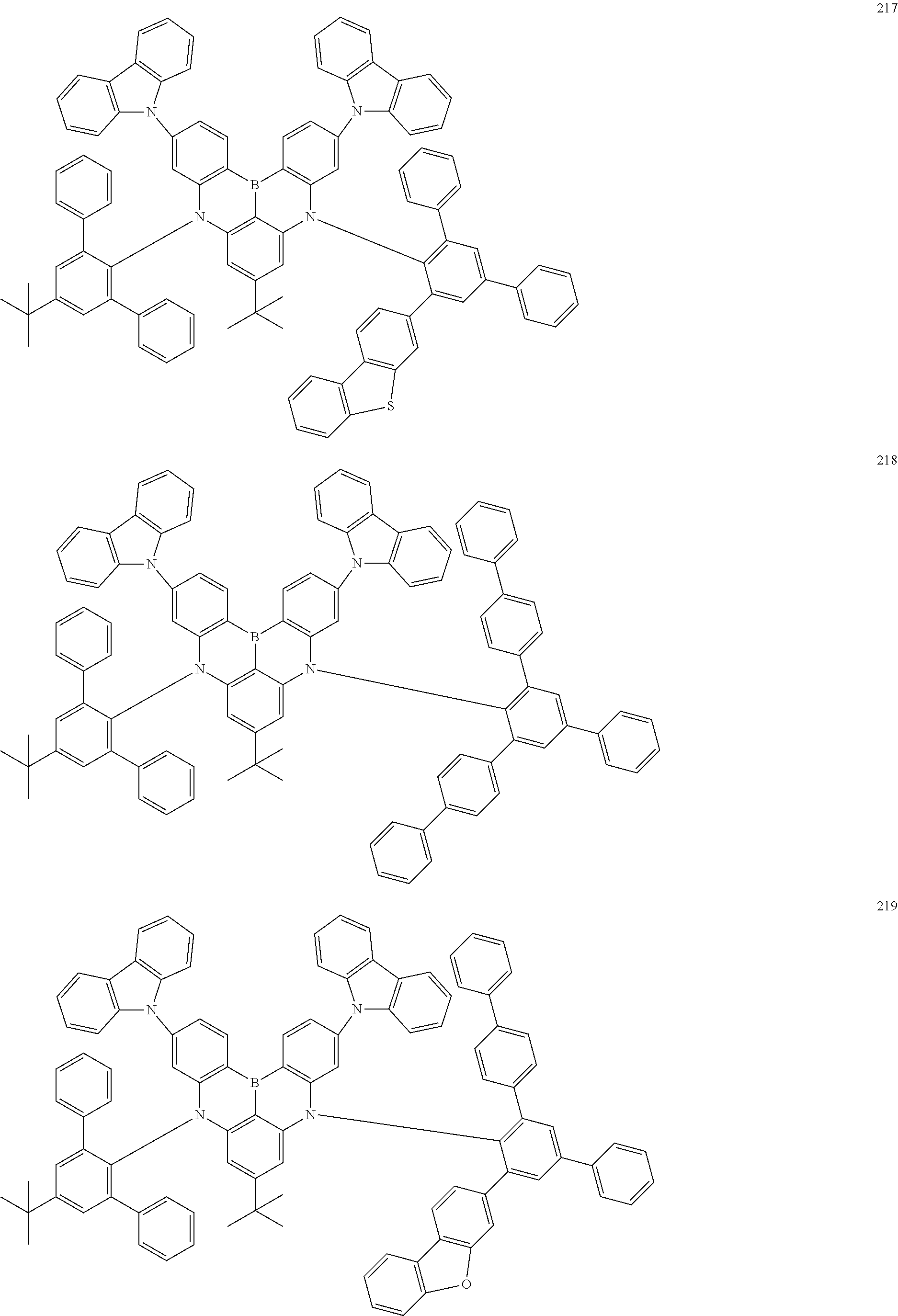 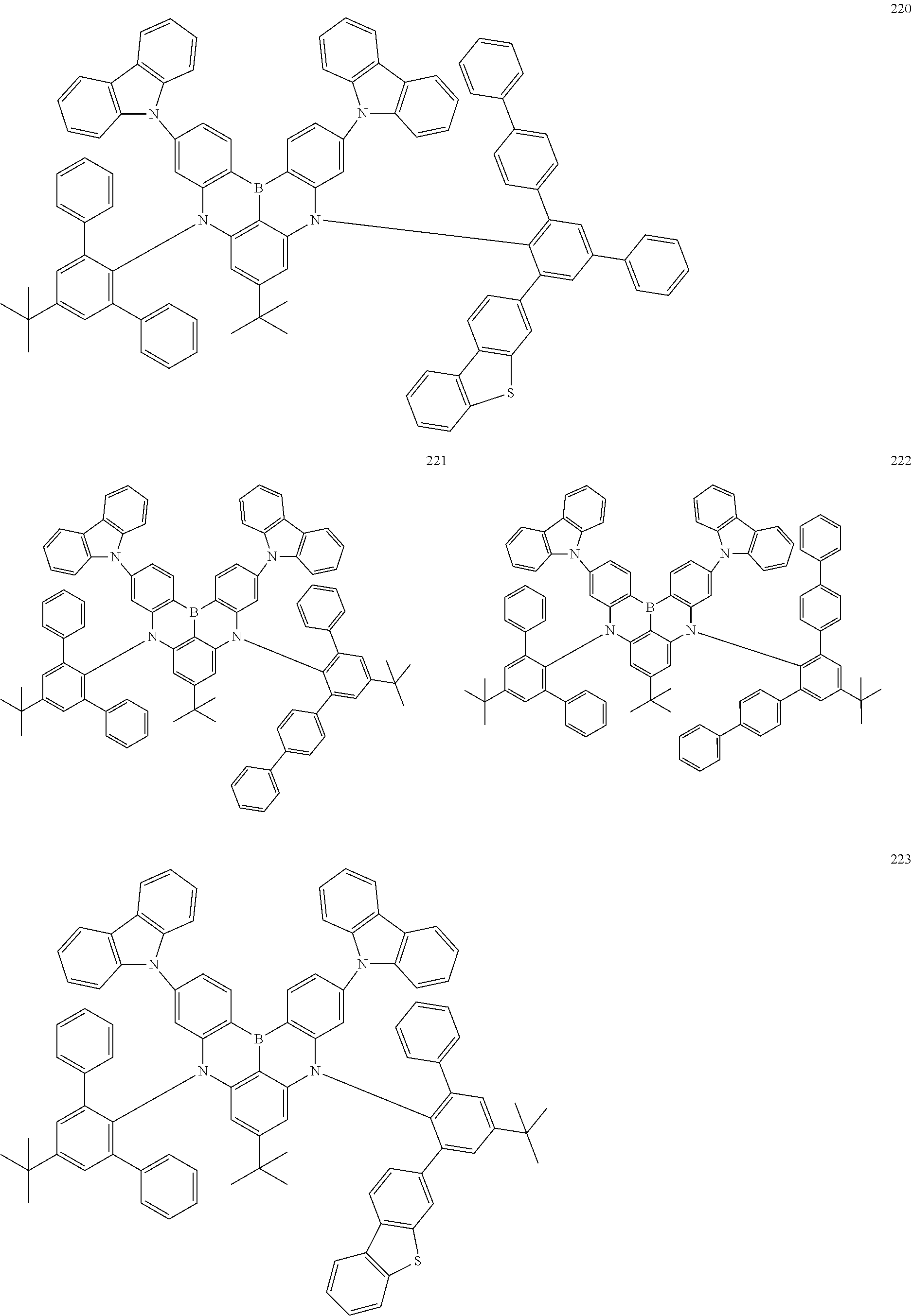 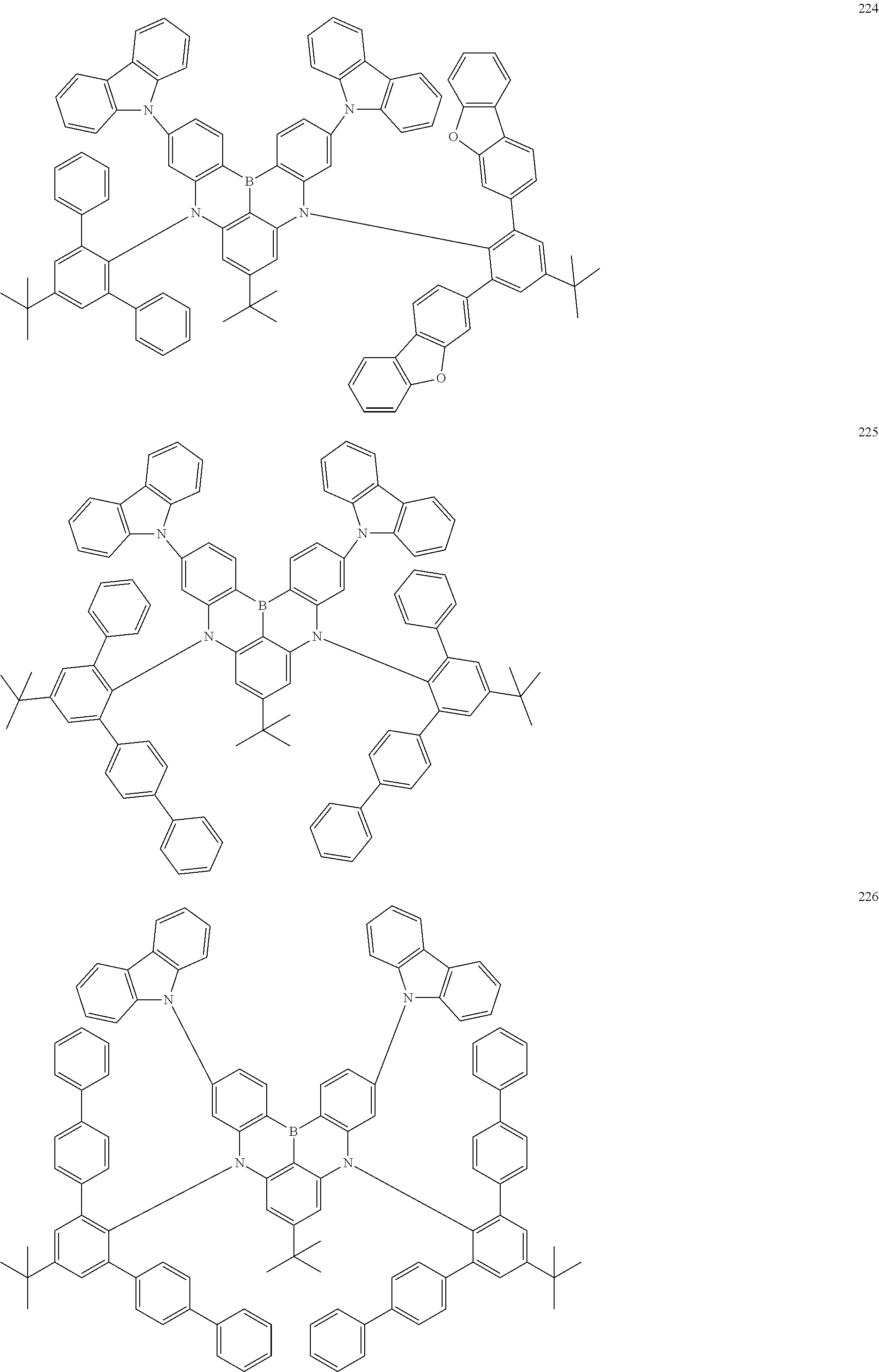 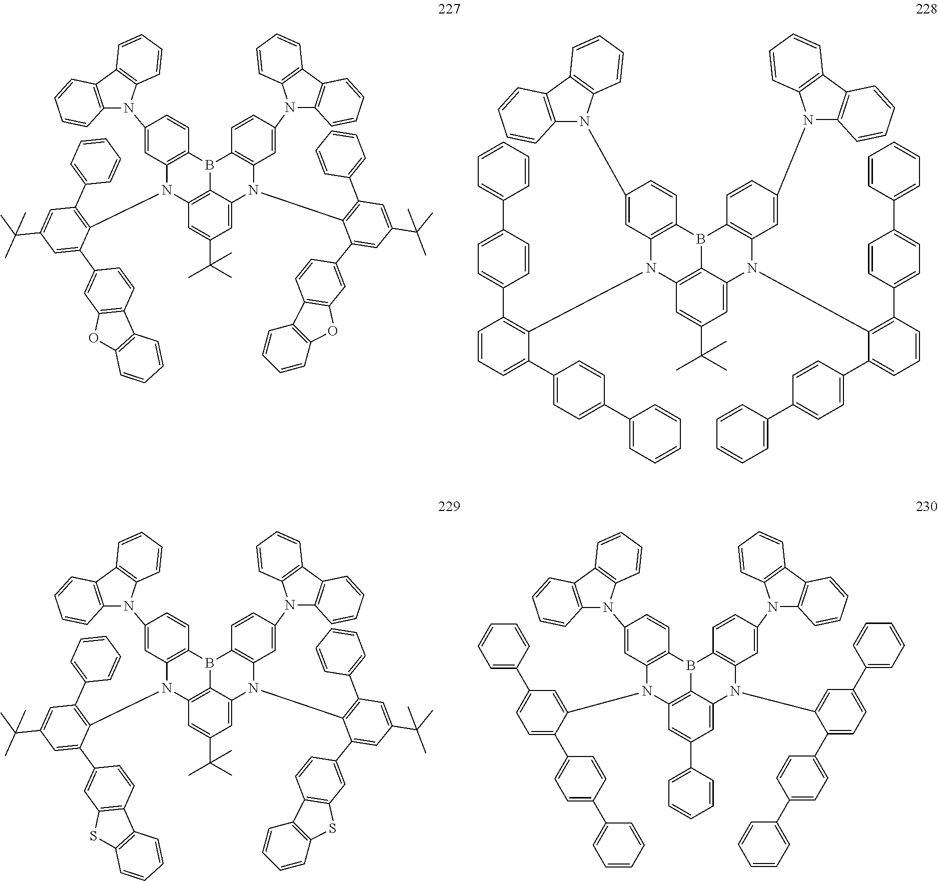 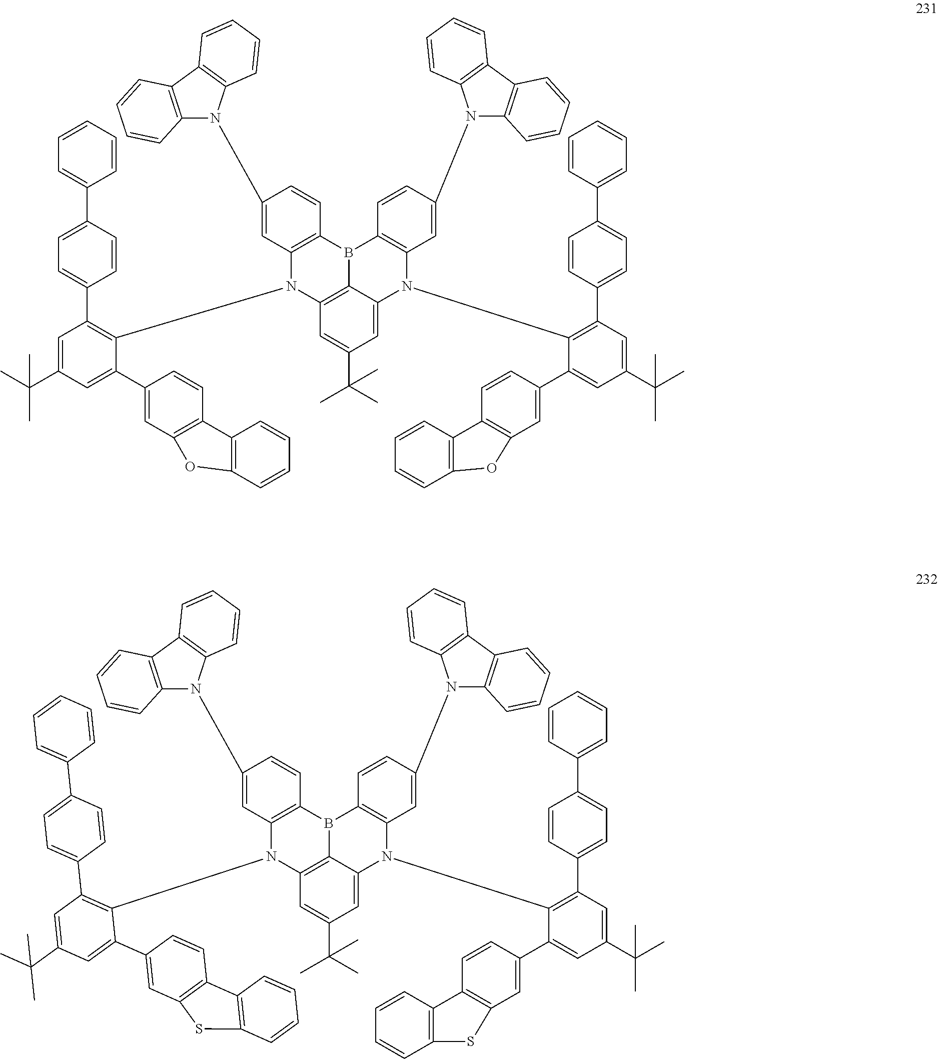 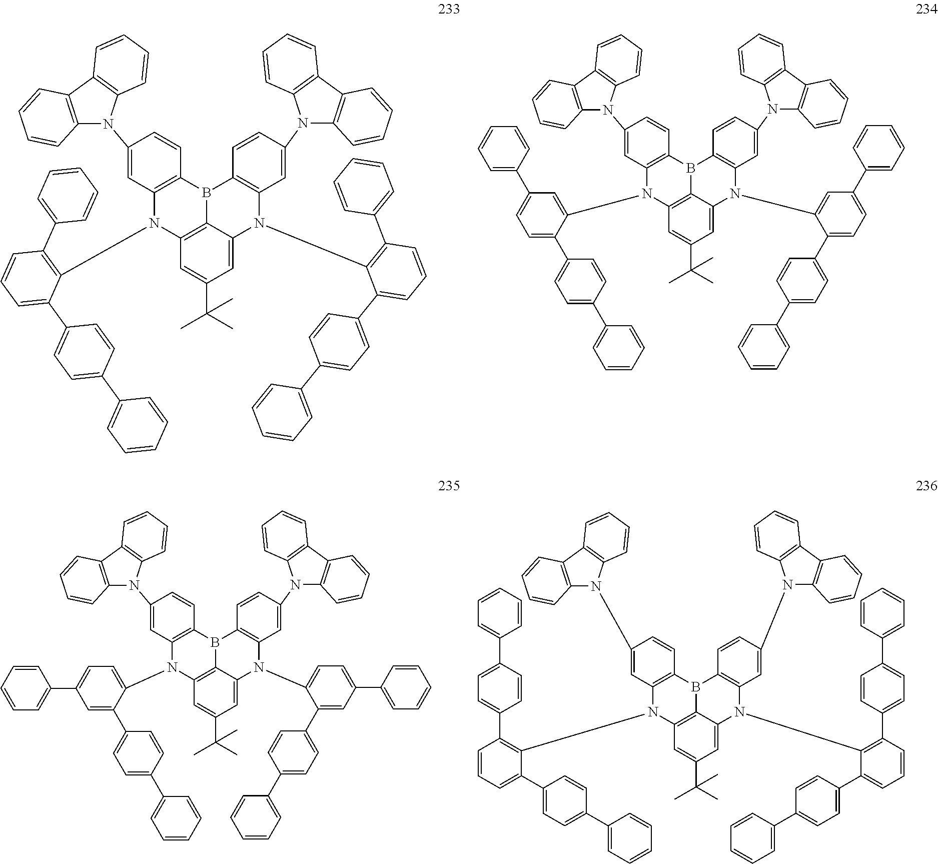 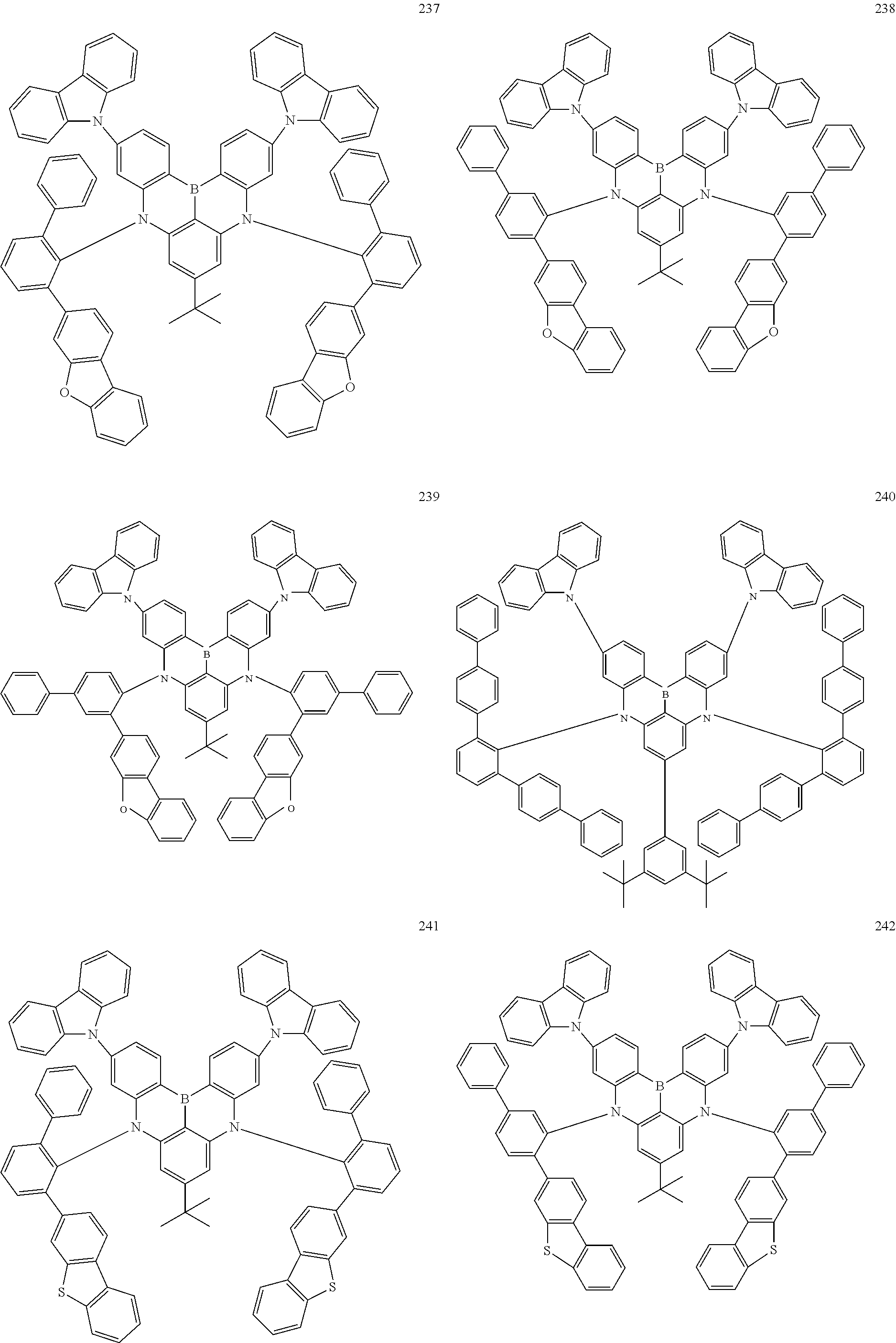 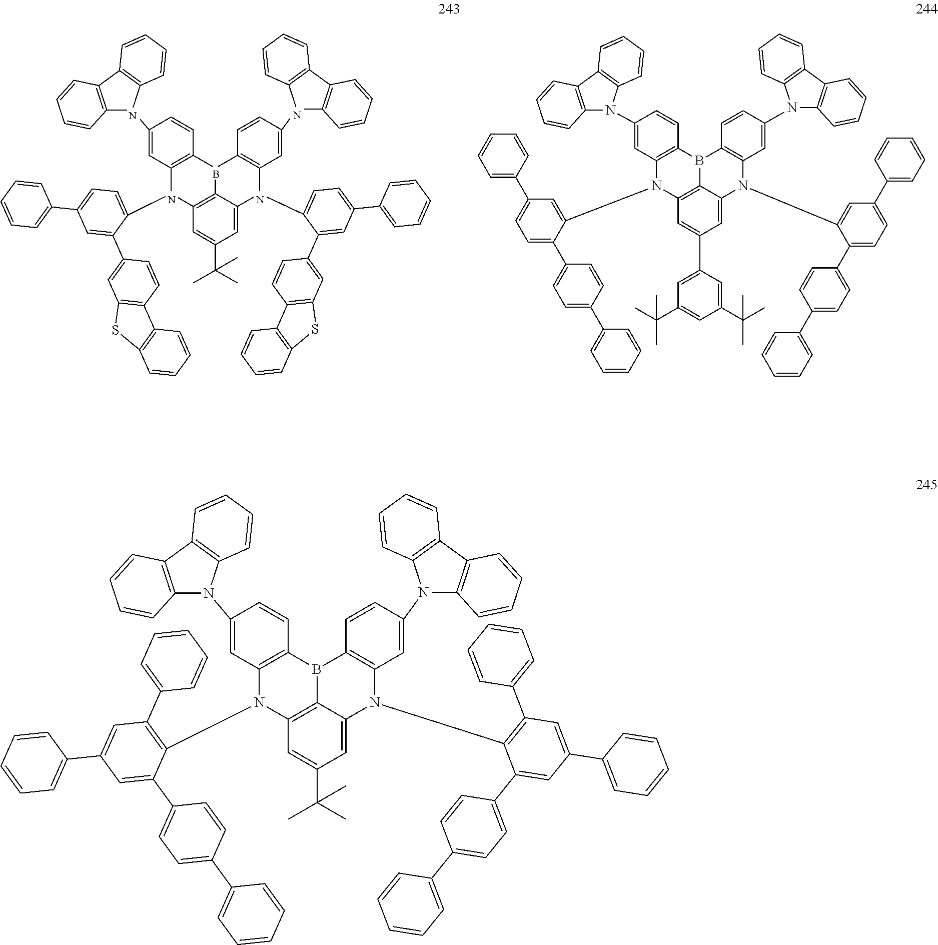 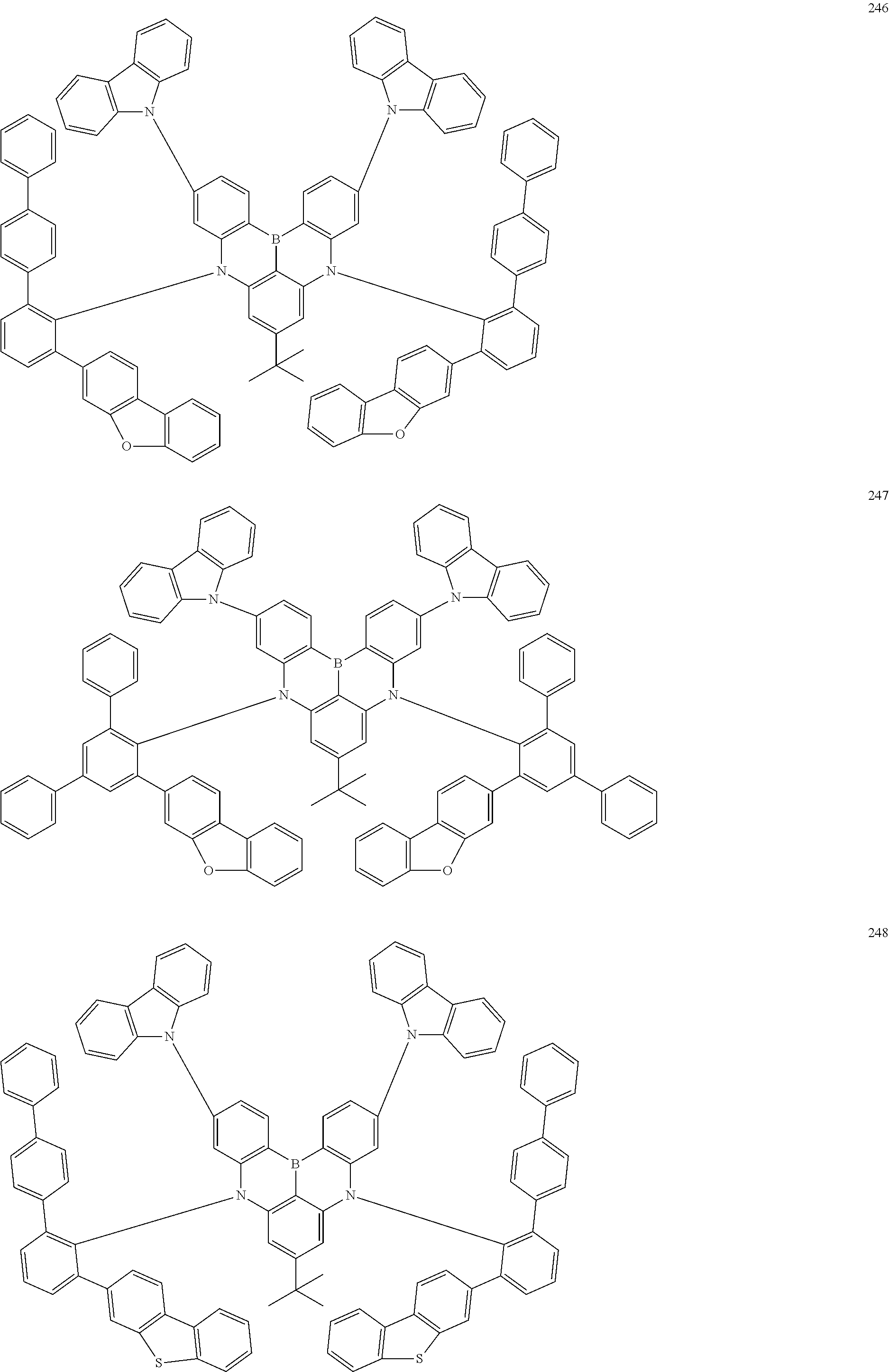 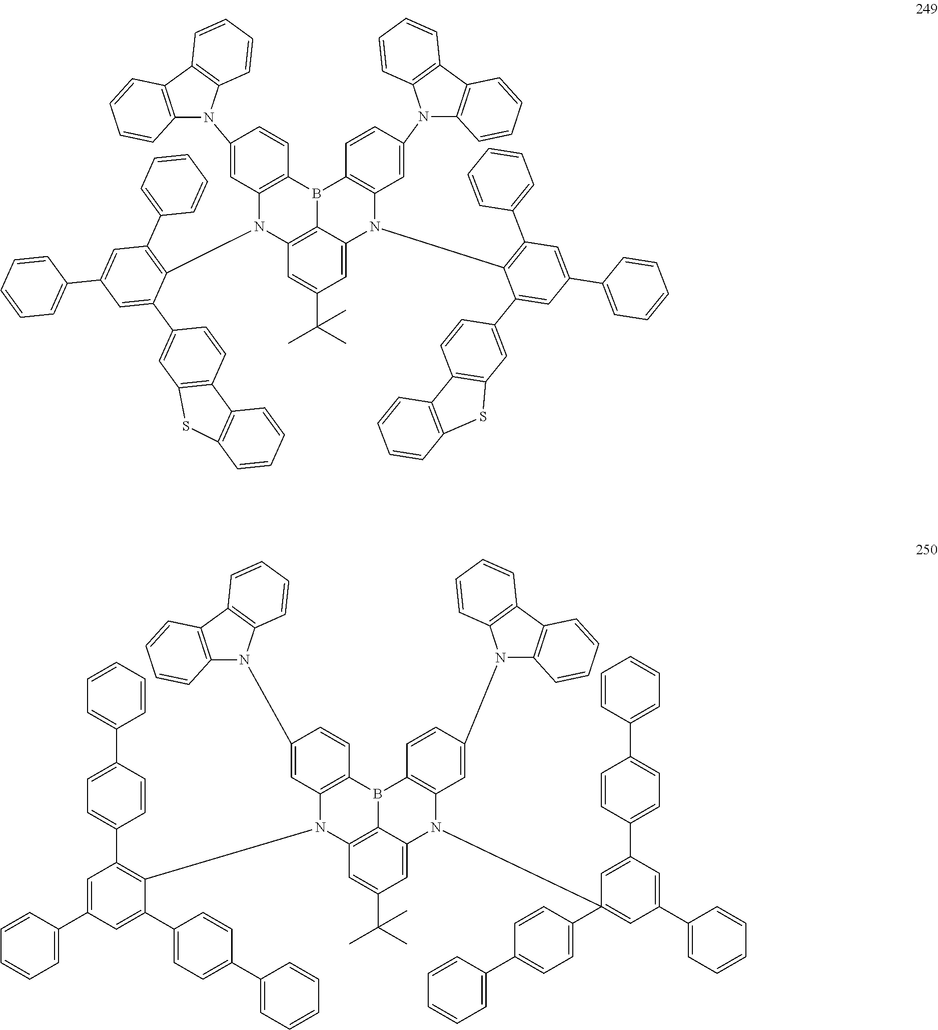 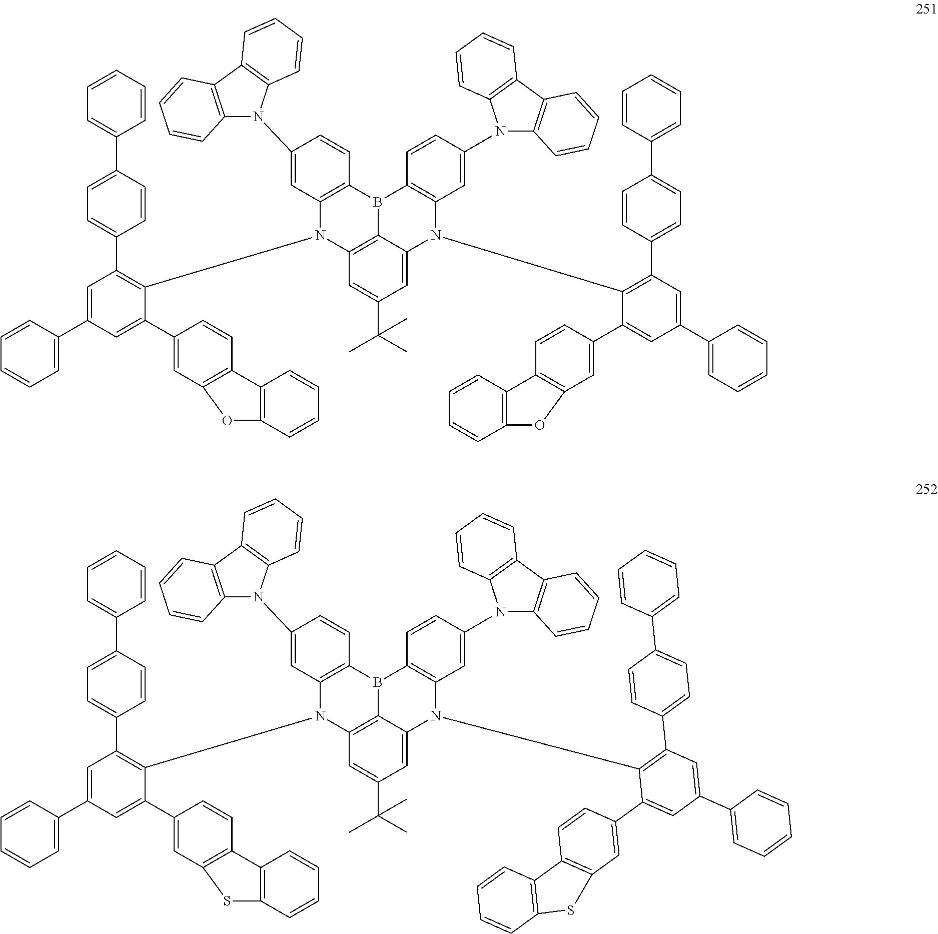 [SMILES: CC(C)(C)c1cc2c3c(c1)N(c1c(-c4ccc(-c5ccccc5)cc4)cc(-c4ccccc4)cc1-c1ccc4c(c1)oc1ccccc14)c1cc(-n4c5ccccc5c5ccccc54)ccc1B3c1ccc(-n3c4ccccc4c4ccccc43)cc1N2c1c(-c2ccc(-c3ccccc3)cc2)cc(-c2ccccc2)cc1-c1ccc2c(c1)oc1ccccc12 ; CC(C)(C)c1cc2c3c(c1)N(c1c(-c4ccc(-c5ccccc5)cc4)cc(-c4ccccc4)cc1-c1ccc4c(c1)sc1ccccc14)c1cc(-n4c5ccccc5c5ccccc54)ccc1B3c1ccc(-n3c4ccccc4c4ccccc43)cc1N2c1c(-c2ccc(-c3ccccc3)cc2)cc(-c2ccccc2)cc1-c1ccc2c(c1)sc1ccccc12] 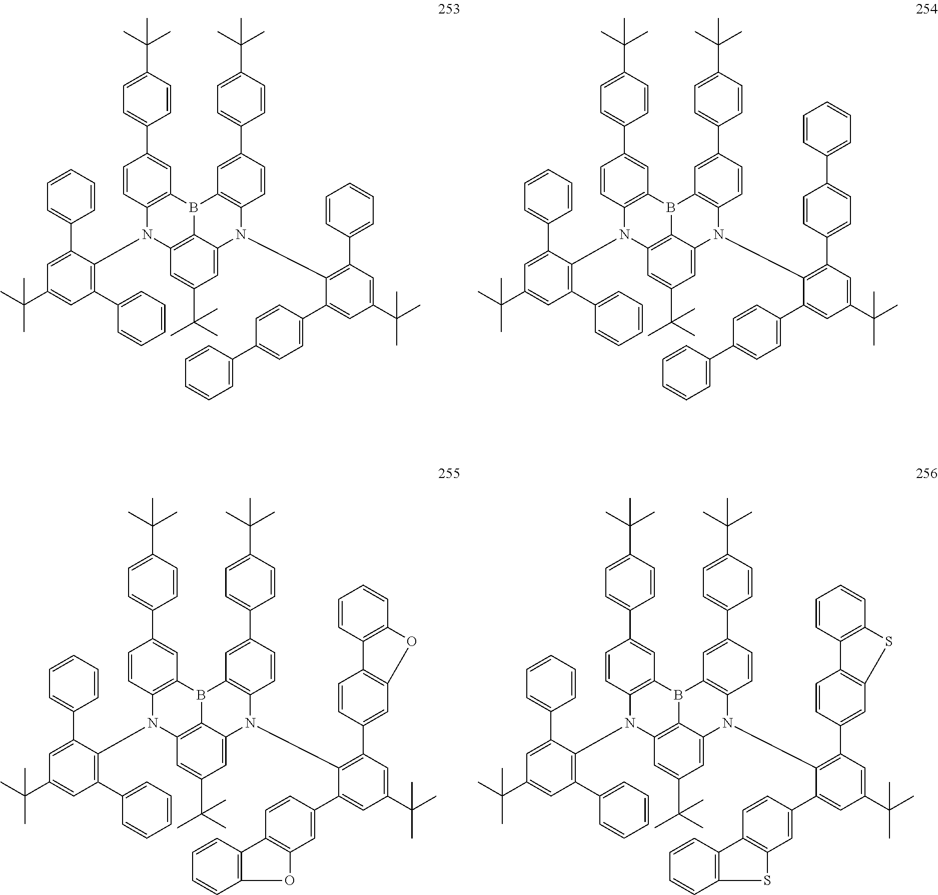 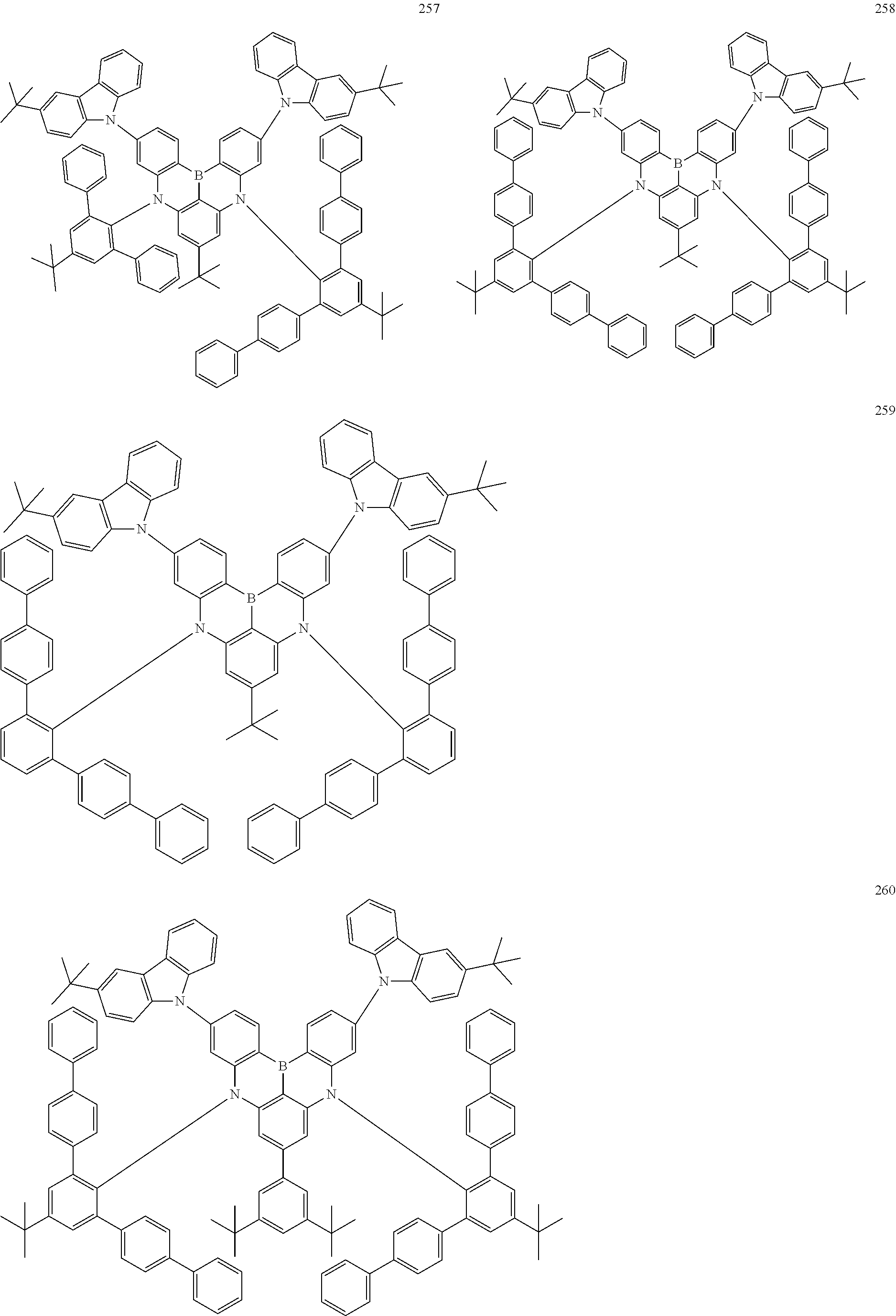 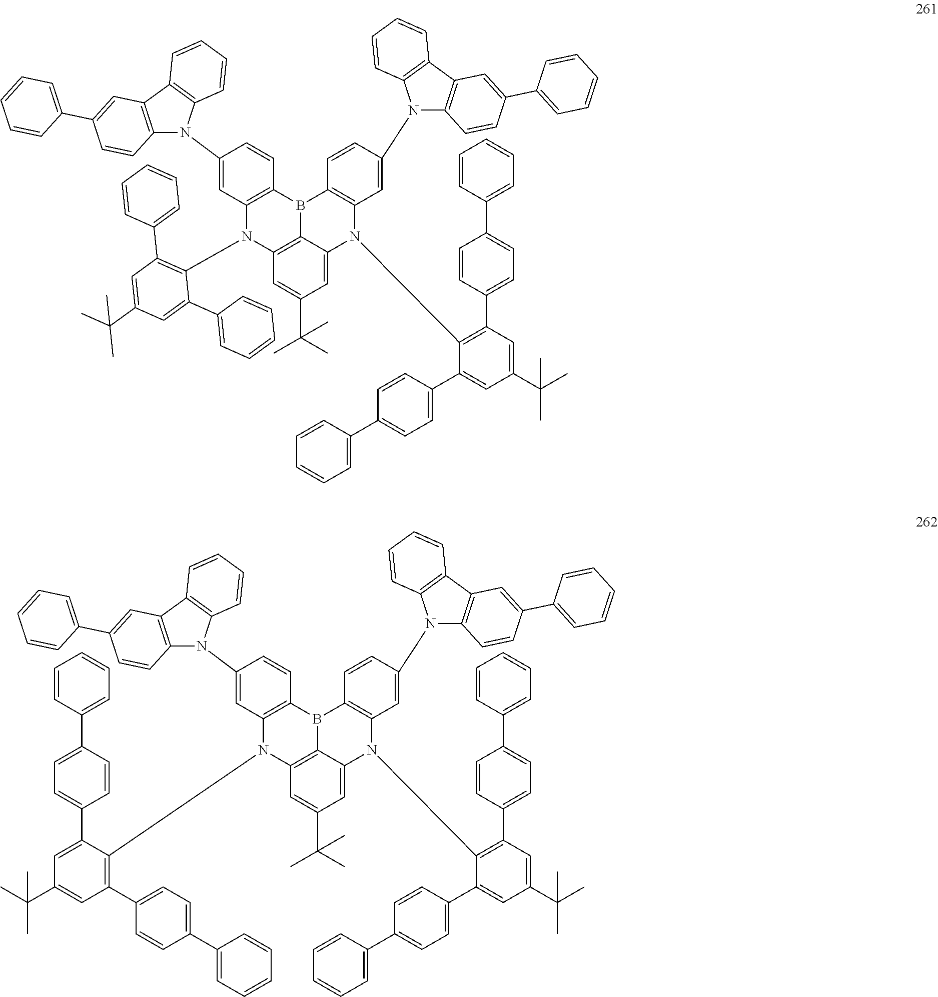 [SMILES: CC(C)(C)c1cc(-c2ccccc2)c(N2c3cc(-n4c5ccccc5c5cc(-c6ccccc6)ccc54)ccc3B3c4ccc(-n5c6ccccc6c6cc(-c7ccccc7)ccc65)cc4N(c4c(-c5ccc(-c6ccccc6)cc5)cc(C(C)(C)C)cc4-c4ccc(-c5ccccc5)cc4)c4cc(C(C)(C)C)cc2c43)c(-c2ccccc2)c1 ; CC(C)(C)c1cc(-c2ccc(-c3ccccc3)cc2)c(N2c3cc(-n4c5ccccc5c5cc(-c6ccccc6)ccc54)ccc3B3c4ccc(-n5c6ccccc6c6cc(-c7ccccc7)ccc65)cc4N(c4c(-c5ccc(-c6ccccc6)cc5)cc(C(C)(C)C)cc4-c4ccc(-c5ccccc5)cc4)c4cc(C(C)(C)C)cc2c43)c(-c2ccc(-c3ccccc3)cc2)c1] 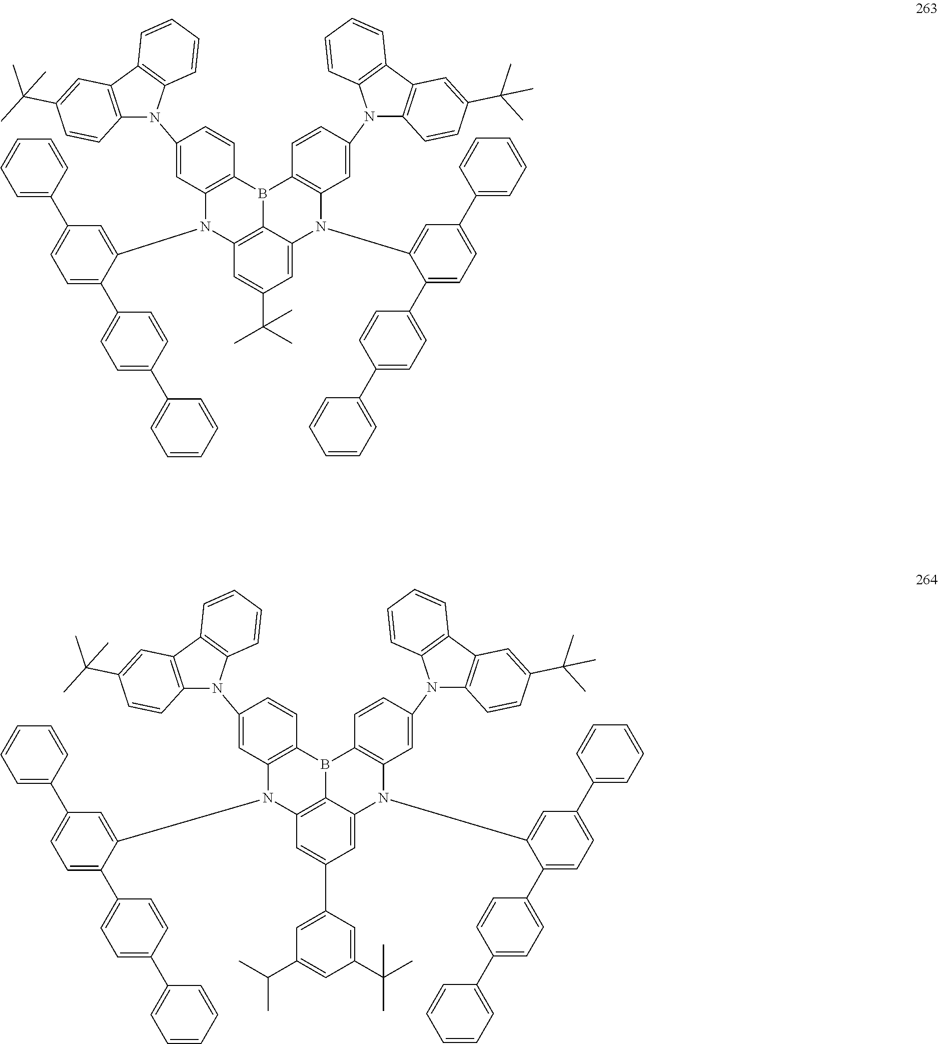 [SMILES: CC(C)(C)c1cc2c3c(c1)N(c1cc(-c4ccccc4)ccc1-c1ccc(-c4ccccc4)cc1)c1cc(-n4c5ccccc5c5cc(C(C)(C)C)ccc54)ccc1B3c1ccc(-n3c4ccccc4c4cc(C(C)(C)C)ccc43)cc1N2c1cc(-c2ccccc2)ccc1-c1ccc(-c2ccccc2)cc1 ; CC(C)c1cc(-c2cc3c4c(c2)N(c2cc(-c5ccccc5)ccc2-c2ccc(-c5ccccc5)cc2)c2cc(-n5c6ccccc6c6cc(C(C)(C)C)ccc65)ccc2B4c2ccc(-n4c5ccccc5c5cc(C(C)(C)C)ccc54)cc2N3c2cc(-c3ccccc3)ccc2-c2ccc(-c3ccccc3)cc2)cc(C(C)(C)C)c1] 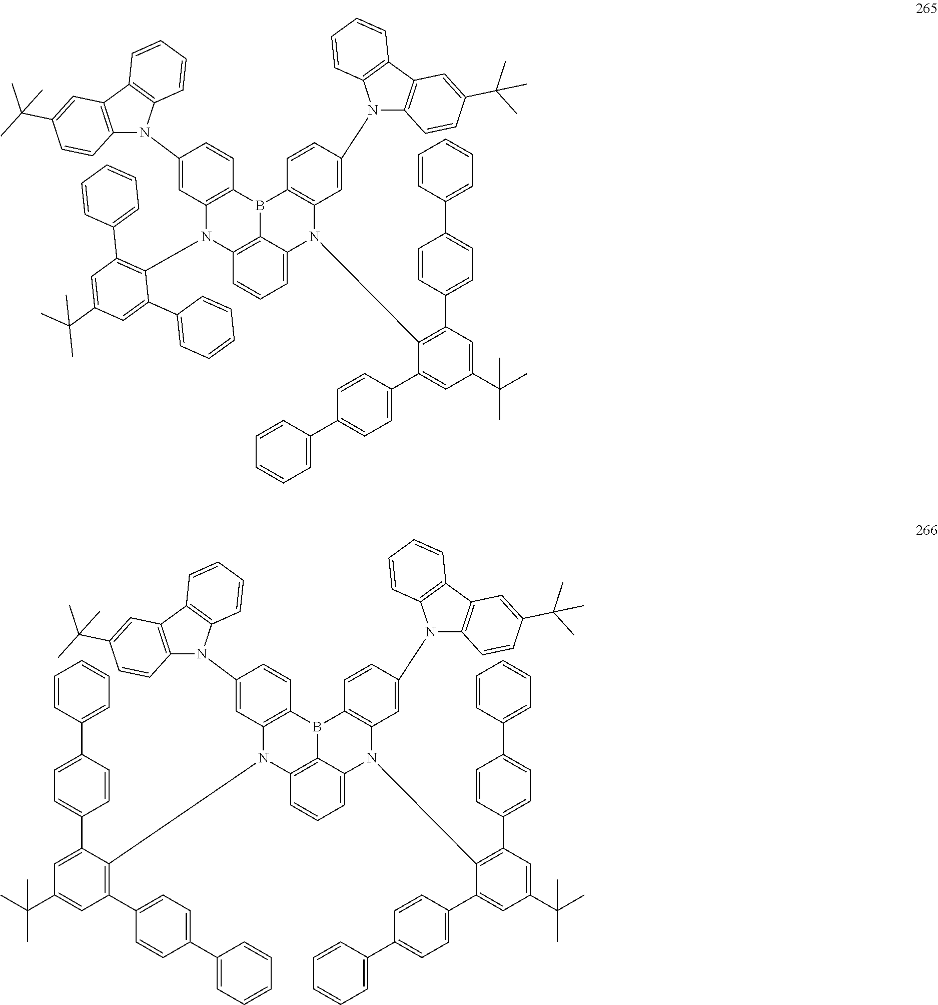 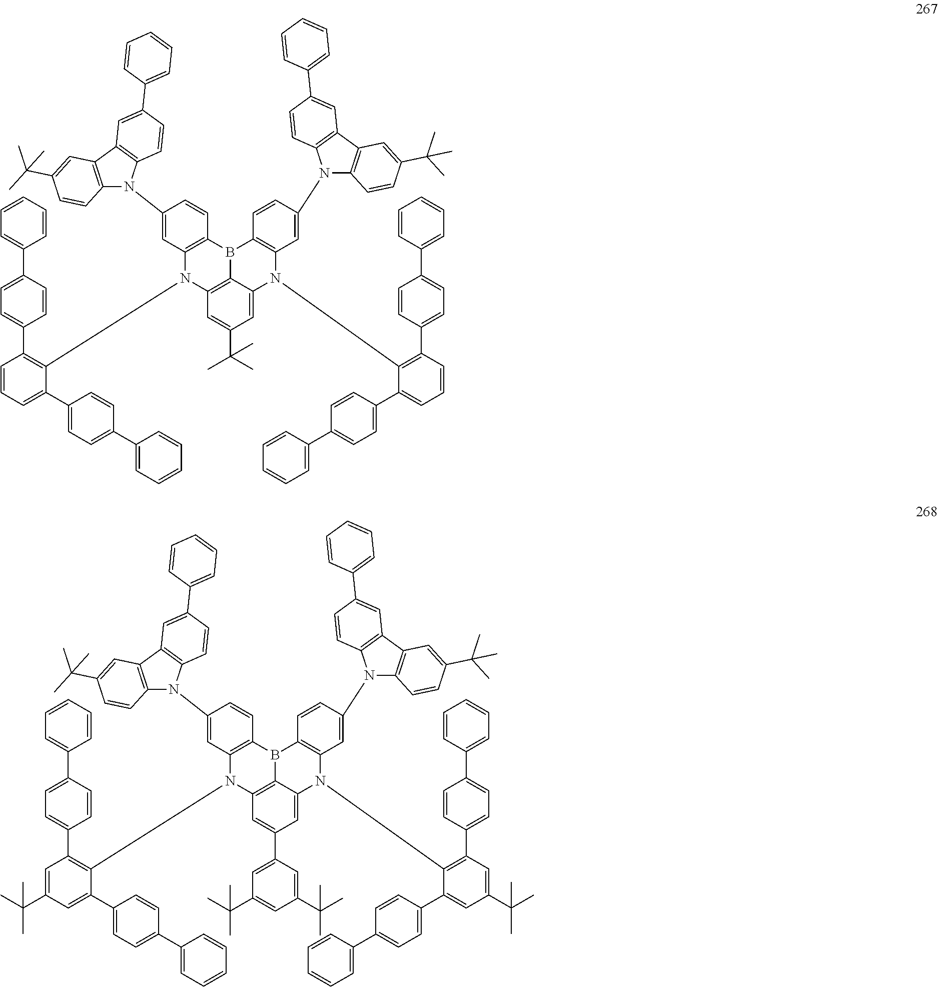 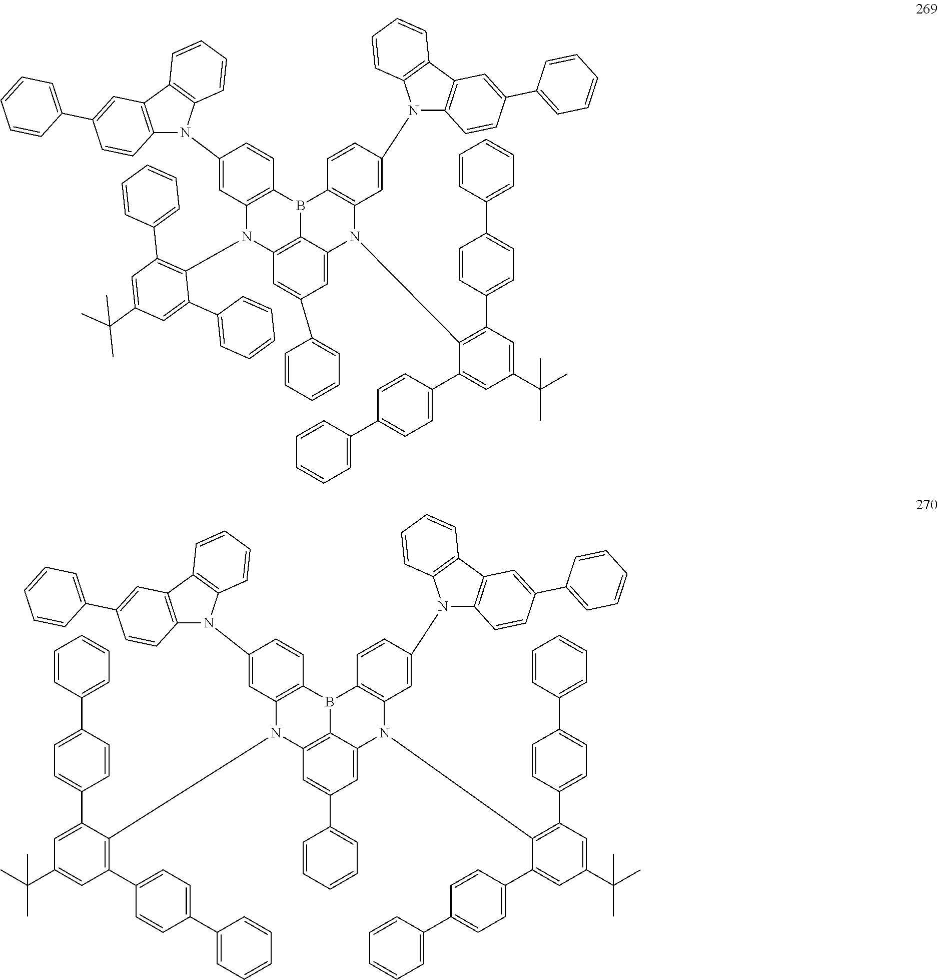 [SMILES: CC(C)(C)c1cc(-c2ccccc2)c(N2c3cc(-n4c5ccccc5c5cc(-c6ccccc6)ccc54)ccc3B3c4ccc(-n5c6ccccc6c6cc(-c7ccccc7)ccc65)cc4N(c4c(-c5ccc(-c6ccccc6)cc5)cc(C(C)(C)C)cc4-c4ccc(-c5ccccc5)cc4)c4cc(-c5ccccc5)cc2c43)c(-c2ccccc2)c1 ; CC(C)(C)c1cc(-c2ccc(-c3ccccc3)cc2)c(N2c3cc(-n4c5ccccc5c5cc(-c6ccccc6)ccc54)ccc3B3c4ccc(-n5c6ccccc6c6cc(-c7ccccc7)ccc65)cc4N(c4c(-c5ccc(-c6ccccc6)cc5)cc(C(C)(C)C)cc4-c4ccc(-c5ccccc5)cc4)c4cc(-c5ccccc5)cc2c43)c(-c2ccc(-c3ccccc3)cc2)c1] 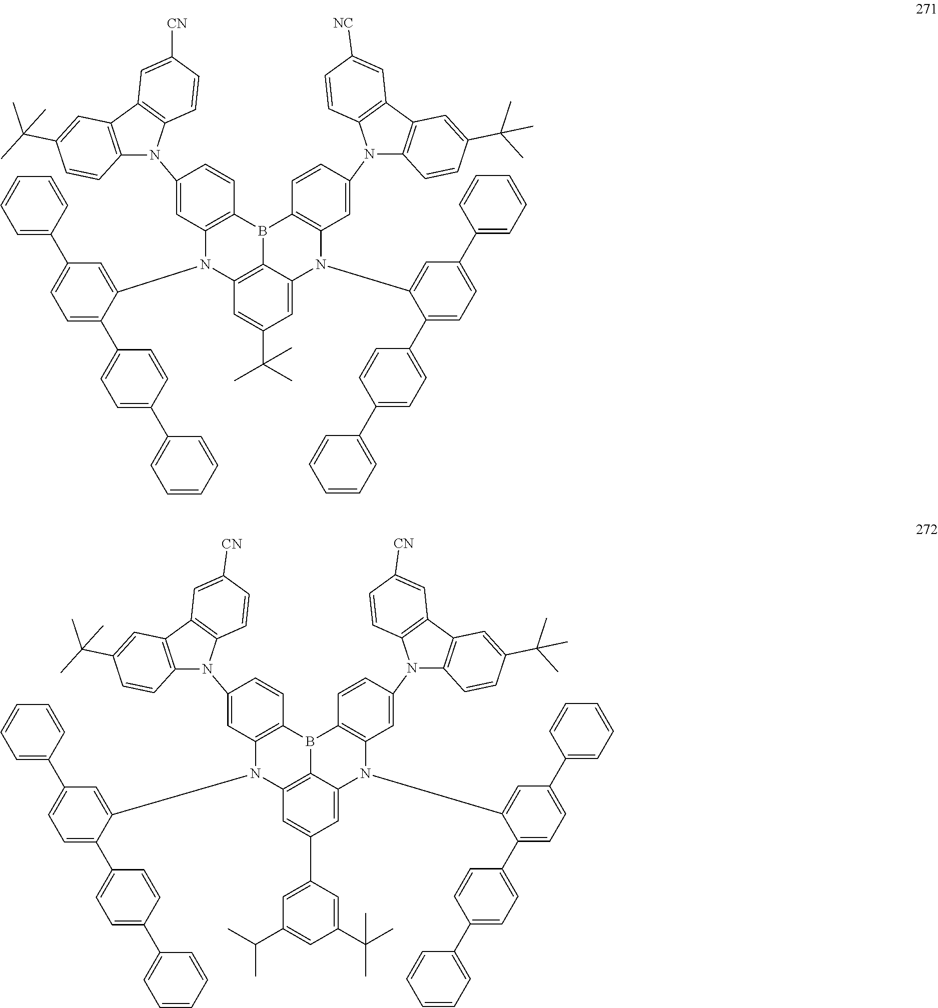 [SMILES: CC(C)(C)c1cc2c3c(c1)N(c1cc(-c4ccccc4)ccc1-c1ccc(-c4ccccc4)cc1)c1cc(-n4c5ccc(C#N)cc5c5cc(C(C)(C)C)ccc54)ccc1B3c1ccc(-n3c4ccc(C#N)cc4c4cc(C(C)(C)C)ccc43)cc1N2c1cc(-c2ccccc2)ccc1-c1ccc(-c2ccccc2)cc1 ; CC(C)c1cc(-c2cc3c4c(c2)N(c2cc(-c5ccccc5)ccc2-c2ccc(-c5ccccc5)cc2)c2cc(-n5c6ccc(C#N)cc6c6cc(C(C)(C)C)ccc65)ccc2B4c2ccc(-n4c5ccc(C#N)cc5c5cc(C(C)(C)C)ccc54)cc2N3c2cc(-c3ccccc3)ccc2-c2ccc(-c3ccccc3)cc2)cc(C(C)(C)C)c1] 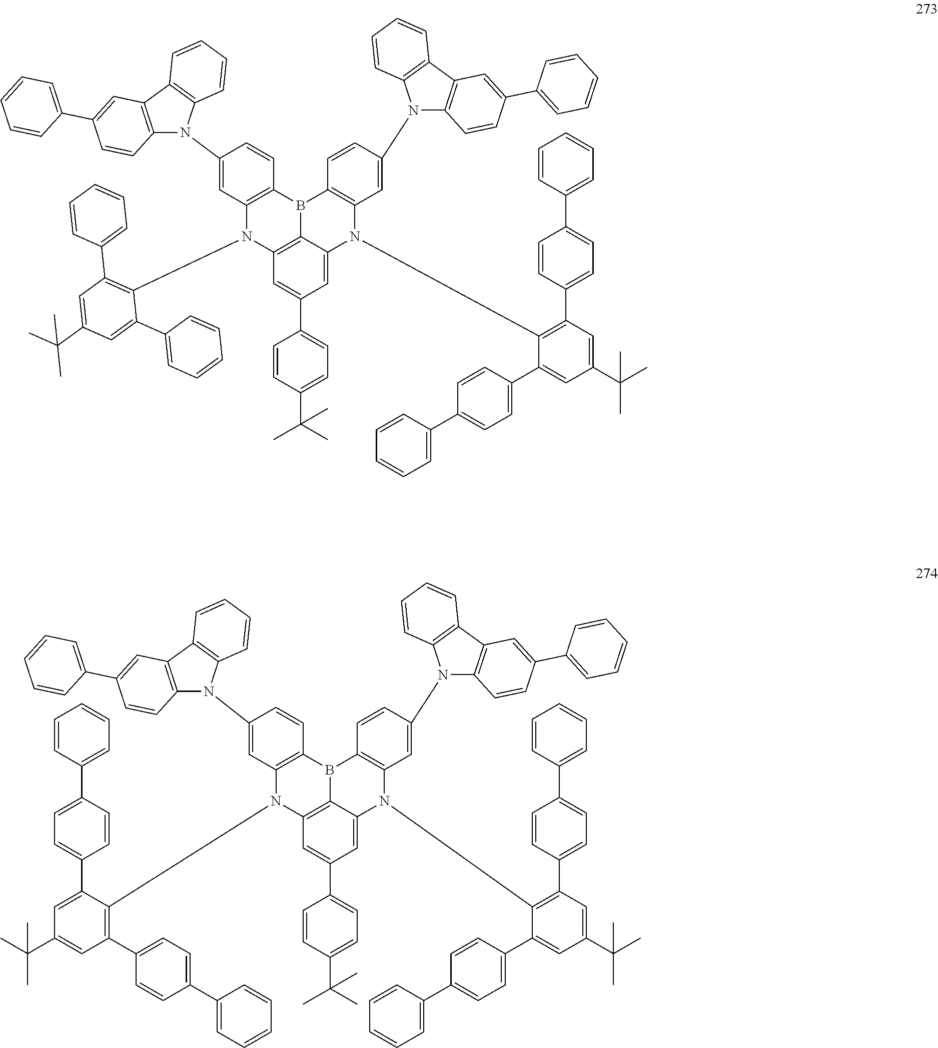 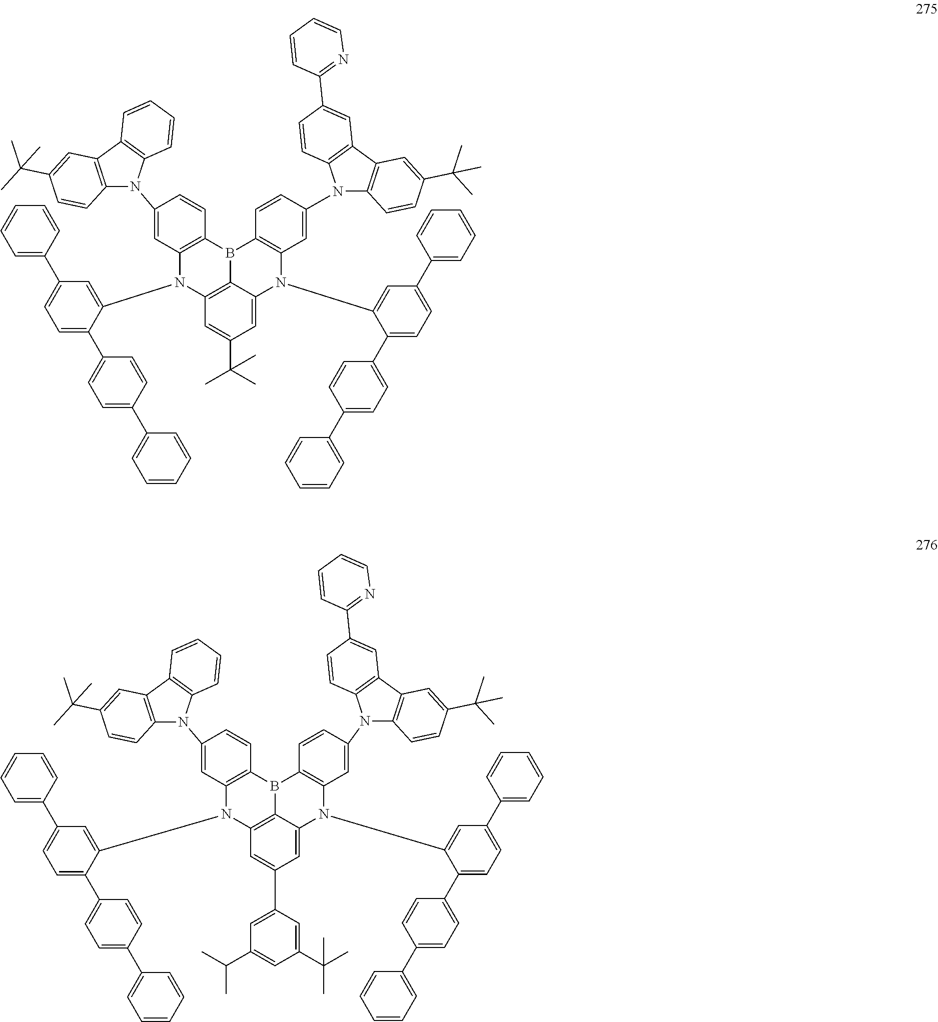 [SMILES: CC(C)(C)c1cc2c3c(c1)N(c1cc(-c4ccccc4)ccc1-c1ccc(-c4ccccc4)cc1)c1cc(-n4c5ccc(-c6ccccn6)cc5c5cc(C(C)(C)C)ccc54)ccc1B3c1ccc(-n3c4ccccc4c4cc(C(C)(C)C)ccc43)cc1N2c1cc(-c2ccccc2)ccc1-c1ccc(-c2ccccc2)cc1 ; CC(C)c1cc(-c2cc3c4c(c2)N(c2cc(-c5ccccc5)ccc2-c2ccc(-c5ccccc5)cc2)c2cc(-n5c6ccc(-c7ccccn7)cc6c6cc(C(C)(C)C)ccc65)ccc2B4c2ccc(-n4c5ccccc5c5cc(C(C)(C)C)ccc54)cc2N3c2cc(-c3ccccc3)ccc2-c2ccc(-c3ccccc3)cc2)cc(C(C)(C)C)c1] 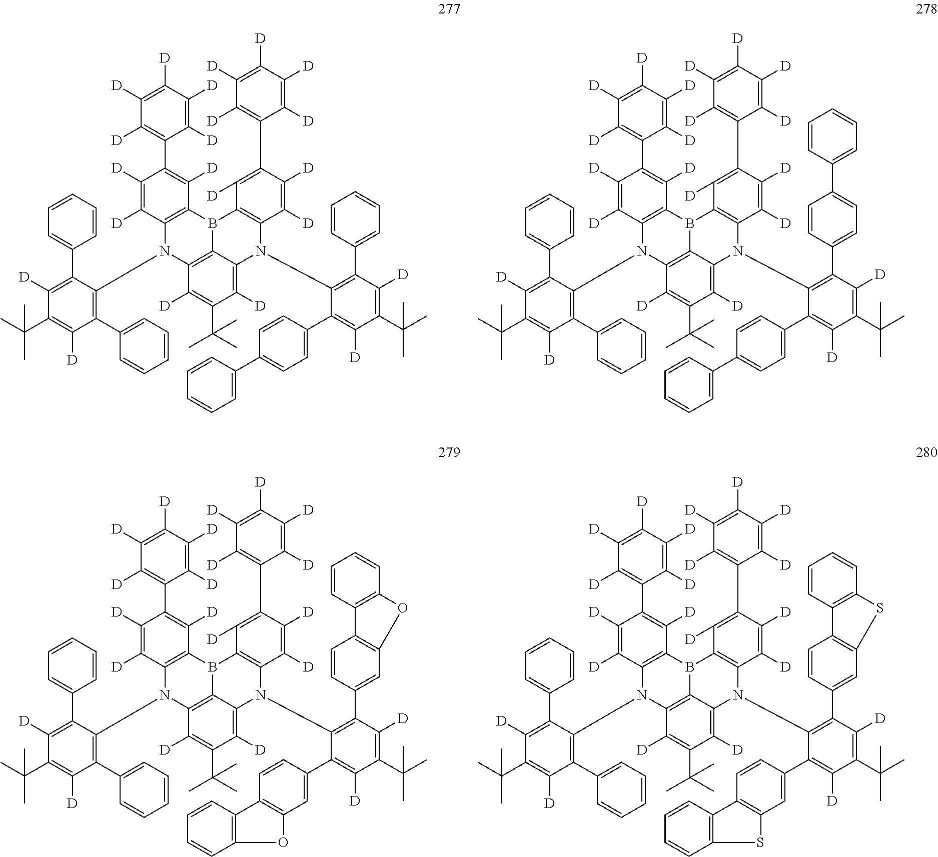 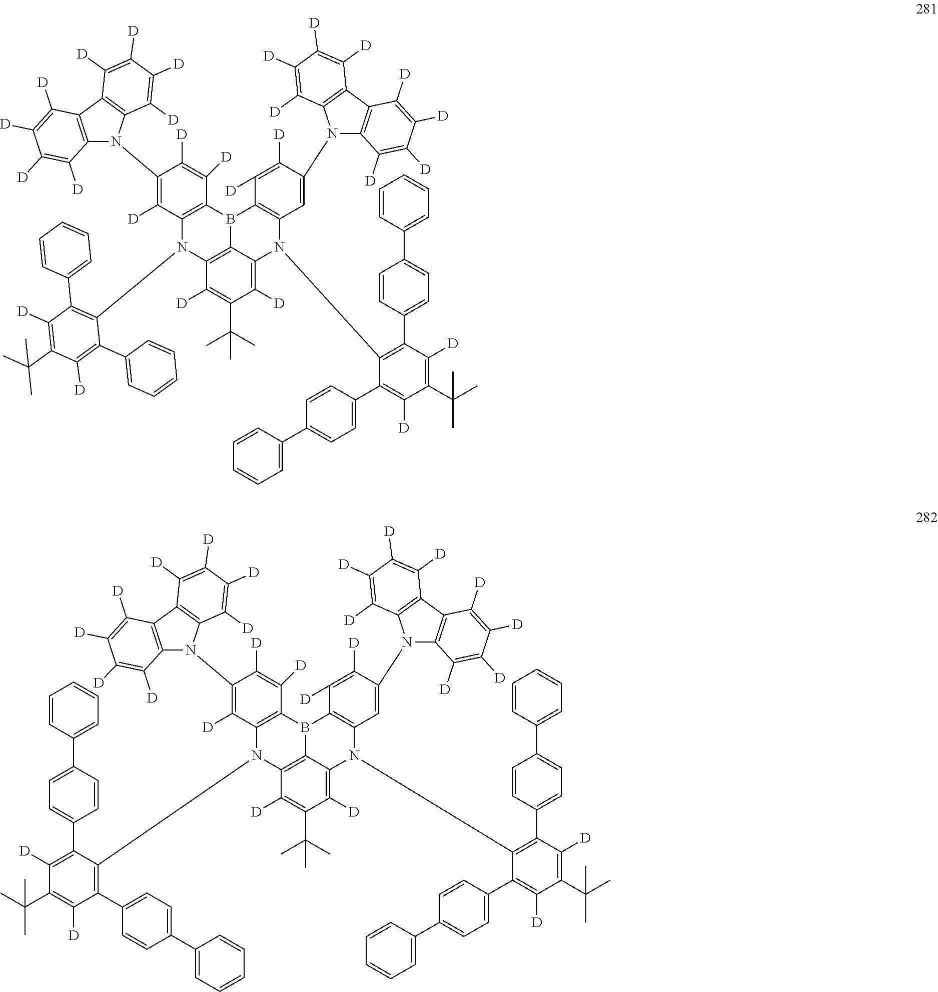 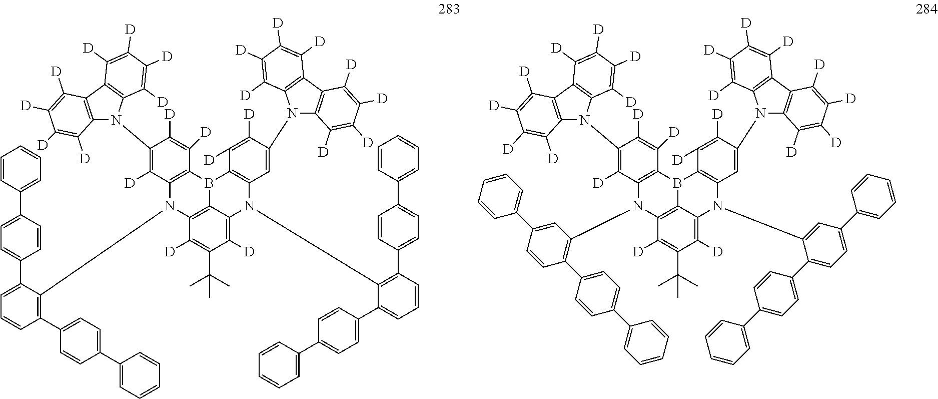 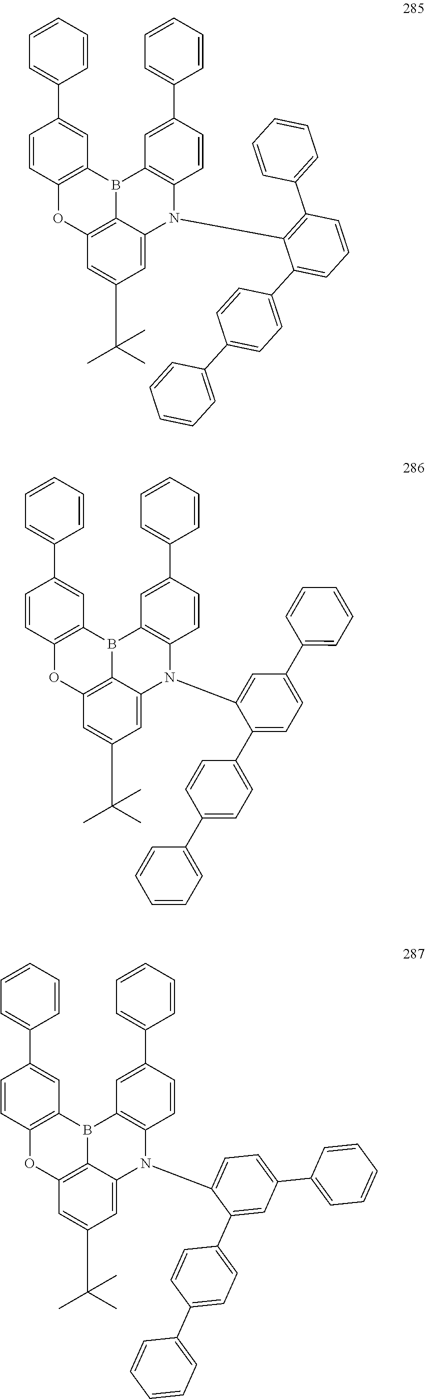 [SMILES: CC(C)(C)c1cc2c3c(c1)N(c1c(-c4ccccc4)cccc1-c1ccc(-c4ccccc4)cc1)c1ccc(-c4ccccc4)cc1B3c1cc(-c3ccccc3)ccc1O2 ; CC(C)(C)c1cc2c3c(c1)N(c1cc(-c4ccccc4)ccc1-c1ccc(-c4ccccc4)cc1)c1ccc(-c4ccccc4)cc1B3c1cc(-c3ccccc3)ccc1O2 ; CC(C)(C)c1cc2c3c(c1)N(c1ccc(-c4ccccc4)cc1-c1ccc(-c4ccccc4)cc1)c1ccc(-c4ccccc4)cc1B3c1cc(-c3ccccc3)ccc1O2] 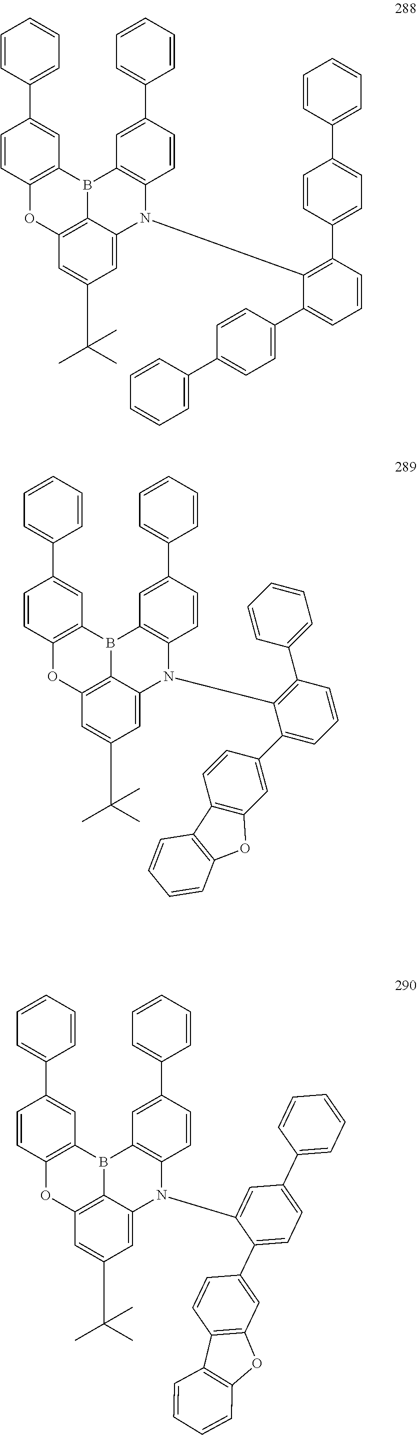 [SMILES: CC(C)(C)c1cc2c3c(c1)N(c1c(-c4ccc(-c5ccccc5)cc4)cccc1-c1ccc(-c4ccccc4)cc1)c1ccc(-c4ccccc4)cc1B3c1cc(-c3ccccc3)ccc1O2 ; CC(C)(C)c1cc2c3c(c1)N(c1c(-c4ccccc4)cccc1-c1ccc4c(c1)oc1ccccc14)c1ccc(-c4ccccc4)cc1B3c1cc(-c3ccccc3)ccc1O2 ; CC(C)(C)c1cc2c3c(c1)N(c1cc(-c4ccccc4)ccc1-c1ccc4c(c1)oc1ccccc14)c1ccc(-c4ccccc4)cc1B3c1cc(-c3ccccc3)ccc1O2] 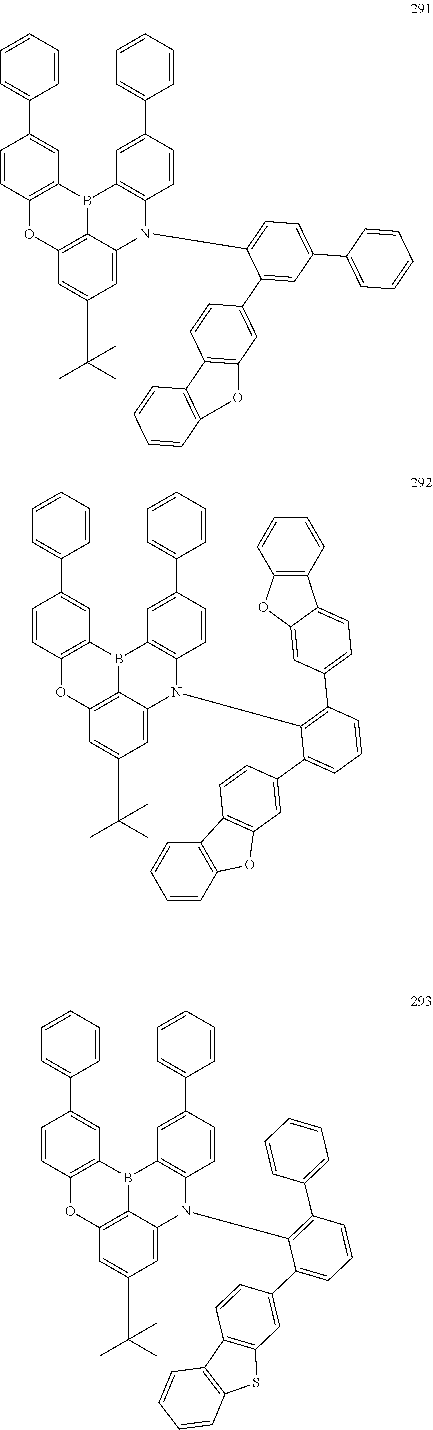 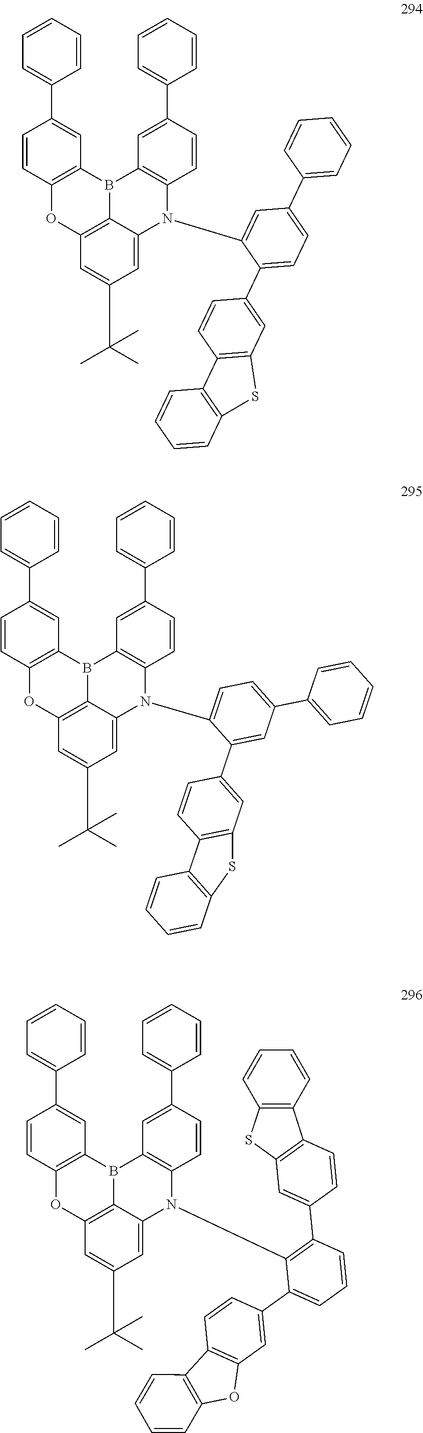 [SMILES: CC(C)(C)c1cc2c3c(c1)N(c1cc(-c4ccccc4)ccc1-c1ccc4c(c1)sc1ccccc14)c1ccc(-c4ccccc4)cc1B3c1cc(-c3ccccc3)ccc1O2 ; CC(C)(C)c1cc2c3c(c1)N(c1ccc(-c4ccccc4)cc1-c1ccc4c(c1)sc1ccccc14)c1ccc(-c4ccccc4)cc1B3c1cc(-c3ccccc3)ccc1O2 ; CC(C)(C)c1cc2c3c(c1)N(c1c(-c4ccc5c(c4)oc4ccccc45)cccc1-c1ccc4c(c1)sc1ccccc14)c1ccc(-c4ccccc4)cc1B3c1cc(-c3ccccc3)ccc1O2] 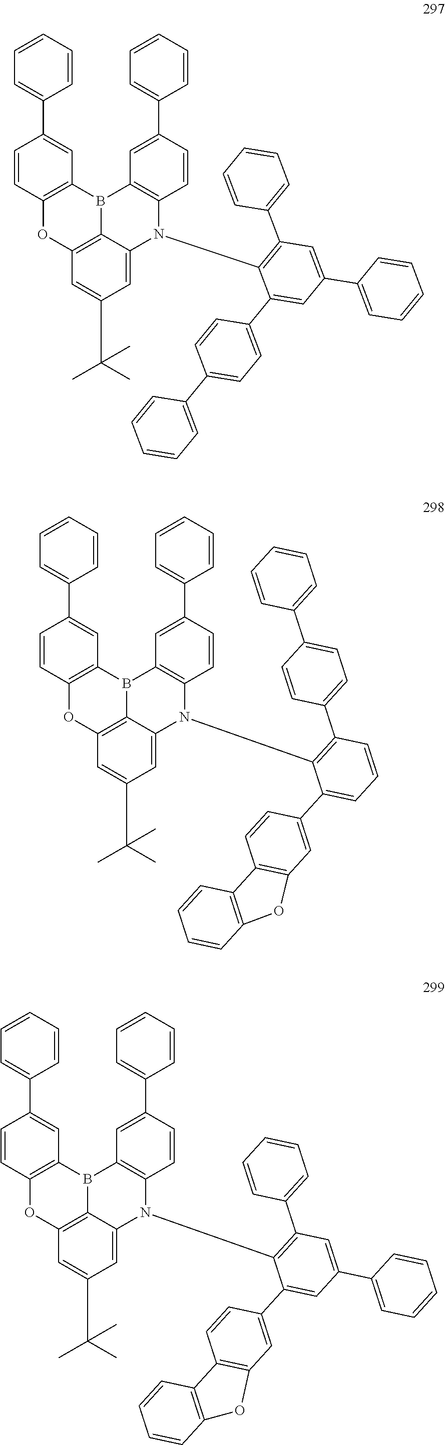 [SMILES: CC(C)(C)c1cc2c3c(c1)N(c1c(-c4ccccc4)cc(-c4ccccc4)cc1-c1ccc(-c4ccccc4)cc1)c1ccc(-c4ccccc4)cc1B3c1cc(-c3ccccc3)ccc1O2 ; CC(C)(C)c1cc2c3c(c1)N(c1c(-c4ccc(-c5ccccc5)cc4)cccc1-c1ccc4c(c1)oc1ccccc14)c1ccc(-c4ccccc4)cc1B3c1cc(-c3ccccc3)ccc1O2 ; CC(C)(C)c1cc2c3c(c1)N(c1c(-c4ccccc4)cc(-c4ccccc4)cc1-c1ccc4c(c1)oc1ccccc14)c1ccc(-c4ccccc4)cc1B3c1cc(-c3ccccc3)ccc1O2] 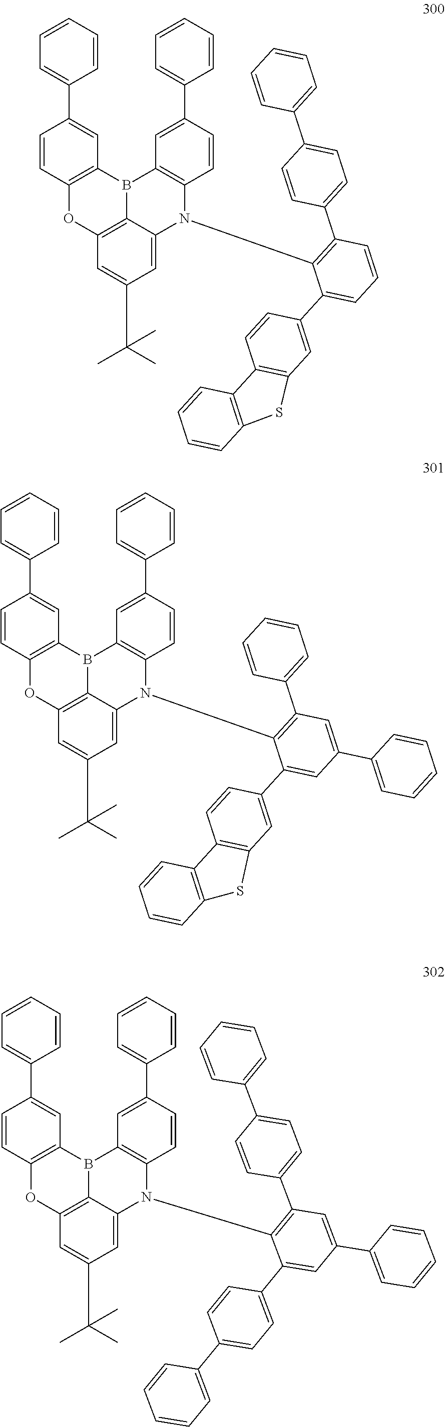 [SMILES: CC(C)(C)c1cc2c3c(c1)N(c1c(-c4ccc(-c5ccccc5)cc4)cccc1-c1ccc4c(c1)sc1ccccc14)c1ccc(-c4ccccc4)cc1B3c1cc(-c3ccccc3)ccc1O2 ; CC(C)(C)c1cc2c3c(c1)N(c1c(-c4ccccc4)cc(-c4ccccc4)cc1-c1ccc4c(c1)sc1ccccc14)c1ccc(-c4ccccc4)cc1B3c1cc(-c3ccccc3)ccc1O2 ; CC(C)(C)c1cc2c3c(c1)N(c1c(-c4ccc(-c5ccccc5)cc4)cc(-c4ccccc4)cc1-c1ccc(-c4ccccc4)cc1)c1ccc(-c4ccccc4)cc1B3c1cc(-c3ccccc3)ccc1O2] 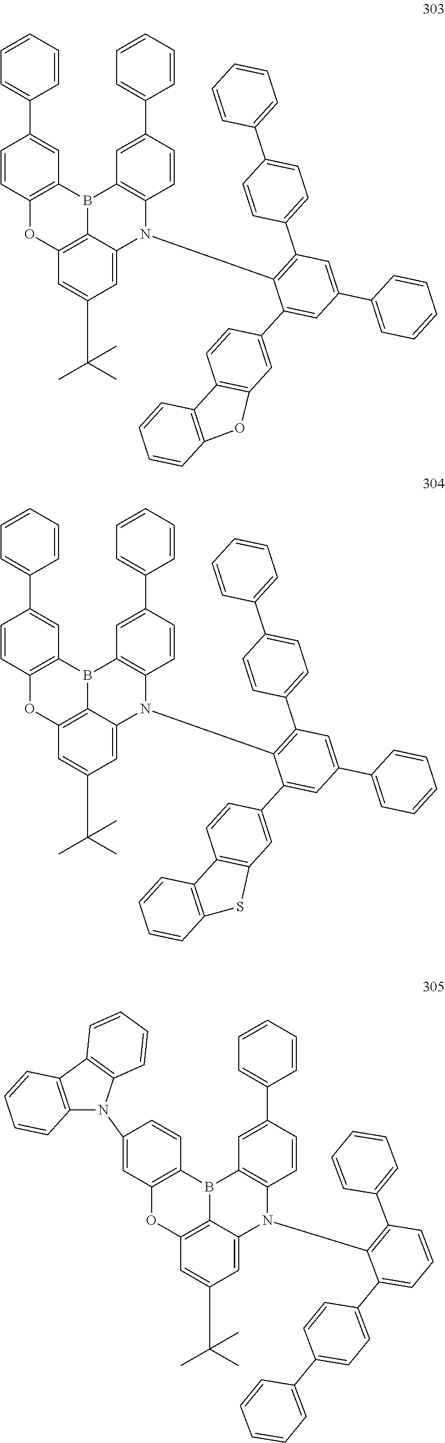 [SMILES: CC(C)(C)c1cc2c3c(c1)N(c1c(-c4ccc(-c5ccccc5)cc4)cc(-c4ccccc4)cc1-c1ccc4c(c1)oc1ccccc14)c1ccc(-c4ccccc4)cc1B3c1cc(-c3ccccc3)ccc1O2 ; CC(C)(C)c1cc2c3c(c1)N(c1c(-c4ccc(-c5ccccc5)cc4)cc(-c4ccccc4)cc1-c1ccc4c(c1)sc1ccccc14)c1ccc(-c4ccccc4)cc1B3c1cc(-c3ccccc3)ccc1O2 ; CC(C)(C)c1cc2c3c(c1)N(c1c(-c4ccccc4)cccc1-c1ccc(-c4ccccc4)cc1)c1ccc(-c4ccccc4)cc1B3c1ccc(-n3c4ccccc4c4ccccc43)cc1O2] 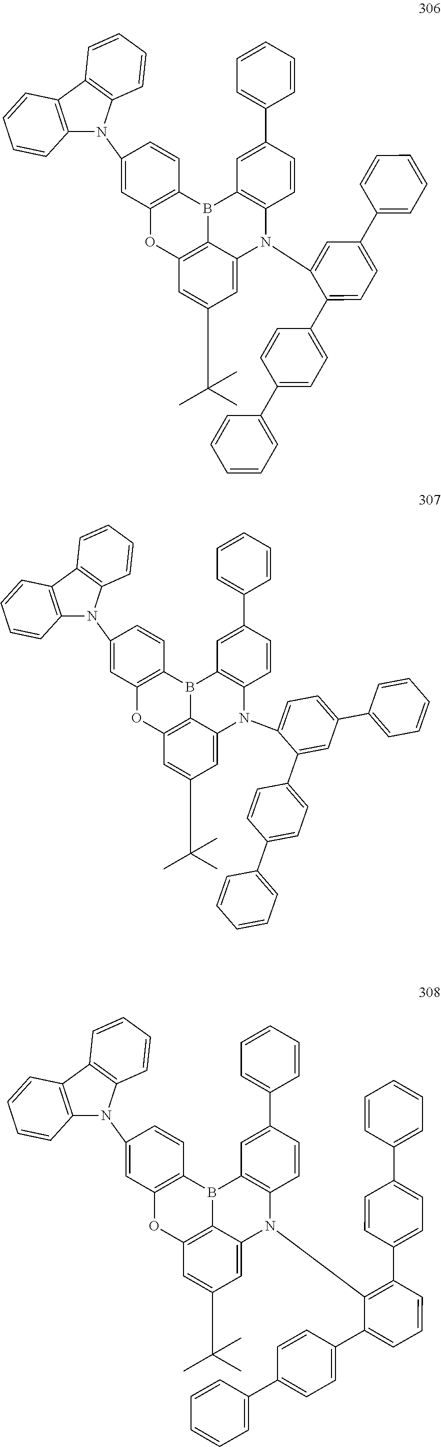 [SMILES: CC(C)(C)c1cc2c3c(c1)N(c1cc(-c4ccccc4)ccc1-c1ccc(-c4ccccc4)cc1)c1ccc(-c4ccccc4)cc1B3c1ccc(-n3c4ccccc4c4ccccc43)cc1O2 ; CC(C)(C)c1cc2c3c(c1)N(c1ccc(-c4ccccc4)cc1-c1ccc(-c4ccccc4)cc1)c1ccc(-c4ccccc4)cc1B3c1ccc(-n3c4ccccc4c4ccccc43)cc1O2 ; CC(C)(C)c1cc2c3c(c1)N(c1c(-c4ccc(-c5ccccc5)cc4)cccc1-c1ccc(-c4ccccc4)cc1)c1ccc(-c4ccccc4)cc1B3c1ccc(-n3c4ccccc4c4ccccc43)cc1O2] 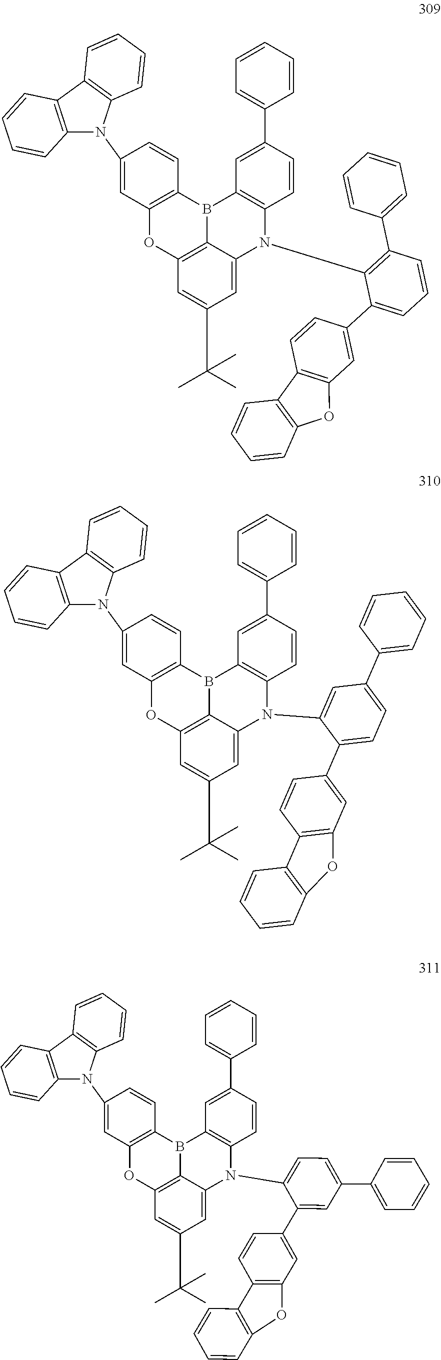 [SMILES: CC(C)(C)c1cc2c3c(c1)N(c1c(-c4ccccc4)cccc1-c1ccc4c(c1)oc1ccccc14)c1ccc(-c4ccccc4)cc1B3c1ccc(-n3c4ccccc4c4ccccc43)cc1O2 ; CC(C)(C)c1cc2c3c(c1)N(c1cc(-c4ccccc4)ccc1-c1ccc4c(c1)oc1ccccc14)c1ccc(-c4ccccc4)cc1B3c1ccc(-n3c4ccccc4c4ccccc43)cc1O2 ; CC(C)(C)c1cc2c3c(c1)N(c1ccc(-c4ccccc4)cc1-c1ccc4c(c1)oc1ccccc14)c1ccc(-c4ccccc4)cc1B3c1ccc(-n3c4ccccc4c4ccccc43)cc1O2] 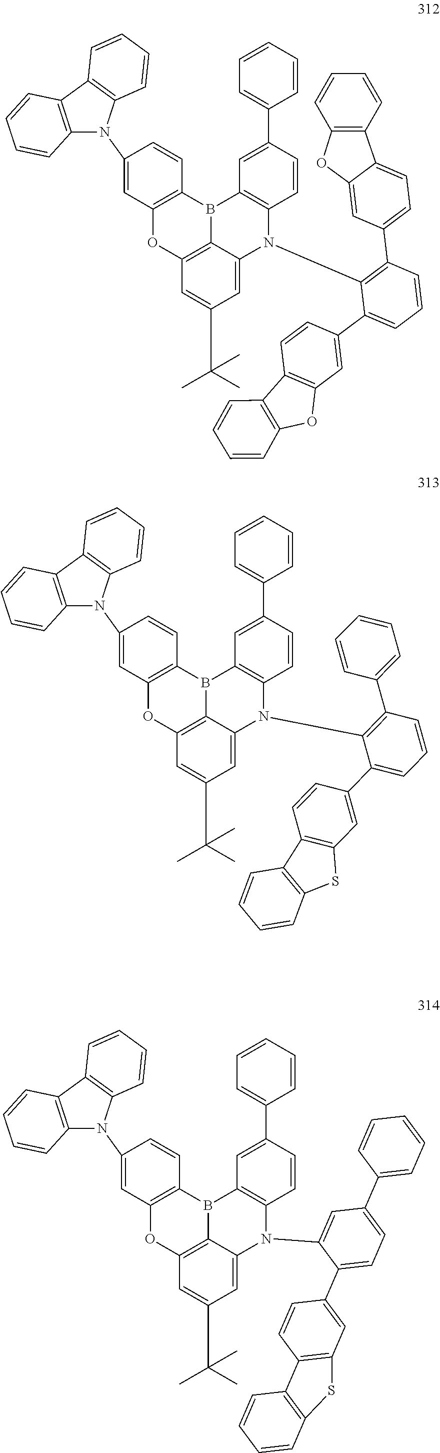 [SMILES: CC(C)(C)c1cc2c3c(c1)N(c1c(-c4ccc5c(c4)oc4ccccc45)cccc1-c1ccc4c(c1)oc1ccccc14)c1ccc(-c4ccccc4)cc1B3c1ccc(-n3c4ccccc4c4ccccc43)cc1O2 ; CC(C)(C)c1cc2c3c(c1)N(c1c(-c4ccccc4)cccc1-c1ccc4c(c1)sc1ccccc14)c1ccc(-c4ccccc4)cc1B3c1ccc(-n3c4ccccc4c4ccccc43)cc1O2 ; CC(C)(C)c1cc2c3c(c1)N(c1cc(-c4ccccc4)ccc1-c1ccc4c(c1)sc1ccccc14)c1ccc(-c4ccccc4)cc1B3c1ccc(-n3c4ccccc4c4ccccc43)cc1O2] 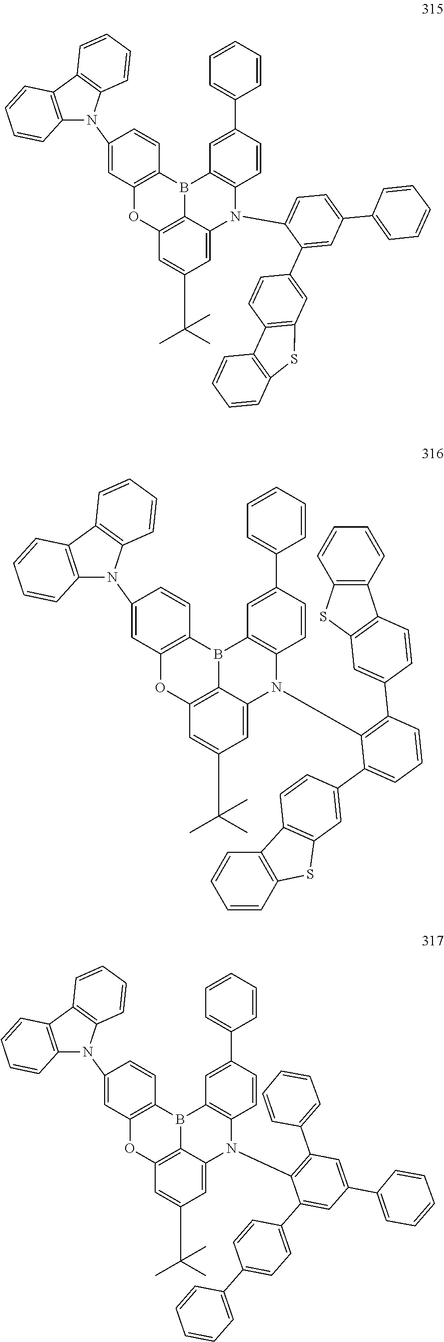 [SMILES: CC(C)(C)c1cc2c3c(c1)N(c1ccc(-c4ccccc4)cc1-c1ccc4c(c1)sc1ccccc14)c1ccc(-c4ccccc4)cc1B3c1ccc(-n3c4ccccc4c4ccccc43)cc1O2 ; CC(C)(C)c1cc2c3c(c1)N(c1c(-c4ccc5c(c4)sc4ccccc45)cccc1-c1ccc4c(c1)sc1ccccc14)c1ccc(-c4ccccc4)cc1B3c1ccc(-n3c4ccccc4c4ccccc43)cc1O2 ; CC(C)(C)c1cc2c3c(c1)N(c1c(-c4ccccc4)cc(-c4ccccc4)cc1-c1ccc(-c4ccccc4)cc1)c1ccc(-c4ccccc4)cc1B3c1ccc(-n3c4ccccc4c4ccccc43)cc1O2] 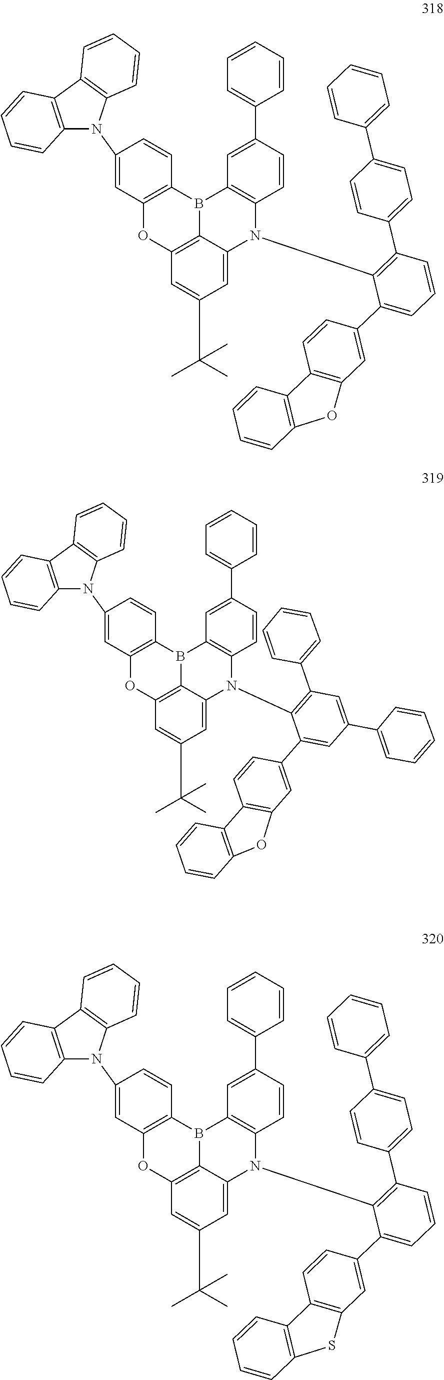 [SMILES: CC(C)(C)c1cc2c3c(c1)N(c1c(-c4ccc(-c5ccccc5)cc4)cccc1-c1ccc4c(c1)oc1ccccc14)c1ccc(-c4ccccc4)cc1B3c1ccc(-n3c4ccccc4c4ccccc43)cc1O2 ; CC(C)(C)c1cc2c3c(c1)N(c1c(-c4ccccc4)cc(-c4ccccc4)cc1-c1ccc4c(c1)oc1ccccc14)c1ccc(-c4ccccc4)cc1B3c1ccc(-n3c4ccccc4c4ccccc43)cc1O2 ; CC(C)(C)c1cc2c3c(c1)N(c1c(-c4ccc(-c5ccccc5)cc4)cccc1-c1ccc4c(c1)sc1ccccc14)c1ccc(-c4ccccc4)cc1B3c1ccc(-n3c4ccccc4c4ccccc43)cc1O2] 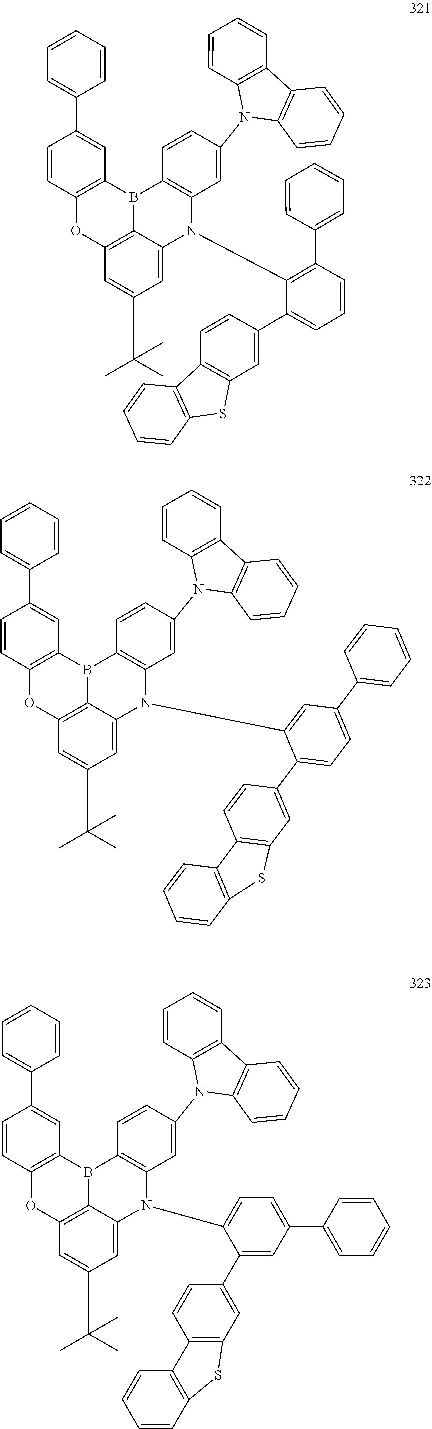 [SMILES: CC(C)(C)c1cc2c3c(c1)N(c1c(-c4ccccc4)cccc1-c1ccc4c(c1)sc1ccccc14)c1cc(-n4c5ccccc5c5ccccc54)ccc1B3c1cc(-c3ccccc3)ccc1O2 ; CC(C)(C)c1cc2c3c(c1)N(c1cc(-c4ccccc4)ccc1-c1ccc4c(c1)sc1ccccc14)c1cc(-n4c5ccccc5c5ccccc54)ccc1B3c1cc(-c3ccccc3)ccc1O2 ; CC(C)(C)c1cc2c3c(c1)N(c1ccc(-c4ccccc4)cc1-c1ccc4c(c1)sc1ccccc14)c1cc(-n4c5ccccc5c5ccccc54)ccc1B3c1cc(-c3ccccc3)ccc1O2] 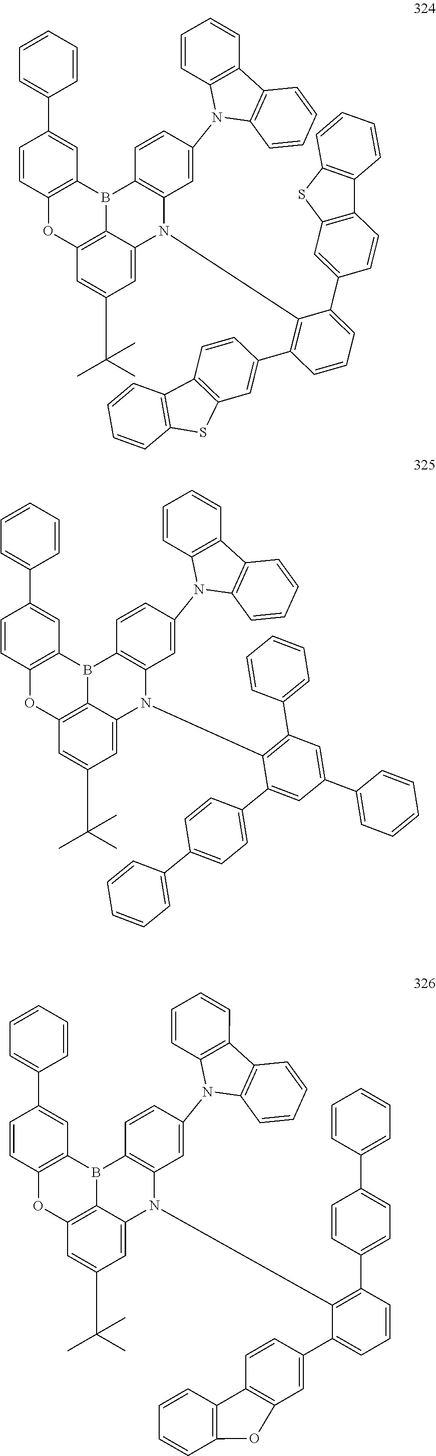 [SMILES: CC(C)(C)c1cc2c3c(c1)N(c1c(-c4ccc5c(c4)sc4ccccc45)cccc1-c1ccc4c(c1)sc1ccccc14)c1cc(-n4c5ccccc5c5ccccc54)ccc1B3c1cc(-c3ccccc3)ccc1O2 ; CC(C)(C)c1cc2c3c(c1)N(c1c(-c4ccccc4)cc(-c4ccccc4)cc1-c1ccc(-c4ccccc4)cc1)c1cc(-n4c5ccccc5c5ccccc54)ccc1B3c1cc(-c3ccccc3)ccc1O2 ; CC(C)(C)c1cc2c3c(c1)N(c1c(-c4ccc(-c5ccccc5)cc4)cccc1-c1ccc4c(c1)oc1ccccc14)c1cc(-n4c5ccccc5c5ccccc54)ccc1B3c1cc(-c3ccccc3)ccc1O2] 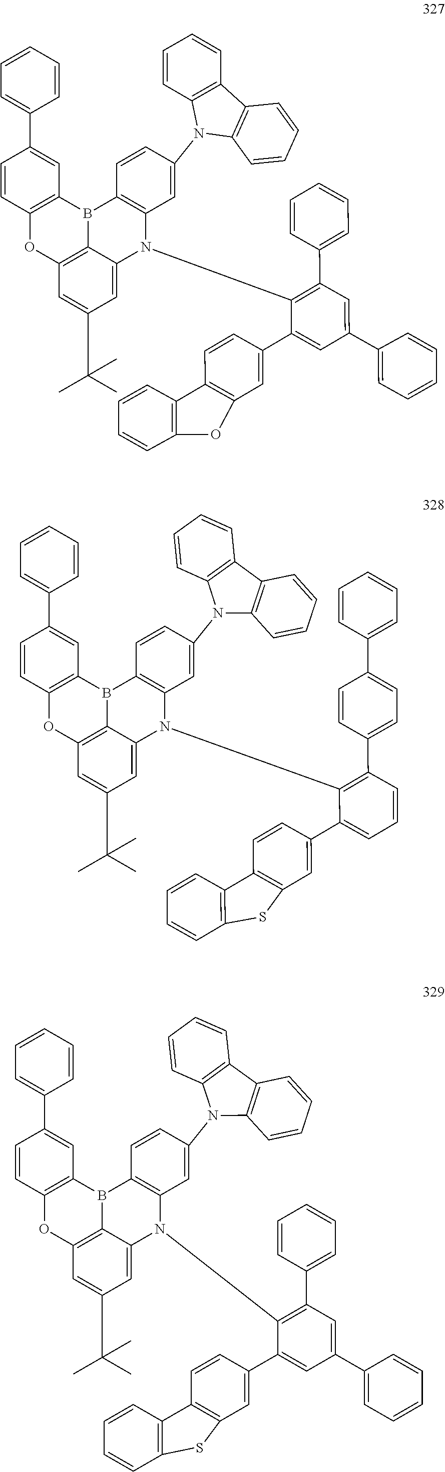 [SMILES: CC(C)(C)c1cc2c3c(c1)N(c1c(-c4ccccc4)cc(-c4ccccc4)cc1-c1ccc4c(c1)oc1ccccc14)c1cc(-n4c5ccccc5c5ccccc54)ccc1B3c1cc(-c3ccccc3)ccc1O2 ; CC(C)(C)c1cc2c3c(c1)N(c1c(-c4ccc(-c5ccccc5)cc4)cccc1-c1ccc4c(c1)sc1ccccc14)c1cc(-n4c5ccccc5c5ccccc54)ccc1B3c1cc(-c3ccccc3)ccc1O2 ; CC(C)(C)c1cc2c3c(c1)N(c1c(-c4ccccc4)cc(-c4ccccc4)cc1-c1ccc4c(c1)sc1ccccc14)c1cc(-n4c5ccccc5c5ccccc54)ccc1B3c1cc(-c3ccccc3)ccc1O2] 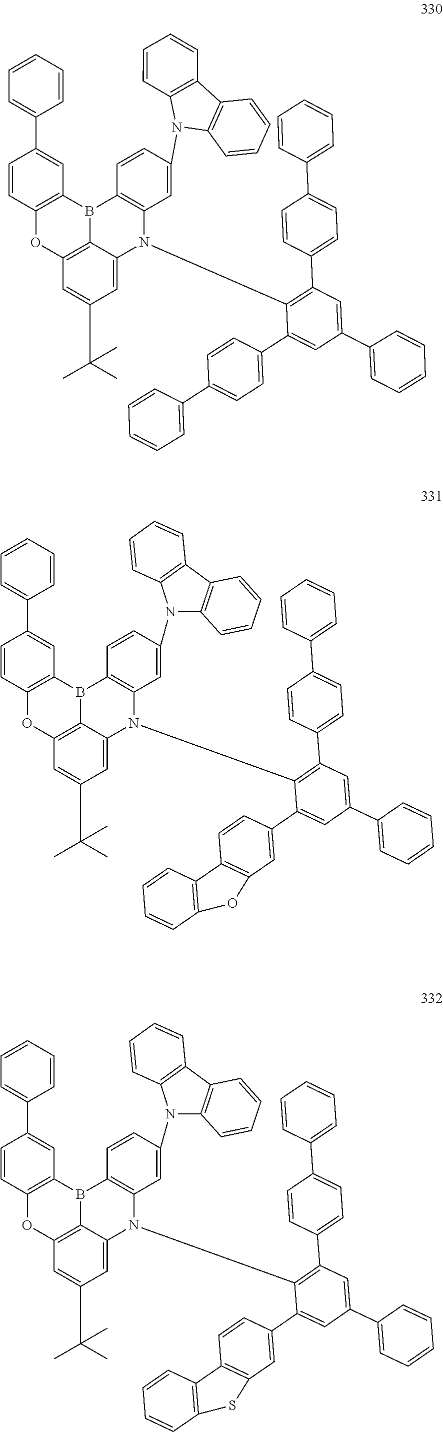 [SMILES: CC(C)(C)c1cc2c3c(c1)N(c1c(-c4ccc(-c5ccccc5)cc4)cc(-c4ccccc4)cc1-c1ccc(-c4ccccc4)cc1)c1cc(-n4c5ccccc5c5ccccc54)ccc1B3c1cc(-c3ccccc3)ccc1O2 ; CC(C)(C)c1cc2c3c(c1)N(c1c(-c4ccc(-c5ccccc5)cc4)cc(-c4ccccc4)cc1-c1ccc4c(c1)oc1ccccc14)c1cc(-n4c5ccccc5c5ccccc54)ccc1B3c1cc(-c3ccccc3)ccc1O2 ; CC(C)(C)c1cc2c3c(c1)N(c1c(-c4ccc(-c5ccccc5)cc4)cc(-c4ccccc4)cc1-c1ccc4c(c1)sc1ccccc14)c1cc(-n4c5ccccc5c5ccccc54)ccc1B3c1cc(-c3ccccc3)ccc1O2] 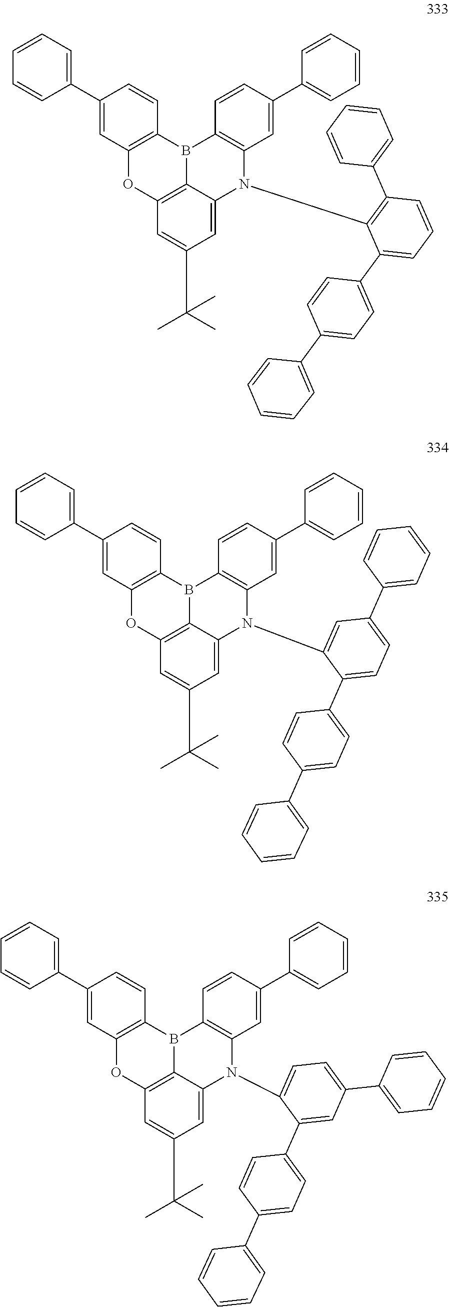 [SMILES: CC(C)(C)c1cc2c3c(c1)N(c1c(-c4ccccc4)cccc1-c1ccc(-c4ccccc4)cc1)c1cc(-c4ccccc4)ccc1B3c1ccc(-c3ccccc3)cc1O2 ; CC(C)(C)c1cc2c3c(c1)N(c1cc(-c4ccccc4)ccc1-c1ccc(-c4ccccc4)cc1)c1cc(-c4ccccc4)ccc1B3c1ccc(-c3ccccc3)cc1O2 ; CC(C)(C)c1cc2c3c(c1)N(c1ccc(-c4ccccc4)cc1-c1ccc(-c4ccccc4)cc1)c1cc(-c4ccccc4)ccc1B3c1ccc(-c3ccccc3)cc1O2] 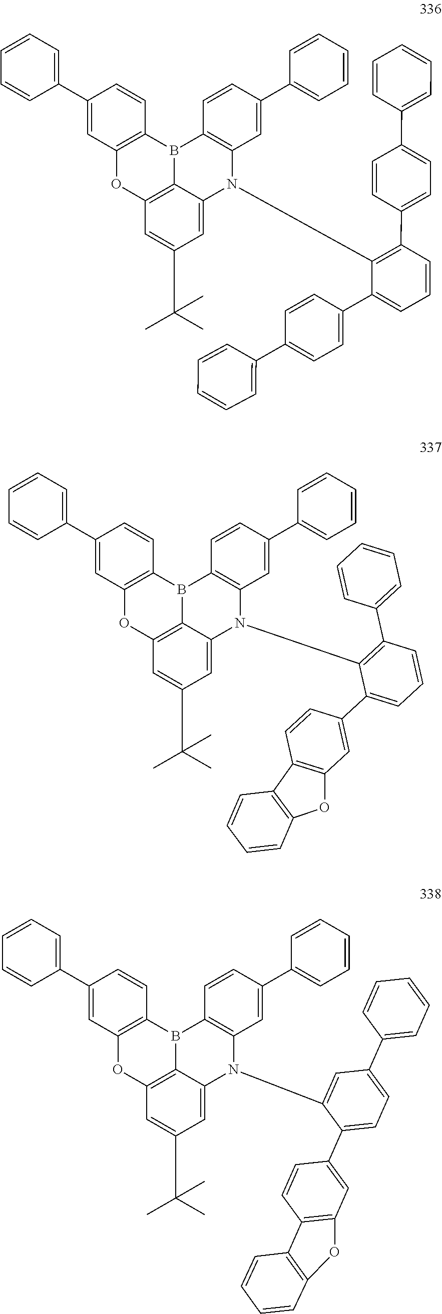 [SMILES: CC(C)(C)c1cc2c3c(c1)N(c1c(-c4ccc(-c5ccccc5)cc4)cccc1-c1ccc(-c4ccccc4)cc1)c1cc(-c4ccccc4)ccc1B3c1ccc(-c3ccccc3)cc1O2 ; CC(C)(C)c1cc2c3c(c1)N(c1c(-c4ccccc4)cccc1-c1ccc4c(c1)oc1ccccc14)c1cc(-c4ccccc4)ccc1B3c1ccc(-c3ccccc3)cc1O2 ; CC(C)(C)c1cc2c3c(c1)N(c1cc(-c4ccccc4)ccc1-c1ccc4c(c1)oc1ccccc14)c1cc(-c4ccccc4)ccc1B3c1ccc(-c3ccccc3)cc1O2] 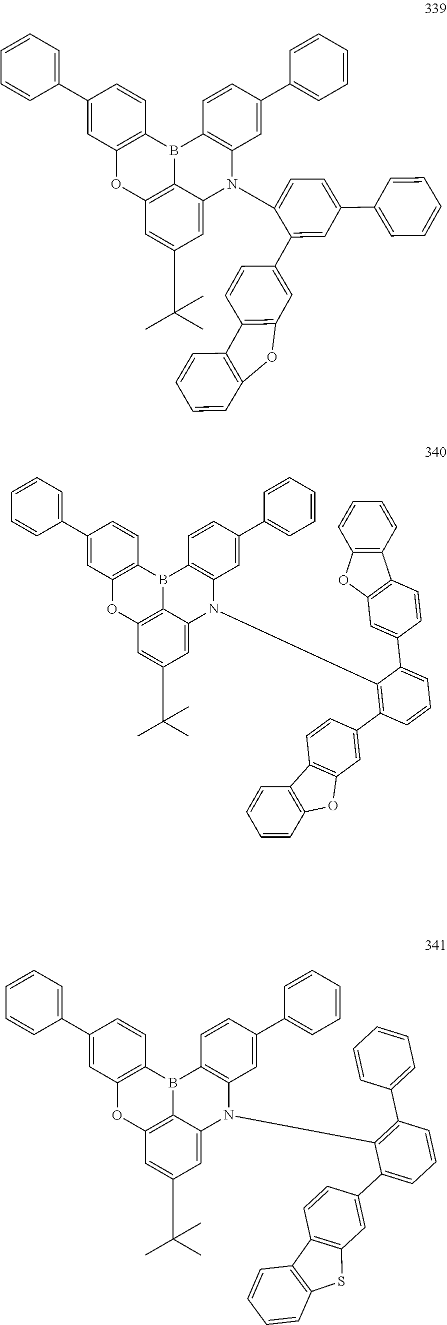 [SMILES: CC(C)(C)c1cc2c3c(c1)N(c1ccc(-c4ccccc4)cc1-c1ccc4c(c1)oc1ccccc14)c1cc(-c4ccccc4)ccc1B3c1ccc(-c3ccccc3)cc1O2 ; CC(C)(C)c1cc2c3c(c1)N(c1c(-c4ccc5c(c4)oc4ccccc45)cccc1-c1ccc4c(c1)oc1ccccc14)c1cc(-c4ccccc4)ccc1B3c1ccc(-c3ccccc3)cc1O2 ; CC(C)(C)c1cc2c3c(c1)N(c1c(-c4ccccc4)cccc1-c1ccc4c(c1)sc1ccccc14)c1cc(-c4ccccc4)ccc1B3c1ccc(-c3ccccc3)cc1O2] 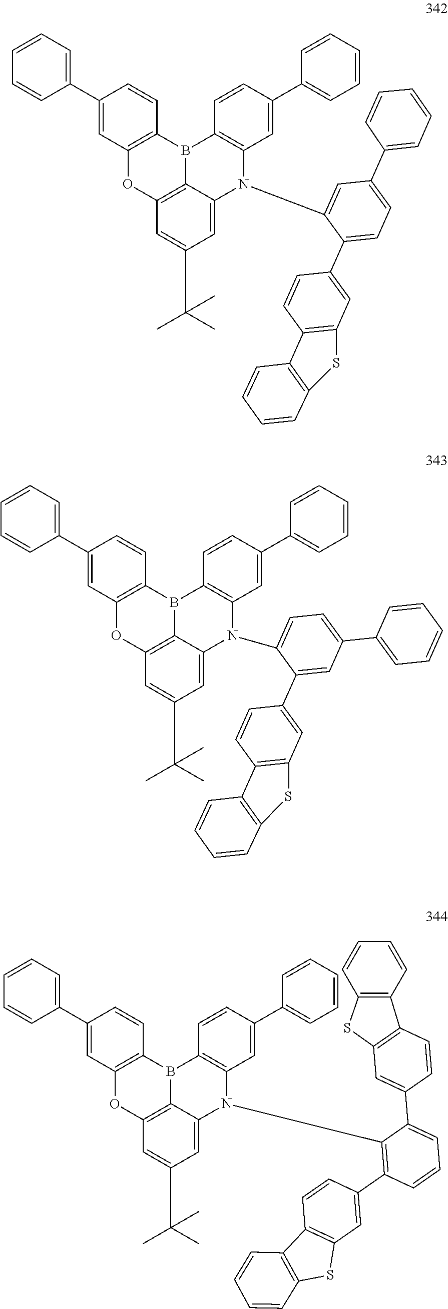 [SMILES: CC(C)(C)c1cc2c3c(c1)N(c1cc(-c4ccccc4)ccc1-c1ccc4c(c1)sc1ccccc14)c1cc(-c4ccccc4)ccc1B3c1ccc(-c3ccccc3)cc1O2 ; CC(C)(C)c1cc2c3c(c1)N(c1ccc(-c4ccccc4)cc1-c1ccc4c(c1)sc1ccccc14)c1cc(-c4ccccc4)ccc1B3c1ccc(-c3ccccc3)cc1O2 ; CC(C)(C)c1cc2c3c(c1)N(c1c(-c4ccc5c(c4)sc4ccccc45)cccc1-c1ccc4c(c1)sc1ccccc14)c1cc(-c4ccccc4)ccc1B3c1ccc(-c3ccccc3)cc1O2] 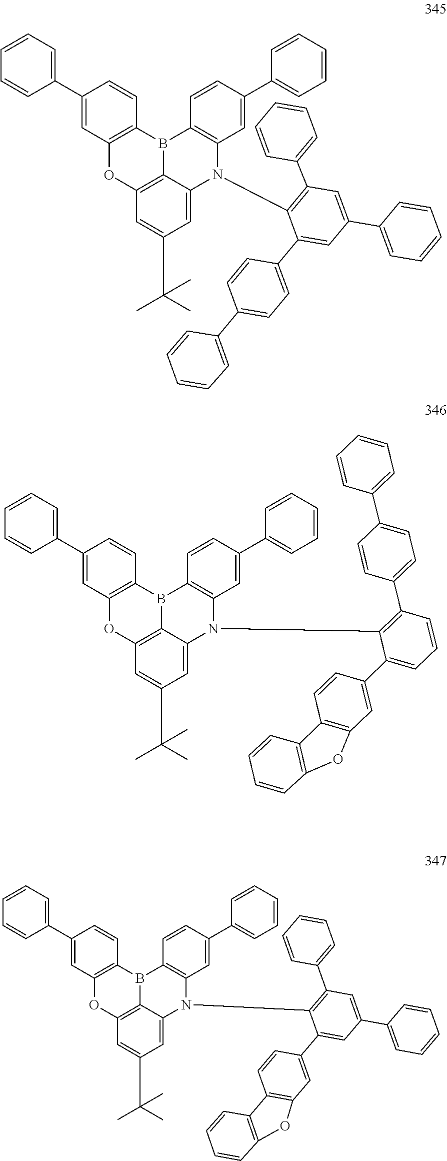 [SMILES: CC(C)(C)c1cc2c3c(c1)N(c1c(-c4ccccc4)cc(-c4ccccc4)cc1-c1ccc(-c4ccccc4)cc1)c1cc(-c4ccccc4)ccc1B3c1ccc(-c3ccccc3)cc1O2 ; CC(C)(C)c1cc2c3c(c1)N(c1c(-c4ccc(-c5ccccc5)cc4)cccc1-c1ccc4c(c1)oc1ccccc14)c1cc(-c4ccccc4)ccc1B3c1ccc(-c3ccccc3)cc1O2 ; CC(C)(C)c1cc2c3c(c1)N(c1c(-c4ccccc4)cc(-c4ccccc4)cc1-c1ccc4c(c1)oc1ccccc14)c1cc(-c4ccccc4)ccc1B3c1ccc(-c3ccccc3)cc1O2] 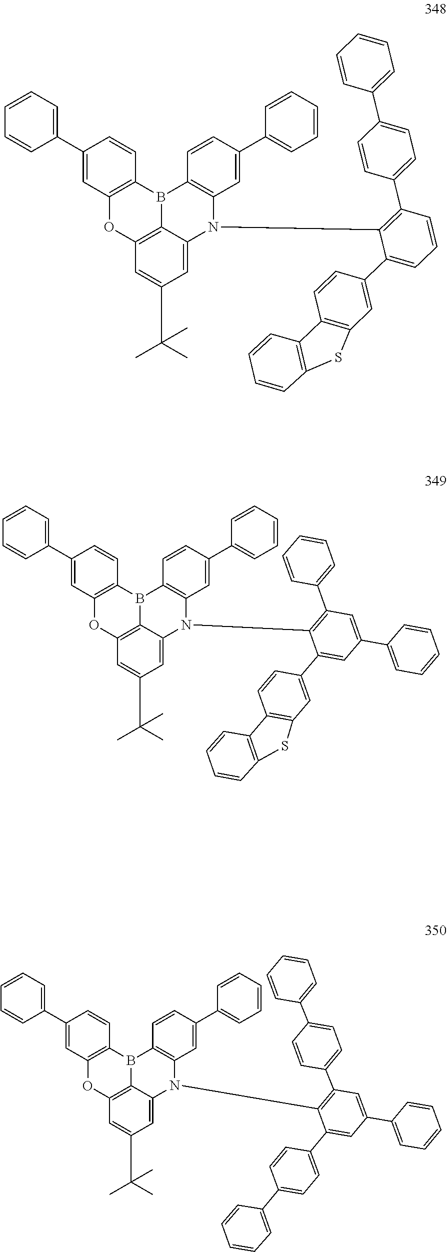 [SMILES: CC(C)(C)c1cc2c3c(c1)N(c1c(-c4ccc(-c5ccccc5)cc4)cccc1-c1ccc4c(c1)sc1ccccc14)c1cc(-c4ccccc4)ccc1B3c1ccc(-c3ccccc3)cc1O2 ; CC(C)(C)c1cc2c3c(c1)N(c1c(-c4ccccc4)cc(-c4ccccc4)cc1-c1ccc4c(c1)sc1ccccc14)c1cc(-c4ccccc4)ccc1B3c1ccc(-c3ccccc3)cc1O2 ; CC(C)(C)c1cc2c3c(c1)N(c1c(-c4ccc(-c5ccccc5)cc4)cc(-c4ccccc4)cc1-c1ccc(-c4ccccc4)cc1)c1cc(-c4ccccc4)ccc1B3c1ccc(-c3ccccc3)cc1O2] 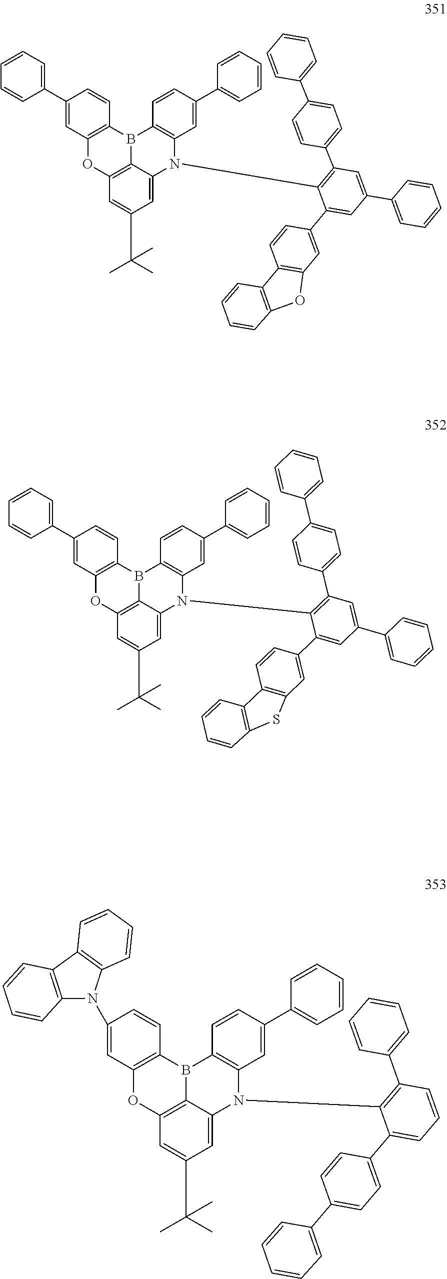 [SMILES: CC(C)(C)c1cc2c3c(c1)N(c1c(-c4ccc(-c5ccccc5)cc4)cc(-c4ccccc4)cc1-c1ccc4c(c1)oc1ccccc14)c1cc(-c4ccccc4)ccc1B3c1ccc(-c3ccccc3)cc1O2 ; CC(C)(C)c1cc2c3c(c1)N(c1c(-c4ccc(-c5ccccc5)cc4)cc(-c4ccccc4)cc1-c1ccc4c(c1)sc1ccccc14)c1cc(-c4ccccc4)ccc1B3c1ccc(-c3ccccc3)cc1O2 ; CC(C)(C)c1cc2c3c(c1)N(c1c(-c4ccccc4)cccc1-c1ccc(-c4ccccc4)cc1)c1cc(-c4ccccc4)ccc1B3c1ccc(-n3c4ccccc4c4ccccc43)cc1O2] 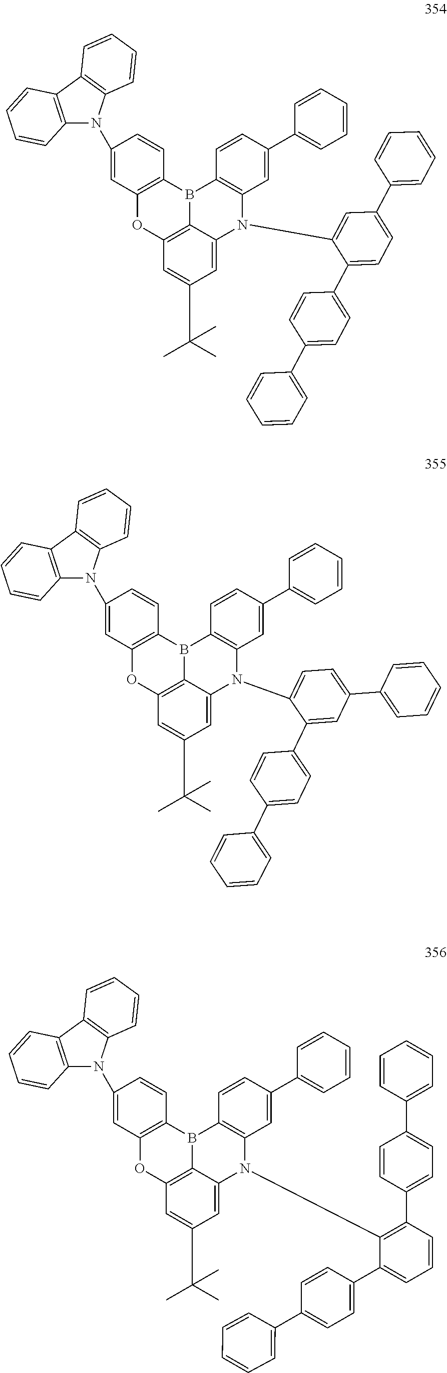 [SMILES: CC(C)(C)c1cc2c3c(c1)N(c1cc(-c4ccccc4)ccc1-c1ccc(-c4ccccc4)cc1)c1cc(-c4ccccc4)ccc1B3c1ccc(-n3c4ccccc4c4ccccc43)cc1O2 ; CC(C)(C)c1cc2c3c(c1)N(c1ccc(-c4ccccc4)cc1-c1ccc(-c4ccccc4)cc1)c1cc(-c4ccccc4)ccc1B3c1ccc(-n3c4ccccc4c4ccccc43)cc1O2 ; CC(C)(C)c1cc2c3c(c1)N(c1c(-c4ccc(-c5ccccc5)cc4)cccc1-c1ccc(-c4ccccc4)cc1)c1cc(-c4ccccc4)ccc1B3c1ccc(-n3c4ccccc4c4ccccc43)cc1O2] 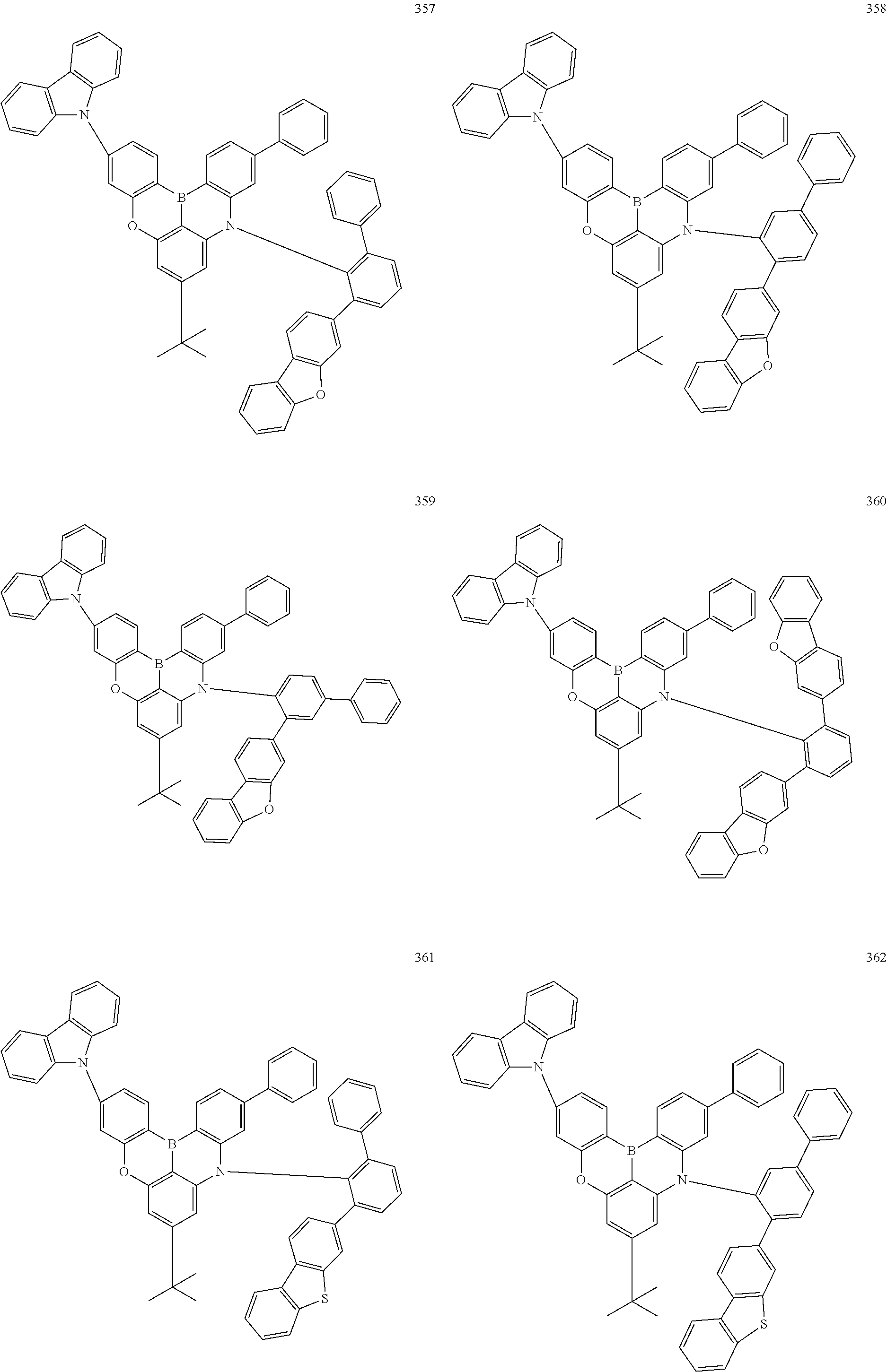 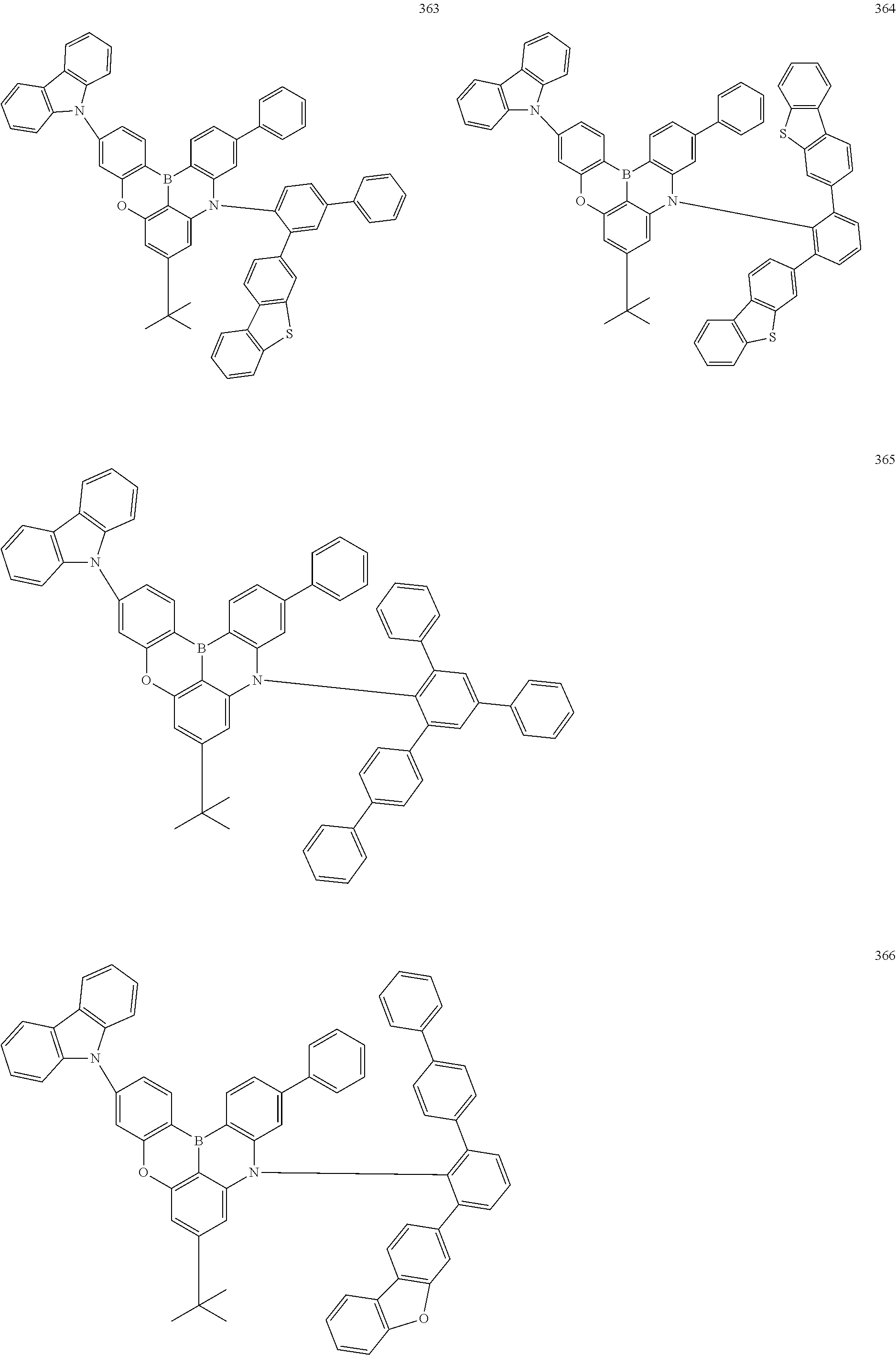 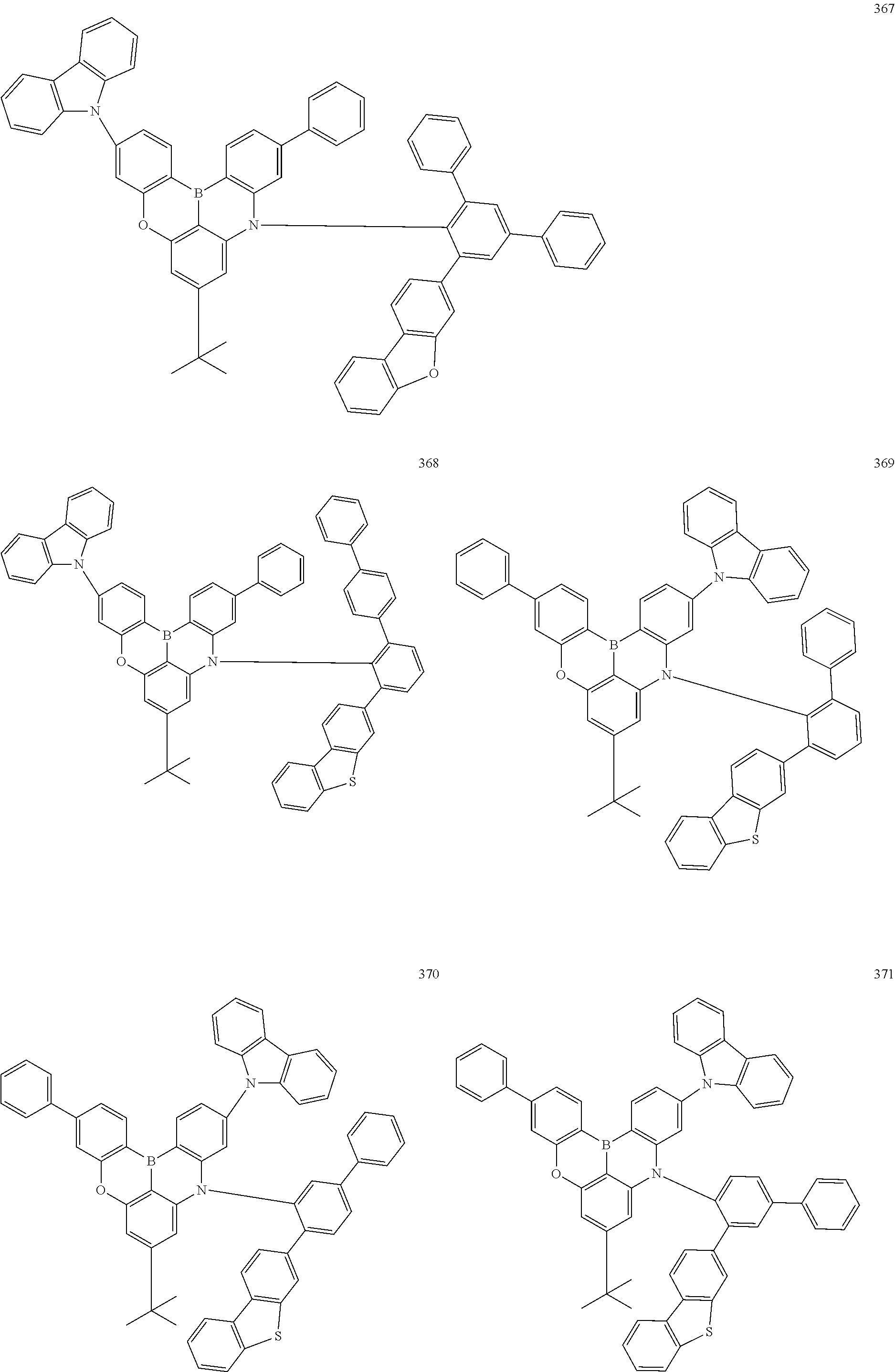 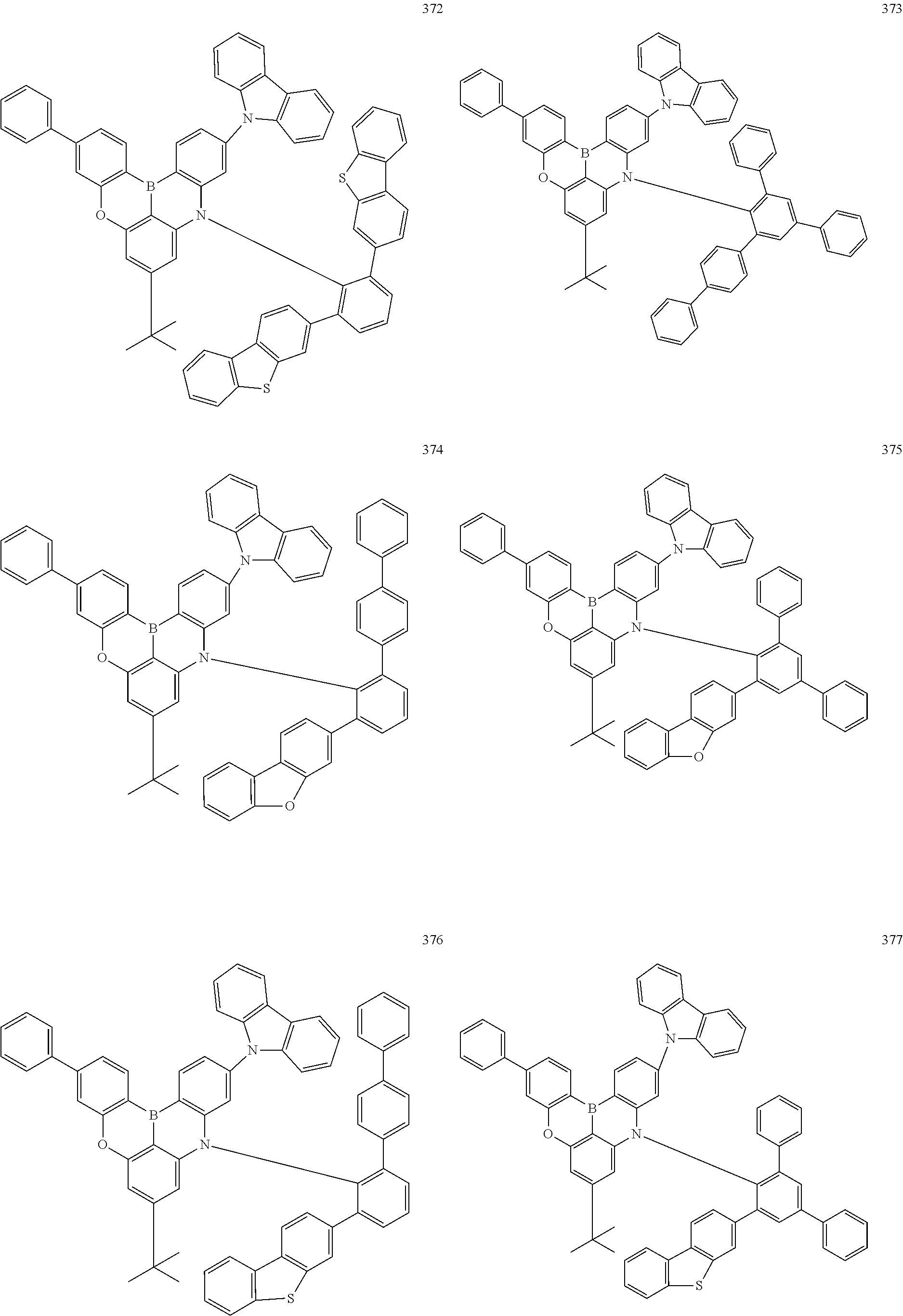 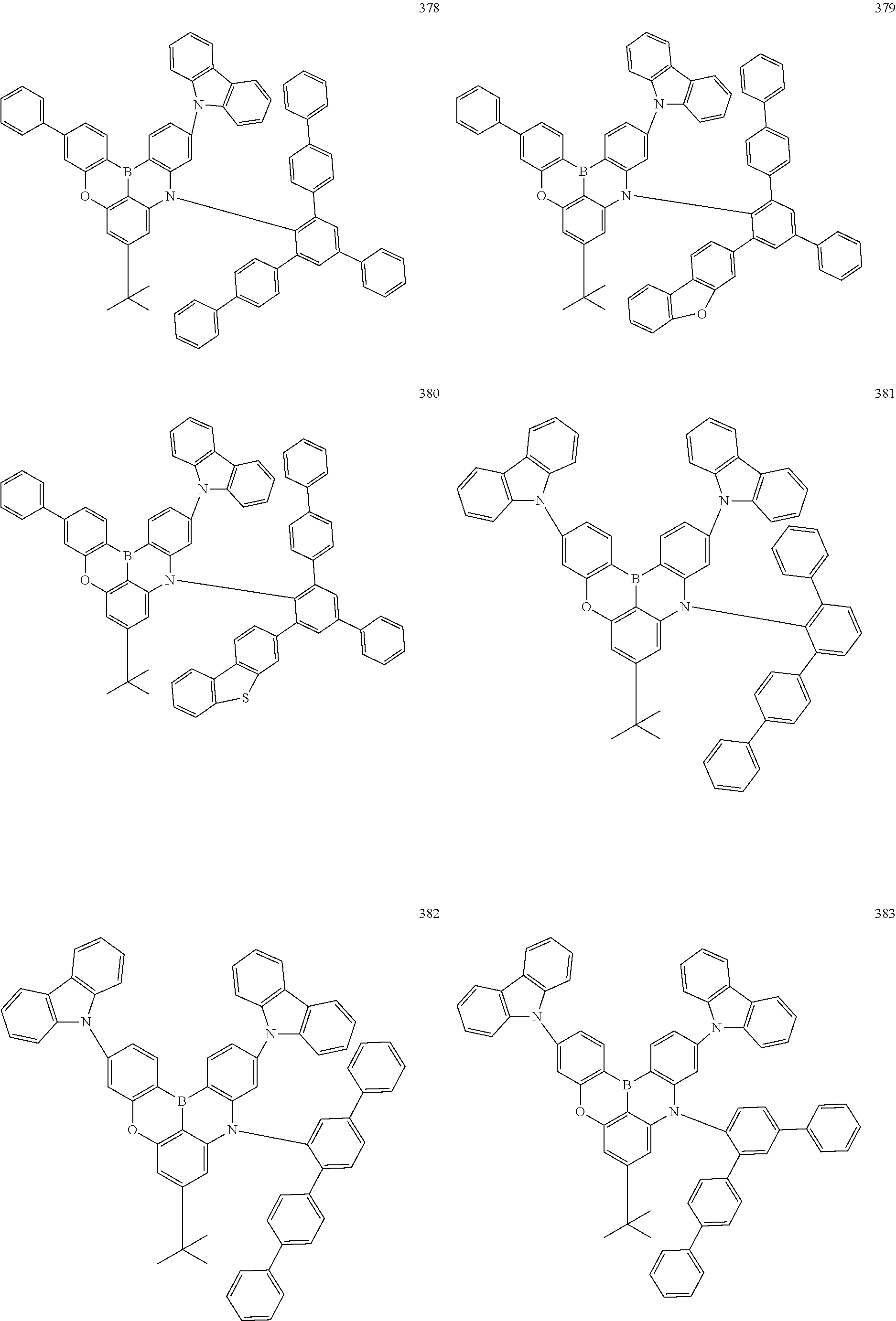 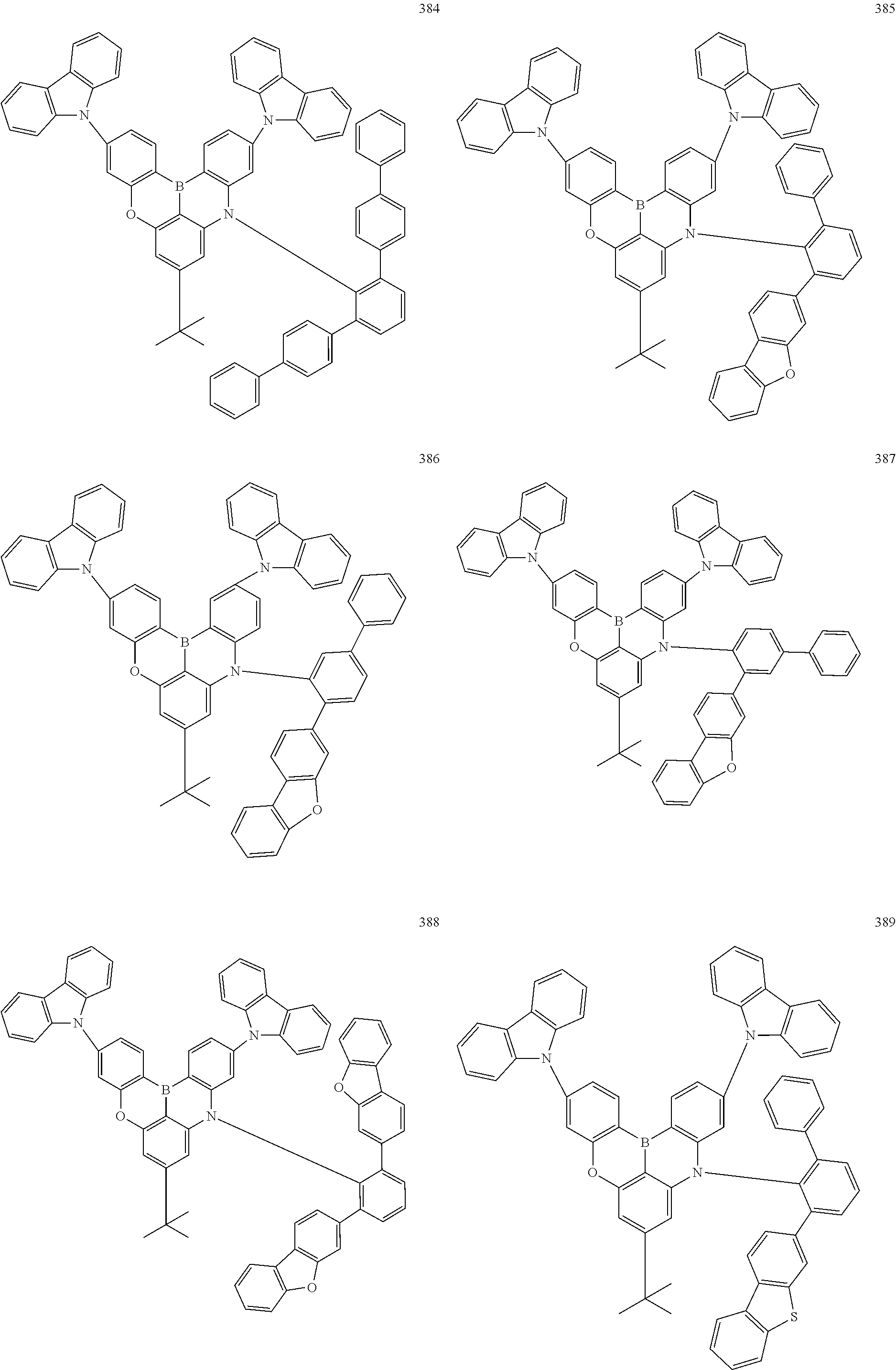 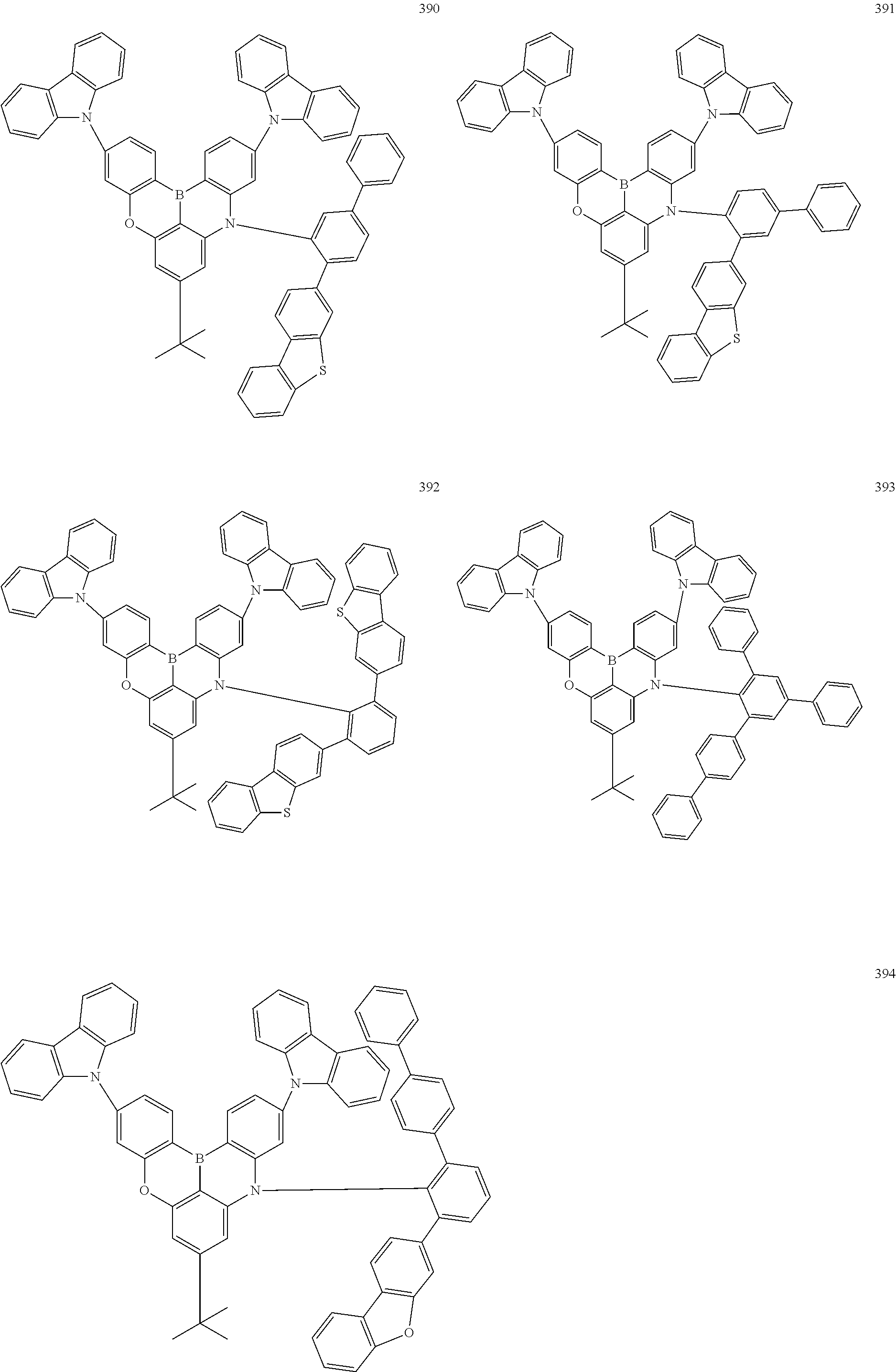 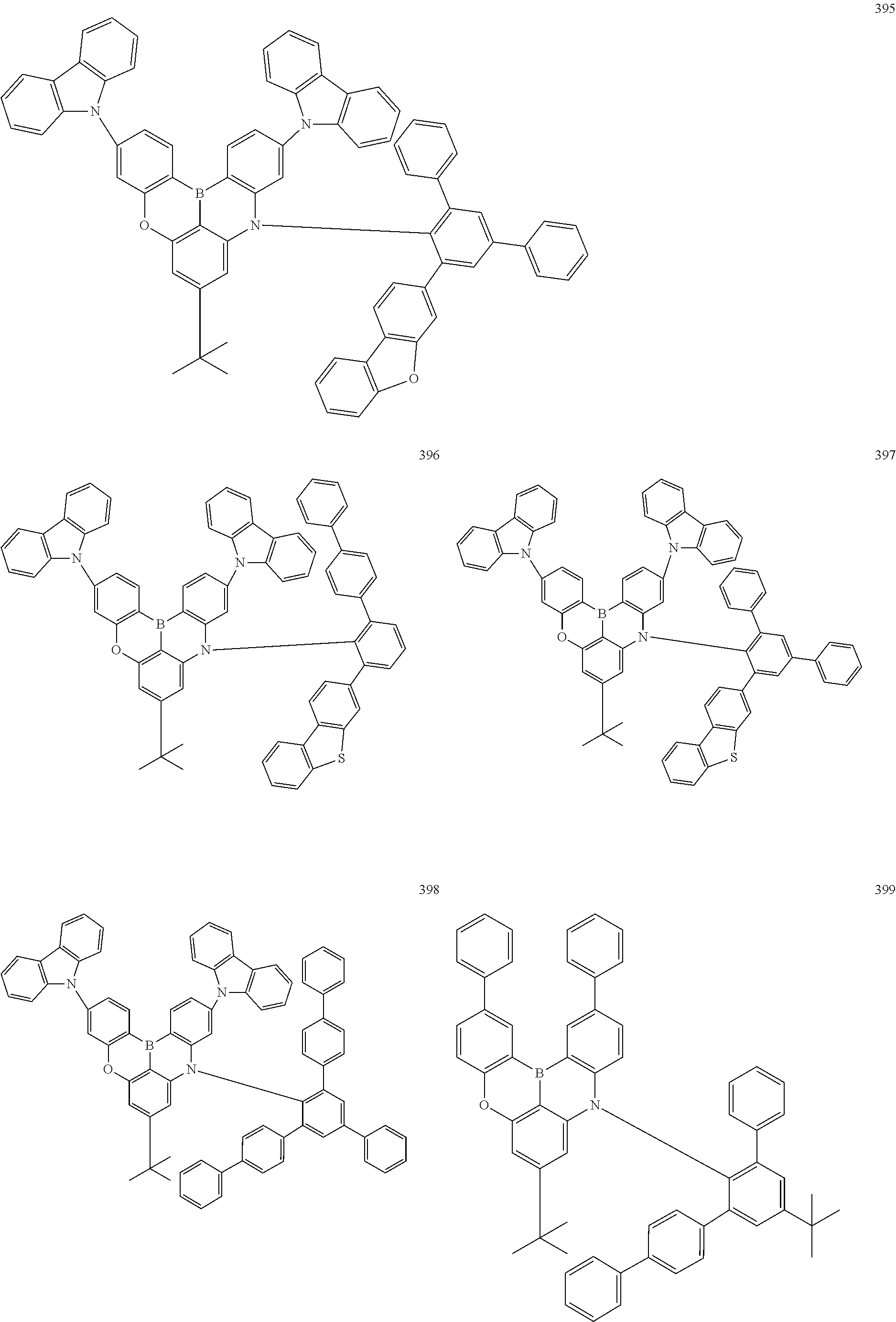 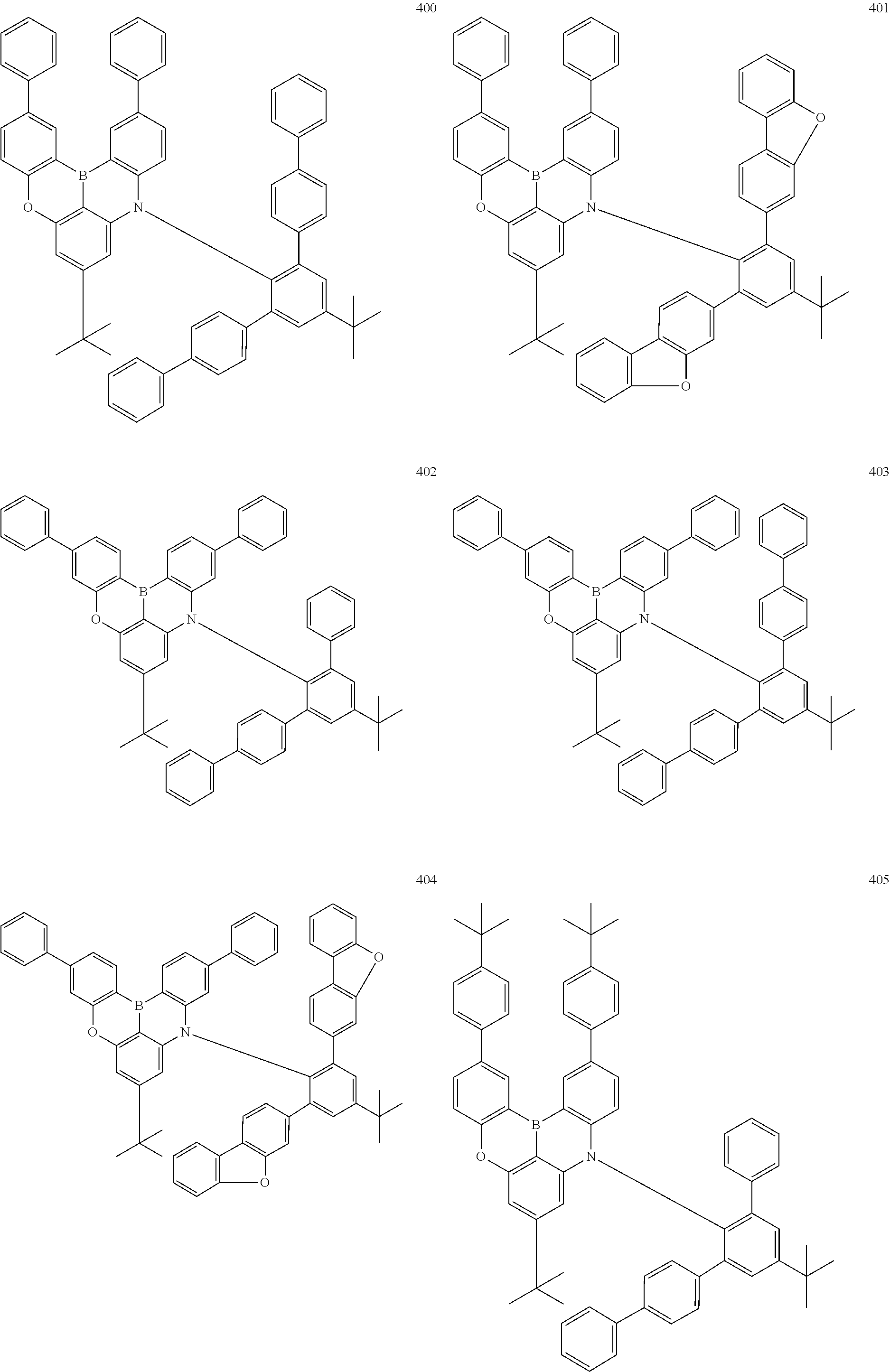 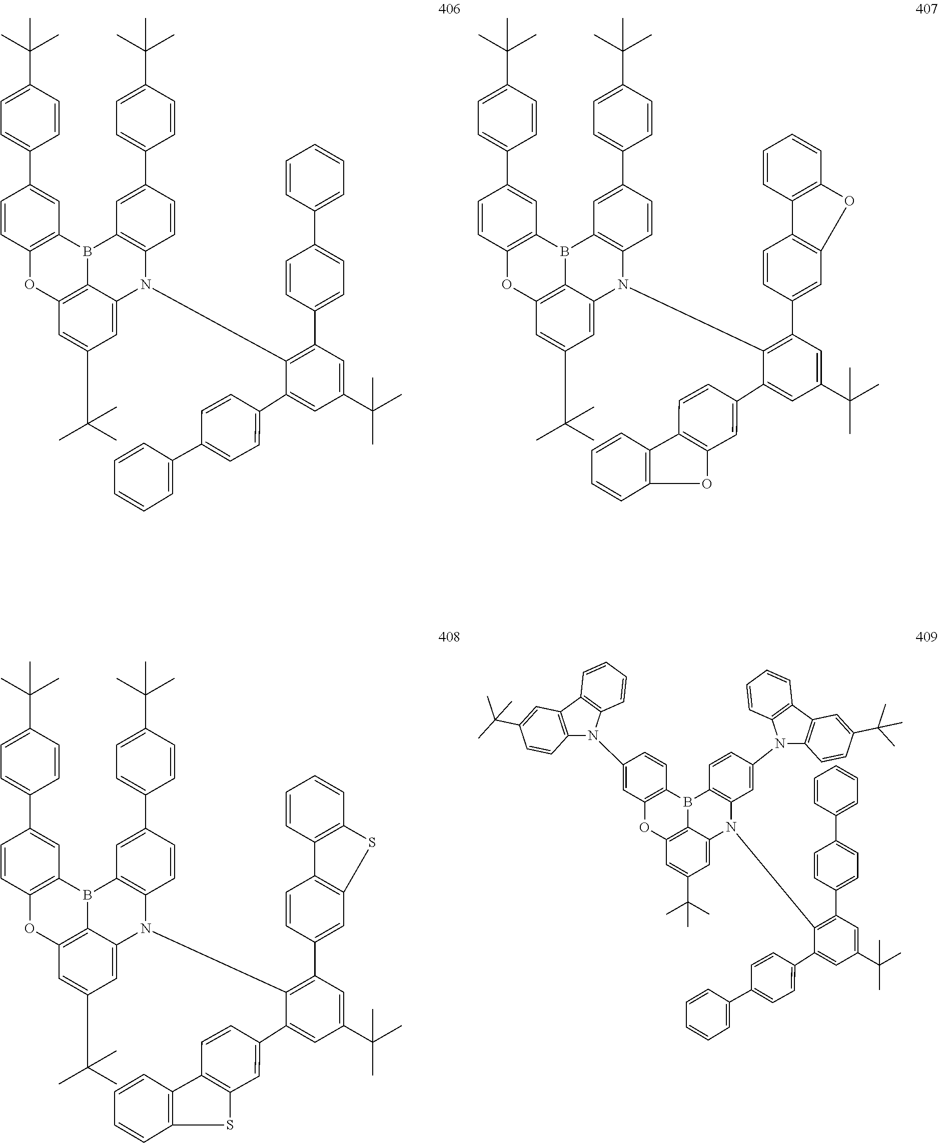 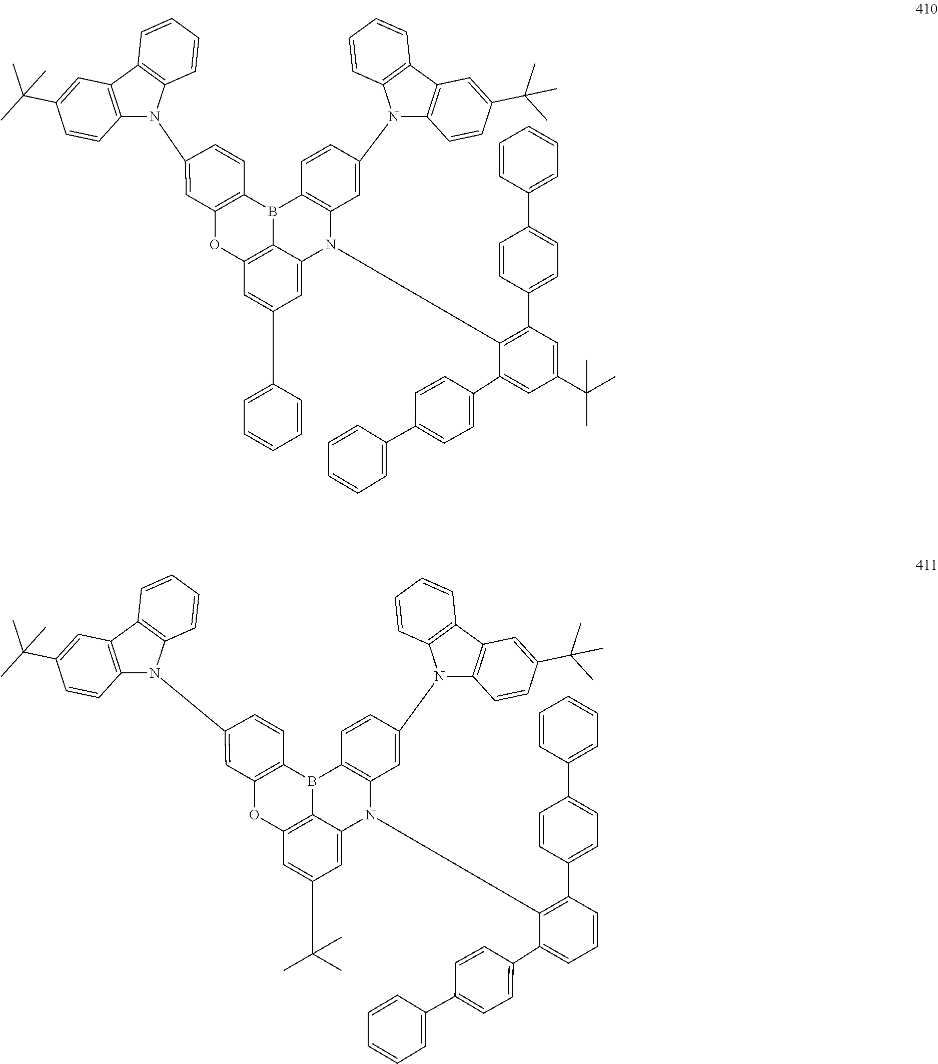 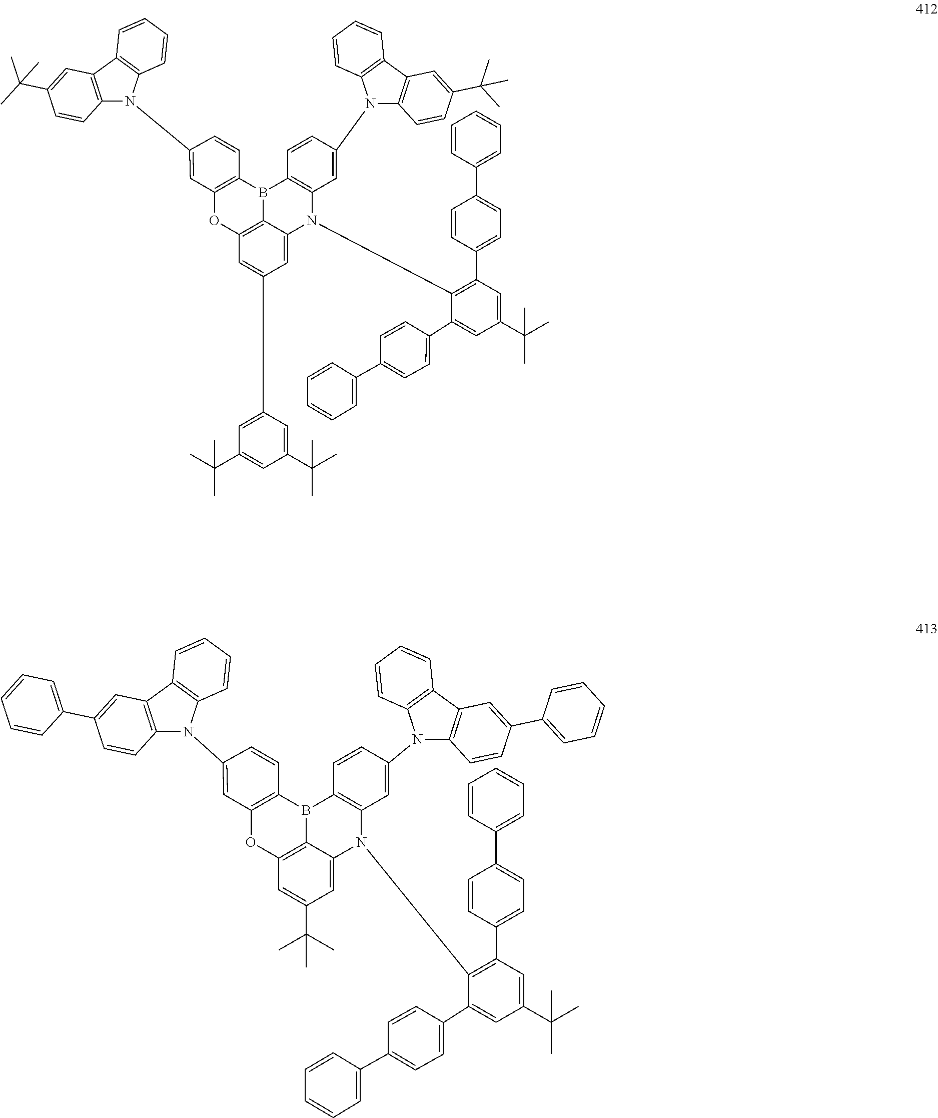 [SMILES: CC(C)(C)c1cc(-c2cc3c4c(c2)N(c2c(-c5ccc(-c6ccccc6)cc5)cc(C(C)(C)C)cc2-c2ccc(-c5ccccc5)cc2)c2cc(-n5c6ccccc6c6cc(C(C)(C)C)ccc65)ccc2B4c2ccc(-n4c5ccccc5c5cc(C(C)(C)C)ccc54)cc2O3)cc(C(C)(C)C)c1 ; CC(C)(C)c1cc(-c2ccc(-c3ccccc3)cc2)c(N2c3cc(-n4c5ccccc5c5cc(-c6ccccc6)ccc54)ccc3B3c4ccc(-n5c6ccccc6c6cc(-c7ccccc7)ccc65)cc4Oc4cc(C(C)(C)C)cc2c43)c(-c2ccc(-c3ccccc3)cc2)c1] 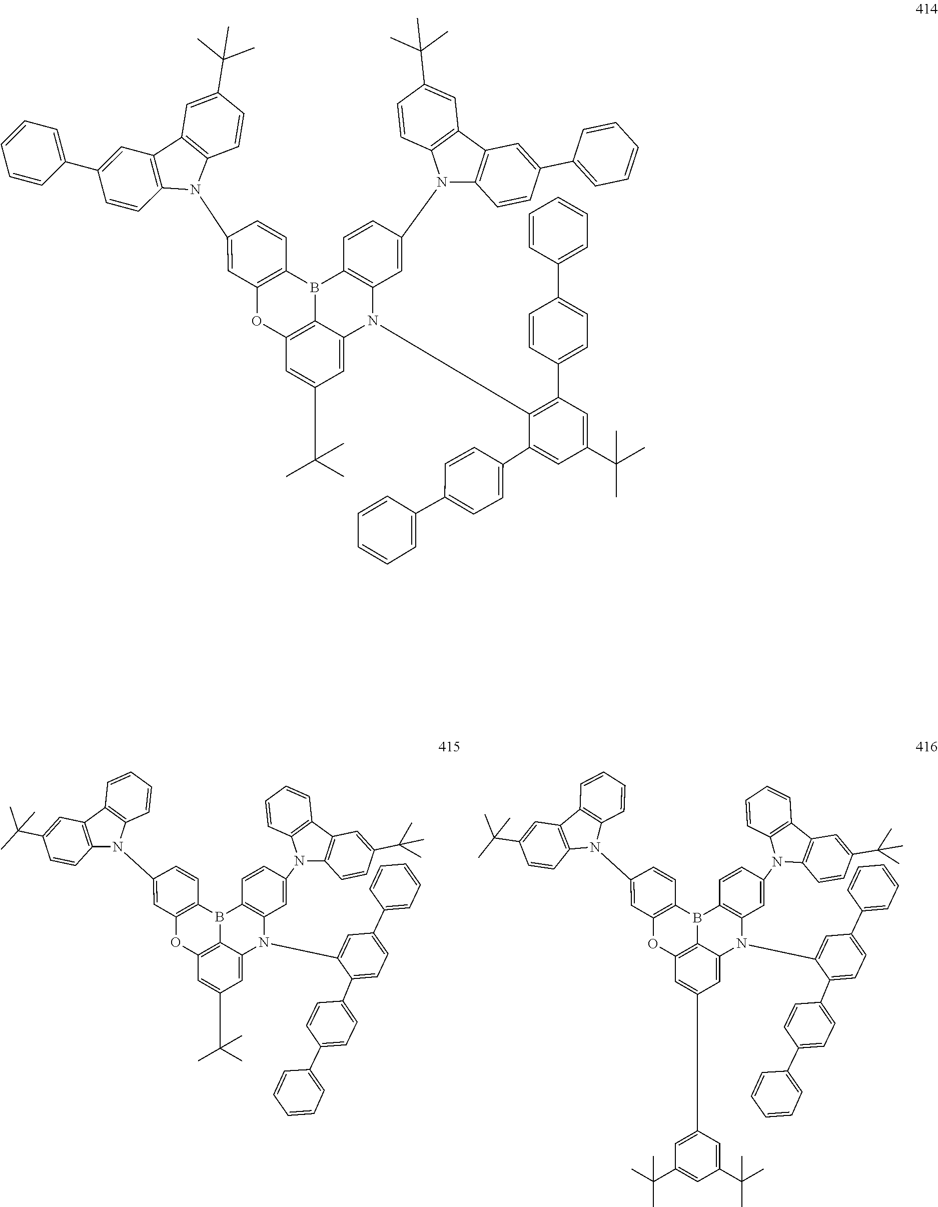 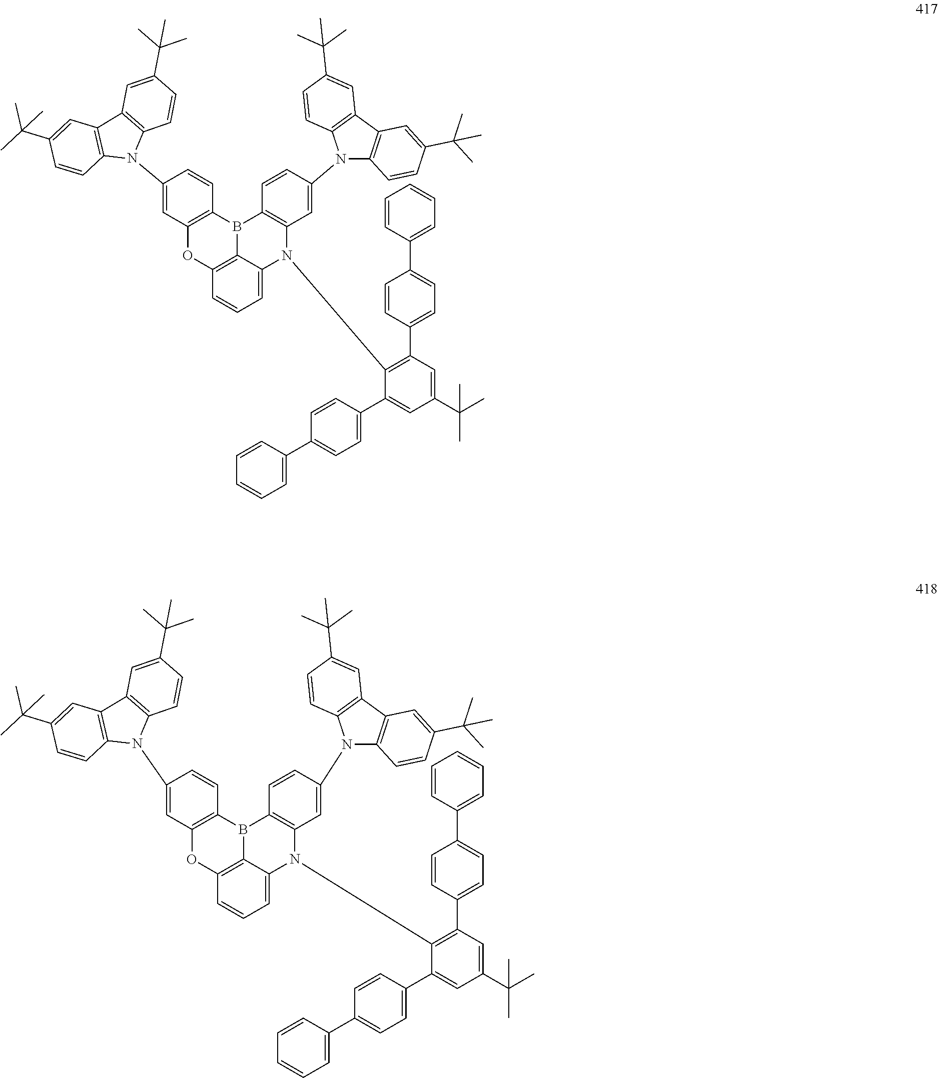 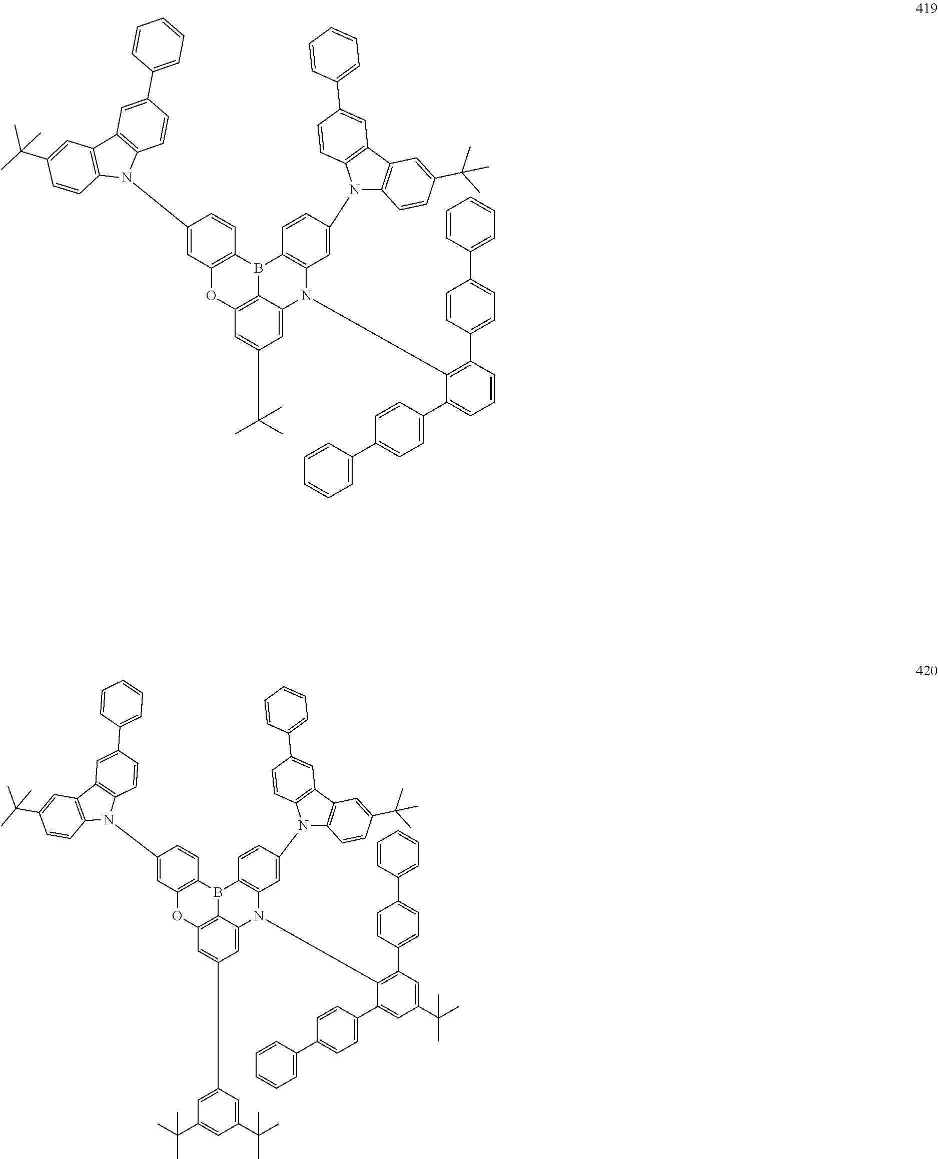 [SMILES: CC(C)(C)c1cc2c3c(c1)N(c1c(-c4ccc(-c5ccccc5)cc4)cccc1-c1ccc(-c4ccccc4)cc1)c1cc(-n4c5ccc(-c6ccccc6)cc5c5cc(C(C)(C)C)ccc54)ccc1B3c1ccc(-n3c4ccc(-c5ccccc5)cc4c4cc(C(C)(C)C)ccc43)cc1O2 ; CC(C)(C)c1cc(-c2cc3c4c(c2)N(c2c(-c5ccc(-c6ccccc6)cc5)cc(C(C)(C)C)cc2-c2ccc(-c5ccccc5)cc2)c2cc(-n5c6ccc(-c7ccccc7)cc6c6cc(C(C)(C)C)ccc65)ccc2B4c2ccc(-n4c5ccc(-c6ccccc6)cc5c5cc(C(C)(C)C)ccc54)cc2O3)cc(C(C)(C)C)c1] 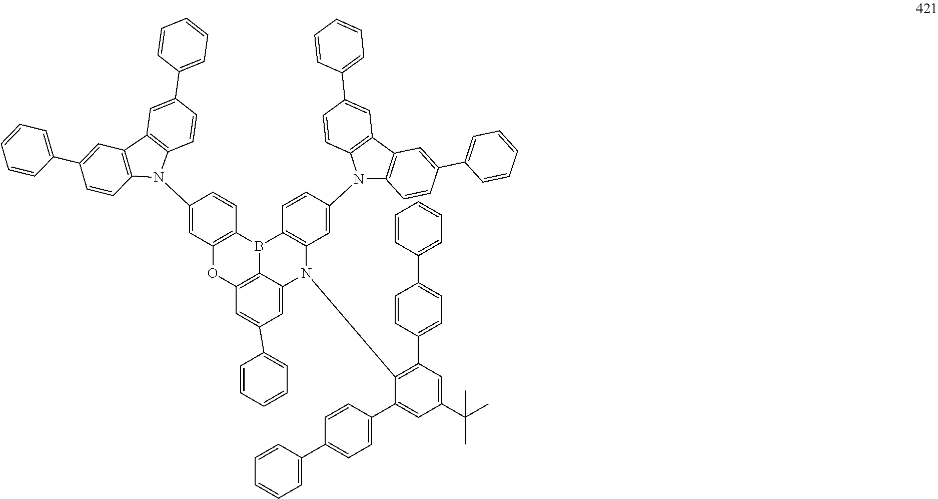 [SMILES: CC(C)(C)c1cc(-c2ccc(-c3ccccc3)cc2)c(N2c3cc(-n4c5ccc(-c6ccccc6)cc5c5cc(-c6ccccc6)ccc54)ccc3B3c4ccc(-n5c6ccc(-c7ccccc7)cc6c6cc(-c7ccccc7)ccc65)cc4Oc4cc(-c5ccccc5)cc2c43)c(-c2ccc(-c3ccccc3)cc2)c1] 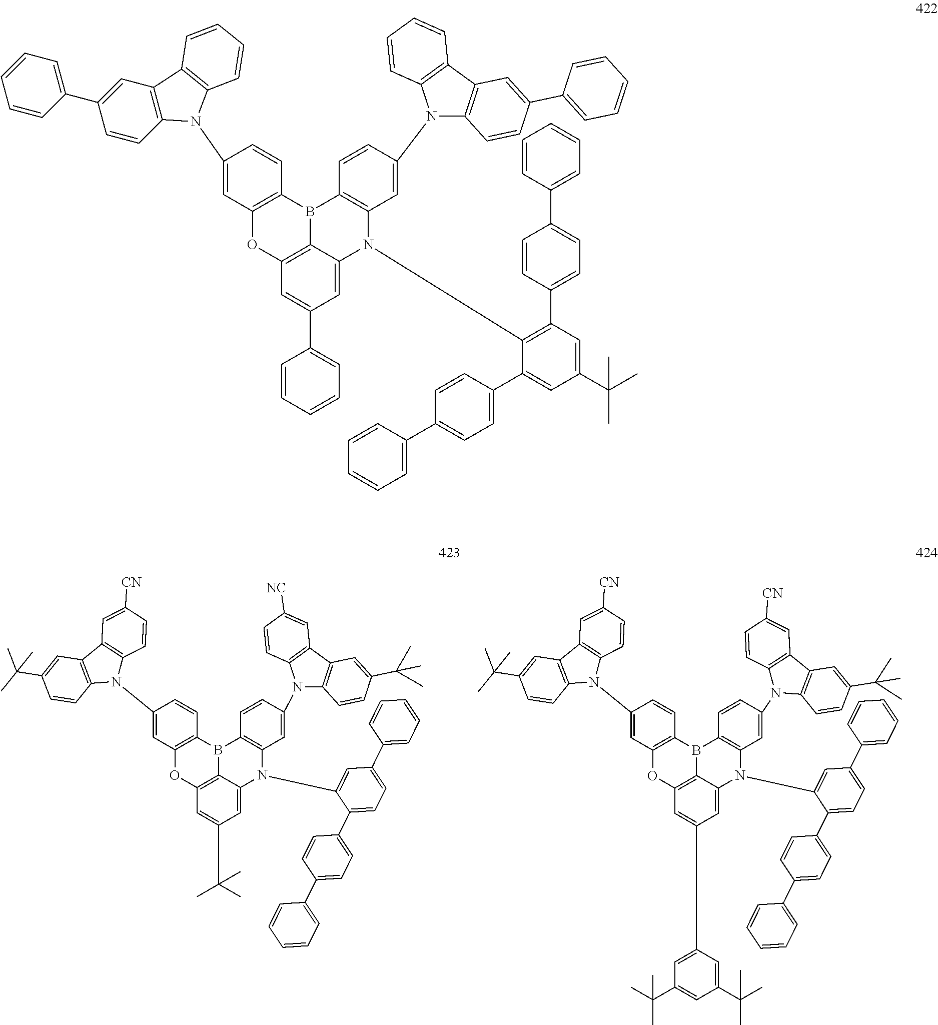 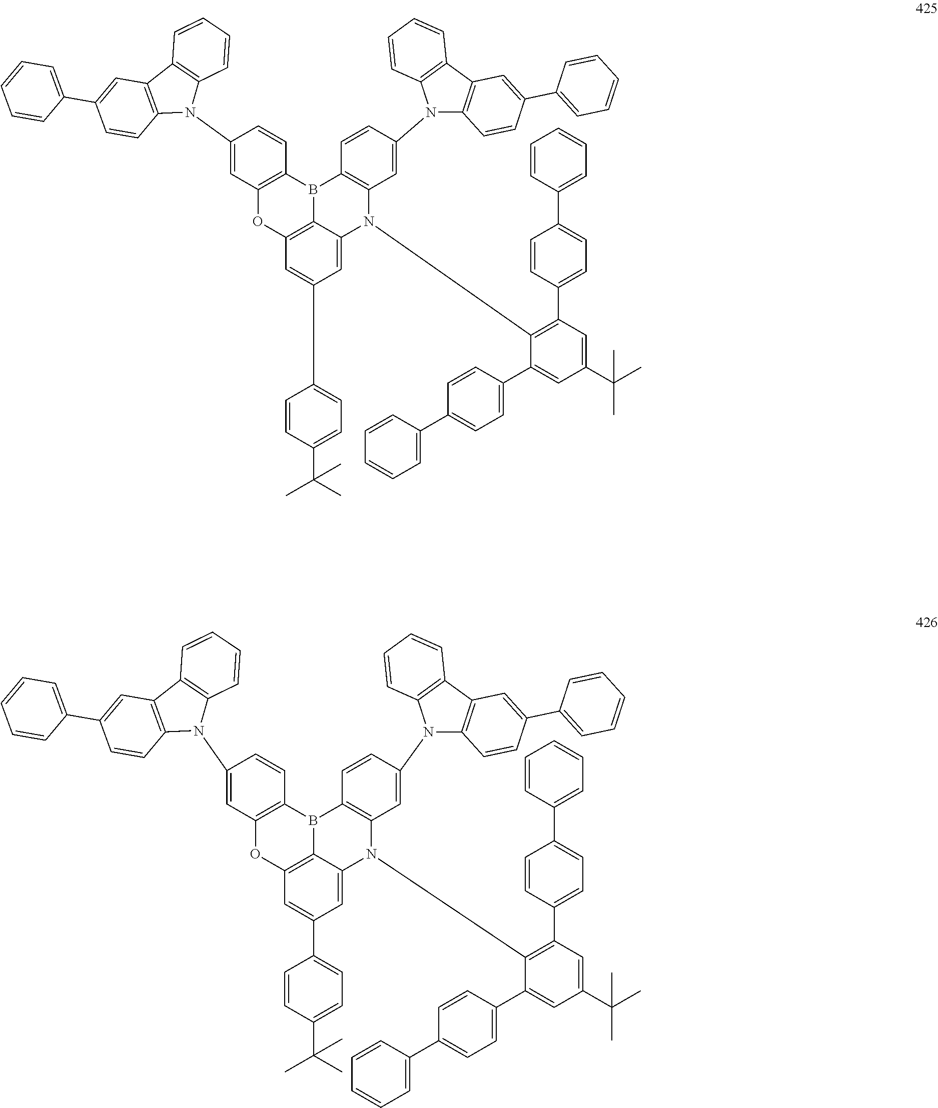 [SMILES: CC(C)(C)c1ccc(-c2cc3c4c(c2)N(c2c(-c5ccc(-c6ccccc6)cc5)cc(C(C)(C)C)cc2-c2ccc(-c5ccccc5)cc2)c2cc(-n5c6ccccc6c6cc(-c7ccccc7)ccc65)ccc2B4c2ccc(-n4c5ccccc5c5cc(-c6ccccc6)ccc54)cc2O3)cc1 ; CC(C)(C)c1ccc(-c2cc3c4c(c2)N(c2c(-c5ccc(-c6ccccc6)cc5)cc(C(C)(C)C)cc2-c2ccc(-c5ccccc5)cc2)c2cc(-n5c6ccccc6c6cc(-c7ccccc7)ccc65)ccc2B4c2ccc(-n4c5ccccc5c5cc(-c6ccccc6)ccc54)cc2O3)cc1] 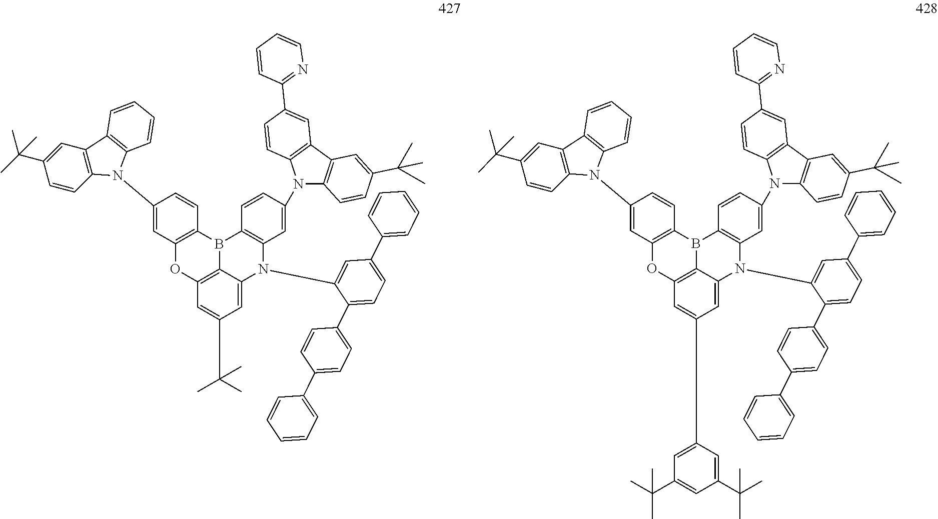 [SMILES: CC(C)(C)c1cc2c3c(c1)N(c1cc(-c4ccccc4)ccc1-c1ccc(-c4ccccc4)cc1)c1cc(-n4c5ccc(-c6ccccn6)cc5c5cc(C(C)(C)C)ccc54)ccc1B3c1ccc(-n3c4ccccc4c4cc(C(C)(C)C)ccc43)cc1O2 ; CC(C)(C)c1cc(-c2cc3c4c(c2)N(c2cc(-c5ccccc5)ccc2-c2ccc(-c5ccccc5)cc2)c2cc(-n5c6ccc(-c7ccccn7)cc6c6cc(C(C)(C)C)ccc65)ccc2B4c2ccc(-n4c5ccccc5c5cc(C(C)(C)C)ccc54)cc2O3)cc(C(C)(C)C)c1] 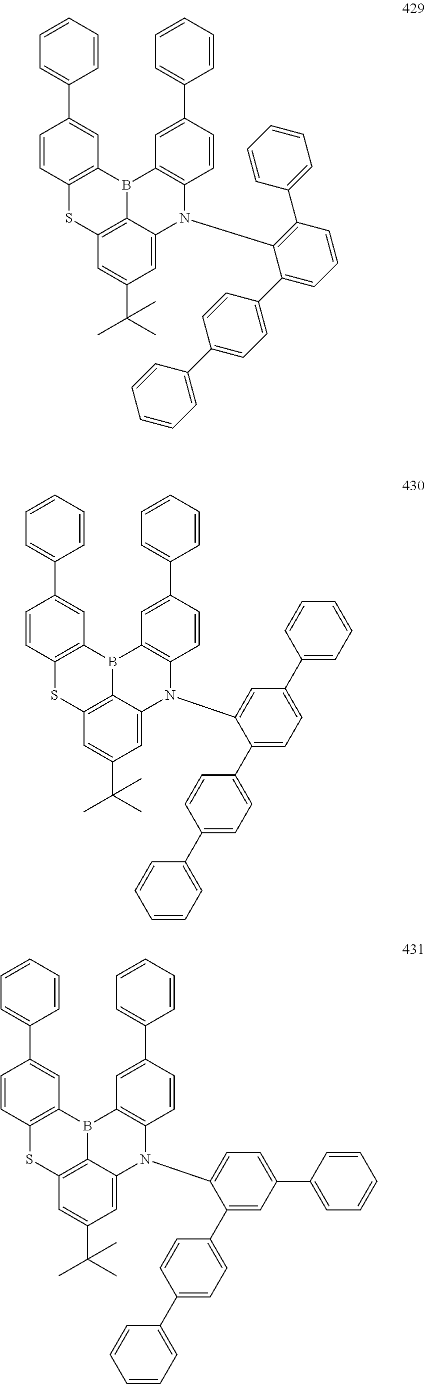 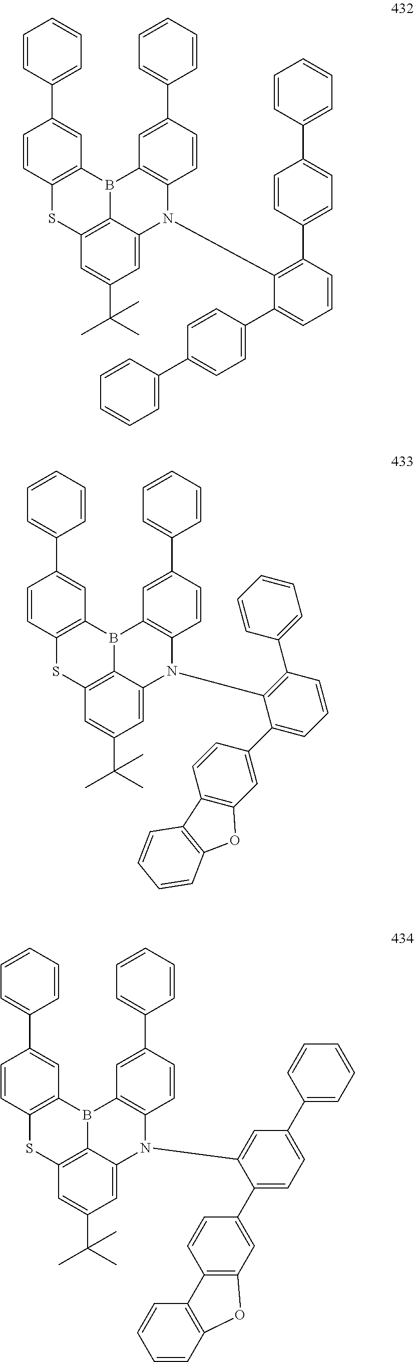 [SMILES: CC(C)(C)c1cc2c3c(c1)N(c1c(-c4ccc(-c5ccccc5)cc4)cccc1-c1ccc(-c4ccccc4)cc1)c1ccc(-c4ccccc4)cc1B3c1cc(-c3ccccc3)ccc1S2 ; CC(C)(C)c1cc2c3c(c1)N(c1c(-c4ccccc4)cccc1-c1ccc4c(c1)oc1ccccc14)c1ccc(-c4ccccc4)cc1B3c1cc(-c3ccccc3)ccc1S2 ; CC(C)(C)c1cc2c3c(c1)N(c1cc(-c4ccccc4)ccc1-c1ccc4c(c1)oc1ccccc14)c1ccc(-c4ccccc4)cc1B3c1cc(-c3ccccc3)ccc1S2] 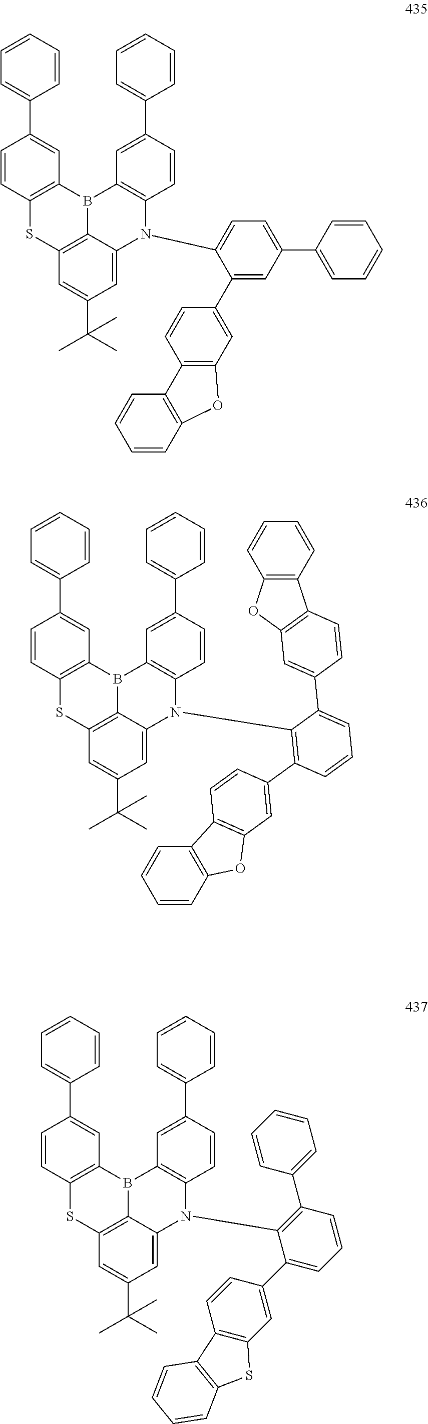 [SMILES: CC(C)(C)c1cc2c3c(c1)N(c1ccc(-c4ccccc4)cc1-c1ccc4c(c1)oc1ccccc14)c1ccc(-c4ccccc4)cc1B3c1cc(-c3ccccc3)ccc1S2 ; CC(C)(C)c1cc2c3c(c1)N(c1c(-c4ccc5c(c4)oc4ccccc45)cccc1-c1ccc4c(c1)oc1ccccc14)c1ccc(-c4ccccc4)cc1B3c1cc(-c3ccccc3)ccc1S2 ; CC(C)(C)c1cc2c3c(c1)N(c1c(-c4ccccc4)cccc1-c1ccc4c(c1)sc1ccccc14)c1ccc(-c4ccccc4)cc1B3c1cc(-c3ccccc3)ccc1S2] 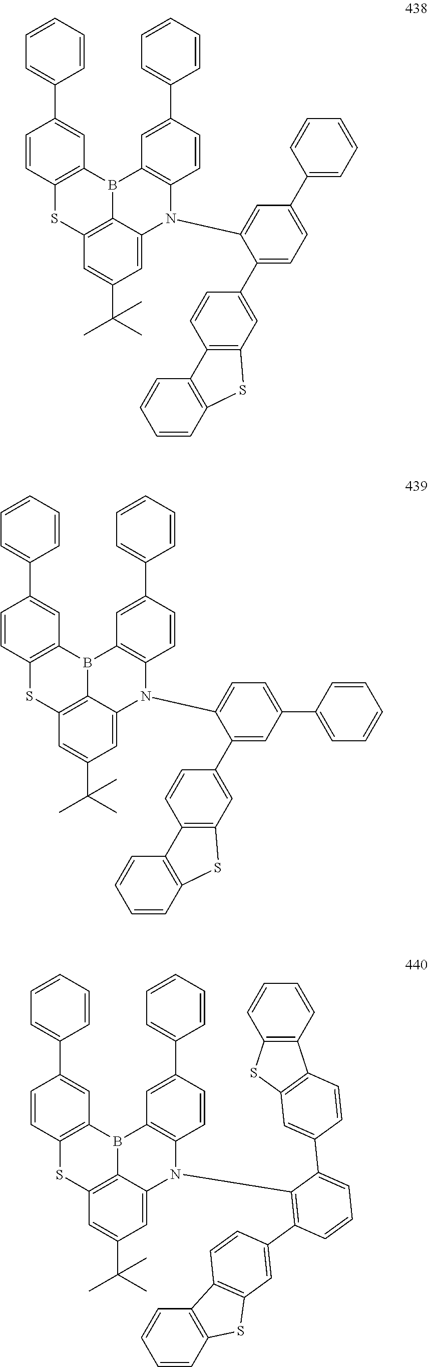 [SMILES: CC(C)(C)c1cc2c3c(c1)N(c1cc(-c4ccccc4)ccc1-c1ccc4c(c1)sc1ccccc14)c1ccc(-c4ccccc4)cc1B3c1cc(-c3ccccc3)ccc1S2 ; CC(C)(C)c1cc2c3c(c1)N(c1ccc(-c4ccccc4)cc1-c1ccc4c(c1)sc1ccccc14)c1ccc(-c4ccccc4)cc1B3c1cc(-c3ccccc3)ccc1S2 ; CC(C)(C)c1cc2c3c(c1)N(c1c(-c4ccc5c(c4)sc4ccccc45)cccc1-c1ccc4c(c1)sc1ccccc14)c1ccc(-c4ccccc4)cc1B3c1cc(-c3ccccc3)ccc1S2] 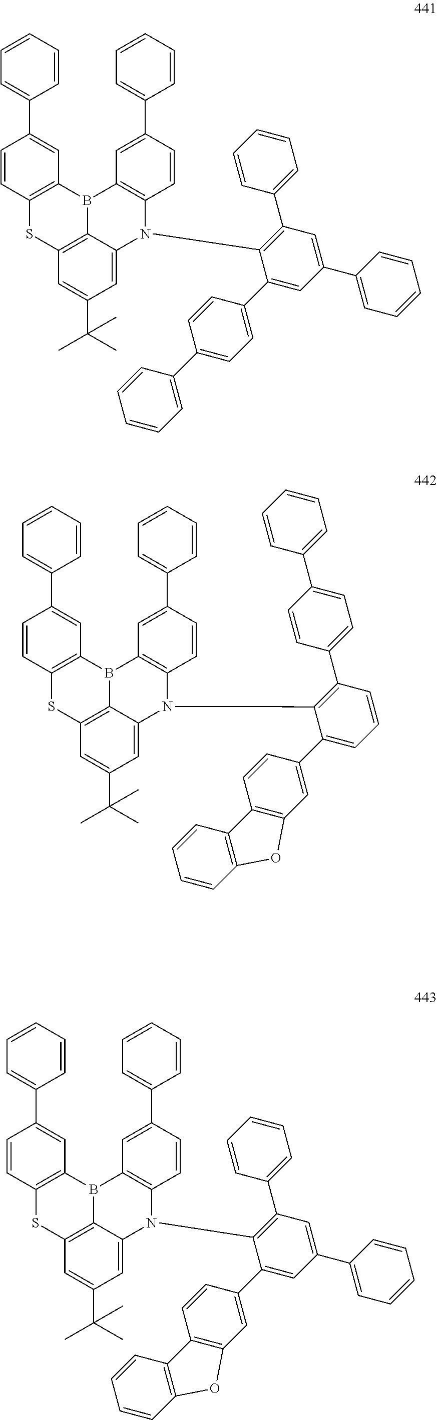 [SMILES: CC(C)(C)c1cc2c3c(c1)N(c1c(-c4ccccc4)cc(-c4ccccc4)cc1-c1ccc(-c4ccccc4)cc1)c1ccc(-c4ccccc4)cc1B3c1cc(-c3ccccc3)ccc1S2 ; CC(C)(C)c1cc2c3c(c1)N(c1c(-c4ccc(-c5ccccc5)cc4)cccc1-c1ccc4c(c1)oc1ccccc14)c1ccc(-c4ccccc4)cc1B3c1cc(-c3ccccc3)ccc1S2 ; CC(C)(C)c1cc2c3c(c1)N(c1c(-c4ccccc4)cc(-c4ccccc4)cc1-c1ccc4c(c1)oc1ccccc14)c1ccc(-c4ccccc4)cc1B3c1cc(-c3ccccc3)ccc1S2] 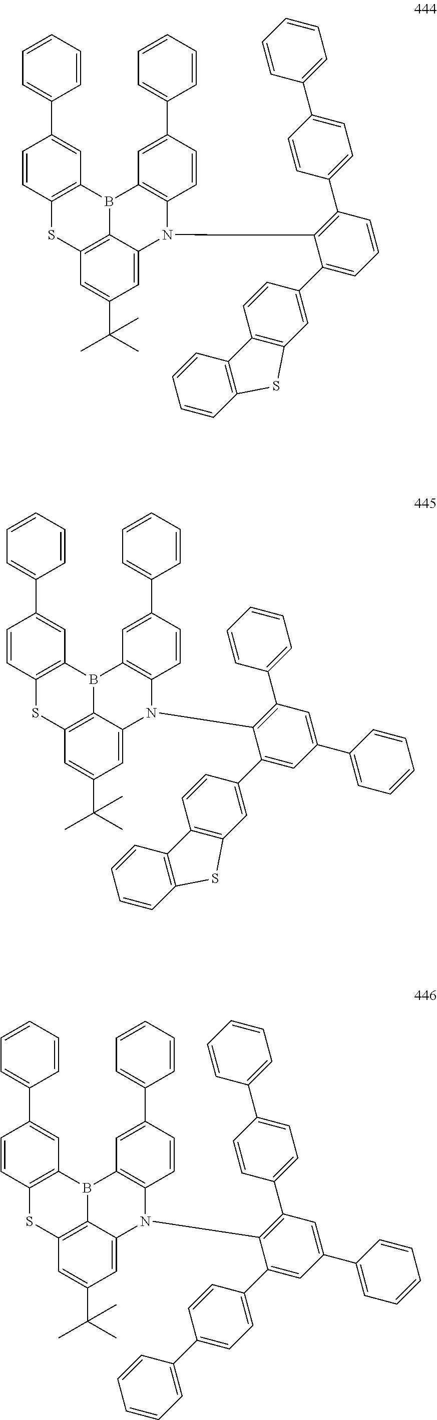 [SMILES: CC(C)(C)c1cc2c3c(c1)N(c1c(-c4ccc(-c5ccccc5)cc4)cccc1-c1ccc4c(c1)sc1ccccc14)c1ccc(-c4ccccc4)cc1B3c1cc(-c3ccccc3)ccc1S2 ; CC(C)(C)c1cc2c3c(c1)N(c1c(-c4ccccc4)cc(-c4ccccc4)cc1-c1ccc4c(c1)sc1ccccc14)c1ccc(-c4ccccc4)cc1B3c1cc(-c3ccccc3)ccc1S2 ; CC(C)(C)c1cc2c3c(c1)N(c1c(-c4ccc(-c5ccccc5)cc4)cc(-c4ccccc4)cc1-c1ccc(-c4ccccc4)cc1)c1ccc(-c4ccccc4)cc1B3c1cc(-c3ccccc3)ccc1S2] 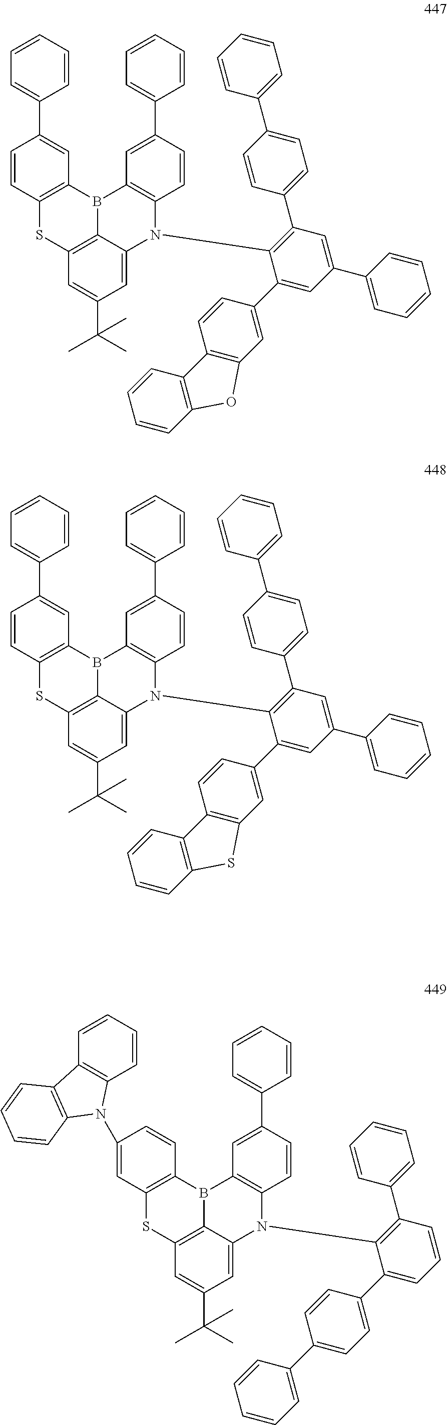 [SMILES: CC(C)(C)c1cc2c3c(c1)N(c1c(-c4ccc(-c5ccccc5)cc4)cc(-c4ccccc4)cc1-c1ccc4c(c1)oc1ccccc14)c1ccc(-c4ccccc4)cc1B3c1cc(-c3ccccc3)ccc1S2 ; CC(C)(C)c1cc2c3c(c1)N(c1c(-c4ccc(-c5ccccc5)cc4)cc(-c4ccccc4)cc1-c1ccc4c(c1)sc1ccccc14)c1ccc(-c4ccccc4)cc1B3c1cc(-c3ccccc3)ccc1S2 ; CC(C)(C)c1cc2c3c(c1)N(c1c(-c4ccccc4)cccc1-c1ccc(-c4ccccc4)cc1)c1ccc(-c4ccccc4)cc1B3c1ccc(-n3c4ccccc4c4ccccc43)cc1S2] 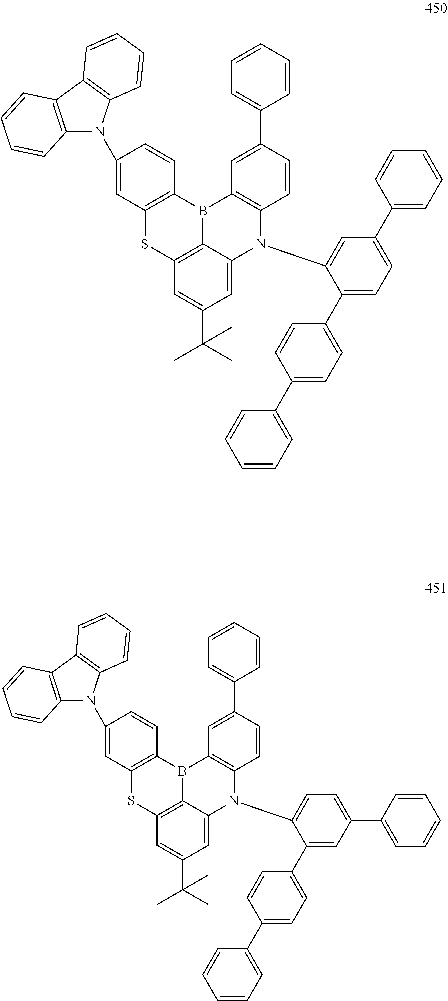 [SMILES: CC(C)(C)c1cc2c3c(c1)N(c1cc(-c4ccccc4)ccc1-c1ccc(-c4ccccc4)cc1)c1ccc(-c4ccccc4)cc1B3c1ccc(-n3c4ccccc4c4ccccc43)cc1S2 ; CC(C)(C)c1cc2c3c(c1)N(c1ccc(-c4ccccc4)cc1-c1ccc(-c4ccccc4)cc1)c1ccc(-c4ccccc4)cc1B3c1ccc(-n3c4ccccc4c4ccccc43)cc1S2] 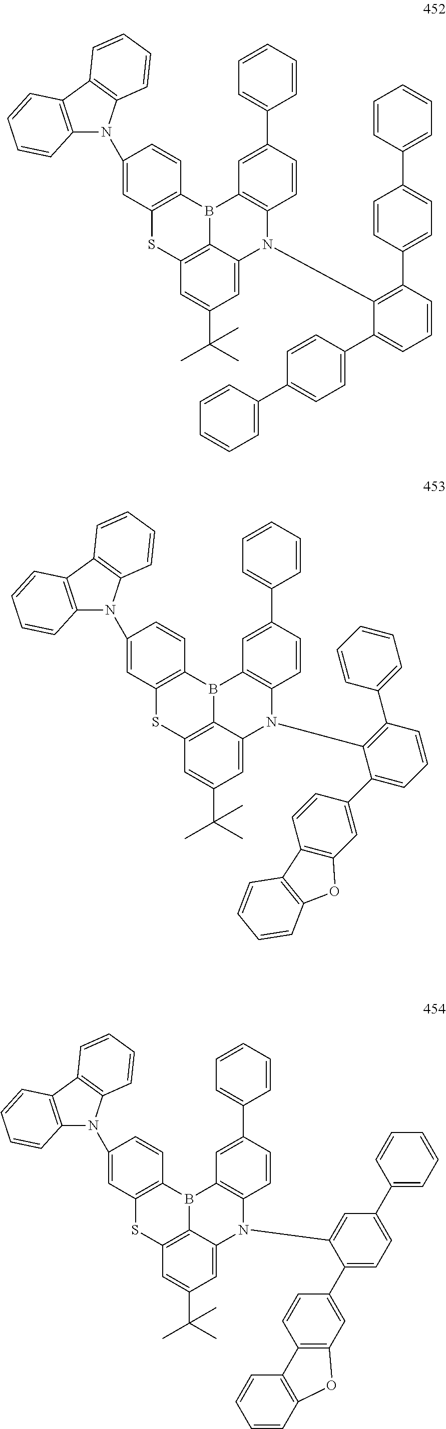 [SMILES: CC(C)(C)c1cc2c3c(c1)N(c1c(-c4ccc(-c5ccccc5)cc4)cccc1-c1ccc(-c4ccccc4)cc1)c1ccc(-c4ccccc4)cc1B3c1ccc(-n3c4ccccc4c4ccccc43)cc1S2 ; CC(C)(C)c1cc2c3c(c1)N(c1c(-c4ccccc4)cccc1-c1ccc4c(c1)oc1ccccc14)c1ccc(-c4ccccc4)cc1B3c1ccc(-n3c4ccccc4c4ccccc43)cc1S2 ; CC(C)(C)c1cc2c3c(c1)N(c1cc(-c4ccccc4)ccc1-c1ccc4c(c1)oc1ccccc14)c1ccc(-c4ccccc4)cc1B3c1ccc(-n3c4ccccc4c4ccccc43)cc1S2] 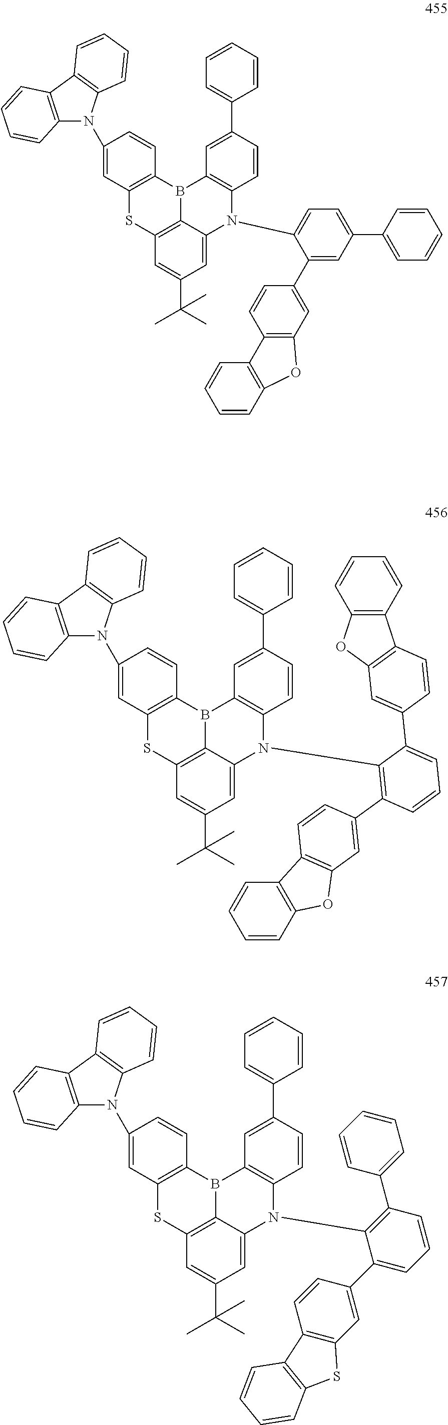 [SMILES: CC(C)(C)c1cc2c3c(c1)N(c1ccc(-c4ccccc4)cc1-c1ccc4c(c1)oc1ccccc14)c1ccc(-c4ccccc4)cc1B3c1ccc(-n3c4ccccc4c4ccccc43)cc1S2 ; CC(C)(C)c1cc2c3c(c1)N(c1c(-c4ccc5c(c4)oc4ccccc45)cccc1-c1ccc4c(c1)oc1ccccc14)c1ccc(-c4ccccc4)cc1B3c1ccc(-n3c4ccccc4c4ccccc43)cc1S2 ; CC(C)(C)c1cc2c3c(c1)N(c1c(-c4ccccc4)cccc1-c1ccc4c(c1)sc1ccccc14)c1ccc(-c4ccccc4)cc1B3c1ccc(-n3c4ccccc4c4ccccc43)cc1S2] 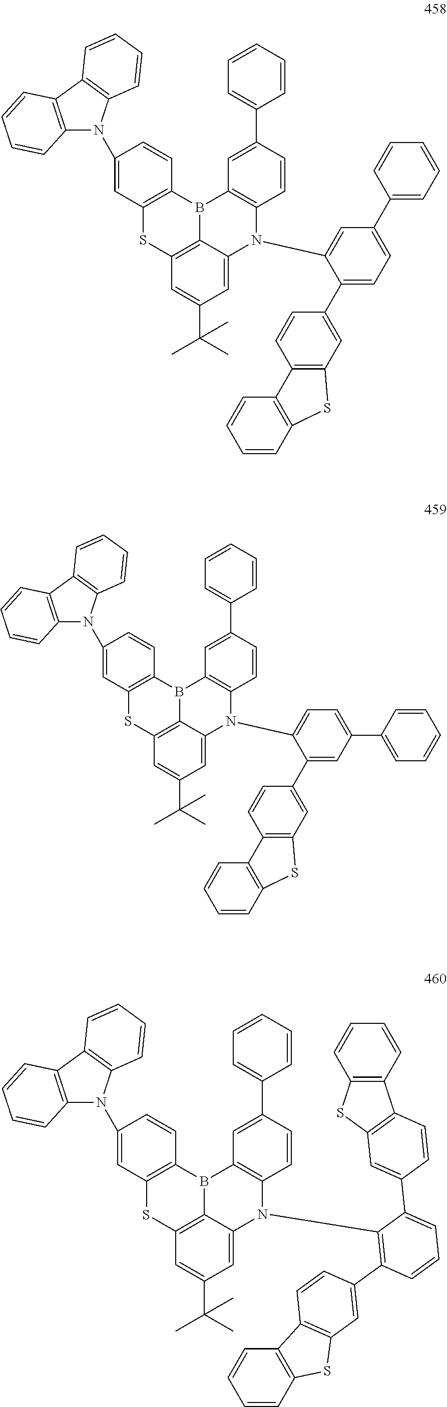 [SMILES: CC(C)(C)c1cc2c3c(c1)N(c1cc(-c4ccccc4)ccc1-c1ccc4c(c1)sc1ccccc14)c1ccc(-c4ccccc4)cc1B3c1ccc(-n3c4ccccc4c4ccccc43)cc1S2 ; CC(C)(C)c1cc2c3c(c1)N(c1ccc(-c4ccccc4)cc1-c1ccc4c(c1)sc1ccccc14)c1ccc(-c4ccccc4)cc1B3c1ccc(-n3c4ccccc4c4ccccc43)cc1S2 ; CC(C)(C)c1cc2c3c(c1)N(c1c(-c4ccc5c(c4)sc4ccccc45)cccc1-c1ccc4c(c1)sc1ccccc14)c1ccc(-c4ccccc4)cc1B3c1ccc(-n3c4ccccc4c4ccccc43)cc1S2] 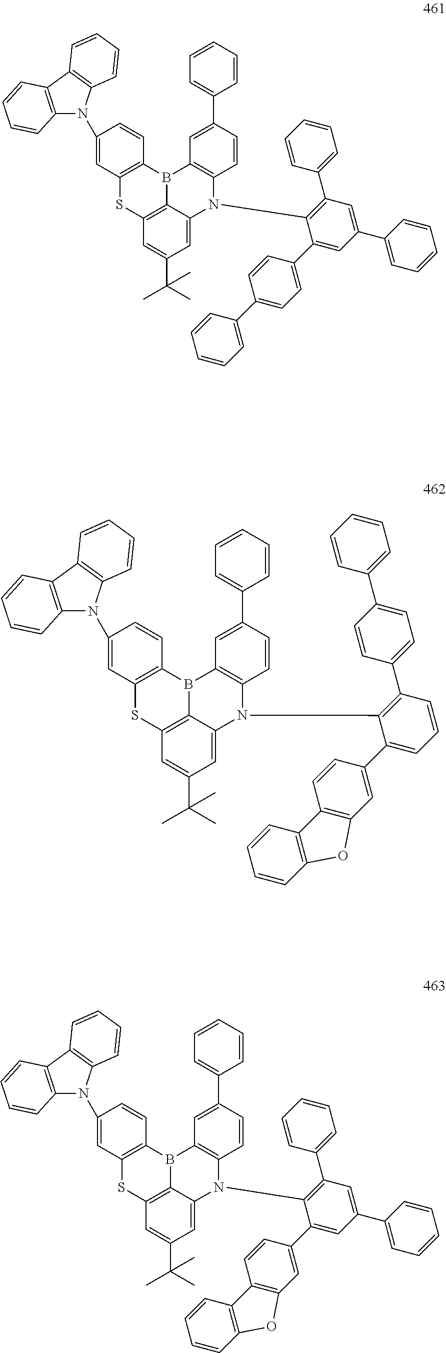 [SMILES: CC(C)(C)c1cc2c3c(c1)N(c1c(-c4ccccc4)cc(-c4ccccc4)cc1-c1ccc(-c4ccccc4)cc1)c1ccc(-c4ccccc4)cc1B3c1ccc(-n3c4ccccc4c4ccccc43)cc1S2 ; CC(C)(C)c1cc2c3c(c1)N(c1c(-c4ccc(-c5ccccc5)cc4)cccc1-c1ccc4c(c1)oc1ccccc14)c1ccc(-c4ccccc4)cc1B3c1ccc(-n3c4ccccc4c4ccccc43)cc1S2 ; CC(C)(C)c1cc2c3c(c1)N(c1c(-c4ccccc4)cc(-c4ccccc4)cc1-c1ccc4c(c1)oc1ccccc14)c1ccc(-c4ccccc4)cc1B3c1ccc(-n3c4ccccc4c4ccccc43)cc1S2] 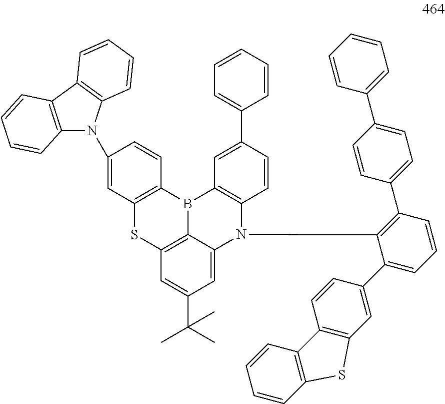 [SMILES: CC(C)(C)c1cc2c3c(c1)N(c1c(-c4ccc(-c5ccccc5)cc4)cccc1-c1ccc4c(c1)sc1ccccc14)c1ccc(-c4ccccc4)cc1B3c1ccc(-n3c4ccccc4c4ccccc43)cc1S2] 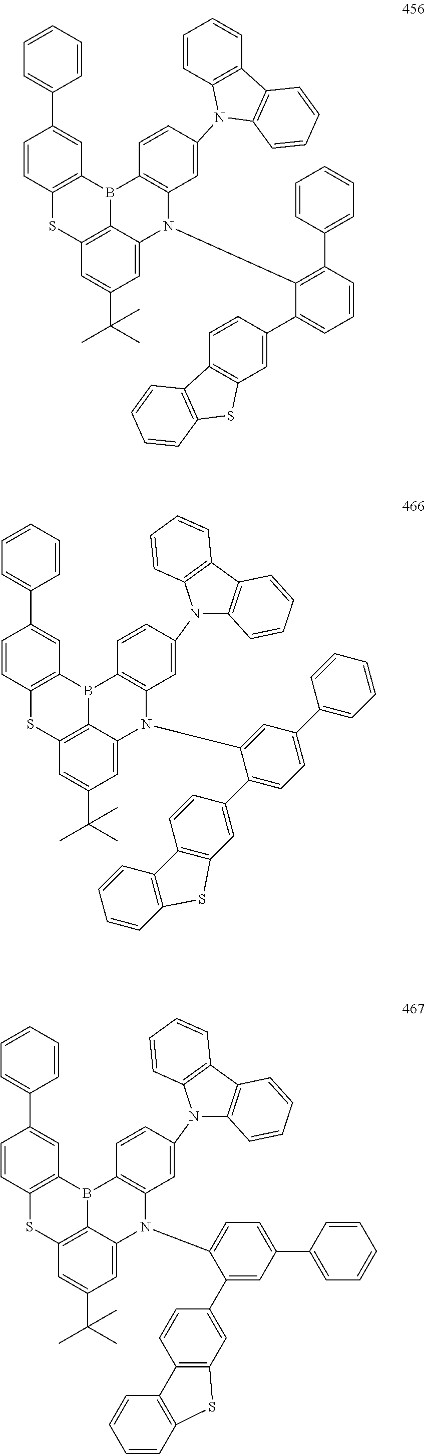 [SMILES: CC(C)(C)c1cc2c3c(c1)N(c1c(-c4ccccc4)cccc1-c1ccc4c(c1)sc1ccccc14)c1cc(-n4c5ccccc5c5ccccc54)ccc1B3c1cc(-c3ccccc3)ccc1S2 ; CC(C)(C)c1cc2c3c(c1)N(c1cc(-c4ccccc4)ccc1-c1ccc4c(c1)sc1ccccc14)c1cc(-n4c5ccccc5c5ccccc54)ccc1B3c1cc(-c3ccccc3)ccc1S2 ; CC(C)(C)c1cc2c3c(c1)N(c1ccc(-c4ccccc4)cc1-c1ccc4c(c1)sc1ccccc14)c1cc(-n4c5ccccc5c5ccccc54)ccc1B3c1cc(-c3ccccc3)ccc1S2] 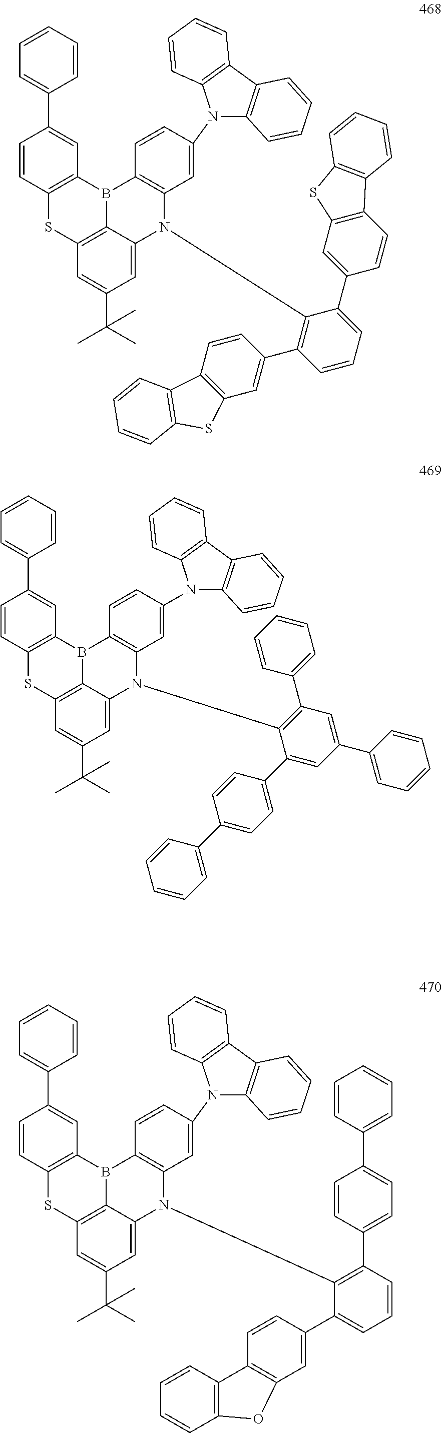 [SMILES: CC(C)(C)c1cc2c3c(c1)N(c1c(-c4ccc5c(c4)sc4ccccc45)cccc1-c1ccc4c(c1)sc1ccccc14)c1cc(-n4c5ccccc5c5ccccc54)ccc1B3c1cc(-c3ccccc3)ccc1S2 ; CC(C)(C)c1cc2c3c(c1)N(c1c(-c4ccccc4)cc(-c4ccccc4)cc1-c1ccc(-c4ccccc4)cc1)c1cc(-n4c5ccccc5c5ccccc54)ccc1B3c1cc(-c3ccccc3)ccc1S2 ; CC(C)(C)c1cc2c3c(c1)N(c1c(-c4ccc(-c5ccccc5)cc4)cccc1-c1ccc4c(c1)oc1ccccc14)c1cc(-n4c5ccccc5c5ccccc54)ccc1B3c1cc(-c3ccccc3)ccc1S2] 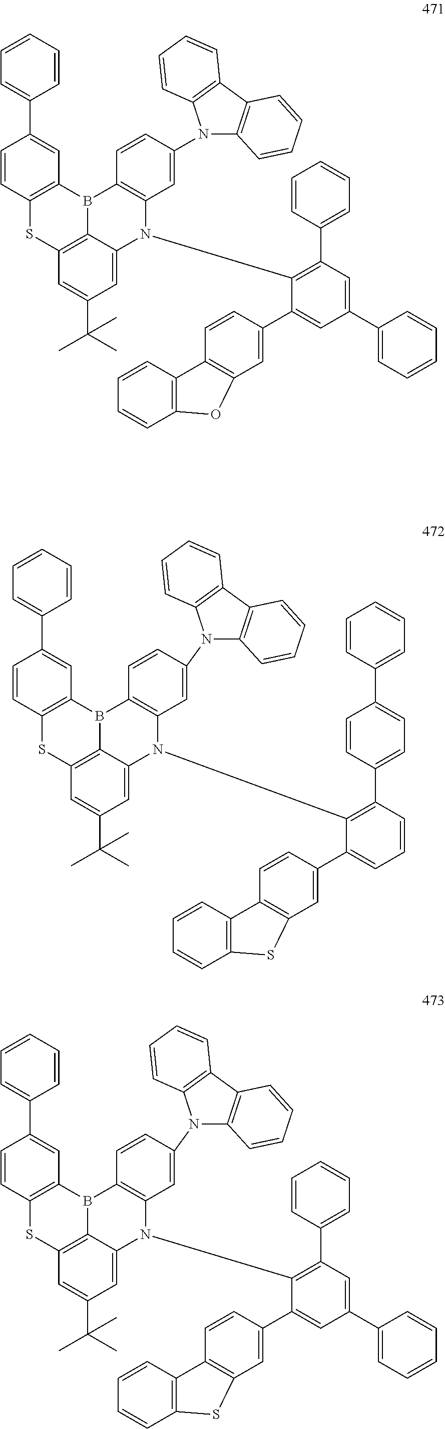 [SMILES: CC(C)(C)c1cc2c3c(c1)N(c1c(-c4ccccc4)cc(-c4ccccc4)cc1-c1ccc4c(c1)oc1ccccc14)c1cc(-n4c5ccccc5c5ccccc54)ccc1B3c1cc(-c3ccccc3)ccc1S2 ; CC(C)(C)c1cc2c3c(c1)N(c1c(-c4ccc(-c5ccccc5)cc4)cccc1-c1ccc4c(c1)sc1ccccc14)c1cc(-n4c5ccccc5c5ccccc54)ccc1B3c1cc(-c3ccccc3)ccc1S2 ; CC(C)(C)c1cc2c3c(c1)N(c1c(-c4ccccc4)cc(-c4ccccc4)cc1-c1ccc4c(c1)sc1ccccc14)c1cc(-n4c5ccccc5c5ccccc54)ccc1B3c1cc(-c3ccccc3)ccc1S2] 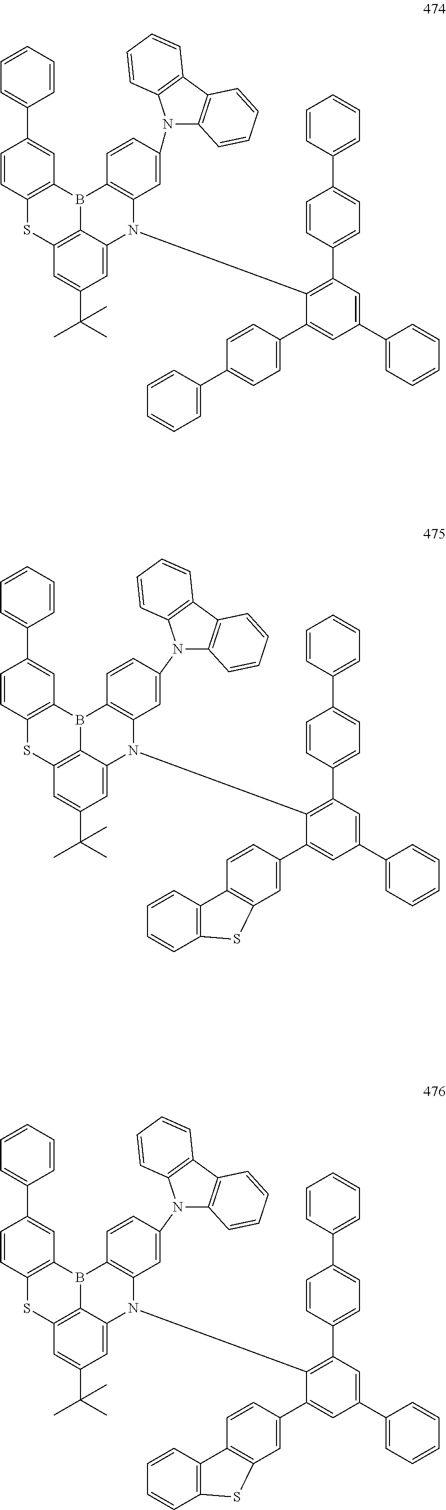 [SMILES: CC(C)(C)c1cc2c3c(c1)N(c1c(-c4ccc(-c5ccccc5)cc4)cc(-c4ccccc4)cc1-c1ccc(-c4ccccc4)cc1)c1cc(-n4c5ccccc5c5ccccc54)ccc1B3c1cc(-c3ccccc3)ccc1S2 ; CC(C)(C)c1cc2c3c(c1)N(c1c(-c4ccc(-c5ccccc5)cc4)cc(-c4ccccc4)cc1-c1ccc4c(c1)sc1ccccc14)c1cc(-n4c5ccccc5c5ccccc54)ccc1B3c1cc(-c3ccccc3)ccc1S2 ; CC(C)(C)c1cc2c3c(c1)N(c1c(-c4ccc(-c5ccccc5)cc4)cc(-c4ccccc4)cc1-c1ccc4c(c1)sc1ccccc14)c1cc(-n4c5ccccc5c5ccccc54)ccc1B3c1cc(-c3ccccc3)ccc1S2] 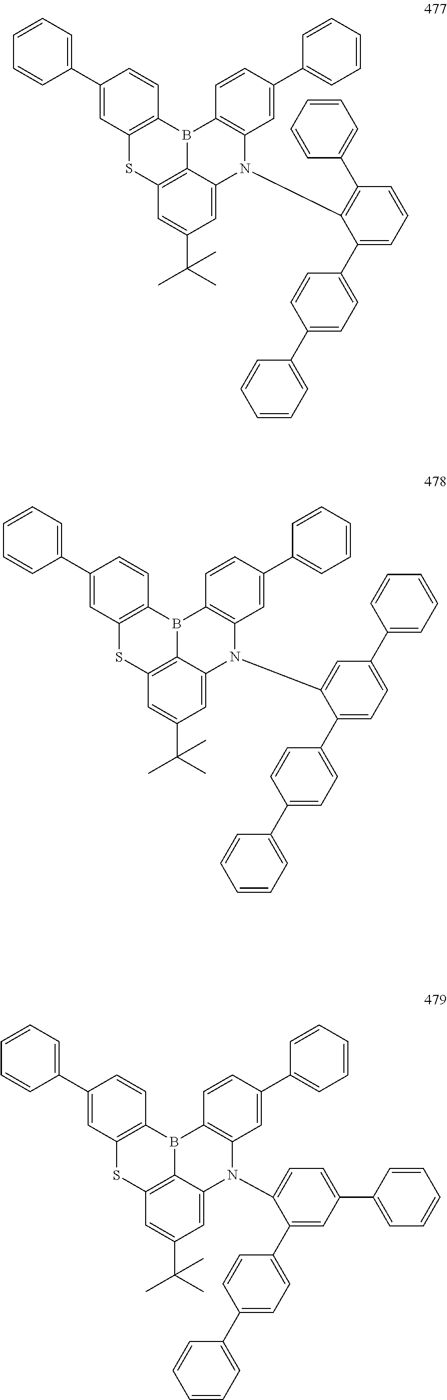 [SMILES: CC(C)(C)c1cc2c3c(c1)N(c1c(-c4ccccc4)cccc1-c1ccc(-c4ccccc4)cc1)c1cc(-c4ccccc4)ccc1B3c1ccc(-c3ccccc3)cc1S2 ; CC(C)(C)c1cc2c3c(c1)N(c1cc(-c4ccccc4)ccc1-c1ccc(-c4ccccc4)cc1)c1cc(-c4ccccc4)ccc1B3c1ccc(-c3ccccc3)cc1S2 ; CC(C)(C)c1cc2c3c(c1)N(c1ccc(-c4ccccc4)cc1-c1ccc(-c4ccccc4)cc1)c1cc(-c4ccccc4)ccc1B3c1ccc(-c3ccccc3)cc1S2] 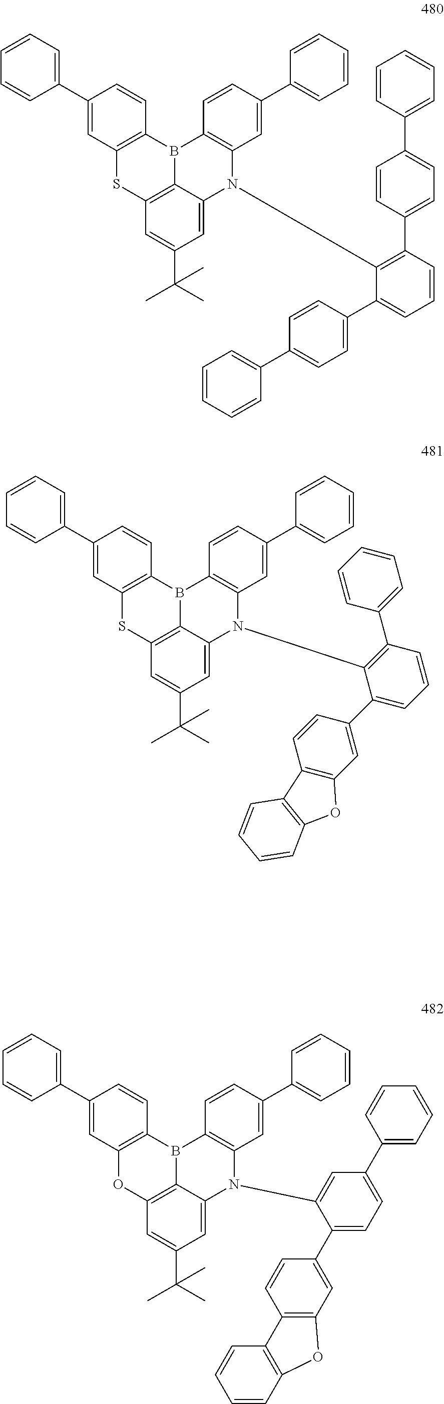 [SMILES: CC(C)(C)c1cc2c3c(c1)N(c1c(-c4ccc(-c5ccccc5)cc4)cccc1-c1ccc(-c4ccccc4)cc1)c1cc(-c4ccccc4)ccc1B3c1ccc(-c3ccccc3)cc1S2 ; CC(C)(C)c1cc2c3c(c1)N(c1c(-c4ccccc4)cccc1-c1ccc4c(c1)oc1ccccc14)c1cc(-c4ccccc4)ccc1B3c1ccc(-c3ccccc3)cc1S2 ; CC(C)(C)c1cc2c3c(c1)N(c1cc(-c4ccccc4)ccc1-c1ccc4c(c1)oc1ccccc14)c1cc(-c4ccccc4)ccc1B3c1ccc(-c3ccccc3)cc1O2] 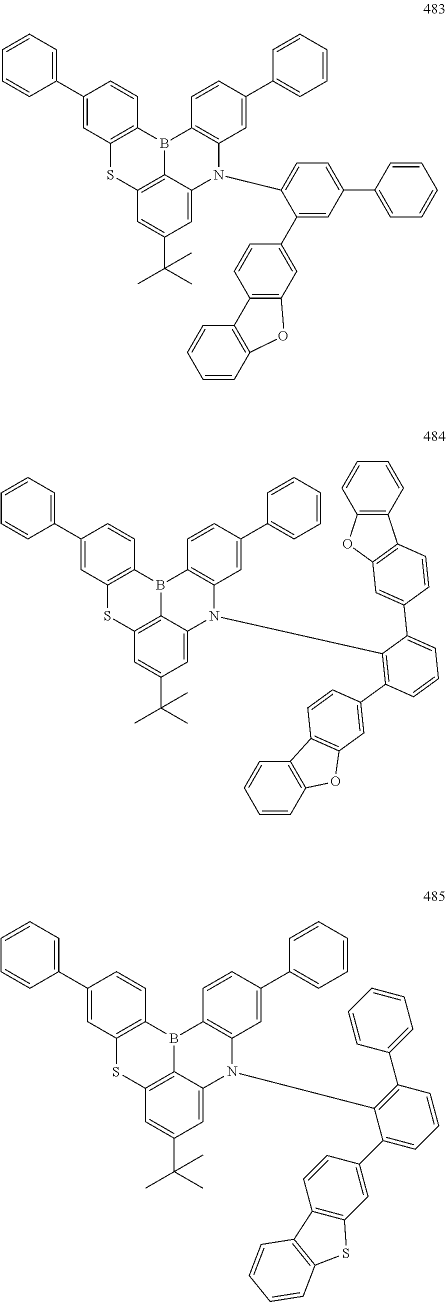 [SMILES: CC(C)(C)c1cc2c3c(c1)N(c1ccc(-c4ccccc4)cc1-c1ccc4c(c1)oc1ccccc14)c1cc(-c4ccccc4)ccc1B3c1ccc(-c3ccccc3)cc1S2 ; CC(C)(C)c1cc2c3c(c1)N(c1c(-c4ccc5c(c4)oc4ccccc45)cccc1-c1ccc4c(c1)oc1ccccc14)c1cc(-c4ccccc4)ccc1B3c1ccc(-c3ccccc3)cc1S2 ; CC(C)(C)c1cc2c3c(c1)N(c1c(-c4ccccc4)cccc1-c1ccc4c(c1)sc1ccccc14)c1cc(-c4ccccc4)ccc1B3c1ccc(-c3ccccc3)cc1S2] 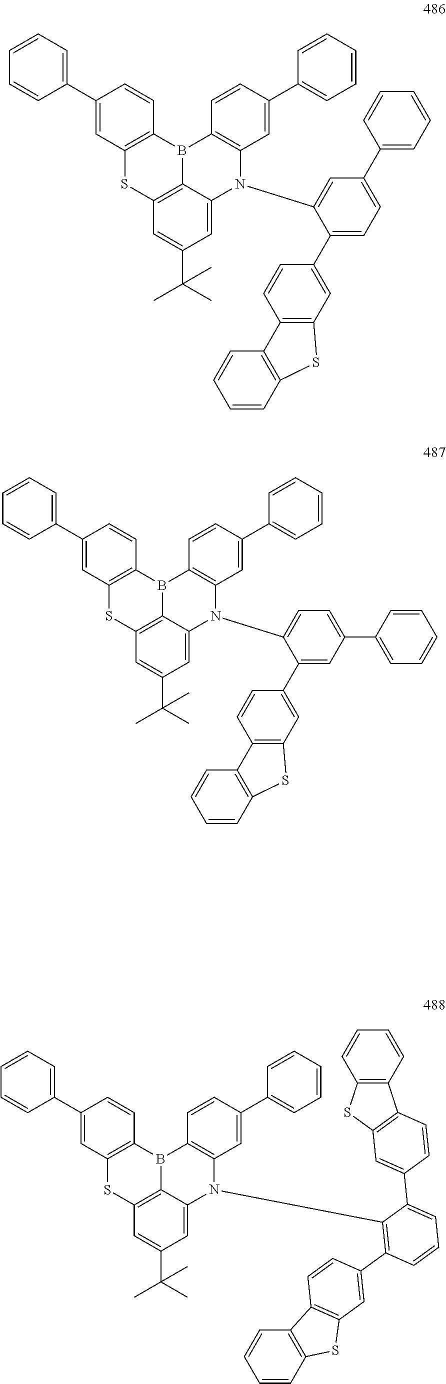 [SMILES: CC(C)(C)c1cc2c3c(c1)N(c1cc(-c4ccccc4)ccc1-c1ccc4c(c1)sc1ccccc14)c1cc(-c4ccccc4)ccc1B3c1ccc(-c3ccccc3)cc1S2 ; CC(C)(C)c1cc2c3c(c1)N(c1ccc(-c4ccccc4)cc1-c1ccc4c(c1)sc1ccccc14)c1cc(-c4ccccc4)ccc1B3c1ccc(-c3ccccc3)cc1S2 ; CC(C)(C)c1cc2c3c(c1)N(c1c(-c4ccc5c(c4)sc4ccccc45)cccc1-c1ccc4c(c1)sc1ccccc14)c1cc(-c4ccccc4)ccc1B3c1ccc(-c3ccccc3)cc1S2] 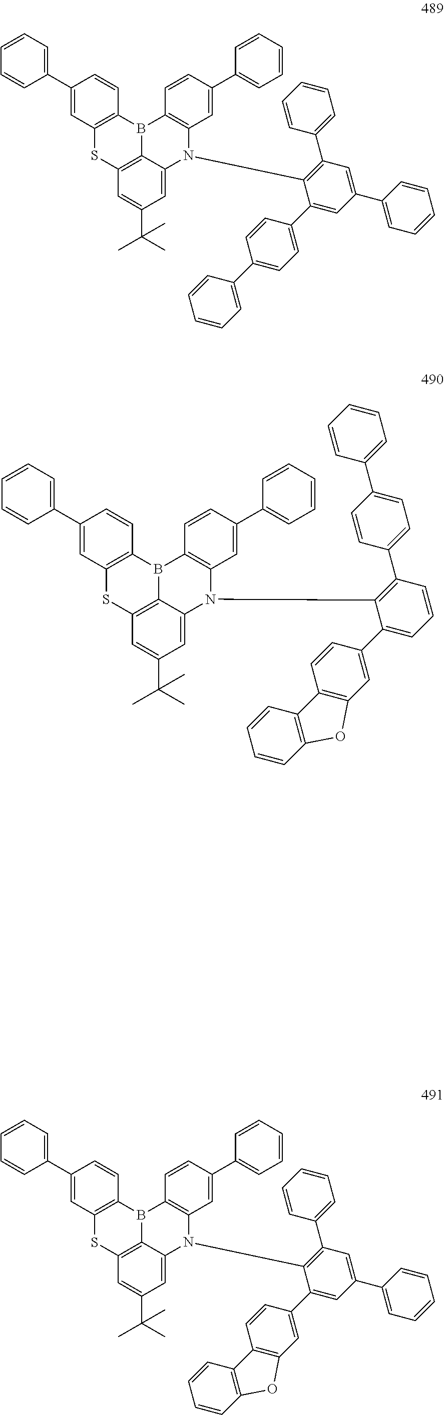 [SMILES: CC(C)(C)c1cc2c3c(c1)N(c1c(-c4ccccc4)cc(-c4ccccc4)cc1-c1ccc(-c4ccccc4)cc1)c1cc(-c4ccccc4)ccc1B3c1ccc(-c3ccccc3)cc1S2 ; CC(C)(C)c1cc2c3c(c1)N(c1c(-c4ccc(-c5ccccc5)cc4)cccc1-c1ccc4c(c1)oc1ccccc14)c1cc(-c4ccccc4)ccc1B3c1ccc(-c3ccccc3)cc1S2 ; CC(C)(C)c1cc2c3c(c1)N(c1c(-c4ccccc4)cc(-c4ccccc4)cc1-c1ccc4c(c1)oc1ccccc14)c1cc(-c4ccccc4)ccc1B3c1ccc(-c3ccccc3)cc1S2] 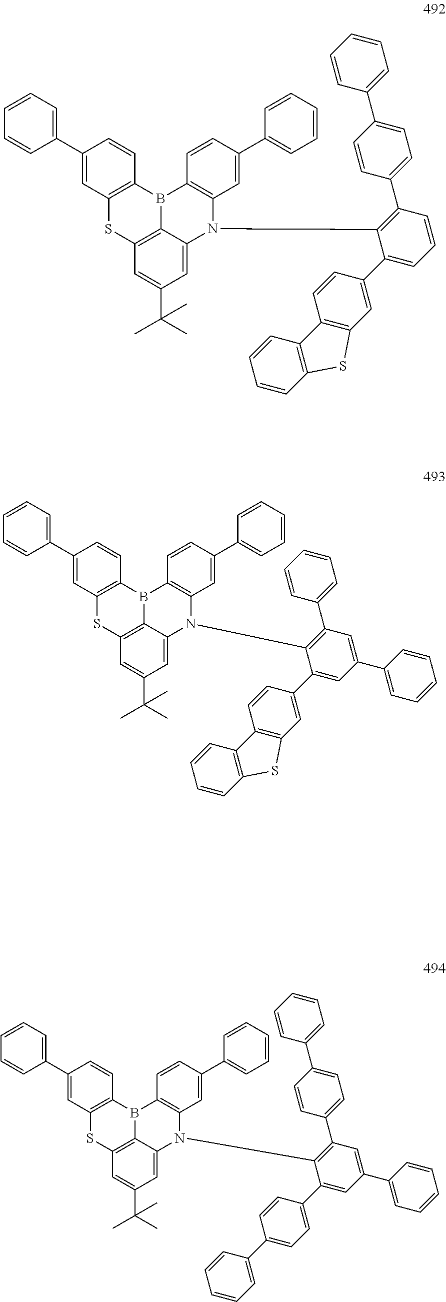 [SMILES: CC(C)(C)c1cc2c3c(c1)N(c1c(-c4ccc(-c5ccccc5)cc4)cccc1-c1ccc4c(c1)sc1ccccc14)c1cc(-c4ccccc4)ccc1B3c1ccc(-c3ccccc3)cc1S2 ; CC(C)(C)c1cc2c3c(c1)N(c1c(-c4ccccc4)cc(-c4ccccc4)cc1-c1ccc4c(c1)sc1ccccc14)c1cc(-c4ccccc4)ccc1B3c1ccc(-c3ccccc3)cc1S2 ; CC(C)(C)c1cc2c3c(c1)N(c1c(-c4ccc(-c5ccccc5)cc4)cc(-c4ccccc4)cc1-c1ccc(-c4ccccc4)cc1)c1cc(-c4ccccc4)ccc1B3c1ccc(-c3ccccc3)cc1S2] 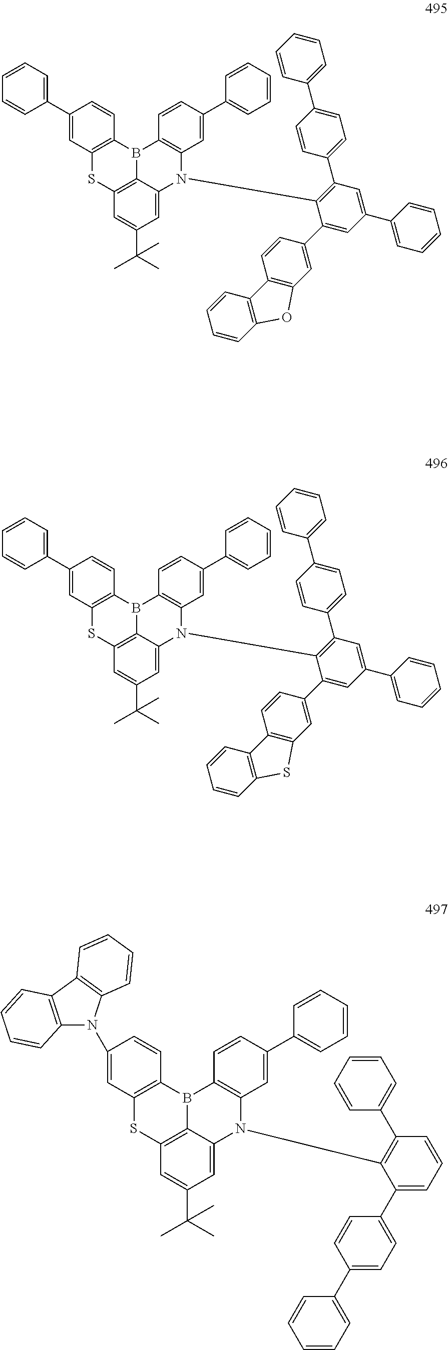 [SMILES: CC(C)(C)c1cc2c3c(c1)N(c1c(-c4ccc(-c5ccccc5)cc4)cc(-c4ccccc4)cc1-c1ccc4c(c1)oc1ccccc14)c1cc(-c4ccccc4)ccc1B3c1ccc(-c3ccccc3)cc1S2 ; CC(C)(C)c1cc2c3c(c1)N(c1c(-c4ccc(-c5ccccc5)cc4)cc(-c4ccccc4)cc1-c1ccc4c(c1)sc1ccccc14)c1cc(-c4ccccc4)ccc1B3c1ccc(-c3ccccc3)cc1S2 ; CC(C)(C)c1cc2c3c(c1)N(c1c(-c4ccccc4)cccc1-c1ccc(-c4ccccc4)cc1)c1cc(-c4ccccc4)ccc1B3c1ccc(-n3c4ccccc4c4ccccc43)cc1S2] 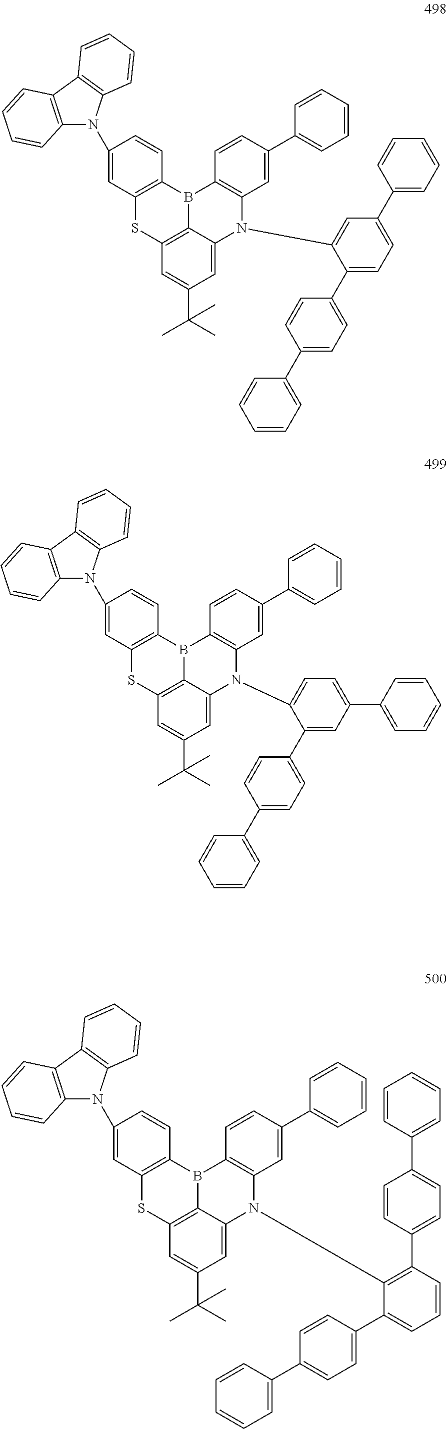 [SMILES: CC(C)(C)c1cc2c3c(c1)N(c1cc(-c4ccccc4)ccc1-c1ccc(-c4ccccc4)cc1)c1cc(-c4ccccc4)ccc1B3c1ccc(-n3c4ccccc4c4ccccc43)cc1S2 ; CC(C)(C)c1cc2c3c(c1)N(c1ccc(-c4ccccc4)cc1-c1ccc(-c4ccccc4)cc1)c1cc(-c4ccccc4)ccc1B3c1ccc(-n3c4ccccc4c4ccccc43)cc1S2 ; CC(C)(C)c1cc2c3c(c1)N(c1c(-c4ccc(-c5ccccc5)cc4)cccc1-c1ccc(-c4ccccc4)cc1)c1cc(-c4ccccc4)ccc1B3c1ccc(-n3c4ccccc4c4ccccc43)cc1S2] 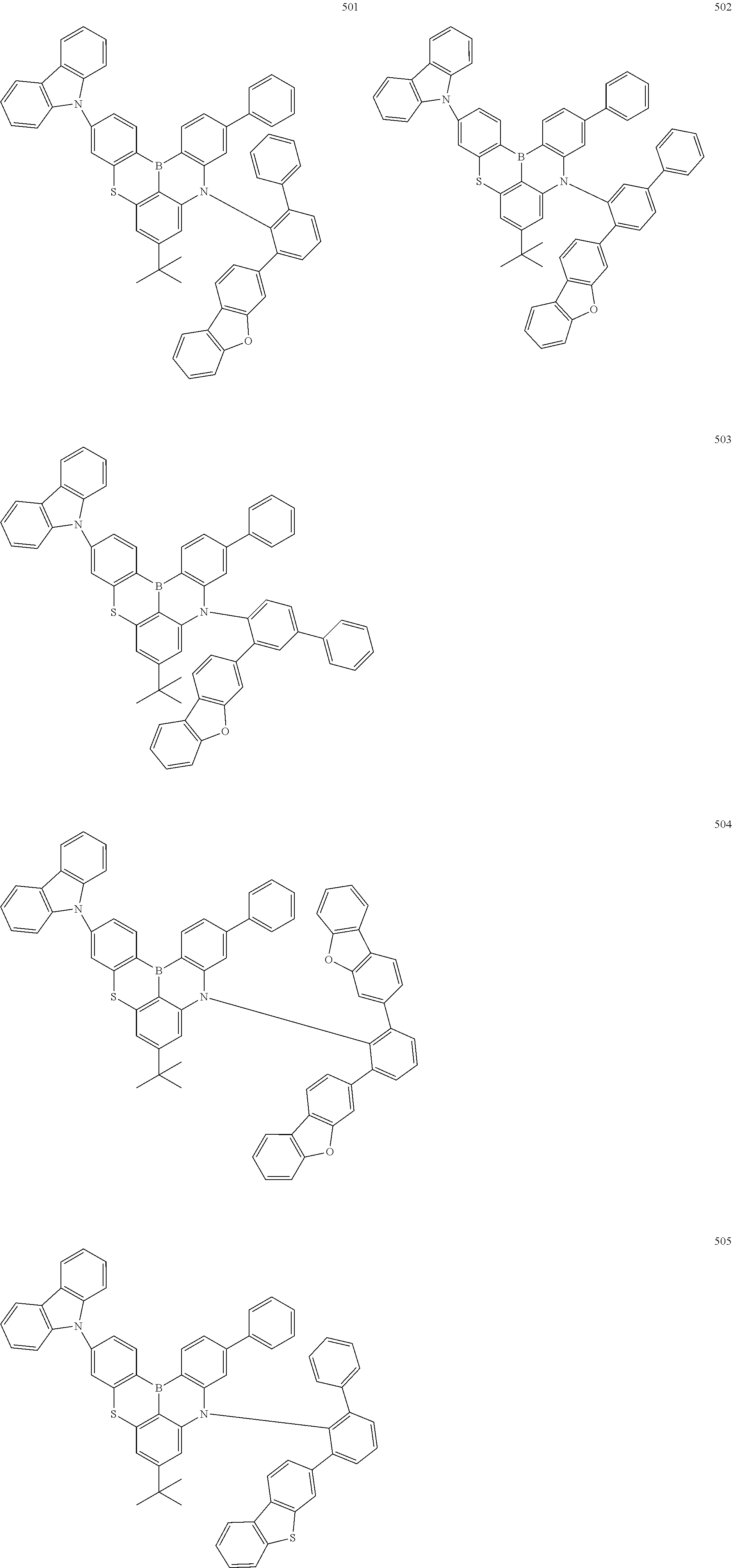 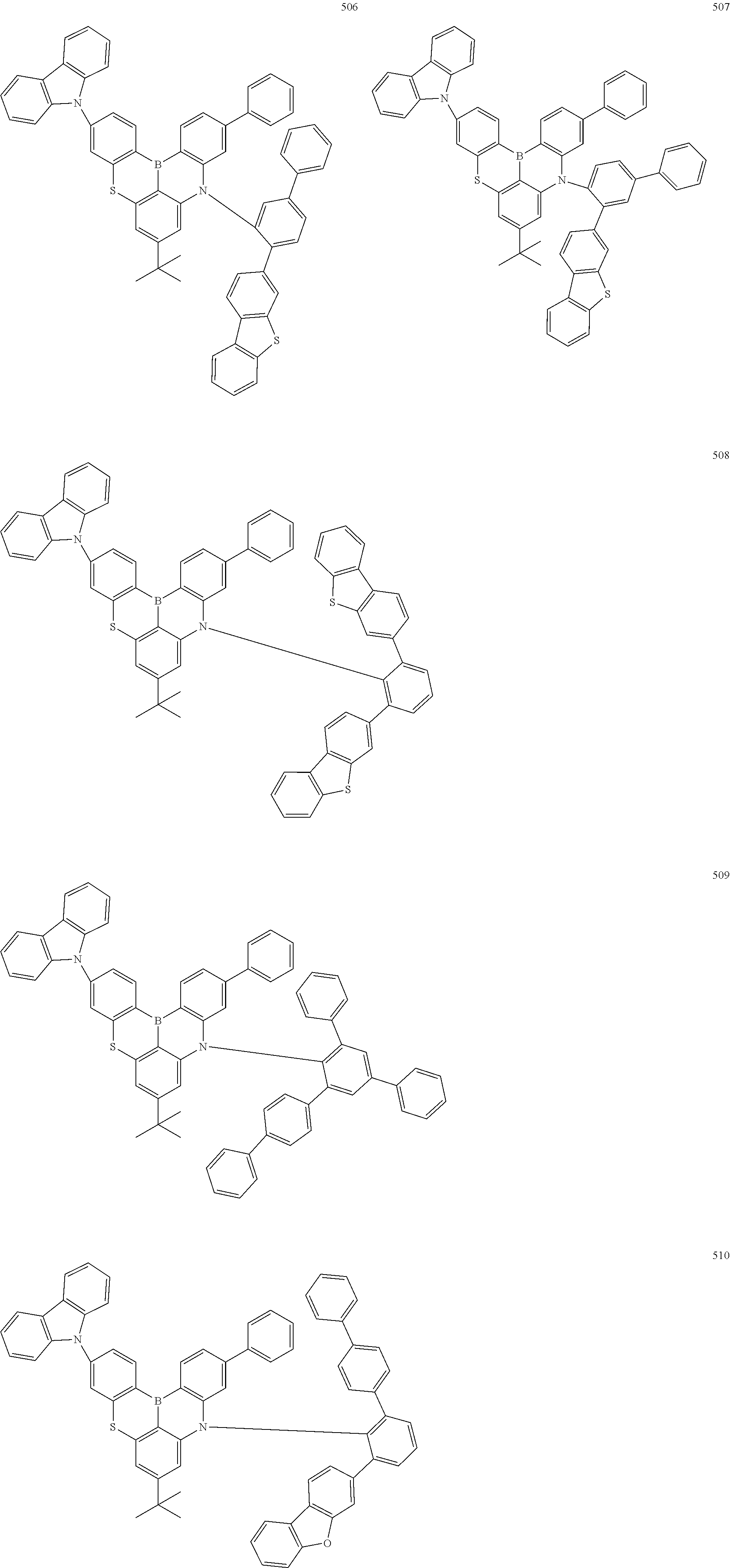 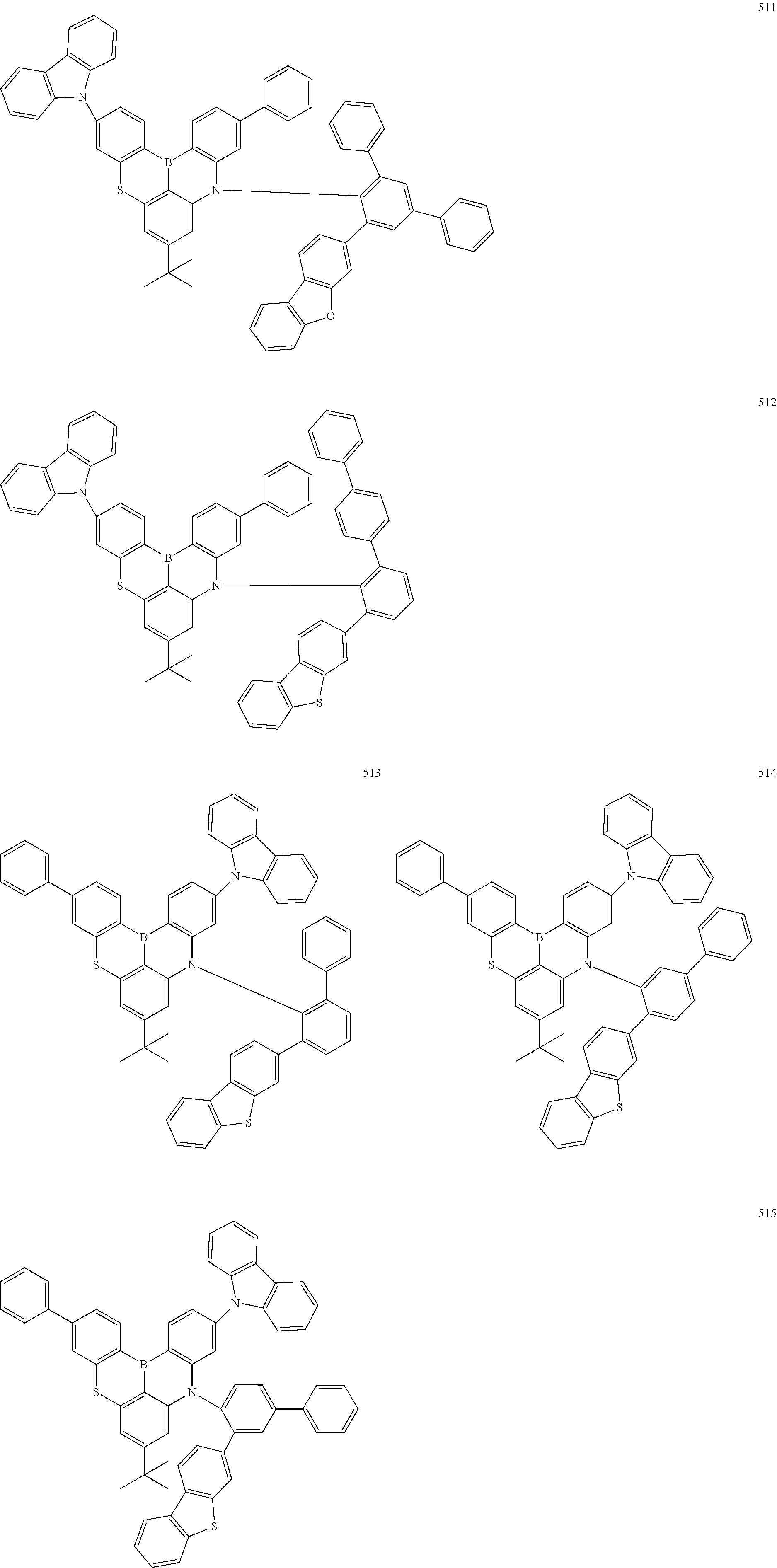 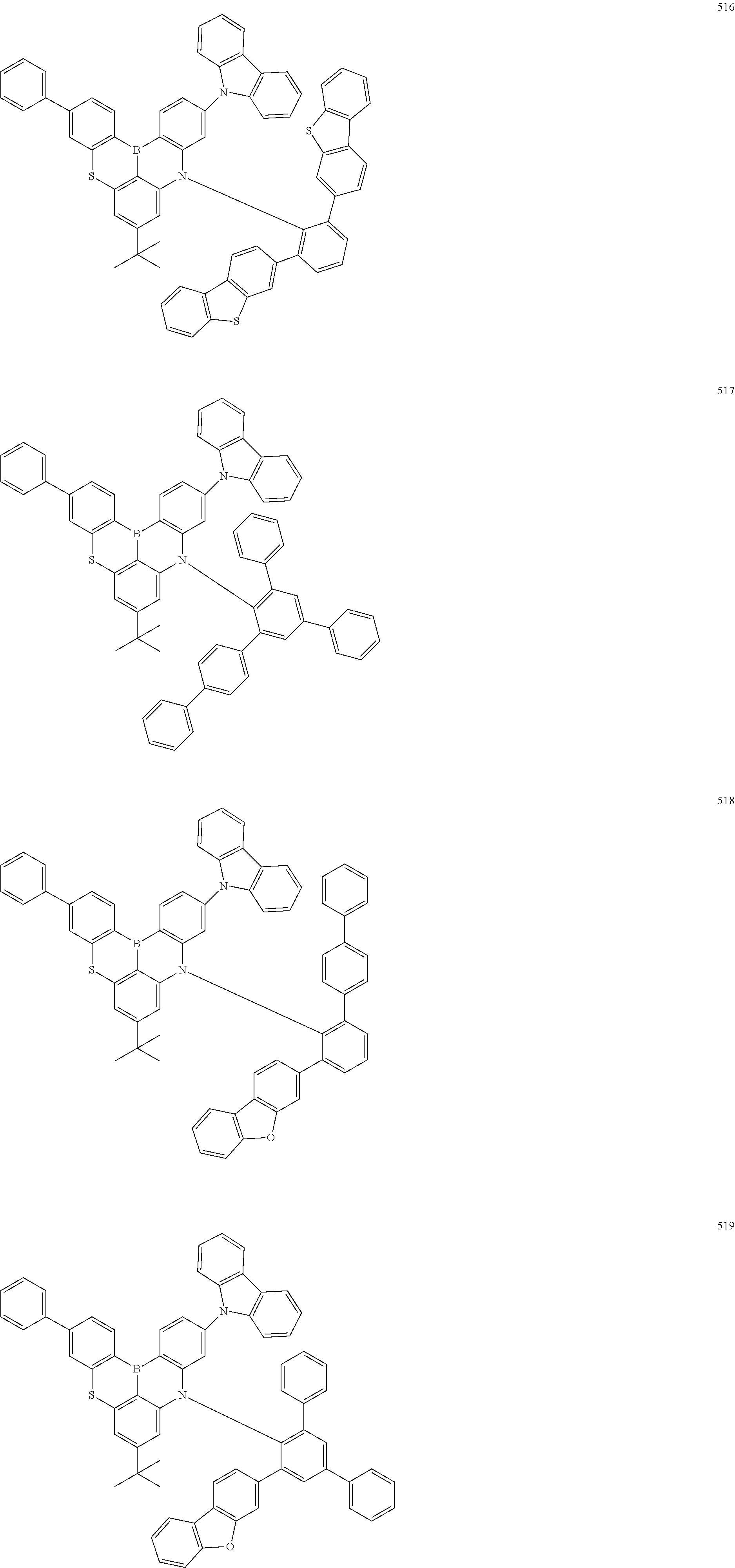 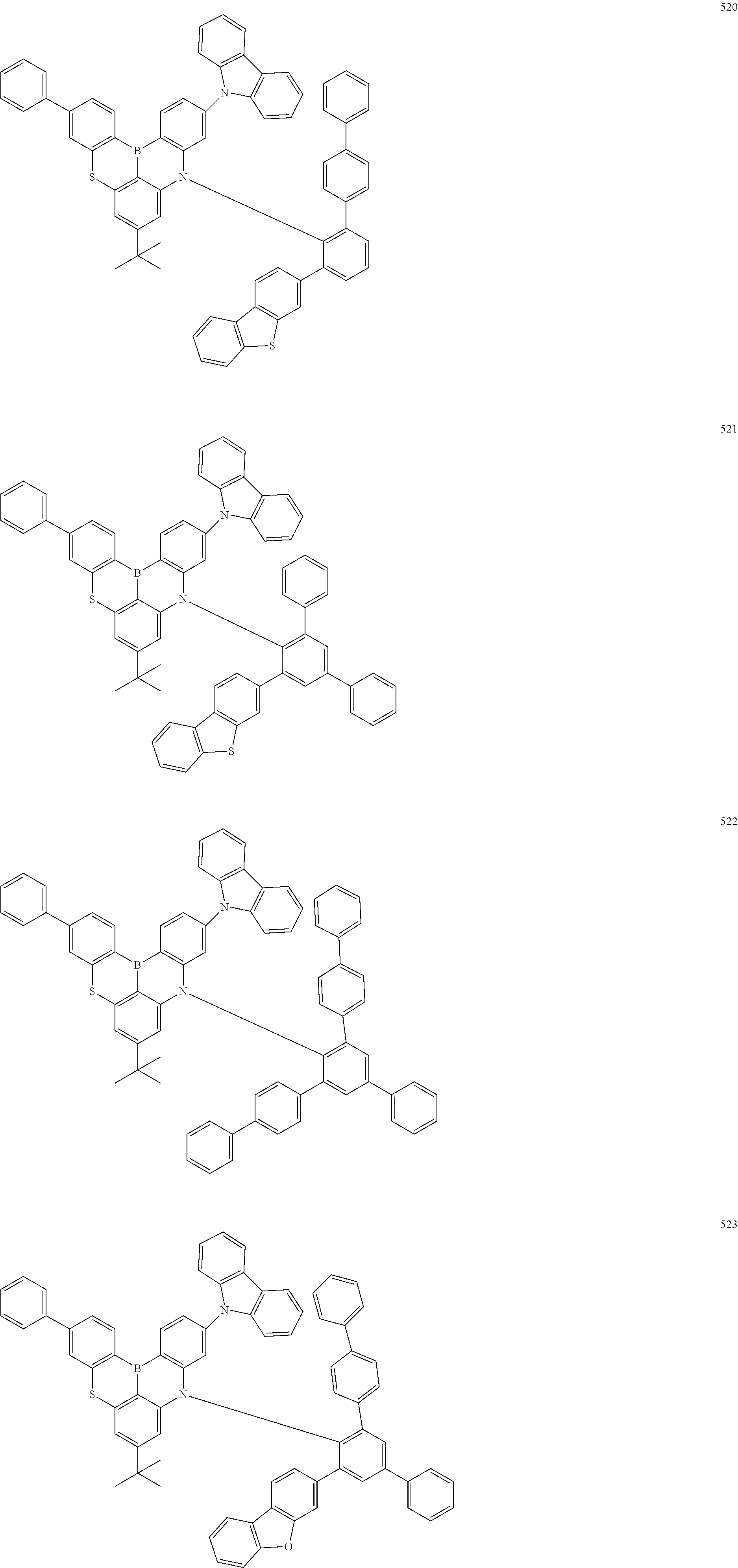 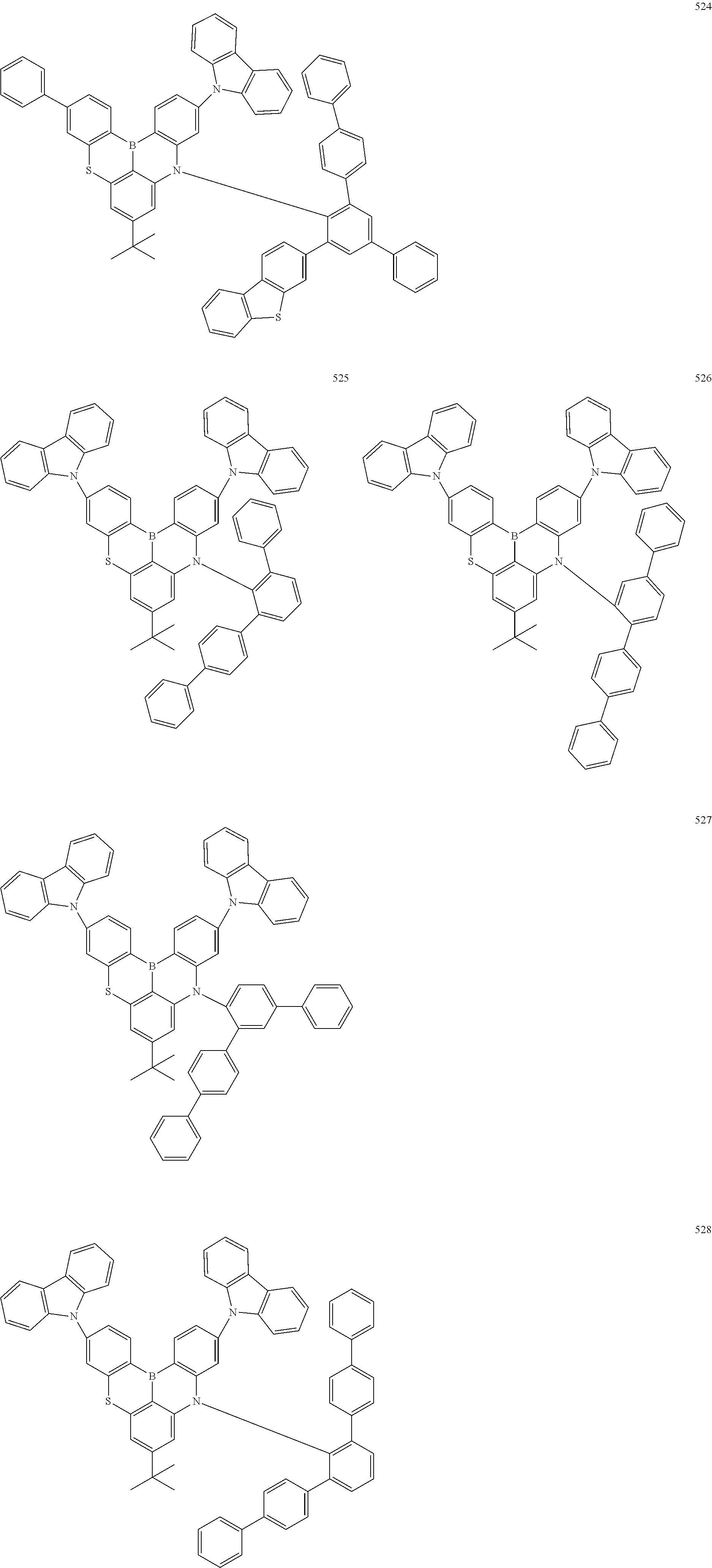 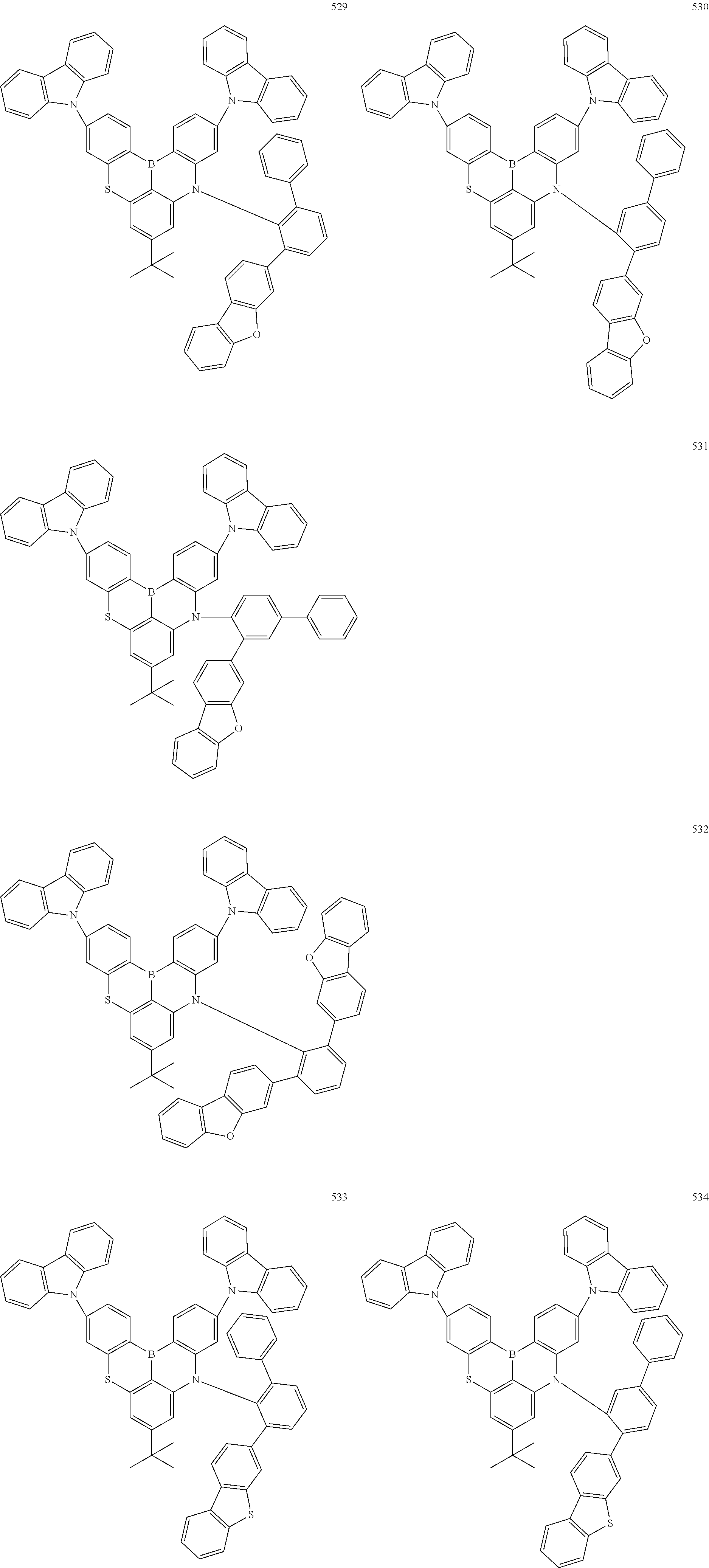 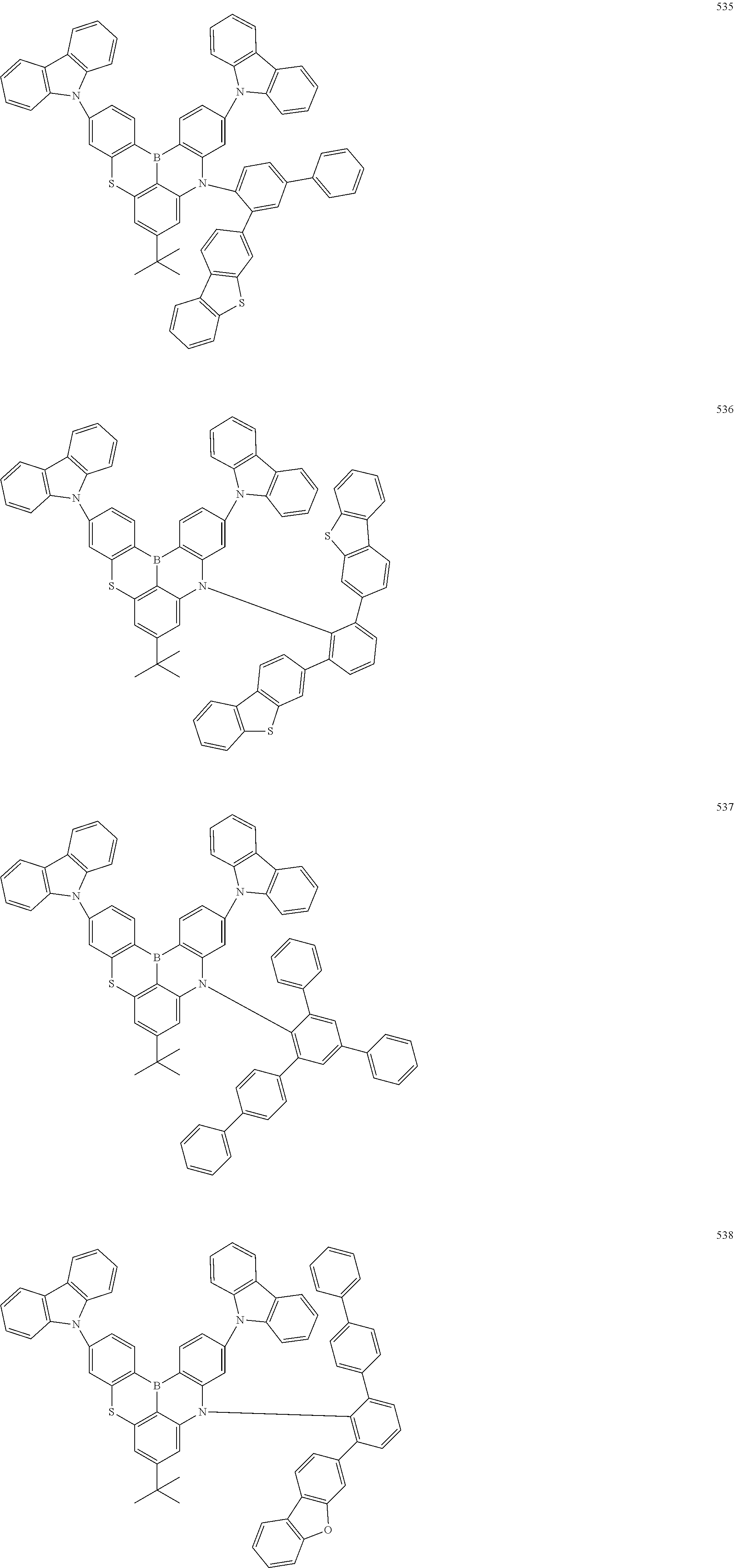 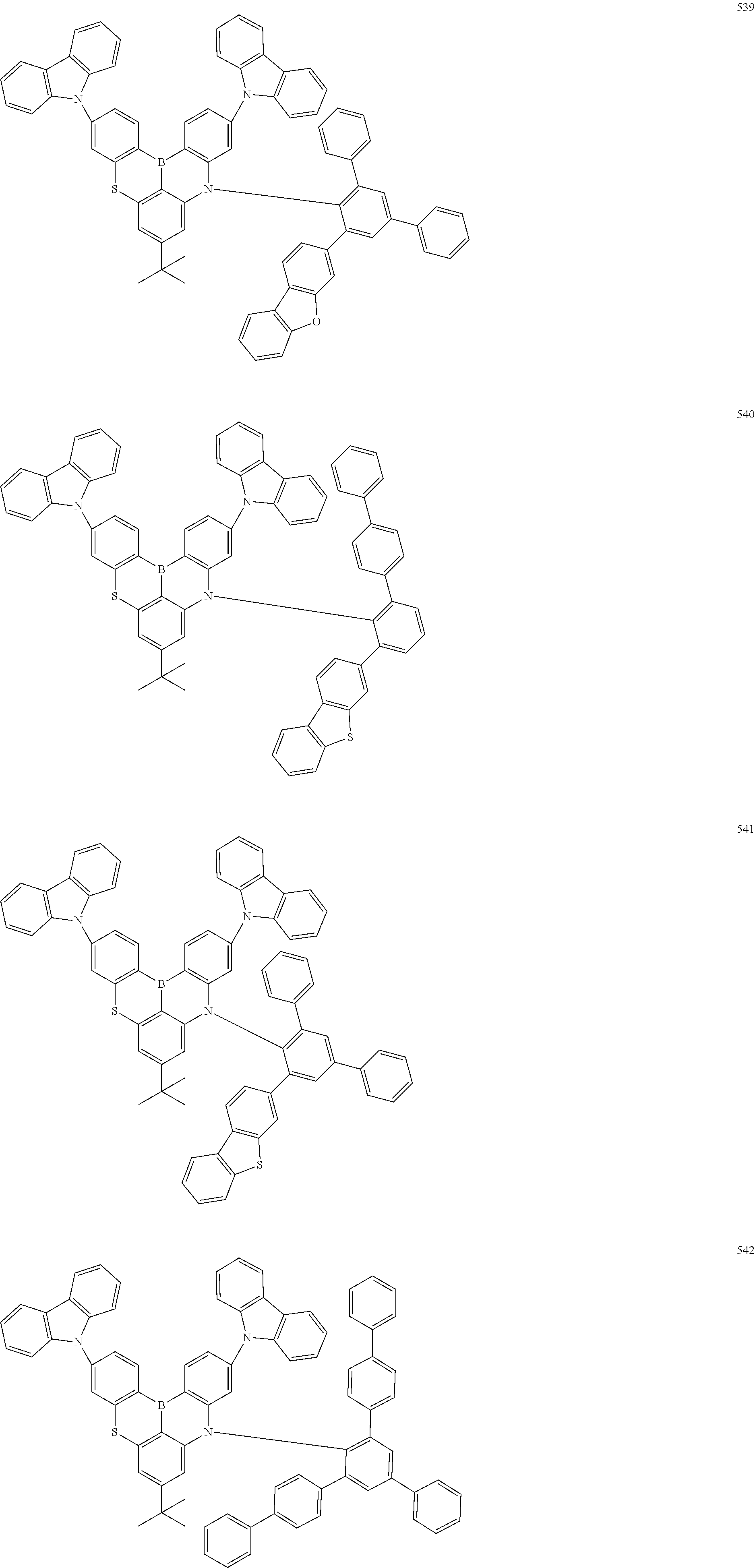 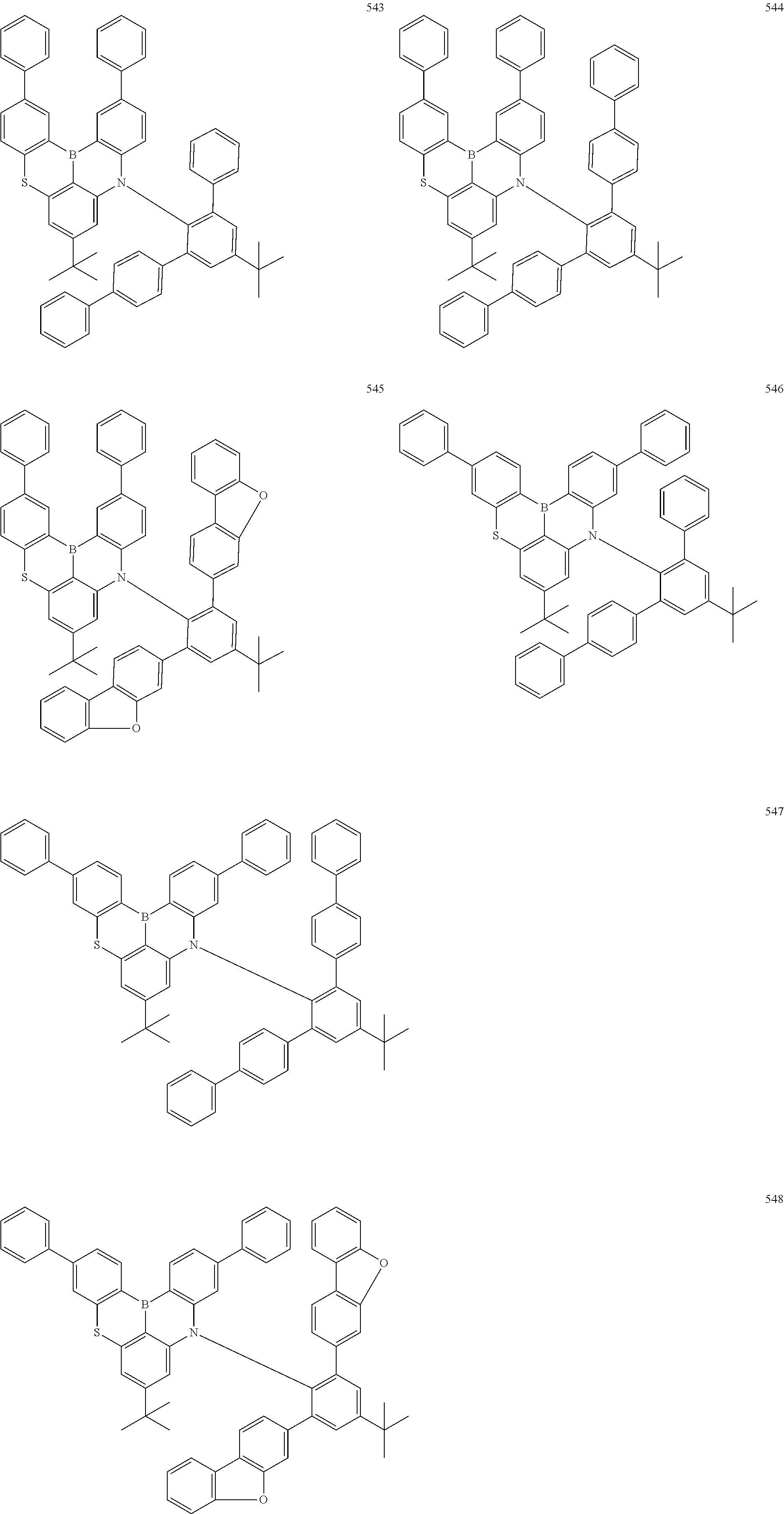 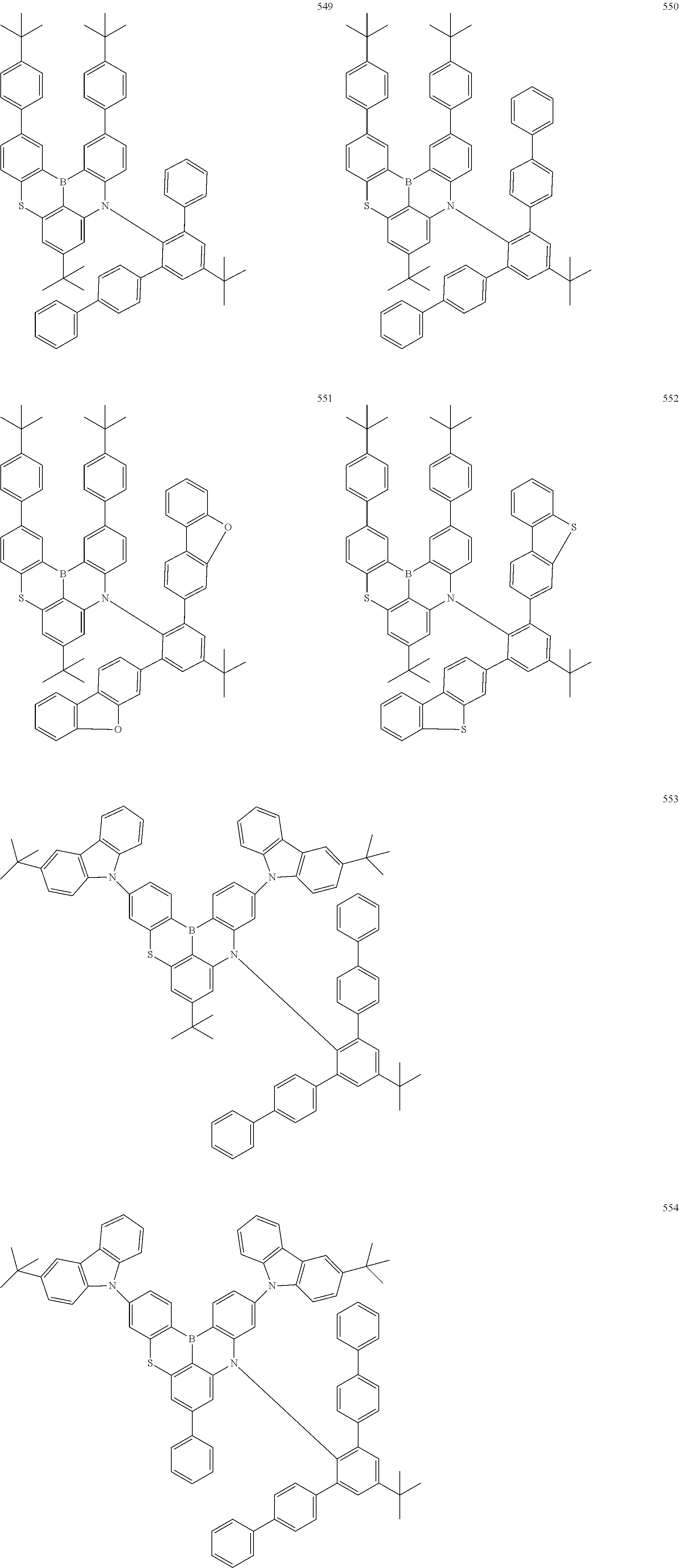 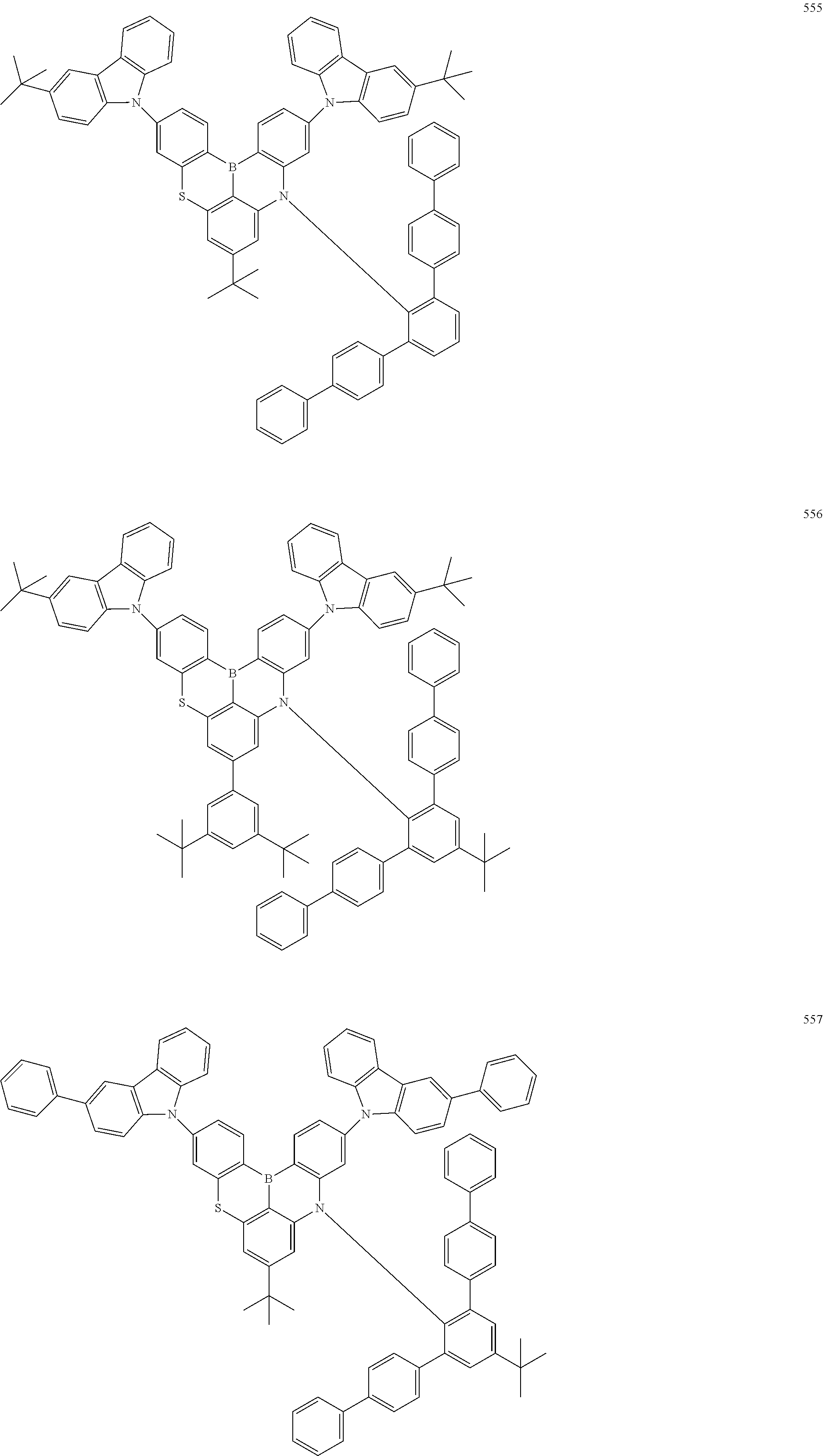 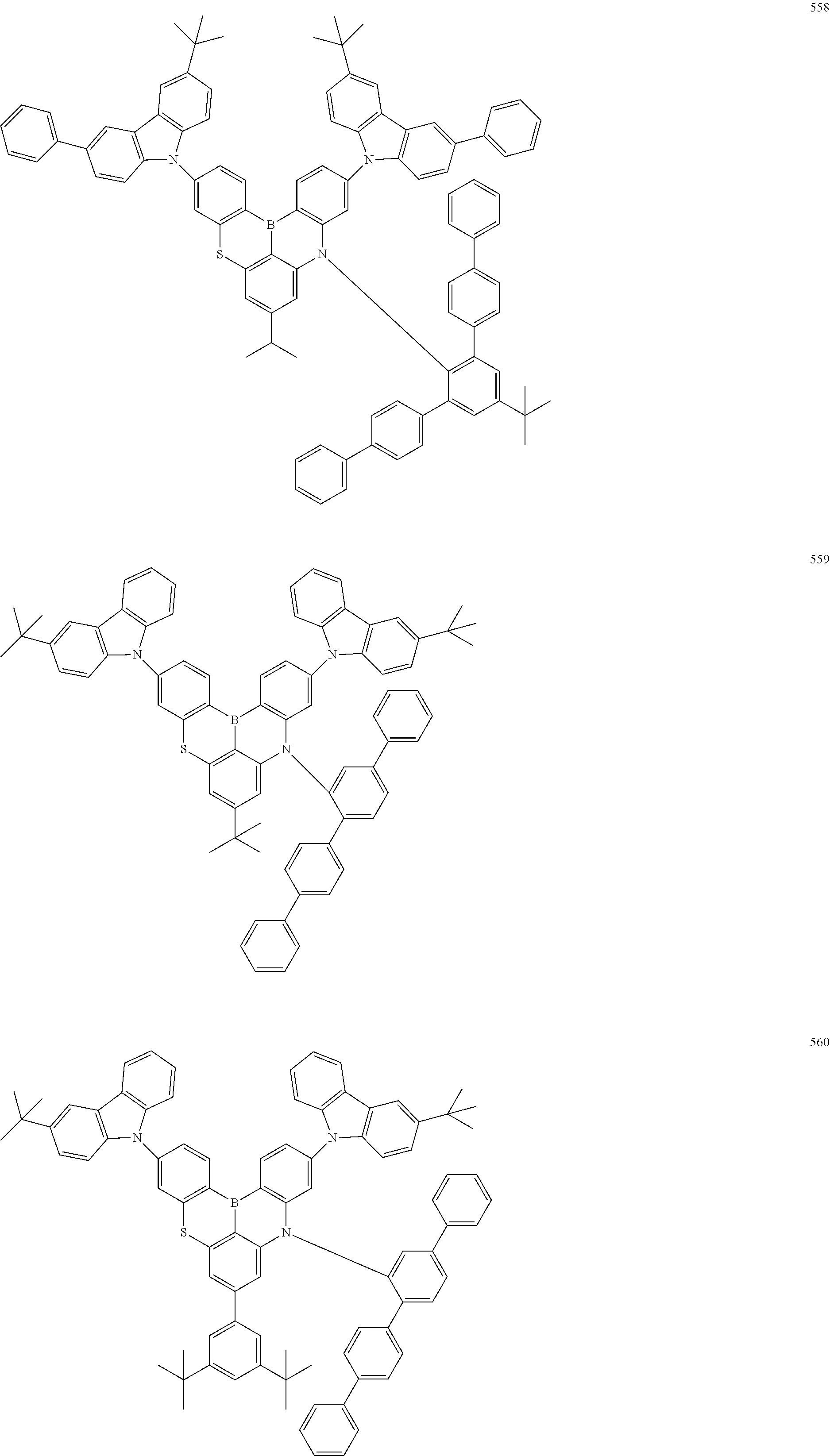 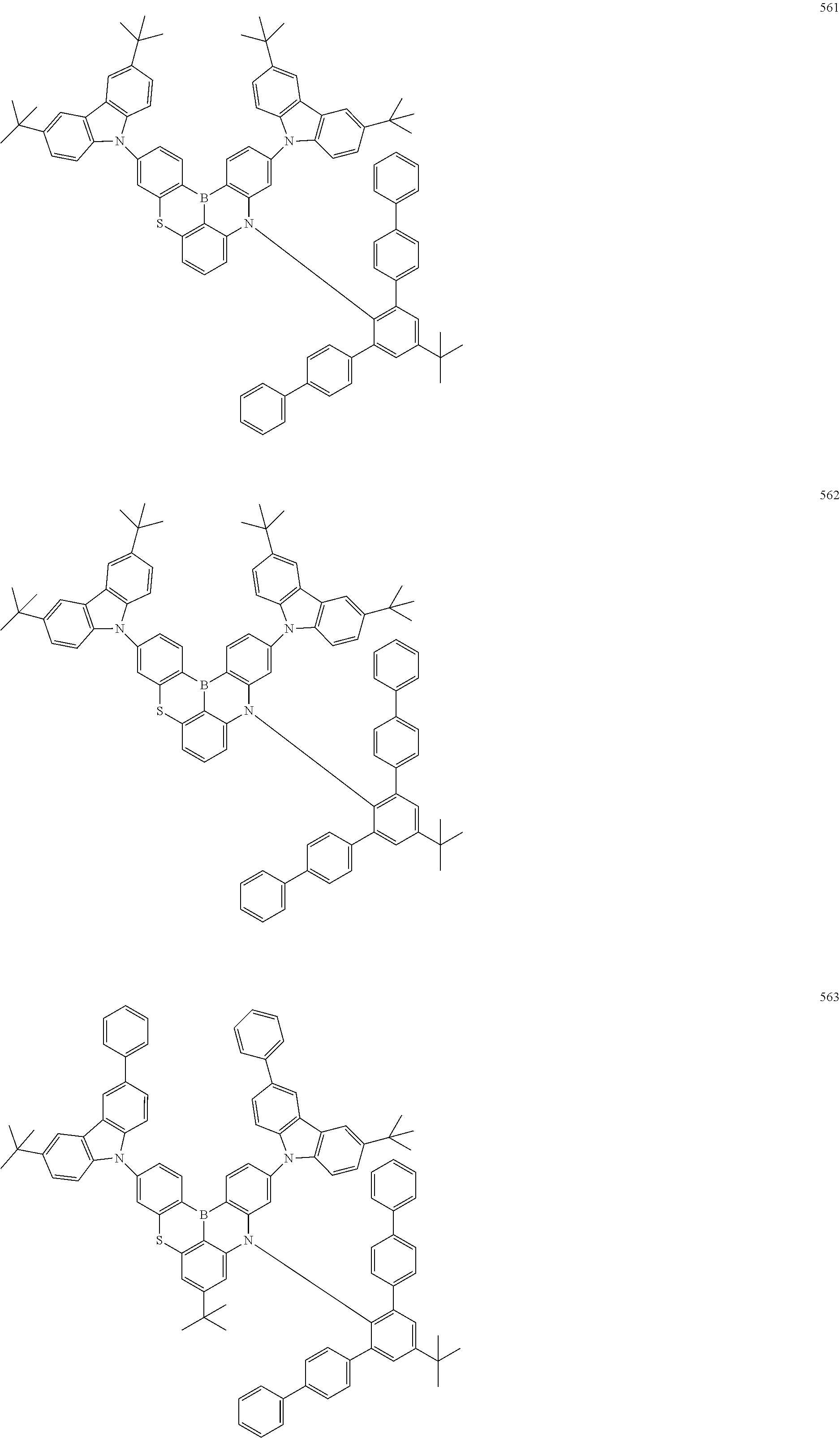 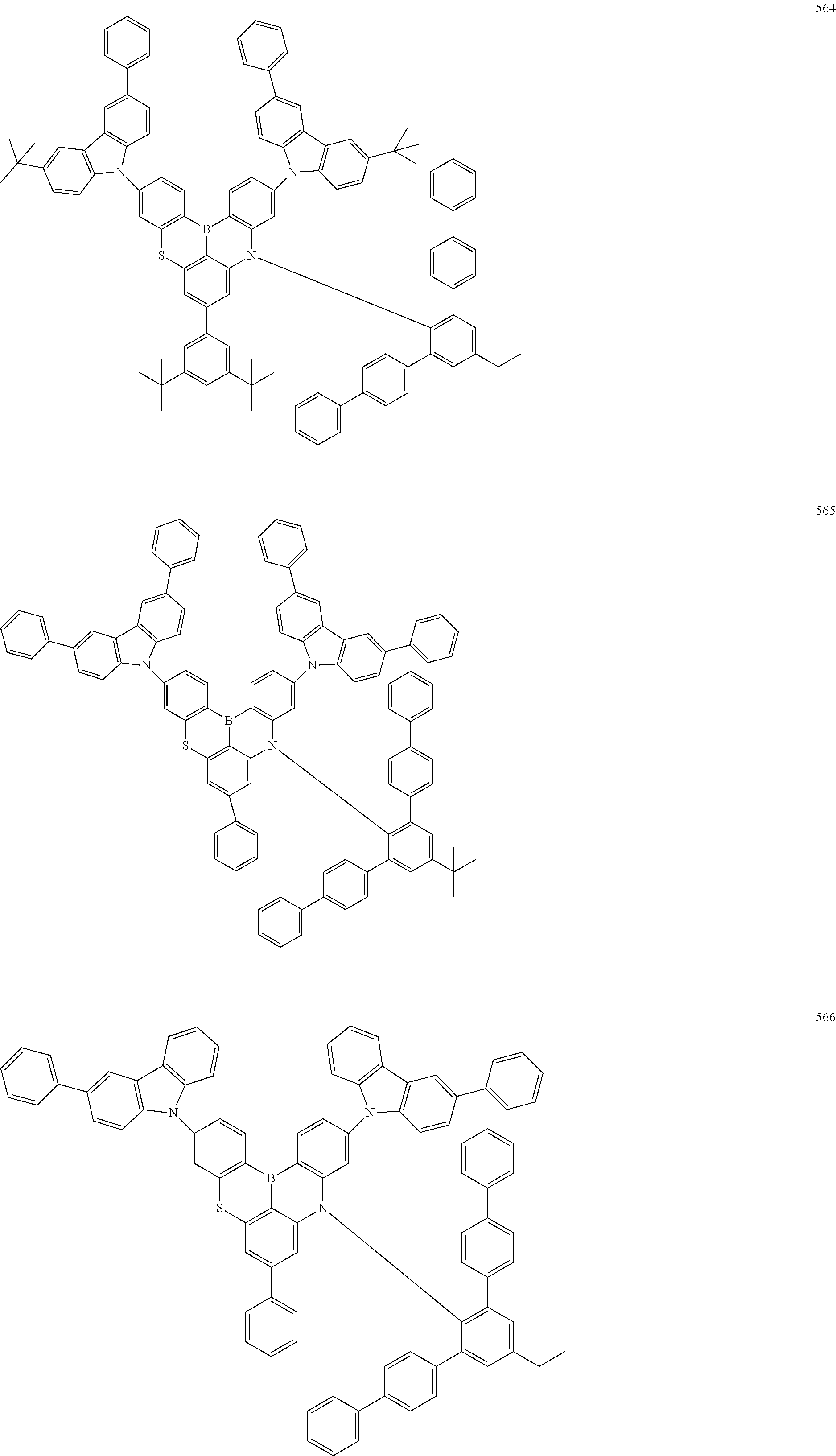 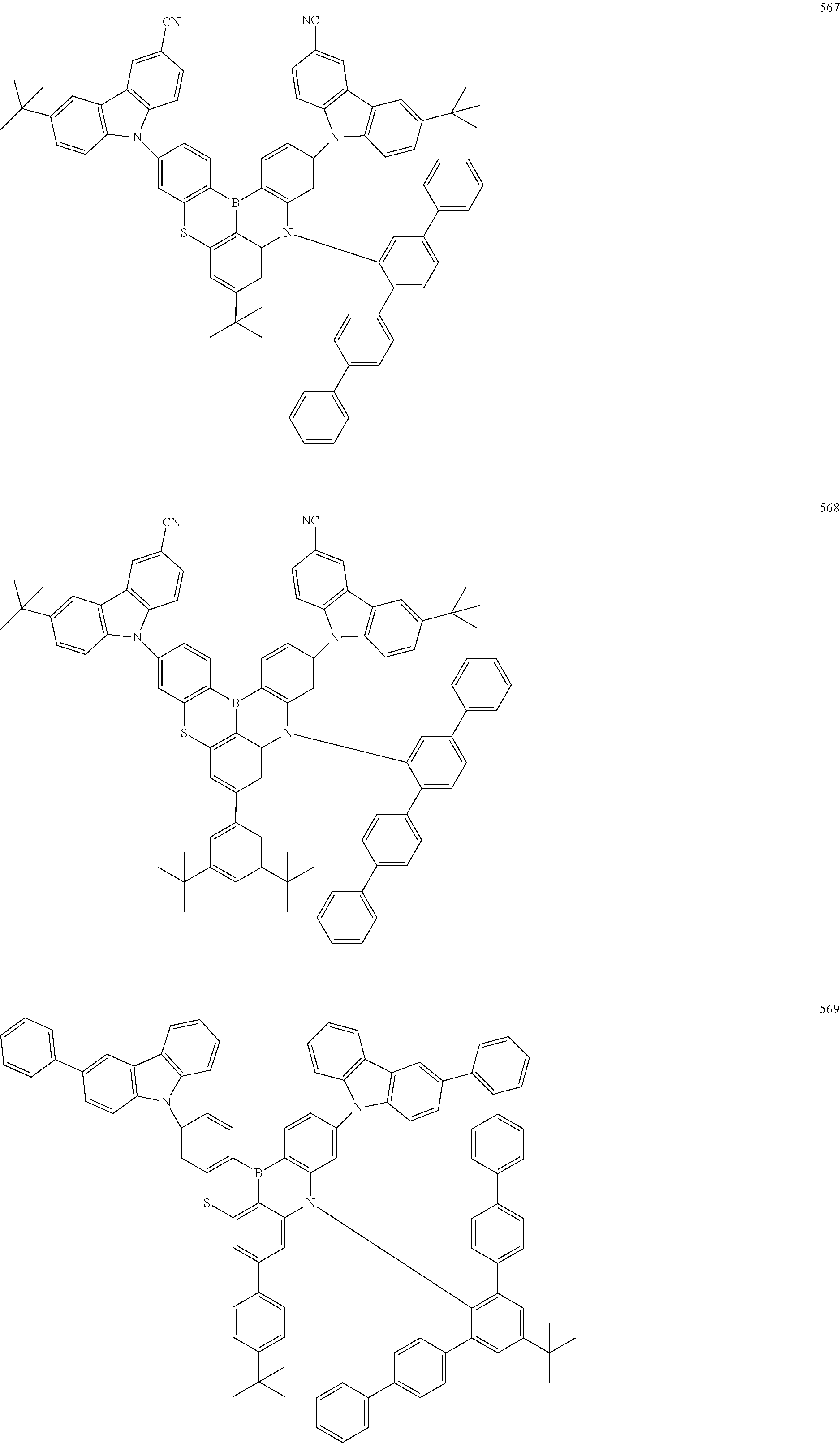 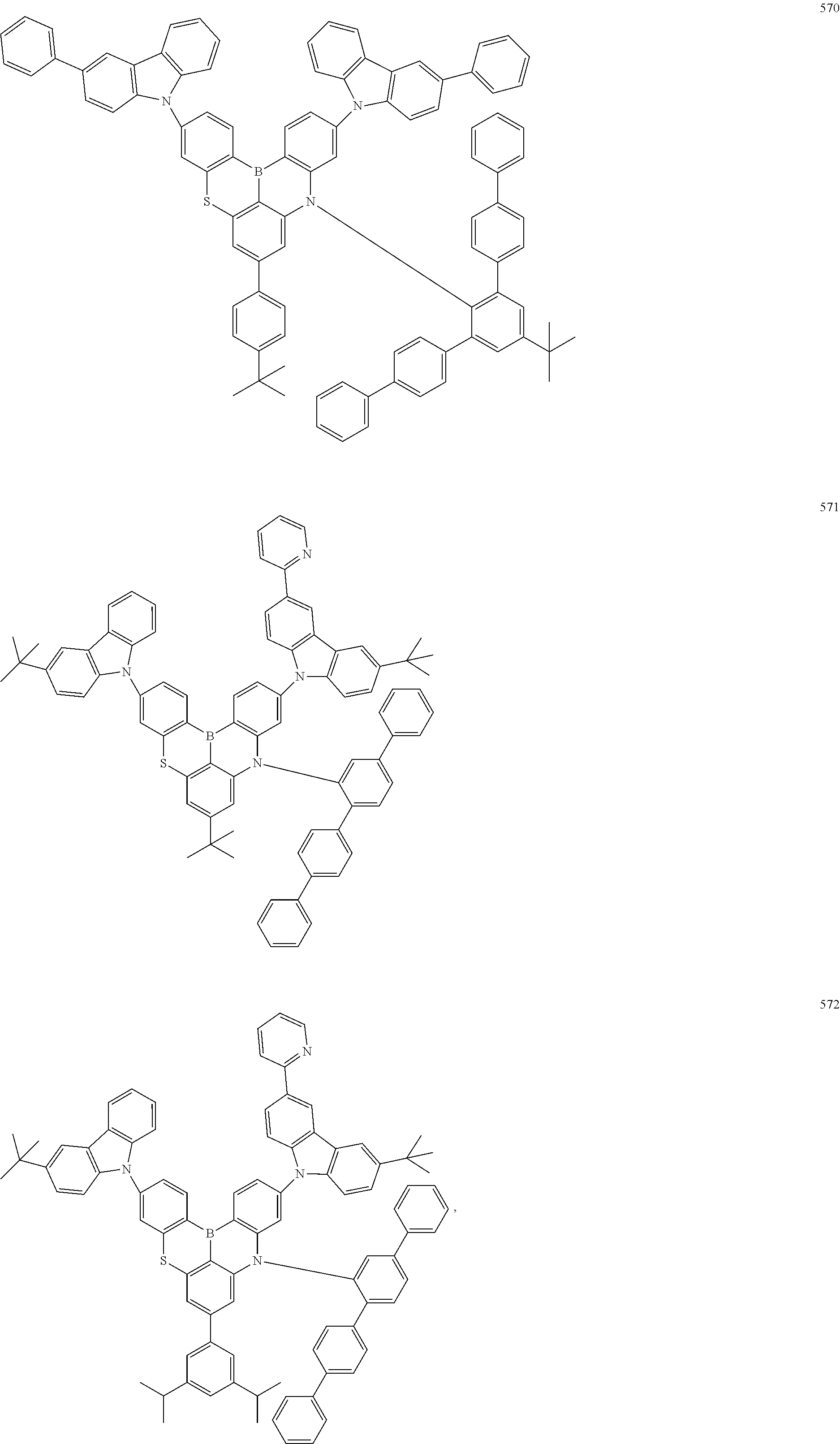
in particular example compounds presented in Compound Group 1, D being deuterium.

11. A fused polycyclic compound represented by Formula 1: 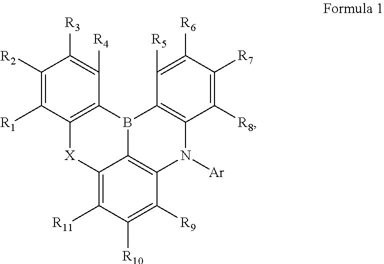
wherein, in Formula 1,
X is O, S, or NR₁₂,
R₁ to R₁₁ are each independently hydrogen, deuterium, a halogen, a cyano group, a hydroxyl group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
R₁₂ is a substituted or unsubstituted aryl group having 6 to 30 ring-forming carbon atoms or a substituted or unsubstituted heteroaryl group having 2 to 30 ring-forming carbon atoms, and when R₁₂ is a substituted or unsubstituted heteroaryl group having 2 to 30 ring-forming carbon atoms, then R₁₂ does not comprise two or more of any one selected from among a dibenzofuran moiety, a dibenzothiophene moiety, and a carbazole moiety, and
Ar is a substituent represented by Formula 2: 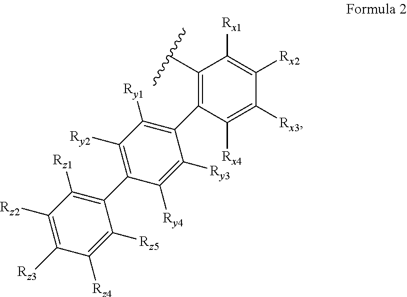
and
wherein, in Formula 2,
Rₓ₁ to Rₓ₄ are each independently hydrogen, deuterium, a halogen, a cyano group, a hydroxyl group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
at least one selected from among Rₓ₁ to Rₓ₃ is a substituted or unsubstituted aryl group having 6 to 30 ring-forming carbon atoms or a substituted or unsubstituted heteroaryl group having 2 to 30 ring-forming carbon atoms,
R_{y1} to R_{y4} and R_{z1} to R_{z5} are each independently hydrogen, deuterium, a halogen, a cyano group, a hydroxyl group, a substituted or unsubstituted oxy group, a substituted or unsubstituted thio group, a substituted or unsubstituted boron group, a substituted or unsubstituted silyl group, a substituted or unsubstituted amine group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or bonded to an adjacent group to form a ring, and 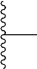
is a position to be connected to Formula 1.

12. The fused polycyclic compound of claim 11,
wherein Rₓ₁ to Rₓ₄ are each independently hydrogen, deuterium, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and
at least one selected from among Rₓ₁ to Rₓ₃ is a substituent represented by any one selected from among Formula 3-1 to Formula 3-4: 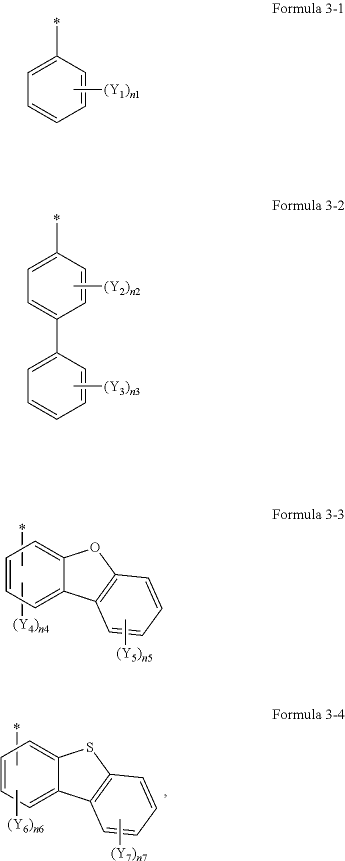
in Formula 3-1 to Formula 3-4,
Y₁ to Y₇ being each independently hydrogen, deuterium, a halogen, a cyano group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
n1 and n3 being each independently an integer of 0 or greater and 5 or less,
n2, n5, and n7 being each independently an integer of 0 or greater and 4 or less,
n4 and n6 being each independently an integer of 0 or greater and 3 or less, and [symbol]
being a position to be connected to Formula 2.

13. The fused polycyclic compound of claim 11, wherein the substituent represented by Formula 2 is represented by any one selected from among Formula 2-1 to Formula 2-3: 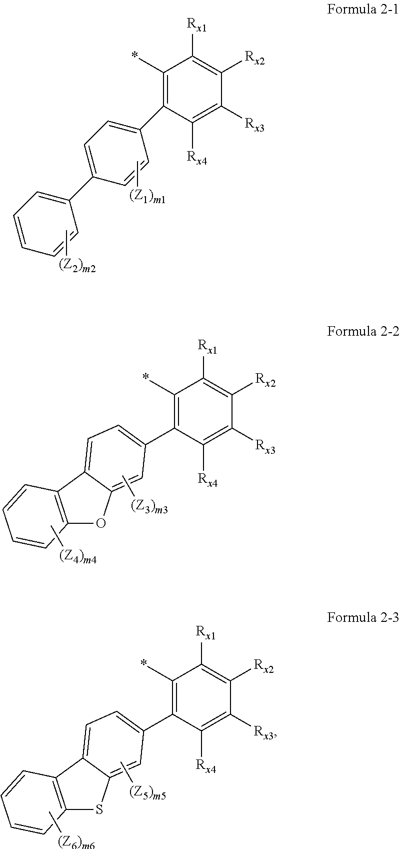
in Formula 2-1 to Formula 2-3,
Z₁ to Z₆ being each independently hydrogen, deuterium, a halogen, a cyano group, or a substituted or unsubstituted alkyl group having 1 to 10 carbon atoms,
m1, m4, and m6 being each independently an integer of 0 or greater and 4 or less,
m2 being an integer of 0 or greater and 5 or less,
m3 and m5 being each independently an integer of 0 or greater and 3 or less, and
Rₓ₁ to Rₓ₄ being each the same as defined in Formula 2.

14. The fused polycyclic compound of claim 11, wherein the substituent represented by Formula 2 is represented by any one selected from among Formula 2-4 to Formula 2-17: 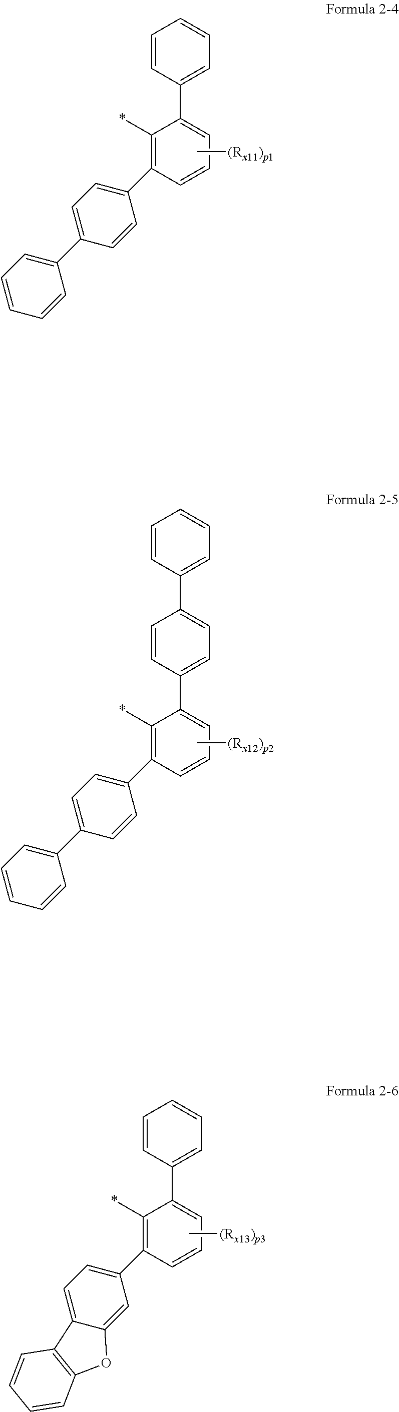 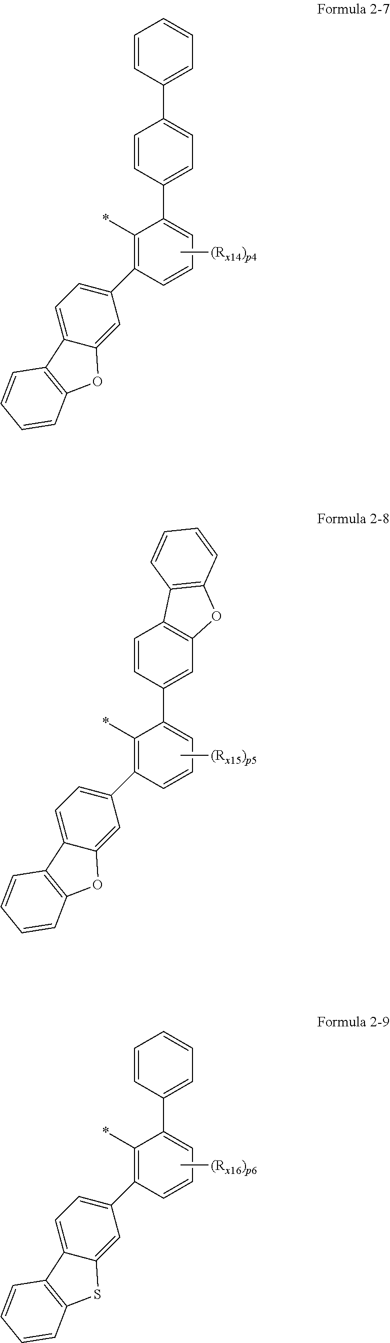 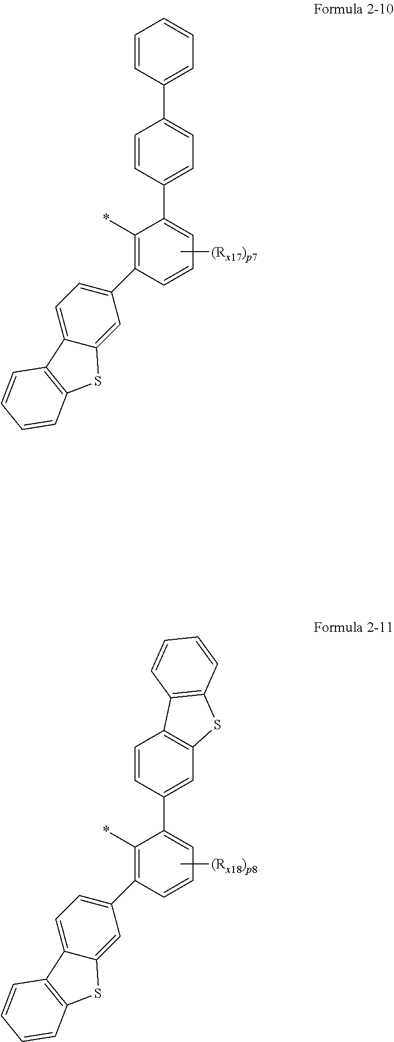 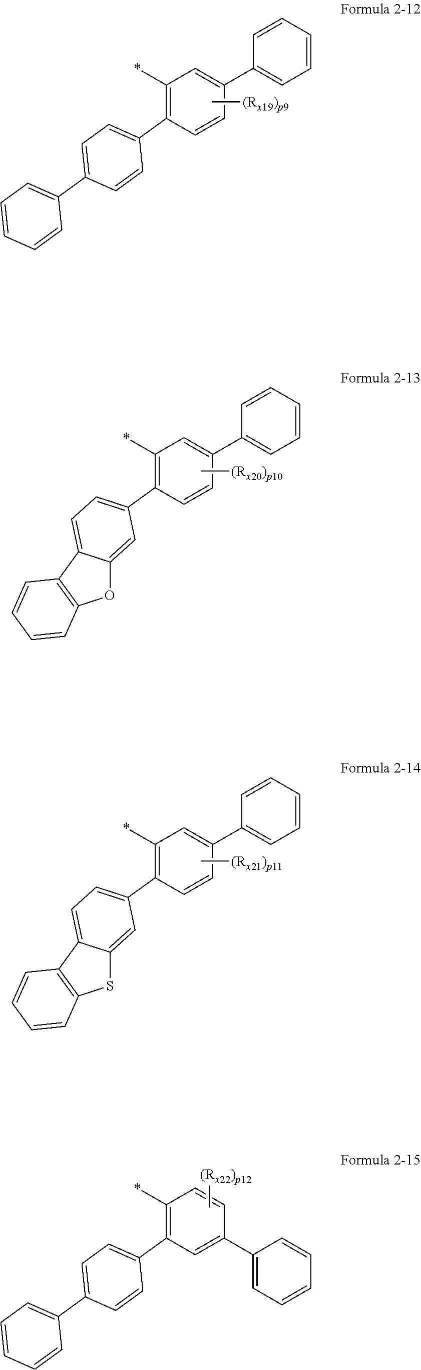 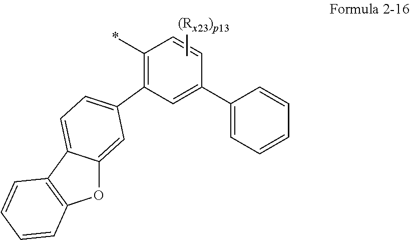 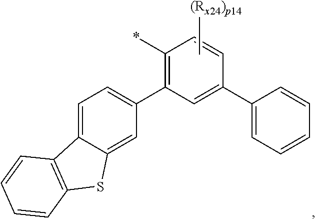
in Formula 2-4 to Formula 2-17,
Rₓ₁₁ to Rₓ₂₄ being each independently hydrogen, deuterium, an unsubstituted t-butyl group, or an unsubstituted phenyl group,
p1 to p14 being each independently an integer of 0 or greater and 3 or less, and [symbol]
being a position to be connected to Formula 1.

15. The fused polycyclic compound of claim 11, wherein the fused polycyclic compound represented by Formula 1 is represented by any one selected from among Formula 1-1 to Formula 1-6: 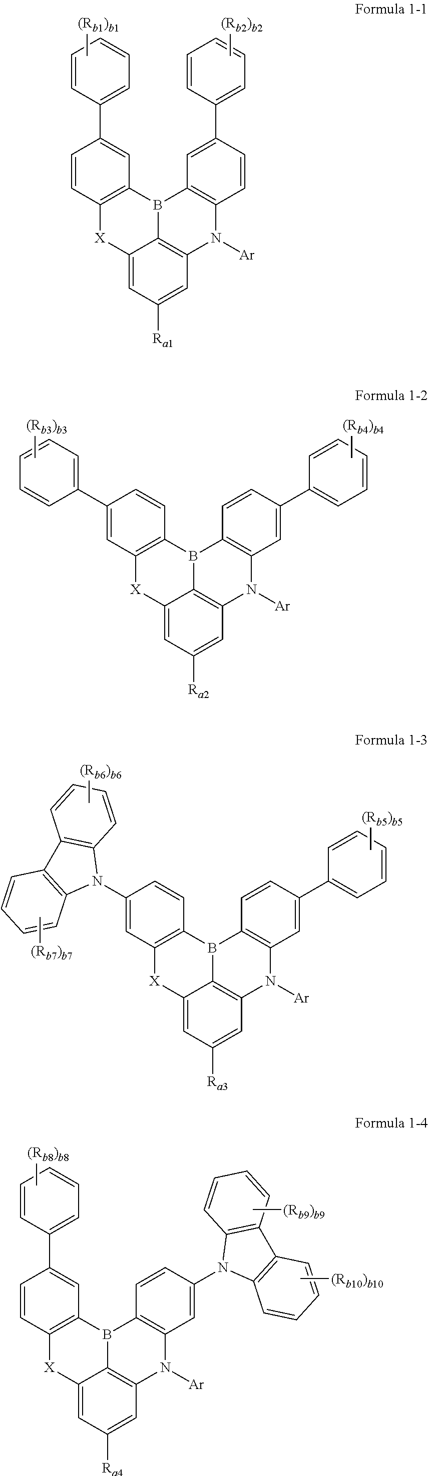 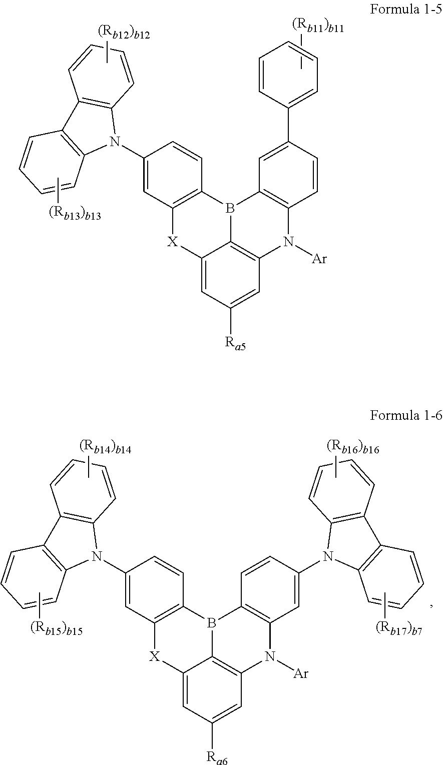
in Formula 1-1 to Formula 1-6,
Rₐ₁ to Rₐ₆ being each independently hydrogen, deuterium, a substituted or unsubstituted t-butyl group, or a substituted or unsubstituted aryl group having 6 to 30 ring-forming carbon atoms,
R_{b1} to R_{b17} being each independently hydrogen, deuterium, a cyano group, a substituted or unsubstituted t-butyl group, a substituted or unsubstituted aryl group having 6 to 30 ring-forming carbon atoms, or an unsubstituted heteroaryl group having 2 to 30 ring-forming carbon atoms,
b1 to b5, b8, and b11 being each independently an integer of 0 or greater and 5 or less,
b6, b7, b9, b10, and b12 to b17 being each independently an integer of 0 or greater and 4 or less,
X and Ar being each the same as defined in Formula 1, and
Formula 1-1 to Formula 1-6 comprising a structure in which any hydrogen being optionally substituted with deuterium.

16. The fused polycyclic compound of claim 11, wherein the fused polycyclic compound represented by Formula 1 is represented by Formula 1-7: 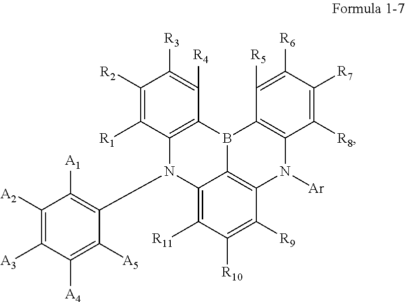
and
wherein, A₁ to A₅ are each independently hydrogen, deuterium, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
a case where two or more selected from among A₁ to A₅ are each independently a substituted or unsubstituted dibenzofuran group, a substituted or unsubstituted dibenzothiophene group, or a substituted or unsubstituted carbazole group is excluded, and
Ar and R₁ to R₁₁ are each the same as defined in Formula 1.

17. The fused polycyclic compound of claim 11, wherein the fused polycyclic compound represented by Formula 1 is represented by any one selected from among Formula 1-8 to Formula 1-16: 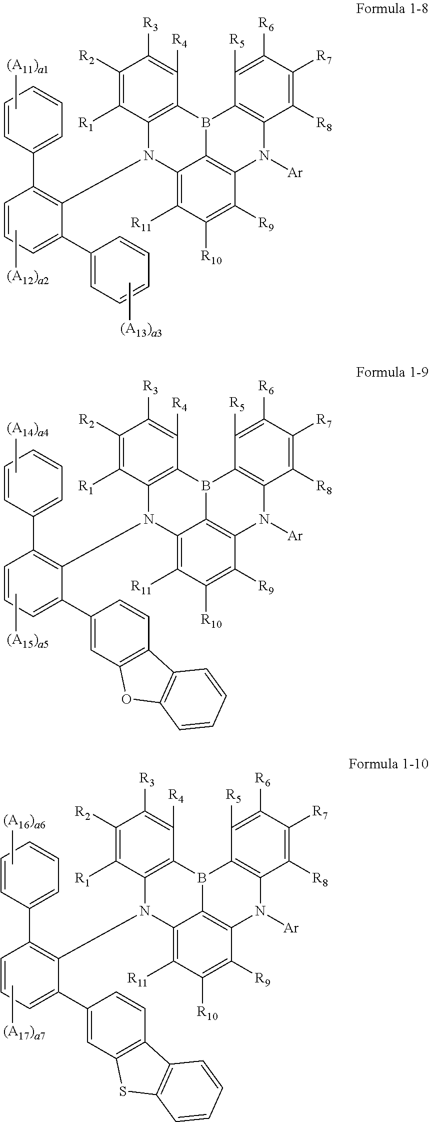 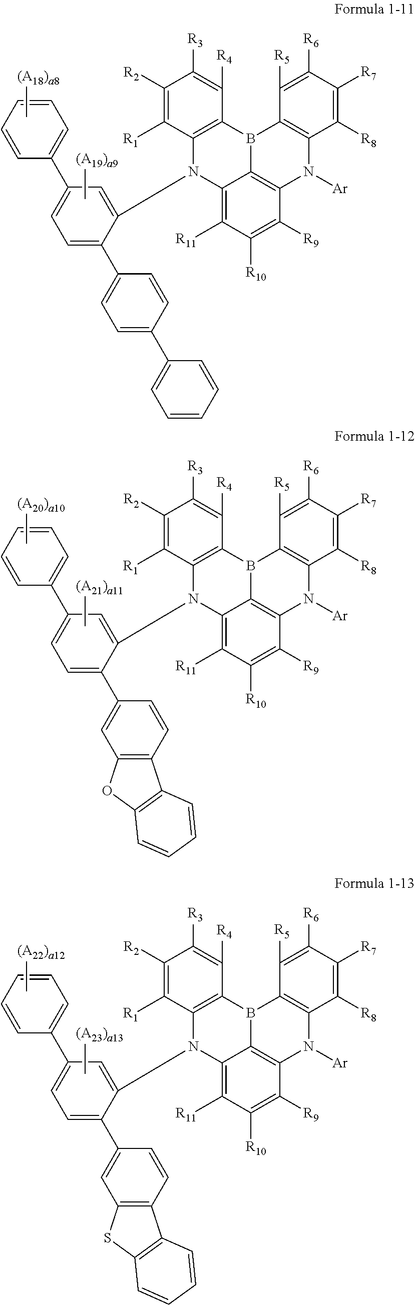 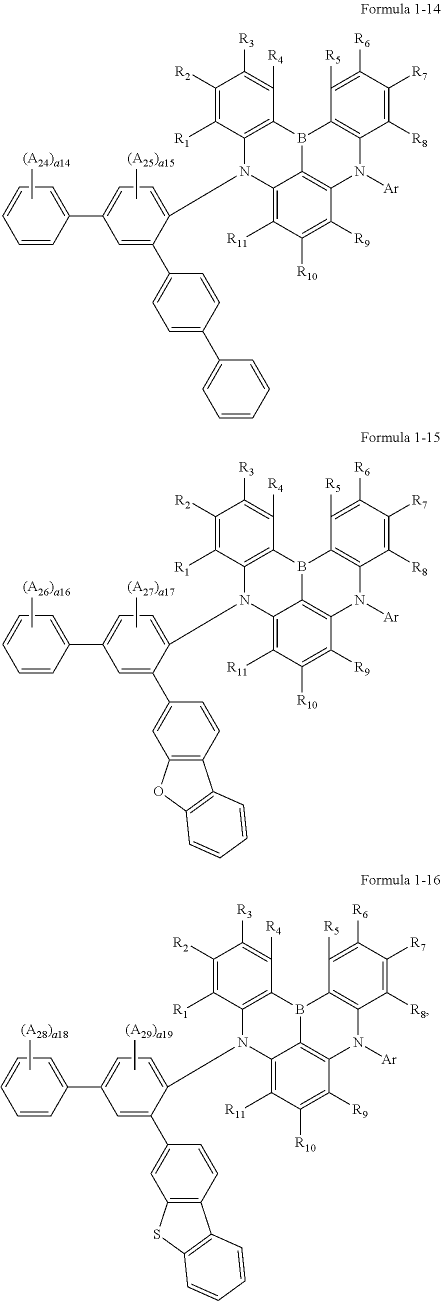
in Formula 1-8 to Formula 1-16,
A₁₁, A₁₃, A₁₄, A₁₆, A₁₈, A₂₀, A₂₂, A₂₄, A₂₆, and A₂₈ being each independently hydrogen, deuterium, or a substituted or unsubstituted aryl group having 6 to 30 ring-forming carbon atoms,
A₁₂, A₁₅, A₁₇, A₁₉, A₂₁, A₂₃, A₂₅, A₂₇, and A₂₉ being each independently hydrogen, deuterium, or a substituted or unsubstituted alkyl group having 1 to 20 carbon atoms, or a substituted or unsubstituted aryl group having 6 to 30 ring-forming carbon atoms,
a1, a3, a4, a6, a8, a10, a12, a14, a16, and a18 being each independently an integer of 0 or greater and 5 or less,
a2, a5, a7, a9, a11, a13, a15, a17, and a19 being each independently an integer of 0 or greater and 3 or less, and
Ar and R₁ to R₁₁ being each the same as defined in Formula 1.

18. The fused polycyclic compound of claim 11, wherein the fused polycyclic compound represented by Formula 1 is any one among selected from compounds in Compound Group 1: 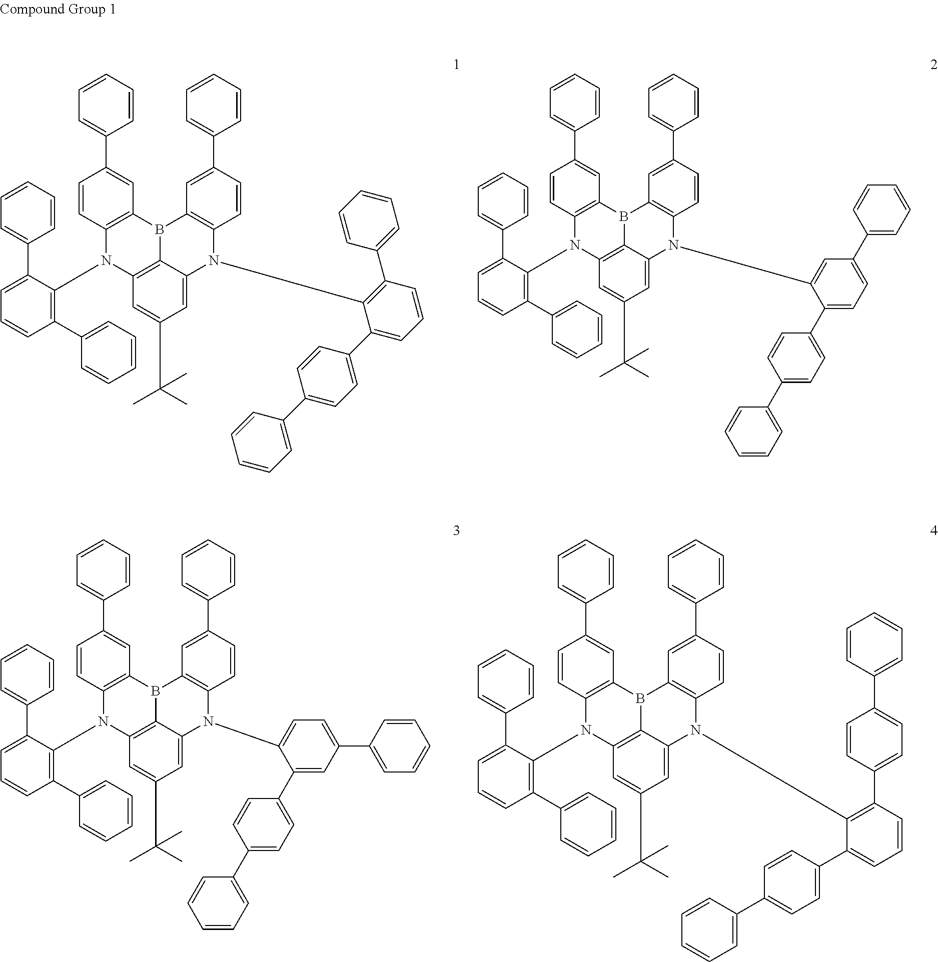 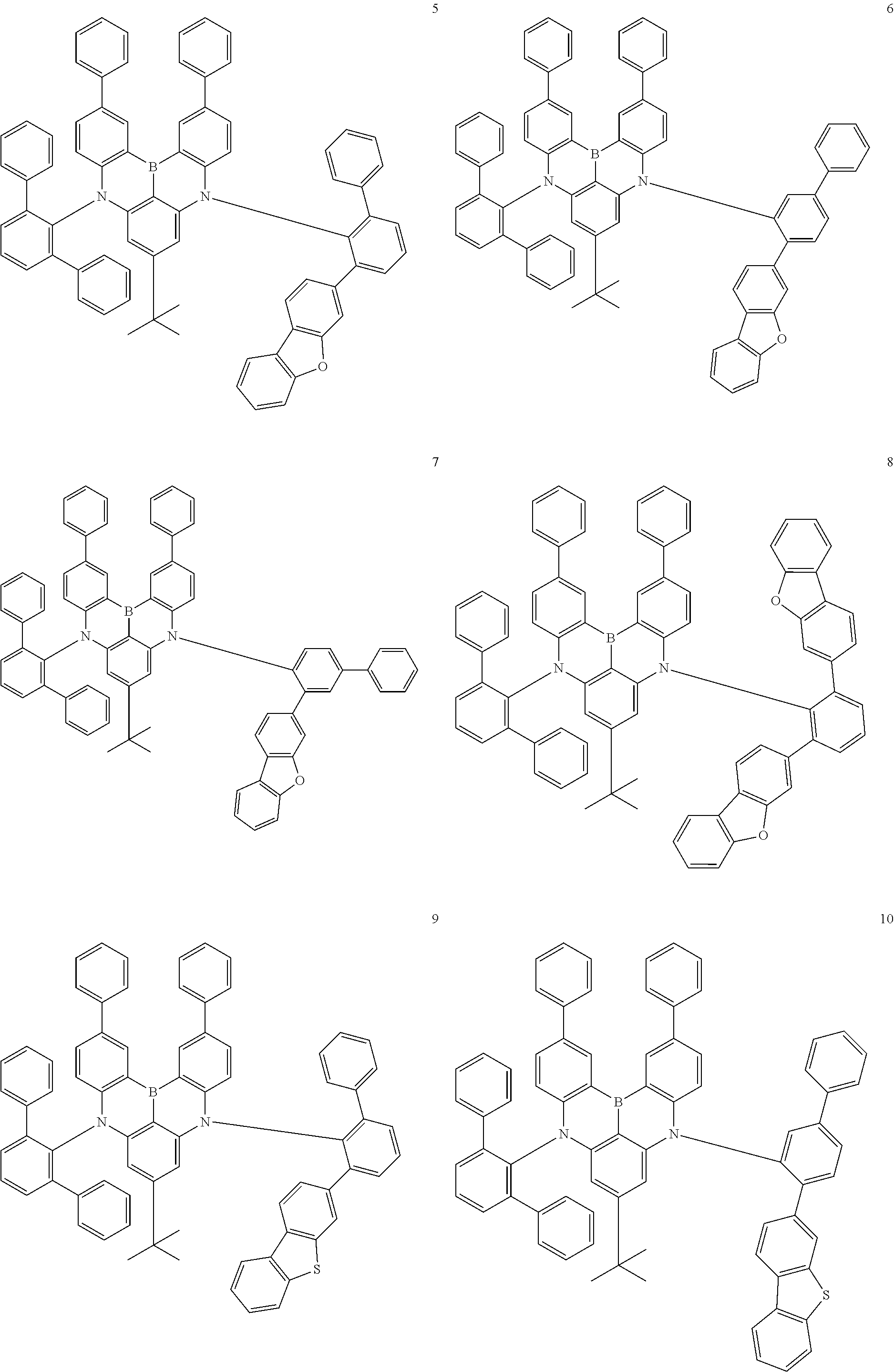 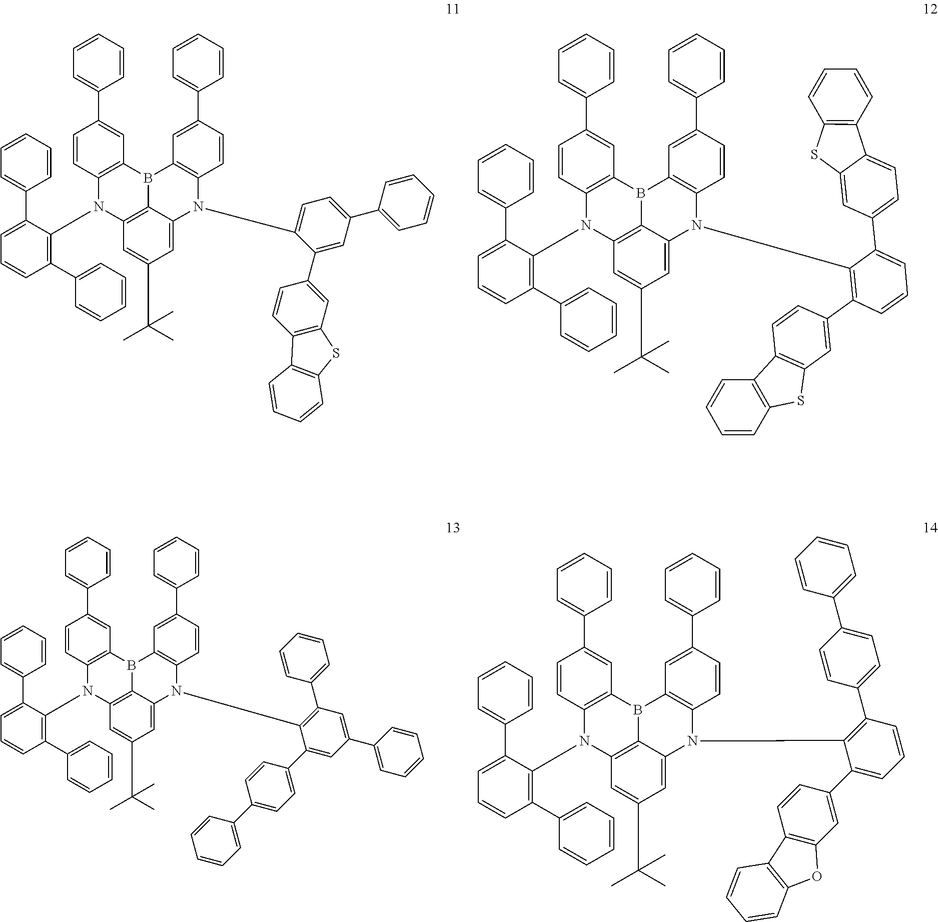 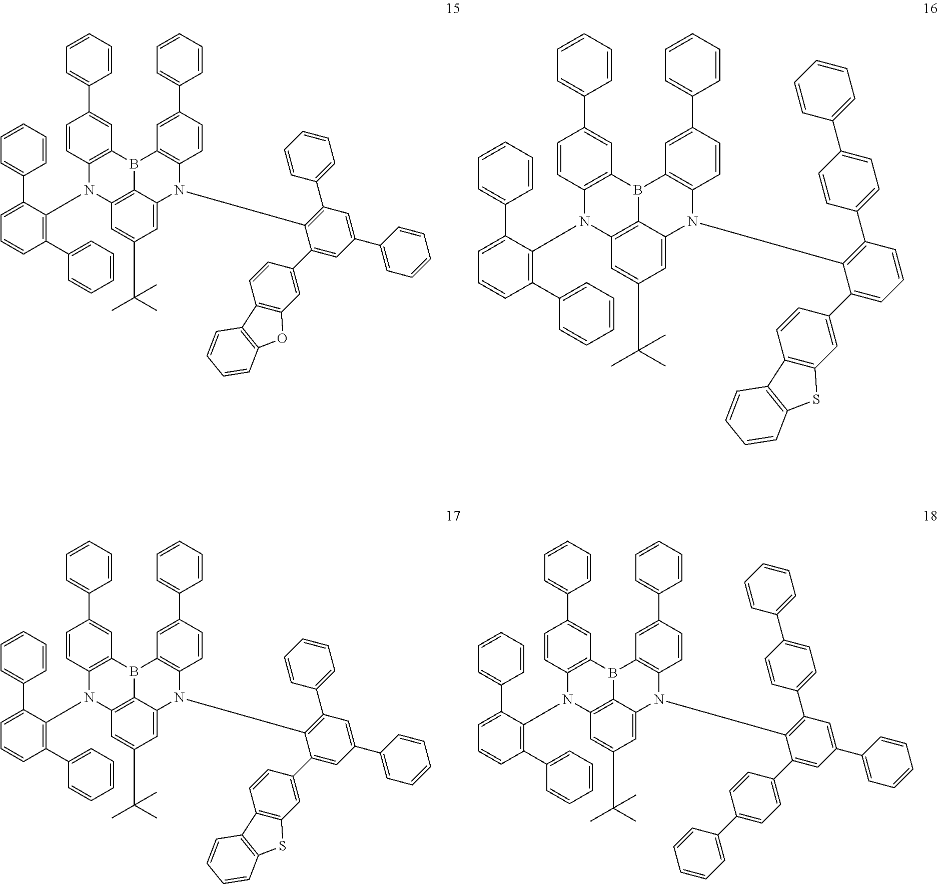 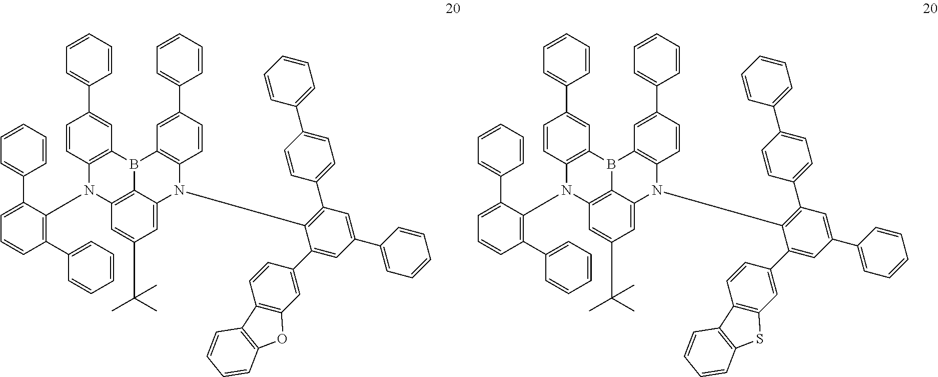 [SMILES: CC(C)(C)c1cc2c3c(c1)N(c1c(-c4ccc(-c5ccccc5)cc4)cc(-c4ccccc4)cc1-c1ccc4c(c1)oc1ccccc14)c1ccc(-c4ccccc4)cc1B3c1cc(-c3ccccc3)ccc1N2c1c(-c2ccccc2)cccc1-c1ccccc1 ; CC(C)(C)c1cc2c3c(c1)N(c1c(-c4ccc(-c5ccccc5)cc4)cc(-c4ccccc4)cc1-c1ccc4c(c1)sc1ccccc14)c1ccc(-c4ccccc4)cc1B3c1cc(-c3ccccc3)ccc1N2c1c(-c2ccccc2)cccc1-c1ccccc1] 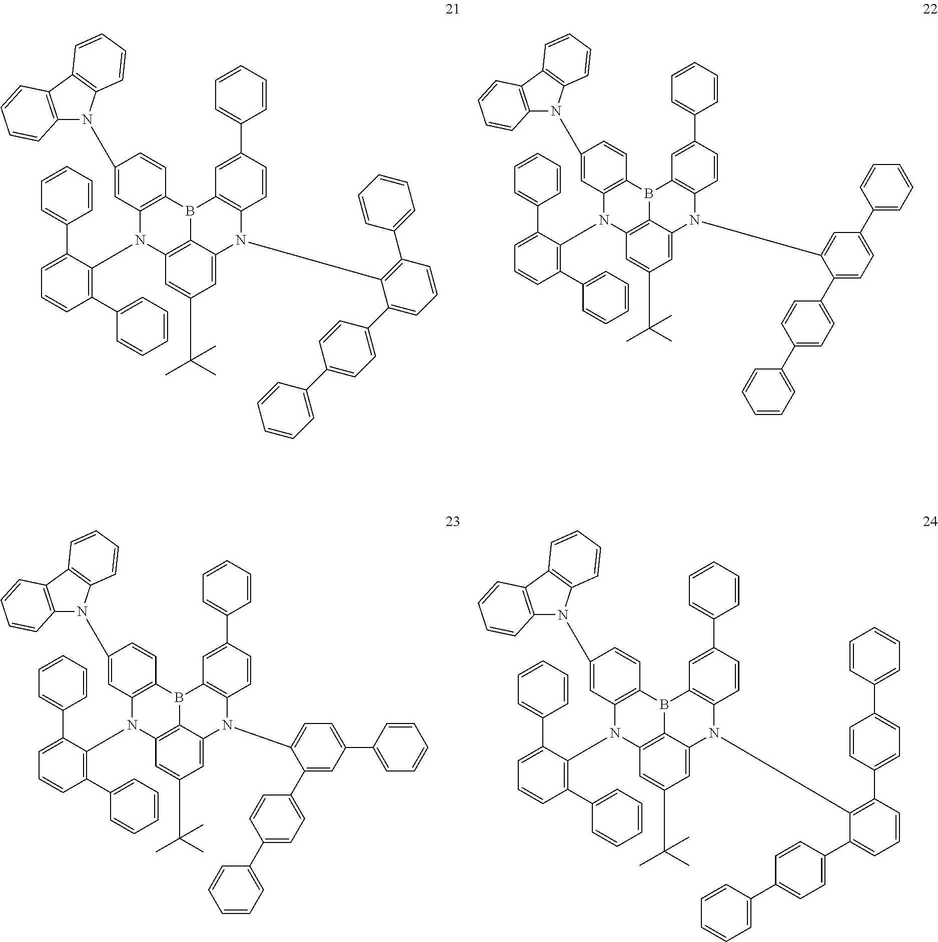 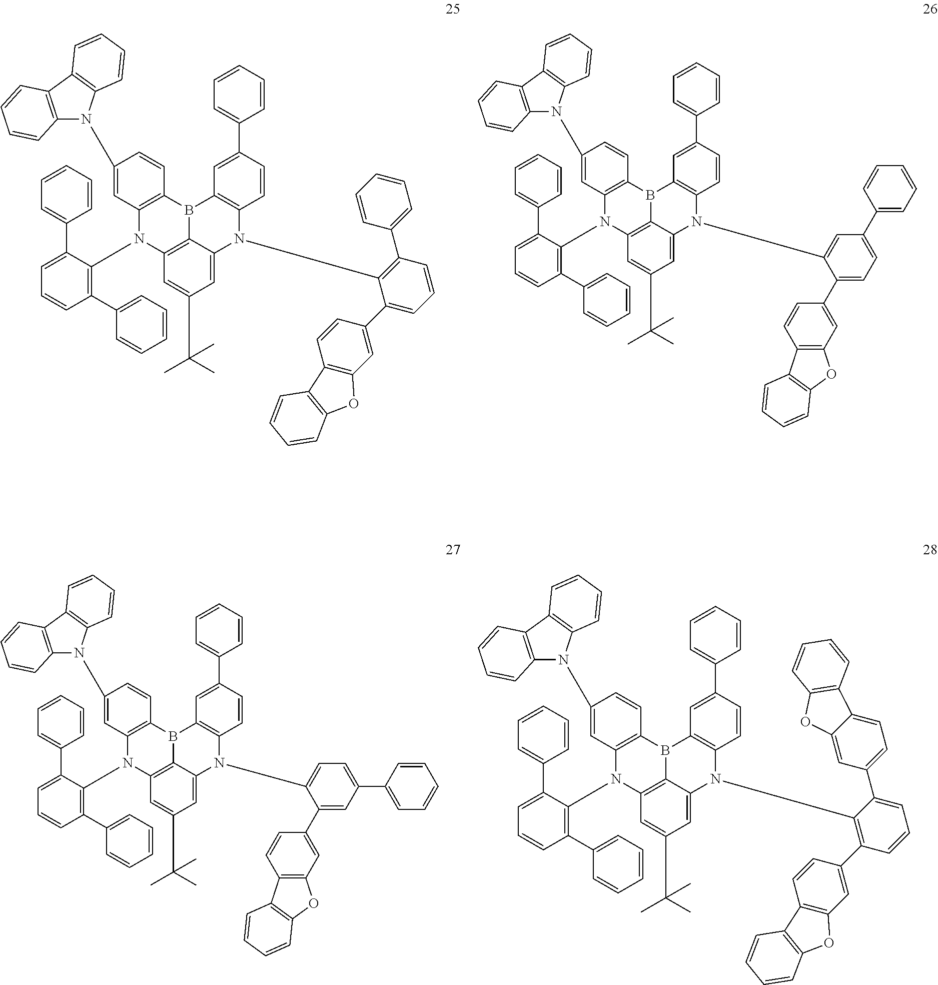 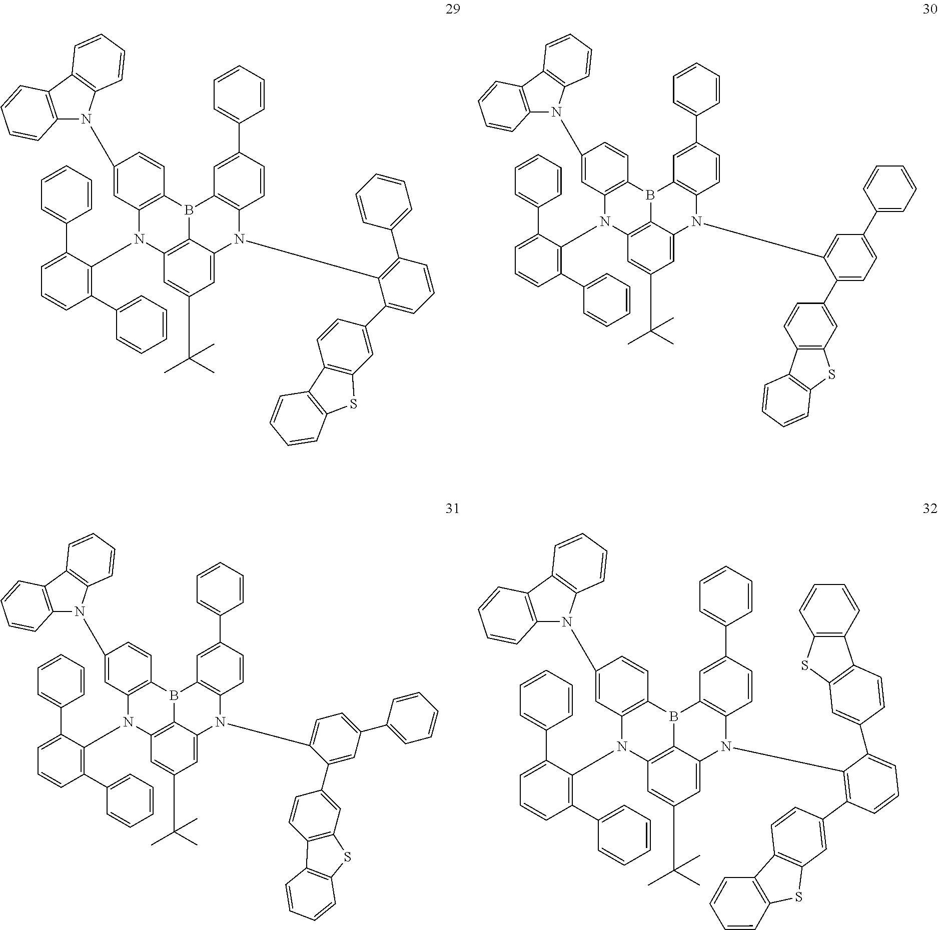 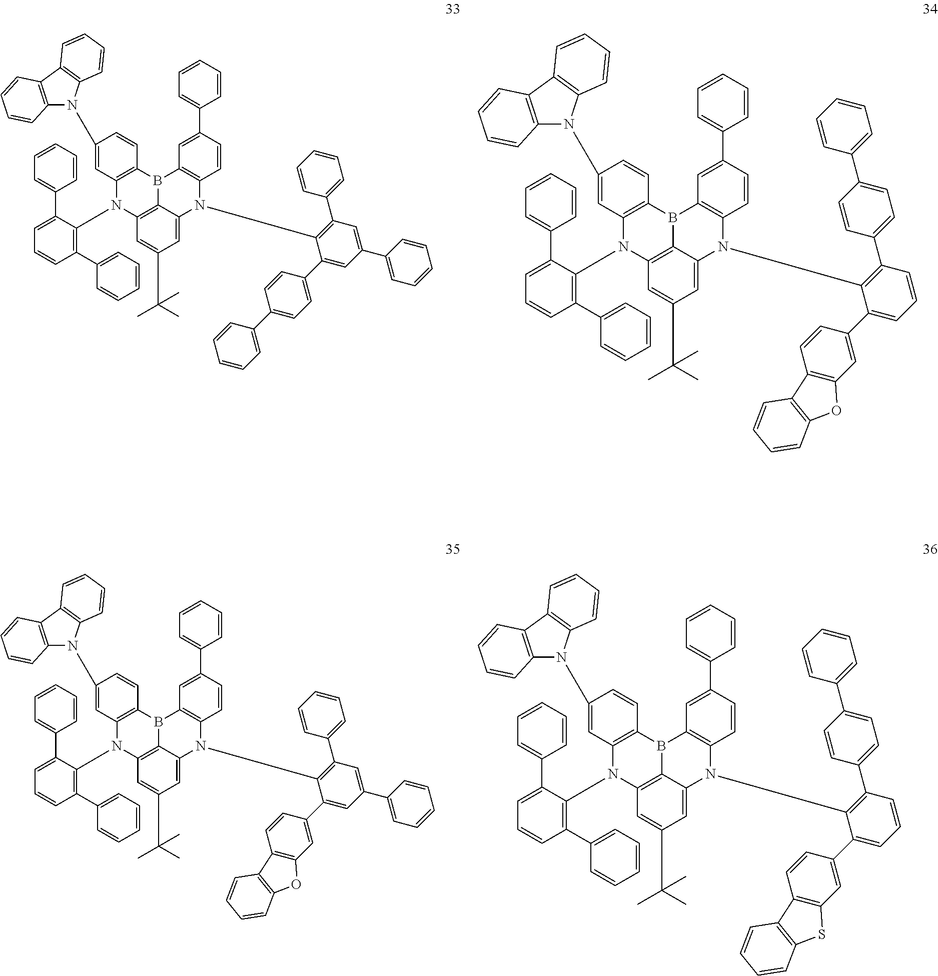 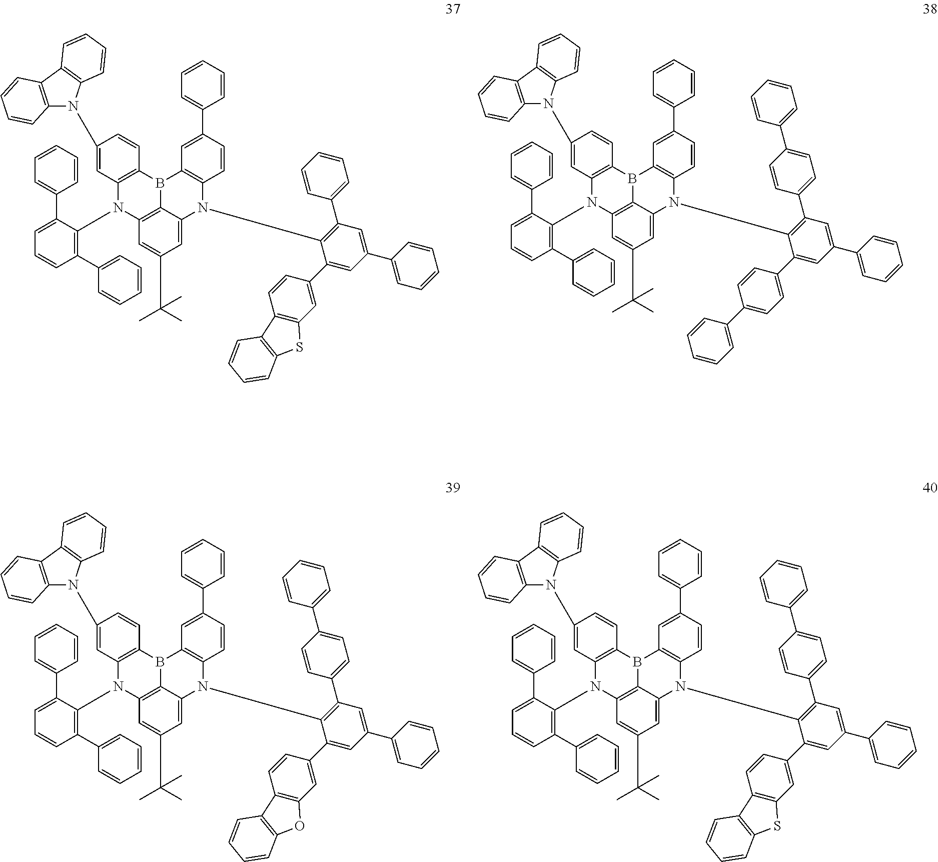 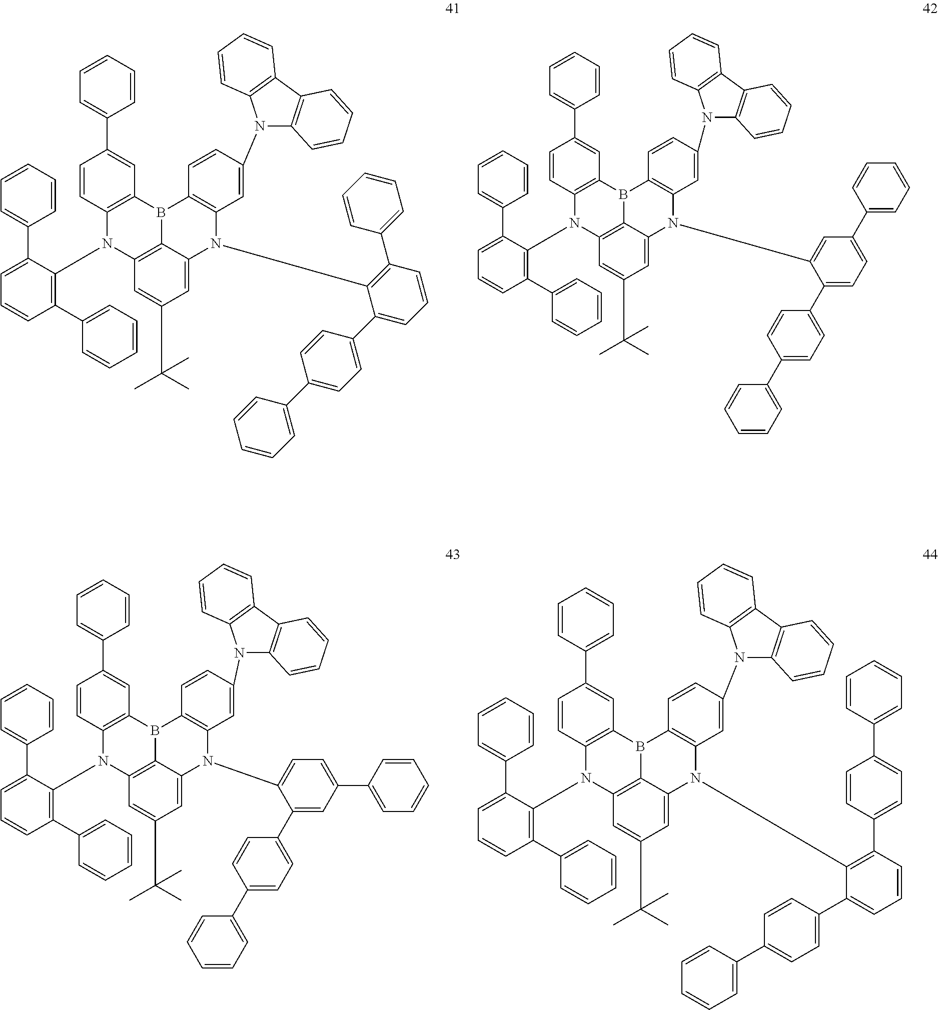 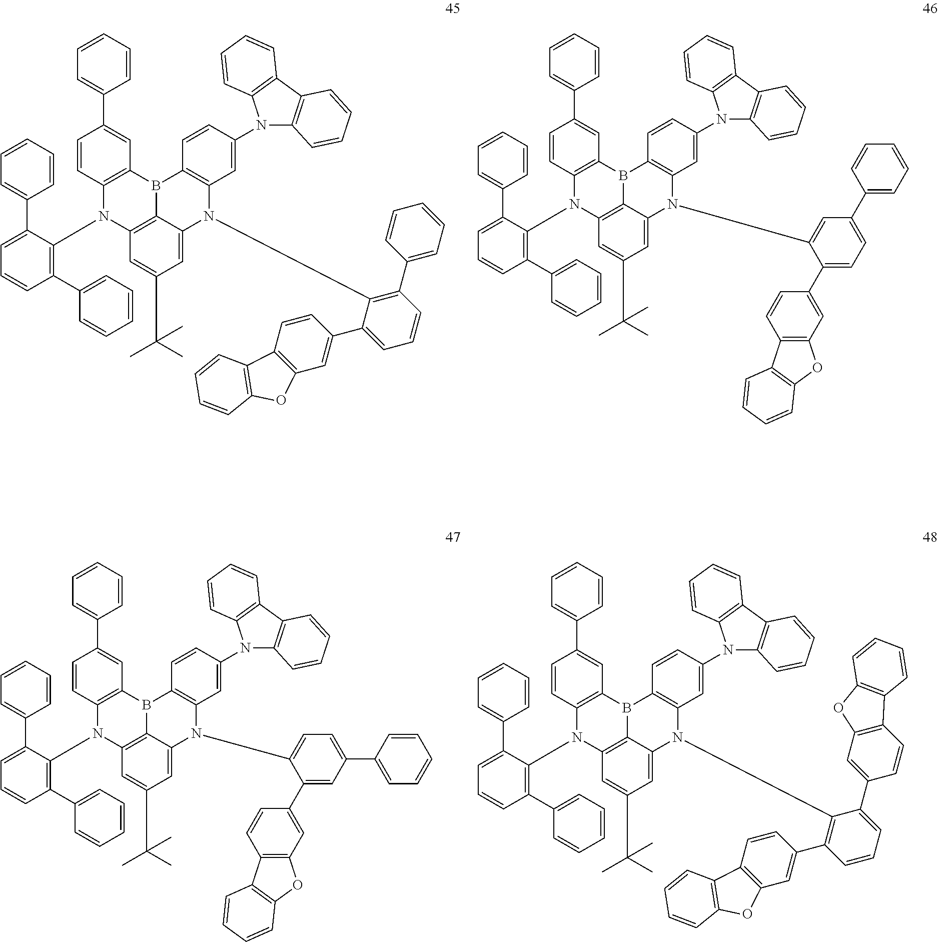 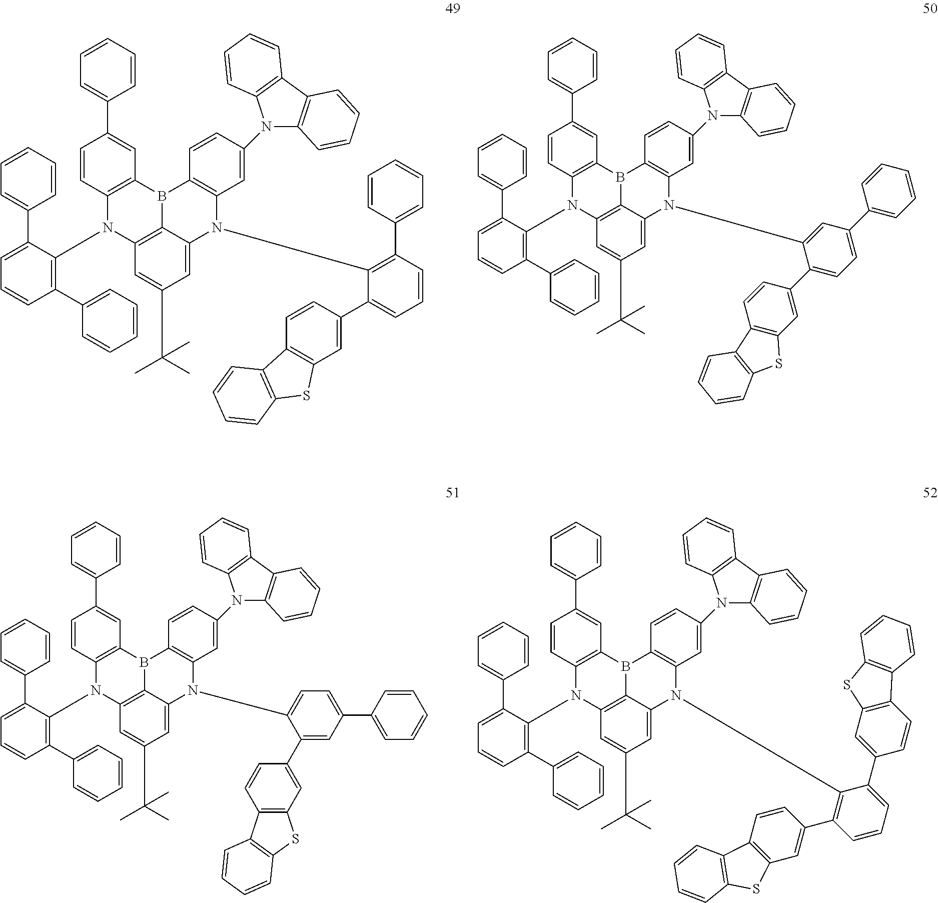 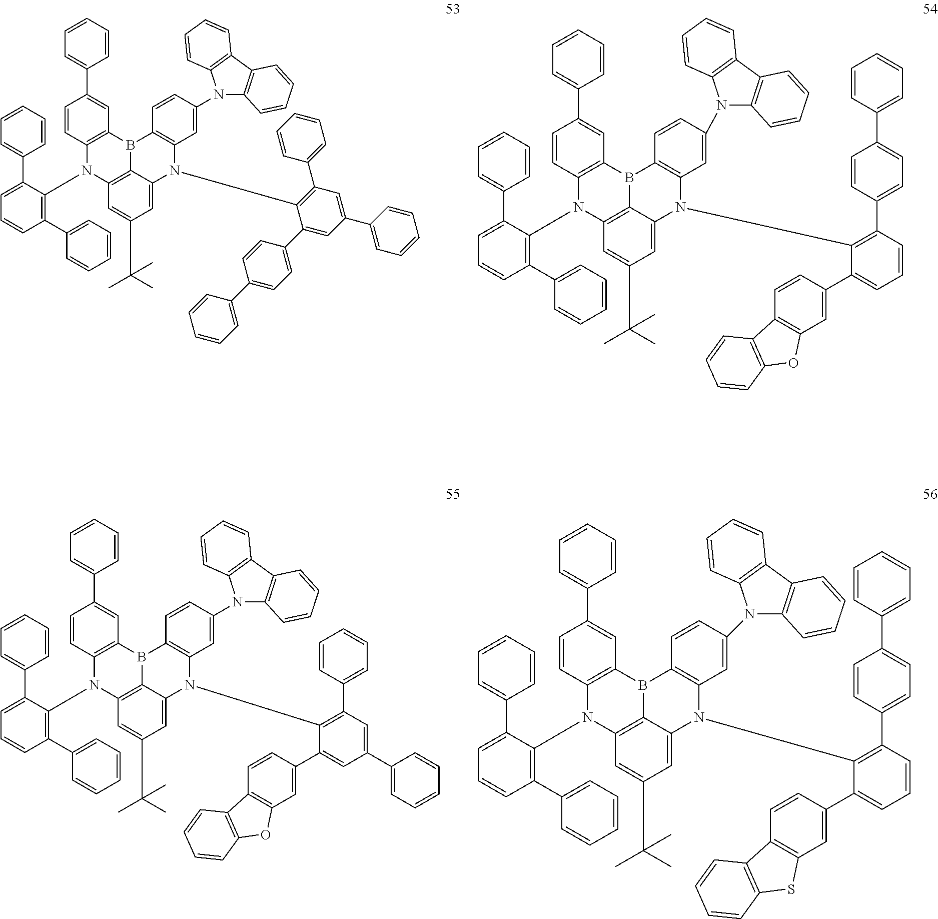 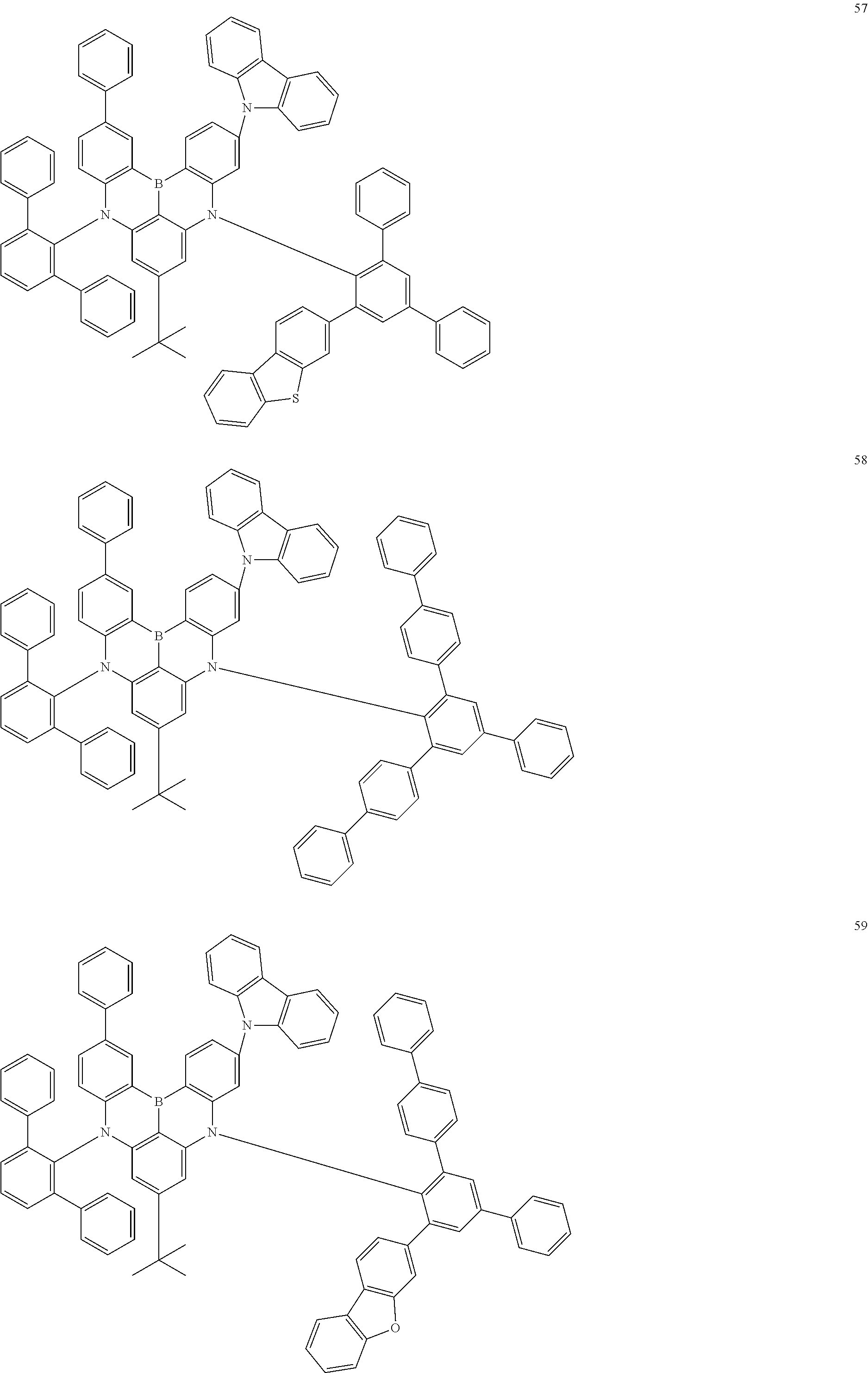 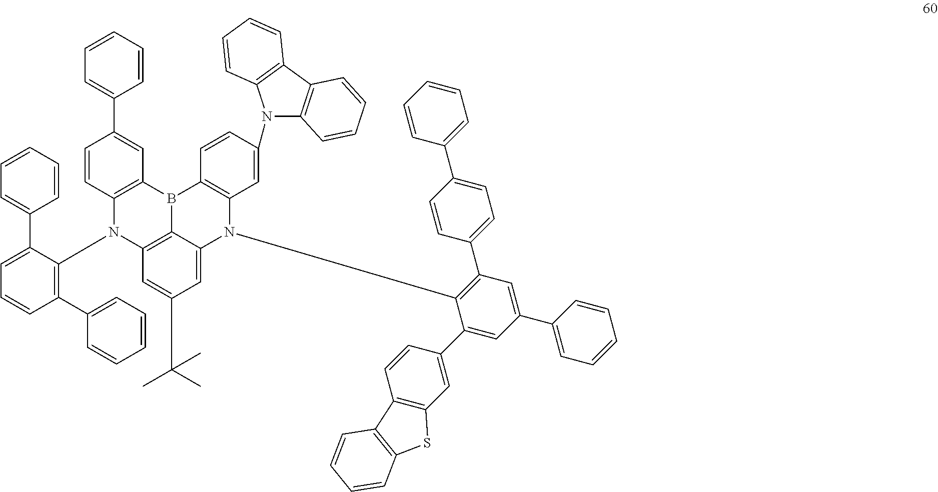 [SMILES: CC(C)(C)c1cc2c3c(c1)N(c1c(-c4ccc(-c5ccccc5)cc4)cc(-c4ccccc4)cc1-c1ccc4c(c1)sc1ccccc14)c1cc(-n4c5ccccc5c5ccccc54)ccc1B3c1cc(-c3ccccc3)ccc1N2c1c(-c2ccccc2)cccc1-c1ccccc1] 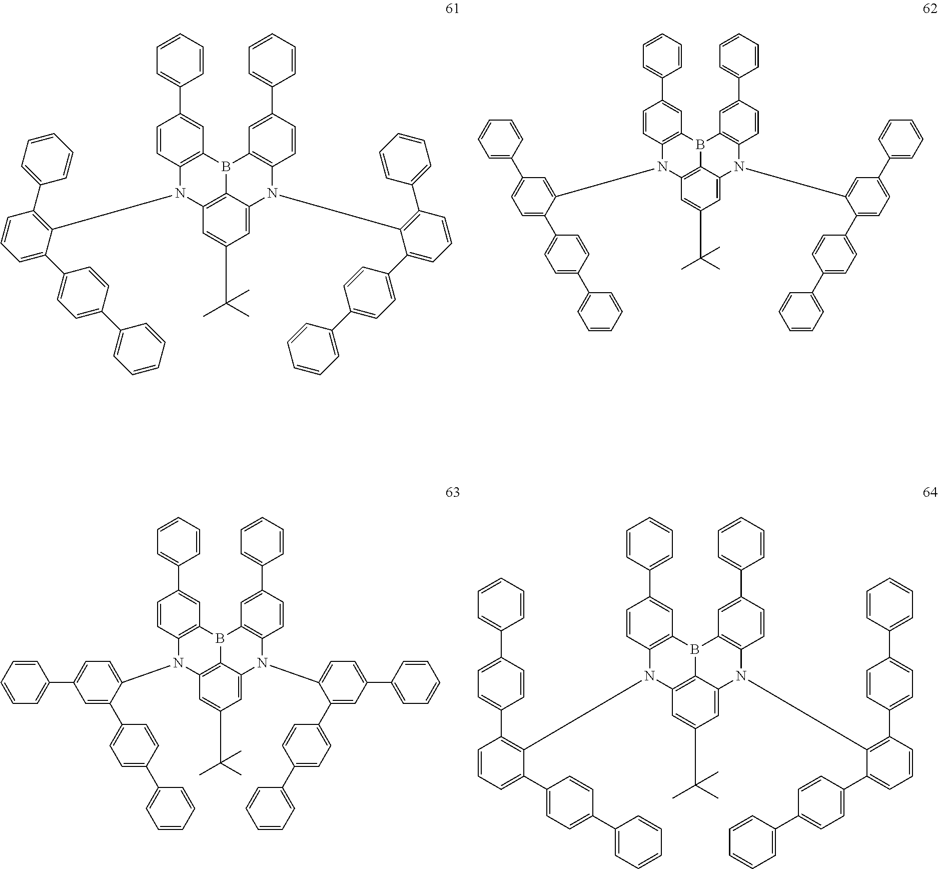 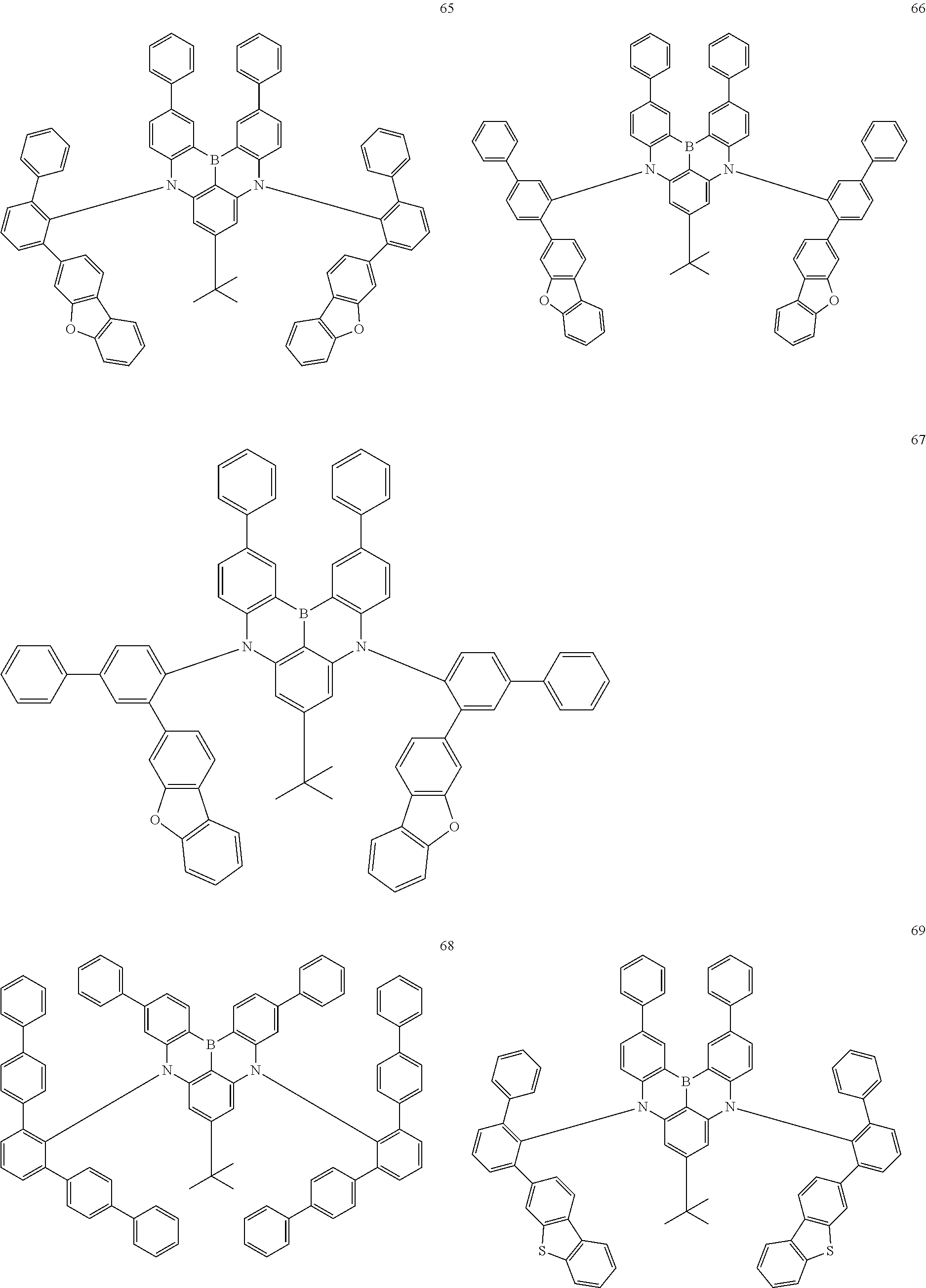 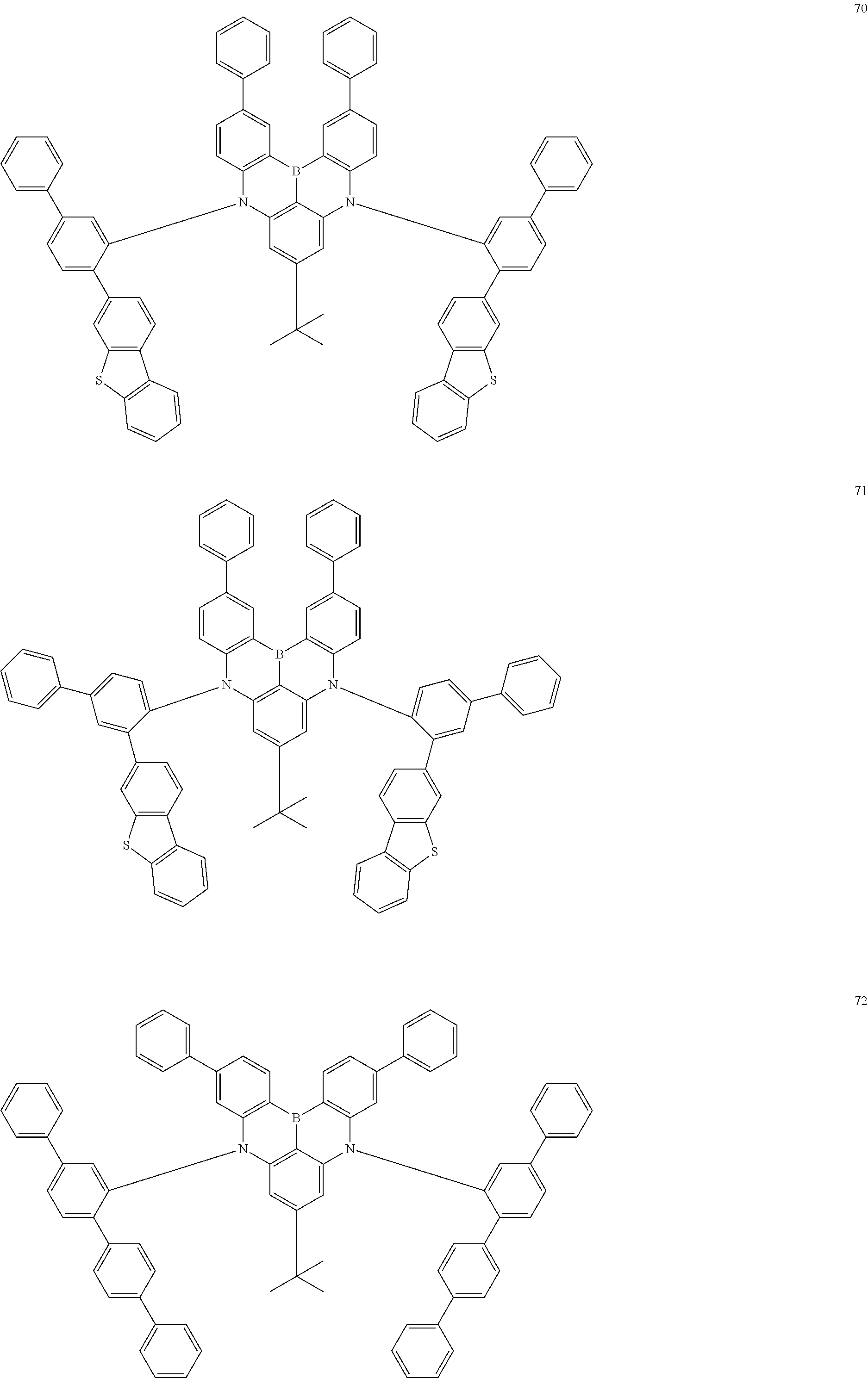 [SMILES: CC(C)(C)c1cc2c3c(c1)N(c1cc(-c4ccccc4)ccc1-c1ccc4c(c1)sc1ccccc14)c1ccc(-c4ccccc4)cc1B3c1cc(-c3ccccc3)ccc1N2c1cc(-c2ccccc2)ccc1-c1ccc2c(c1)sc1ccccc12 ; CC(C)(C)c1cc2c3c(c1)N(c1ccc(-c4ccccc4)cc1-c1ccc4c(c1)sc1ccccc14)c1ccc(-c4ccccc4)cc1B3c1cc(-c3ccccc3)ccc1N2c1ccc(-c2ccccc2)cc1-c1ccc2c(c1)sc1ccccc12 ; CC(C)(C)c1cc2c3c(c1)N(c1cc(-c4ccccc4)ccc1-c1ccc(-c4ccccc4)cc1)c1cc(-c4ccccc4)ccc1B3c1ccc(-c3ccccc3)cc1N2c1cc(-c2ccccc2)ccc1-c1ccc(-c2ccccc2)cc1] 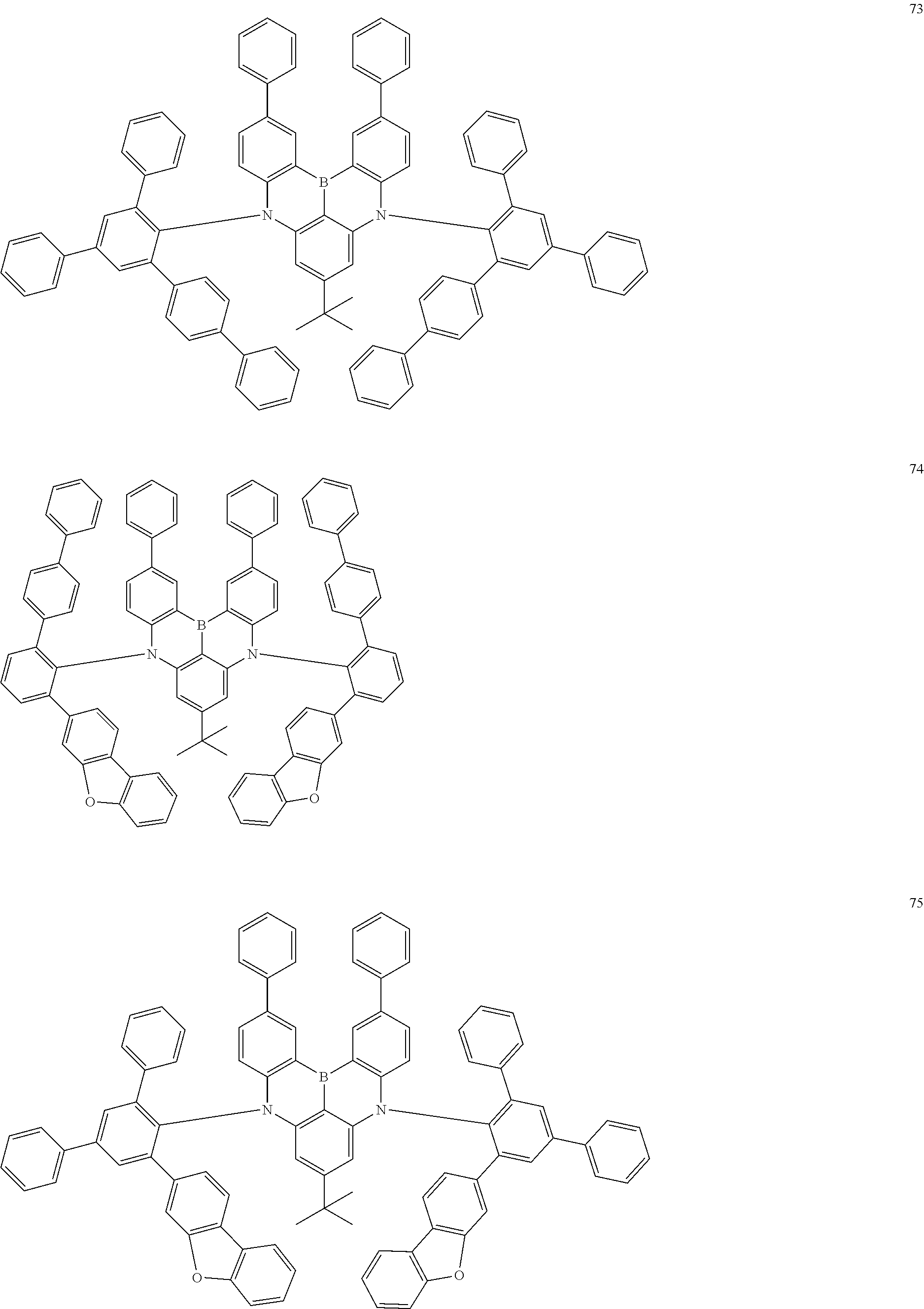 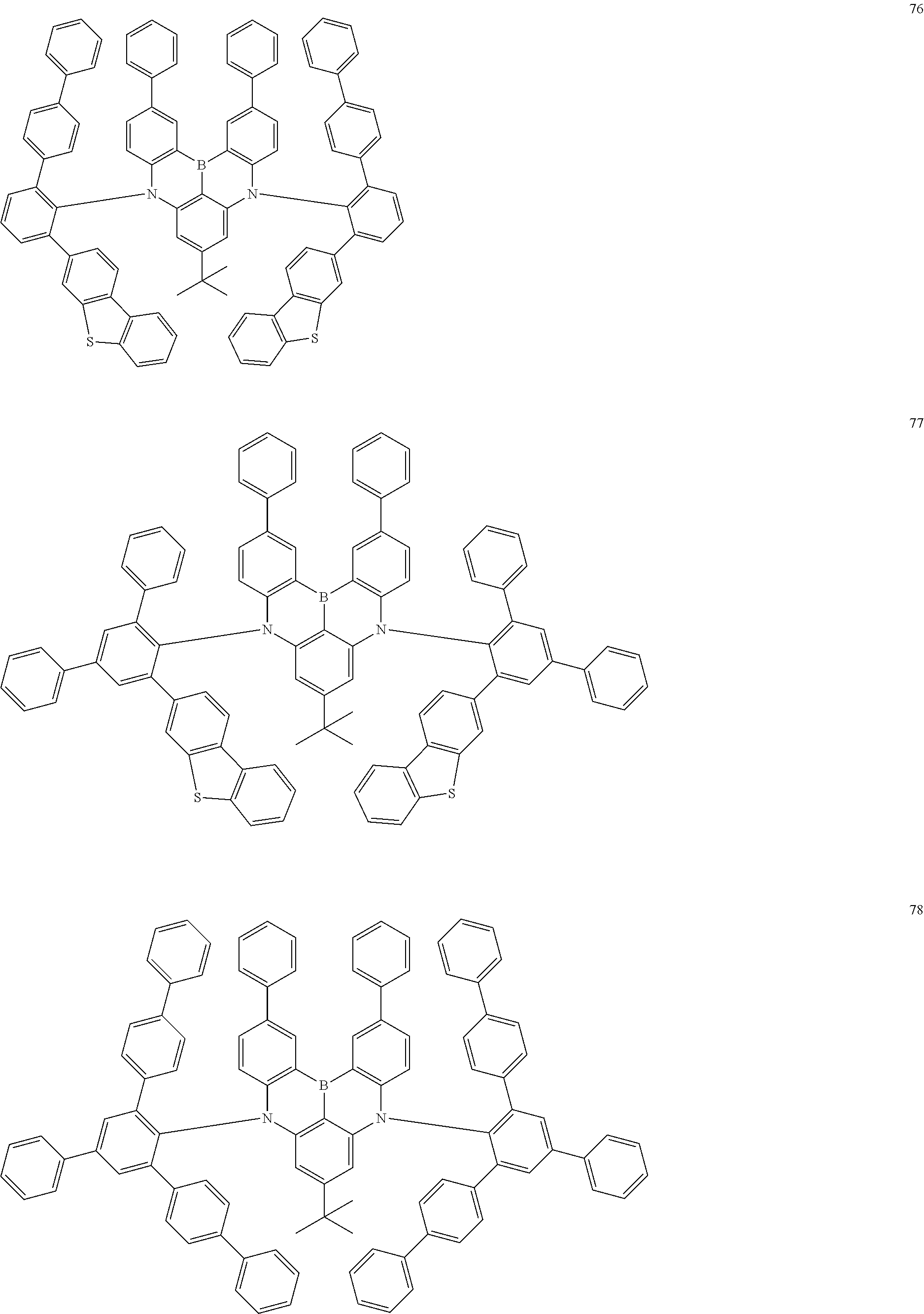 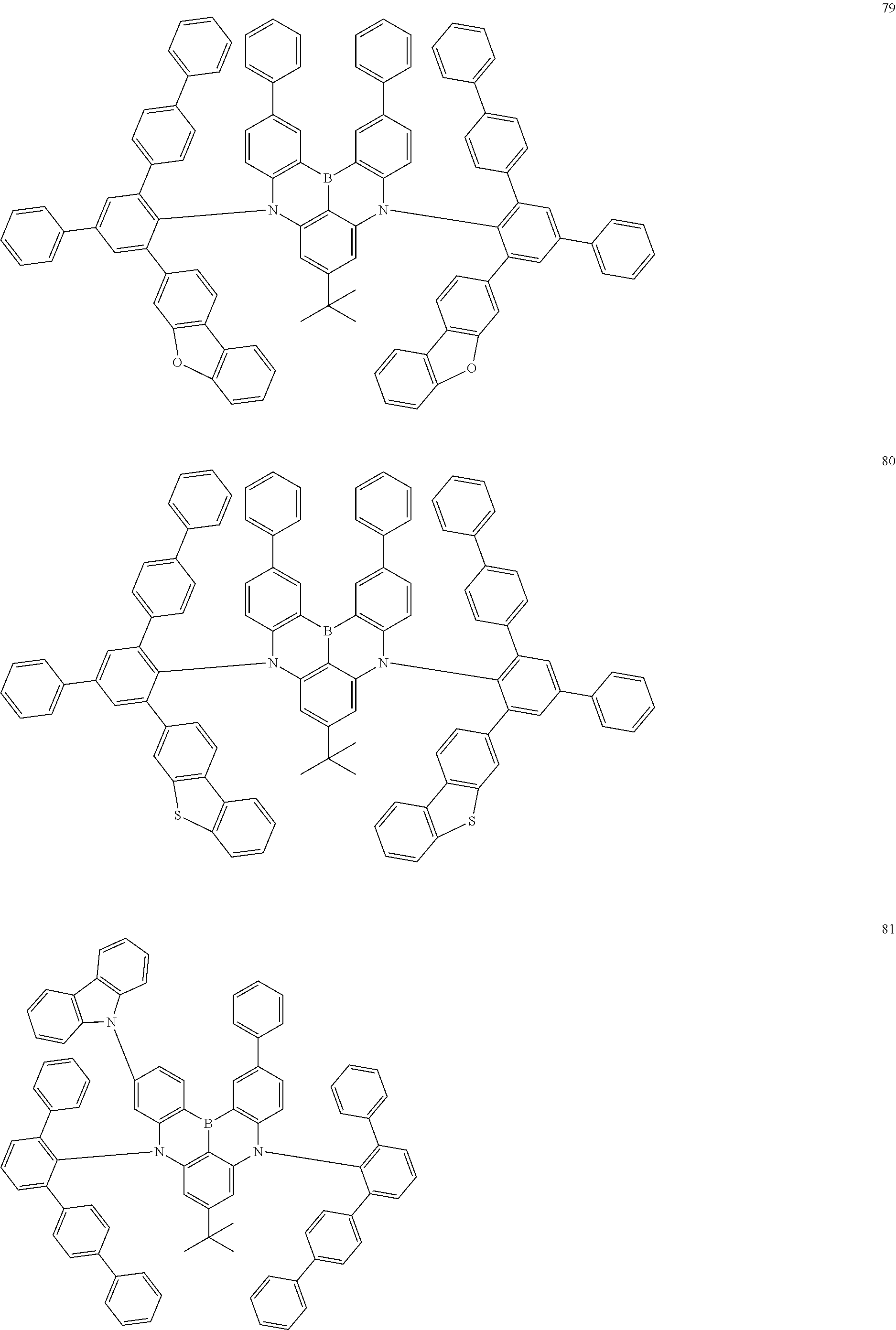 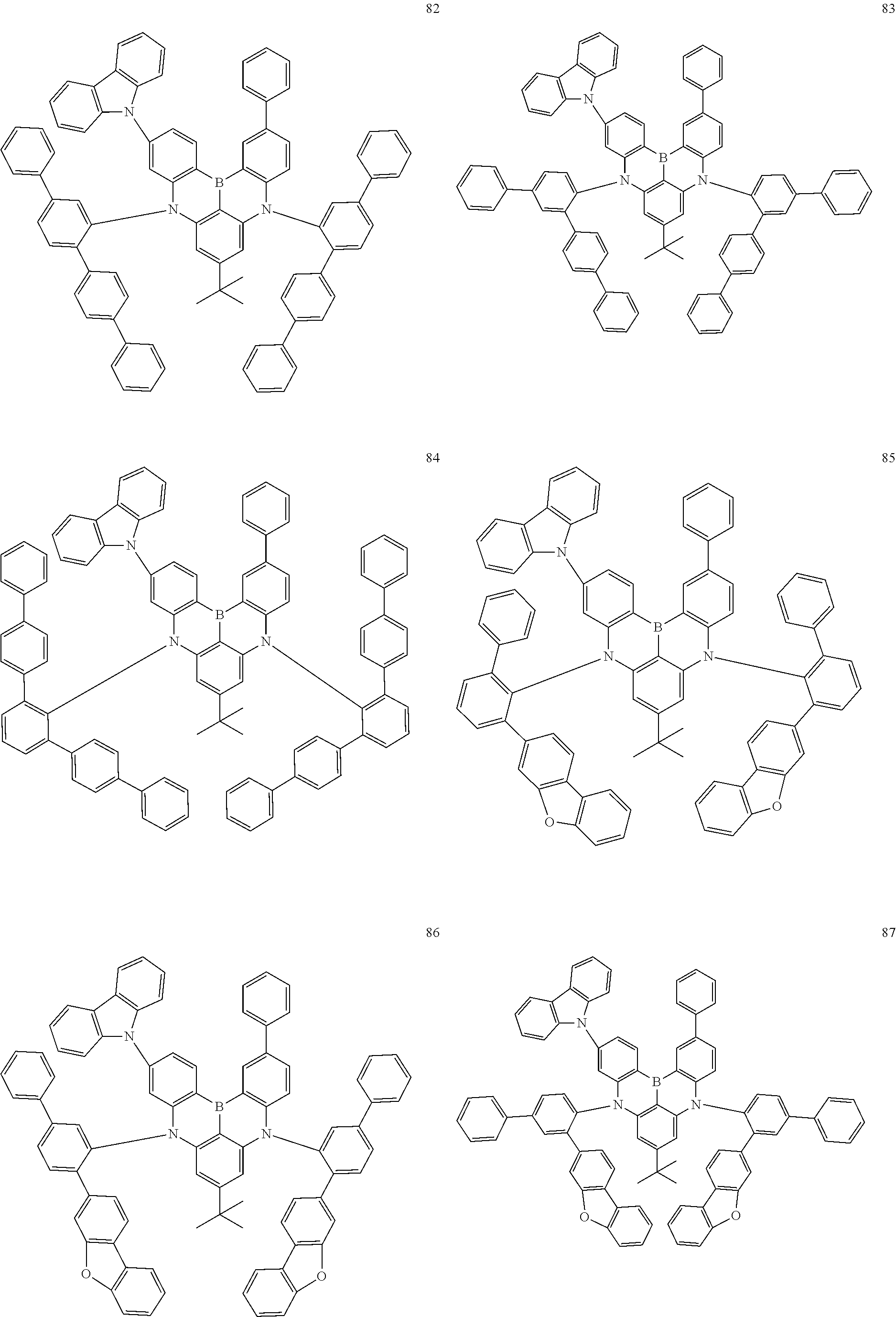 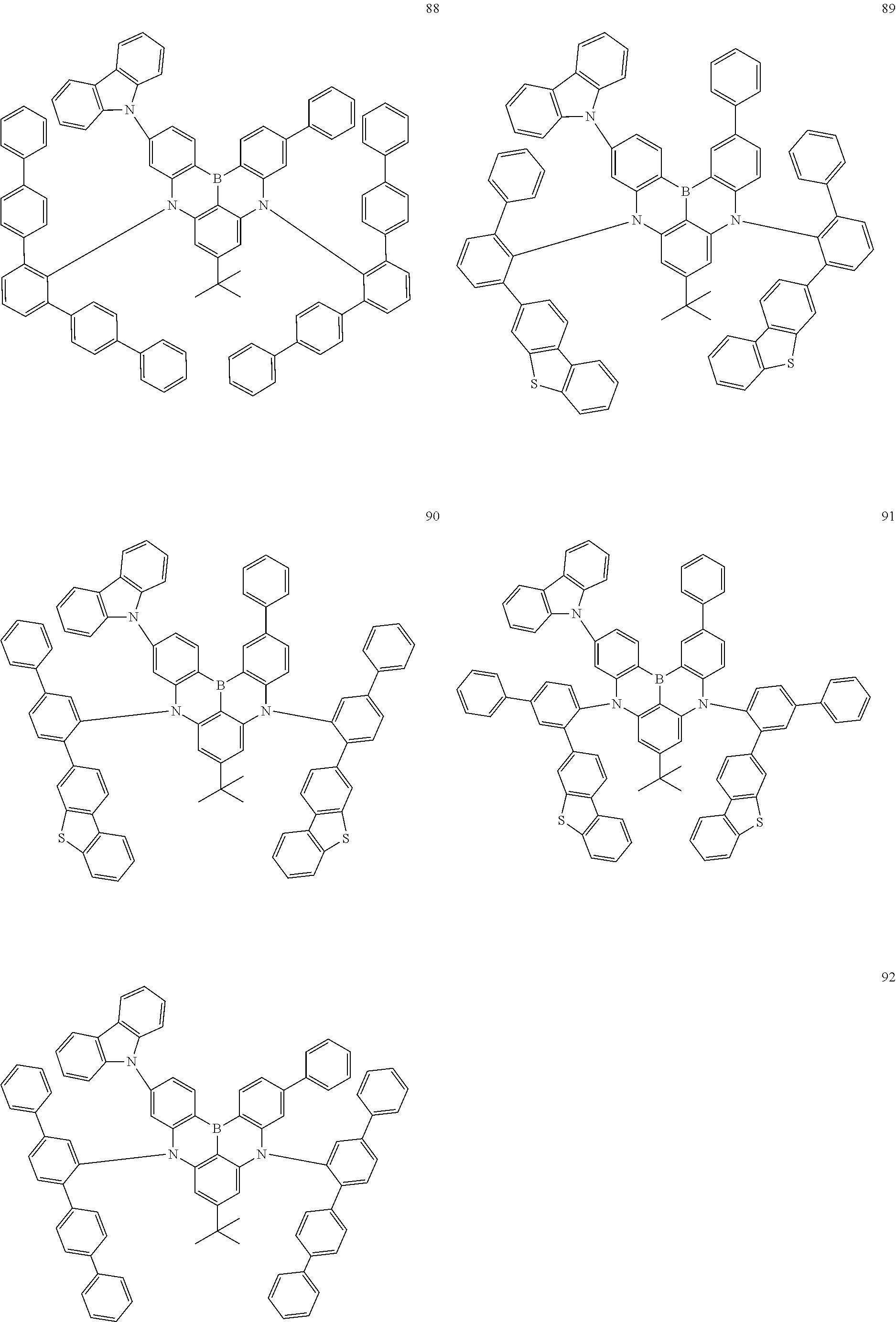 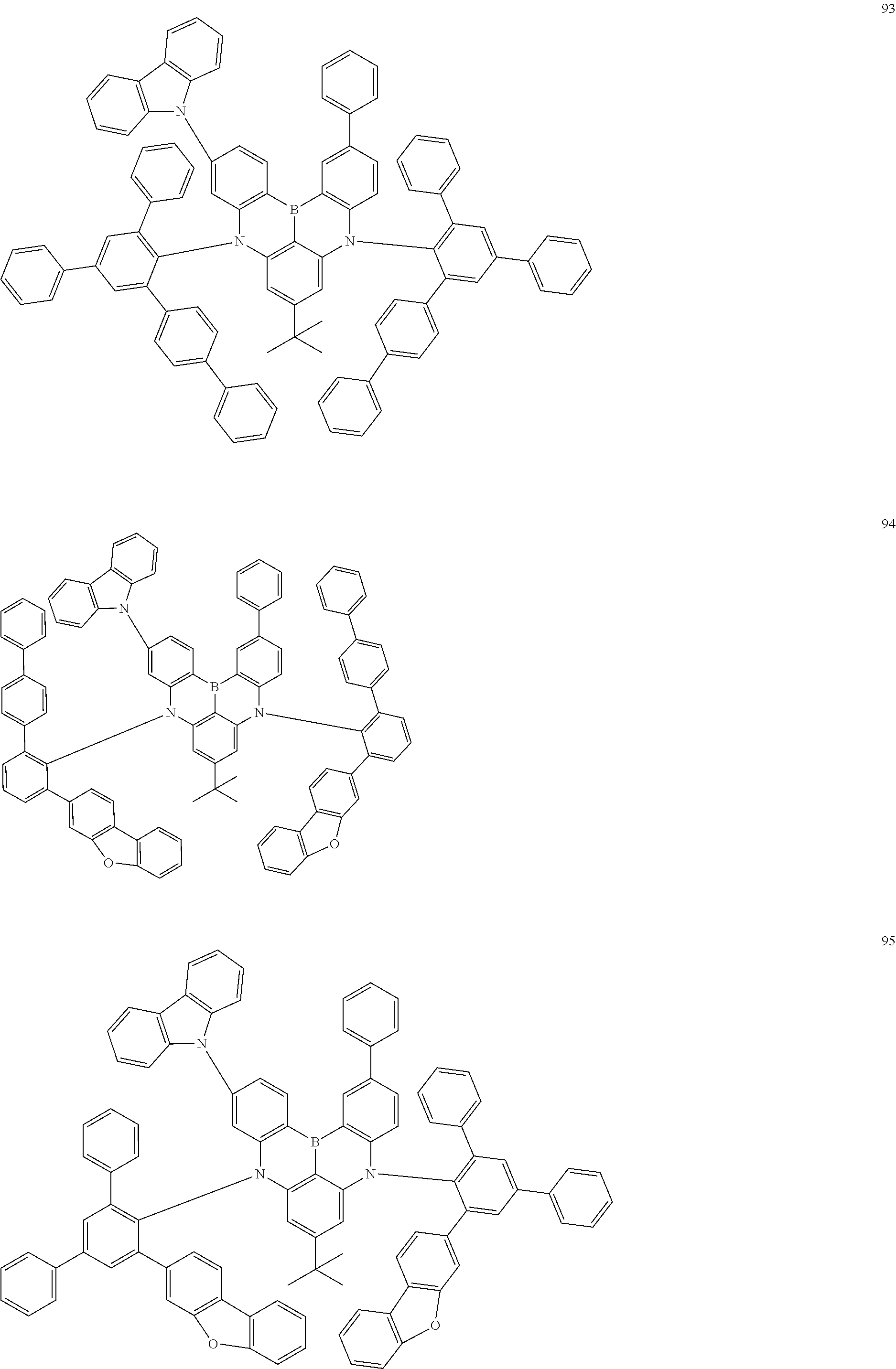 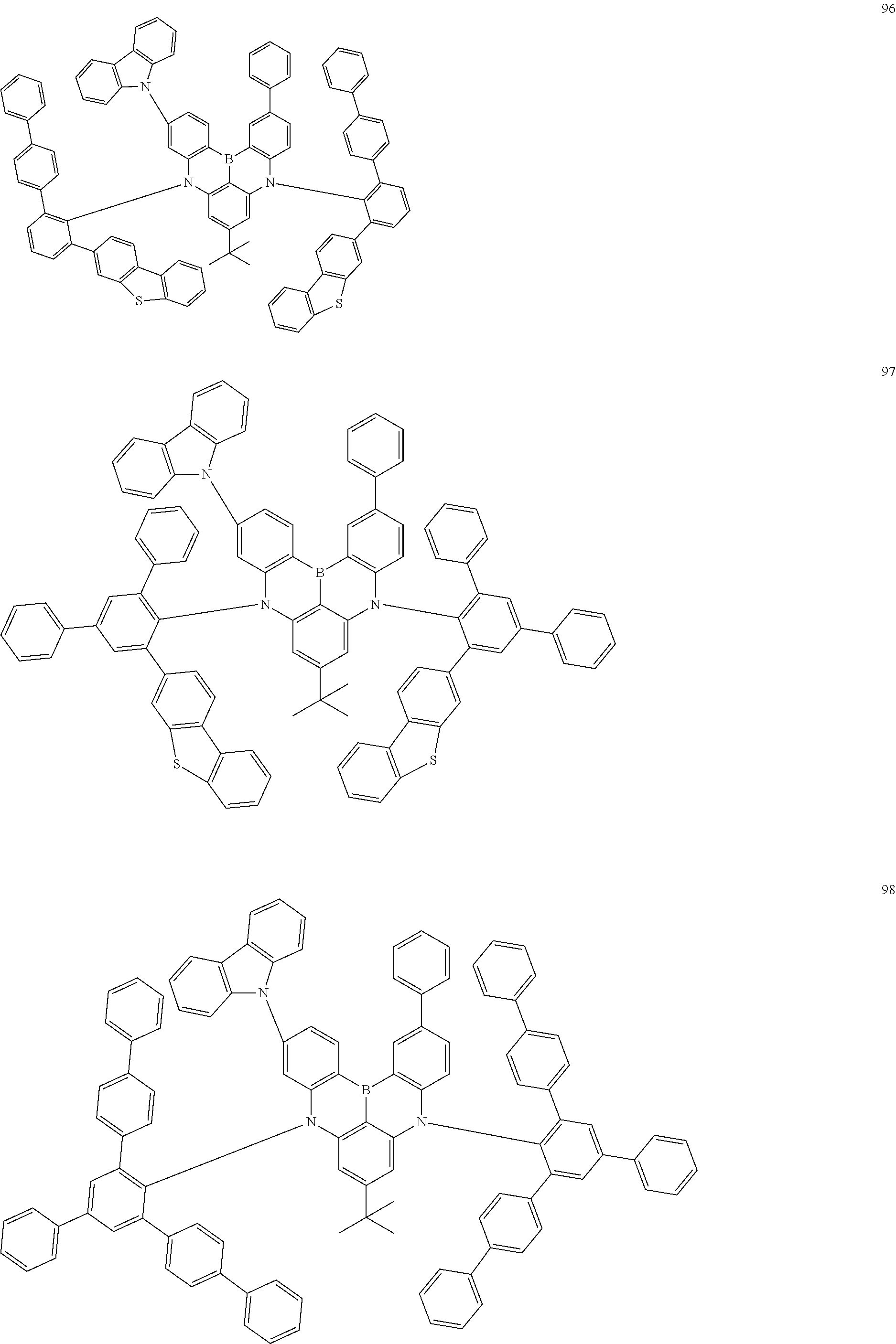 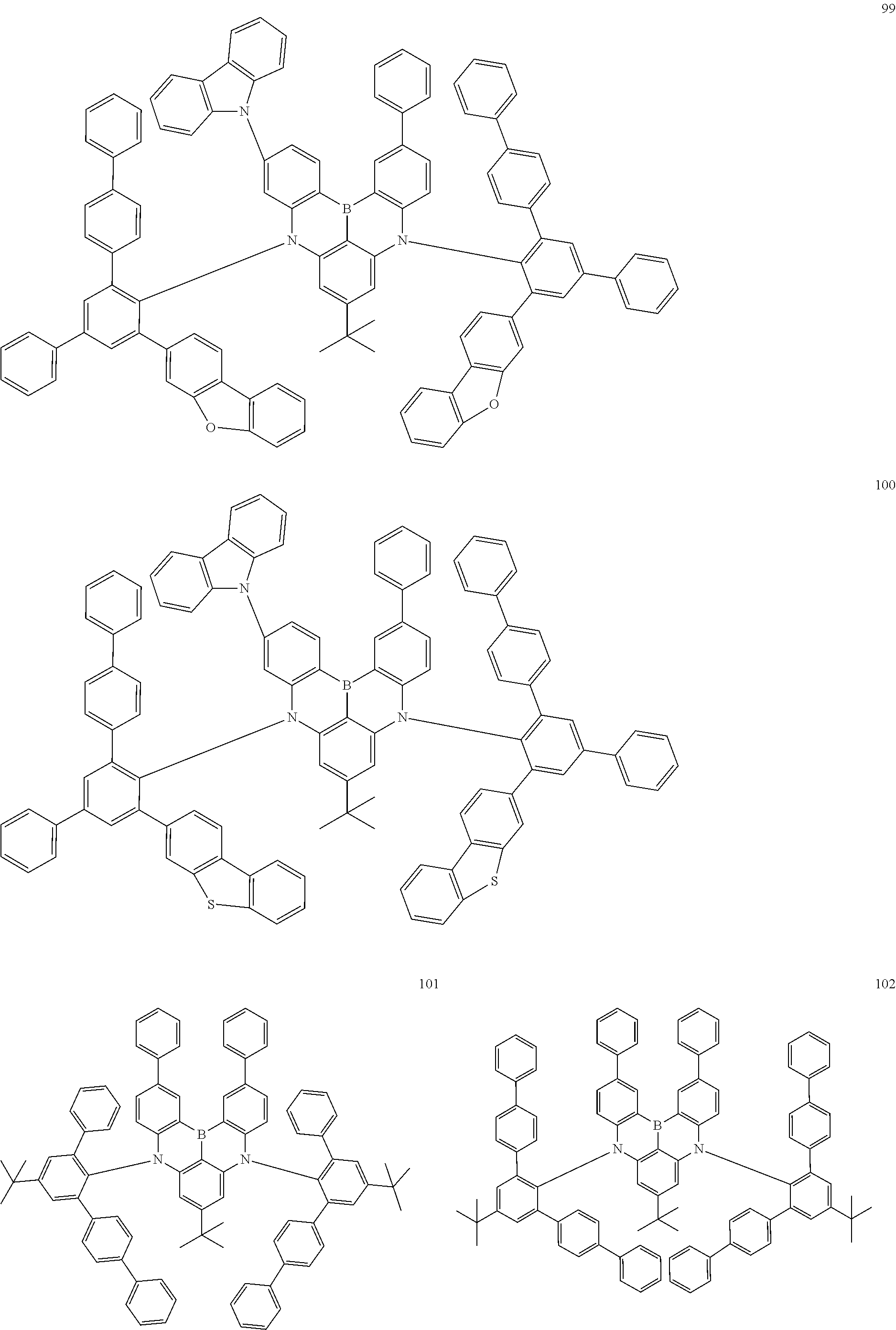 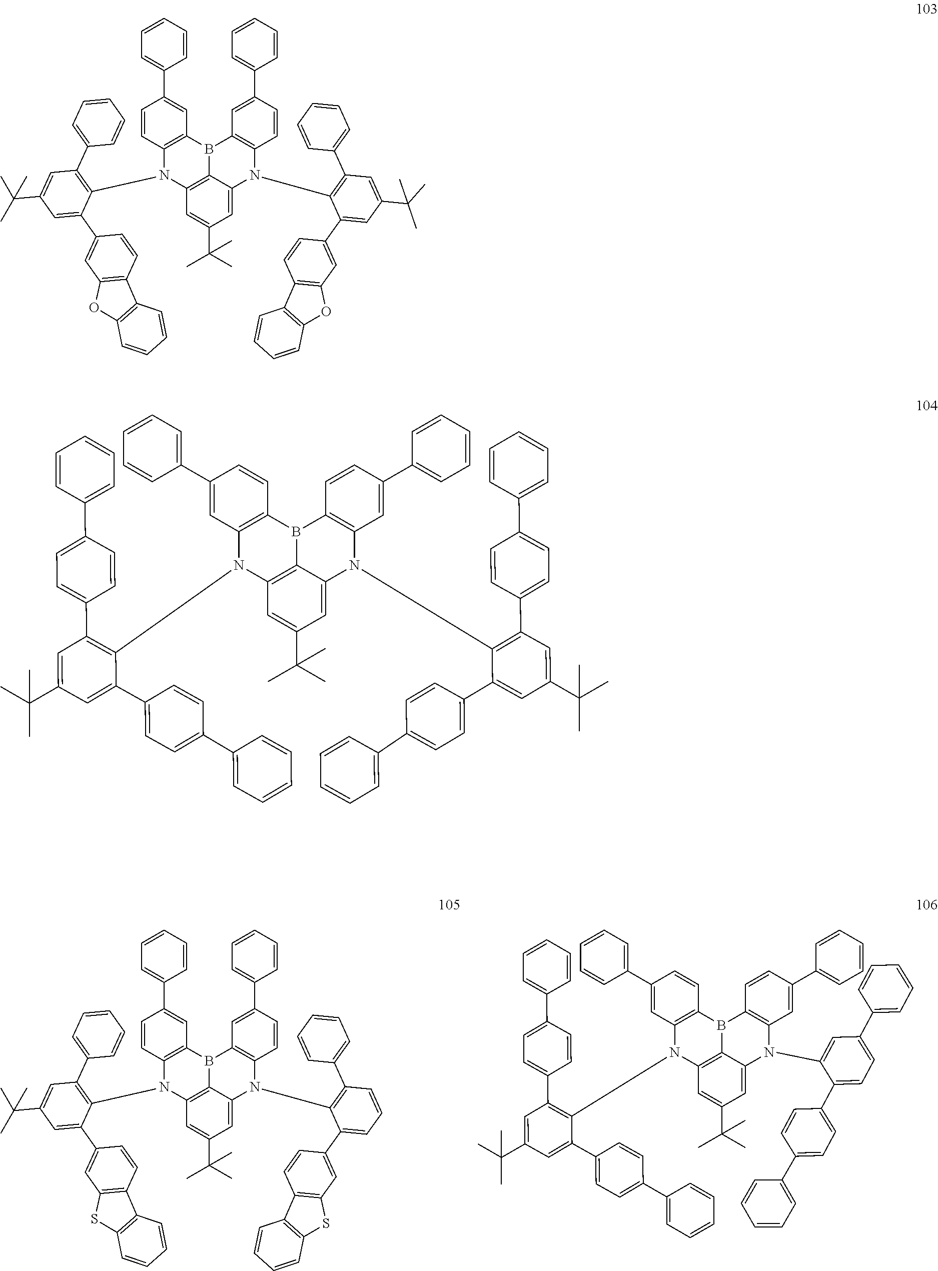 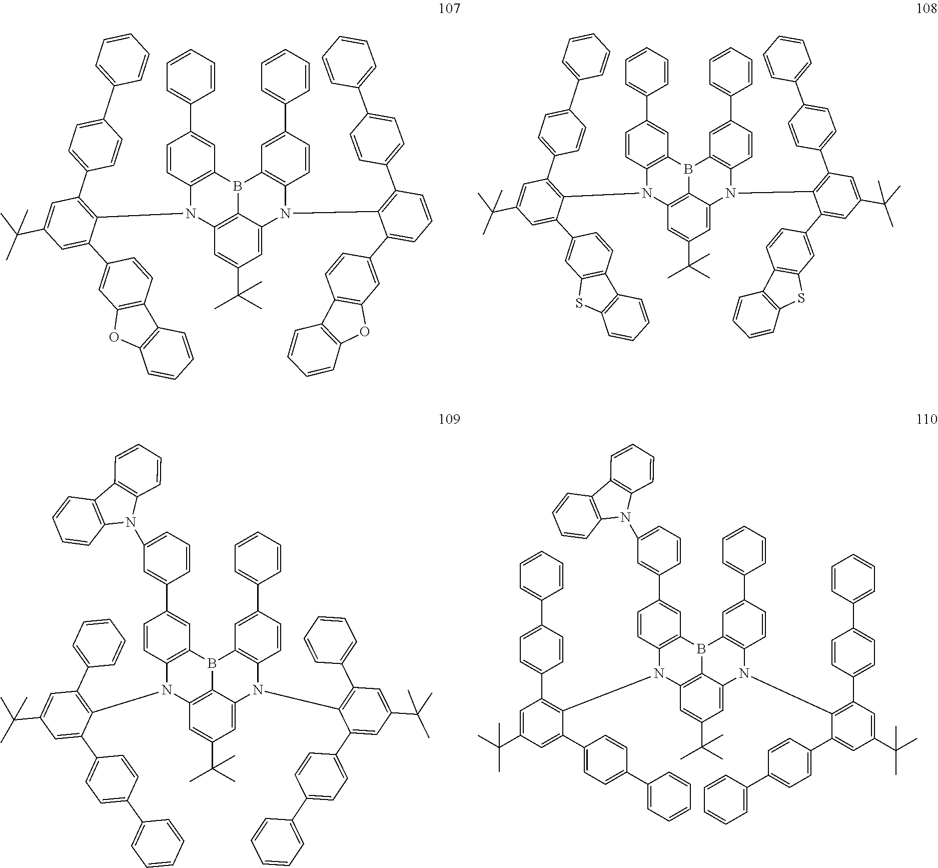 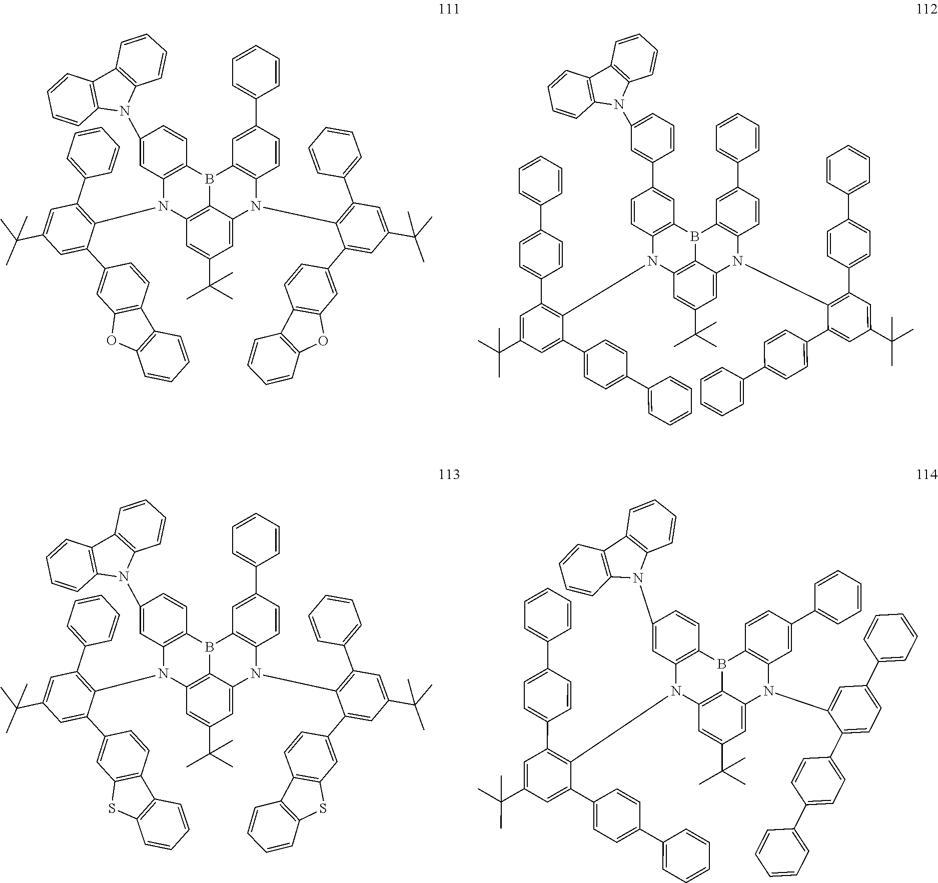 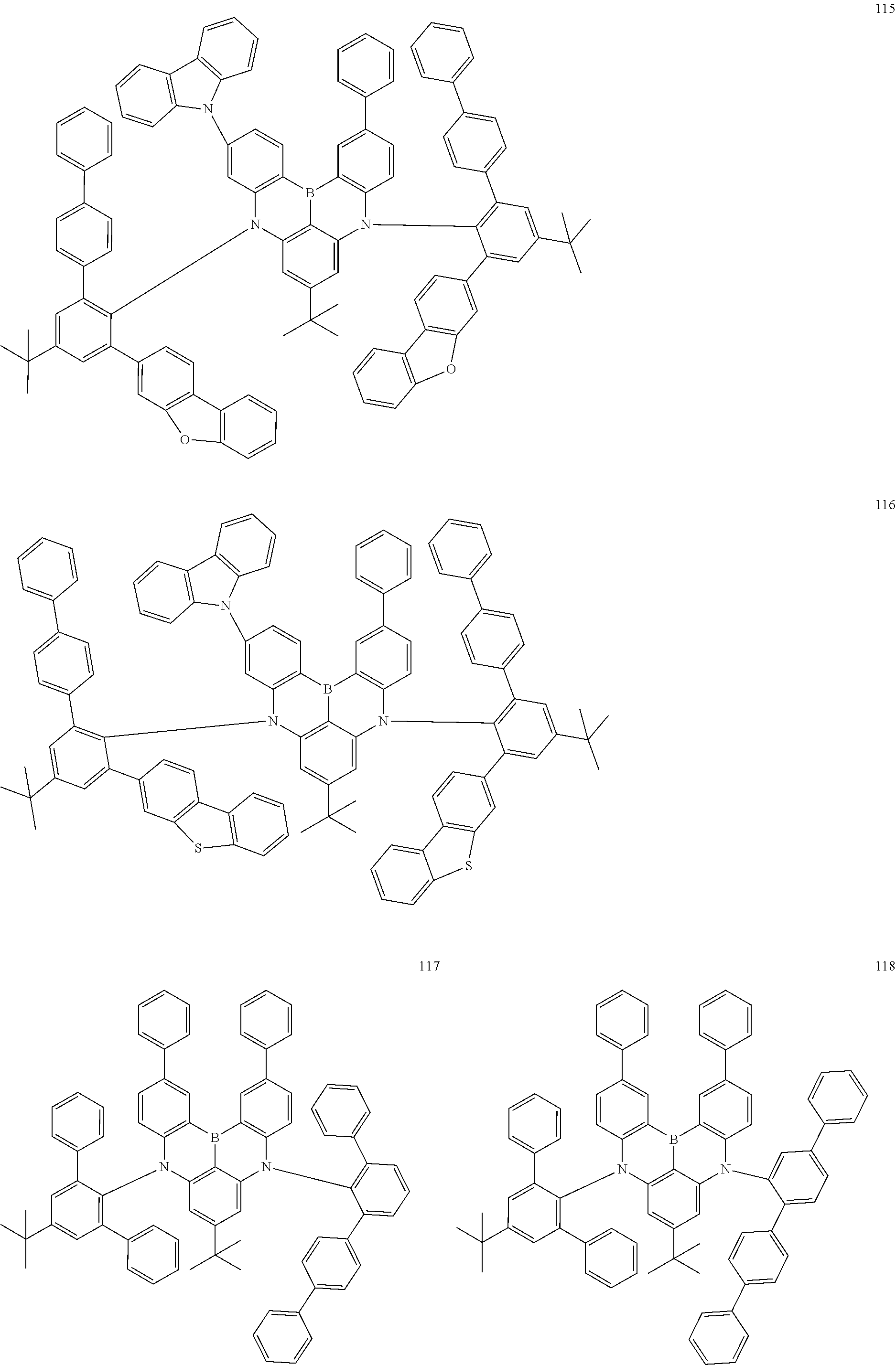 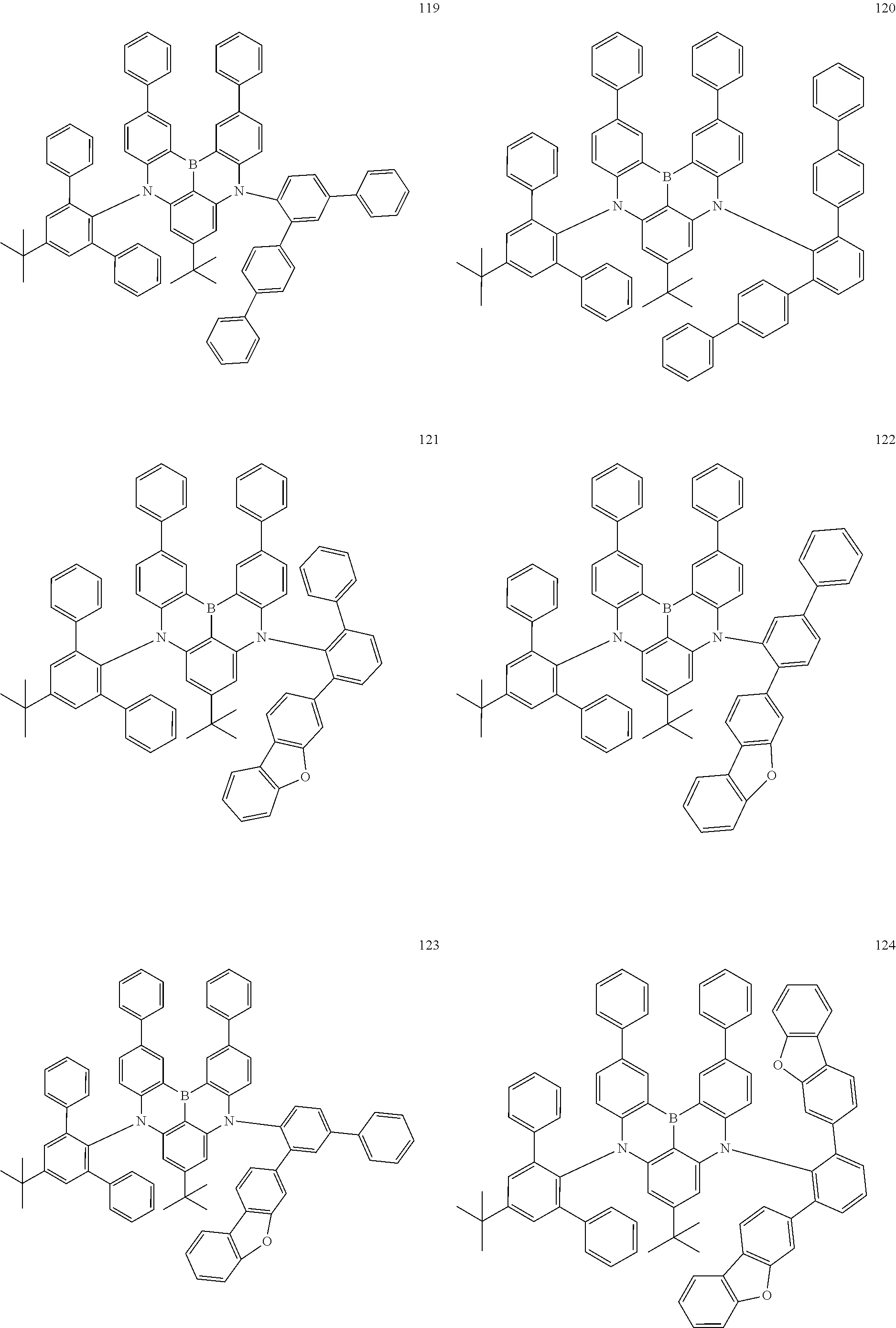 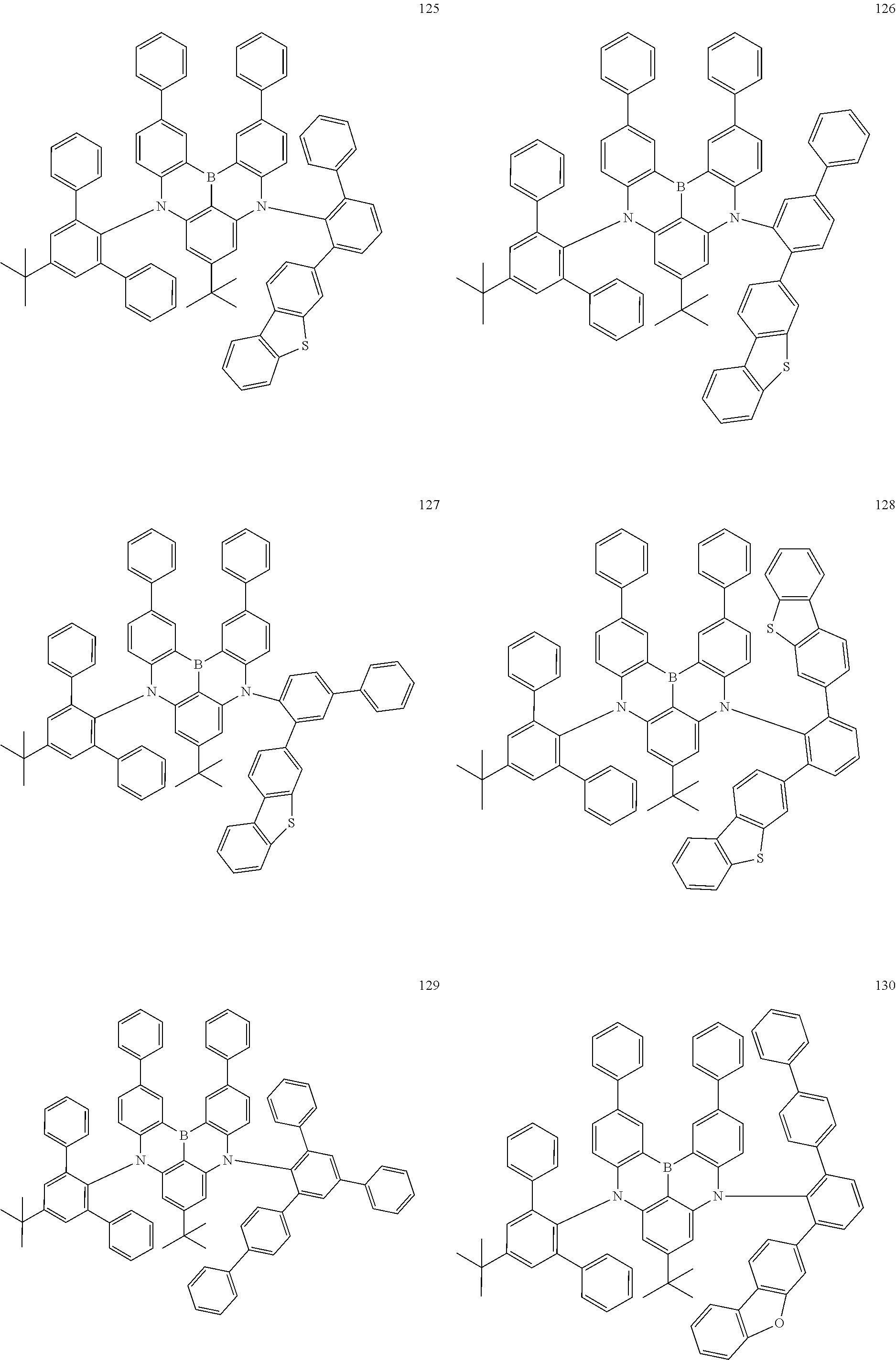 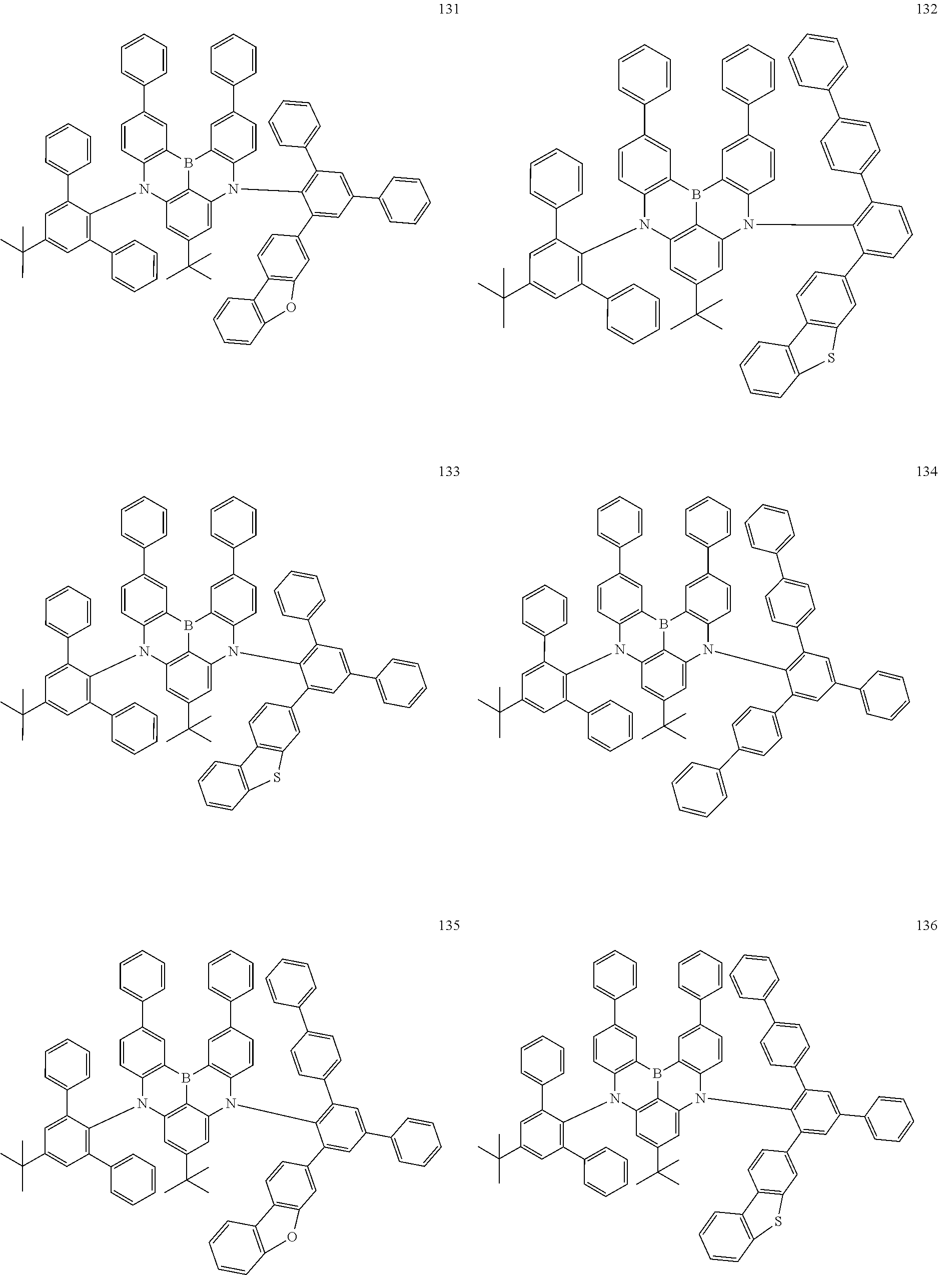 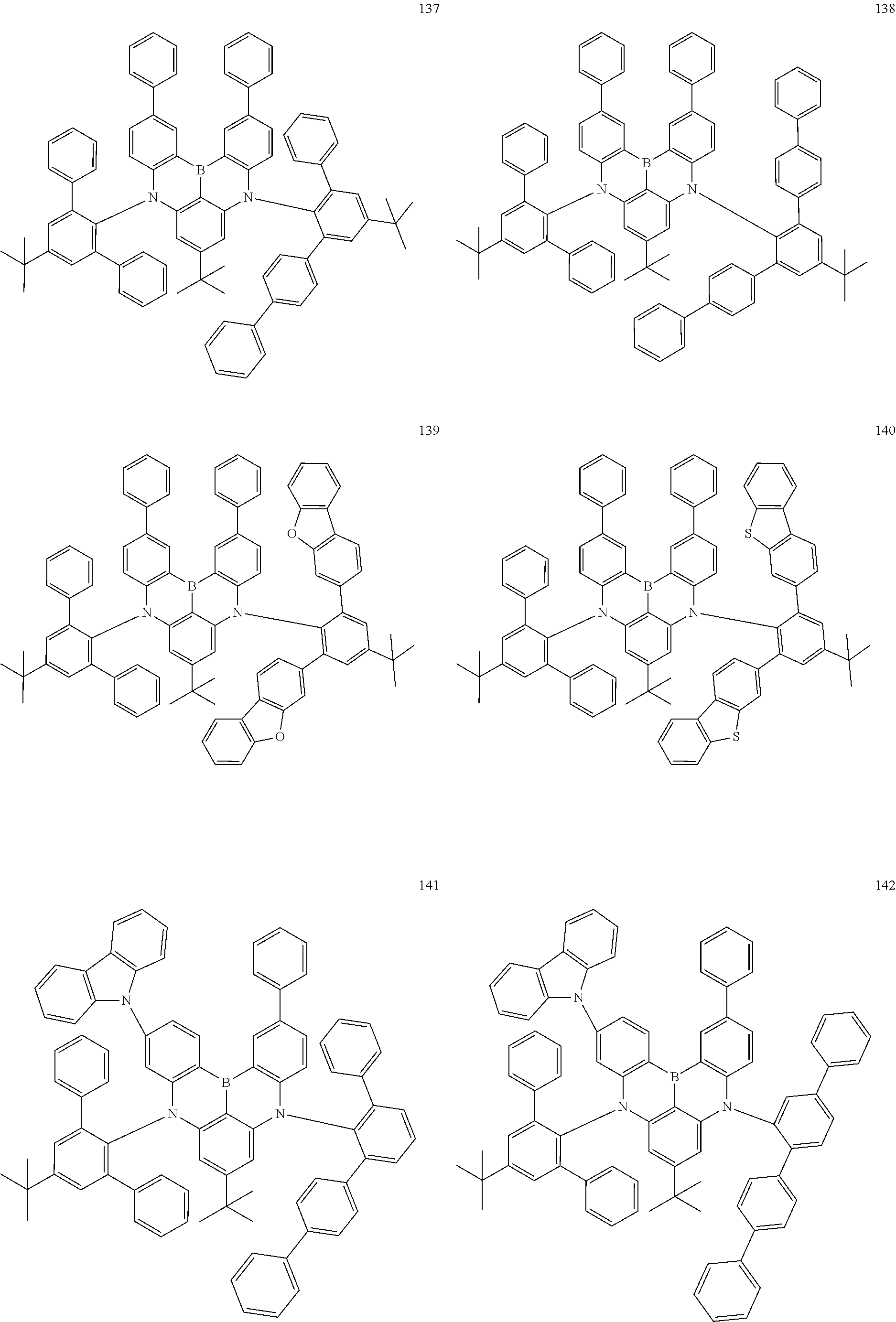 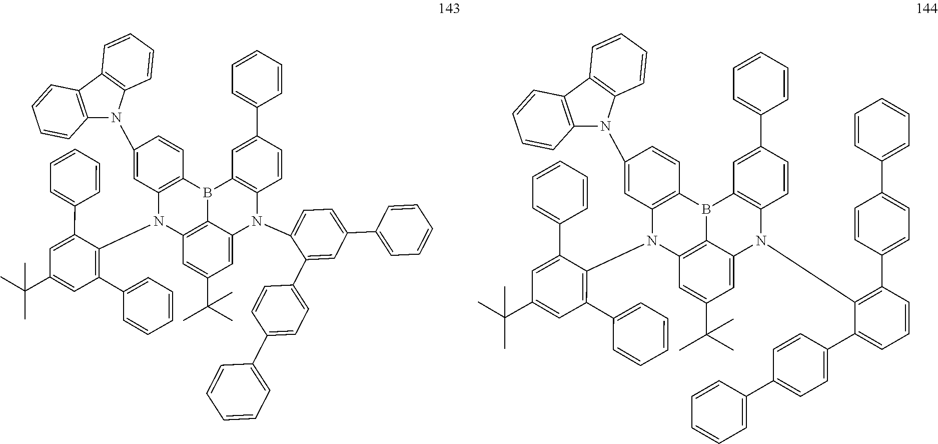 [SMILES: CC(C)(C)c1cc(-c2ccccc2)c(N2c3cc(-n4c5ccccc5c5ccccc54)ccc3B3c4cc(-c5ccccc5)ccc4N(c4ccc(-c5ccccc5)cc4-c4ccc(-c5ccccc5)cc4)c4cc(C(C)(C)C)cc2c43)c(-c2ccccc2)c1 ; CC(C)(C)c1cc(-c2ccccc2)c(N2c3cc(-n4c5ccccc5c5ccccc54)ccc3B3c4cc(-c5ccccc5)ccc4N(c4c(-c5ccc(-c6ccccc6)cc5)cccc4-c4ccc(-c5ccccc5)cc4)c4cc(C(C)(C)C)cc2c43)c(-c2ccccc2)c1] 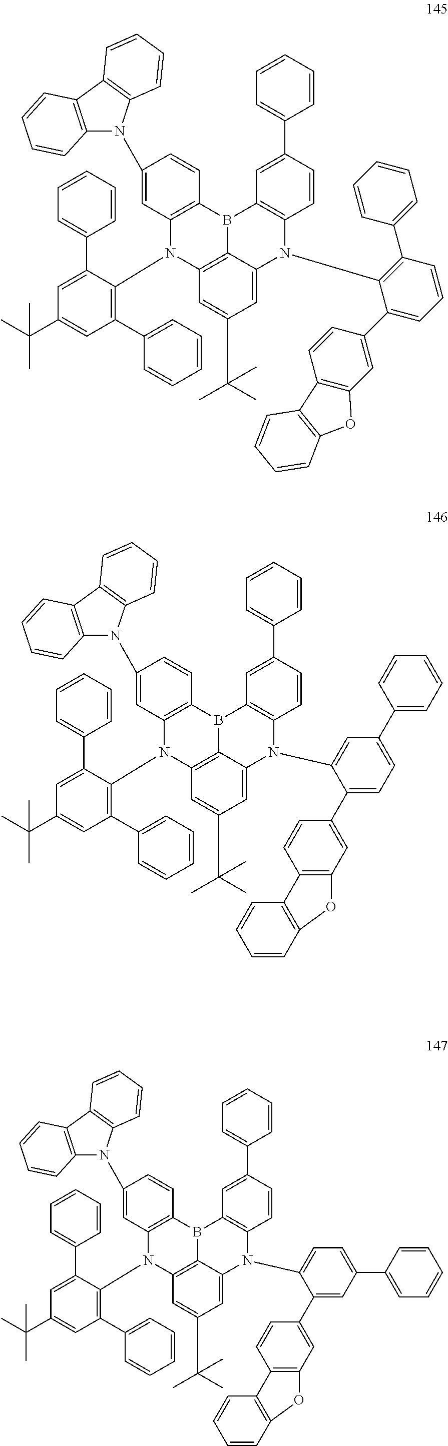 [SMILES: CC(C)(C)c1cc(-c2ccccc2)c(N2c3cc(-n4c5ccccc5c5ccccc54)ccc3B3c4cc(-c5ccccc5)ccc4N(c4c(-c5ccccc5)cccc4-c4ccc5c(c4)oc4ccccc45)c4cc(C(C)(C)C)cc2c43)c(-c2ccccc2)c1 ; CC(C)(C)c1cc(-c2ccccc2)c(N2c3cc(-n4c5ccccc5c5ccccc54)ccc3B3c4cc(-c5ccccc5)ccc4N(c4cc(-c5ccccc5)ccc4-c4ccc5c(c4)oc4ccccc45)c4cc(C(C)(C)C)cc2c43)c(-c2ccccc2)c1 ; CC(C)(C)c1cc(-c2ccccc2)c(N2c3cc(-n4c5ccccc5c5ccccc54)ccc3B3c4cc(-c5ccccc5)ccc4N(c4ccc(-c5ccccc5)cc4-c4ccc5c(c4)oc4ccccc45)c4cc(C(C)(C)C)cc2c43)c(-c2ccccc2)c1] 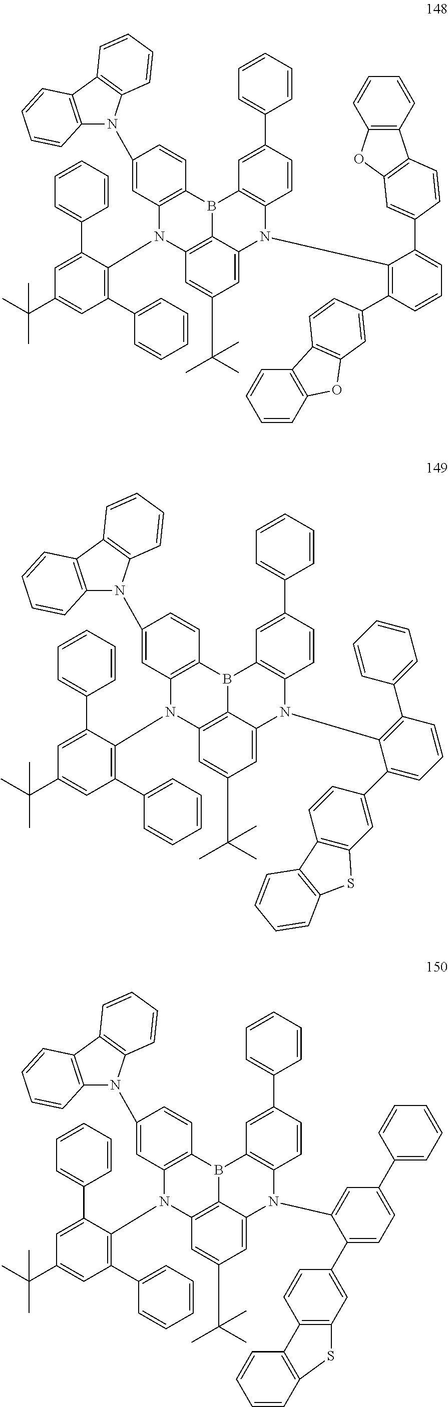 [SMILES: CC(C)(C)c1cc(-c2ccccc2)c(N2c3cc(-n4c5ccccc5c5ccccc54)ccc3B3c4cc(-c5ccccc5)ccc4N(c4c(-c5ccc6c(c5)oc5ccccc56)cccc4-c4ccc5c(c4)oc4ccccc45)c4cc(C(C)(C)C)cc2c43)c(-c2ccccc2)c1 ; CC(C)(C)c1cc(-c2ccccc2)c(N2c3cc(-n4c5ccccc5c5ccccc54)ccc3B3c4cc(-c5ccccc5)ccc4N(c4c(-c5ccccc5)cccc4-c4ccc5c(c4)sc4ccccc45)c4cc(C(C)(C)C)cc2c43)c(-c2ccccc2)c1 ; CC(C)(C)c1cc(-c2ccccc2)c(N2c3cc(-n4c5ccccc5c5ccccc54)ccc3B3c4cc(-c5ccccc5)ccc4N(c4cc(-c5ccccc5)ccc4-c4ccc5c(c4)sc4ccccc45)c4cc(C(C)(C)C)cc2c43)c(-c2ccccc2)c1] 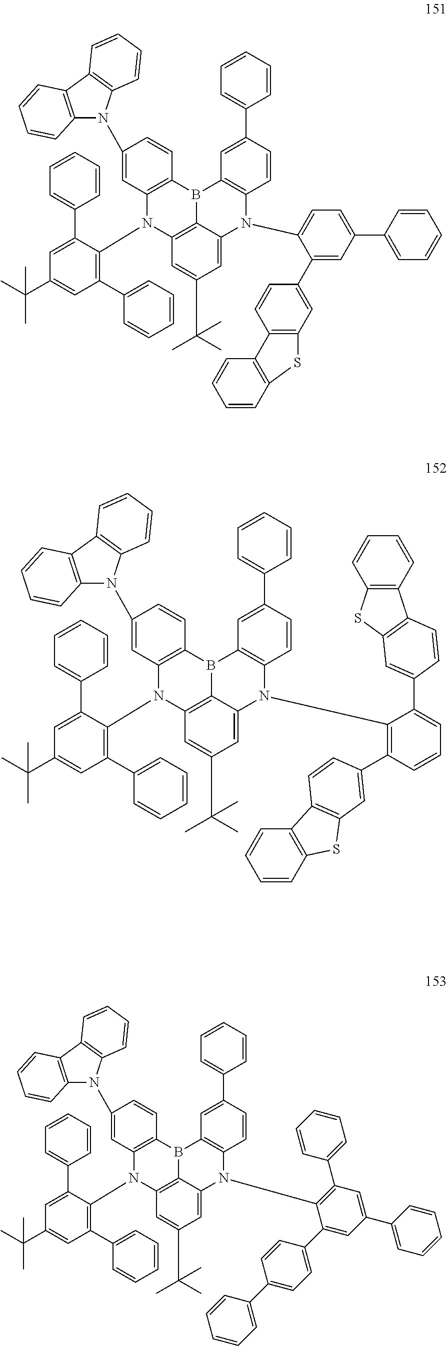 [SMILES: CC(C)(C)c1cc(-c2ccccc2)c(N2c3cc(-n4c5ccccc5c5ccccc54)ccc3B3c4cc(-c5ccccc5)ccc4N(c4ccc(-c5ccccc5)cc4-c4ccc5c(c4)sc4ccccc45)c4cc(C(C)(C)C)cc2c43)c(-c2ccccc2)c1 ; CC(C)(C)c1cc(-c2ccccc2)c(N2c3cc(-n4c5ccccc5c5ccccc54)ccc3B3c4cc(-c5ccccc5)ccc4N(c4c(-c5ccc6c(c5)sc5ccccc56)cccc4-c4ccc5c(c4)sc4ccccc45)c4cc(C(C)(C)C)cc2c43)c(-c2ccccc2)c1 ; CC(C)(C)c1cc(-c2ccccc2)c(N2c3cc(-n4c5ccccc5c5ccccc54)ccc3B3c4cc(-c5ccccc5)ccc4N(c4c(-c5ccccc5)cc(-c5ccccc5)cc4-c4ccc(-c5ccccc5)cc4)c4cc(C(C)(C)C)cc2c43)c(-c2ccccc2)c1] 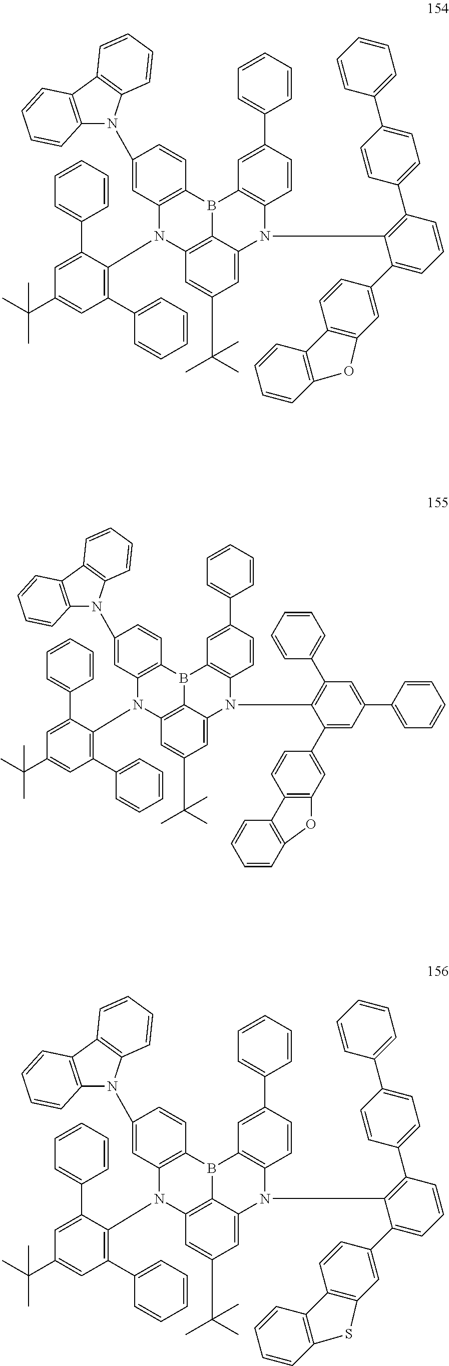 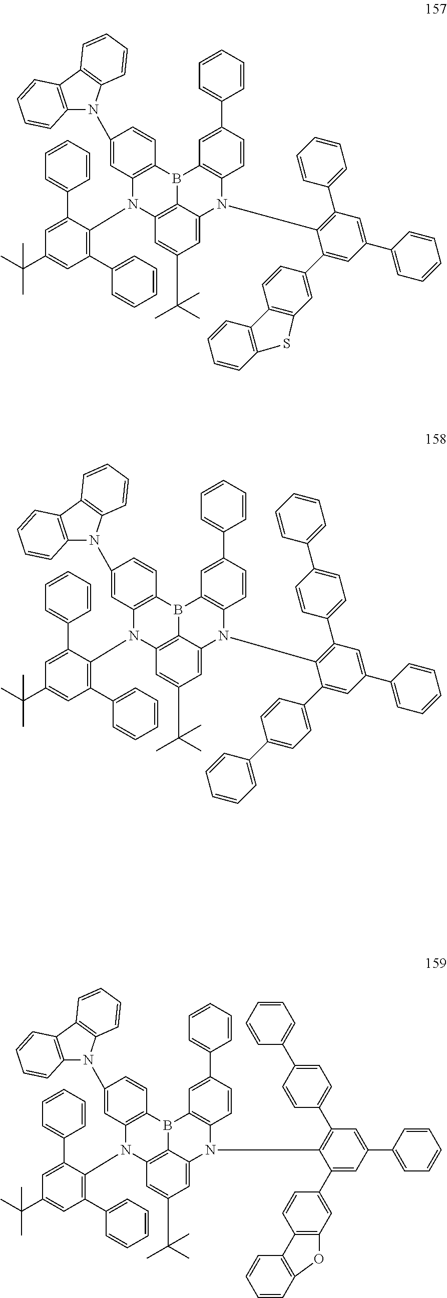 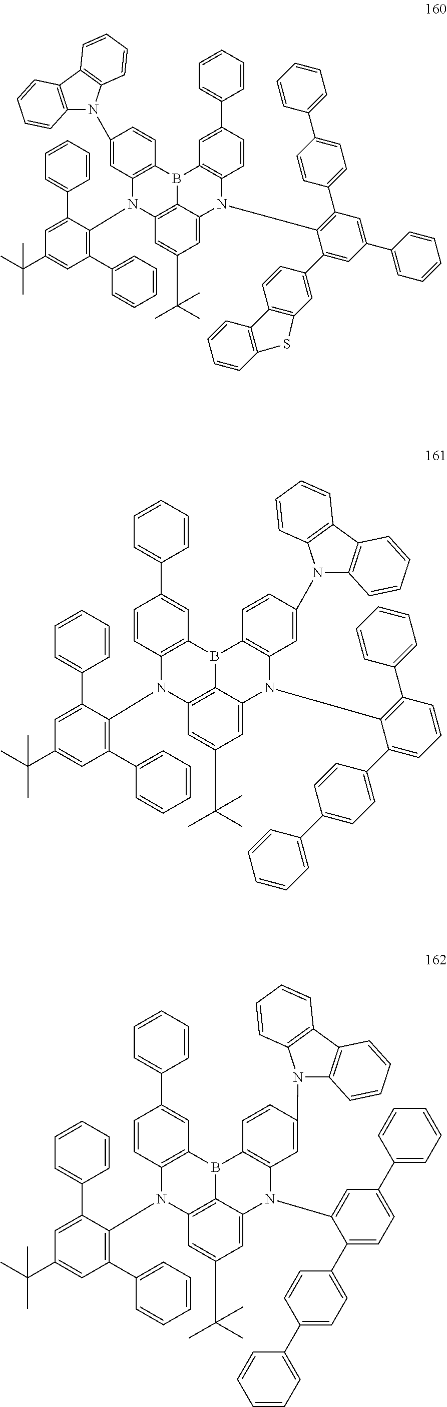 [SMILES: CC(C)(C)c1cc(-c2ccccc2)c(N2c3cc(-n4c5ccccc5c5ccccc54)ccc3B3c4cc(-c5ccccc5)ccc4N(c4c(-c5ccc(-c6ccccc6)cc5)cc(-c5ccccc5)cc4-c4ccc5c(c4)sc4ccccc45)c4cc(C(C)(C)C)cc2c43)c(-c2ccccc2)c1 ; CC(C)(C)c1cc(-c2ccccc2)c(N2c3ccc(-c4ccccc4)cc3B3c4ccc(-n5c6ccccc6c6ccccc65)cc4N(c4c(-c5ccccc5)cccc4-c4ccc(-c5ccccc5)cc4)c4cc(C(C)(C)C)cc2c43)c(-c2ccccc2)c1 ; CC(C)(C)c1cc(-c2ccccc2)c(N2c3ccc(-c4ccccc4)cc3B3c4ccc(-n5c6ccccc6c6ccccc65)cc4N(c4cc(-c5ccccc5)ccc4-c4ccc(-c5ccccc5)cc4)c4cc(C(C)(C)C)cc2c43)c(-c2ccccc2)c1] 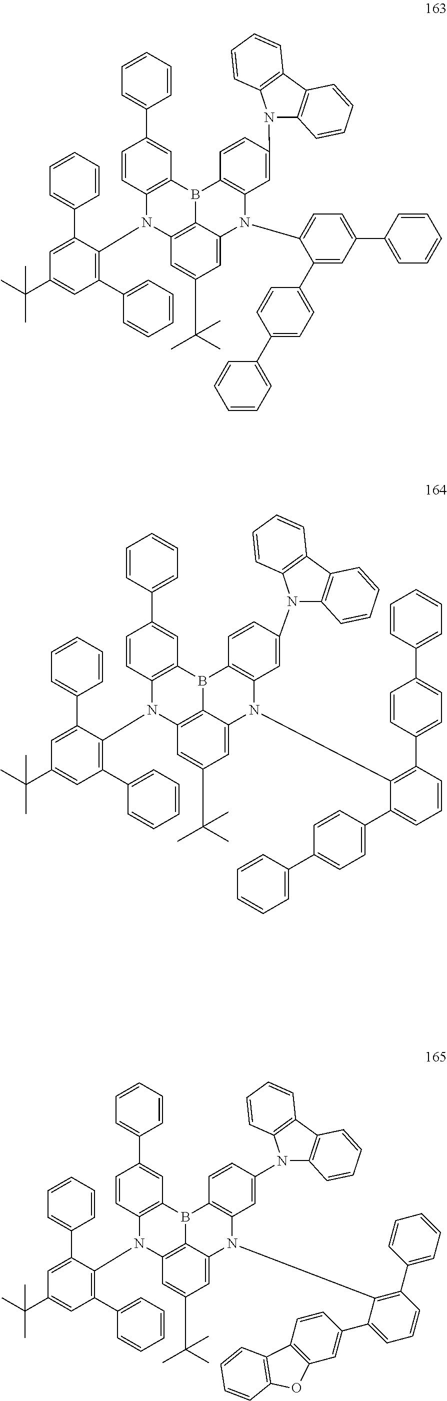 [SMILES: CC(C)(C)c1cc(-c2ccccc2)c(N2c3ccc(-c4ccccc4)cc3B3c4ccc(-n5c6ccccc6c6ccccc65)cc4N(c4ccc(-c5ccccc5)cc4-c4ccc(-c5ccccc5)cc4)c4cc(C(C)(C)C)cc2c43)c(-c2ccccc2)c1 ; CC(C)(C)c1cc(-c2ccccc2)c(N2c3ccc(-c4ccccc4)cc3B3c4ccc(-n5c6ccccc6c6ccccc65)cc4N(c4c(-c5ccc(-c6ccccc6)cc5)cccc4-c4ccc(-c5ccccc5)cc4)c4cc(C(C)(C)C)cc2c43)c(-c2ccccc2)c1 ; CC(C)(C)c1cc(-c2ccccc2)c(N2c3ccc(-c4ccccc4)cc3B3c4ccc(-n5c6ccccc6c6ccccc65)cc4N(c4c(-c5ccccc5)cccc4-c4ccc5c(c4)oc4ccccc45)c4cc(C(C)(C)C)cc2c43)c(-c2ccccc2)c1] 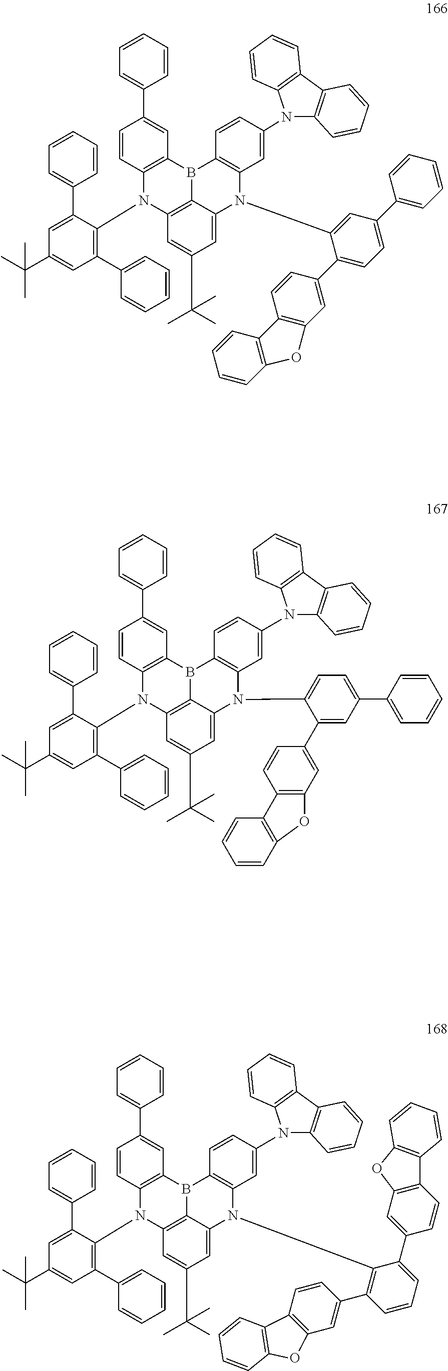 [SMILES: CC(C)(C)c1cc(-c2ccccc2)c(N2c3ccc(-c4ccccc4)cc3B3c4ccc(-n5c6ccccc6c6ccccc65)cc4N(c4cc(-c5ccccc5)ccc4-c4ccc5c(c4)oc4ccccc45)c4cc(C(C)(C)C)cc2c43)c(-c2ccccc2)c1 ; CC(C)(C)c1cc(-c2ccccc2)c(N2c3ccc(-c4ccccc4)cc3B3c4ccc(-n5c6ccccc6c6ccccc65)cc4N(c4ccc(-c5ccccc5)cc4-c4ccc5c(c4)oc4ccccc45)c4cc(C(C)(C)C)cc2c43)c(-c2ccccc2)c1 ; CC(C)(C)c1cc(-c2ccccc2)c(N2c3ccc(-c4ccccc4)cc3B3c4ccc(-n5c6ccccc6c6ccccc65)cc4N(c4c(-c5ccc6c(c5)oc5ccccc56)cccc4-c4ccc5c(c4)oc4ccccc45)c4cc(C(C)(C)C)cc2c43)c(-c2ccccc2)c1] 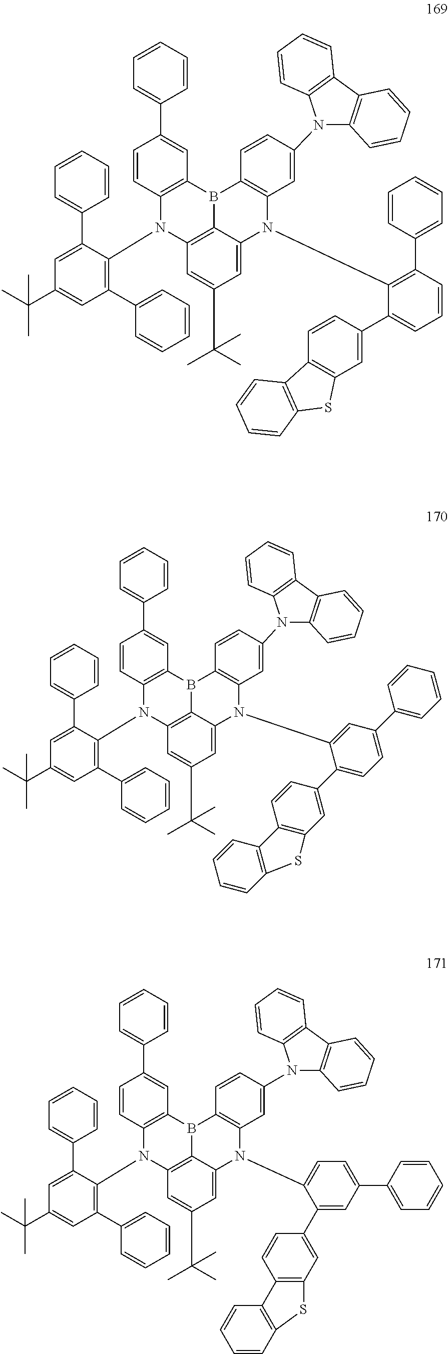 [SMILES: CC(C)(C)c1cc(-c2ccccc2)c(N2c3ccc(-c4ccccc4)cc3B3c4ccc(-n5c6ccccc6c6ccccc65)cc4N(c4c(-c5ccccc5)cccc4-c4ccc5c(c4)sc4ccccc45)c4cc(C(C)(C)C)cc2c43)c(-c2ccccc2)c1 ; CC(C)(C)c1cc(-c2ccccc2)c(N2c3ccc(-c4ccccc4)cc3B3c4ccc(-n5c6ccccc6c6ccccc65)cc4N(c4cc(-c5ccccc5)ccc4-c4ccc5c(c4)sc4ccccc45)c4cc(C(C)(C)C)cc2c43)c(-c2ccccc2)c1 ; CC(C)(C)c1cc(-c2ccccc2)c(N2c3ccc(-c4ccccc4)cc3B3c4ccc(-n5c6ccccc6c6ccccc65)cc4N(c4ccc(-c5ccccc5)cc4-c4ccc5c(c4)sc4ccccc45)c4cc(C(C)(C)C)cc2c43)c(-c2ccccc2)c1] 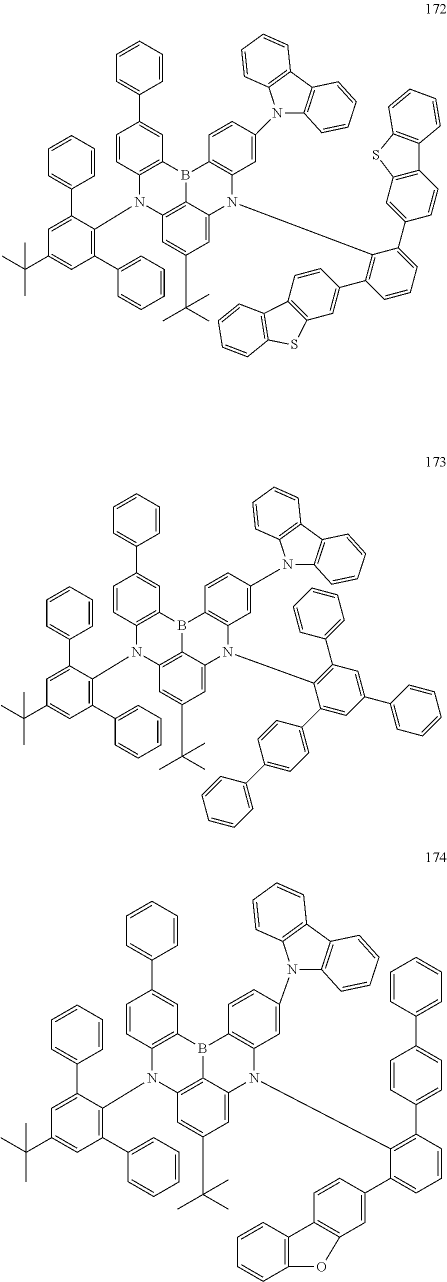 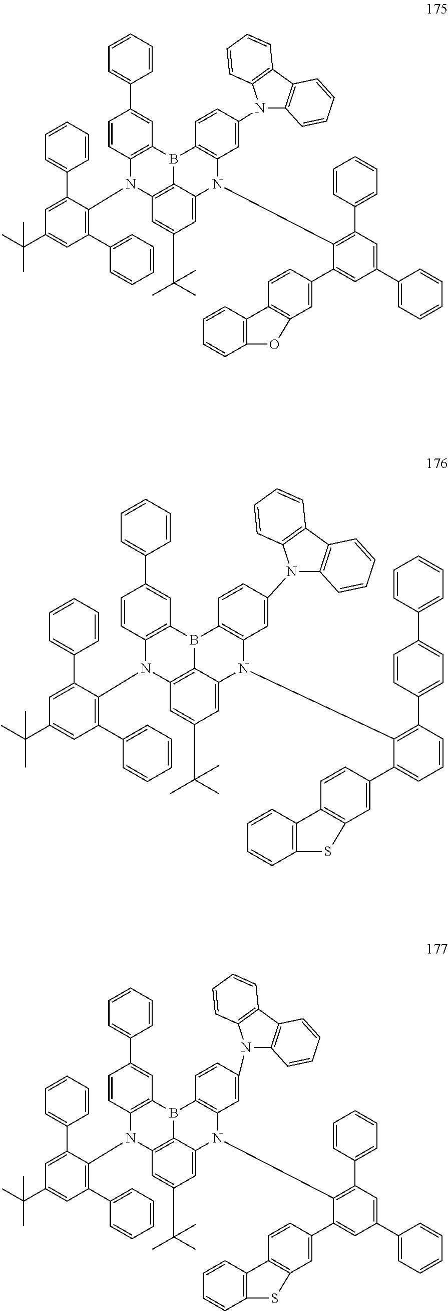 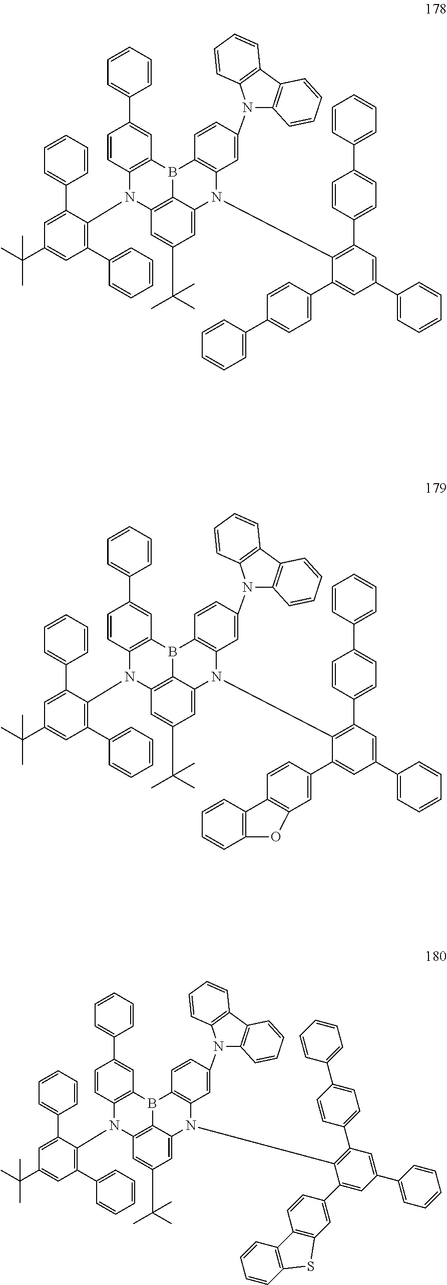 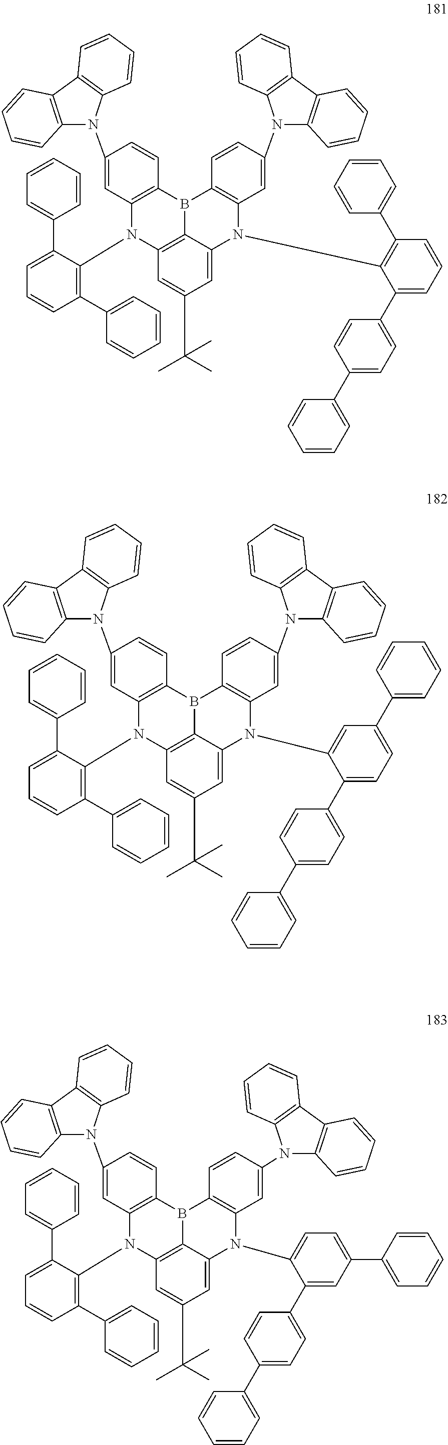 [SMILES: CC(C)(C)c1cc2c3c(c1)N(c1c(-c4ccccc4)cccc1-c1ccc(-c4ccccc4)cc1)c1cc(-n4c5ccccc5c5ccccc54)ccc1B3c1ccc(-n3c4ccccc4c4ccccc43)cc1N2c1c(-c2ccccc2)cccc1-c1ccccc1 ; CC(C)(C)c1cc2c3c(c1)N(c1c(-c4ccccc4)cccc1-c1ccccc1)c1cc(-n4c5ccccc5c5ccccc54)ccc1B3c1ccc(-n3c4ccccc4c4ccccc43)cc1N2c1cc(-c2ccccc2)ccc1-c1ccc(-c2ccccc2)cc1 ; CC(C)(C)c1cc2c3c(c1)N(c1c(-c4ccccc4)cccc1-c1ccccc1)c1cc(-n4c5ccccc5c5ccccc54)ccc1B3c1ccc(-n3c4ccccc4c4ccccc43)cc1N2c1ccc(-c2ccccc2)cc1-c1ccc(-c2ccccc2)cc1] 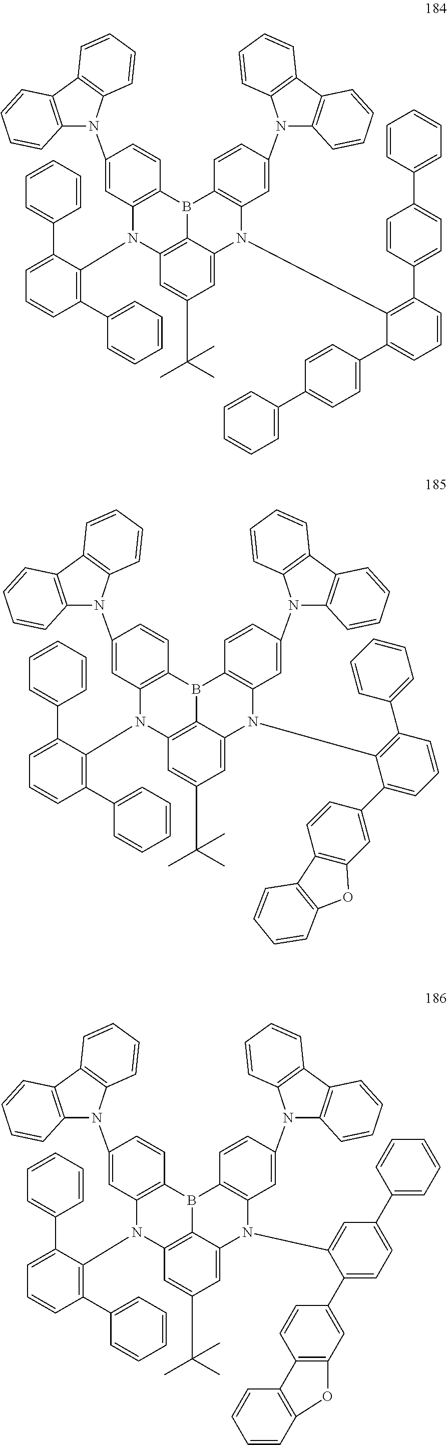 [SMILES: CC(C)(C)c1cc2c3c(c1)N(c1c(-c4ccc(-c5ccccc5)cc4)cccc1-c1ccc(-c4ccccc4)cc1)c1cc(-n4c5ccccc5c5ccccc54)ccc1B3c1ccc(-n3c4ccccc4c4ccccc43)cc1N2c1c(-c2ccccc2)cccc1-c1ccccc1 ; CC(C)(C)c1cc2c3c(c1)N(c1c(-c4ccccc4)cccc1-c1ccc4c(c1)oc1ccccc14)c1cc(-n4c5ccccc5c5ccccc54)ccc1B3c1ccc(-n3c4ccccc4c4ccccc43)cc1N2c1c(-c2ccccc2)cccc1-c1ccccc1 ; CC(C)(C)c1cc2c3c(c1)N(c1c(-c4ccccc4)cccc1-c1ccccc1)c1cc(-n4c5ccccc5c5ccccc54)ccc1B3c1ccc(-n3c4ccccc4c4ccccc43)cc1N2c1cc(-c2ccccc2)ccc1-c1ccc2c(c1)oc1ccccc12] 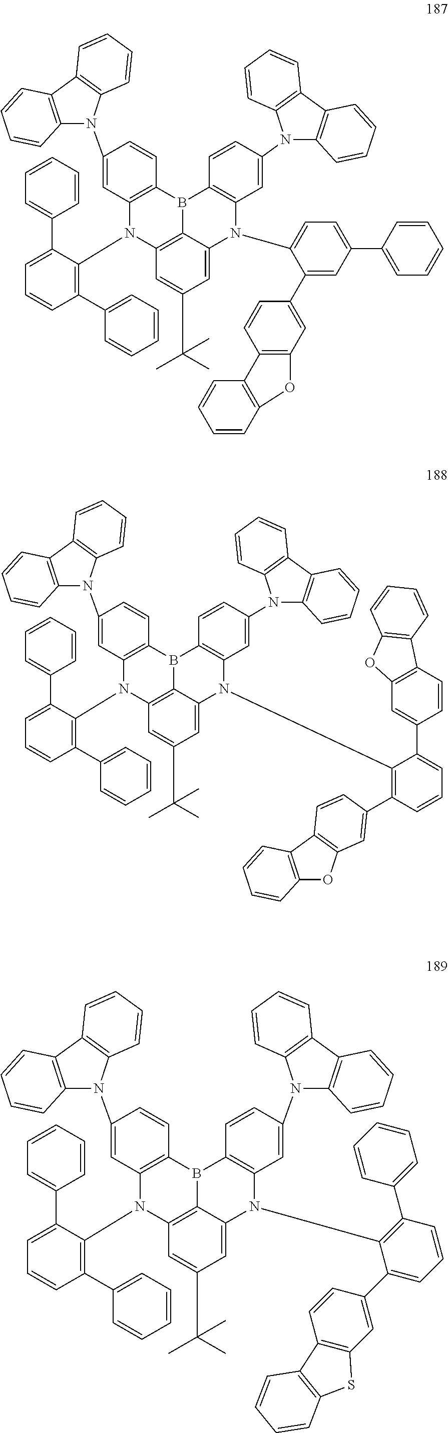 [SMILES: CC(C)(C)c1cc2c3c(c1)N(c1c(-c4ccccc4)cccc1-c1ccccc1)c1cc(-n4c5ccccc5c5ccccc54)ccc1B3c1ccc(-n3c4ccccc4c4ccccc43)cc1N2c1ccc(-c2ccccc2)cc1-c1ccc2c(c1)oc1ccccc12 ; CC(C)(C)c1cc2c3c(c1)N(c1c(-c4ccc5c(c4)oc4ccccc45)cccc1-c1ccc4c(c1)oc1ccccc14)c1cc(-n4c5ccccc5c5ccccc54)ccc1B3c1ccc(-n3c4ccccc4c4ccccc43)cc1N2c1c(-c2ccccc2)cccc1-c1ccccc1 ; CC(C)(C)c1cc2c3c(c1)N(c1c(-c4ccccc4)cccc1-c1ccc4c(c1)sc1ccccc14)c1cc(-n4c5ccccc5c5ccccc54)ccc1B3c1ccc(-n3c4ccccc4c4ccccc43)cc1N2c1c(-c2ccccc2)cccc1-c1ccccc1] 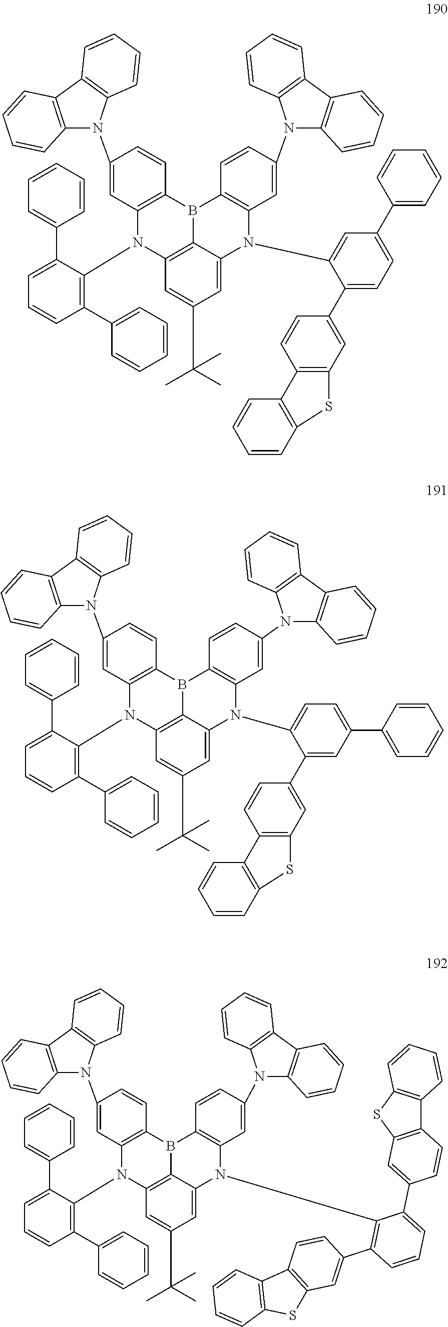 [SMILES: CC(C)(C)c1cc2c3c(c1)N(c1c(-c4ccccc4)cccc1-c1ccccc1)c1cc(-n4c5ccccc5c5ccccc54)ccc1B3c1ccc(-n3c4ccccc4c4ccccc43)cc1N2c1cc(-c2ccccc2)ccc1-c1ccc2c(c1)sc1ccccc12 ; CC(C)(C)c1cc2c3c(c1)N(c1c(-c4ccccc4)cccc1-c1ccccc1)c1cc(-n4c5ccccc5c5ccccc54)ccc1B3c1ccc(-n3c4ccccc4c4ccccc43)cc1N2c1ccc(-c2ccccc2)cc1-c1ccc2c(c1)sc1ccccc12 ; CC(C)(C)c1cc2c3c(c1)N(c1c(-c4ccc5c(c4)sc4ccccc45)cccc1-c1ccc4c(c1)sc1ccccc14)c1cc(-n4c5ccccc5c5ccccc54)ccc1B3c1ccc(-n3c4ccccc4c4ccccc43)cc1N2c1c(-c2ccccc2)cccc1-c1ccccc1] 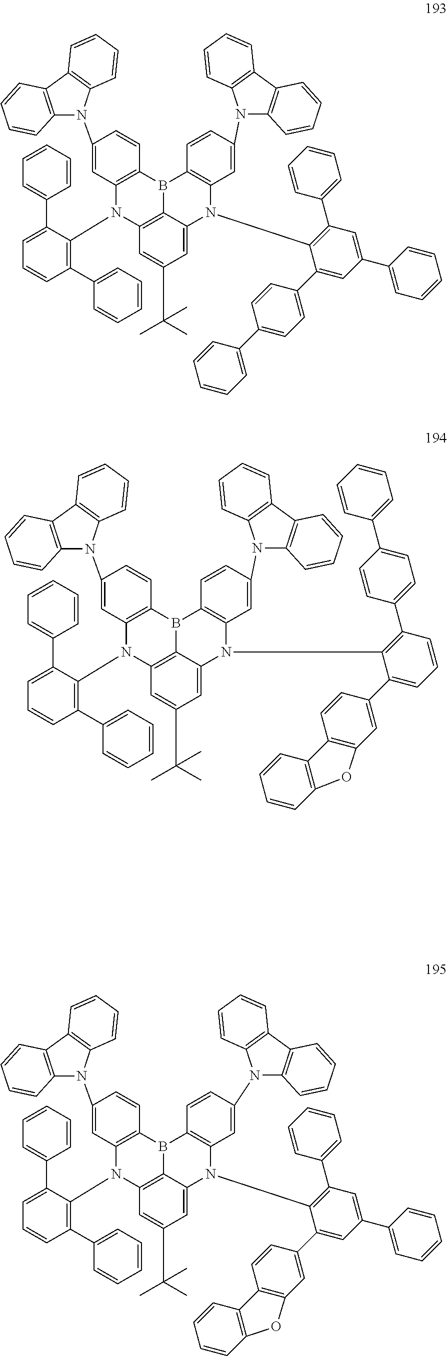 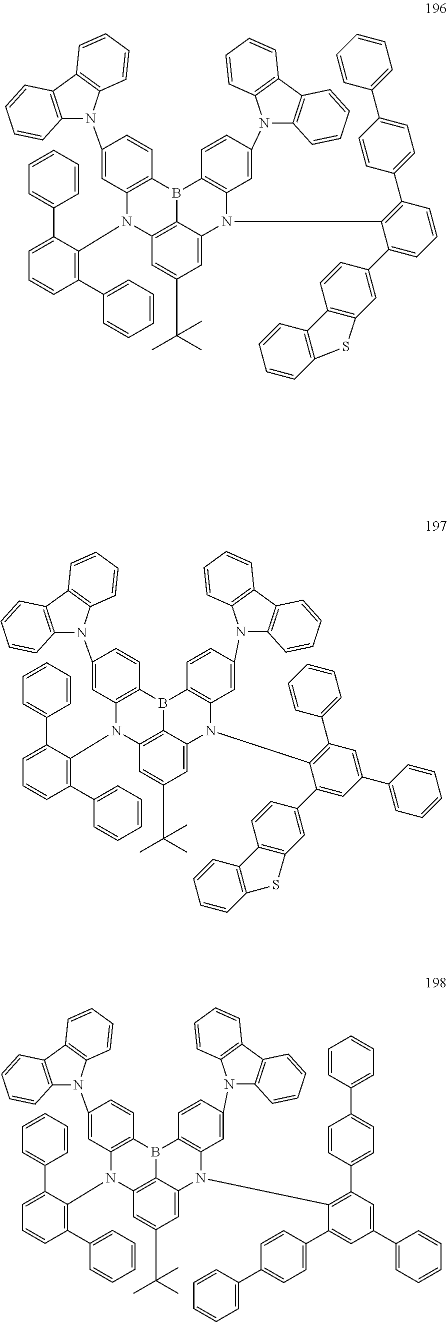 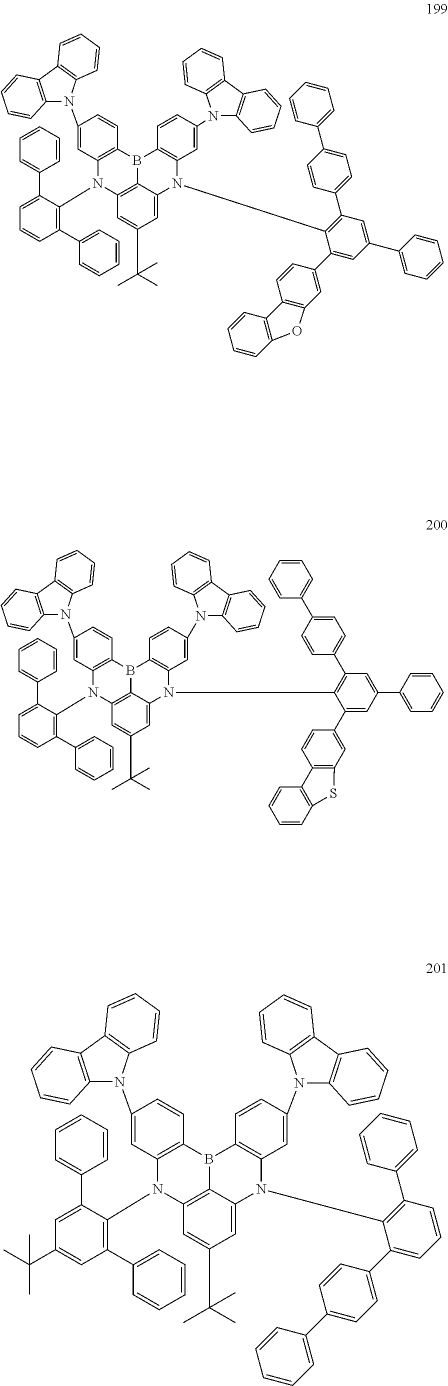 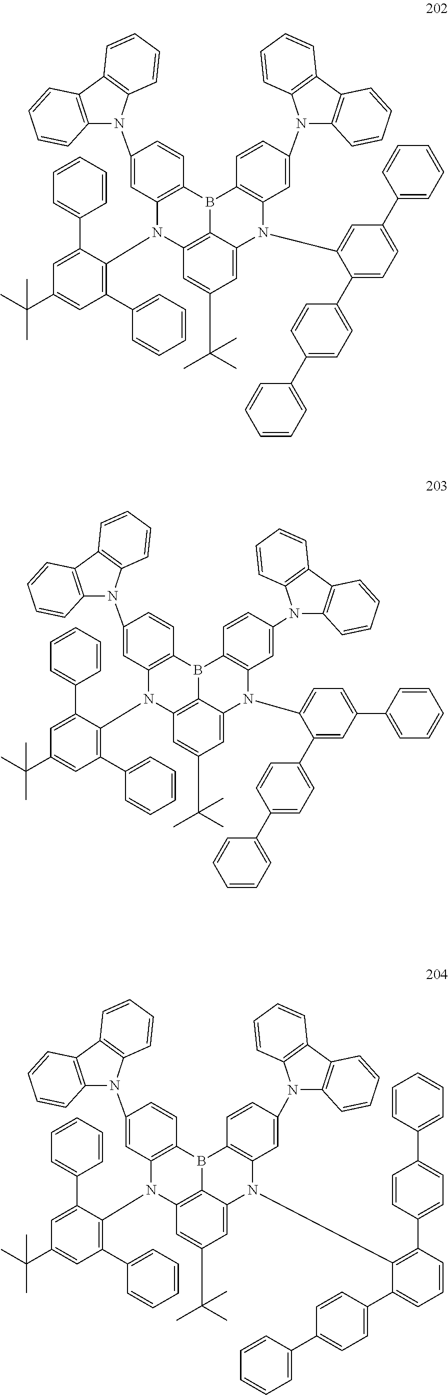 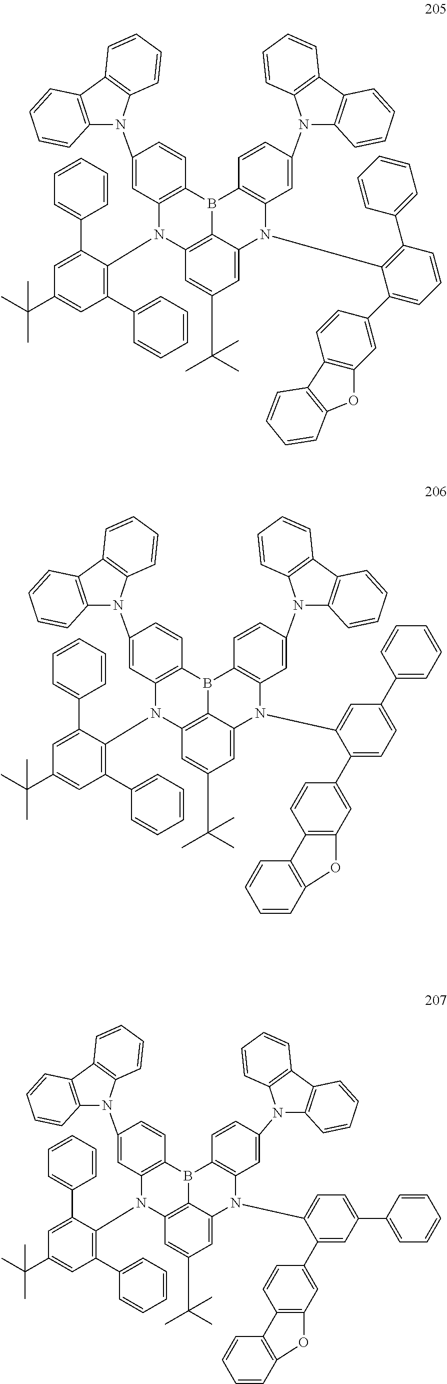 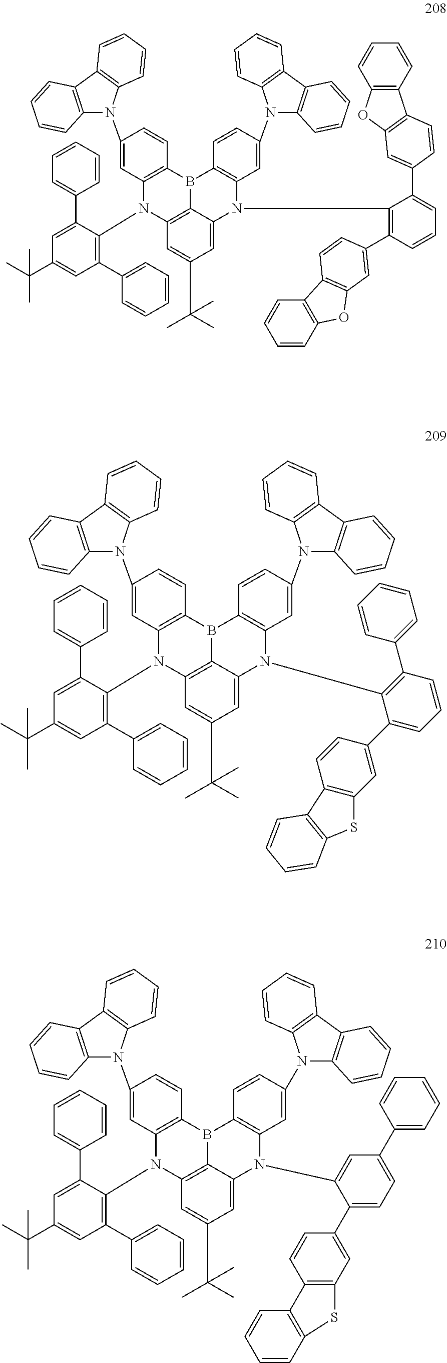 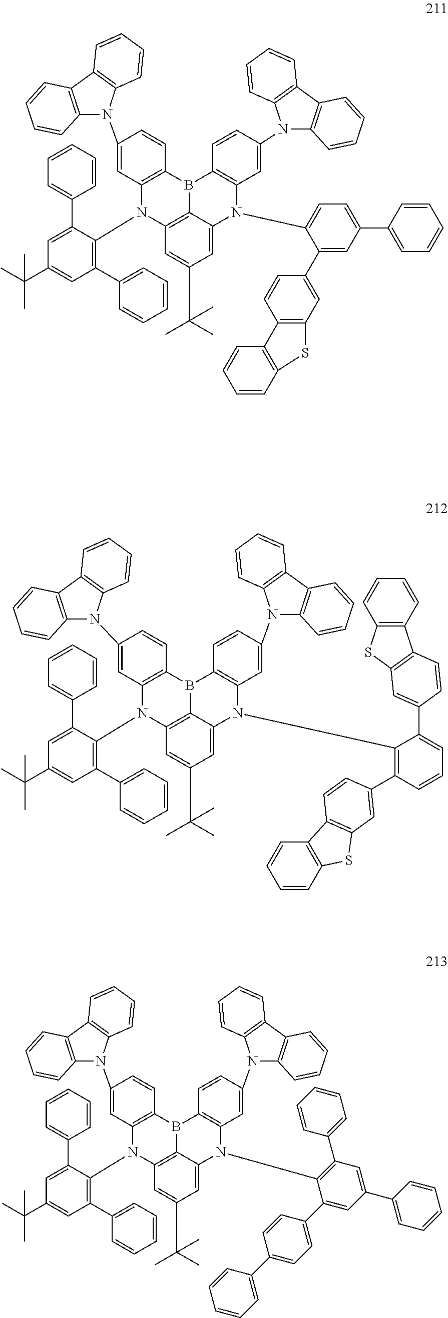 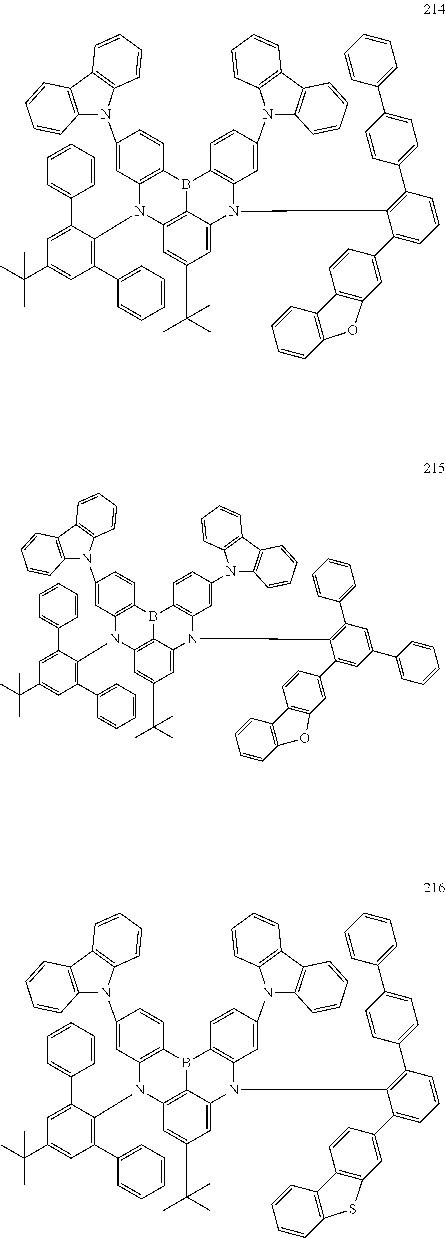 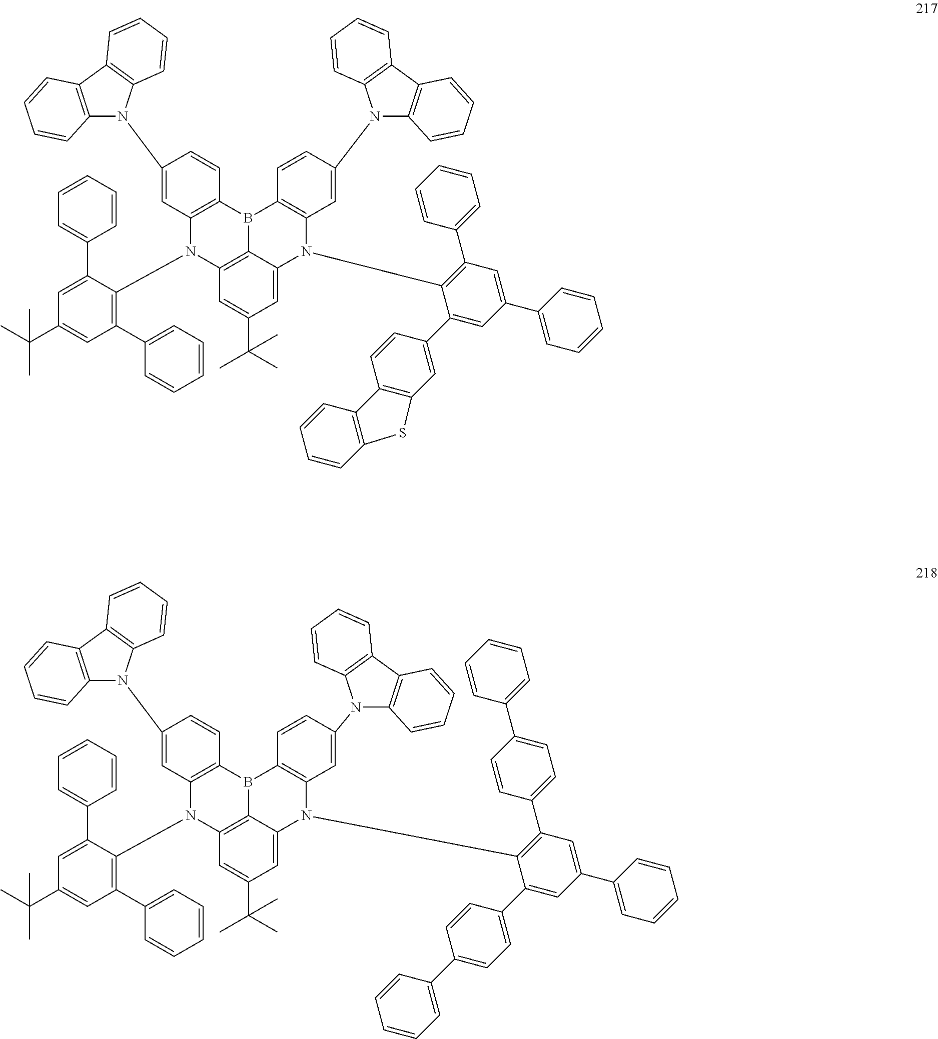 [SMILES: CC(C)(C)c1cc(-c2ccccc2)c(N2c3cc(-n4c5ccccc5c5ccccc54)ccc3B3c4ccc(-n5c6ccccc6c6ccccc65)cc4N(c4c(-c5ccccc5)cc(-c5ccccc5)cc4-c4ccc5c(c4)sc4ccccc45)c4cc(C(C)(C)C)cc2c43)c(-c2ccccc2)c1 ; CC(C)(C)c1cc(-c2ccccc2)c(N2c3cc(-n4c5ccccc5c5ccccc54)ccc3B3c4ccc(-n5c6ccccc6c6ccccc65)cc4N(c4c(-c5ccc(-c6ccccc6)cc5)cc(-c5ccccc5)cc4-c4ccc(-c5ccccc5)cc4)c4cc(C(C)(C)C)cc2c43)c(-c2ccccc2)c1] 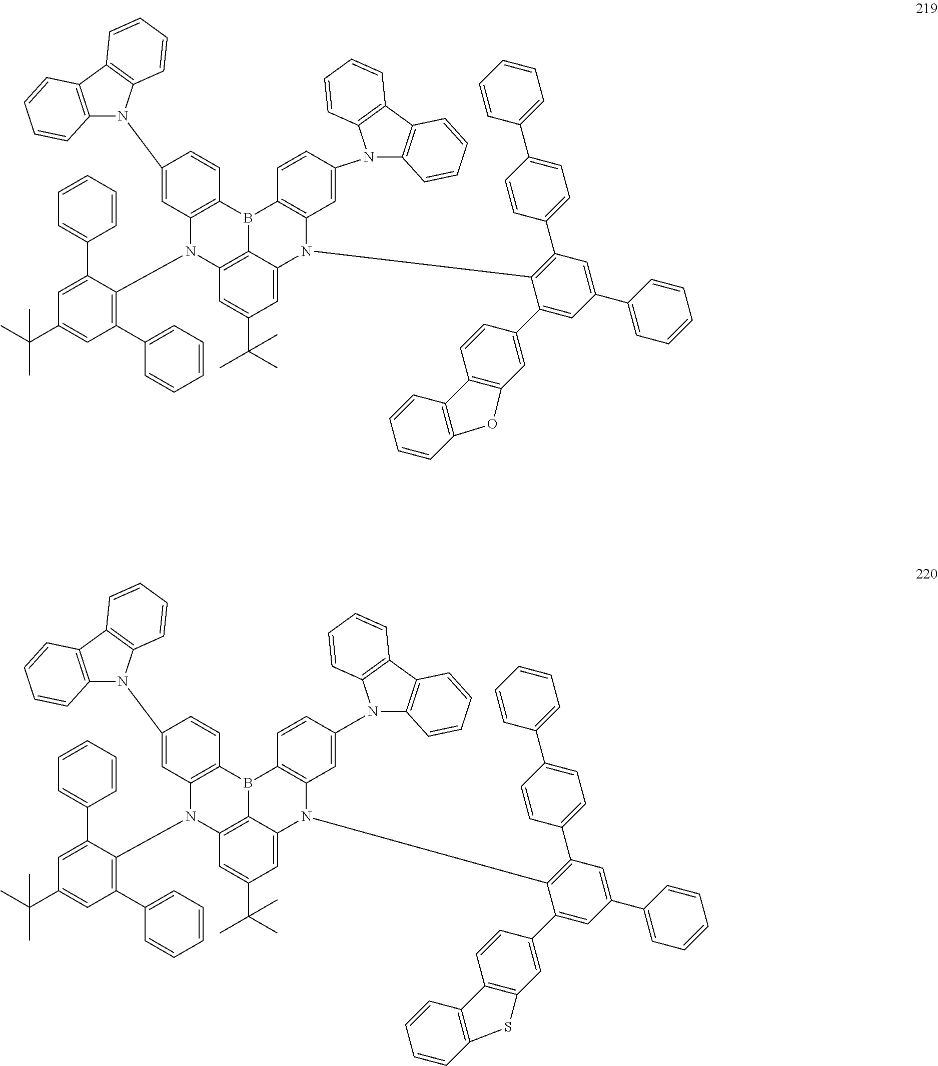 [SMILES: CC(C)(C)c1cc(-c2ccccc2)c(N2c3cc(-n4c5ccccc5c5ccccc54)ccc3B3c4ccc(-n5c6ccccc6c6ccccc65)cc4N(c4c(-c5ccc(-c6ccccc6)cc5)cc(-c5ccccc5)cc4-c4ccc5c(c4)oc4ccccc45)c4cc(C(C)(C)C)cc2c43)c(-c2ccccc2)c1 ; CC(C)(C)c1cc(-c2ccccc2)c(N2c3cc(-n4c5ccccc5c5ccccc54)ccc3B3c4ccc(-n5c6ccccc6c6ccccc65)cc4N(c4c(-c5ccc(-c6ccccc6)cc5)cc(-c5ccccc5)cc4-c4ccc5c(c4)sc4ccccc45)c4cc(C(C)(C)C)cc2c43)c(-c2ccccc2)c1] 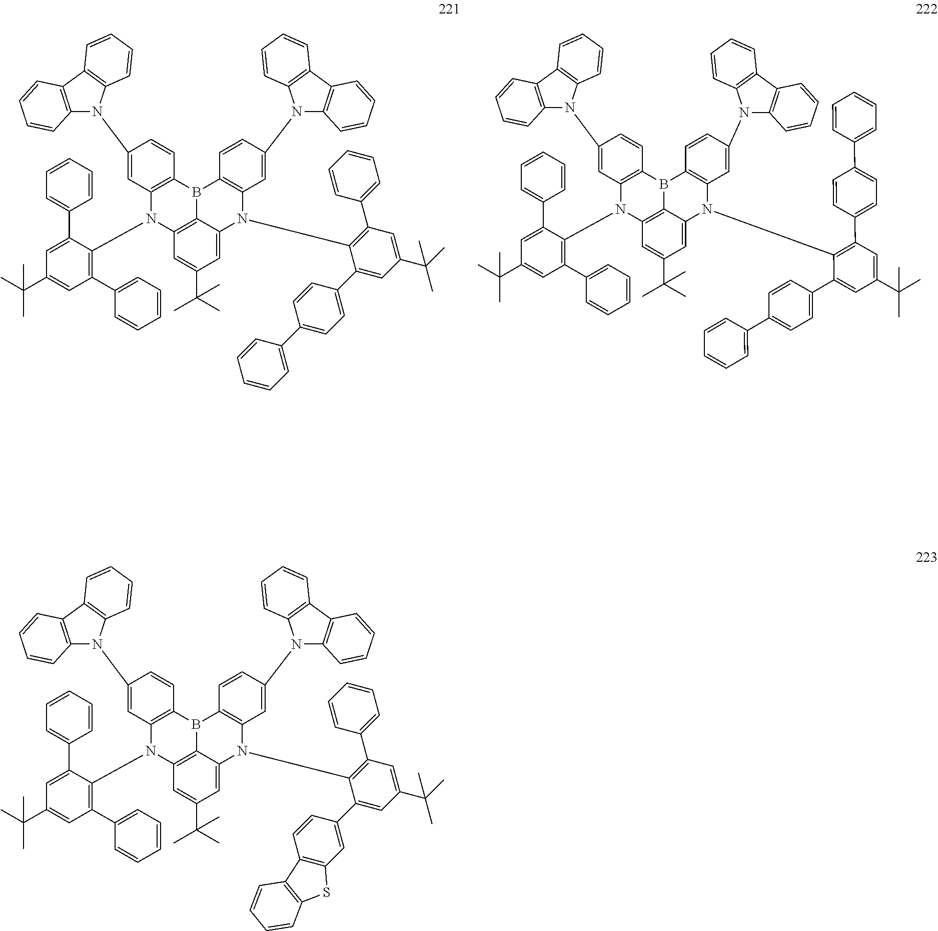 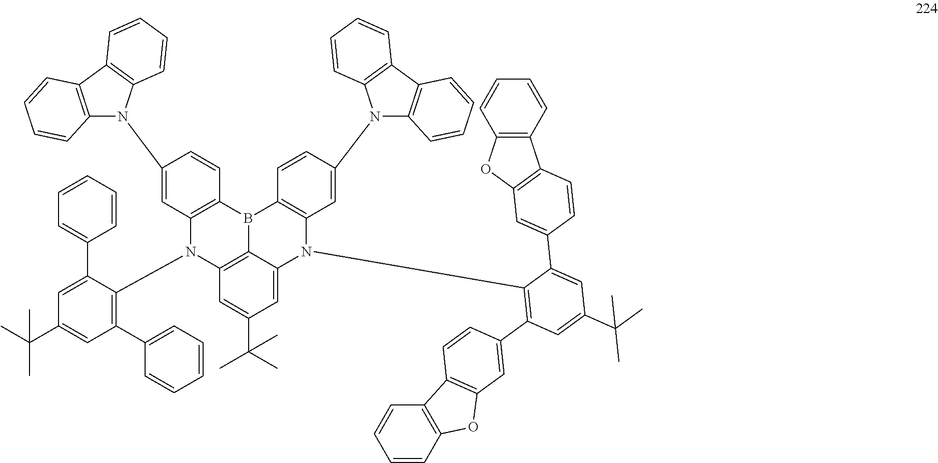 [SMILES: CC(C)(C)c1cc(-c2ccccc2)c(N2c3cc(-n4c5ccccc5c5ccccc54)ccc3B3c4ccc(-n5c6ccccc6c6ccccc65)cc4N(c4c(-c5ccc6c(c5)oc5ccccc56)cc(C(C)(C)C)cc4-c4ccc5c(c4)oc4ccccc45)c4cc(C(C)(C)C)cc2c43)c(-c2ccccc2)c1] 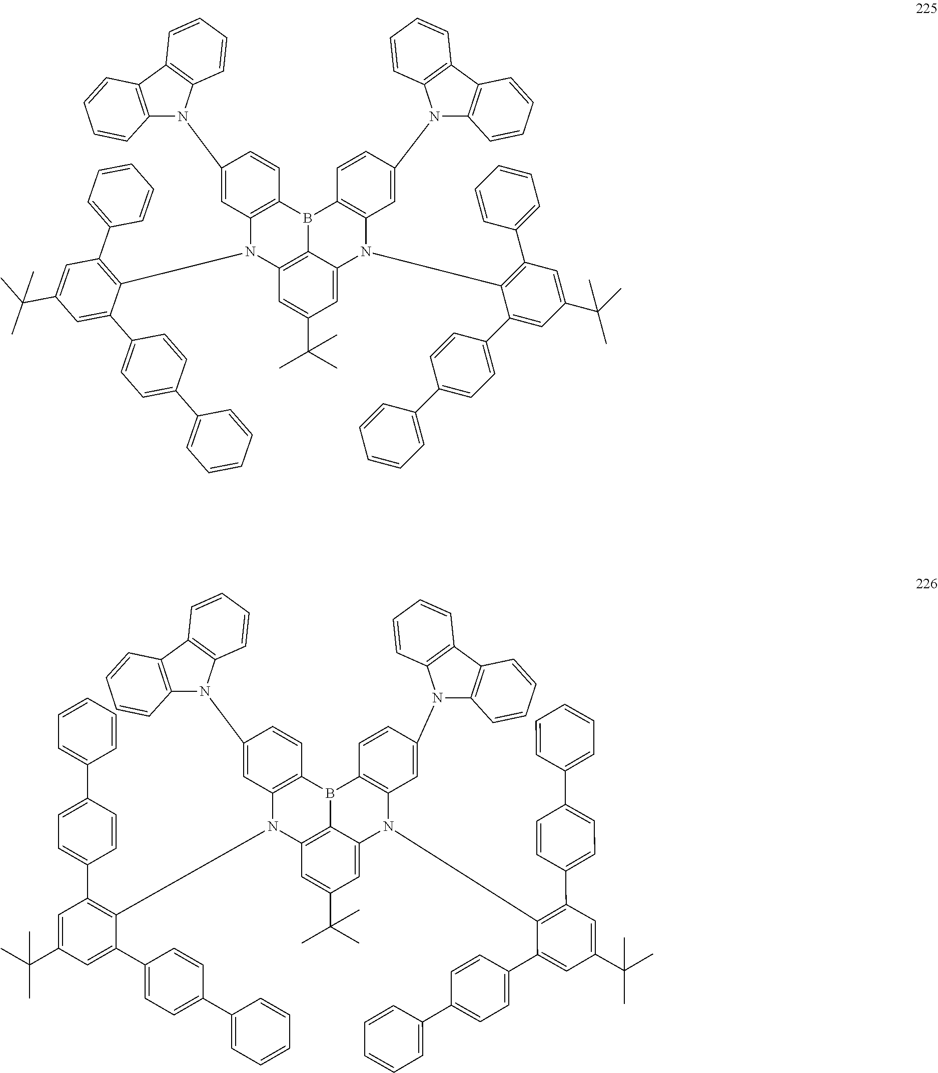 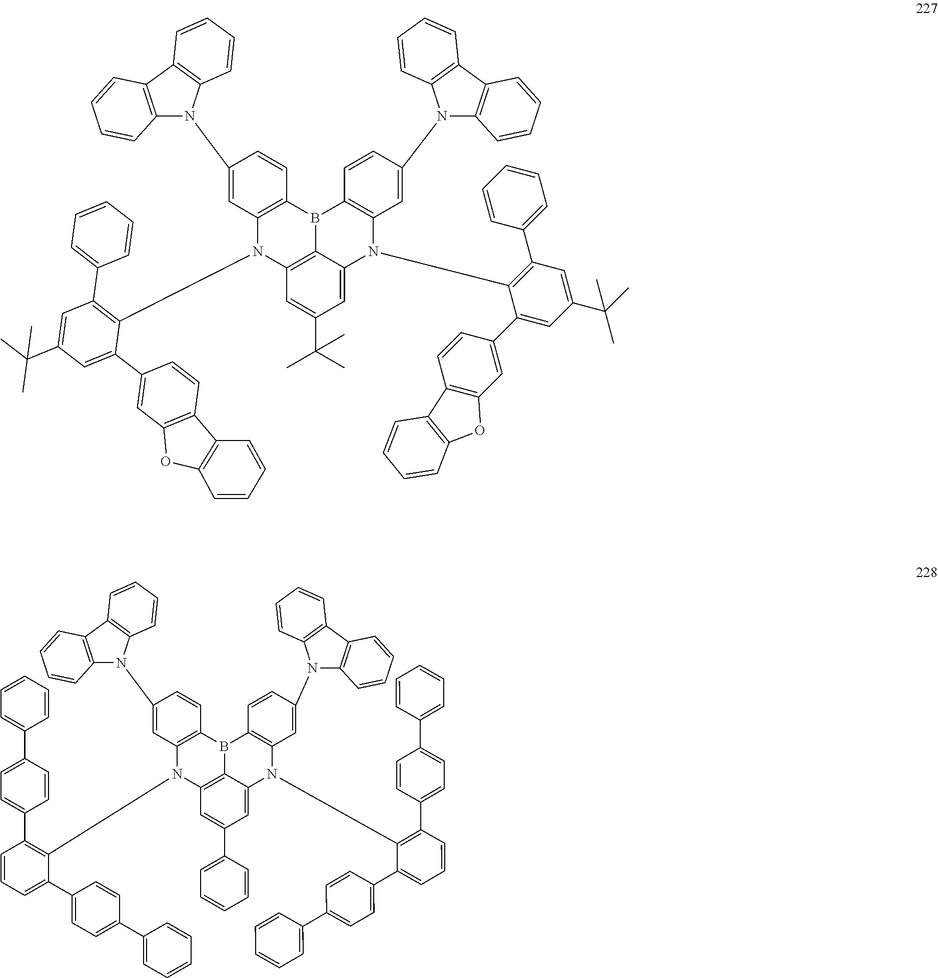 [SMILES: CC(C)(C)c1cc(-c2ccccc2)c(N2c3cc(-n4c5ccccc5c5ccccc54)ccc3B3c4ccc(-n5c6ccccc6c6ccccc65)cc4N(c4c(-c5ccccc5)cc(C(C)(C)C)cc4-c4ccc5c(c4)oc4ccccc45)c4cc(C(C)(C)C)cc2c43)c(-c2ccc3c(c2)oc2ccccc23)c1 ; c1ccc(-c2ccc(-c3cccc(-c4ccc(-c5ccccc5)cc4)c3N3c4cc(-n5c6ccccc6c6ccccc65)ccc4B4c5ccc(-n6c7ccccc7c7ccccc76)cc5N(c5c(-c6ccc(-c7ccccc7)cc6)cccc5-c5ccc(-c6ccccc6)cc5)c5cc(-c6ccccc6)cc3c54)cc2)cc1] 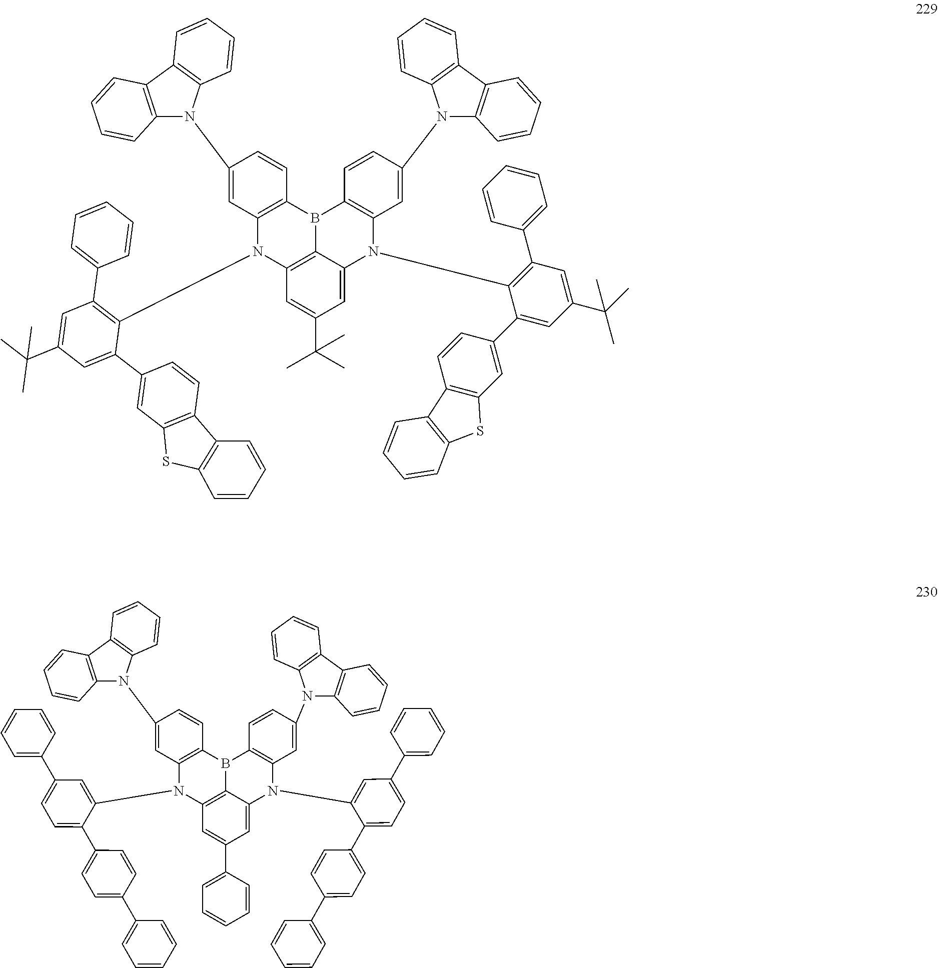 [SMILES: CC(C)(C)c1cc(-c2ccccc2)c(N2c3cc(-n4c5ccccc5c5ccccc54)ccc3B3c4ccc(-n5c6ccccc6c6ccccc65)cc4N(c4c(-c5ccccc5)cc(C(C)(C)C)cc4-c4ccc5c(c4)sc4ccccc45)c4cc(C(C)(C)C)cc2c43)c(-c2ccc3c(c2)sc2ccccc23)c1 ; c1ccc(-c2ccc(-c3ccc(-c4ccccc4)cc3N3c4cc(-n5c6ccccc6c6ccccc65)ccc4B4c5ccc(-n6c7ccccc7c7ccccc76)cc5N(c5cc(-c6ccccc6)ccc5-c5ccc(-c6ccccc6)cc5)c5cc(-c6ccccc6)cc3c54)cc2)cc1] 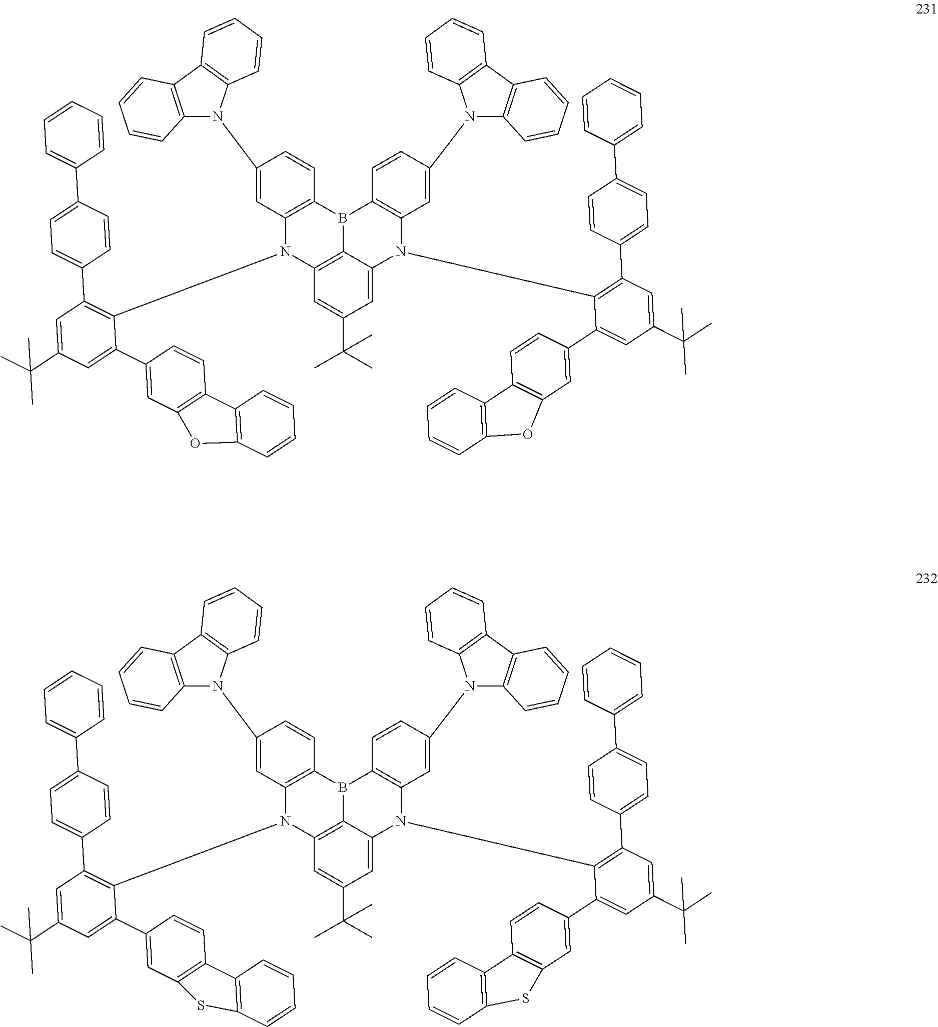 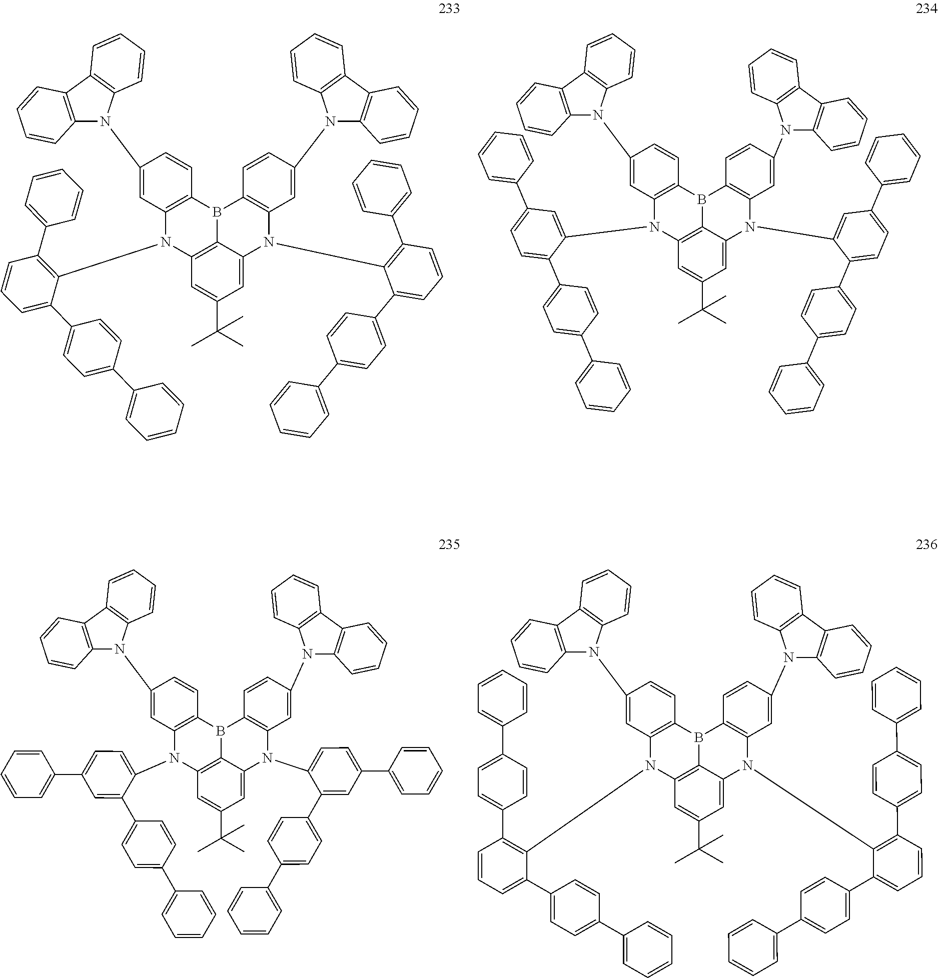 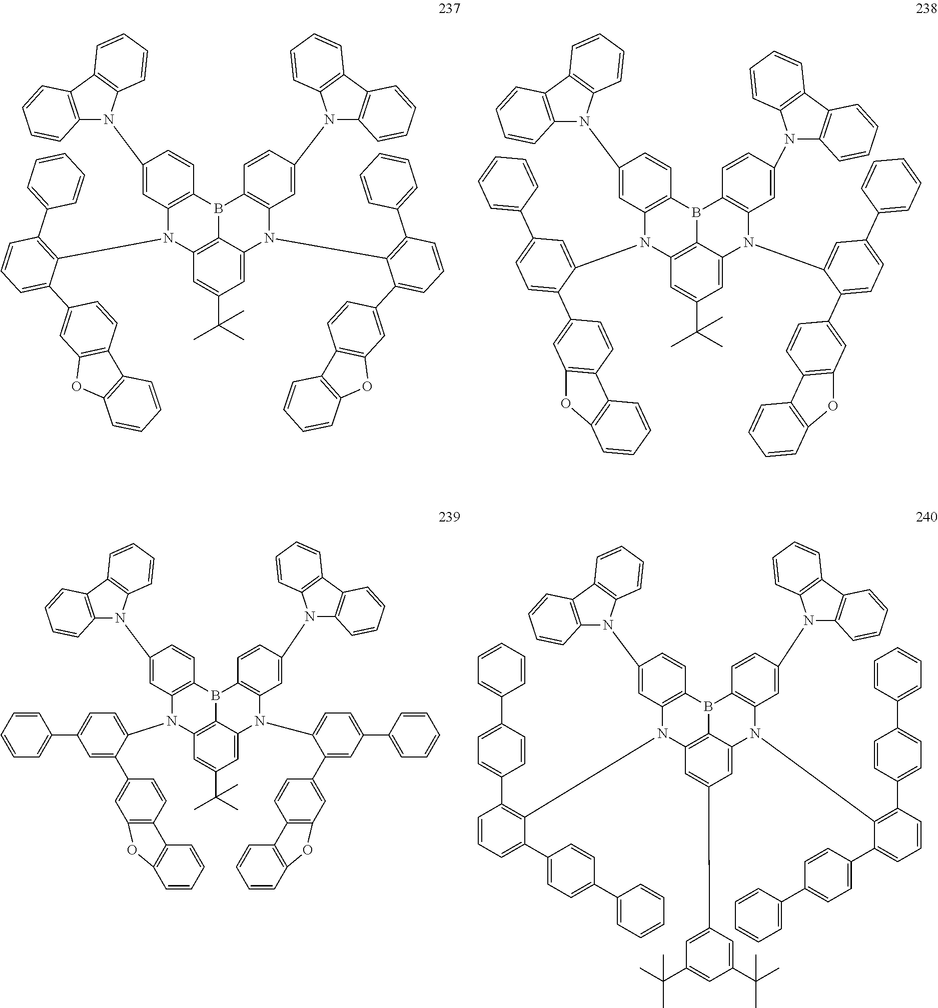 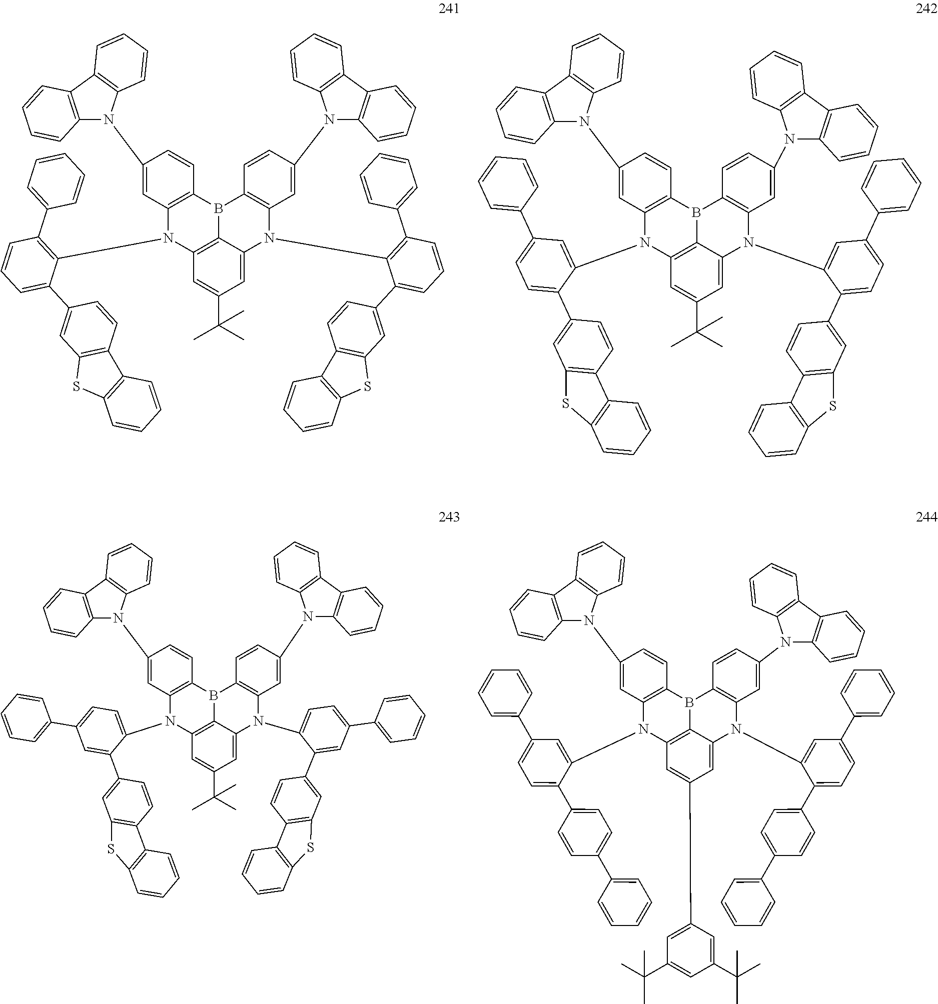 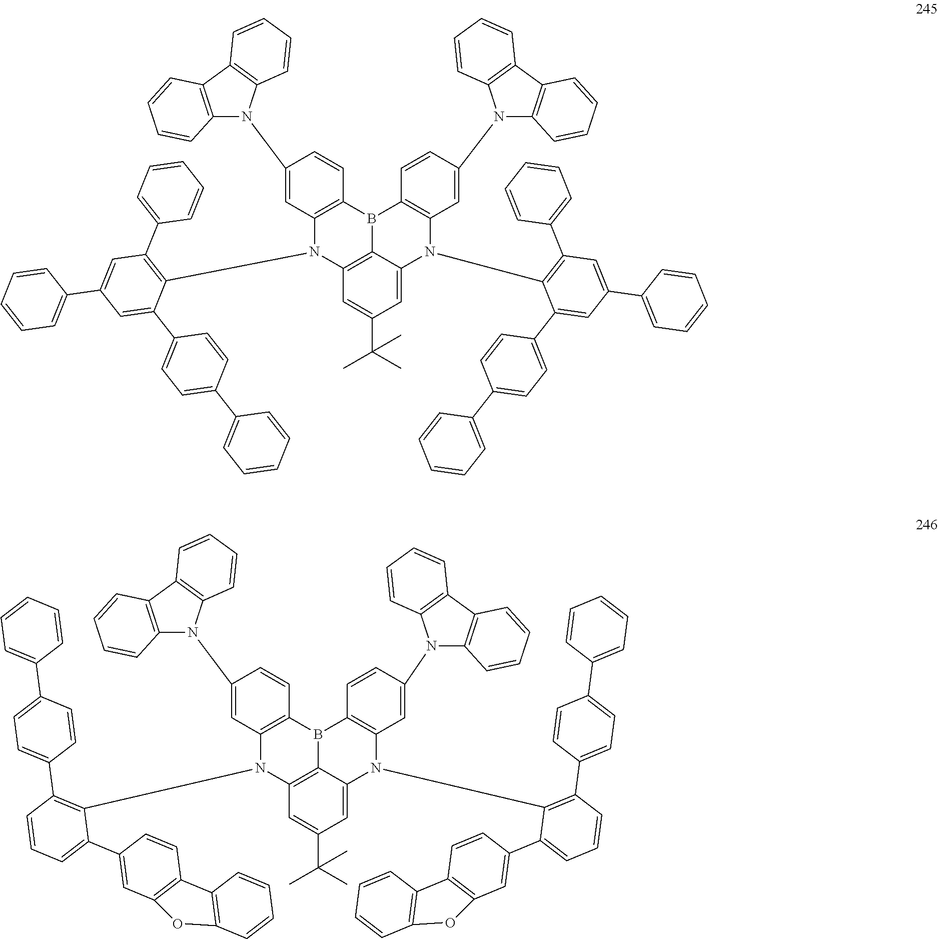 [SMILES: CC(C)(C)c1cc2c3c(c1)N(c1c(-c4ccccc4)cc(-c4ccccc4)cc1-c1ccc(-c4ccccc4)cc1)c1cc(-n4c5ccccc5c5ccccc54)ccc1B3c1ccc(-n3c4ccccc4c4ccccc43)cc1N2c1c(-c2ccccc2)cc(-c2ccccc2)cc1-c1ccc(-c2ccccc2)cc1 ; CC(C)(C)c1cc2c3c(c1)N(c1c(-c4ccc(-c5ccccc5)cc4)cccc1-c1ccc4c(c1)oc1ccccc14)c1cc(-n4c5ccccc5c5ccccc54)ccc1B3c1ccc(-n3c4ccccc4c4ccccc43)cc1N2c1c(-c2ccc(-c3ccccc3)cc2)cccc1-c1ccc2c(c1)oc1ccccc12] 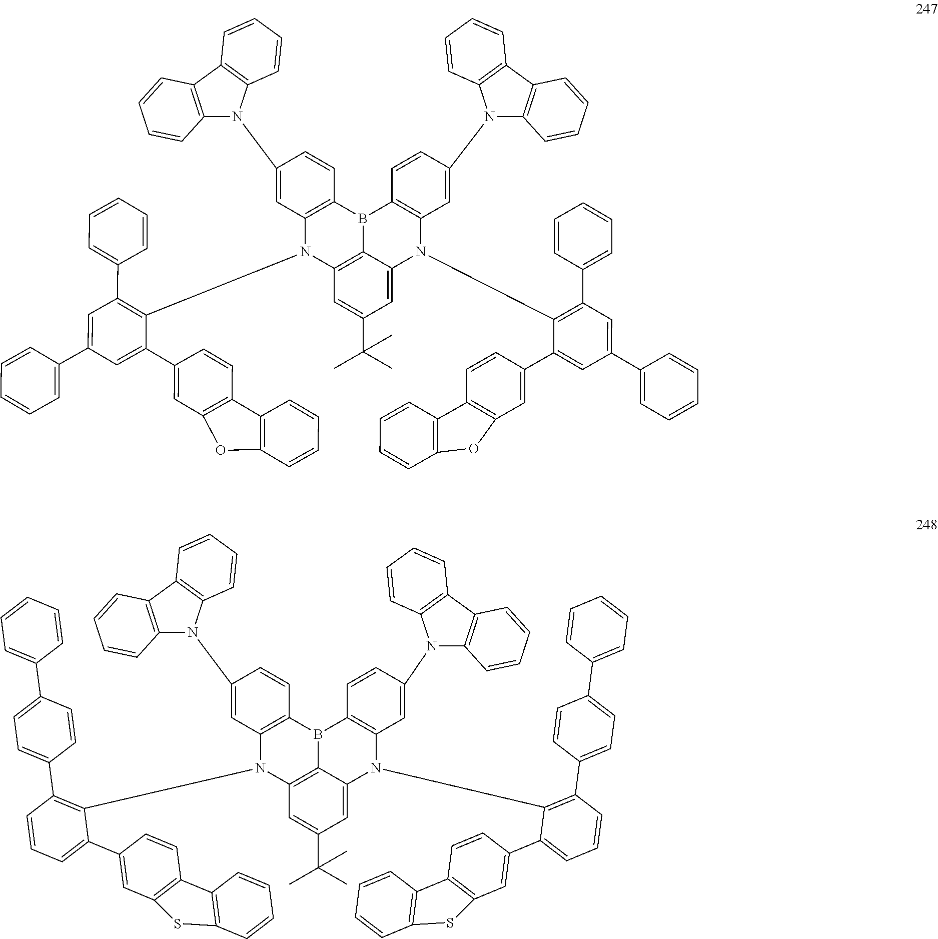 [SMILES: CC(C)(C)c1cc2c3c(c1)N(c1c(-c4ccccc4)cc(-c4ccccc4)cc1-c1ccc4c(c1)oc1ccccc14)c1cc(-n4c5ccccc5c5ccccc54)ccc1B3c1ccc(-n3c4ccccc4c4ccccc43)cc1N2c1c(-c2ccccc2)cc(-c2ccccc2)cc1-c1ccc2c(c1)oc1ccccc12 ; CC(C)(C)c1cc2c3c(c1)N(c1c(-c4ccc(-c5ccccc5)cc4)cccc1-c1ccc4c(c1)sc1ccccc14)c1cc(-n4c5ccccc5c5ccccc54)ccc1B3c1ccc(-n3c4ccccc4c4ccccc43)cc1N2c1c(-c2ccc(-c3ccccc3)cc2)cccc1-c1ccc2c(c1)sc1ccccc12] 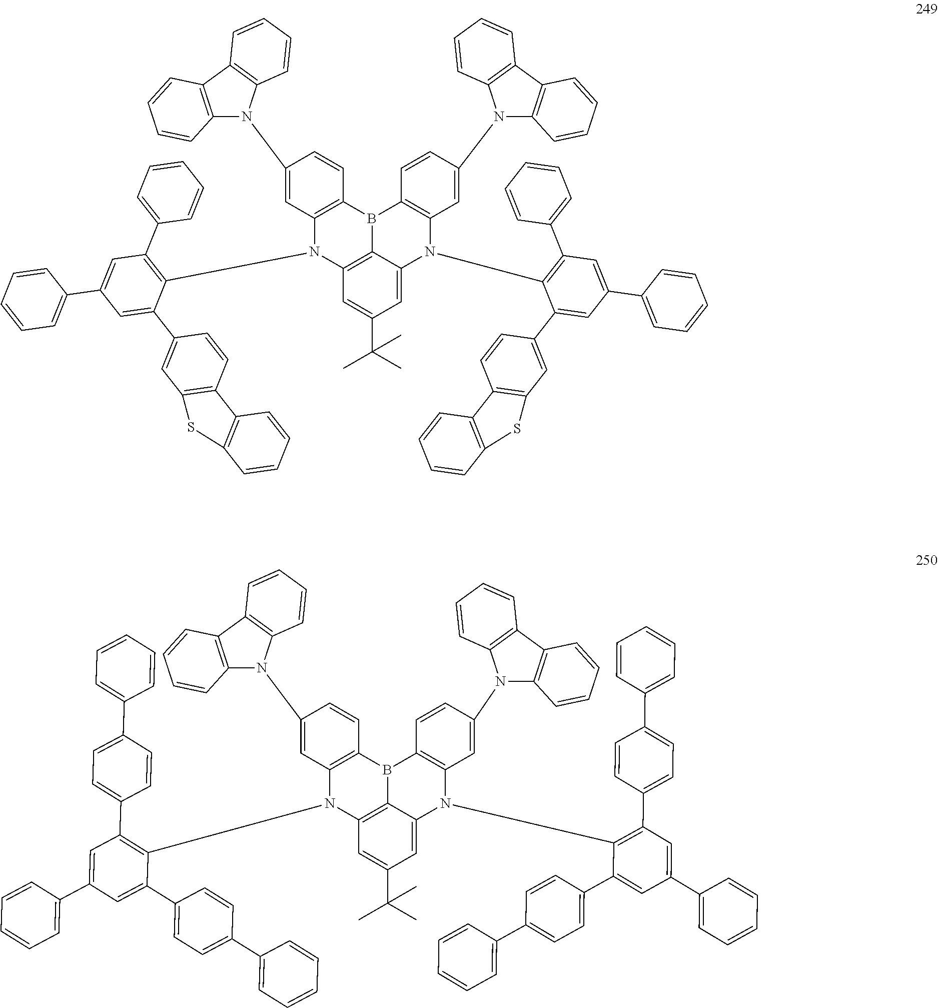 [SMILES: CC(C)(C)c1cc2c3c(c1)N(c1c(-c4ccccc4)cc(-c4ccccc4)cc1-c1ccc4c(c1)sc1ccccc14)c1cc(-n4c5ccccc5c5ccccc54)ccc1B3c1ccc(-n3c4ccccc4c4ccccc43)cc1N2c1c(-c2ccccc2)cc(-c2ccccc2)cc1-c1ccc2c(c1)sc1ccccc12 ; CC(C)(C)c1cc2c3c(c1)N(c1c(-c4ccc(-c5ccccc5)cc4)cc(-c4ccccc4)cc1-c1ccc(-c4ccccc4)cc1)c1cc(-n4c5ccccc5c5ccccc54)ccc1B3c1ccc(-n3c4ccccc4c4ccccc43)cc1N2c1c(-c2ccc(-c3ccccc3)cc2)cc(-c2ccccc2)cc1-c1ccc(-c2ccccc2)cc1] 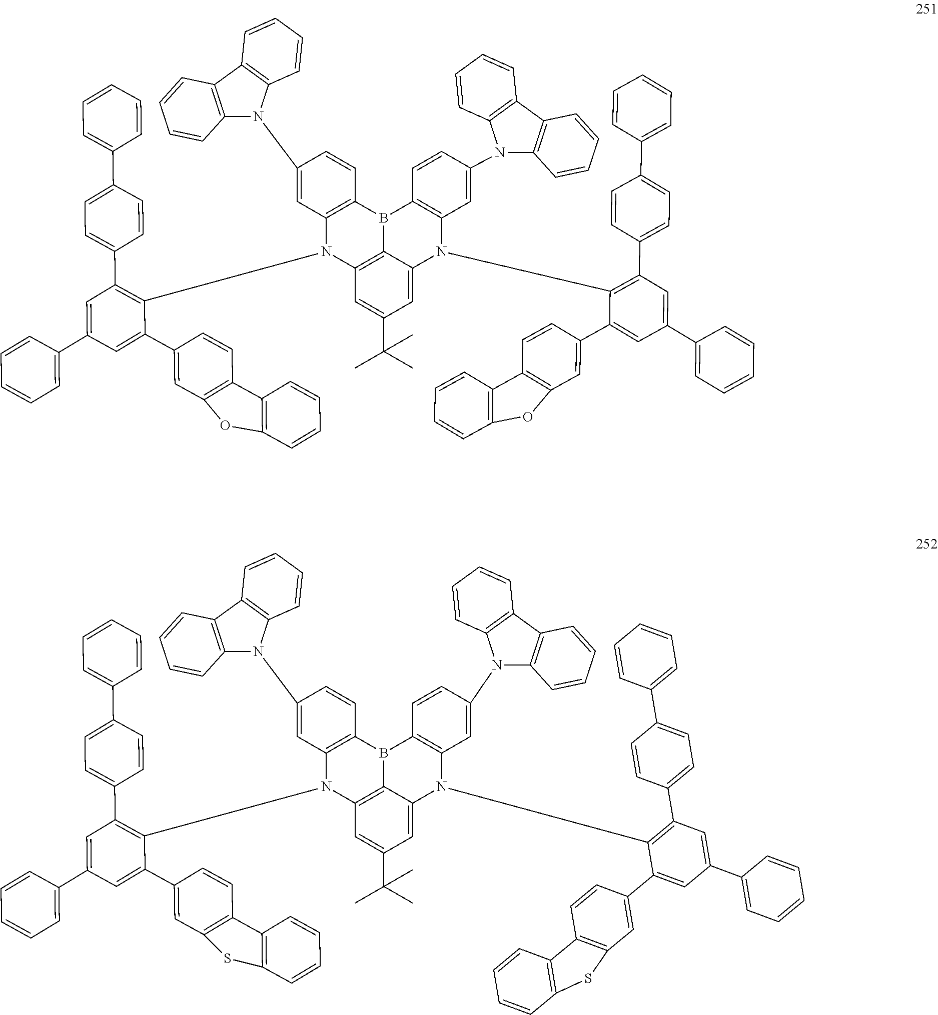 [SMILES: CC(C)(C)c1cc2c3c(c1)N(c1c(-c4ccc(-c5ccccc5)cc4)cc(-c4ccccc4)cc1-c1ccc4c(c1)oc1ccccc14)c1cc(-n4c5ccccc5c5ccccc54)ccc1B3c1ccc(-n3c4ccccc4c4ccccc43)cc1N2c1c(-c2ccc(-c3ccccc3)cc2)cc(-c2ccccc2)cc1-c1ccc2c(c1)oc1ccccc12 ; CC(C)(C)c1cc2c3c(c1)N(c1c(-c4ccc(-c5ccccc5)cc4)cc(-c4ccccc4)cc1-c1ccc4c(c1)sc1ccccc14)c1cc(-n4c5ccccc5c5ccccc54)ccc1B3c1ccc(-n3c4ccccc4c4ccccc43)cc1N2c1c(-c2ccc(-c3ccccc3)cc2)cc(-c2ccccc2)cc1-c1ccc2c(c1)sc1ccccc12] 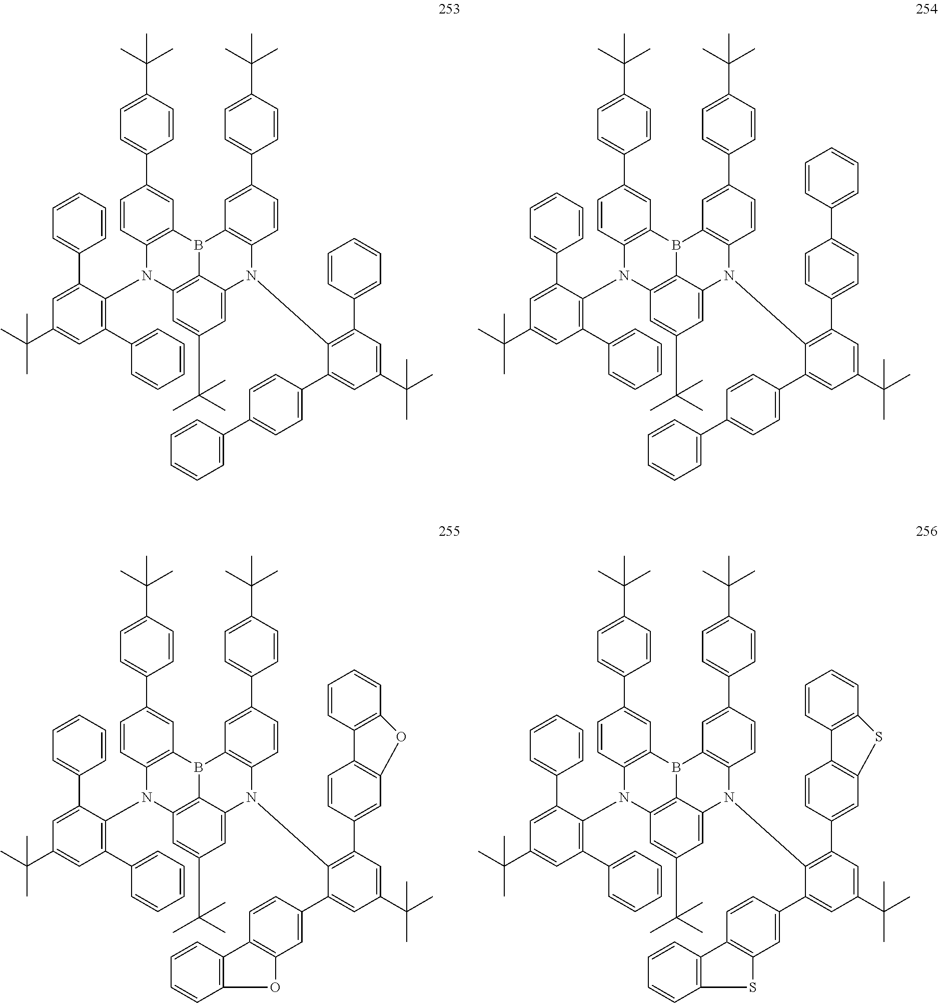 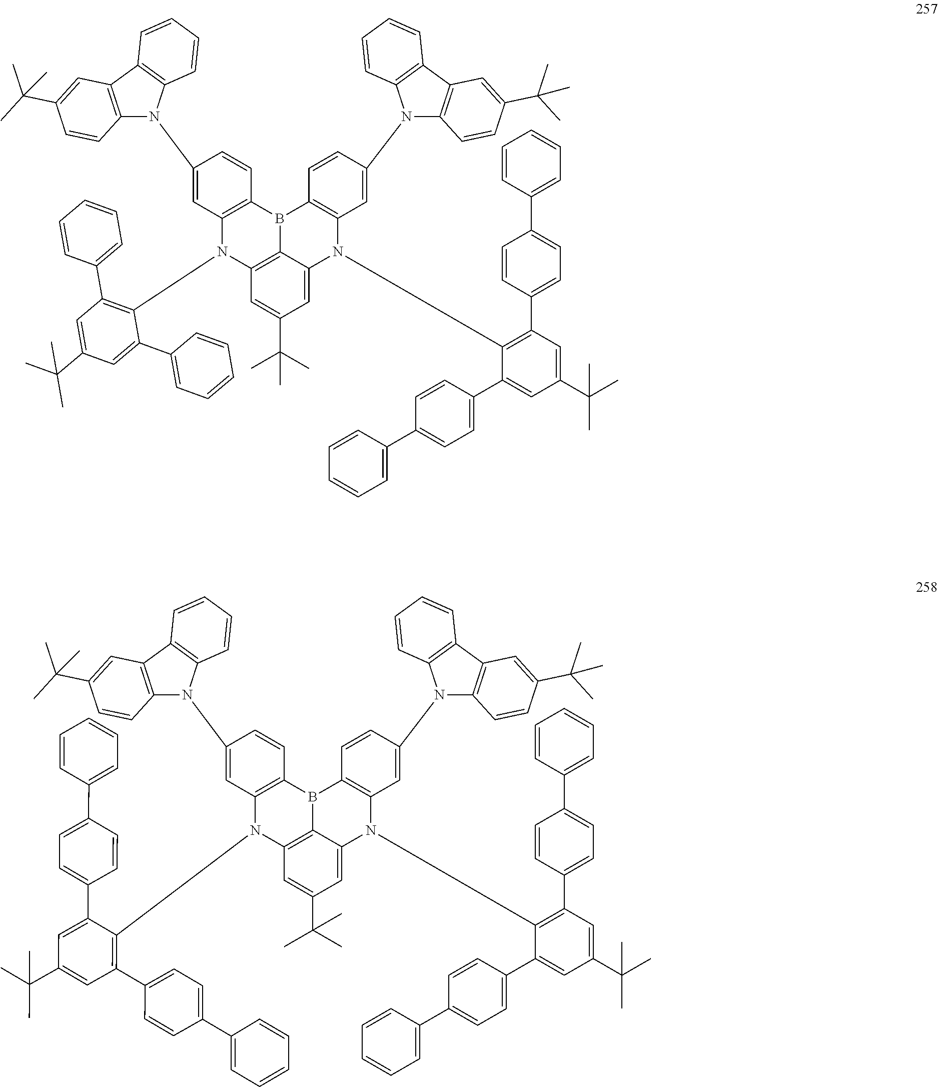 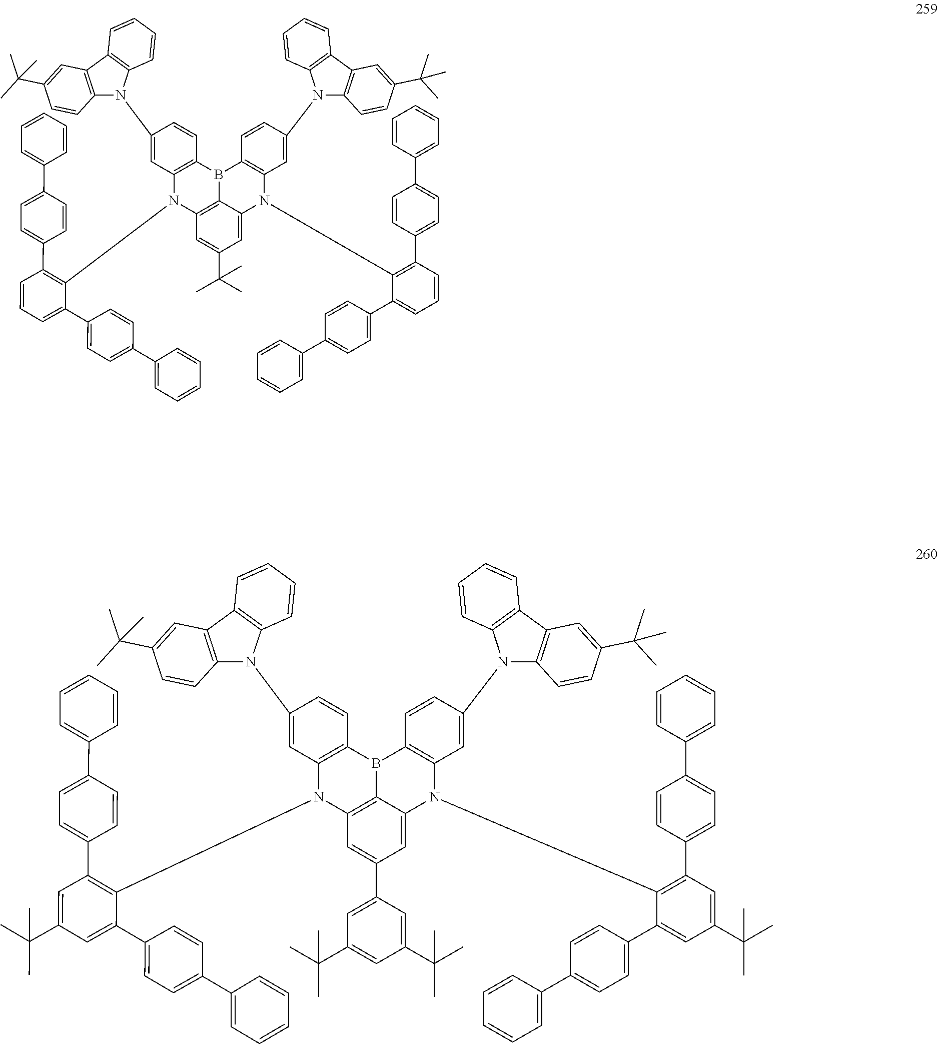 [SMILES: CC(C)(C)c1cc2c3c(c1)N(c1c(-c4ccc(-c5ccccc5)cc4)cccc1-c1ccc(-c4ccccc4)cc1)c1cc(-n4c5ccccc5c5cc(C(C)(C)C)ccc54)ccc1B3c1ccc(-n3c4ccccc4c4cc(C(C)(C)C)ccc43)cc1N2c1c(-c2ccc(-c3ccccc3)cc2)cccc1-c1ccc(-c2ccccc2)cc1 ; CC(C)(C)c1cc(-c2cc3c4c(c2)N(c2c(-c5ccc(-c6ccccc6)cc5)cc(C(C)(C)C)cc2-c2ccc(-c5ccccc5)cc2)c2cc(-n5c6ccccc6c6cc(C(C)(C)C)ccc65)ccc2B4c2ccc(-n4c5ccccc5c5cc(C(C)(C)C)ccc54)cc2N3c2c(-c3ccc(-c4ccccc4)cc3)cc(C(C)(C)C)cc2-c2ccc(-c3ccccc3)cc2)cc(C(C)(C)C)c1] 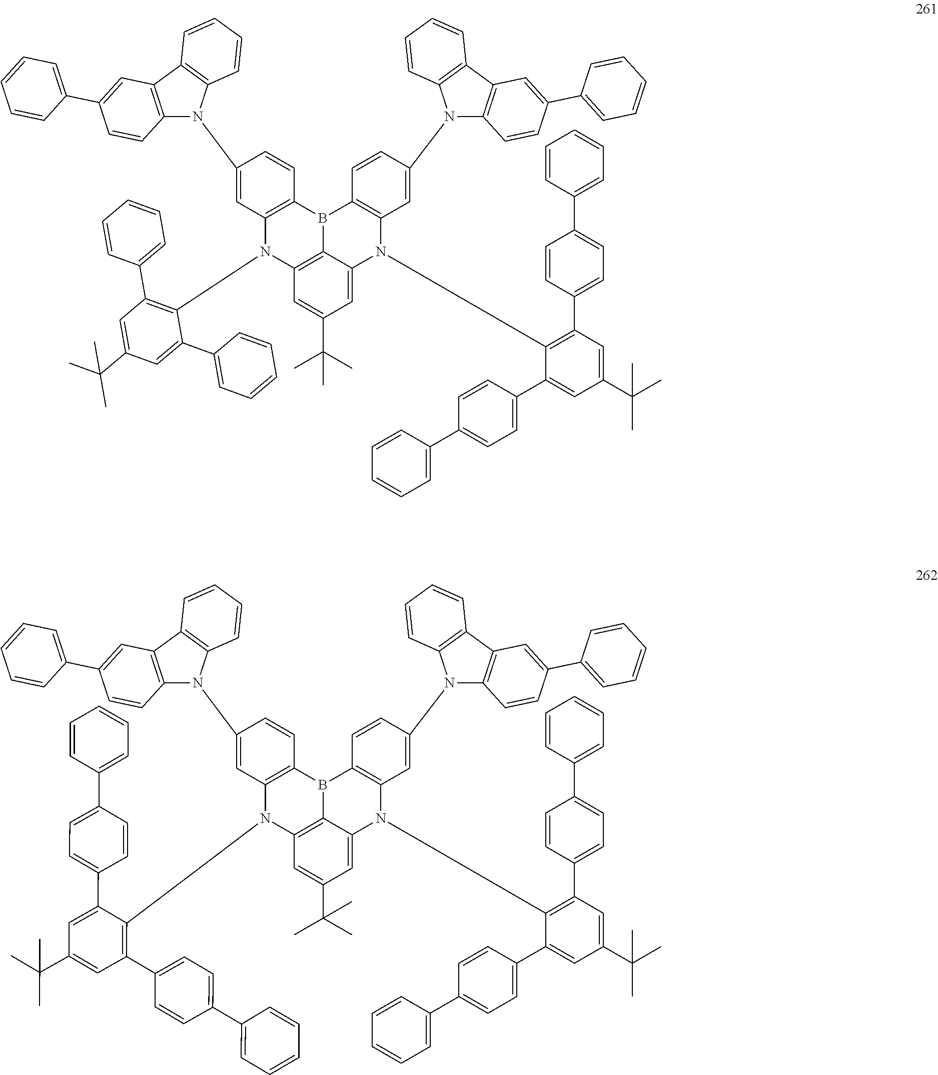 [SMILES: CC(C)(C)c1cc(-c2ccccc2)c(N2c3cc(-n4c5ccccc5c5cc(-c6ccccc6)ccc54)ccc3B3c4ccc(-n5c6ccccc6c6cc(-c7ccccc7)ccc65)cc4N(c4c(-c5ccc(-c6ccccc6)cc5)cc(C(C)(C)C)cc4-c4ccc(-c5ccccc5)cc4)c4cc(C(C)(C)C)cc2c43)c(-c2ccccc2)c1 ; CC(C)(C)c1cc(-c2ccc(-c3ccccc3)cc2)c(N2c3cc(-n4c5ccccc5c5cc(-c6ccccc6)ccc54)ccc3B3c4ccc(-n5c6ccccc6c6cc(-c7ccccc7)ccc65)cc4N(c4c(-c5ccc(-c6ccccc6)cc5)cc(C(C)(C)C)cc4-c4ccc(-c5ccccc5)cc4)c4cc(C(C)(C)C)cc2c43)c(-c2ccc(-c3ccccc3)cc2)c1] 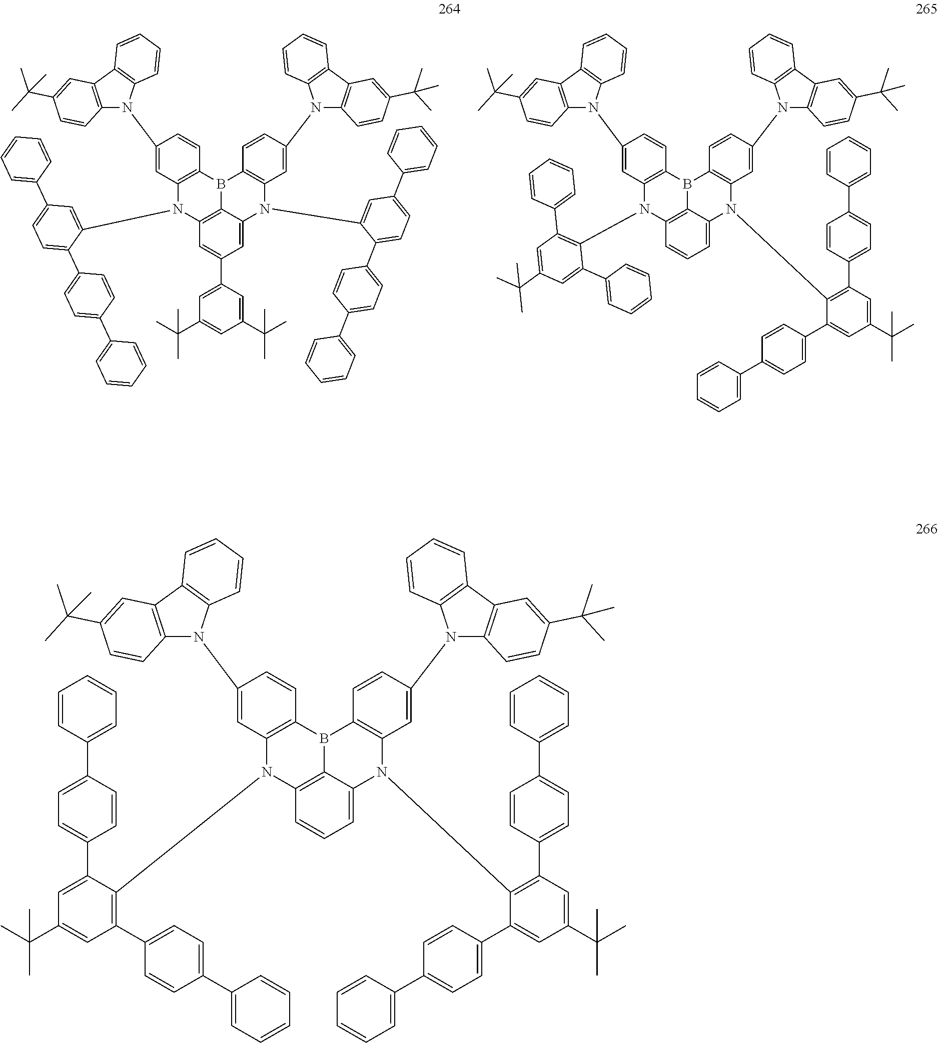 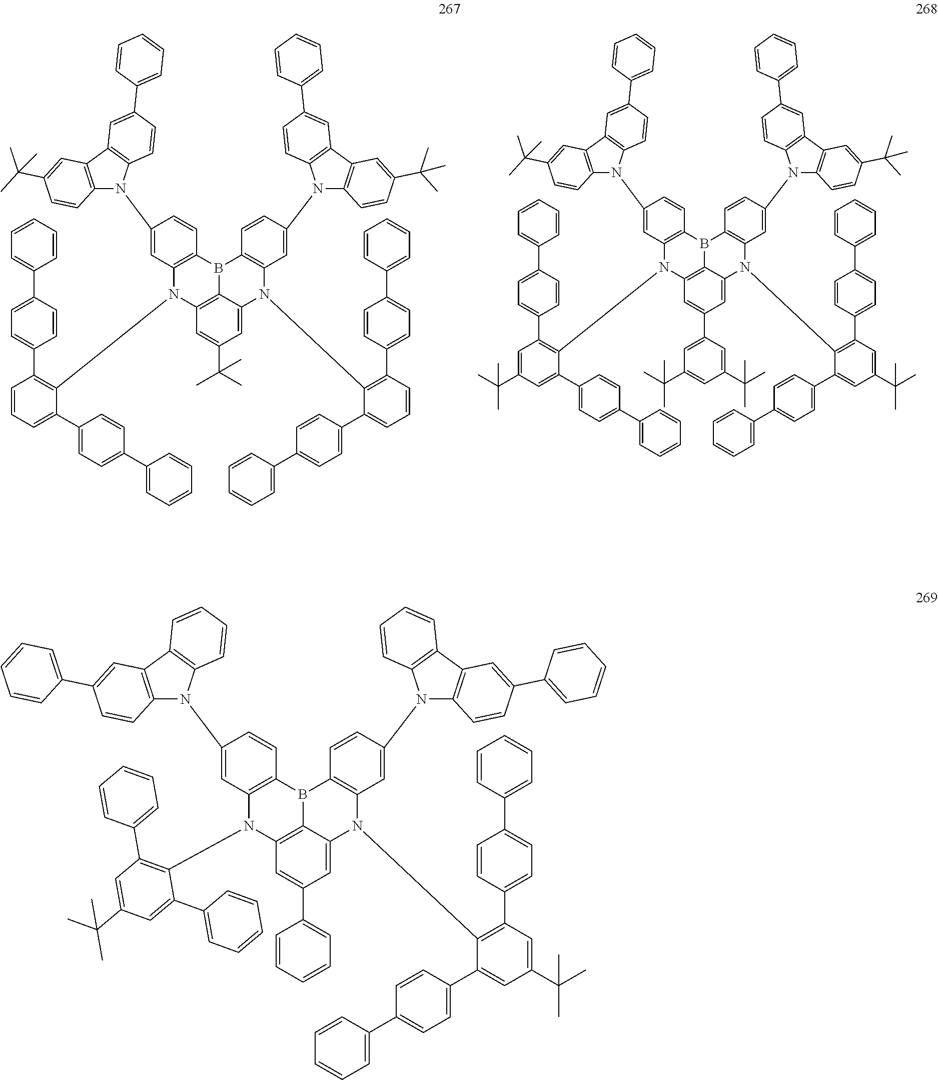 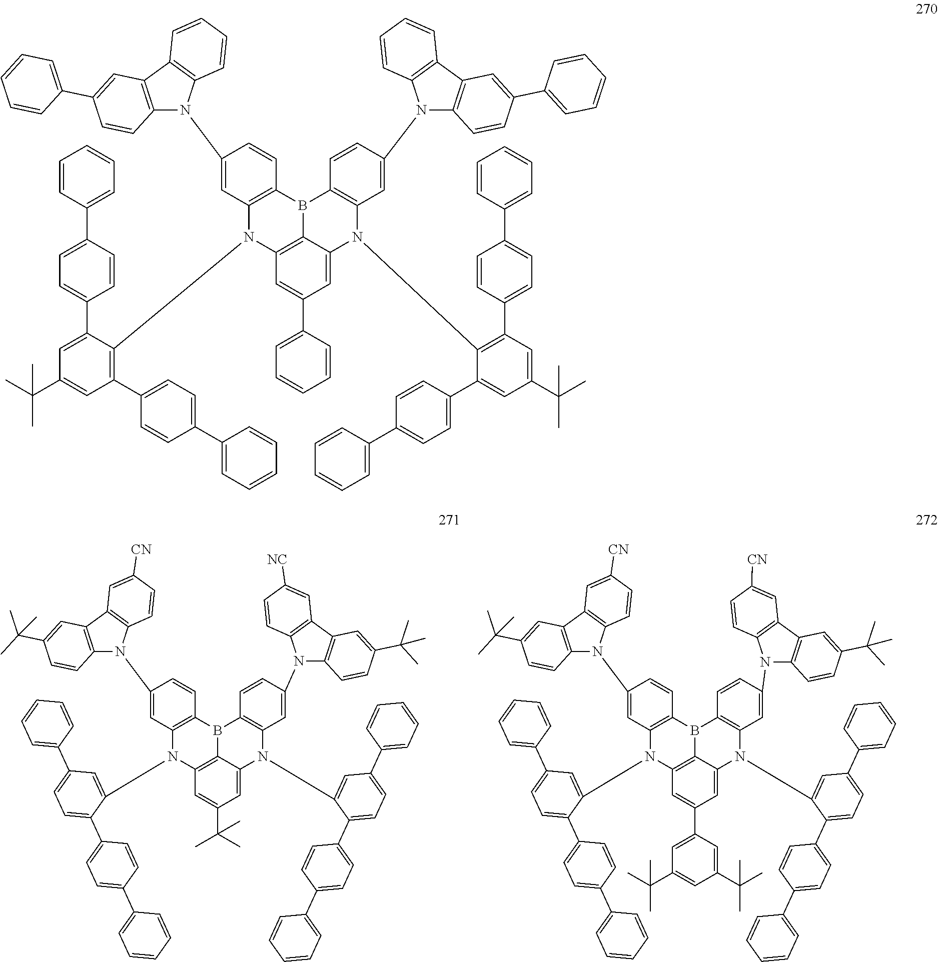 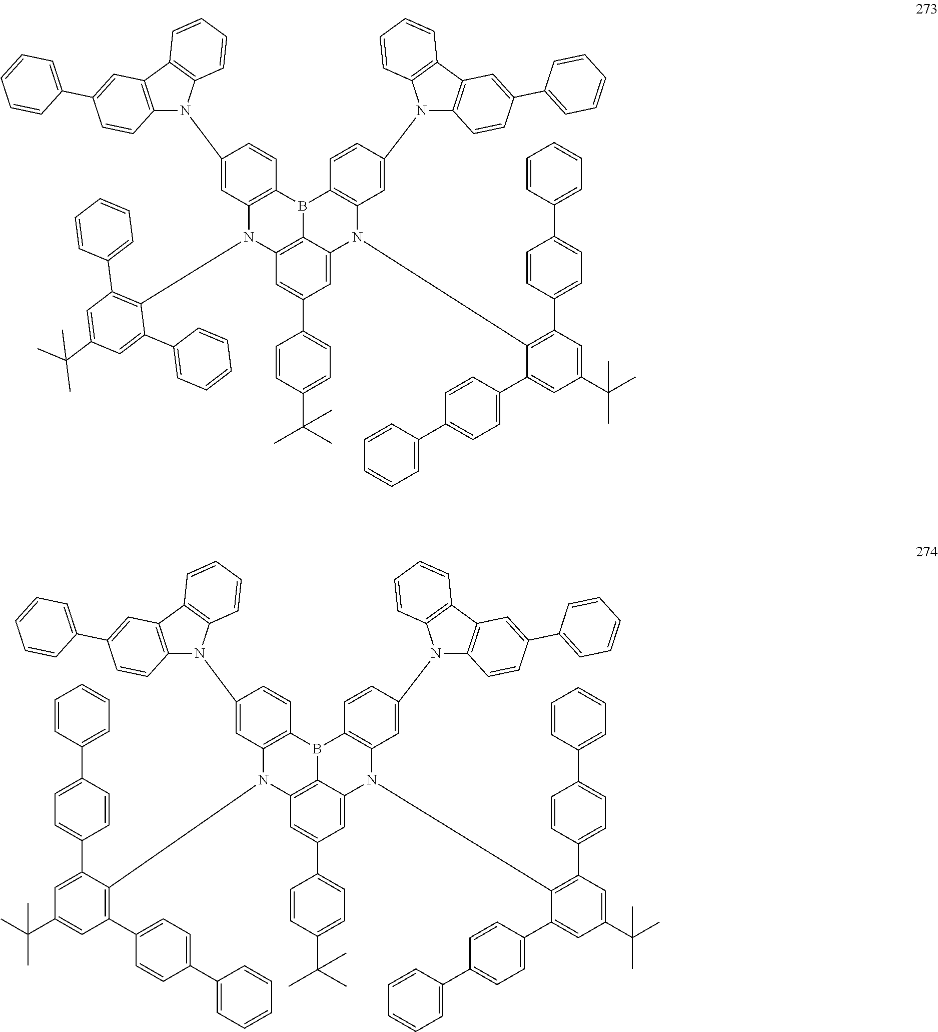 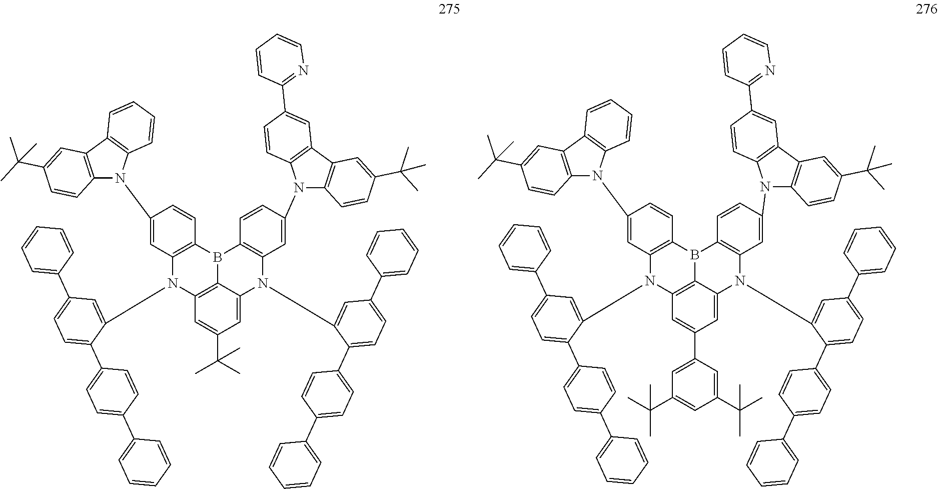 [SMILES: CC(C)(C)c1cc2c3c(c1)N(c1cc(-c4ccccc4)ccc1-c1ccc(-c4ccccc4)cc1)c1cc(-n4c5ccc(-c6ccccn6)cc5c5cc(C(C)(C)C)ccc54)ccc1B3c1ccc(-n3c4ccccc4c4cc(C(C)(C)C)ccc43)cc1N2c1cc(-c2ccccc2)ccc1-c1ccc(-c2ccccc2)cc1 ; CC(C)(C)c1cc(-c2cc3c4c(c2)N(c2cc(-c5ccccc5)ccc2-c2ccc(-c5ccccc5)cc2)c2cc(-n5c6ccc(-c7ccccn7)cc6c6cc(C(C)(C)C)ccc65)ccc2B4c2ccc(-n4c5ccccc5c5cc(C(C)(C)C)ccc54)cc2N3c2cc(-c3ccccc3)ccc2-c2ccc(-c3ccccc3)cc2)cc(C(C)(C)C)c1] 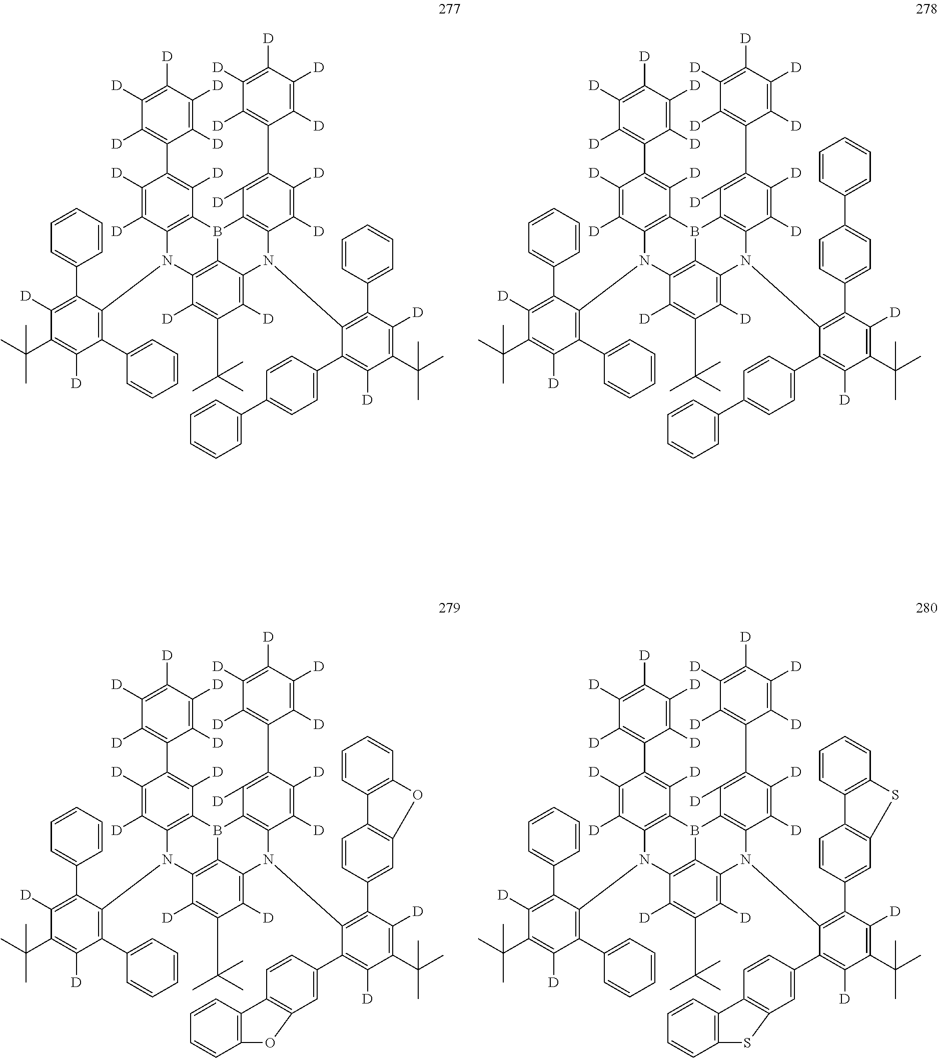 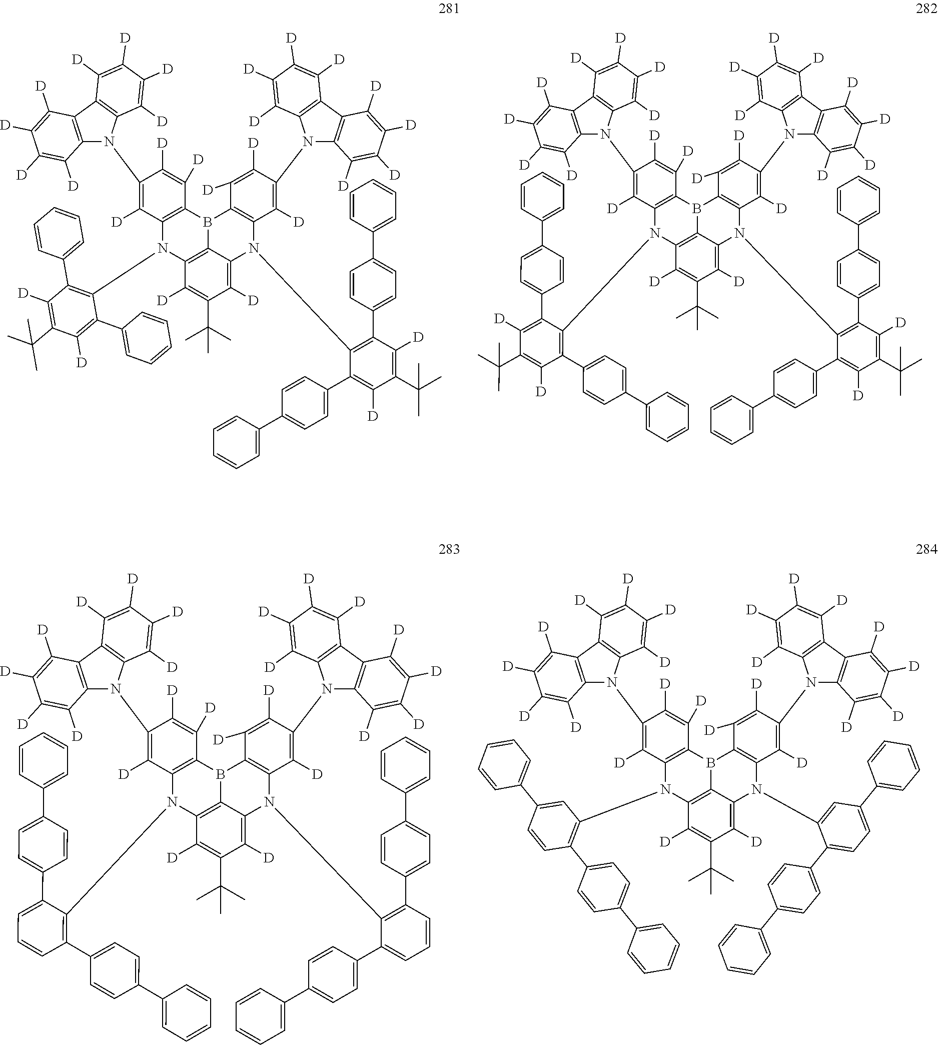 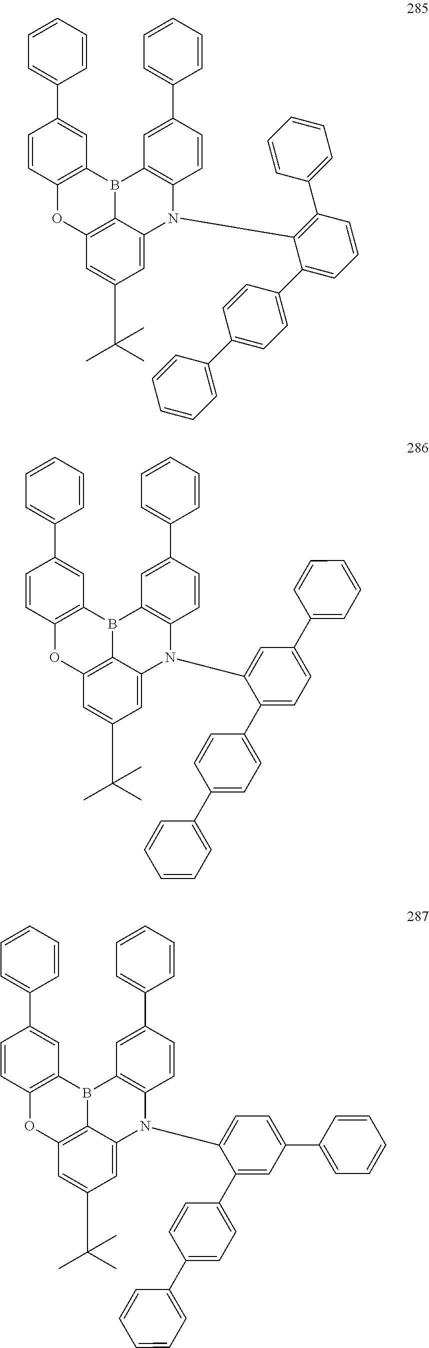 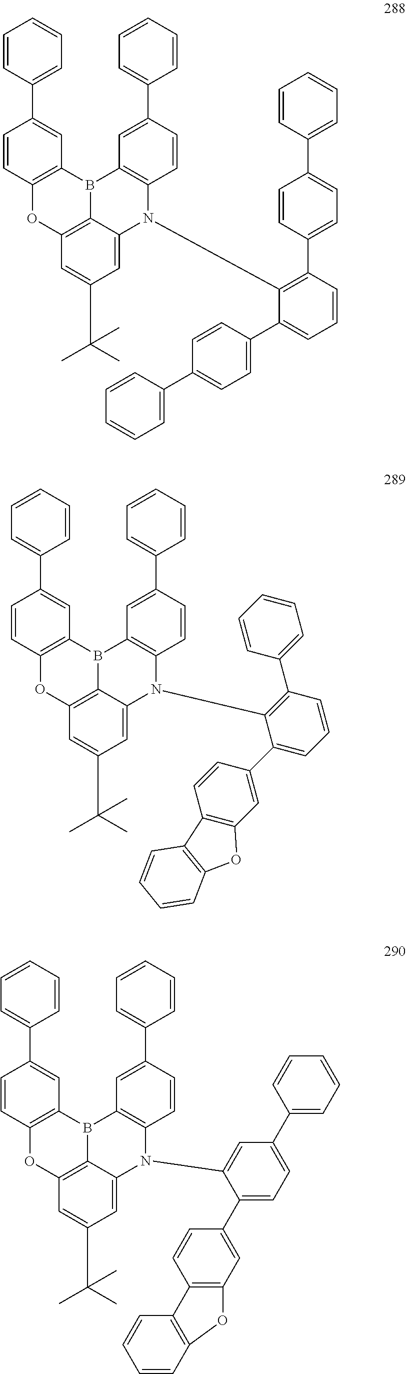 [SMILES: CC(C)(C)c1cc2c3c(c1)N(c1c(-c4ccc(-c5ccccc5)cc4)cccc1-c1ccc(-c4ccccc4)cc1)c1ccc(-c4ccccc4)cc1B3c1cc(-c3ccccc3)ccc1O2 ; CC(C)(C)c1cc2c3c(c1)N(c1c(-c4ccccc4)cccc1-c1ccc4c(c1)oc1ccccc14)c1ccc(-c4ccccc4)cc1B3c1cc(-c3ccccc3)ccc1O2 ; CC(C)(C)c1cc2c3c(c1)N(c1cc(-c4ccccc4)ccc1-c1ccc4c(c1)oc1ccccc14)c1ccc(-c4ccccc4)cc1B3c1cc(-c3ccccc3)ccc1O2] 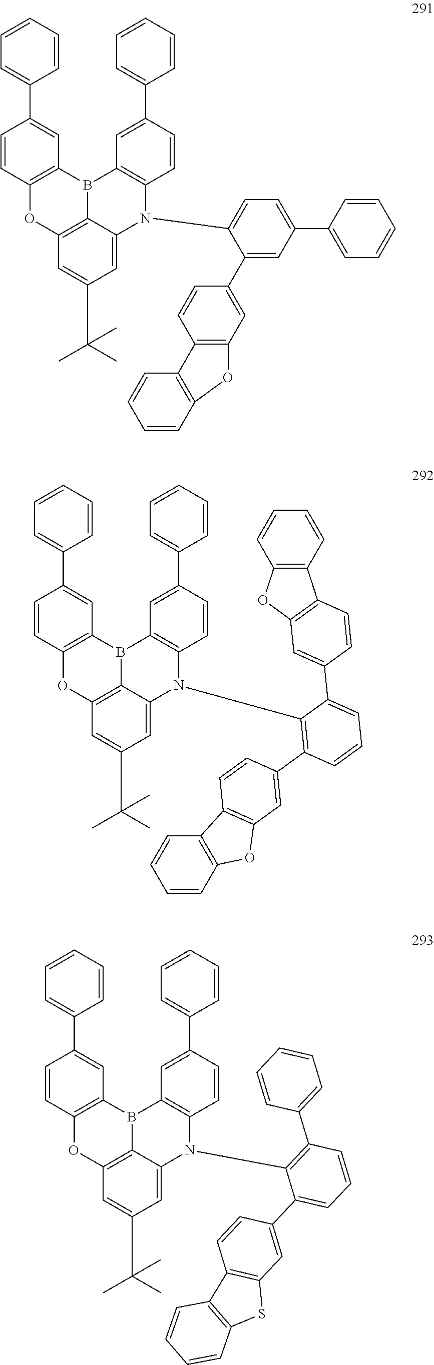 [SMILES: CC(C)(C)c1cc2c3c(c1)N(c1ccc(-c4ccccc4)cc1-c1ccc4c(c1)oc1ccccc14)c1ccc(-c4ccccc4)cc1B3c1cc(-c3ccccc3)ccc1O2 ; CC(C)(C)c1cc2c3c(c1)N(c1c(-c4ccc5c(c4)oc4ccccc45)cccc1-c1ccc4c(c1)oc1ccccc14)c1ccc(-c4ccccc4)cc1B3c1cc(-c3ccccc3)ccc1O2 ; CC(C)(C)c1cc2c3c(c1)N(c1c(-c4ccccc4)cccc1-c1ccc4c(c1)sc1ccccc14)c1ccc(-c4ccccc4)cc1B3c1cc(-c3ccccc3)ccc1O2] 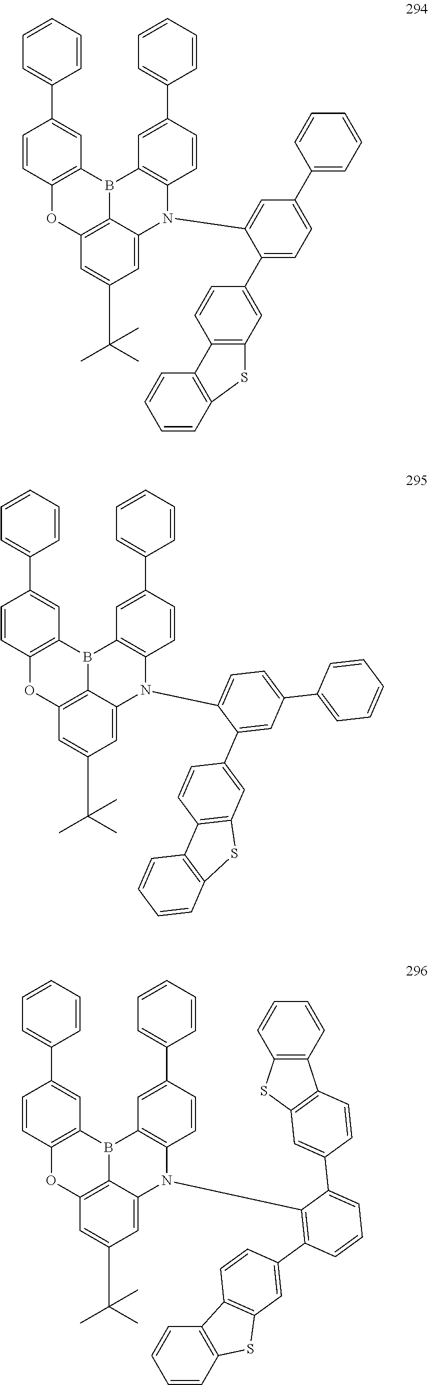 [SMILES: CC(C)(C)c1cc2c3c(c1)N(c1cc(-c4ccccc4)ccc1-c1ccc4c(c1)sc1ccccc14)c1ccc(-c4ccccc4)cc1B3c1cc(-c3ccccc3)ccc1O2 ; CC(C)(C)c1cc2c3c(c1)N(c1ccc(-c4ccccc4)cc1-c1ccc4c(c1)sc1ccccc14)c1ccc(-c4ccccc4)cc1B3c1cc(-c3ccccc3)ccc1O2 ; CC(C)(C)c1cc2c3c(c1)N(c1c(-c4ccc5c(c4)sc4ccccc45)cccc1-c1ccc4c(c1)sc1ccccc14)c1ccc(-c4ccccc4)cc1B3c1cc(-c3ccccc3)ccc1O2] 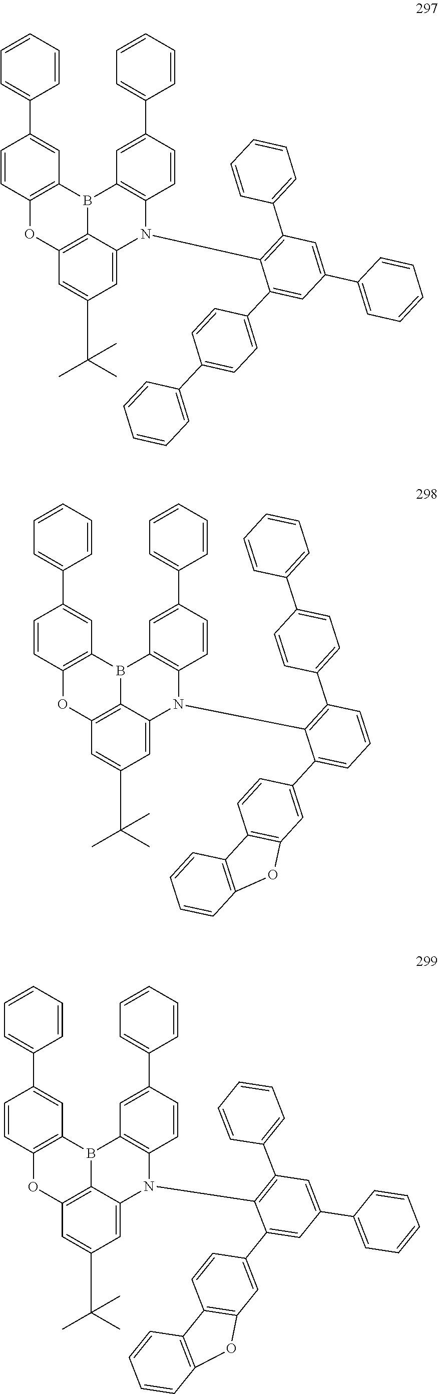 [SMILES: CC(C)(C)c1cc2c3c(c1)N(c1c(-c4ccccc4)cc(-c4ccccc4)cc1-c1ccc(-c4ccccc4)cc1)c1ccc(-c4ccccc4)cc1B3c1cc(-c3ccccc3)ccc1O2 ; CC(C)(C)c1cc2c3c(c1)N(c1c(-c4ccc(-c5ccccc5)cc4)cccc1-c1ccc4c(c1)oc1ccccc14)c1ccc(-c4ccccc4)cc1B3c1cc(-c3ccccc3)ccc1O2 ; CC(C)(C)c1cc2c3c(c1)N(c1c(-c4ccccc4)cc(-c4ccccc4)cc1-c1ccc4c(c1)oc1ccccc14)c1ccc(-c4ccccc4)cc1B3c1cc(-c3ccccc3)ccc1O2] 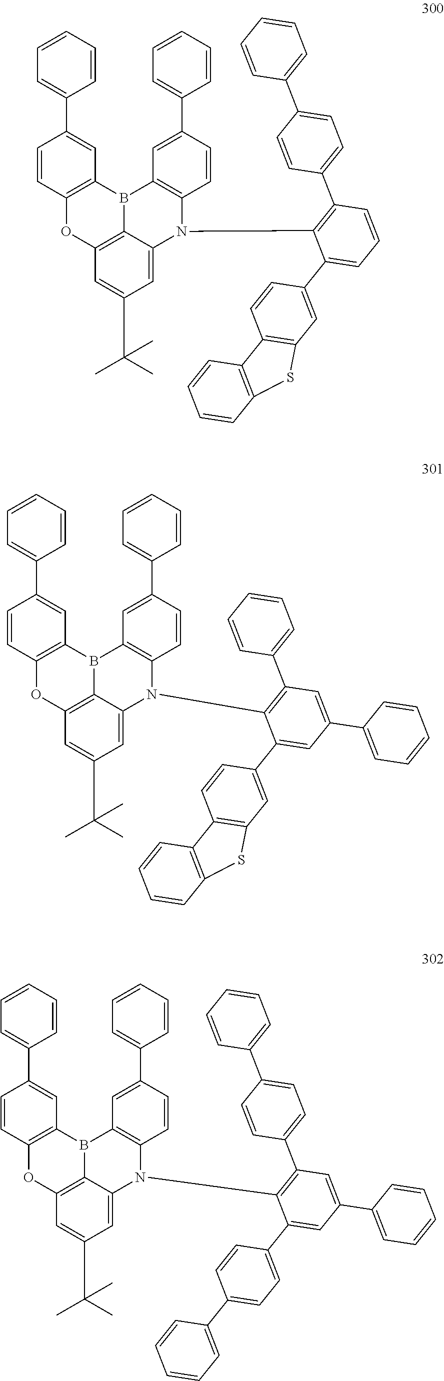 [SMILES: CC(C)(C)c1cc2c3c(c1)N(c1c(-c4ccc(-c5ccccc5)cc4)cccc1-c1ccc4c(c1)sc1ccccc14)c1ccc(-c4ccccc4)cc1B3c1cc(-c3ccccc3)ccc1O2 ; CC(C)(C)c1cc2c3c(c1)N(c1c(-c4ccccc4)cc(-c4ccccc4)cc1-c1ccc4c(c1)sc1ccccc14)c1ccc(-c4ccccc4)cc1B3c1cc(-c3ccccc3)ccc1O2 ; CC(C)(C)c1cc2c3c(c1)N(c1c(-c4ccc(-c5ccccc5)cc4)cc(-c4ccccc4)cc1-c1ccc(-c4ccccc4)cc1)c1ccc(-c4ccccc4)cc1B3c1cc(-c3ccccc3)ccc1O2] 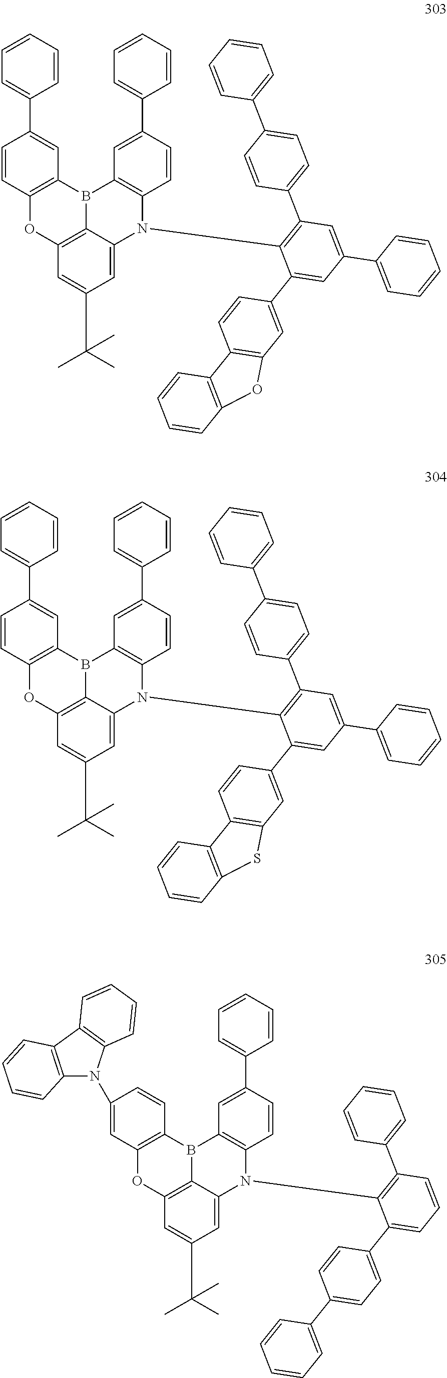 [SMILES: CC(C)(C)c1cc2c3c(c1)N(c1c(-c4ccc(-c5ccccc5)cc4)cc(-c4ccccc4)cc1-c1ccc4c(c1)oc1ccccc14)c1ccc(-c4ccccc4)cc1B3c1cc(-c3ccccc3)ccc1O2 ; CC(C)(C)c1cc2c3c(c1)N(c1c(-c4ccc(-c5ccccc5)cc4)cc(-c4ccccc4)cc1-c1ccc4c(c1)sc1ccccc14)c1ccc(-c4ccccc4)cc1B3c1cc(-c3ccccc3)ccc1O2 ; CC(C)(C)c1cc2c3c(c1)N(c1c(-c4ccccc4)cccc1-c1ccc(-c4ccccc4)cc1)c1ccc(-c4ccccc4)cc1B3c1ccc(-n3c4ccccc4c4ccccc43)cc1O2] 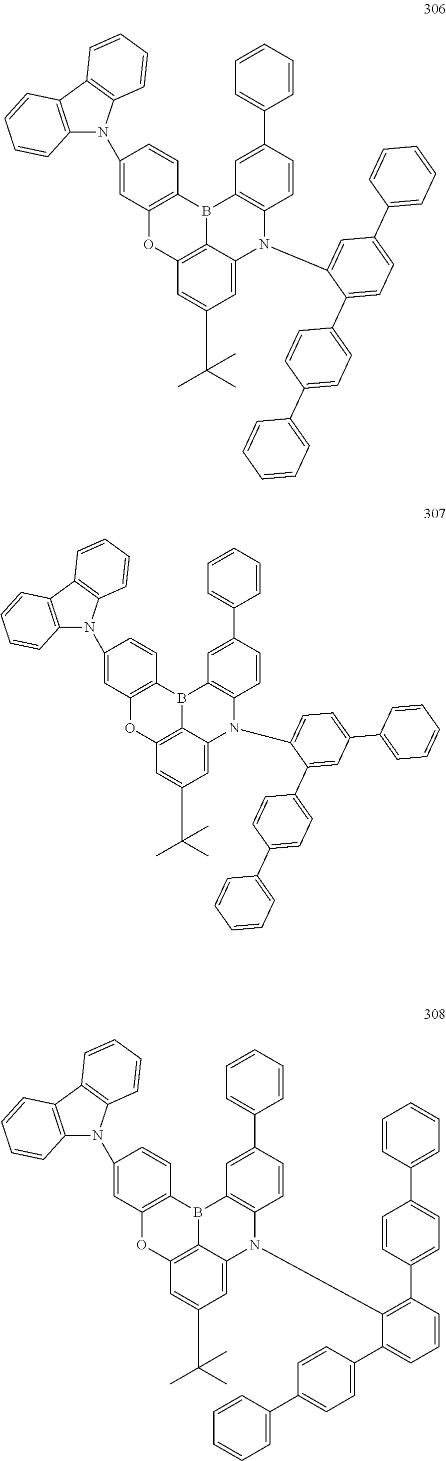 [SMILES: CC(C)(C)c1cc2c3c(c1)N(c1cc(-c4ccccc4)ccc1-c1ccc(-c4ccccc4)cc1)c1ccc(-c4ccccc4)cc1B3c1ccc(-n3c4ccccc4c4ccccc43)cc1O2 ; CC(C)(C)c1cc2c3c(c1)N(c1ccc(-c4ccccc4)cc1-c1ccc(-c4ccccc4)cc1)c1ccc(-c4ccccc4)cc1B3c1ccc(-n3c4ccccc4c4ccccc43)cc1O2 ; CC(C)(C)c1cc2c3c(c1)N(c1c(-c4ccc(-c5ccccc5)cc4)cccc1-c1ccc(-c4ccccc4)cc1)c1ccc(-c4ccccc4)cc1B3c1ccc(-n3c4ccccc4c4ccccc43)cc1O2] 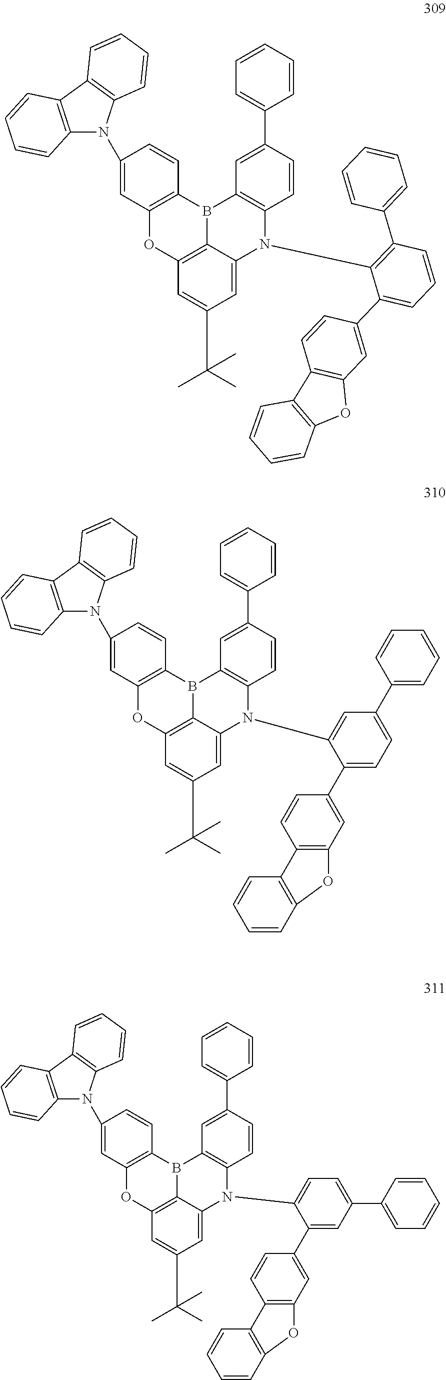 [SMILES: CC(C)(C)c1cc2c3c(c1)N(c1c(-c4ccccc4)cccc1-c1ccc4c(c1)oc1ccccc14)c1ccc(-c4ccccc4)cc1B3c1ccc(-n3c4ccccc4c4ccccc43)cc1O2 ; CC(C)(C)c1cc2c3c(c1)N(c1cc(-c4ccccc4)ccc1-c1ccc4c(c1)oc1ccccc14)c1ccc(-c4ccccc4)cc1B3c1ccc(-n3c4ccccc4c4ccccc43)cc1O2 ; CC(C)(C)c1cc2c3c(c1)N(c1ccc(-c4ccccc4)cc1-c1ccc4c(c1)oc1ccccc14)c1ccc(-c4ccccc4)cc1B3c1ccc(-n3c4ccccc4c4ccccc43)cc1O2] 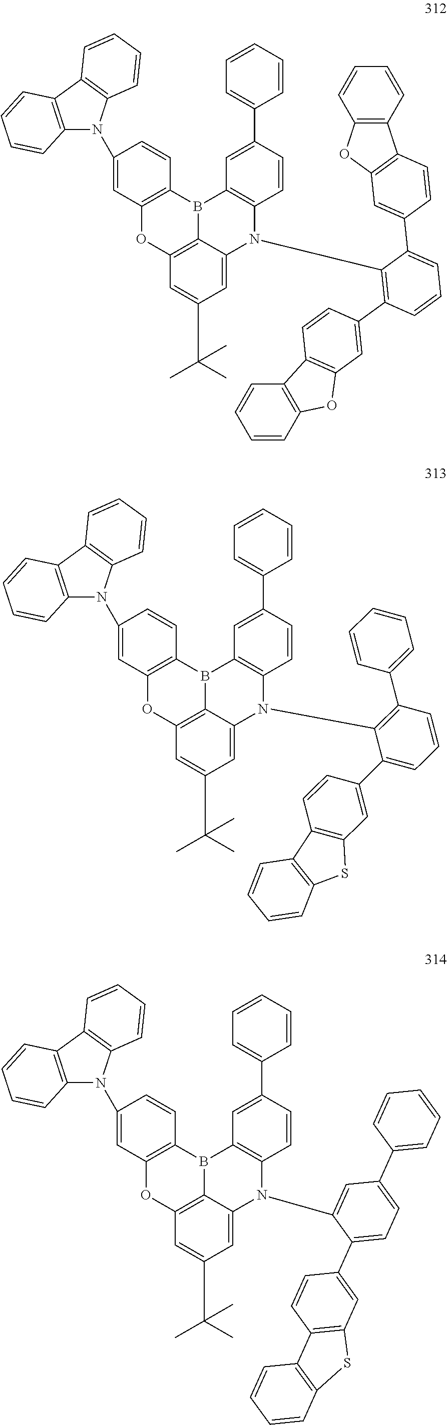 [SMILES: CC(C)(C)c1cc2c3c(c1)N(c1c(-c4ccc5c(c4)oc4ccccc45)cccc1-c1ccc4c(c1)oc1ccccc14)c1ccc(-c4ccccc4)cc1B3c1ccc(-n3c4ccccc4c4ccccc43)cc1O2 ; CC(C)(C)c1cc2c3c(c1)N(c1c(-c4ccccc4)cccc1-c1ccc4c(c1)sc1ccccc14)c1ccc(-c4ccccc4)cc1B3c1ccc(-n3c4ccccc4c4ccccc43)cc1O2 ; CC(C)(C)c1cc2c3c(c1)N(c1cc(-c4ccccc4)ccc1-c1ccc4c(c1)sc1ccccc14)c1ccc(-c4ccccc4)cc1B3c1ccc(-n3c4ccccc4c4ccccc43)cc1O2] 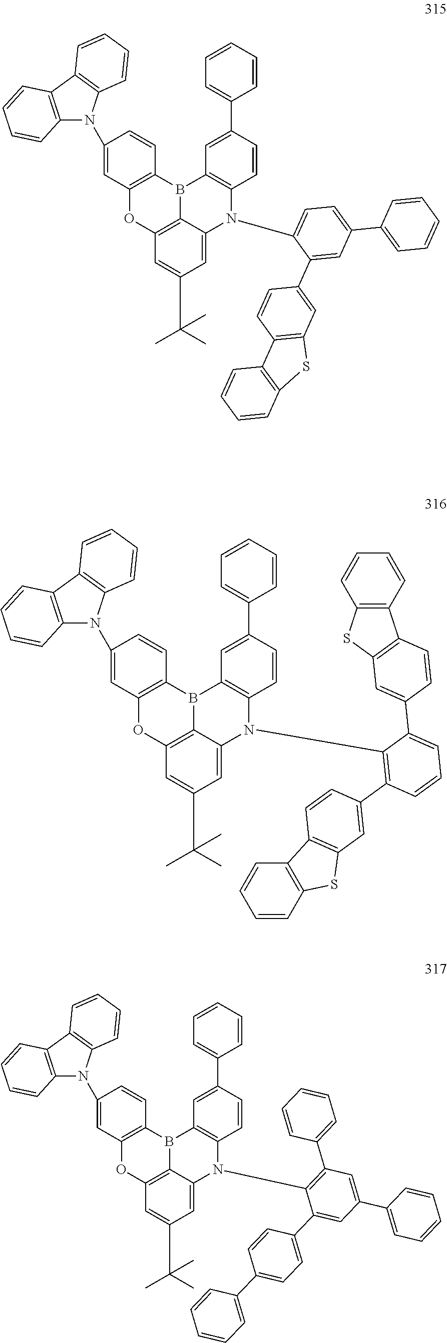 [SMILES: CC(C)(C)c1cc2c3c(c1)N(c1ccc(-c4ccccc4)cc1-c1ccc4c(c1)sc1ccccc14)c1ccc(-c4ccccc4)cc1B3c1ccc(-n3c4ccccc4c4ccccc43)cc1O2 ; CC(C)(C)c1cc2c3c(c1)N(c1c(-c4ccc5c(c4)sc4ccccc45)cccc1-c1ccc4c(c1)sc1ccccc14)c1ccc(-c4ccccc4)cc1B3c1ccc(-n3c4ccccc4c4ccccc43)cc1O2 ; CC(C)(C)c1cc2c3c(c1)N(c1c(-c4ccccc4)cc(-c4ccccc4)cc1-c1ccc(-c4ccccc4)cc1)c1ccc(-c4ccccc4)cc1B3c1ccc(-n3c4ccccc4c4ccccc43)cc1O2] 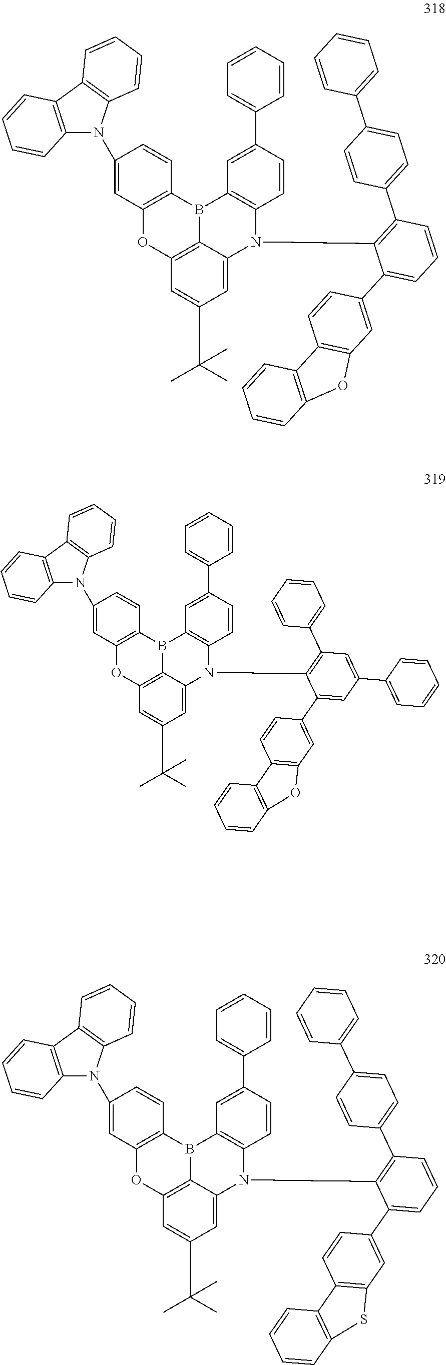 [SMILES: CC(C)(C)c1cc2c3c(c1)N(c1c(-c4ccc(-c5ccccc5)cc4)cccc1-c1ccc4c(c1)oc1ccccc14)c1ccc(-c4ccccc4)cc1B3c1ccc(-n3c4ccccc4c4ccccc43)cc1O2 ; CC(C)(C)c1cc2c3c(c1)N(c1c(-c4ccccc4)cc(-c4ccccc4)cc1-c1ccc4c(c1)oc1ccccc14)c1ccc(-c4ccccc4)cc1B3c1ccc(-n3c4ccccc4c4ccccc43)cc1O2 ; CC(C)(C)c1cc2c3c(c1)N(c1c(-c4ccc(-c5ccccc5)cc4)cccc1-c1ccc4c(c1)sc1ccccc14)c1ccc(-c4ccccc4)cc1B3c1ccc(-n3c4ccccc4c4ccccc43)cc1O2] 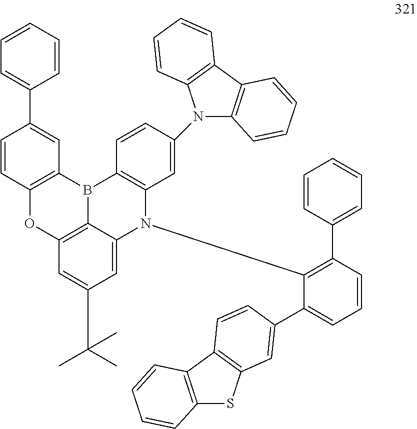 [SMILES: CC(C)(C)c1cc2c3c(c1)N(c1c(-c4ccccc4)cccc1-c1ccc4c(c1)sc1ccccc14)c1cc(-n4c5ccccc5c5ccccc54)ccc1B3c1cc(-c3ccccc3)ccc1O2] 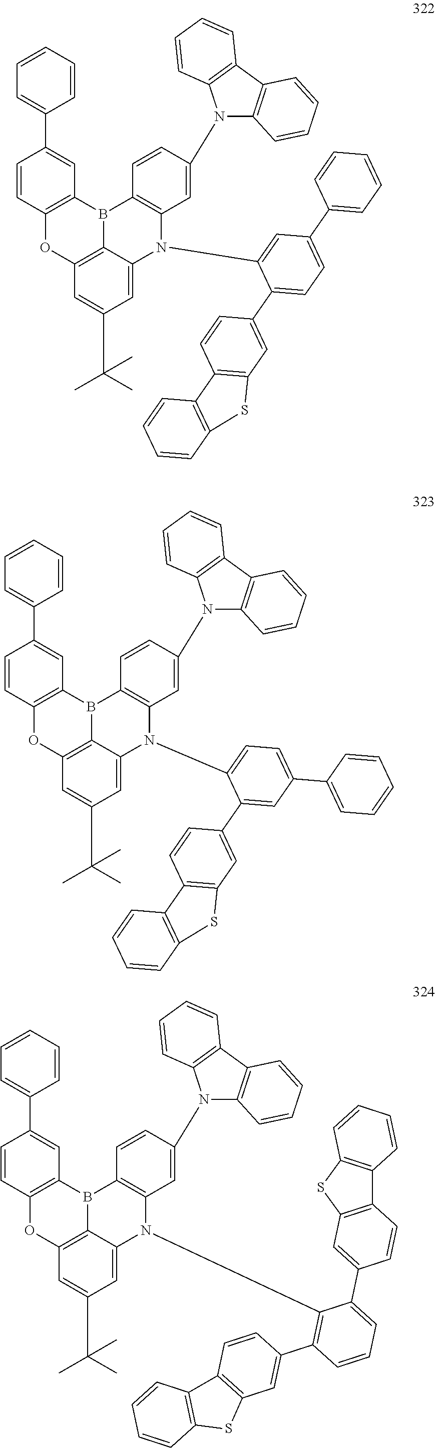 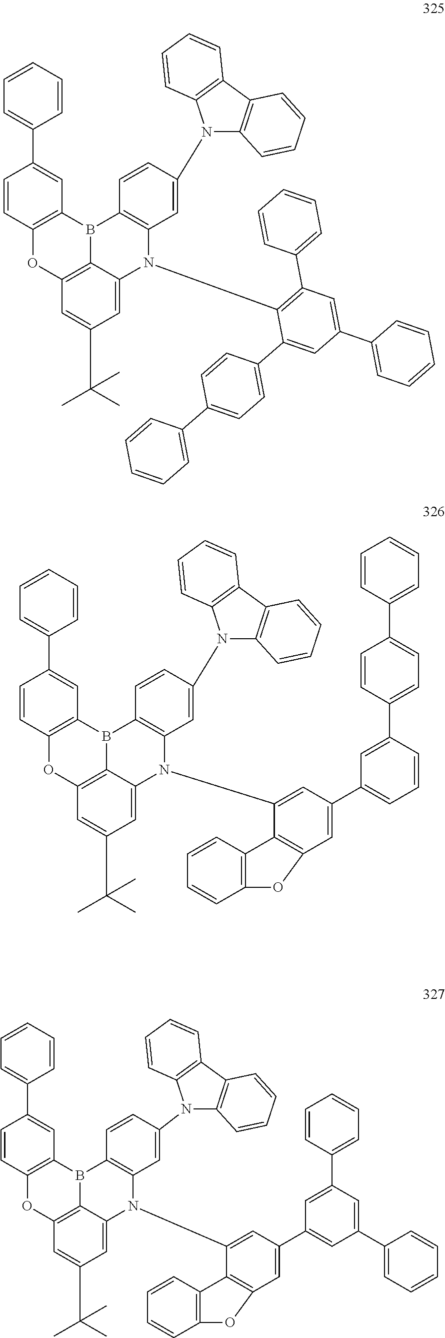 [SMILES: CC(C)(C)c1cc2c3c(c1)N(c1c(-c4ccccc4)cc(-c4ccccc4)cc1-c1ccc(-c4ccccc4)cc1)c1cc(-n4c5ccccc5c5ccccc54)ccc1B3c1cc(-c3ccccc3)ccc1O2 ; CC(C)(C)c1cc2c3c(c1)N(c1cc(-c4cccc(-c5ccc(-c6ccccc6)cc5)c4)cc4oc5ccccc5c14)c1cc(-n4c5ccccc5c5ccccc54)ccc1B3c1cc(-c3ccccc3)ccc1O2 ; CC(C)(C)c1cc2c3c(c1)N(c1cc(-c4cc(-c5ccccc5)cc(-c5ccccc5)c4)cc4oc5ccccc5c14)c1cc(-n4c5ccccc5c5ccccc54)ccc1B3c1cc(-c3ccccc3)ccc1O2] 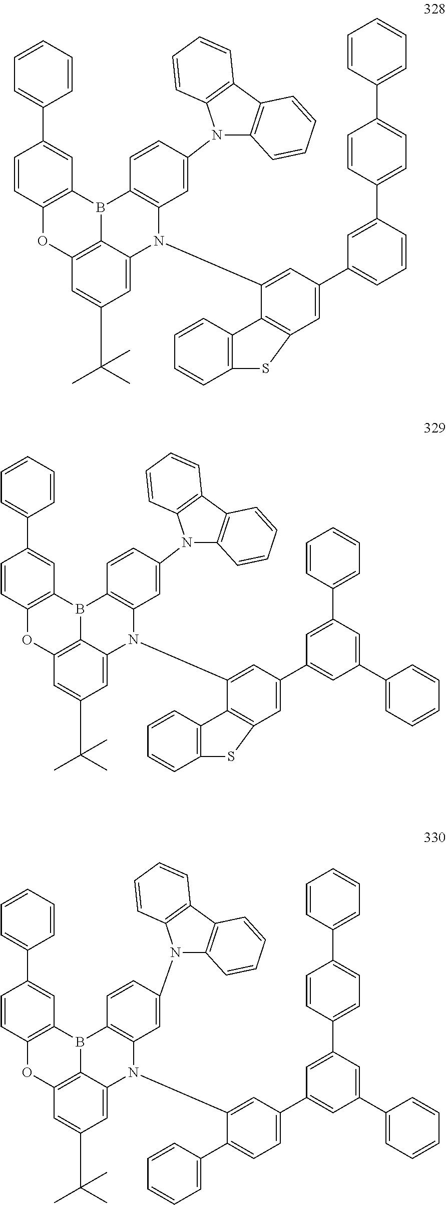 [SMILES: CC(C)(C)c1cc2c3c(c1)N(c1cc(-c4cccc(-c5ccc(-c6ccccc6)cc5)c4)cc4sc5ccccc5c14)c1cc(-n4c5ccccc5c5ccccc54)ccc1B3c1cc(-c3ccccc3)ccc1O2 ; CC(C)(C)c1cc2c3c(c1)N(c1cc(-c4cc(-c5ccccc5)cc(-c5ccccc5)c4)cc4sc5ccccc5c14)c1cc(-n4c5ccccc5c5ccccc54)ccc1B3c1cc(-c3ccccc3)ccc1O2 ; CC(C)(C)c1cc2c3c(c1)N(c1cc(-c4cc(-c5ccccc5)cc(-c5ccc(-c6ccccc6)cc5)c4)ccc1-c1ccccc1)c1cc(-n4c5ccccc5c5ccccc54)ccc1B3c1cc(-c3ccccc3)ccc1O2] 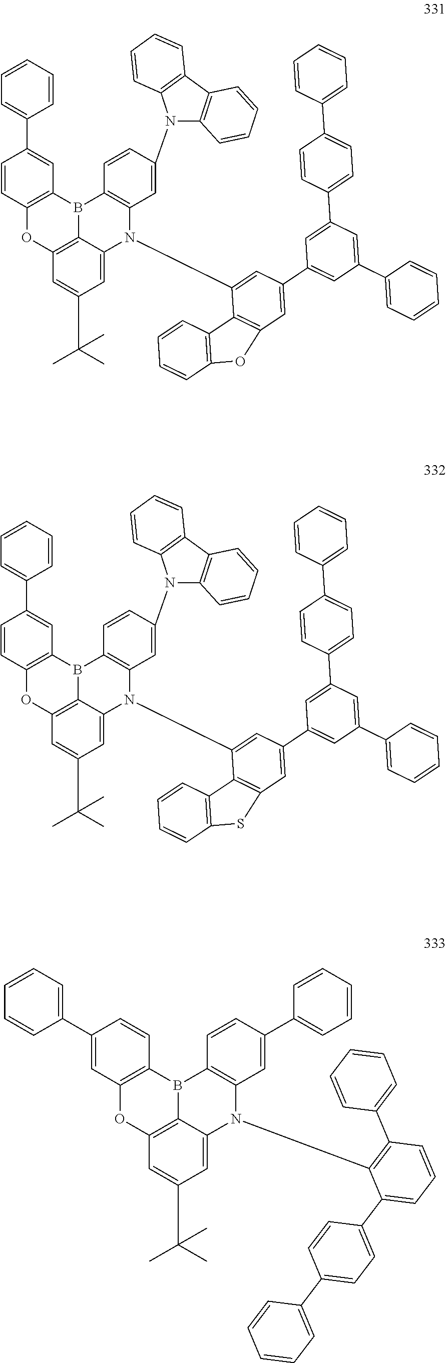 [SMILES: CC(C)(C)c1cc2c3c(c1)N(c1cc(-c4cc(-c5ccccc5)cc(-c5ccc(-c6ccccc6)cc5)c4)cc4oc5ccccc5c14)c1cc(-n4c5ccccc5c5ccccc54)ccc1B3c1cc(-c3ccccc3)ccc1O2 ; CC(C)(C)c1cc2c3c(c1)N(c1cc(-c4cc(-c5ccccc5)cc(-c5ccc(-c6ccccc6)cc5)c4)cc4sc5ccccc5c14)c1cc(-n4c5ccccc5c5ccccc54)ccc1B3c1cc(-c3ccccc3)ccc1O2 ; CC(C)(C)c1cc2c3c(c1)N(c1c(-c4ccccc4)cccc1-c1ccc(-c4ccccc4)cc1)c1cc(-c4ccccc4)ccc1B3c1ccc(-c3ccccc3)cc1O2] 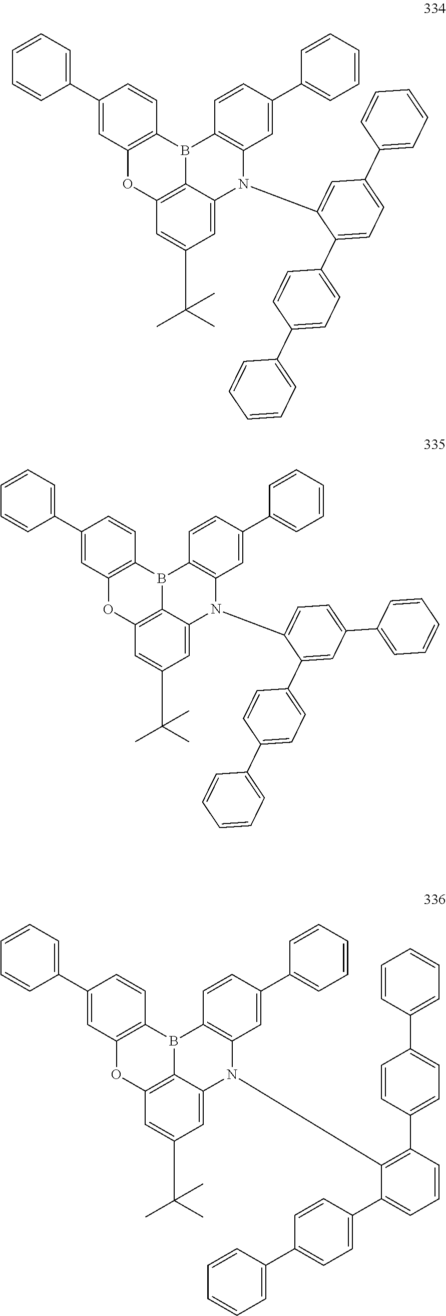 [SMILES: CC(C)(C)c1cc2c3c(c1)N(c1cc(-c4ccccc4)ccc1-c1ccc(-c4ccccc4)cc1)c1cc(-c4ccccc4)ccc1B3c1ccc(-c3ccccc3)cc1O2 ; CC(C)(C)c1cc2c3c(c1)N(c1ccc(-c4ccccc4)cc1-c1ccc(-c4ccccc4)cc1)c1cc(-c4ccccc4)ccc1B3c1ccc(-c3ccccc3)cc1O2 ; CC(C)(C)c1cc2c3c(c1)N(c1c(-c4ccc(-c5ccccc5)cc4)cccc1-c1ccc(-c4ccccc4)cc1)c1cc(-c4ccccc4)ccc1B3c1ccc(-c3ccccc3)cc1O2] 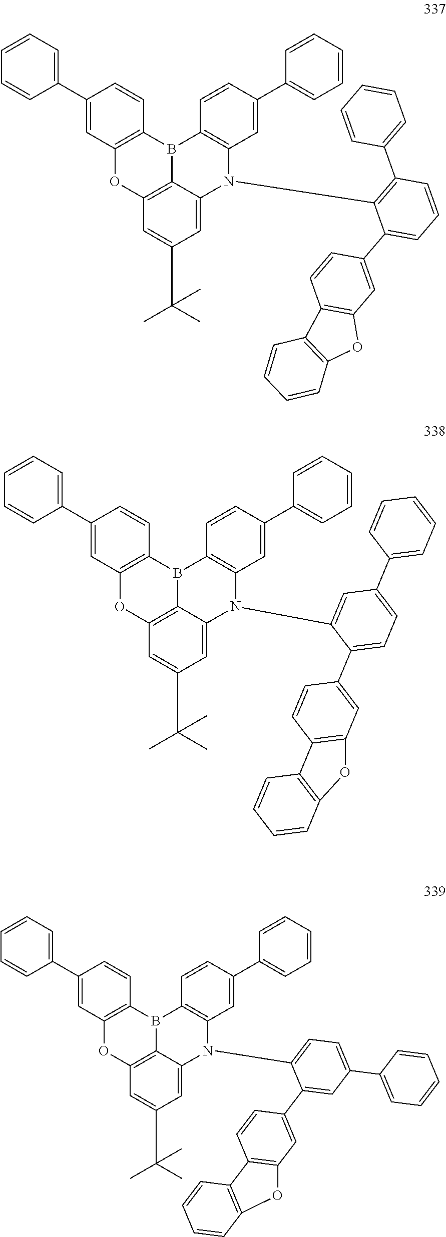 [SMILES: CC(C)(C)c1cc2c3c(c1)N(c1c(-c4ccccc4)cccc1-c1ccc4c(c1)oc1ccccc14)c1cc(-c4ccccc4)ccc1B3c1ccc(-c3ccccc3)cc1O2 ; CC(C)(C)c1cc2c3c(c1)N(c1cc(-c4ccccc4)ccc1-c1ccc4c(c1)oc1ccccc14)c1cc(-c4ccccc4)ccc1B3c1ccc(-c3ccccc3)cc1O2 ; CC(C)(C)c1cc2c3c(c1)N(c1ccc(-c4ccccc4)cc1-c1ccc4c(c1)oc1ccccc14)c1cc(-c4ccccc4)ccc1B3c1ccc(-c3ccccc3)cc1O2] 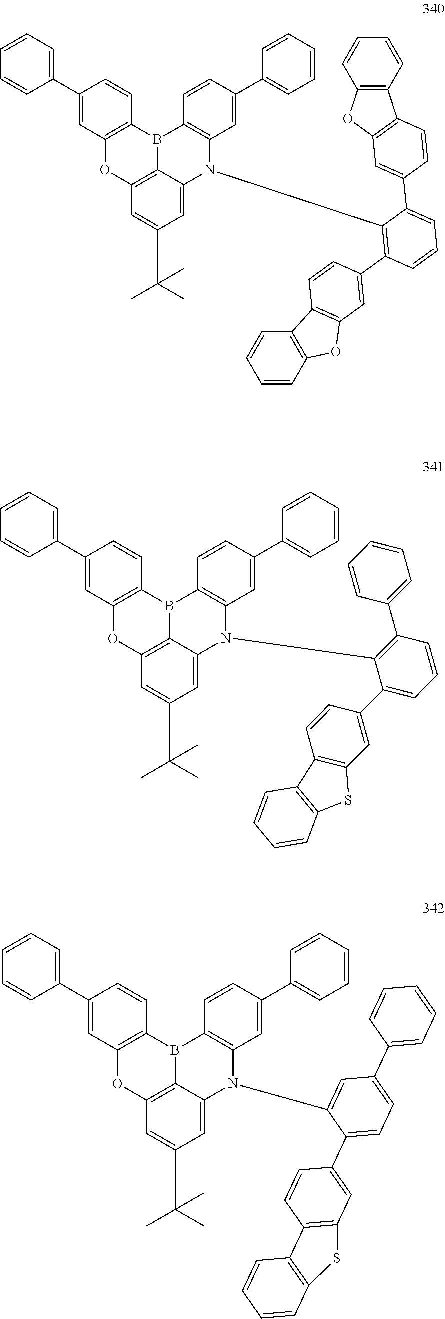 [SMILES: CC(C)(C)c1cc2c3c(c1)N(c1c(-c4ccc5c(c4)oc4ccccc45)cccc1-c1ccc4c(c1)oc1ccccc14)c1cc(-c4ccccc4)ccc1B3c1ccc(-c3ccccc3)cc1O2 ; CC(C)(C)c1cc2c3c(c1)N(c1c(-c4ccccc4)cccc1-c1ccc4c(c1)sc1ccccc14)c1cc(-c4ccccc4)ccc1B3c1ccc(-c3ccccc3)cc1O2 ; CC(C)(C)c1cc2c3c(c1)N(c1cc(-c4ccccc4)ccc1-c1ccc4c(c1)sc1ccccc14)c1cc(-c4ccccc4)ccc1B3c1ccc(-c3ccccc3)cc1O2] 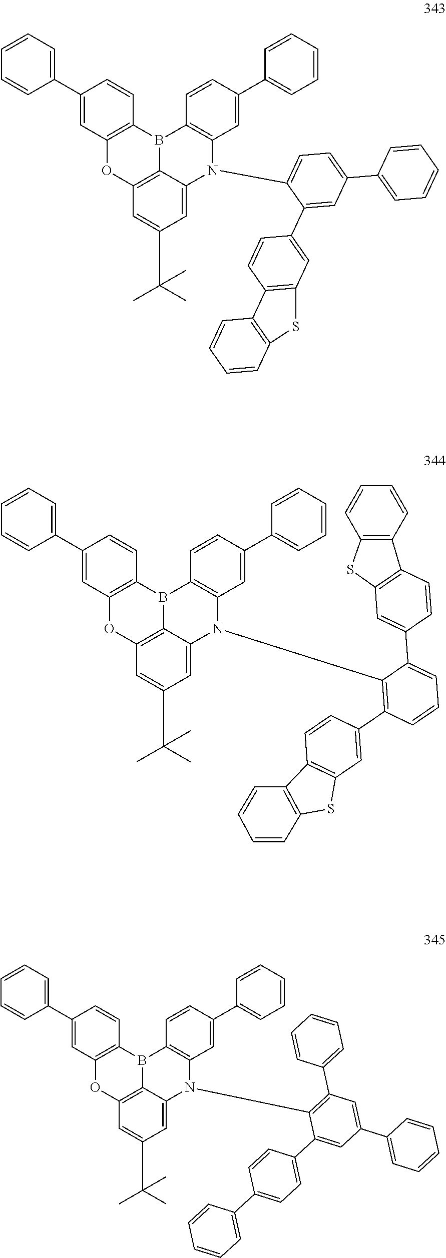 [SMILES: CC(C)(C)c1cc2c3c(c1)N(c1ccc(-c4ccccc4)cc1-c1ccc4c(c1)sc1ccccc14)c1cc(-c4ccccc4)ccc1B3c1ccc(-c3ccccc3)cc1O2 ; CC(C)(C)c1cc2c3c(c1)N(c1c(-c4ccc5c(c4)sc4ccccc45)cccc1-c1ccc4c(c1)sc1ccccc14)c1cc(-c4ccccc4)ccc1B3c1ccc(-c3ccccc3)cc1O2 ; CC(C)(C)c1cc2c3c(c1)N(c1c(-c4ccccc4)cc(-c4ccccc4)cc1-c1ccc(-c4ccccc4)cc1)c1cc(-c4ccccc4)ccc1B3c1ccc(-c3ccccc3)cc1O2] 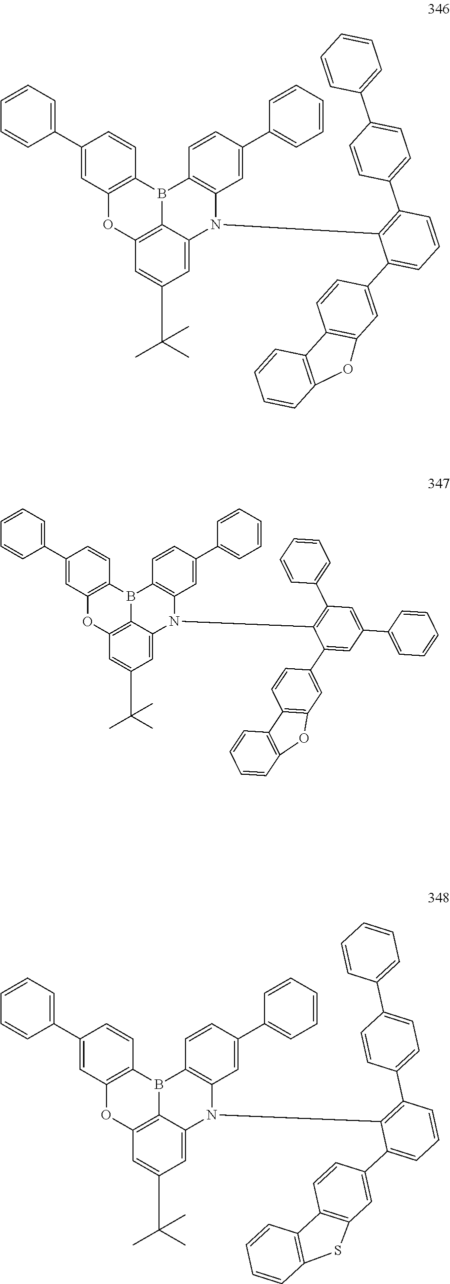 [SMILES: CC(C)(C)c1cc2c3c(c1)N(c1c(-c4ccc(-c5ccccc5)cc4)cccc1-c1ccc4c(c1)oc1ccccc14)c1cc(-c4ccccc4)ccc1B3c1ccc(-c3ccccc3)cc1O2 ; CC(C)(C)c1cc2c3c(c1)N(c1c(-c4ccccc4)cc(-c4ccccc4)cc1-c1ccc4c(c1)oc1ccccc14)c1cc(-c4ccccc4)ccc1B3c1ccc(-c3ccccc3)cc1O2 ; CC(C)(C)c1cc2c3c(c1)N(c1c(-c4ccc(-c5ccccc5)cc4)cccc1-c1ccc4c(c1)sc1ccccc14)c1cc(-c4ccccc4)ccc1B3c1ccc(-c3ccccc3)cc1O2] 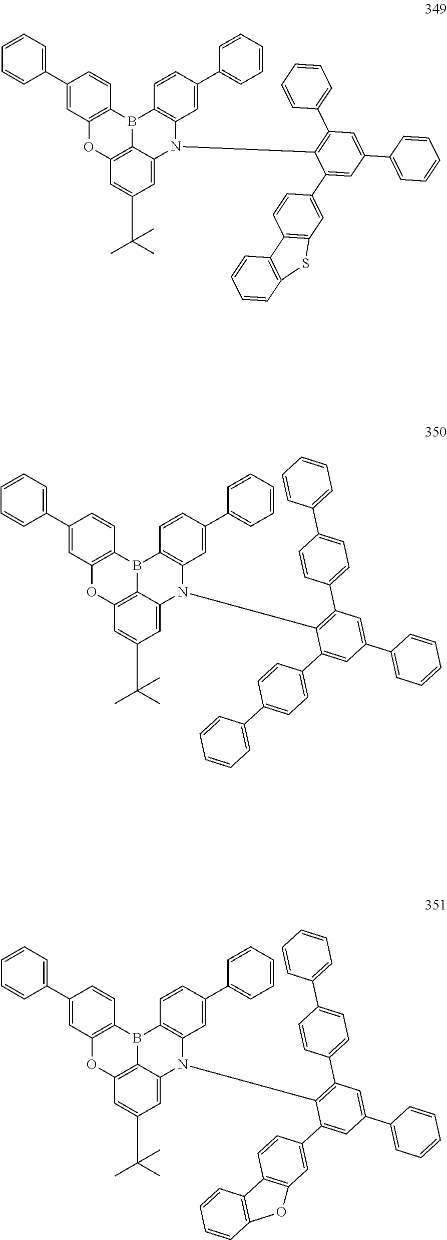 [SMILES: CC(C)(C)c1cc2c3c(c1)N(c1c(-c4ccccc4)cc(-c4ccccc4)cc1-c1ccc4c(c1)sc1ccccc14)c1cc(-c4ccccc4)ccc1B3c1ccc(-c3ccccc3)cc1O2 ; CC(C)(C)c1cc2c3c(c1)N(c1c(-c4ccc(-c5ccccc5)cc4)cc(-c4ccccc4)cc1-c1ccc(-c4ccccc4)cc1)c1cc(-c4ccccc4)ccc1B3c1ccc(-c3ccccc3)cc1O2 ; CC(C)(C)c1cc2c3c(c1)N(c1c(-c4ccc(-c5ccccc5)cc4)cc(-c4ccccc4)cc1-c1ccc4c(c1)oc1ccccc14)c1cc(-c4ccccc4)ccc1B3c1ccc(-c3ccccc3)cc1O2] 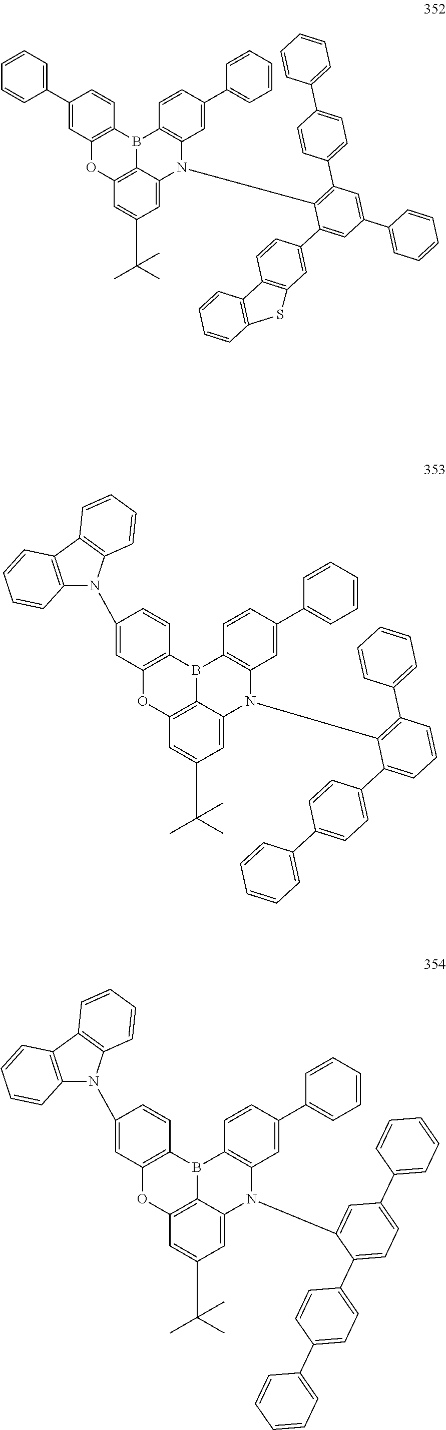 [SMILES: CC(C)(C)c1cc2c3c(c1)N(c1c(-c4ccc(-c5ccccc5)cc4)cc(-c4ccccc4)cc1-c1ccc4c(c1)sc1ccccc14)c1cc(-c4ccccc4)ccc1B3c1ccc(-c3ccccc3)cc1O2 ; CC(C)(C)c1cc2c3c(c1)N(c1c(-c4ccccc4)cccc1-c1ccc(-c4ccccc4)cc1)c1cc(-c4ccccc4)ccc1B3c1ccc(-n3c4ccccc4c4ccccc43)cc1O2 ; CC(C)(C)c1cc2c3c(c1)N(c1cc(-c4ccccc4)ccc1-c1ccc(-c4ccccc4)cc1)c1cc(-c4ccccc4)ccc1B3c1ccc(-n3c4ccccc4c4ccccc43)cc1O2] 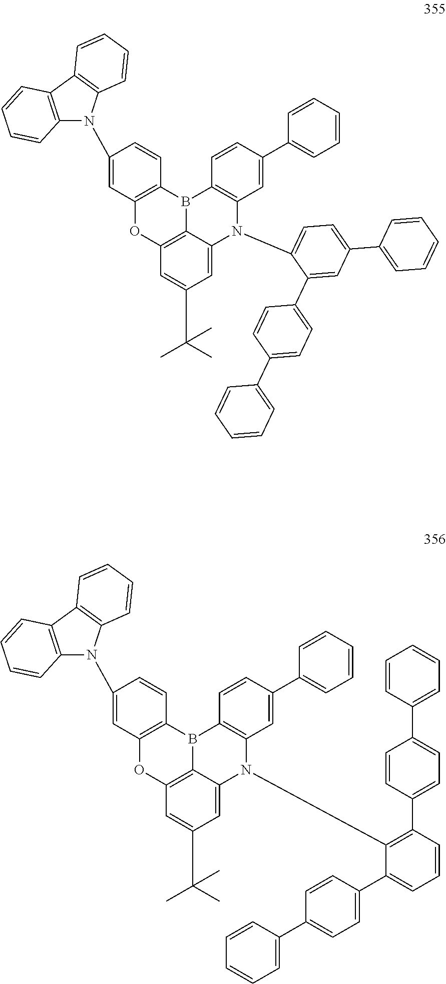 [SMILES: CC(C)(C)c1cc2c3c(c1)N(c1ccc(-c4ccccc4)cc1-c1ccc(-c4ccccc4)cc1)c1cc(-c4ccccc4)ccc1B3c1ccc(-n3c4ccccc4c4ccccc43)cc1O2 ; CC(C)(C)c1cc2c3c(c1)N(c1c(-c4ccc(-c5ccccc5)cc4)cccc1-c1ccc(-c4ccccc4)cc1)c1cc(-c4ccccc4)ccc1B3c1ccc(-n3c4ccccc4c4ccccc43)cc1O2] 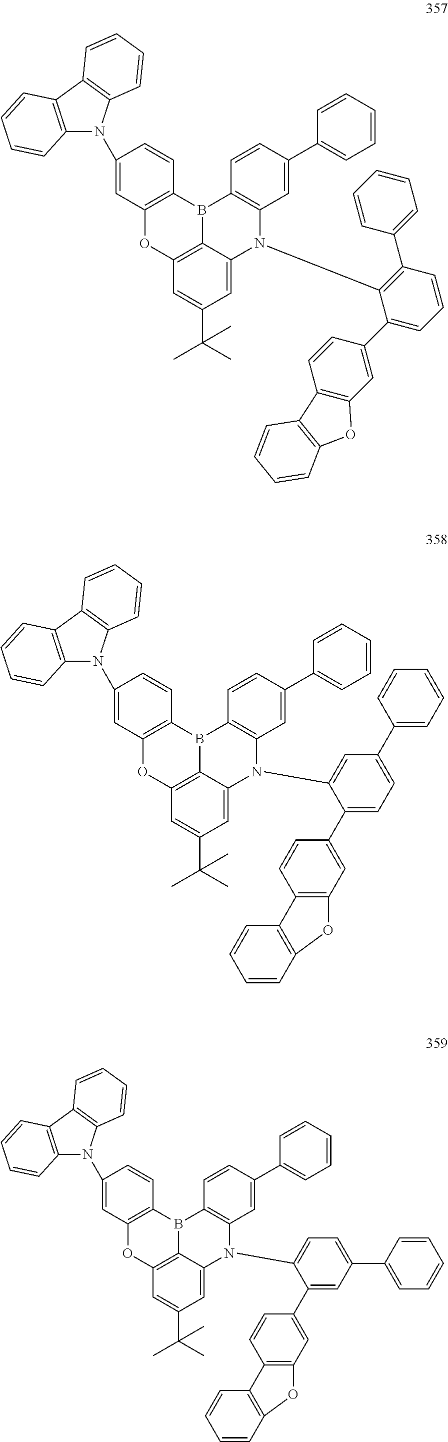 [SMILES: CC(C)(C)c1cc2c3c(c1)N(c1c(-c4ccccc4)cccc1-c1ccc4c(c1)oc1ccccc14)c1cc(-c4ccccc4)ccc1B3c1ccc(-n3c4ccccc4c4ccccc43)cc1O2 ; CC(C)(C)c1cc2c3c(c1)N(c1cc(-c4ccccc4)ccc1-c1ccc4c(c1)oc1ccccc14)c1cc(-c4ccccc4)ccc1B3c1ccc(-n3c4ccccc4c4ccccc43)cc1O2 ; CC(C)(C)c1cc2c3c(c1)N(c1ccc(-c4ccccc4)cc1-c1ccc4c(c1)oc1ccccc14)c1cc(-c4ccccc4)ccc1B3c1ccc(-n3c4ccccc4c4ccccc43)cc1O2] 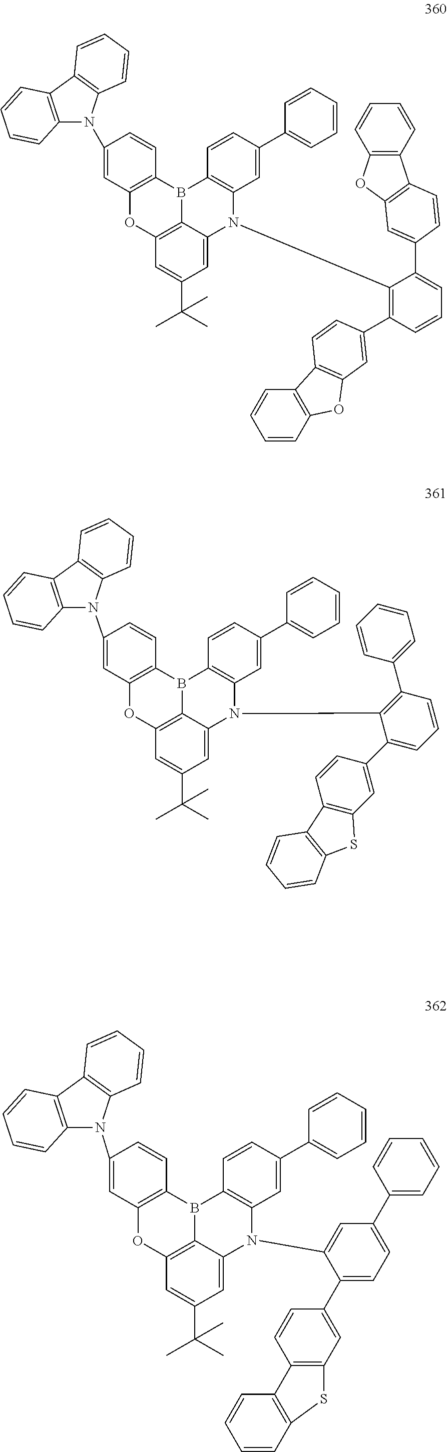 [SMILES: CC(C)(C)c1cc2c3c(c1)N(c1c(-c4ccc5c(c4)oc4ccccc45)cccc1-c1ccc4c(c1)oc1ccccc14)c1cc(-c4ccccc4)ccc1B3c1ccc(-n3c4ccccc4c4ccccc43)cc1O2 ; CC(C)(C)c1cc2c3c(c1)N(c1c(-c4ccccc4)cccc1-c1ccc4c(c1)sc1ccccc14)c1cc(-c4ccccc4)ccc1B3c1ccc(-n3c4ccccc4c4ccccc43)cc1O2 ; CC(C)(C)c1cc2c3c(c1)N(c1cc(-c4ccccc4)ccc1-c1ccc4c(c1)sc1ccccc14)c1cc(-c4ccccc4)ccc1B3c1ccc(-n3c4ccccc4c4ccccc43)cc1O2] 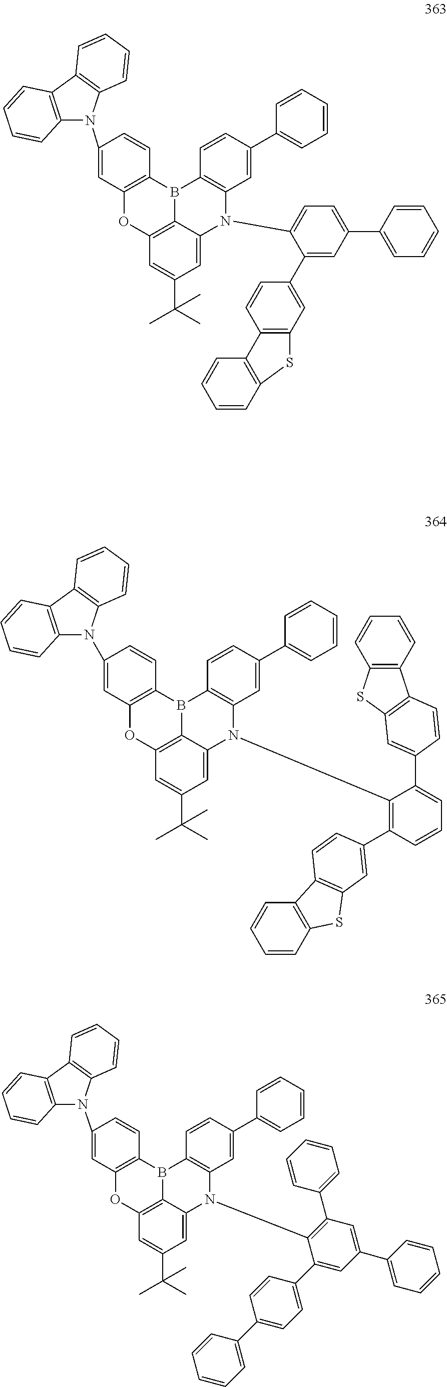 [SMILES: CC(C)(C)c1cc2c3c(c1)N(c1ccc(-c4ccccc4)cc1-c1ccc4c(c1)sc1ccccc14)c1cc(-c4ccccc4)ccc1B3c1ccc(-n3c4ccccc4c4ccccc43)cc1O2 ; CC(C)(C)c1cc2c3c(c1)N(c1c(-c4ccc5c(c4)sc4ccccc45)cccc1-c1ccc4c(c1)sc1ccccc14)c1cc(-c4ccccc4)ccc1B3c1ccc(-n3c4ccccc4c4ccccc43)cc1O2 ; CC(C)(C)c1cc2c3c(c1)N(c1c(-c4ccccc4)cc(-c4ccccc4)cc1-c1ccc(-c4ccccc4)cc1)c1cc(-c4ccccc4)ccc1B3c1ccc(-n3c4ccccc4c4ccccc43)cc1O2] 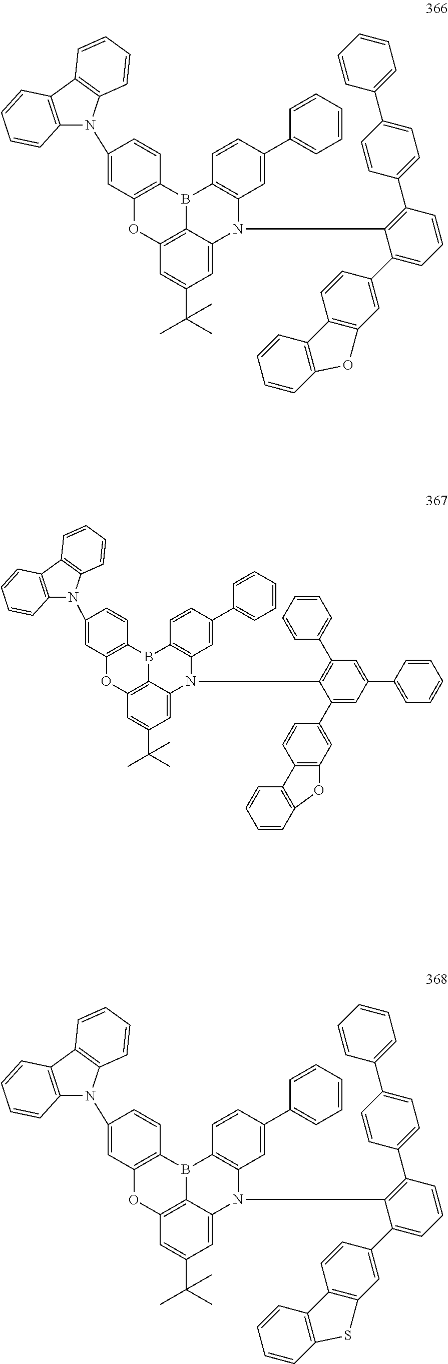 [SMILES: CC(C)(C)c1cc2c3c(c1)N(c1c(-c4ccc(-c5ccccc5)cc4)cccc1-c1ccc4c(c1)oc1ccccc14)c1cc(-c4ccccc4)ccc1B3c1ccc(-n3c4ccccc4c4ccccc43)cc1O2 ; CC(C)(C)c1cc2c3c(c1)N(c1c(-c4ccccc4)cc(-c4ccccc4)cc1-c1ccc4c(c1)oc1ccccc14)c1cc(-c4ccccc4)ccc1B3c1ccc(-n3c4ccccc4c4ccccc43)cc1O2 ; CC(C)(C)c1cc2c3c(c1)N(c1c(-c4ccc(-c5ccccc5)cc4)cccc1-c1ccc4c(c1)sc1ccccc14)c1cc(-c4ccccc4)ccc1B3c1ccc(-n3c4ccccc4c4ccccc43)cc1O2] 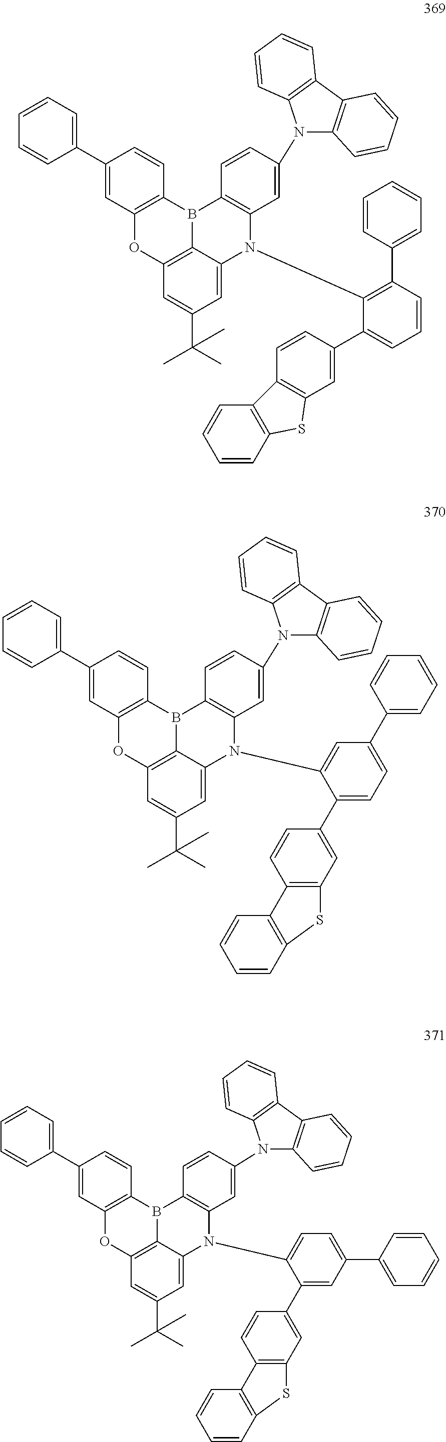 [SMILES: CC(C)(C)c1cc2c3c(c1)N(c1c(-c4ccccc4)cccc1-c1ccc4c(c1)sc1ccccc14)c1cc(-n4c5ccccc5c5ccccc54)ccc1B3c1ccc(-c3ccccc3)cc1O2 ; CC(C)(C)c1cc2c3c(c1)N(c1cc(-c4ccccc4)ccc1-c1ccc4c(c1)sc1ccccc14)c1cc(-n4c5ccccc5c5ccccc54)ccc1B3c1ccc(-c3ccccc3)cc1O2 ; CC(C)(C)c1cc2c3c(c1)N(c1ccc(-c4ccccc4)cc1-c1ccc4c(c1)sc1ccccc14)c1cc(-n4c5ccccc5c5ccccc54)ccc1B3c1ccc(-c3ccccc3)cc1O2] 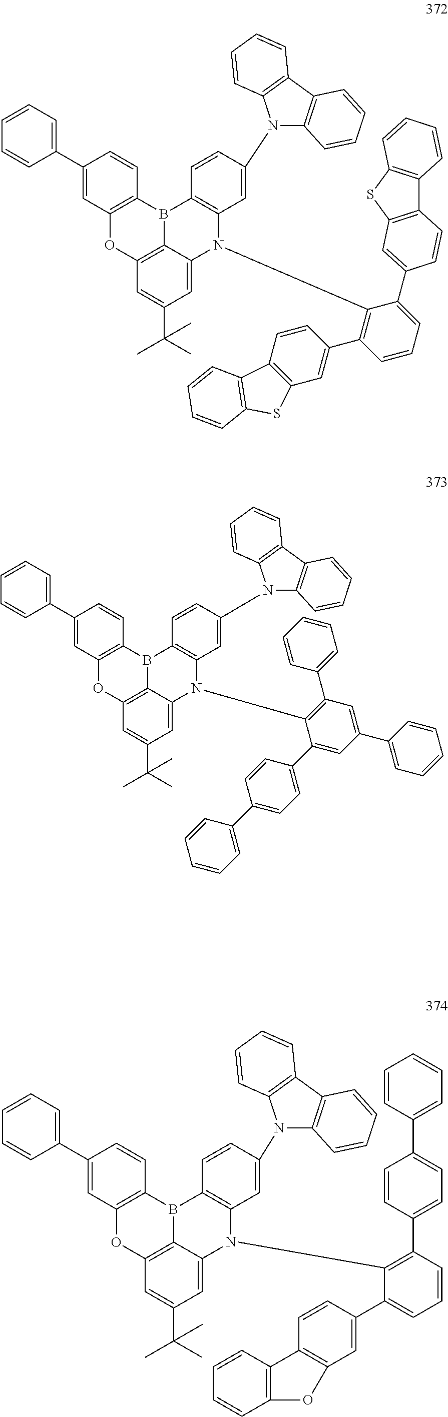 [SMILES: CC(C)(C)c1cc2c3c(c1)N(c1c(-c4ccc5c(c4)sc4ccccc45)cccc1-c1ccc4c(c1)sc1ccccc14)c1cc(-n4c5ccccc5c5ccccc54)ccc1B3c1ccc(-c3ccccc3)cc1O2 ; CC(C)(C)c1cc2c3c(c1)N(c1c(-c4ccccc4)cc(-c4ccccc4)cc1-c1ccc(-c4ccccc4)cc1)c1cc(-n4c5ccccc5c5ccccc54)ccc1B3c1ccc(-c3ccccc3)cc1O2 ; CC(C)(C)c1cc2c3c(c1)N(c1c(-c4ccc(-c5ccccc5)cc4)cccc1-c1ccc4c(c1)oc1ccccc14)c1cc(-n4c5ccccc5c5ccccc54)ccc1B3c1ccc(-c3ccccc3)cc1O2] 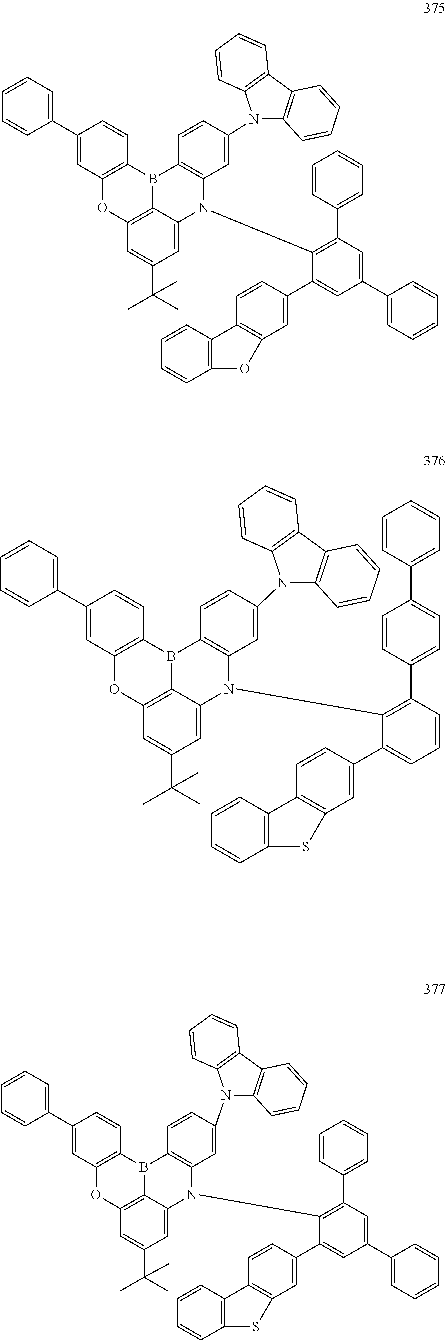 [SMILES: CC(C)(C)c1cc2c3c(c1)N(c1c(-c4ccccc4)cc(-c4ccccc4)cc1-c1ccc4c(c1)oc1ccccc14)c1cc(-n4c5ccccc5c5ccccc54)ccc1B3c1ccc(-c3ccccc3)cc1O2 ; CC(C)(C)c1cc2c3c(c1)N(c1c(-c4ccc(-c5ccccc5)cc4)cccc1-c1ccc4c(c1)sc1ccccc14)c1cc(-n4c5ccccc5c5ccccc54)ccc1B3c1ccc(-c3ccccc3)cc1O2 ; CC(C)(C)c1cc2c3c(c1)N(c1c(-c4ccccc4)cc(-c4ccccc4)cc1-c1ccc4c(c1)sc1ccccc14)c1cc(-n4c5ccccc5c5ccccc54)ccc1B3c1ccc(-c3ccccc3)cc1O2] 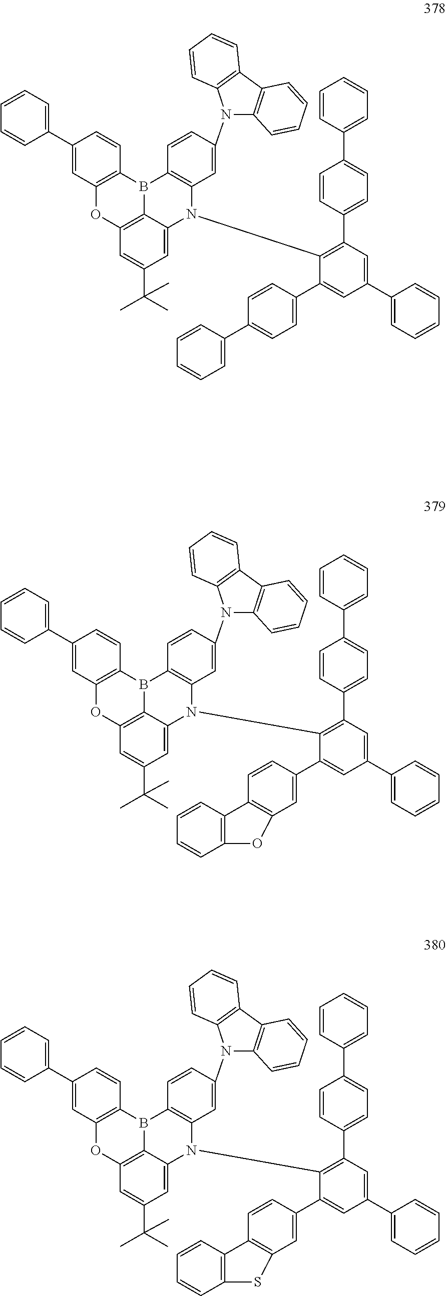 [SMILES: CC(C)(C)c1cc2c3c(c1)N(c1c(-c4ccc(-c5ccccc5)cc4)cc(-c4ccccc4)cc1-c1ccc(-c4ccccc4)cc1)c1cc(-n4c5ccccc5c5ccccc54)ccc1B3c1ccc(-c3ccccc3)cc1O2 ; CC(C)(C)c1cc2c3c(c1)N(c1c(-c4ccc(-c5ccccc5)cc4)cc(-c4ccccc4)cc1-c1ccc4c(c1)oc1ccccc14)c1cc(-n4c5ccccc5c5ccccc54)ccc1B3c1ccc(-c3ccccc3)cc1O2 ; CC(C)(C)c1cc2c3c(c1)N(c1c(-c4ccc(-c5ccccc5)cc4)cc(-c4ccccc4)cc1-c1ccc4c(c1)sc1ccccc14)c1cc(-n4c5ccccc5c5ccccc54)ccc1B3c1ccc(-c3ccccc3)cc1O2] 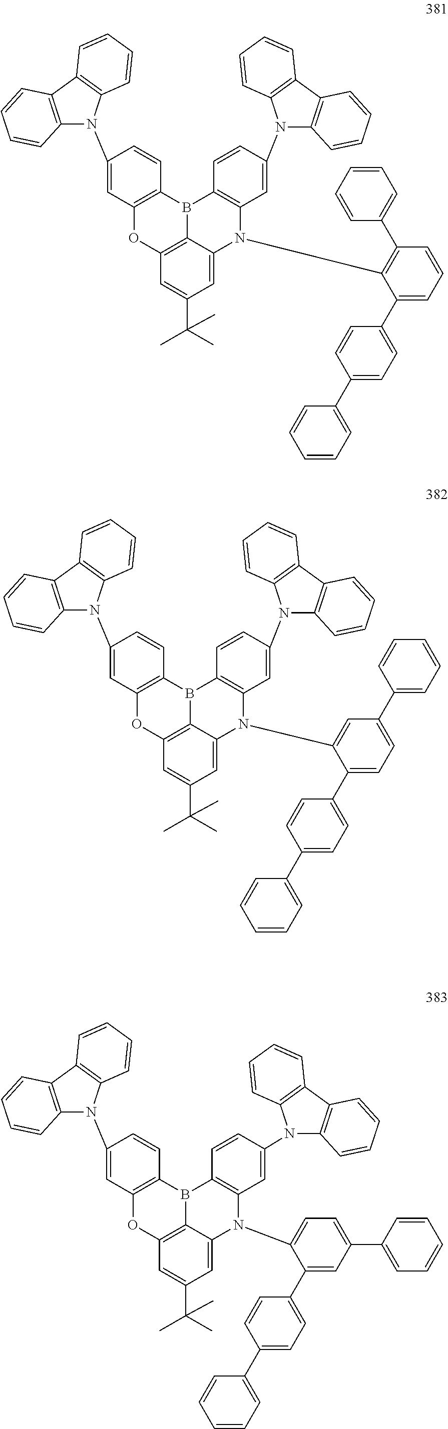 [SMILES: CC(C)(C)c1cc2c3c(c1)N(c1c(-c4ccccc4)cccc1-c1ccc(-c4ccccc4)cc1)c1cc(-n4c5ccccc5c5ccccc54)ccc1B3c1ccc(-n3c4ccccc4c4ccccc43)cc1O2 ; CC(C)(C)c1cc2c3c(c1)N(c1cc(-c4ccccc4)ccc1-c1ccc(-c4ccccc4)cc1)c1cc(-n4c5ccccc5c5ccccc54)ccc1B3c1ccc(-n3c4ccccc4c4ccccc43)cc1O2 ; CC(C)(C)c1cc2c3c(c1)N(c1ccc(-c4ccccc4)cc1-c1ccc(-c4ccccc4)cc1)c1cc(-n4c5ccccc5c5ccccc54)ccc1B3c1ccc(-n3c4ccccc4c4ccccc43)cc1O2] 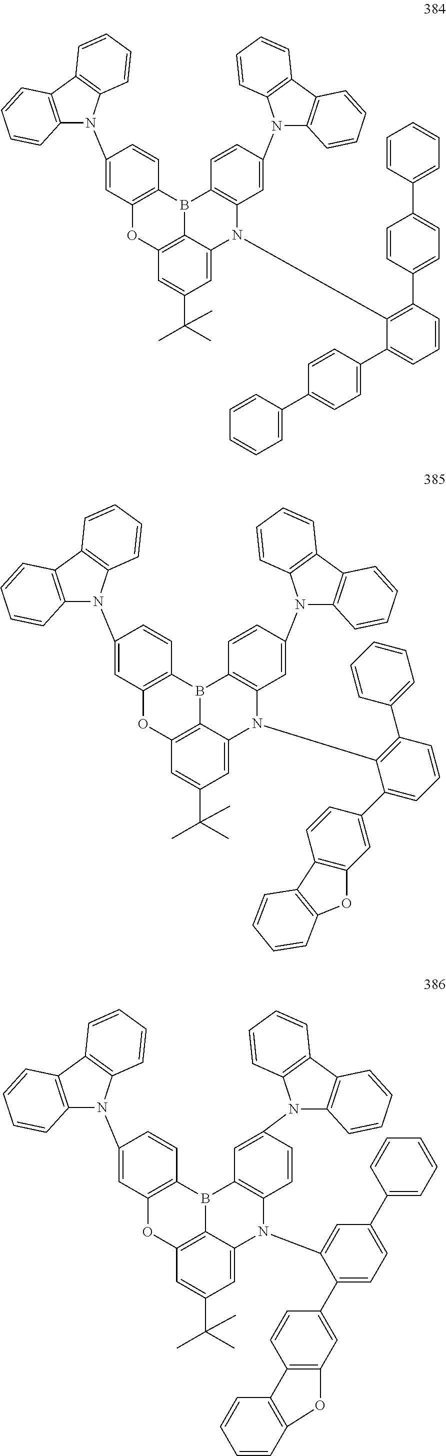 [SMILES: CC(C)(C)c1cc2c3c(c1)N(c1c(-c4ccc(-c5ccccc5)cc4)cccc1-c1ccc(-c4ccccc4)cc1)c1cc(-n4c5ccccc5c5ccccc54)ccc1B3c1ccc(-n3c4ccccc4c4ccccc43)cc1O2 ; CC(C)(C)c1cc2c3c(c1)N(c1c(-c4ccccc4)cccc1-c1ccc4c(c1)oc1ccccc14)c1cc(-n4c5ccccc5c5ccccc54)ccc1B3c1ccc(-n3c4ccccc4c4ccccc43)cc1O2 ; CC(C)(C)c1cc2c3c(c1)N(c1cc(-c4ccccc4)ccc1-c1ccc4c(c1)oc1ccccc14)c1ccc(-n4c5ccccc5c5ccccc54)cc1B3c1ccc(-n3c4ccccc4c4ccccc43)cc1O2] 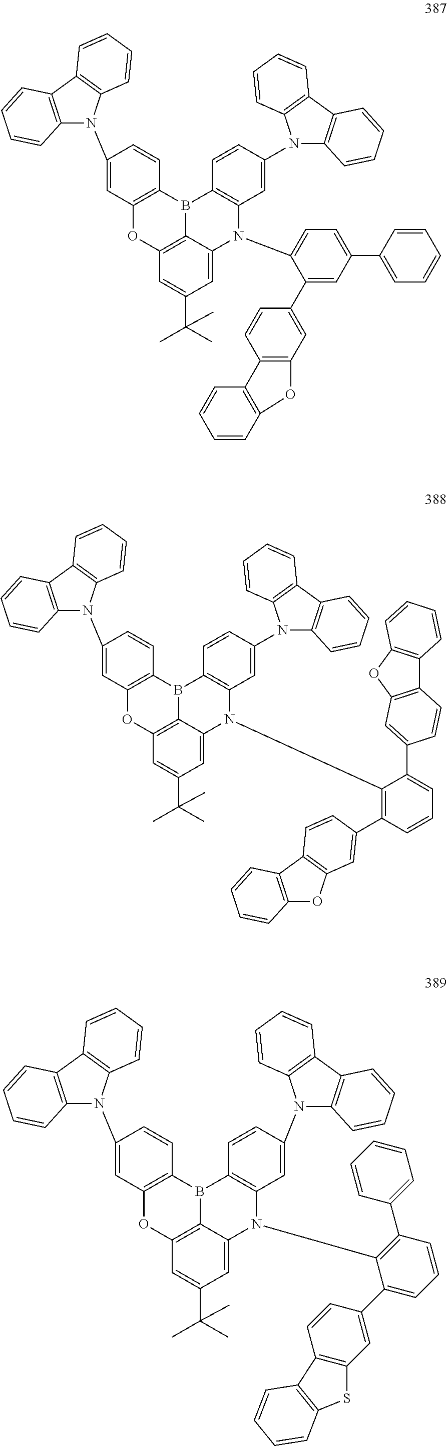 [SMILES: CC(C)(C)c1cc2c3c(c1)N(c1ccc(-c4ccccc4)cc1-c1ccc4c(c1)oc1ccccc14)c1cc(-n4c5ccccc5c5ccccc54)ccc1B3c1ccc(-n3c4ccccc4c4ccccc43)cc1O2 ; CC(C)(C)c1cc2c3c(c1)N(c1c(-c4ccc5c(c4)oc4ccccc45)cccc1-c1ccc4c(c1)oc1ccccc14)c1cc(-n4c5ccccc5c5ccccc54)ccc1B3c1ccc(-n3c4ccccc4c4ccccc43)cc1O2 ; CC(C)(C)c1cc2c3c(c1)N(c1c(-c4ccccc4)cccc1-c1ccc4c(c1)sc1ccccc14)c1cc(-n4c5ccccc5c5ccccc54)ccc1B3c1ccc(-n3c4ccccc4c4ccccc43)cc1O2] 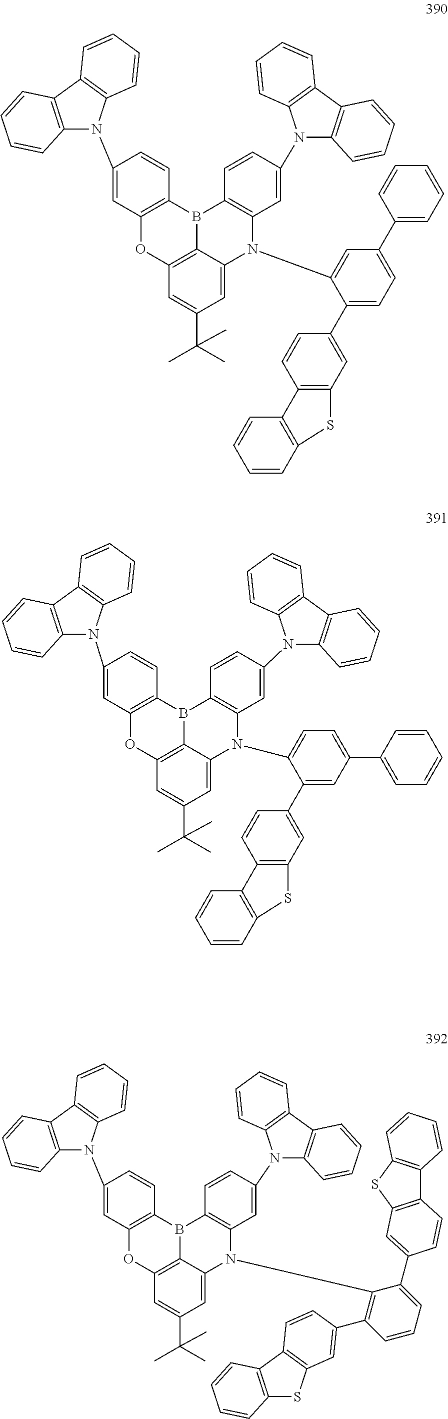 [SMILES: CC(C)(C)c1cc2c3c(c1)N(c1cc(-c4ccccc4)ccc1-c1ccc4c(c1)sc1ccccc14)c1cc(-n4c5ccccc5c5ccccc54)ccc1B3c1ccc(-n3c4ccccc4c4ccccc43)cc1O2 ; CC(C)(C)c1cc2c3c(c1)N(c1ccc(-c4ccccc4)cc1-c1ccc4c(c1)sc1ccccc14)c1cc(-n4c5ccccc5c5ccccc54)ccc1B3c1ccc(-n3c4ccccc4c4ccccc43)cc1O2 ; CC(C)(C)c1cc2c3c(c1)N(c1c(-c4ccc5c(c4)sc4ccccc45)cccc1-c1ccc4c(c1)sc1ccccc14)c1cc(-n4c5ccccc5c5ccccc54)ccc1B3c1ccc(-n3c4ccccc4c4ccccc43)cc1O2] 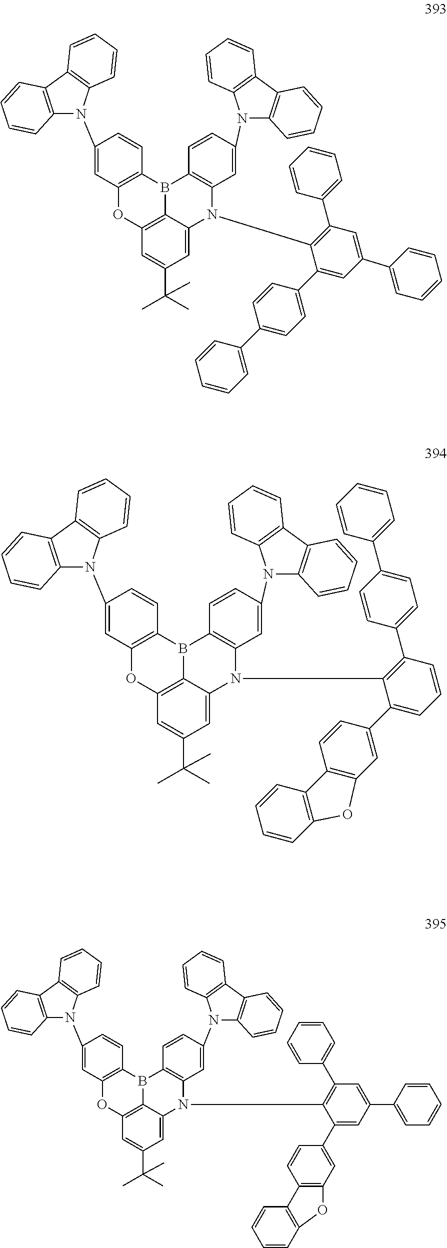 [SMILES: CC(C)(C)c1cc2c3c(c1)N(c1c(-c4ccccc4)cc(-c4ccccc4)cc1-c1ccc(-c4ccccc4)cc1)c1cc(-n4c5ccccc5c5ccccc54)ccc1B3c1ccc(-n3c4ccccc4c4ccccc43)cc1O2 ; CC(C)(C)c1cc2c3c(c1)N(c1c(-c4ccc(-c5ccccc5)cc4)cccc1-c1ccc4c(c1)oc1ccccc14)c1cc(-n4c5ccccc5c5ccccc54)ccc1B3c1ccc(-n3c4ccccc4c4ccccc43)cc1O2 ; CC(C)(C)c1cc2c3c(c1)N(c1c(-c4ccccc4)cc(-c4ccccc4)cc1-c1ccc4c(c1)oc1ccccc14)c1cc(-n4c5ccccc5c5ccccc54)ccc1B3c1ccc(-n3c4ccccc4c4ccccc43)cc1O2] 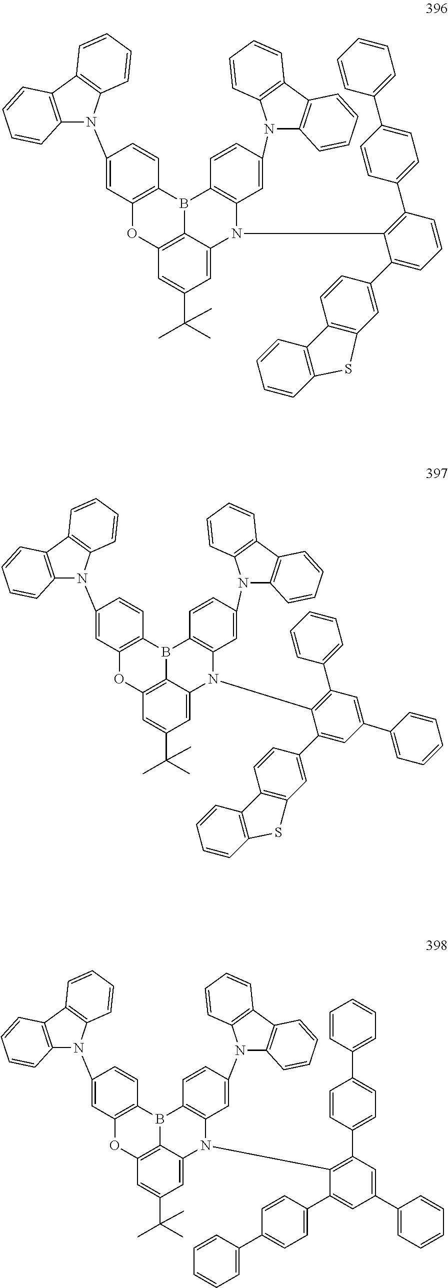 [SMILES: CC(C)(C)c1cc2c3c(c1)N(c1c(-c4ccc(-c5ccccc5)cc4)cccc1-c1ccc4c(c1)sc1ccccc14)c1cc(-n4c5ccccc5c5ccccc54)ccc1B3c1ccc(-n3c4ccccc4c4ccccc43)cc1O2 ; CC(C)(C)c1cc2c3c(c1)N(c1c(-c4ccccc4)cc(-c4ccccc4)cc1-c1ccc4c(c1)sc1ccccc14)c1cc(-n4c5ccccc5c5ccccc54)ccc1B3c1ccc(-n3c4ccccc4c4ccccc43)cc1O2 ; CC(C)(C)c1cc2c3c(c1)N(c1c(-c4ccc(-c5ccccc5)cc4)cc(-c4ccccc4)cc1-c1ccc(-c4ccccc4)cc1)c1cc(-n4c5ccccc5c5ccccc54)ccc1B3c1ccc(-n3c4ccccc4c4ccccc43)cc1O2] 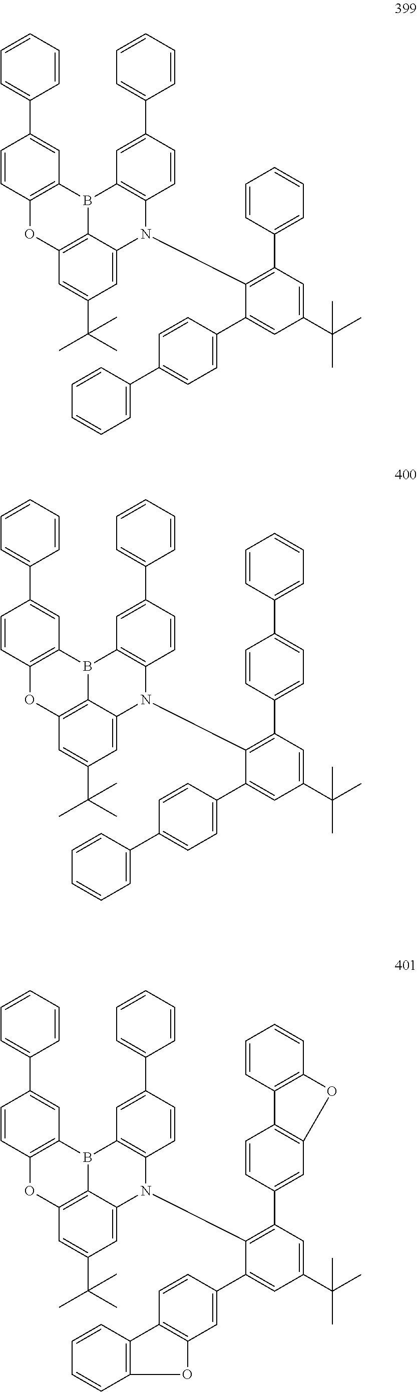 [SMILES: CC(C)(C)c1cc(-c2ccccc2)c(N2c3ccc(-c4ccccc4)cc3B3c4cc(-c5ccccc5)ccc4Oc4cc(C(C)(C)C)cc2c43)c(-c2ccc(-c3ccccc3)cc2)c1 ; CC(C)(C)c1cc(-c2ccc(-c3ccccc3)cc2)c(N2c3ccc(-c4ccccc4)cc3B3c4cc(-c5ccccc5)ccc4Oc4cc(C(C)(C)C)cc2c43)c(-c2ccc(-c3ccccc3)cc2)c1 ; CC(C)(C)c1cc(-c2ccc3c(c2)oc2ccccc23)c(N2c3ccc(-c4ccccc4)cc3B3c4cc(-c5ccccc5)ccc4Oc4cc(C(C)(C)C)cc2c43)c(-c2ccc3c(c2)oc2ccccc23)c1] 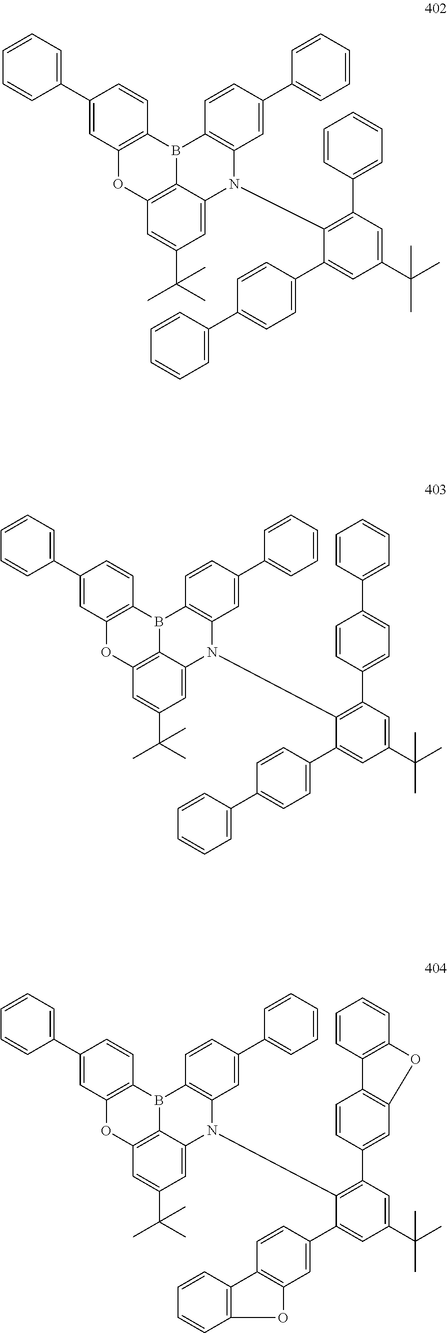 [SMILES: CC(C)(C)c1cc(-c2ccccc2)c(N2c3cc(-c4ccccc4)ccc3B3c4ccc(-c5ccccc5)cc4Oc4cc(C(C)(C)C)cc2c43)c(-c2ccc(-c3ccccc3)cc2)c1 ; CC(C)(C)c1cc(-c2ccc(-c3ccccc3)cc2)c(N2c3cc(-c4ccccc4)ccc3B3c4ccc(-c5ccccc5)cc4Oc4cc(C(C)(C)C)cc2c43)c(-c2ccc(-c3ccccc3)cc2)c1 ; CC(C)(C)c1cc(-c2ccc3c(c2)oc2ccccc23)c(N2c3cc(-c4ccccc4)ccc3B3c4ccc(-c5ccccc5)cc4Oc4cc(C(C)(C)C)cc2c43)c(-c2ccc3c(c2)oc2ccccc23)c1] 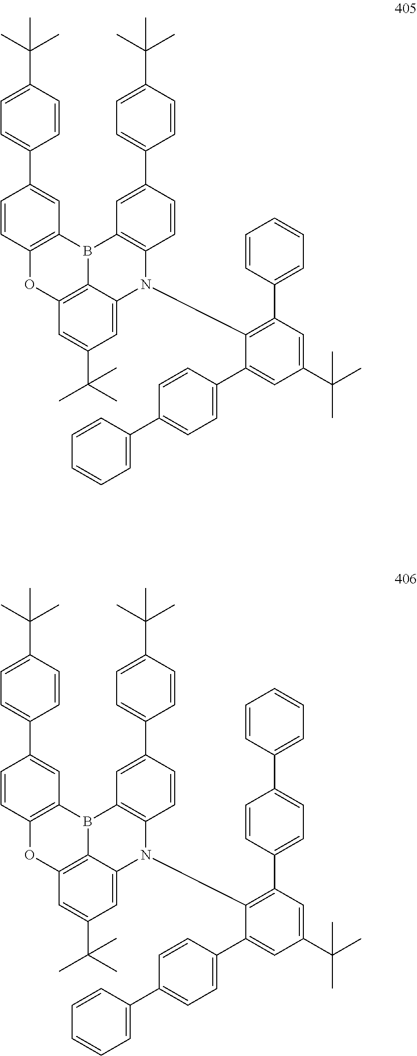 [SMILES: CC(C)(C)c1ccc(-c2ccc3c(c2)B2c4cc(-c5ccc(C(C)(C)C)cc5)ccc4N(c4c(-c5ccccc5)cc(C(C)(C)C)cc4-c4ccc(-c5ccccc5)cc4)c4cc(C(C)(C)C)cc(c42)O3)cc1 ; CC(C)(C)c1ccc(-c2ccc3c(c2)B2c4cc(-c5ccc(C(C)(C)C)cc5)ccc4N(c4c(-c5ccc(-c6ccccc6)cc5)cc(C(C)(C)C)cc4-c4ccc(-c5ccccc5)cc4)c4cc(C(C)(C)C)cc(c42)O3)cc1] 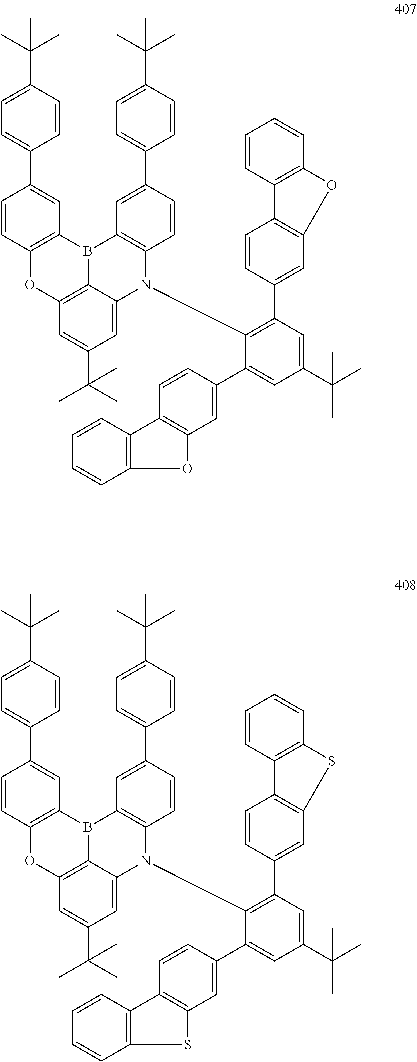 [SMILES: CC(C)(C)c1ccc(-c2ccc3c(c2)B2c4cc(-c5ccc(C(C)(C)C)cc5)ccc4N(c4c(-c5ccc6c(c5)oc5ccccc56)cc(C(C)(C)C)cc4-c4ccc5c(c4)oc4ccccc45)c4cc(C(C)(C)C)cc(c42)O3)cc1 ; CC(C)(C)c1ccc(-c2ccc3c(c2)B2c4cc(-c5ccc(C(C)(C)C)cc5)ccc4N(c4c(-c5ccc6c(c5)sc5ccccc56)cc(C(C)(C)C)cc4-c4ccc5c(c4)sc4ccccc45)c4cc(C(C)(C)C)cc(c42)O3)cc1] 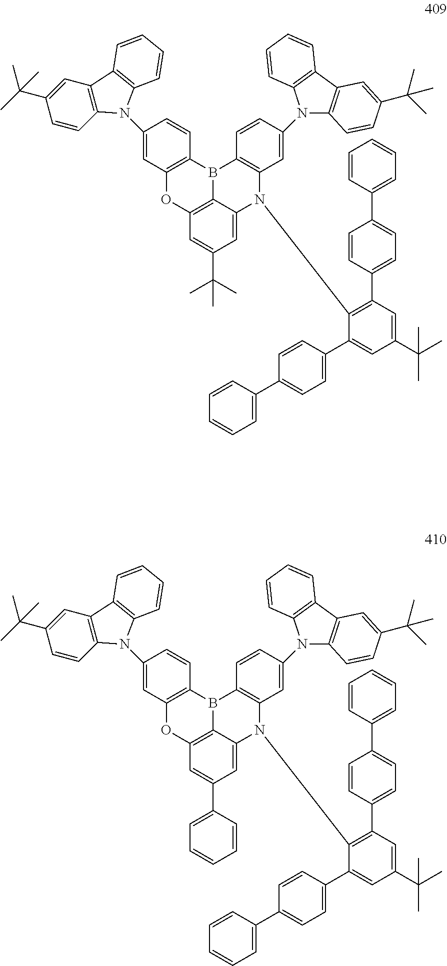 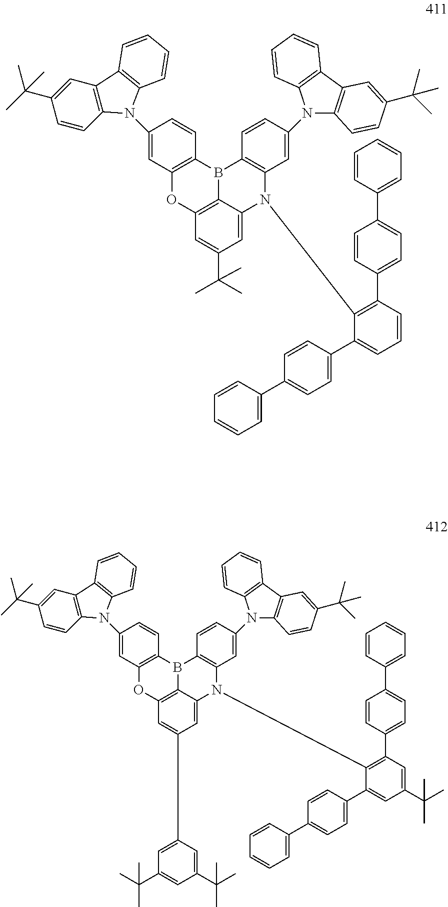 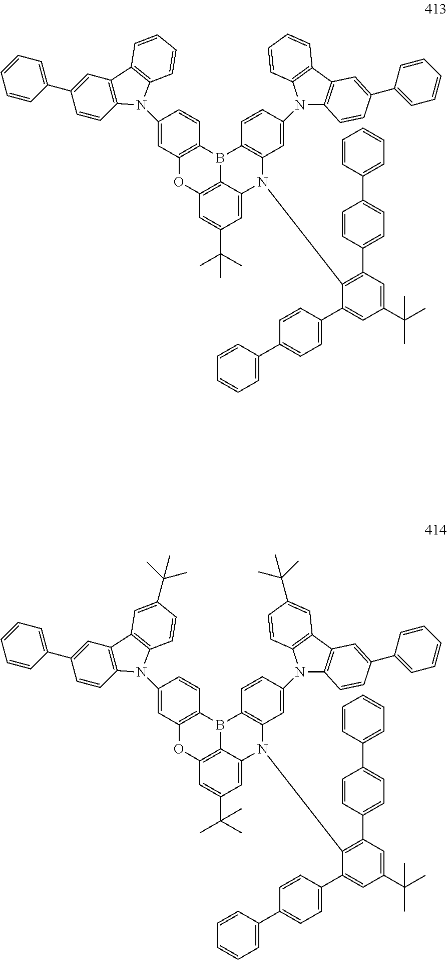 [SMILES: CC(C)(C)c1cc(-c2ccc(-c3ccccc3)cc2)c(N2c3cc(-n4c5ccccc5c5cc(-c6ccccc6)ccc54)ccc3B3c4ccc(-n5c6ccccc6c6cc(-c7ccccc7)ccc65)cc4Oc4cc(C(C)(C)C)cc2c43)c(-c2ccc(-c3ccccc3)cc2)c1 ; CC(C)(C)c1cc(-c2ccc(-c3ccccc3)cc2)c(N2c3cc(-n4c5ccc(-c6ccccc6)cc5c5cc(C(C)(C)C)ccc54)ccc3B3c4ccc(-n5c6ccc(-c7ccccc7)cc6c6cc(C(C)(C)C)ccc65)cc4Oc4cc(C(C)(C)C)cc2c43)c(-c2ccc(-c3ccccc3)cc2)c1] 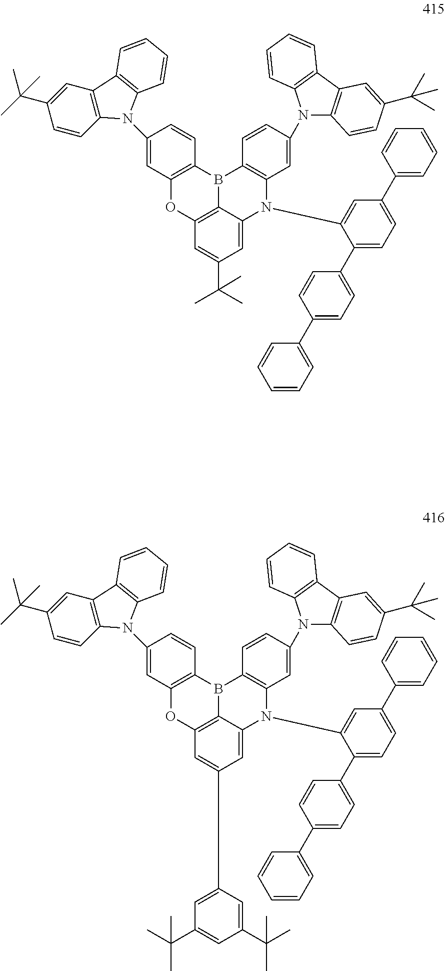 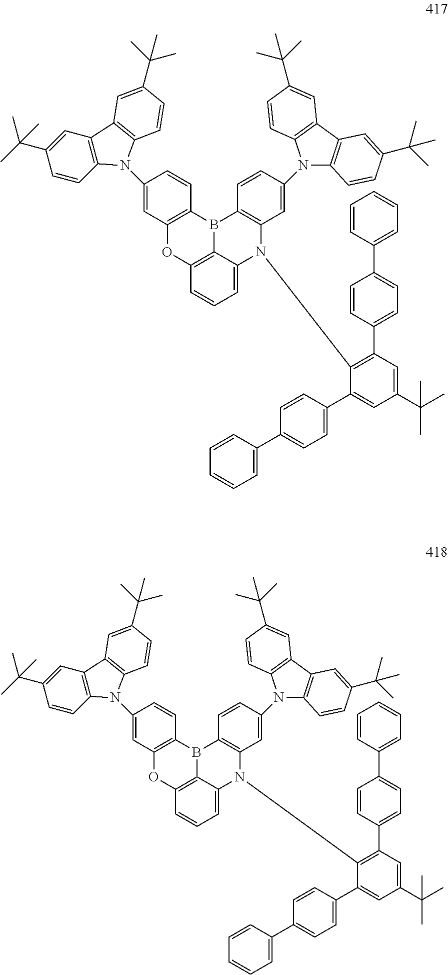 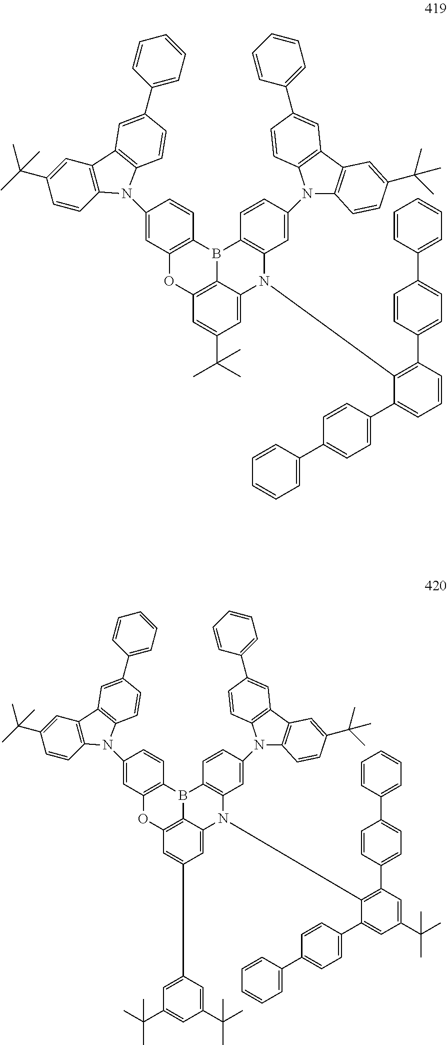 [SMILES: CC(C)(C)c1cc2c3c(c1)N(c1c(-c4ccc(-c5ccccc5)cc4)cccc1-c1ccc(-c4ccccc4)cc1)c1cc(-n4c5ccc(-c6ccccc6)cc5c5cc(C(C)(C)C)ccc54)ccc1B3c1ccc(-n3c4ccc(-c5ccccc5)cc4c4cc(C(C)(C)C)ccc43)cc1O2 ; CC(C)(C)c1cc(-c2cc3c4c(c2)N(c2c(-c5ccc(-c6ccccc6)cc5)cc(C(C)(C)C)cc2-c2ccc(-c5ccccc5)cc2)c2cc(-n5c6ccc(-c7ccccc7)cc6c6cc(C(C)(C)C)ccc65)ccc2B4c2ccc(-n4c5ccc(-c6ccccc6)cc5c5cc(C(C)(C)C)ccc54)cc2O3)cc(C(C)(C)C)c1] 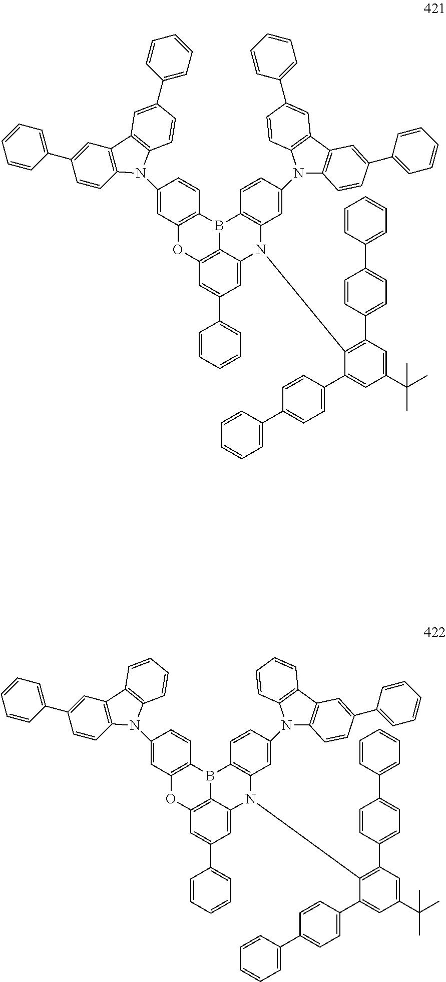 [SMILES: CC(C)(C)c1cc(-c2ccc(-c3ccccc3)cc2)c(N2c3cc(-n4c5ccc(-c6ccccc6)cc5c5cc(-c6ccccc6)ccc54)ccc3B3c4ccc(-n5c6ccc(-c7ccccc7)cc6c6cc(-c7ccccc7)ccc65)cc4Oc4cc(-c5ccccc5)cc2c43)c(-c2ccc(-c3ccccc3)cc2)c1 ; CC(C)(C)c1cc(-c2ccc(-c3ccccc3)cc2)c(N2c3cc(-n4c5ccccc5c5cc(-c6ccccc6)ccc54)ccc3B3c4ccc(-n5c6ccccc6c6cc(-c7ccccc7)ccc65)cc4Oc4cc(-c5ccccc5)cc2c43)c(-c2ccc(-c3ccccc3)cc2)c1] 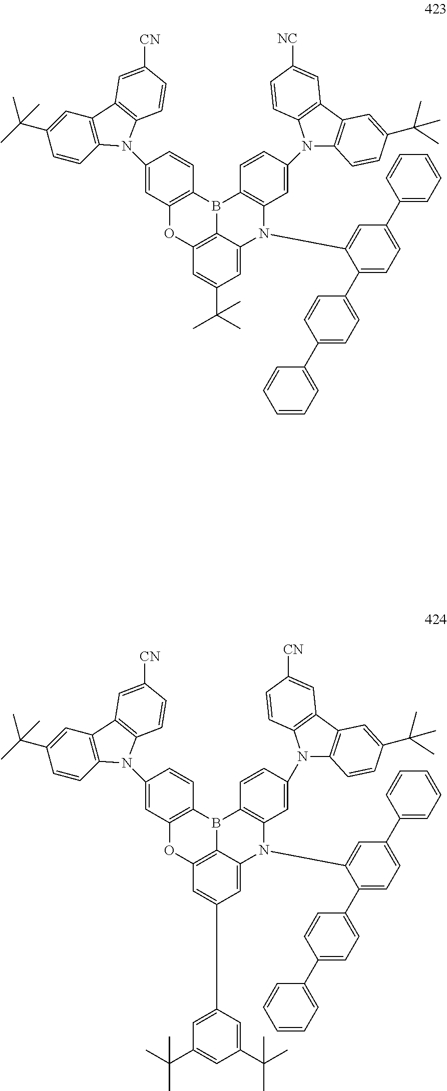 [SMILES: CC(C)(C)c1cc2c3c(c1)N(c1cc(-c4ccccc4)ccc1-c1ccc(-c4ccccc4)cc1)c1cc(-n4c5ccc(C#N)cc5c5cc(C(C)(C)C)ccc54)ccc1B3c1ccc(-n3c4ccc(C#N)cc4c4cc(C(C)(C)C)ccc43)cc1O2 ; CC(C)(C)c1cc(-c2cc3c4c(c2)N(c2cc(-c5ccccc5)ccc2-c2ccc(-c5ccccc5)cc2)c2cc(-n5c6ccc(C#N)cc6c6cc(C(C)(C)C)ccc65)ccc2B4c2ccc(-n4c5ccc(C#N)cc5c5cc(C(C)(C)C)ccc54)cc2O3)cc(C(C)(C)C)c1] 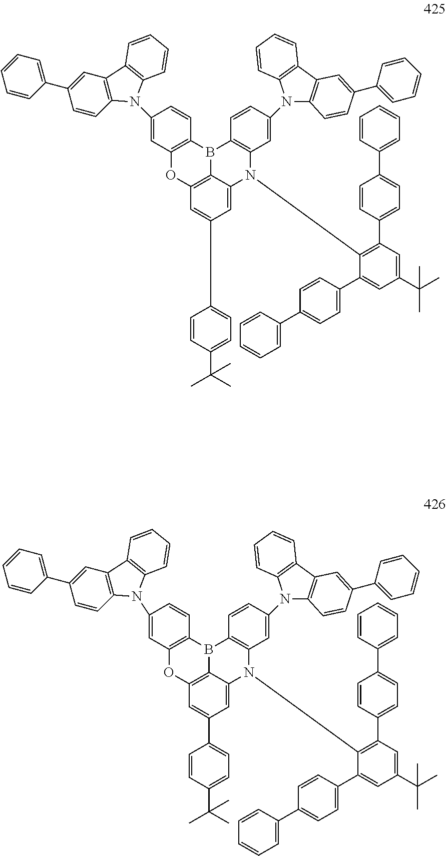 [SMILES: CC(C)(C)c1ccc(-c2cc3c4c(c2)N(c2c(-c5ccc(-c6ccccc6)cc5)cc(C(C)(C)C)cc2-c2ccc(-c5ccccc5)cc2)c2cc(-n5c6ccccc6c6cc(-c7ccccc7)ccc65)ccc2B4c2ccc(-n4c5ccccc5c5cc(-c6ccccc6)ccc54)cc2O3)cc1 ; CC(C)(C)c1ccc(-c2cc3c4c(c2)N(c2c(-c5ccc(-c6ccccc6)cc5)cc(C(C)(C)C)cc2-c2ccc(-c5ccccc5)cc2)c2cc(-n5c6ccccc6c6cc(-c7ccccc7)ccc65)ccc2B4c2ccc(-n4c5ccccc5c5cc(-c6ccccc6)ccc54)cc2O3)cc1] 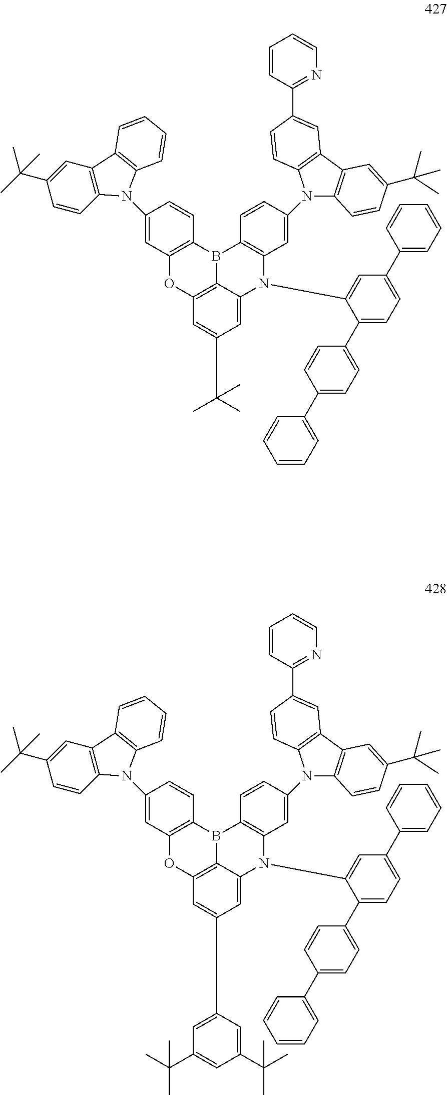 [SMILES: CC(C)(C)c1cc2c3c(c1)N(c1cc(-c4ccccc4)ccc1-c1ccc(-c4ccccc4)cc1)c1cc(-n4c5ccc(-c6ccccn6)cc5c5cc(C(C)(C)C)ccc54)ccc1B3c1ccc(-n3c4ccccc4c4cc(C(C)(C)C)ccc43)cc1O2 ; CC(C)(C)c1cc(-c2cc3c4c(c2)N(c2cc(-c5ccccc5)ccc2-c2ccc(-c5ccccc5)cc2)c2cc(-n5c6ccc(-c7ccccn7)cc6c6cc(C(C)(C)C)ccc65)ccc2B4c2ccc(-n4c5ccccc5c5cc(C(C)(C)C)ccc54)cc2O3)cc(C(C)(C)C)c1] 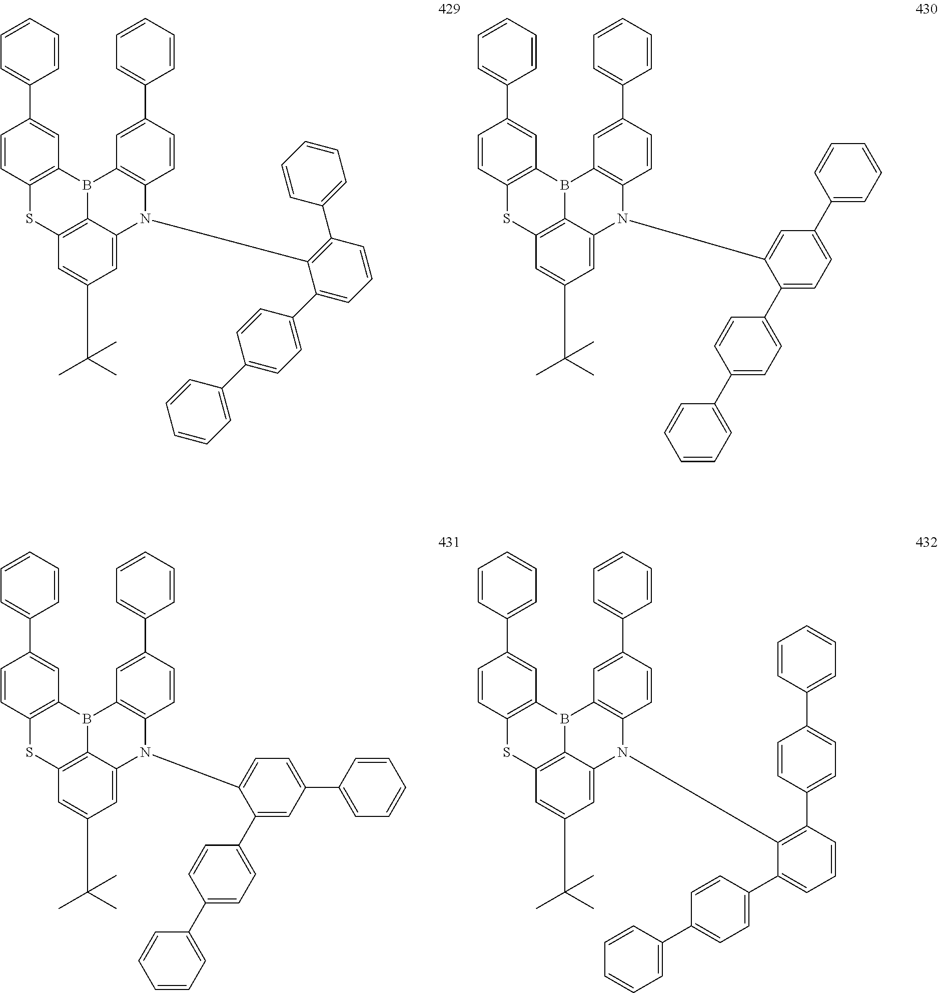 [SMILES: CC(C)(C)c1cc2c3c(c1)N(c1c(-c4ccccc4)cccc1-c1ccc(-c4ccccc4)cc1)c1ccc(-c4ccccc4)cc1B3c1cc(-c3ccccc3)ccc1S2 ; CC(C)(C)c1cc2c3c(c1)N(c1cc(-c4ccccc4)ccc1-c1ccc(-c4ccccc4)cc1)c1ccc(-c4ccccc4)cc1B3c1cc(-c3ccccc3)ccc1S2 ; CC(C)(C)c1cc2c3c(c1)N(c1ccc(-c4ccccc4)cc1-c1ccc(-c4ccccc4)cc1)c1ccc(-c4ccccc4)cc1B3c1cc(-c3ccccc3)ccc1S2 ; CC(C)(C)c1cc2c3c(c1)N(c1c(-c4ccc(-c5ccccc5)cc4)cccc1-c1ccc(-c4ccccc4)cc1)c1ccc(-c4ccccc4)cc1B3c1cc(-c3ccccc3)ccc1S2] 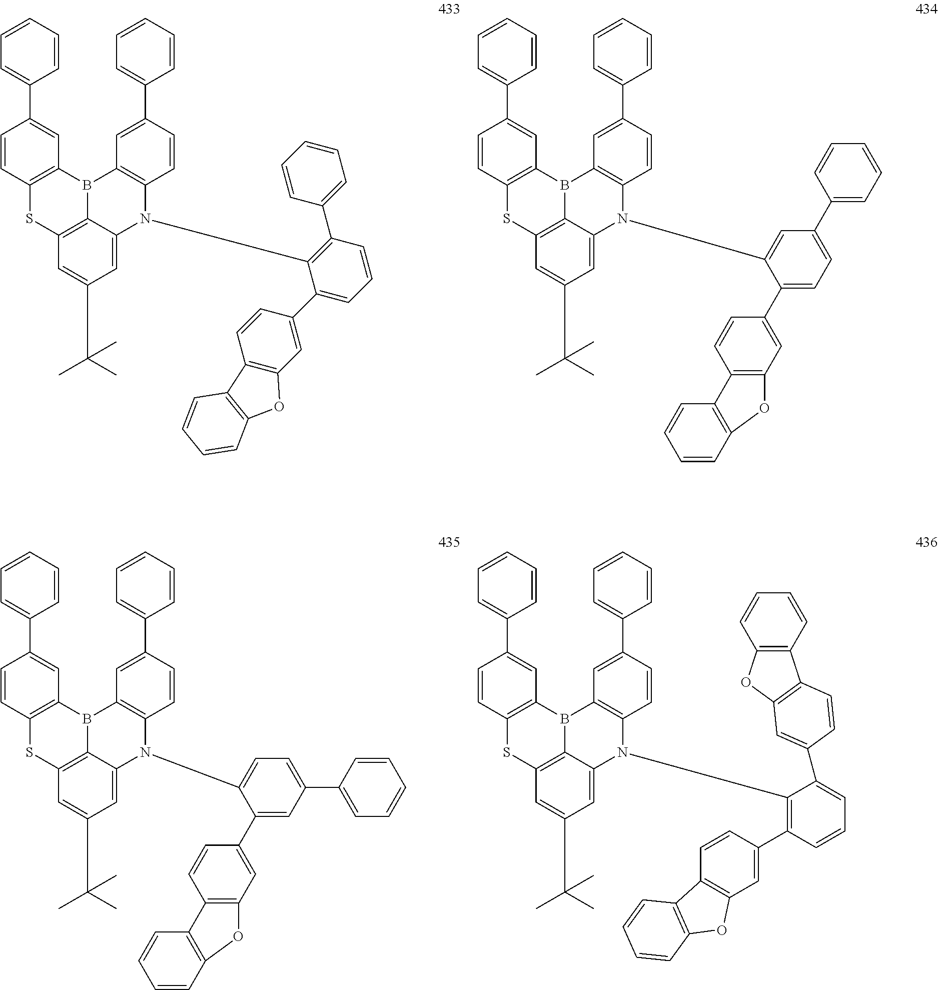 [SMILES: CC(C)(C)c1cc2c3c(c1)N(c1c(-c4ccccc4)cccc1-c1ccc4c(c1)oc1ccccc14)c1ccc(-c4ccccc4)cc1B3c1cc(-c3ccccc3)ccc1S2 ; CC(C)(C)c1cc2c3c(c1)N(c1cc(-c4ccccc4)ccc1-c1ccc4c(c1)oc1ccccc14)c1ccc(-c4ccccc4)cc1B3c1cc(-c3ccccc3)ccc1S2 ; CC(C)(C)c1cc2c3c(c1)N(c1ccc(-c4ccccc4)cc1-c1ccc4c(c1)oc1ccccc14)c1ccc(-c4ccccc4)cc1B3c1cc(-c3ccccc3)ccc1S2 ; CC(C)(C)c1cc2c3c(c1)N(c1c(-c4ccc5c(c4)oc4ccccc45)cccc1-c1ccc4c(c1)oc1ccccc14)c1ccc(-c4ccccc4)cc1B3c1cc(-c3ccccc3)ccc1S2] 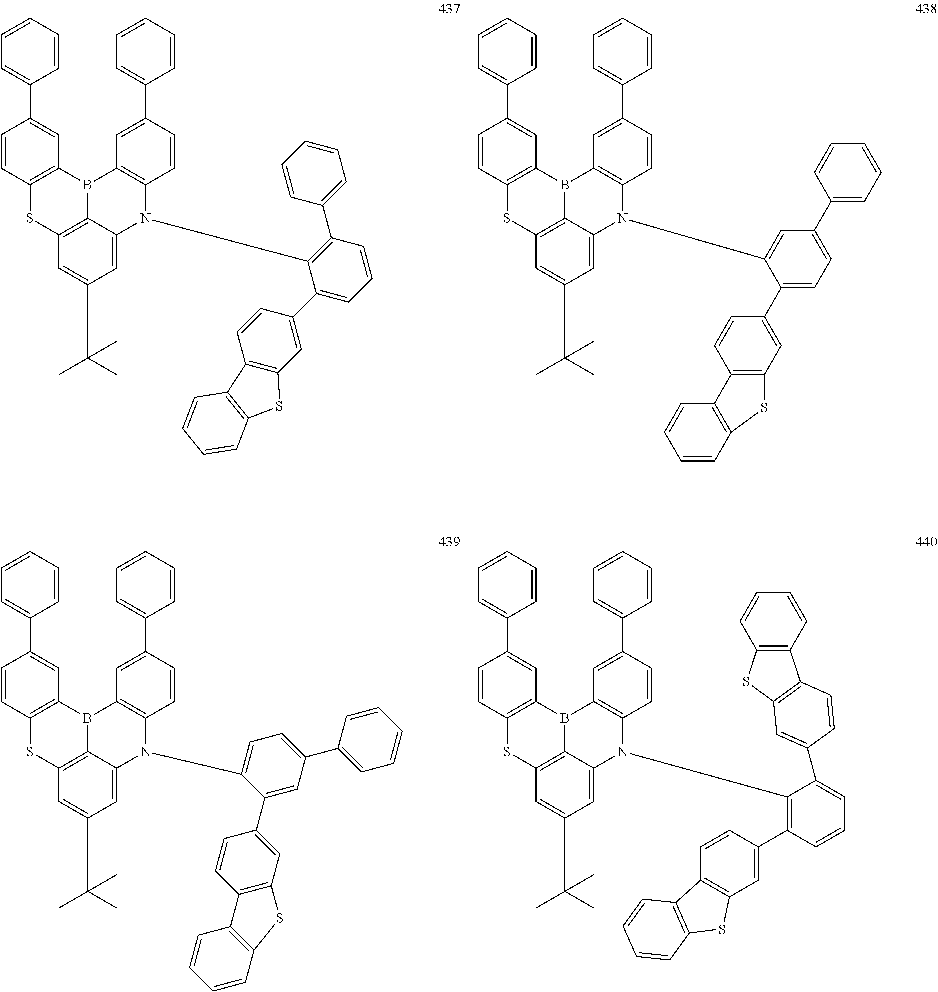 [SMILES: CC(C)(C)c1cc2c3c(c1)N(c1c(-c4ccccc4)cccc1-c1ccc4c(c1)sc1ccccc14)c1ccc(-c4ccccc4)cc1B3c1cc(-c3ccccc3)ccc1S2 ; CC(C)(C)c1cc2c3c(c1)N(c1cc(-c4ccccc4)ccc1-c1ccc4c(c1)sc1ccccc14)c1ccc(-c4ccccc4)cc1B3c1cc(-c3ccccc3)ccc1S2 ; CC(C)(C)c1cc2c3c(c1)N(c1ccc(-c4ccccc4)cc1-c1ccc4c(c1)sc1ccccc14)c1ccc(-c4ccccc4)cc1B3c1cc(-c3ccccc3)ccc1S2 ; CC(C)(C)c1cc2c3c(c1)N(c1c(-c4ccc5c(c4)sc4ccccc45)cccc1-c1ccc4c(c1)sc1ccccc14)c1ccc(-c4ccccc4)cc1B3c1cc(-c3ccccc3)ccc1S2] 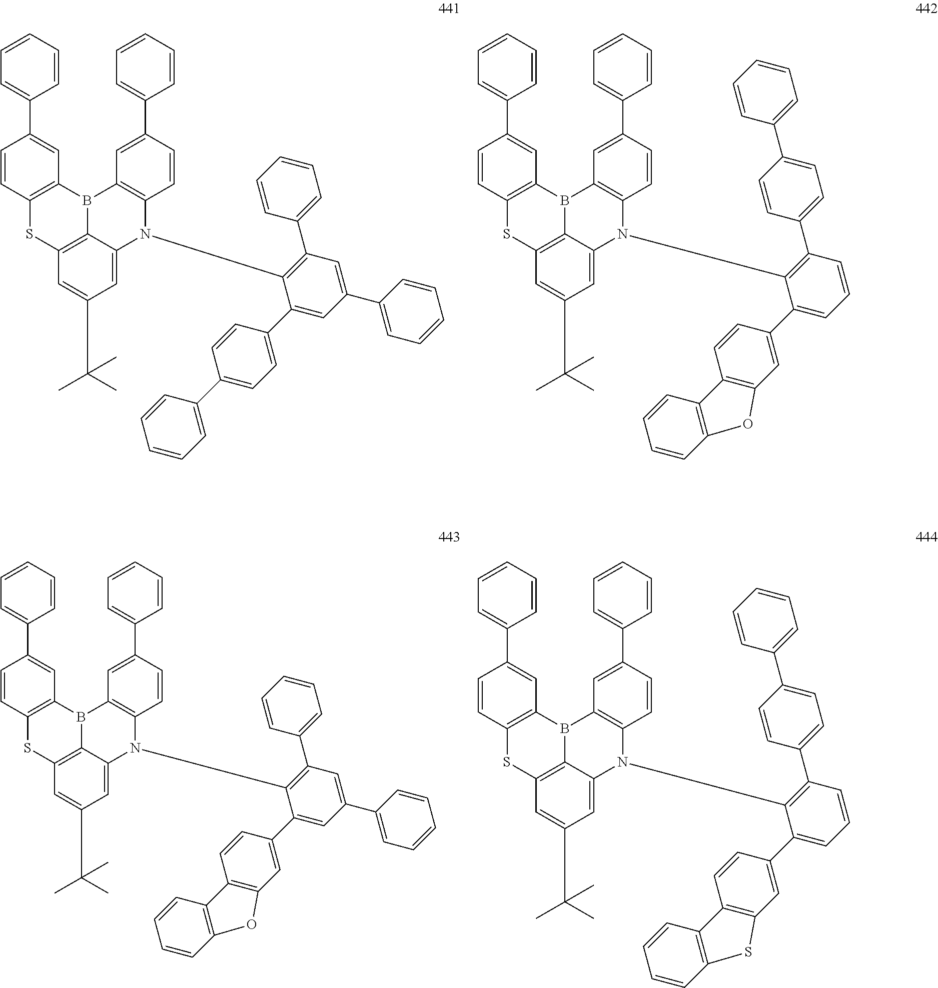 [SMILES: CC(C)(C)c1cc2c3c(c1)N(c1c(-c4ccccc4)cc(-c4ccccc4)cc1-c1ccc(-c4ccccc4)cc1)c1ccc(-c4ccccc4)cc1B3c1cc(-c3ccccc3)ccc1S2 ; CC(C)(C)c1cc2c3c(c1)N(c1c(-c4ccc(-c5ccccc5)cc4)cccc1-c1ccc4c(c1)oc1ccccc14)c1ccc(-c4ccccc4)cc1B3c1cc(-c3ccccc3)ccc1S2 ; CC(C)(C)c1cc2c3c(c1)N(c1c(-c4ccccc4)cc(-c4ccccc4)cc1-c1ccc4c(c1)oc1ccccc14)c1ccc(-c4ccccc4)cc1B3c1cc(-c3ccccc3)ccc1S2 ; CC(C)(C)c1cc2c3c(c1)N(c1c(-c4ccc(-c5ccccc5)cc4)cccc1-c1ccc4c(c1)sc1ccccc14)c1ccc(-c4ccccc4)cc1B3c1cc(-c3ccccc3)ccc1S2] 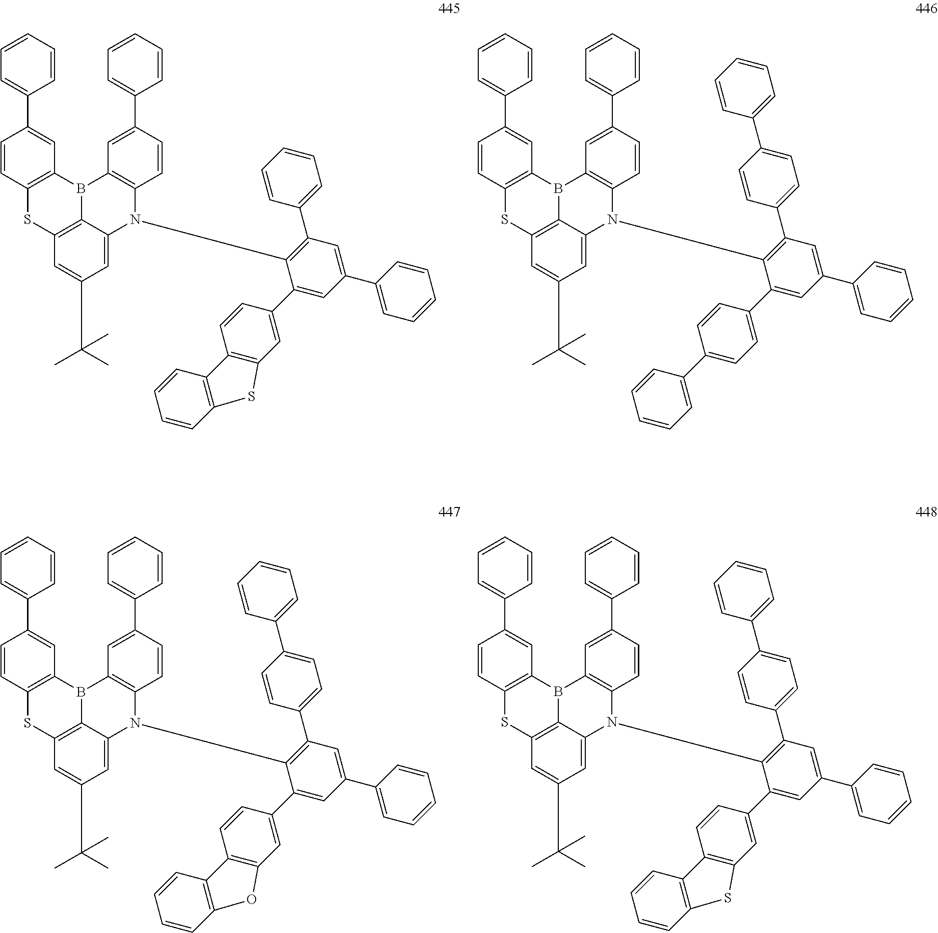 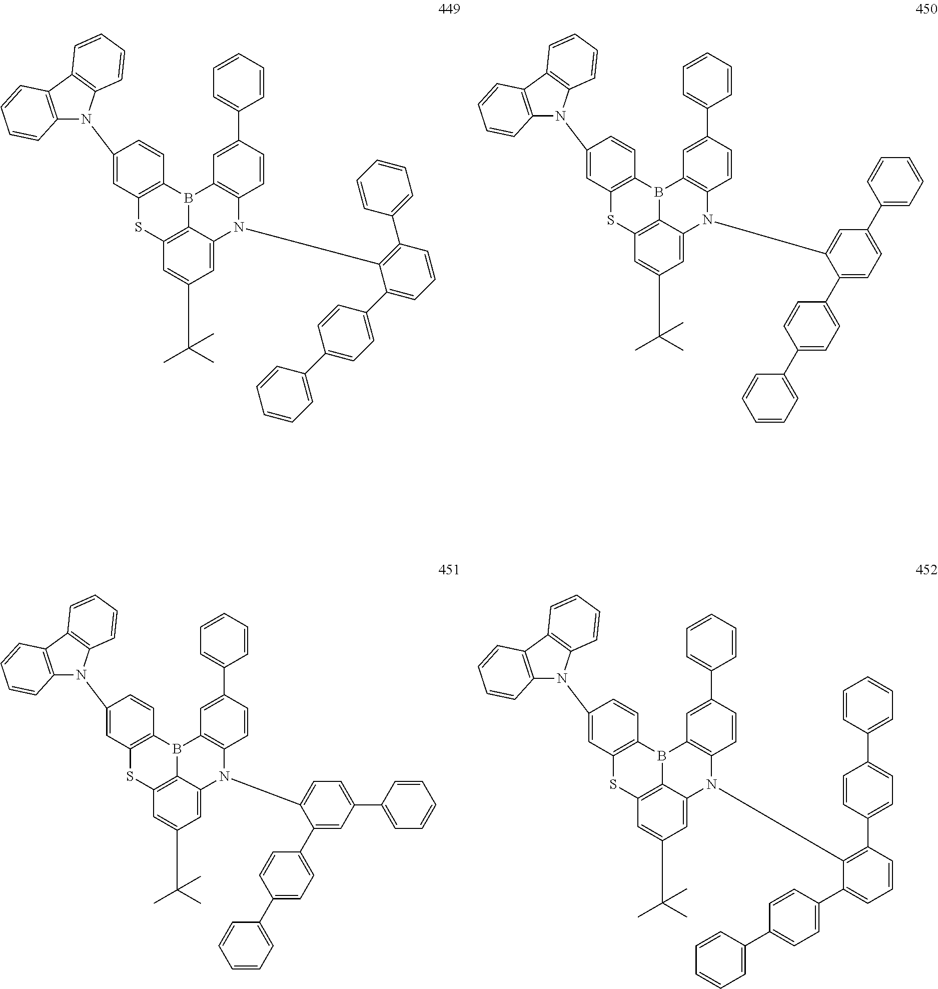 [SMILES: CC(C)(C)c1cc2c3c(c1)N(c1c(-c4ccccc4)cccc1-c1ccc(-c4ccccc4)cc1)c1ccc(-c4ccccc4)cc1B3c1ccc(-n3c4ccccc4c4ccccc43)cc1S2 ; CC(C)(C)c1cc2c3c(c1)N(c1cc(-c4ccccc4)ccc1-c1ccc(-c4ccccc4)cc1)c1ccc(-c4ccccc4)cc1B3c1ccc(-n3c4ccccc4c4ccccc43)cc1S2 ; CC(C)(C)c1cc2c3c(c1)N(c1ccc(-c4ccccc4)cc1-c1ccc(-c4ccccc4)cc1)c1ccc(-c4ccccc4)cc1B3c1ccc(-n3c4ccccc4c4ccccc43)cc1S2 ; CC(C)(C)c1cc2c3c(c1)N(c1c(-c4ccc(-c5ccccc5)cc4)cccc1-c1ccc(-c4ccccc4)cc1)c1ccc(-c4ccccc4)cc1B3c1ccc(-n3c4ccccc4c4ccccc43)cc1S2] 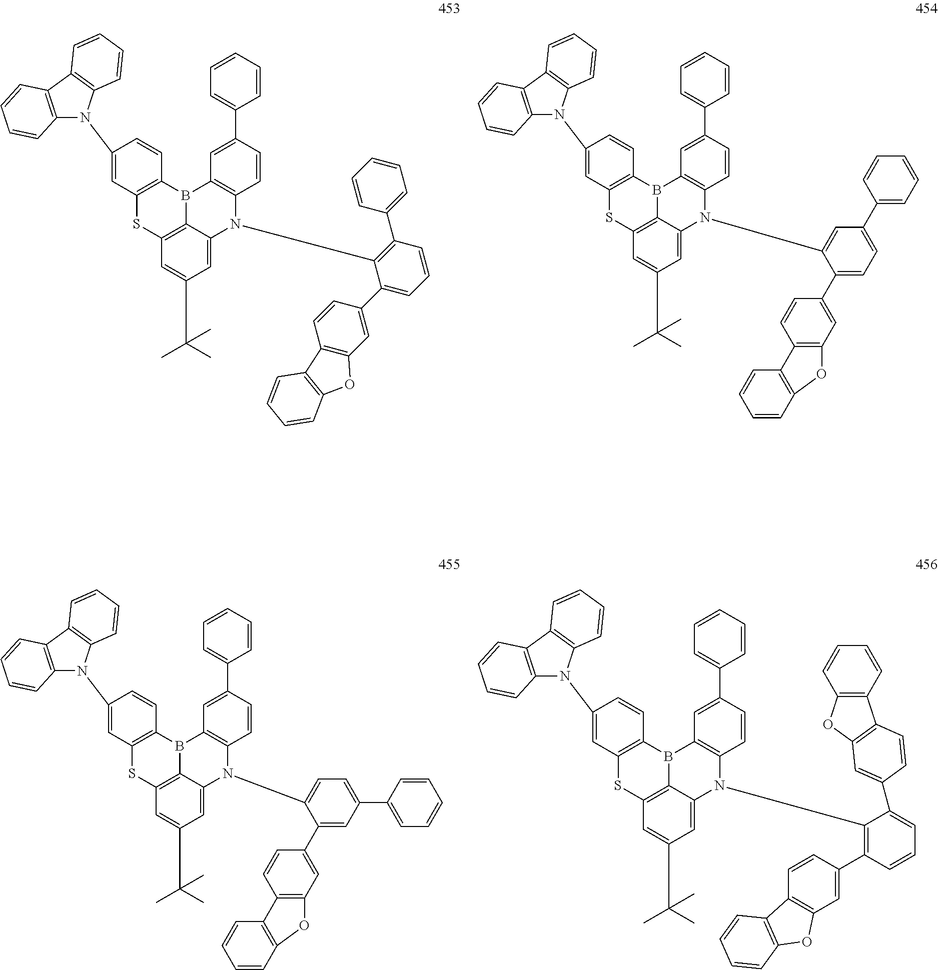 [SMILES: CC(C)(C)c1cc2c3c(c1)N(c1c(-c4ccccc4)cccc1-c1ccc4c(c1)oc1ccccc14)c1ccc(-c4ccccc4)cc1B3c1ccc(-n3c4ccccc4c4ccccc43)cc1S2 ; CC(C)(C)c1cc2c3c(c1)N(c1cc(-c4ccccc4)ccc1-c1ccc4c(c1)oc1ccccc14)c1ccc(-c4ccccc4)cc1B3c1ccc(-n3c4ccccc4c4ccccc43)cc1S2 ; CC(C)(C)c1cc2c3c(c1)N(c1ccc(-c4ccccc4)cc1-c1ccc4c(c1)oc1ccccc14)c1ccc(-c4ccccc4)cc1B3c1ccc(-n3c4ccccc4c4ccccc43)cc1S2 ; CC(C)(C)c1cc2c3c(c1)N(c1c(-c4ccc5c(c4)oc4ccccc45)cccc1-c1ccc4c(c1)oc1ccccc14)c1ccc(-c4ccccc4)cc1B3c1ccc(-n3c4ccccc4c4ccccc43)cc1S2] 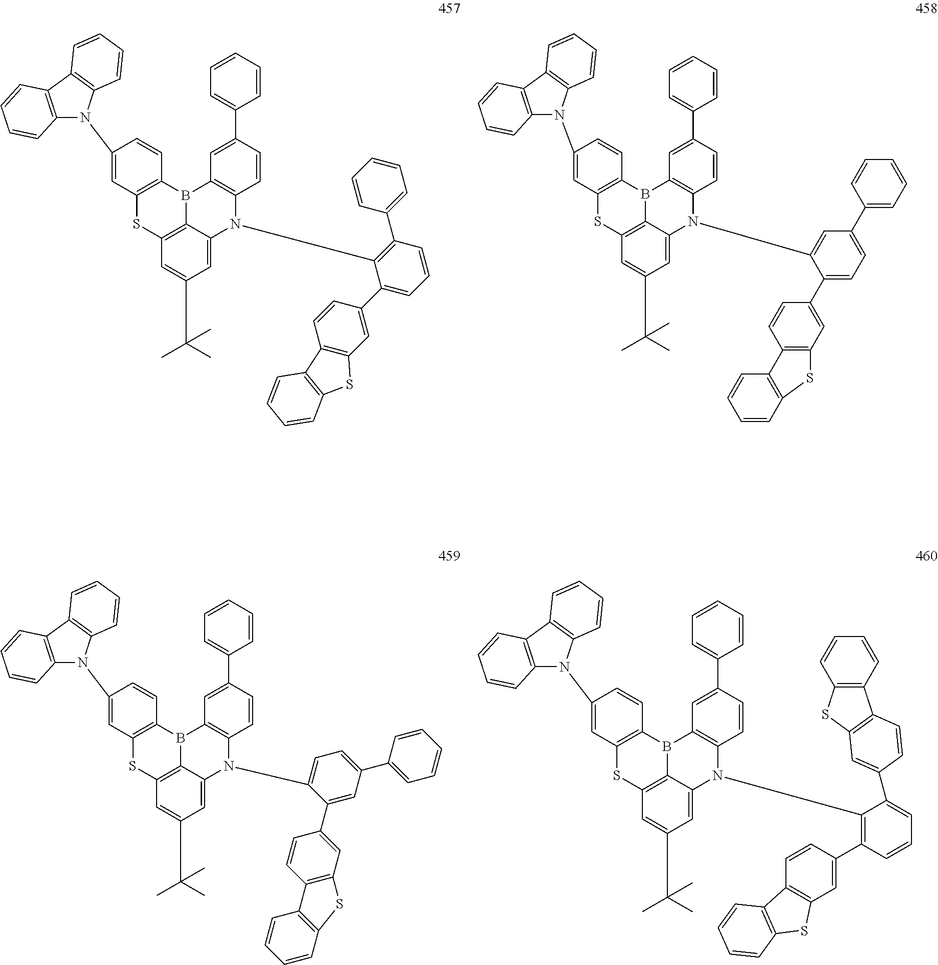 [SMILES: CC(C)(C)c1cc2c3c(c1)N(c1c(-c4ccccc4)cccc1-c1ccc4c(c1)sc1ccccc14)c1ccc(-c4ccccc4)cc1B3c1ccc(-n3c4ccccc4c4ccccc43)cc1S2 ; CC(C)(C)c1cc2c3c(c1)N(c1cc(-c4ccccc4)ccc1-c1ccc4c(c1)sc1ccccc14)c1ccc(-c4ccccc4)cc1B3c1ccc(-n3c4ccccc4c4ccccc43)cc1S2 ; CC(C)(C)c1cc2c3c(c1)N(c1ccc(-c4ccccc4)cc1-c1ccc4c(c1)sc1ccccc14)c1ccc(-c4ccccc4)cc1B3c1ccc(-n3c4ccccc4c4ccccc43)cc1S2 ; CC(C)(C)c1cc2c3c(c1)N(c1c(-c4ccc5c(c4)sc4ccccc45)cccc1-c1ccc4c(c1)sc1ccccc14)c1ccc(-c4ccccc4)cc1B3c1ccc(-n3c4ccccc4c4ccccc43)cc1S2] 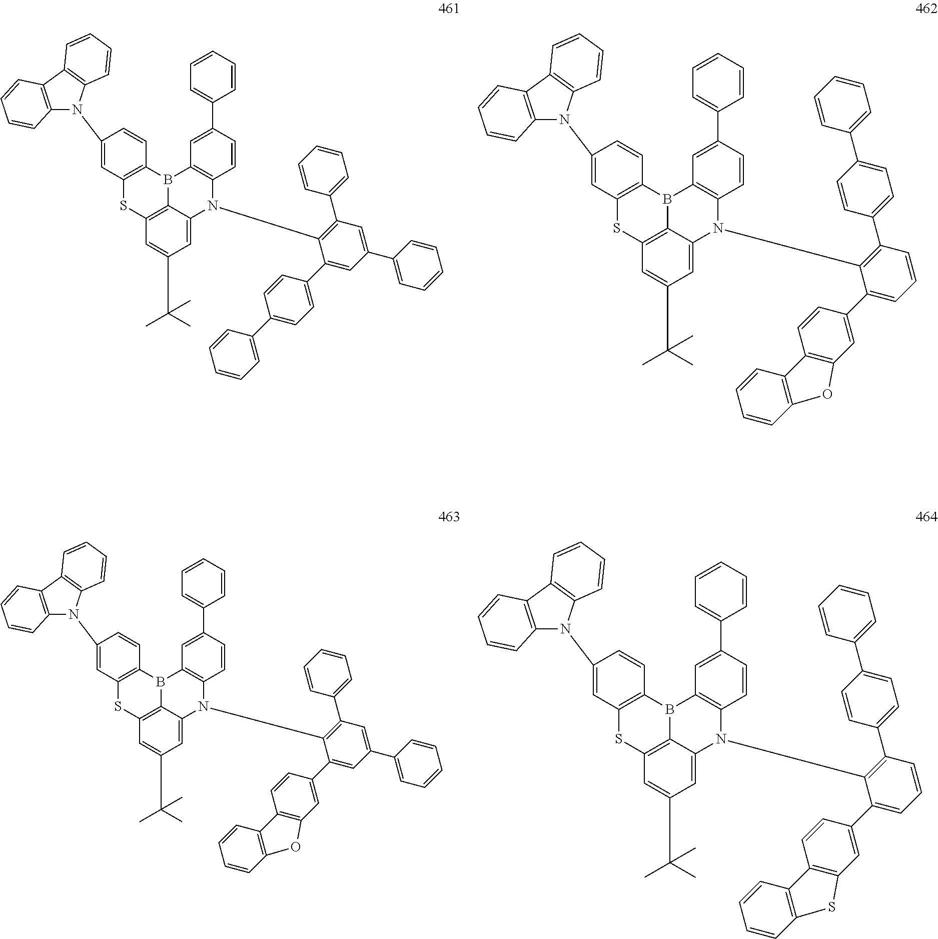 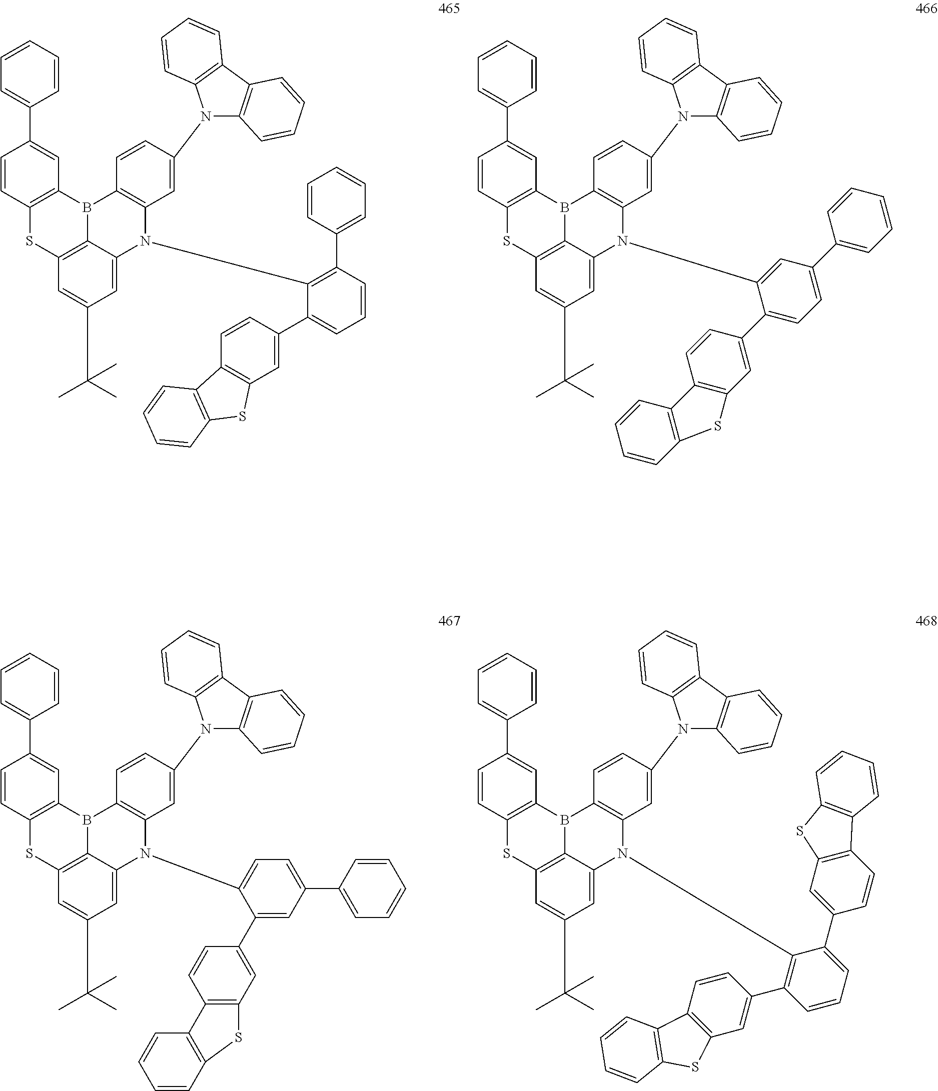 [SMILES: CC(C)(C)c1cc2c3c(c1)N(c1c(-c4ccccc4)cccc1-c1ccc4c(c1)sc1ccccc14)c1cc(-n4c5ccccc5c5ccccc54)ccc1B3c1cc(-c3ccccc3)ccc1S2 ; CC(C)(C)c1cc2c3c(c1)N(c1cc(-c4ccccc4)ccc1-c1ccc4c(c1)sc1ccccc14)c1cc(-n4c5ccccc5c5ccccc54)ccc1B3c1cc(-c3ccccc3)ccc1S2 ; CC(C)(C)c1cc2c3c(c1)N(c1ccc(-c4ccccc4)cc1-c1ccc4c(c1)sc1ccccc14)c1cc(-n4c5ccccc5c5ccccc54)ccc1B3c1cc(-c3ccccc3)ccc1S2 ; CC(C)(C)c1cc2c3c(c1)N(c1c(-c4ccc5c(c4)sc4ccccc45)cccc1-c1ccc4c(c1)sc1ccccc14)c1cc(-n4c5ccccc5c5ccccc54)ccc1B3c1cc(-c3ccccc3)ccc1S2] 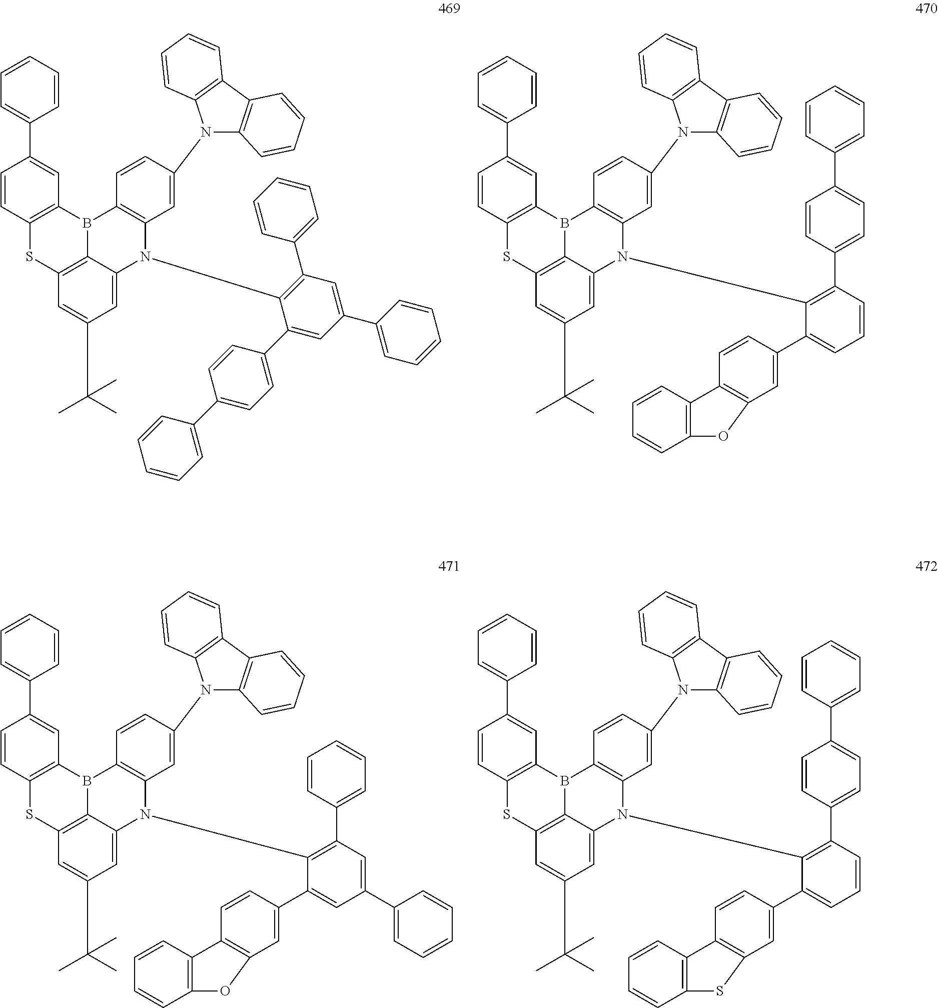 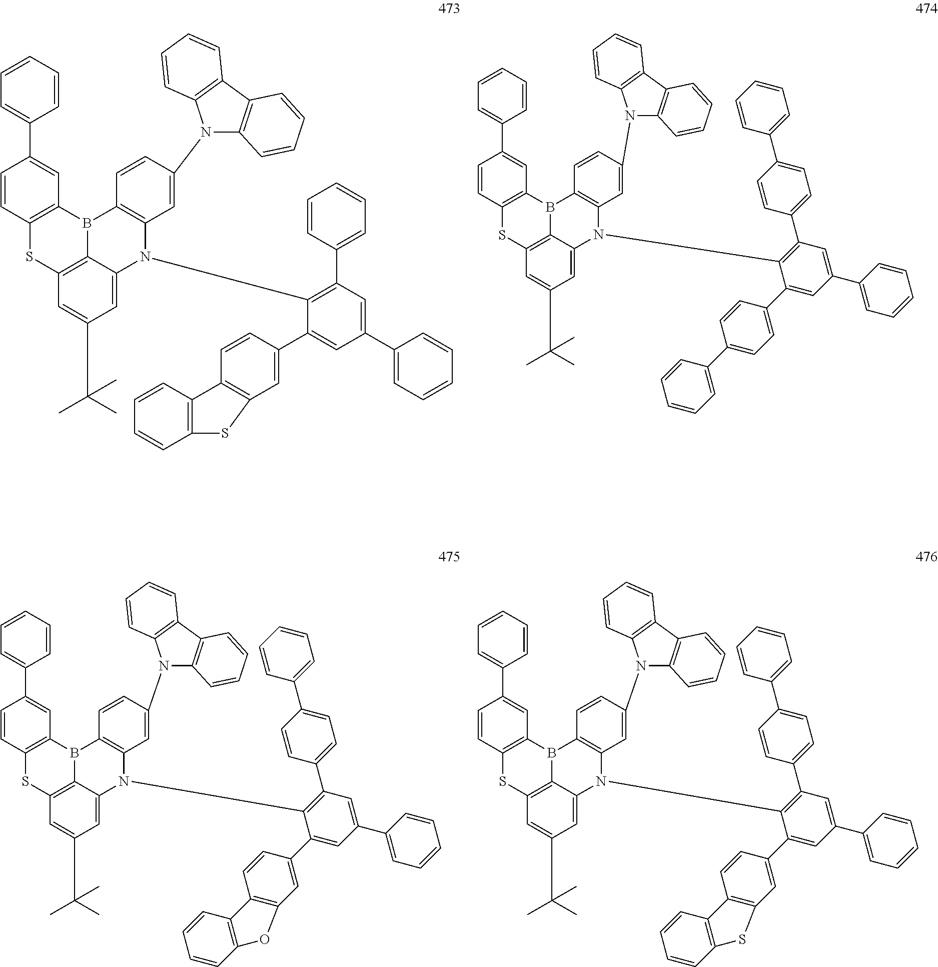 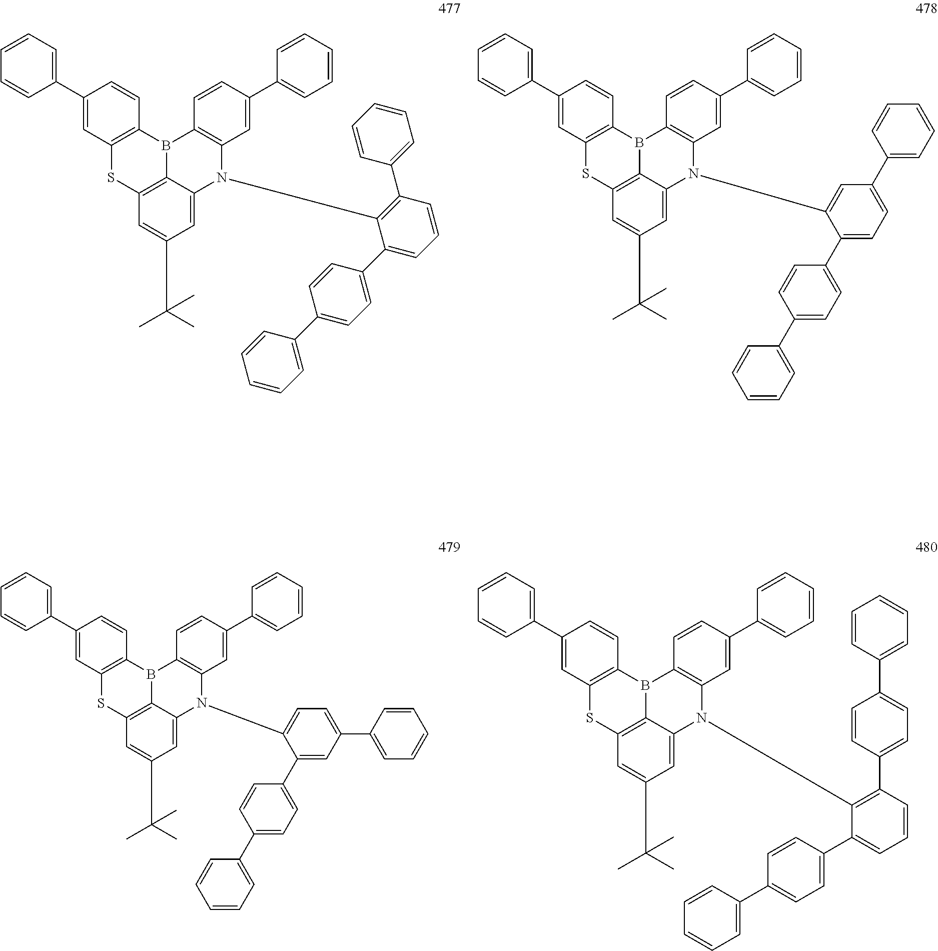 [SMILES: CC(C)(C)c1cc2c3c(c1)N(c1c(-c4ccccc4)cccc1-c1ccc(-c4ccccc4)cc1)c1cc(-c4ccccc4)ccc1B3c1ccc(-c3ccccc3)cc1S2 ; CC(C)(C)c1cc2c3c(c1)N(c1cc(-c4ccccc4)ccc1-c1ccc(-c4ccccc4)cc1)c1cc(-c4ccccc4)ccc1B3c1ccc(-c3ccccc3)cc1S2 ; CC(C)(C)c1cc2c3c(c1)N(c1ccc(-c4ccccc4)cc1-c1ccc(-c4ccccc4)cc1)c1cc(-c4ccccc4)ccc1B3c1ccc(-c3ccccc3)cc1S2 ; CC(C)(C)c1cc2c3c(c1)N(c1c(-c4ccc(-c5ccccc5)cc4)cccc1-c1ccc(-c4ccccc4)cc1)c1cc(-c4ccccc4)ccc1B3c1ccc(-c3ccccc3)cc1S2] 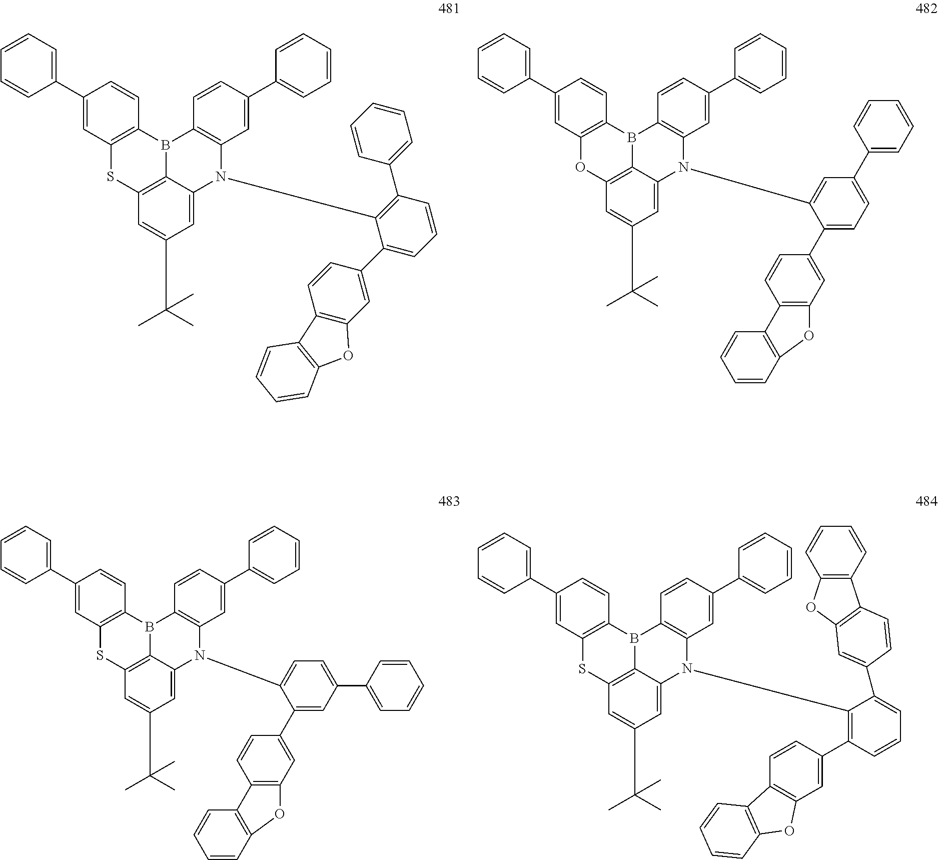 [SMILES: CC(C)(C)c1cc2c3c(c1)N(c1c(-c4ccccc4)cccc1-c1ccc4c(c1)oc1ccccc14)c1cc(-c4ccccc4)ccc1B3c1ccc(-c3ccccc3)cc1S2 ; CC(C)(C)c1cc2c3c(c1)N(c1cc(-c4ccccc4)ccc1-c1ccc4c(c1)oc1ccccc14)c1cc(-c4ccccc4)ccc1B3c1ccc(-c3ccccc3)cc1O2 ; CC(C)(C)c1cc2c3c(c1)N(c1ccc(-c4ccccc4)cc1-c1ccc4c(c1)oc1ccccc14)c1cc(-c4ccccc4)ccc1B3c1ccc(-c3ccccc3)cc1S2 ; CC(C)(C)c1cc2c3c(c1)N(c1c(-c4ccc5c(c4)oc4ccccc45)cccc1-c1ccc4c(c1)oc1ccccc14)c1cc(-c4ccccc4)ccc1B3c1ccc(-c3ccccc3)cc1S2] 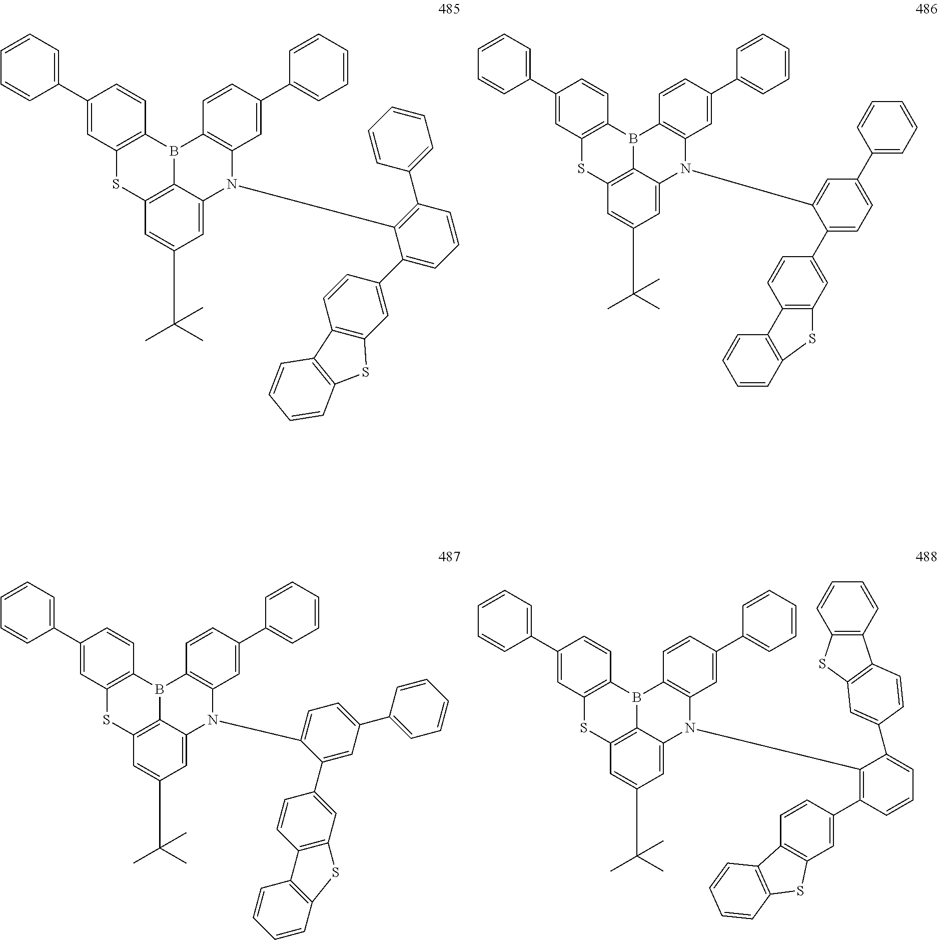 [SMILES: CC(C)(C)c1cc2c3c(c1)N(c1c(-c4ccccc4)cccc1-c1ccc4c(c1)sc1ccccc14)c1cc(-c4ccccc4)ccc1B3c1ccc(-c3ccccc3)cc1S2 ; CC(C)(C)c1cc2c3c(c1)N(c1cc(-c4ccccc4)ccc1-c1ccc4c(c1)sc1ccccc14)c1cc(-c4ccccc4)ccc1B3c1ccc(-c3ccccc3)cc1S2 ; CC(C)(C)c1cc2c3c(c1)N(c1ccc(-c4ccccc4)cc1-c1ccc4c(c1)sc1ccccc14)c1cc(-c4ccccc4)ccc1B3c1ccc(-c3ccccc3)cc1S2 ; CC(C)(C)c1cc2c3c(c1)N(c1c(-c4ccc5c(c4)sc4ccccc45)cccc1-c1ccc4c(c1)sc1ccccc14)c1cc(-c4ccccc4)ccc1B3c1ccc(-c3ccccc3)cc1S2] 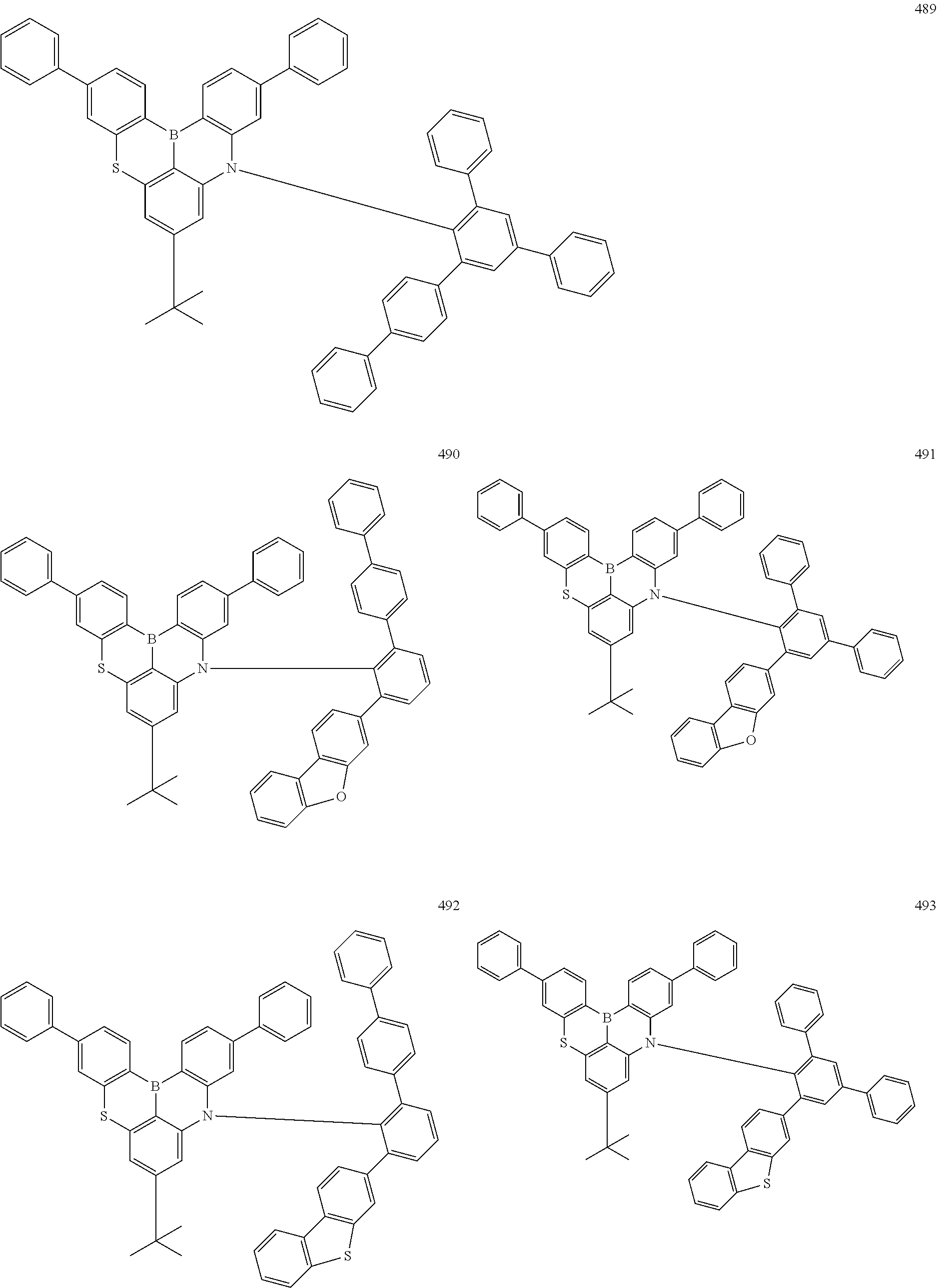 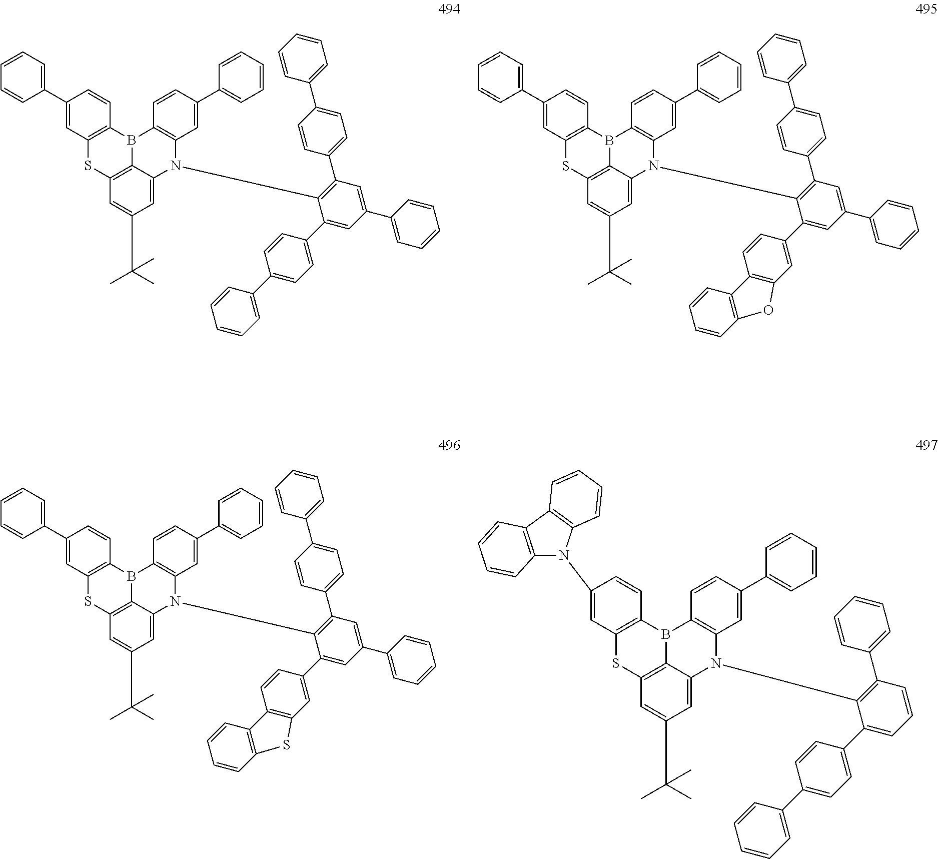 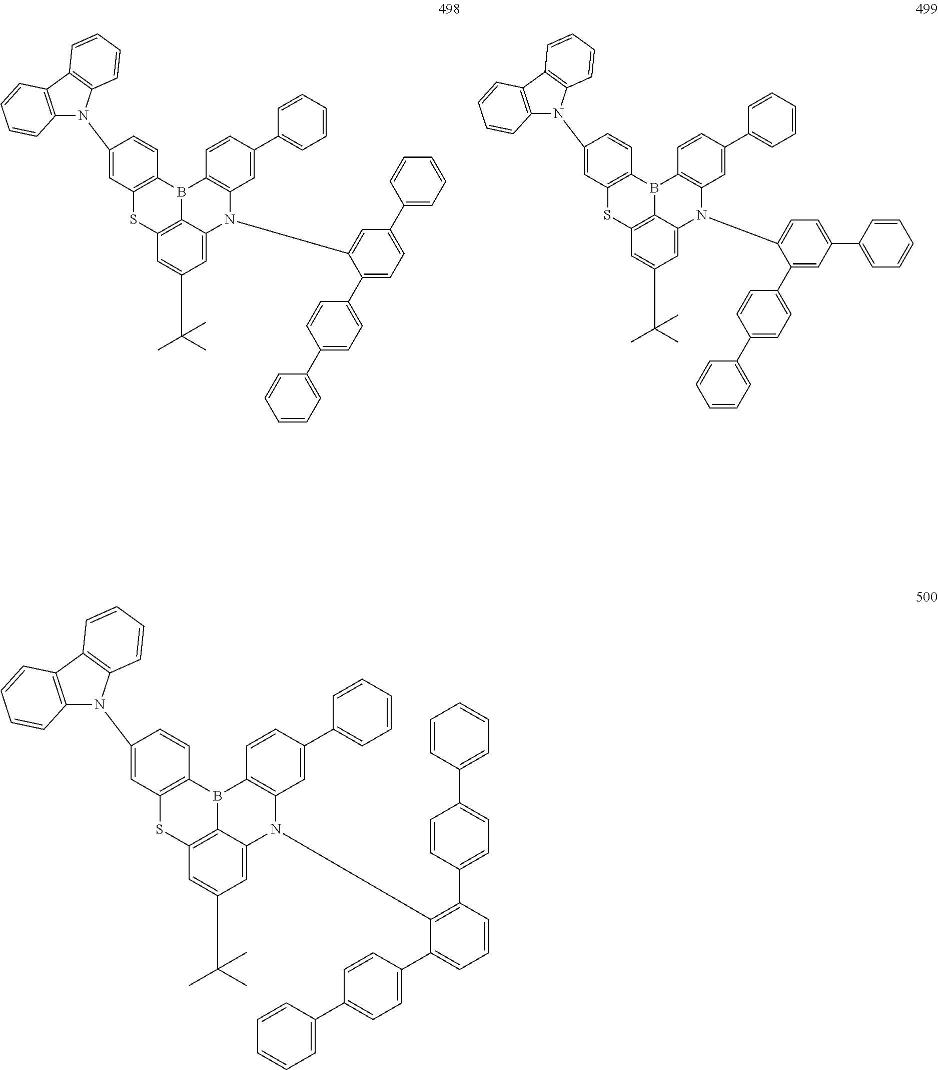 [SMILES: CC(C)(C)c1cc2c3c(c1)N(c1cc(-c4ccccc4)ccc1-c1ccc(-c4ccccc4)cc1)c1cc(-c4ccccc4)ccc1B3c1ccc(-n3c4ccccc4c4ccccc43)cc1S2 ; CC(C)(C)c1cc2c3c(c1)N(c1ccc(-c4ccccc4)cc1-c1ccc(-c4ccccc4)cc1)c1cc(-c4ccccc4)ccc1B3c1ccc(-n3c4ccccc4c4ccccc43)cc1S2 ; CC(C)(C)c1cc2c3c(c1)N(c1c(-c4ccc(-c5ccccc5)cc4)cccc1-c1ccc(-c4ccccc4)cc1)c1cc(-c4ccccc4)ccc1B3c1ccc(-n3c4ccccc4c4ccccc43)cc1S2] 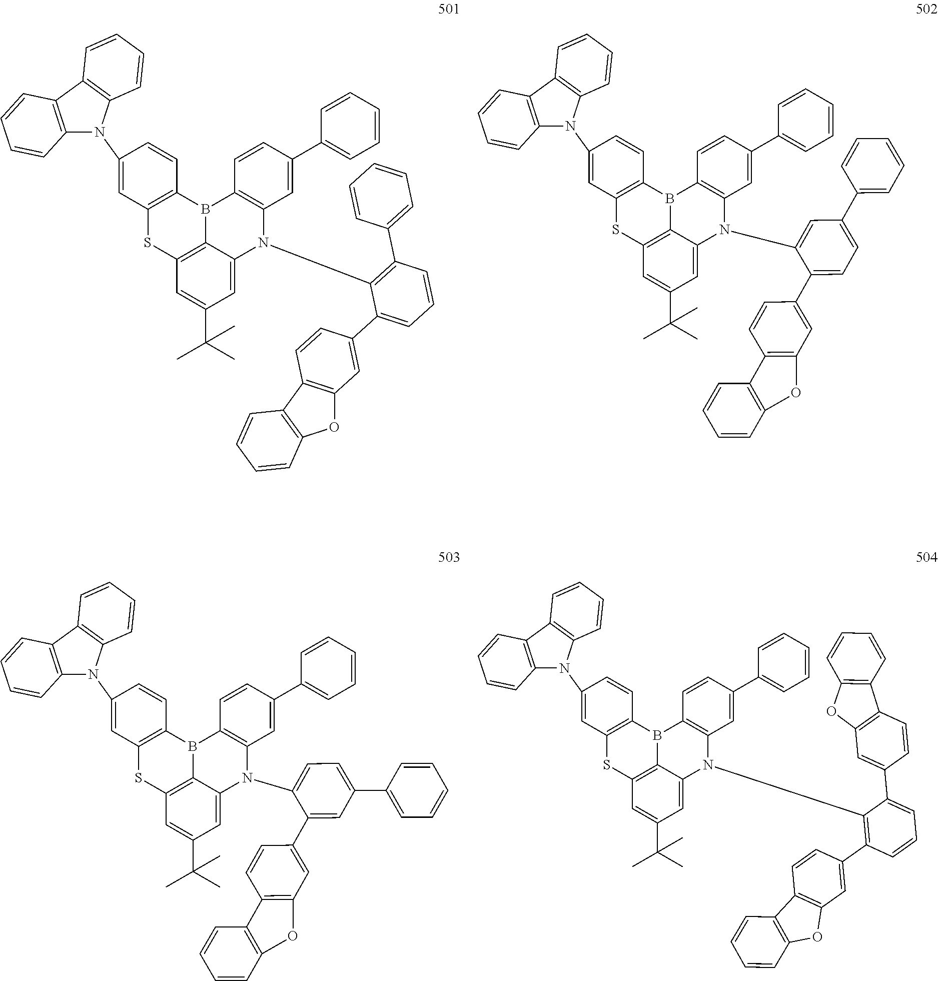 [SMILES: CC(C)(C)c1cc2c3c(c1)N(c1c(-c4ccccc4)cccc1-c1ccc4c(c1)oc1ccccc14)c1cc(-c4ccccc4)ccc1B3c1ccc(-n3c4ccccc4c4ccccc43)cc1S2 ; CC(C)(C)c1cc2c3c(c1)N(c1cc(-c4ccccc4)ccc1-c1ccc4c(c1)oc1ccccc14)c1cc(-c4ccccc4)ccc1B3c1ccc(-n3c4ccccc4c4ccccc43)cc1S2 ; CC(C)(C)c1cc2c3c(c1)N(c1ccc(-c4ccccc4)cc1-c1ccc4c(c1)oc1ccccc14)c1cc(-c4ccccc4)ccc1B3c1ccc(-n3c4ccccc4c4ccccc43)cc1S2 ; CC(C)(C)c1cc2c3c(c1)N(c1c(-c4ccc5c(c4)oc4ccccc45)cccc1-c1ccc4c(c1)oc1ccccc14)c1cc(-c4ccccc4)ccc1B3c1ccc(-n3c4ccccc4c4ccccc43)cc1S2] 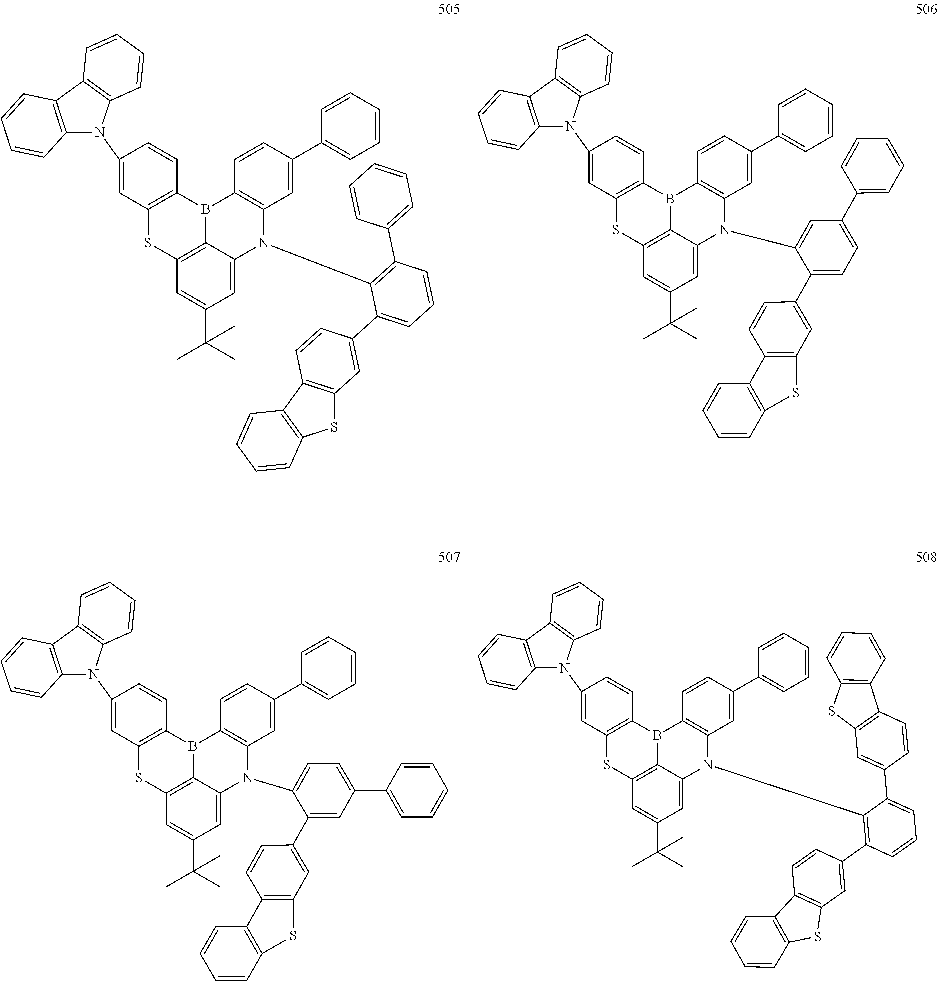 [SMILES: CC(C)(C)c1cc2c3c(c1)N(c1c(-c4ccccc4)cccc1-c1ccc4c(c1)sc1ccccc14)c1cc(-c4ccccc4)ccc1B3c1ccc(-n3c4ccccc4c4ccccc43)cc1S2 ; CC(C)(C)c1cc2c3c(c1)N(c1cc(-c4ccccc4)ccc1-c1ccc4c(c1)sc1ccccc14)c1cc(-c4ccccc4)ccc1B3c1ccc(-n3c4ccccc4c4ccccc43)cc1S2 ; CC(C)(C)c1cc2c3c(c1)N(c1ccc(-c4ccccc4)cc1-c1ccc4c(c1)sc1ccccc14)c1cc(-c4ccccc4)ccc1B3c1ccc(-n3c4ccccc4c4ccccc43)cc1S2 ; CC(C)(C)c1cc2c3c(c1)N(c1c(-c4ccc5c(c4)sc4ccccc45)cccc1-c1ccc4c(c1)sc1ccccc14)c1cc(-c4ccccc4)ccc1B3c1ccc(-n3c4ccccc4c4ccccc43)cc1S2] 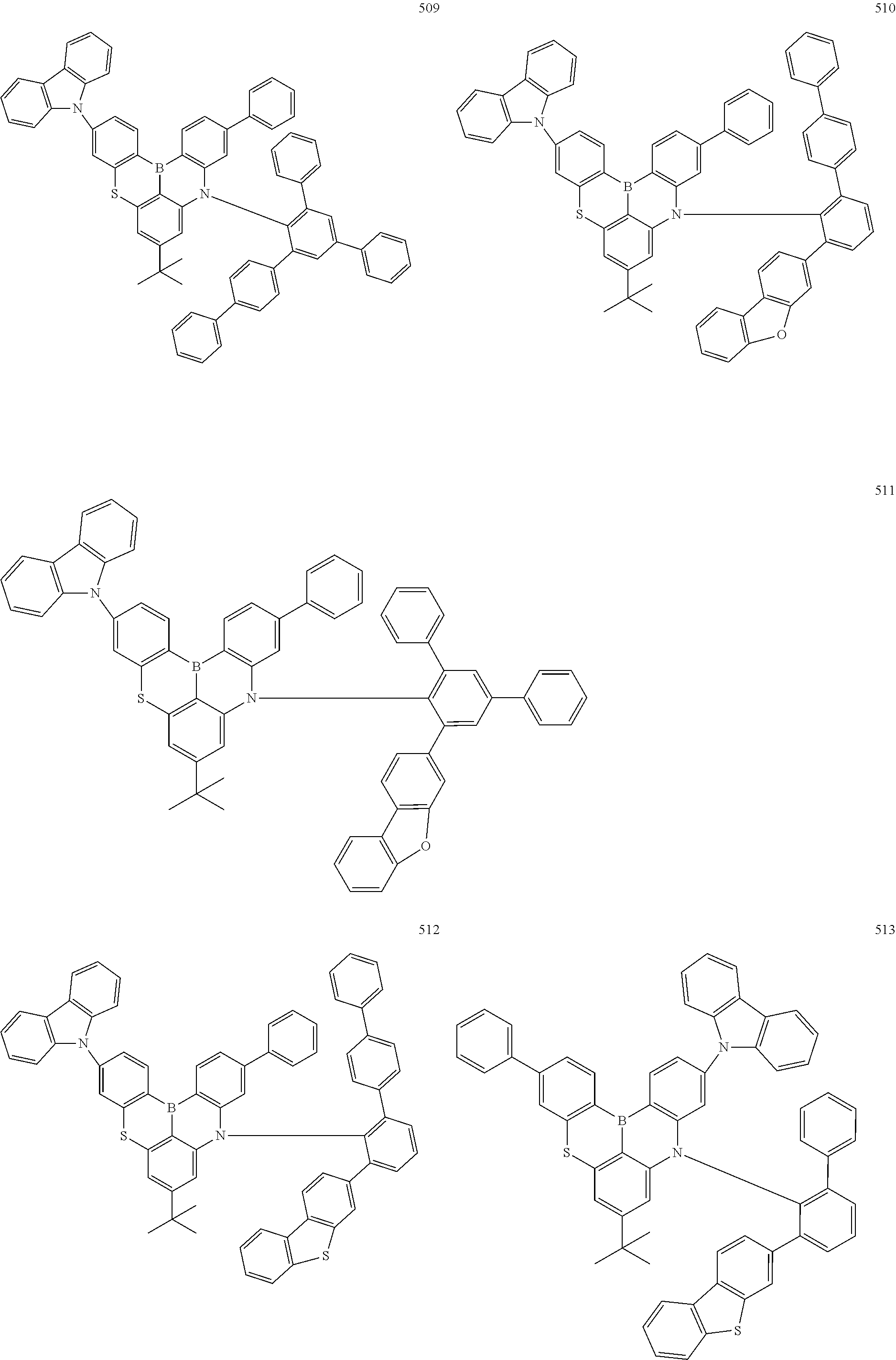 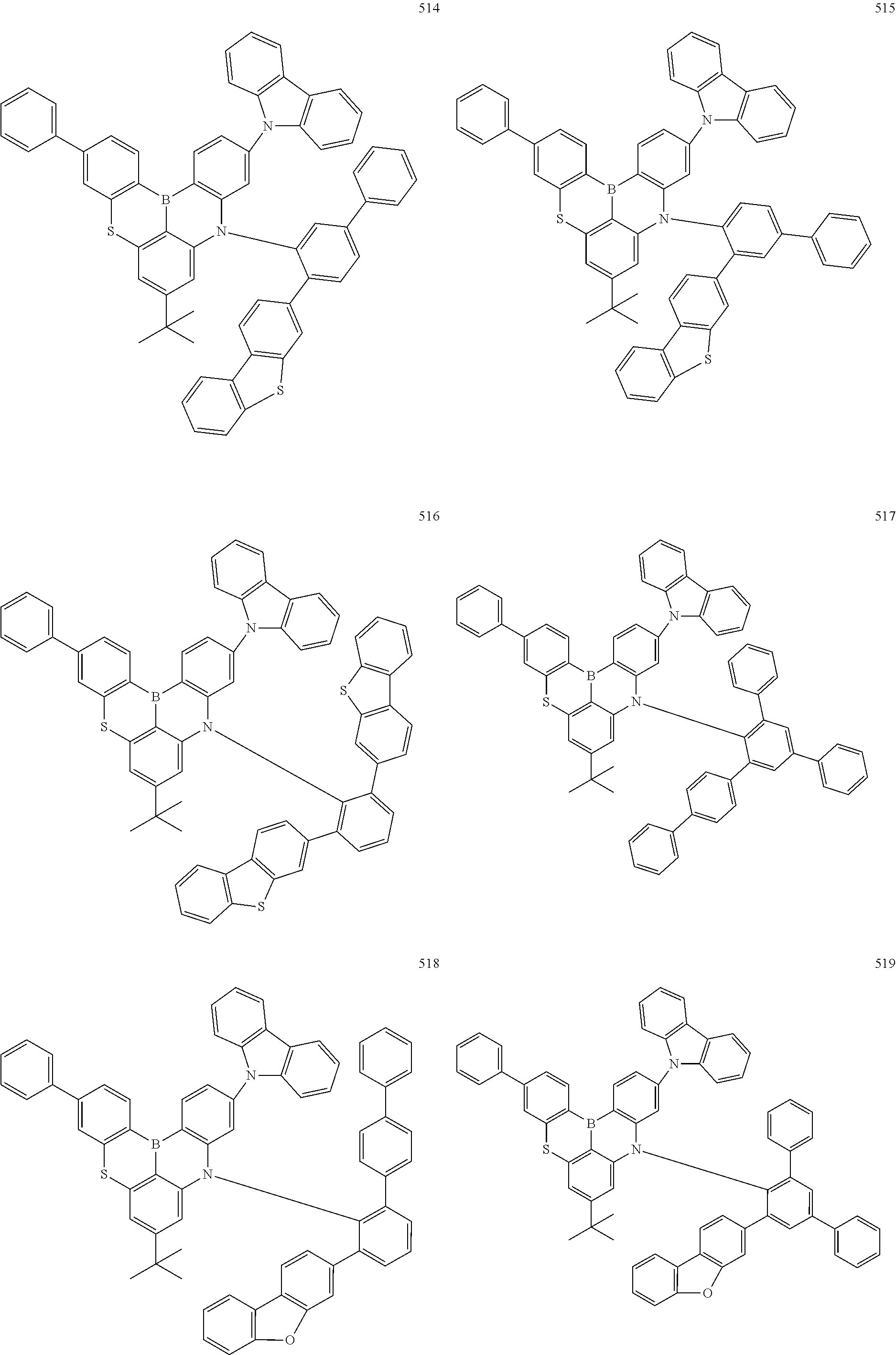 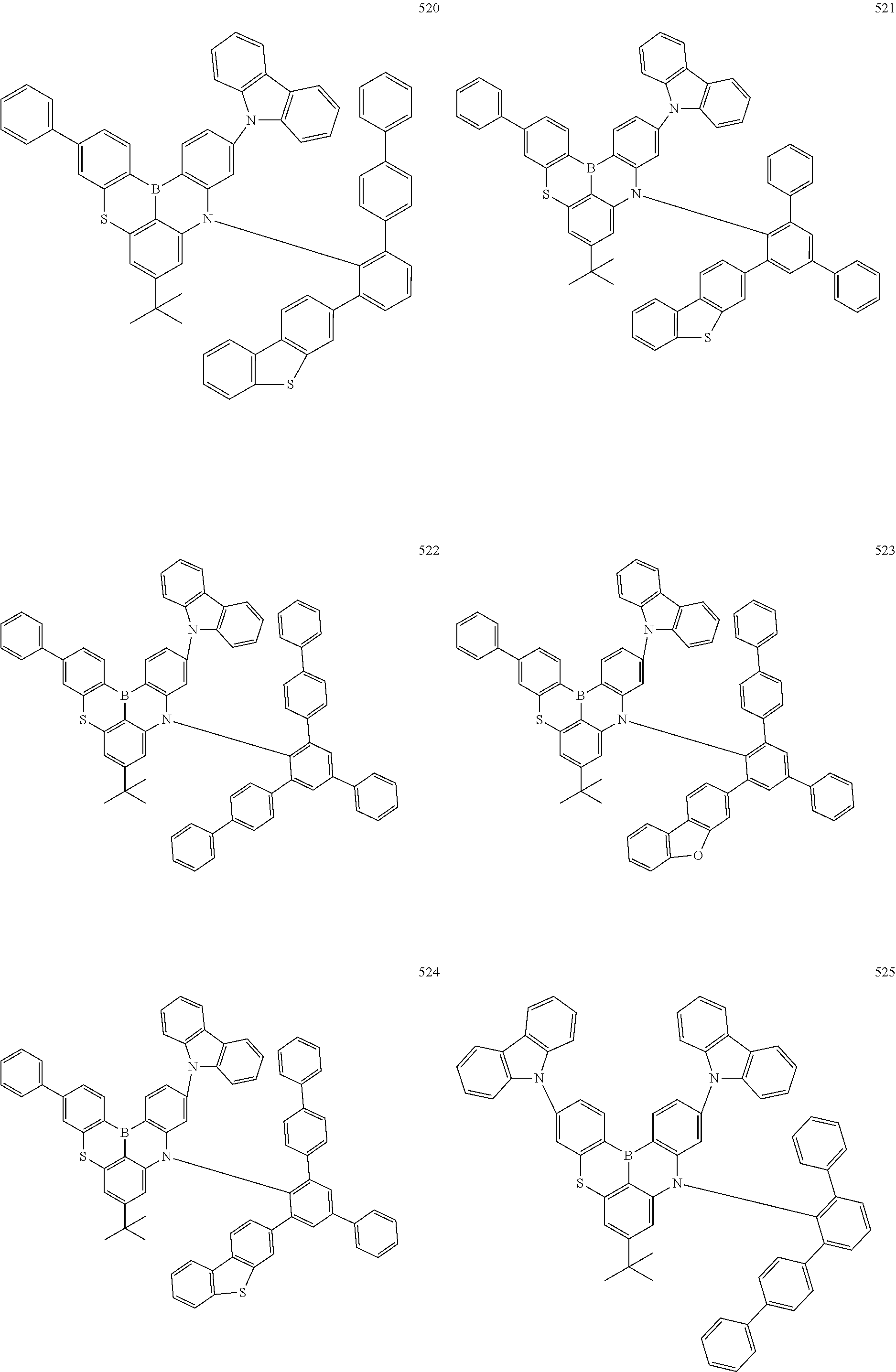 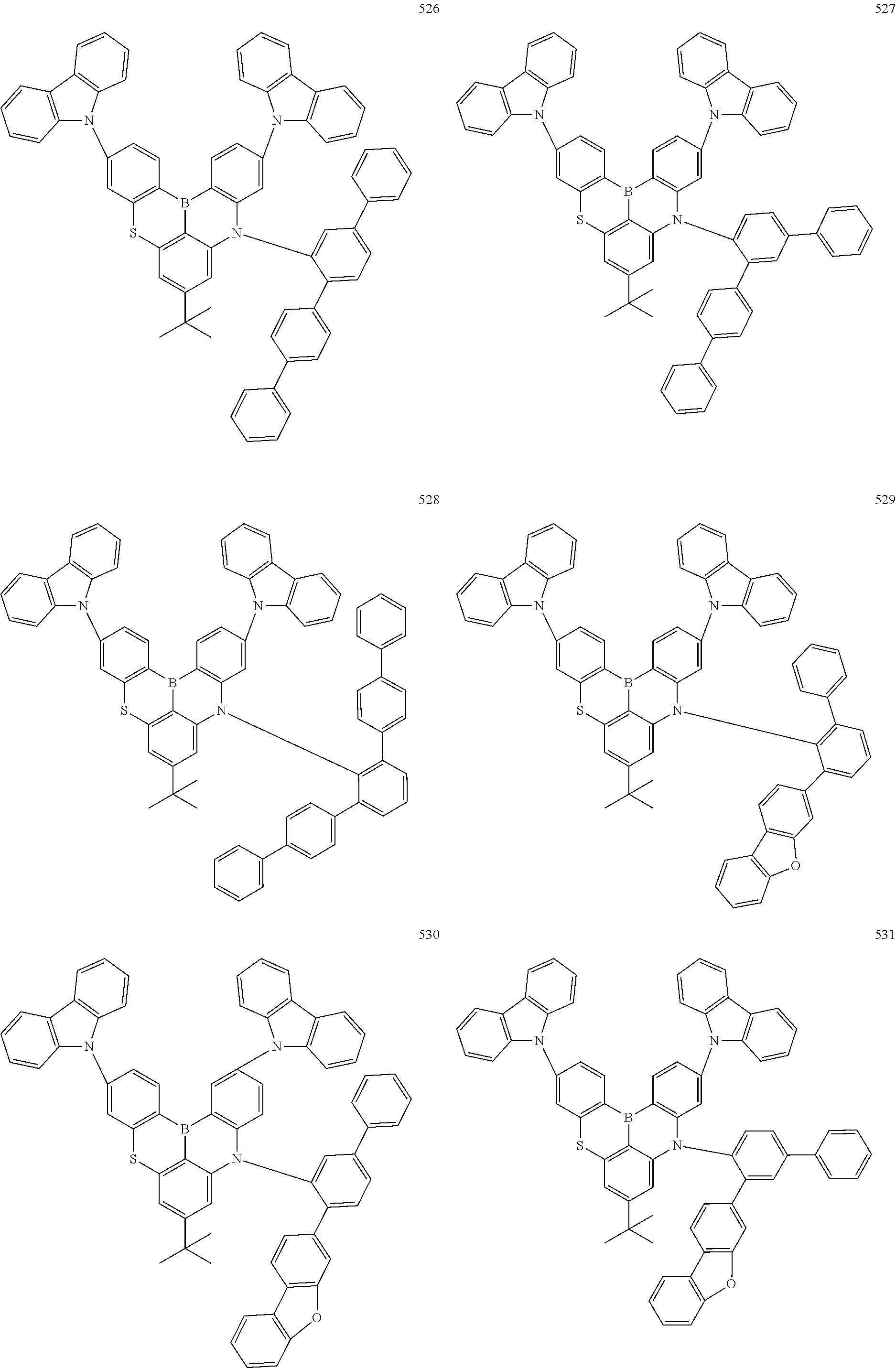 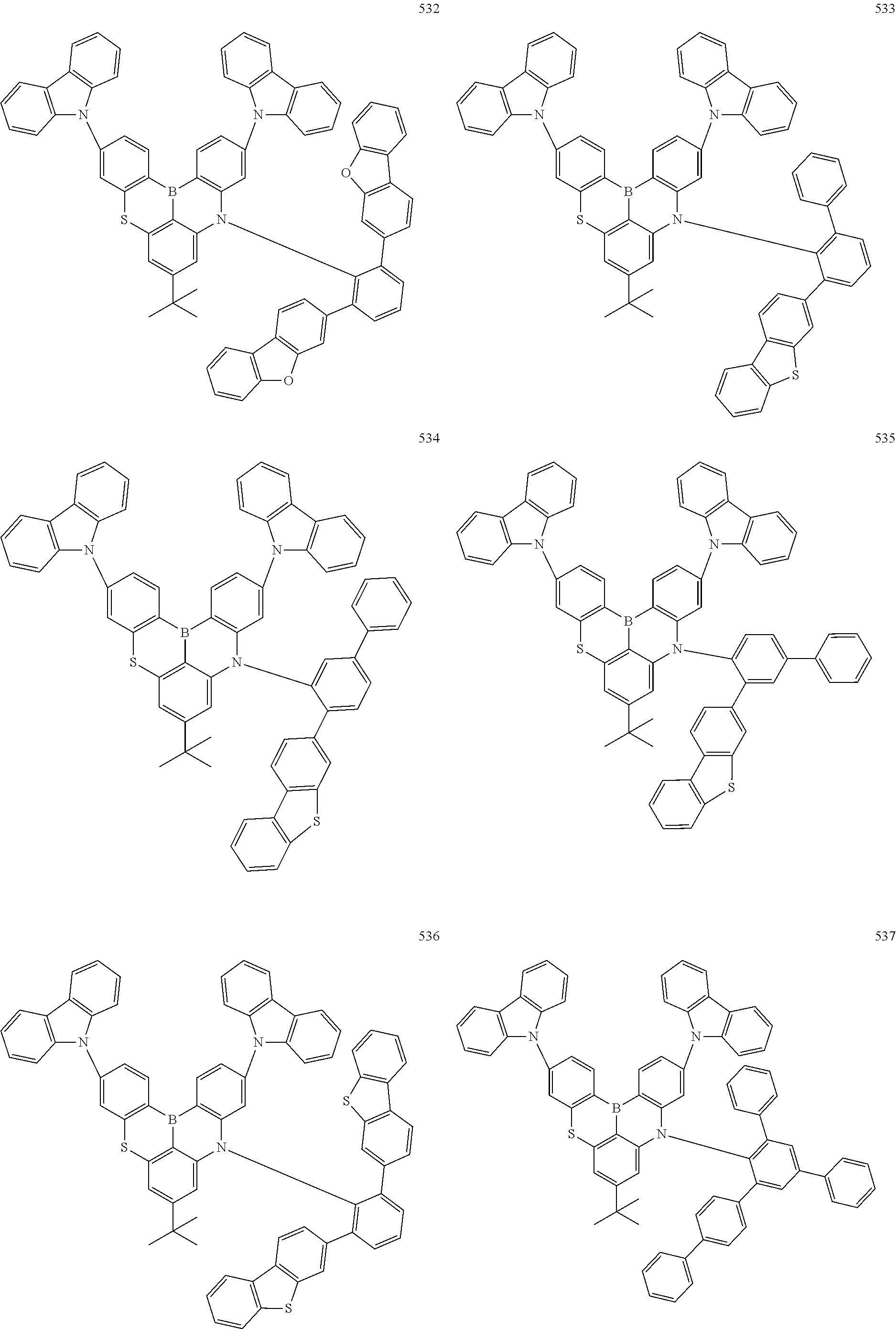 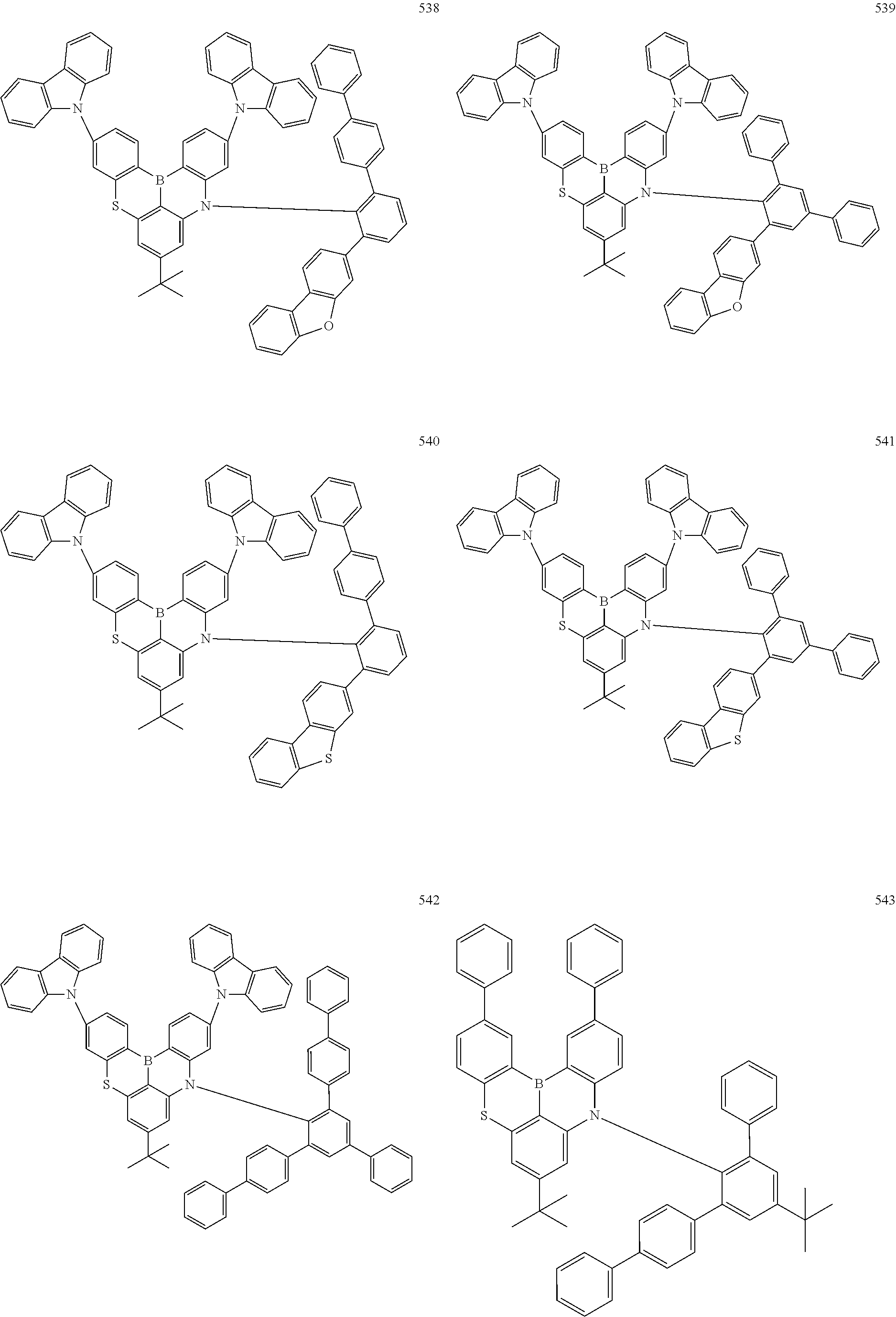 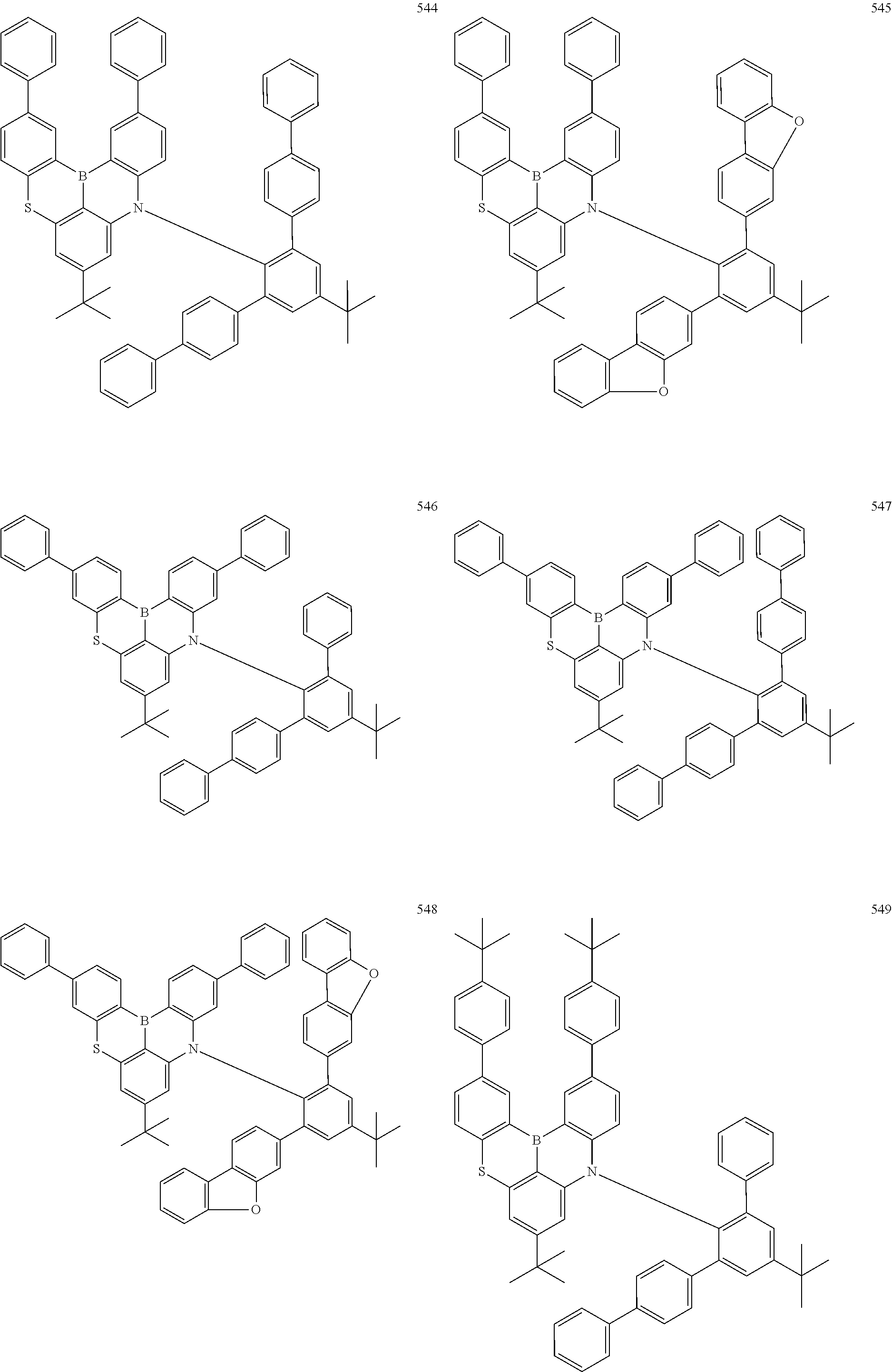 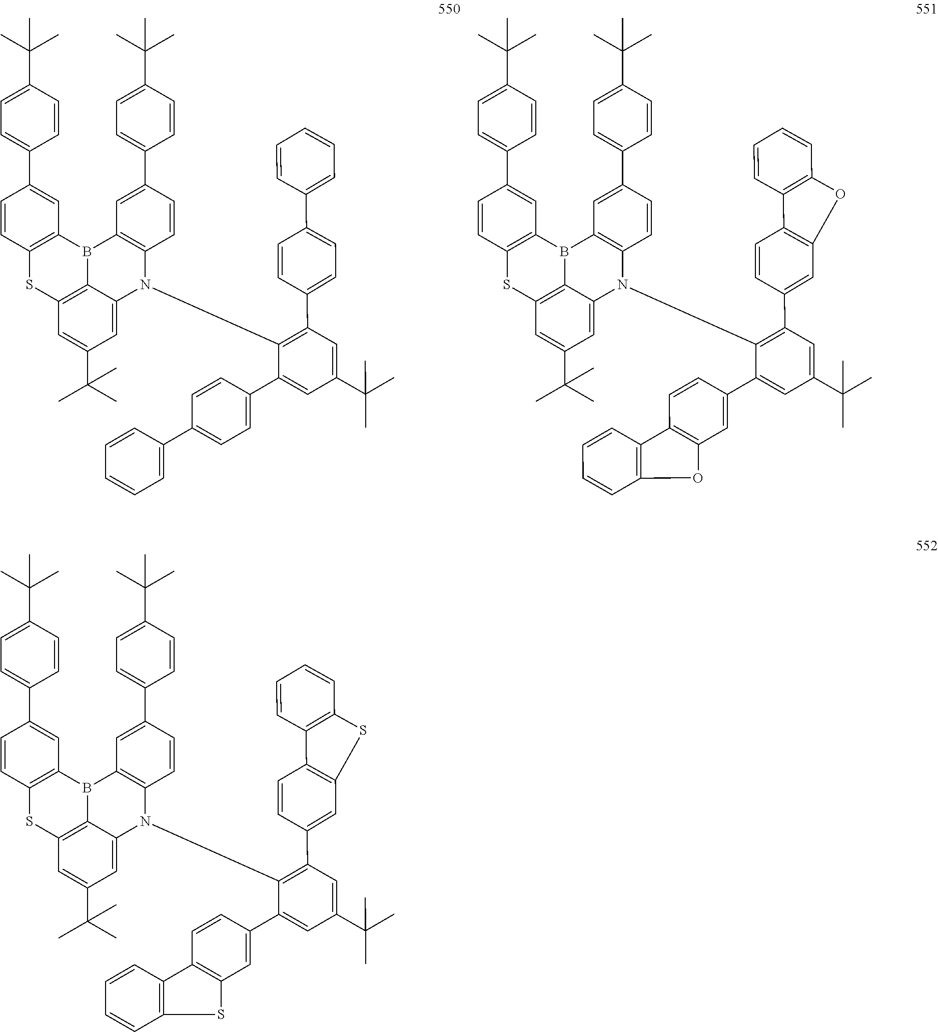 [SMILES: CC(C)(C)c1ccc(-c2ccc3c(c2)B2c4cc(-c5ccc(C(C)(C)C)cc5)ccc4N(c4c(-c5ccc(-c6ccccc6)cc5)cc(C(C)(C)C)cc4-c4ccc(-c5ccccc5)cc4)c4cc(C(C)(C)C)cc(c42)S3)cc1 ; CC(C)(C)c1ccc(-c2ccc3c(c2)B2c4cc(-c5ccc(C(C)(C)C)cc5)ccc4N(c4c(-c5ccc6c(c5)oc5ccccc56)cc(C(C)(C)C)cc4-c4ccc5c(c4)oc4ccccc45)c4cc(C(C)(C)C)cc(c42)S3)cc1 ; CC(C)(C)c1ccc(-c2ccc3c(c2)B2c4cc(-c5ccc(C(C)(C)C)cc5)ccc4N(c4c(-c5ccc6c(c5)sc5ccccc56)cc(C(C)(C)C)cc4-c4ccc5c(c4)sc4ccccc45)c4cc(C(C)(C)C)cc(c42)S3)cc1] 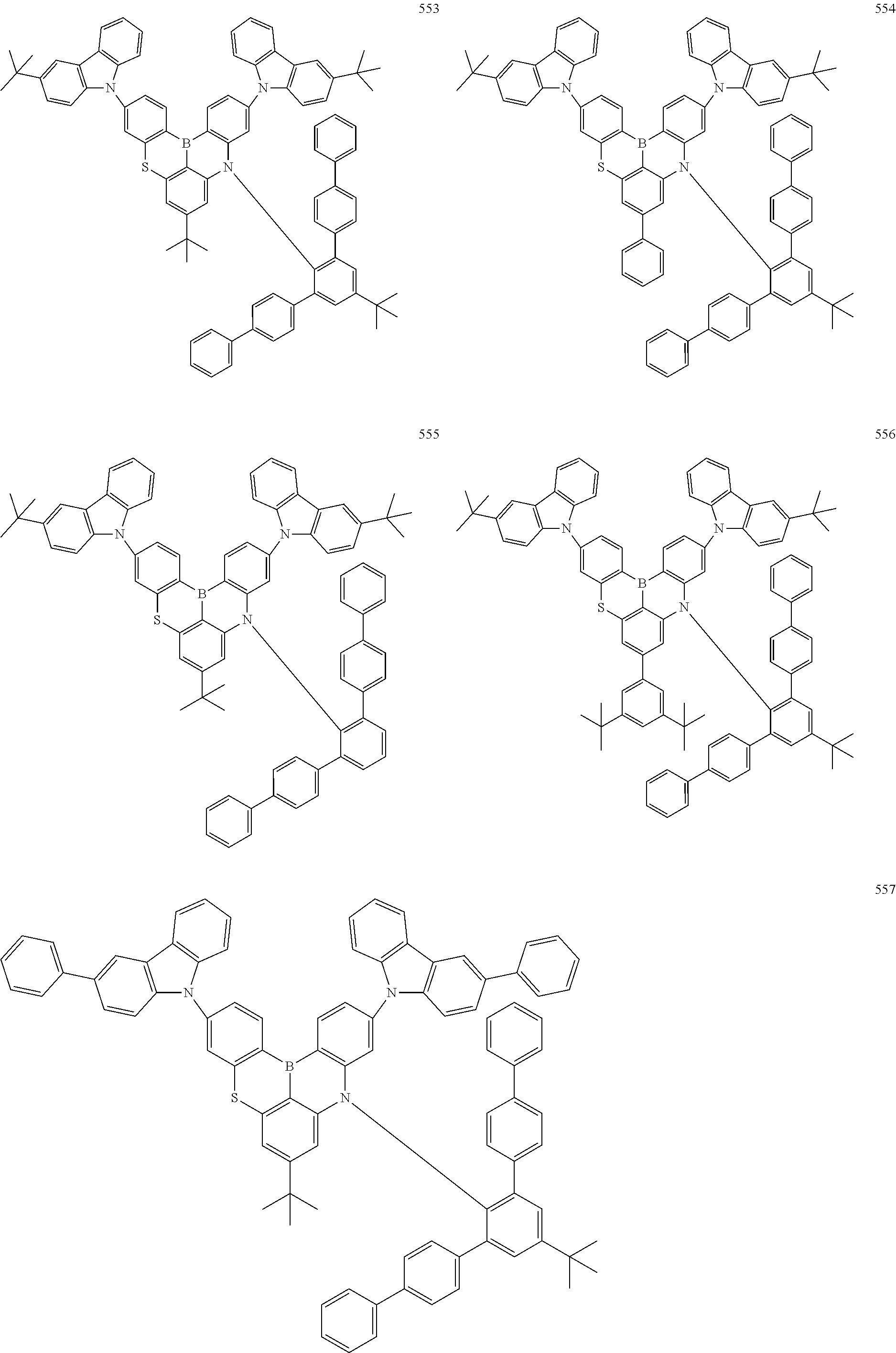 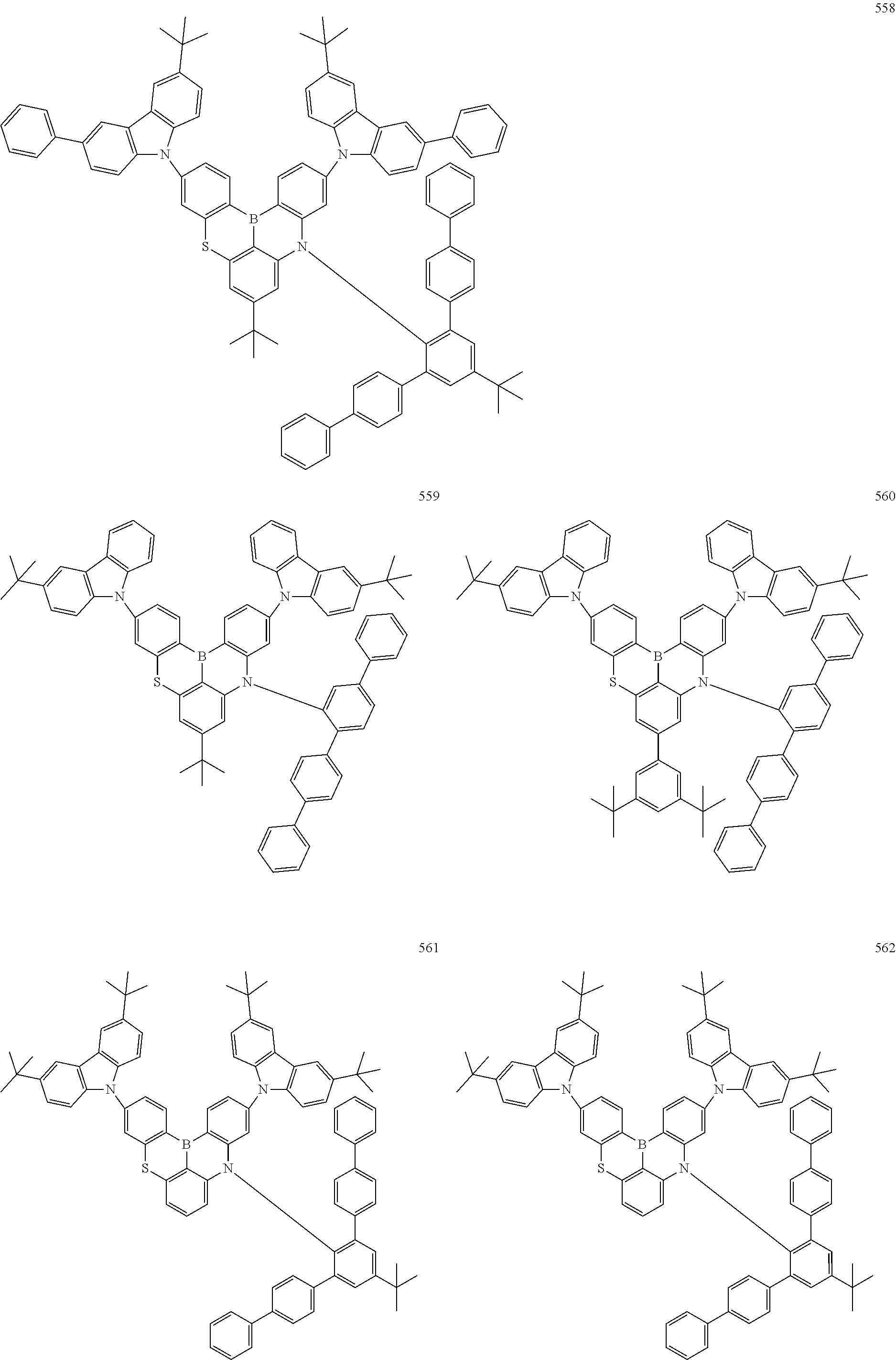 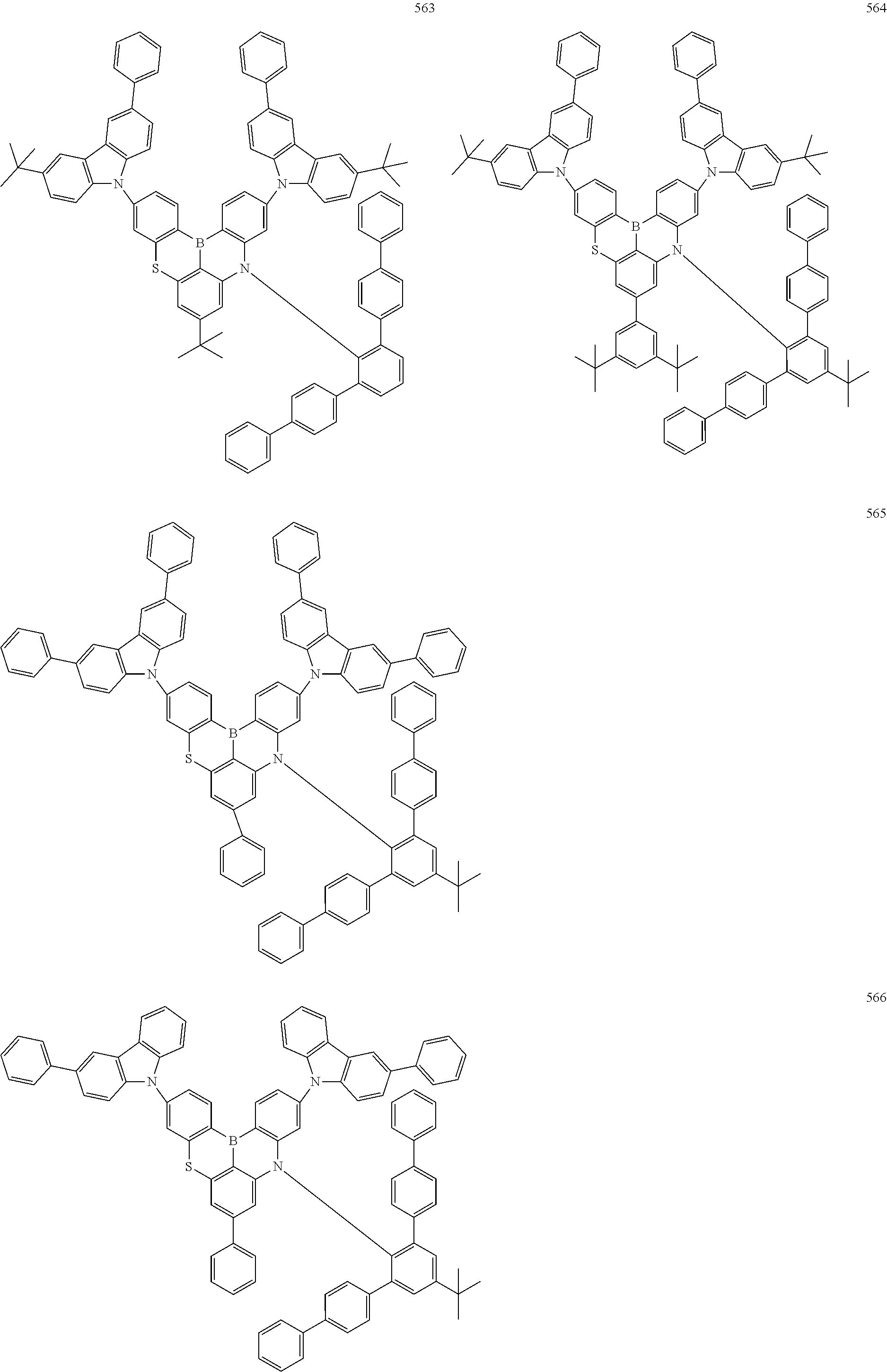 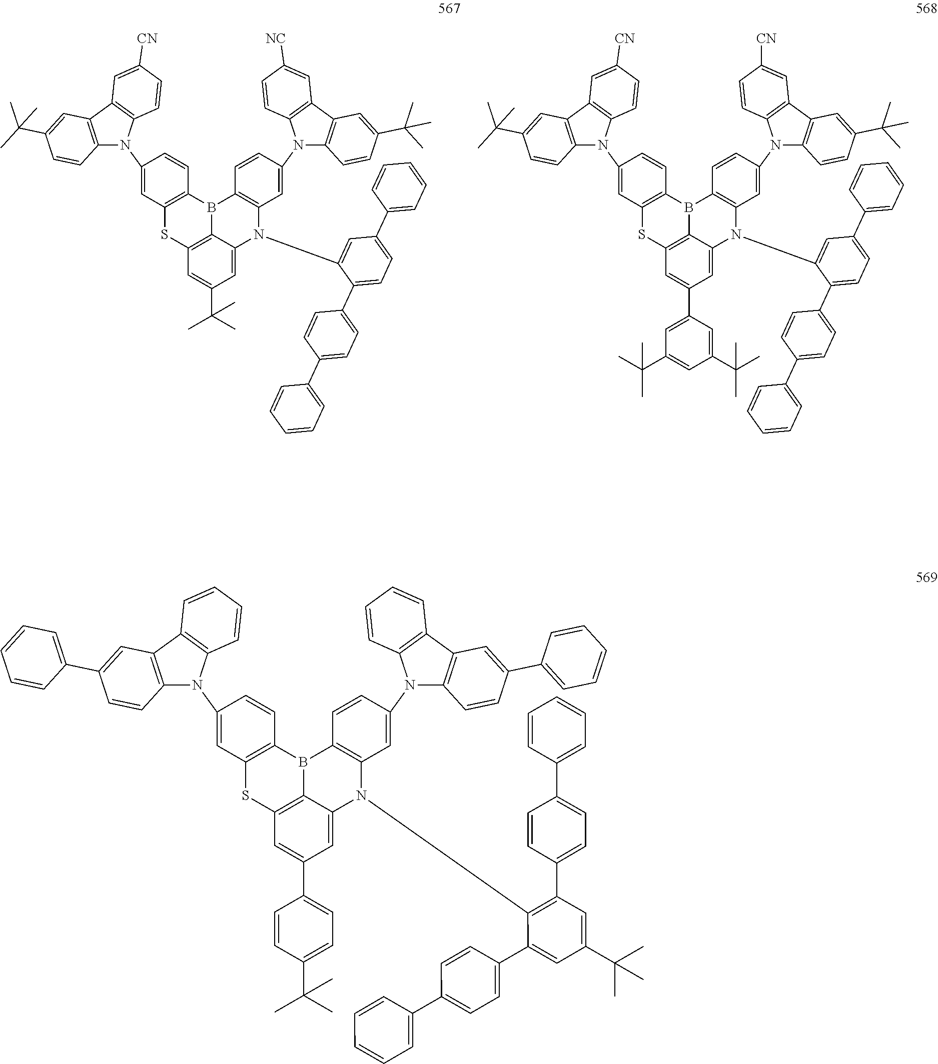 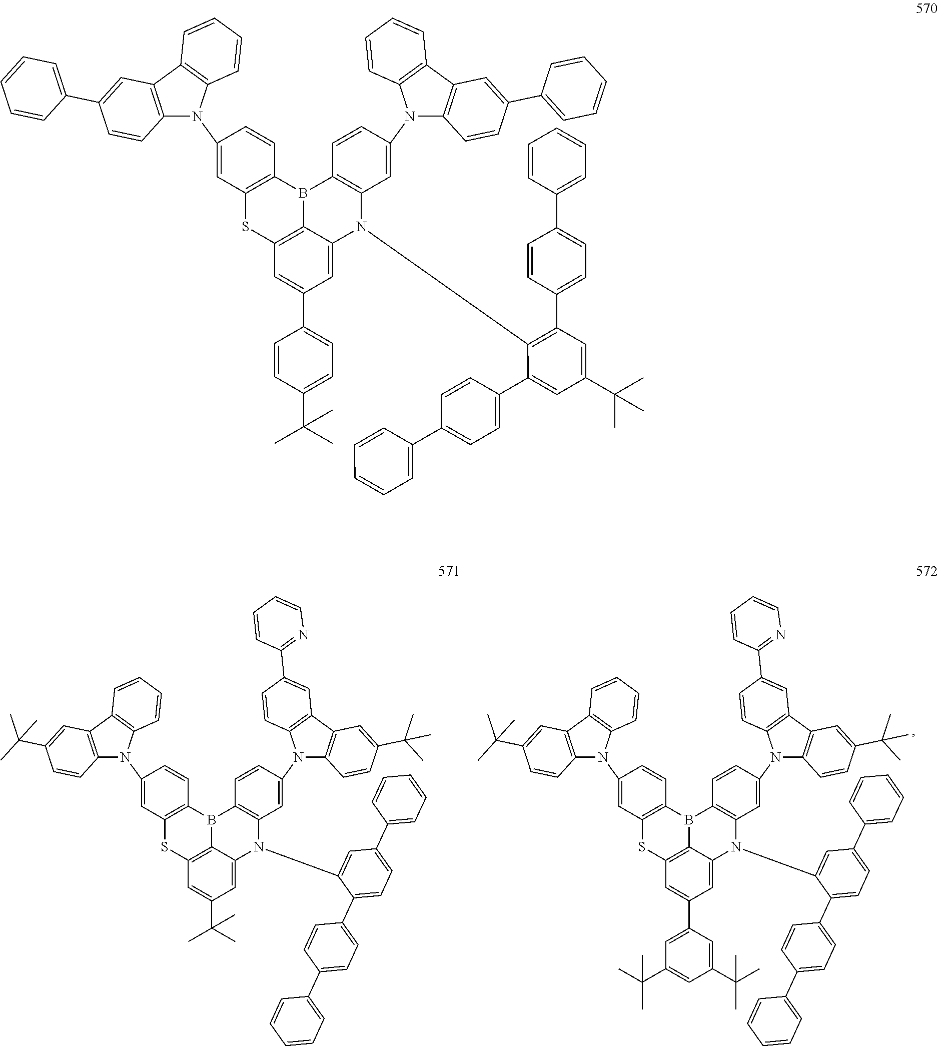
in particular example compounds presented in Compound Group 1, D being deuterium.

19. An electronic apparatus, comprising:
a base layer;
a circuit layer on the base layer; and
a display element layer on the circuit layer, and comprising a light emitting element,
wherein the light emitting element comprises a first electrode, a second electrode on the first electrode, and an emission layer between the first electrode and the second electrode and comprising a first compound represented by Formula 1: 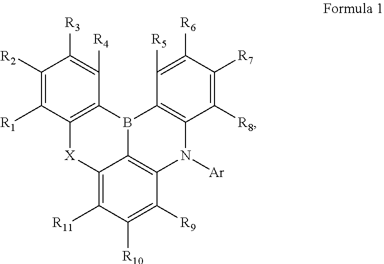
wherein, in Formula 1,
X is O, S, or NR₁₂,
R₁ to R₁₁ are each independently hydrogen, deuterium, a halogen, a cyano group, a hydroxyl group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
R₁₂ is a substituted or unsubstituted aryl group having 6 to 30 ring-forming carbon atoms or a substituted or unsubstituted heteroaryl group having 2 to 30 ring-forming carbon atoms, and when R₁₂ is a substituted or unsubstituted heteroaryl group having 2 to 30 ring-forming carbon atoms, then R₁₂ does not comprise two or more of any one selected from among a dibenzofuran moiety, a dibenzothiophene moiety, and a carbazole moiety, and
Ar is a substituent represented by Formula 2: 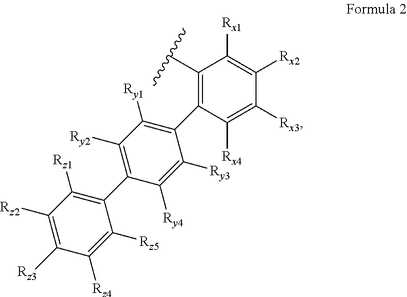
and
wherein, in Formula 2,
Rₓ₁ to Rₓ₄ are each independently hydrogen, deuterium, a halogen, a cyano group, a hydroxyl group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
at least one selected from among Rₓ₁ to Rₓ₃ is a substituted or unsubstituted aryl group having 6 to 30 ring-forming carbon atoms or a substituted or unsubstituted heteroaryl group having 2 to 30 ring-forming carbon atoms,
R_{y1} to R_{y4} and Rz to R_{z5} are each independently hydrogen, deuterium, a halogen, a cyano group, a hydroxyl group, a substituted or unsubstituted oxy group, a substituted or unsubstituted thio group, a substituted or unsubstituted boron group, a substituted or unsubstituted silyl group, a substituted or unsubstituted amine group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or bonded to an adjacent group to form a ring, and 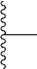
is a position to be connected to Formula 1.

20. The electronic apparatus of claim 19, wherein the electronic apparatus is at least one selected from among a large-size display device comprising a television, a monitor, and an outdoor billboard, and a small- and medium-size display device comprising a personal computer, a laptop computer, a personal digital assistant, a vehicular display device, a game console, a portable electronic device, and a camera.
